(19) United States
(12) Patent Application Publication
(10) Pub. No.: US 2026/0314262 A1
(43) Pub. Date: Oct. 8, 2026

(54) LIGHT-EMITTING ELEMENT, FUSED POLYCYCLIC COMPOUND FOR THE LIGHT-EMITTING ELEMENT, AND ELECTRONIC APPARATUS INCLUDING THE LIGHT-EMITTING ELEMENT

(71) Applicant: Samsung Display Co., Ltd., Yongin-si (KR)

(72) Inventor: Hirokazu KUWABARA, Yokohama-shi (JP)

(21) Appl. No.: 19/533,865

(22) Filed: Feb. 9, 2026

(30) Foreign Application Priority Data
Mar. 25, 2025 (JP) 2025-049728

(51) Int. Cl. H10K 85/60; C07F 5/02; C09K 11/02; C09K 11/06; H10K 50/12; H10K 85/30

(52) U.S. Cl. CPC H10K 85/658; C07F 5/027; C09K 11/02; C09K 11/06; H10K 85/346; H10K 85/6572; C09K 2211/1007; C09K 2211/1018; H10K 50/12

(57) ABSTRACT

A light-emitting element may include a first electrode, a second electrode on the first electrode, and an emission layer between the first electrode and the second electrode. The emission layer may include a first compound represented by Formula 1. The light-emitting element may exhibit long lifespan properties.

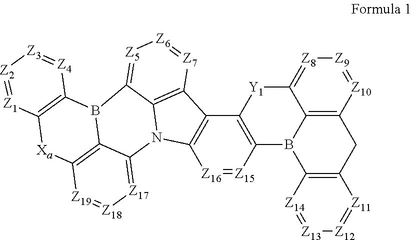

### CROSS-REFERENCE TO RELATED APPLICATION

The present application claims priority to and the benefit of Japanese Patent Application No. 2025-049728, filed on Mar. 25, 2025, in the Japan Patent Office, the entire content of which is incorporated herein by reference.

### BACKGROUND

### 1. Field

One or more embodiments of the present disclosure relate to a light-emitting element, a fused polycyclic compound used in the light-emitting element, and an electronic apparatus including the light-emitting element.

### 2. Description of the Related Art

As image-displaying devices, organic electroluminescence display devices have been actively developed. The organic electroluminescence display devices are display devices that include self-luminous-type (kind) light-emitting elements (e.g., organic light emitting elements), which recombine, in an emission layer, holes and electrons respectively injected from a first electrode and a second electrode, thereby causing emission materials in the emission layer to emit light to implement displaying.

For application of light-emitting elements to display devices, improvements or enhancements in lifespan and/or the like are desired or required, and development of materials for light-emitting elements, which may stably achieve the improvements or enhancements, is increasingly desired or demanded.

### SUMMARY

One or more aspects of embodiments of the present disclosure are directed toward a light-emitting element exhibiting long lifespan properties and an electronic apparatus including the light-emitting element.

One or more aspects of embodiments of the present disclosure are directed toward a fused polycyclic compound which is a material to improve or enhance a lifespan of a light-emitting element.

Additional aspects of embodiments will be set forth in part in the description which follows and, in part, will be apparent from the description or may be learned by practice of the presented embodiments of the disclosure.

One or more embodiments of the present disclosure provide a light-emitting element including a first electrode, a second electrode arranged on the first electrode, and an emission layer arranged between the first electrode and the second electrode and including a first compound represented by Formula 1.

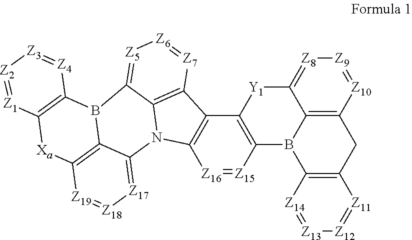

In Formula 1, Xₐ, X_{b}, and Y₁ may each independently be O, S, or NRₓ, Z₁ to Z₁₉ may each independently be N or CR_{y}, Rₓ and R_{y} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be (e.g., may be optionally) bonded to an adjacent group to form a ring, and the first compound may include a structure in which any hydrogen atom in a molecule is substituted with a deuterium atom (e.g., the first compound may include a chemical structure in which one or more hydrogen atoms of the first compound are optionally substituted with deuterium atom).

In one or more embodiments, the emission layer may further include at least one selected from among a second compound represented by Formula HT-1, a third compound represented by Formula ET-1, and a fourth compound represented by Formula D-1:

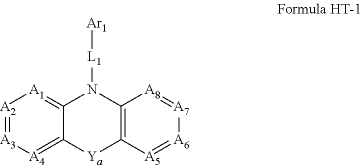

In Formula HT-1, A₁ to A₈ may each independently be N or CR₅₁, L₁ may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms, Ya may be a direct linkage (e.g., a single covalent bond), CR₅₂R₅₃, or SiR₅₄R₅₅, Ar₁ may be a substituted or unsubstituted aryl group having 6 to 30 ring-forming carbon atoms or a substituted or unsubstituted heteroaryl group having 2 to 30 ring-forming carbon atoms, R₅₁ to R₅₅ may each independently be a hydrogen atom, a deuterium atom, a halogen atom (e.g., F, Cl, Br, or I), a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring.

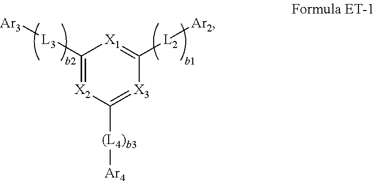

In Formula ET-1, at least one selected from among X₁ to X₃ may be N, and the others may be CR₅₆, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, L₂ to L₄ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms.

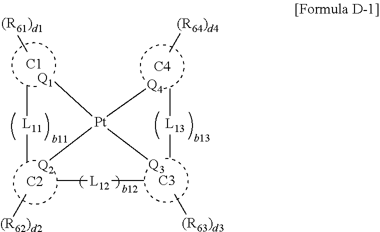

In Formula D-1, Q₁ to Q₄ may each independently be C or N, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, L₁₁ to L₁₃ may each independently be a direct linkage (e.g., a single covalent bond), *—O—*, *—S—*,

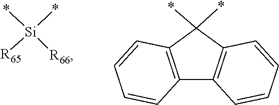

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be a hydrogen atom, a deuterium atom, a halogen atom (e.g., F, Cl, Br, or I), a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, Formula 1 may be represented by Formula 2.

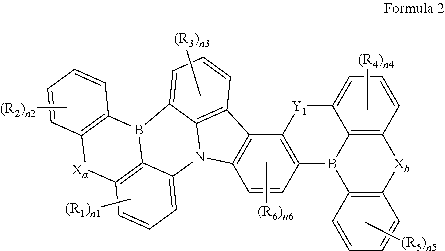

In Formula 2, R₁ to R₆ may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, n1, n3, and n4 may each independently be an integer of 0 to 3, n2 and n5 may each independently be an integer of 0 to 4, n6 may be an integer of 0 to 2, and Xₐ, X_{b}, and Y₁ may each independently be the same as defined in Formula 1.

Formula 2 may be represented by any one selected from among Formula 2-1 to Formula 2-8.

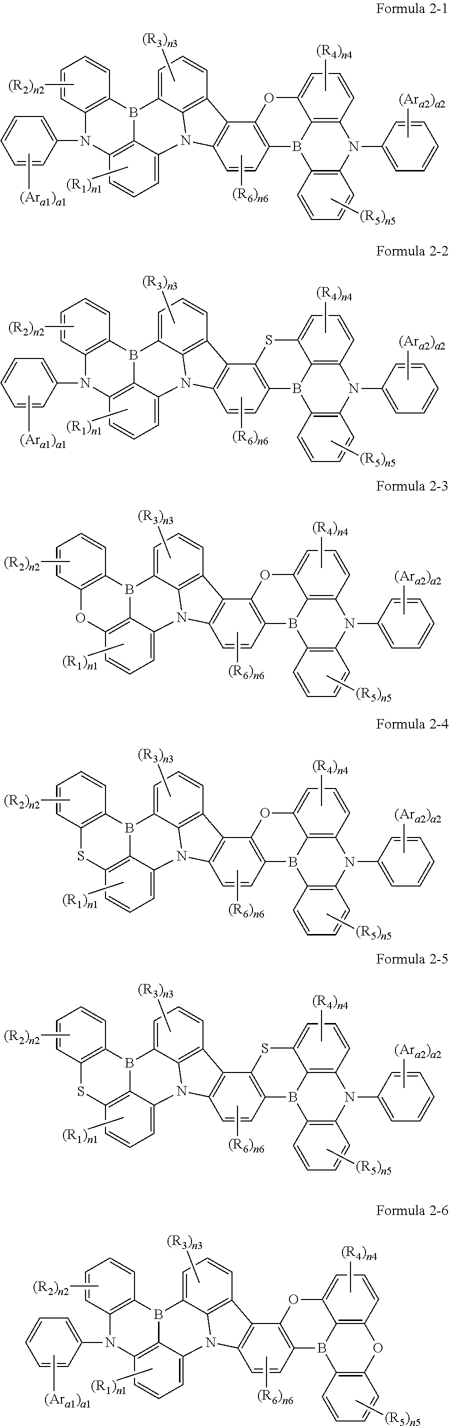

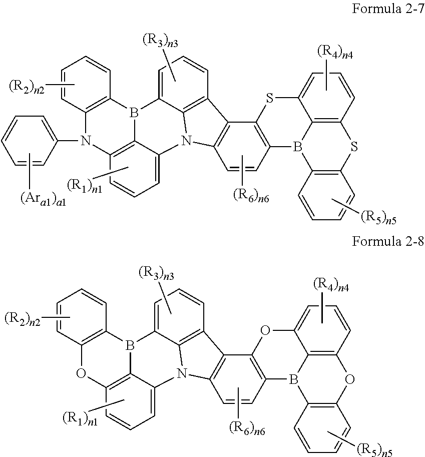

In Formula 2-1 to Formula 2-8, Arₐ₁ and Arₐ₂ may each independently be a hydrogen atom, a deuterium atom, a substituted or unsubstituted alkyl group having 1 to 20 carbon atoms, a substituted or unsubstituted cycloalkyl group having 3 to 10 ring-forming carbon atoms, or a substituted or unsubstituted aryl group having 6 to 30 ring-forming carbon atoms, and/or may be bonded to an adjacent group to form a ring, a1 and a2 may each independently be an integer of 0 to 5, and R₁ to R₆ and n1 to n6 may each independently be the same as defined in Formula 2.

In one or more embodiments, Formula 2 may be represented by Formula 3.

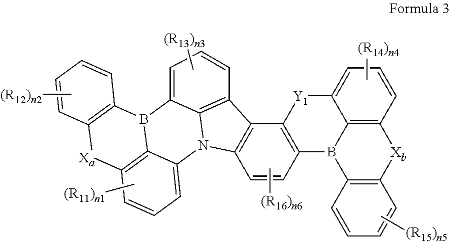

In Formula 3, R₁₁ to R₁₅ may each independently be a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, R₁₆ may be a hydrogen atom or a deuterium atom, n16 may be an integer of 0 to 2, Xₐ, X_{b}, and Y₁ may each independently be the same as defined in Formula 1, and n1 to n5 may each independently be the same as defined in Formula 2.

In one or more embodiments, Formula 2 may be represented by Formula 4.

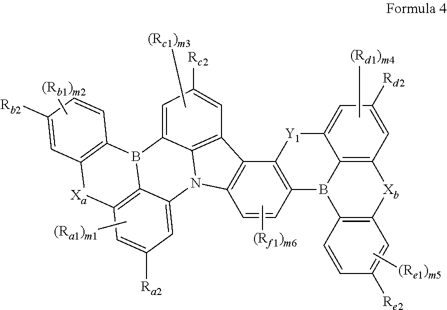

In Formula 4, Rₐ₁, R_{b1}, R_{c1}, R_{d1}, Rₑ₁, and R_{f1} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, Rₐ₂, R_{b2}, R_{c2}, R_{d2}, and Rₑ₂ may each independently be a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, m1, m3, and m4 may each independently be an integer of 0 to 2, m2 and m5 may each independently be an integer of 0 to 3, m6 may be an integer of 0 to 2, and Xₐ, X_{b}, and Y₁ may each independently be the same as defined in Formula 1.

In one or more embodiments, R₁ to R₆ in Formula 2 may each independently be a hydrogen atom or a deuterium atom, or may be represented by any one selected from among R-1 to R-14:

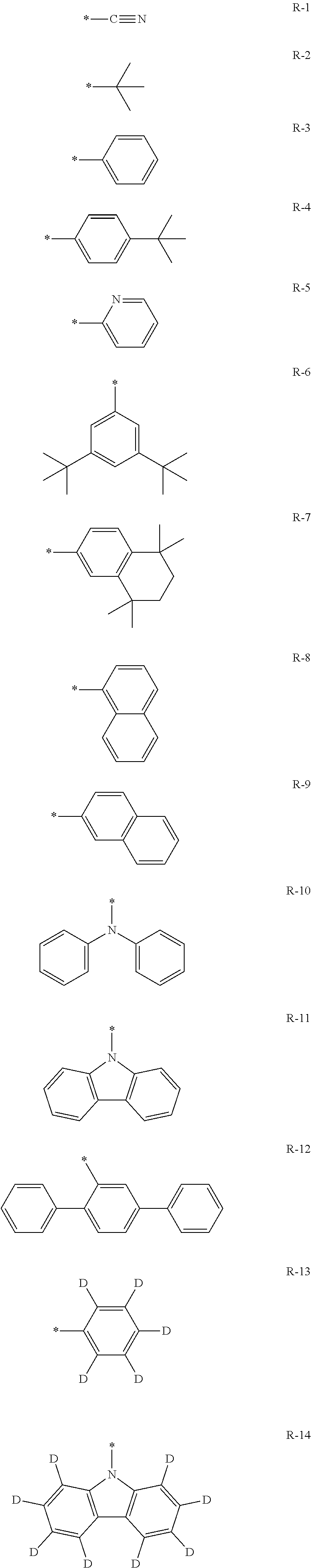

In R-13 and R-14, D is a deuterium atom.

In one or more embodiments, in Formula 1, Rₓ may be a hydrogen atom, a deuterium atom, a substituted or unsubstituted phenyl group, a substituted or unsubstituted benzocyclohexyl group, a substituted or unsubstituted biphenyl group, a substituted or unsubstituted terphenyl group, or a substituted or unsubstituted quarterphenyl group.

In one or more embodiments, in Formula 1, Rₓ may each independently be represented by any one selected from among W-1 to W-14:

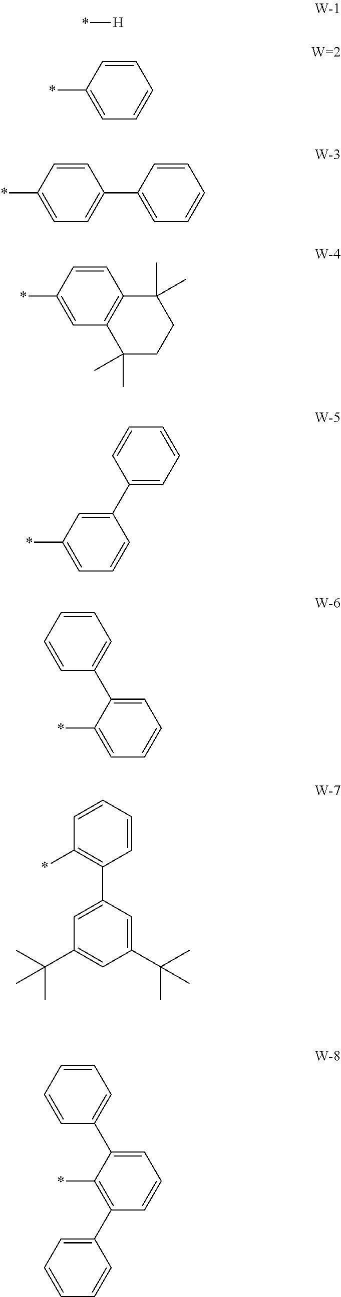

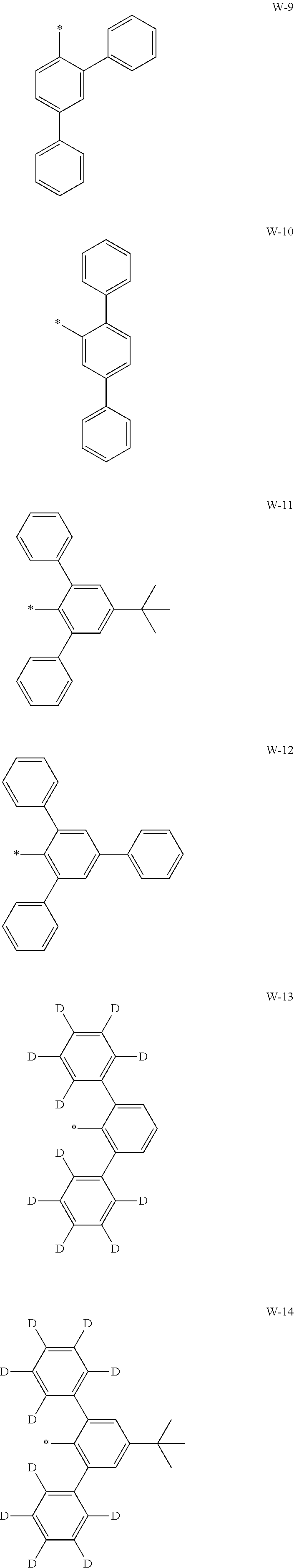 [SMILES: *c1ccc(-c2ccccc2)cc1-c1ccccc1 ; *c1cc(-c2ccccc2)ccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2c([2H])c([2H])c([2H])c([2H])c2[2H])cccc1-c1c([2H])c([2H])c([2H])c([2H])c1[2H] ; *c1c(-c2c([2H])c([2H])c([2H])c([2H])c2[2H])cc(C(C)(C)C)cc1-c1c([2H])c([2H])c([2H])c([2H])c1[2H]]

In W-13 and W-14, D is a deuterium atom.

In one or more embodiments of the present disclosure, a fused polycyclic compound may be represented by Formula 1.

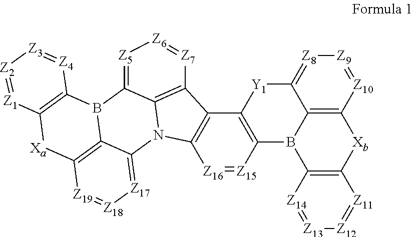

In Formula 1, Xₐ, X_{b}, and Y₁ may each independently be O, S, or NRₓ, Z₁ to Z₁₉ may each independently be N or CR_{y}, Rₓ and R_{y} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, and the fused polycyclic compound may include a structure in which any hydrogen atom in a molecule is substituted with a deuterium atom (e.g., the fused polycyclic compound may include a chemical structure in which one or more hydrogen atoms of the fused polycyclic compound are optionally substituted with deuterium atom).

In one or more embodiments of the present disclosure, an electronic apparatus may include a display device to provide an image, the display device may include a base layer, a circuit layer arranged on the base layer, and a display element layer arranged on the circuit layer and including a light-emitting element, the light-emitting element may include a first electrode, a second electrode arranged on the first electrode, and an emission layer arranged between the first electrode and the second electrode, and the emission layer may include a fused polycyclic compound represented by Formula 1.

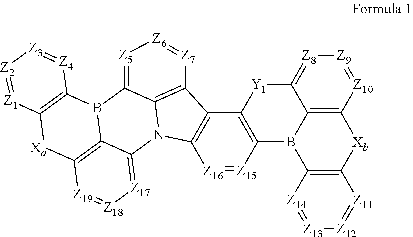

In Formula 1, Xₐ, X_{b}, and Y₁ may each independently be O, S, or NRₓ, Z₁ to Z₁₉ may each independently be N or CR_{y}, Rₓ and R_{y} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring, and the fused polycyclic compound may include a structure in which any hydrogen atom in a molecule is substituted with a deuterium atom (e.g., the fused polycyclic compound may include a chemical structure in which one or more hydrogen atoms of the fused polycyclic compound are optionally substituted with deuterium atom).

In one or more embodiments, the electronic apparatus may further include at least one selected from among a processor, a memory, and a power module.

For example, in one or more embodiments, a light-emitting element is provided wherein an emission layer includes a fused polycyclic compound represented by Formula 1 (optionally embodied by Formulae 2 to 4 and by compounds selected from Compound Group 1), the variables being as defined in this specification, and wherein the compound may include at least one deuterium atom. In one or more embodiments, the emission layer further comprises host materials selected from compounds represented by Formula HT-1 and Formula ET-1 and a sensitizer represented by Formula D-1, and the element is arranged in a stack including a first electrode, a hole-transport region, the emission layer, an electron-transport region, and a second electrode. The disclosure also provides electronic apparatuses having a display element layer that includes such light-emitting elements. These embodiments collectively place the compositions, device architectures, and system implementations in cohesive context, demonstrate blue-emmission performance with improved or enhanced material stability and service life.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a plan view illustrating a display device according to one or more embodiments;

FIG. 2 is a cross-sectional view illustrating a portion taken along the line I-I′ in FIG. 1;

FIG. 3 is a cross-sectional view schematically illustrating a light-emitting element according to one or more embodiments;

FIG. 4 is a cross-sectional view schematically illustrating a light-emitting element according to one or more embodiments;

FIG. 5 is a cross-sectional view schematically illustrating a light-emitting element according to one or more embodiments;

FIG. 6 is a cross-sectional view schematically illustrating a light-emitting element according to one or more embodiments;

FIG. 7 is a cross-sectional view illustrating a display device according to one or more embodiments;

FIG. 8 is a cross-sectional view illustrating a display device according to one or more embodiments;

FIG. 9 is a cross-sectional view illustrating a display device according to one or more embodiments;

FIG. 10 is a cross-sectional view illustrating a display device according to one or more embodiments;

FIG. 11 is a view illustrating an interior of a vehicle in which display devices according to one or more embodiments are arranged.

FIG. 12 is a perspective view illustrating an electronic apparatus according to one or more embodiments;

FIG. 13 is an exploded perspective view illustrating an electronic apparatus according to one or more embodiments;

FIG. 14 is a block diagram of an electronic apparatus according to one or more embodiments; and

FIG. 15 illustrates schematic views of electronic apparatuses according to one or more embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that if (e.g., when) an element (or a region, a layer, a portion, and/or the like) is referred to as being “on,” “above” “connected to,” or “coupled to” another element, it may be directly on, directly above, directly connected to, or directly coupled to the other element, or intervening elements may be arranged therebetween. In contrast, if (e.g., when) an element is referred to as being “directly on” or “directly above” another element, there are no intervening elements present therebetween.

In the drawings, the thickness, the ratio, and the size of the element may be exaggerated for effective description of the technical contents.

As used herein, the term “and/or” includes any and all combinations of one or more of the associated listed items.

It will be understood that, although the terms “first,” “second,” and/or the like may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section described herein may be termed a second element, component, region, layer, or section without departing from the scope of the present disclosure. Similarly, a second element, component, region, layer, or section may be termed a first element, component, region, layer, or section.

As used herein, the singular forms, “a,” “an,” and “the” are intended to include the plural forms as well, unless the context clearly indicates otherwise.

Also, the terms “below,” “on lower side,” “above,” “on upper side,” and/or the like may be used to describe the relationships of the elements illustrated in the drawings. These terms have relative concepts and are described on the basis of the directions indicated in the drawings.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

Unless otherwise defined, all terms (including technical and scientific terms) used herein have substantially the same meaning as generally understood by one of ordinary skill in the art to which the present disclosure belongs. It will be further understood that terms, such as those defined in generally used dictionaries, should be interpreted as having a meaning that is consistent with their meaning in the context of the relevant art and will not be interpreted in an idealized or overly formal sense unless expressly so defined herein.

In the present disclosure, the term “substituted or unsubstituted” may refer to substituted or unsubstituted with at least one substituent selected from the group consisting of a deuterium atom, a halogen atom (e.g., F, Cl, Br, or I), a cyano group, a nitro group, an amine group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the substituents exemplified herein may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may be monocyclic or polycyclic. In one or more embodiments, the rings formed by being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the present disclosure, examples of the halogen atom may include a fluorine atom, a chlorine atom, a bromine atom, or an iodine atom.

In the present disclosure, the alkyl group may be linear or branched. The number of carbons in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 60, 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not limited, but may be 2 to 60, 2 1 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, the hydrocarbon ring group refers to any functional group or substituent derived from an aliphatic hydrocarbon ring. The number of ring-forming carbon atoms in the hydrocarbon ring group may be 5 to 60, 5 to 30, or 5 to 20.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, the fluorenyl group may be substituted, and two substituents may be bonded to each other to form a spiro structure. Examples of the substituted fluorenyl group are as follows. However, embodiments of the present disclosure are not limited thereto.

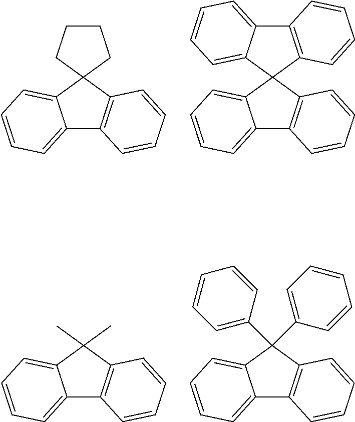

The heterocyclic group herein refers to any functional group or substituent derived from a ring containing at least one of B, O, N, P, Si, or S as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 60, 2 to 30, 2 to 20, or 2 to 10.

In the present disclosure, the aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, the heteroaryl group may contain at least one of B, O, N, P, Si, S or Se as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the description of the aryl group herein may be applied to an arylene group except that the arylene group is a divalent group. The description of the heteroaryl group herein may be applied to a heteroarylene group except that the heteroarylene group is a divalent group.

In the present disclosure, the silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the present disclosure, the number of ring-forming carbon atoms in the carbonyl group is not limited, but may be 1 to 40, 1 to 30, or 1 to 20. For example, the carbonyl group may have the following structures, but embodiments of the present disclosure are not limited thereto.

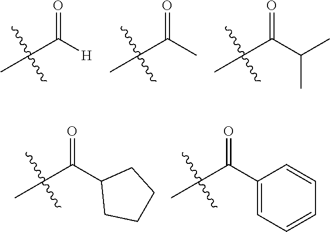

In the present disclosure, the number of carbon atoms in the sulfinyl group and the sulfonyl group is not limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, the thio group may include an alkylthio group and/or an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but embodiments of the present disclosure are not limited thereto.

In the present disclosure, an oxy group may refer to that an oxygen atom is bonded to the alkyl group or the aryl group as defined herein. The oxy group may include an alkoxy group and/or an aryl oxy group. The alkoxy group may be a linear chain, a branched chain, or a ring chain. The number of carbon atoms in the alkoxy group is not limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

The boron group herein may refer to that a boron atom is bonded to the alkyl group or the aryl group as defined herein. The boron group may include an alkyl boron group and/or an aryl boron group. Examples of the boron group may include a dimethylboron group, a diethylboron group, a t-butylmethylboron group, a diphenylboron group, a phenylboron group, and/or the like, but embodiments of the present disclosure are not limited thereto.

In the present disclosure, the number of carbon atoms in an amine group is not limited, but may be 1 to 50, 1 to 30, or 1 to 20. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto.

In the present disclosure, the alkyl group selected from among an alkylthio group, an alkylsulfoxy group, an alkylaryl group, an alkylamino group, an alkyl boron group, an alkyl silyl group, an alkyl amine group, and an alkyl selenium group is the same as the examples of the alkyl group described herein.

In the present disclosure, the aryl group selected from among an aryloxy group, an arylthio group, an arylsulfoxy group, an arylamino group, an arylboron group, an arylsilyl group, and an arylamine group is the same as the examples of the aryl group described herein.

In the present disclosure, a direct linkage may refer to a single bond (e.g., a single covalent bond). In the present disclosure,

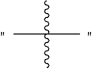

and “—*” refer to a position to be connected.

Hereinafter, one or more embodiments of the present disclosure will be described in more detail with reference to the accompanying drawings.

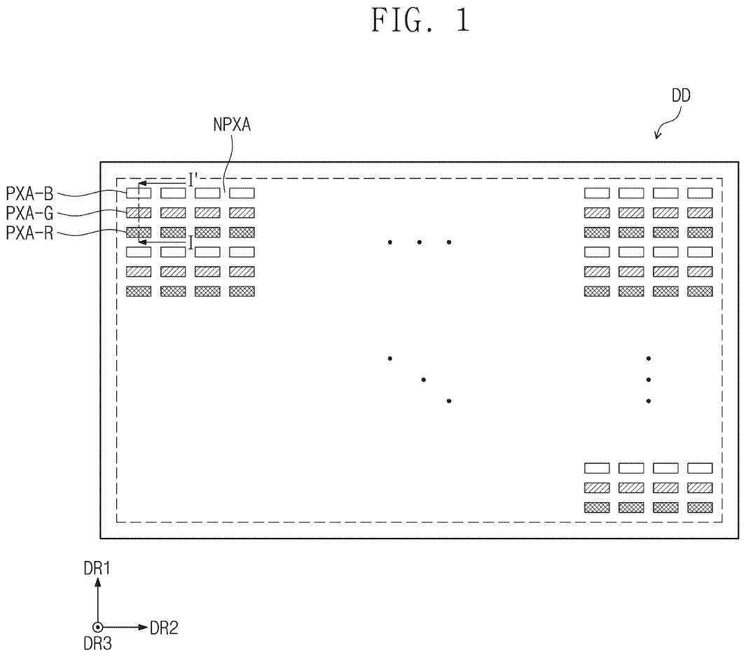

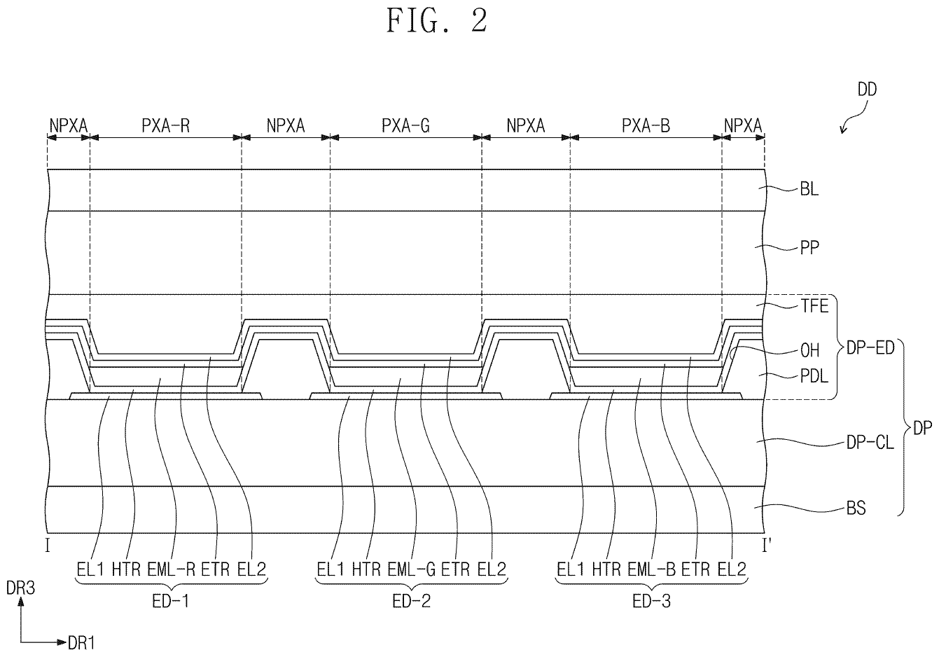

FIG. 1 is a plan view illustrating one or more embodiments of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer or a color filter layer. In one or more embodiments, unlike the configuration or arrangement illustrated in the drawing, the optical layer PP may not be provided in the display device DD of one or more embodiments.

A base substrate BL may be arranged on the optical layer PP. The base substrate BL may be a member which provides a base surface on which the optical layer PP is arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, unlike the configuration or arrangement illustrated, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 arranged between portions of the pixel defining film PDL, and an encapsulation layer TFE arranged on the light emitting elements ED-1, ED-2, and ED-3.

The base layer BS may be a member which provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. Each of the transistors may include a control electrode, an input electrode, and an output electrode. For example, the circuit layer DP-CL may include a switching transistor and a driving transistor to drive the light emitting elements ED-1, ED-2, and ED-3 of the display element layer DP-ED.

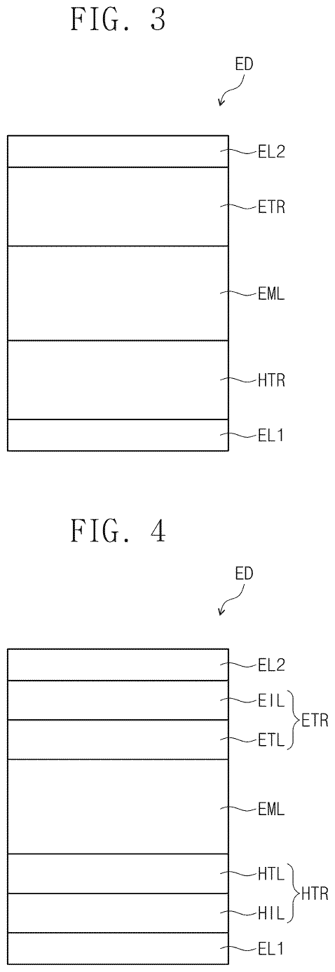

Each of the light emitting elements ED-1, ED-2, and ED-3 may have a structure of each light emitting element ED of one or more embodiments according to FIGS. 3 to 6, which will be described herein in more detail. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are arranged in openings OH defined in the pixel defining film PDL, and the hole transport region HTR, the electron transport region ETR, and the second electrode EL2 are provided as a common layer in the entire (e.g., almost entire) light emitting elements ED-1, ED-2, and ED-3. However, embodiments of the present disclosure are not limited thereto, and unlike the configuration or arrangement illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation (e.g., electrical insulation) layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film may be to protect the display element layer DP-ED from moisture/oxygen, and the encapsulation-organic film may be to protect the display element layer DP-ED from foreign substances, such as dust particles. The encapsulation-inorganic film may include silicon nitride, silicon oxynitride, silicon oxide, titanium oxide, aluminum oxide, and/or the like, but embodiments of the present disclosure are not limited thereto. The encapsulation-organic film may include an acrylic-based compound, an epoxy-based compound, and/or the like. The encapsulation-organic film may include a photopolymerizable organic material, but embodiments of the present disclosure are not limited thereto.

The encapsulation layer TFE may be arranged on the second electrode EL2 and may be arranged to fill the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from each other on a plane (e.g., in plan view).

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2, and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In one or more embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas if (e.g., when) viewed on a plane (e.g., in plan view) defined by the first directional axis DR1 and the second directional axis DR2 (e.g., in plan view).

In one or more embodiments, an arrangement form of the light emitting regions PXA-R, PXA-G, and PXA-B is not limited to the configuration or arrangement illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, the arrangement form of the light emitting regions PXA-R, PXA-G, and PXA-B may be a PENTILE® arrangement structure (e.g., an RGBG matrix, an RGBG structure, or an RGBG matrix structure) or a DIAMOND PIXEL™ arrangement structure (e.g., a display (e.g., an OLED display) containing red, blue, and green (RGB) emission regions arranged in the shape of diamonds). PENTILE® is a duly registered trademark of Samsung Display Co., Ltd. DIAMOND PIXEL™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than the area of the blue light emitting region PXA-B, but embodiments of the present disclosure are not limited thereto.

Hereinafter, FIG. 3 to FIG. 6 are cross-sectional views schematically illustrating light emitting elements according to one or more embodiments. The light emitting element ED of one or more embodiments may include a first electrode EL1, a hole transport region HTR, an emission layer EML, an electron transport region ETR, and a second electrode EL2 stacked in order.

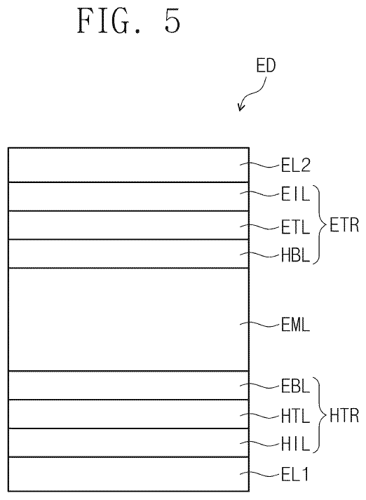

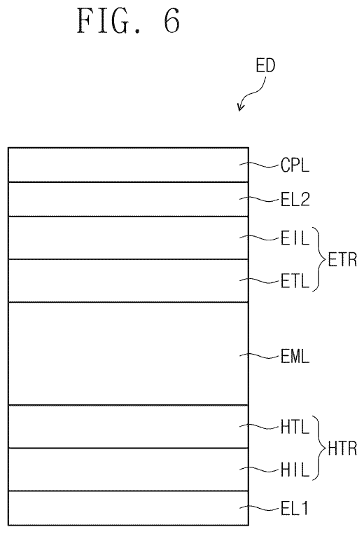

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In one or more embodiments, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments including a capping layer CPL arranged on a second electrode EL2.

The first electrode EL1 may have conductivity (e.g., the first electrode EL1 may be a conductor). The first electrode EL1 may be formed or composed of a metal material, a metal alloy, or a conductive (e.g., electrically conductive) compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is the transmissive electrode, the first electrode EL1 may include a transparent (e.g., substantially transparent) metal oxide, such as indium tin oxide (ITO), indium zinc oxide (IZO), zinc oxide (ZnO), and/or indium tin zinc oxide (ITZO). If (e.g., when) the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, or a compound or mixture thereof (e.g., a mixture of Ag and Mg). In one or more embodiments, the first electrode EL1 may have a multilayer structure including a reflective film or a transflective film formed or composed of the materials described herein, and a transparent (e.g., substantially transparent) conductive (e.g., electrically conductive) film formed or composed of ITO, IZO, ZnO, ITZO, and/or the like. For example, the first electrode EL1 may have a three-layer structure of ITO/Ag/ITO, but embodiments of the present disclosure are not limited thereto. In one or more embodiments, embodiments of the present disclosure are not limited thereto, and the first electrode EL1 may include the metal materials described herein, combinations of at least two metal materials of the metal materials described herein, oxides of the metal materials described herein, and/or the like. The thickness of the first electrode EL1 may be in the range of about 700 Å to about 10,000 Å. For example, the thickness of the first electrode EL1 may be in the range of about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, in the range of about 50 Å to about 15,000 Å.

The hole transport region HTR may have a single layer formed or composed of a single material, a single layer formed or composed of a plurality of different materials, or a multilayer structure including a plurality of layers formed or composed of a plurality of different materials.

For example, the hole transport region HTR may have a single layer structure of the hole injection layer HIL or the hole transport layer HTL, or may have a single layer structure formed or composed of a hole injection material and a hole transport material. In one or more embodiments, the hole transport region HTR may have a single layer structure formed or composed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed using one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

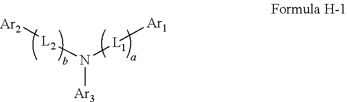

In Formula H-1, L₁ and L₂ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater (e.g., an integer of 2 to 10), a plurality of L₁'s and L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In one or more embodiments, in Formula H-i, Ar₃ may be a substituted or unsubstituted aryl group having 6 to 30 ring-forming carbon atoms or a substituted or unsubstituted heteroaryl group having 2 to 30 ring-forming carbon atoms.

The compound represented by Formula H-1 may be a monoamine compound. In one or more embodiments, the compound represented by Formula H-1 may be a diamine compound in which at least one selected from among Ar₁ to Ar₃ includes the amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

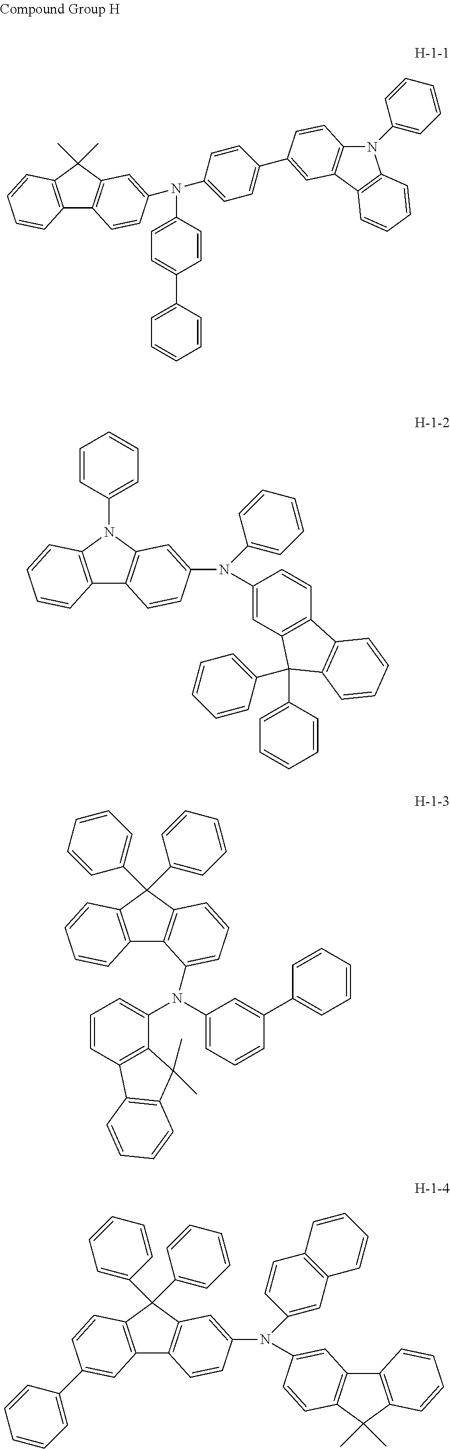 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

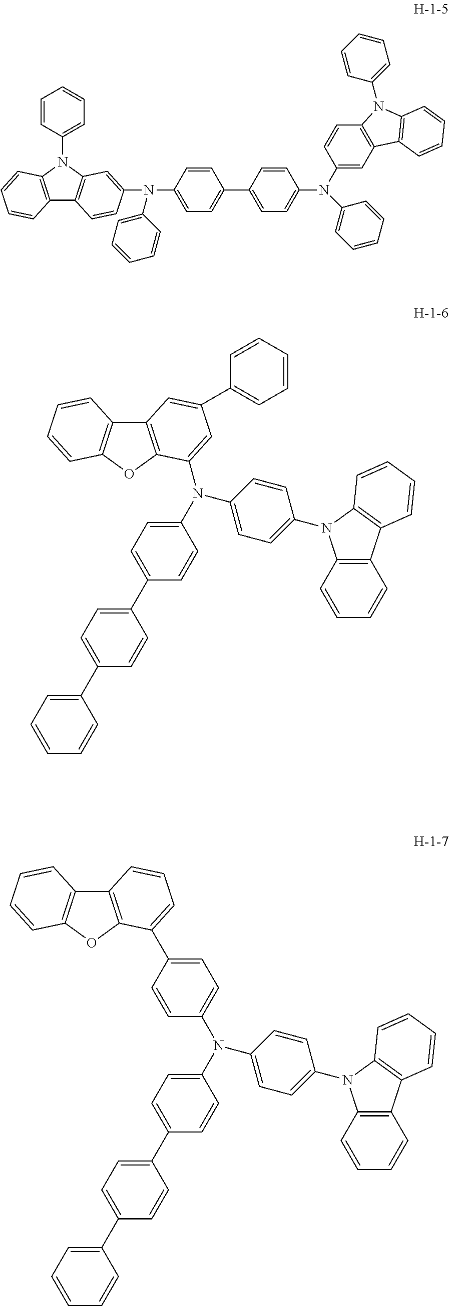 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

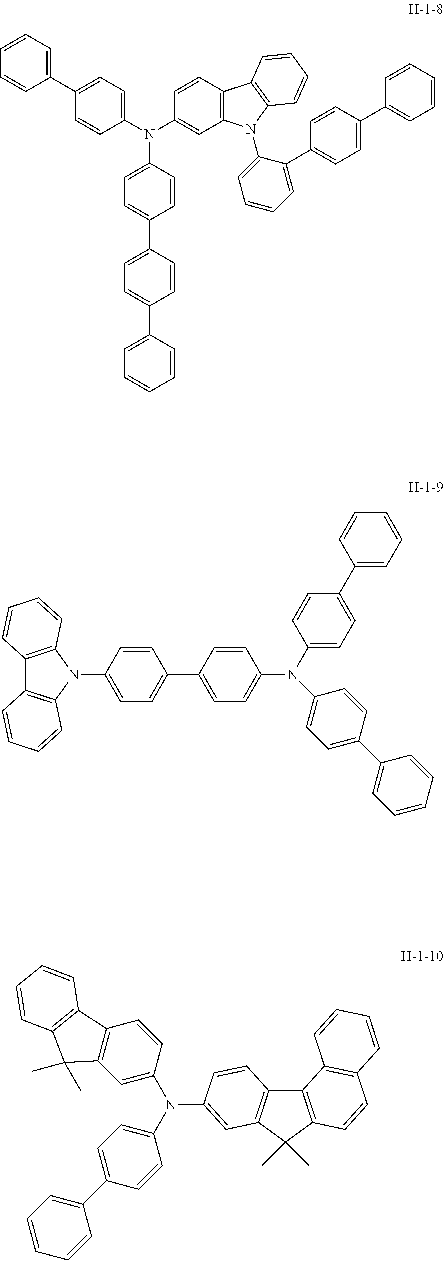 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

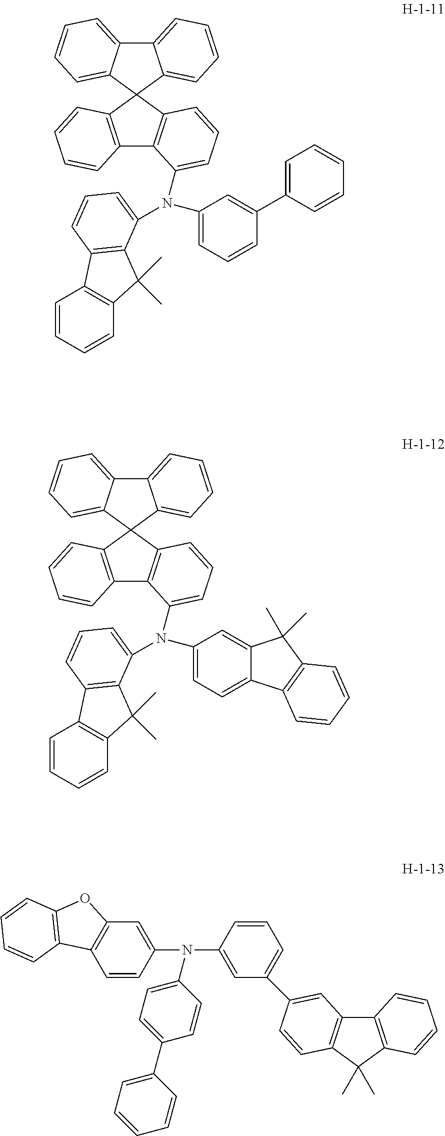 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

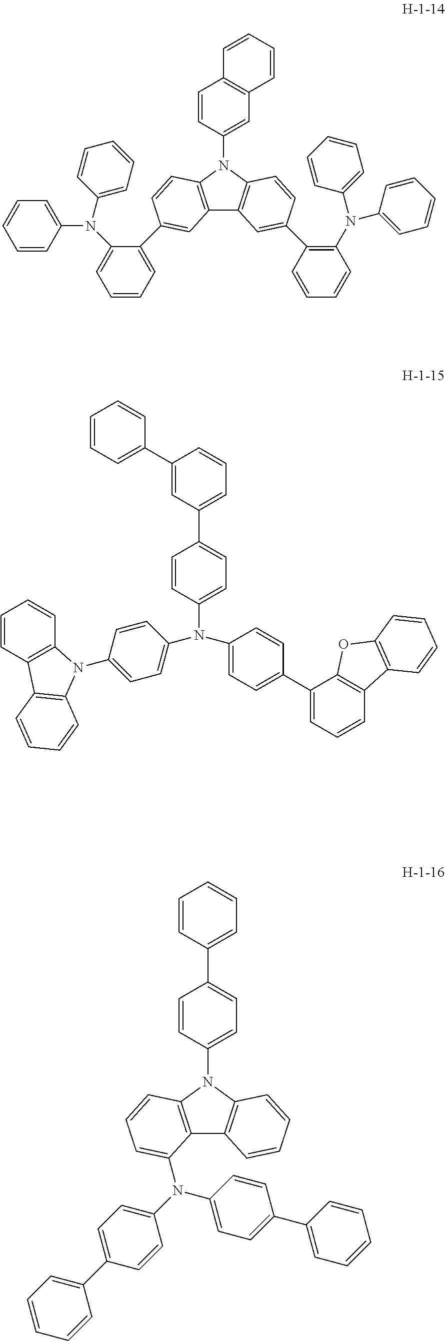 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

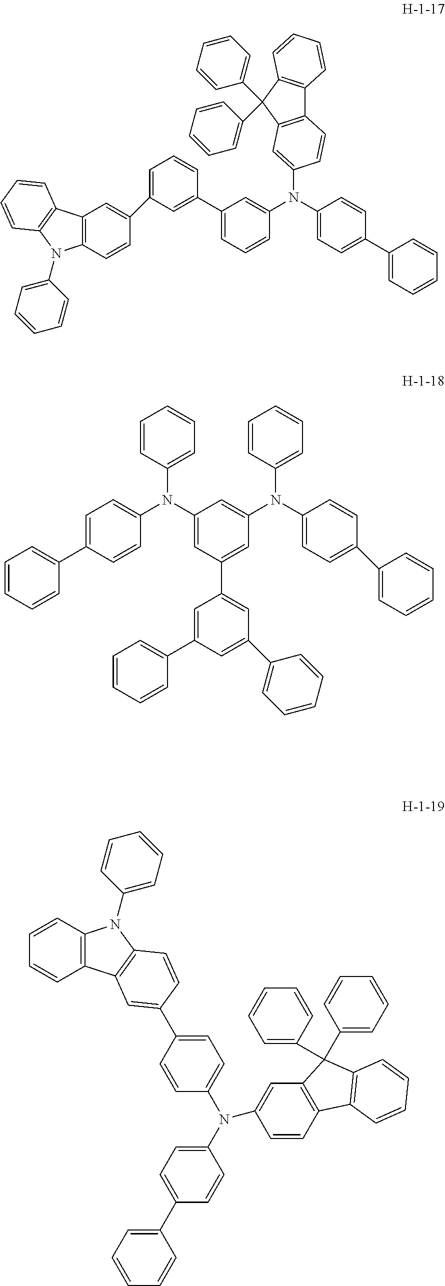 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound, such as copper phthalocyanine, N¹,N^{1′}-([1,1′-biphenyl]-4,4′-diyl)bis(N¹-phenyl-N4, N4-di-m-tolylbenzene-1,4-diamine) (DNTPD), 4,4′,4″-[tris(3-methyl phenyl)phenylamino]triphenylamine (m-MTDATA), 4,4′,4″-tris(N, N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HATCN), and/or the like.

The hole transport region HTR may include a carbazole-based derivative, such as N-phenyl carbazole and/or polyvinyl carbazole, a fluorene-based derivative, a triphenylamine-based derivative, such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the compounds of the hole transport region described herein in at least one of a hole injection layer HIL, a hole transport layer HTL, or an electron blocking layer EBL.

The thickness of the hole transport region HTR may be in the range of about 100 Å to about 10,000 Å, for example, from about 100 Å to about 5,000 Å. If (e.g., when) the hole transport region HTR includes the hole injection layer HIL, the hole injection layer HIL may have, for example, a thickness of about 30 Å to about 1,000 Å. If (e.g., when) the hole transport region HTR includes the hole transport layer HTL, the hole transport layer HTL may have a thickness of about 30 Å to about 1,000 Å. For example, if (e.g., when) the hole transport region HTR includes the electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL, and the electron blocking layer EBL satisfy the foregoing ranges, satisfactory or suitable hole transport properties may be achieved without a substantial increase in driving voltage.

The hole transport region HTR may further include a charge generating material to increase conductivity (e.g., electrical conductivity) in addition to the materials described herein. The charge generating material may be dispersed uniformly (e.g., substantially uniformly) or non-uniformly (e.g., substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound, such as CuI and/or RbI, a quinone derivative, such as tetracyanoquinodimethane (TCNQ) and/or 2,3,5,6-tetrafluoro-7,7′8,8-tetracyanoquinodimethane (F4-TCNQ), a metal oxide, such as tungsten oxide and/or molybdenum oxide, a cyano group-containing compound, such as dipyrazino[2,3-f:2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL may be a layer that serves to prevent the electron injection (or to reduce a degree or occurrence of the electron injection) from the electron transport region ETR to the hole transport region HTR.

In one or more embodiments, an emission layer EML may include a first compound according to one or more embodiments. The emission layer EML according to one or more embodiments may further include at least one selected from among second to fourth compounds. The second compound may include a fused ring with three rings, which contains a nitrogen atom as a ring-forming atom. The third compound may include a six-membered ring containing at least one nitrogen atom as a ring-forming atom. The fourth compound may include an organometallic complex. The second to fourth compounds will be described in more detail herein.

In the present disclosure, the first compound may be referred to as a fused polycyclic compound according to one or more embodiments. The fused polycyclic compound according to one or more embodiments may include, as a core structure, a fused ring with 11 rings in which a carbazole ring is fused with two or more rings. In one or more embodiments, the fused polycyclic compound according to one or more embodiments may include at least one of an oxygen atom, a sulfur atom, or a nitrogen atom as a ring-forming atom at a para-position with respect to two boron atoms in the core structure. Therefore, the fused polycyclic compound according to one or more embodiments may exhibit excellent or suitable material stability and contribute to improvements or enhancements in lifespan of the light-emitting element ED.

The light-emitting element ED may include a fused polycyclic compound according to one or more embodiments. The fused polycyclic compound according to one or more embodiments may be represented by Formula 1.

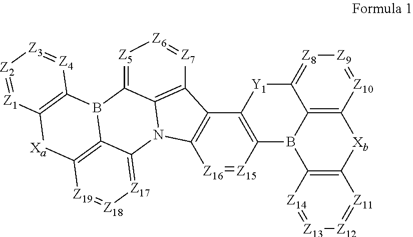

In Formula 1, Xₐ, X_{b}, and Y₁ may each independently be O, S, or NRₓ. For example, Xₐ and X_{b} may each independently be O or S, and Y₁ may be NRₓ. Xₐ and X_{b} may each independently be NRₓ, and Y₁ may be O or S. However, this is an example, and embodiments of the present disclosure are not limited thereto.

In Formula 1, Z₁ to Z₁₉ may each independently be N or CR_{y}. For example, Z₁ to Z₁₉ may each independently be CR_{y}. However, this is an example, and embodiments of the present disclosure are not limited thereto.

In Formula 1, Rₓ and R_{y} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring. For example, Rₓ and R_{y} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and may be optionally bonded to an adjacent group to form a ring. For example, Rₓ may be a hydrogen atom, a deuterium atom, a substituted or unsubstituted aryl group having 6 to 30 ring-forming carbon atoms, or a substituted or unsubstituted heteroaryl group having 3 to 30 ring-forming carbon atoms and/or may be bonded to an adjacent group to form a ring. For example, Rₓ may be a hydrogen atom, a deuterium atom, a substituted or unsubstituted phenyl group, a substituted or unsubstituted benzocyclohexyl group, a substituted or unsubstituted biphenyl group, a substituted or unsubstituted terphenyl group, or a substituted or unsubstituted quarterphenyl group. Rₓ may be represented by any one selected from among W-1 to W-14. In W-13 and W-14 D is a deuterium atom.

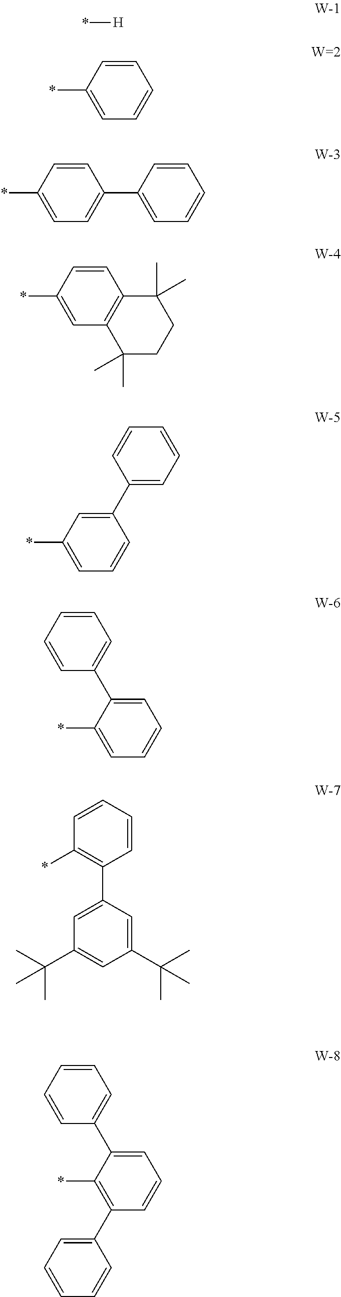

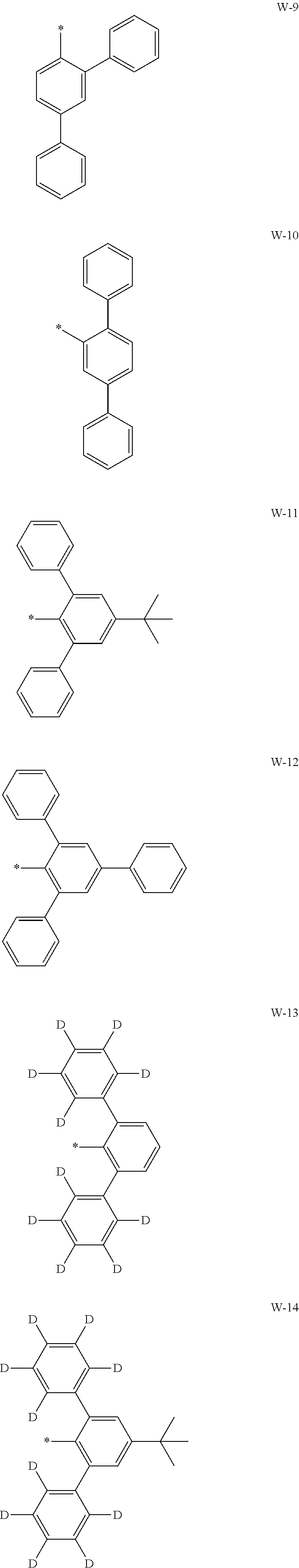 [SMILES: *c1ccc(-c2ccccc2)cc1-c1ccccc1 ; *c1cc(-c2ccccc2)ccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2c([2H])c([2H])c([2H])c([2H])c2[2H])cccc1-c1c([2H])c([2H])c([2H])c([2H])c1[2H] ; *c1c(-c2c([2H])c([2H])c([2H])c([2H])c2[2H])cc(C(C)(C)C)cc1-c1c([2H])c([2H])c([2H])c([2H])c1[2H]]

For example, R_{y} may be a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring. For example, R_{y} may be a hydrogen atom, a deuterium atom, a cyano group, a substituted or unsubstituted t-butyl group, a substituted or unsubstituted phenyl group, a substituted or unsubstituted t-butylphenyl group, a substituted or unsubstituted pyridine group, a substituted or unsubstituted benzocyclohexyl group, a substituted or unsubstituted naphthalene group, a substituted or unsubstituted diphenylamine group, a substituted or unsubstituted carbazole group, or a substituted or unsubstituted terphenyl group.

In one or more embodiments, the fused polycyclic compound represented by Formula 1 may include a structure in which any hydrogen atom in a molecule is substituted with a deuterium atom (e.g., the fused polycyclic compound represented by Formula 1 may include a chemical structure in which one or more hydrogen atoms of the fused polycyclic compound are optionally substituted with deuterium atom). For example, a deuterium atom may be directly bonded to the fused ring with 11 rings, in which a carbazole group is fused with two or more rings. In one or more embodiments, a substituent that is substituted with a deuterium atom may be bonded to the fused ring with 11 rings.

In one or more embodiments, Formula 1 may be represented by Formula 2. Formula 2 may represent a case where Z₁ to Z₁₉ are CR_{y} in Formula 1.

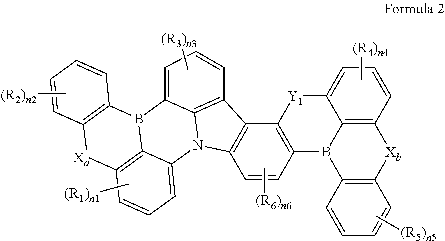

The details described in Formula 1 may be similarly applied to Xₐ, X_{b}, and Y₁ in Formula 2. In Formula 2, R₁ to R₆ may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring. For example, R₁ to Rs may not be each independently a hydrogen atom or a deuterium atom. However, this is an example, and embodiments of the present disclosure are not limited thereto.

For example, R₁ to R₆ may each independently be a hydrogen atom, a deuterium atom, a cyano group, a substituted or unsubstituted t-butyl group, a substituted or unsubstituted phenyl group, a substituted or unsubstituted t-butylphenyl group, a substituted or unsubstituted pyridine group, a substituted or unsubstituted benzocyclohexyl group, a substituted or unsubstituted naphthalene group, a substituted or unsubstituted diphenylamine group, a substituted or unsubstituted carbazole group, or a substituted or unsubstituted terphenyl group. R₁ to R₆ may each independently be a hydrogen atom or a deuterium atom, or be represented by any one selected from among R-1 to R-14. In R-13 and R-14, D is a deuterium atom.

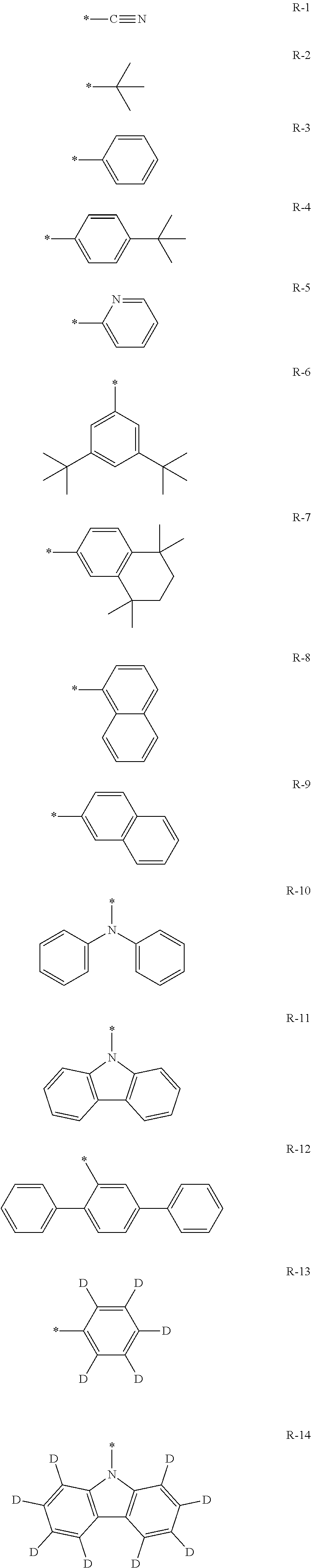

For example, R₁ and R₄ may be the same, and R₁ and R₄ may be each represented by any one selected from among R-1 to R-14. For example, R₂ and Rs may be the same, and R₂ and Rs may be each represented by any one selected from among R-1 to R-14. R₃ and R₆ may be the same, and R₃ and R₆ may be each represented by any one selected from among R-1 to R-14. However, this is an example, and embodiments of the present disclosure are not limited thereto.

In Formula 2, n1, n3, and n4 may each independently be an integer of 0 to 3, n2 and n5 may each independently be an integer of 0 to 4, and n6 may be an integer of 0 to 2. If (e.g., when) n1 is an integer of 2 or greater, a plurality of R₁ may be the same, or at least one selected from among the plurality of R₁ may be different. A case where n1 is 3, and three R₁ are hydrogen atoms may be the same as a case where n1 is 0. If (e.g., when) n3 is an integer of 2 or greater, a plurality of R₃ may be the same, or at least one selected from among the plurality of R₃ may be different. A case where n3 is 3, and three R₃ are hydrogen atoms may be the same as a case where n3 is 0. If (e.g., when) n4 is an integer of 2 or greater, a plurality of R₄ may be the same, or at least one selected from among the plurality of R₄ may be different. A case where n4 is 3, and three R₄ are hydrogen atoms, may be the same as a case where n4 is 0.

If (e.g., when) n2 is an integer of 2 or greater, a plurality of R₂ may be the same, or at least one selected from among the plurality of R₂ may be different. A case where n2 is 4, and four R₂ are hydrogen atoms, may be the same as a case where n2 is 0. If (e.g., when) n5 is an integer of 2 or greater, a plurality of Rs may be the same, or at least one selected from among the plurality of Rs may be different. A case where n5 is 4, and four Rs are hydrogen atoms, may be the same as a case where n5 is 0.

If (e.g., when) n6 is 2, a plurality of R₆ may be the same as or different from each other. A case where n6 is 2, and two R₆ are hydrogen atoms may be the same as a case where n6 is 0.

In one or more embodiments, Formula 2 may be represented by any one selected from among 2-1 to 2-8. Formula 2-1 may represent a case where Xₐ and X_{b} are each independently NRₓ, and Y₁ is O in Formula 2. Formula 2-2 may represent a case where Xₐ and X_{b} are each independently NRₓ, and Y₁ is S in Formula 2. Formula 2-3 may represent a case where Xₐ and Y₁ are each independently O, and X_{b} is NRₓ in Formula 2. Formula 2-4 may represent a case where Xₐ is S, Y₁ is 0, and X_{b} is NRₓ in Formula 2. Formula 2-5 may represent a case where Xₐ and Y₁ are each independently S, and X_{b} is NRₓ in Formula 2. Formula 2-6 may represent a case where X_{b} and Y₁ are each independently O, and Xₐ is NRₓ in Formula 2. Formula 2-7 may represent a case where X_{b} and Y₁ are each independently S, and Xₐ is NRₓ in Formula 2. Formula 2-8 may represent a case where Xₐ, X_{b}, and Y₁ are each independently O in Formula 2. Formula 2-1

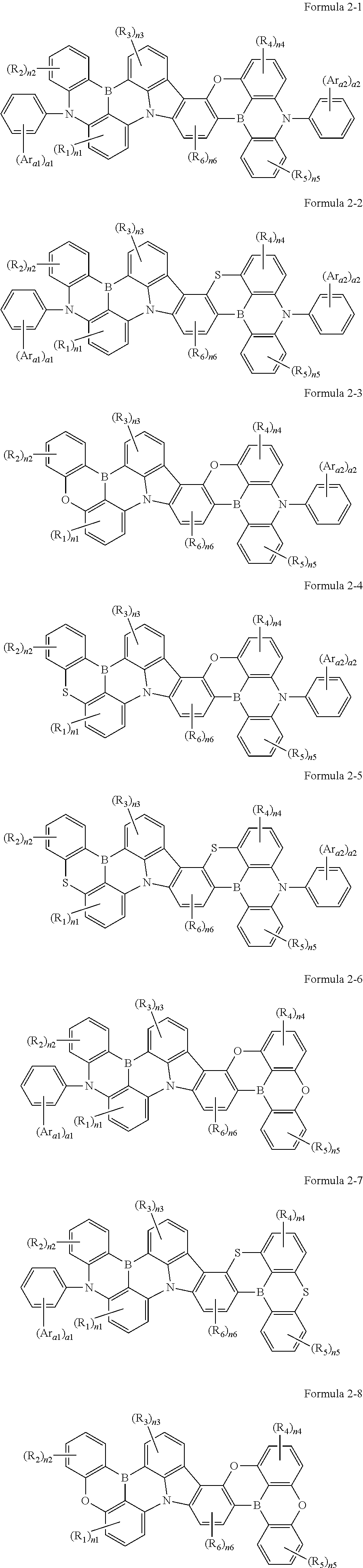

The details described in Formula 2 may be similarly applied to R₁ to R₆, and n1 to n6 in Formulas 2-1 to 2-8. In Formula 2-1 to 2-8, Arₐ₁ and Arₐ₂ may each independently be a hydrogen atom, a deuterium atom, a substituted or unsubstituted alkyl group having 1 to 20 carbon atoms, a substituted or unsubstituted cycloalkyl group having 3 to 10 ring-forming carbon atoms, or a substituted or unsubstituted aryl group having 6 to 30 ring-forming carbon atoms, and/or may be bonded to an adjacent group to form a ring. For example, Arₐ₁ and Arₐ₂ may each independently be a hydrogen atom, a deuterium atom, a substituted or unsubstituted t-butyl group, a substituted or unsubstituted cyclohexyl group, a substituted or unsubstituted phenyl group, or Arₐ₁ and Arₐ₂ may each independently be bonded to a benzene ring to form a ring. However, this is an example, but embodiments of the present disclosure are not limited thereto.

In Formula 2-1 to 2-8, a1 and a2 may each independently be an integer of 0 to 5. If (e.g., when) a1 is an integer of 2 or greater, a plurality of Arₐ₁ may be the same, or at least one selected from among the plurality of Arₐ₁ may be different. A case where a1 is 5, and five Arₐ₁ are hydrogen atoms may be the same as a case where a1 is 0. If (e.g., when) a2 is an integer of 2 or greater, a plurality of Arₐ₂ may be the same, or at least one selected from among the plurality of Arₐ₂ may be different. A case where a2 is 5, and five Arₐ₂ are hydrogen atoms may be the same as a case where a2 is 0.

In one or more embodiments, Formula 2 may be represented by Formula 3. Formula 3 may represent a case where R₁ to Rs are not each independently a hydrogen atom or a deuterium atom, and R₆ is a hydrogen atom or a deuterium atom in Formula 2.

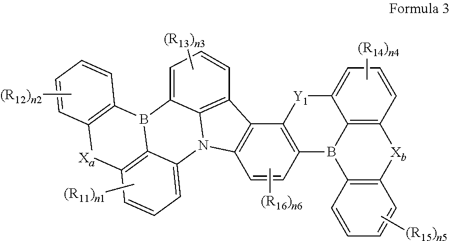

The details described in Formula 1 may be similarly applied to Xₐ, X_{b}, and Y₁ in Formula 3. The details described in Formula 2 may be similarly applied to n1 to n5. For example, n1 to n5 may not be each independently 0. However, this is an example, but embodiments of the present disclosure are not limited thereto.

In Formula 3, R₁₁ to R₁₅ may each independently be a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring. R₁₆ may be a hydrogen atom or a deuterium atom.

In Formula 3, n16 may be an integer of 0 to 2. If (e.g., when) n16 is 2, a plurality R₁₆ of may be the same as or different from each other. A case where n16 is 2, and two R₁₆ are hydrogen atoms may be the same as a case where n16 is 0.

In one or more embodiments, Formula 2 may be represented by Formula 4. Formula 4 may represent a case where bonding positions of R₁ to Rs in Formula 2 are specified.

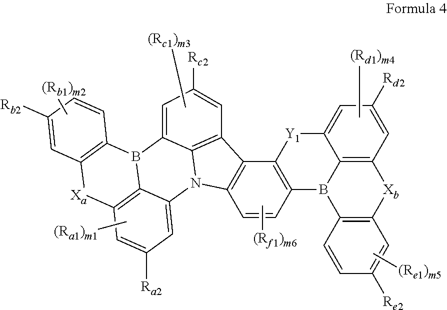

The details described in Formula 1 may be similarly applied to Xₐ, X_{b}, and Y₁ in Formula 4. In Formula 4, Rₐ₁, R_{b1}, R_{c1}, Rₐ₁, Rₑ₁, and R_{f1} may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring.

In Formula 4, Rₐ₂, R_{b2}, R_{c2}, R_{d2}, and Rₑ₂ may each independently be a hydrogen atom, a deuterium atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or may be bonded to an adjacent group to form a ring. For example, Rₐ₂ and R_{d2} may be the same. R_{b2} and Rₑ₂ may be the same. However, this is an example, but embodiments of the present disclosure are not limited thereto.

In Formula 4, m1, m3, and m4 may each independently be an integer of 0 to 2, m2 and m5 may each independently be an integer of 0 to 3, and m6 may be an integer of 0 to 2. If (e.g., when) m1 is 2, a plurality Rai may be the same as or different from each other. A case where m1 is 2, and two Rai are hydrogen atoms may be the same as a case where m1 is 0. If (e.g., when) m3 is 2, a plurality R_{c1} may be the same as or different from each other. A case where m3 is 2, and two R_{c1} are hydrogen atoms, may be the same as a case where m3 is 0. If (e.g., when) m4 is 2, a plurality Rₐ₁ may be the same as or different from each other. A case where m4 is 2, and two Rₐ₁ are hydrogen atoms, may be the same as a case where m4 is 0.

If (e.g., when) m2 is an integer of 2 or greater, a plurality of R_{b1} may be the same, or at least one selected from among the plurality of R_{b1} may be different. A case where m2 is 3, and three R_{b1} are hydrogen atoms, may be the same as a case where m2 is 0. If (e.g., when) m5 is an integer of 2 or greater, a plurality of Rₑ₁ may be the same, or at least one selected from among the plurality of Rₑ₁ may be different. A case where m5 is 3, and three Rₑ₁ are hydrogen atoms, may be the same as a case where m5 is 0.

If (e.g., when) m6 is 2, a plurality of R_{f1} may be the same as or different from each other. A case where m6 is 2, and two R_{f1} are hydrogen atoms, may be the same as a case where m6 is 0.

Formula 1 may be represented by any one selected from among the compounds in Compound Group 1. The fused polycyclic compound according to one or more embodiments may be represented by any one selected from among the compounds in Compound Group 1. The light-emitting element ED according to one or more embodiments may include at least one selected from among the compounds in Compound Group 1. In Compound Group 1, D is a deuterium atom.

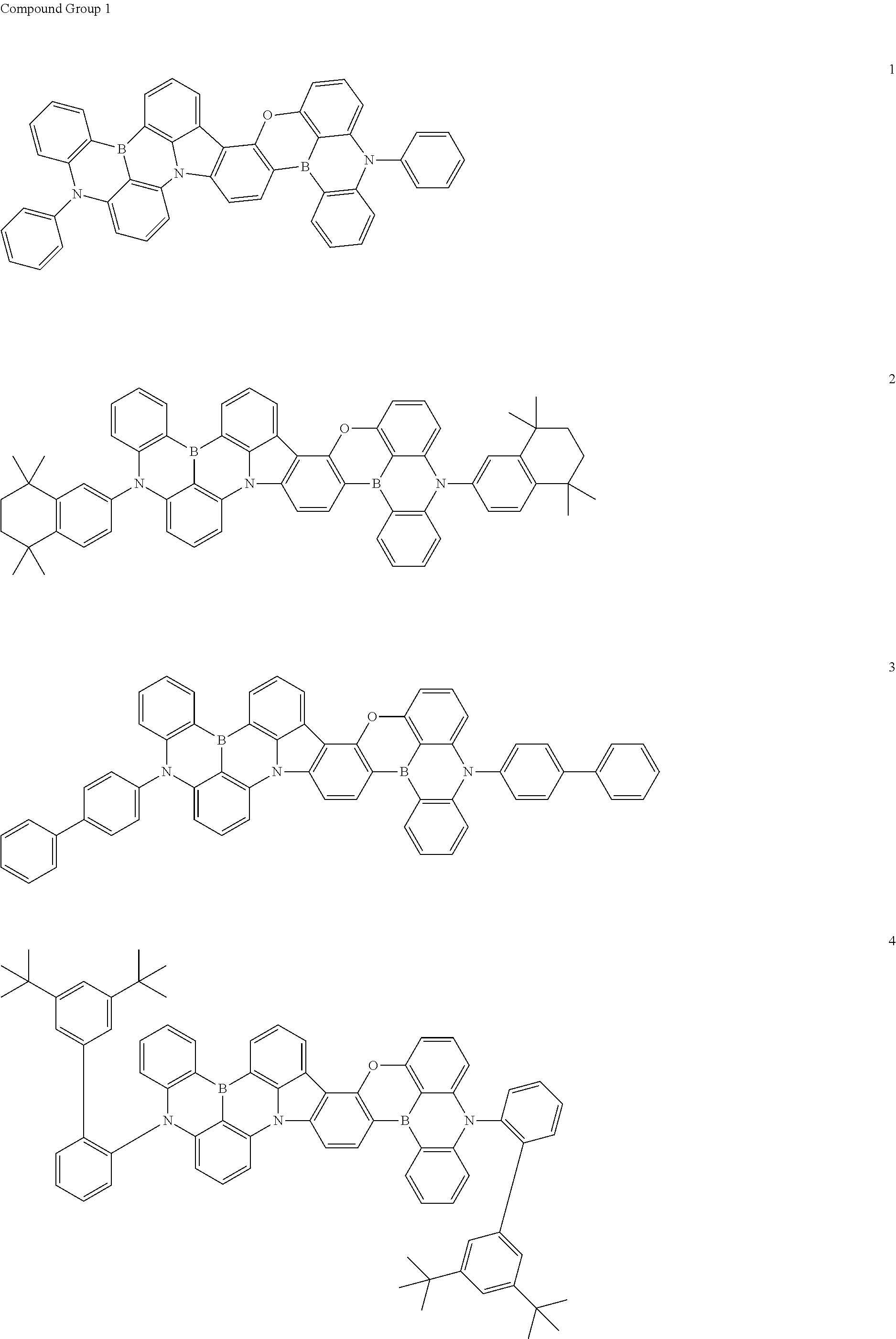

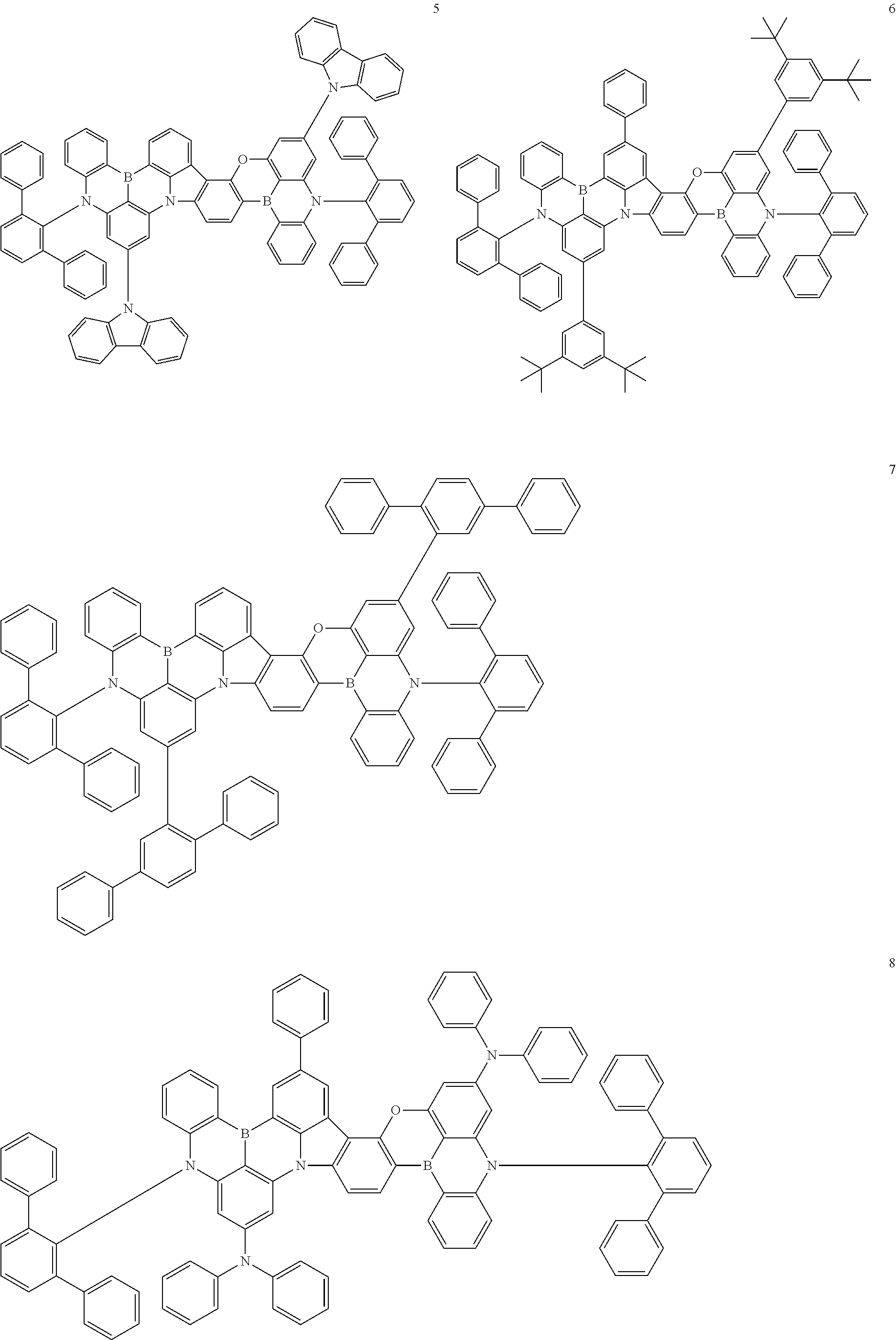

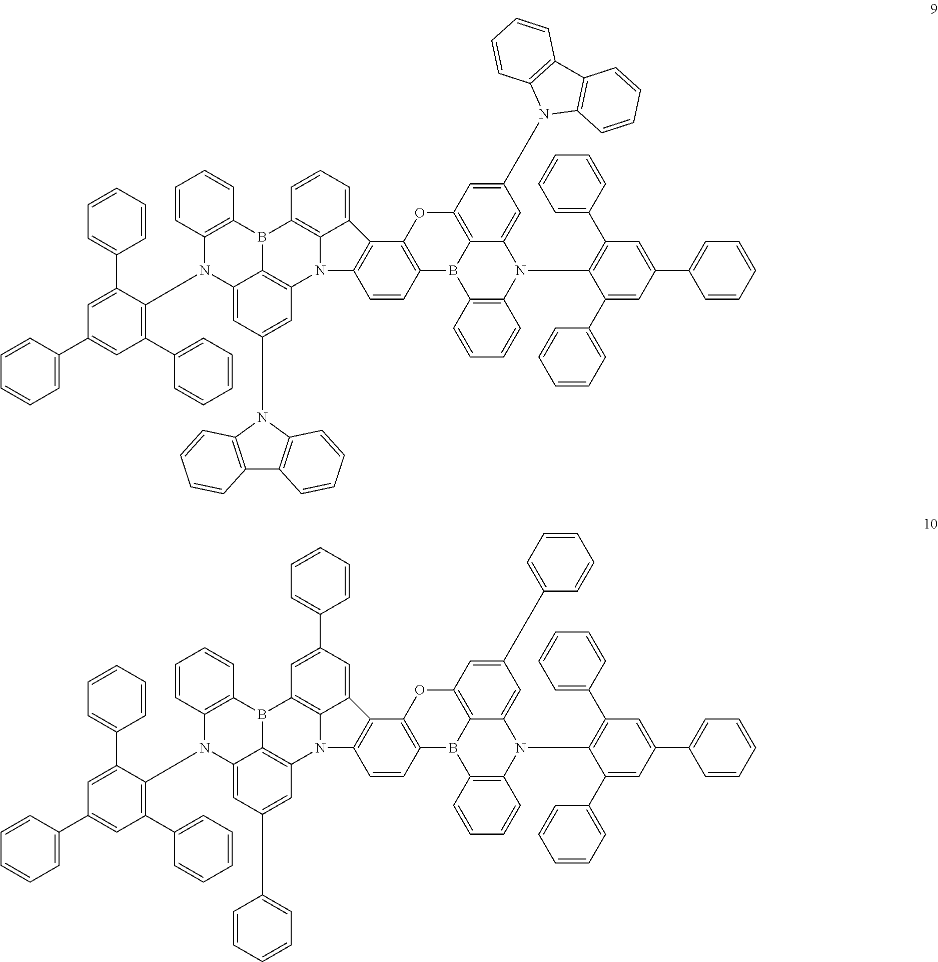 [SMILES: c1ccc(-c2cc(-c3ccccc3)c(N3c4ccccc4B4c5ccc6c(c5Oc5cc(-n7c8ccccc8c8ccccc87)cc3c54)c3cccc4c3n6-c3cc(-n5c6ccccc6c6ccccc65)cc5c3B4c3ccccc3N5c3c(-c4ccccc4)cc(-c4ccccc4)cc3-c3ccccc3)c(-c3ccccc3)c2)cc1 ; c1ccc(-c2cc(-c3ccccc3)c(N3c4ccccc4B4c5ccc6c(c5Oc5cc(-c7ccccc7)cc3c54)c3cc(-c4ccccc4)cc4c3n6-c3cc(-c5ccccc5)cc5c3B4c3ccccc3N5c3c(-c4ccccc4)cc(-c4ccccc4)cc3-c3ccccc3)c(-c3ccccc3)c2)cc1]

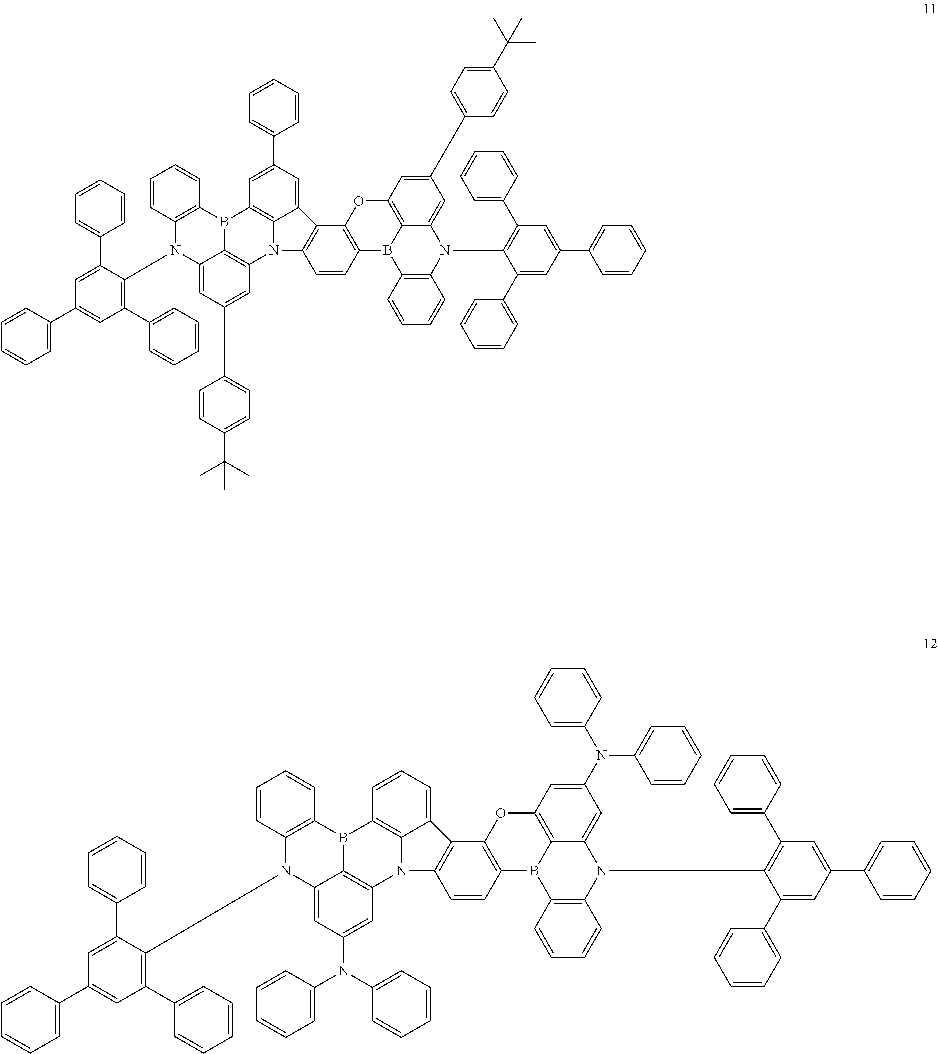 [SMILES: CC(C)(C)c1ccc(-c2cc3c4c(c2)N(c2c(-c5ccccc5)cc(-c5ccccc5)cc2-c2ccccc2)c2ccccc2B4c2ccc4c(c2O3)c2cc(-c3ccccc3)cc3c2n4-c2cc(-c4ccc(C(C)(C)C)cc4)cc4c2B3c2ccccc2N4c2c(-c3ccccc3)cc(-c3ccccc3)cc2-c2ccccc2)cc1 ; c1ccc(-c2cc(-c3ccccc3)c(N3c4ccccc4B4c5ccc6c(c5Oc5cc(N(c7ccccc7)c7ccccc7)cc3c54)c3cccc4c3n6-c3cc(N(c5ccccc5)c5ccccc5)cc5c3B4c3ccccc3N5c3c(-c4ccccc4)cc(-c4ccccc4)cc3-c3ccccc3)c(-c3ccccc3)c2)cc1]

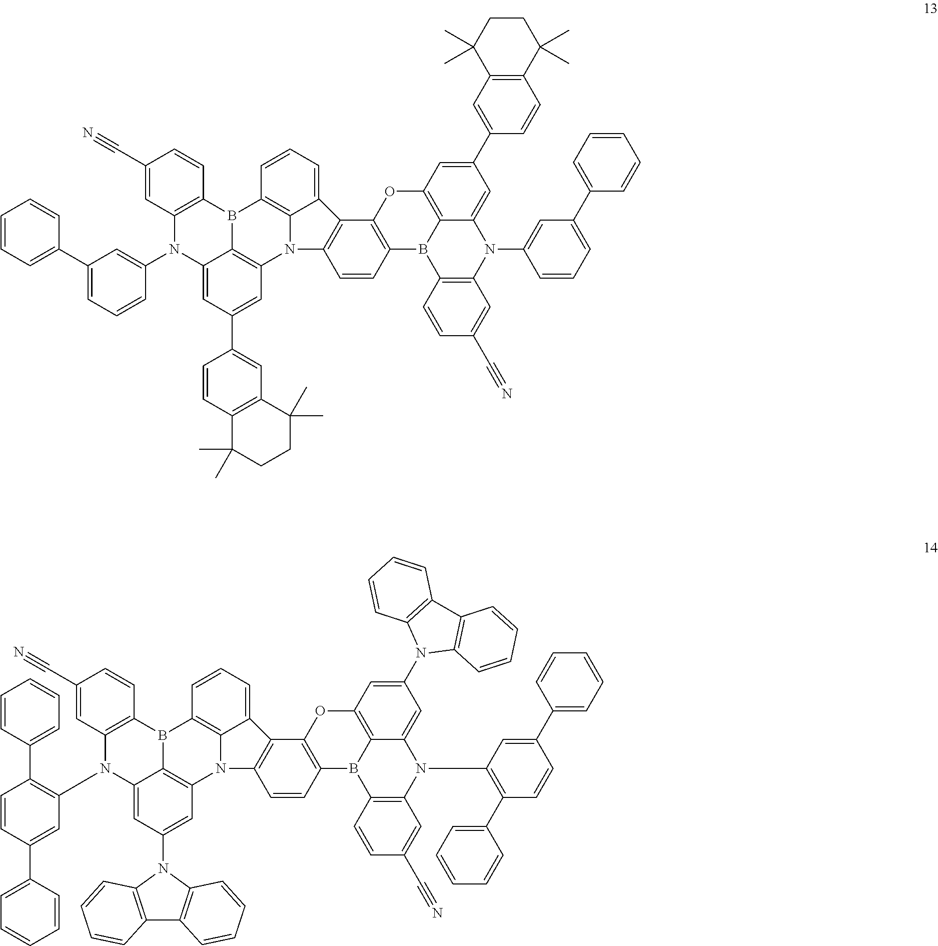 [SMILES: CC1(C)CCC(C)(C)c2cc(-c3cc4c5c(c3)N(c3cccc(-c6ccccc6)c3)c3cc(C#N)ccc3B5c3ccc5c(c3O4)c3cccc4c3n5-c3cc(-c5ccc6c(c5)C(C)(C)CCC6(C)C)cc5c3B4c3ccc(C#N)cc3N5c3cccc(-c4ccccc4)c3)ccc21 ; N#Cc1ccc2c(c1)N(c1cc(-c3ccccc3)ccc1-c1ccccc1)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1N2c1cc(-c2ccccc2)ccc1-c1ccccc1]

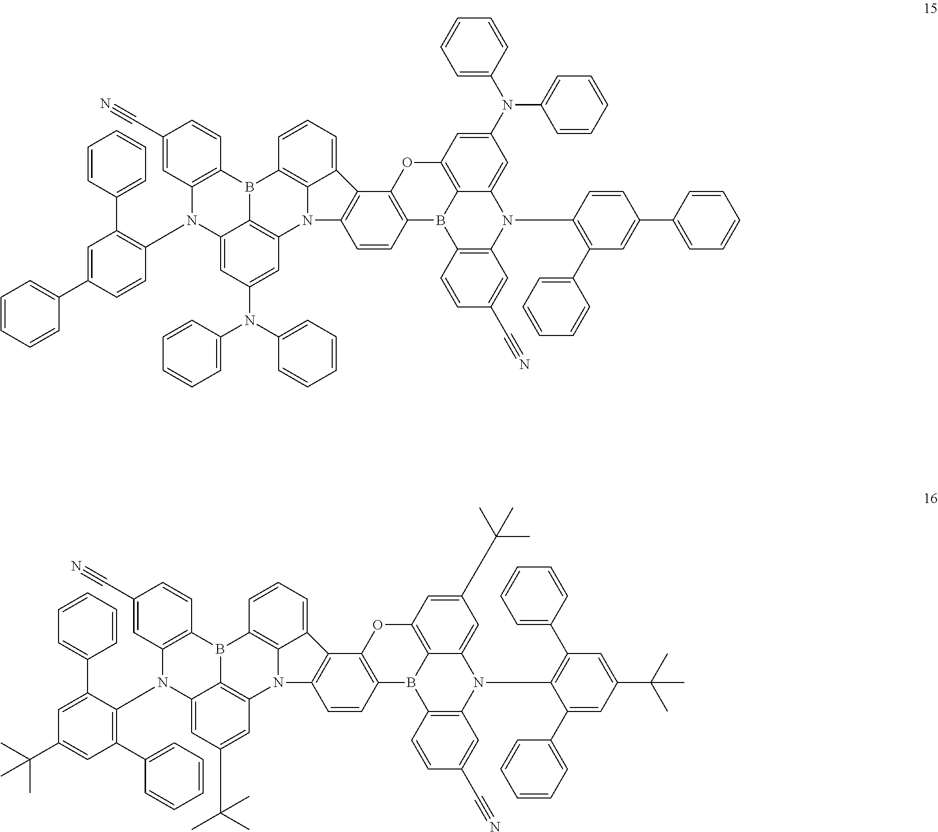 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C#N)ccc3B3c4ccc5c(c4Oc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1]

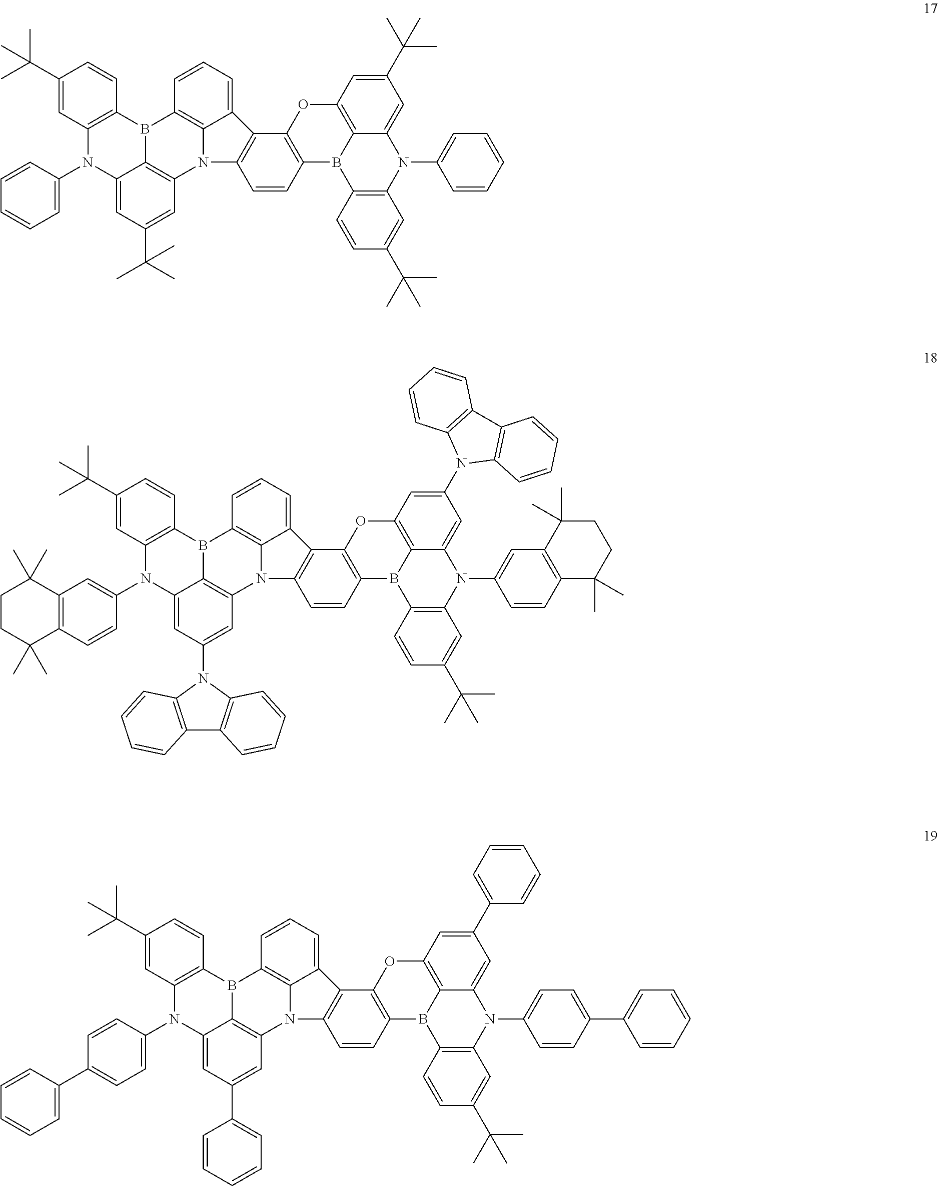 [SMILES: CC(C)(C)c1ccc2c(c1)N(c1ccccc1)c1cc(C(C)(C)C)cc3c1B2c1ccc2c(c1O3)c1cccc3c1n2-c1cc(C(C)(C)C)cc2c1B3c1ccc(C(C)(C)C)cc1N2c1ccccc1 ; CC(C)(C)c1ccc2c(c1)N(c1ccc3c(c1)C(C)(C)CCC3(C)C)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1N2c1ccc2c(c1)C(C)(C)CCC2(C)C ; CC(C)(C)c1ccc2c(c1)N(c1ccc(-c3ccccc3)cc1)c1cc(-c3ccccc3)cc3c1B2c1ccc2c(c1O3)c1cccc3c1n2-c1cc(-c2ccccc2)cc2c1B3c1ccc(C(C)(C)C)cc1N2c1ccc(-c2ccccc2)cc1]

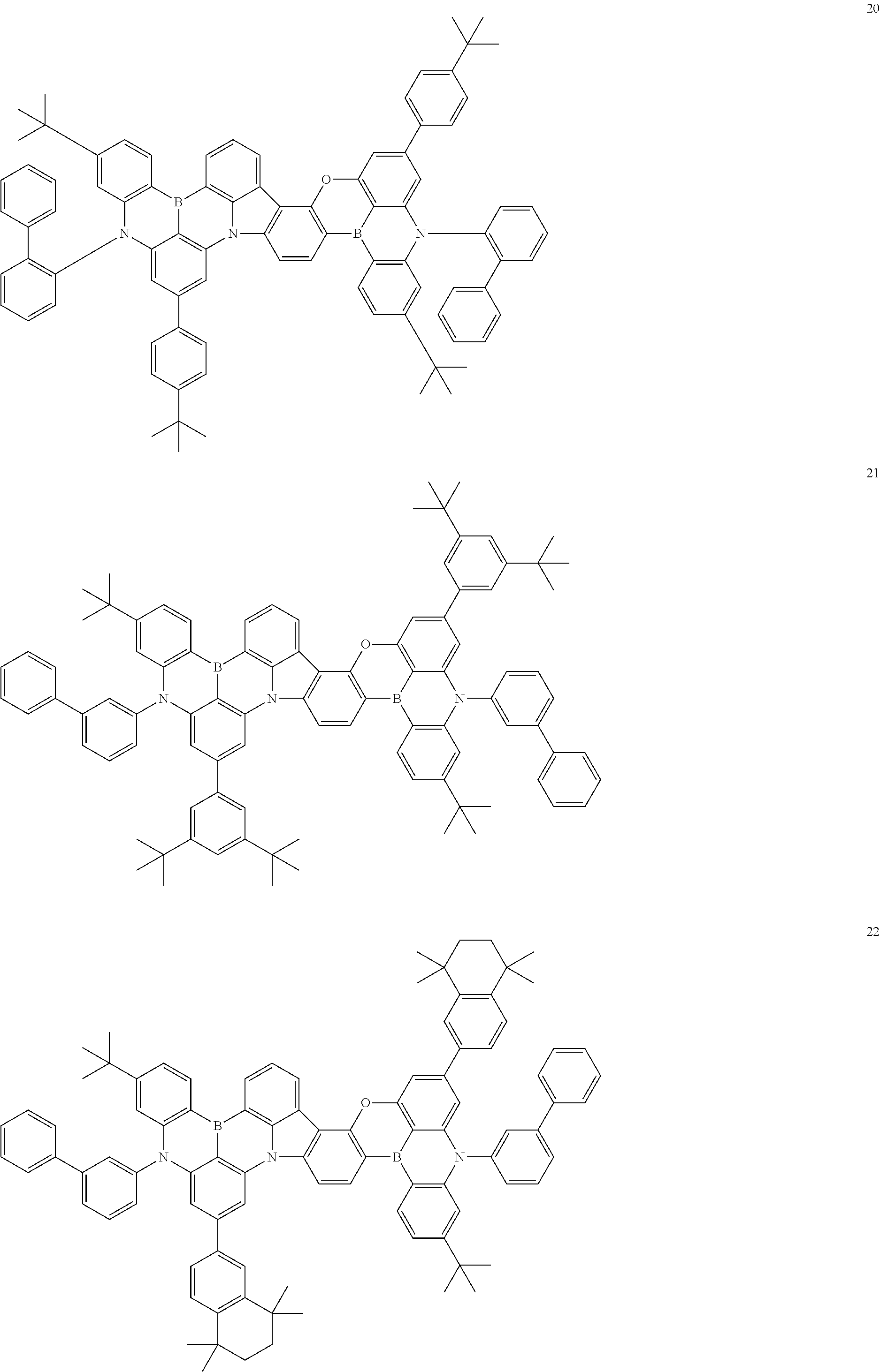

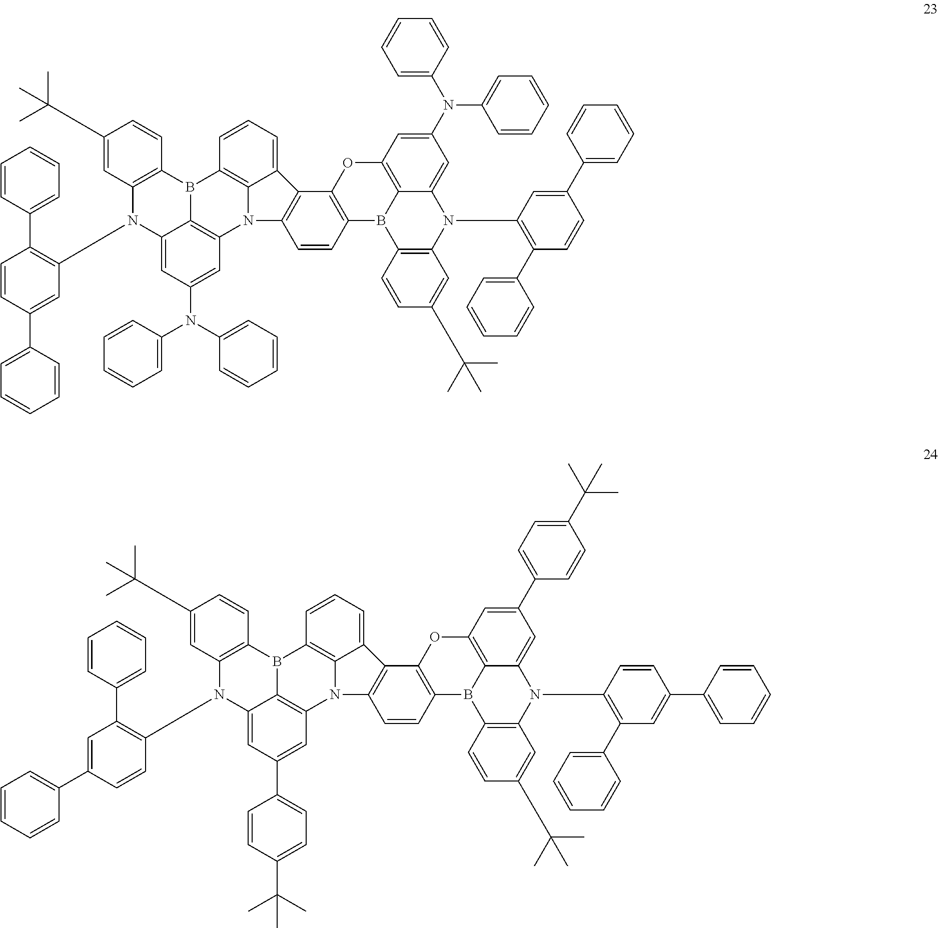 [SMILES: CC(C)(C)c1ccc2c(c1)N(c1cc(-c3ccccc3)ccc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)N(c2ccc(-c5ccccc5)cc2-c2ccccc2)c2cc(C(C)(C)C)ccc2B4c2ccc4c(c2O3)c2cccc3c2n4-c2cc(-c4ccc(C(C)(C)C)cc4)cc4c2B3c2ccc(C(C)(C)C)cc2N4c2ccc(-c3ccccc3)cc2-c2ccccc2)cc1]

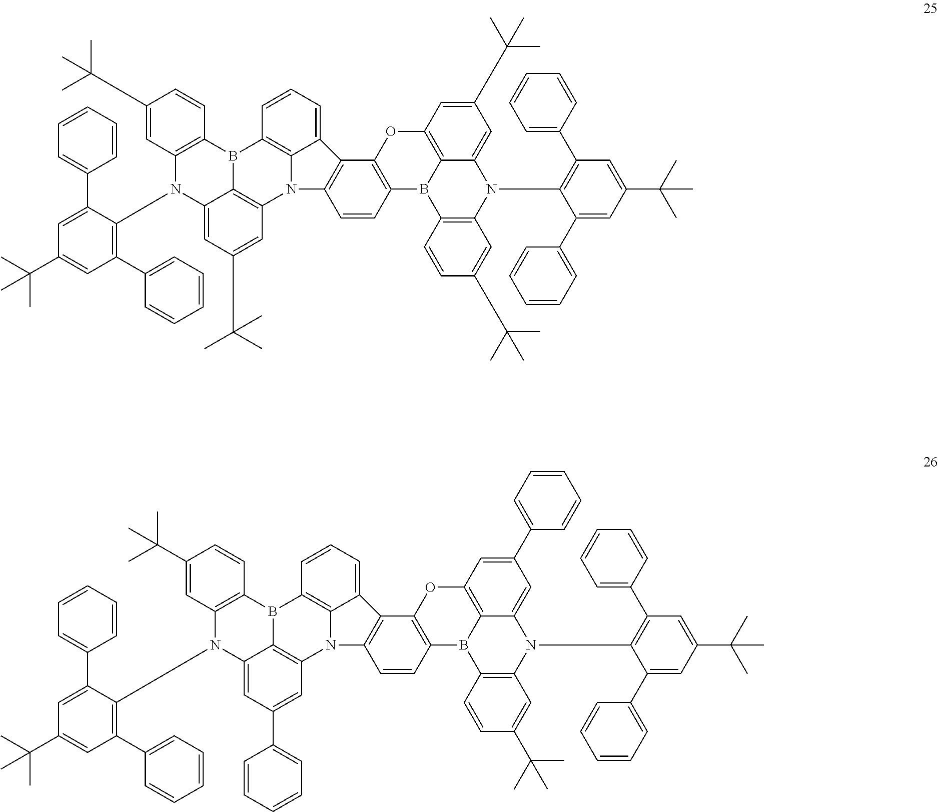

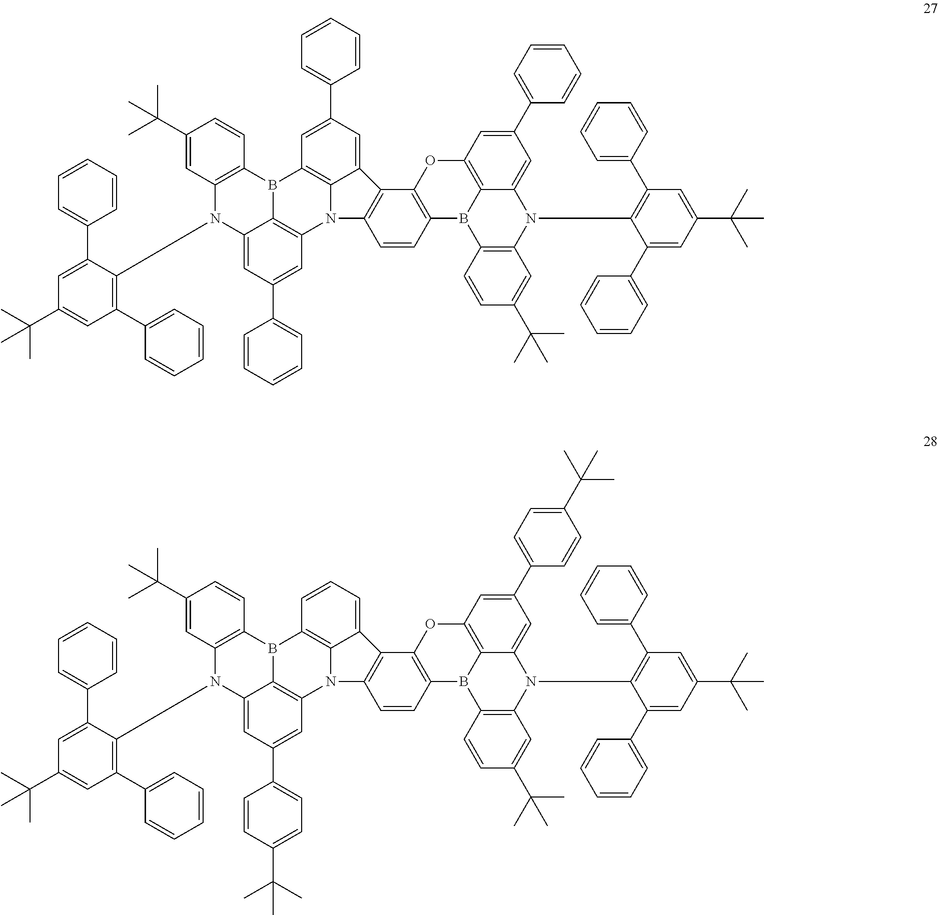

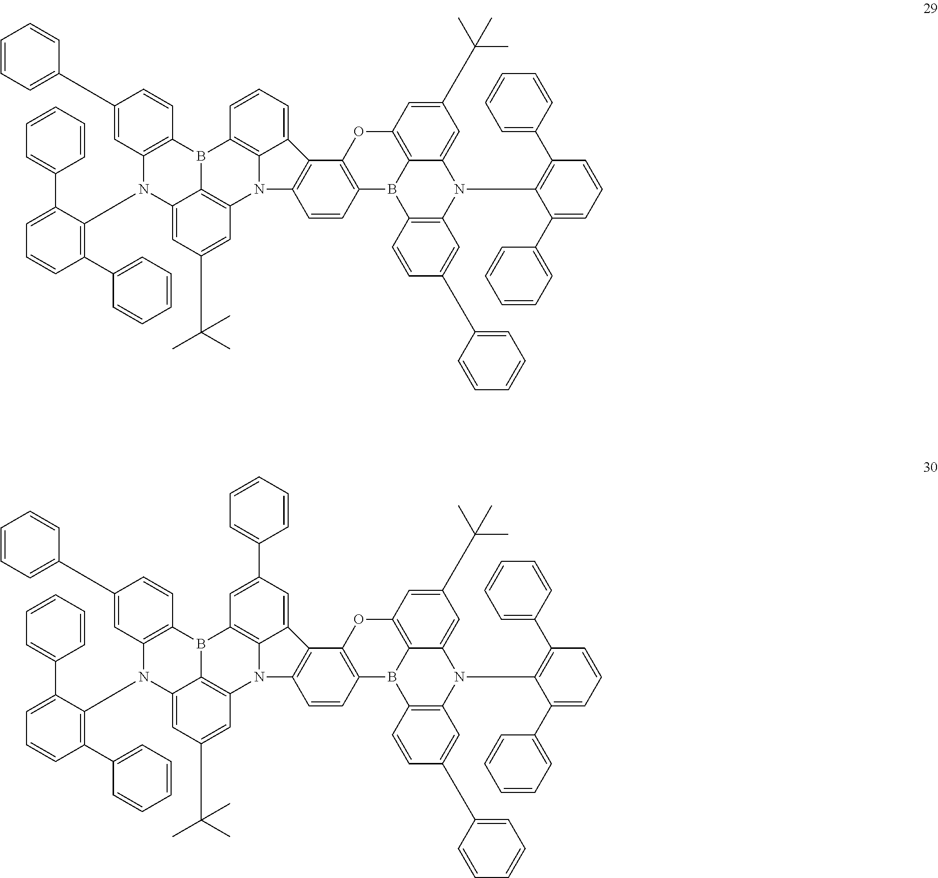 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1]

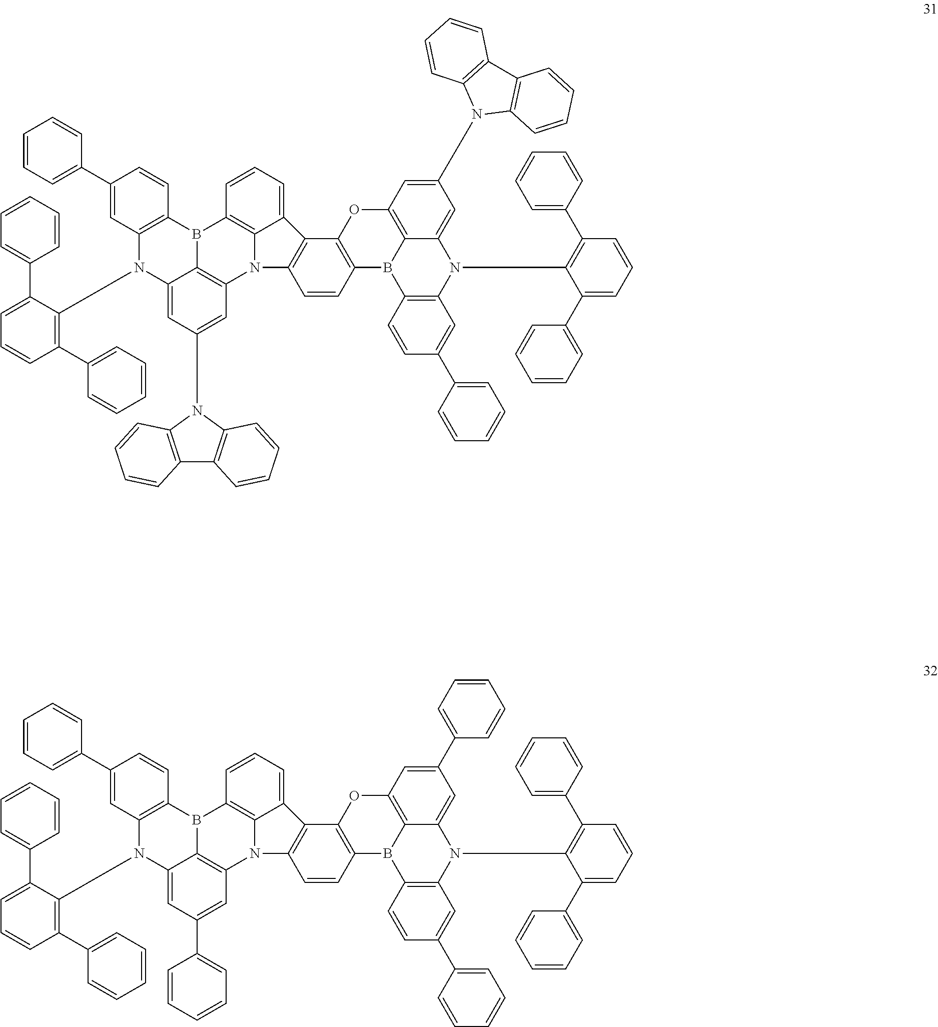 [SMILES: c1ccc(-c2ccc3c(c2)N(c2c(-c4ccccc4)cccc2-c2ccccc2)c2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccccc4)cc2N3c2c(-c3ccccc3)cccc2-c2ccccc2)cc1]

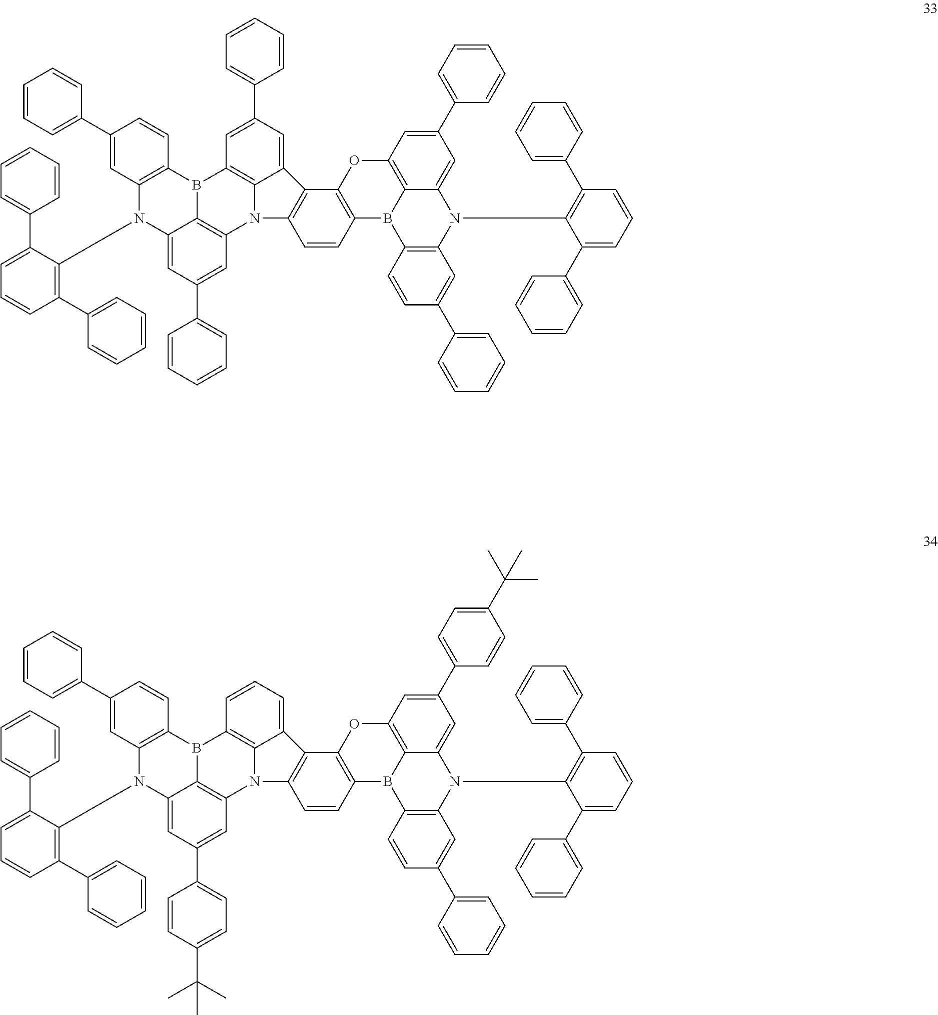 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cc(-c4ccccc4)cc4c2n3-c2cc(-c3ccccc3)cc3c2B4c2ccc(-c4ccccc4)cc2N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2N4c2c(-c3ccccc3)cccc2-c2ccccc2)cc1]

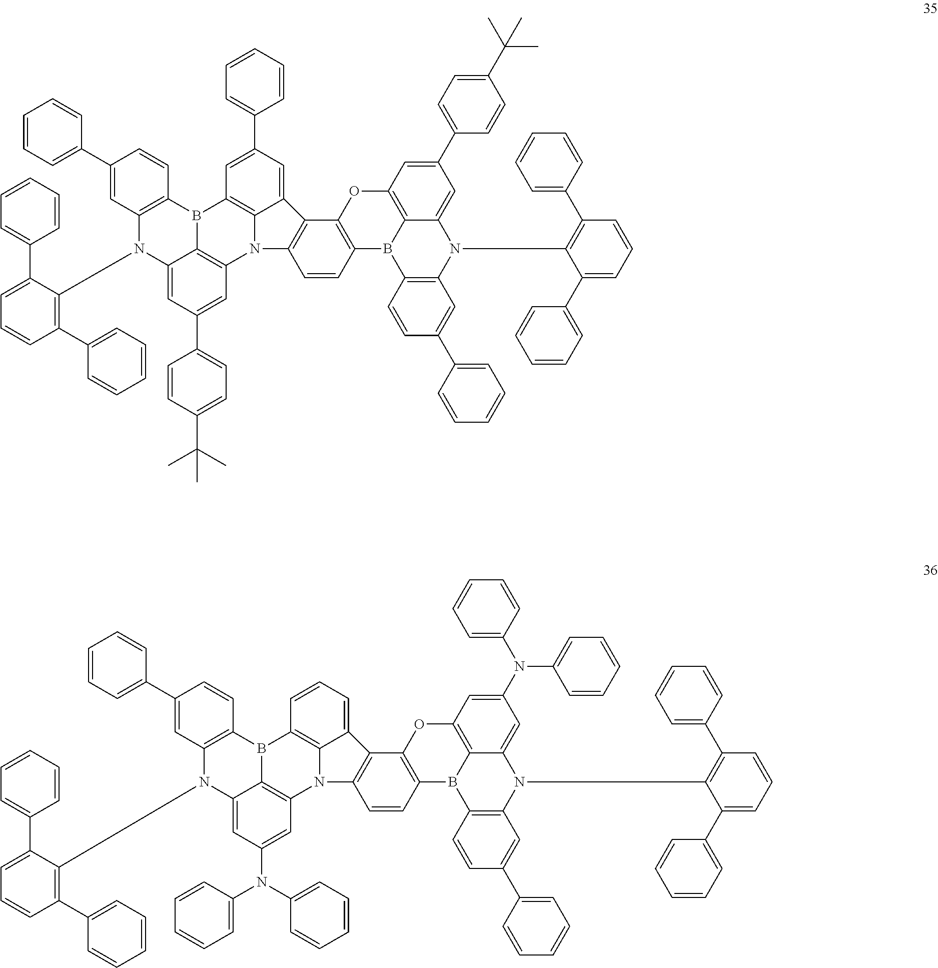 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2N4c2c(-c3ccccc3)cccc2-c2ccccc2)cc1 ; c1ccc(-c2ccc3c(c2)N(c2c(-c4ccccc4)cccc2-c2ccccc2)c2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1]

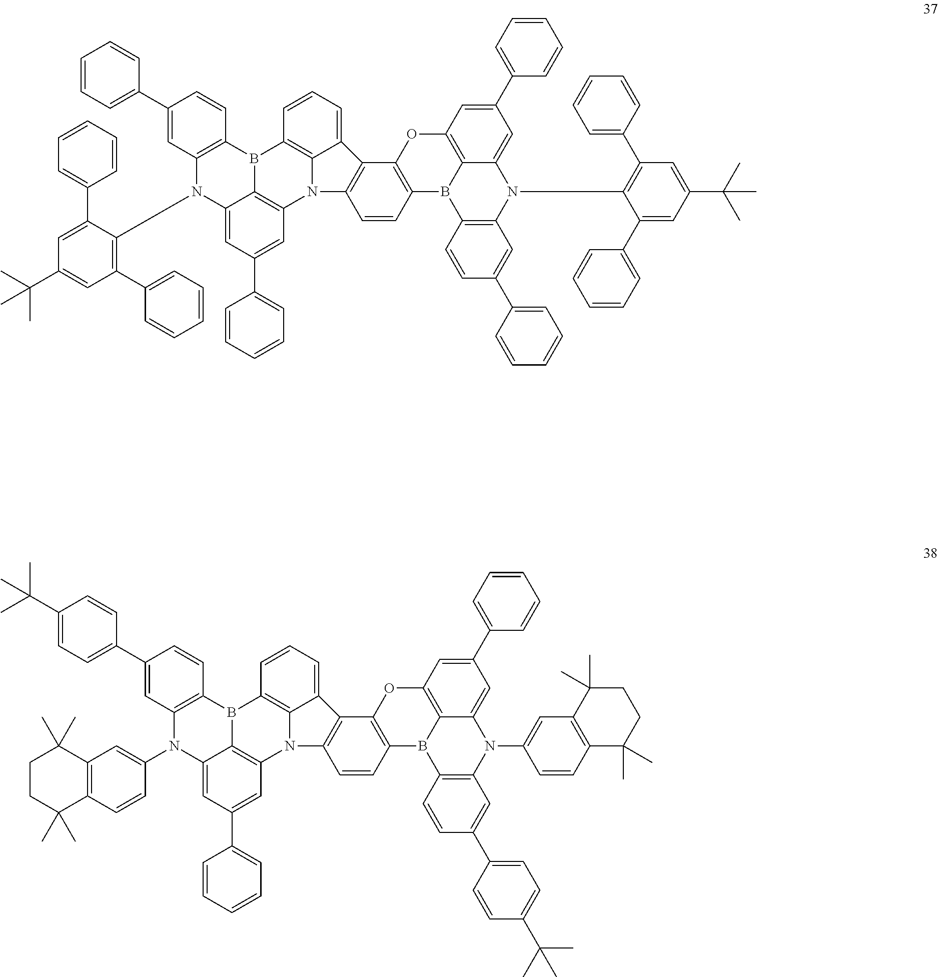

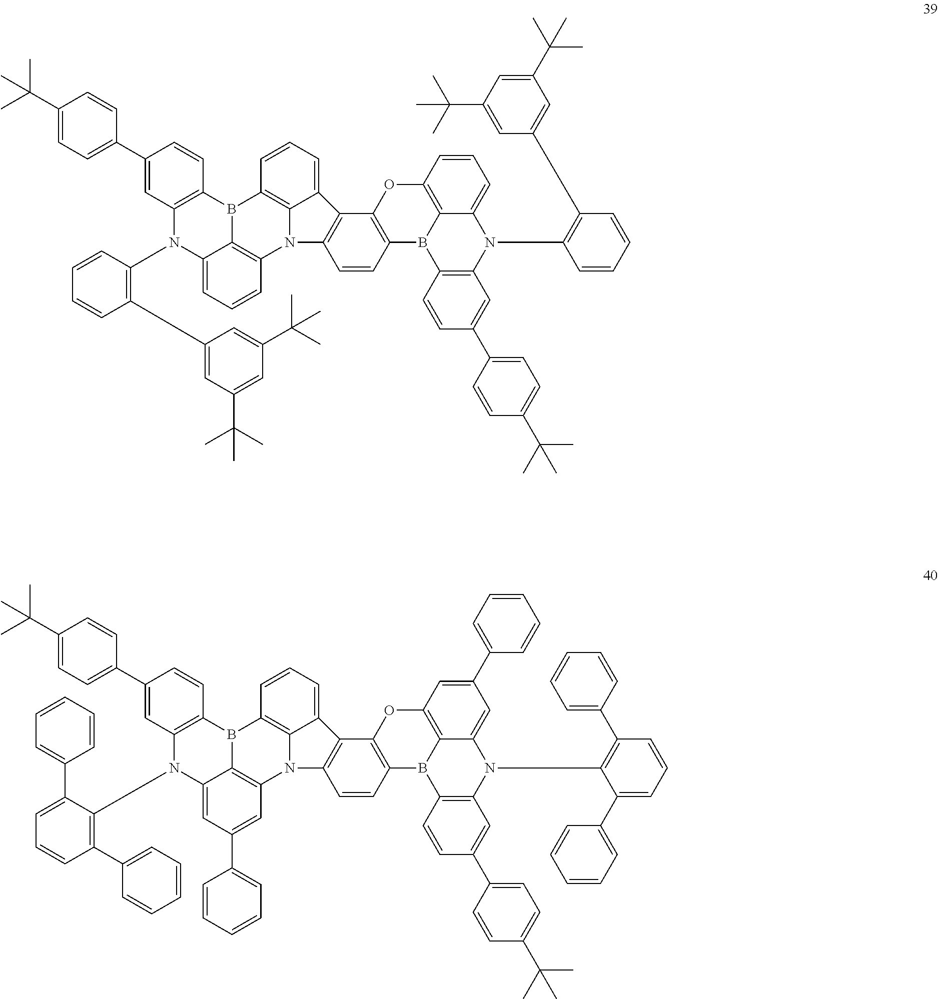 [SMILES: CC(C)(C)c1ccc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4ccc(C(C)(C)C)cc4)cc2N3c2ccccc2-c2cc(C(C)(C)C)cc(C(C)(C)C)c2)cc1 ; CC(C)(C)c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2N3c2c(-c3ccccc3)cccc2-c2ccccc2)cc1]

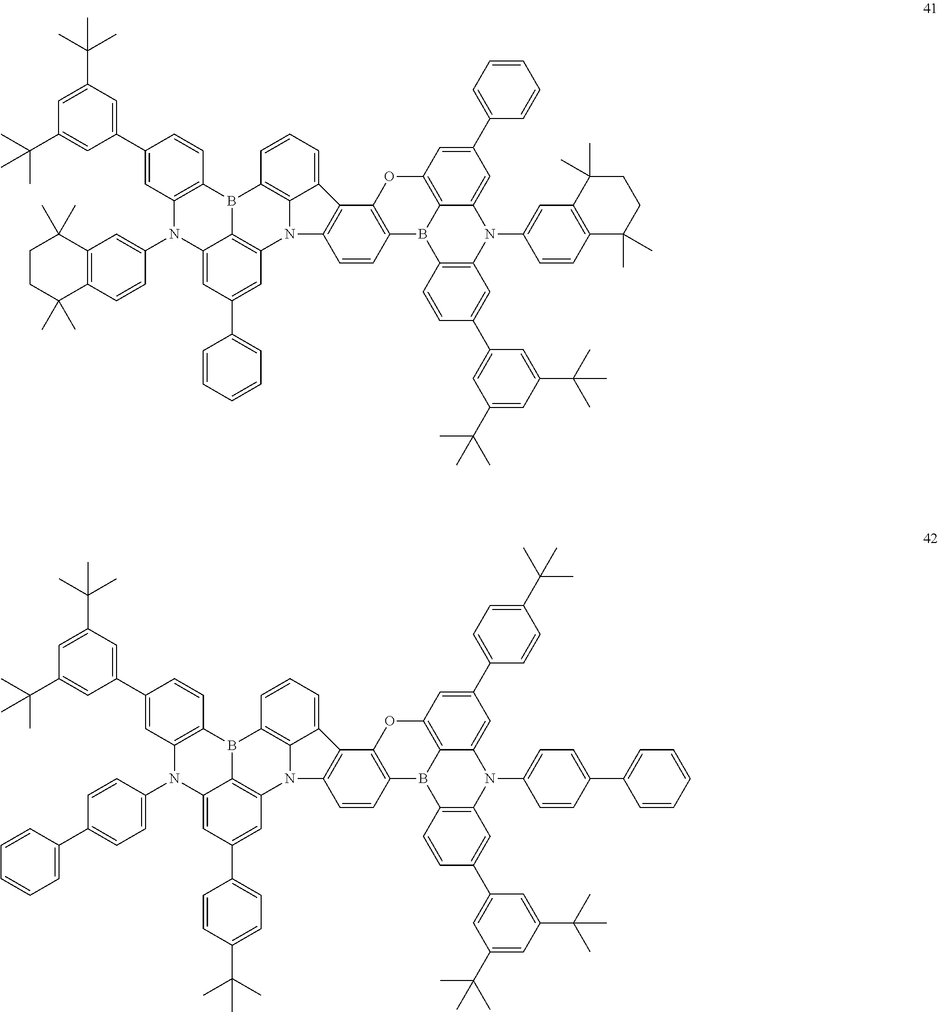

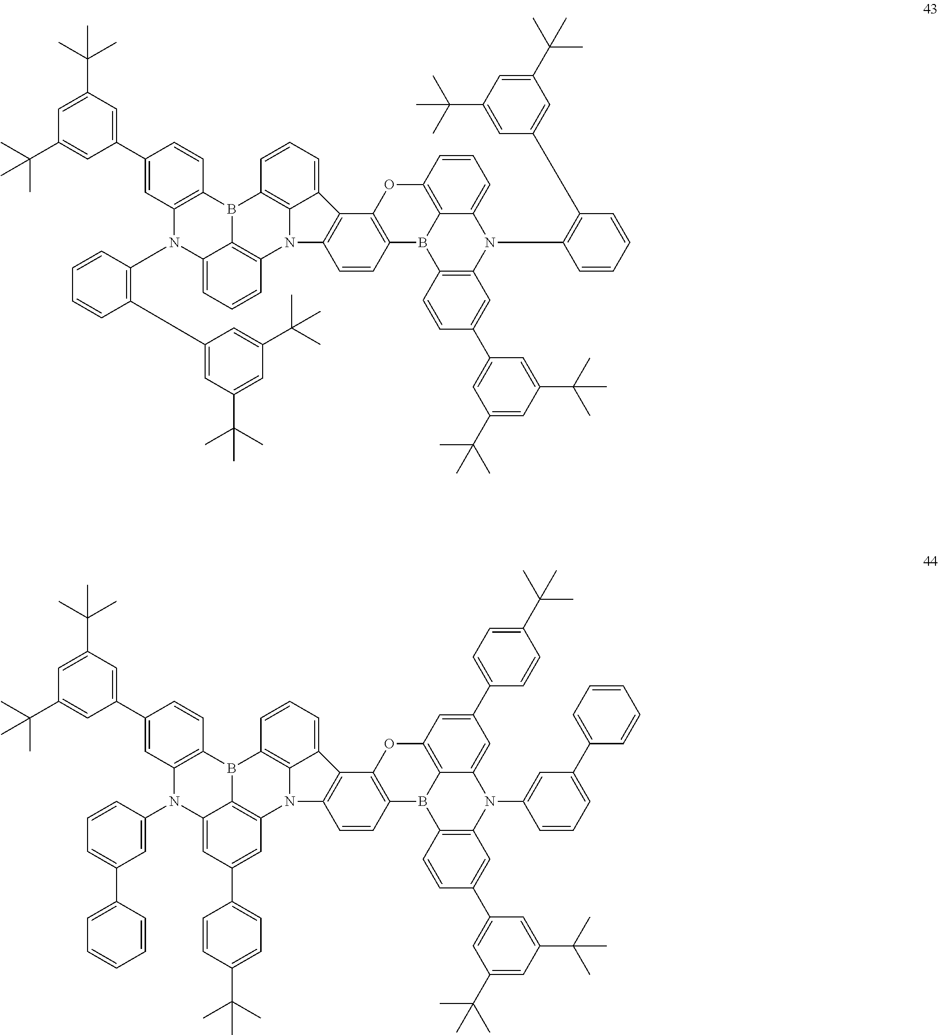 [SMILES: CC(C)(C)c1cc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4cc(C(C)(C)C)cc(C(C)(C)C)c4)cc2N3c2ccccc2-c2cc(C(C)(C)C)cc(C(C)(C)C)c2)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2N4c2cccc(-c3ccccc3)c2)cc1]

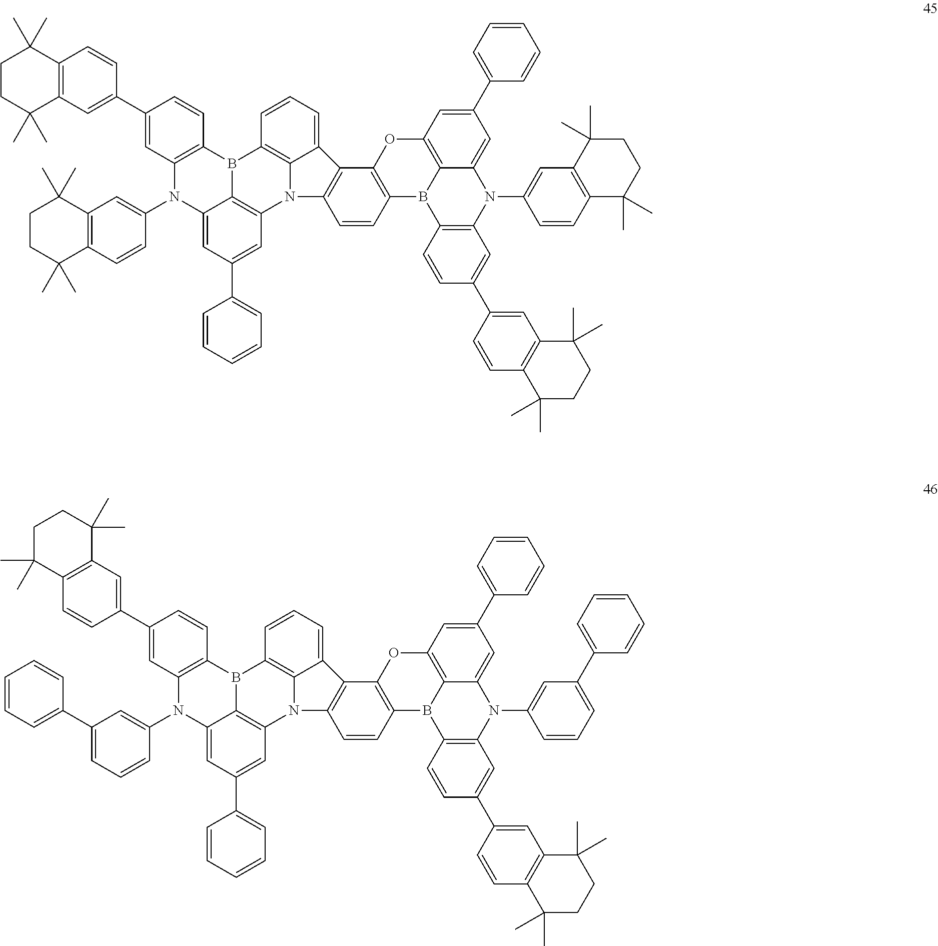

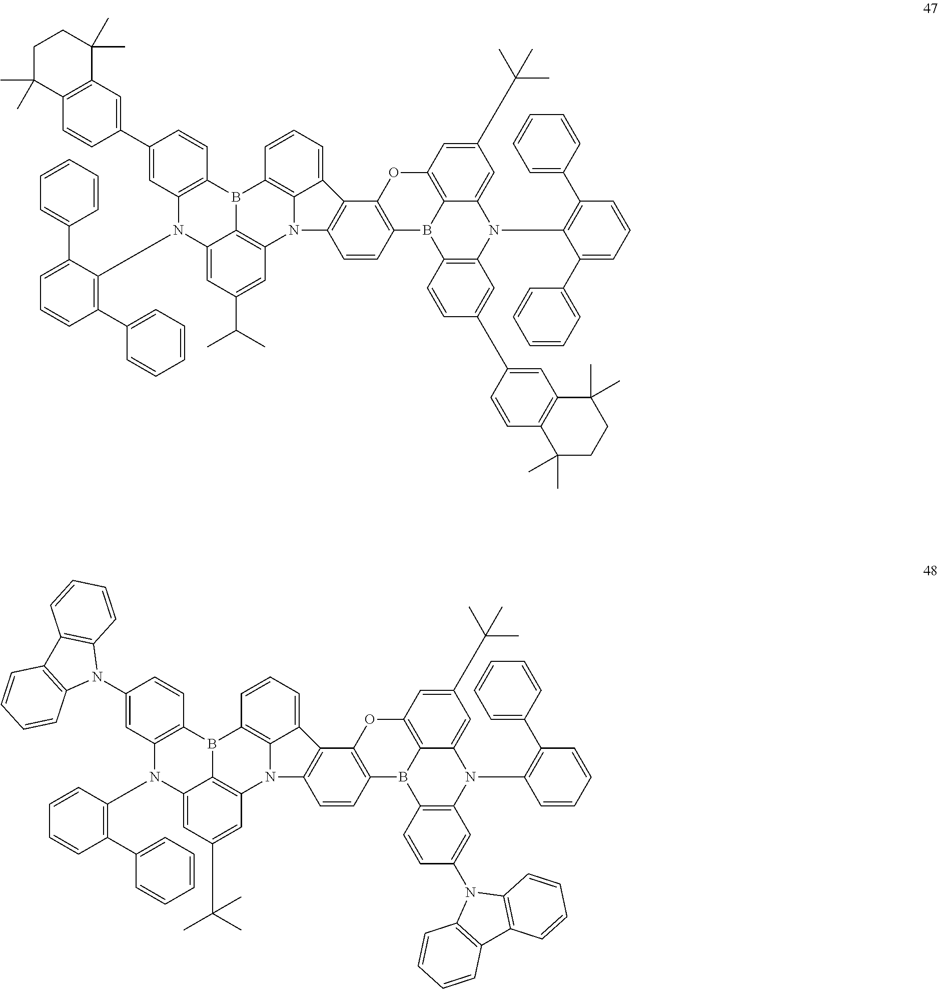 [SMILES: CC(C)c1cc2c3c(c1)-n1c4ccc5c(c4c4cccc(c41)B3c1ccc(-c3ccc4c(c3)C(C)(C)CCC4(C)C)cc1N2c1c(-c2ccccc2)cccc1-c1ccccc1)Oc1cc(C(C)(C)C)cc2c1B5c1ccc(-c3ccc4c(c3)C(C)(C)CCC4(C)C)cc1N2c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1ccccc1-c1ccccc1]

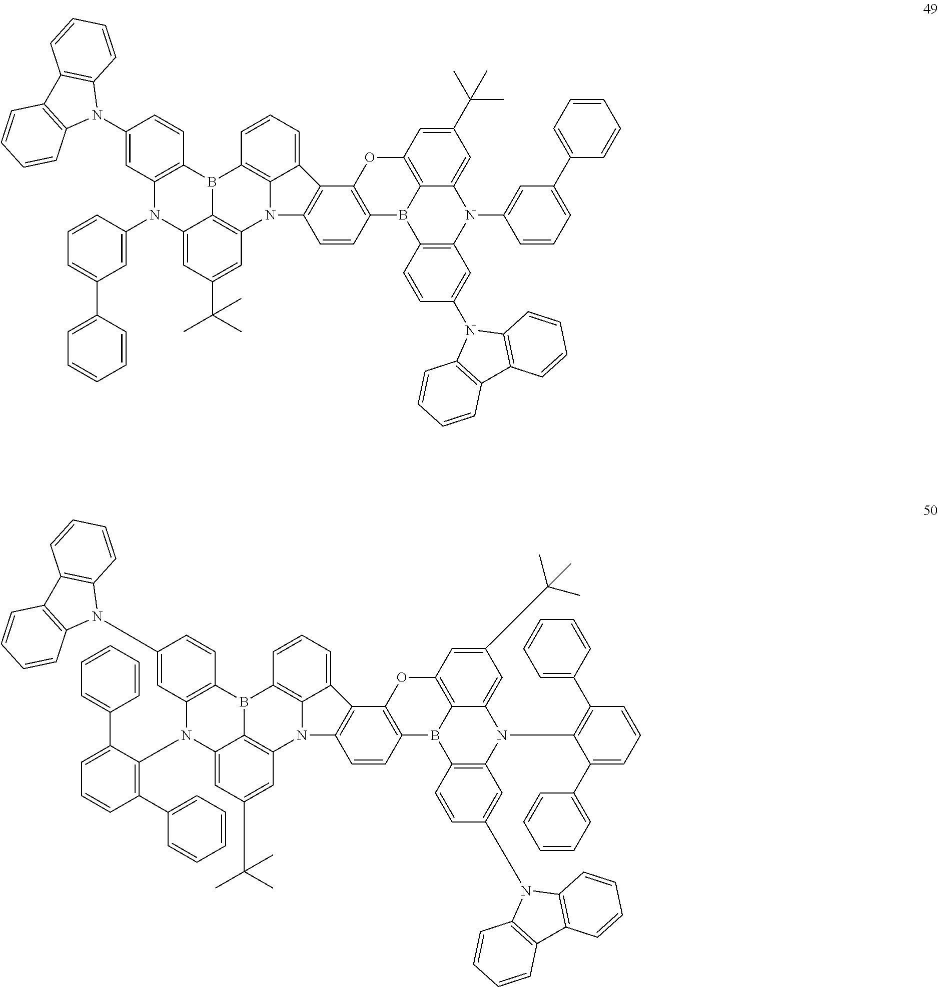 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cccc1-c1ccccc1]

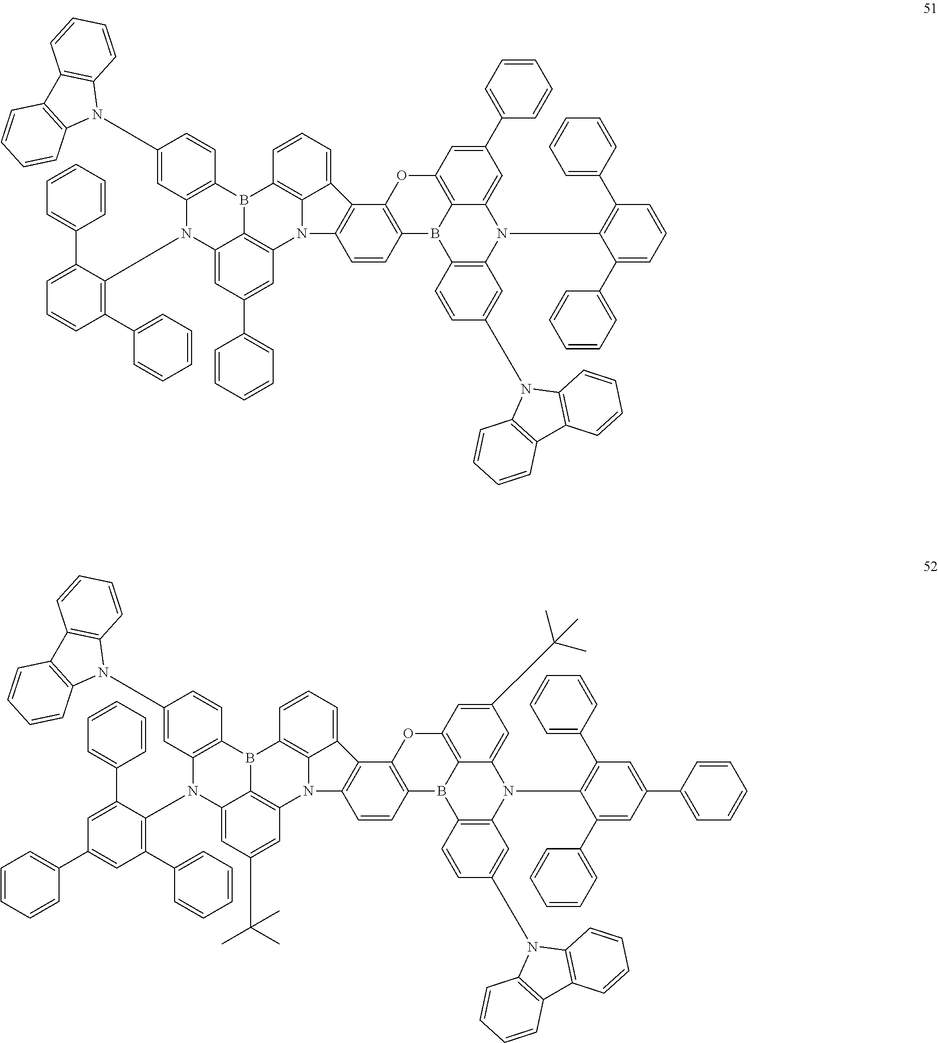 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2N4c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cc(-c2ccccc2)cc1-c1ccccc1]

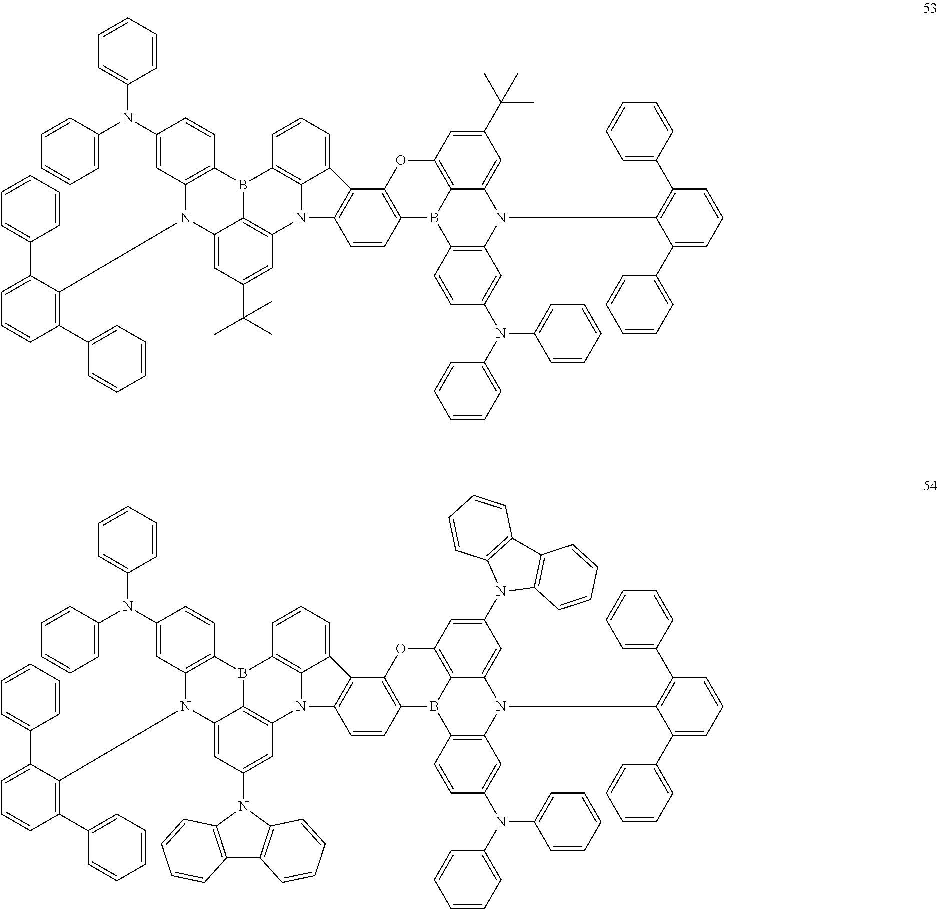 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1N3c1c(-c2ccccc2)cccc1-c1ccccc1 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2N4c2c(-c3ccccc3)cccc2-c2ccccc2)cc1]

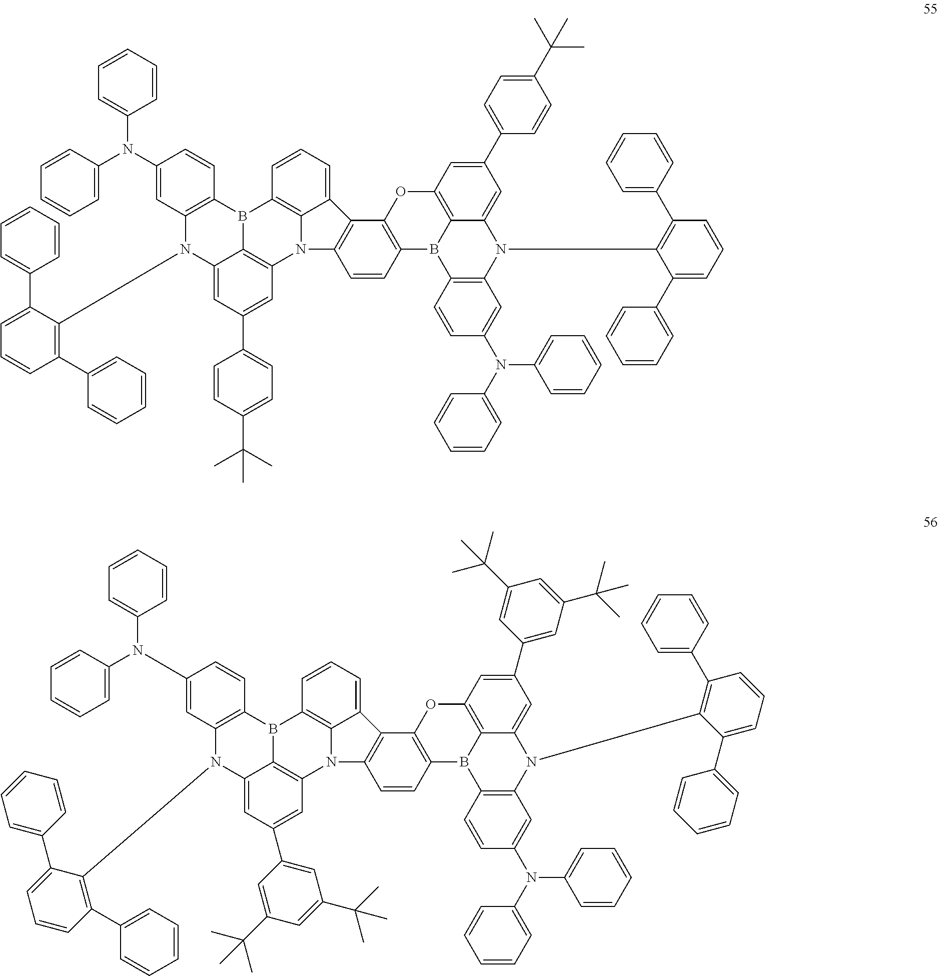 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2N4c2c(-c3ccccc3)cccc2-c2ccccc2)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2N4c2c(-c3ccccc3)cccc2-c2ccccc2)cc(C(C)(C)C)c1]

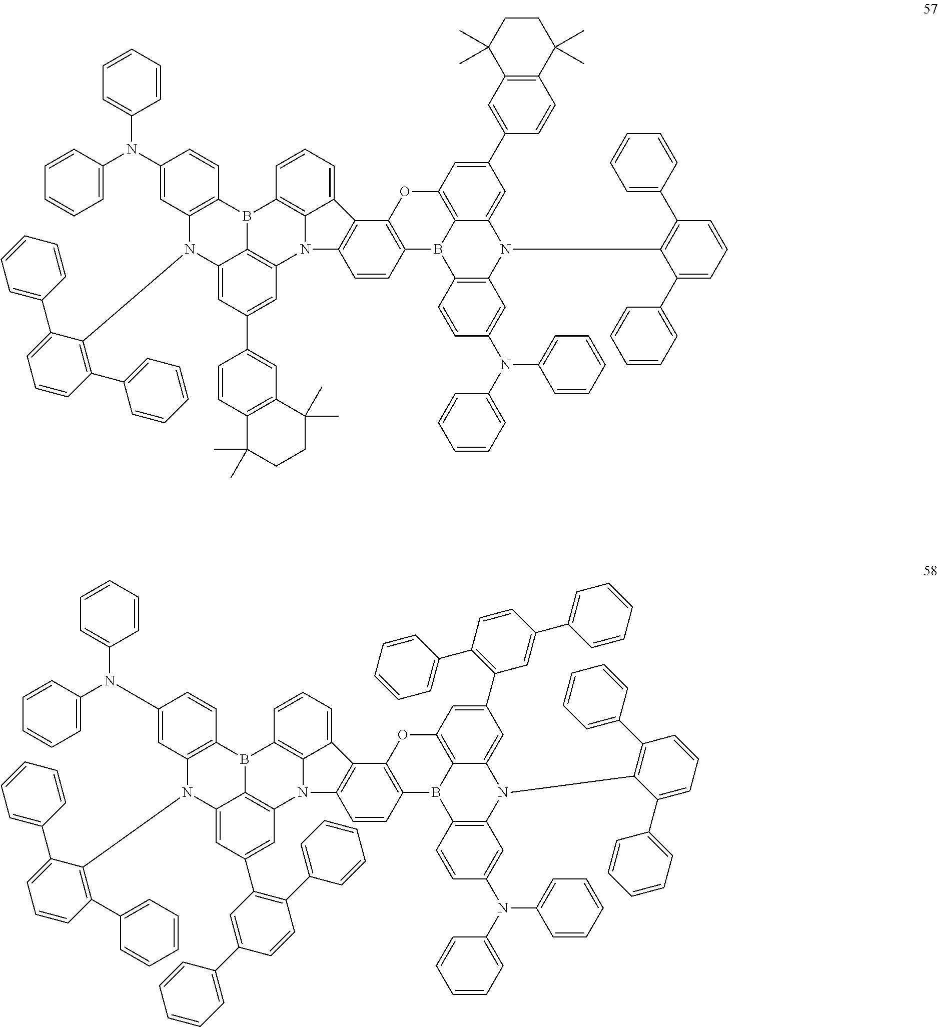 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3N5c3c(-c4ccccc4)cccc3-c3ccccc3)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3N5c3c(-c4ccccc4)cccc3-c3ccccc3)c2)cc1]

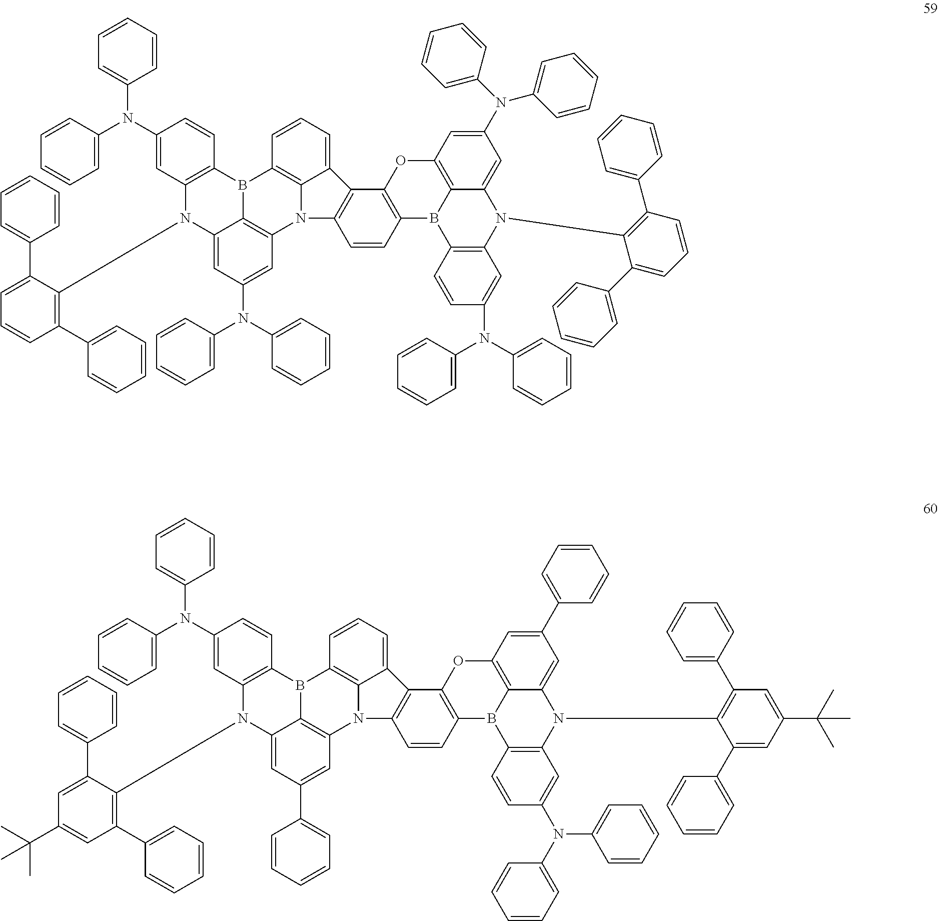 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2N4c2c(-c3ccccc3)cccc2-c2ccccc2)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2N4c2c(-c3ccccc3)cc(C(C)(C)C)cc2-c2ccccc2)c(-c2ccccc2)c1]

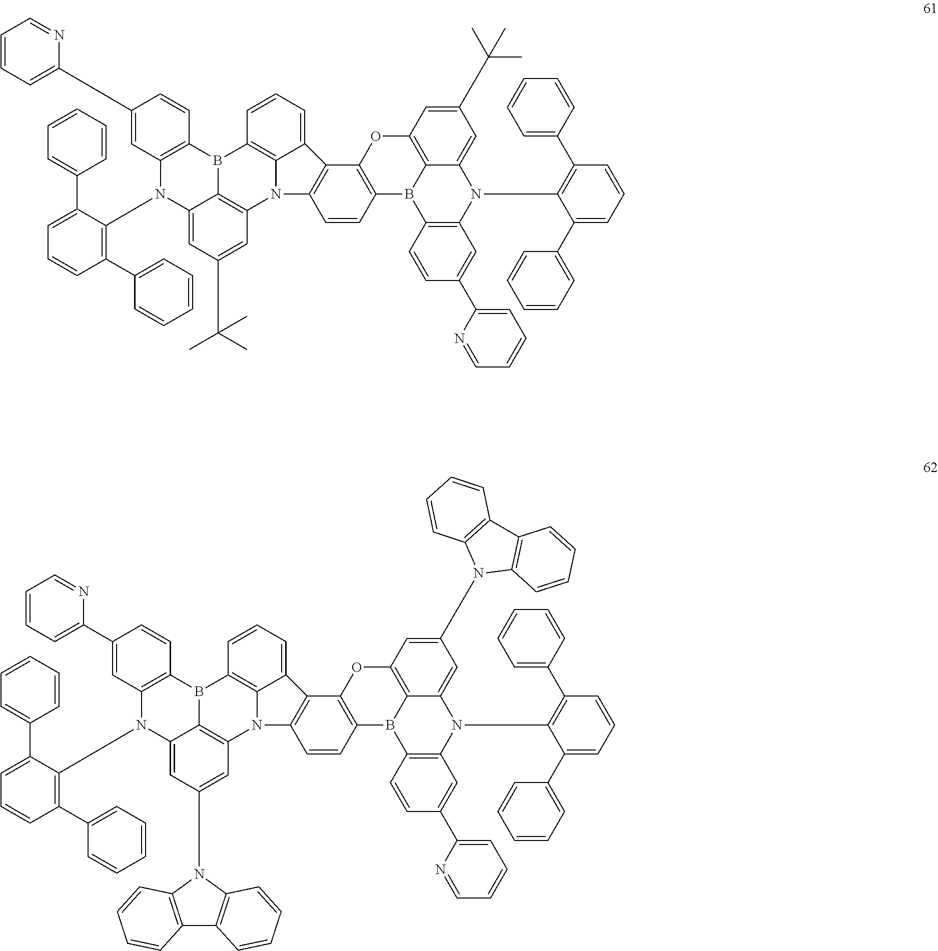 [SMILES: CC(C)(C)c1cc2c3c(c1)N(c1c(-c4ccccc4)cccc1-c1ccccc1)c1cc(-c4ccccn4)ccc1B3c1ccc3c(c1O2)c1cccc2c1n3-c1cc(C(C)(C)C)cc3c1B2c1ccc(-c2ccccn2)cc1N3c1c(-c2ccccc2)cccc1-c1ccccc1 ; c1ccc(-c2cccc(-c3ccccc3)c2N2c3cc(-c4ccccn4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(-c3ccccn3)cc2N4c2c(-c3ccccc3)cccc2-c2ccccc2)cc1]

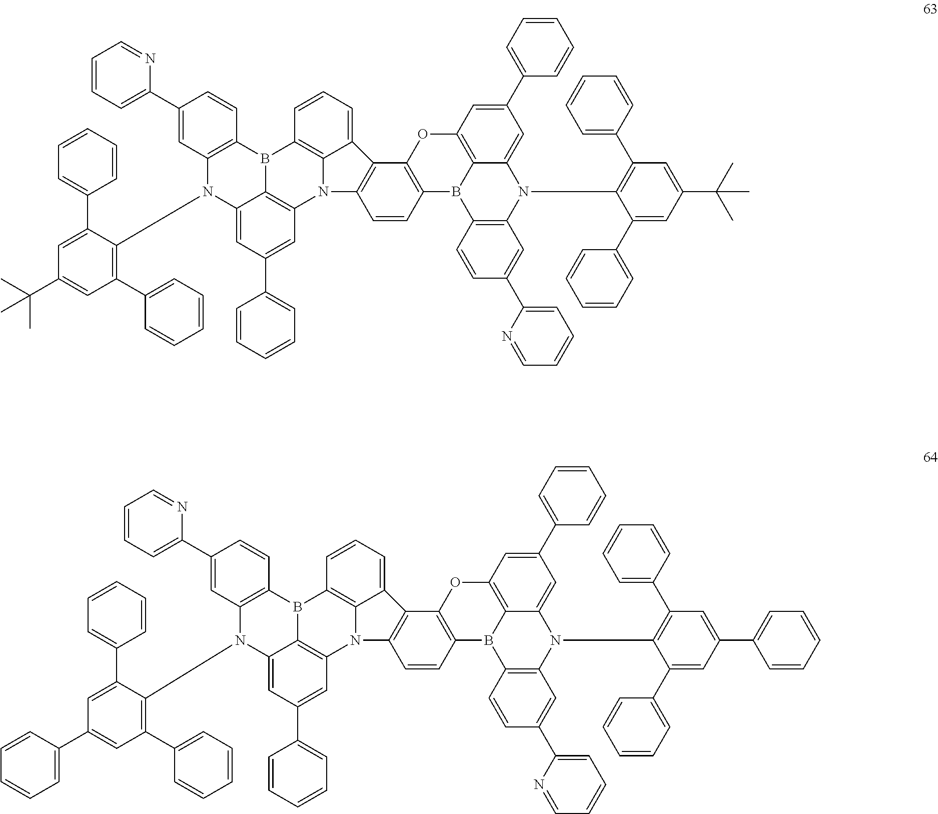 [SMILES: CC(C)(C)c1cc(-c2ccccc2)c(N2c3cc(-c4ccccn4)ccc3B3c4ccc5c(c4Oc4cc(-c6ccccc6)cc2c43)c2cccc3c2n5-c2cc(-c4ccccc4)cc4c2B3c2ccc(-c3ccccn3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccccn5)ccc4B4c5ccc6c(c5Oc5cc(-c7ccccc7)cc3c54)c3cccc4c3n6-c3cc(-c5ccccc5)cc5c3B4c3ccc(-c4ccccn4)cc3N5c3c(-c4ccccc4)cc(-c4ccccc4)cc3-c3ccccc3)c(-c3ccccc3)c2)cc1]

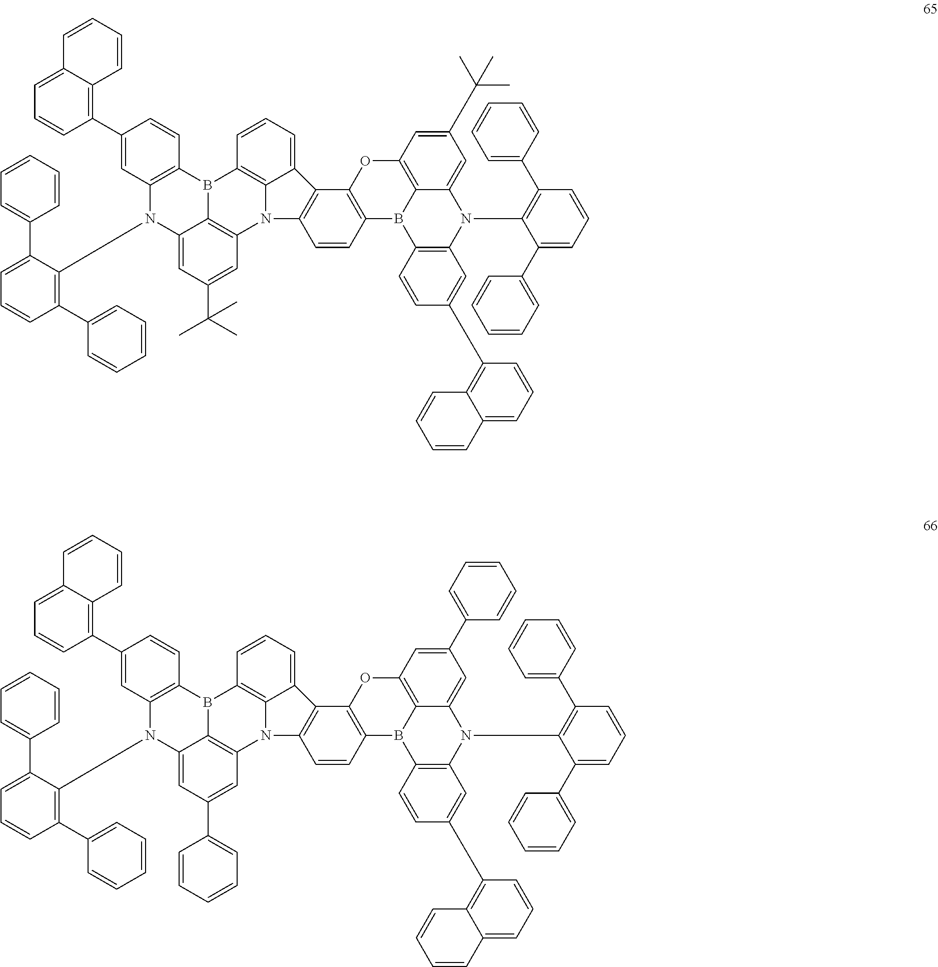 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1N3c1c(-c2ccccc2)cccc1-c1ccccc1 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2N4c2c(-c3ccccc3)cccc2-c2ccccc2)cc1]

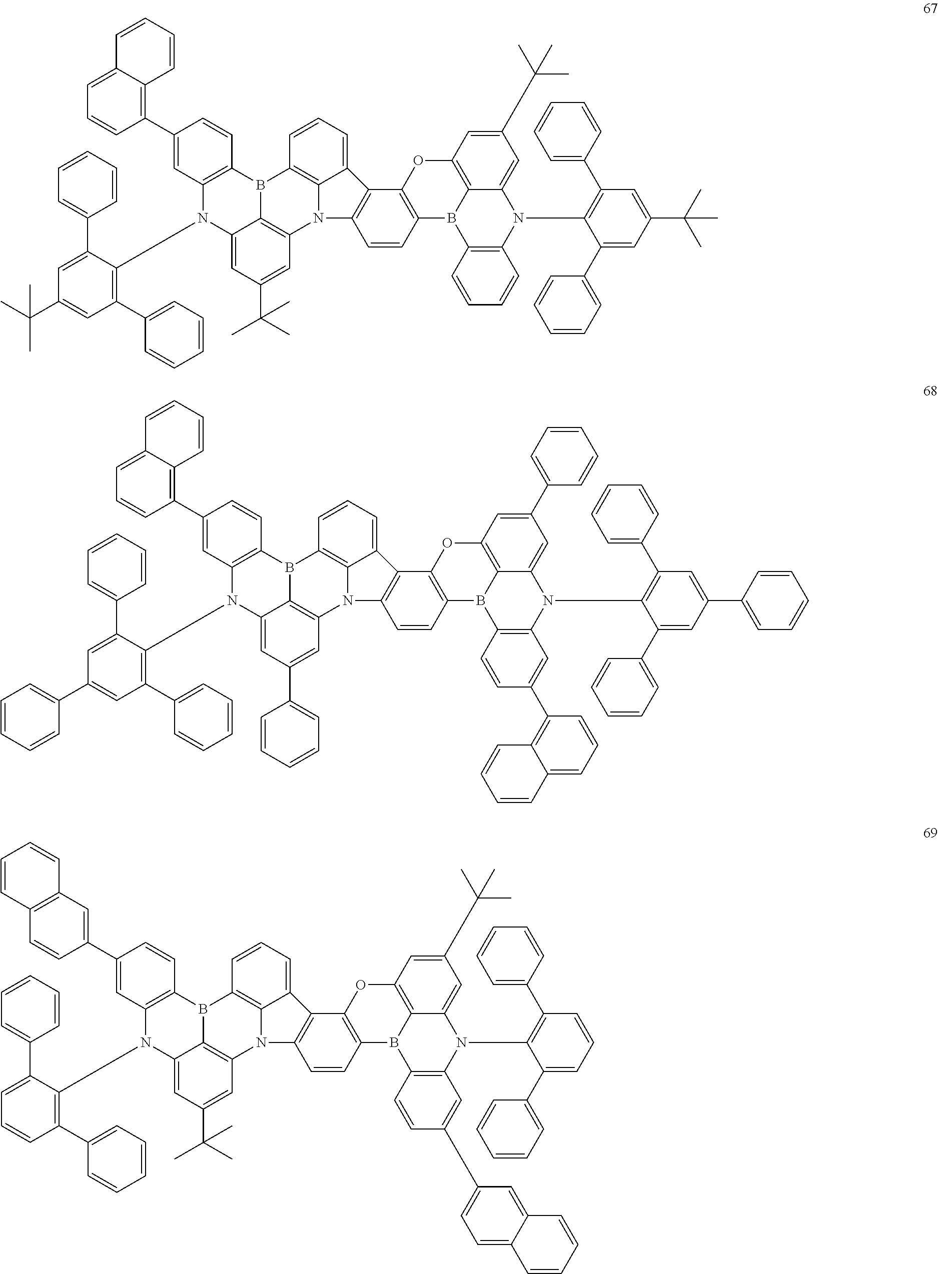

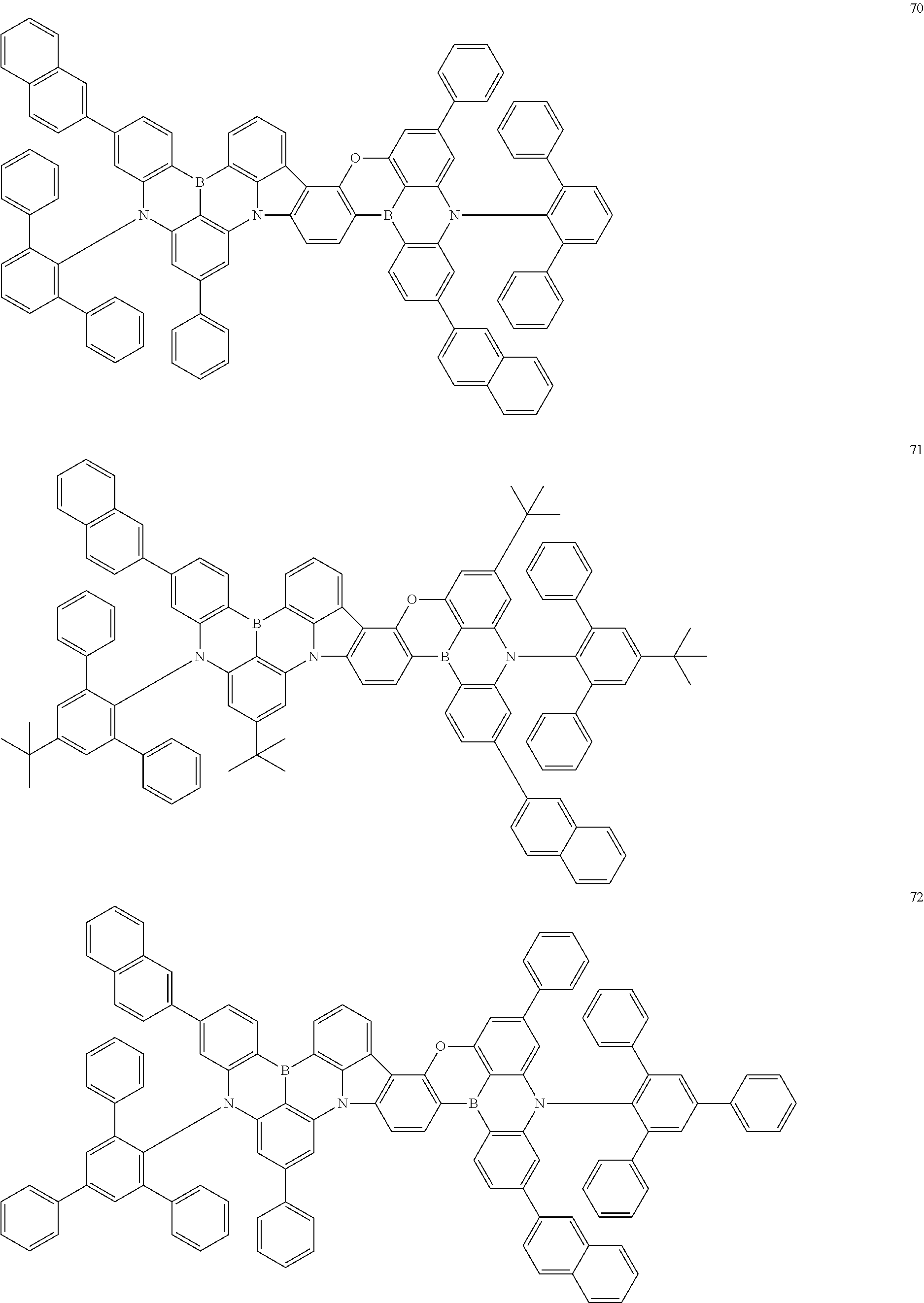

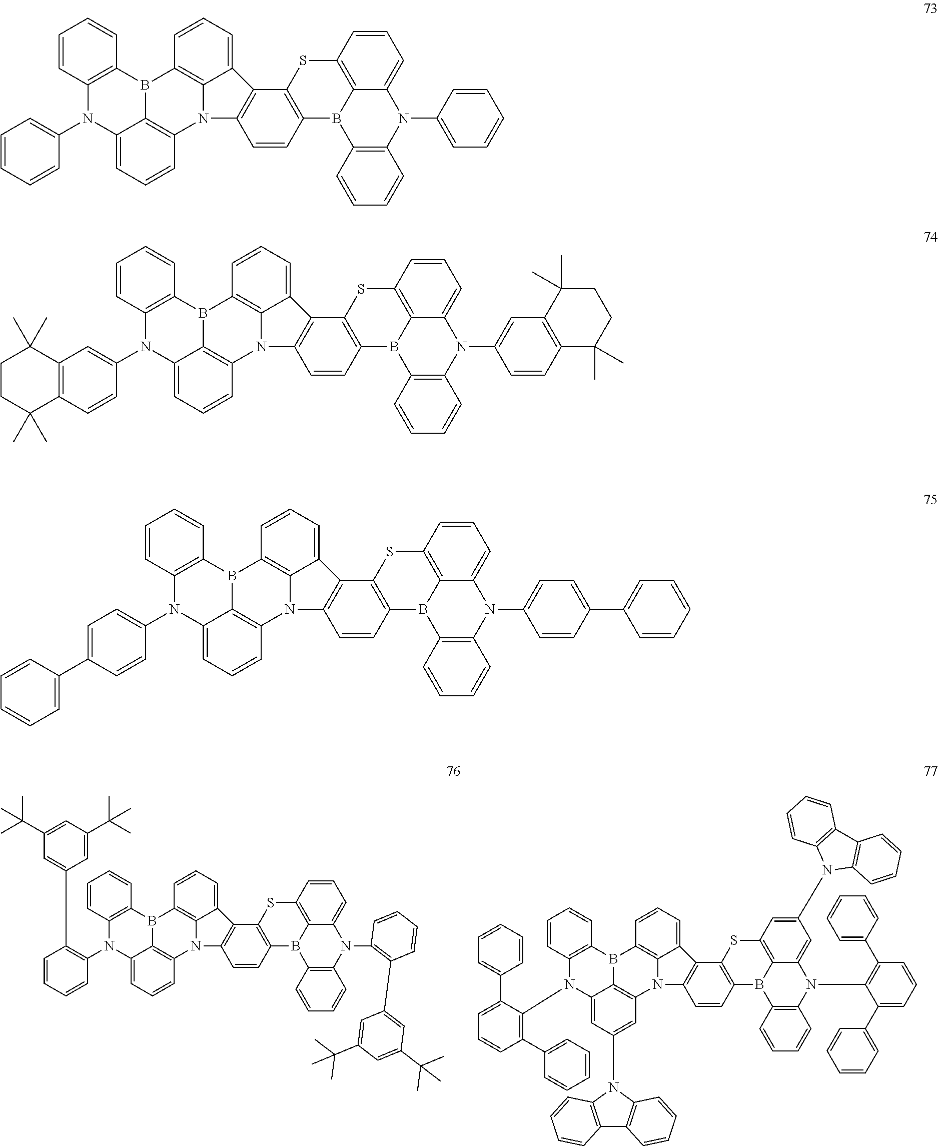

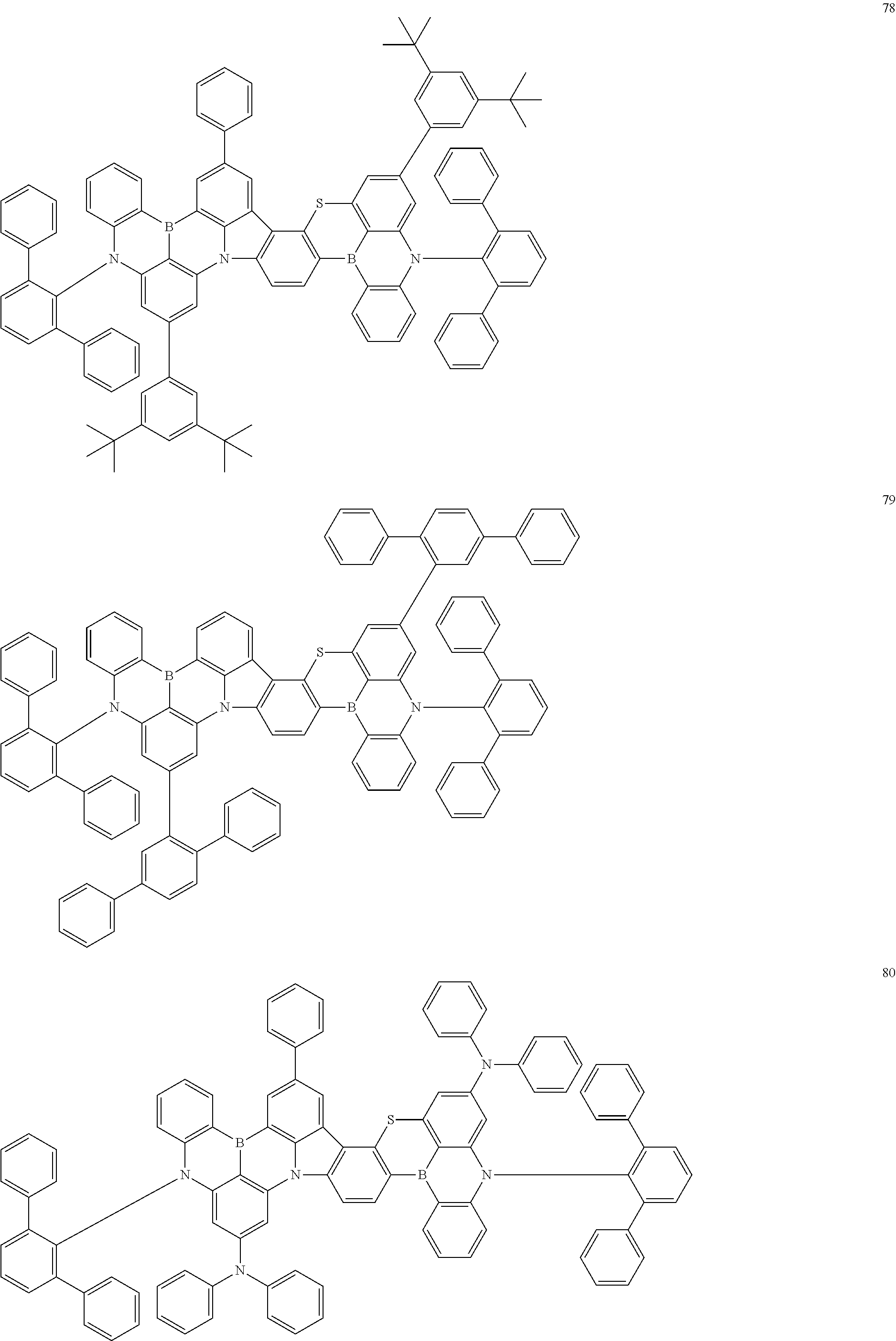

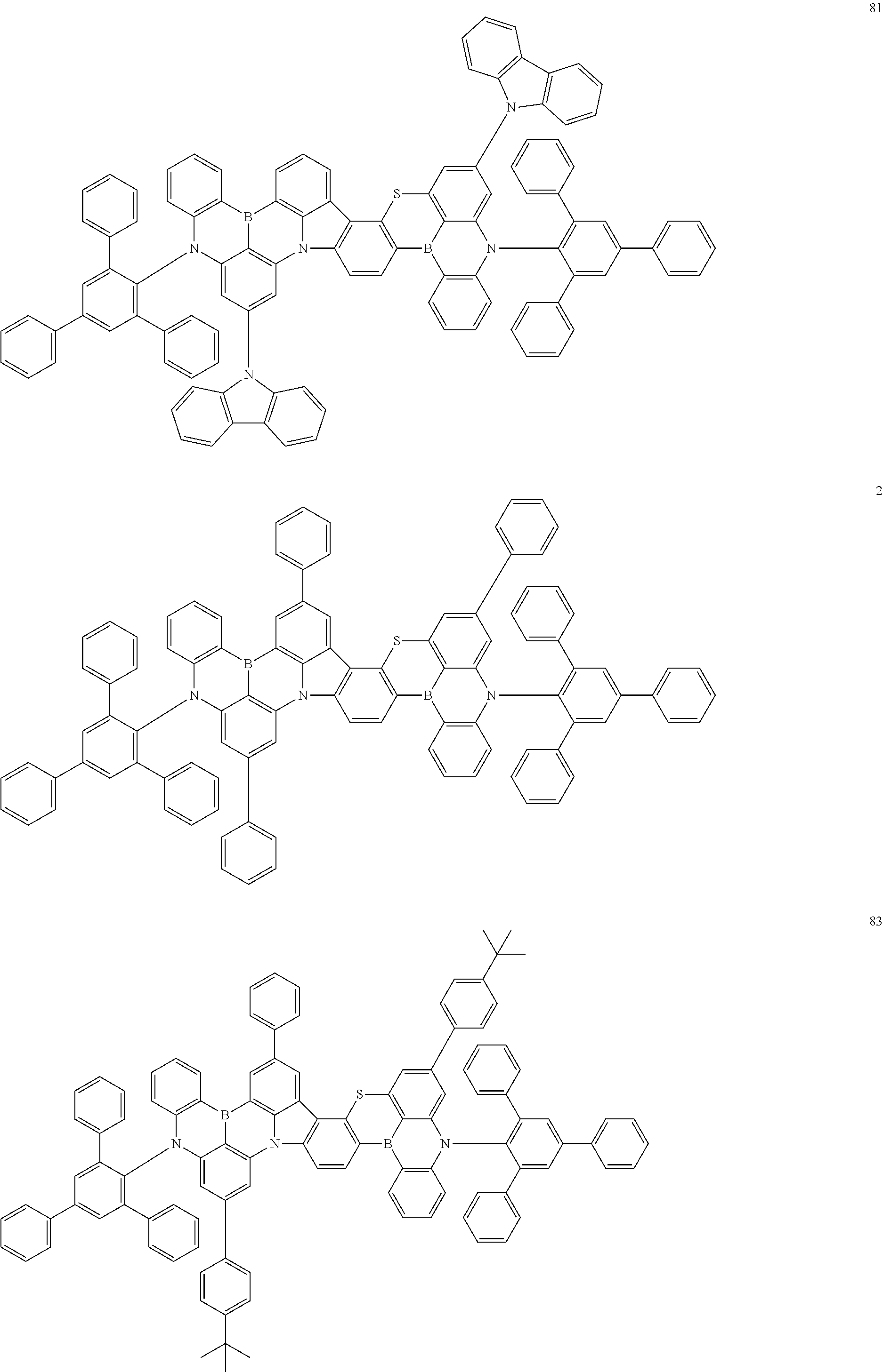

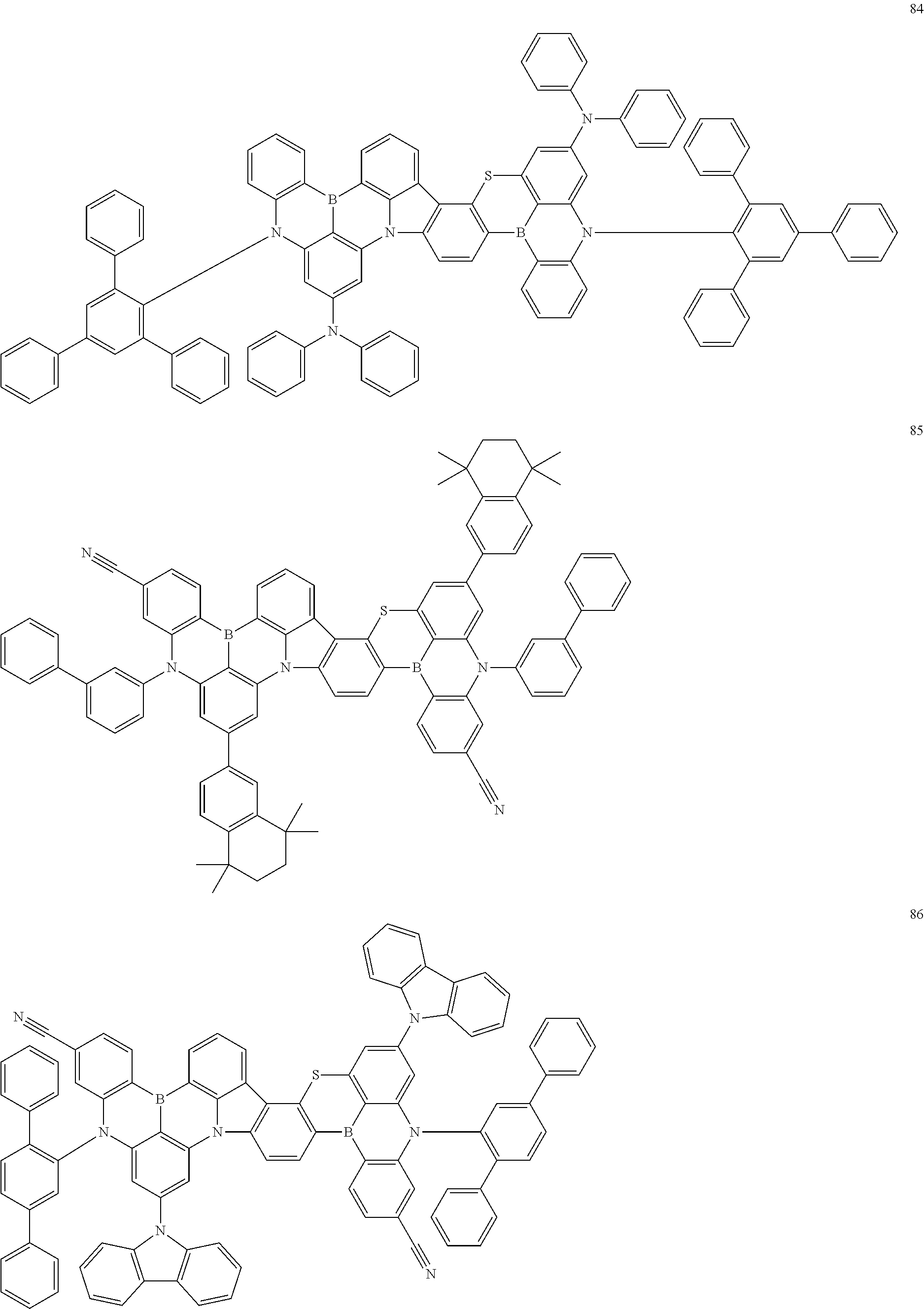

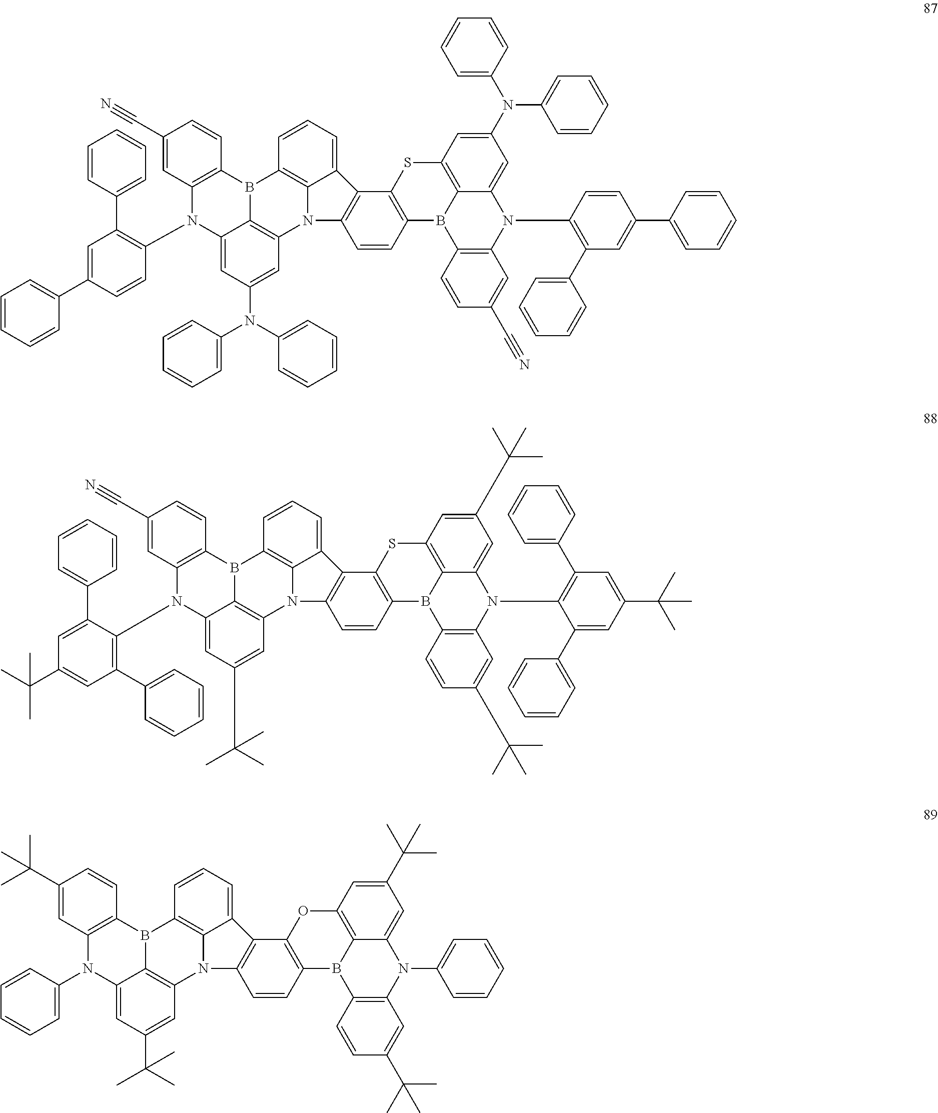 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C(C)(C)C)ccc3B3c4ccc5c(c4Sc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1 ; CC(C)(C)c1ccc2c(c1)N(c1ccccc1)c1cc(C(C)(C)C)cc3c1B2c1ccc2c(c1O3)c1cccc3c1n2-c1cc(C(C)(C)C)cc2c1B3c1ccc(C(C)(C)C)cc1N2c1ccccc1]

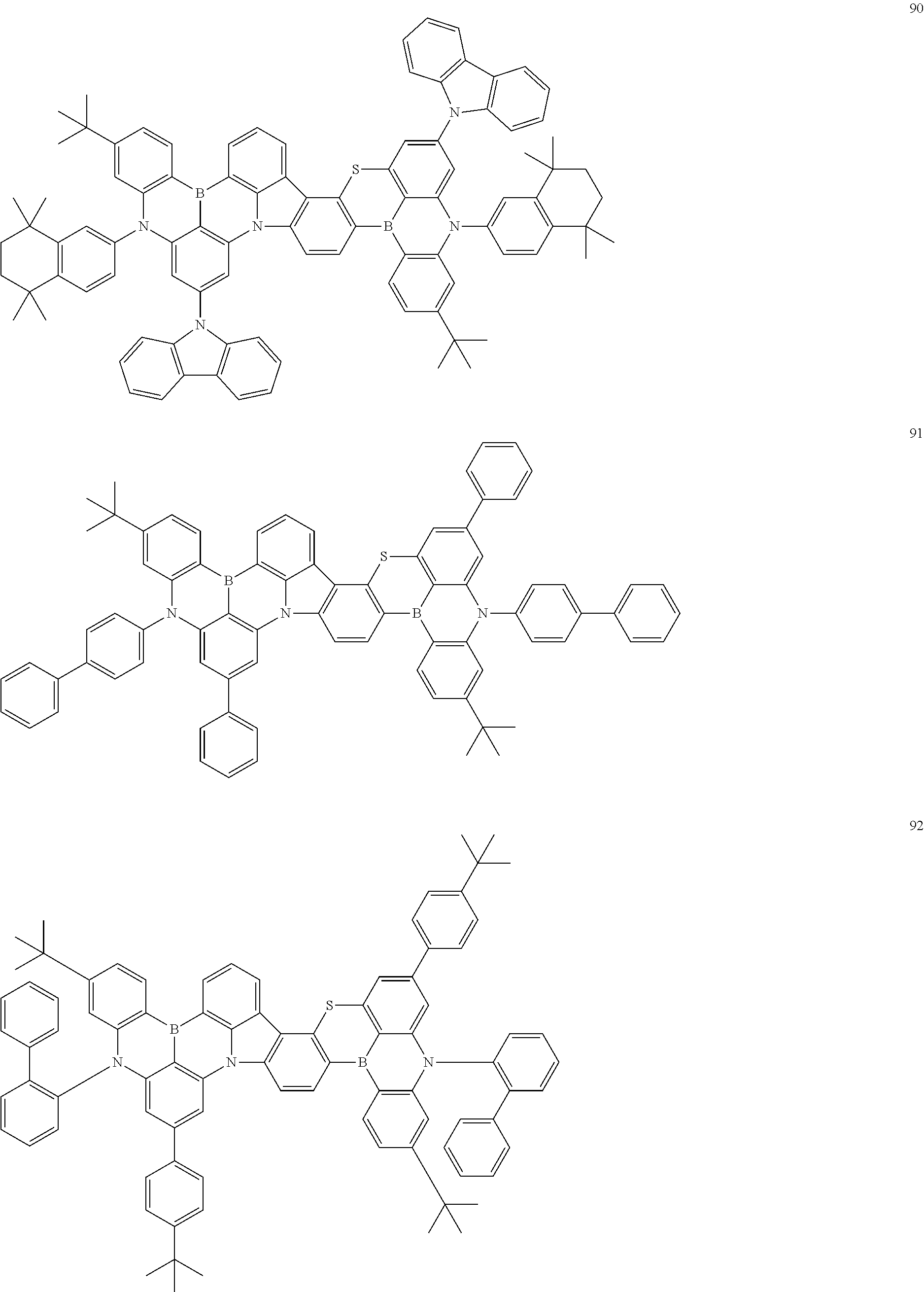

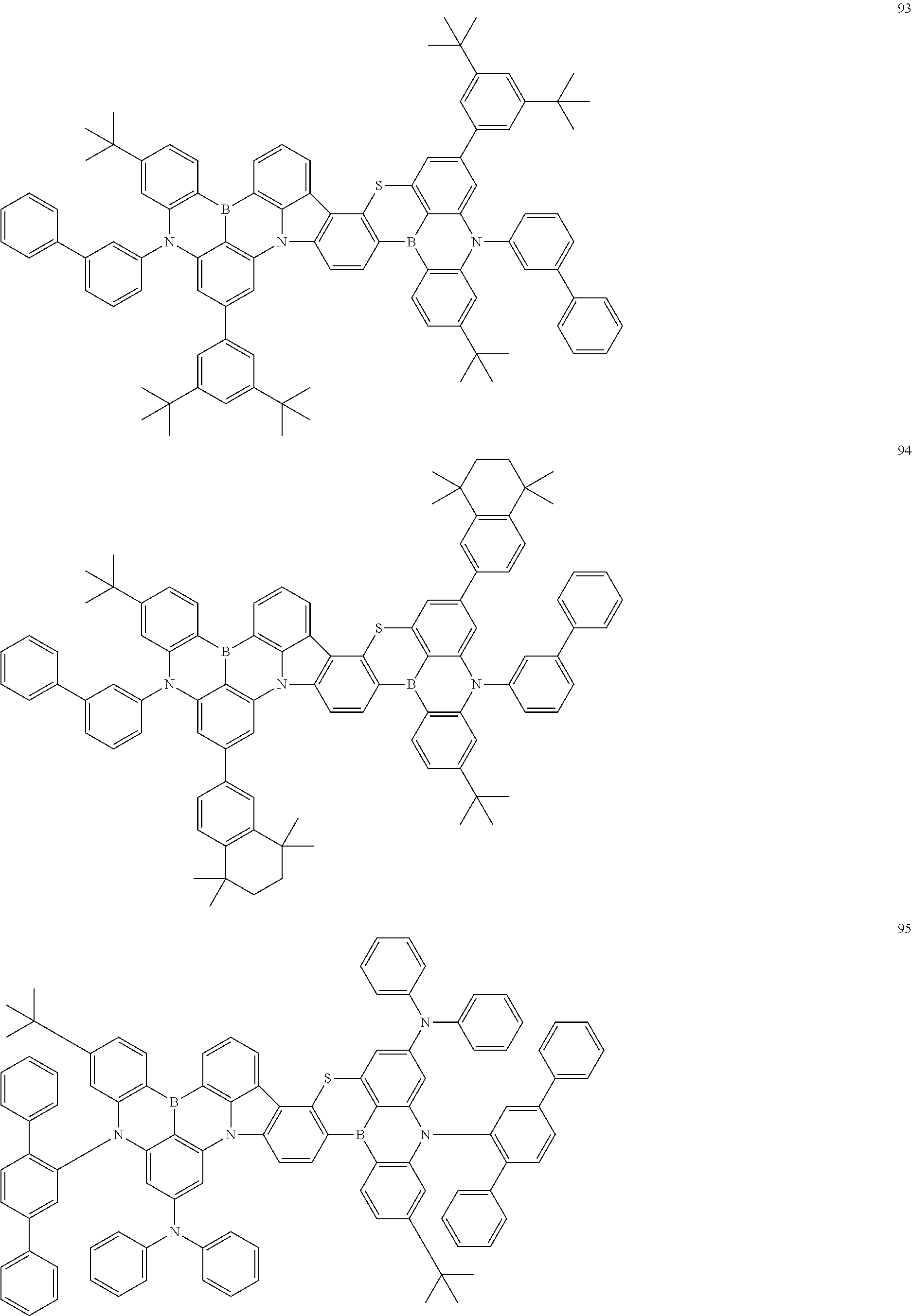

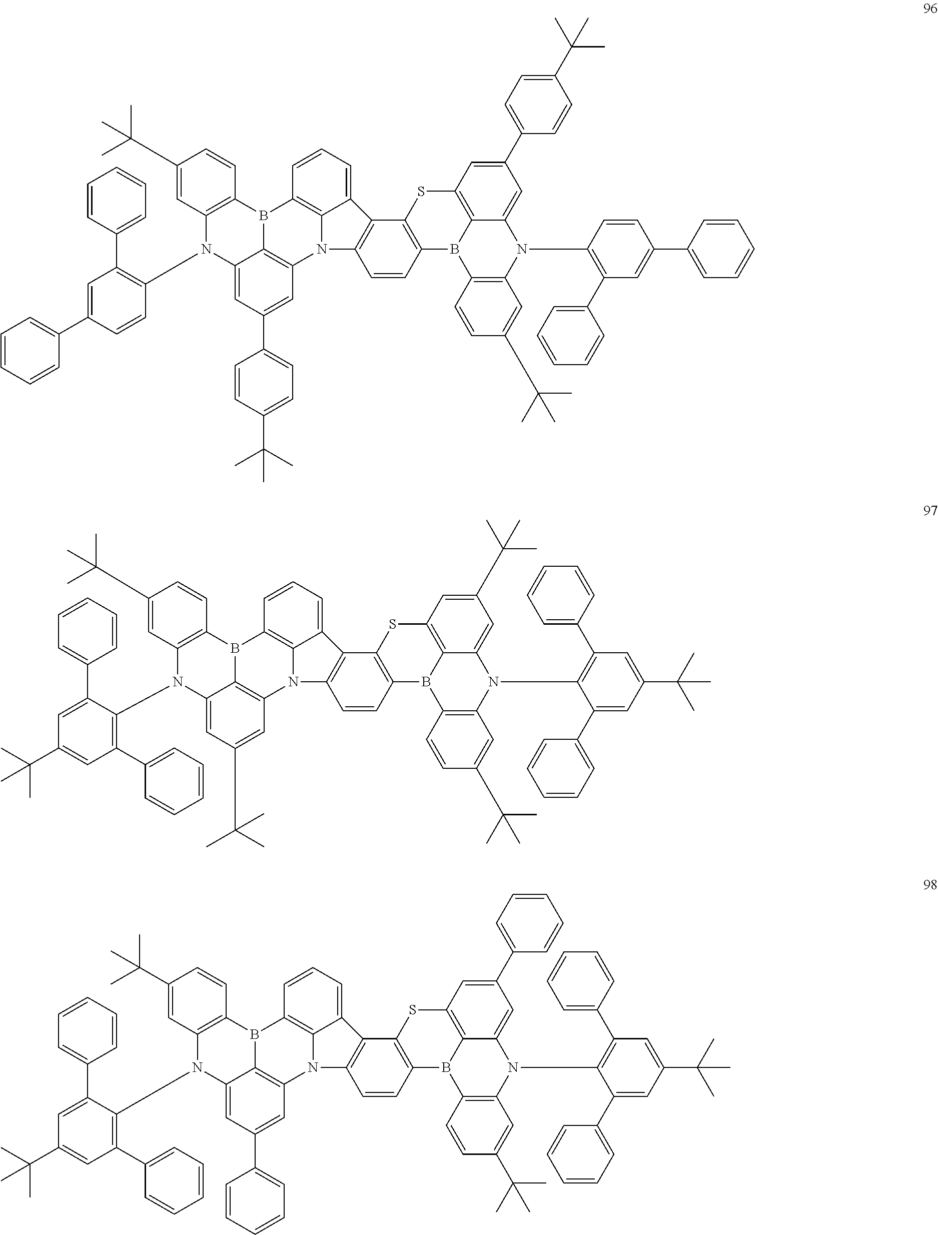

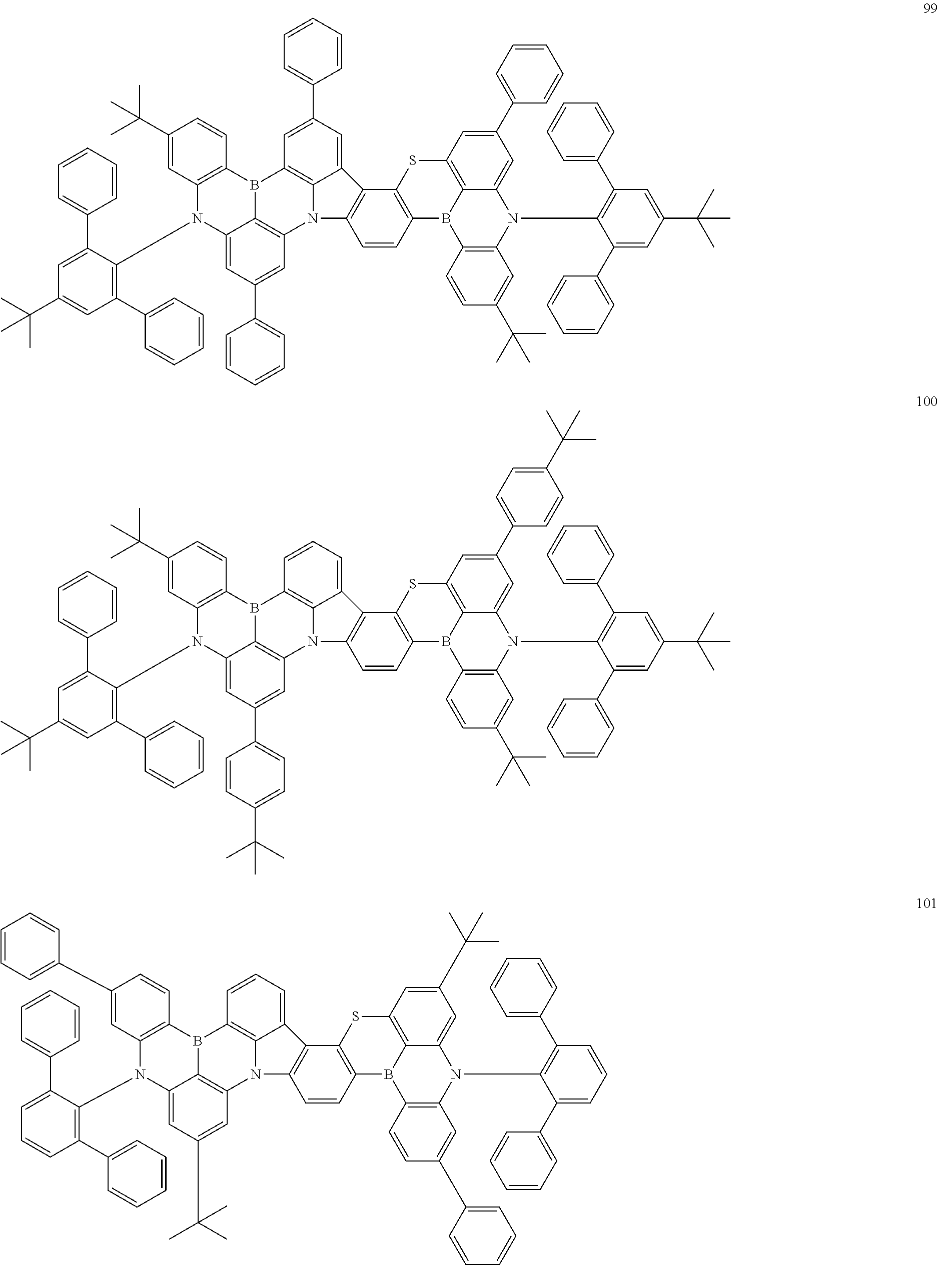

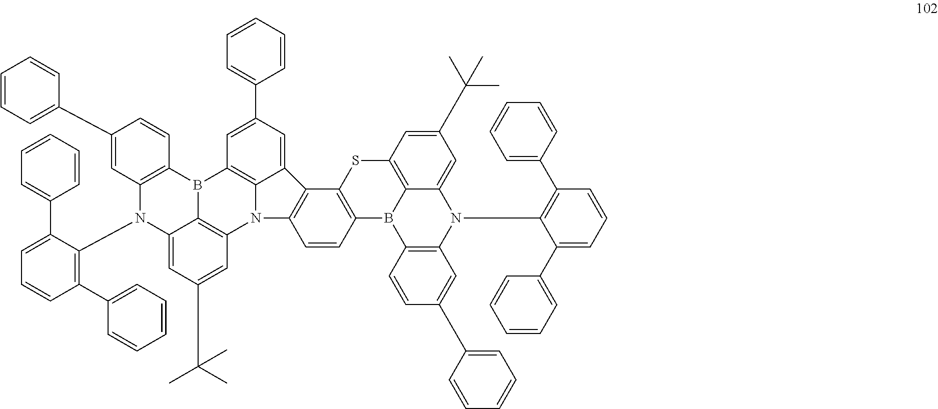 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1]

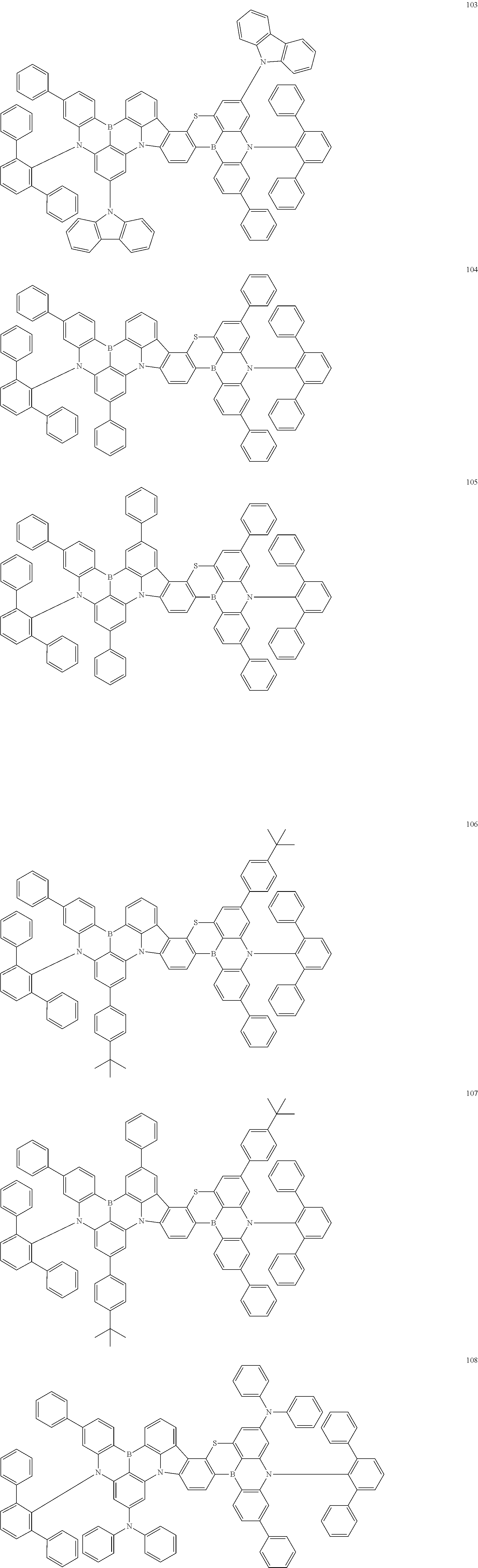

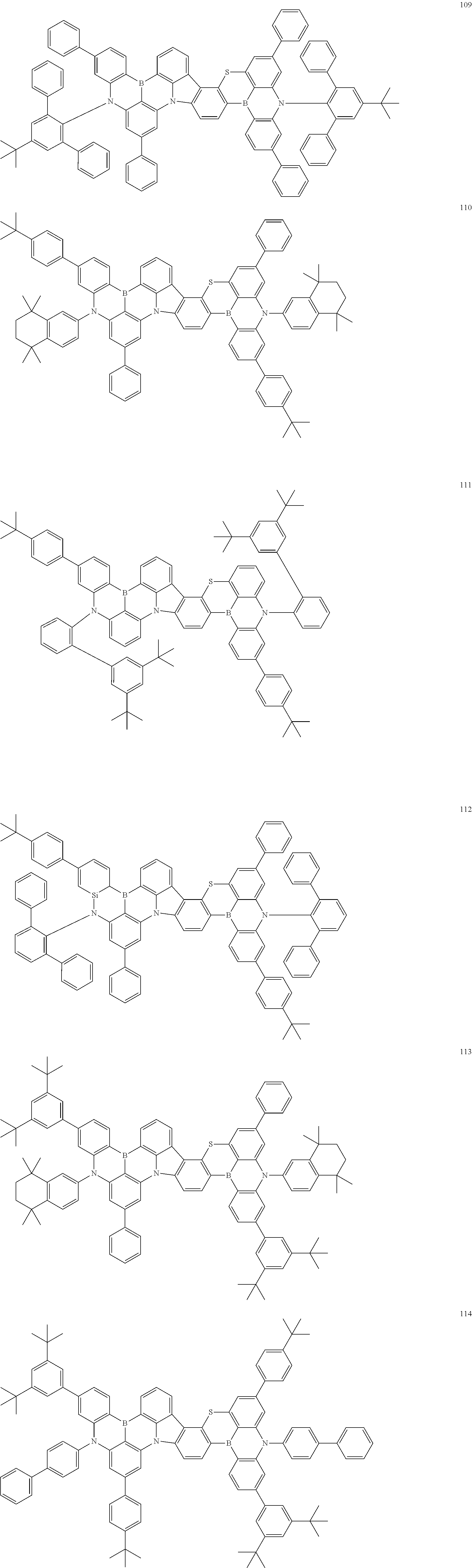

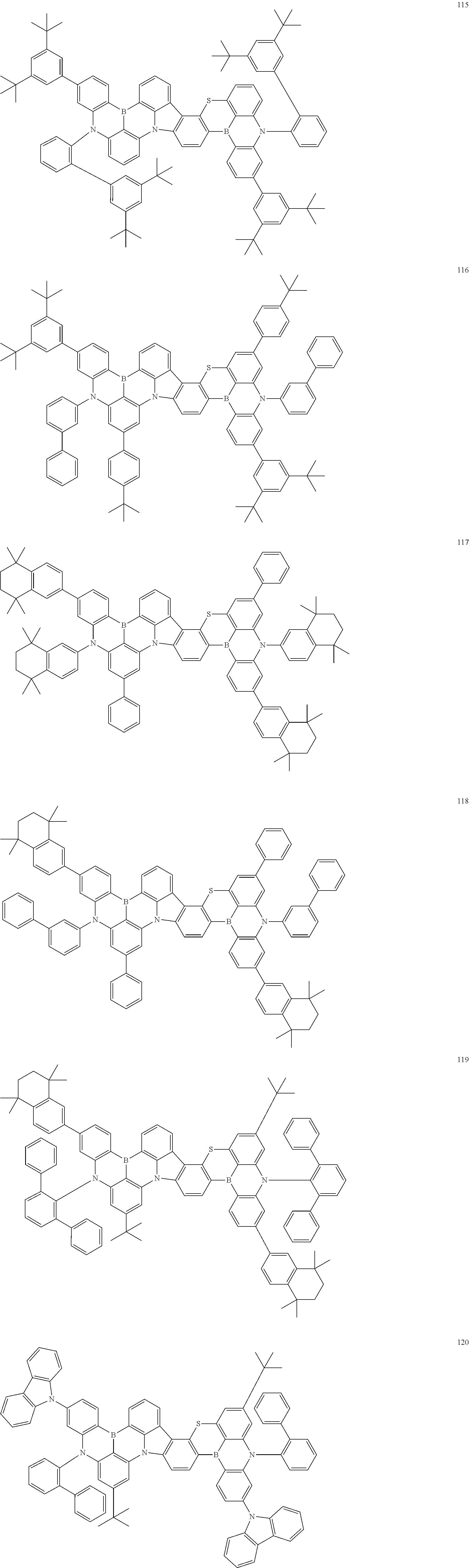

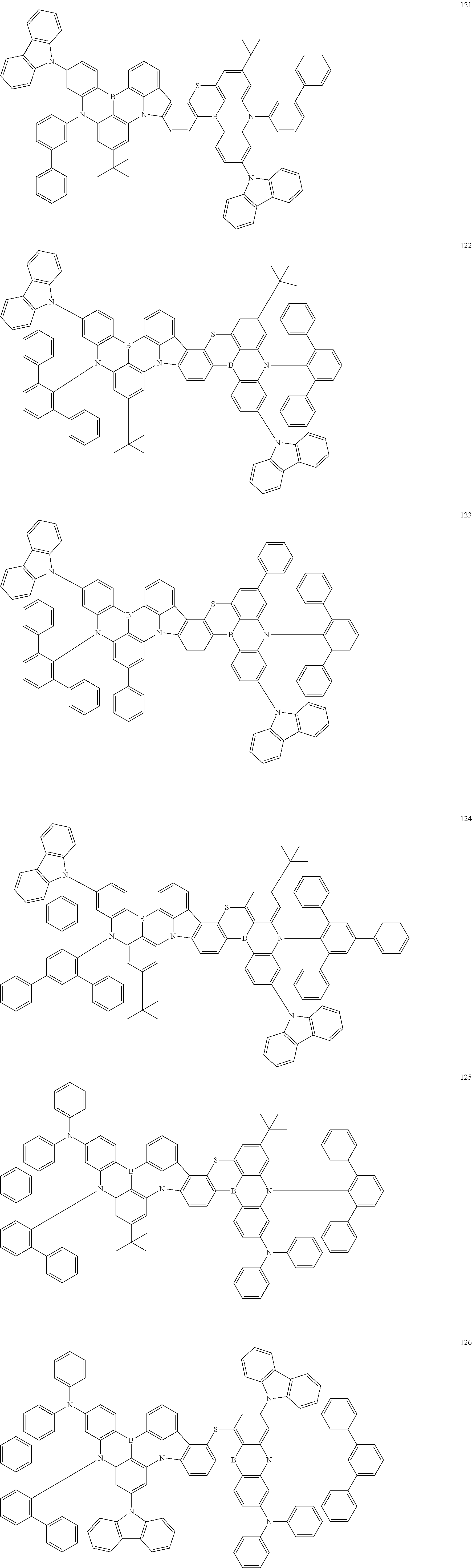

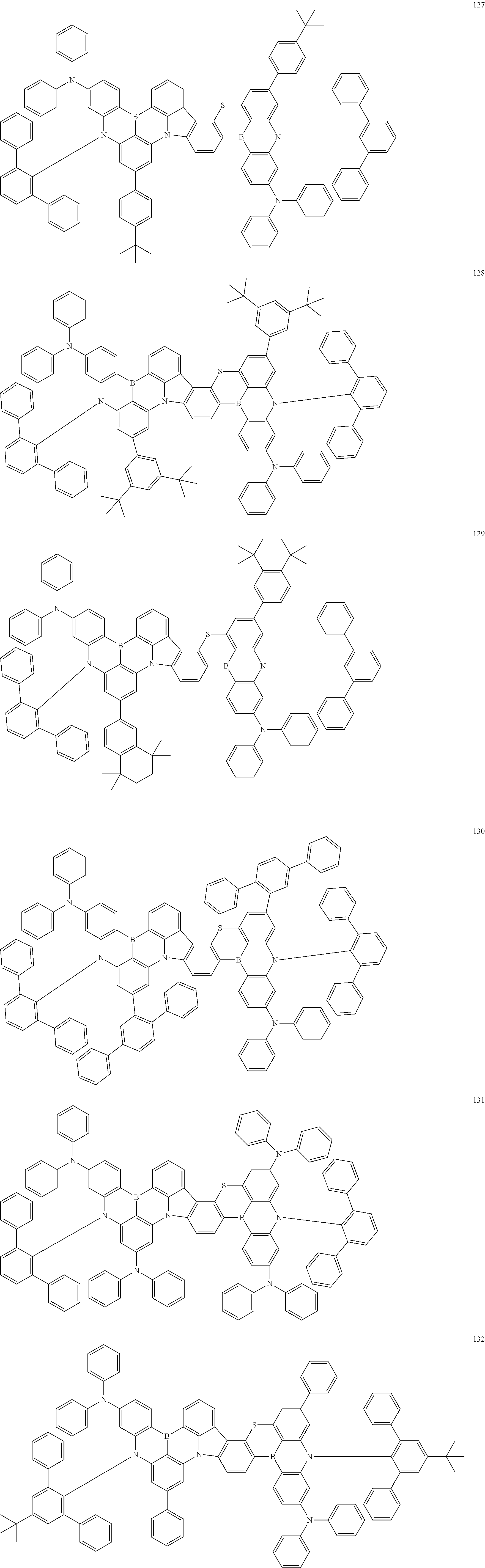

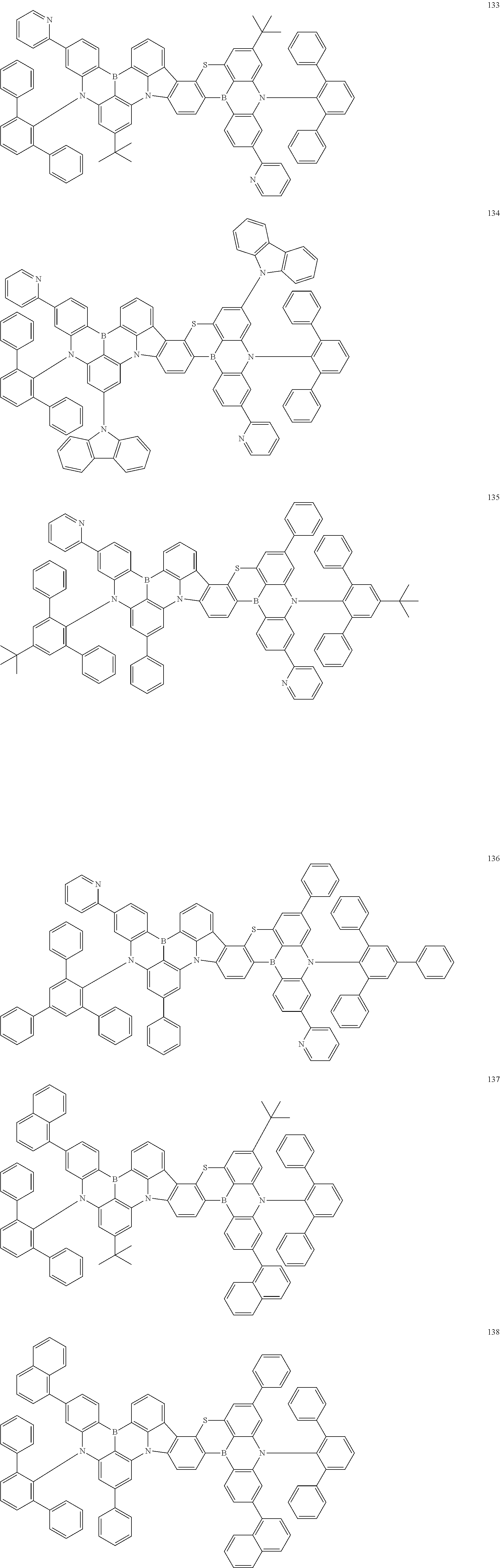

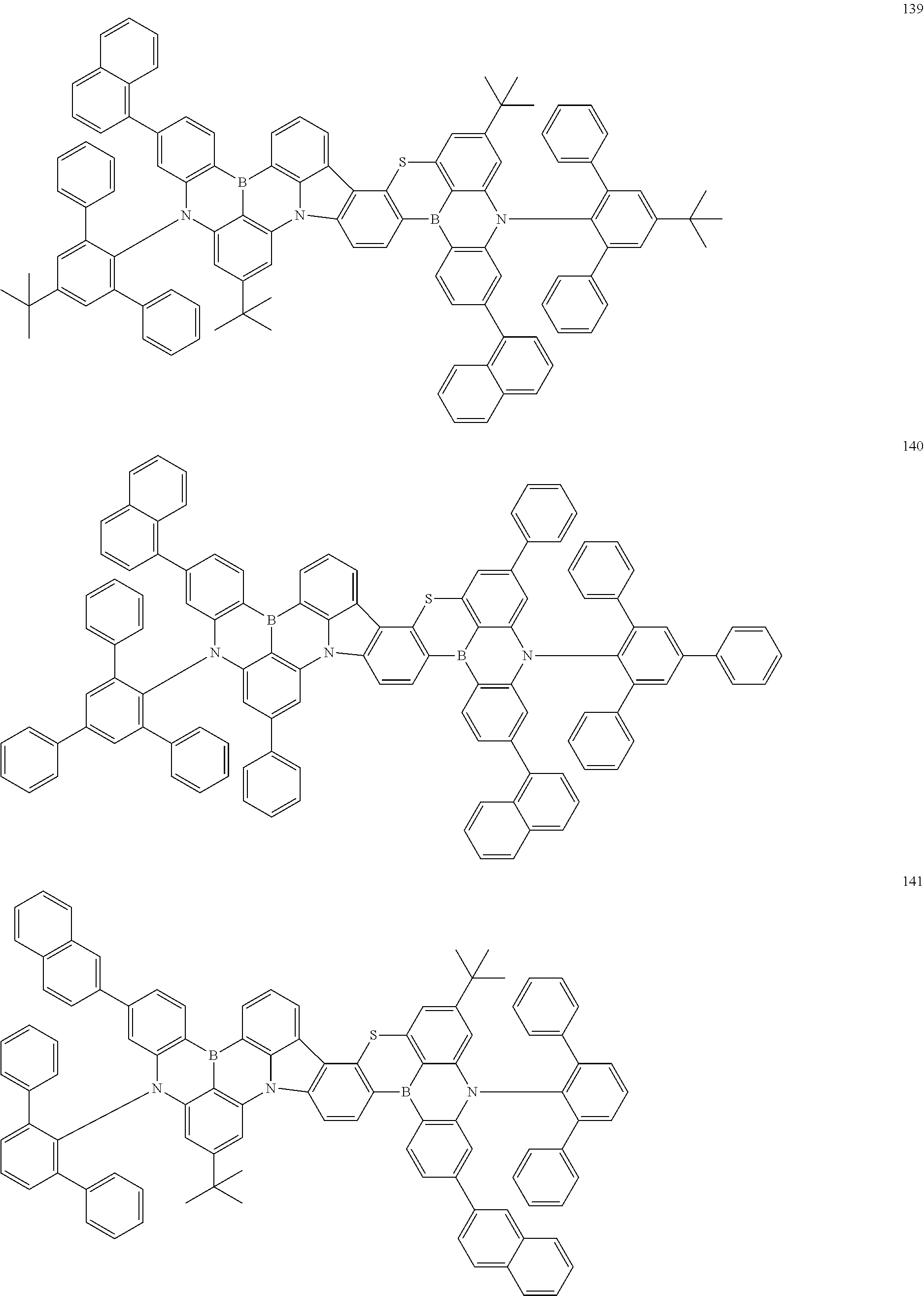

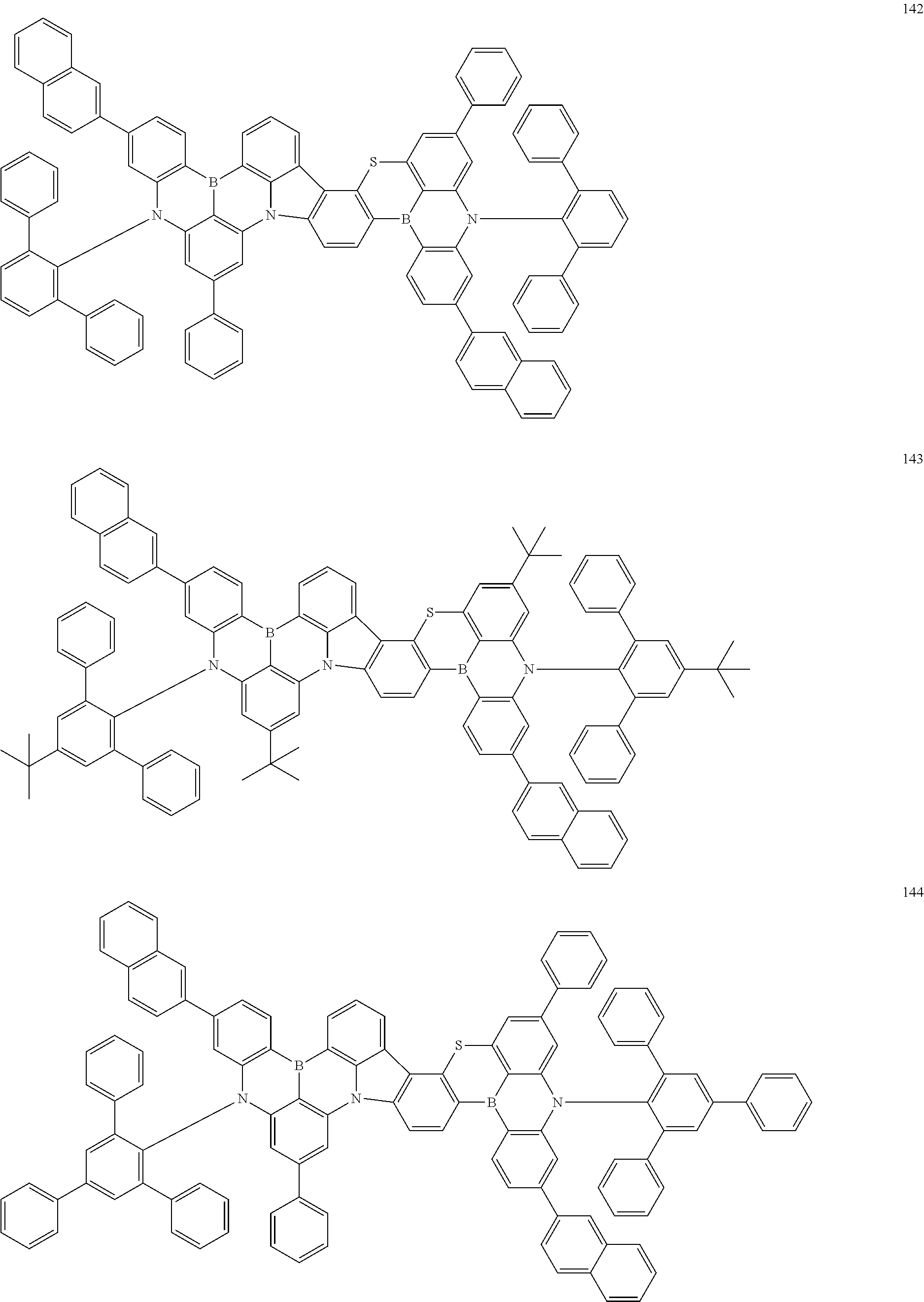

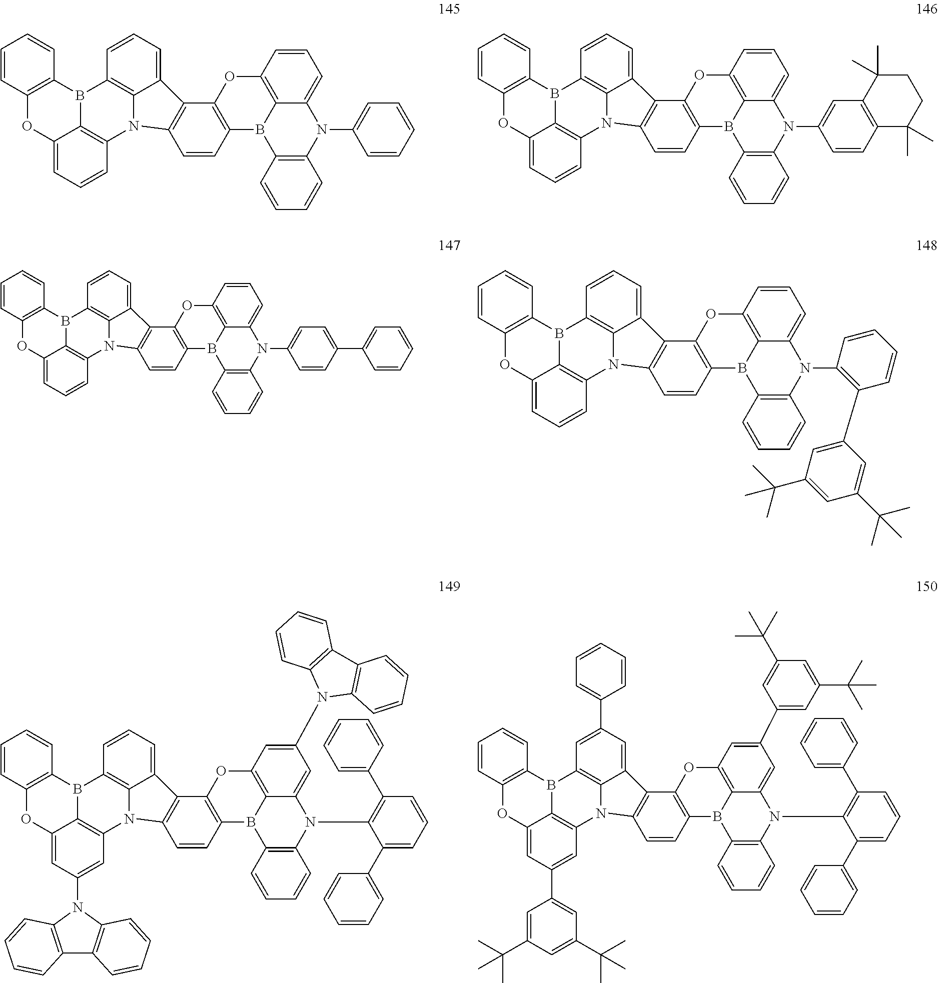

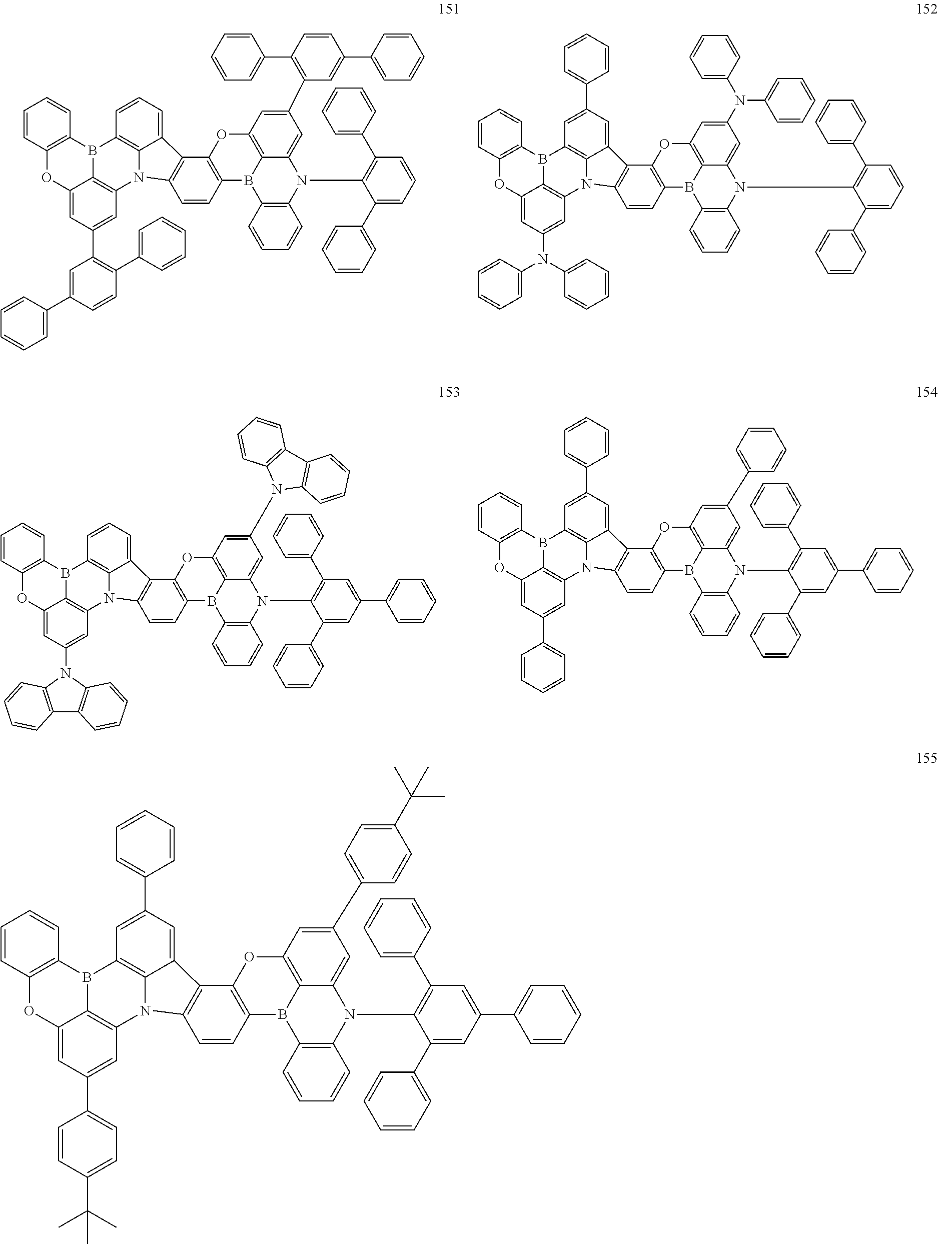

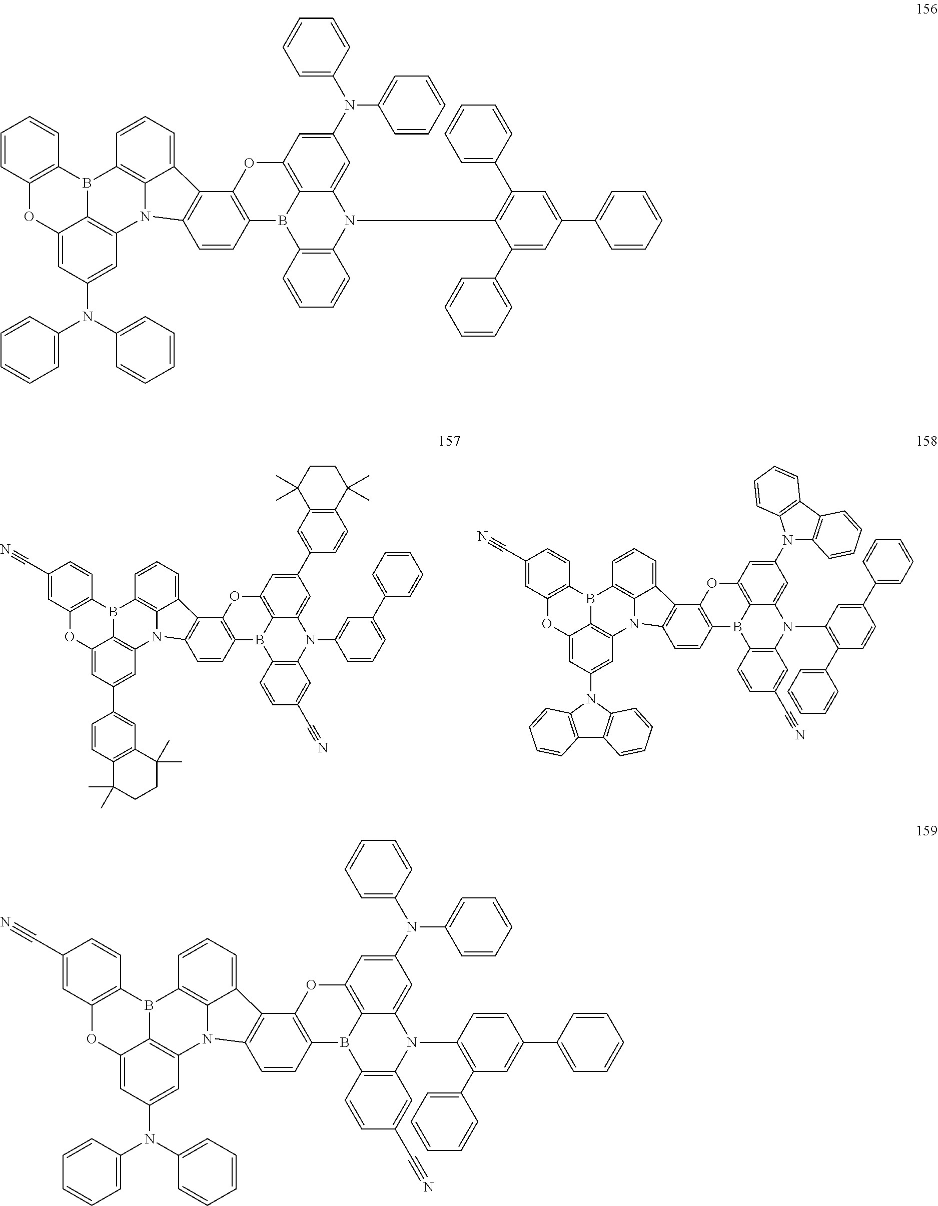

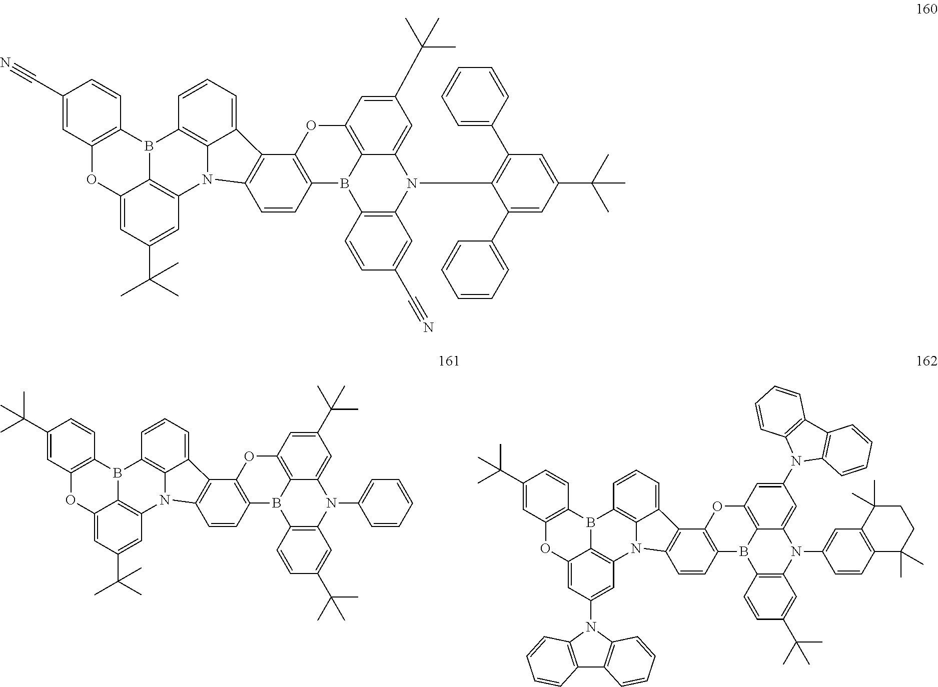

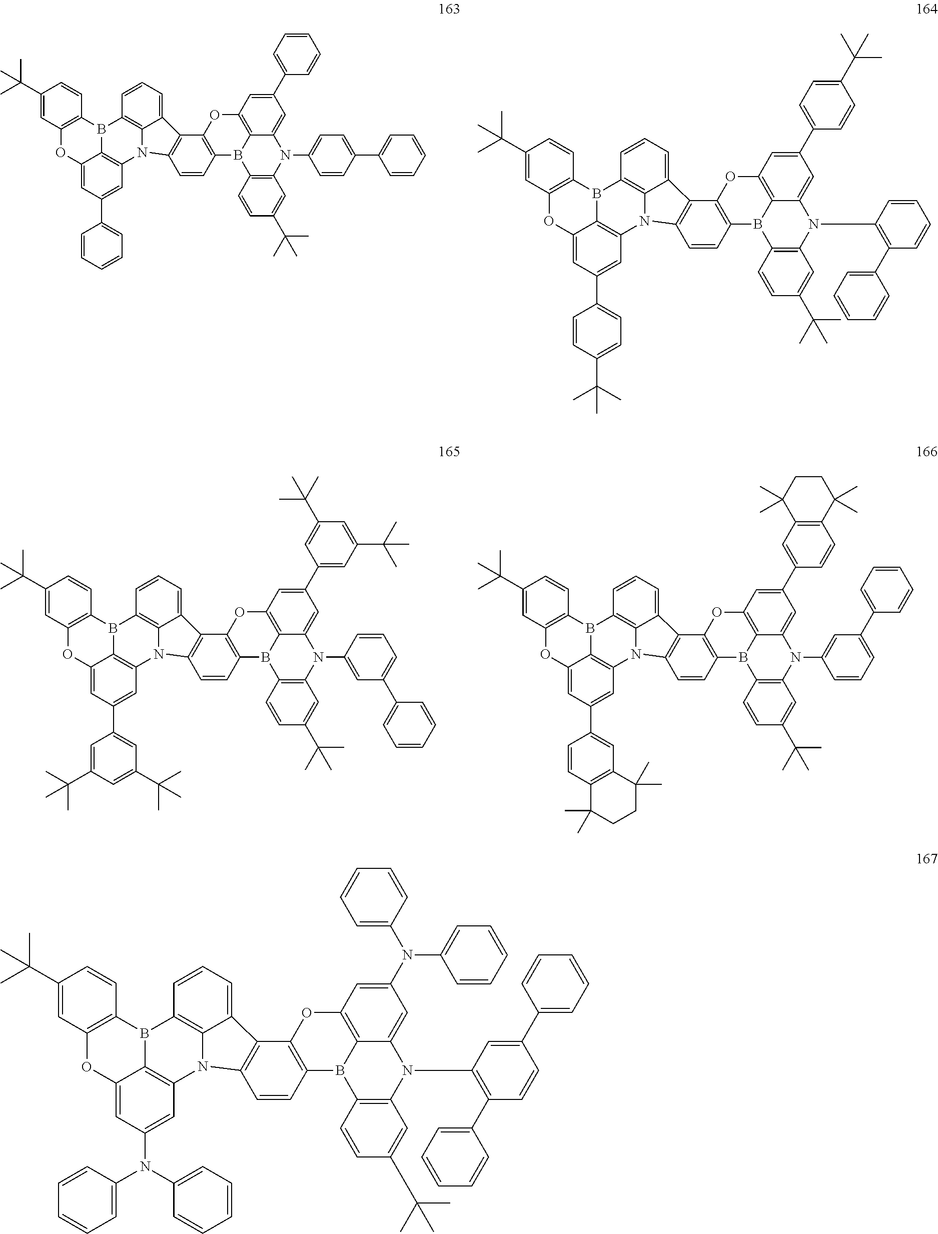

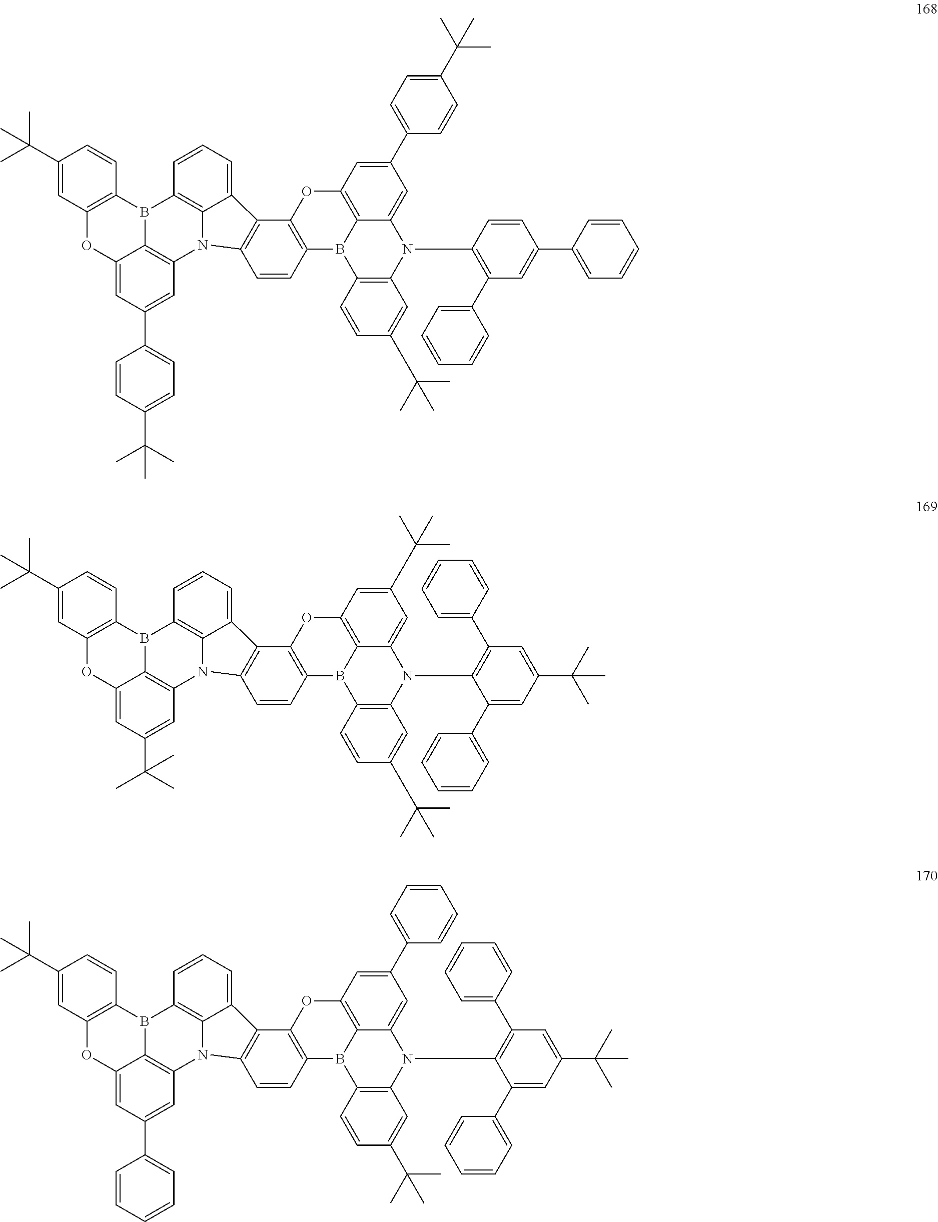

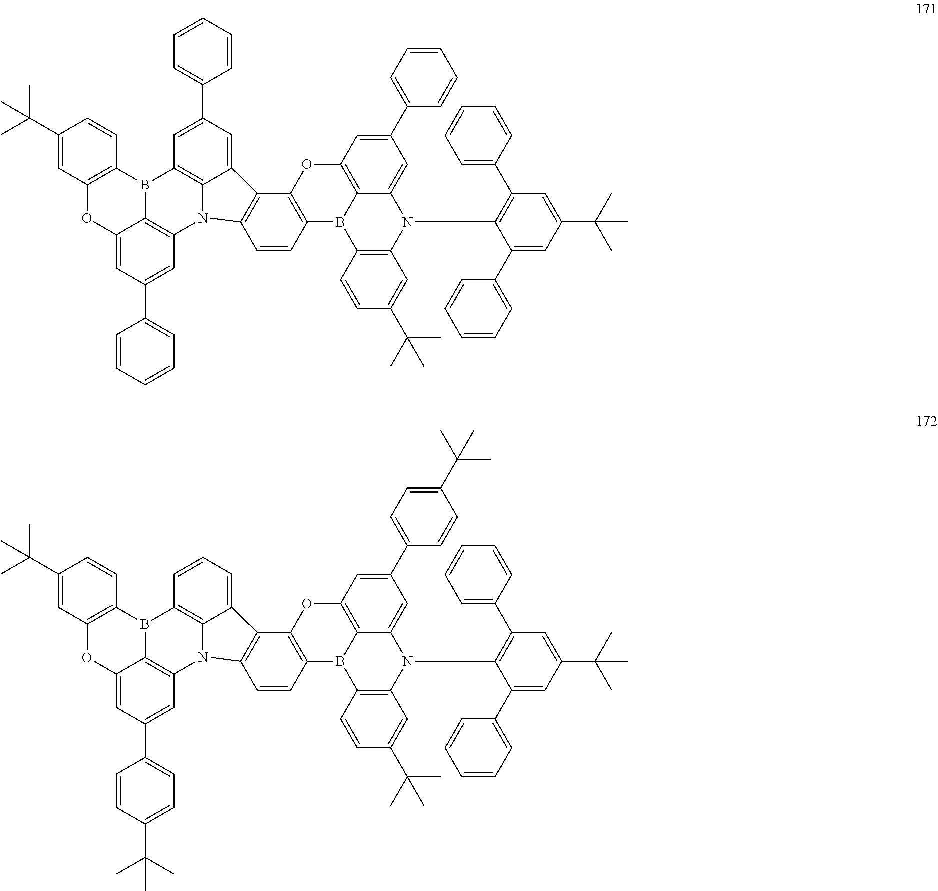

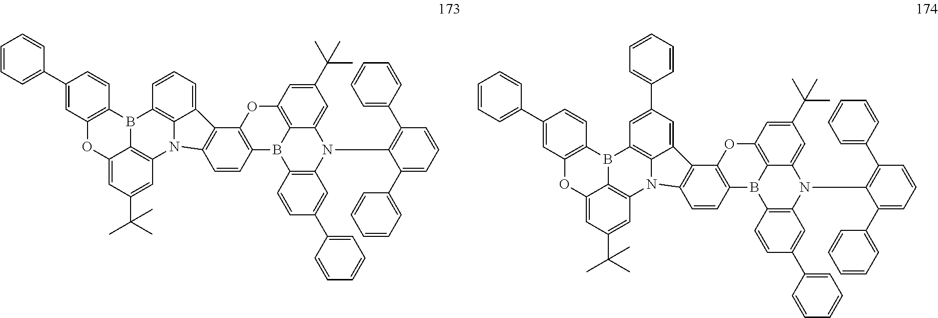 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1O3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1O3]

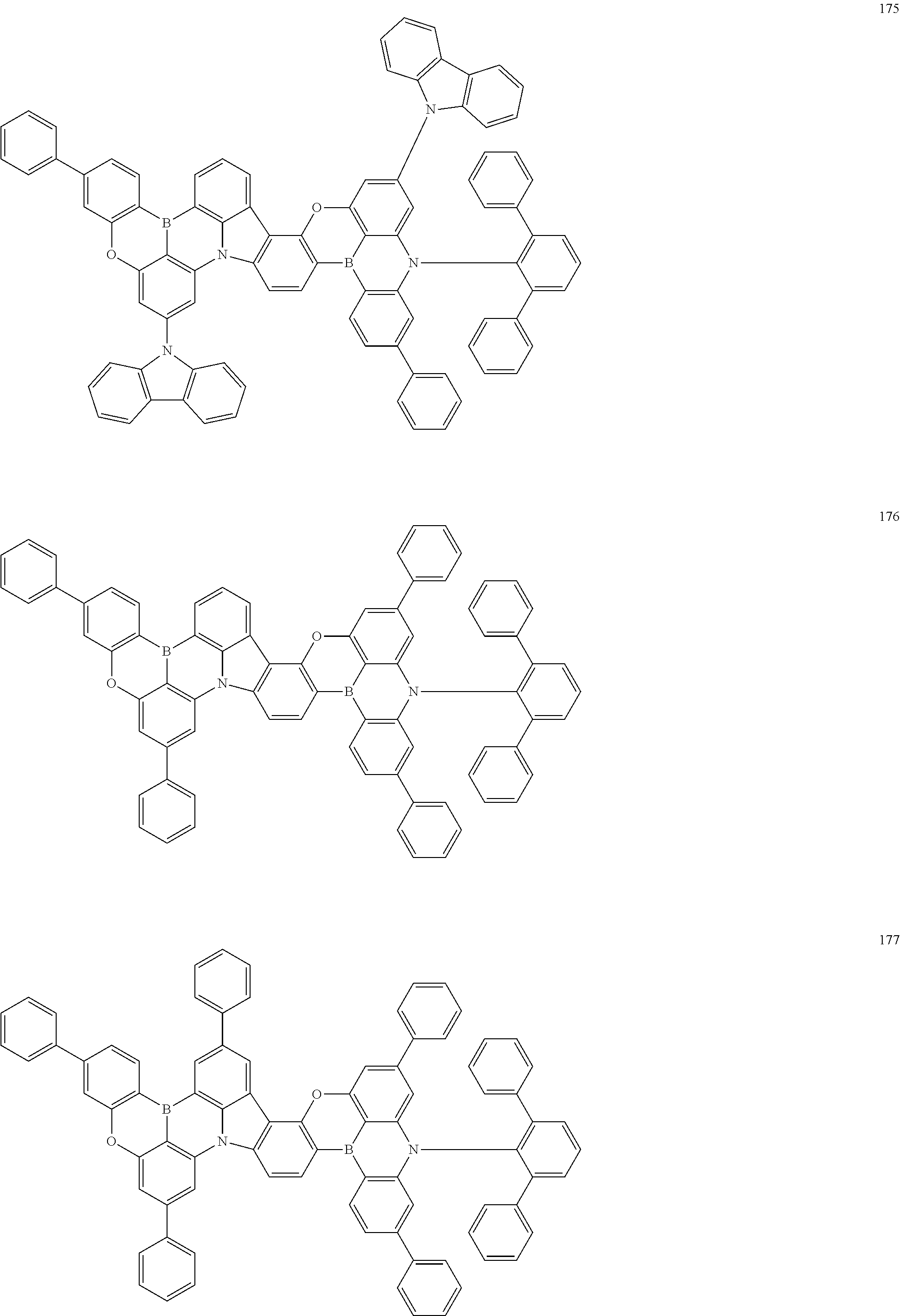 [SMILES: c1ccc(-c2ccc3c(c2)Oc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)O6)cc1 ; c1ccc(-c2ccc3c(c2)Oc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1 ; c1ccc(-c2ccc3c(c2)Oc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1]

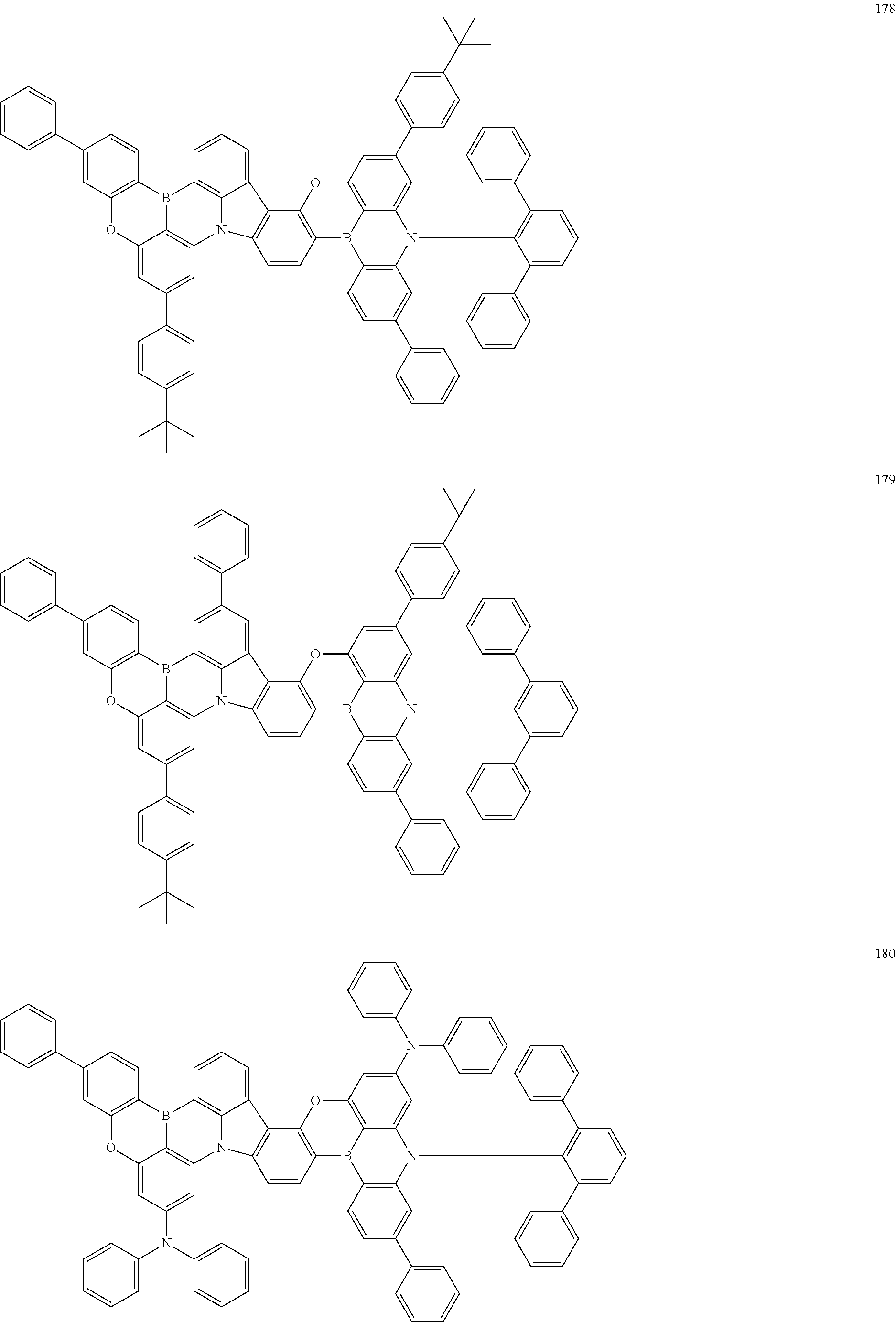

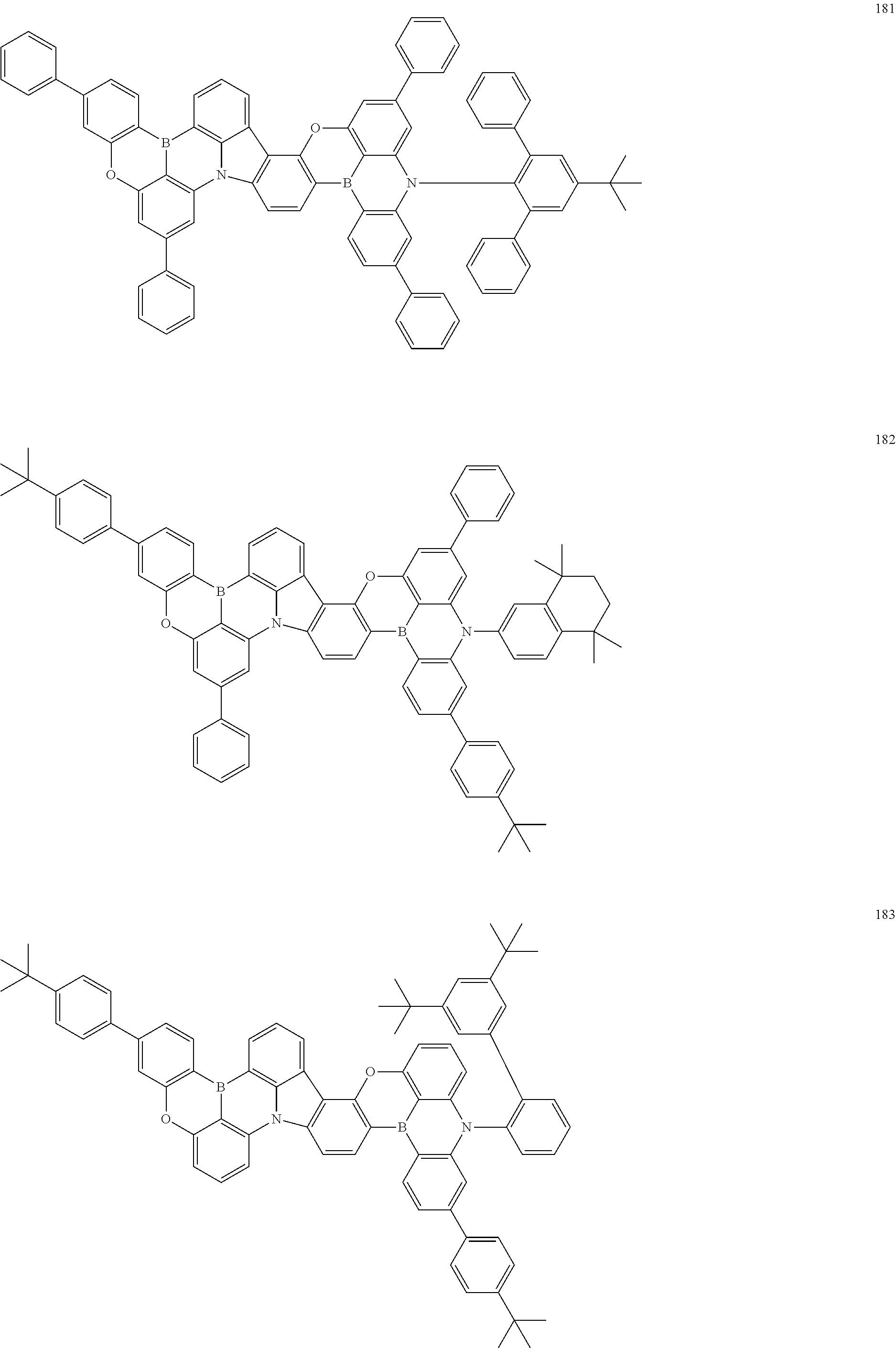

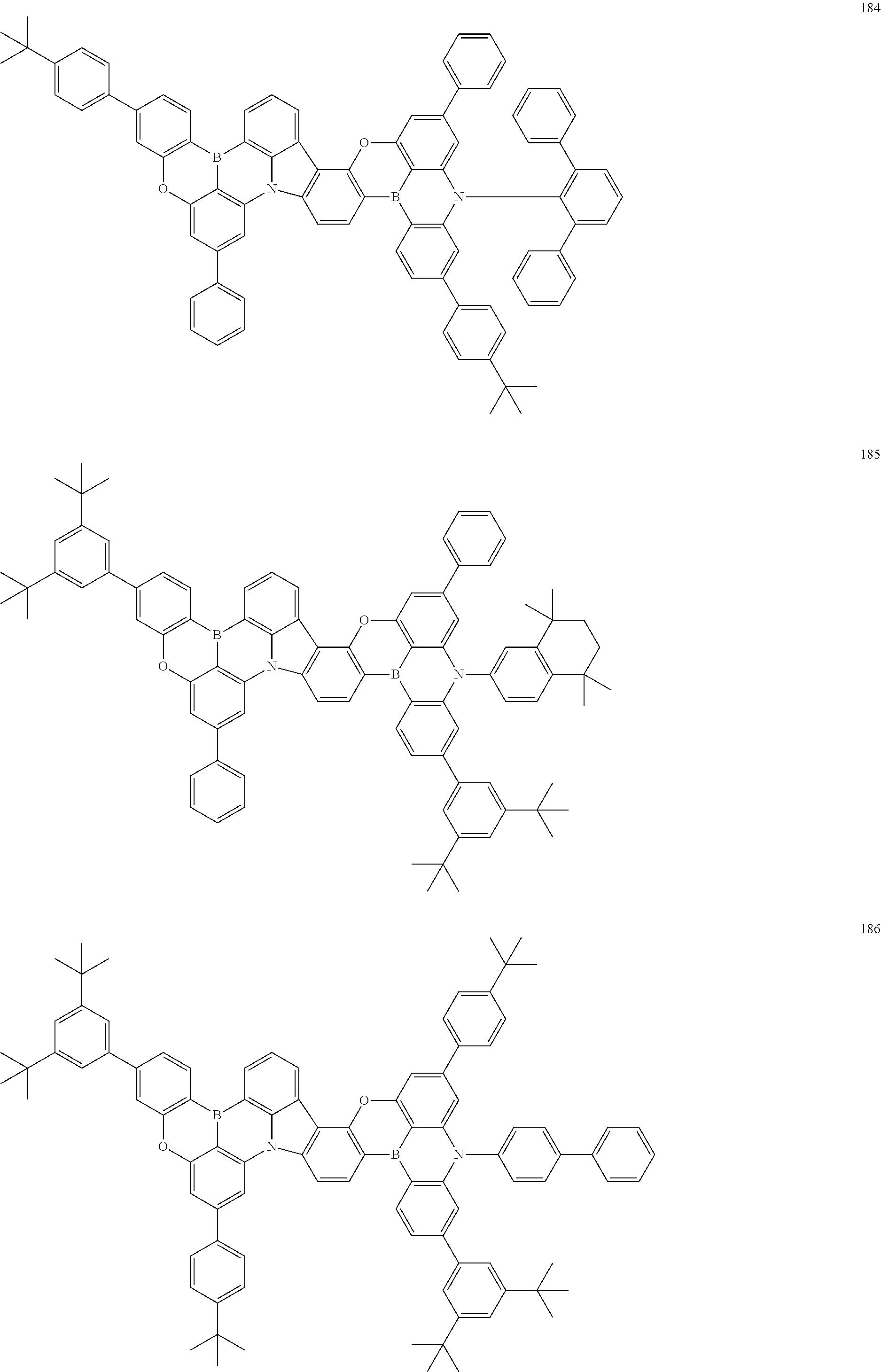

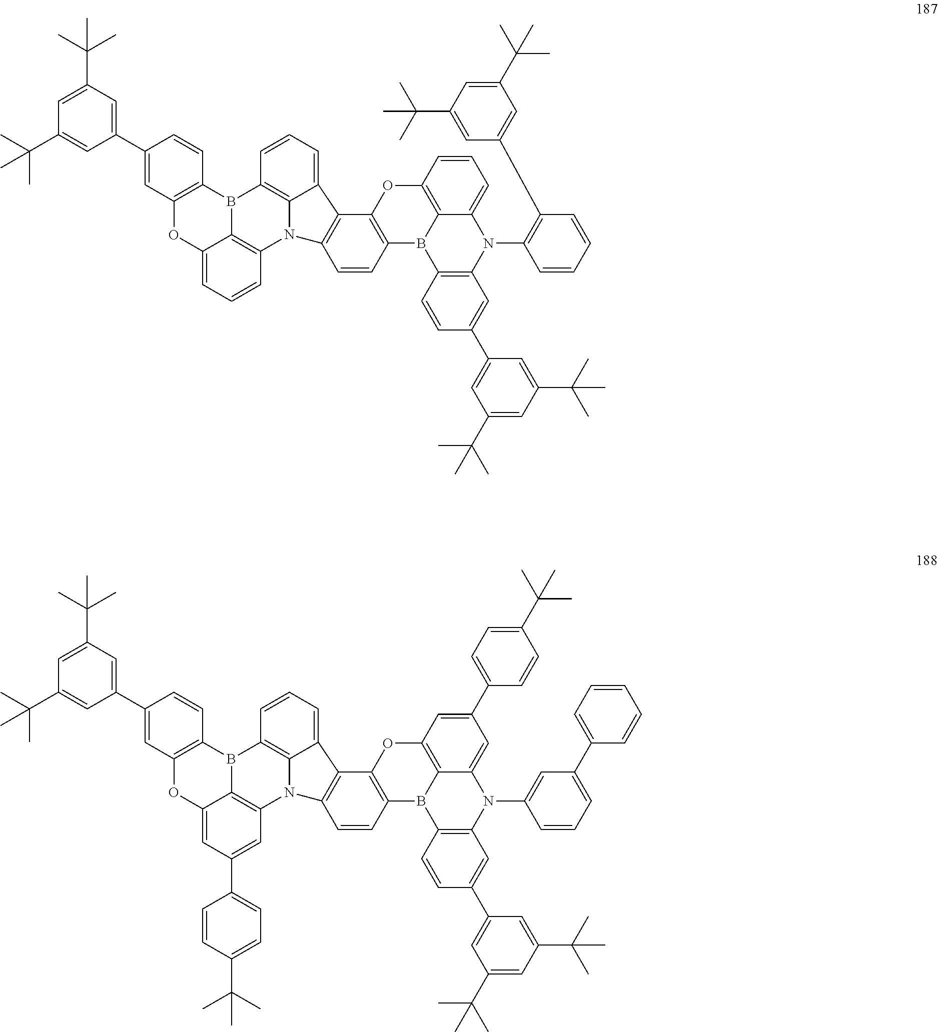

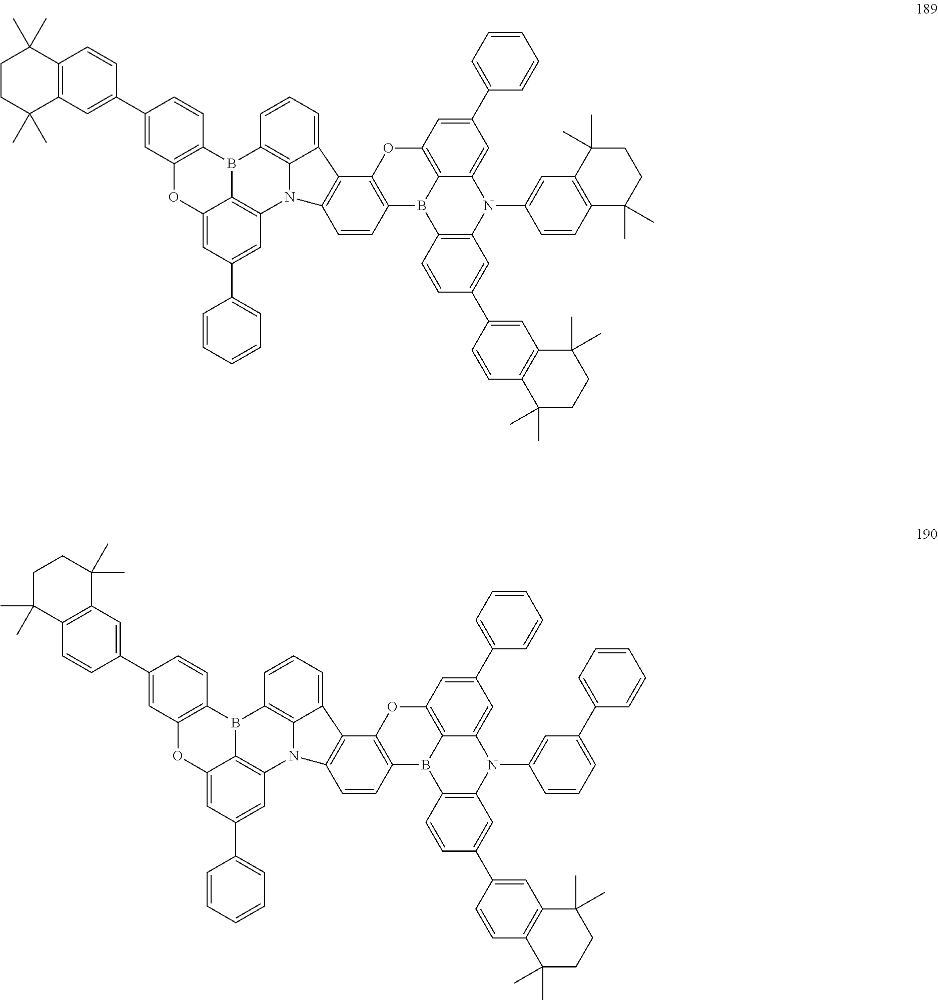

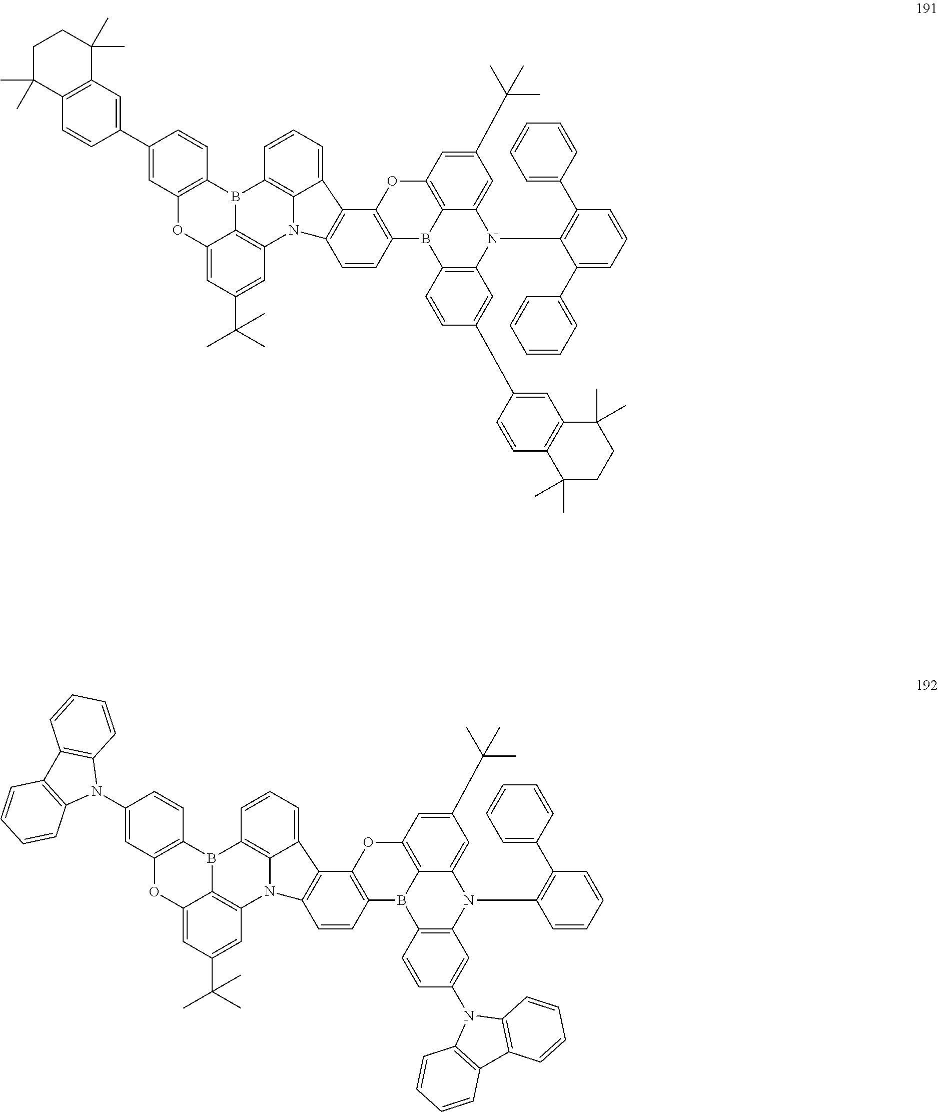 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1O3 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3]

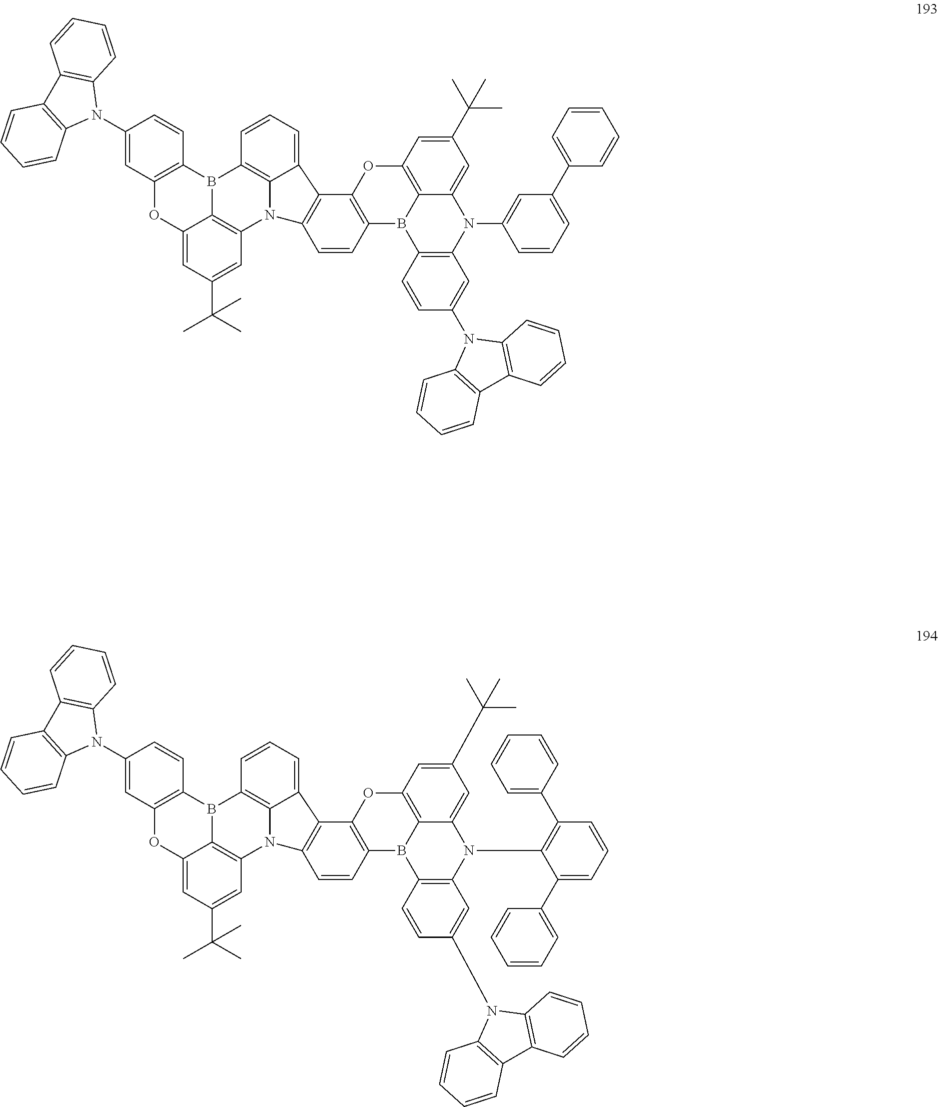 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3]

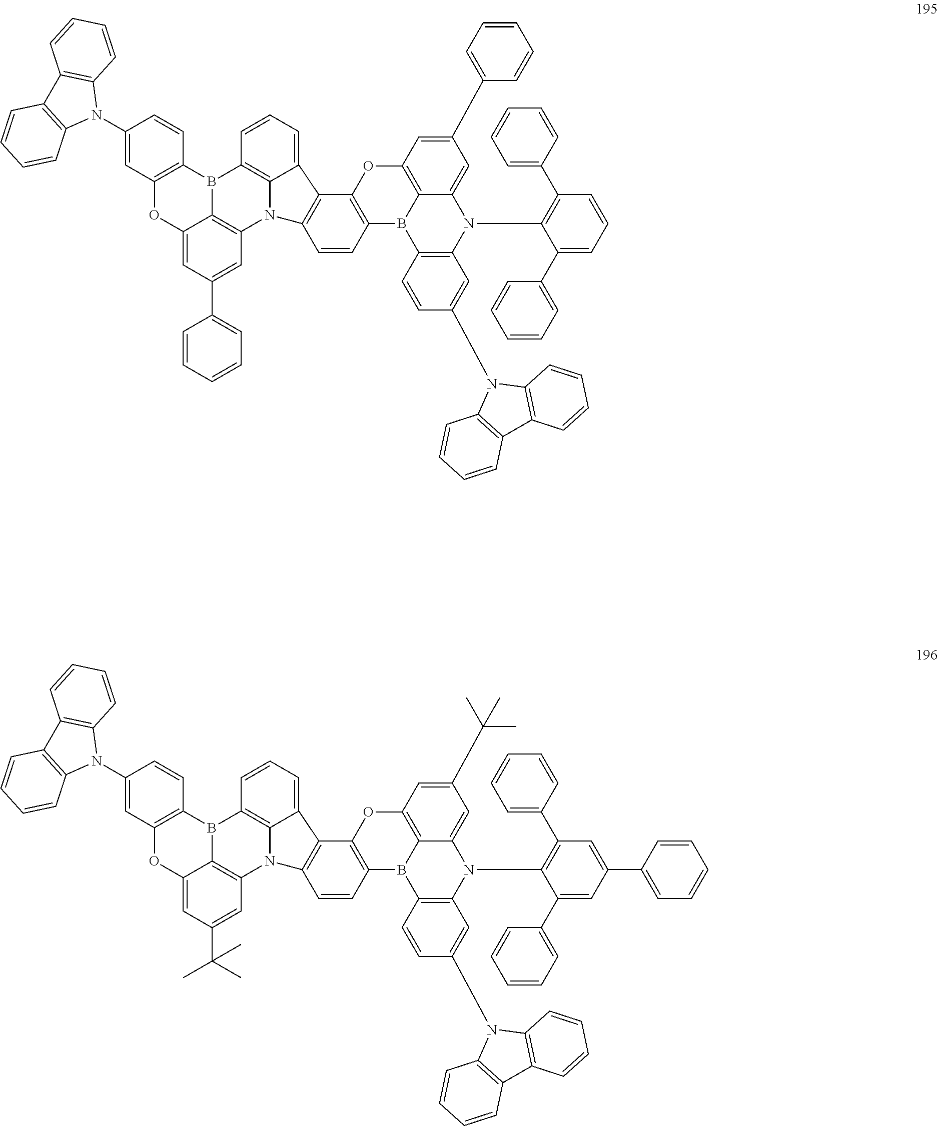 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2O4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3]

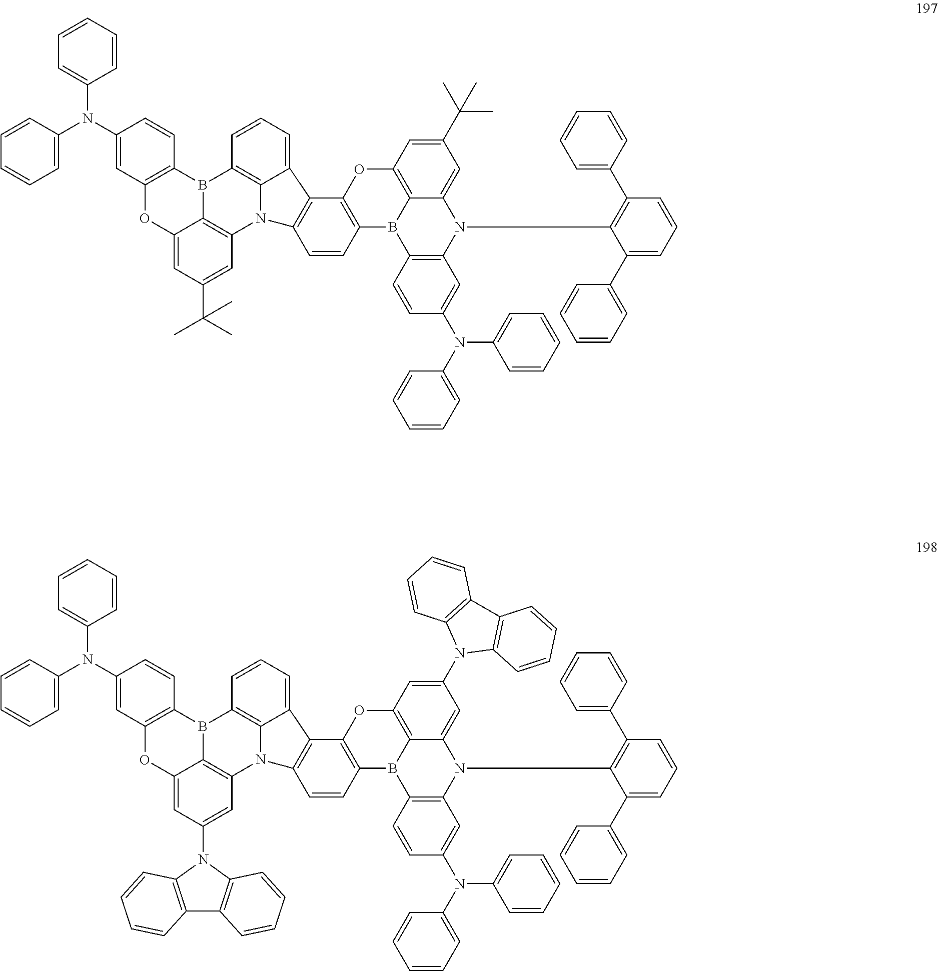 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1O3 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2O4)cc1]

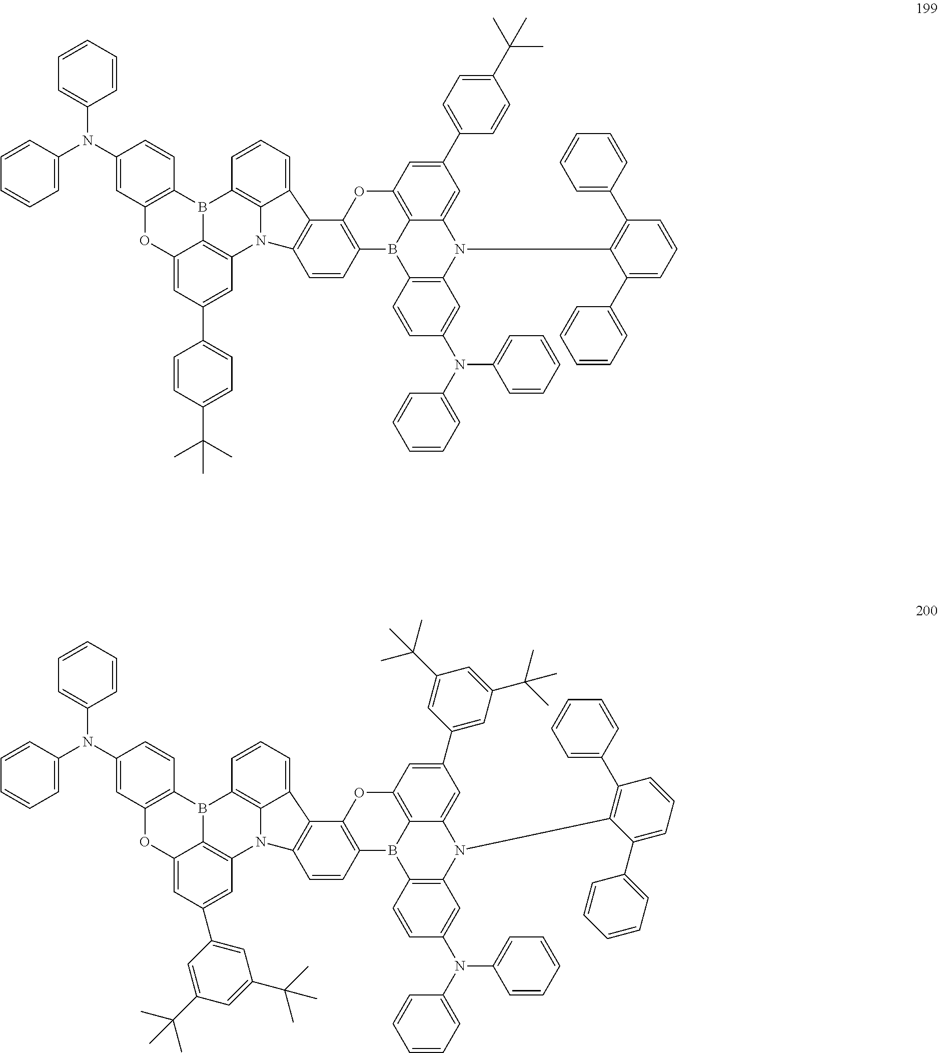 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2O4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2O4)cc(C(C)(C)C)c1]

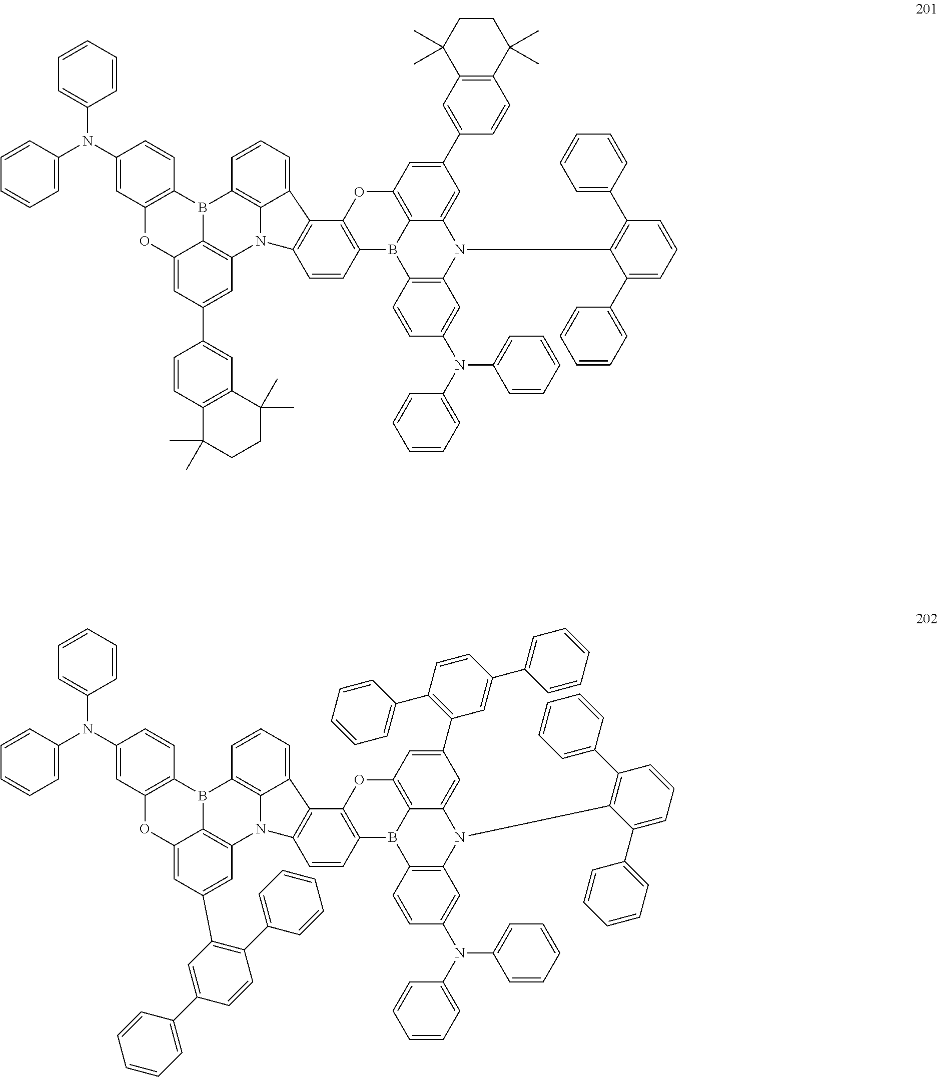 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3O5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3O5)c2)cc1]

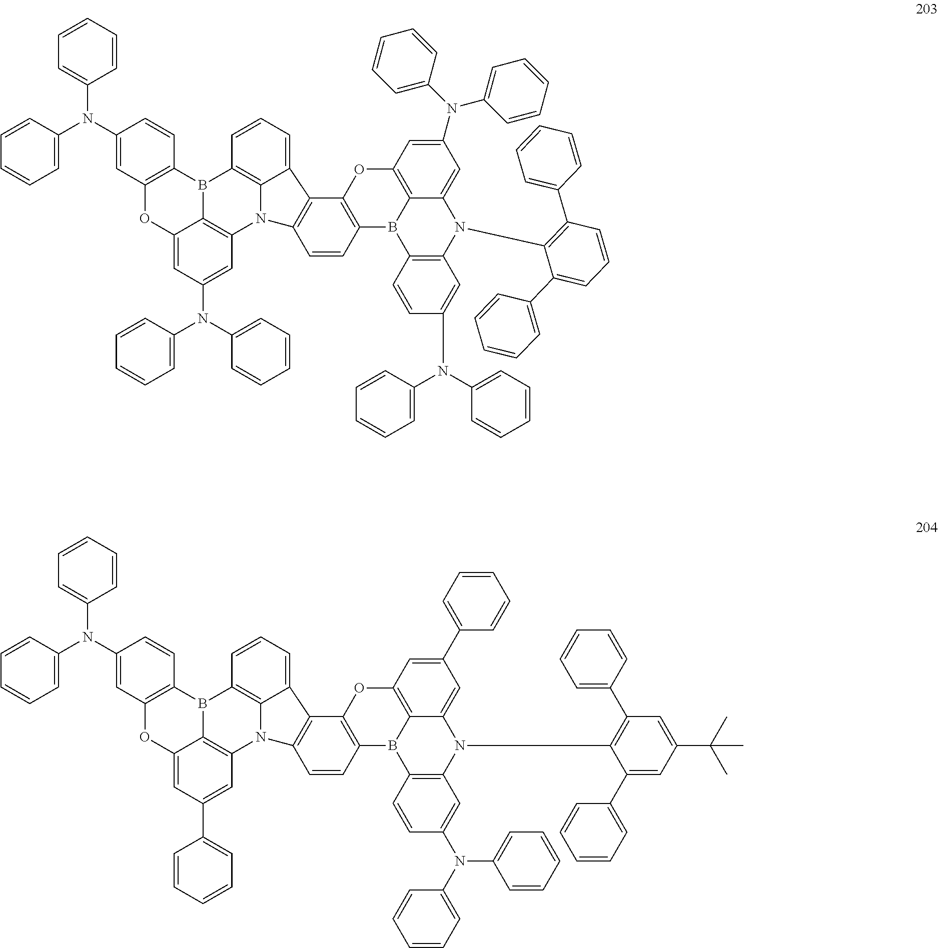 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2O4)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2O4)c(-c2ccccc2)c1]

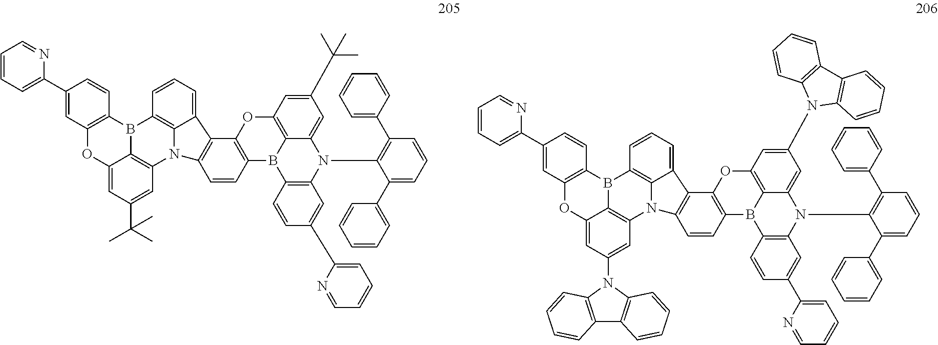 [SMILES: CC(C)(C)c1cc2c3c(c1)N(c1c(-c4ccccc4)cccc1-c1ccccc1)c1cc(-c4ccccn4)ccc1B3c1ccc3c(c1O2)c1cccc2c1n3-c1cc(C(C)(C)C)cc3c1B2c1ccc(-c2ccccn2)cc1O3 ; c1ccc(-c2cccc(-c3ccccc3)c2N2c3cc(-c4ccccn4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(-c3ccccn3)cc2O4)cc1]

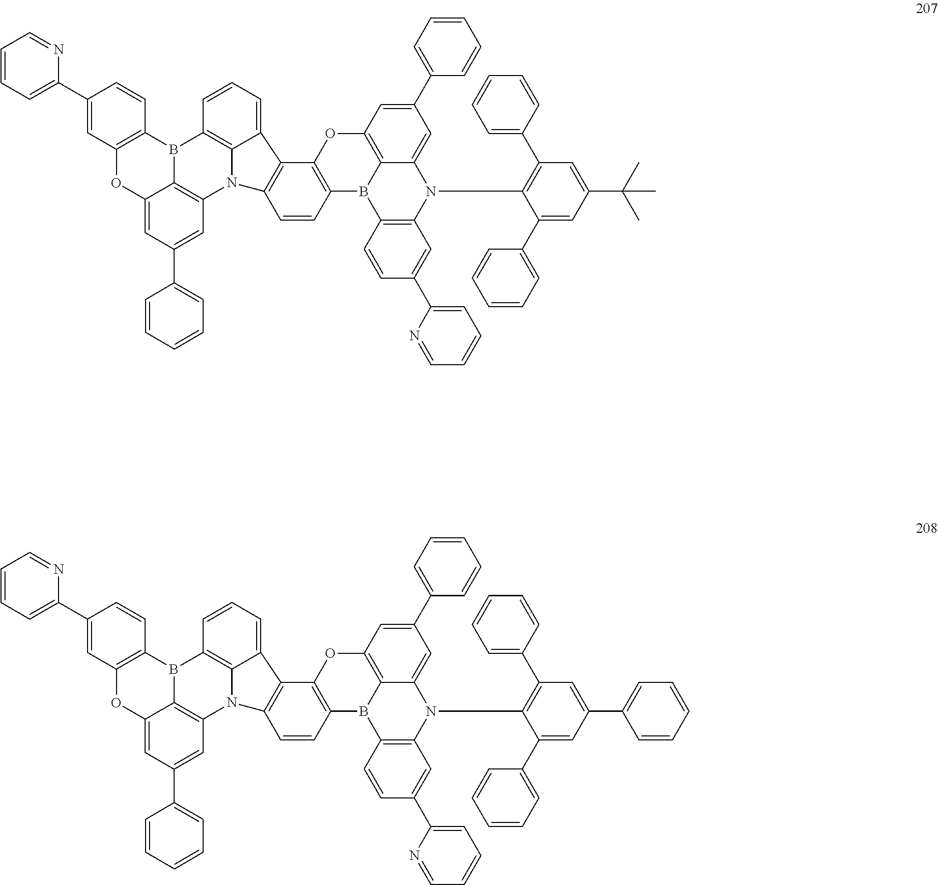 [SMILES: CC(C)(C)c1cc(-c2ccccc2)c(N2c3cc(-c4ccccn4)ccc3B3c4ccc5c(c4Oc4cc(-c6ccccc6)cc2c43)c2cccc3c2n5-c2cc(-c4ccccc4)cc4c2B3c2ccc(-c3ccccn3)cc2O4)c(-c2ccccc2)c1 ; c1ccc(-c2cc(-c3ccccc3)c(N3c4cc(-c5ccccn5)ccc4B4c5ccc6c(c5Oc5cc(-c7ccccc7)cc3c54)c3cccc4c3n6-c3cc(-c5ccccc5)cc5c3B4c3ccc(-c4ccccn4)cc3O5)c(-c3ccccc3)c2)cc1]

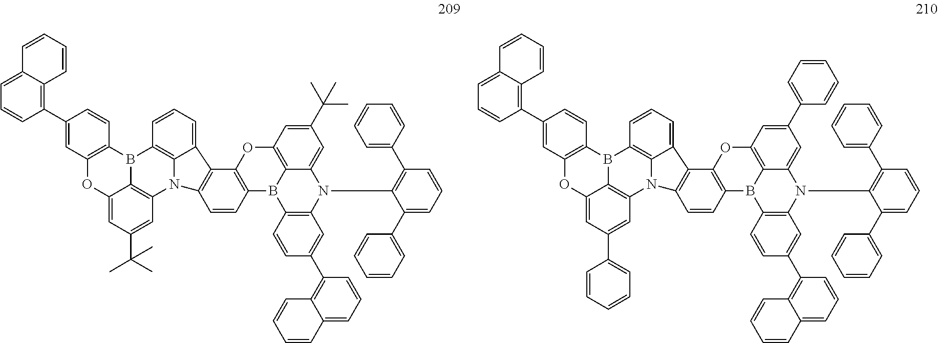 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1O3 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2O4)cc1]

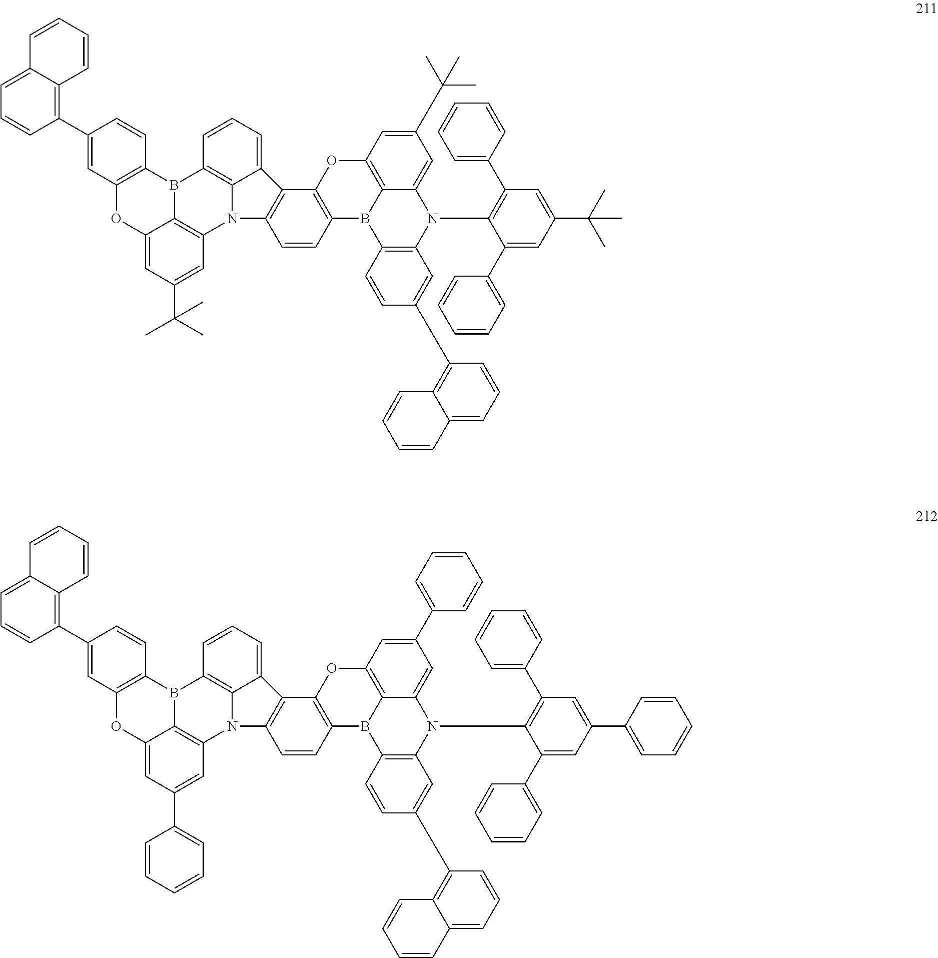 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2O4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3O5)c(-c3ccccc3)c2)cc1]

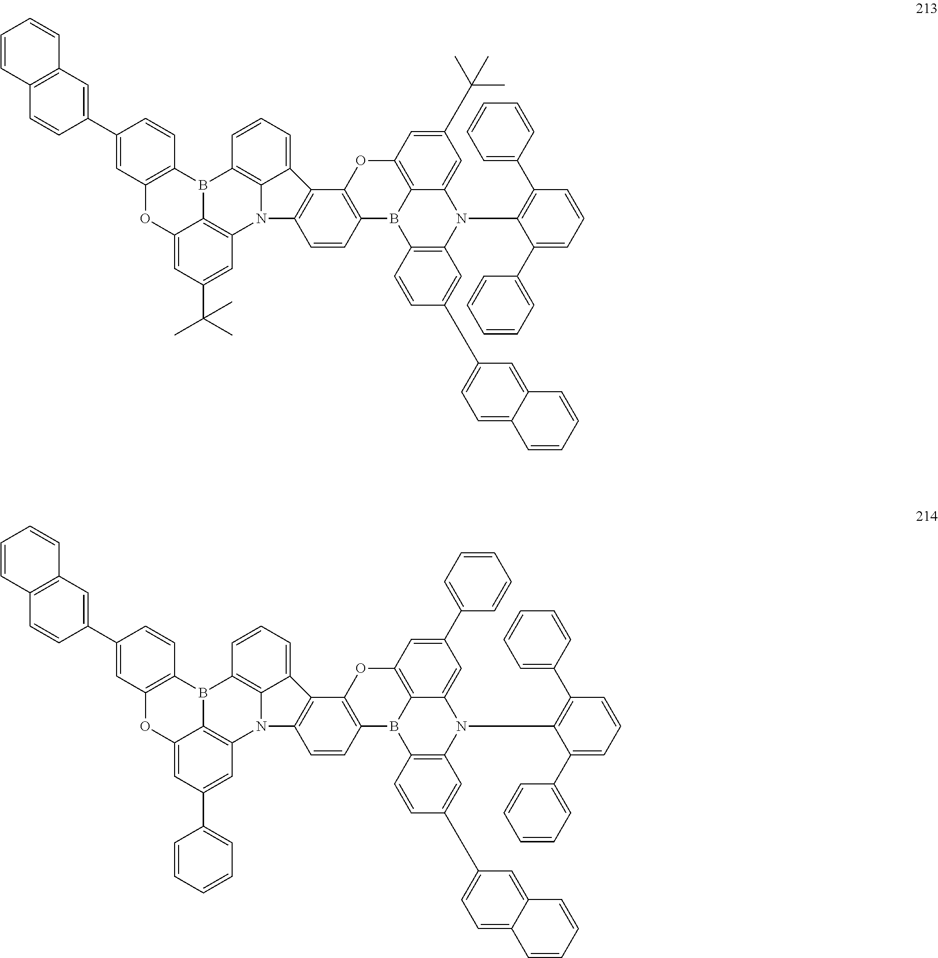 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1O3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2O4)cc1]

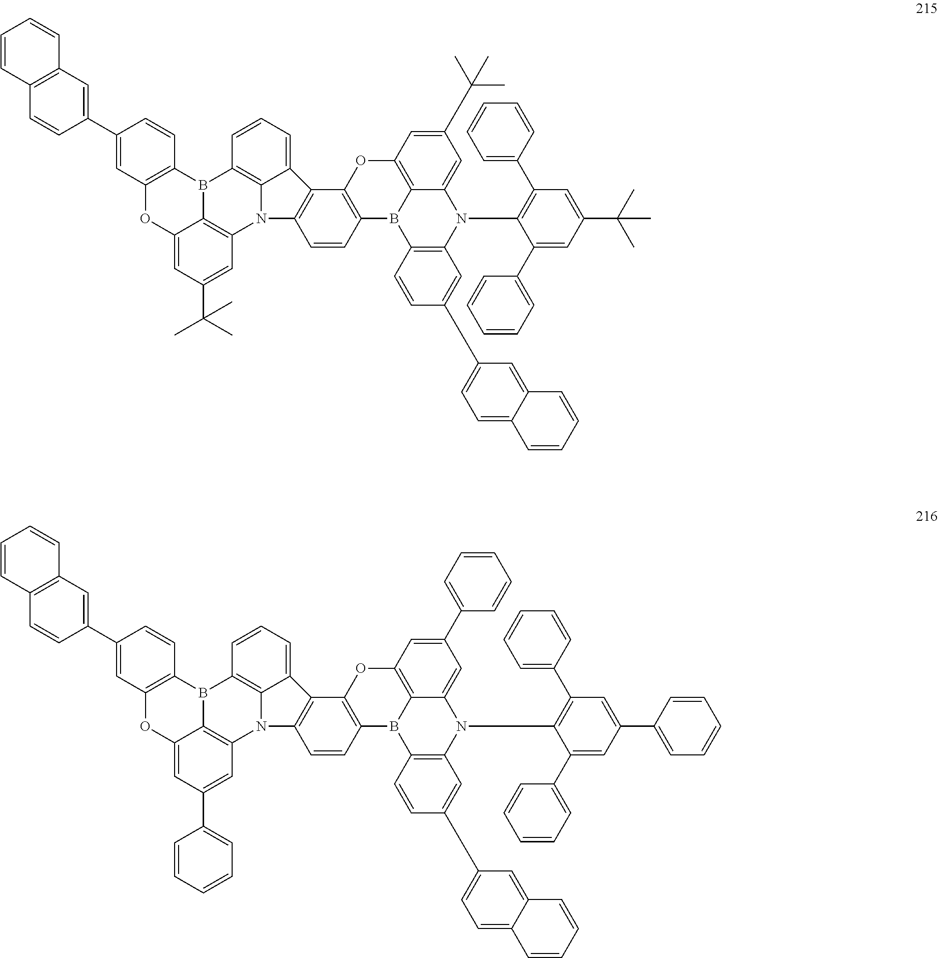 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2O4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3O5)c(-c3ccccc3)c2)cc1]

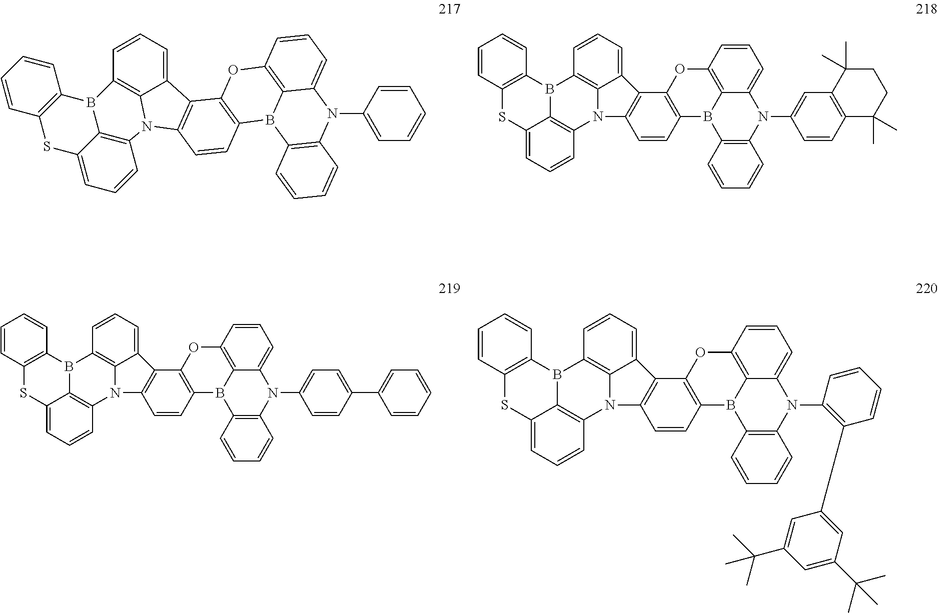 [SMILES: c1ccc(N2c3ccccc3B3c4ccc5c(c4Oc4cccc2c43)c2cccc3c2n5-c2cccc4c2B3c2ccccc2S4)cc1 ; CC1(C)CCC(C)(C)c2cc(N3c4ccccc4B4c5ccc6c(c5Oc5cccc3c54)c3cccc4c3n6-c3cccc5c3B4c3ccccc3S5)ccc21 ; c1ccc(-c2ccc(N3c4ccccc4B4c5ccc6c(c5Oc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Oc4cccc2c43)c2cccc3c2n5-c2cccc4c2B3c2ccccc2S4)cc(C(C)(C)C)c1]

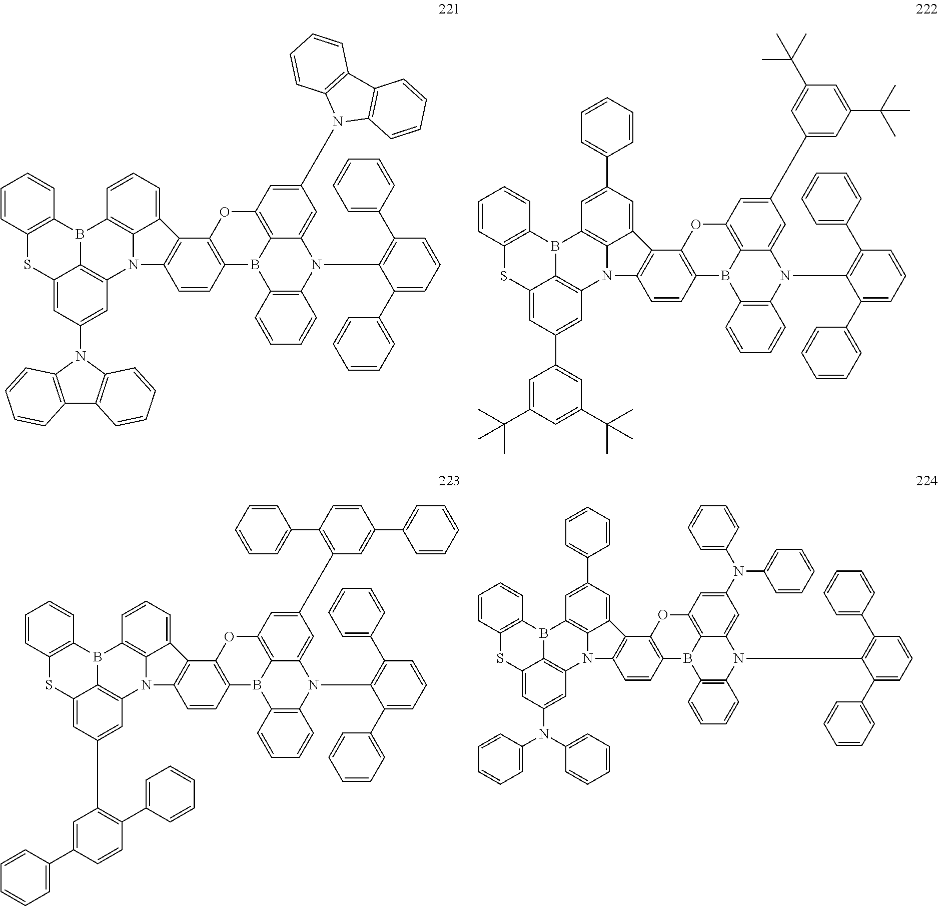

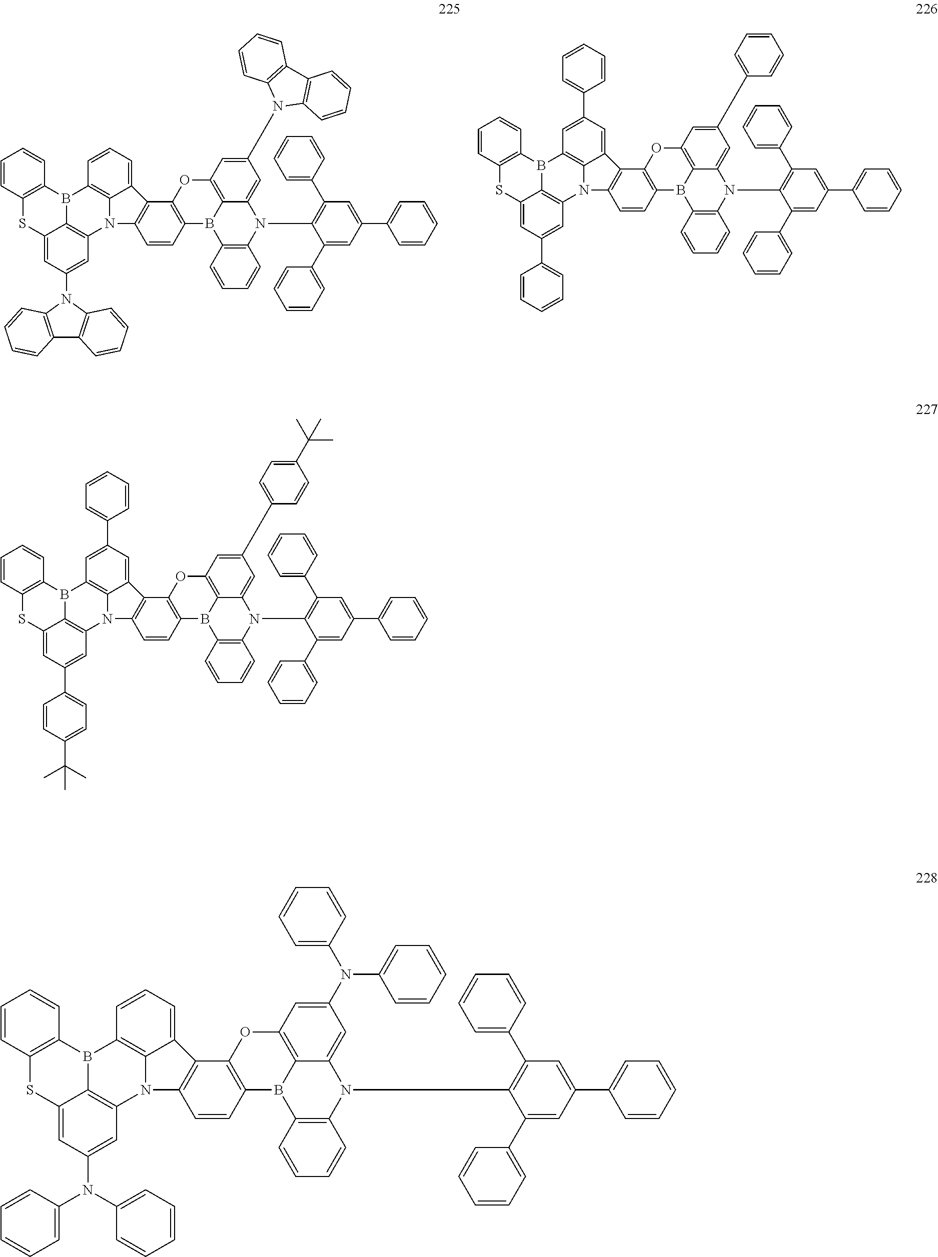

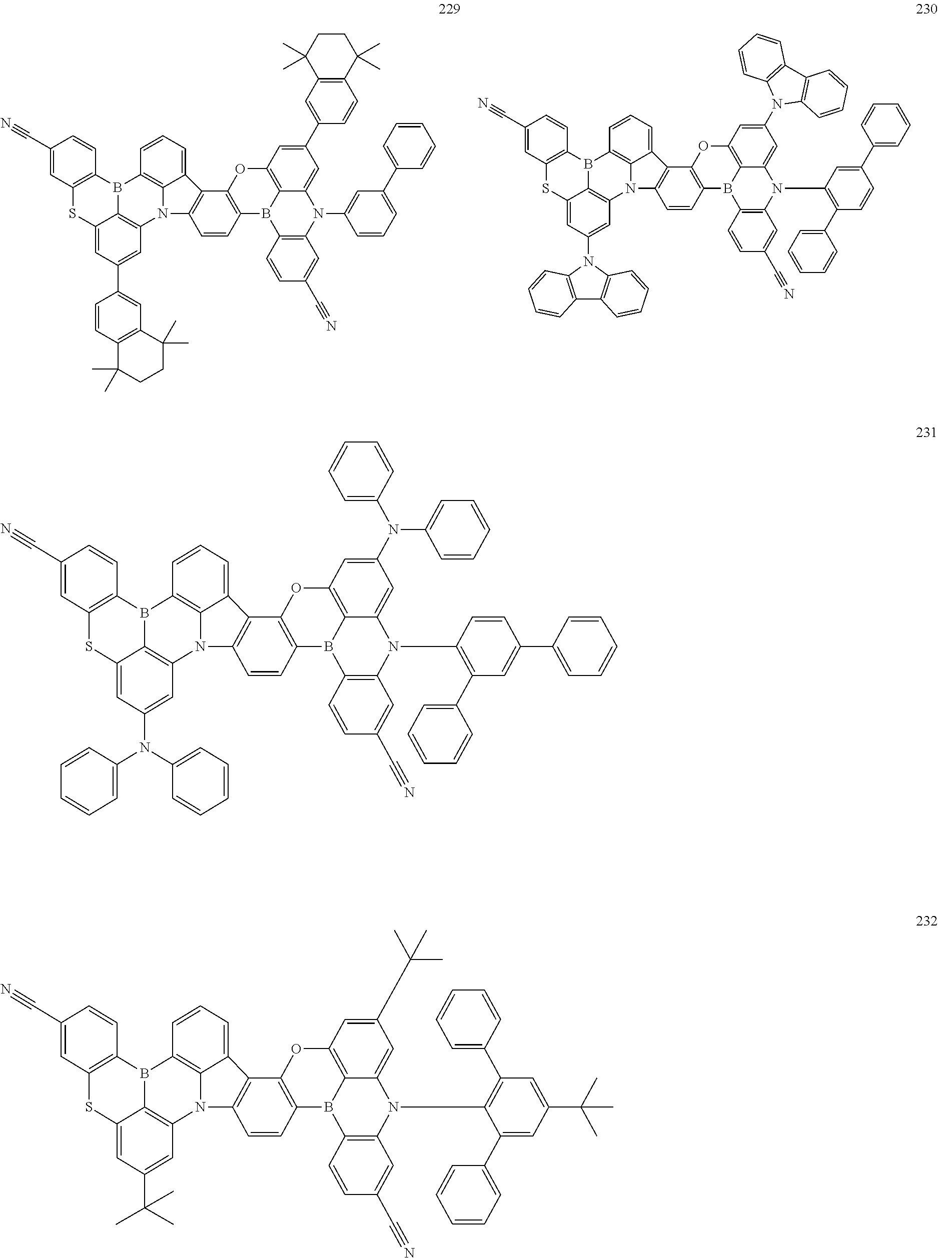

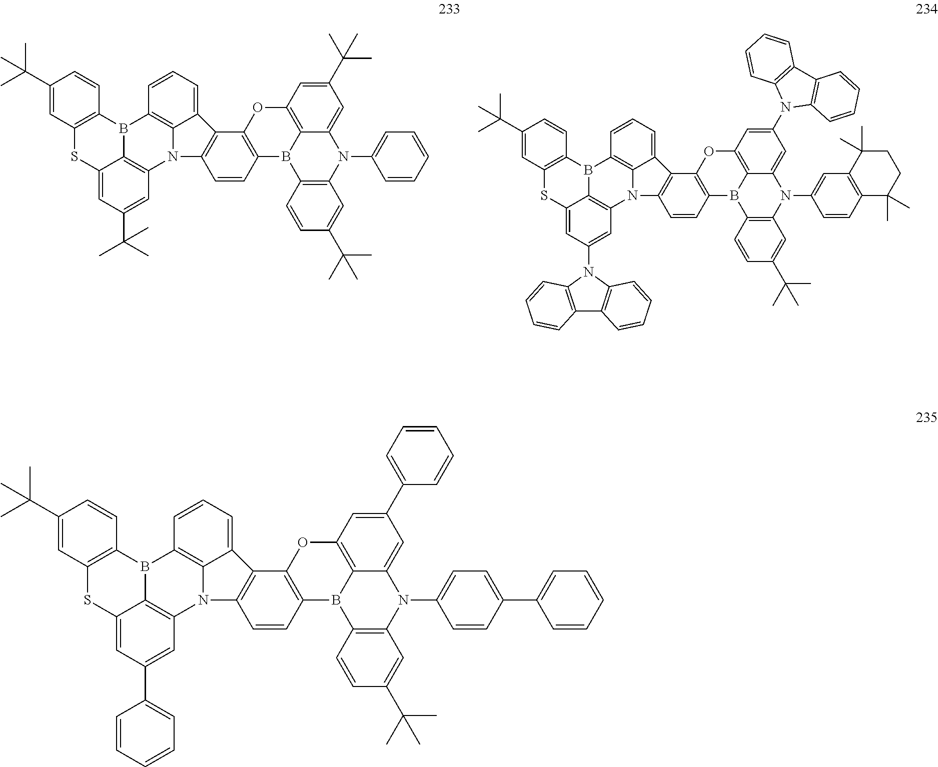 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)O5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)O5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)O5]

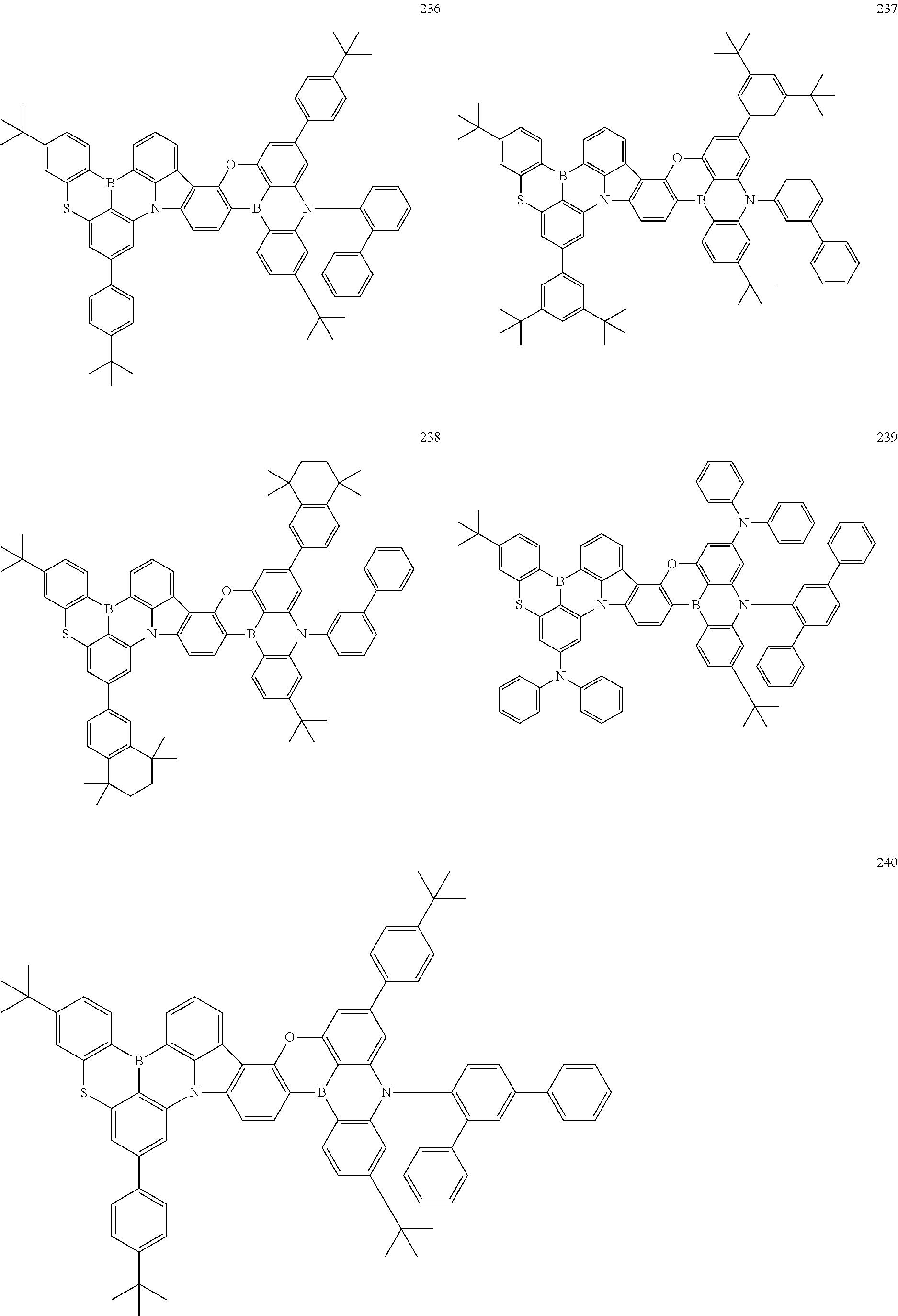

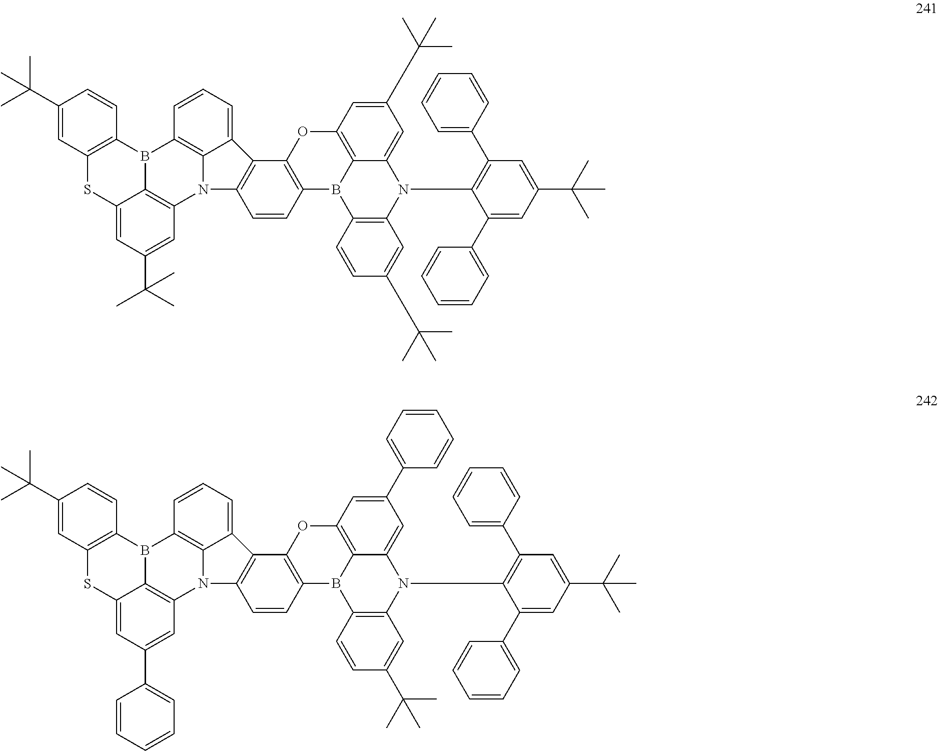

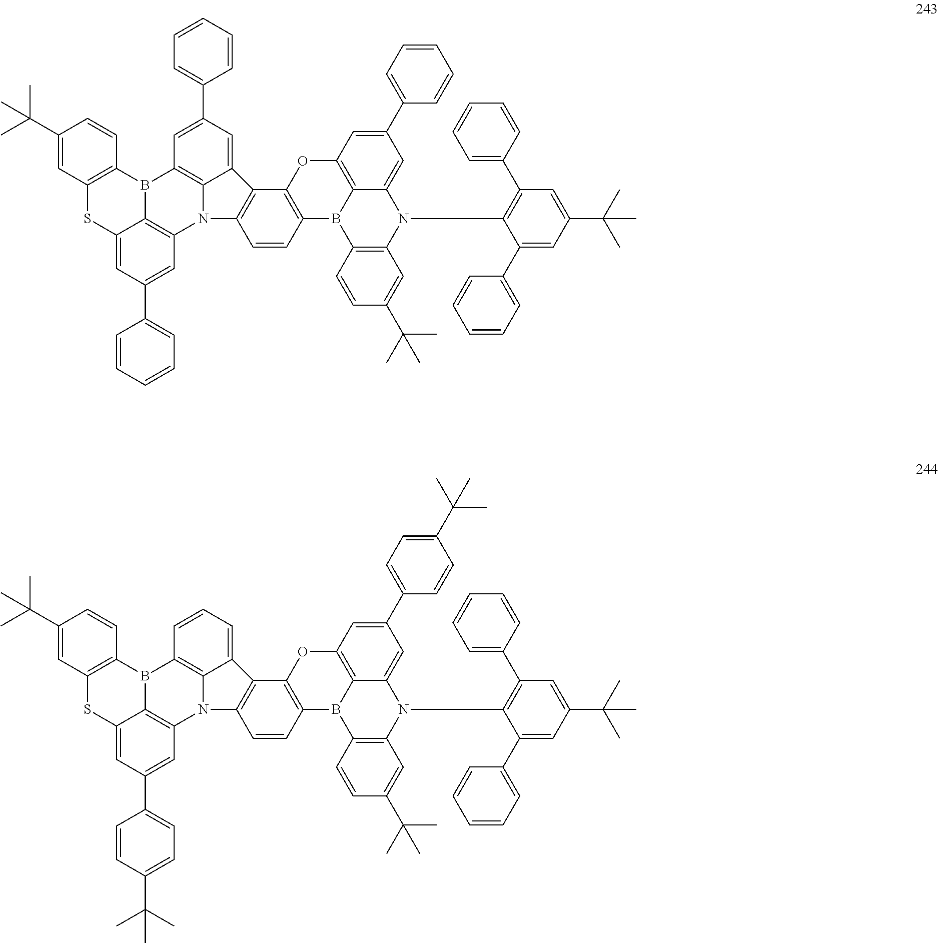

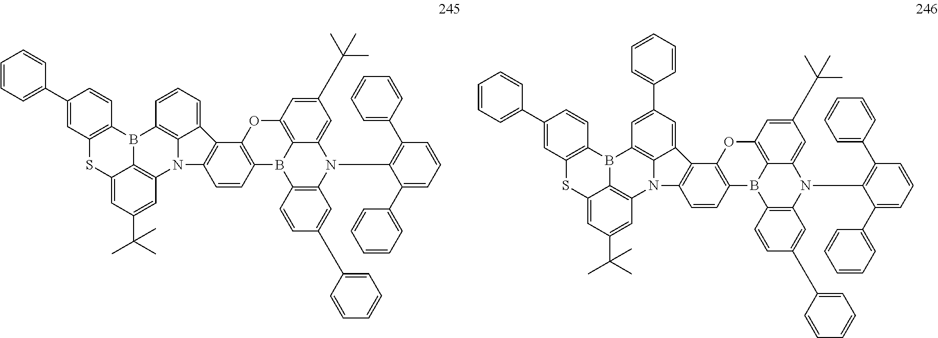 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1S3]

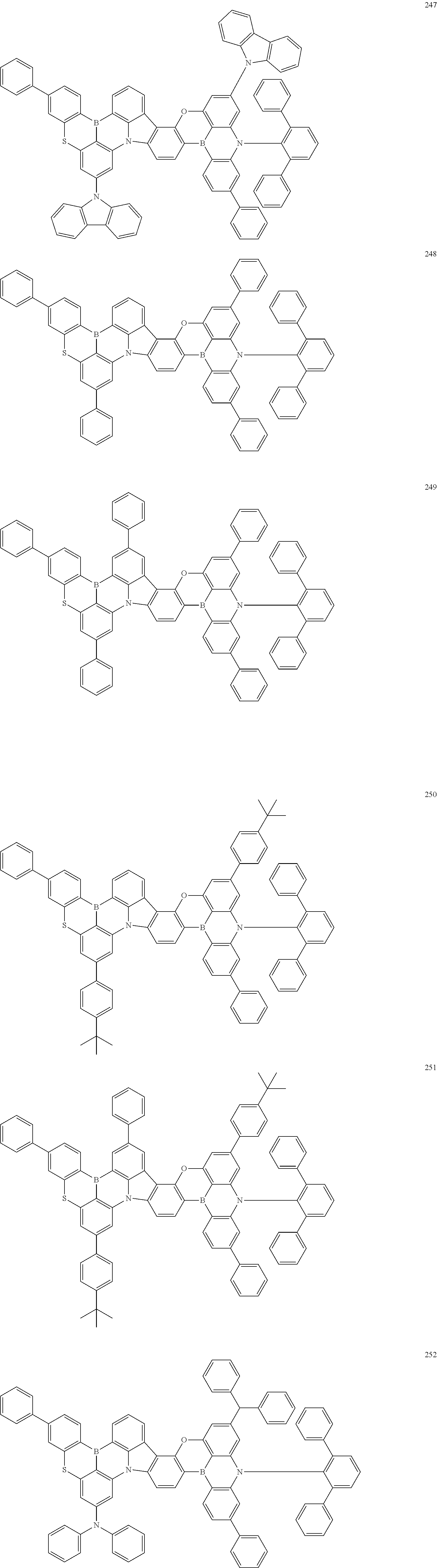

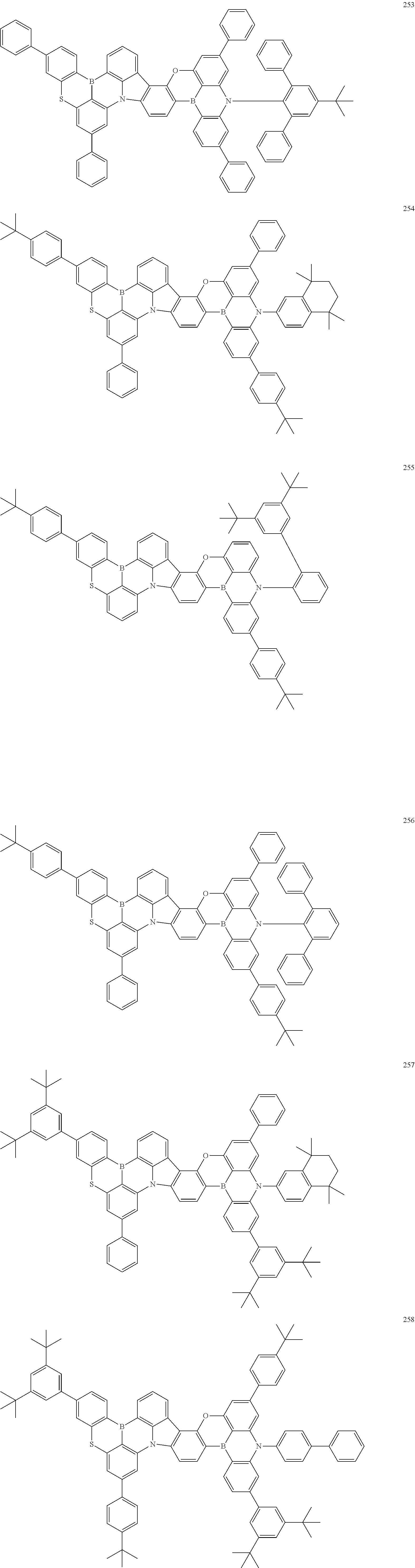

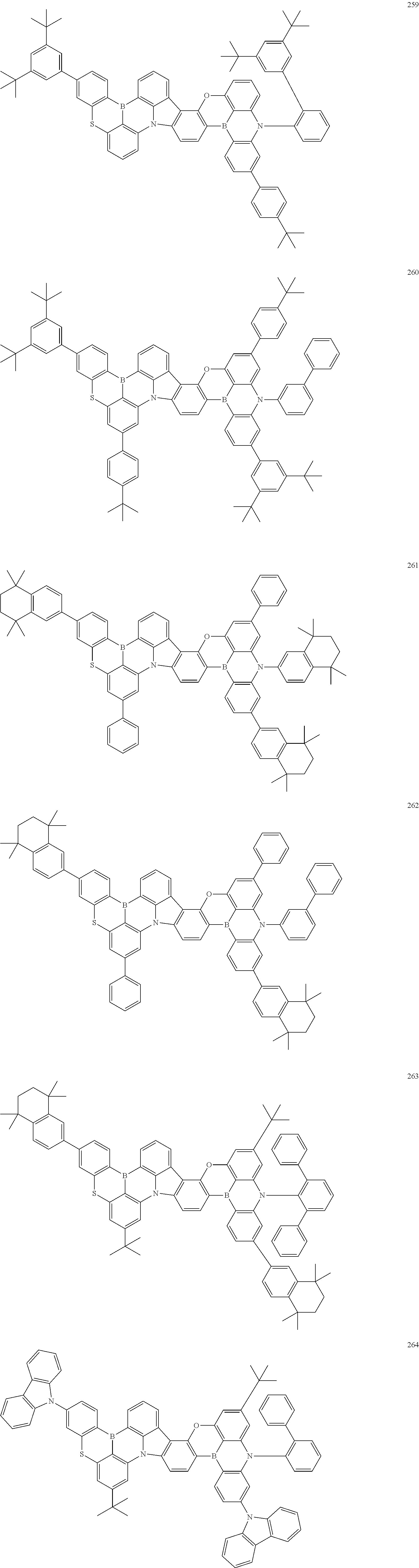

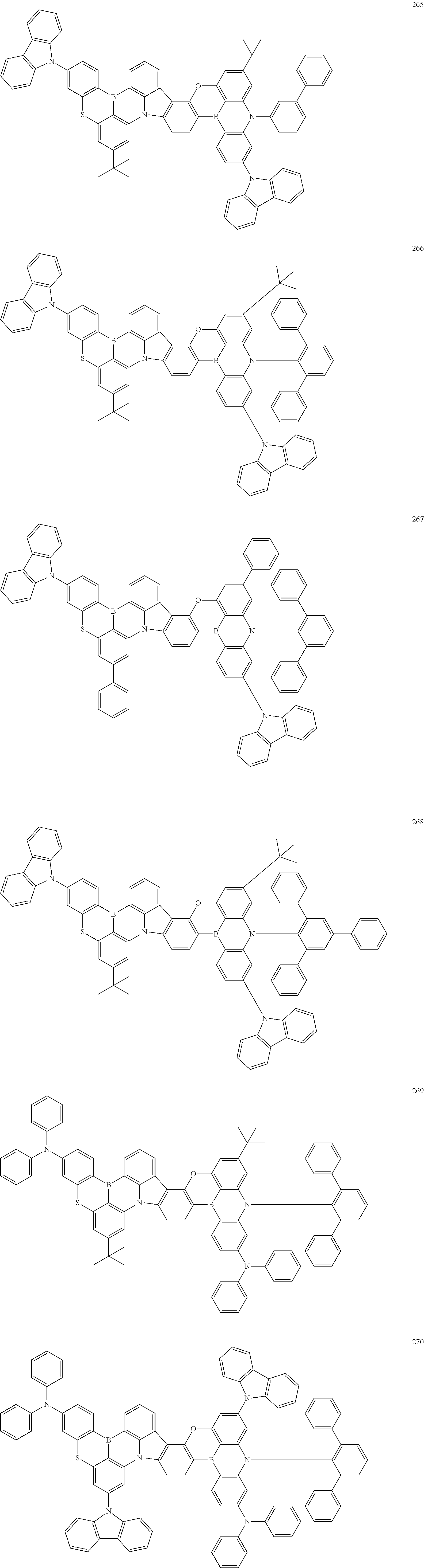

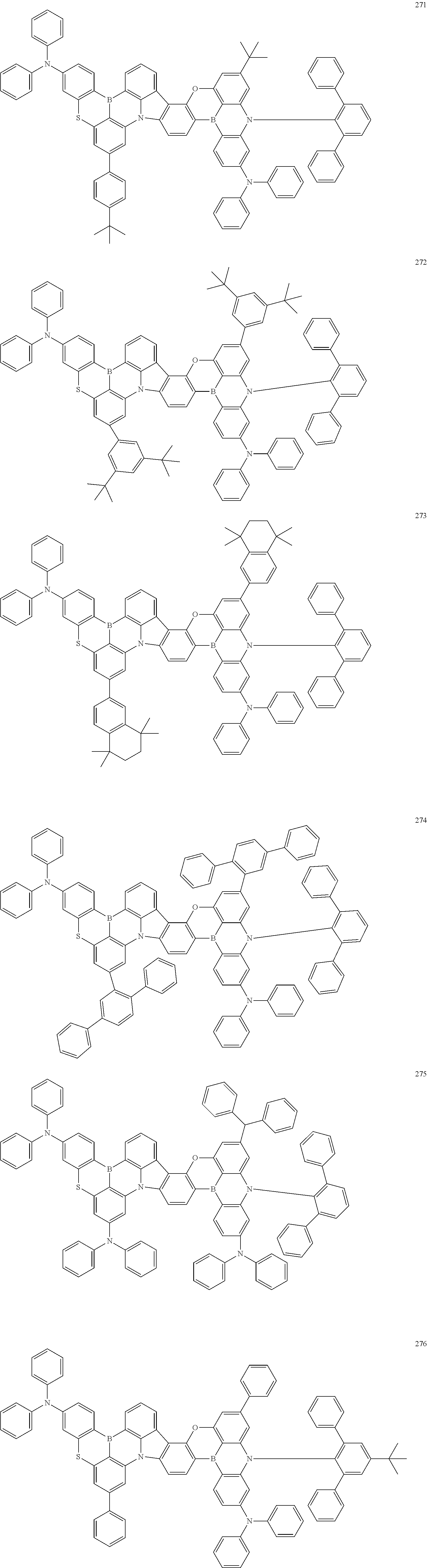

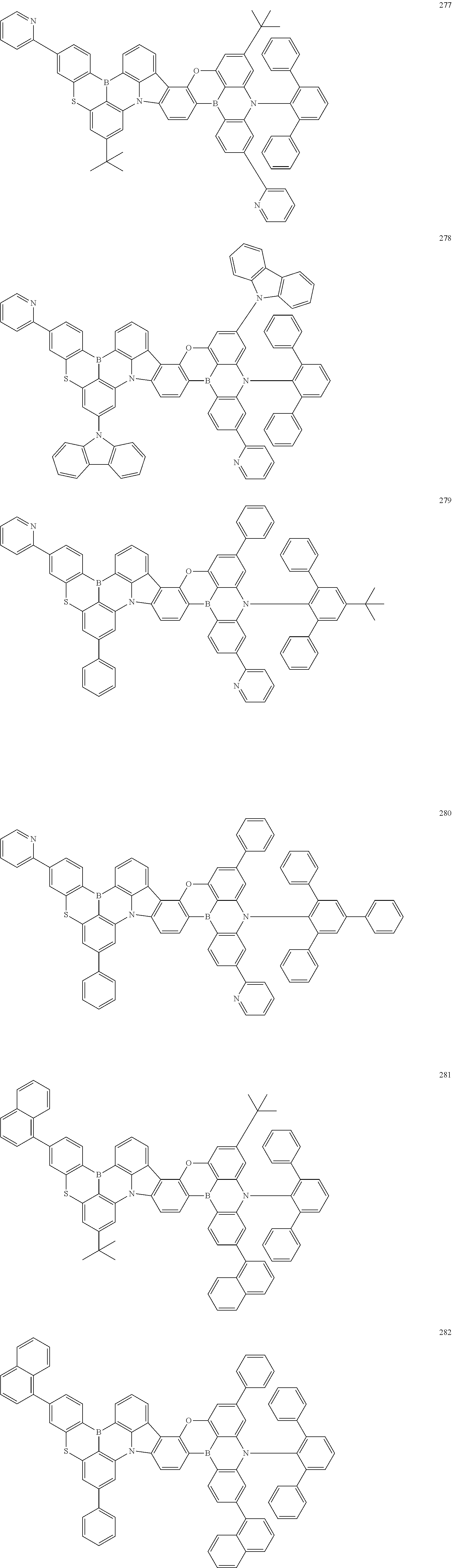

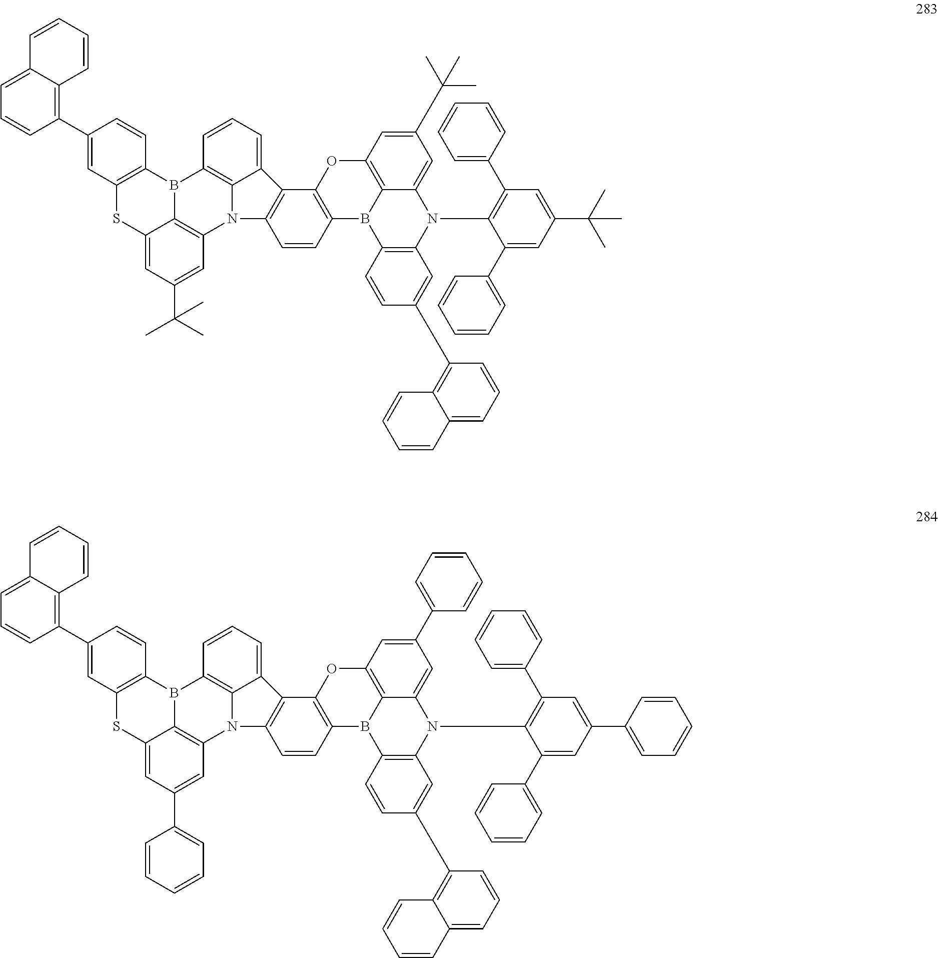 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1]

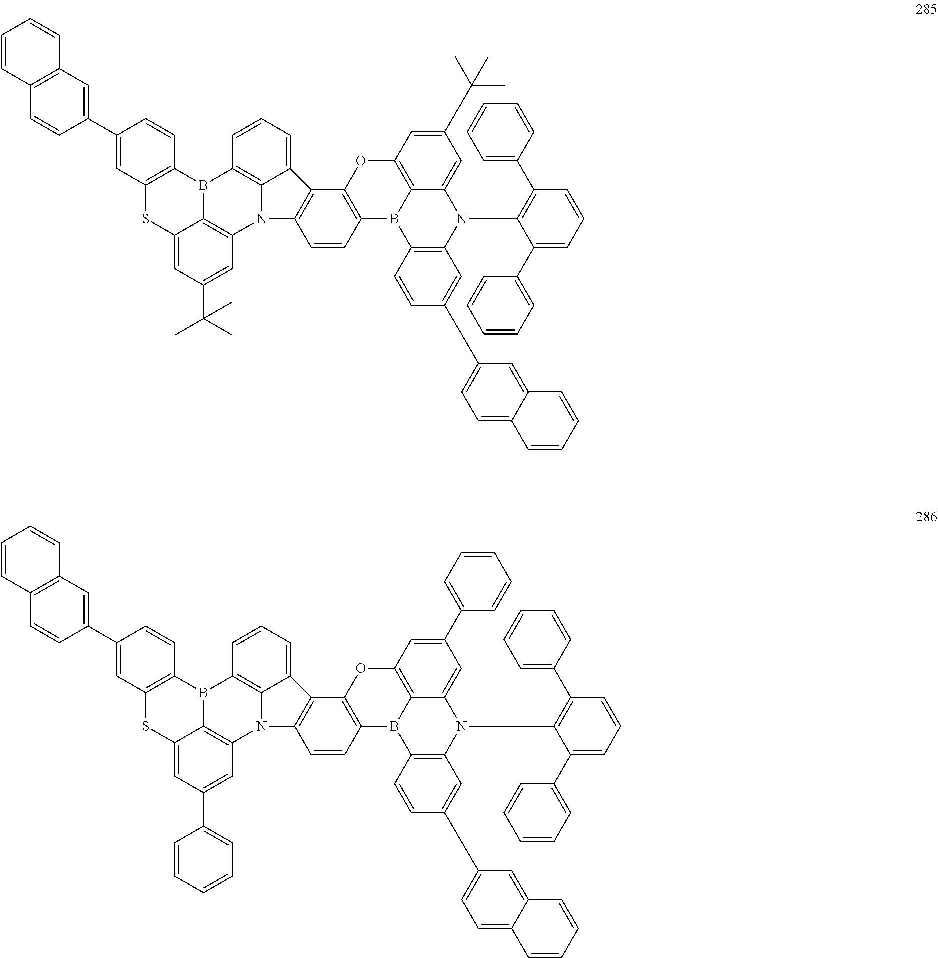 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2S4)cc1]

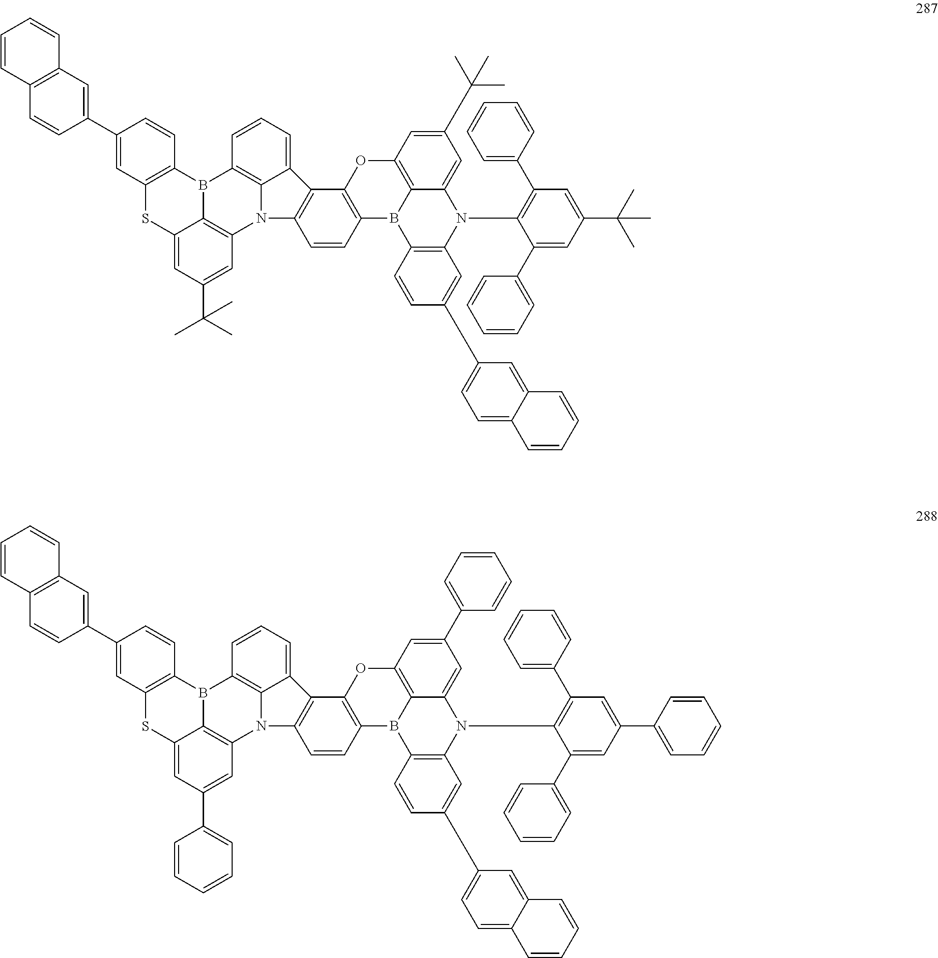 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1]

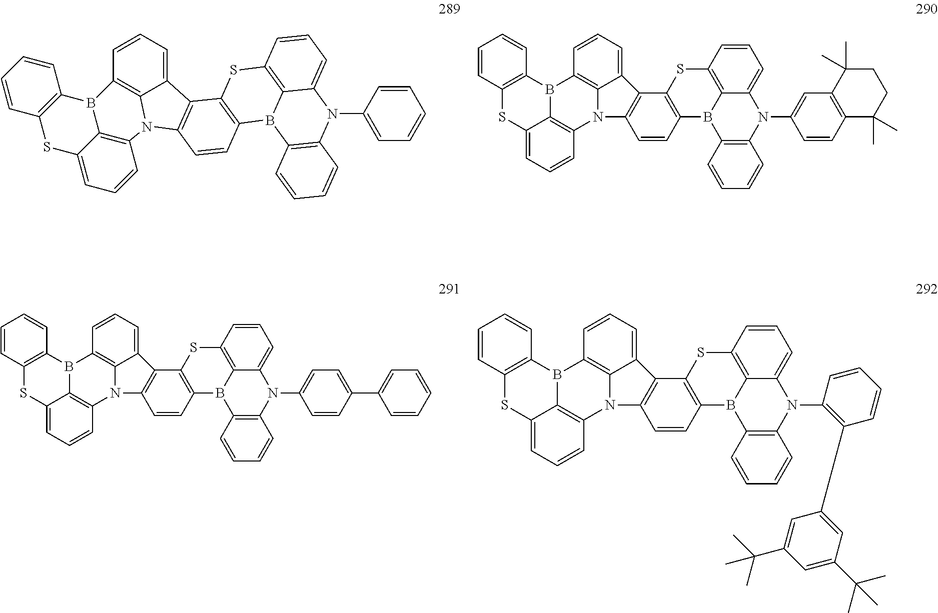 [SMILES: c1ccc(N2c3ccccc3B3c4ccc5c(c4Sc4cccc2c43)c2cccc3c2n5-c2cccc4c2B3c2ccccc2S4)cc1 ; CC1(C)CCC(C)(C)c2cc(N3c4ccccc4B4c5ccc6c(c5Sc5cccc3c54)c3cccc4c3n6-c3cccc5c3B4c3ccccc3S5)ccc21 ; c1ccc(-c2ccc(N3c4ccccc4B4c5ccc6c(c5Sc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Sc4cccc2c43)c2cccc3c2n5-c2cccc4c2B3c2ccccc2S4)cc(C(C)(C)C)c1]

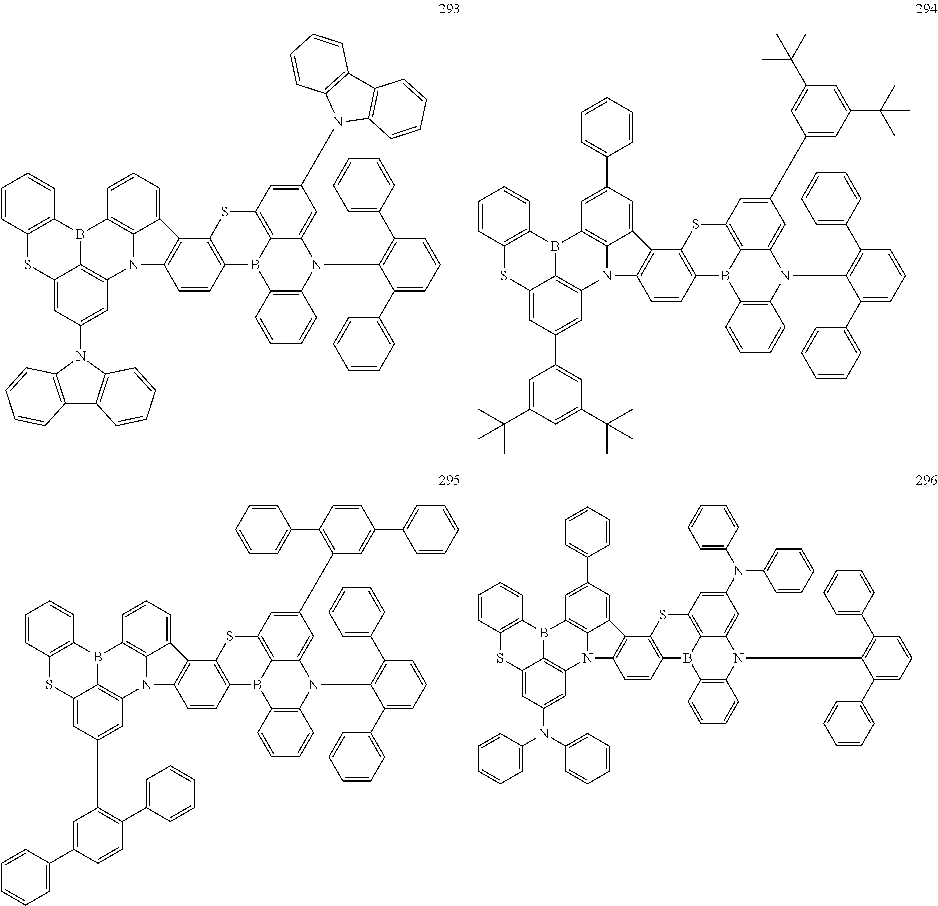

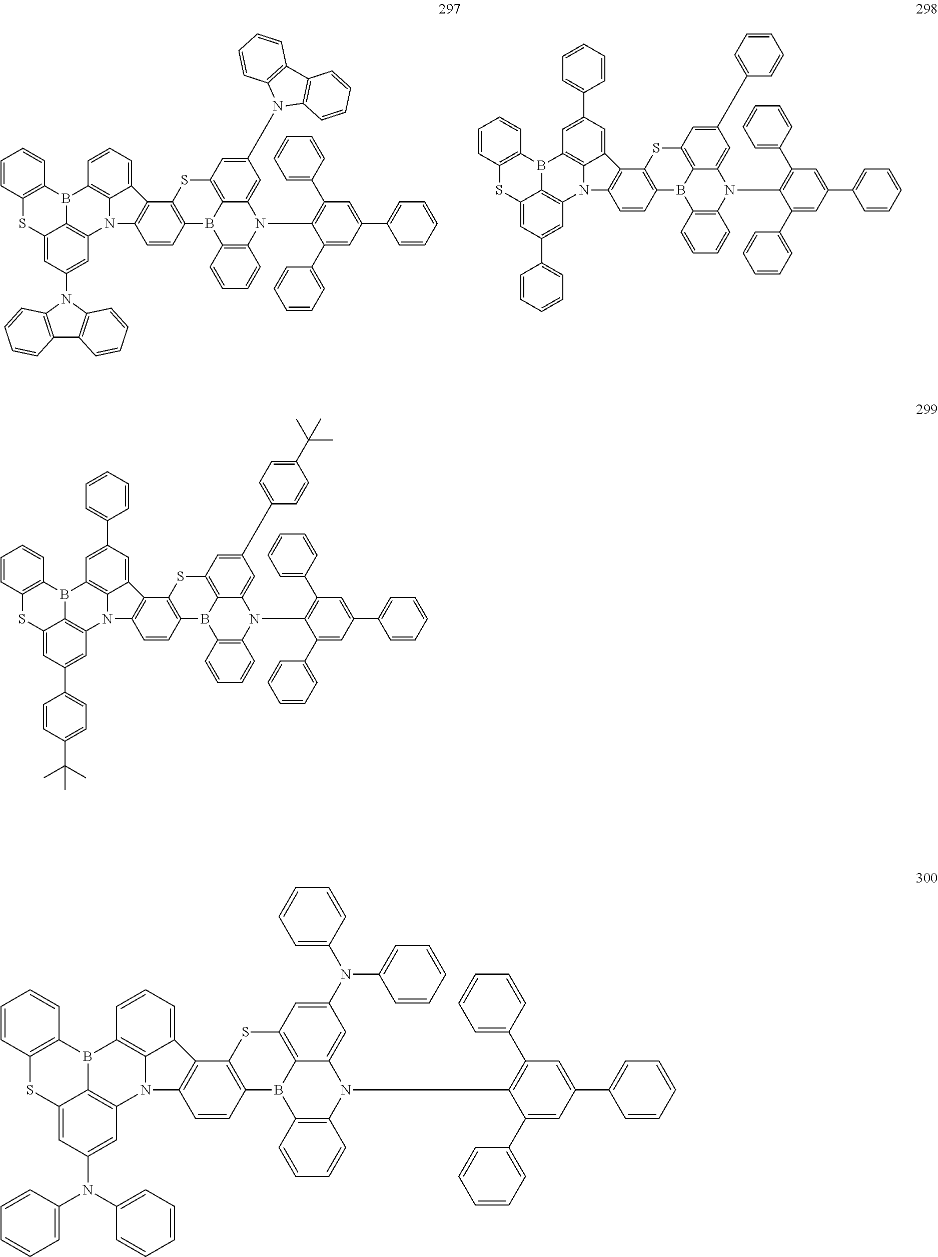

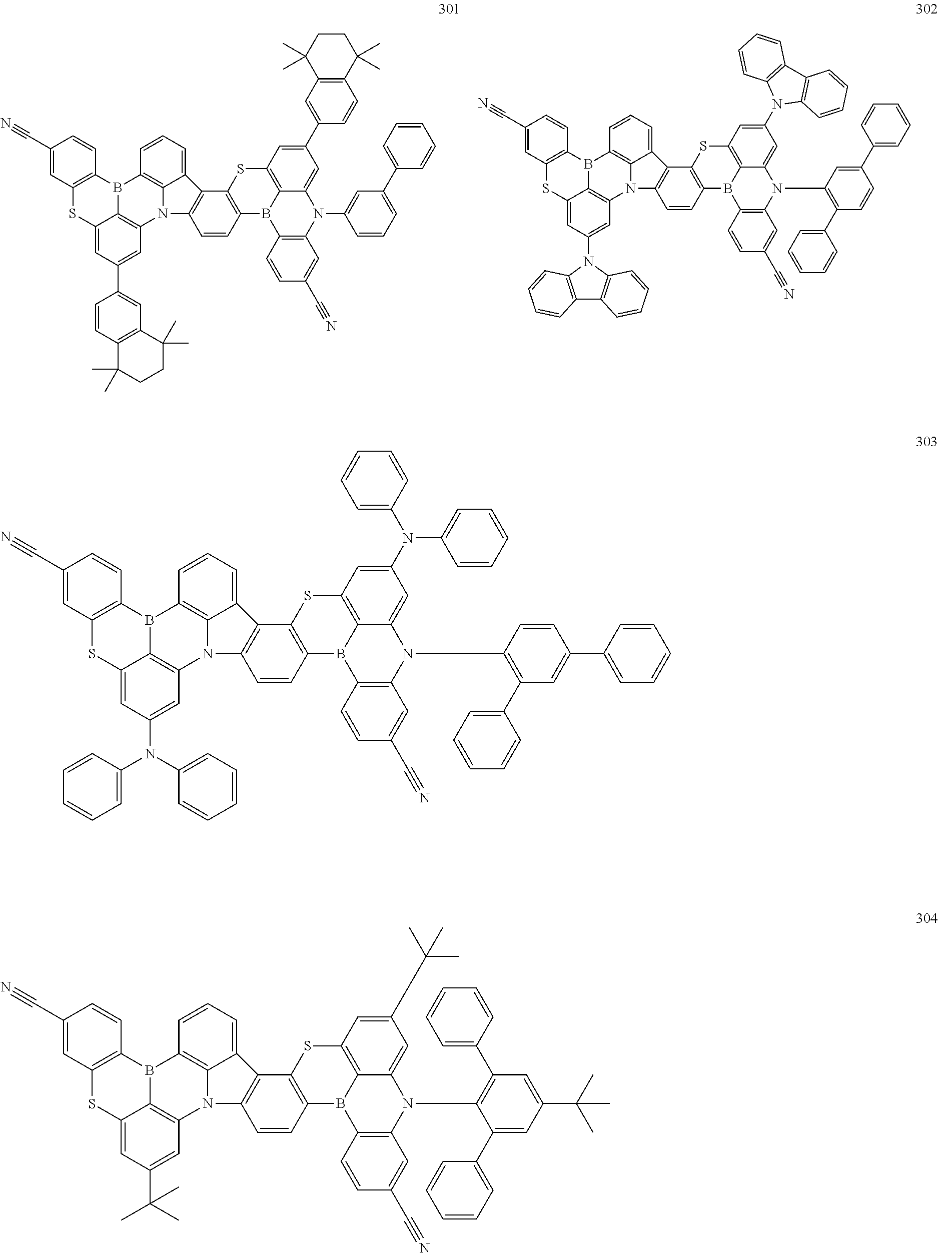

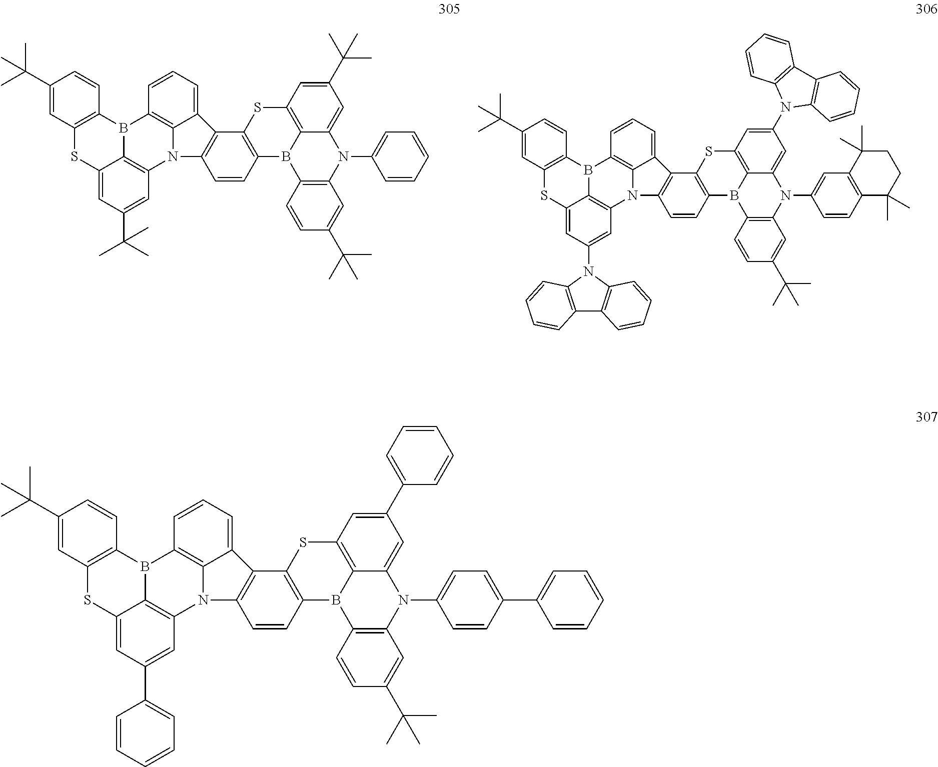 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)S5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)S5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)S5]

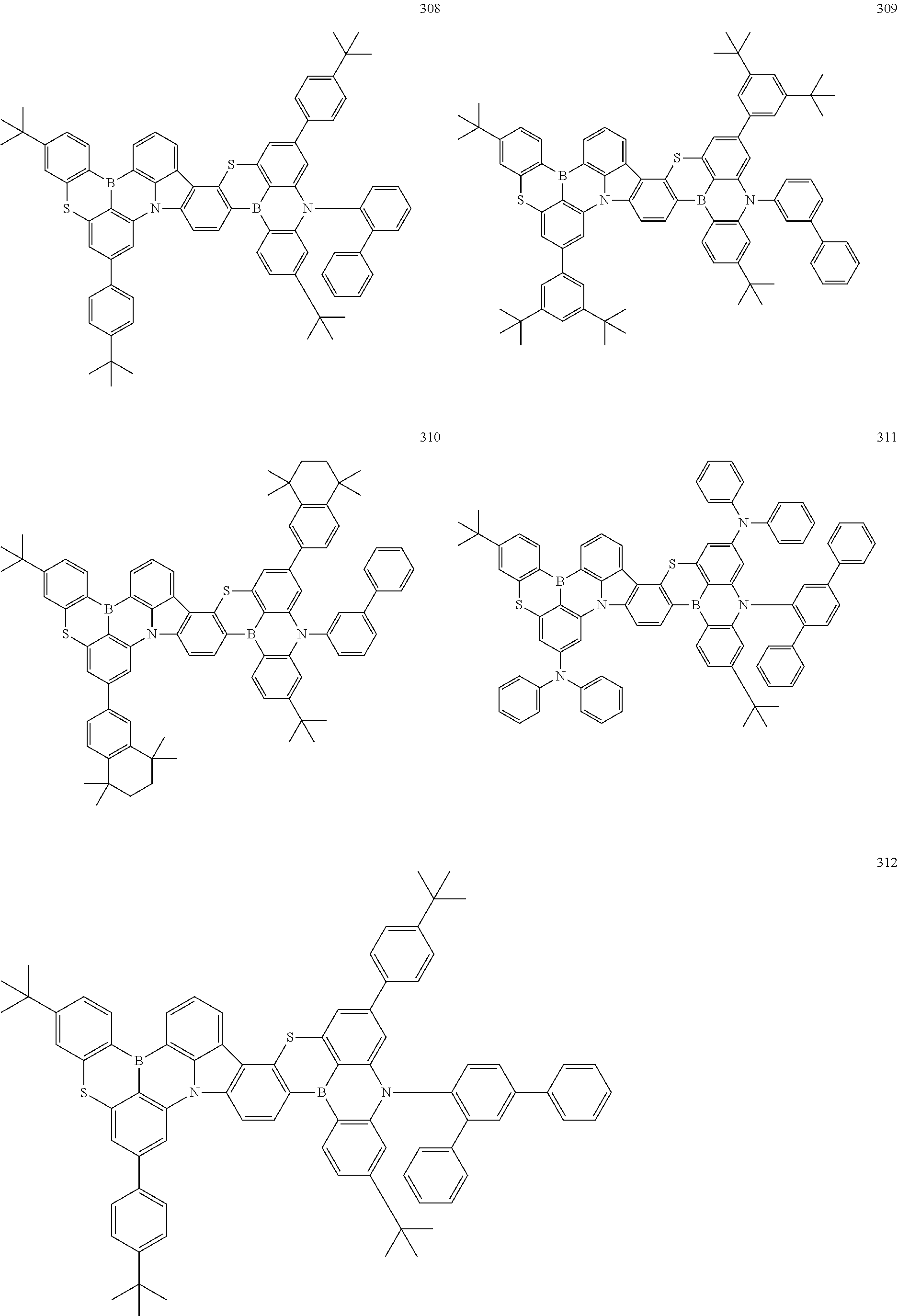

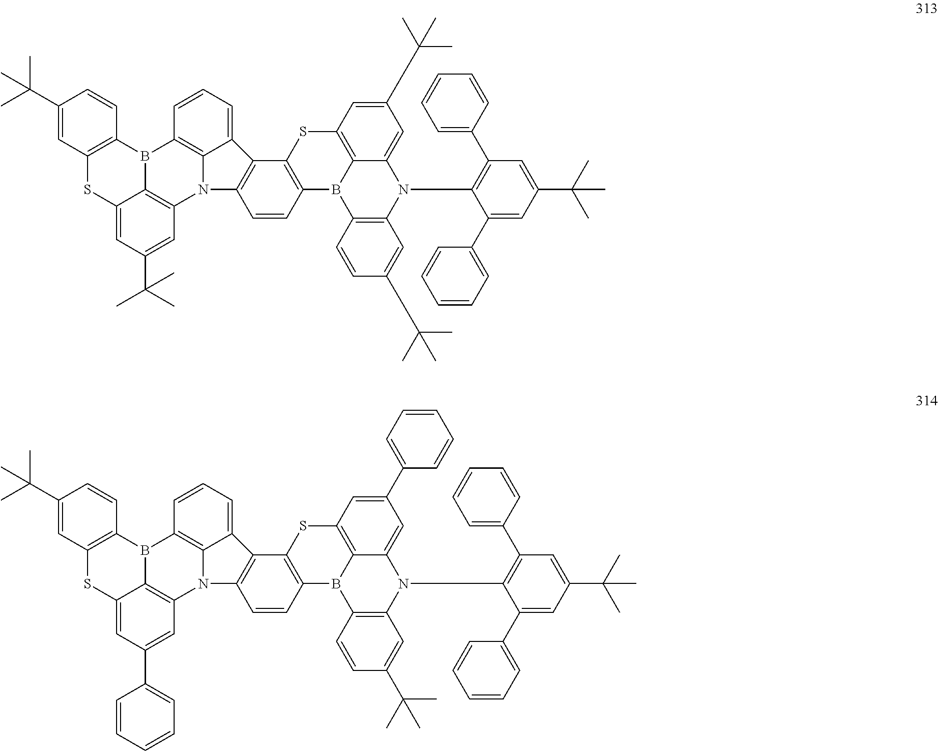

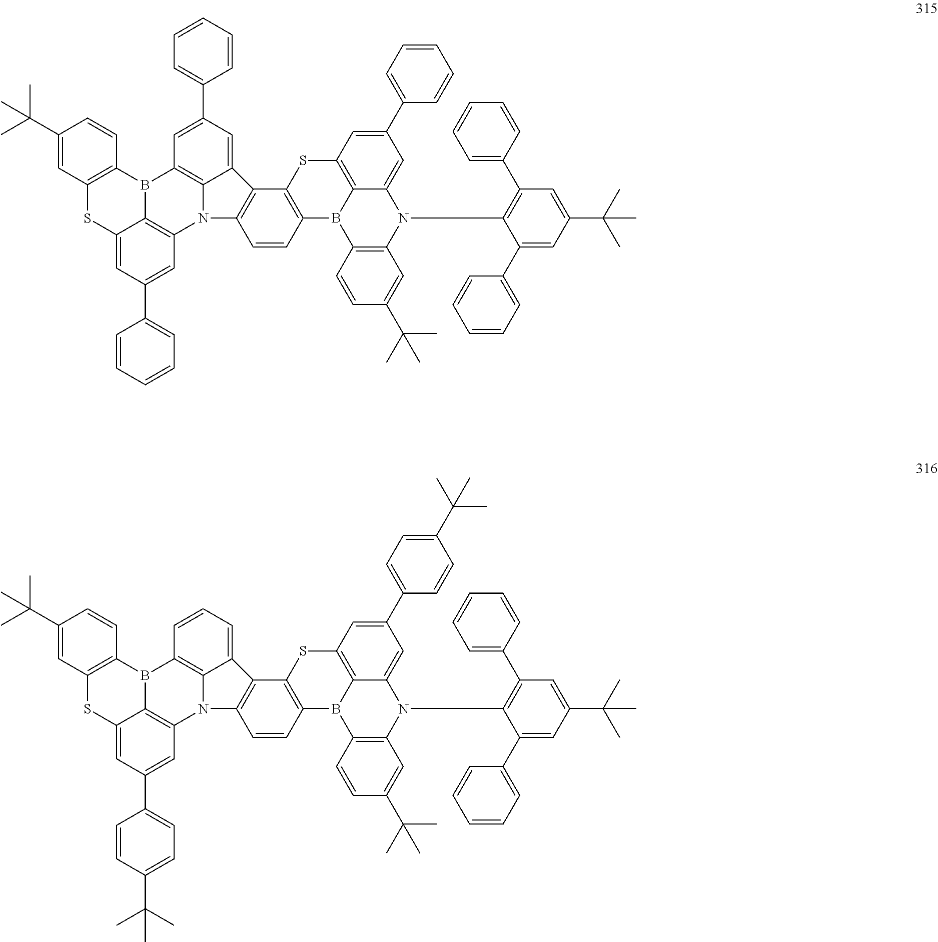

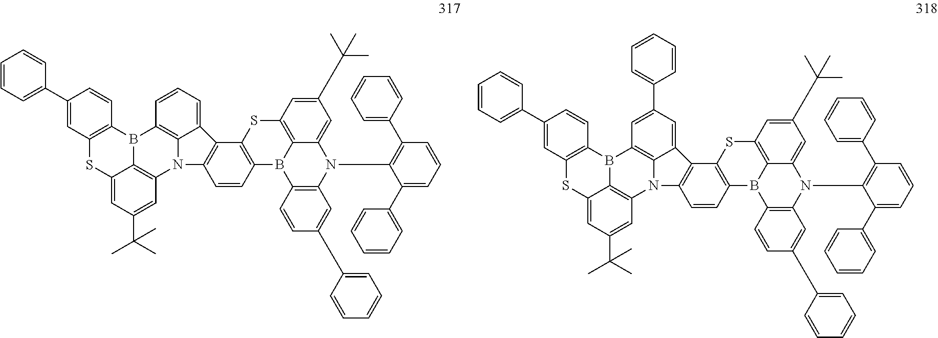 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1S3]

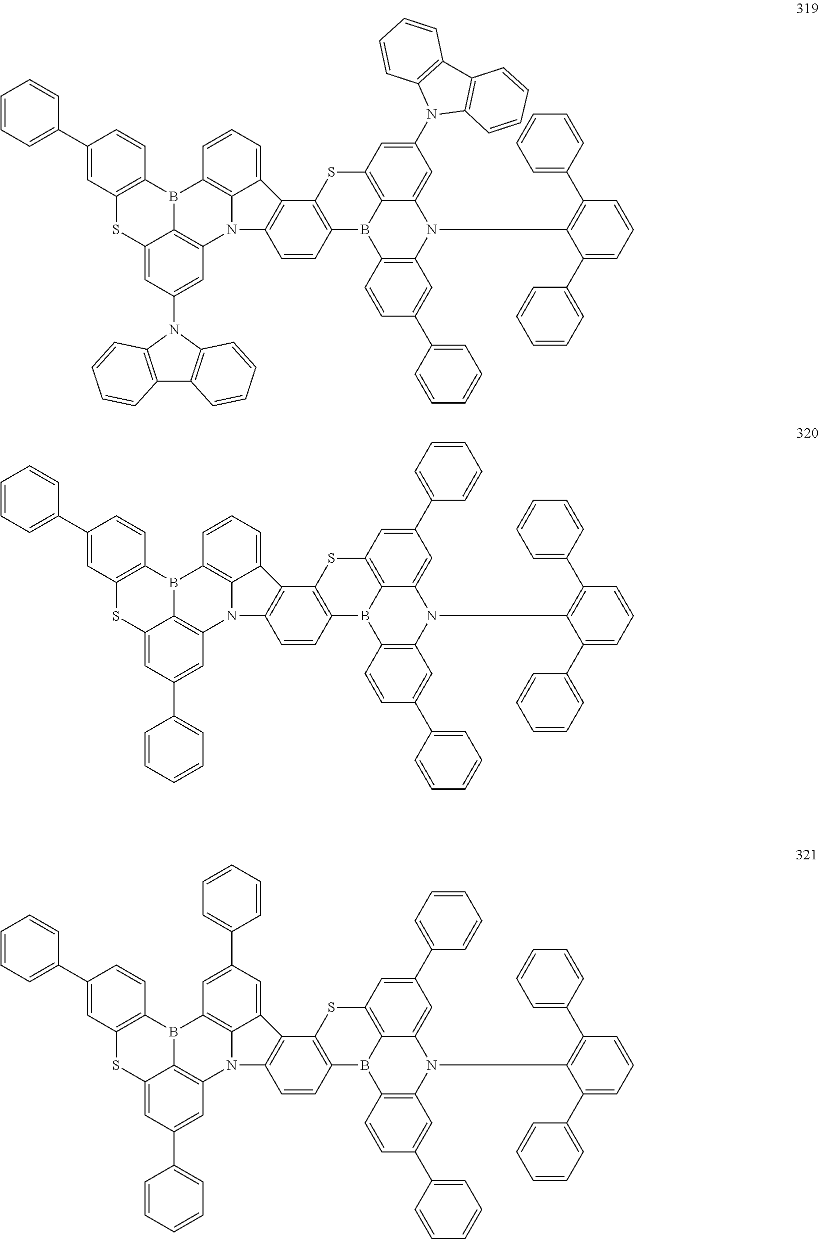

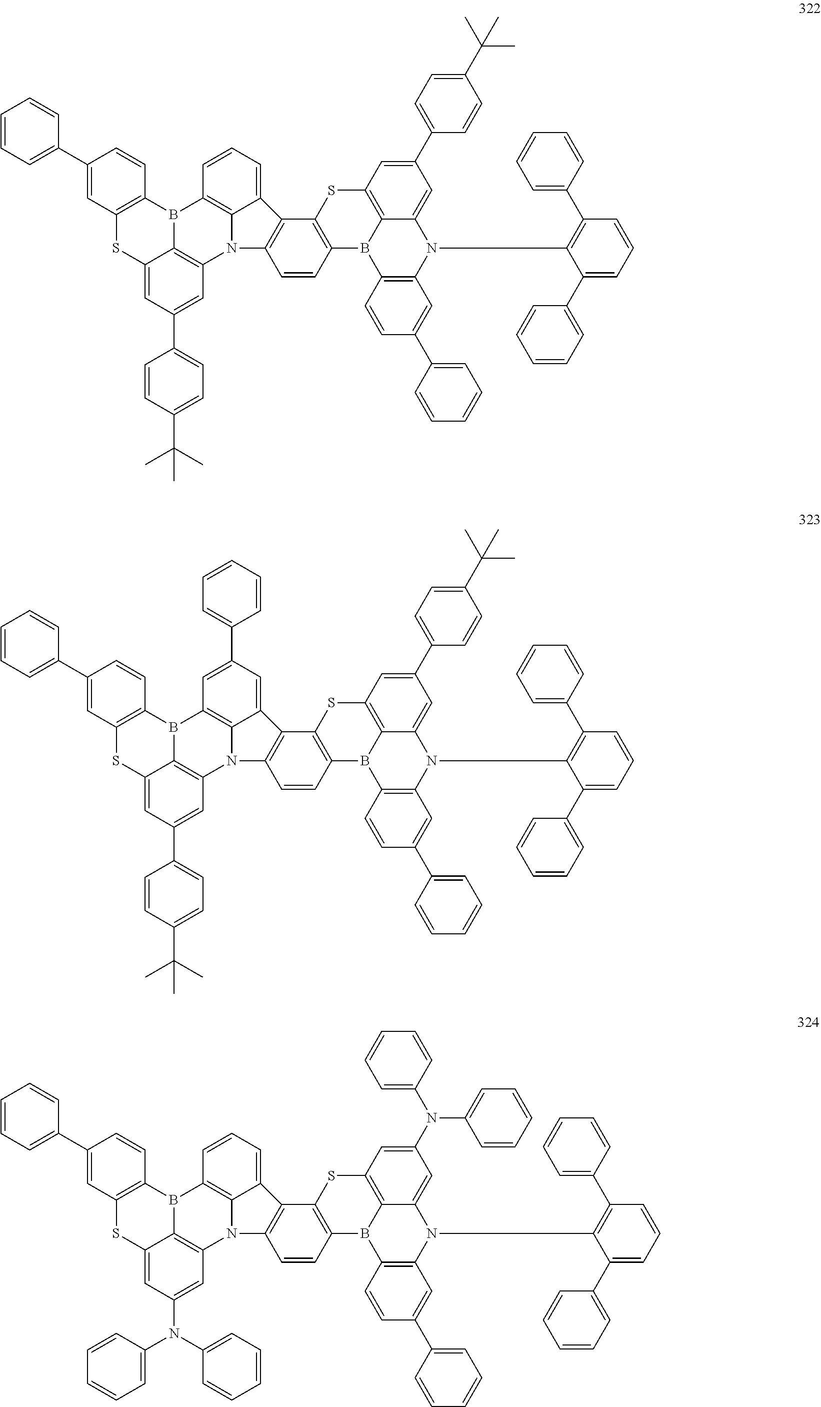

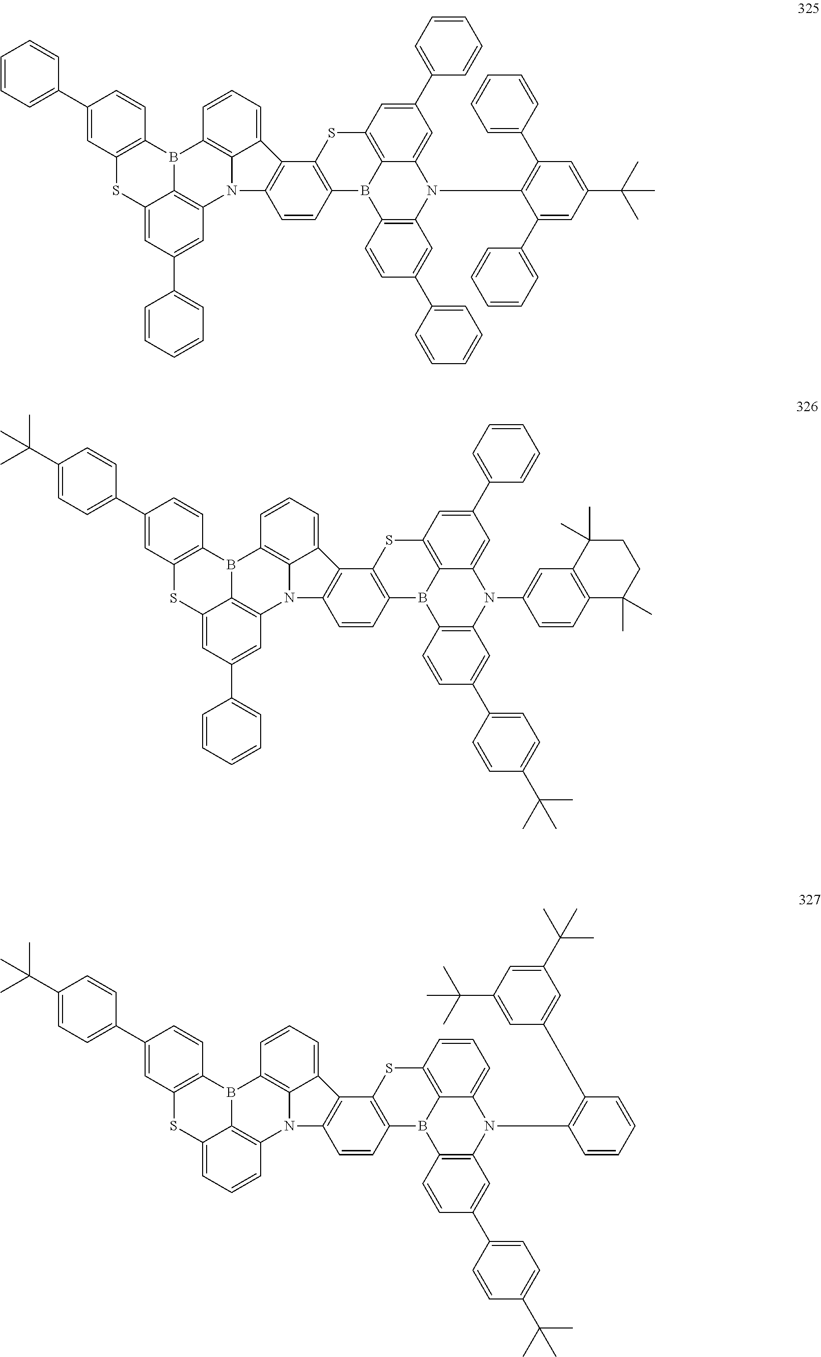

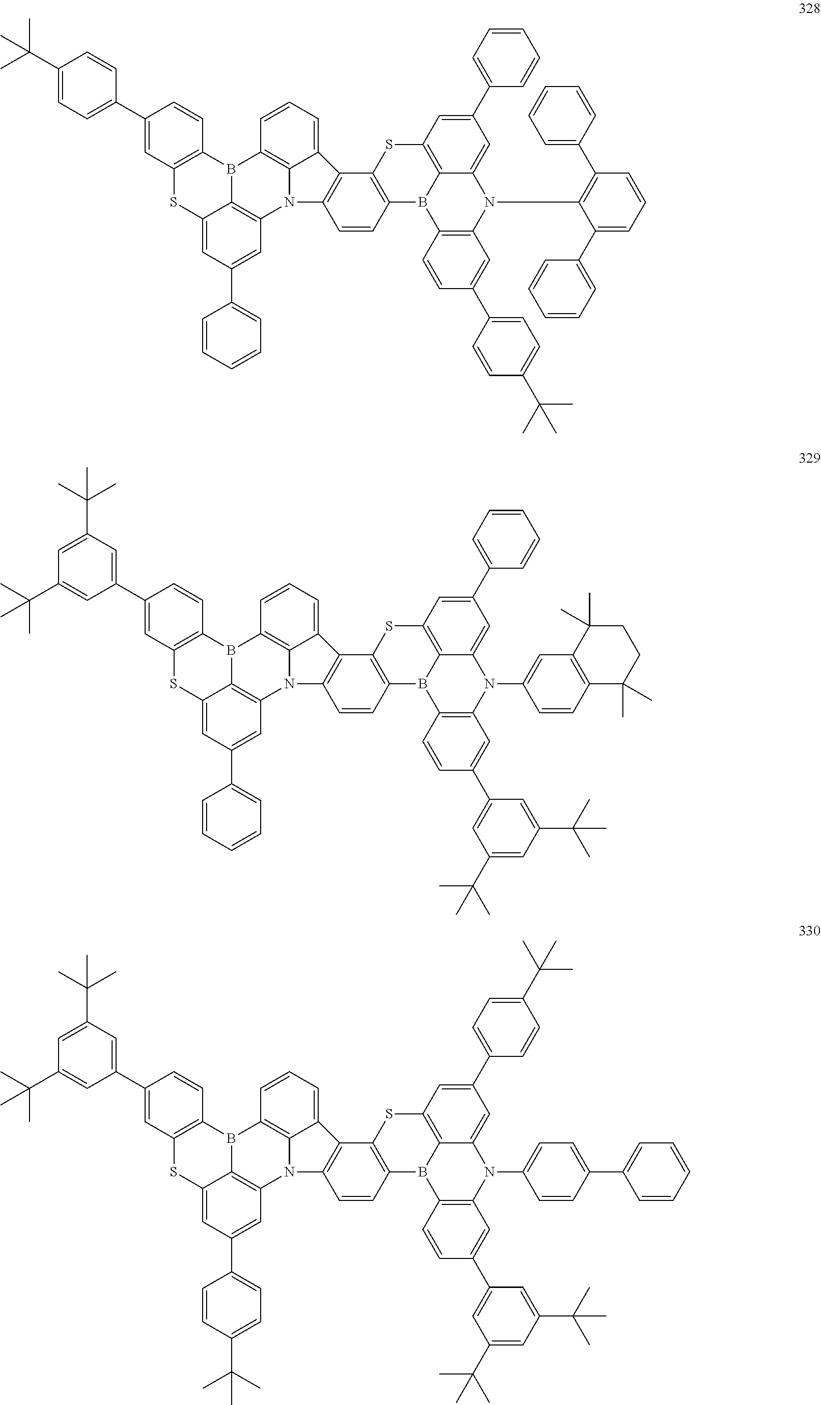

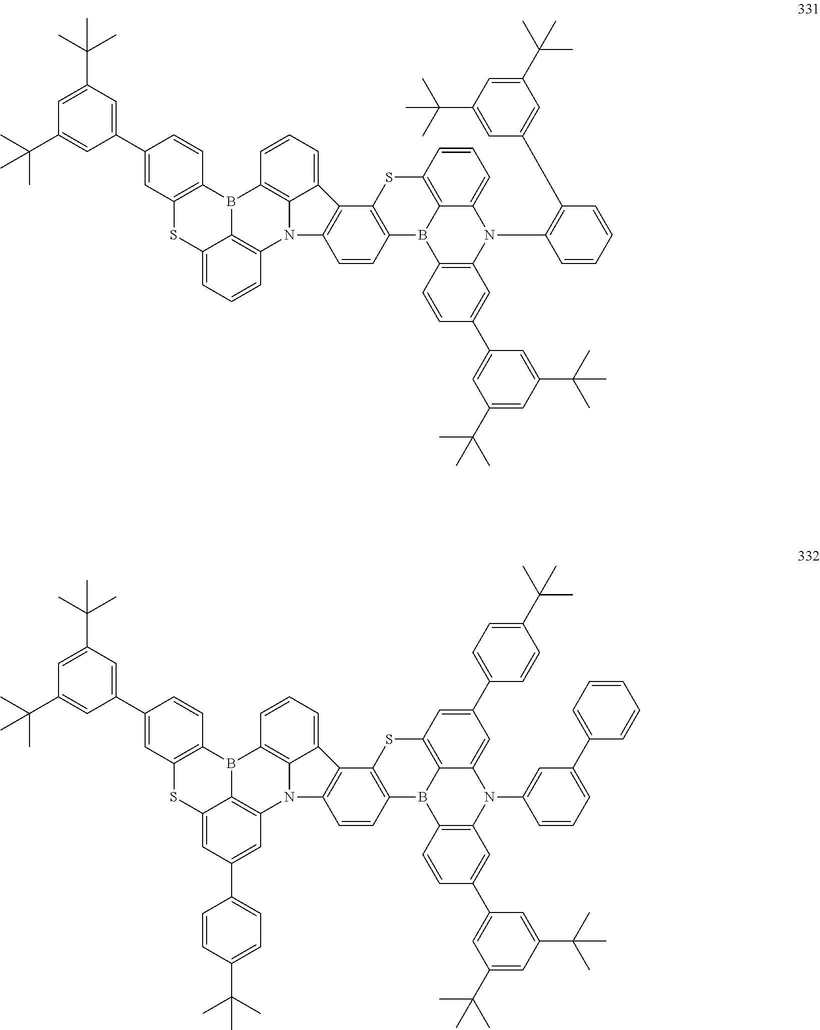 [SMILES: CC(C)(C)c1cc(-c2ccc3c(c2)Sc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)S6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2S3)c2cccc3c2n4-c2cc(-c4ccc(C(C)(C)C)cc4)cc4c2B3c2ccc(-c3cc(C(C)(C)C)cc(C(C)(C)C)c3)cc2S4)cc1]

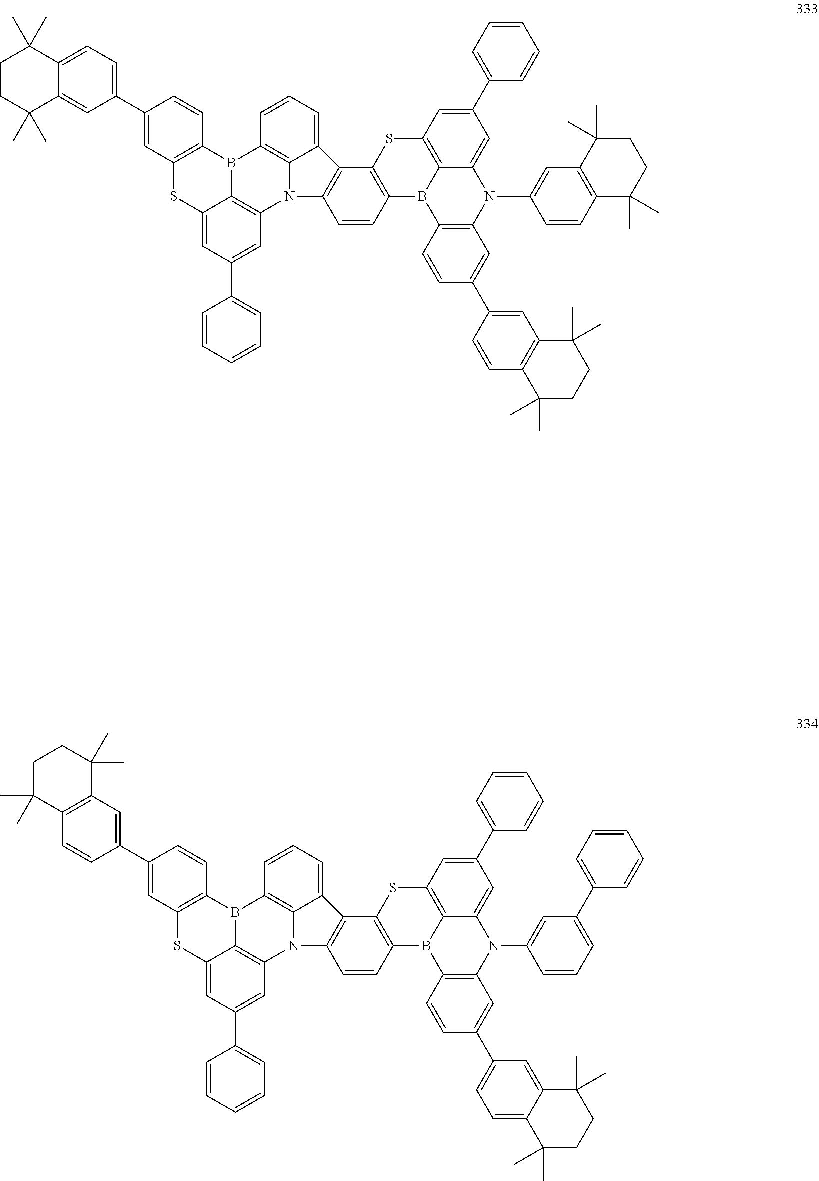

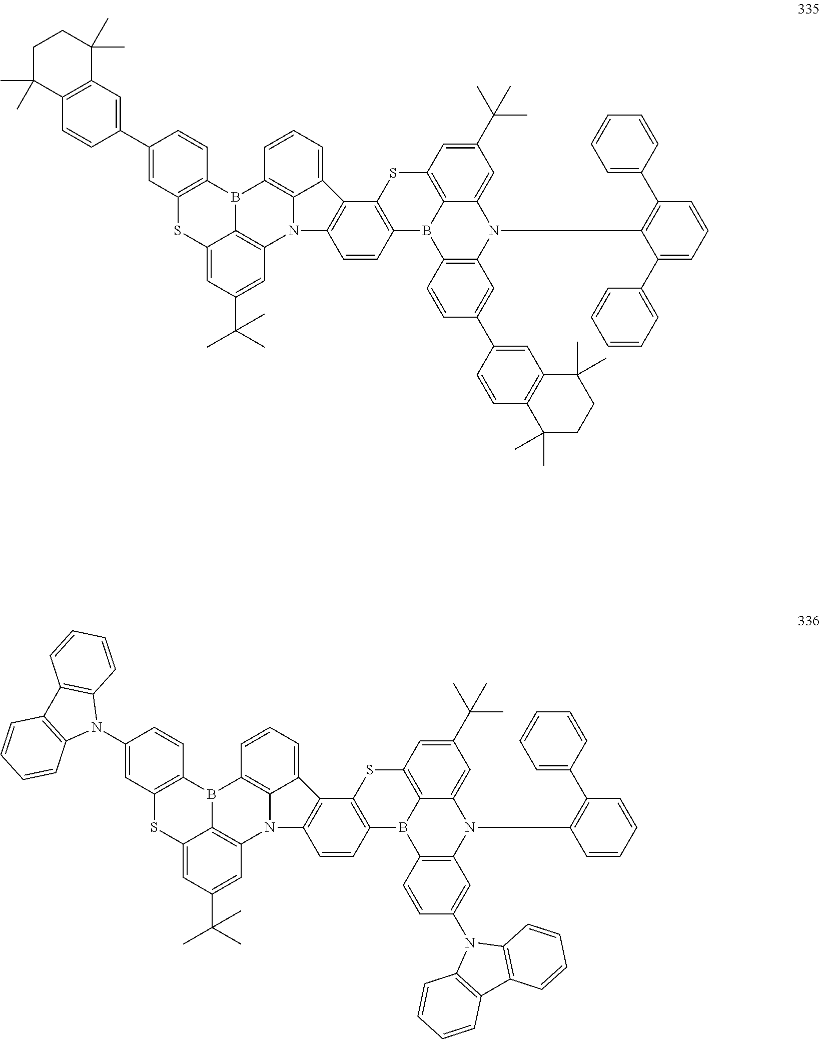 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1S2)c1cccc2c1n3-c1cc(C(C)(C)C)cc3c1B2c1ccc(-c2ccc4c(c2)C(C)(C)CCC4(C)C)cc1S3 ; CC(C)(C)c1cc2c3c(c1)N(c1ccccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3]

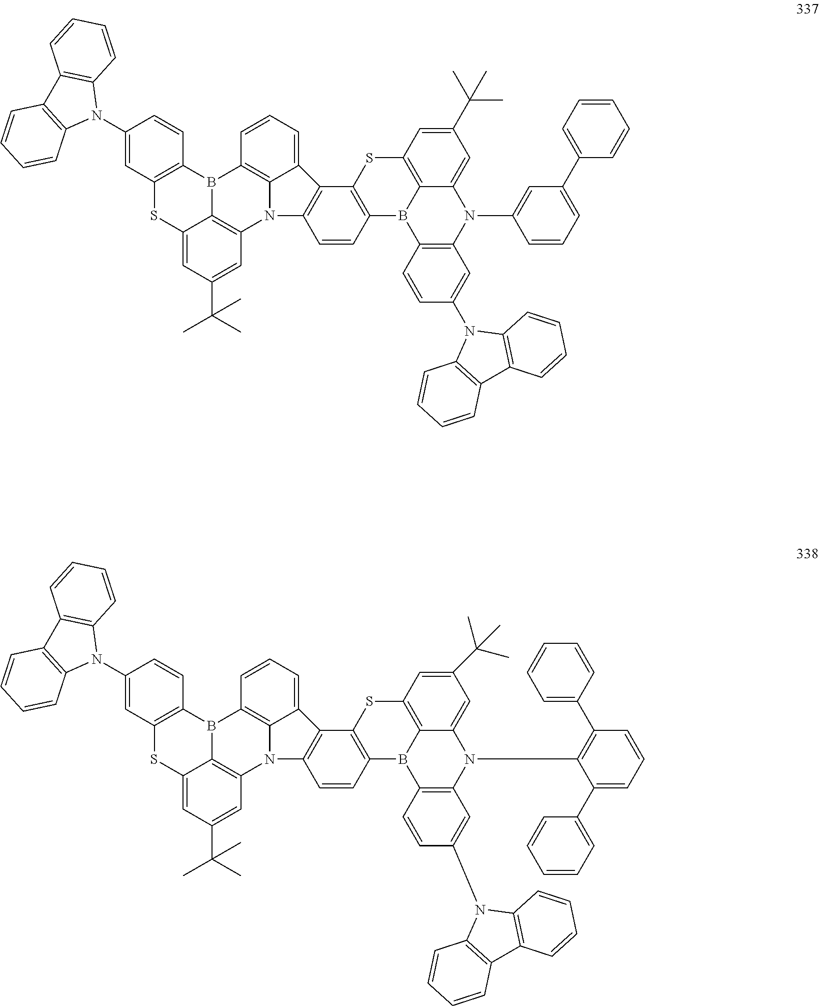 [SMILES: CC(C)(C)c1cc2c3c(c1)N(c1cccc(-c4ccccc4)c1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3]

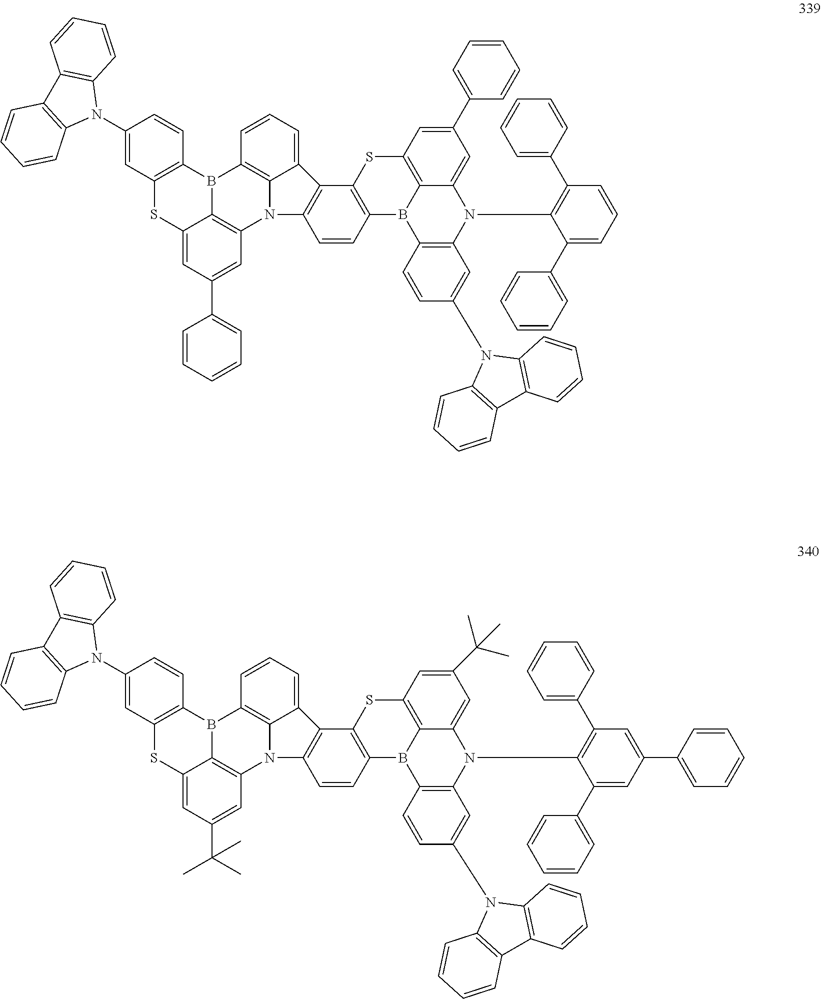 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2S3)c2cccc3c2n4-c2cc(-c4ccccc4)cc4c2B3c2ccc(-n3c5ccccc5c5ccccc53)cc2S4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3]

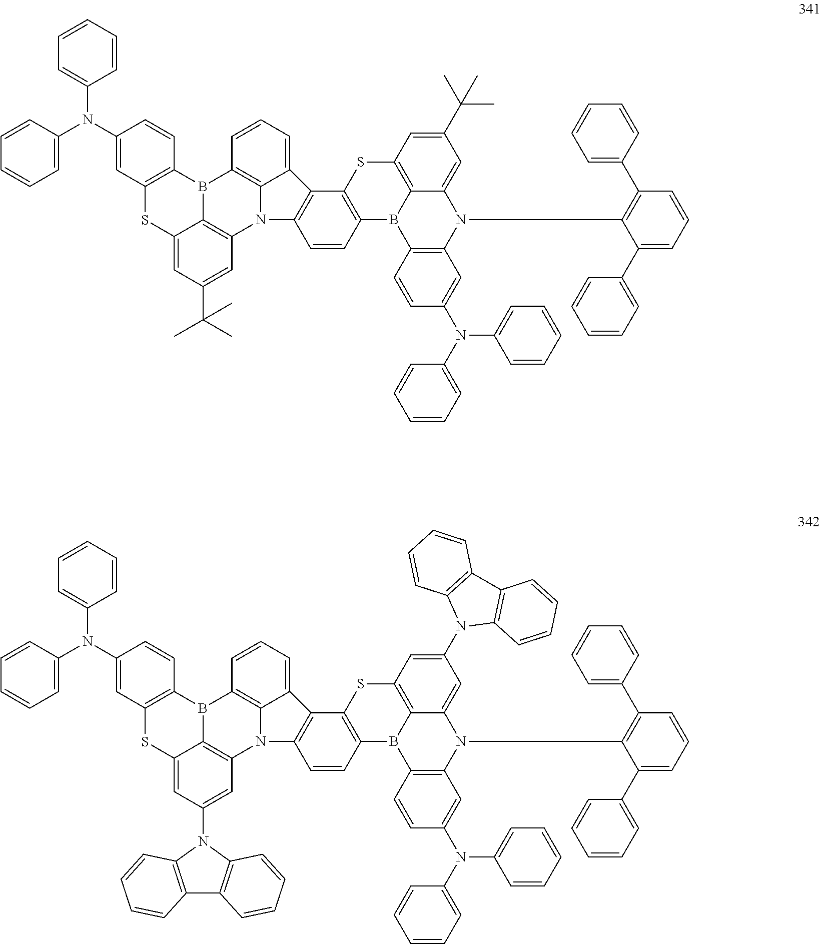 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1S2)c1cccc2c1n3-c1cc(C(C)(C)C)cc3c1B2c1ccc(N(c2ccccc2)c2ccccc2)cc1S3 ; c1ccc(-c2cccc(-c3ccccc3)c2N2c3cc(N(c4ccccc4)c4ccccc4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2S4)cc1]

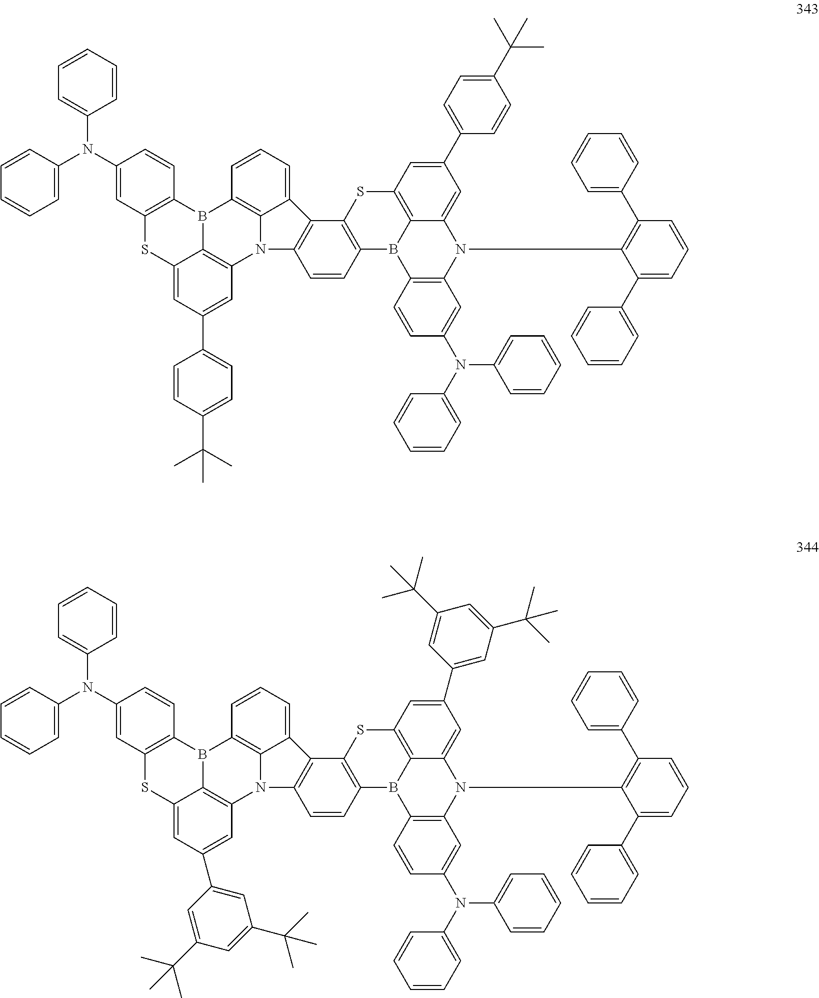 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4ccc(C(C)(C)C)cc4)cc4c2B3c2ccc(N(c3ccccc3)c3ccccc3)cc2S4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4cc(C(C)(C)C)cc(C(C)(C)C)c4)cc4c2B3c2ccc(N(c3ccccc3)c3ccccc3)cc2S4)cc(C(C)(C)C)c1]

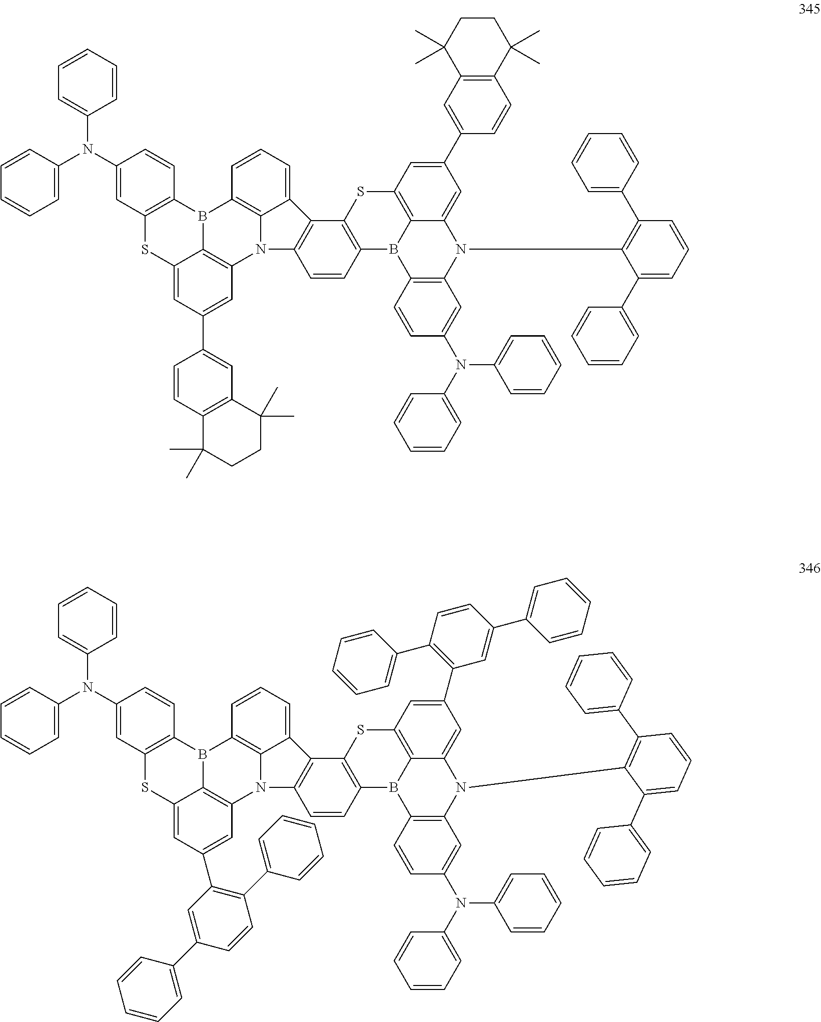 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5ccc6c(c5)C(C)(C)CCC6(C)C)cc5c3B4c3ccc(N(c4ccccc4)c4ccccc4)cc3S5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5cc(-c6ccccc6)ccc5-c5ccccc5)cc5c3B4c3ccc(N(c4ccccc4)c4ccccc4)cc3S5)c2)cc1]

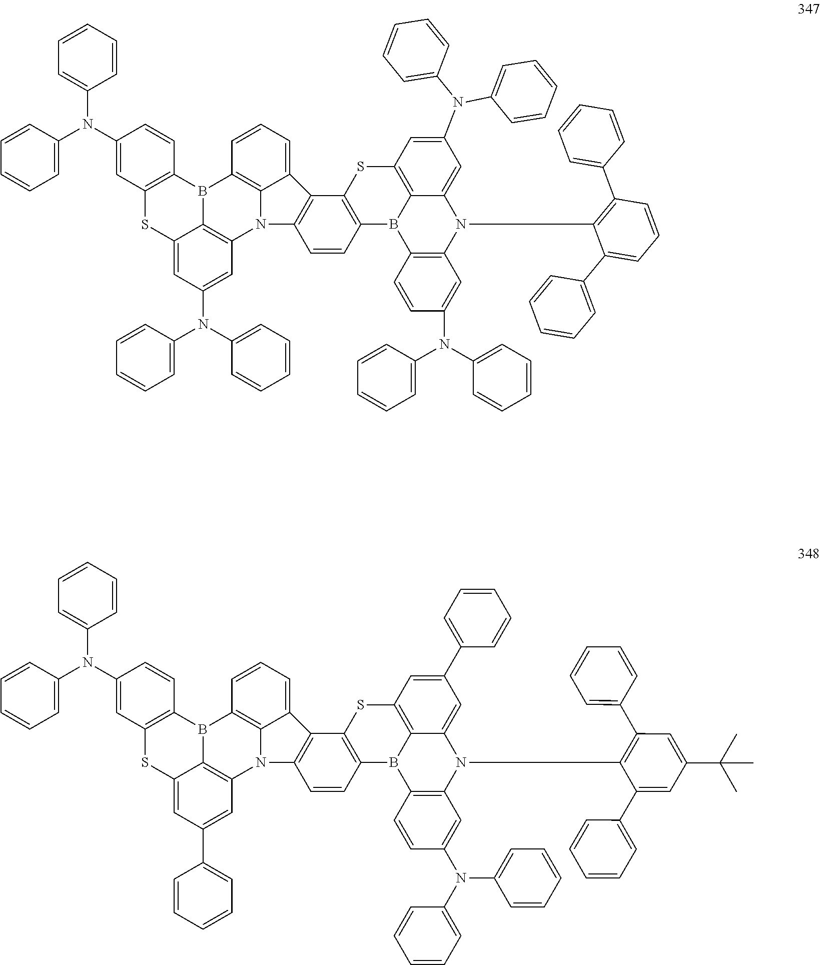 [SMILES: c1ccc(-c2cccc(-c3ccccc3)c2N2c3cc(N(c4ccccc4)c4ccccc4)ccc3B3c4ccc5c(c4Sc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2S4)cc1 ; CC(C)(C)c1cc(-c2ccccc2)c(N2c3cc(N(c4ccccc4)c4ccccc4)ccc3B3c4ccc5c(c4Sc4cc(-c6ccccc6)cc2c43)c2cccc3c2n5-c2cc(-c4ccccc4)cc4c2B3c2ccc(N(c3ccccc3)c3ccccc3)cc2S4)c(-c2ccccc2)c1]

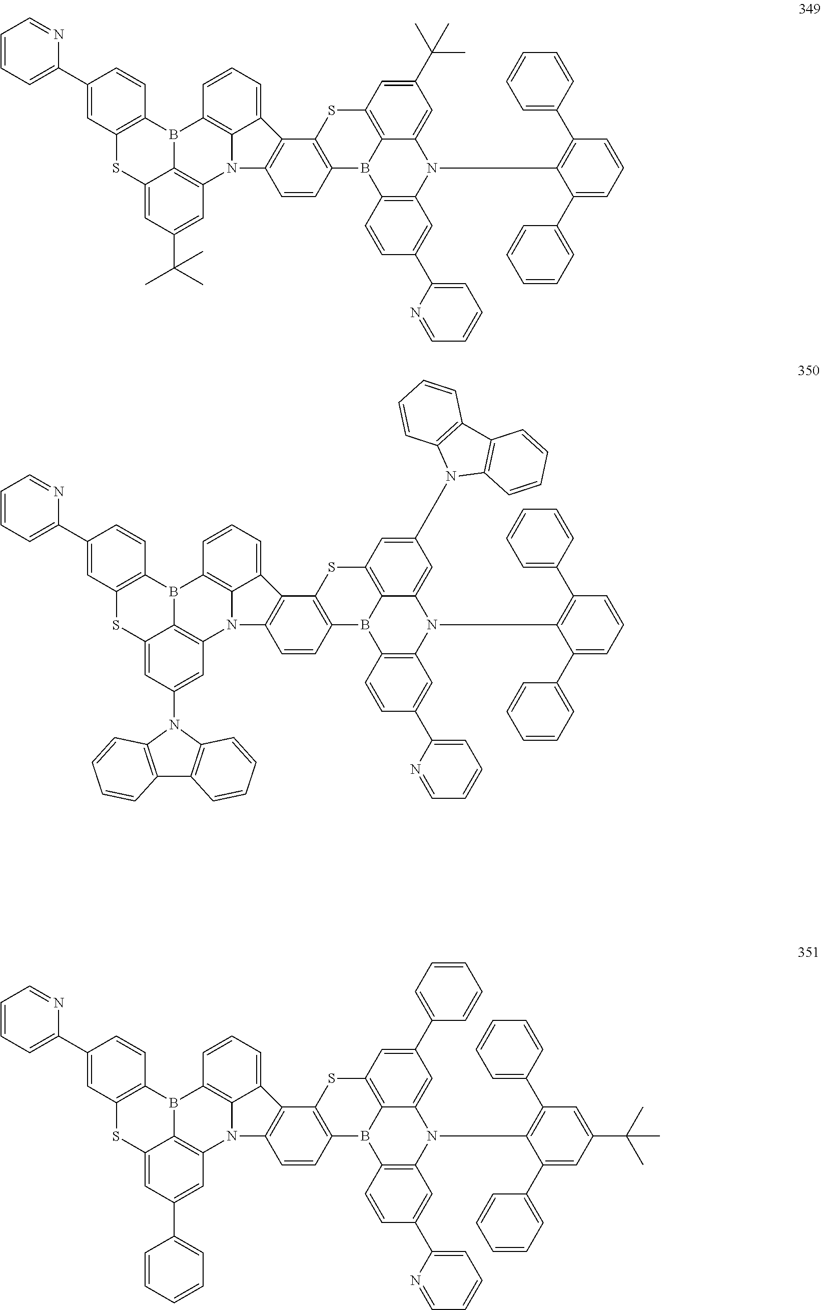

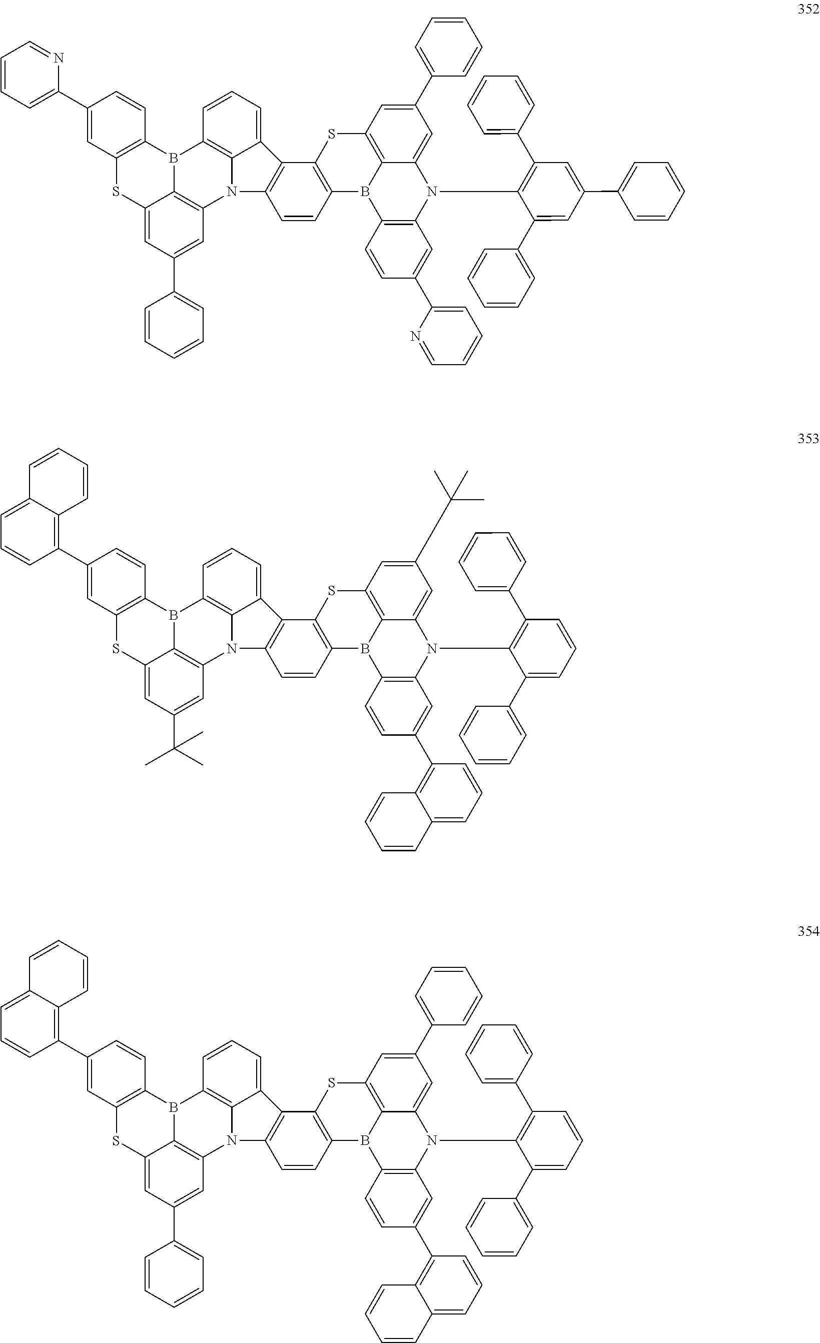 [SMILES: c1ccc(-c2cc(-c3ccccc3)c(N3c4cc(-c5ccccn5)ccc4B4c5ccc6c(c5Sc5cc(-c7ccccc7)cc3c54)c3cccc4c3n6-c3cc(-c5ccccc5)cc5c3B4c3ccc(-c4ccccn4)cc3S5)c(-c3ccccc3)c2)cc1 ; CC(C)(C)c1cc2c3c(c1)N(c1c(-c4ccccc4)cccc1-c1ccccc1)c1cc(-c4cccc5ccccc45)ccc1B3c1ccc3c(c1S2)c1cccc2c1n3-c1cc(C(C)(C)C)cc3c1B2c1ccc(-c2cccc4ccccc24)cc1S3 ; c1ccc(-c2cc3c4c(c2)N(c2c(-c5ccccc5)cccc2-c2ccccc2)c2cc(-c5cccc6ccccc56)ccc2B4c2ccc4c(c2S3)c2cccc3c2n4-c2cc(-c4ccccc4)cc4c2B3c2ccc(-c3cccc5ccccc35)cc2S4)cc1]

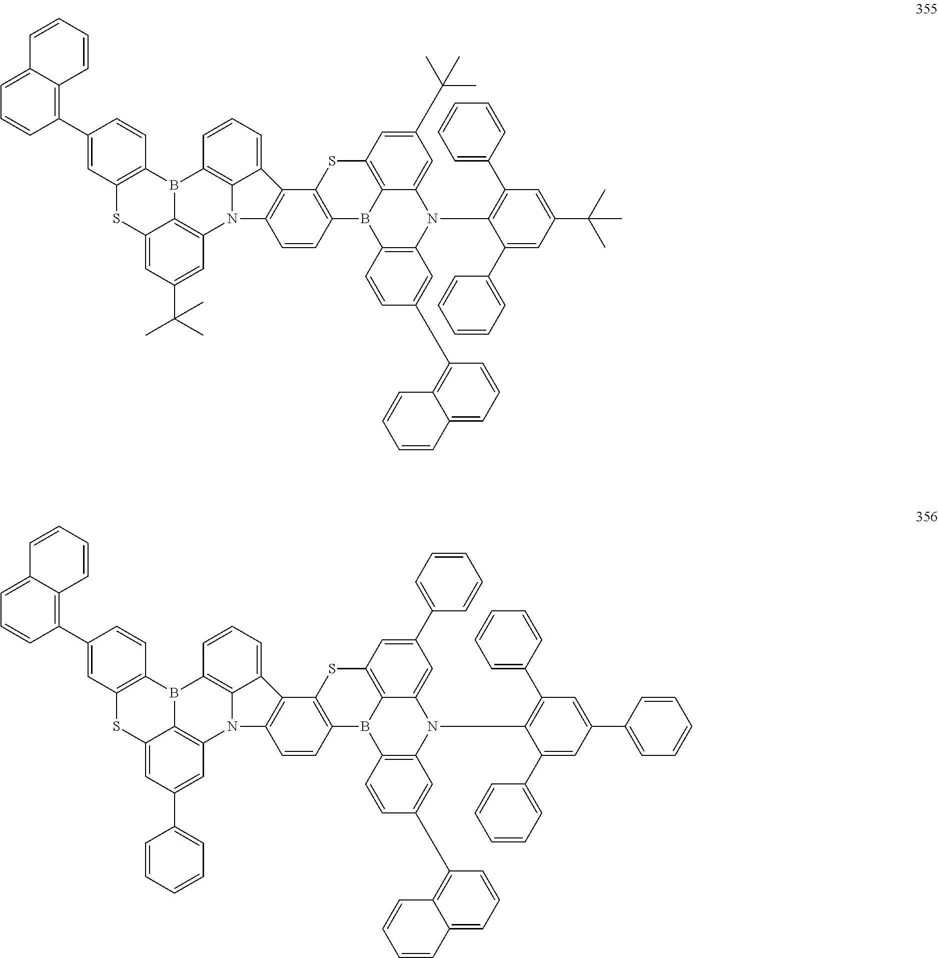 [SMILES: CC(C)(C)c1cc(-c2ccccc2)c(N2c3cc(-c4cccc5ccccc45)ccc3B3c4ccc5c(c4Sc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Sc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1]

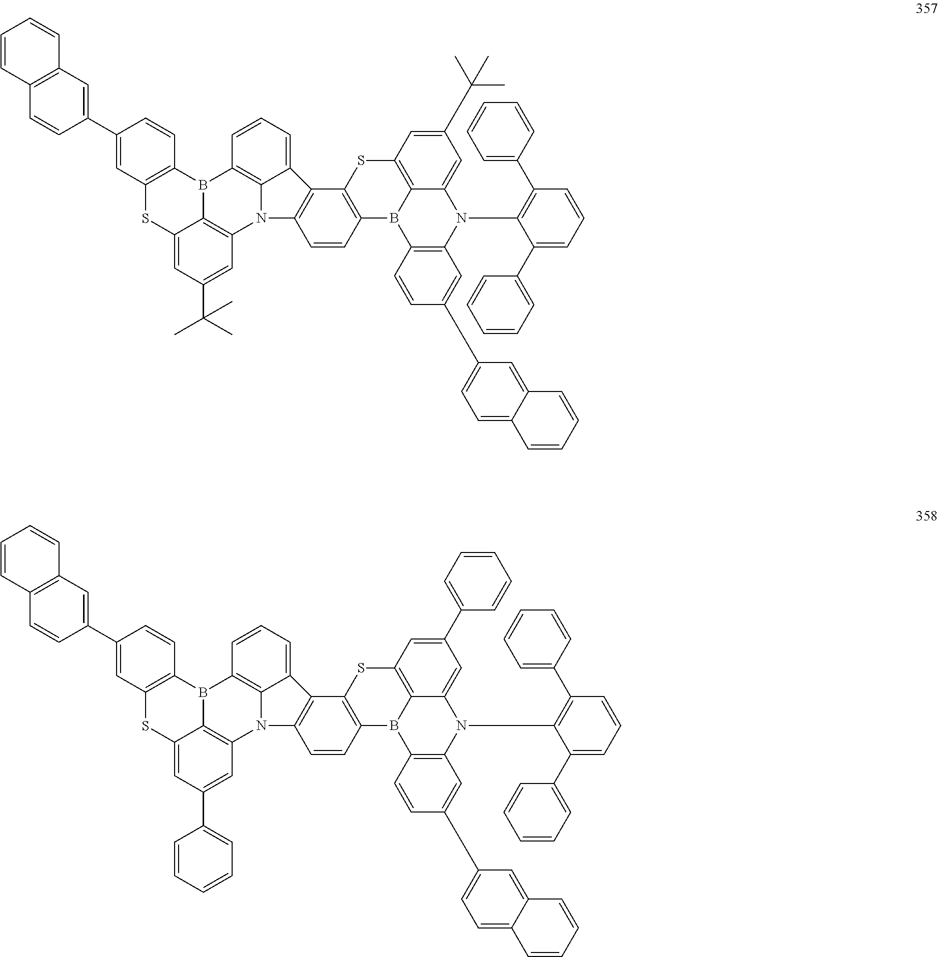 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1S2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2S3)c2cccc3c2n4-c2cc(-c4ccccc4)cc4c2B3c2ccc(-c3ccc5ccccc5c3)cc2S4)cc1]

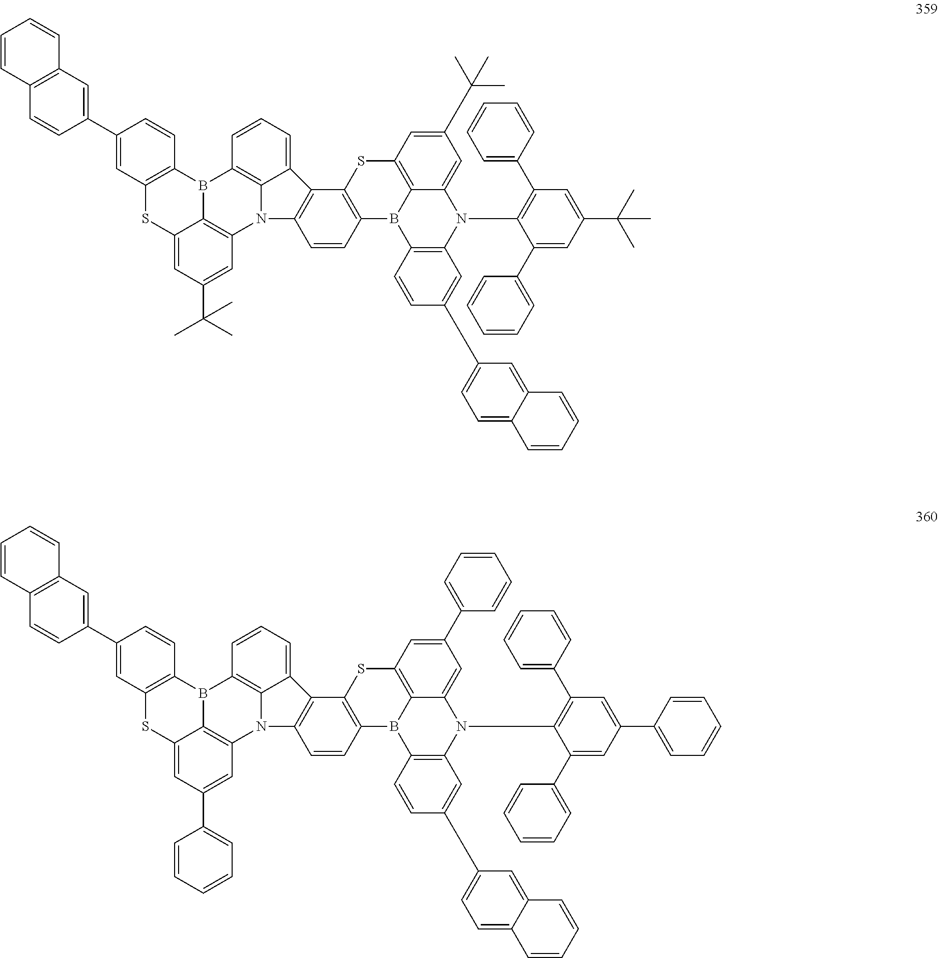 [SMILES: CC(C)(C)c1cc(-c2ccccc2)c(N2c3cc(-c4ccc5ccccc5c4)ccc3B3c4ccc5c(c4Sc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Sc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1]

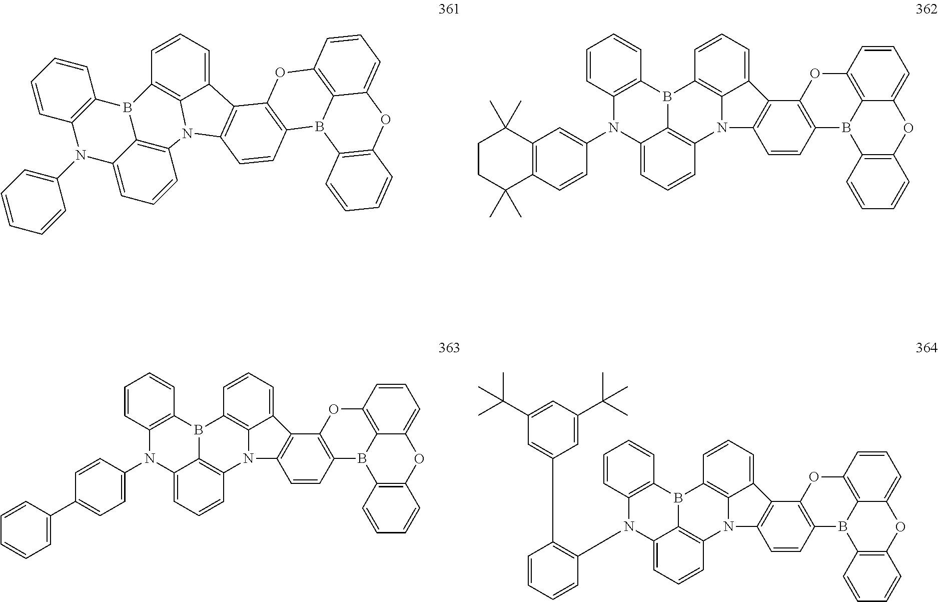 [SMILES: c1ccc(N2c3ccccc3B3c4c2cccc4-n2c4ccc5c(c4c4cccc3c42)Oc2cccc3c2B5c2ccccc2O3)cc1 ; CC1(C)CCC(C)(C)c2cc(N3c4ccccc4B4c5c3cccc5-n3c5ccc6c(c5c5cccc4c53)Oc3cccc4c3B6c3ccccc3O4)ccc21 ; c1ccc(-c2ccc(N3c4ccccc4B4c5c3cccc5-n3c5ccc6c(c5c5cccc4c53)Oc3cccc4c3B6c3ccccc3O4)cc2)cc1 ; CC(C)(C)c1cc(-c2ccccc2N2c3ccccc3B3c4c2cccc4-n2c4ccc5c(c4c4cccc3c42)Oc2cccc3c2B5c2ccccc2O3)cc(C(C)(C)C)c1]

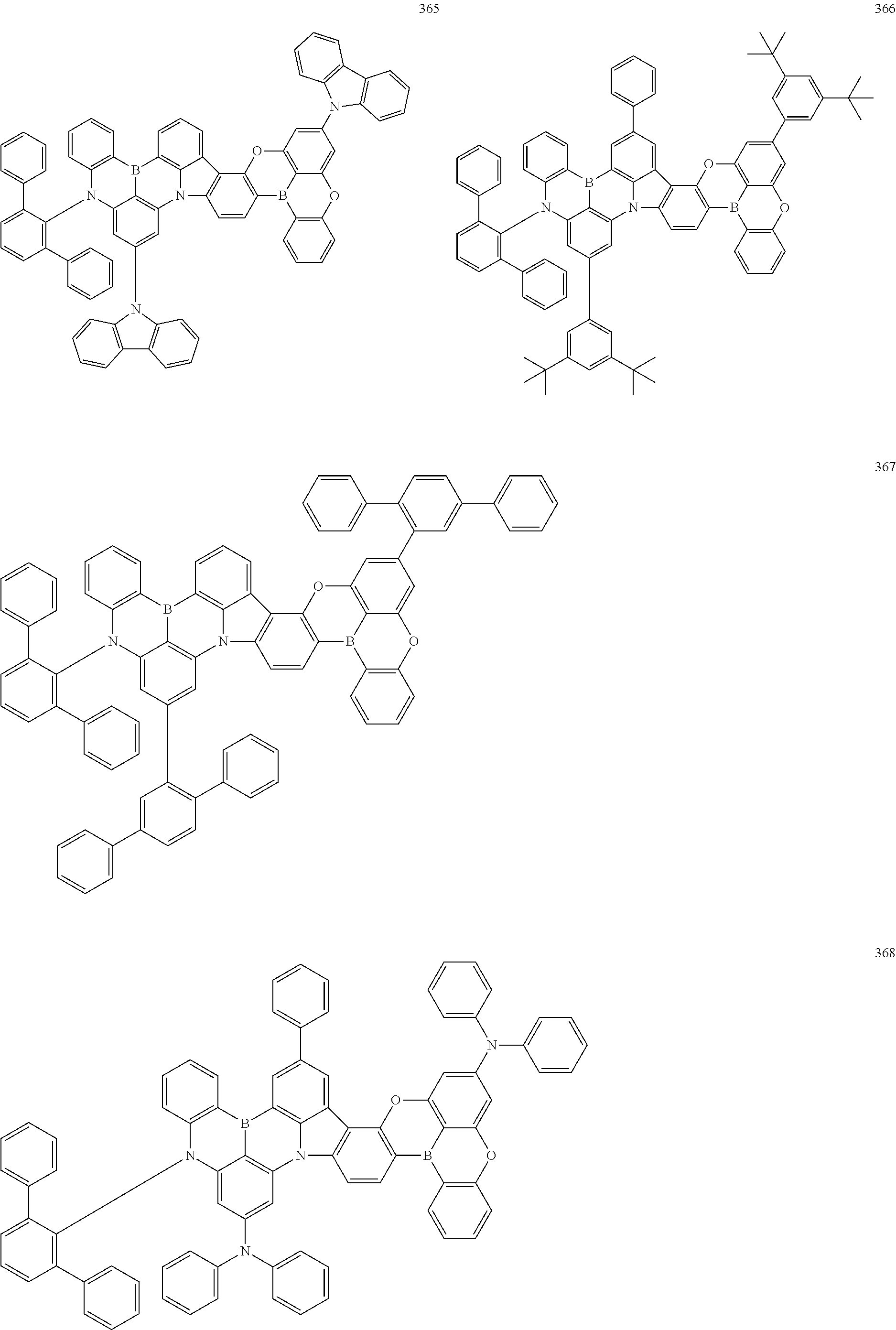

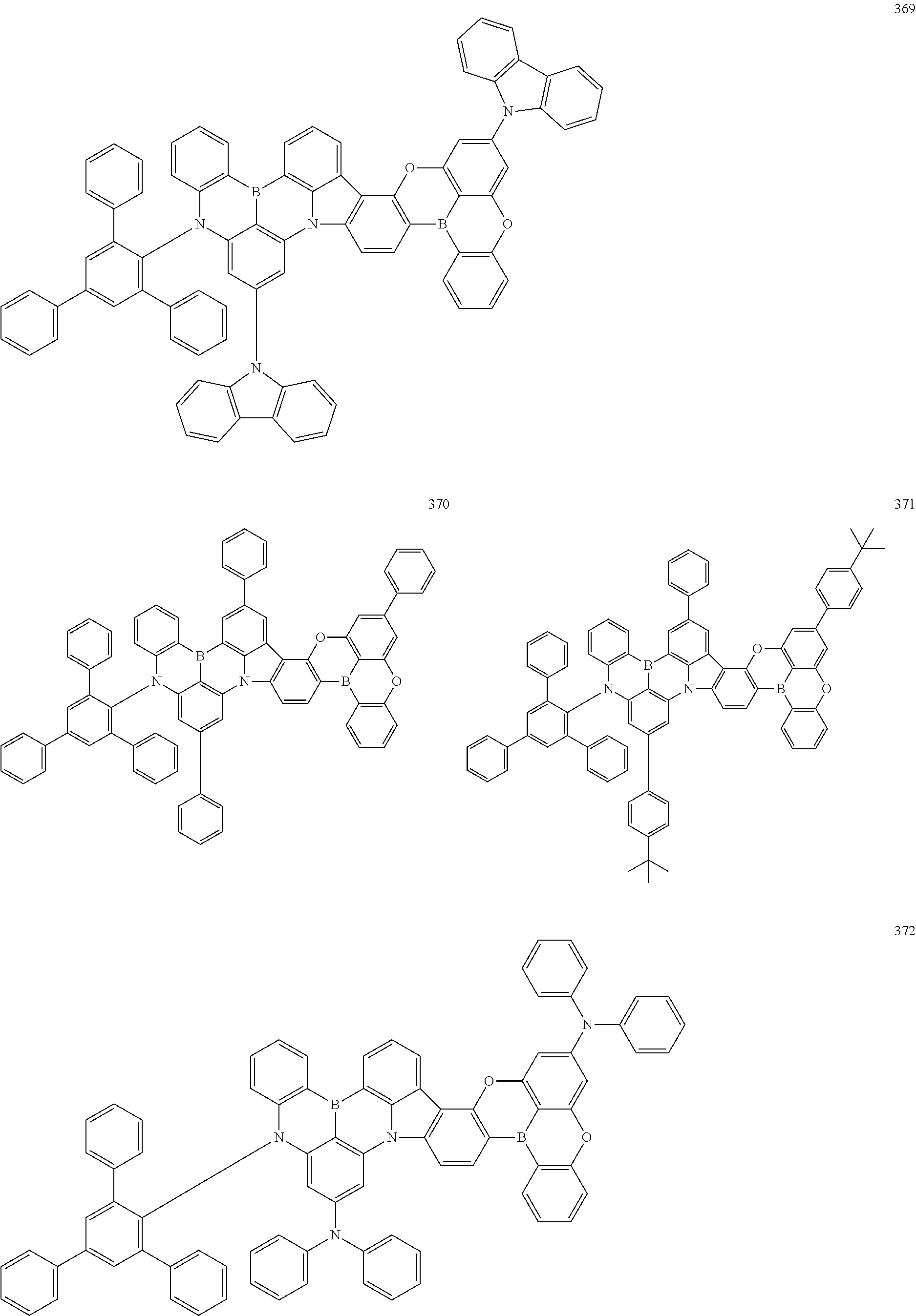

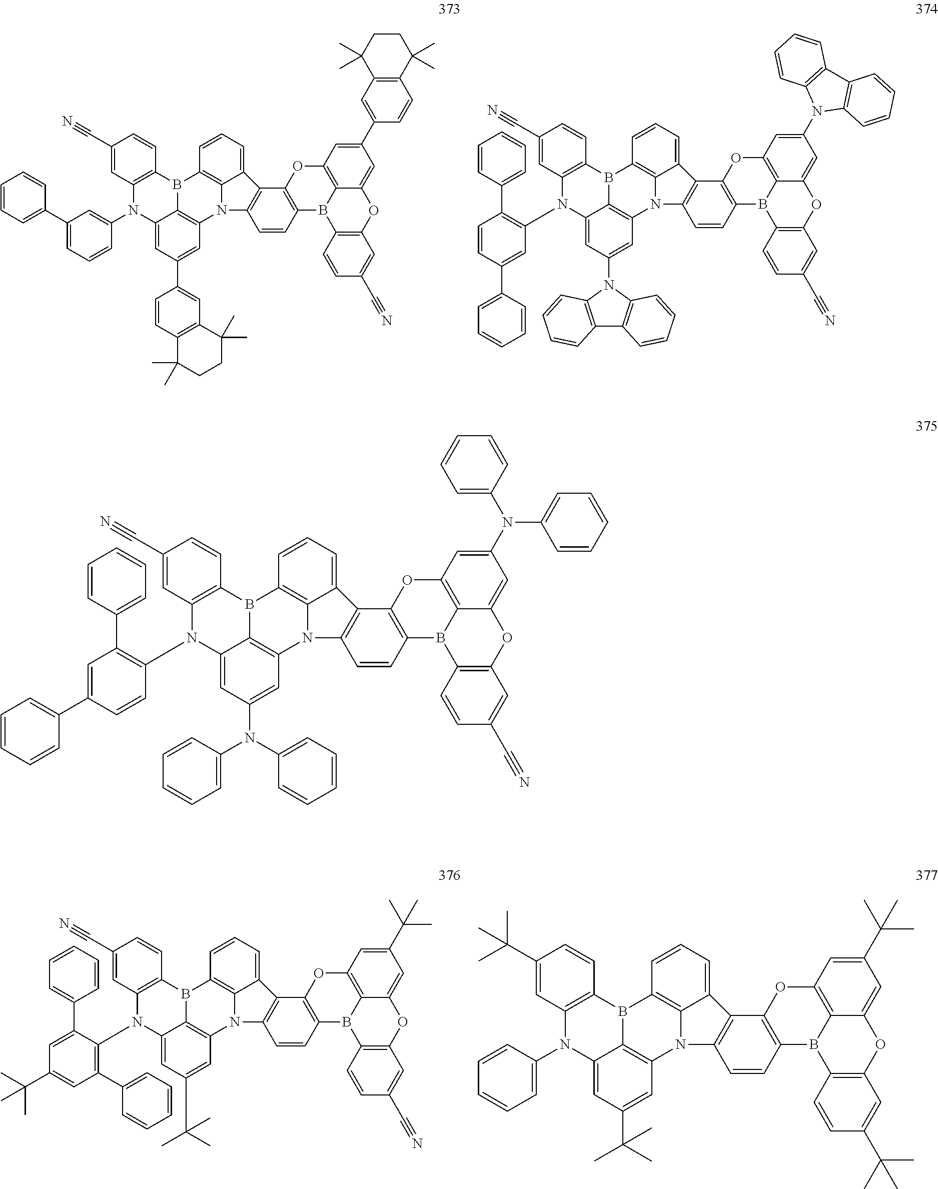

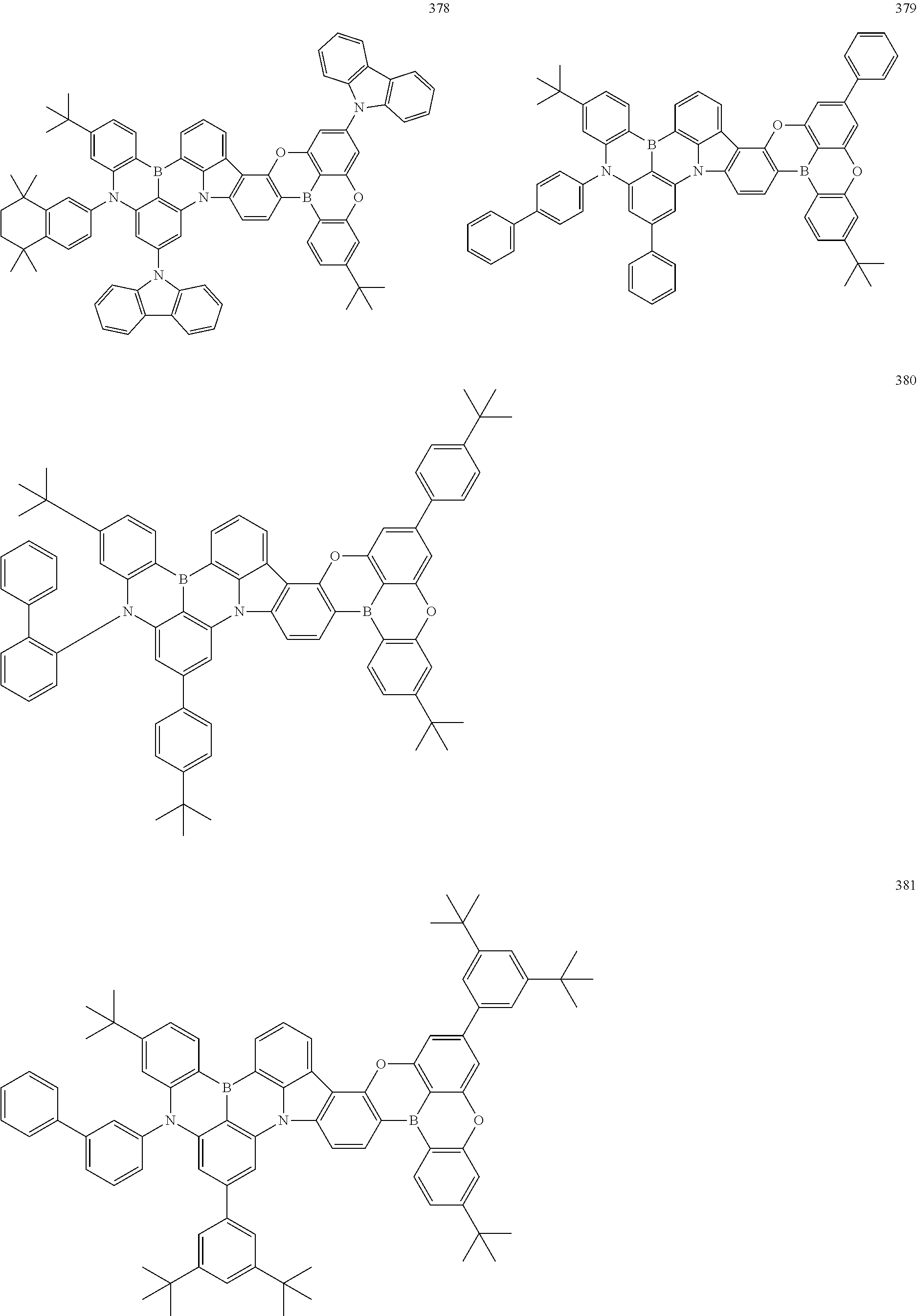

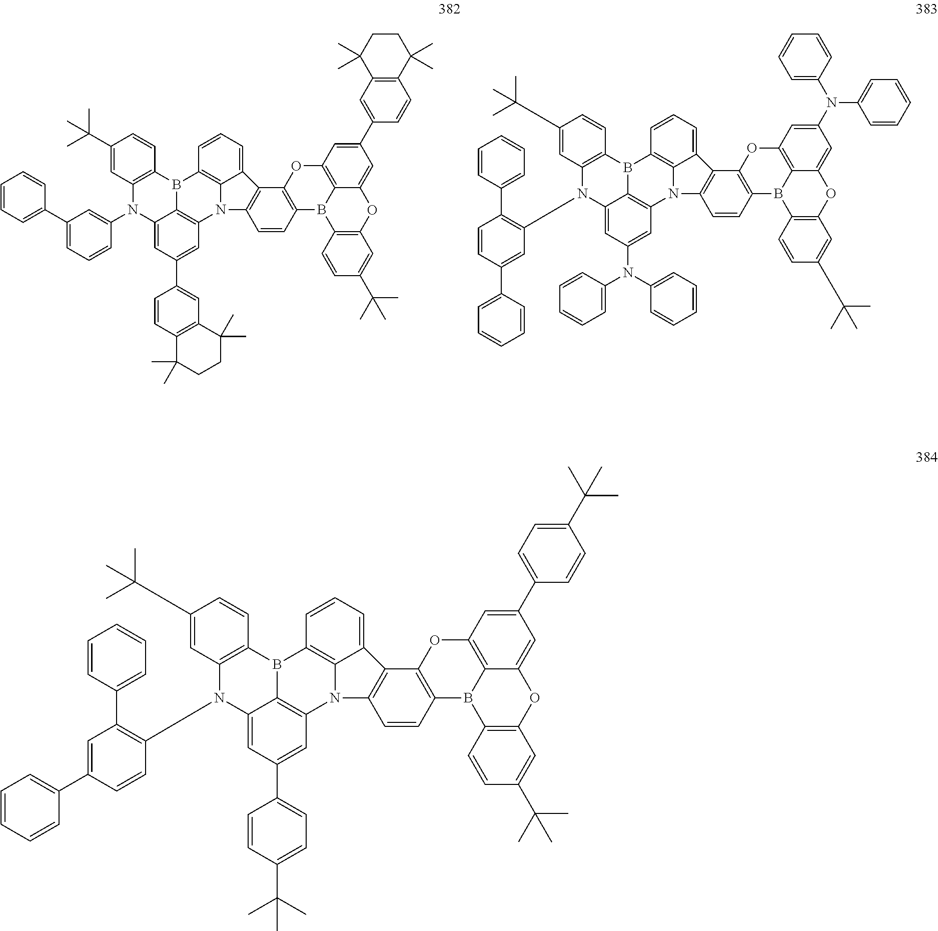 [SMILES: CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1N2c1cccc(-c2ccccc2)c1 ; CC(C)(C)c1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2N5c2ccc(-c5ccccc5)cc2-c2ccccc2)B4c2ccc(C(C)(C)C)cc2O3)cc1]

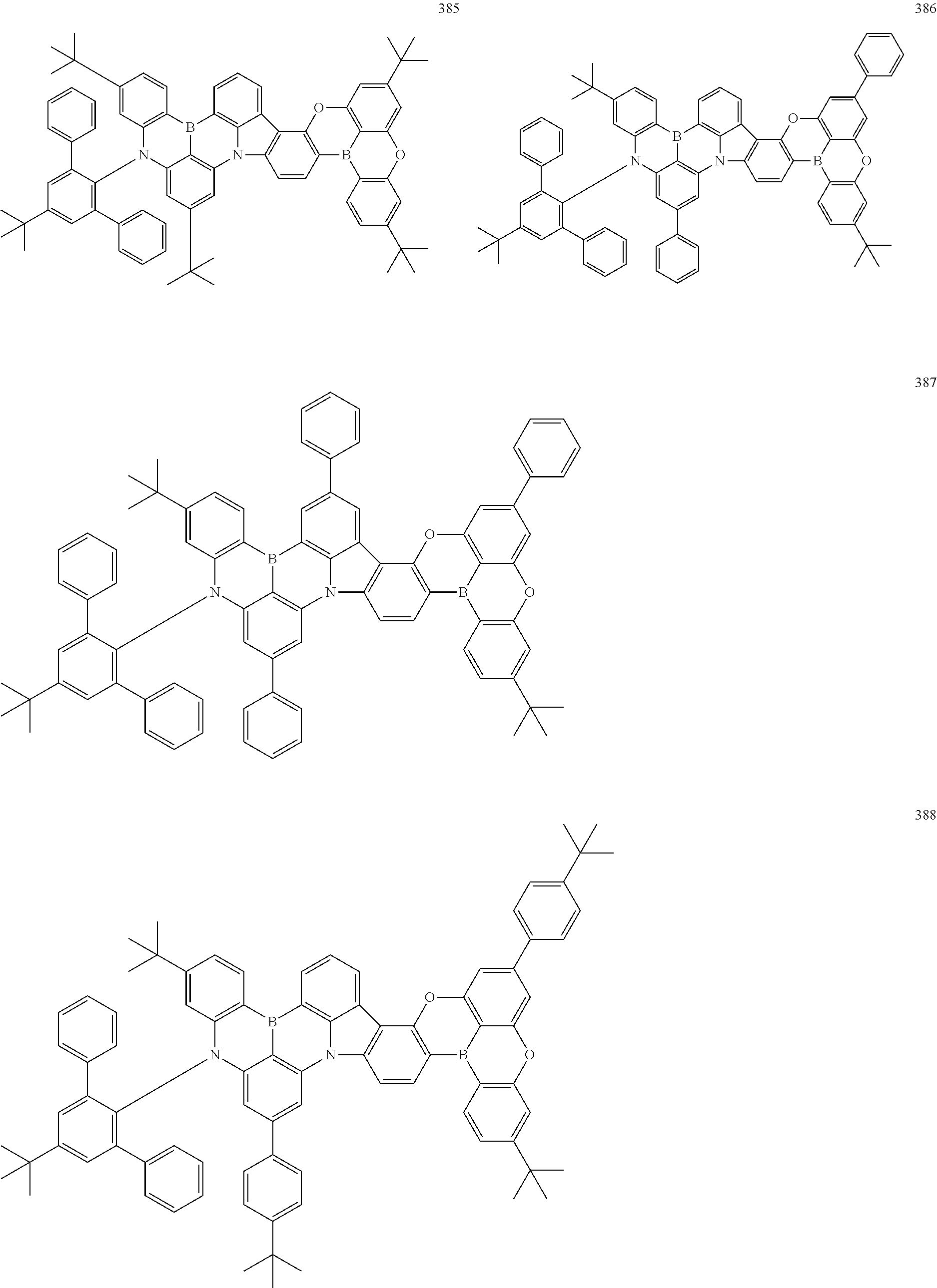

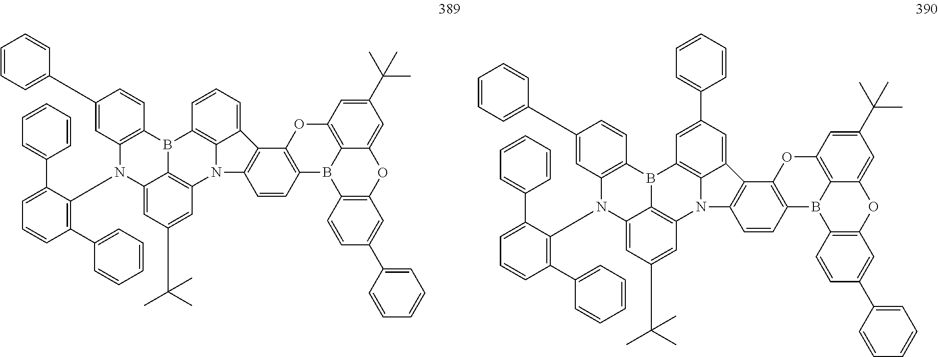 [SMILES: CC(C)(C)c1cc2c3c(c1)Oc1c(ccc4c1c1cccc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2]

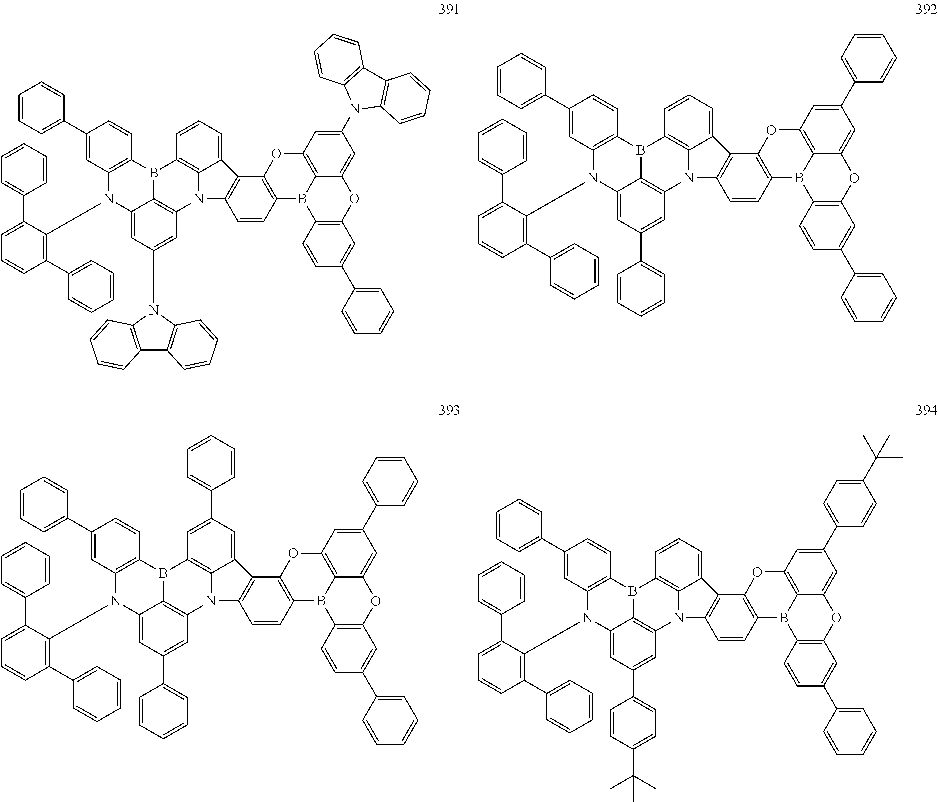

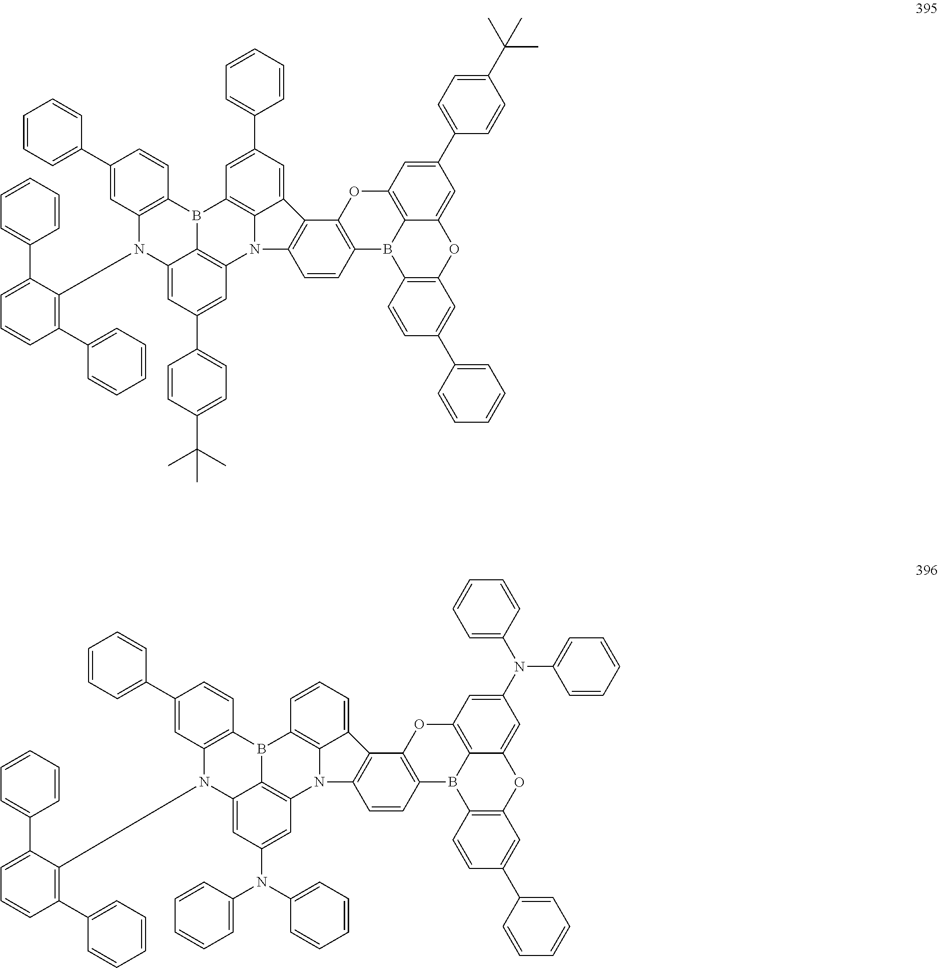 [SMILES: CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2O3)cc1 ; c1ccc(-c2ccc3c(c2)Oc2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1]

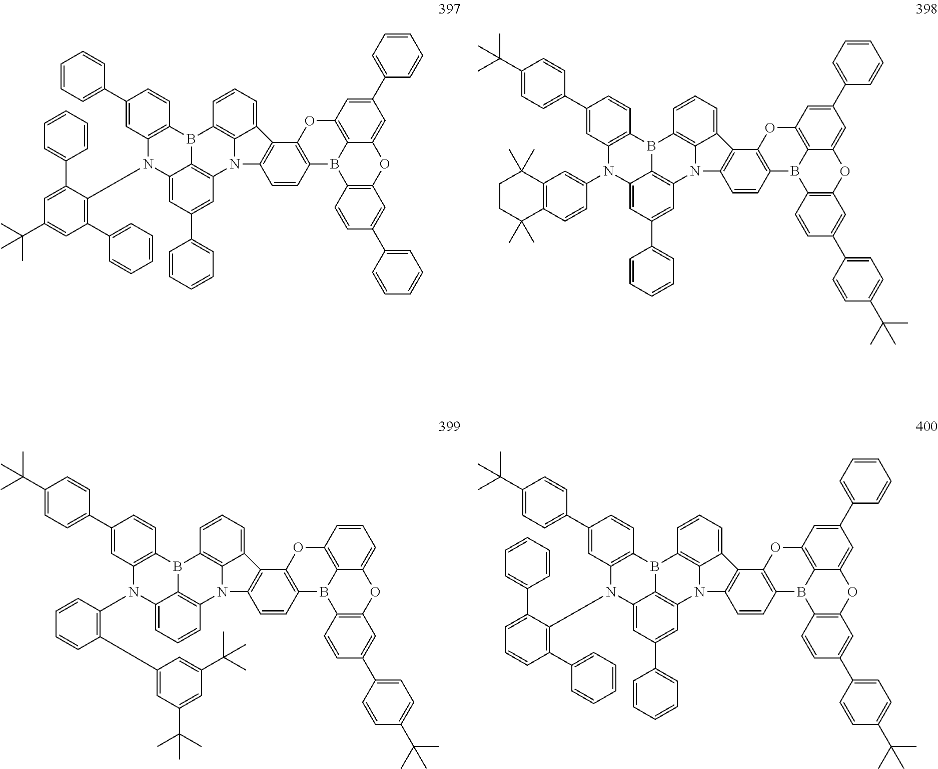

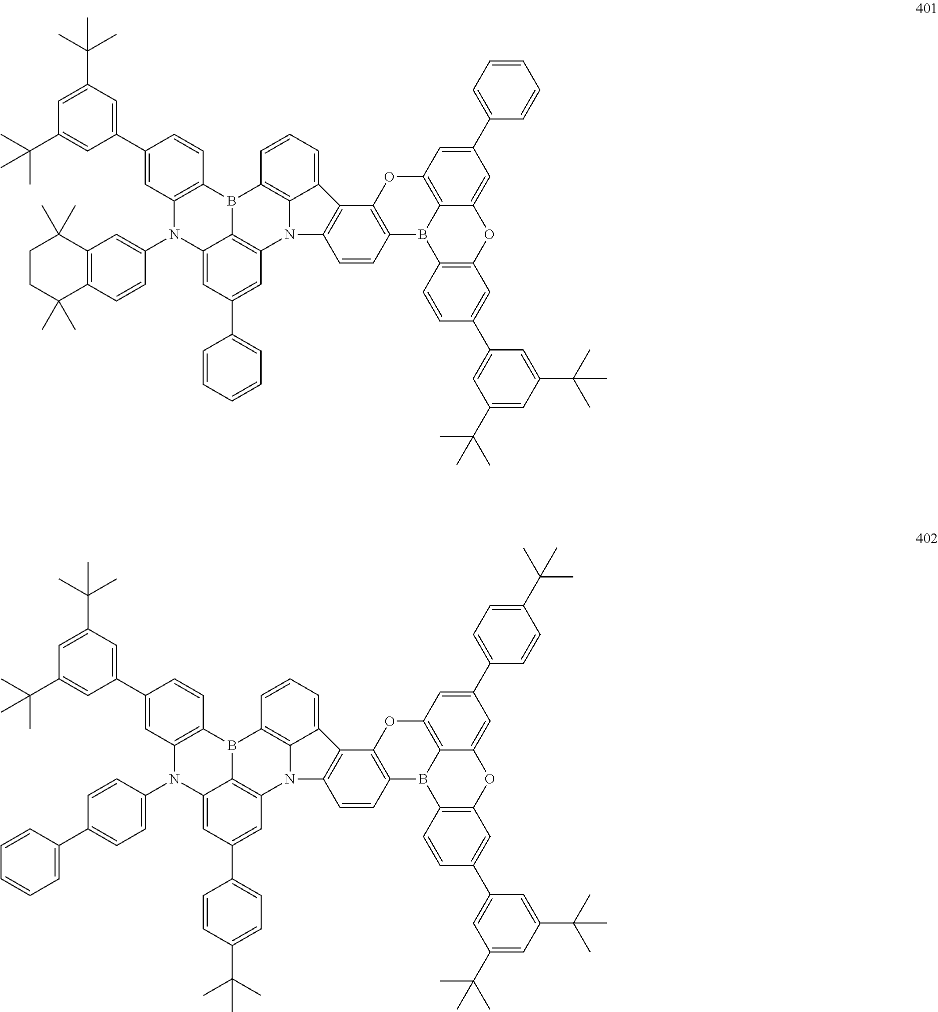

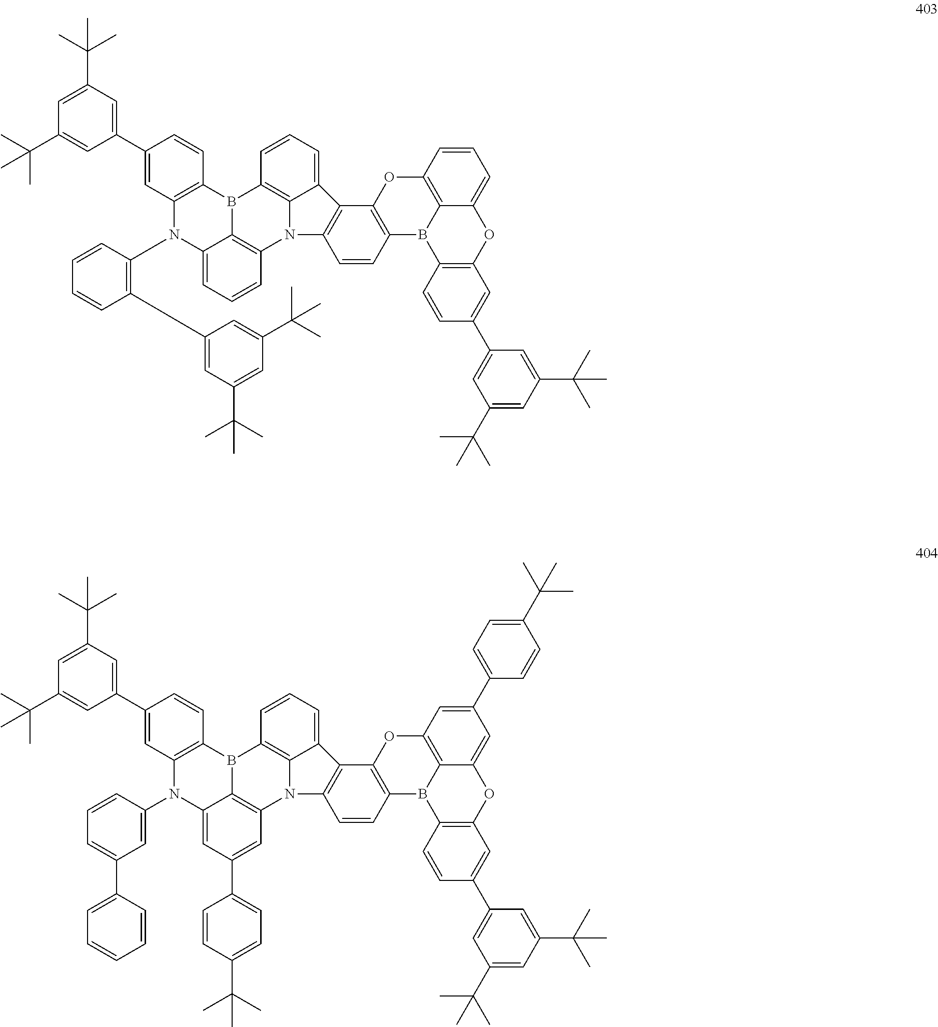

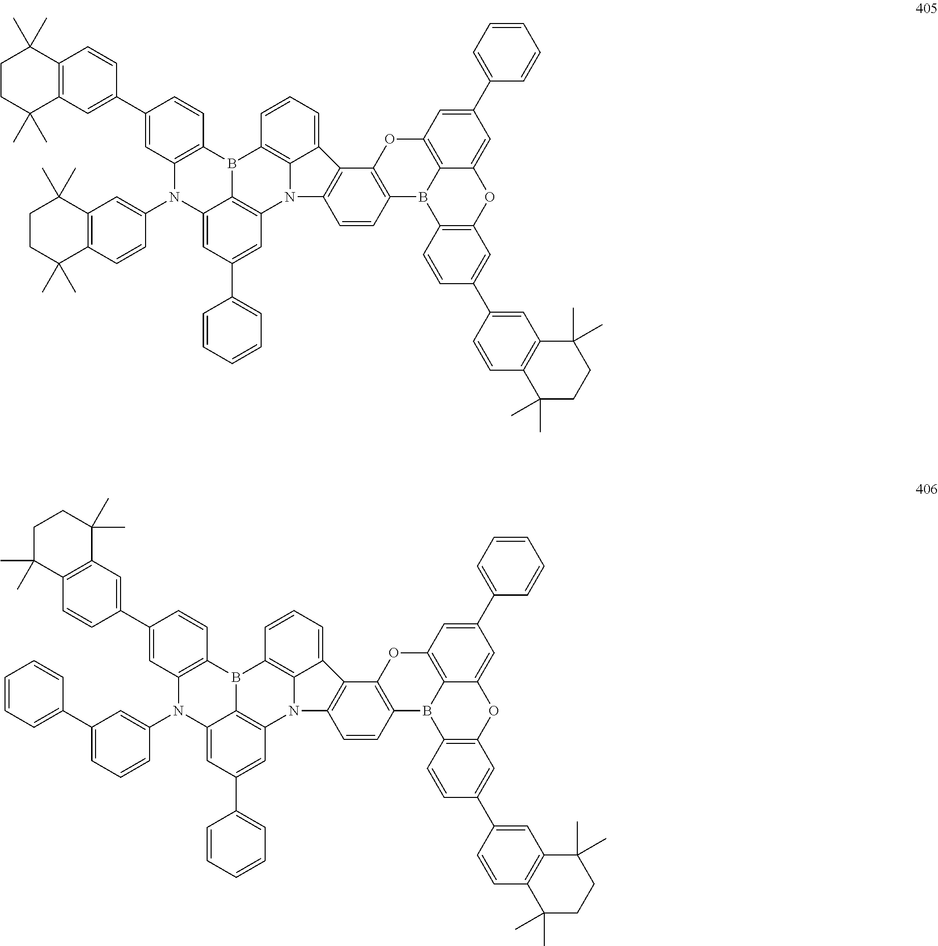

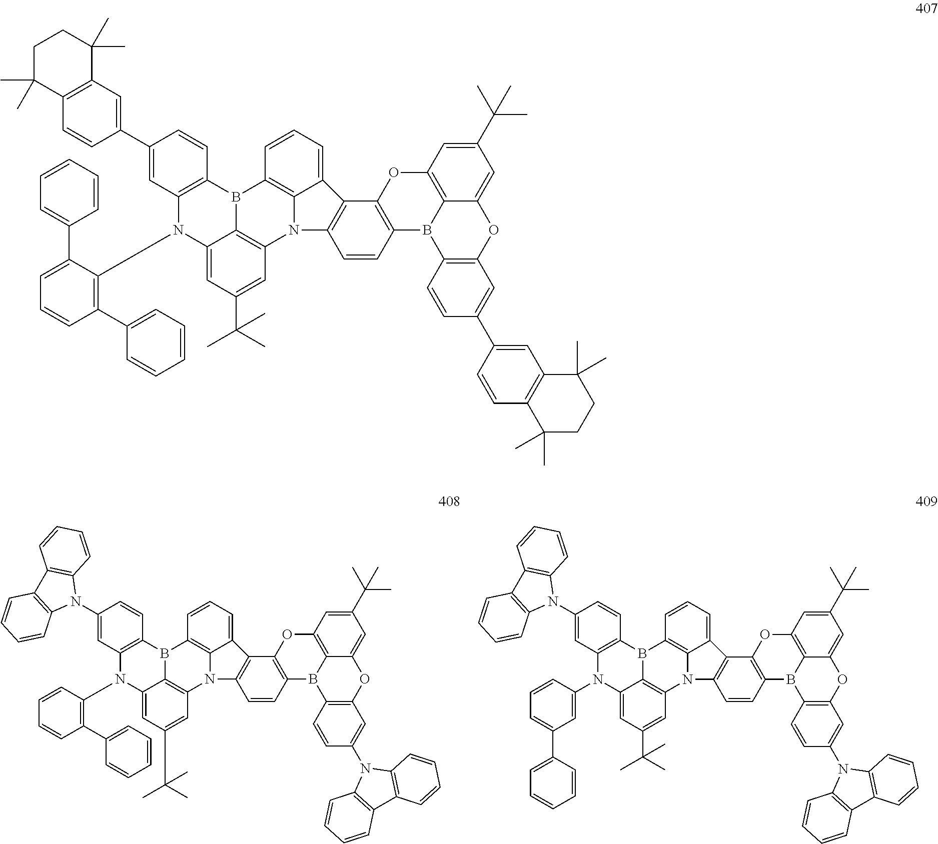

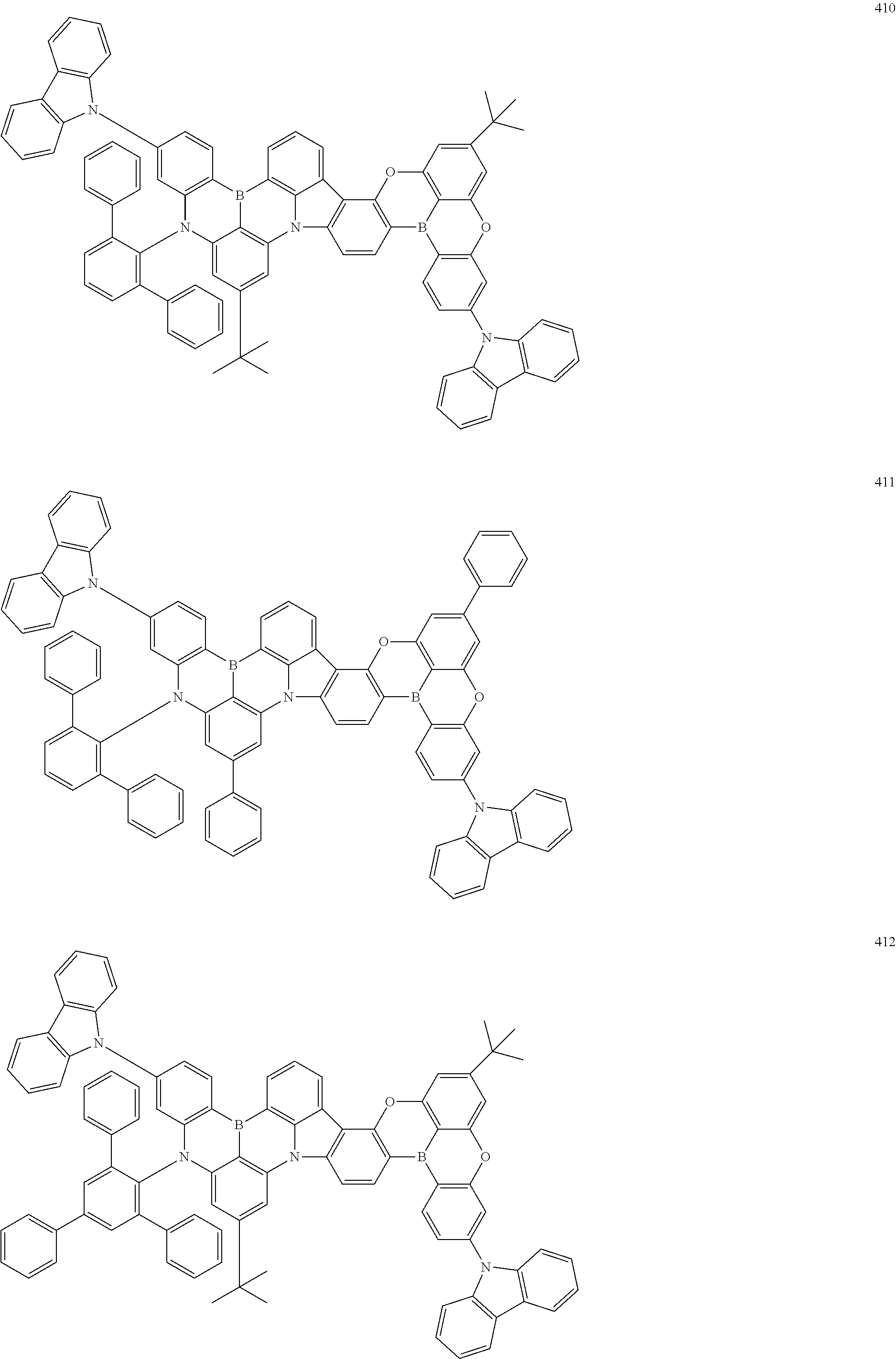 [SMILES: CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1O2 ; c1ccc(-c2cc3c4c(c2)Oc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2O3)cc1 ; CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1O2]

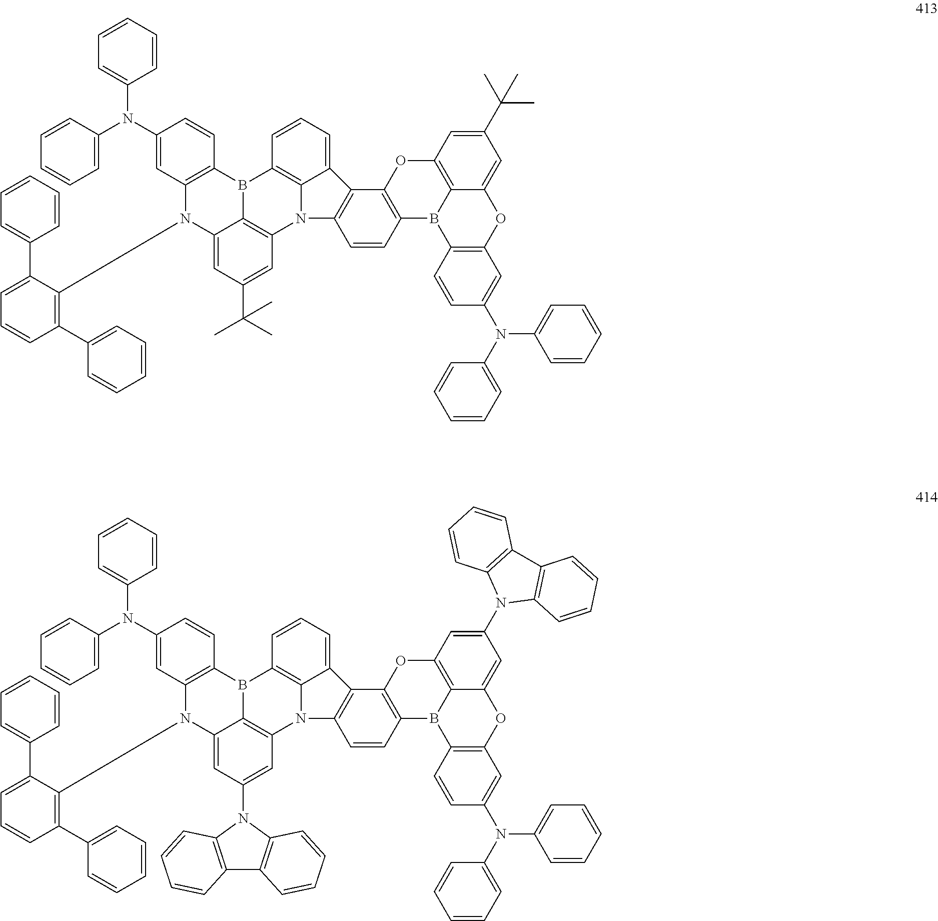 [SMILES: CC(C)(C)c1cc2c3c(c1)Oc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1O2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Oc2cc(-n3c4ccccc4c4ccccc43)cc3c2B5c2ccc(N(c4ccccc4)c4ccccc4)cc2O3)cc1]

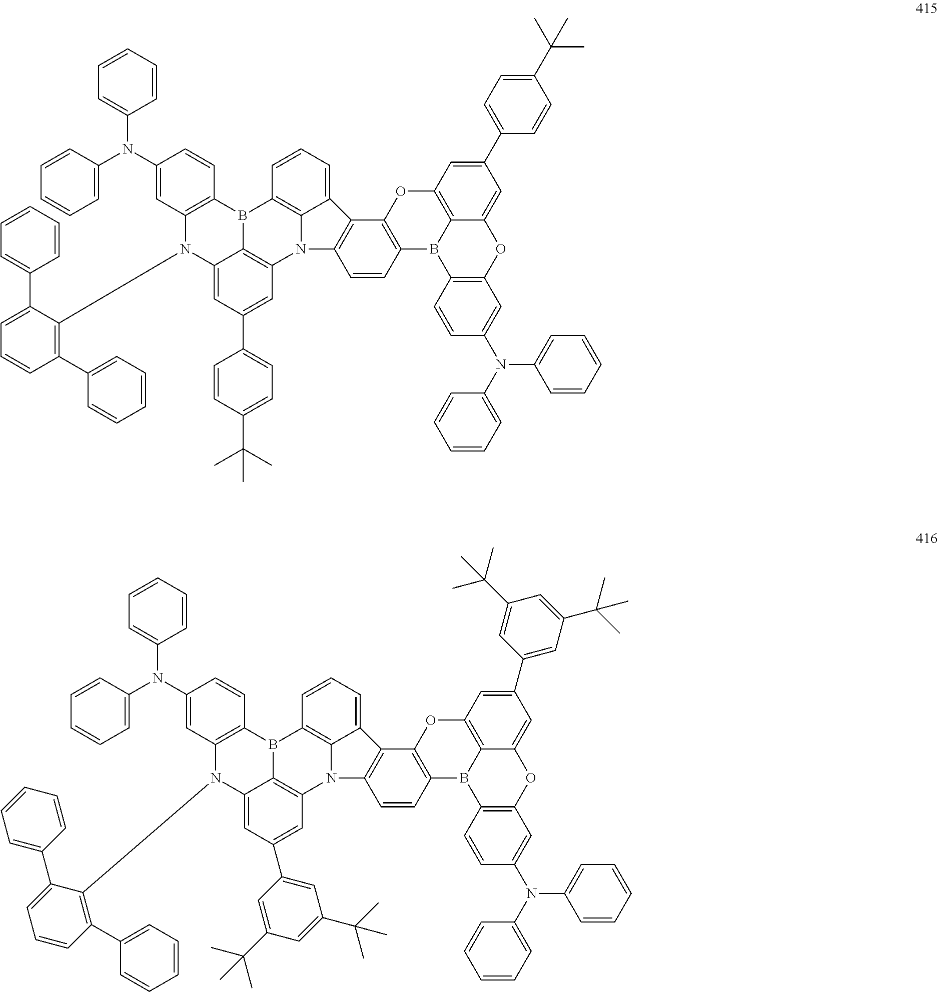 [SMILES: CC(C)(C)c1ccc(-c2cc3c4c(c2)Oc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc1 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc(C(C)(C)C)c1]

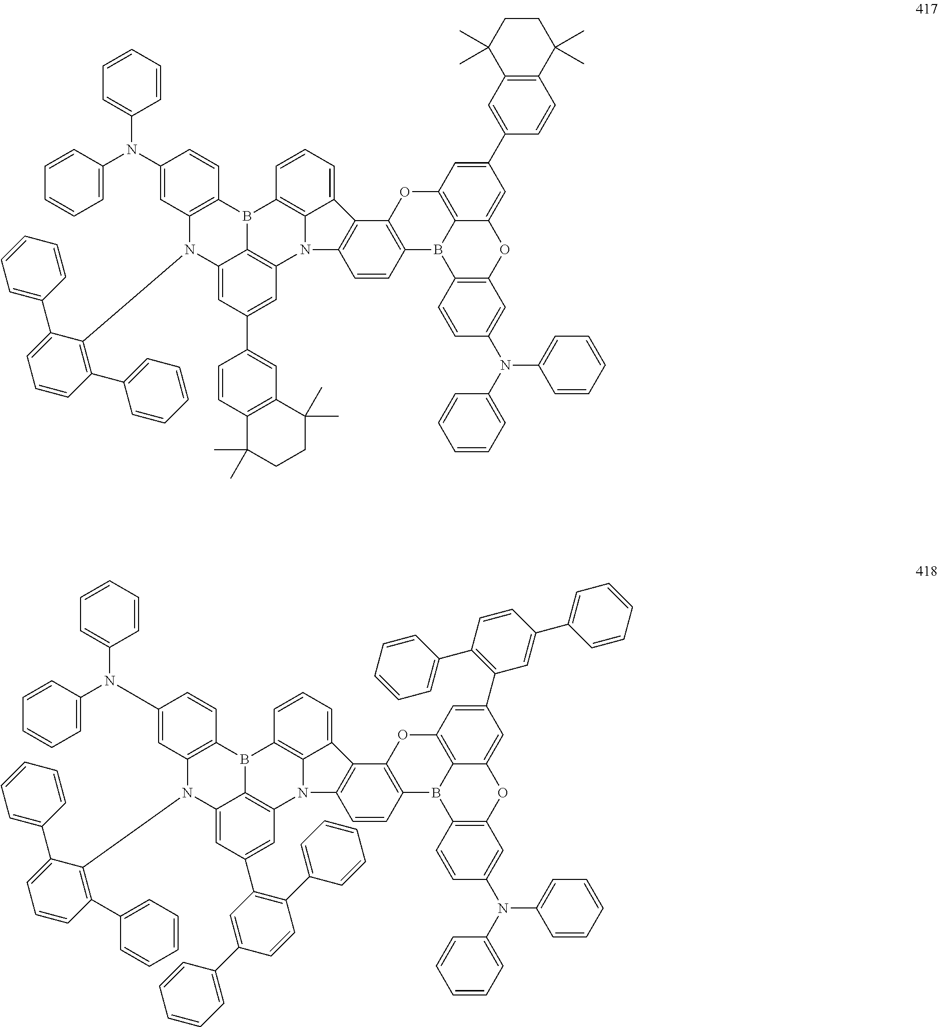 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)ccc21 ; c1ccc(-c2ccc(-c3ccccc3)c(-c3cc4c5c(c3)Oc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)c2)cc1]

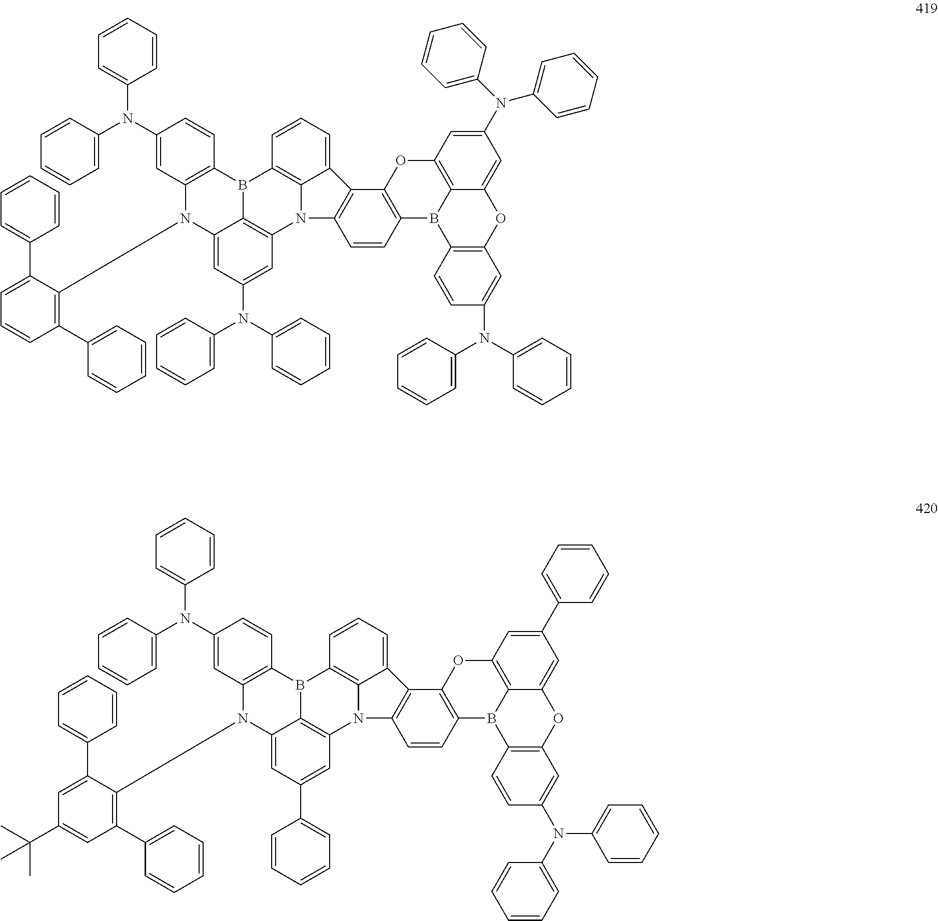 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Oc2cc(N(c3ccccc3)c3ccccc3)cc3c2B5c2ccc(N(c4ccccc4)c4ccccc4)cc2O3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Oc2cc(-c3ccccc3)cc3c2B5c2ccc(N(c4ccccc4)c4ccccc4)cc2O3)c(-c2ccccc2)c1]

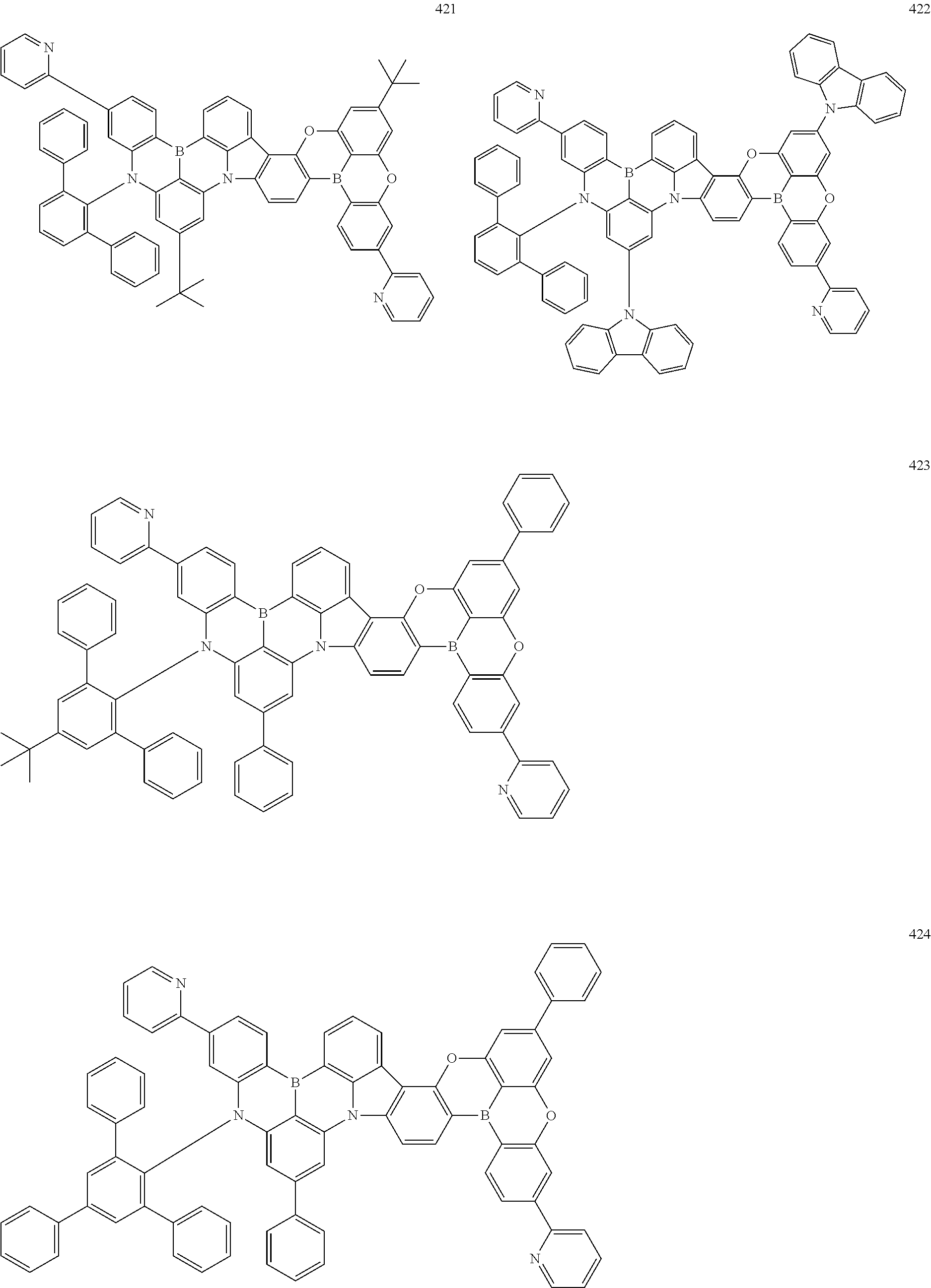

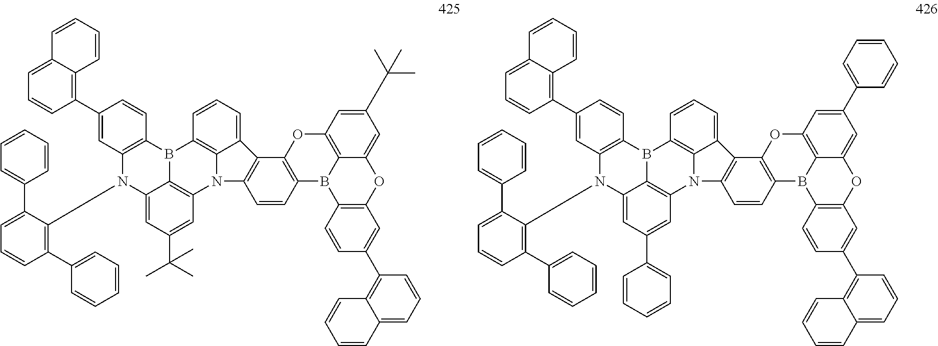 [SMILES: CC(C)(C)c1cc2c3c(c1)Oc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2O3)cc1]

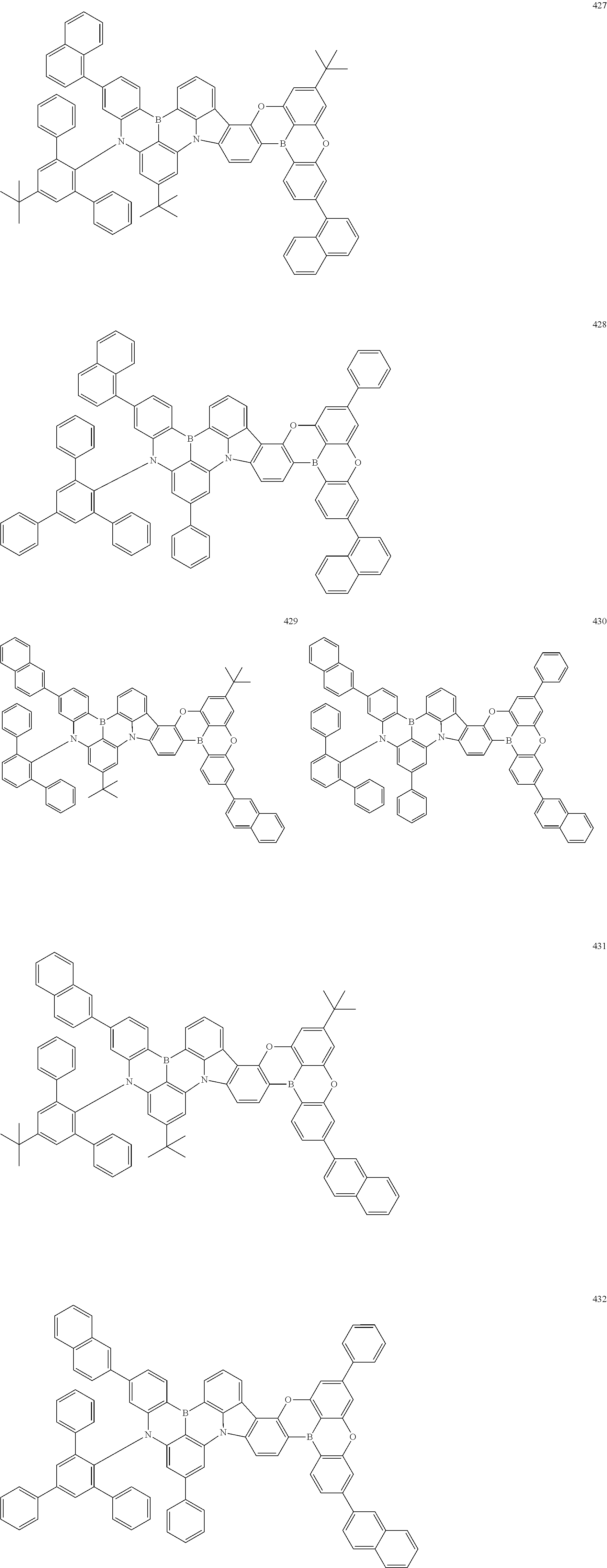

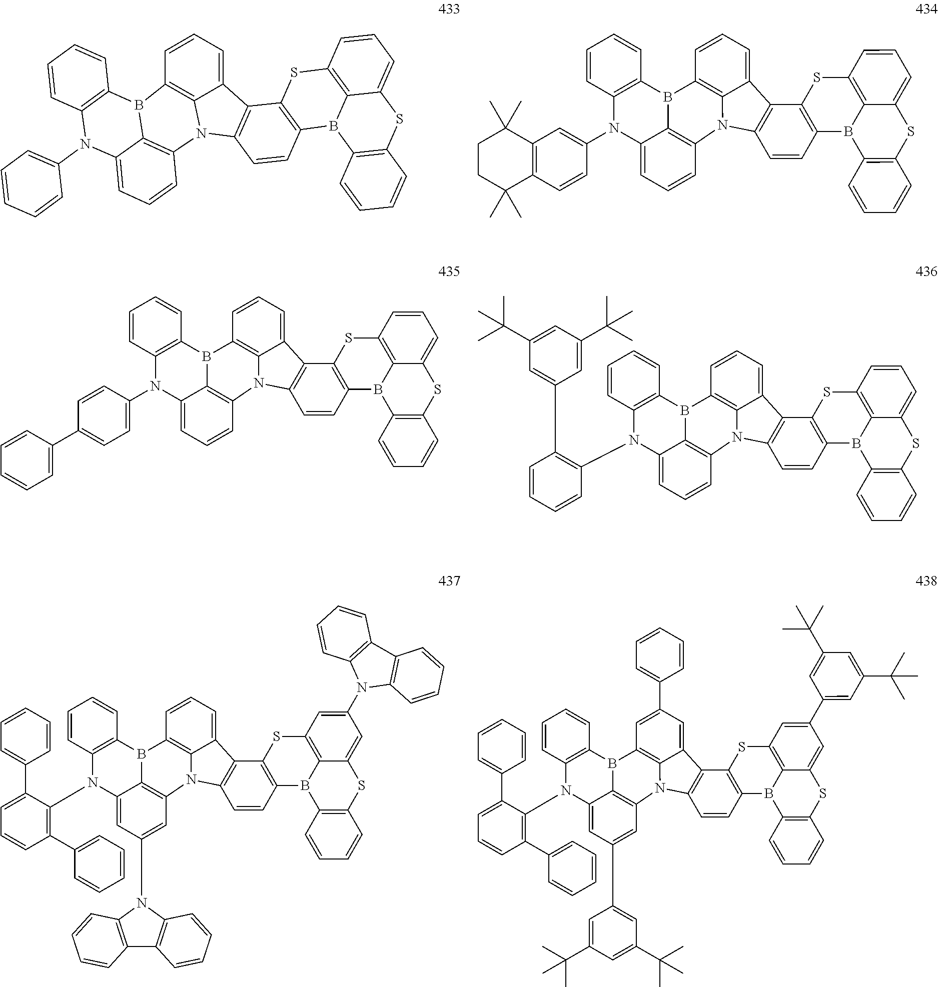

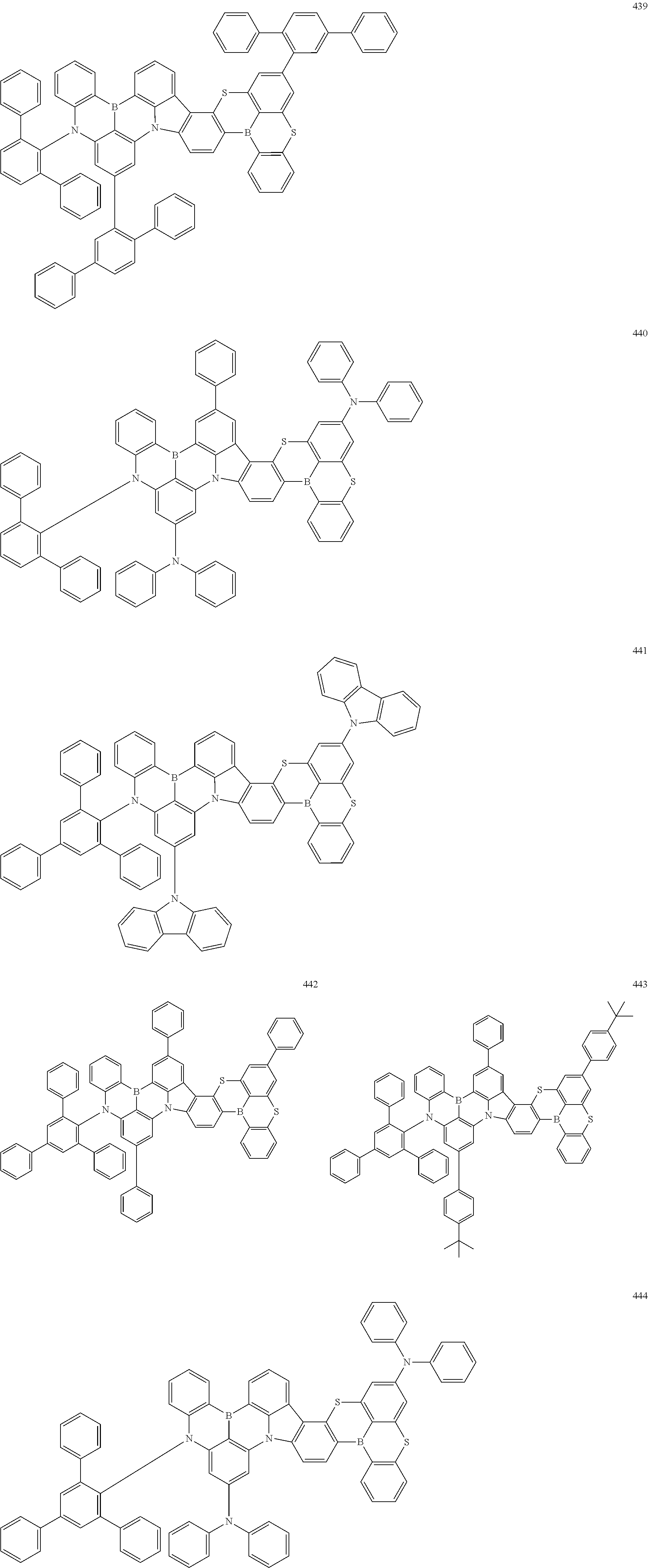

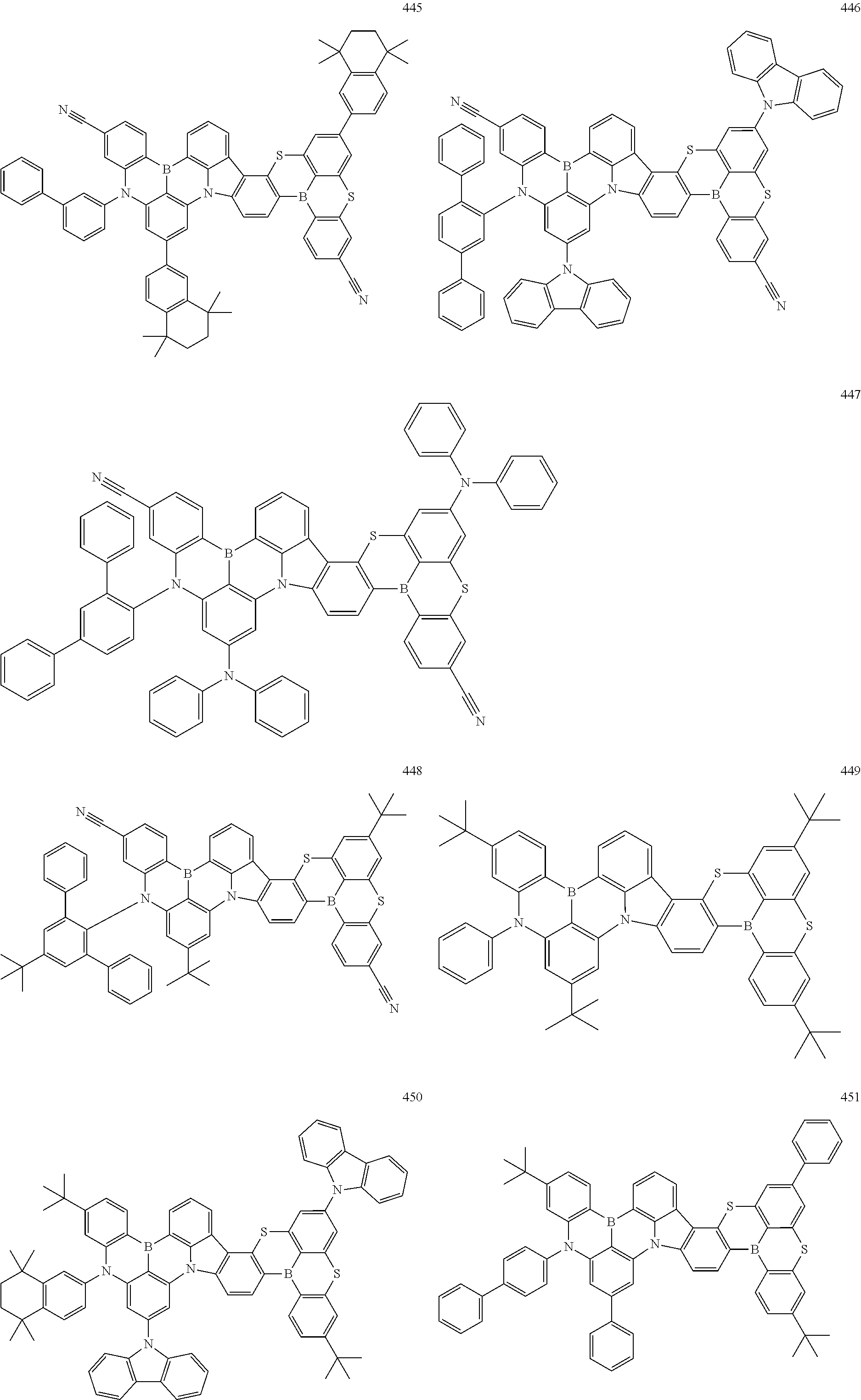

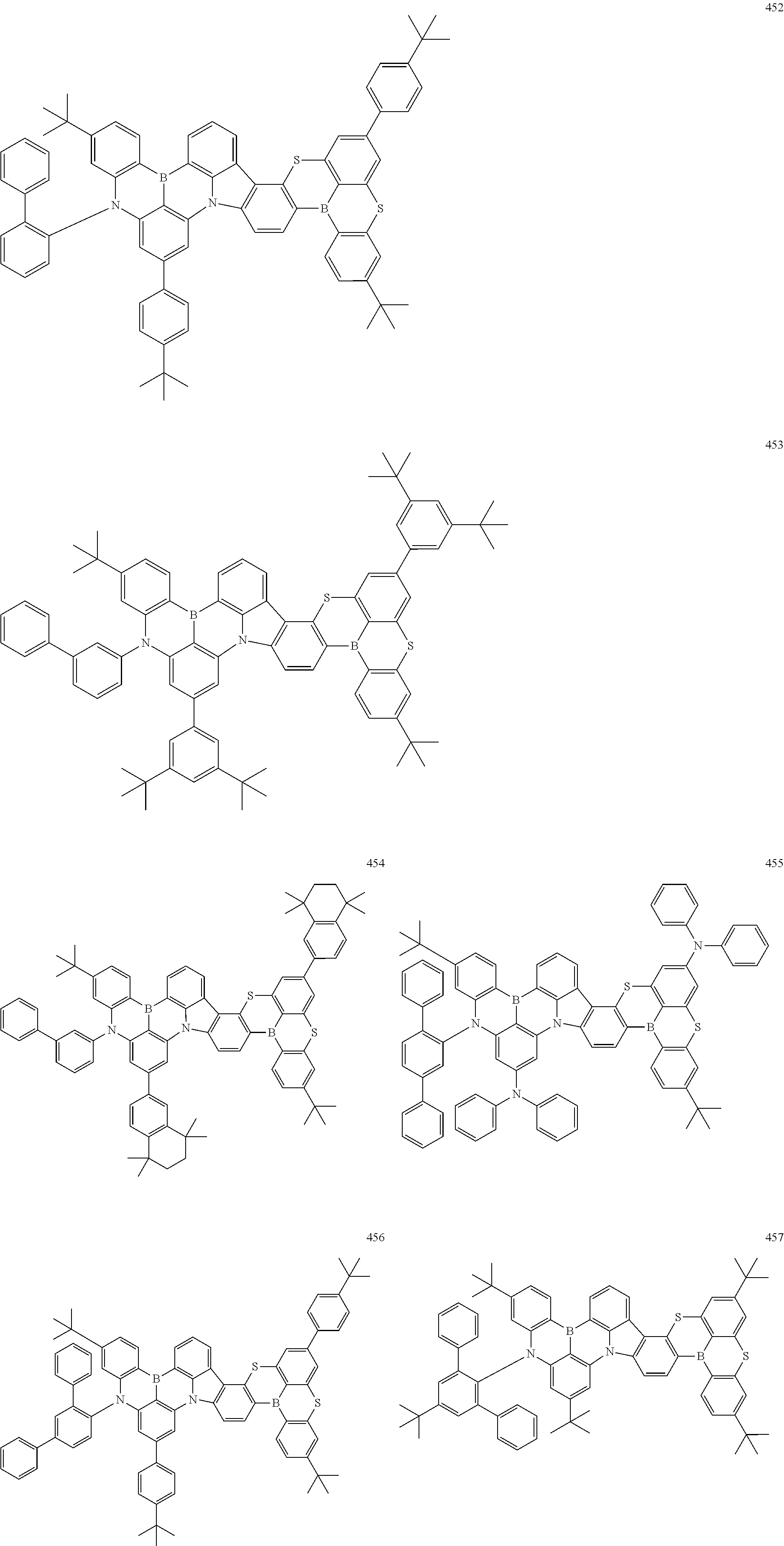

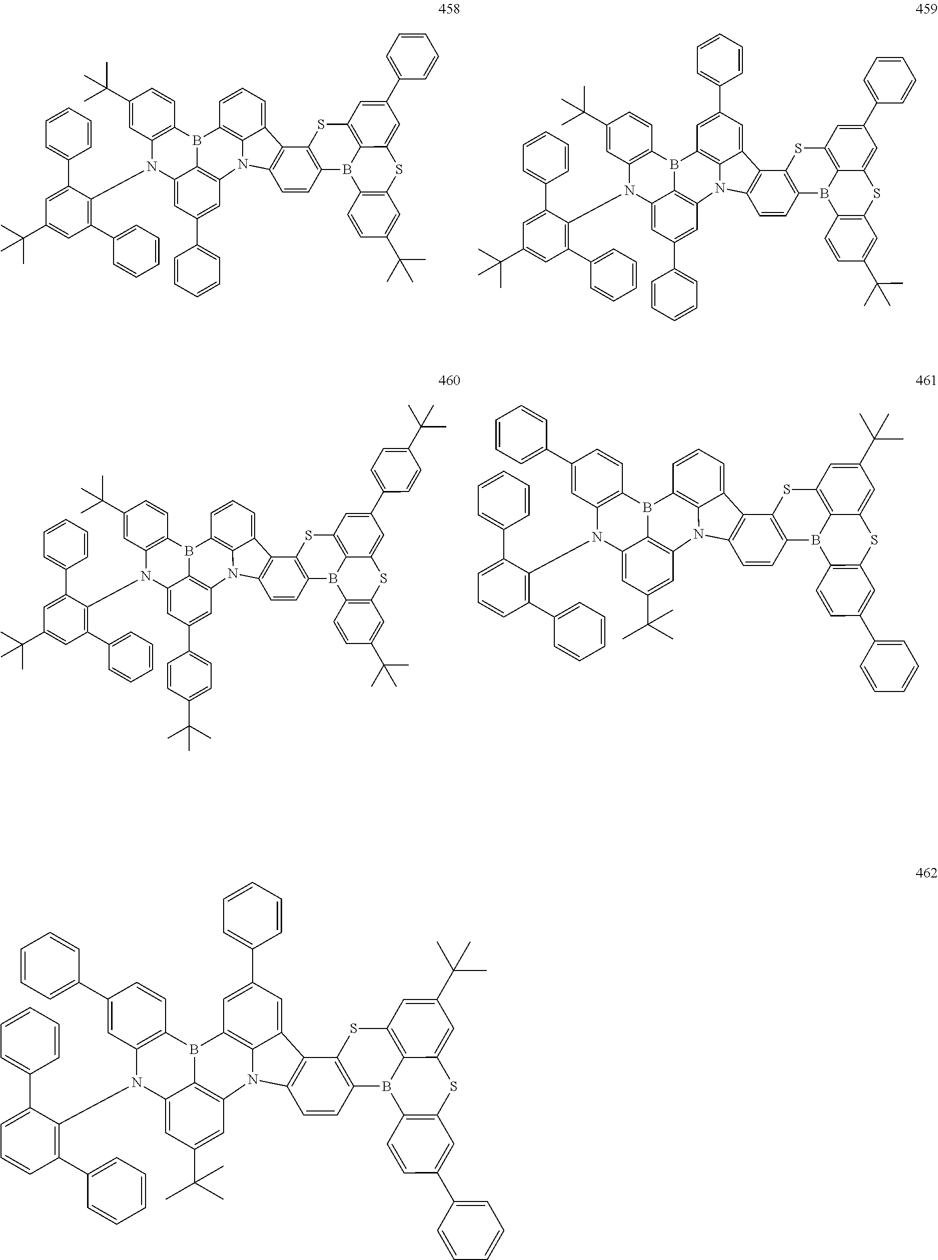

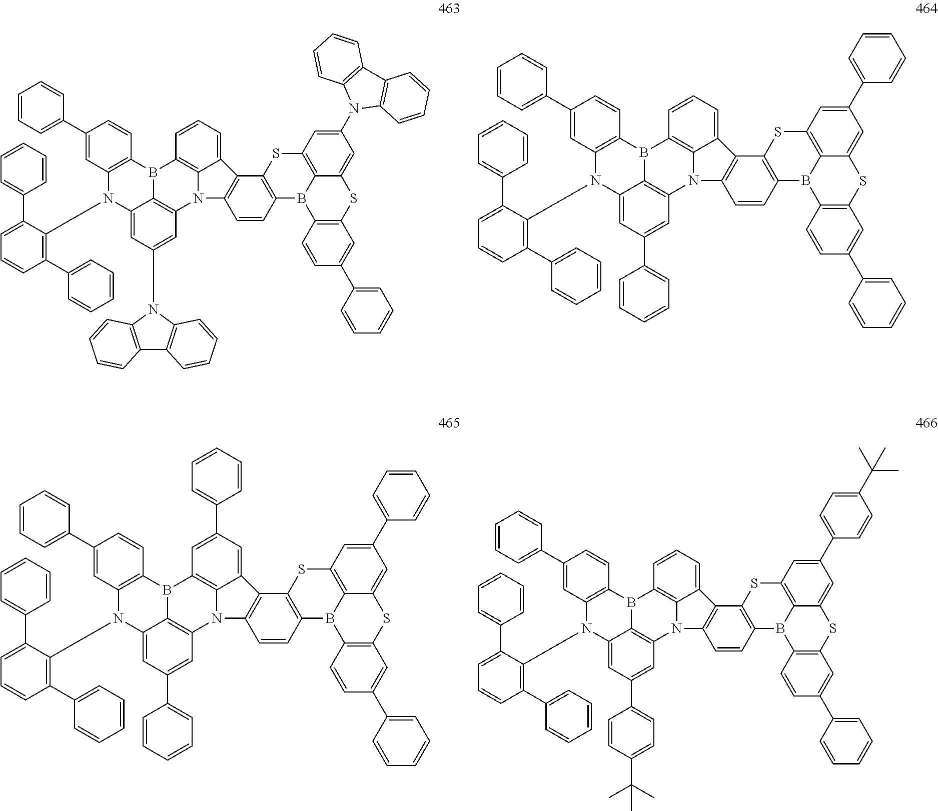

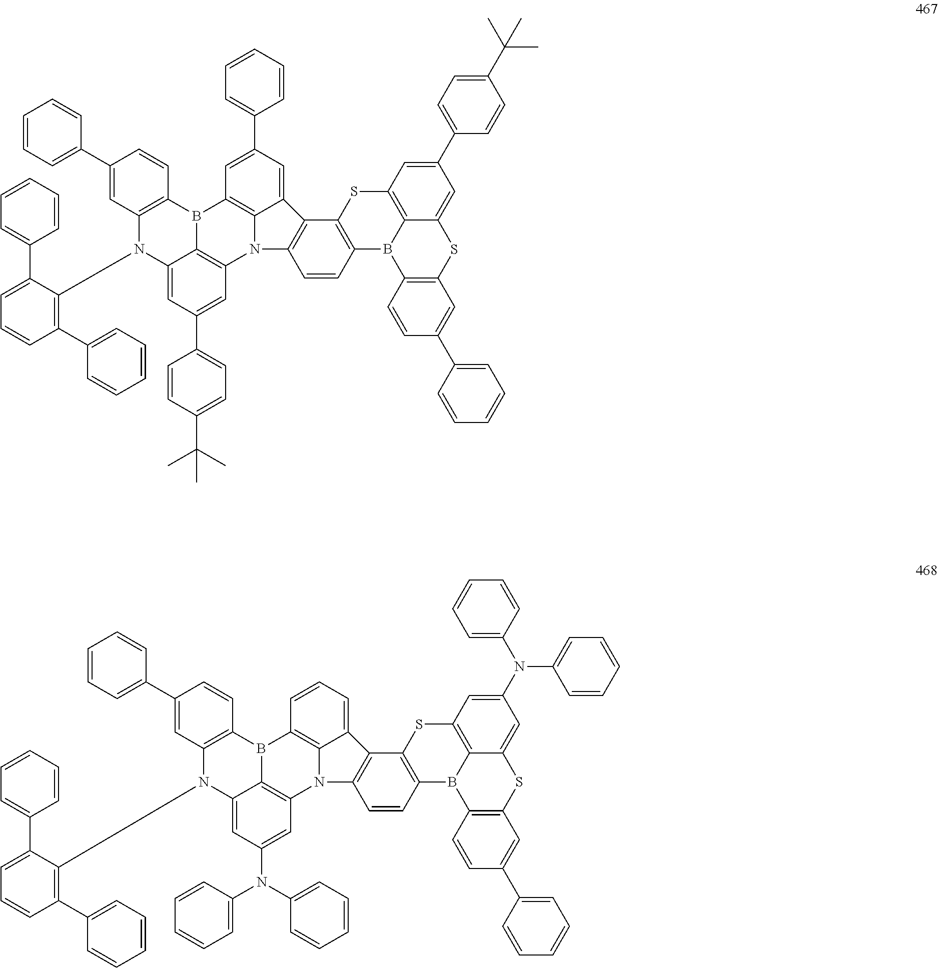 [SMILES: CC(C)(C)c1ccc(-c2cc3c4c(c2)Sc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2S3)cc1 ; c1ccc(-c2ccc3c(c2)Sc2cc(N(c4ccccc4)c4ccccc4)cc4c2B3c2ccc3c(c2S4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1]

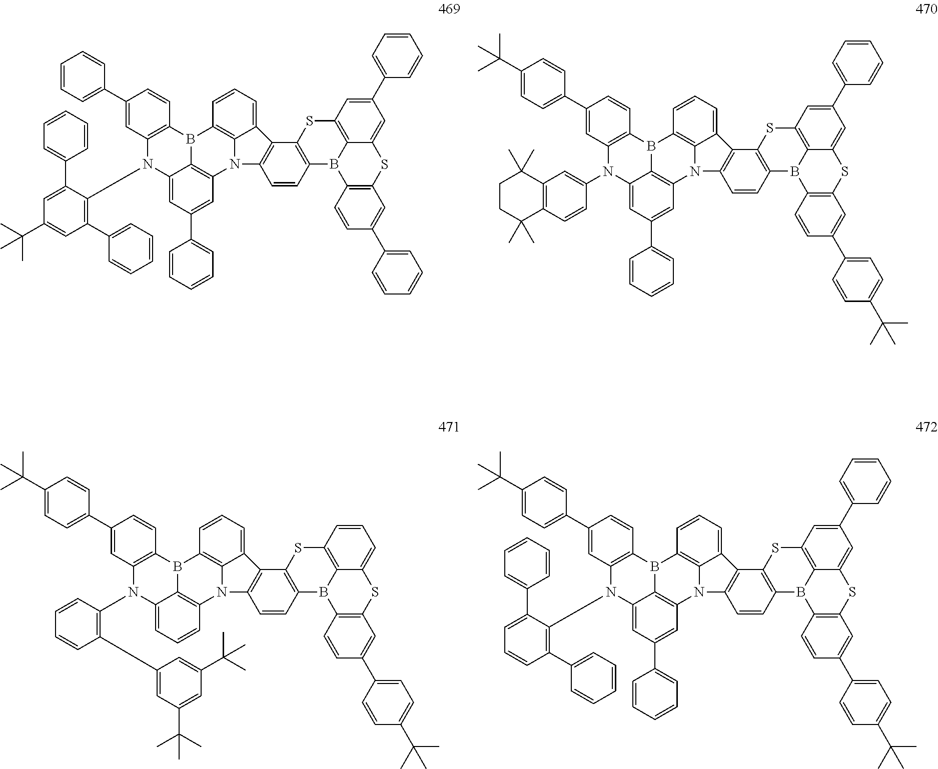

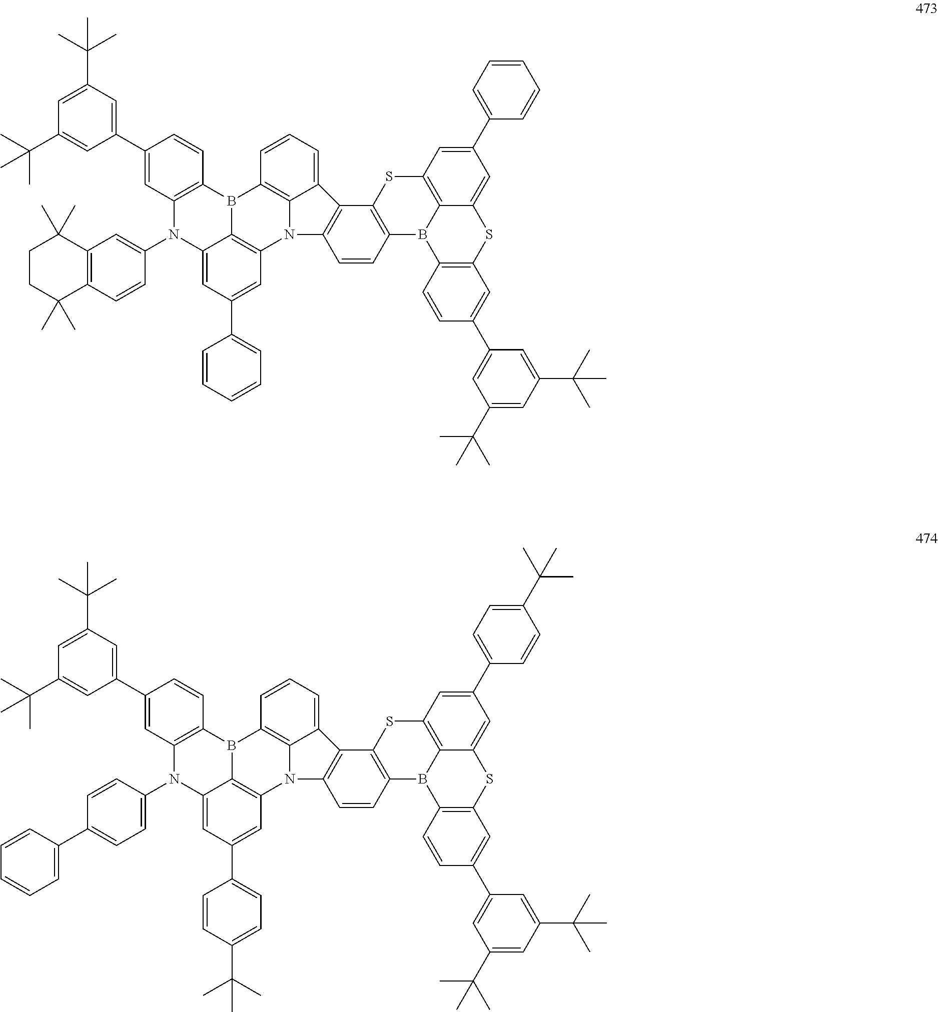

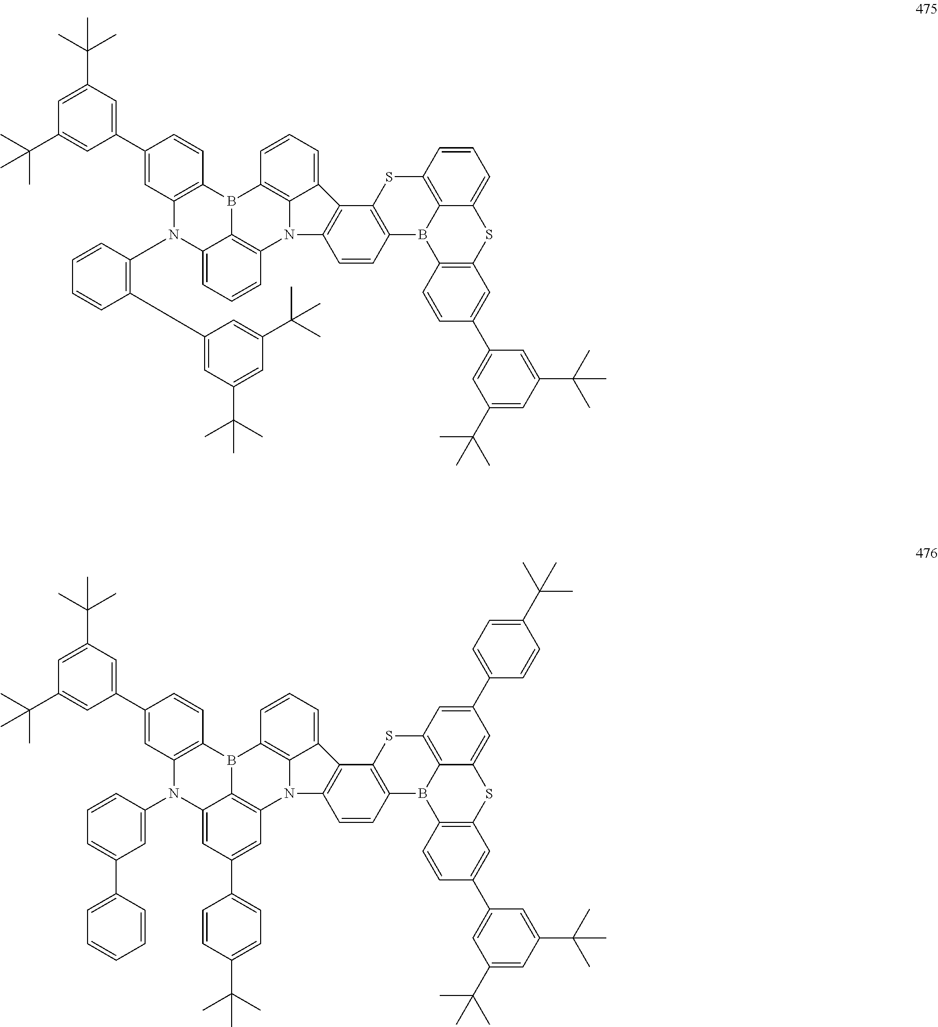

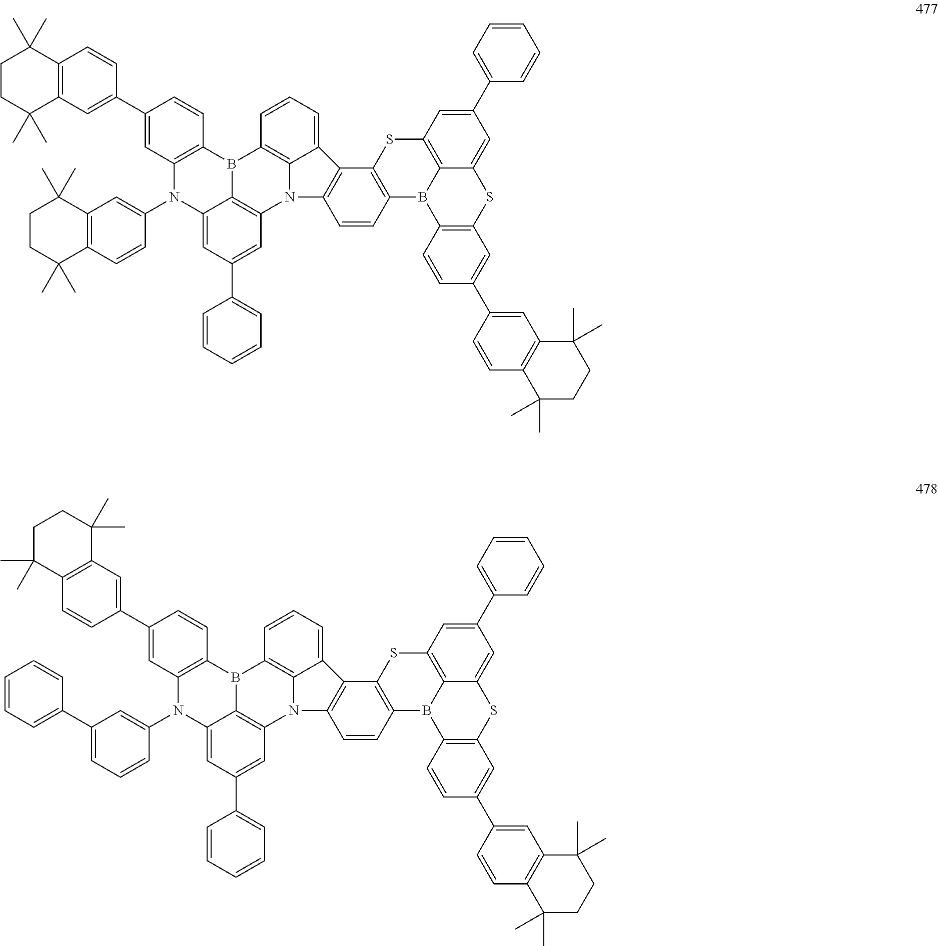

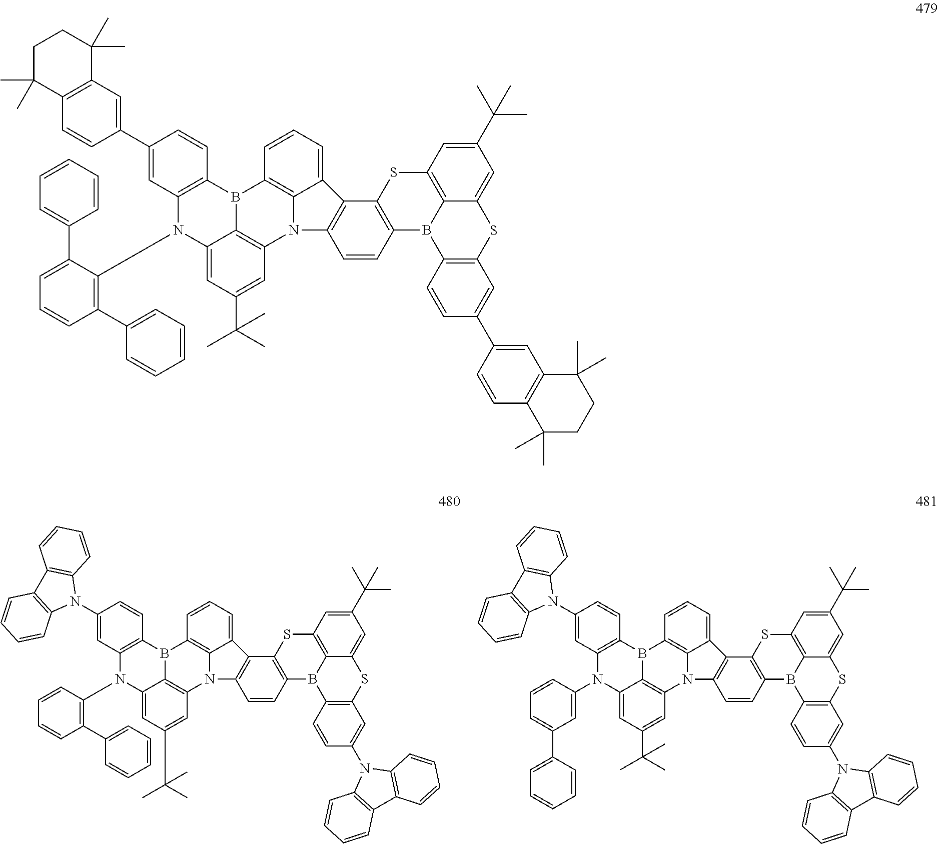

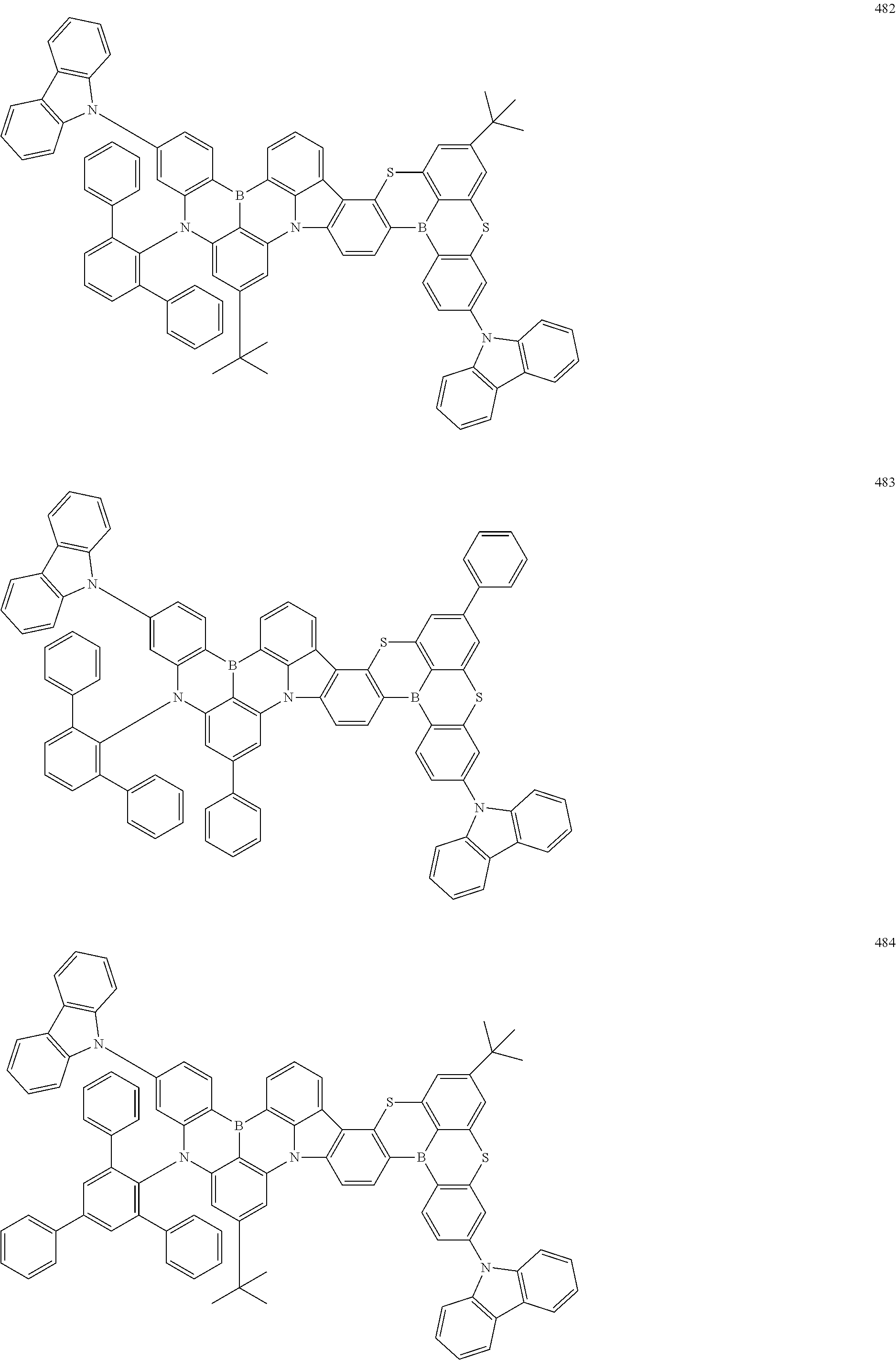 [SMILES: CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1S2 ; c1ccc(-c2cc3c4c(c2)Sc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2S3)cc1 ; CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1S2]

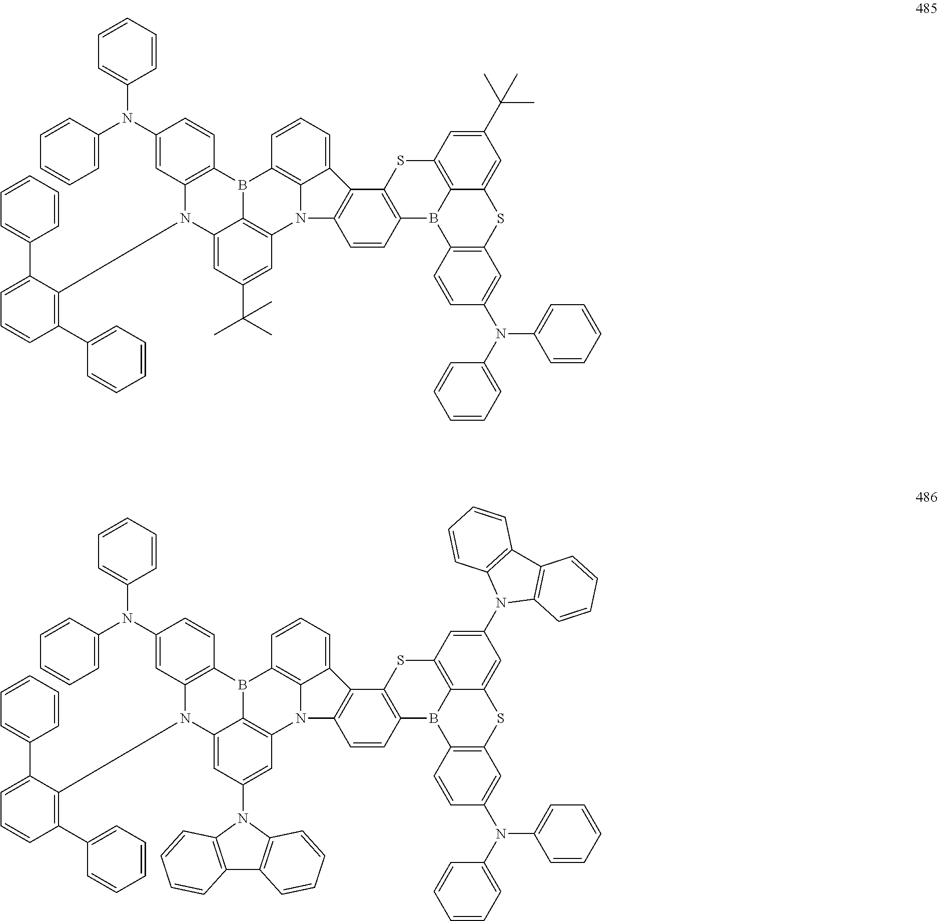 [SMILES: CC(C)(C)c1cc2c3c(c1)Sc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1S2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Sc2cc(-n3c4ccccc4c4ccccc43)cc3c2B5c2ccc(N(c4ccccc4)c4ccccc4)cc2S3)cc1]

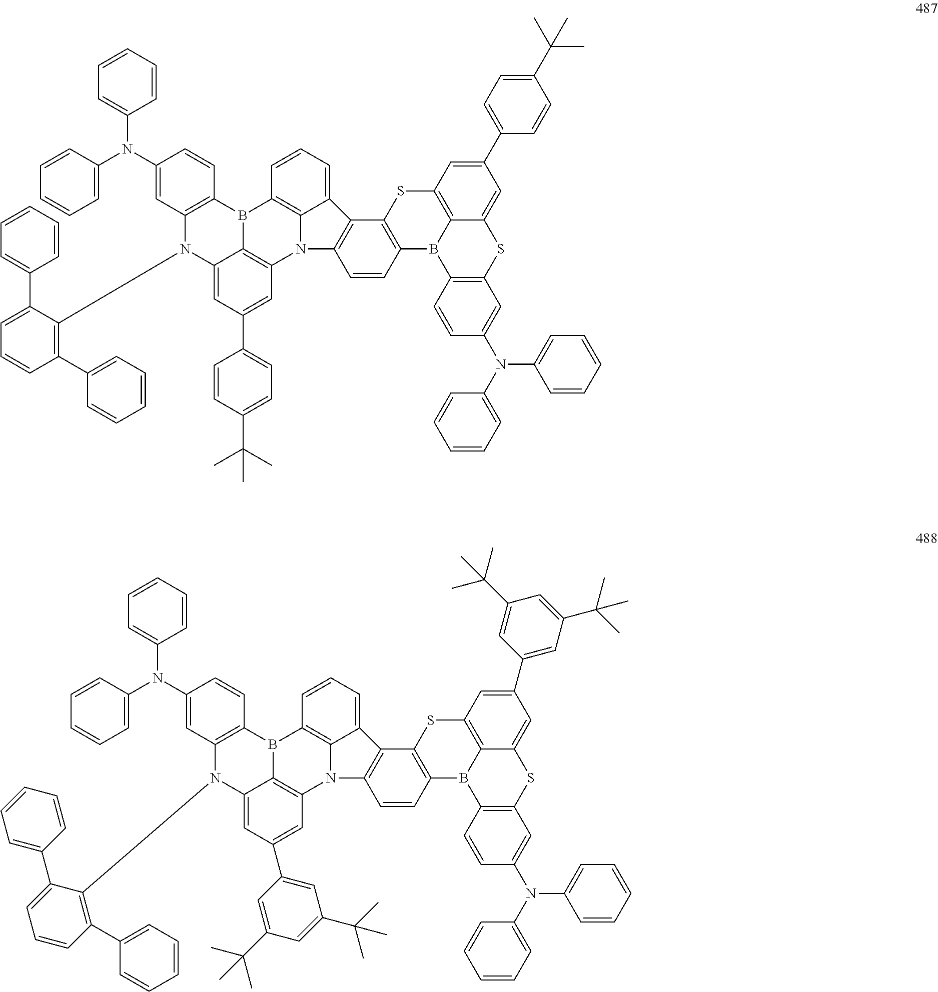 [SMILES: CC(C)(C)c1ccc(-c2cc3c4c(c2)Sc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc1 ; CC(C)(C)c1cc(-c2cc3c4c(c2)Sc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc(C(C)(C)C)c1]

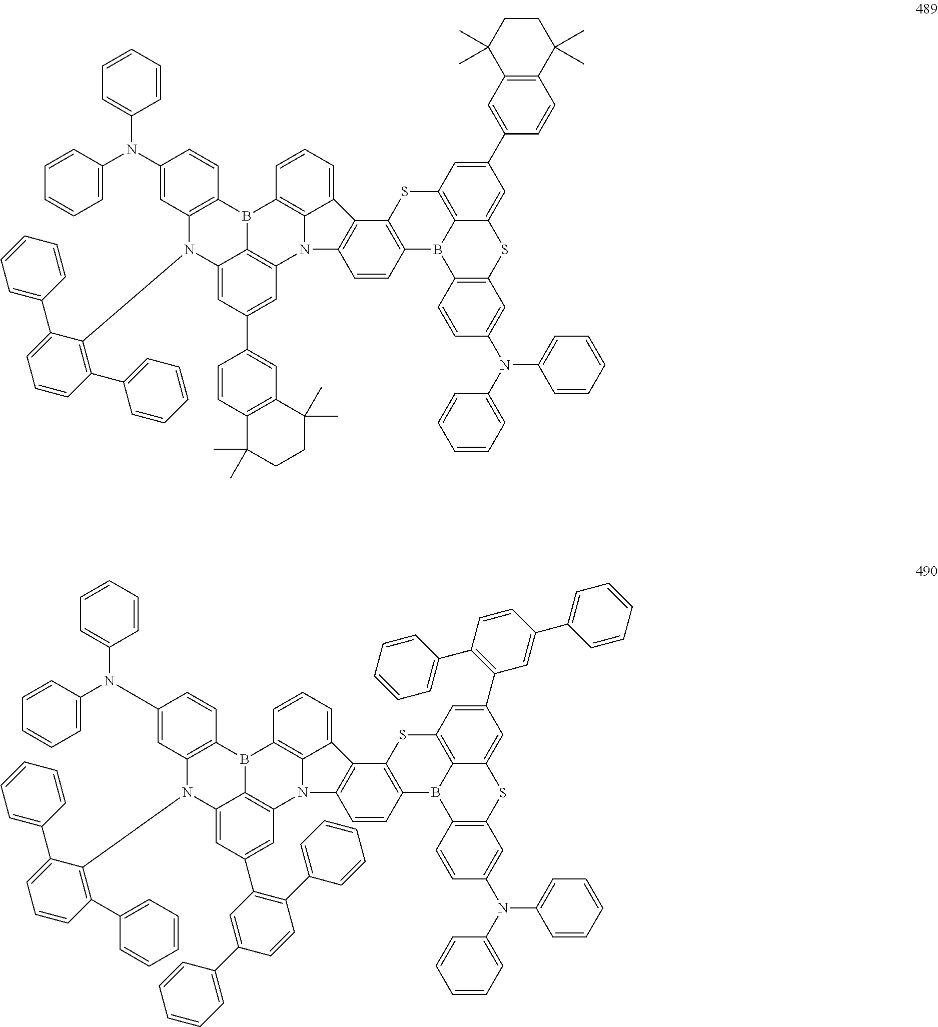 [SMILES: CC1(C)CCC(C)(C)c2cc(-c3cc4c5c(c3)Sc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)ccc21 ; c1ccc(-c2ccc(-c3ccccc3)c(-c3cc4c5c(c3)Sc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)c2)cc1]

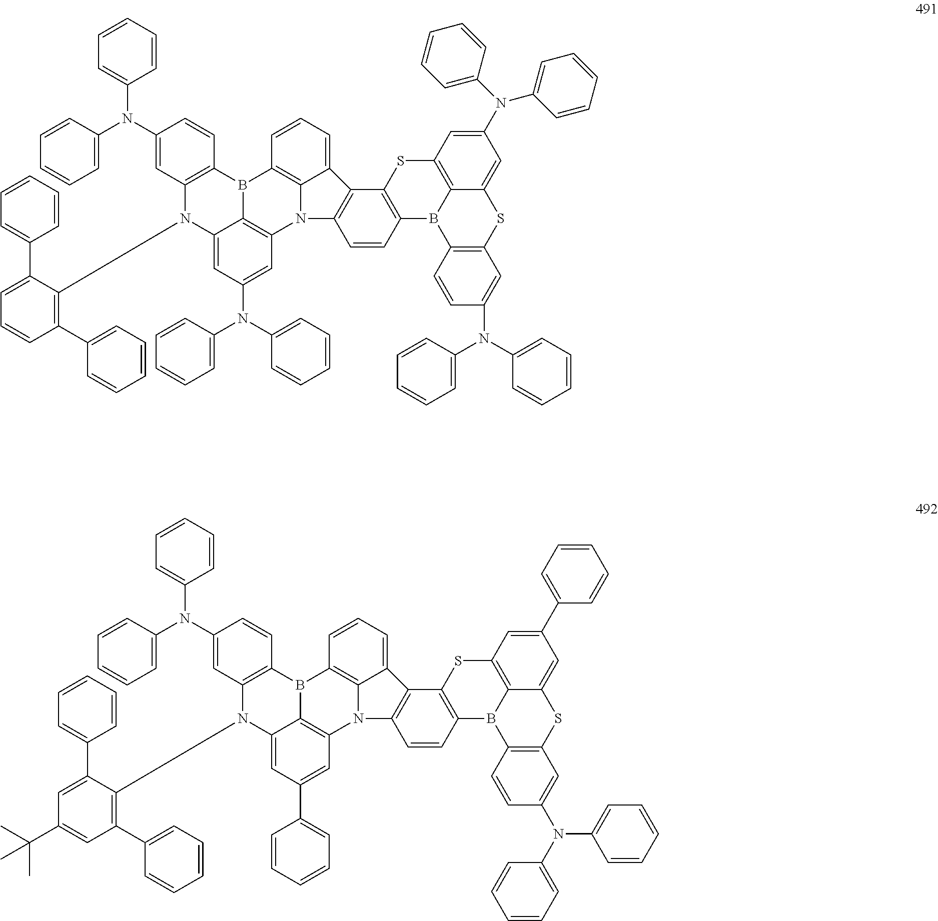 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Sc2cc(N(c3ccccc3)c3ccccc3)cc3c2B5c2ccc(N(c4ccccc4)c4ccccc4)cc2S3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Sc2cc(-c3ccccc3)cc3c2B5c2ccc(N(c4ccccc4)c4ccccc4)cc2S3)c(-c2ccccc2)c1]

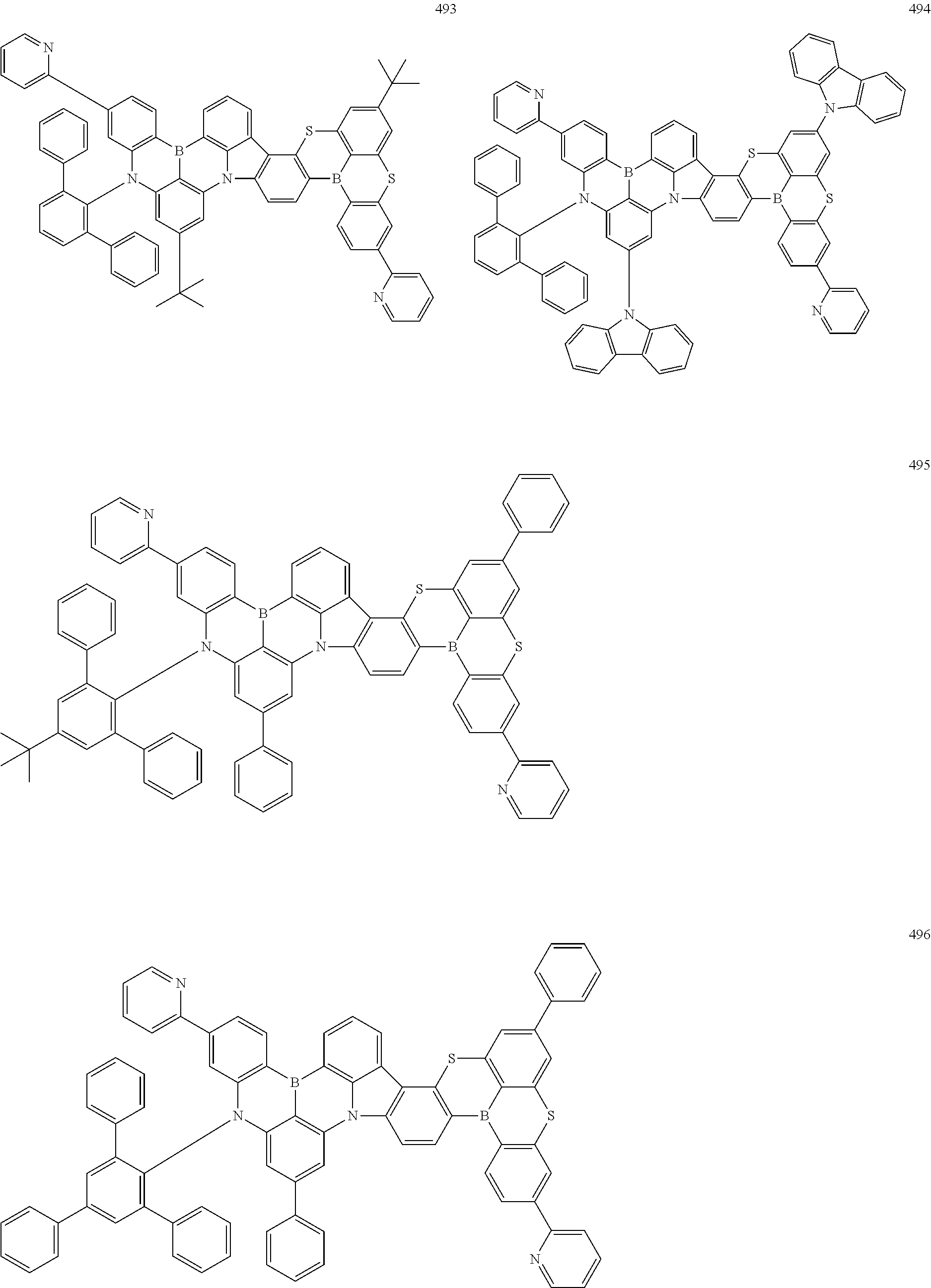

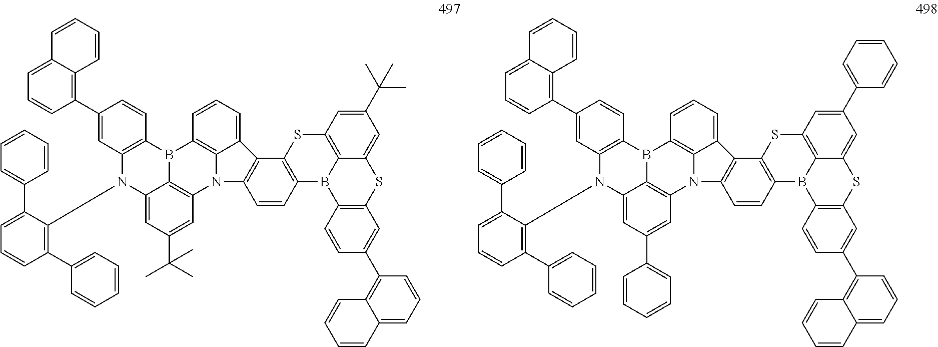 [SMILES: CC(C)(C)c1cc2c3c(c1)Sc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1S2 ; c1ccc(-c2cc3c4c(c2)Sc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2S3)cc1]

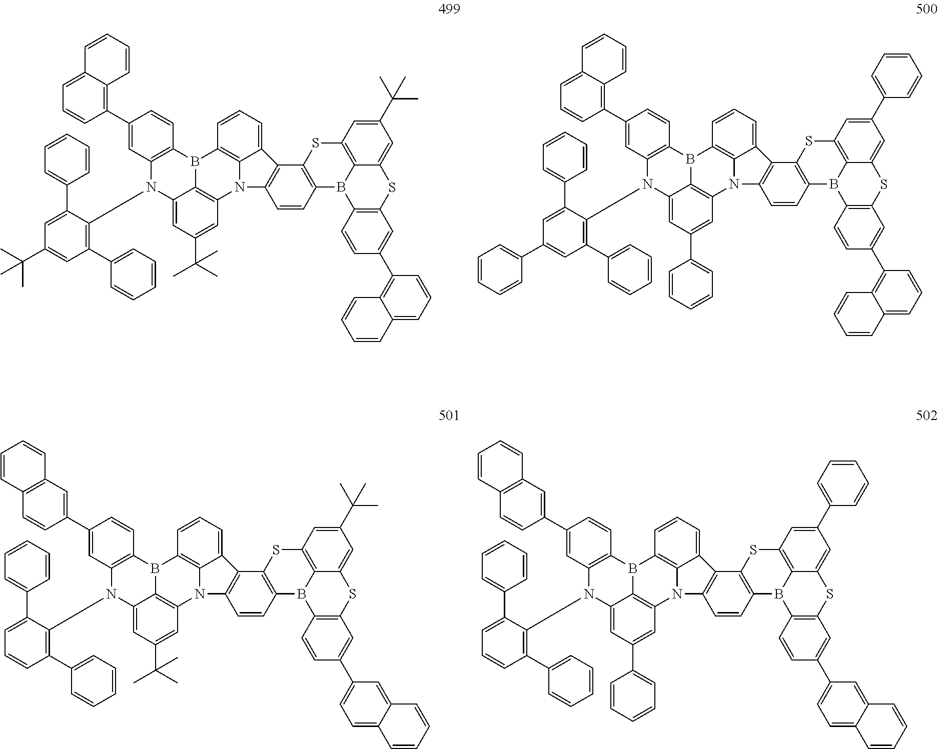

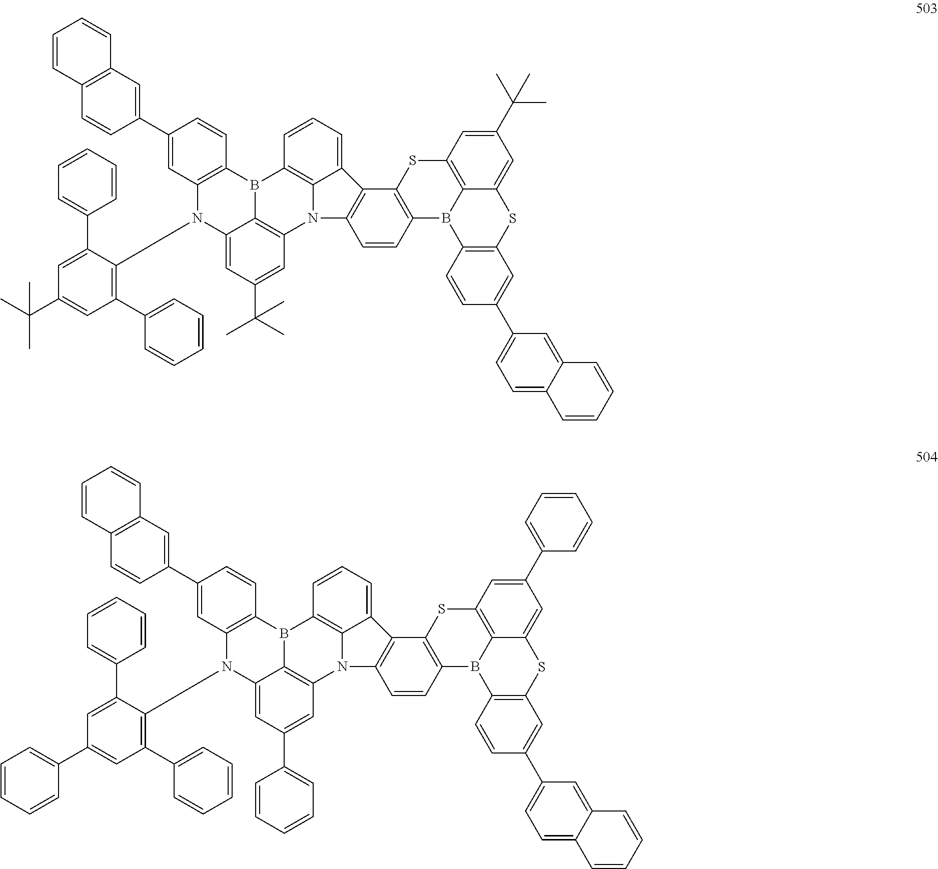 [SMILES: CC(C)(C)c1cc2c3c(c1)Sc1c(ccc4c1c1cccc5c1n4-c1cc(C(C)(C)C)cc4c1B5c1ccc(-c5ccc6ccccc6c5)cc1N4c1c(-c4ccccc4)cc(C(C)(C)C)cc1-c1ccccc1)B3c1ccc(-c3ccc4ccccc4c3)cc1S2 ; c1ccc(-c2cc3c4c(c2)Sc2c(ccc5c2c2cccc6c2n5-c2cc(-c5ccccc5)cc5c2B6c2ccc(-c6ccc7ccccc7c6)cc2N5c2c(-c5ccccc5)cc(-c5ccccc5)cc2-c2ccccc2)B4c2ccc(-c4ccc5ccccc5c4)cc2S3)cc1]

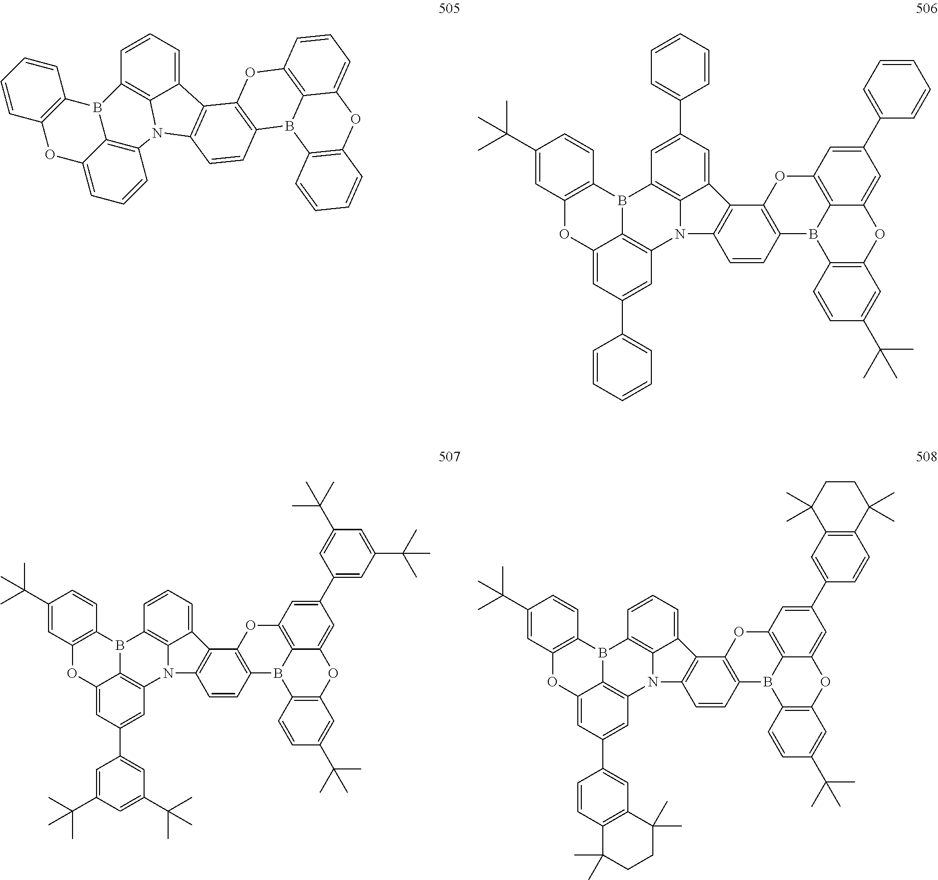 [SMILES: c1ccc2c(c1)Oc1cccc3c1B2c1ccc2c(c1O3)c1cccc3c1n2-c1cccc2c1B3c1ccccc1O2 ; CC(C)(C)c1ccc2c(c1)Oc1cc(-c3ccccc3)cc3c1B2c1ccc2c(c1O3)c1cc(-c3ccccc3)cc3c1n2-c1cc(-c2ccccc2)cc2c1B3c1ccc(C(C)(C)C)cc1O2 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(C(C)(C)C)cc2O5)B4c2ccc(C(C)(C)C)cc2O3)cc(C(C)(C)C)c1 ; CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1O2]

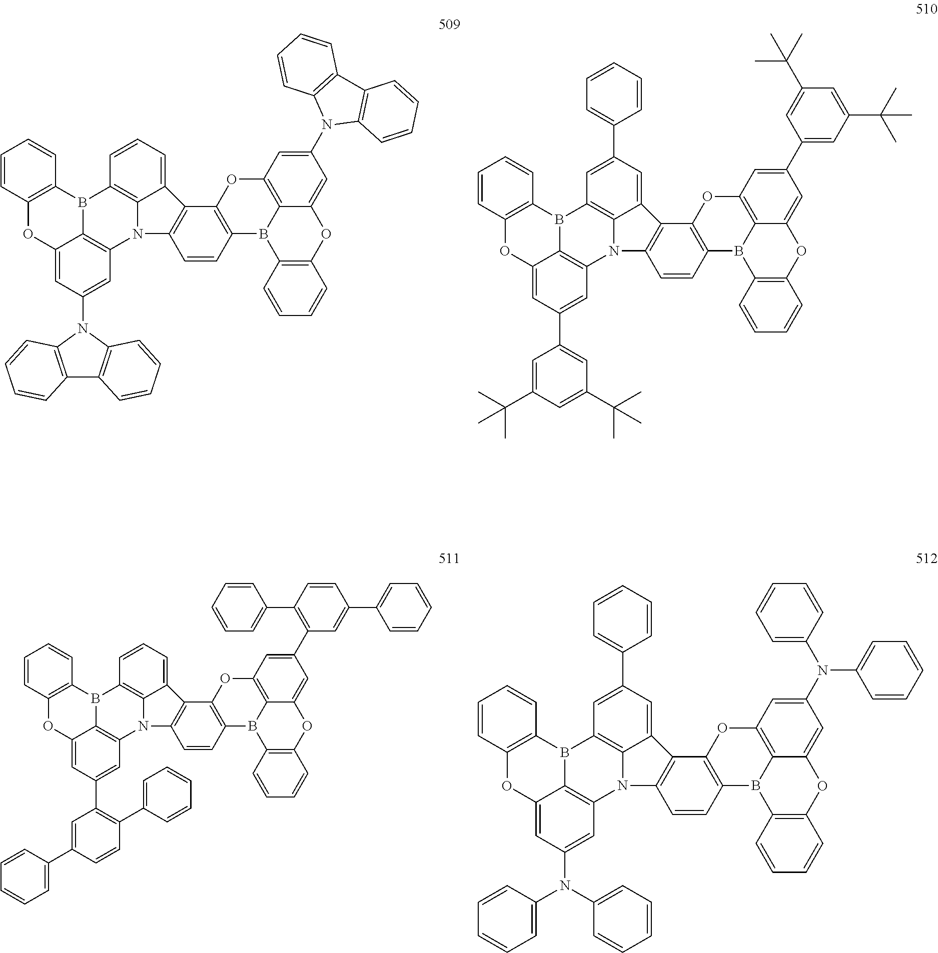

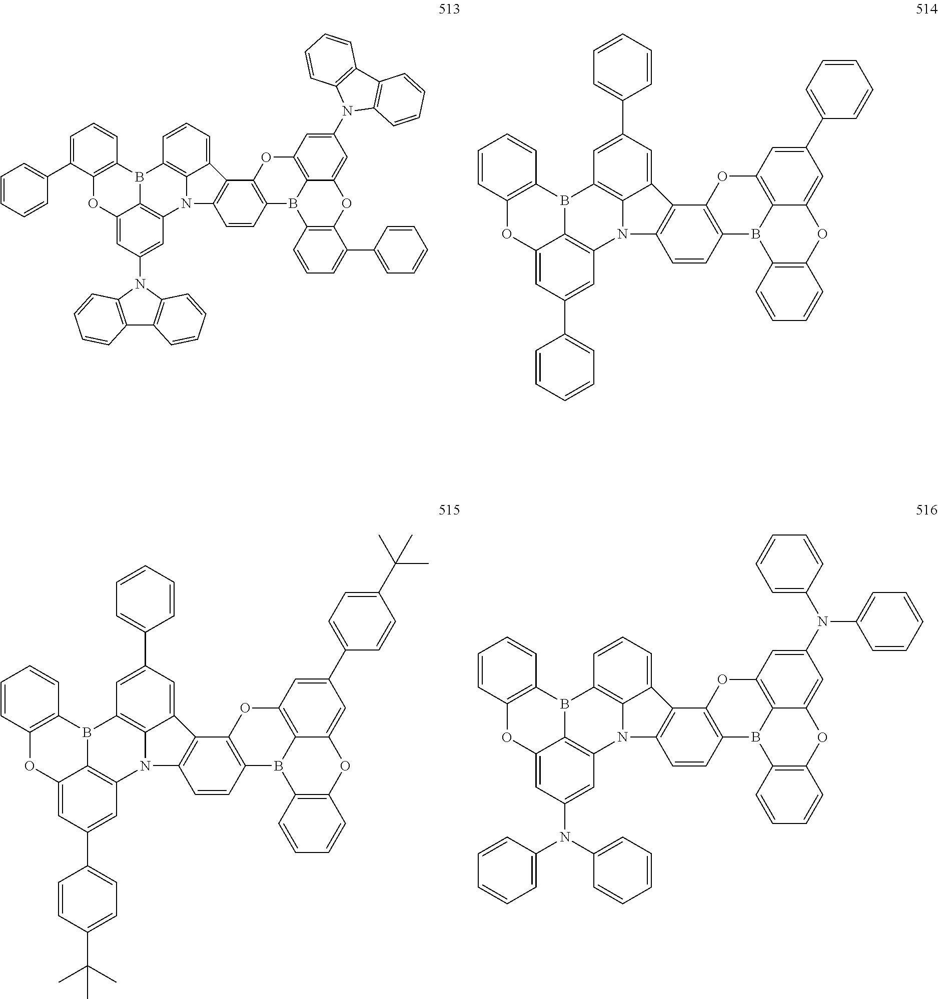 [SMILES: c1ccc(-c2cccc3c2Oc2cc(-n4c5ccccc5c5ccccc54)cc4c2B3c2ccc3c(c2O4)c2cccc4c2n3-c2cc(-n3c5ccccc5c5ccccc53)cc3c2B4c2cccc(-c4ccccc4)c2O3)cc1 ; c1ccc(-c2cc3c4c(c2)Oc2c(ccc5c2c2cc(-c6ccccc6)cc6c2n5-c2cc(-c5ccccc5)cc5c2B6c2ccccc2O5)B4c2ccccc2O3)cc1 ; CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccccc2O5)B4c2ccccc2O3)cc1 ; c1ccc(N(c2ccccc2)c2cc3c4c(c2)Oc2c(ccc5c2c2cccc6c2n5-c2cc(N(c5ccccc5)c5ccccc5)cc5c2B6c2ccccc2O5)B4c2ccccc2O3)cc1]

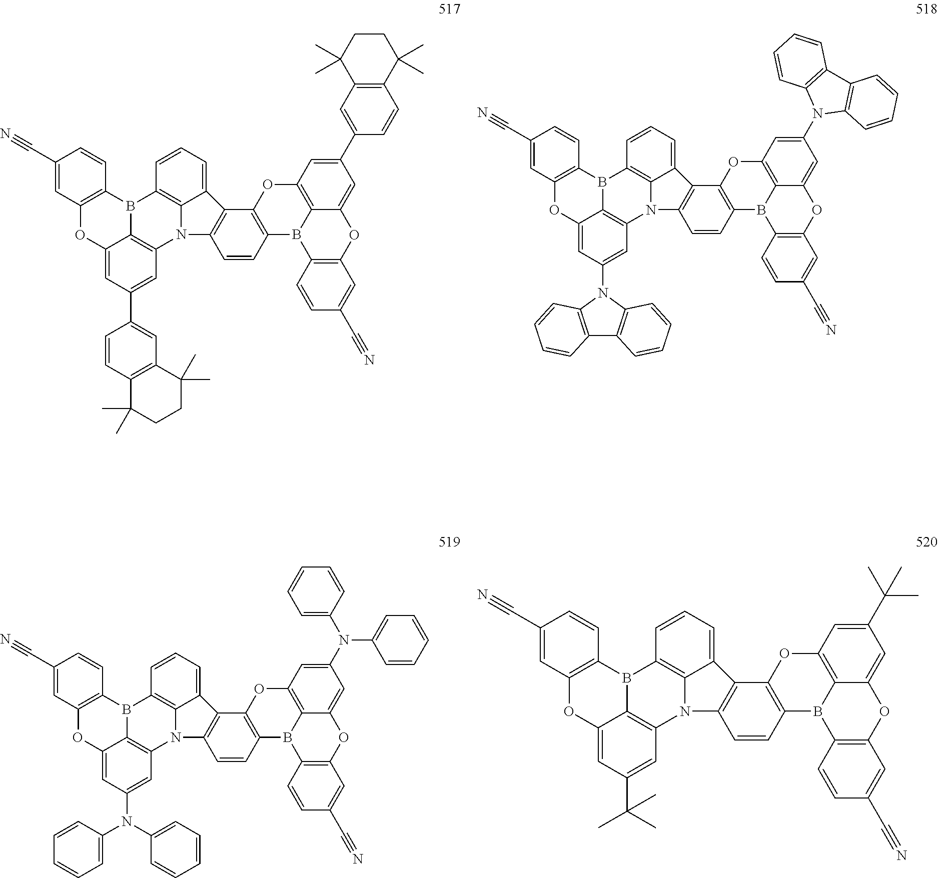 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(C#N)cc3O6)B5c3ccc(C#N)cc3O4)ccc21 ; N#Cc1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1O2 ; N#Cc1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1O2 ; CC(C)(C)c1cc2c3c(c1)Oc1c(ccc4c1c1cccc5c1n4-c1cc(C(C)(C)C)cc4c1B5c1ccc(C#N)cc1O4)B3c1ccc(C#N)cc1O2]

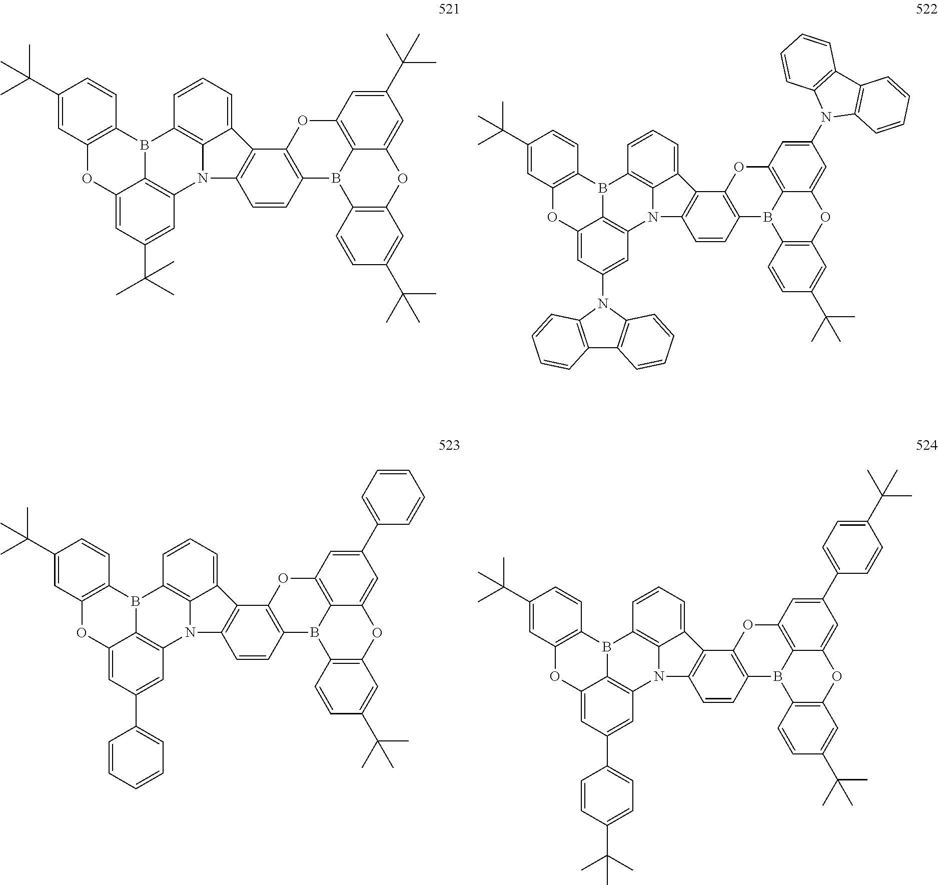 [SMILES: CC(C)(C)c1ccc2c(c1)Oc1cc(C(C)(C)C)cc3c1B2c1ccc2c(c1O3)c1cccc3c1n2-c1cc(C(C)(C)C)cc2c1B3c1ccc(C(C)(C)C)cc1O2 ; CC(C)(C)c1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1O2 ; CC(C)(C)c1ccc2c(c1)Oc1cc(-c3ccccc3)cc3c1B2c1ccc2c(c1O3)c1cccc3c1n2-c1cc(-c2ccccc2)cc2c1B3c1ccc(C(C)(C)C)cc1O2 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2O5)B4c2ccc(C(C)(C)C)cc2O3)cc1]

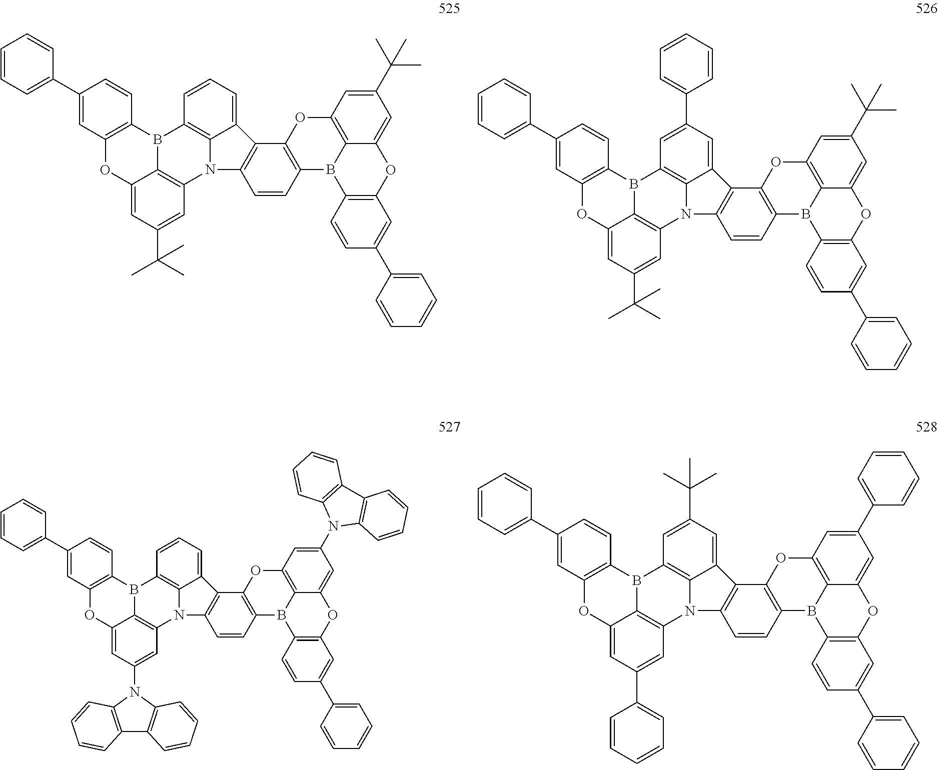 [SMILES: CC(C)(C)c1cc2c3c(c1)Oc1c(ccc4c1c1cccc5c1n4-c1cc(C(C)(C)C)cc4c1B5c1ccc(-c5ccccc5)cc1O4)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1O4)B3c1ccc(-c3ccccc3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2O3)cc1 ; CC(C)(C)c1cc2c3c(c1)c1c4c(ccc1n3-c1cc(-c3ccccc3)cc3c1B2c1ccc(-c2ccccc2)cc1O3)B1c2ccc(-c3ccccc3)cc2Oc2cc(-c3ccccc3)cc(c21)O4]

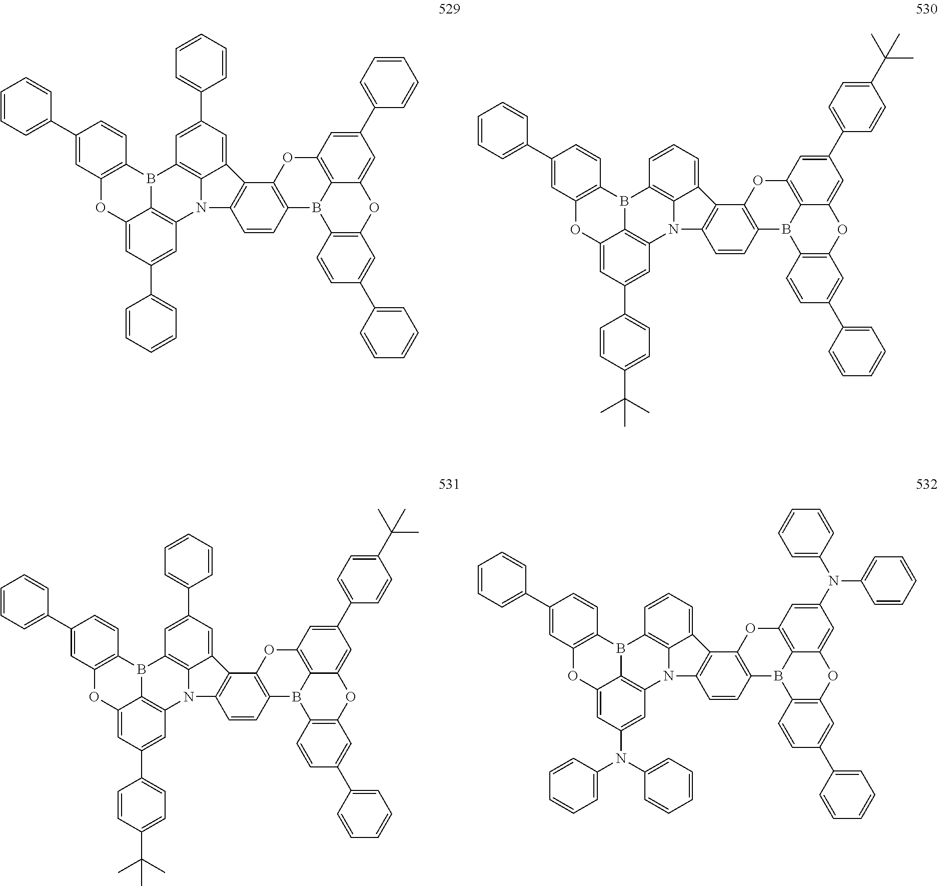

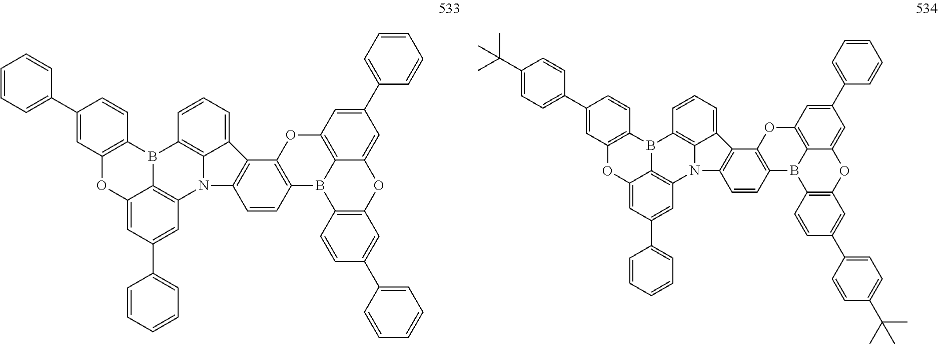 [SMILES: c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccccc4)cc2O3)cc1 ; CC(C)(C)c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2O3)cc1]

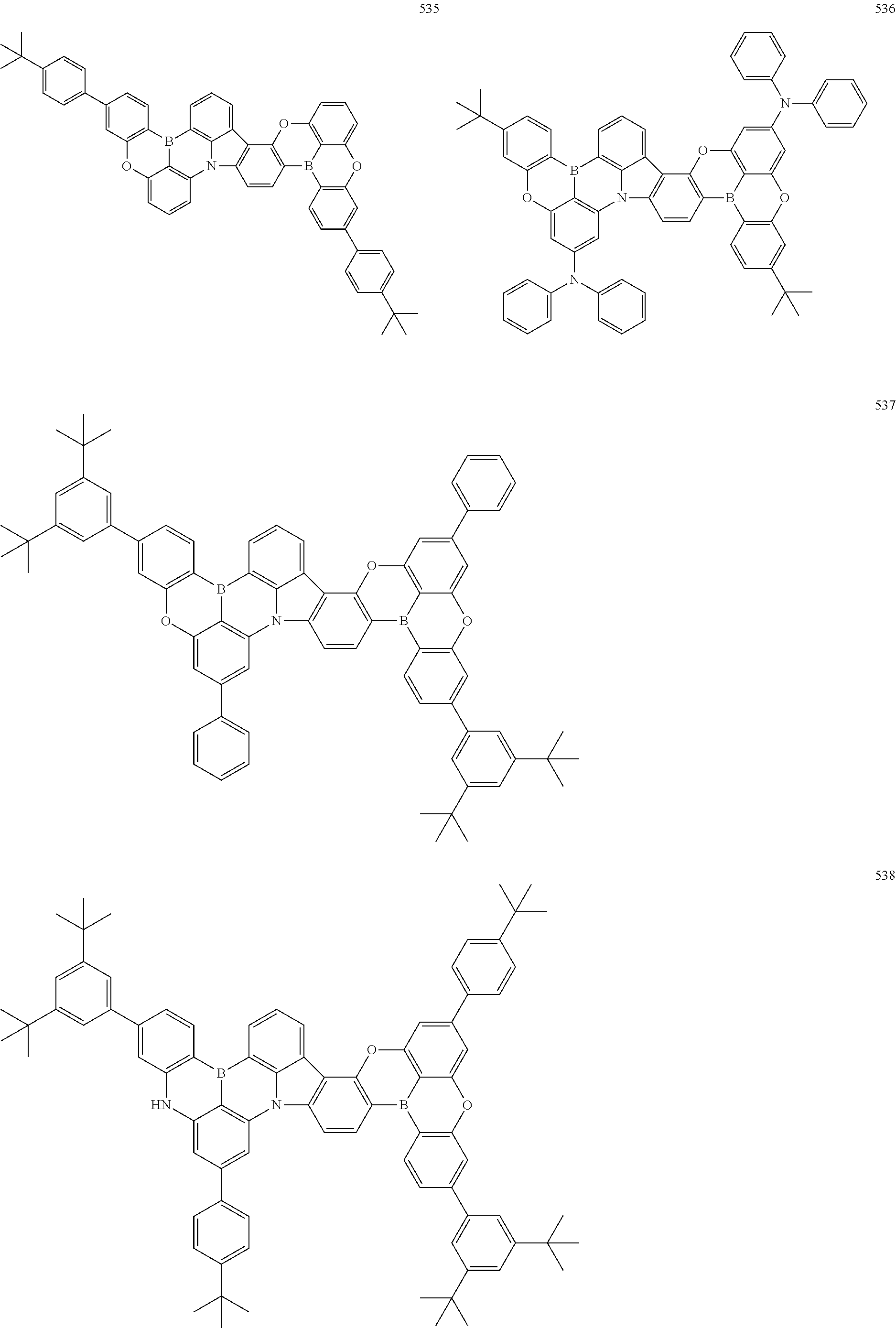

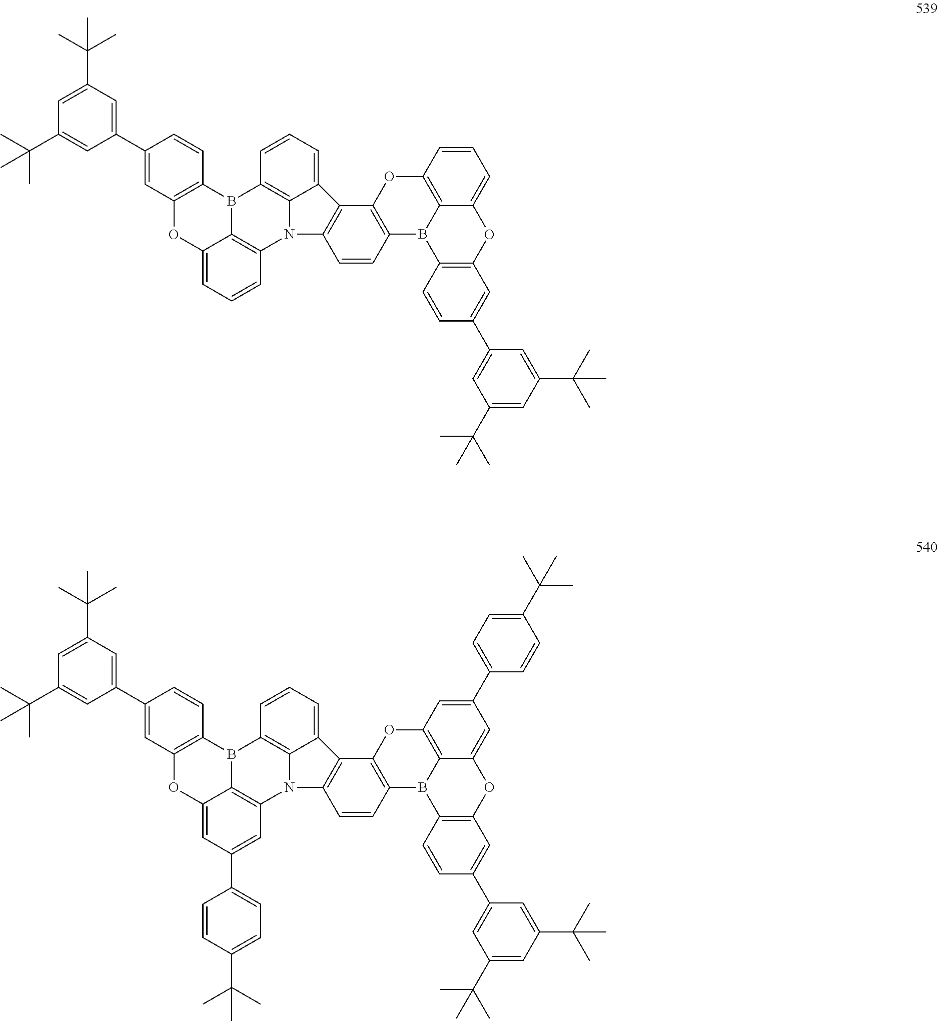

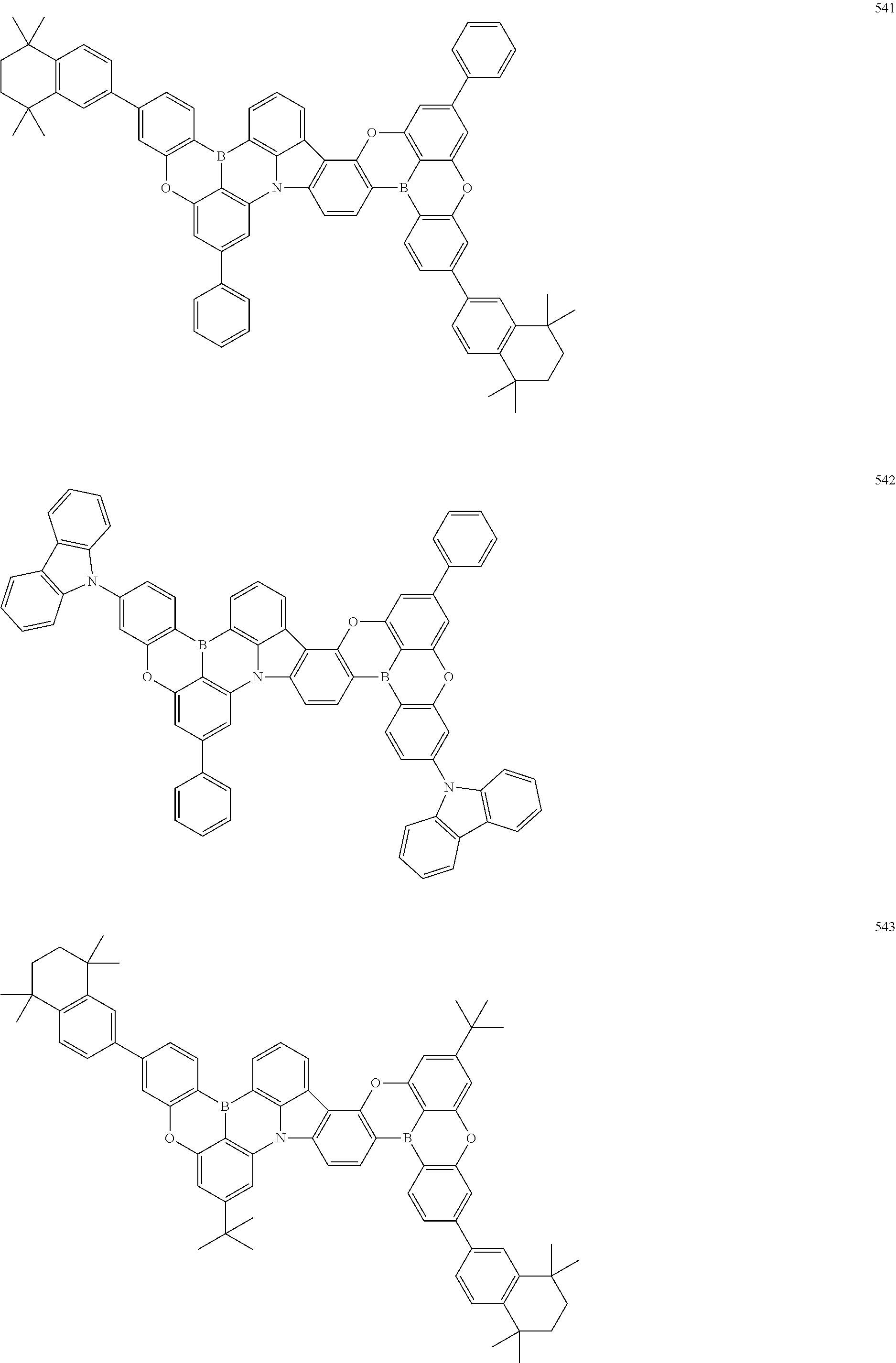

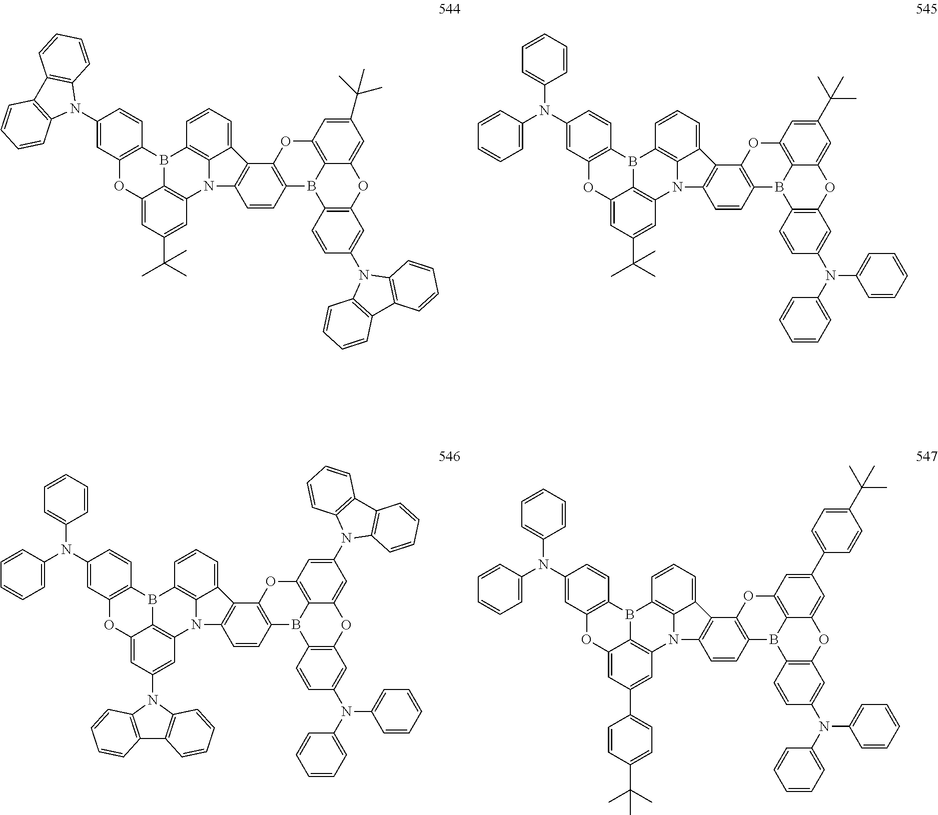

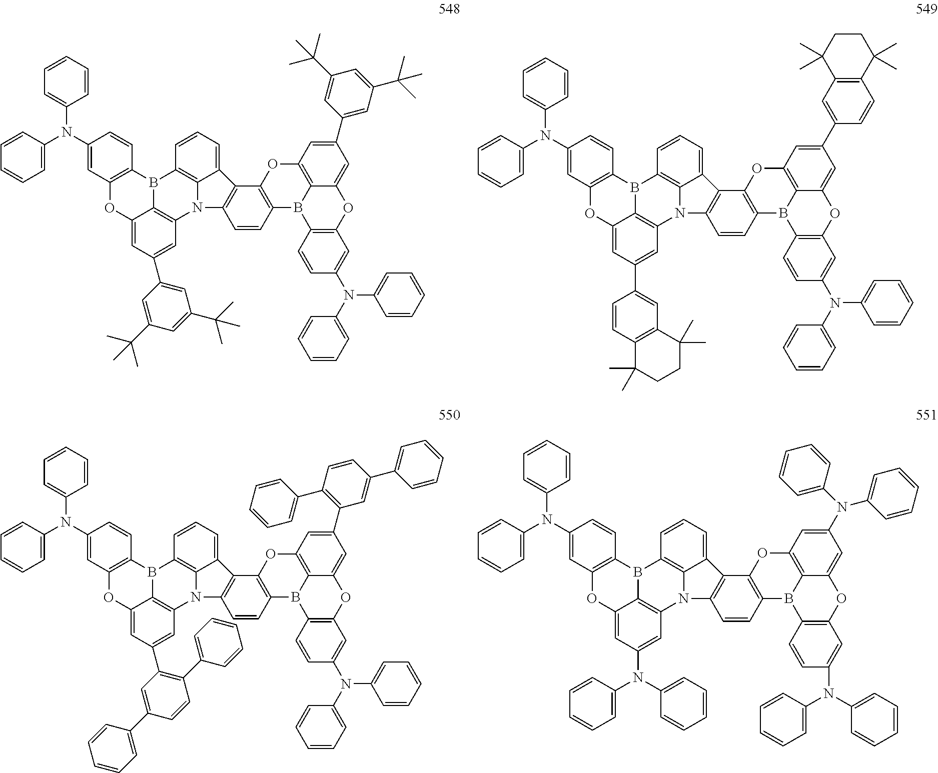

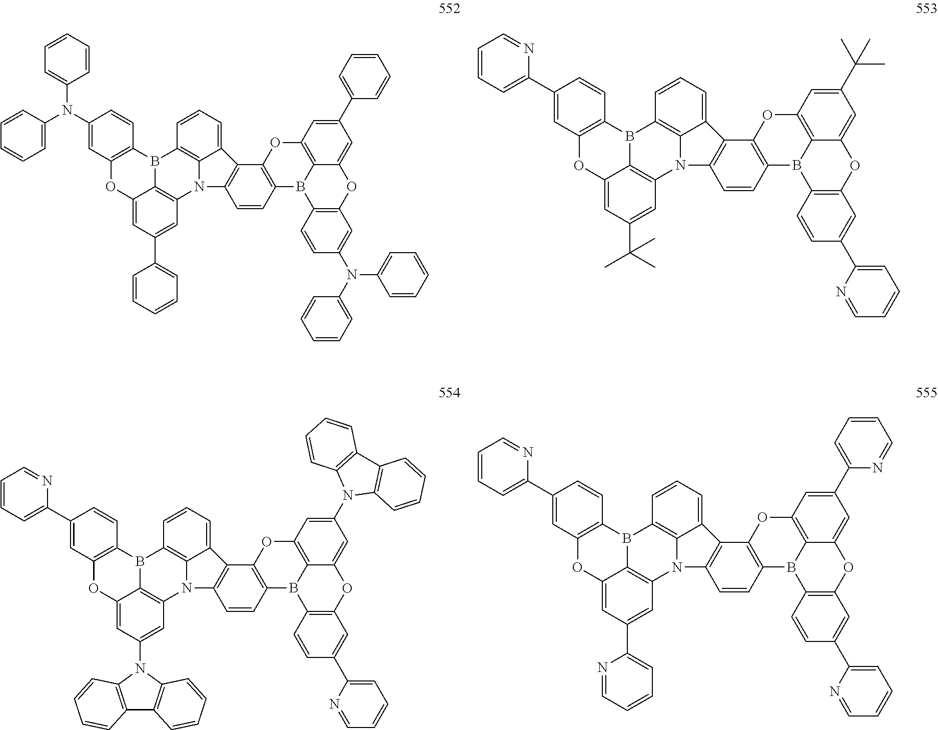 [SMILES: c1ccc(-c2cc3c4c(c2)Oc2c(ccc5c2c2cccc6c2n5-c2cc(-c5ccccc5)cc5c2B6c2ccc(N(c6ccccc6)c6ccccc6)cc2O5)B4c2ccc(N(c4ccccc4)c4ccccc4)cc2O3)cc1 ; CC(C)(C)c1cc2c3c(c1)Oc1c(ccc4c1c1cccc5c1n4-c1cc(C(C)(C)C)cc4c1B5c1ccc(-c5ccccn5)cc1O4)B3c1ccc(-c3ccccn3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccn4)cc2O3)nc1 ; c1ccc(-c2ccc3c(c2)Oc2cc(-c4ccccn4)cc4c2B3c2ccc3c(c2O4)c2cccc4c2n3-c2cc(-c3ccccn3)cc3c2B4c2ccc(-c4ccccn4)cc2O3)nc1]

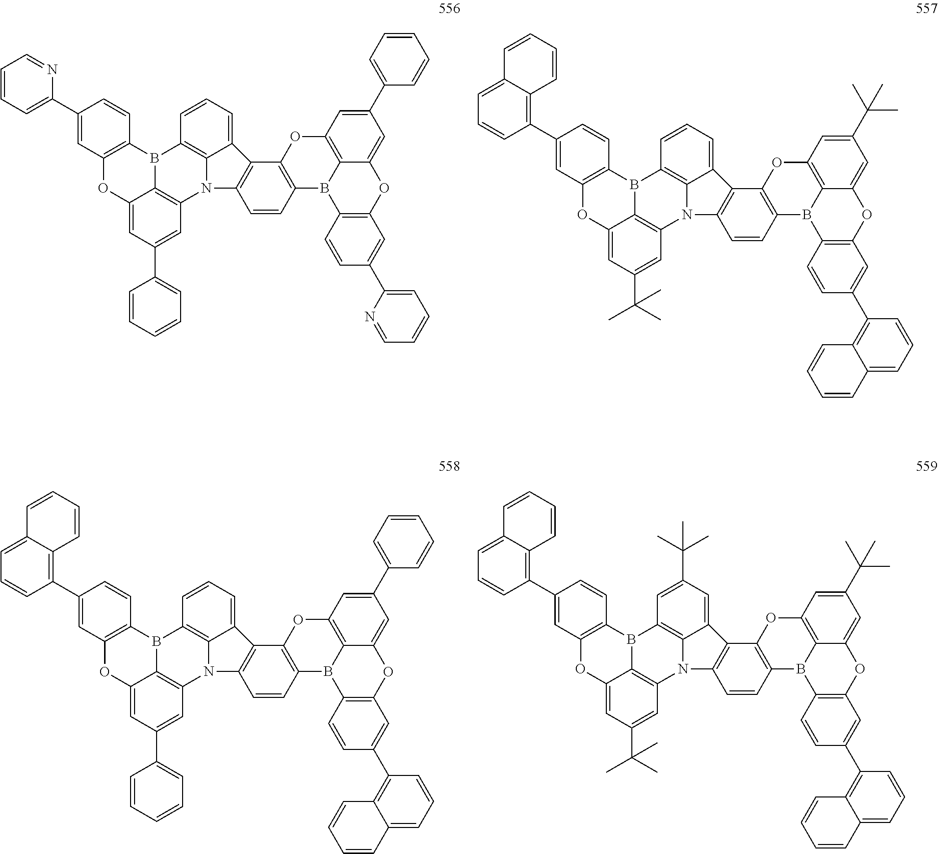 [SMILES: c1ccc(-c2cc3c4c(c2)Oc2c(ccc5c2c2cccc6c2n5-c2cc(-c5ccccc5)cc5c2B6c2ccc(-c6ccccn6)cc2O5)B4c2ccc(-c4ccccn4)cc2O3)cc1 ; CC(C)(C)c1cc2c3c(c1)Oc1c(ccc4c1c1cccc5c1n4-c1cc(C(C)(C)C)cc4c1B5c1ccc(-c5cccc6ccccc56)cc1O4)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2O5)B4c2ccc(-c4cccc5ccccc45)cc2O3)cc1 ; CC(C)(C)c1cc2c3c(c1)Oc1c(ccc4c1c1cc(C(C)(C)C)cc5c1n4-c1cc(C(C)(C)C)cc4c1B5c1ccc(-c5cccc6ccccc56)cc1O4)B3c1ccc(-c3cccc4ccccc34)cc1O2]

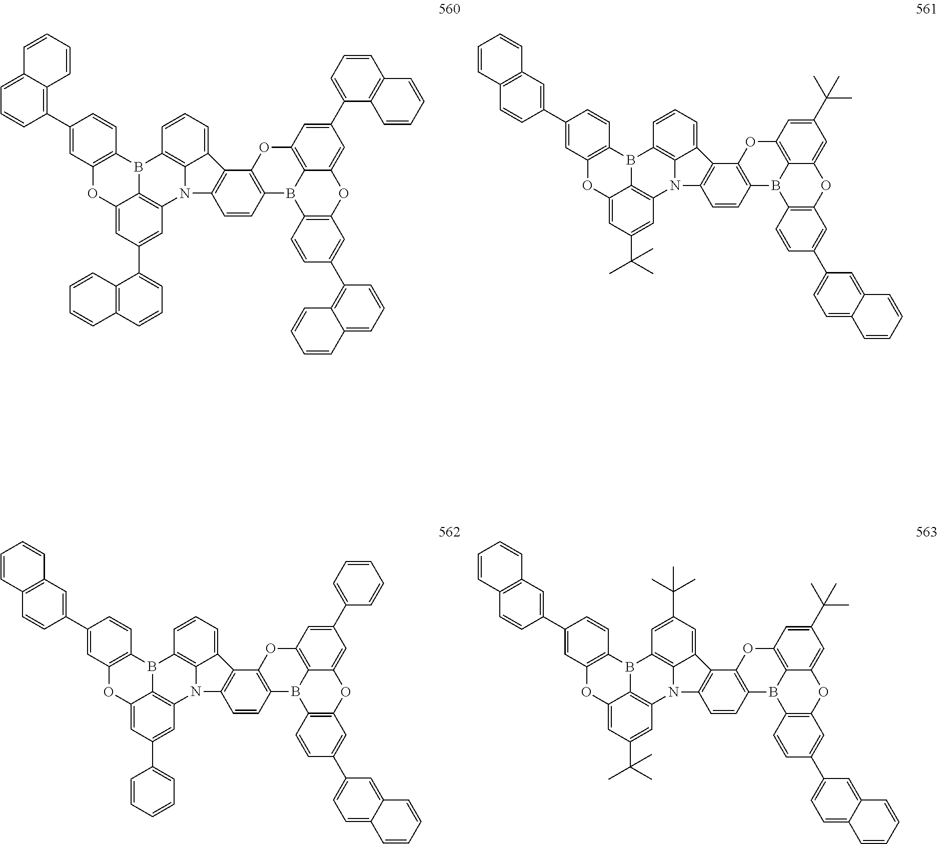

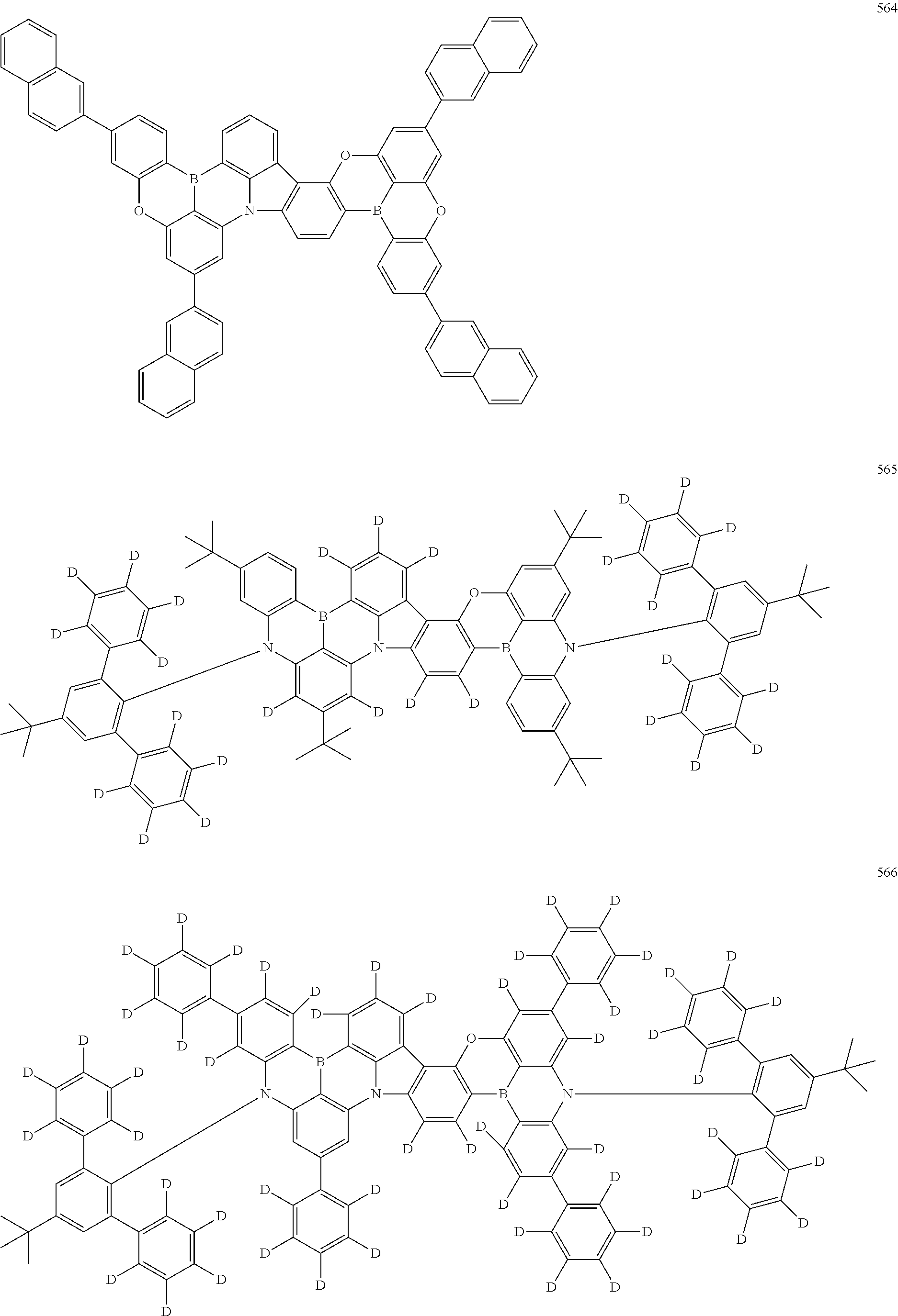

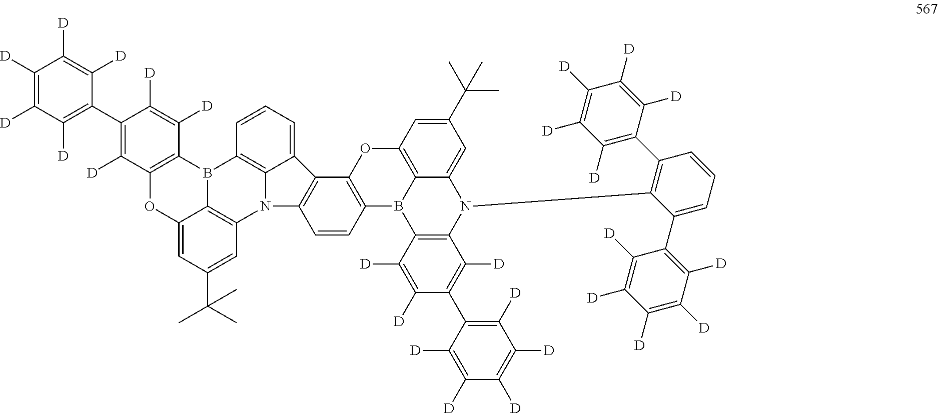 [SMILES: [2H]c1c([2H])c([2H])c(-c2cccc(-c3c([2H])c([2H])c([2H])c([2H])c3[2H])c2N2c3cc(C(C)(C)C)cc4c3B(c3ccc5c(c3O4)c3cccc4c3n5-c3cc(C(C)(C)C)cc5c3B4c3c([2H])c([2H])c(-c4c([2H])c([2H])c([2H])c([2H])c4[2H])c([2H])c3O5)c3c([2H])c([2H])c(-c4c([2H])c([2H])c([2H])c([2H])c4[2H])c([2H])c32)c([2H])c1[2H]]

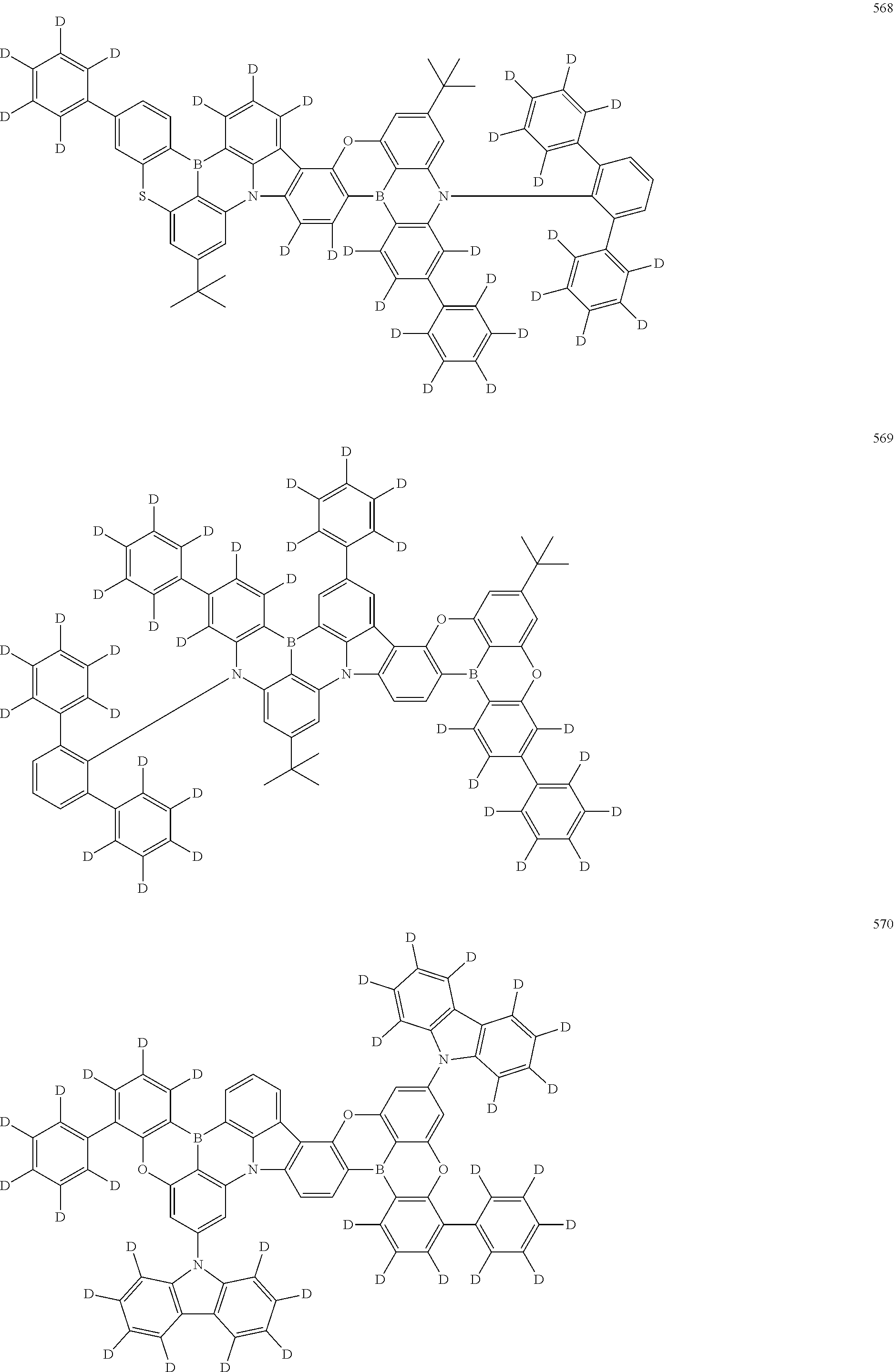

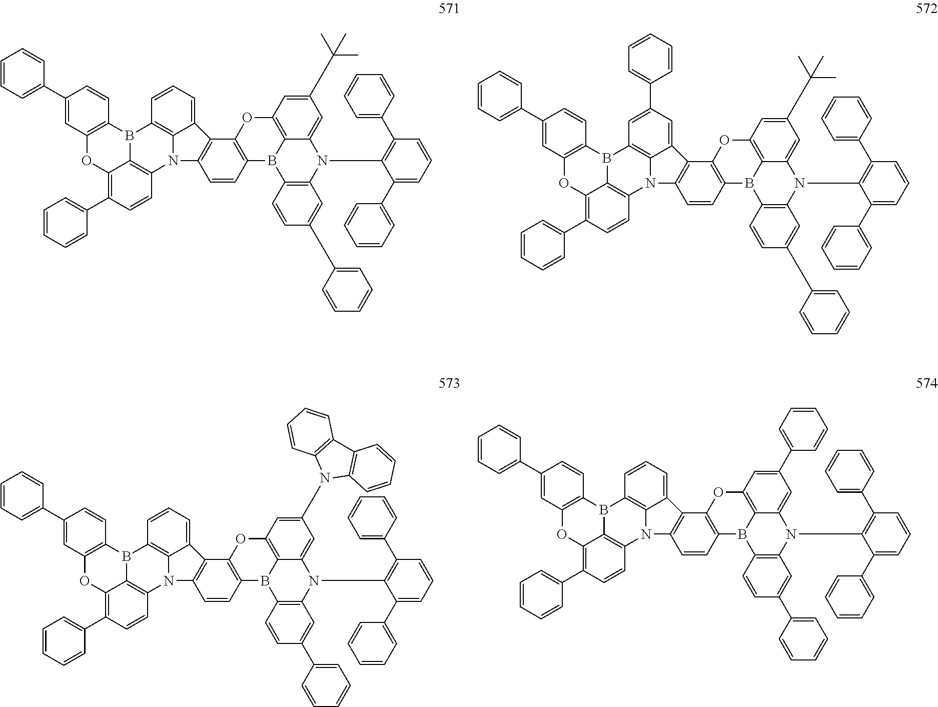

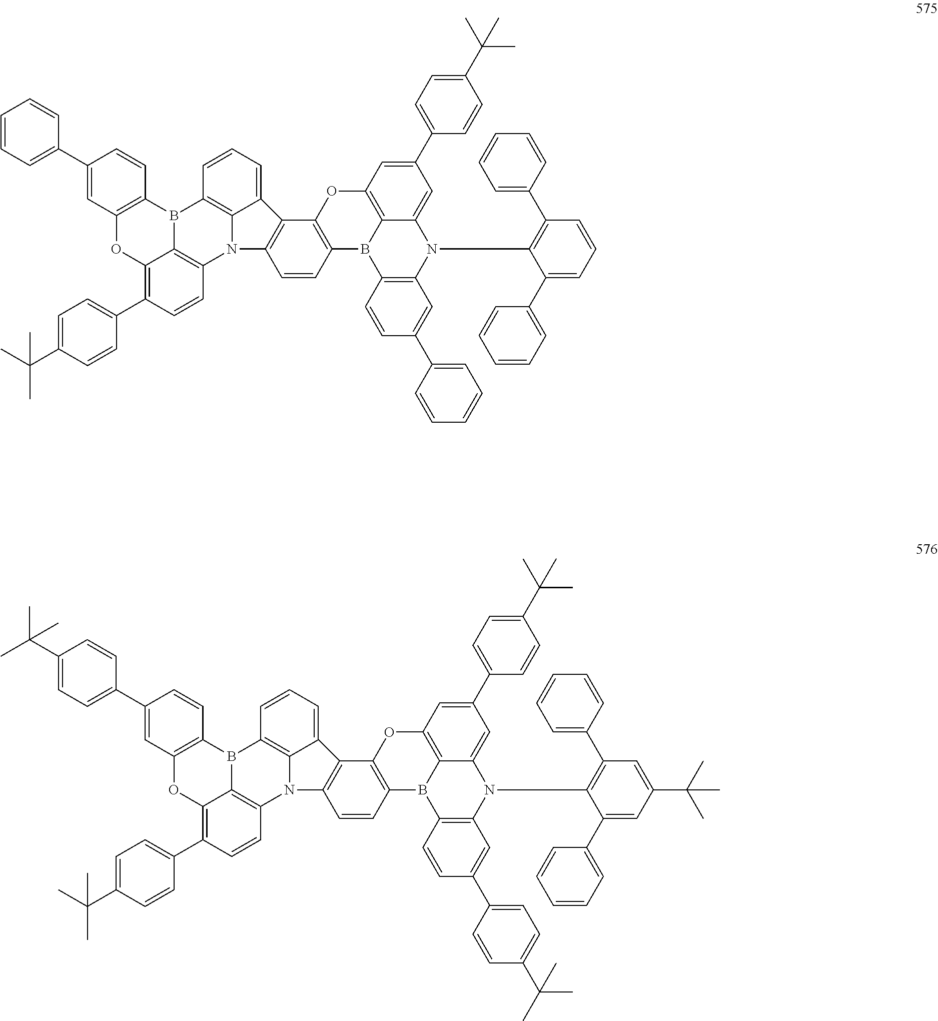 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2ccc(-c4ccc(C(C)(C)C)cc4)c4c2B3c2ccc(-c3ccccc3)cc2O4)cc1 ; CC(C)(C)c1ccc(-c2ccc3c(c2)Oc2c(-c4ccc(C(C)(C)C)cc4)ccc4c2B3c2cccc3c5c6c(ccc5n-4c23)B2c3ccc(-c4ccc(C(C)(C)C)cc4)cc3N(c3c(-c4ccccc4)cc(C(C)(C)C)cc3-c3ccccc3)c3cc(-c4ccc(C(C)(C)C)cc4)cc(c32)O6)cc1]

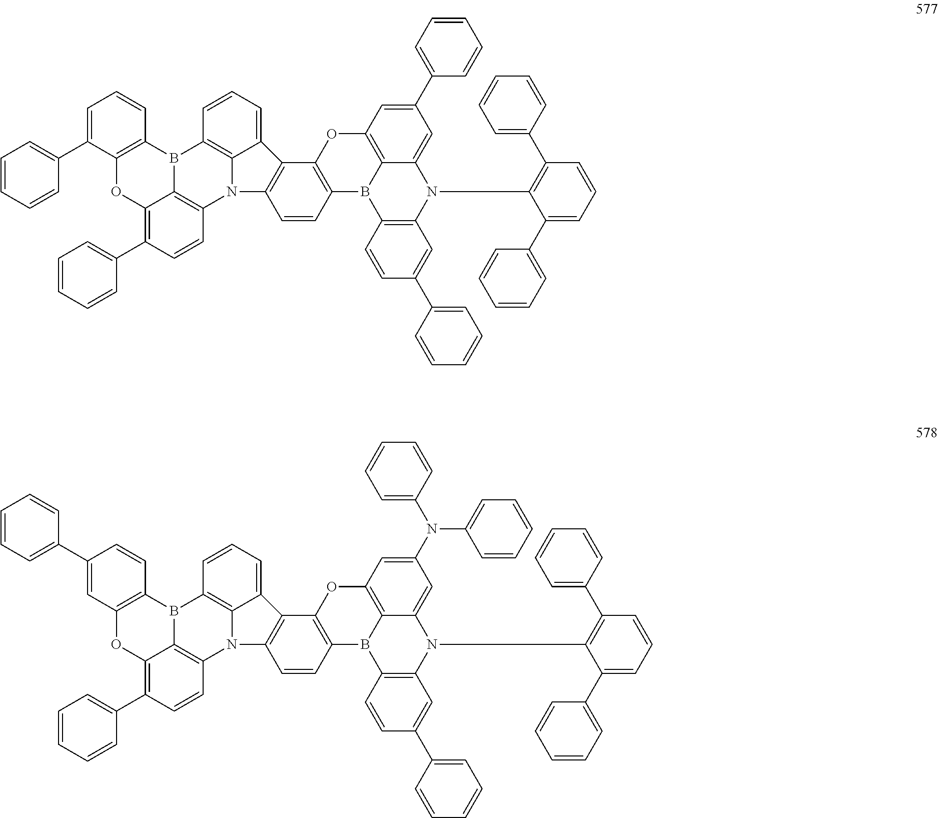 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2ccc(-c3ccccc3)c3c2B4c2cccc(-c4ccccc4)c2O3)cc1 ; c1ccc(-c2ccc3c(c2)Oc2c(-c4ccccc4)ccc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1]

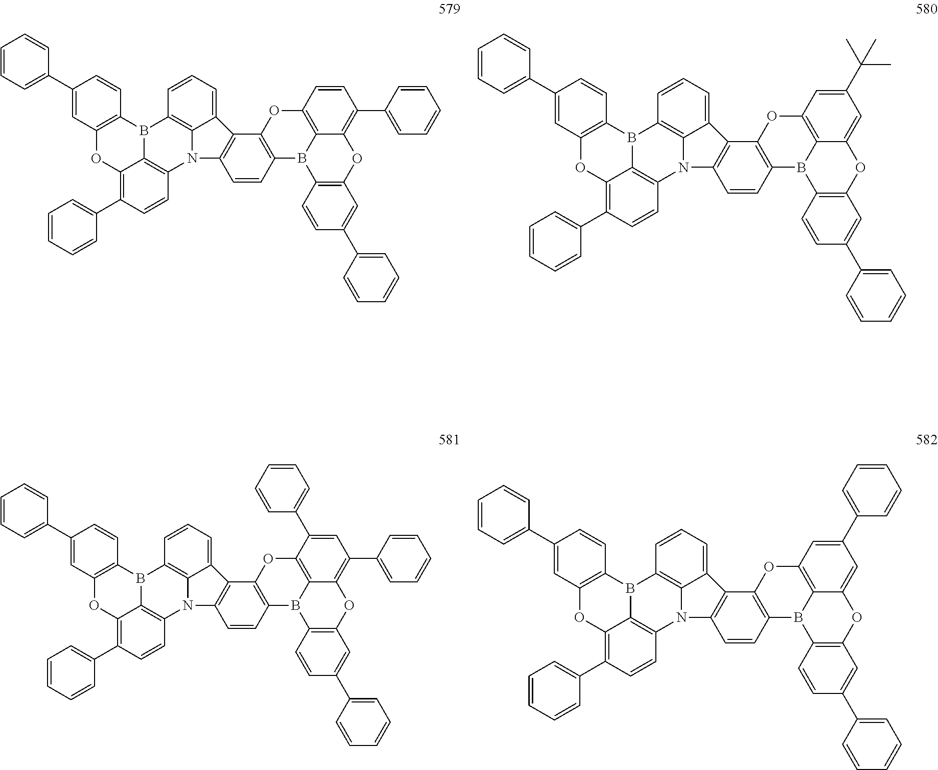 [SMILES: c1ccc(-c2ccc3c(c2)Oc2c(-c4ccccc4)ccc4c2B3c2ccc3c(c2O4)c2cccc4c2n3-c2ccc(-c3ccccc3)c3c2B4c2ccc(-c4ccccc4)cc2O3)cc1 ; CC(C)(C)c1cc2c3c(c1)Oc1c(ccc4c1c1cccc5c1n4-c1ccc(-c4ccccc4)c4c1B5c1ccc(-c5ccccc5)cc1O4)B3c1ccc(-c3ccccc3)cc1O2 ; c1ccc(-c2ccc3c(c2)Oc2c(-c4ccccc4)cc(-c4ccccc4)c4c2B3c2ccc3c(c2O4)c2cccc4c2n3-c2ccc(-c3ccccc3)c3c2B4c2ccc(-c4ccccc4)cc2O3)cc1 ; c1ccc(-c2ccc3c(c2)Oc2cc(-c4ccccc4)cc4c2B3c2ccc3c(c2O4)c2cccc4c2n3-c2ccc(-c3ccccc3)c3c2B4c2ccc(-c4ccccc4)cc2O3)cc1]

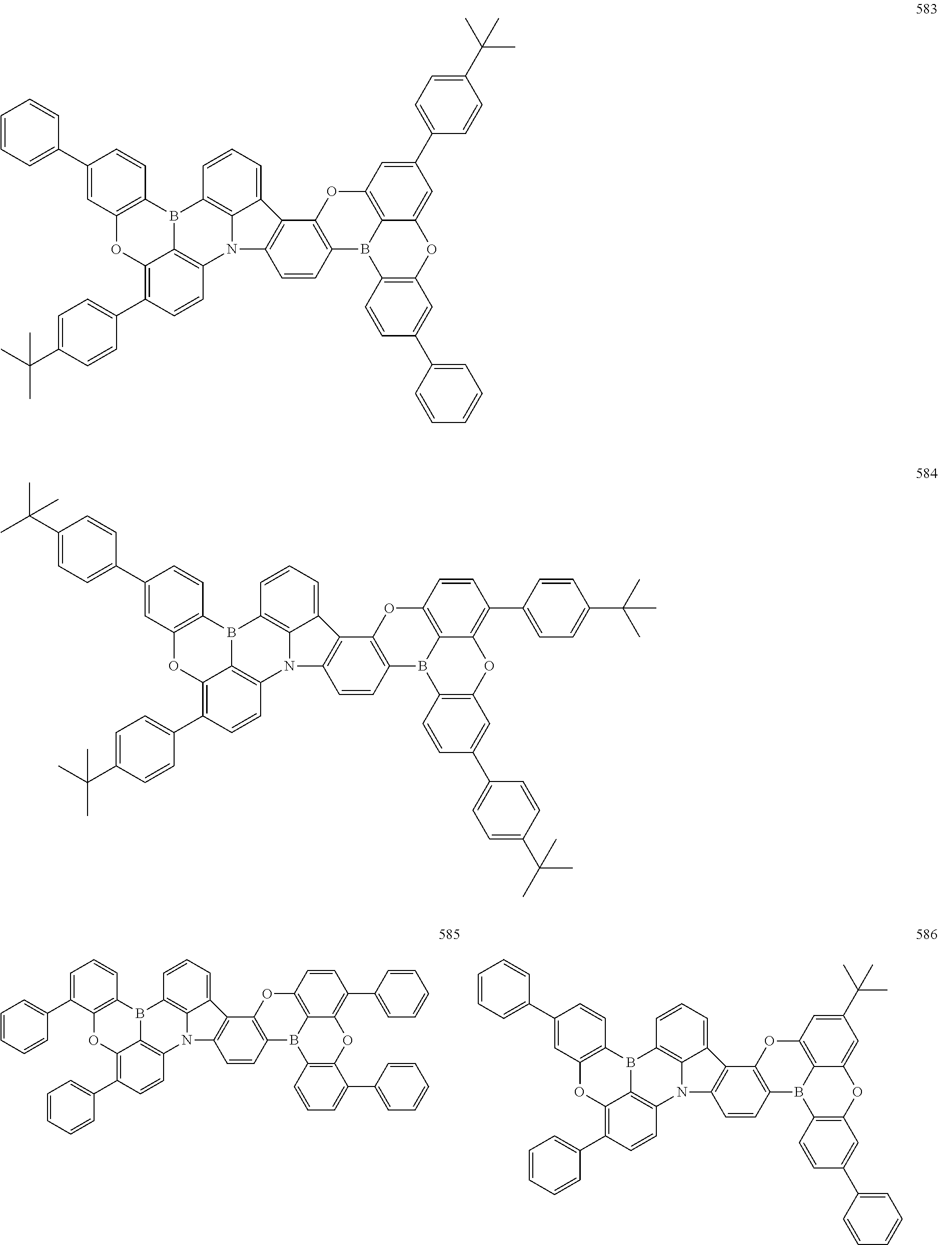

A light-emitting element ED including the fused polycyclic compound according to one or more embodiments may have a peak emission wavelength in a wavelength region of about 440 nm to about 480 nm. The peak emission wavelength may indicate a wavelength of a position at which an emission intensity is maximum in an emission spectrum. The light-emitting element ED including the fused polycyclic compound according to one or more embodiments may be to emit blue light. A third light-emitting element ED-3 (FIG. 2) which emits blue light may include the fused polycyclic compound according to one or more embodiments.

The emission layer EML may include the fused polycyclic compound according to one or more embodiments as a dopant. The fused polycyclic compound according to one or more embodiments may be a delayed fluorescent material. The fused polycyclic compound according to one or more embodiments may be a material of thermally activated delayed fluorescence (TADF). The fused polycyclic compound according to one or more embodiments may be to emit light by converting triplet excitons to singlet excitons due to a reverse inter system crossing (RISC) mechanism.

A generally used compound that includes a fused ring with nine rings including no carbazole group has a high molecular weight. Therefore, the extent of the intermolecular reaction of the generally used compound is high, which makes purification by sublimation difficult during synthesis of the compound, and thus the generally used compound exhibits poor thermal resistance and a short lifespan.

Unlike the generally used compound, the fused polycyclic compound according to one or more embodiments may include, as a core structure, a fused ring with 11 rings in which a carbazole ring is fused with two or more rings and thus may exhibit improved or enhanced thermal resistance. The fused ring with 11 rings, in which a carbazole ring is fused with two or more rings, may have large resonance or conjugation, and thus the fused polycyclic compound according to one or more embodiments may be easily purified by sublimation during synthesis of the compound, have an increase in thermal resistance, and exhibit excellent or suitable material stability. In one or more embodiments, by introduction of the fused ring with 11 rings which includes a carbazole ring and has large resonance, electron mobility of the compound increases, thus possibility of electron transfer may increase, and thus a molar extinction coefficient (s) and oscillator strength of the fused polycyclic compound may be improved or enhanced. The compound having a high molar extinction coefficient and a high oscillator strength may have increased emissivity and thus may contribute to an increase in internal quantum efficiency. Therefore, the light-emitting element ED including the fused polycyclic compound according to one or more embodiments may exhibit long lifespan properties.

The fused polycyclic compound according to one or more embodiments may include, as a core structure, a fused ring with 11 rings, in which a carbazole ring is fused with two or more rings and thus, as described herein, may have a large resonance or conjugation, thereby having high structural stability and substantially uniform electron distribution. Therefore, the fused polycyclic compound according to one or more embodiments may exhibit reactivity capable of introducing a plurality of functional groups. Accordingly, the fused polycyclic compound according to one or more embodiments may be useful for synthesizing a derivative. In one or more embodiments, the fused polycyclic compound according to one or more embodiments may contribute to reduction in a molecular weight.

In one or more embodiments, the emission layer EML may include the fused polycyclic compound according to one or more embodiments, and may further include at least one selected from among second to fourth compounds. In one or more embodiments, the emission layer EML may include a second compound represented by Formula HT-1. For example, the second compound may be used as a hole transporting host material in the emission layer EML.

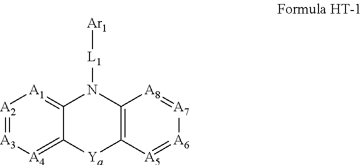

In Formula HT-1, A₁ to A₈ may each independently be N or CR₅₁. For example, all of A₁ to A₈ may be CR₅₁. In one or more embodiments, any one selected from among A₁ to A₈ may be N, and the rest may be CR₅₁.

In Formula HT-1, L₁ may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. For example, L₁ may be a direct linkage (e.g., a single covalent bond), a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Ya may be a direct linkage (e.g., a single covalent bond), CR₅₂R₅₃, or SiR₅₄R₅₅. For example, it may refer to that the two benzene rings linked to the nitrogen atom in Formula HT-1 are linked via a direct linkage (e.g., a single covalent bond),

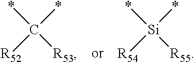

In Formula HT-1, if (e.g., when) Yₐ is a direct linkage (e.g., a single covalent bond), the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be a hydrogen atom, a deuterium atom, a halogen atom (e.g., F, Cl, Br, or I), a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

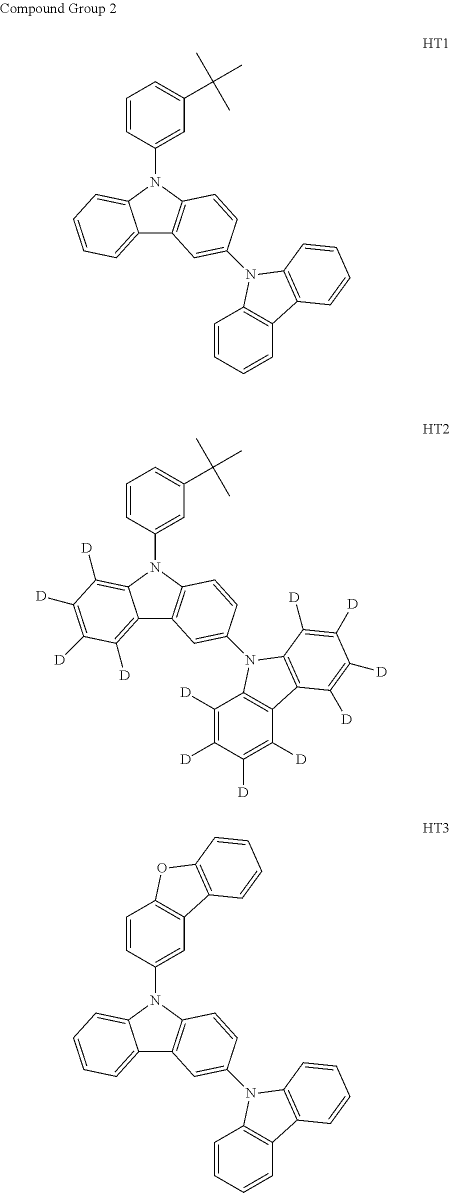 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

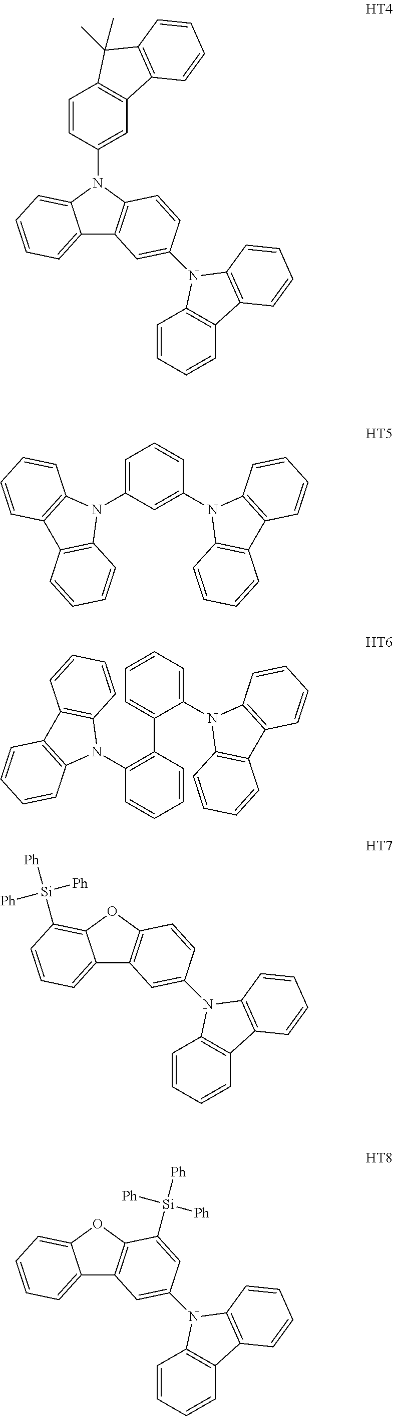 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

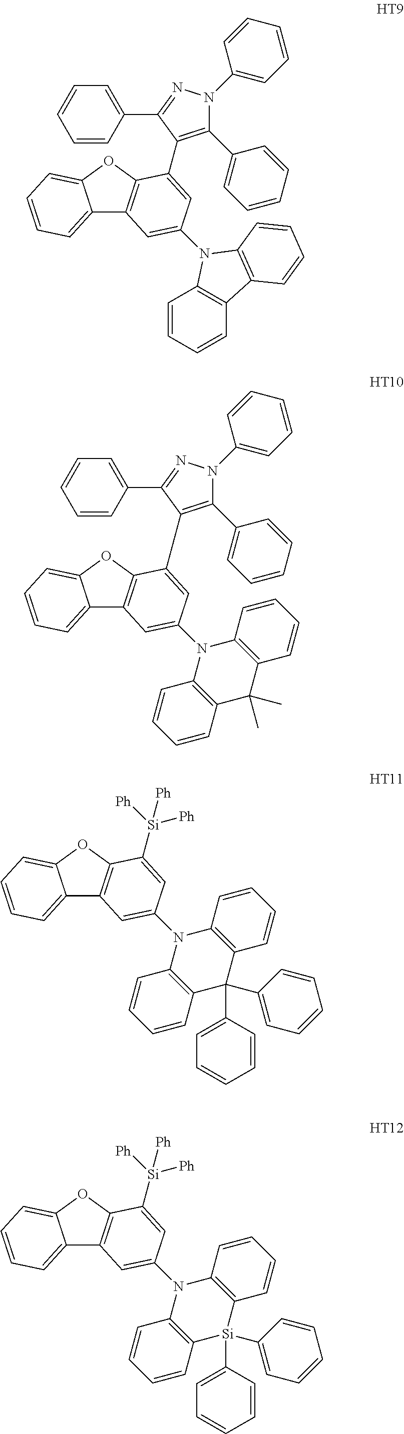 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

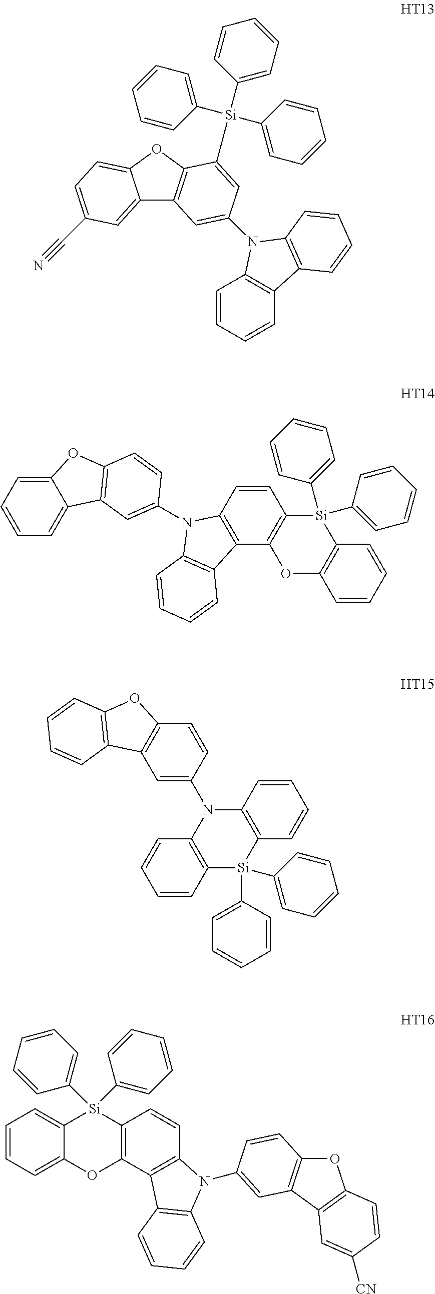 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

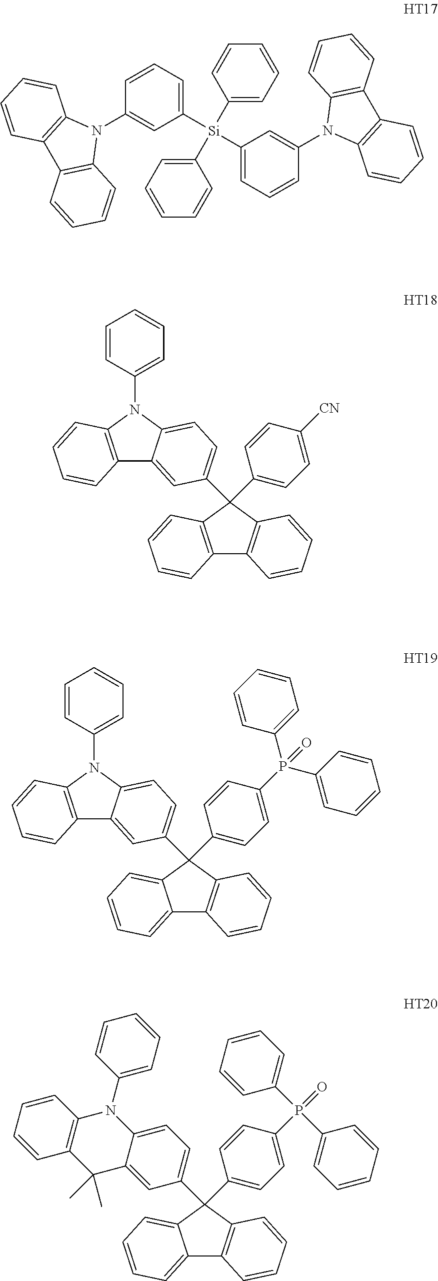 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

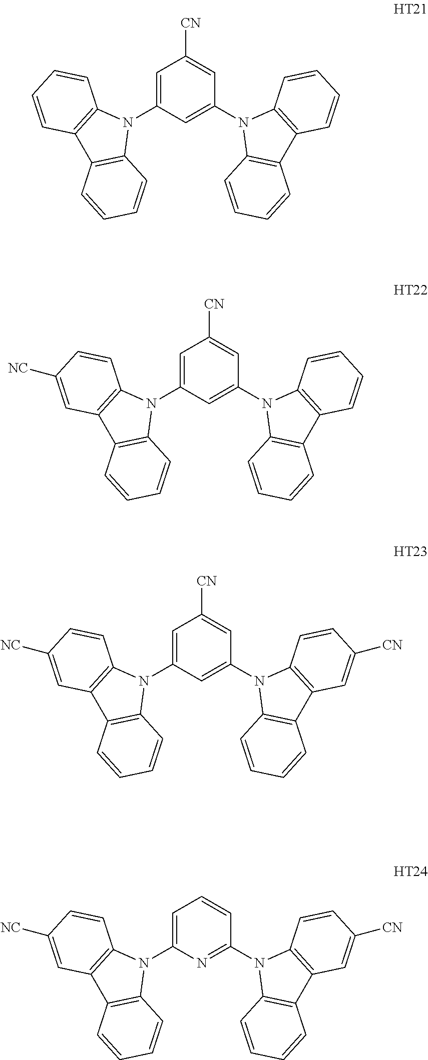 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

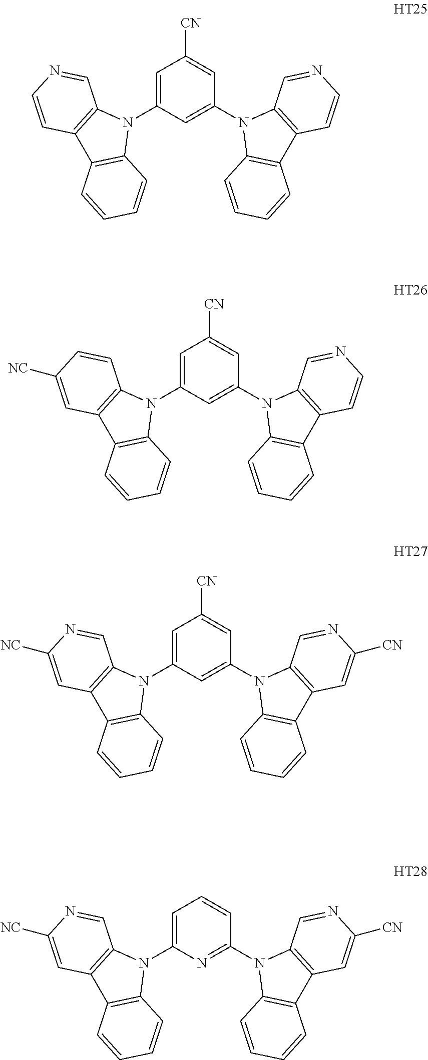 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

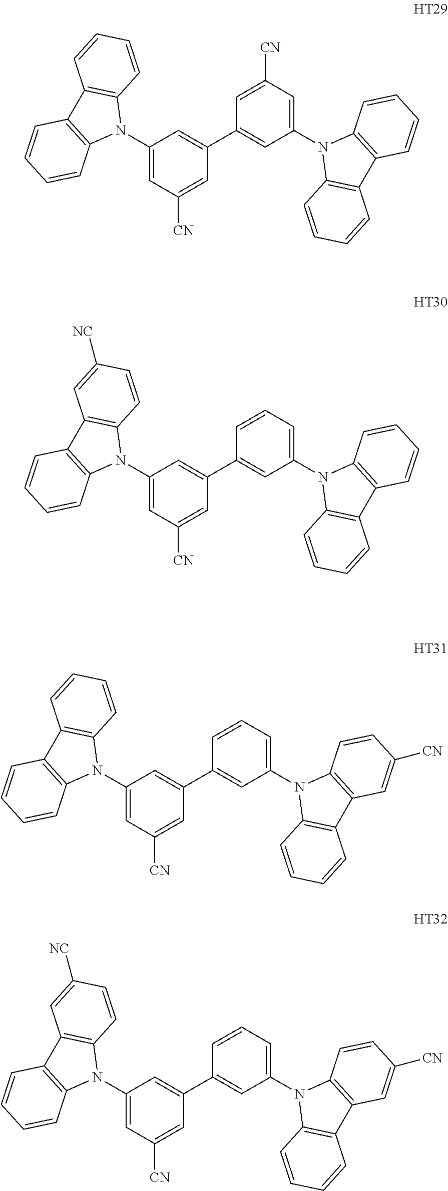 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

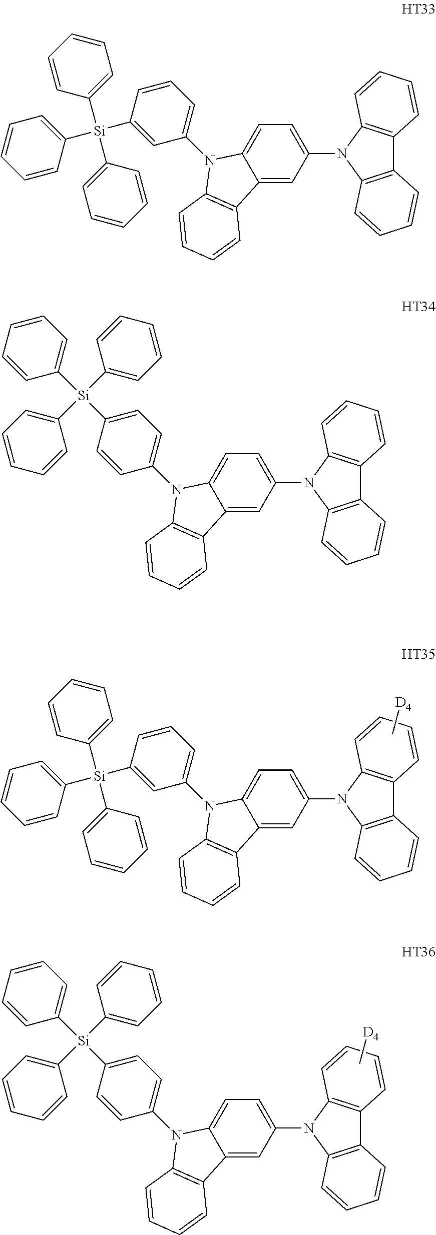

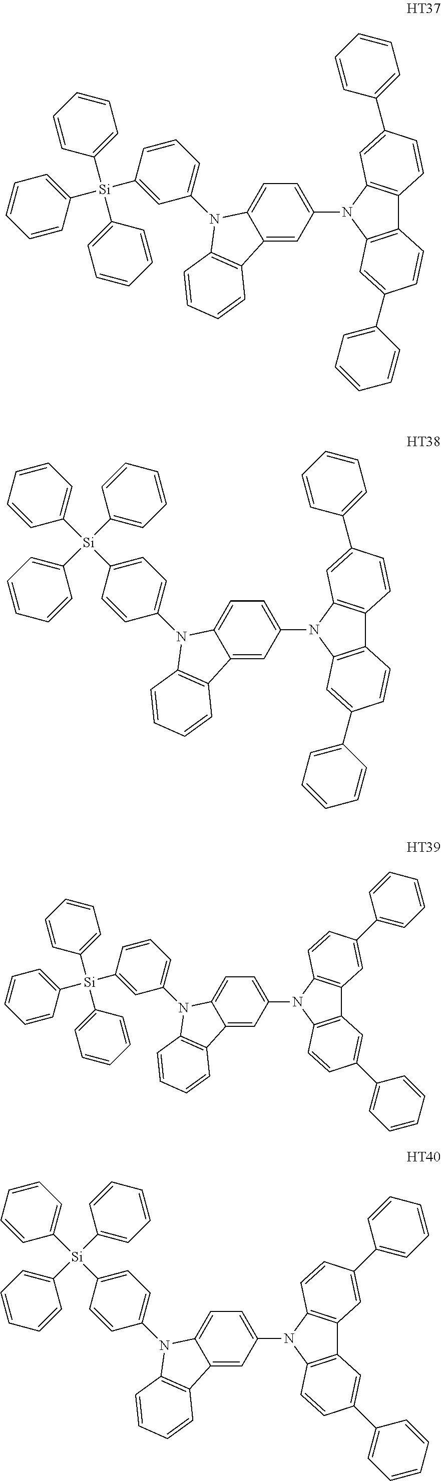 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

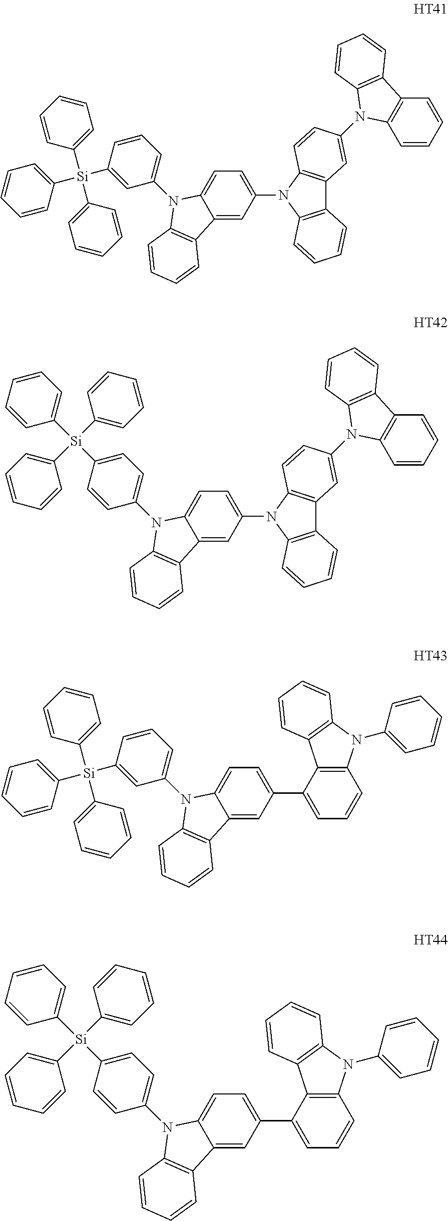 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

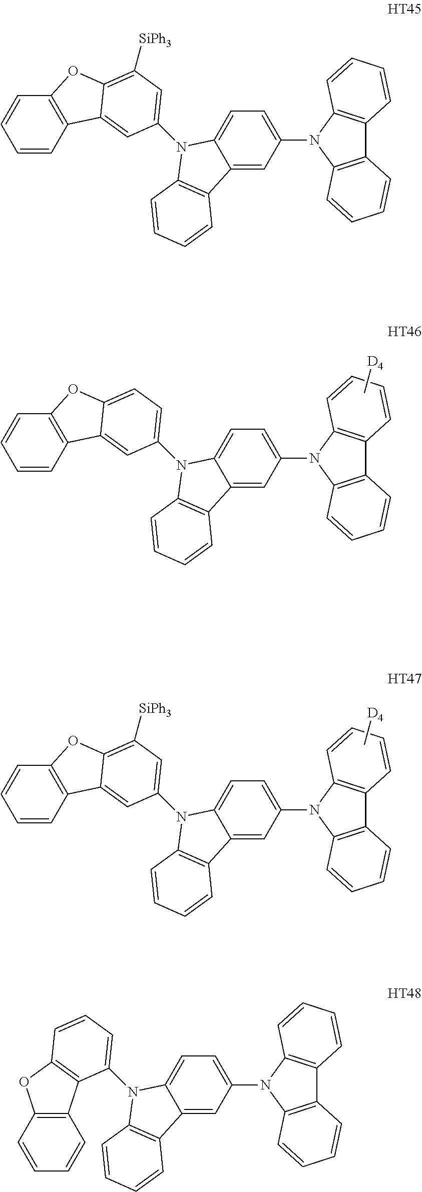

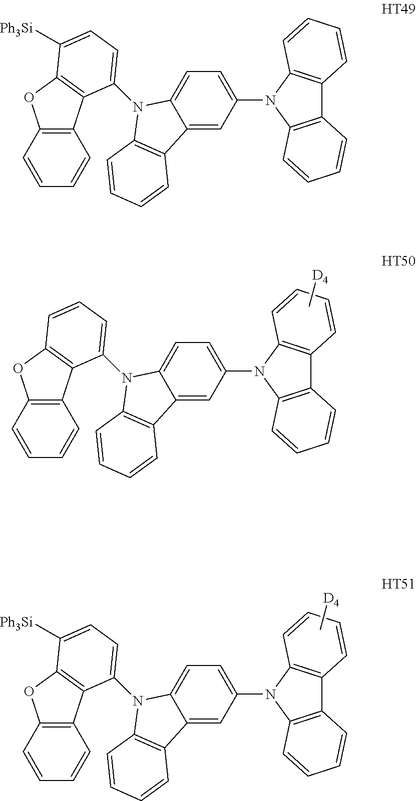

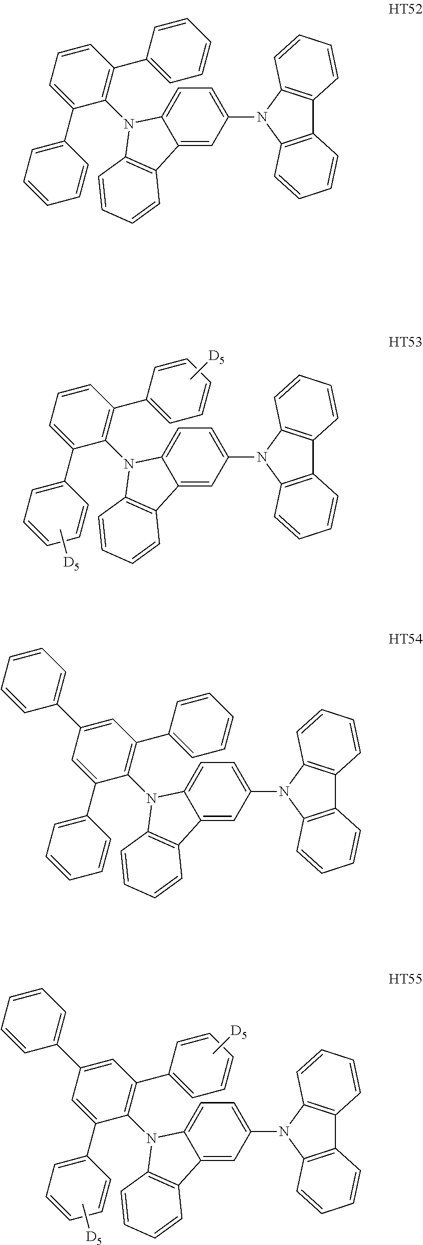

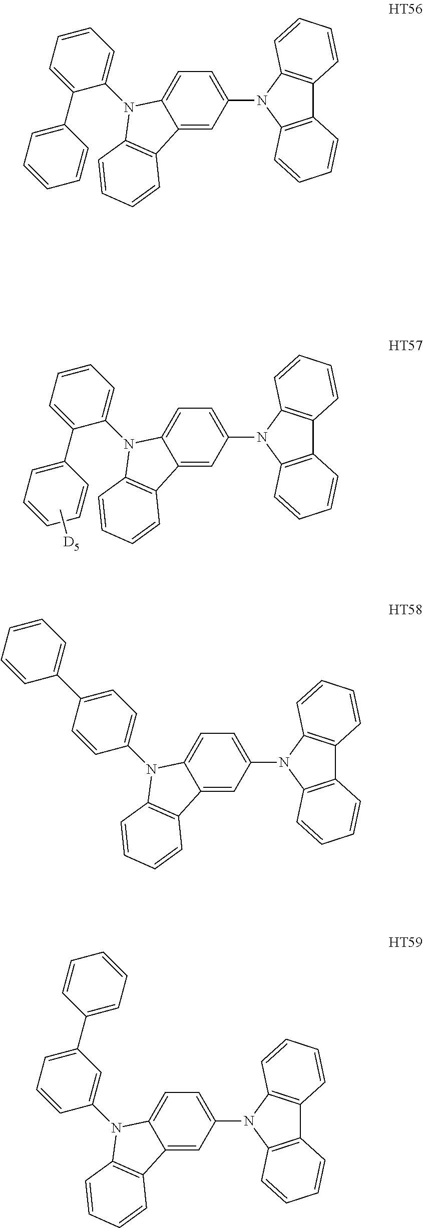

In the compounds presented in Compound Group 2, “D” refers to a deuterium atom, and “Ph” refers to a substituted or unsubstituted phenyl group. For example, in the compounds presented in Compound Group 2, “Ph” may refer to an unsubstituted phenyl group.

In one or more embodiments, the emission layer EML may include the third compound represented by Formula ET-1. For example, the third compound may be used as an electron transport host material for the emission layer EML.

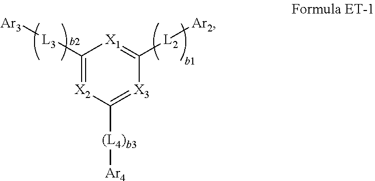

In Formula ET-1, at least one selected from among X₁ to X₃ may be N, and the rest may be CR₅₆. For example, any one selected from among X₁ to X₃ may be N, and the rest may each independently be CR₅₆. In this case, the third compound represented by Formula ET-1 may include a pyridine moiety. In one or more embodiments, two selected from among X₁ to X₃ may be N, and the rest may be CR₅₆. In this case, the third compound represented by Formula ET-1 may include a pyrimidine moiety. In one or more embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are integers of 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be represented by any one selected from among the compounds in Compound Group 3. The light emitting element ED of one or more embodiments may include at least (e.g., any) one selected from among the compounds in Compound Group 3.

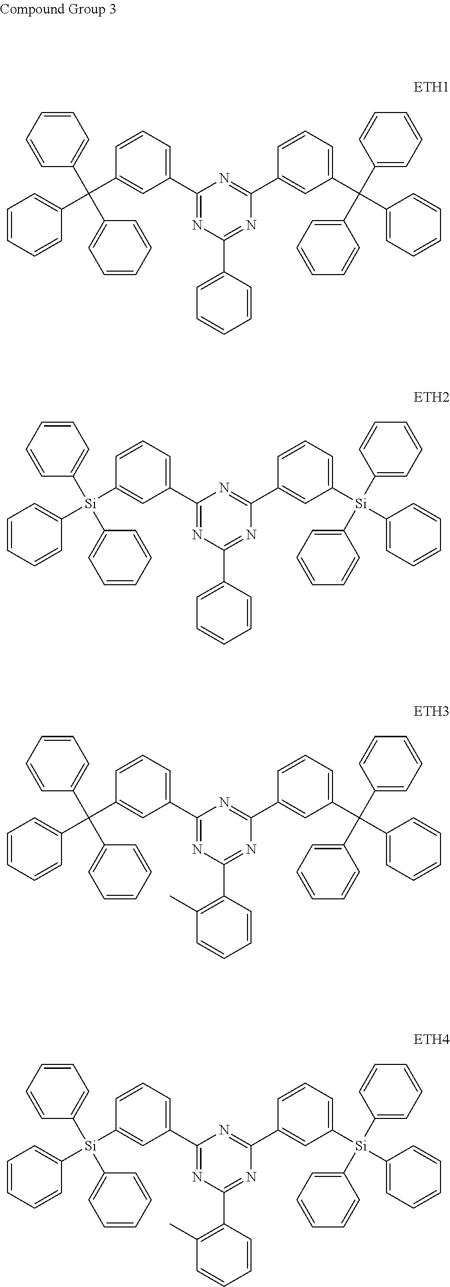 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

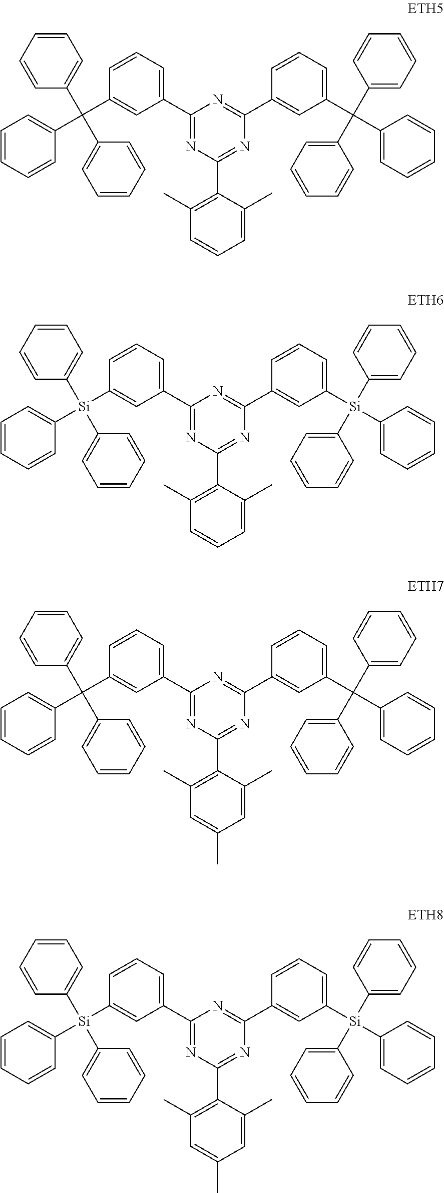 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

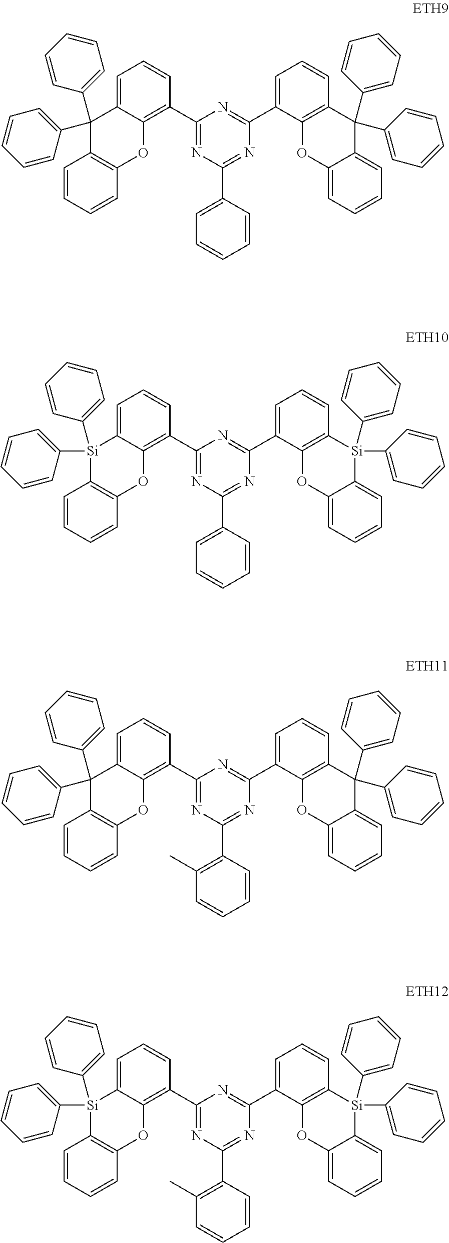 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

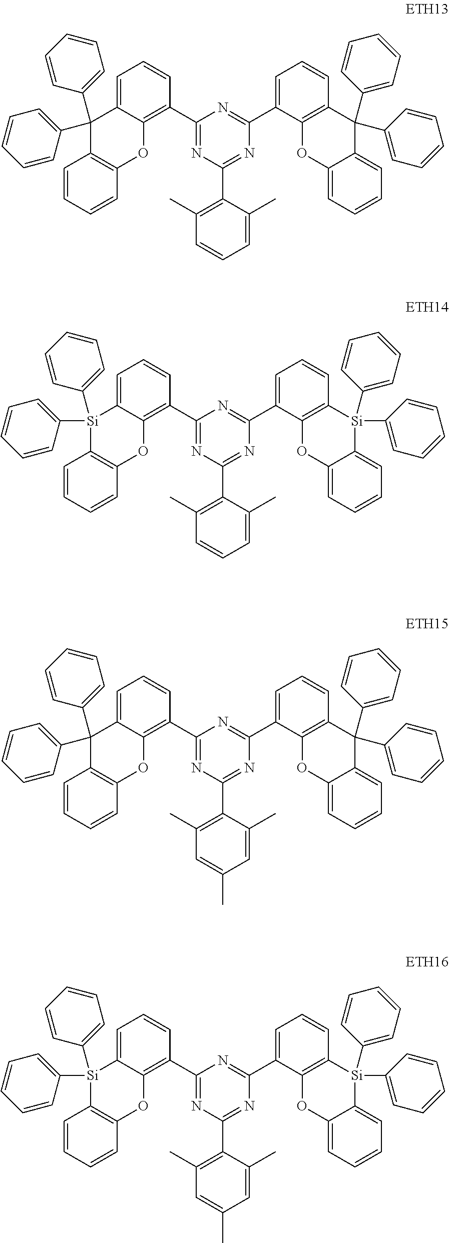 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

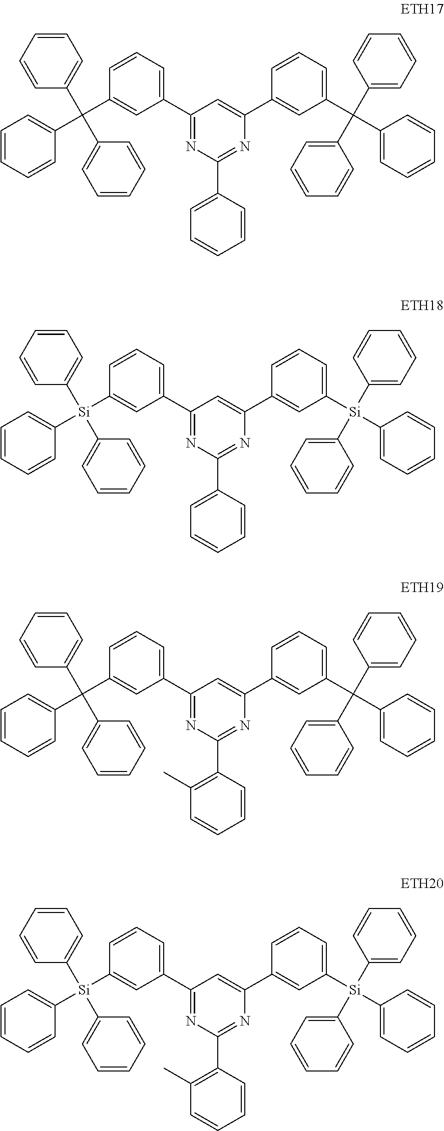 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

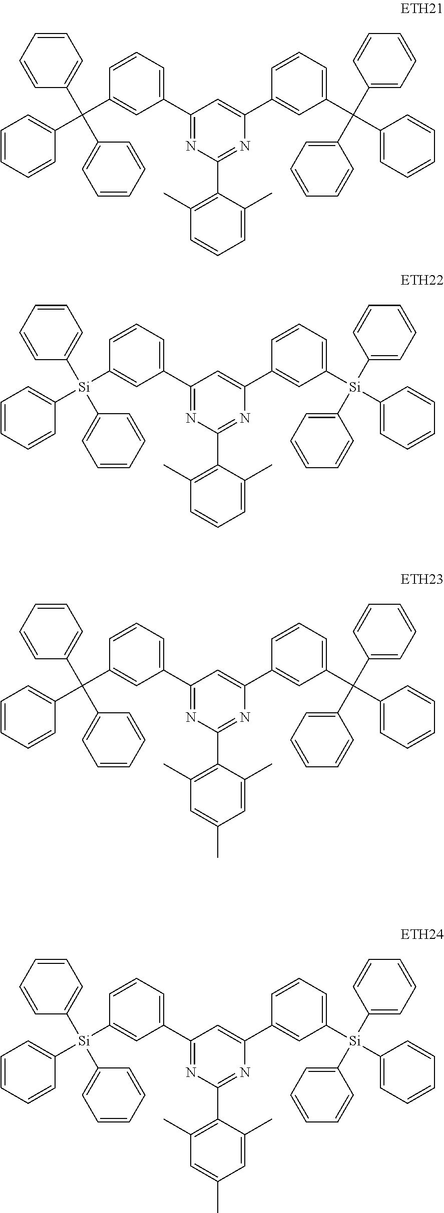 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

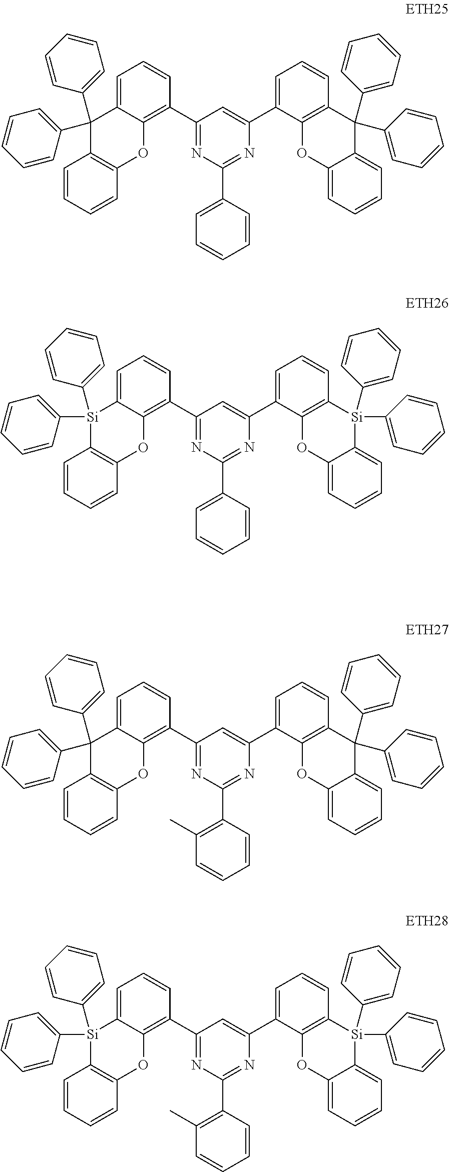 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

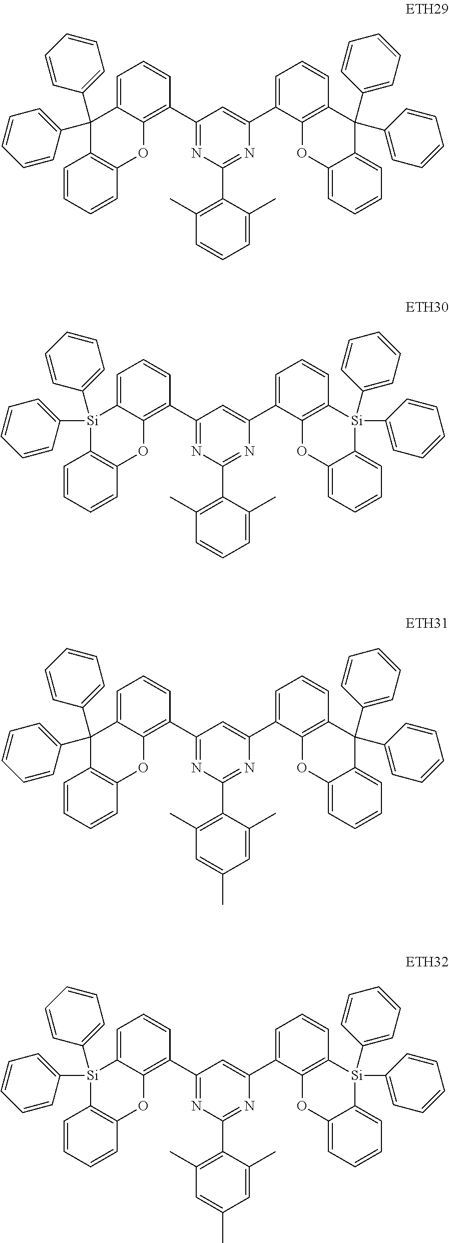 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

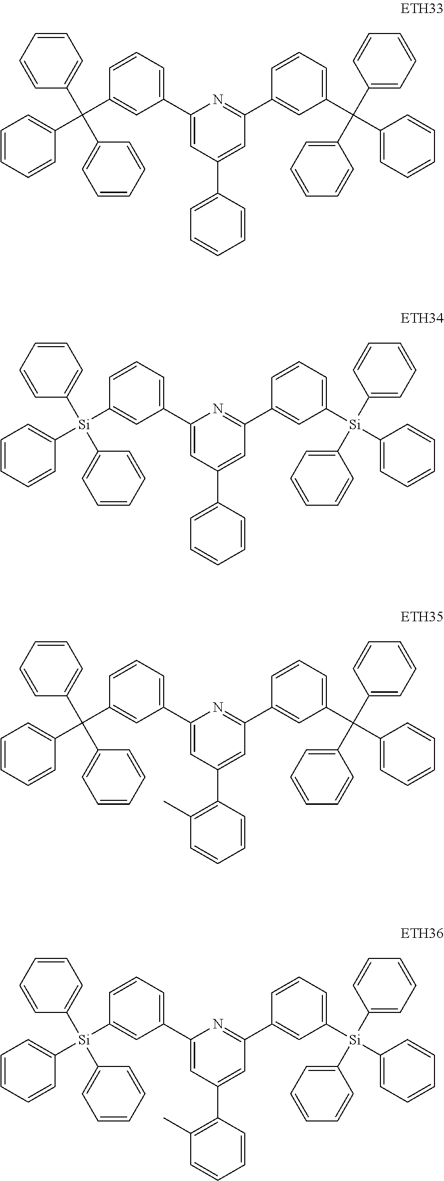 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

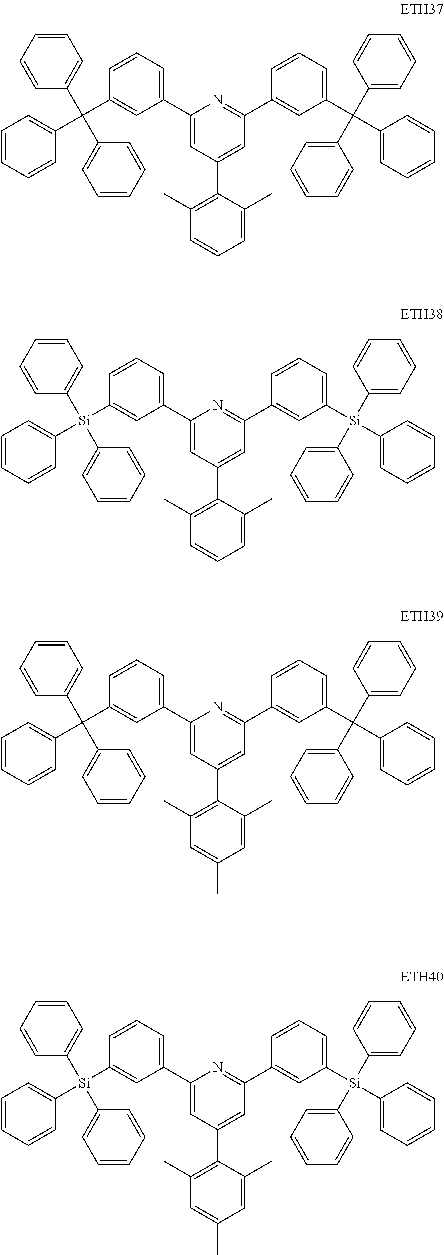 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

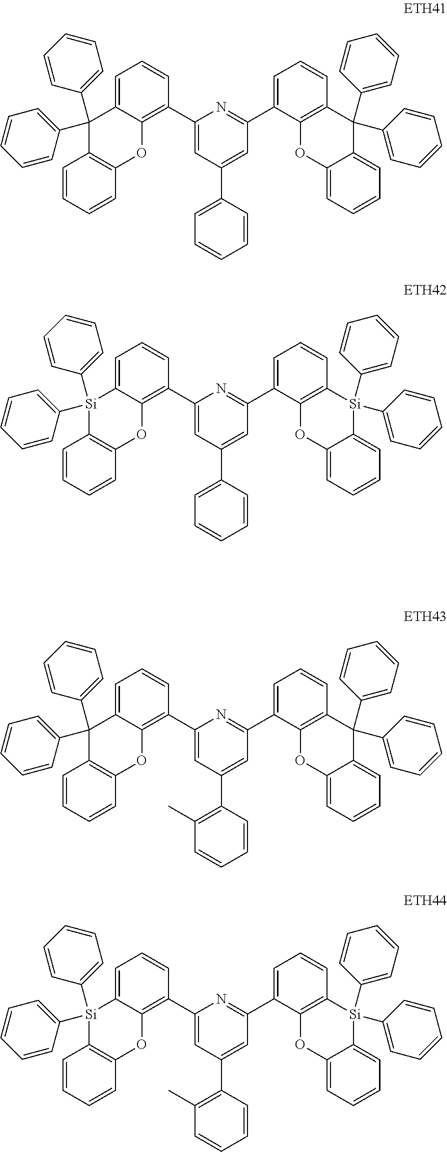 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

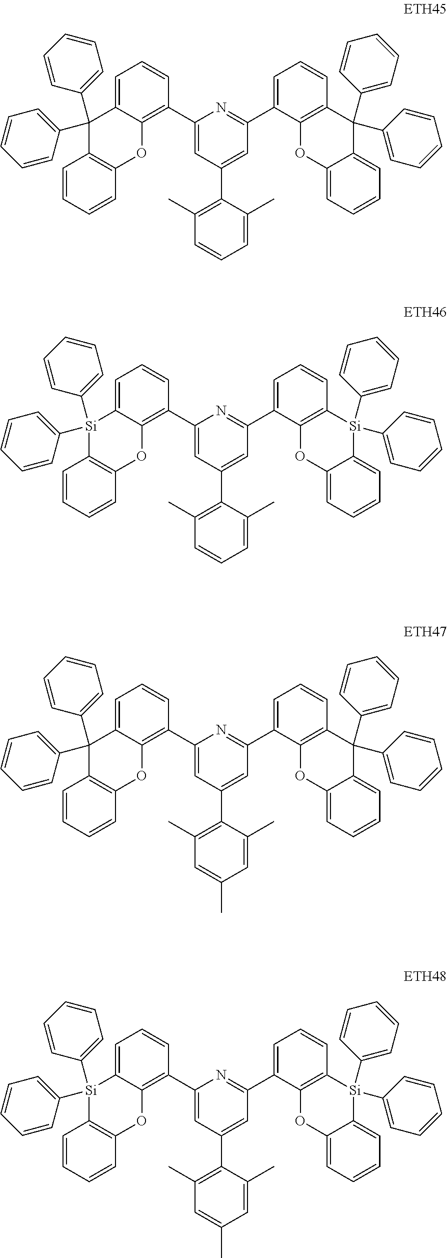 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

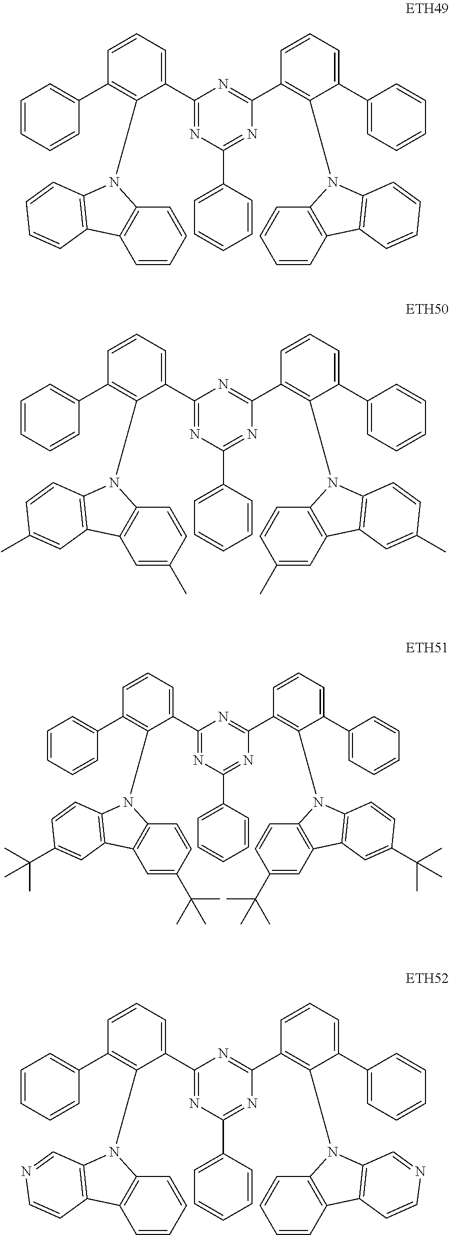

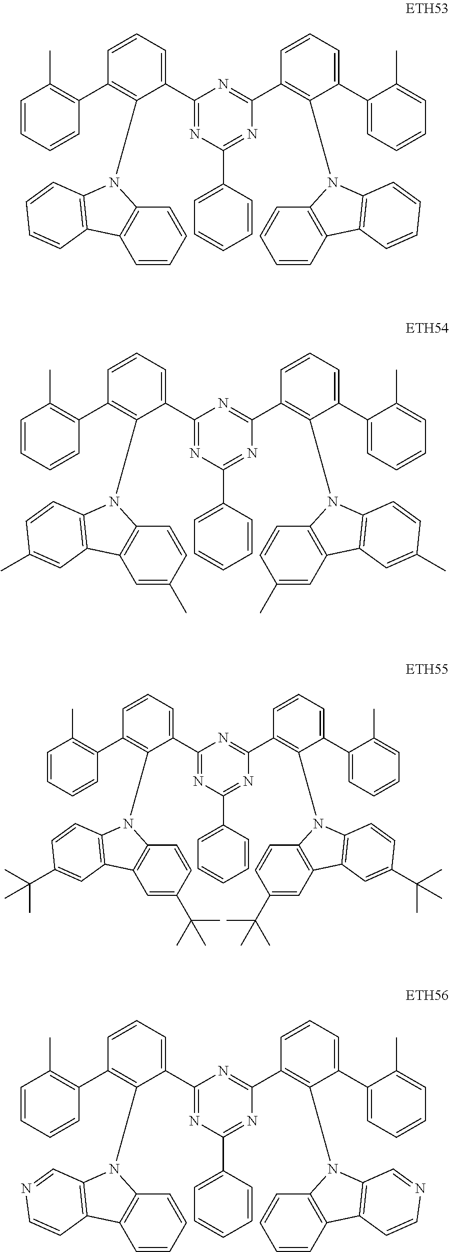

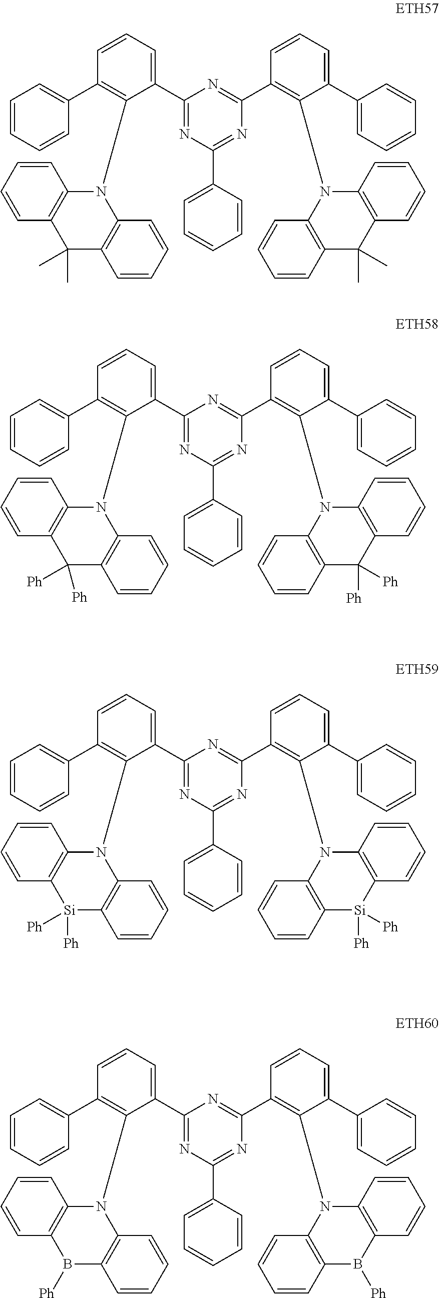

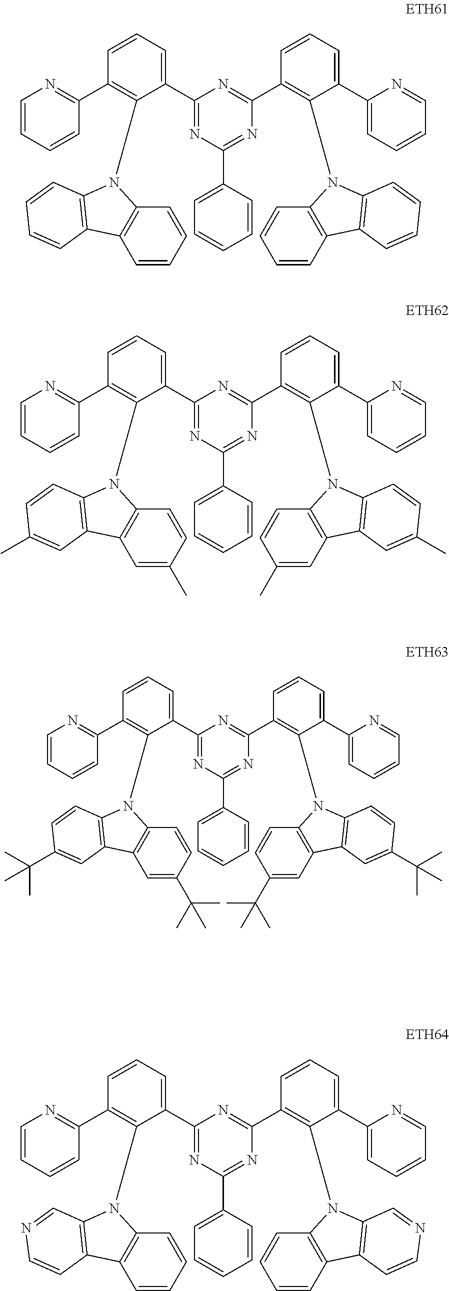

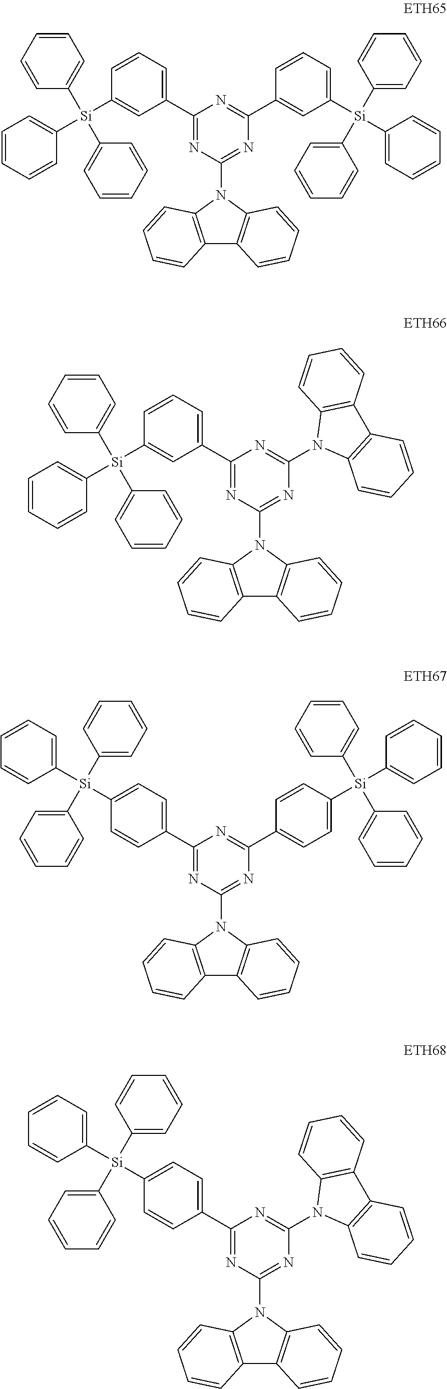 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

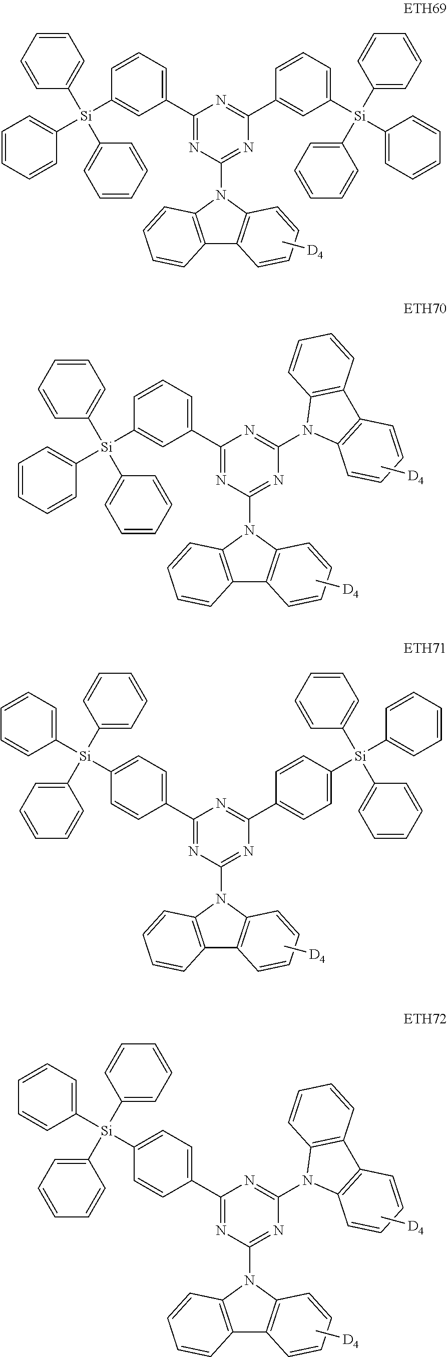

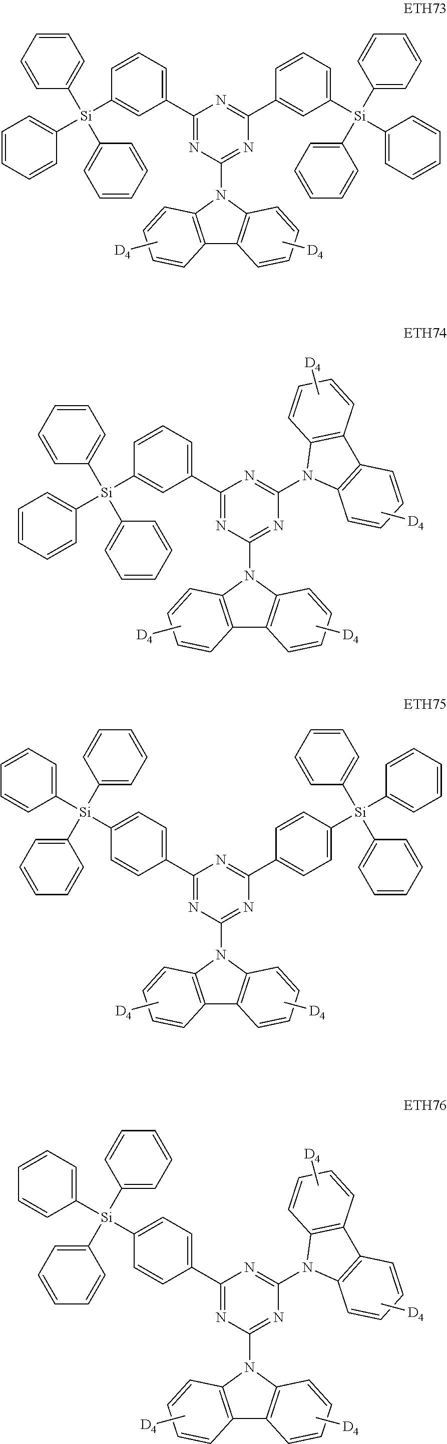

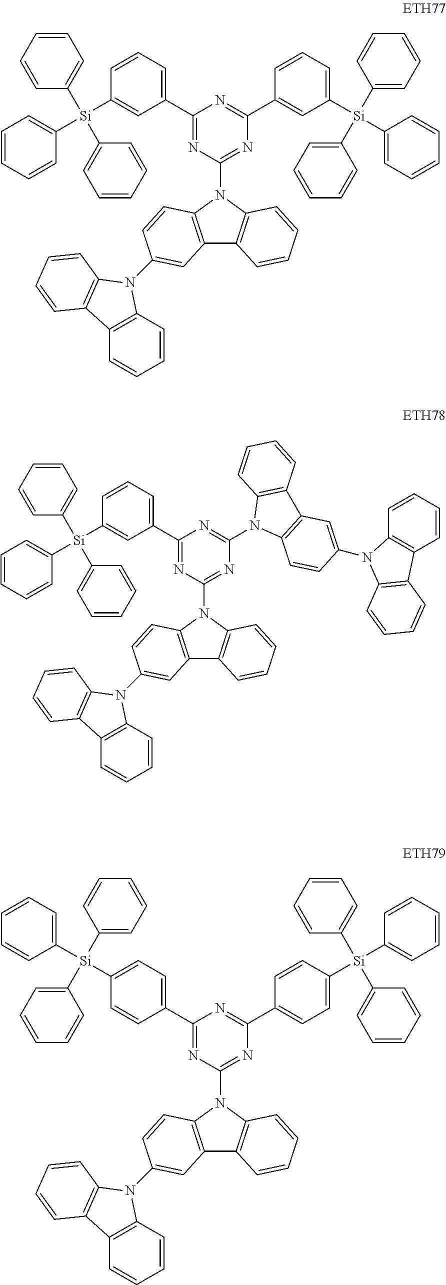 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

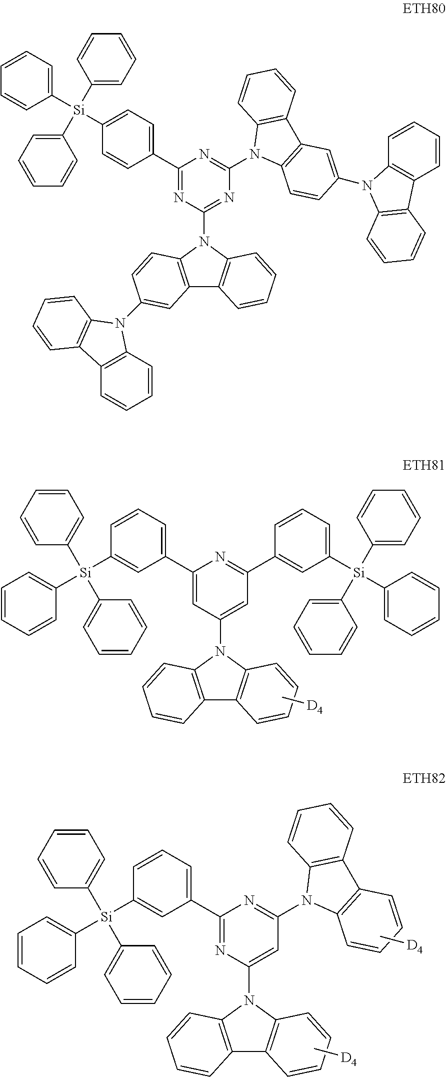

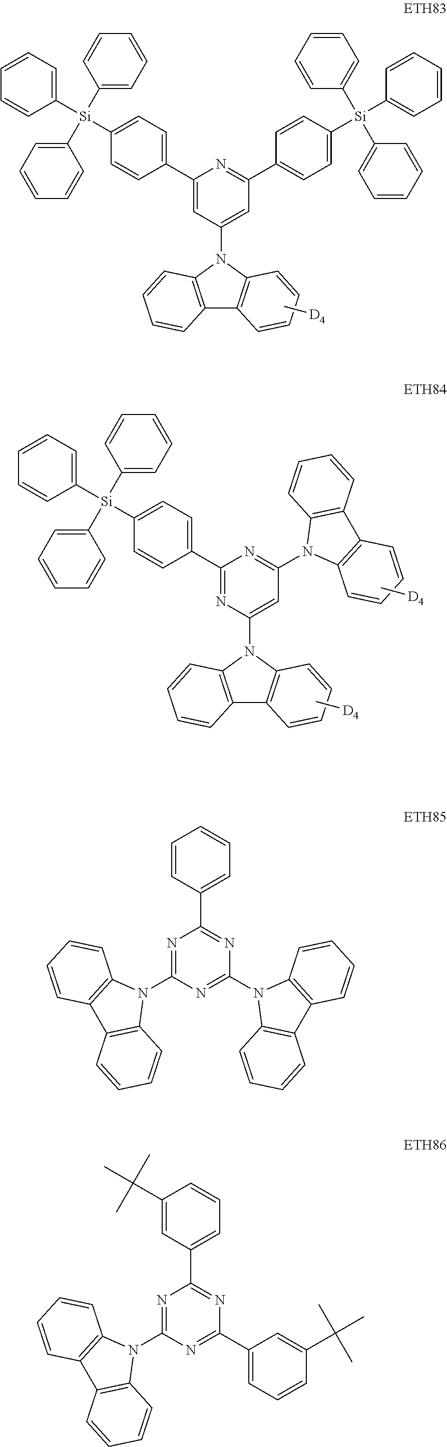

In the compounds presented in Compound Group 3, “D” refers to a deuterium atom, and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be in the range of about 2.4 eV to about 3.0 eV. In one or more embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described herein. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

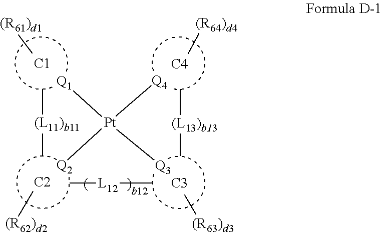

In Formula D-1, Q₁ to 04 may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage (e.g., a single covalent bond), *—O—*, *—S—*,

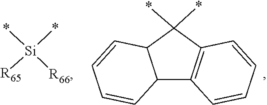

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*” refers to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be a hydrogen atom, a deuterium atom, a halogen atom (e.g., F, Cl, Br, or I), a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₆₁ to R₆₆ may be bonded to an adjacent group to form a ring. R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The case where each of d1 to d4 is 4 and R₆₁'s to R₆₄′ are each hydrogen atoms may be the same as the case where each of d1 to d4 is 0. If (e.g., when) each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

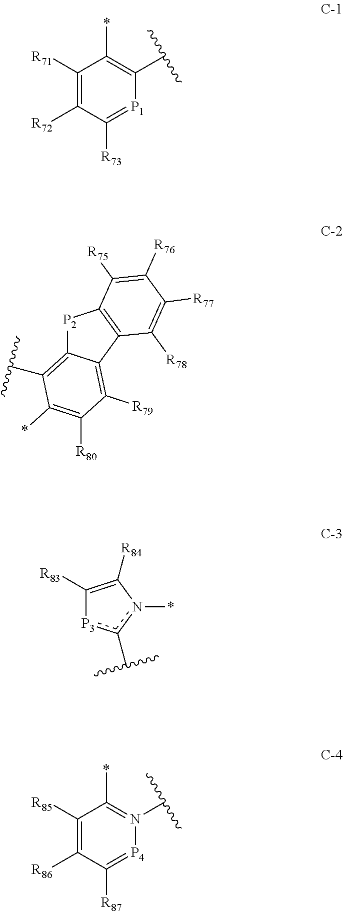

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in C-1 to C-4,

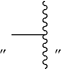

corresponds to a part linked to Pt that is a central metal atom, and “—*” corresponds to a part linked to a neighboring cyclic group (C1 to C4) or a linker (L₁₁ to L₁₃).

The emission layer EML of one or more embodiments may include the first compound, which is a fused polycyclic compound, and at least one selected from among the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, the fourth compound serving as an auxiliary dopant may accelerate energy delivery to the first compound that is a light emitting dopant, thereby increasing the emission ratio of the first compound. Therefore, the emission layer EML of one or more embodiments may improve or enhance luminous efficiency. In one or more embodiments, if (e.g., when) the energy delivery to the first compound is increased, an exciton formed in the emission layer EML is not accumulated inside the emission layer EML and emits light rapidly, and thus deterioration (e.g., a degree or occurrence of deterioration) of the device may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may include at least one selected from among the compounds represented by Compound Group 4. The emission layer EML may include at least one selected from among the compounds represented by Compound Group 4 as a sensitizer material.

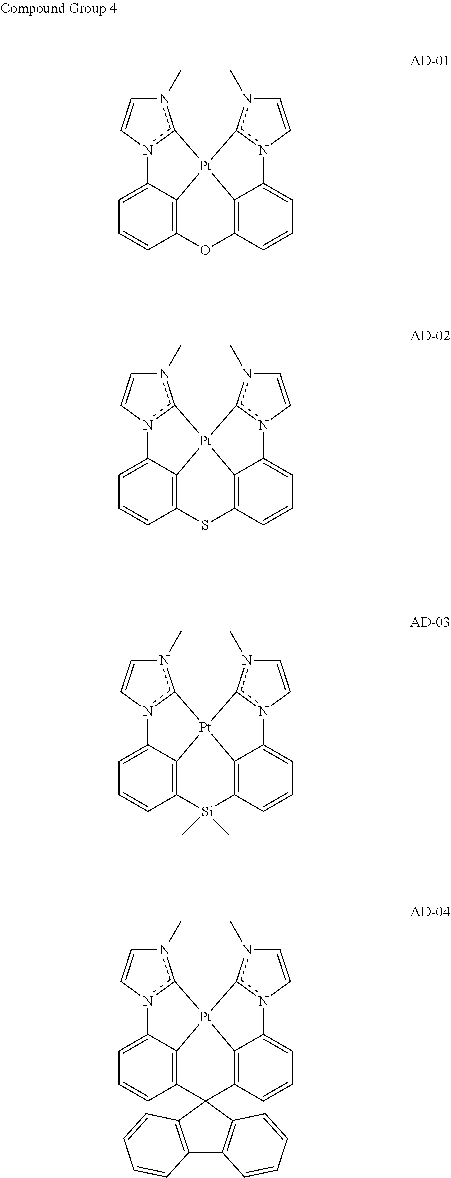

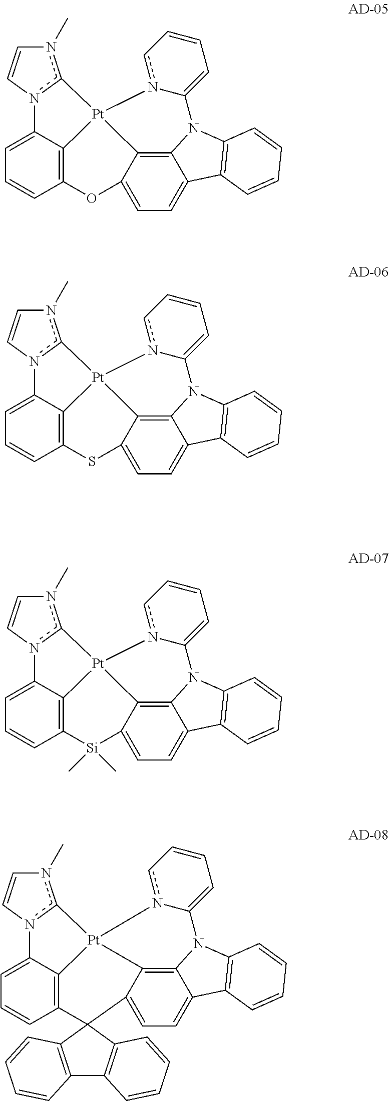

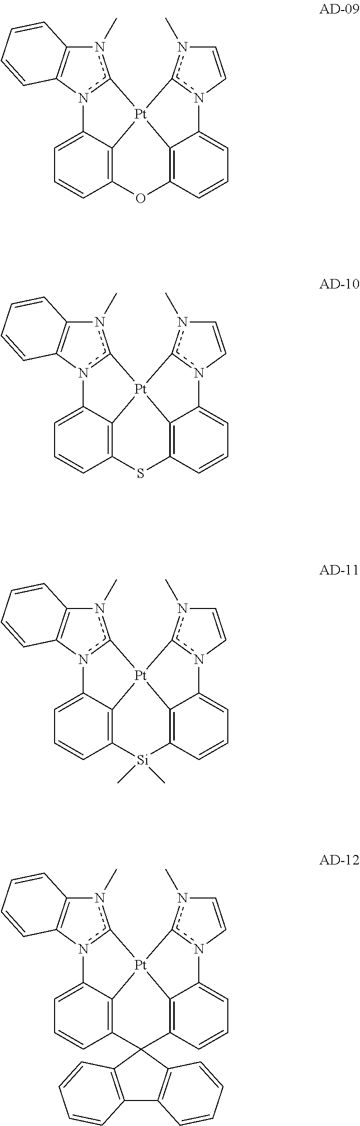

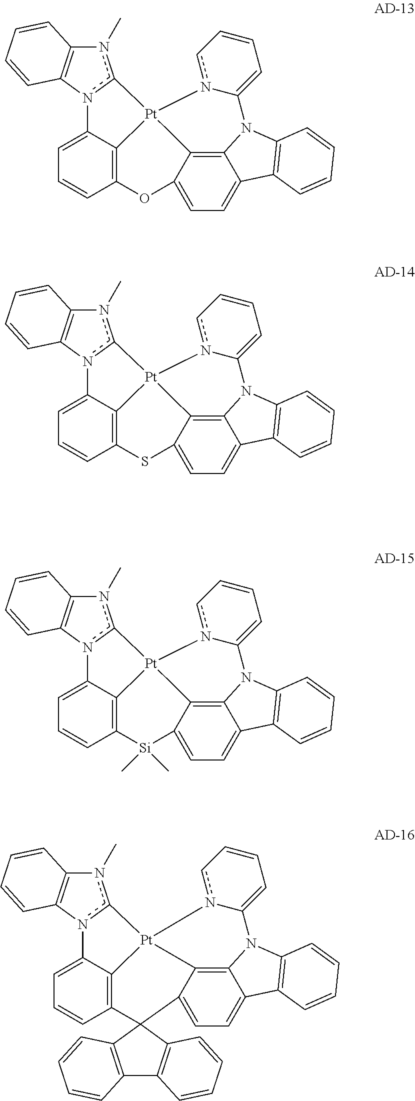

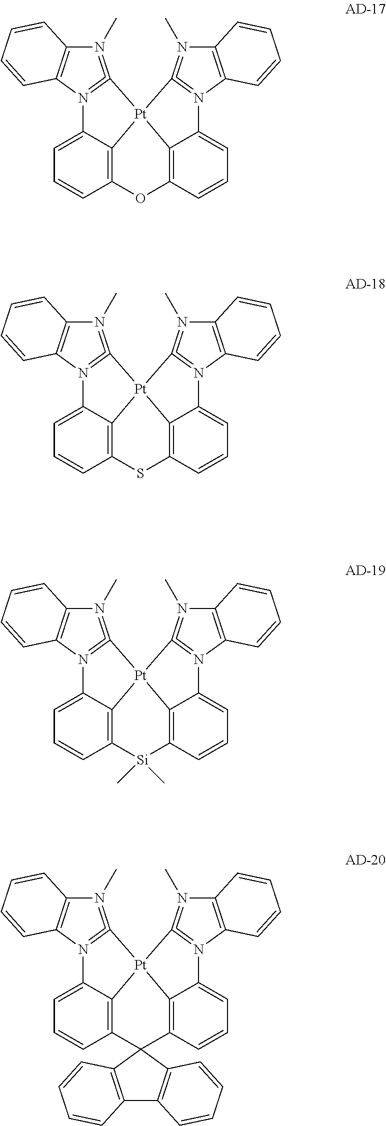

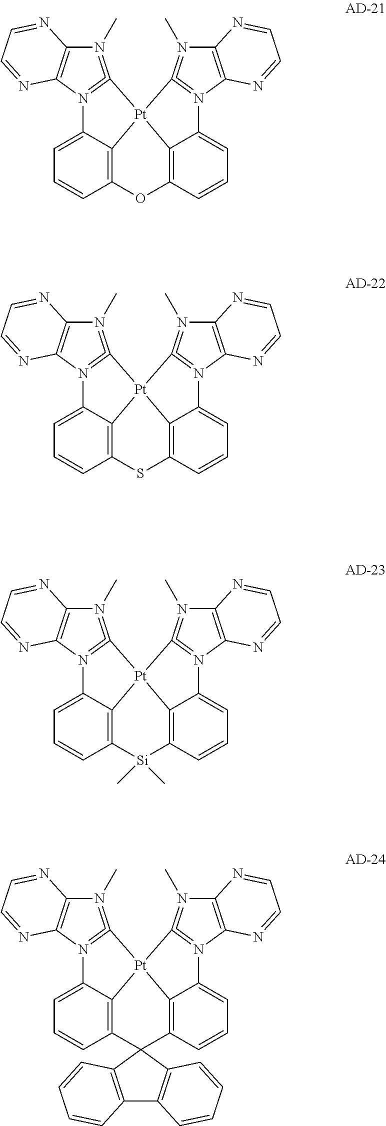

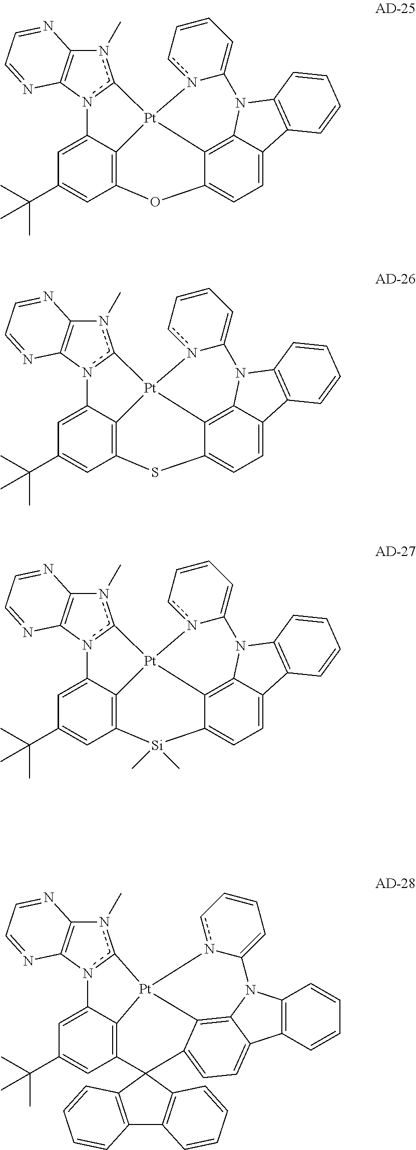

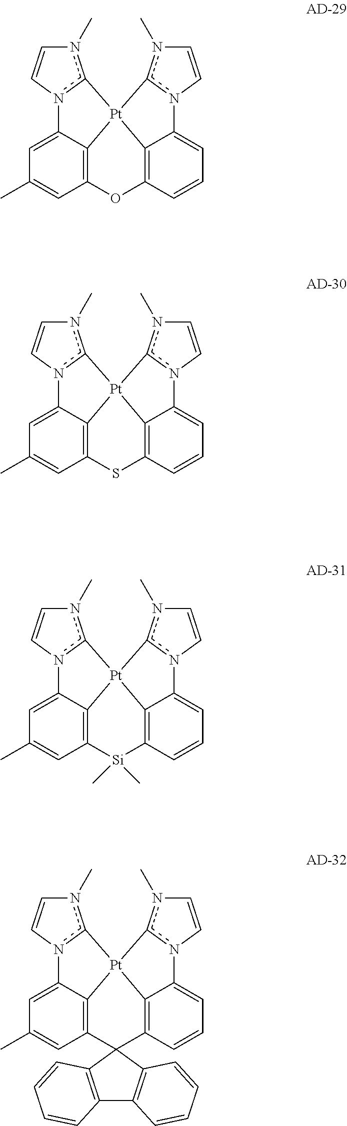

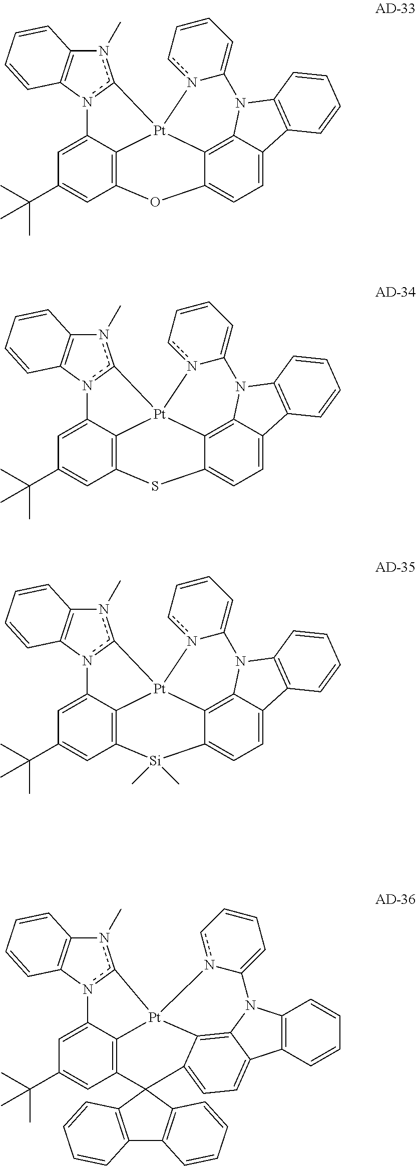

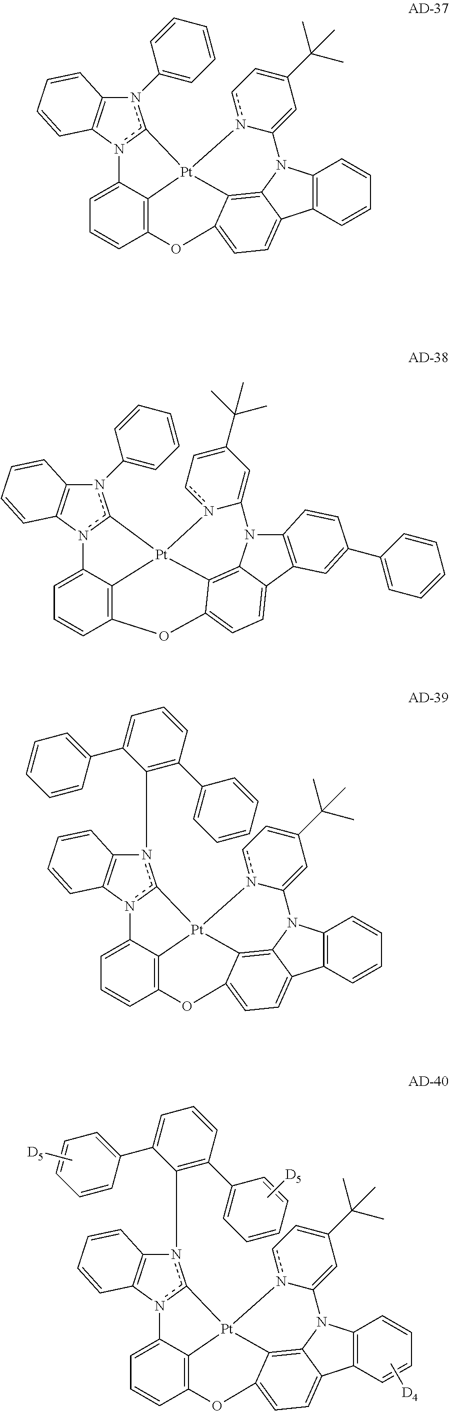

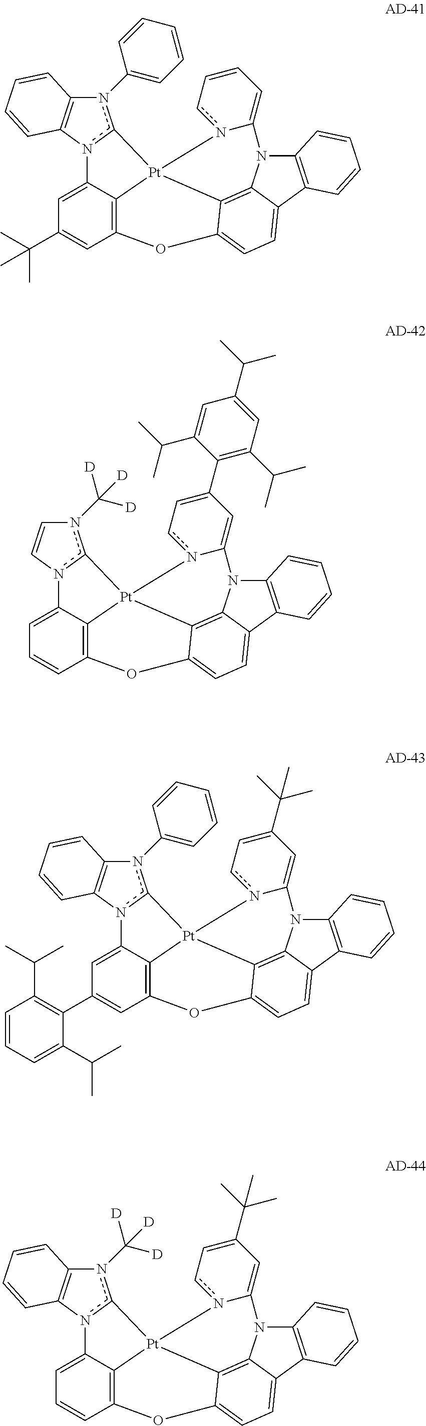

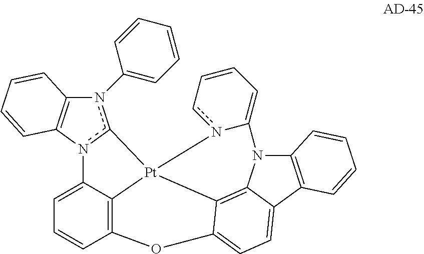

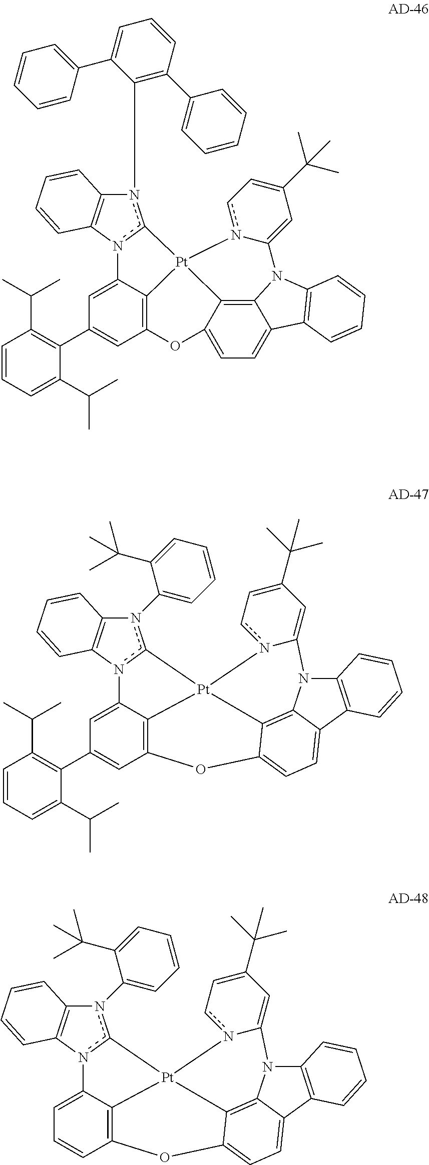

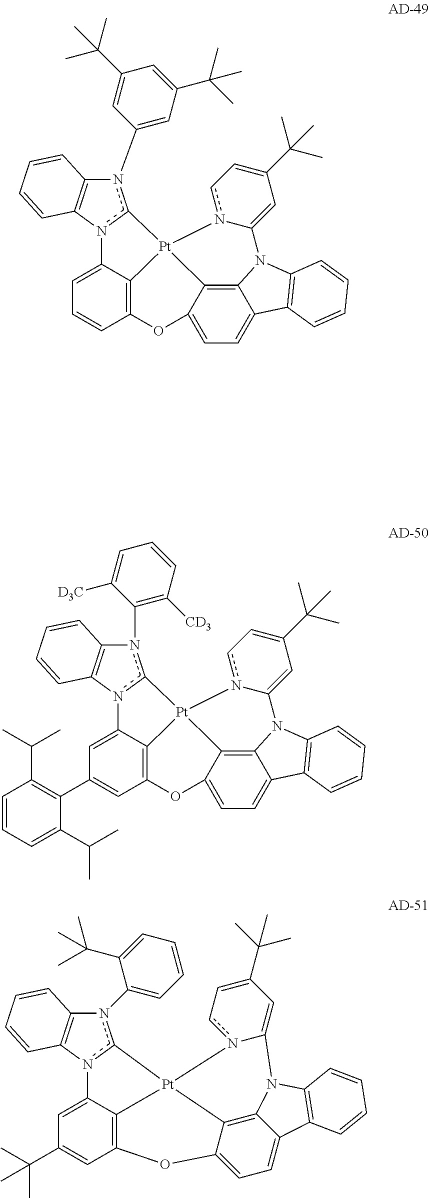

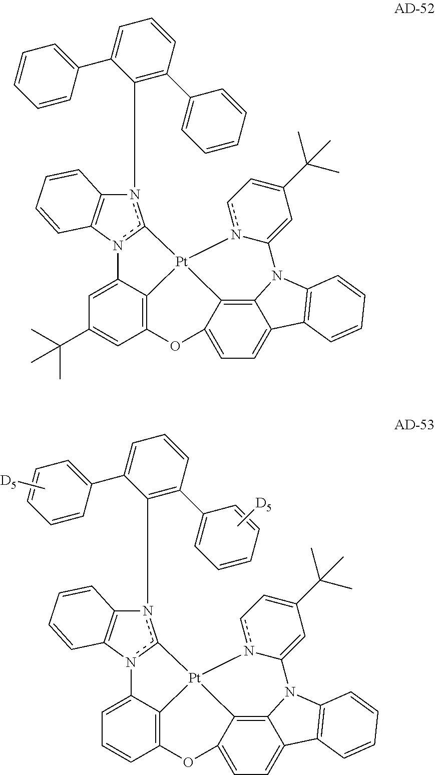

In the compounds presented in Compound Group 4, “D” refers to a deuterium atom.

If (e.g., when) the emission layer EML in the light emitting element ED of one or more embodiments includes all of the first compound, the second compound, and the third compound, with respect to the total weight (e.g., based on a total of 100 wt %) of the first compound, the second compound, and the third compound, the content (e.g., amount) of the first compound may be in the range of about 0.1 wt % to about 5 wt %. However, embodiments of the present disclosure are not limited thereto. If (e.g., when) the content (e.g., amount) of the first compound satisfies the proportion described herein, the energy transfer from the second compound and the third compound to the first compound may increase, and thus the luminous efficiency and element service life may increase.

The contents (e.g., amounts) of the second compound and the third compound in the emission layer EML may be the rest excluding the weight of the first compound. For example, the contents (e.g., amounts) of the second compound and the third compound in the emission layer EML may be in the range of about 65 wt % to about 95 wt % with respect to the total weight (e.g., based on a total of 100 wt %) of the first compound, the second compound, and the third compound.

In the total weight of the second compound and the third compound, the weight ratio of the second compound and the third compound may be in the range of about 3:7 to about 7:3.

If (e.g., when) the contents (e.g., amounts) of the second compound and the third compound satisfy the foregoing ratio, a charge balance characteristic in the emission layer EML may be improved or enhanced, and thus the luminous efficiency and device service life may increase. If (e.g., when) the contents (e.g., amounts) of the second compound and the third compound deviate from the foregoing ratio range, a charge balance in the emission layer EML may be broken, and thus the luminous efficiency may be reduced and the device may be easily deteriorated.

If (e.g., when) the emission layer EML includes the fourth compound, the content (e.g., amount) of the fourth compound in the emission layer EML may be in the range of about 10 wt % to about 30 wt % with respect to the total weight (e.g., based on a total of 100 wt %) of the first compound, the second compound, the third compound, and the fourth compound. However, embodiments of the present disclosure are not limited thereto. If (e.g., when) the content (e.g., amount) of the fourth compound satisfies the content (e.g., amount) described herein, the energy delivery from the host to the first compound which is a light emitting dopant may be increased, thereby a luminous ratio may be improved or enhanced, and thus the luminous efficiency of the emission layer EML may be improved or enhanced. If (e.g., when) the first compound, the second compound, the third compound, and the fourth compound included in the emission layer EML satisfy the content (e.g., amount) ratio range described herein, excellent or suitable luminous efficiency and long service life may be achieved.

The emission layer EML may be provided on the hole transport region HTR. The emission layer EML may have a thickness of, for example, about 100 Å to about 1,000 Å or about 100 Å to about 300 Å. The emission layer EML may have a single layer formed or composed of a single material, a single layer formed or composed of a plurality of different materials, or a multilayer structure having a plurality of layers formed or composed of a plurality of different materials.

The emission layer EML may further include a compound described herein in addition to the fused polycyclic compound of one or more embodiments.

In the light emitting element ED of one or more embodiments, the emission layer EML may include an anthracene derivative, a pyrene derivative, a fluoranthene derivative, a chrysene derivative, a dihydrobenzanthracene derivative, and/or a triphenylene derivative. For example, the emission layer EML may include the anthracene derivative and/or the pyrene derivative.

In each light emitting element ED of one or more embodiments illustrated in FIGS. 3 to 6, the emission layer EML may further include a host and a dopant that are generally available or generally used besides the host and dopant described herein, and, for example, the emission layer EML may include a compound represented by Formula E-1. The compound represented by Formula E-1 may be used as a fluorescent host material.

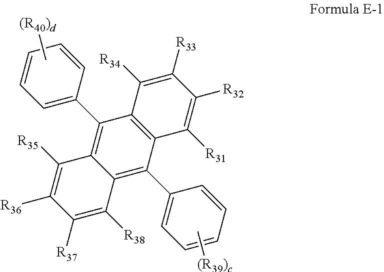

In Formula E-1, R₃₁ to R₄₀ may each independently be a hydrogen atom, a deuterium atom, a halogen atom (e.g., F, Cl, Br, or I), a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compound E21:

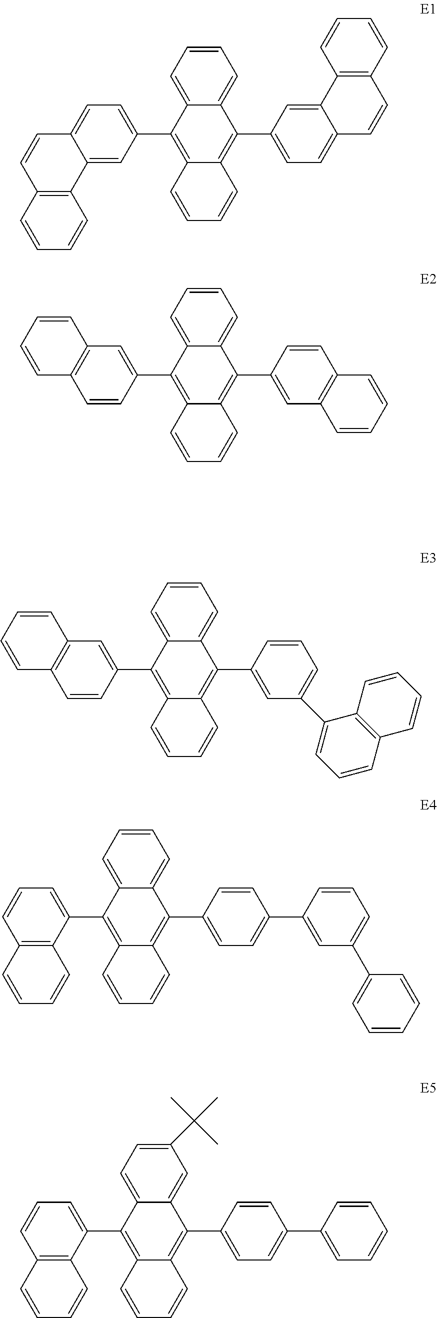

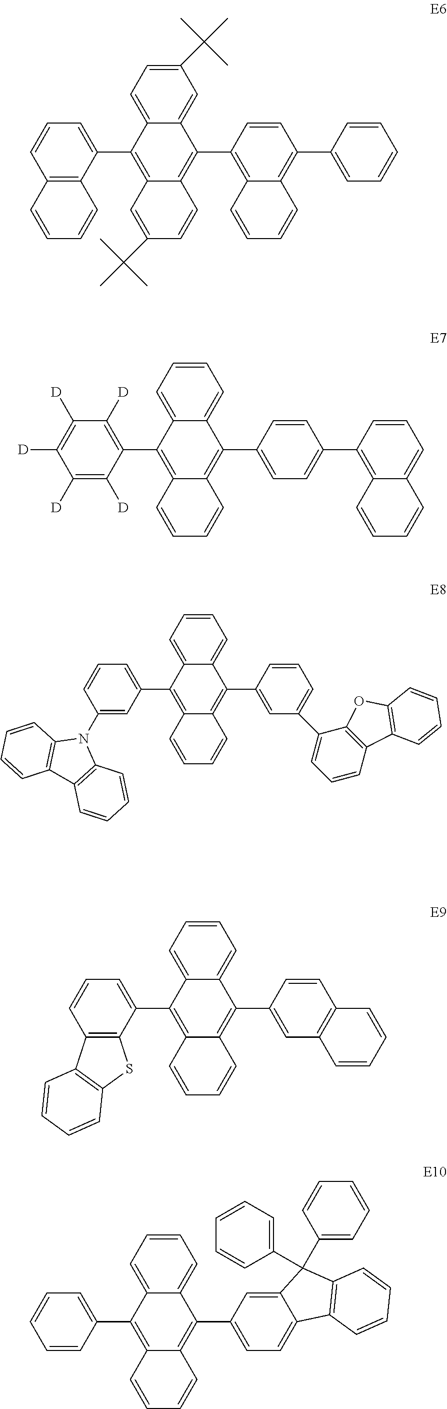

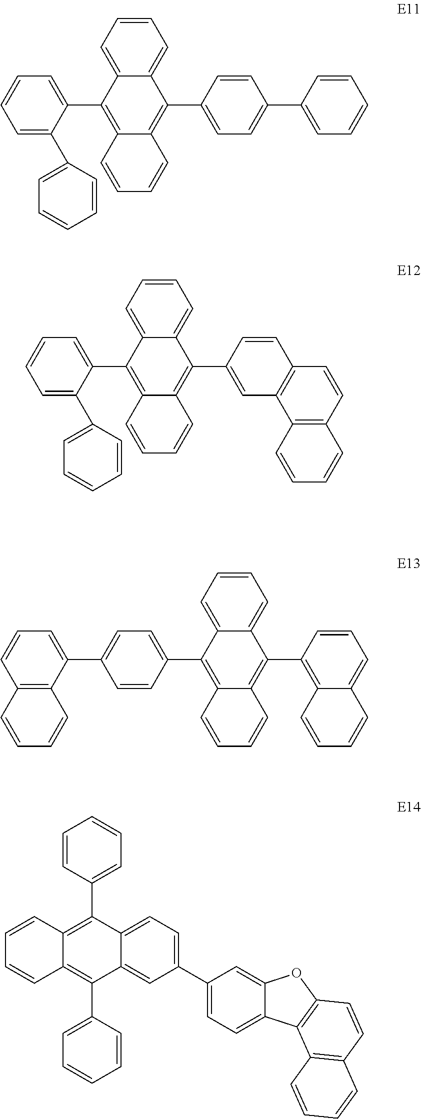

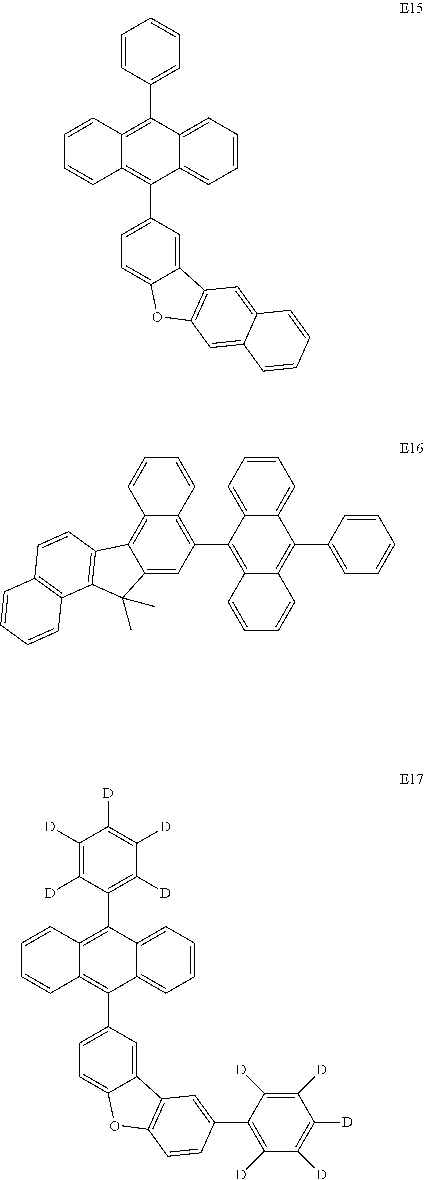

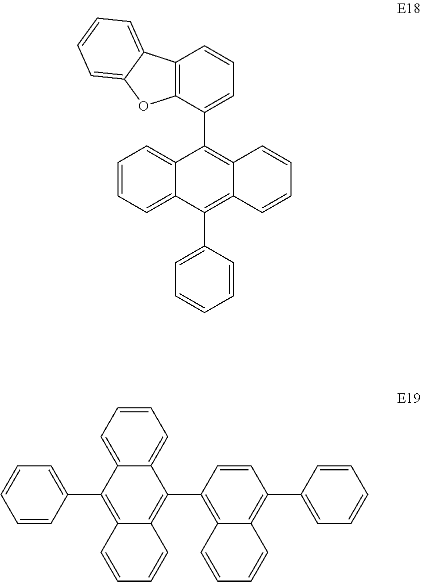

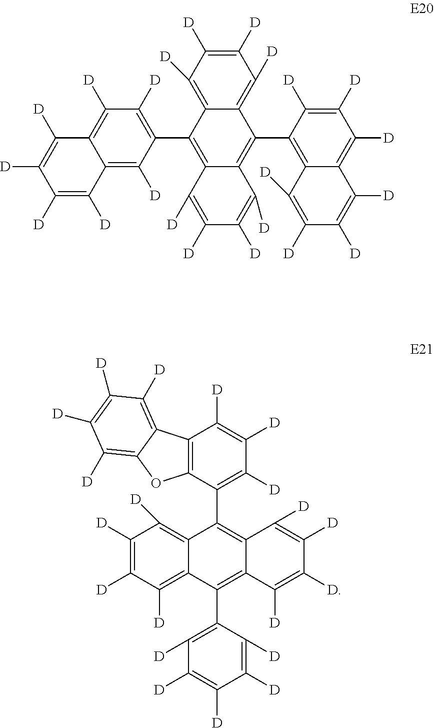

In one or more embodiments, the emission layer EML may include a compound represented by Formula E-2a or Formula E-2b. The compound represented by Formula E-2a or Formula E-2b may be used as a host material of a phosphorescent emission layer.

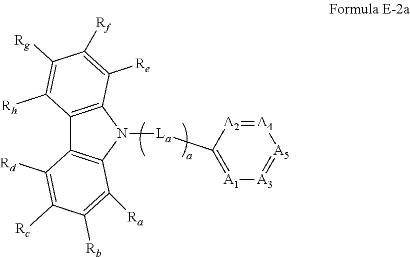

In Formula E-2a, a may be an integer of 0 to 10, and Lₐ may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In one or more embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

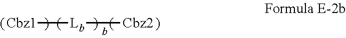

In Formula E-2b, Cbz1 and Cbz2 may each independently be an unsubstituted carbazole group or a carbazole group substituted with an aryl group having 6 to 30 ring-forming carbon atoms. L_{b} may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or more, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are examples, and the compound represented by Formula E-2a or Formula E-2b is not limited to those represented in Compound Group E-2.

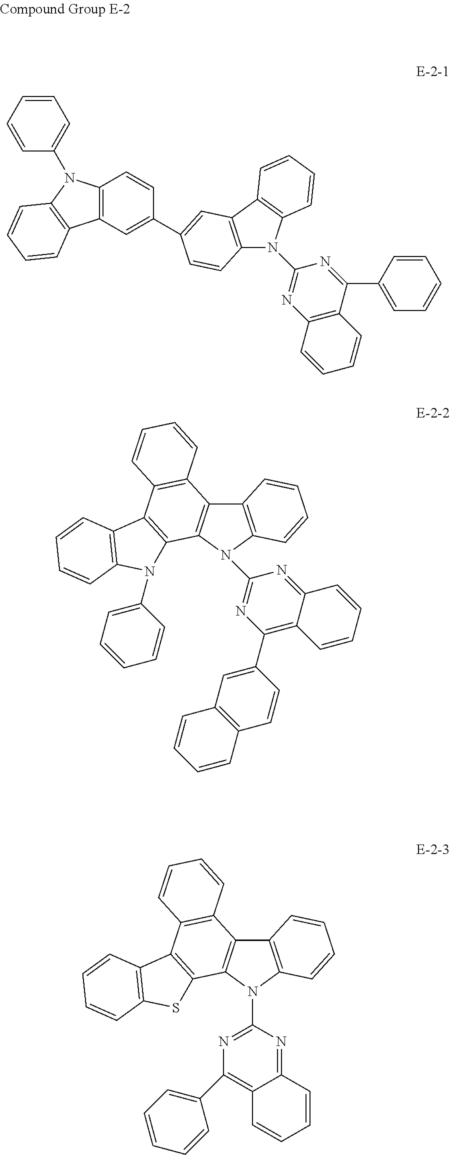 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

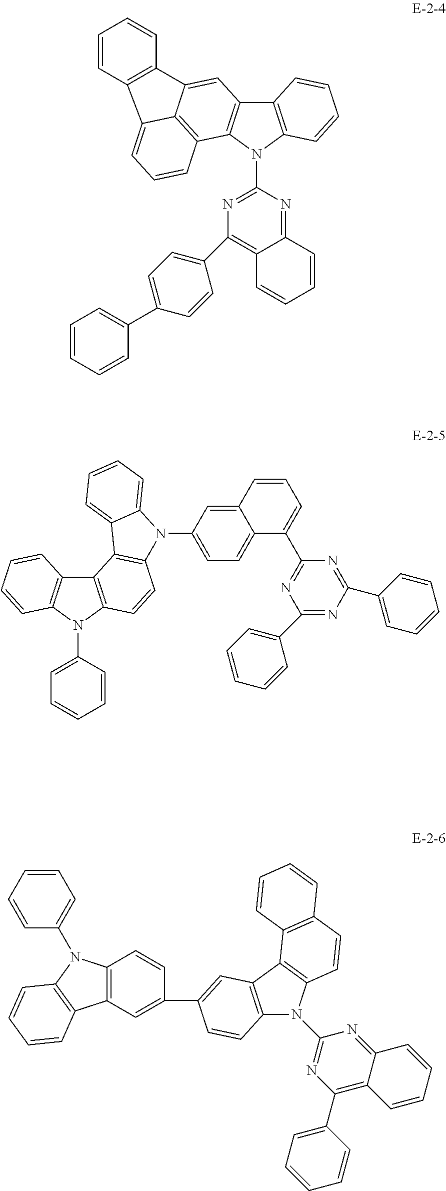 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

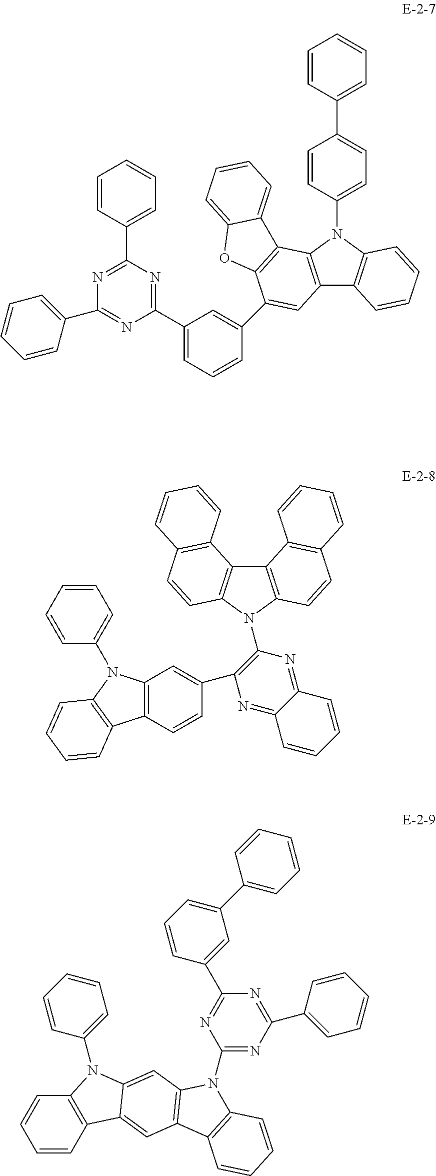 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

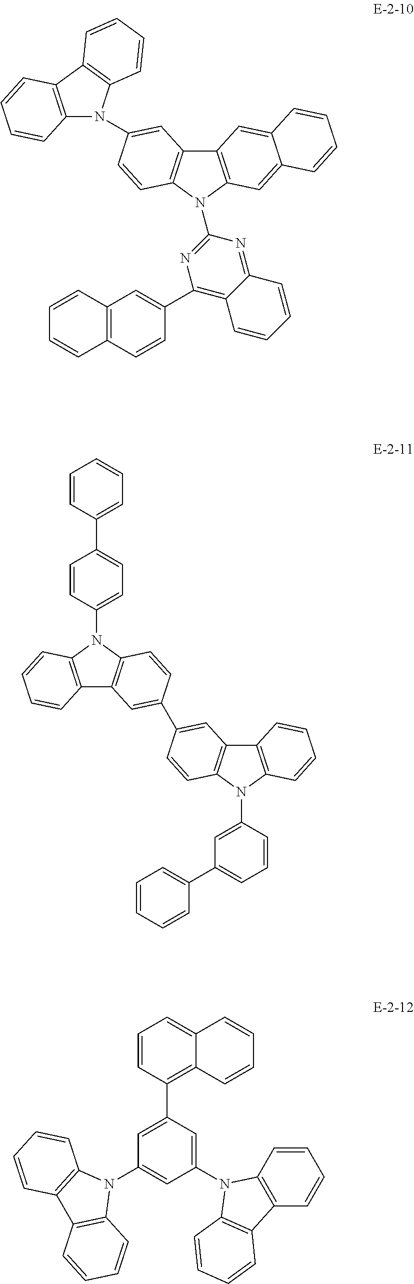 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

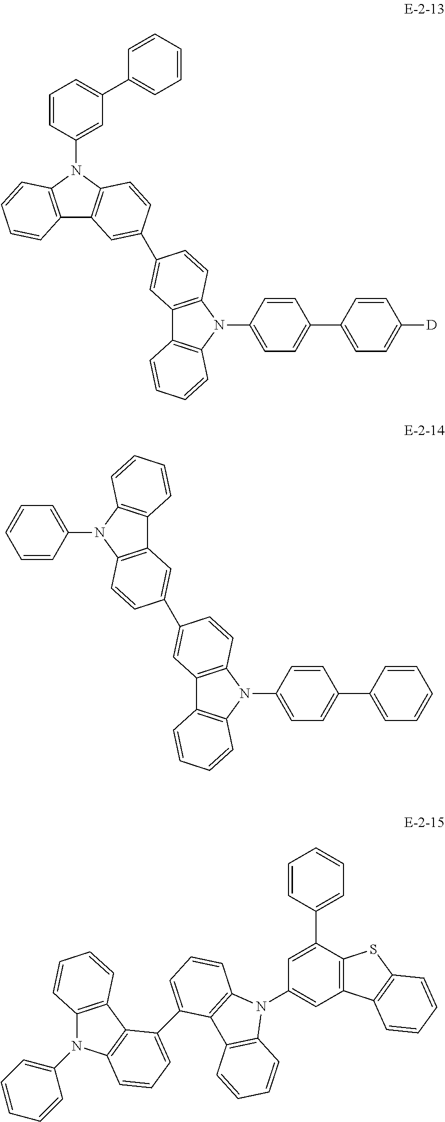 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

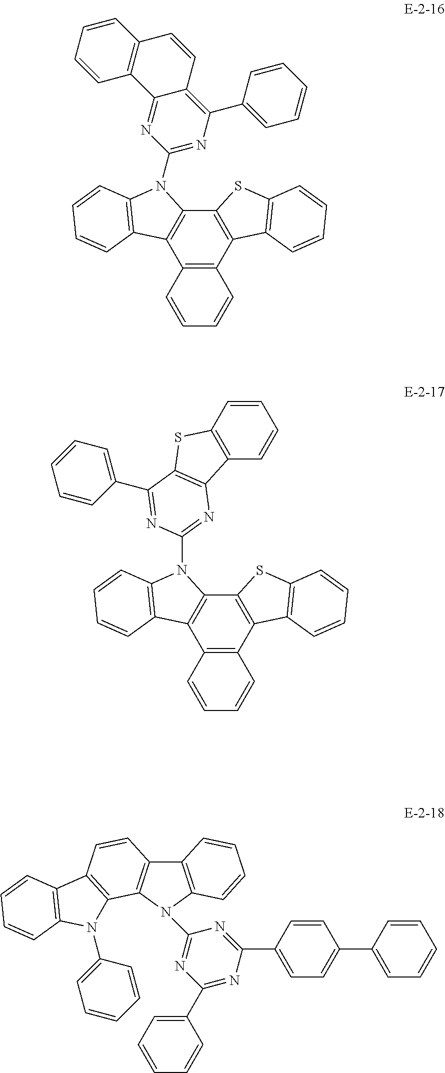 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

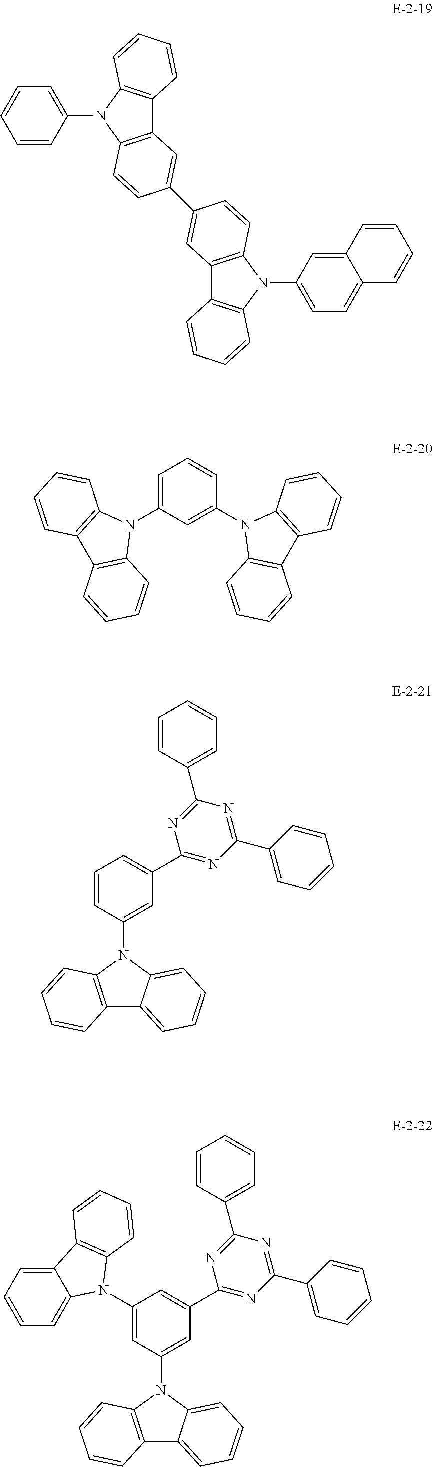 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

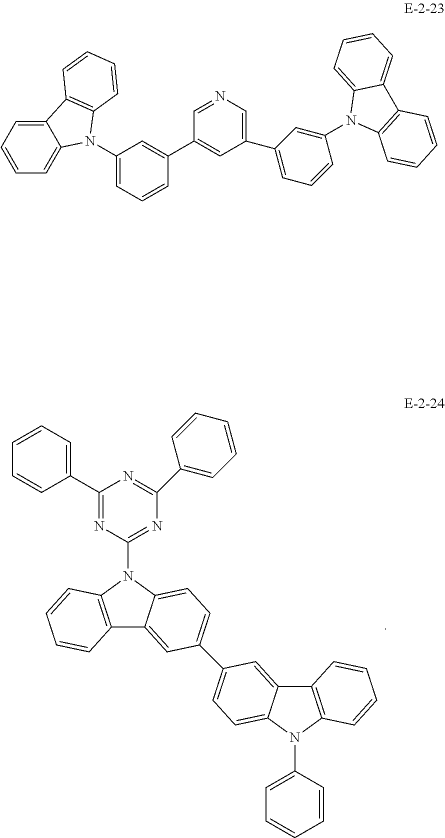 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, and, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

The emission layer EML may include the compound represented by Formula M-a. The compound represented by Formula M-a may be used as a phosphorescent dopant material.

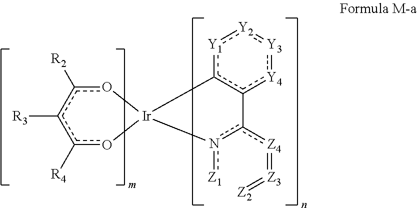

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m may be 0 or 1, and n may be 2 or 3. In Formula M-a, if (e.g., when) m is 0, n may be 3, and if (e.g., when) m is 1, n may be 2.

The compound represented by Formula M-a may be used as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

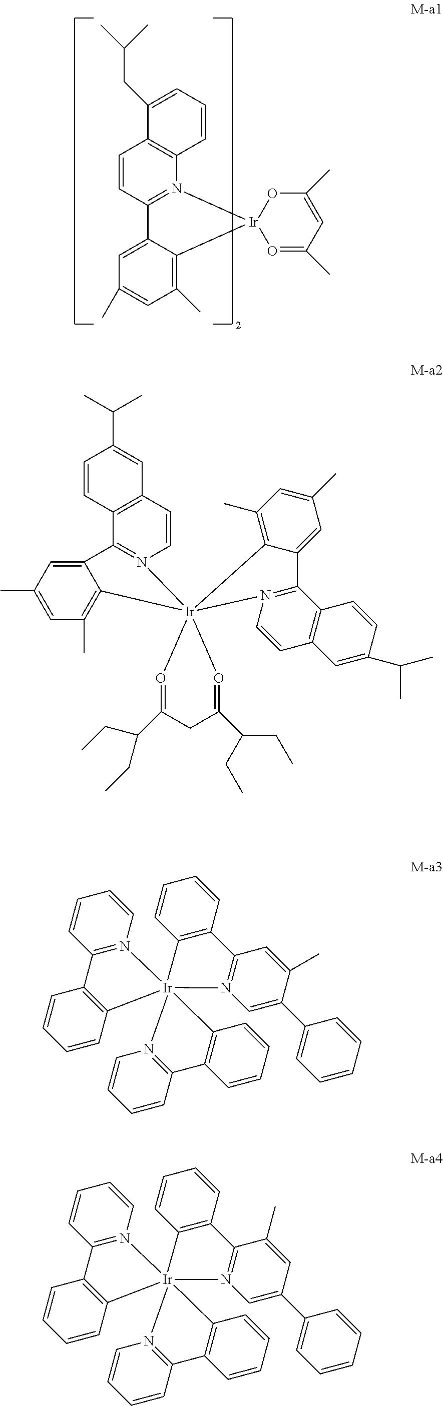

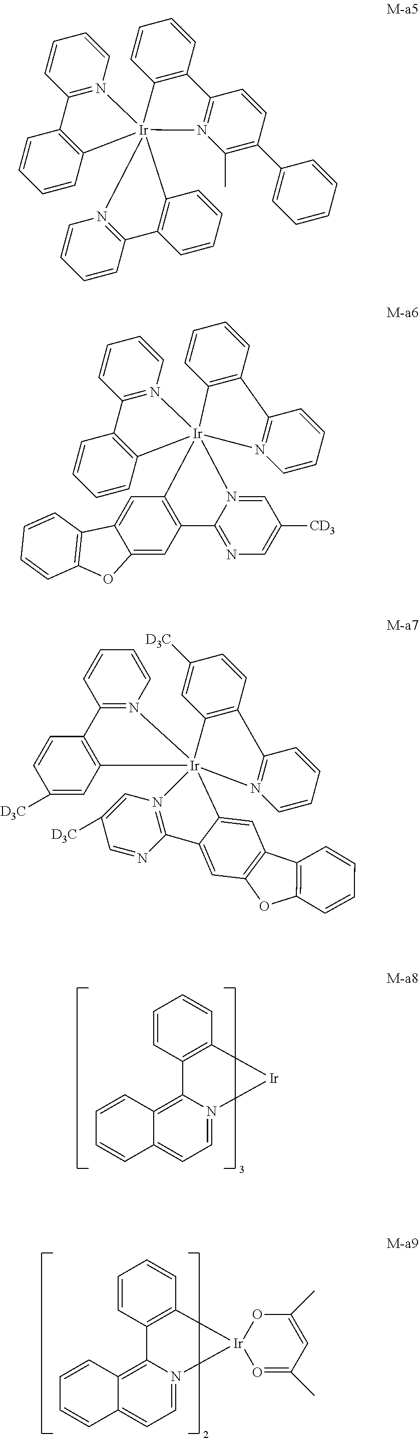

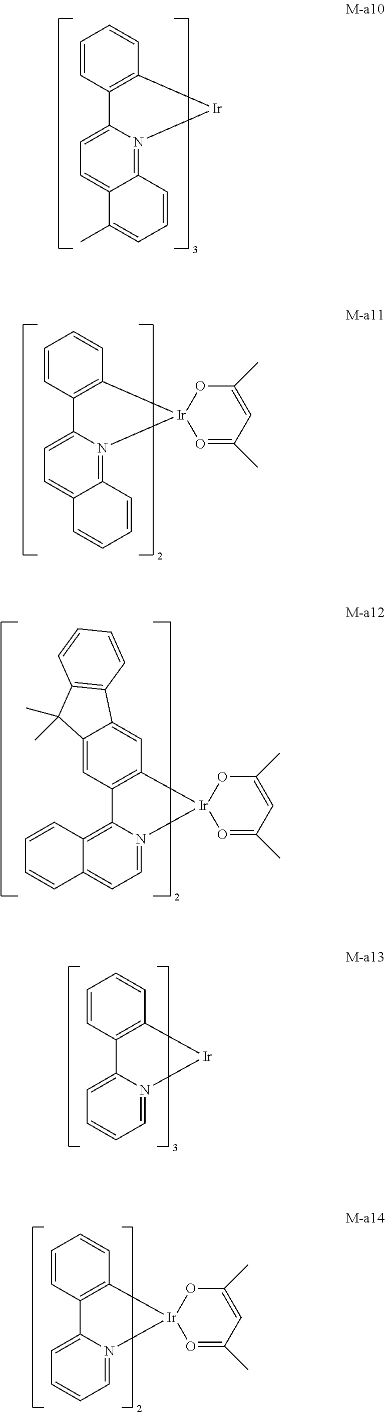

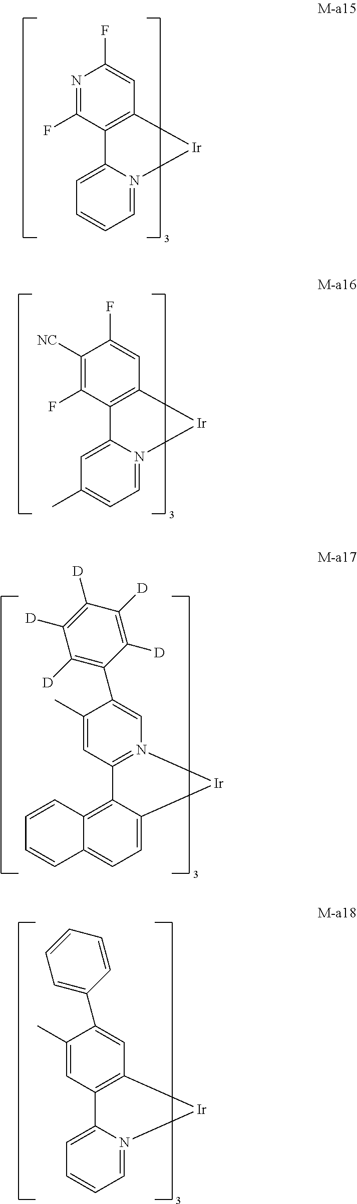

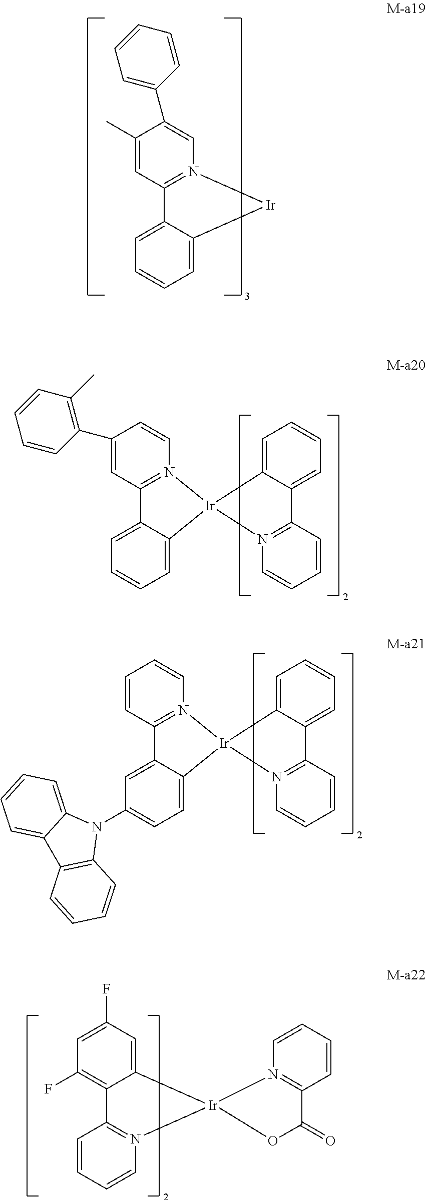

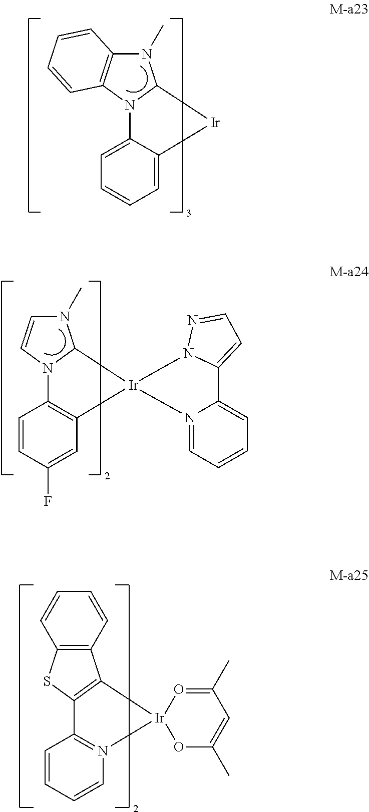

The emission layer EML may include a compound represented by any one selected from among Formula F-a to Formula F-c. The compound represented by Formula F-a to Formula F-c may be used as a fluorescence dopant material.

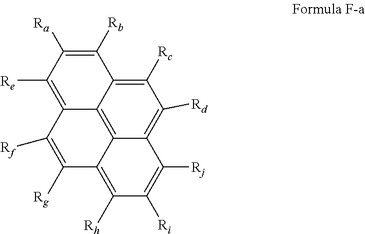

In Formula F-a, two selected from among Rₐ to Rⱼ may each independently be substituted with *—NAr₁Ar₂. The others, which are not substituted with *—NAr₁Ar₂, selected from among Rₐ to Rⱼ may each independently be a hydrogen atom, a deuterium atom, a halogen atom (e.g., F, Cl, Br, or I), a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

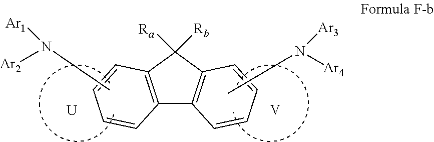

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring may constitute a fused ring at a portion indicated by U or V, and if (e.g., when) the number of U or V is 0, a ring indicated by U or V may not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

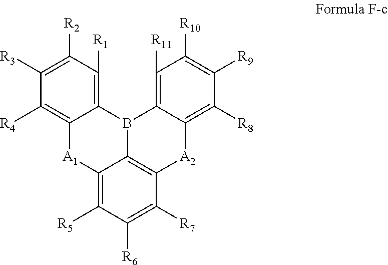

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom (e.g., F, Cl, Br, or I), a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-c, A₁ and A₂ may each independently be bonded to substituents of an adjacent ring to form a fused ring. For example, if (e.g., when) A₁ and A₂ are each independently NRₘ, A₁ may be bonded to R₄ or Rs to form a ring. In one or more embodiments, A₂ may be bonded to R₇ or R₈ to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, and/or 1,4-bis(N,N-diphenylamino)pyrene)), and/or the like.

The emission layer EML may further include a suitable phosphorescence dopant material. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N, C2′)picolinate) (FIrpic), bis(2,4-difluorophenylpyridinato)-tetrakis(1-pyrazolyl)borate iridium(III) (Fir6), and/or platinum octaethyl porphyrin (PtOEP) may be used as a phosphorescent dopant. However, embodiments of the present disclosure are not limited thereto.

The emission layer EML may include a quantum dot material. The core of the quantum dot may be selected from among a group II-VI compound, a group III-VI compound, a group I-III-VI compound, a group III-V compound, a group III-II-V compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The group III-VI compound may include: a binary compound, such as In₂S₃ and In₂Se₃; a ternary compound, such as InGaS₃ and InGaSe₃; or any combination thereof.

The group 1-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂ and a mixture thereof; or a quaternary compound, such as AgInGaS₂ and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The group III-V compound may further include a group II metal. For example, as the group III-II-V compound, InZnP and/or the like may be selected.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

Each element included in the multi-element compounds, such as the binary compound, the ternary compound, and the quaternary compound, may be present in particles at a substantially uniform concentration or a substantially non-uniform concentration. For example, Formula described herein may indicates the types (kinds) of elements included in the compound, and an element ratio in the compound may be different. For example, AgInGaS₂ may indicate AgInₓGa₁₋ₓS₂ (where x is a real number between 0 to 1).

The quantum dot may have a single structure in which a substantially uniform concentration of each element included in the corresponding quantum dot, or a dual structure of core-shell. For example, materials included in the core may be different from materials included in the shell.

The shell of the quantum dot may serve as a protection layer to protect the core from chemical alteration (or to reduce a degree or occurrence of chemical alternation of the core) to maintain semiconductor properties and/or a charging layer to impart electrophoretic properties to the quantum dot. The shell may be a single layer or a multilayer. An interface between the core and the shell may have a concentration gradient that the concentration of the elements present in the shell may decrease gradually getting toward the core.

In one or more embodiments, the quantum dot may have a core-shell structure that includes a core including the nano crystal described herein and a shell around (e.g., surrounding) the core. Examples of the shell of the quantum dot may include an oxide of a metal or a non-metal, a semiconductor compound, or a combination thereof.

Examples of the oxide of metal or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound, such as MgAl₂O₄, CoFe₂O₄, NiFe₂O₄, and CoMn₂O₄, but embodiments of the present disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Each element included in the multi-element compound, such as the binary compound and the ternary compound, may be present in particles at a substantially uniform concentration or substantially non-uniform concentration. For example, the Formula described herein may indicate the types (kinds) of elements included in the compound, and an element ratio in the compound may be different.

The quantum dot may have, in a light emitting wavelength spectrum, a full width of half maximum (FWHM) of about 45 nm or less, for example, about 40 nm or less, and, for example, about 30 nm or less, and color purity or color reproducibility may be improved or enhanced in the foregoing range. In one or more embodiments, light emitted through the quantum dot may be emitted in all directions, and thus an optical viewing angle may be improved or enhanced.

In one or more embodiments, shape of the quantum dot may be a shape generally used in the art and is not limited. However, for example, the quantum dot may adopt a spherical, pyramidal, multi-arm-shaped, or cubic nanoparticle, a nanotube, a nanowire, a nanofiber, a nanoplate particle, and/or the like.

An energy band gap may be controlled or selected by controlling the size of the quantum dot or by controlling the element ratio in the quantum dot compound, and thus light with one or more suitable wavelength bands may be emitted from the quantum dot emission layer. Therefore, by using the quantum dot described herein (using quantum dots in different sizes or with different element ratios in the quantum dot compound), a light-emitting element that emits light with one or more suitable wavelengths may be achieved. For example, the size of the quantum dot and the element ratio in the quantum dot compound may be selected such that red, green, and/or blue light is emitted. In one or more embodiments, the quantum dots may be configured or provided to emit white light by combining one or more suitable colors of light.

In each of the light emitting elements ED of one or more embodiments illustrated in FIGS. 3 to 6, the electron transport region ETR may be provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed or composed of a single material, a single layer formed or composed of a plurality of different materials, or a multilayer structure including a plurality of layers formed or composed of a plurality of different materials.

For example, the electron transport region ETR may have a single layer structure of the electron injection layer EIL or the electron transport layer ETL, and may have a single layer structure formed or composed of an electron injection material and an electron transport material. In one or more embodiments, the electron transport region ETR may have a single layer structure formed or composed of a plurality of different materials or may have a structure in which an electron transport layer ETL/electron injection layer EIL, a hole blocking layer HBL/electron transport layer ETL/electron injection layer EIL are stacked in order from the emission layer EML, but embodiments of the present disclosure are not limited thereto. The electron transport region ETR may have a thickness, for example, in the range of about 1,000 Å to about 1,500 Å.

The electron transport region ETR may be formed using one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

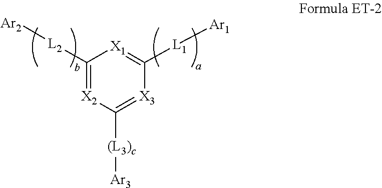

In Formula ET-2, at least one selected from among X₁ to X₃ may be N, and the rest may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c each are independently an integer of 2 or more, L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1, 10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

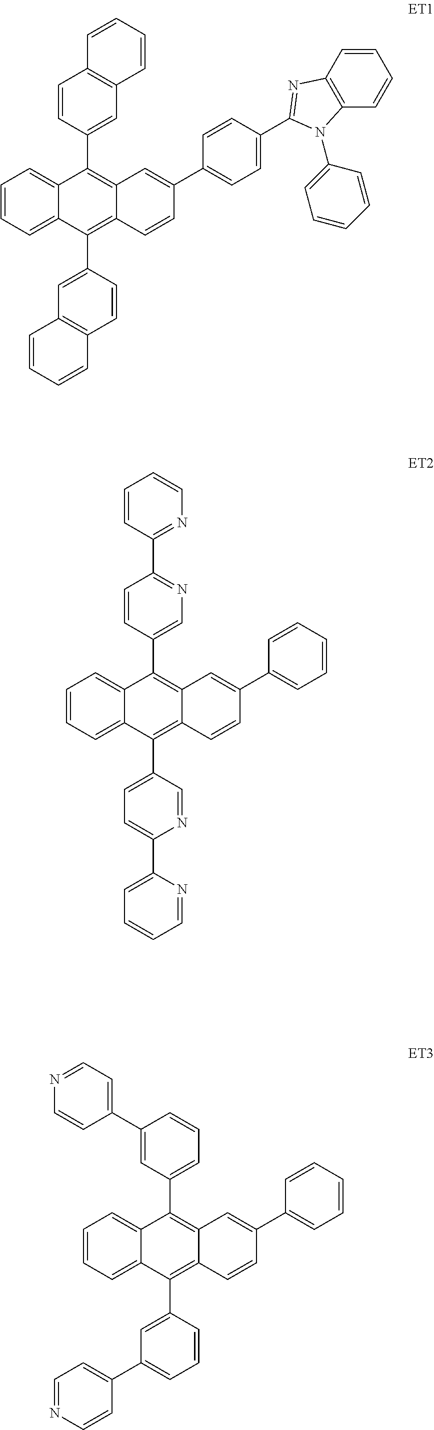 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

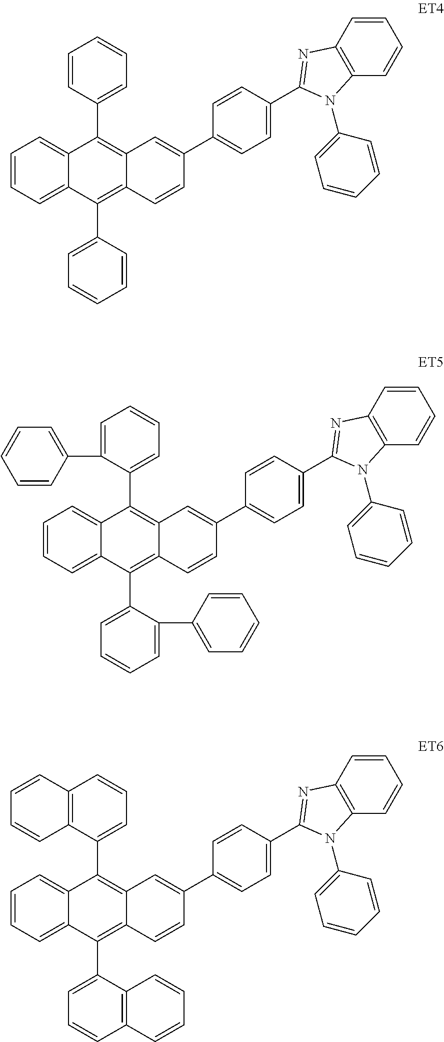 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

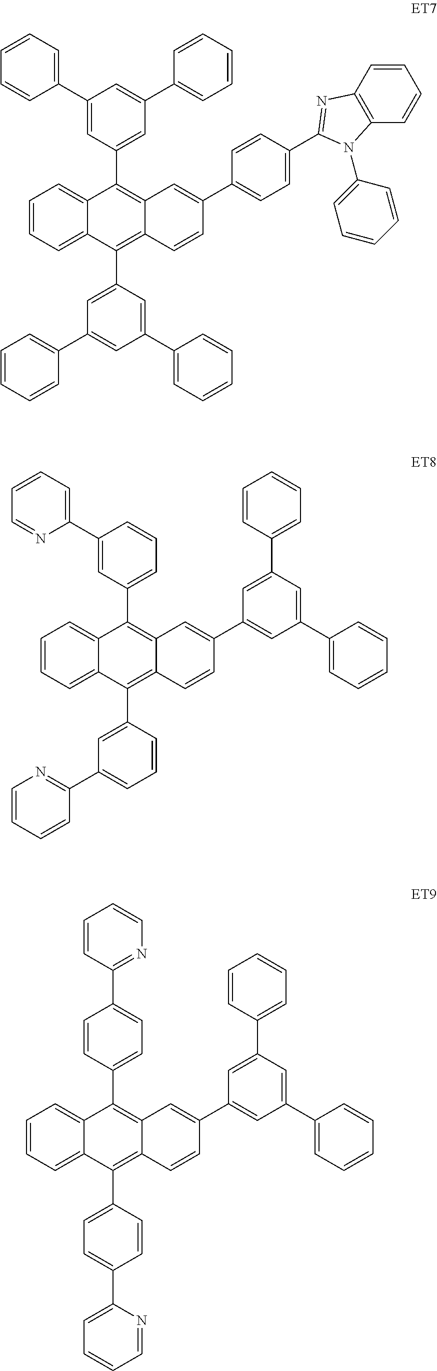 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

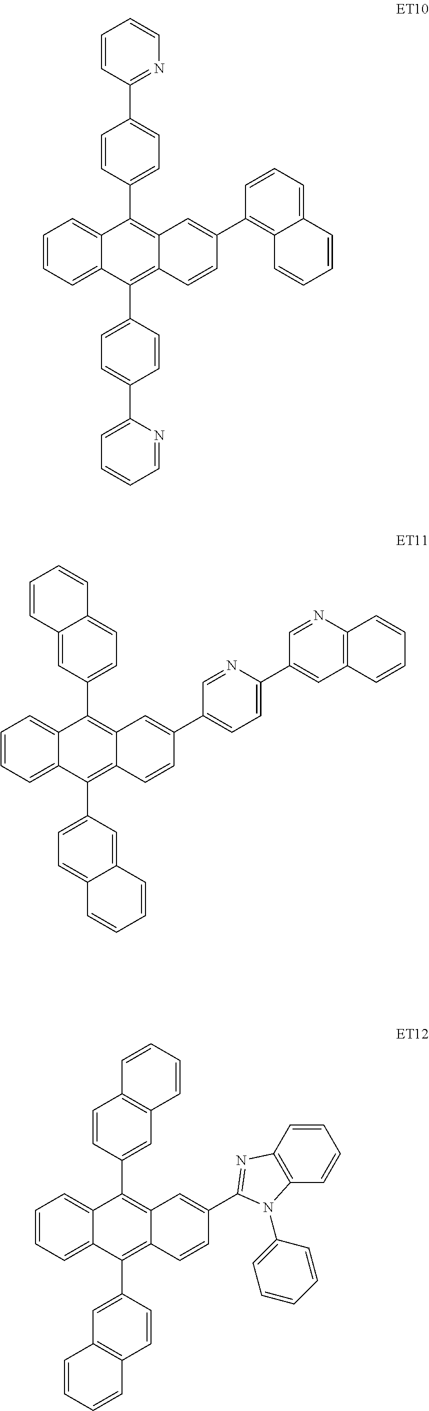 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

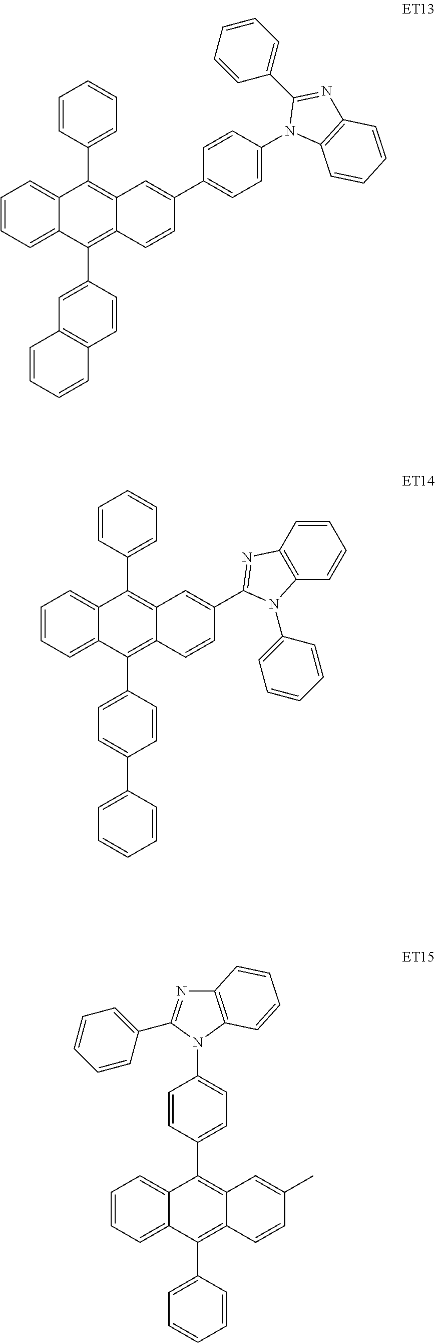 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

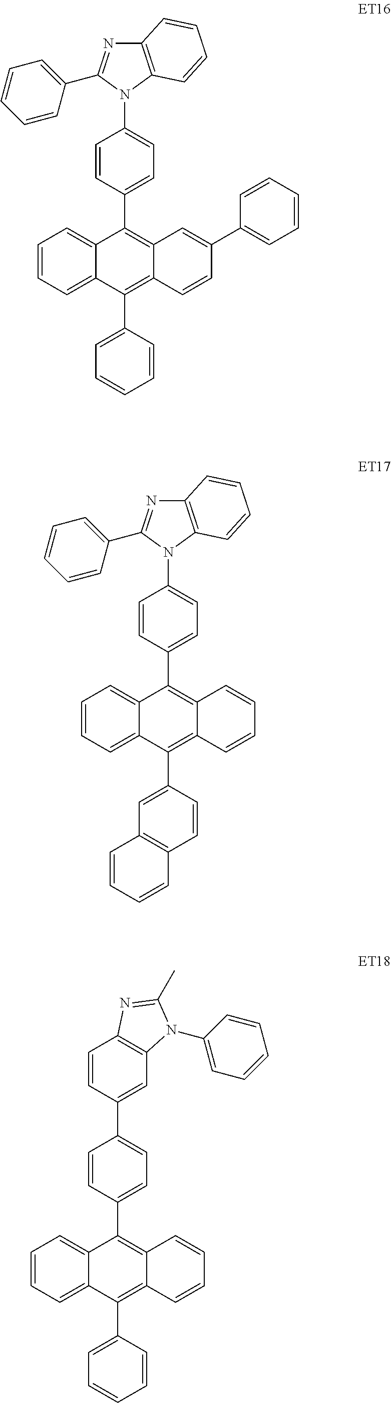 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

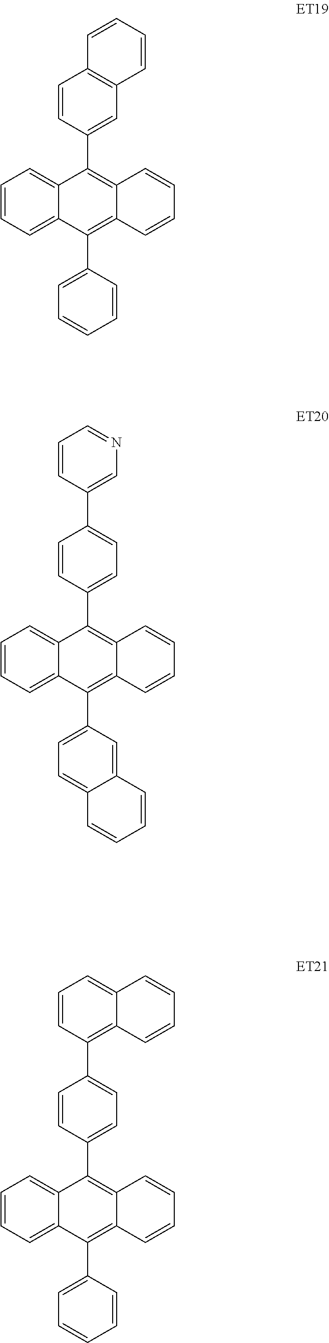

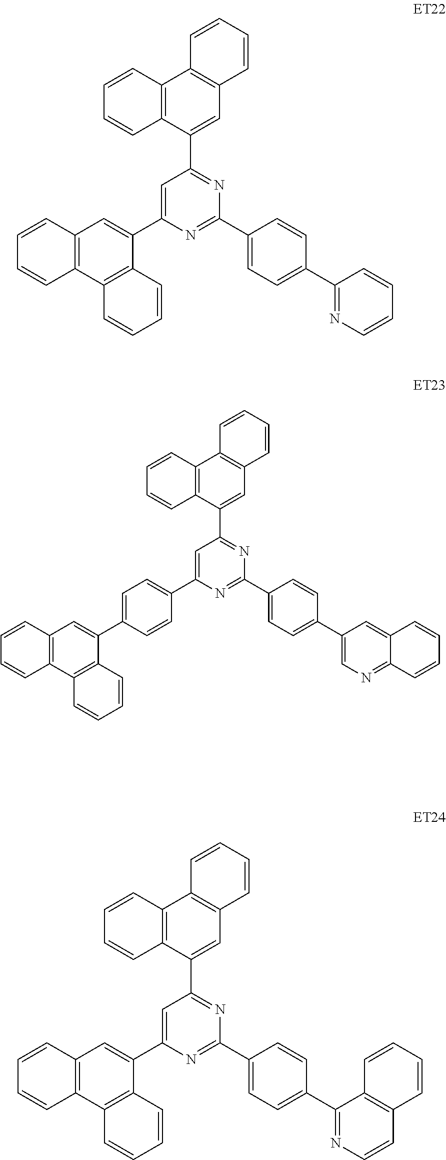 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

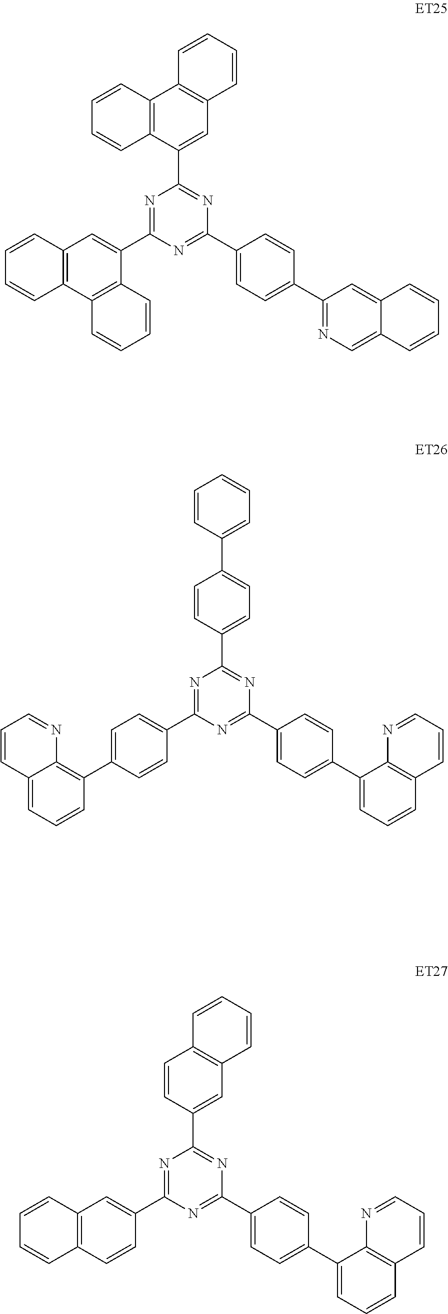 [SMILES: c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

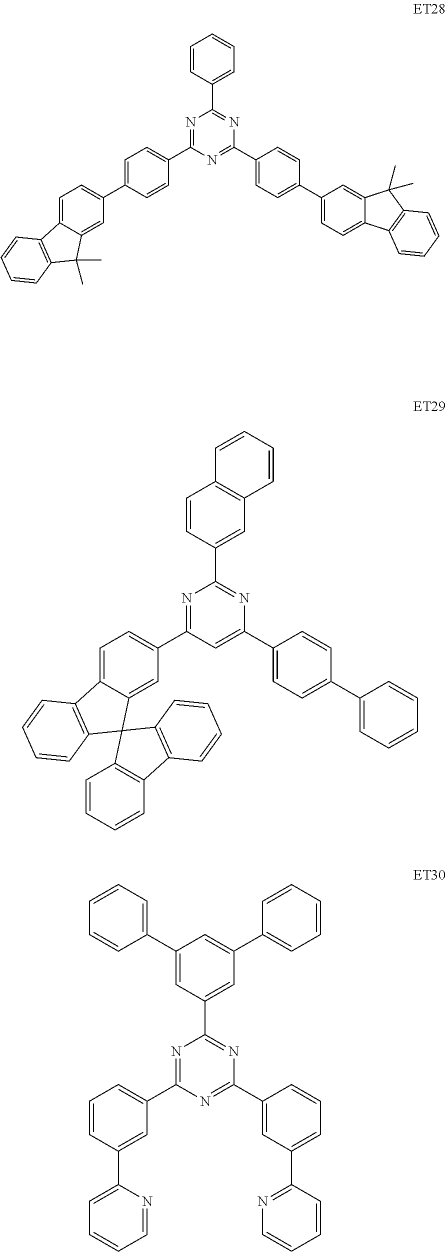 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

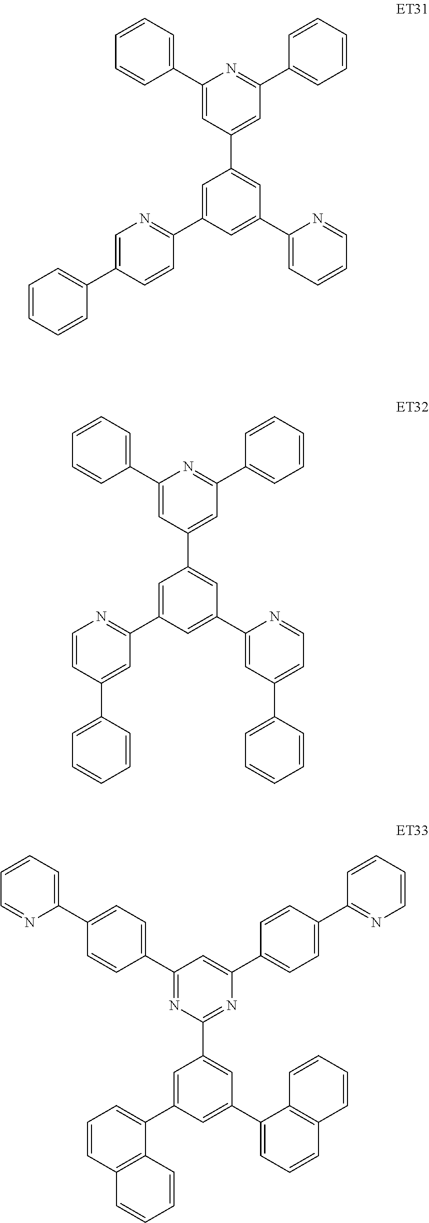 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

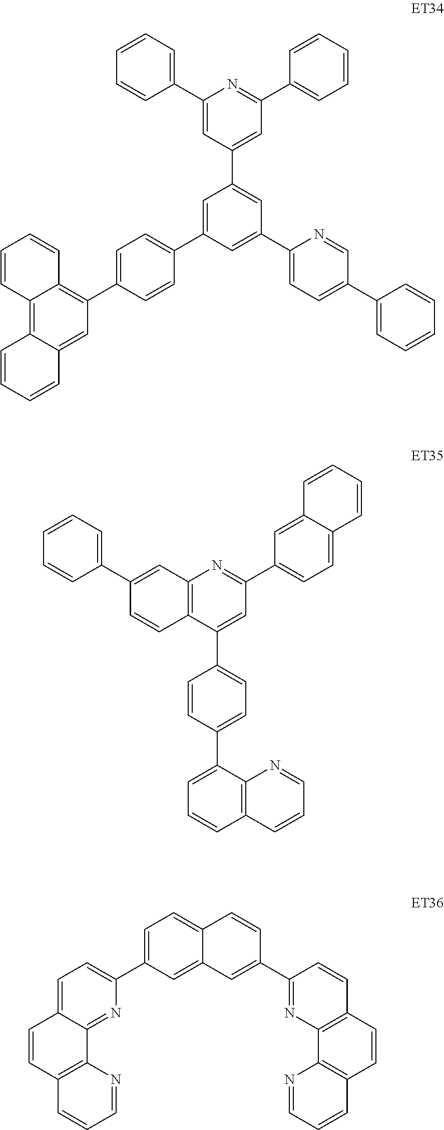 [SMILES: c1ccc(-c2ccc(-c3cc(-c4ccc(-c5cc6ccccc6c6ccccc56)cc4)cc(-c4cc(-c5ccccc5)nc(-c5ccccc5)c4)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide, such as LiF, NaCl, CsF, RbCl, RbI, CuI, and KI, a lanthanide metal, such as Yb, and a co-deposited material of the metal halide and the lanthanide metal. For example, the electron transport region ETR may include KI:Yb, RbI:Yb, LiF:Yb, and/or the like, as a co-deposited material. In one or more embodiments, the electron transport region ETR may be formed using a metal oxide, such as Li₂O or BaO, or lithium-8-hydroxyquinolinolate (Liq), and/or the like, but embodiments of the present disclosure are not limited thereto. The electron transport region ETR may also be formed or composed of a mixture material of an electron transport material and an insulating (e.g., electrically insulating) organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1, 10-phenanthroline (BCP), diphenyl(4-(triphenylsilyl)phenyl)phosphine oxide (TSPO1), or 4,7-diphenyl-1, 10-phenanthroline (Bphen) in addition to the materials described herein, but embodiments of the present disclosure are not limited thereto.

The electron transport region ETR may include the compounds of the hole transport region described herein in at least one of the electron injection layer EIL, the electron transport layer ETL, or the hole blocking layer HBL.

If (e.g., when) the electron transport region ETR includes the electron transport layer ETL, the electron transport layer ETL may have a thickness of about 100 Å to about 1,000 Å, for example, about 150 Å to about 500 Å. If (e.g., when) the thickness of the electron transport layer ETL satisfies the foregoing range, satisfactory electron transport characteristics may be obtained without a substantial increase in driving voltage. If (e.g., when) the electron transport region ETR includes the electron injection layer EIL, the electron injection layer EIL may have a thickness of about 1 Å to about 100 Å, for example, about 3 Å to about 90 Å. If (e.g., when) the thickness of the electron injection layer EIL satisfies the foregoing range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may be formed or composed of a transparent (e.g., substantially transparent) metal oxide, for example, indium tin oxide (ITO), indium zinc oxide (IZO), zinc oxide (ZnO), indium tin zinc oxide (ITZO), and/or the like.

If (e.g., when) the second electrode EL2 is the transflective electrode or the reflective electrode, the second electrode EL2 may include Ag, Mg, Cu, A₁, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In one or more embodiments, the second electrode EL2 may have a multilayer structure including a reflective film or a transflective film formed or composed of the materials described herein, and a transparent (e.g., substantially transparent) conductive (e.g., electrically conductive) film formed or composed of ITO, IZO, ZnO, ITZO, and/or the like. For example, the second electrode EL2 may include the metal materials described herein, combinations of at least two metal materials of the metal materials described herein, oxides of the metal materials described herein, and/or the like.

The second electrode EL2 may be connected with an auxiliary electrode. If (e.g., when) the second electrode EL2 is connected with the auxiliary electrode, the resistance (e.g., electrical resistance) of the second electrode EL2 may be decreased.

In one or more embodiments, a capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ (wherein 0<x≤2; e.g., Si₃N₄), SiO_{y} (wherein 0<y≤2; e.g., SiO₂), and/or the like.

For example, if (e.g., when) the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), an epoxy resin, an acrylate resin, such as methacrylate, and/or the like. However, embodiments of the present disclosure are not limited thereto, and the capping layer CPL may include at least one selected from among Compounds P1 to P5:

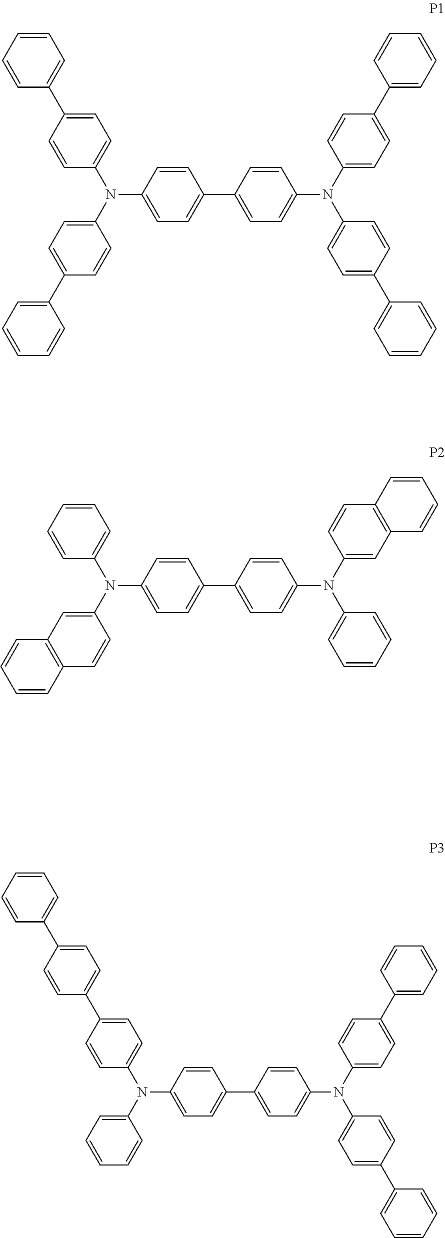 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

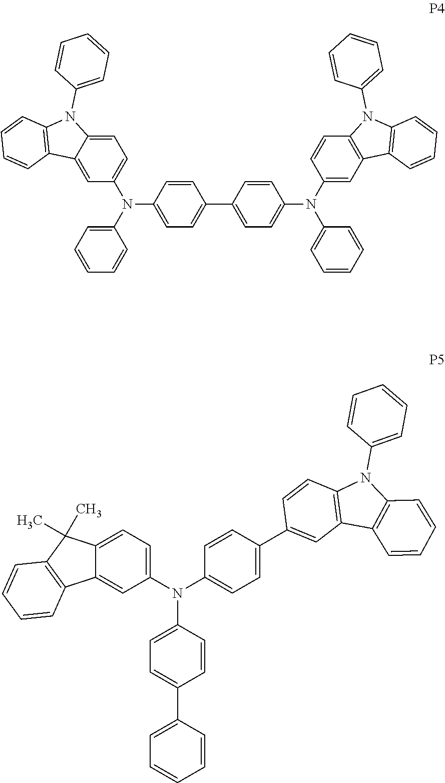 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL may be about 1.6 or more with respect to light in a wavelength range of about 550 nm to about 660 nm.

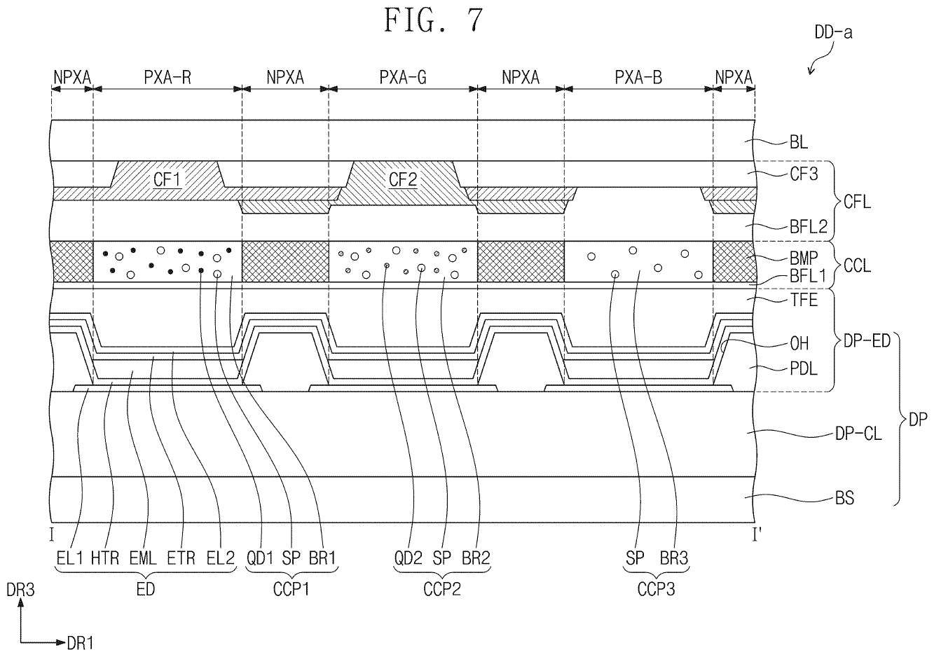

Each of FIGS. 7 to 10 are cross-sectional views of display devices according to one or more embodiments. Hereinafter, in describing the display devices of one or more embodiments with reference to FIGS. 7 to 10, the duplicated features which have been described in FIGS. 1 to 6 may not be described again, but their differences will be mainly described.

Referring to FIG. 7, the display device DD-a according to one or more embodiments may include a display panel DP including a display element layer DP-ED, a light controlling layer CCL arranged on the display panel DP, and a color filter layer CFL. In one or more embodiments, as illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, substantially the same structure as the light emitting elements ED of FIG. 3 to FIG. 6 may be applied to the structure of the light emitting element ED, illustrated in FIG. 7.

Referring to FIG. 7, the emission layer EML may be arranged in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue light. In one or more embodiments, unlike the configuration or arrangement illustrated, the emission layer EML may be provided as a common layer in the entire (e.g., almost entire) light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2, and CCP3. The light control parts CCP1, CCP2, and CCP3 may be spaced and/or apart (e.g., spaced apart or separated) from each other.

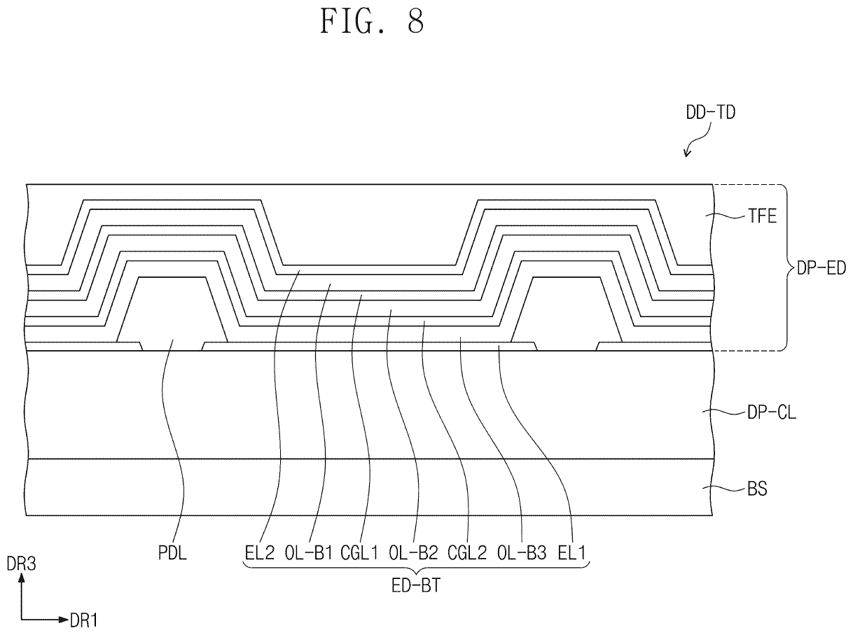

Referring to FIG. 8, divided patterns BMP may be arranged between the light control parts CCP1, CCP2, and CCP3 which are spaced and/or apart (e.g., spaced apart or separated) from each other, but embodiments of the present disclosure are not limited thereto. FIG. 8 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. Substantially the same as described herein may be applied with respect to the quantum dots QD1 and QD2.

In one or more embodiments, the light control layer CCL may further include a scatterer (e.g., a light scatterer) SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may be media in which the quantum dots QD1 and QD2 and the scatterer SP are dispersed and may be formed or composed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent (e.g., substantially transparent) resins. In one or more embodiments, the first base resin BR1, the second base resin BR2, and the third base resin BR3 may be substantially the same as or different from each other.

The light control layer CCL may include a barrier layer BFL1. The barrier layer BFL1 may serve to prevent the penetration (or to reduce a degree or occurrence of the penetration) of moisture and/or oxygen (hereinafter, referred to as “moisture/oxygen”). The barrier layer BFL1 may block the light control parts CCP1, 1 CCP2, and CCP3 from being exposed to moisture/oxygen (or reduce a degree to or occurrence of which the light control parts CCP1, CCP2, and CCP3 are exposed to moisture/oxygen). In one or more embodiments, the barrier layer BFL1 may cover the light control parts CCP1, CCP2, and CCP3. In one or more embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed or composed of a single layer or a plurality of layers.

In the display device DD-a of one or more embodiments, the color filter layer CFL may be arranged on the light control layer CCL. For example, the color filter layer CFL may be directly arranged on the light control layer CCL. In this case, the barrier layer BFL2 may not be provided.

The color filter layer CFL may include color filters CF1, CF2, and CF3. The color filter layer CFL may include a first filter CF1 to transmit the second color light, a second filter CF2 to transmit the third color light, and a third filter CF3 to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, embodiments of the present disclosure are not limited thereto, and the third filter CF3 may not include (e.g., may exclude) a pigment and/or a dye. The third filter CF3 may include a polymeric photosensitive resin and may not include (e.g., may exclude) a pigment and/or a dye. The third filter CF3 may be transparent (e.g., substantially transparent). The third filter CF3 may be formed or composed of a transparent (e.g., substantially transparent) photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material and/or an inorganic light shielding material containing a black pigment and/or a black dye. The light shielding part may prevent light leakage (or reduce a degree or occurrence of light leakage) and may separate boundaries between the adjacent filters CF1, CF2, and CF3. In one or more embodiments, the light shielding part may be formed or composed of a blue filter.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CFL. The base substrate BL may be a member which provides a base surface in which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, unlike the configuration or arrangement illustrated, the base substrate BL may not be provided.

FIG. 8 is a cross-sectional view illustrating a portion of a display device according to one or more embodiments. In the display device DD-TD of one or more embodiments, a light emitting element ED-BT may include two or more light emitting structures OL-B1, OL-B2, and OL-B3. The light emitting element ED-BT may include oppositely arranged first electrode EL1 and second electrode EL2 (e.g., the light emitting element ED-BT may include first electrode EL1 and second electrode EL2 that are opposite to each other), and two or more light emitting structures OL-B1, OL-B2, and OL-B3, which are stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR, arranged with the emission layer EML (FIG. 7) therebetween. For example, the light emitting element ED-BT included in the display device DD-TD of one or more embodiments may be a light emitting element with a tandem structure, including two or more emission layers.

In one or more embodiments, as illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit white light.

Charge generation layers CGL1 and CGL2 may be respectively arranged between two of the neighboring light emitting structures OL-B1, OL-B2, and OL-B3. The charge generation layers CGL1 and CGL2 may include a positive type (kind) (p-type (kind)) charge generation layer and/or a negative type (kind) (n-type (kind)) charge generation layer.

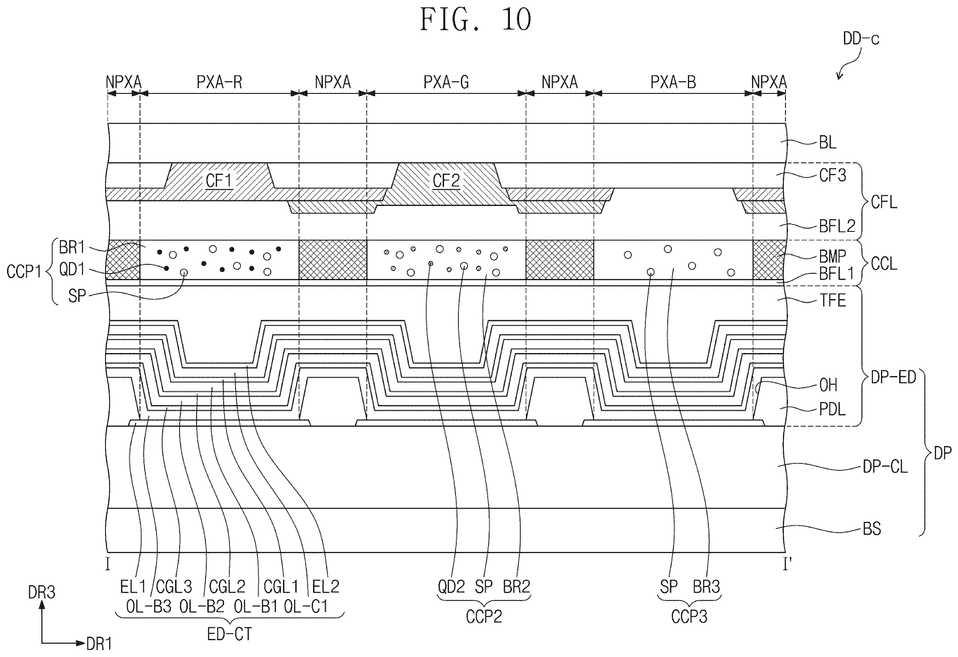

Referring to FIG. 10, a display device DD-b according to one or more embodiments may include light emitting elements ED-1, ED-2, and ED-3, in which two emission layers are stacked. Compared to the display device DD of an embodiment, as illustrated in FIG. 2, an embodiment illustrated in FIG. 10 differs in that each of the first to third light emitting elements ED-1, ED-2, and ED-3 includes two emission layers stacked in a thickness direction. Two emission layers in each of the first to third light emitting elements ED-1, ED-2, and ED-3 may be to emit light having substantially the same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. In one or more embodiments, the third light emitting element ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be arranged between the emission auxiliary part OG and the electron transport region ETR. The second red emission layer EML-R2, the second green emission layer EML-G2, and the second blue emission layer EML-B2 may be arranged between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer PL may be arranged on the display element layer DP-ED. The optical auxiliary layer PL may include a polarizing layer. The optical auxiliary layer PL may be arranged on the display panel DP and may be to control reflected light in the display panel DP due to external light. Unlike the configuration or arrangement illustrated herein, the optical auxiliary layer PL in the display device according to one or more embodiments may not be provided.

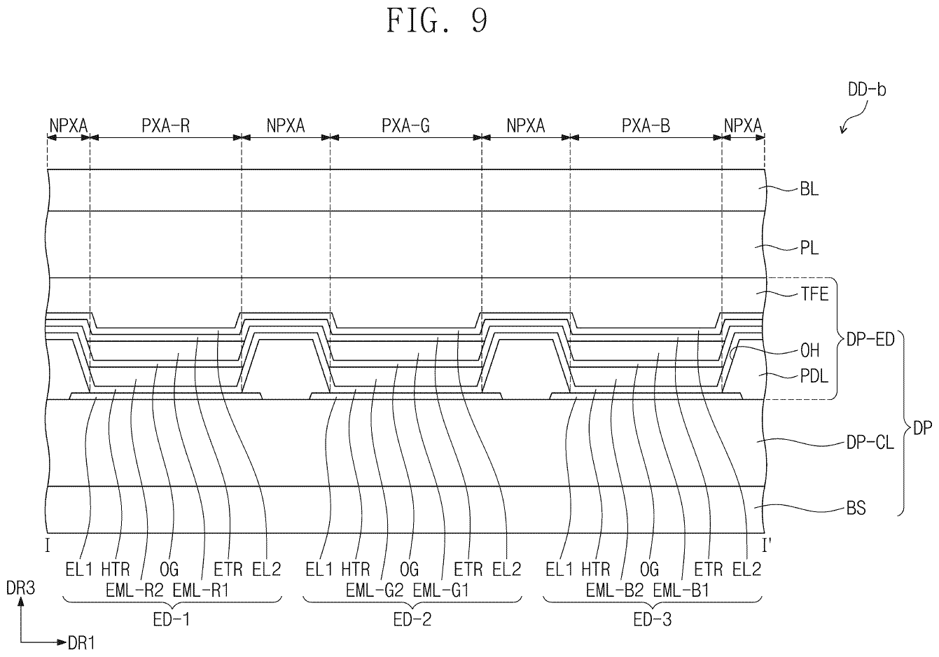

Different from FIG. 8 and FIG. 9, a display device DD-c in FIG. 10 is illustrated to include four light emitting structures OL-B1, OL-B2, OL-B3, and OL-C1. A light emitting element ED-CT may include oppositely arranged first electrode EL1 and second electrode EL2 (e.g., a light emitting element ED-CT may include first electrode EL1 and second electrode EL2 that are opposite to each other), and first to fourth light emitting structures OL-B1, OL-B2, OL-B3, and OL-C1 stacked in order in a thickness direction between the first electrode EL1 and the second electrode EL2. Charge generation layers CGL1, CGL2, and CGL3 may be arranged between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

The charge generation layers CGL1, CGL2, and CGL3 arranged between adjacent light emitting structures OL-B1, OL-B2, OL-B3, and OL-C1 may include a positive type (kind) (p-type (kind)) charge generation layer and/or a negative type (kind) (n-type (kind)) charge generation layer.

In one or more embodiments, an electronic apparatus may include a display device including two or more light emitting elements and a control part to control the display device. The electronic apparatus of one or more embodiments may be a device activated according to electrical signals. The electronic apparatus may include display devices of one or more embodiments. For example, the electronic apparatuses may include large-size display devices, such as televisions, monitors, and outside billboards, and medium- and small-size display devices, such as personal computers, laptop computers, personal digital terminals, display apparatuses for automobiles, game consoles, portable electronic apparatuses, and cameras.

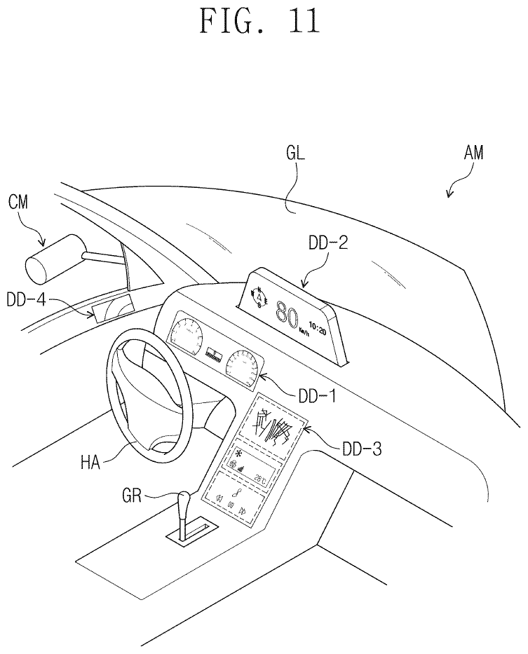

FIG. 11 is a diagram illustrating an automobile AM in which first to fourth display devices DD-1, DD-2, DD-3, and DD-4 are arranged. At least one selected from among the first to fourth display devices DD-1, DD-2, DD-3, and DD-4 may include substantially the same configurations or arrangements as those of the display devices DD, DD-TD, DD-a, DD-b, and DD-c of one or more embodiments, as described referring to FIGS. 1, 2, and 7 to 10.

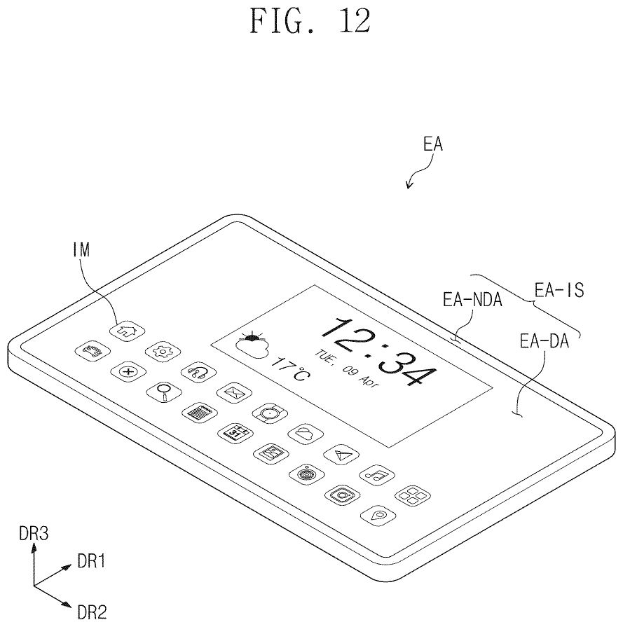

In FIG. 12, a vehicle is illustrated as an automobile AM, but this is an example, and the first to fourth display devices DD-1, DD-2, DD-3, and DD-4 may be arranged on other transport means, such as bicycles, motorcycles, trains, ships, and airplanes. In one or more embodiments, at least one selected from among the first to fourth display devices DD-1, DD-2, DD-3, and DD-4 including substantially the same configurations or arrangements as those of the display devices DD, DD-TD, DD-a, DD-b, and DD-c may be introduced in personal computers, laptop computers, personal digital terminals, game consoles, portable electronic devices, televisions, monitors, external billboards, and/or the like. In one or more embodiments, these are suggested as examples, and the display device may be introduced in other electronic apparatuses as long as not deviated from the scope of the present disclosure.

At least one selected from among the first to fourth display devices DD-1, DD-2, DD-3, and DD-4 may include the light emitting element ED, as described referring to FIG. 3 to FIG. 6.

Referring to FIG. 11, the vehicle AM may include a steering wheel HA and a gear GR to drive the vehicle AM. In one or more embodiments, the vehicle AM may include a front window GL arranged so as to face the driver (e.g., so as to be opposite to the driver).

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (for example, revolutions per minute (RPM)), an image which indicates a fuel state, and/or the like. A first scale and a second scale may be indicated as a digital image.

The second display device DD-2 may be arranged in a second region opposite to (e.g., facing) the driver's seat and overlapping the front window GL. The driver's seat may be a seat in which the steering wheel HA is arranged. For example, the second display device DD-2 may be a head up display (HUD) which displays second information of the vehicle AM. The second display device DD-2 may be optically transparent (e.g., substantially transparent). The second information may include digital numbers which indicate a driving speed, and may further include information, such as the current time. Unlike the configuration or arrangement illustrated, the second information of the second display device DD-2 may be projected to the front window GL to be displayed.

The third display device DD-3 may be arranged in a third region adjacent to the gear GR. For example, the third display device DD-3 may be arranged between the driver's seat and the passenger seat and may be a center information display (CID) for a vehicle to display third information. The passenger seat may be a seat spaced and/or apart (e.g., spaced apart or separated) from the driver's seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR and may be arranged in a fourth region adjacent to the side of the vehicle AM. For example, the fourth display device DD-4 may be a digital side-view mirror which displays fourth information. The fourth display device DD-4 may be to display an image outside the vehicle AM taken by a camera module CM arranged outside the vehicle AM. The fourth information may include an image outside the vehicle AM.

The first to fourth information described herein may be examples, and the first to fourth display devices DD-1, DD-2, DD-3, and DD-4 may further be to display information about the inside and outside of the vehicle AM. The first to fourth information may include different information. However, embodiments of the present disclosure are not limited thereto, and a part of the first to fourth information may include substantially the same information as one another.

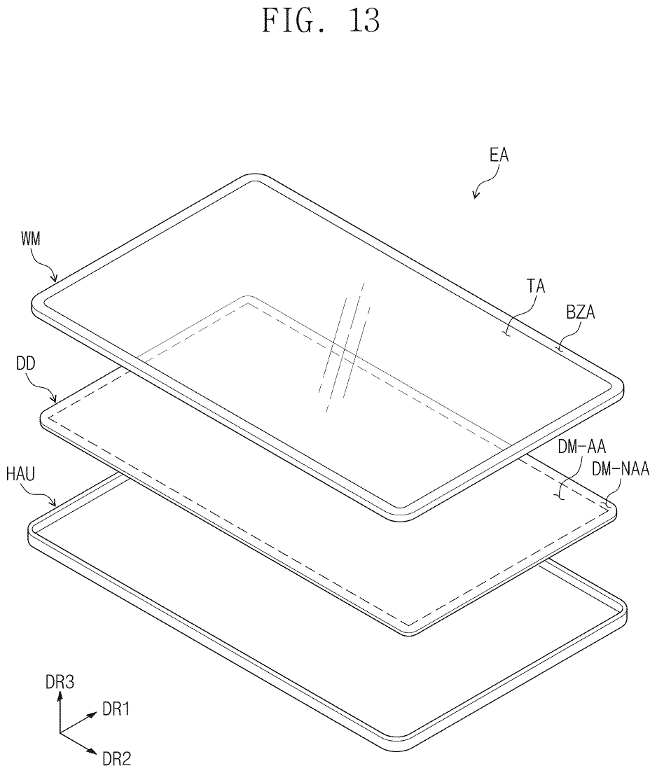

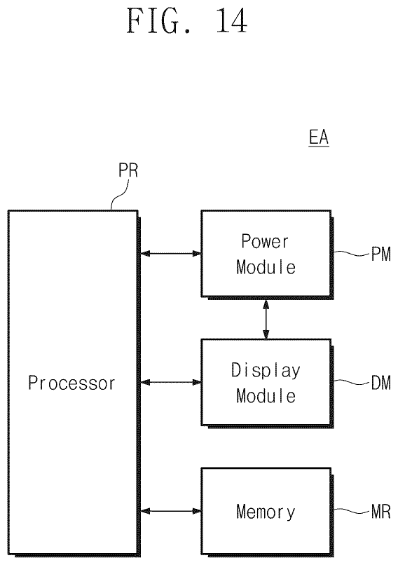

FIG. 12 is a perspective view illustrating an electronic apparatus according to one or more embodiments. FIG. 13 is an exploded perspective view illustrating an electronic apparatus according to one or more embodiments.

An image IM may be displayed through a display surface EA-IS of the electronic apparatus EA. The image IM may include a still image as well as a dynamic image. The display surface EA-IS may be substantially parallel to a surface defined by a first direction axis DR1 and a second direction axis DR2. In FIG. 12, the electronic apparatus EA is equipped with a flat display surface EA-IS, but embodiments of the present disclosure are not limited thereto. For example, the electronic apparatus EA may include a curved display surface or a three-dimensional display surface. In one or more embodiments, the three-dimensional display surface may include a plurality of display regions indicating different directions from each other.

The display surface EA-IS may include a display region EA-DA and a non-display region EA-NDA. The electronic apparatus EA may be to display an image IM through the display region EA-DA.

The non-display region EA-NDA may have a selected (e.g., set or predetermined) color. The non-display region EA-NDA may be a region adjacent to the display region EA-DA. The non-display region EA-NDA may be around (e.g., surround) the display region EA-DA. Therefore, a shape of the display region EA-DA may be substantially defined by the non-display region EA-NDA. However, what is illustrated in FIG. 12 is an example, and the non-display region EA-NDA may be arranged adjacent to only one side of the display region EA-DA and may also not be provided.

Referring to FIG. 13, the electronic apparatus EA may include a display device DD. In one or more embodiments, the electronic apparatus EA may further include a window member WM and a housing HAU.

The window member WM may cover an entire (e.g., almost entire) exterior of the electronic apparatus EA. The window member WM may include a transmissive region TA and a bezel region BZA. A front surface of the window member WM including the transmissive region TA and the bezel region BZA may correspond to a front surface of the electronic apparatus EA. The transmissive region TA may correspond to the display region EA-DA of the electronic apparatus EA illustrated in FIG. 12, and the bezel region BZA may correspond to the non-display region EA-NDA of the electronic apparatus EA illustrated in FIG. 12.

The transmissive region TA may be an optically transparent (e.g., substantially transparent) region. The bezel region BZA may be a region having relatively lower light transmittance than the transmissive region TA. The bezel region BZA may have a selected (e.g., set or predetermined) color. The bezel region BZA may be adjacent to the transmissive region TA and may be around (e.g., surround) the transmissive region TA. The bezel region BZA may define a shape of the transmissive region TA. However, embodiments of the present disclosure are not limited to what is illustrated, the bezel region BZA may be arranged adjacent to only one side of the transmissive region TA, and a portion thereof may also not be provided.

The housing HAU may include a material having relatively high rigidity. For example, the housing HAU may include a frame and/or a plate composed of glass, plastic, and/or metal. A plurality of frames and/or plates may be provided. The housing HAU may provide an accommodation space. The display device DD may be accommodated in the accommodation space and protected from an external impact.

The display device DD may include substantially the same configuration or arrangement as at least one selected from among the display device DD, DD-TD, DD-a, DD-b, and DD-c, each according to one or more embodiments, described with reference to FIGS. 1, 2, and 7 to 10. The display device DD may include the light-emitting element ED, described with reference to FIG. 3 to FIG. 6. Therefore, the electronic apparatus EA including the display device DD according to one or more embodiments may exhibit excellent or suitable reliability.

In the display device DD, an active region DM-AA and a peripheral region DM-NAA may be defined. The active region DM-AA may overlap the display region EA-DA illustrated in FIG. 12, and the peripheral region DM-NAA may overlap the non-display region EA-NDA illustrated in FIG. 12.

The active region DM-AA may be a region activated in response to an electrical signal. The peripheral region DM-NAA may be a region arranged adjacent to at least one side of the active region DM-AA. The active region DM-AA may include a non-emission region NPXA and emission regions PXA-R, PXA-G, and PXA-B, illustrated in FIG. 1. The peripheral region DM-NAA may be arranged to cover the active region DM-AA. However, embodiments of the present disclosure are not limited thereto, and, unlike what is illustrated, a portion of the peripheral region DM-NAA may not be provided. In the peripheral region DM-NAA, a driving circuit, a driving wire, and/or the like to drive the active region DM-AA may be arranged.

The display device according to one or more embodiments may be applied to one or more suitable electronic apparatuses. The electronic apparatus according to one or more embodiments may include the display device described herein and may further include a module or a device, having another additional function, in addition to the display device.

FIG. 14 is a block diagram of an electronic apparatus according to one or more embodiments. Referring to FIG. 14, an electronic apparatus EA according to one or more embodiments may include a display module DM, a processor PR, a memory MR, and a power module PM.

The processor PR may include at least one selected from among a central processing unit (CPU), an application processor (AP), a graphic processing unit (GPU), a communication processor (CP), an image signal processor (ISP), and a controller.

In the memory MR, data information for an operation of the processor PR or the display module DM may be stored. If (e.g., when) the processor PR executes an application stored in the memory MR, an image data signal and/or an input control signal may be transmitted to the display module DM, and the display module DM, and the display module DM may process the received signal and output image information through a display screen.

The power module PM may include a power supply module, such as a power adaptor or a battery device, and a power conversion module that converts power supplied by the power supply module to generate power for the operation of the electronic apparatus EA.

At least one selected from among the components of the electronic apparatus EA described herein may be included in the display devices described herein according to one or more embodiments. In one or more embodiments, one or more suitable independent modules functionally included in one module may be included in the display device, and one or more other modules may be provided separately from the display device. For example, the display device may include a display module DM, and a processor PR, a memory MR, and a power module PM may be provided in the form of other devices within the electronic apparatus EA, not the display device.

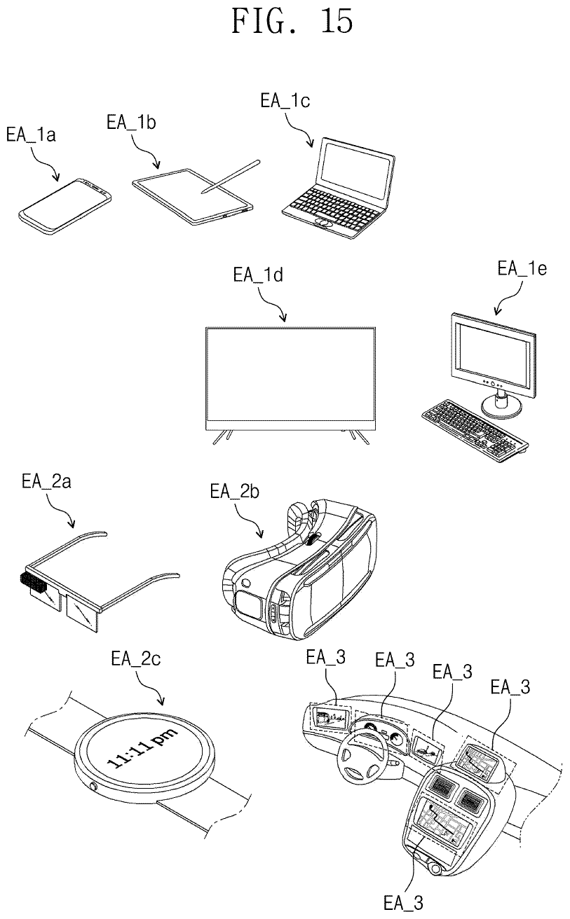

FIG. 15 illustrates schematic views of electronic apparatuses according to one or more embodiments. Referring to FIG. 15, one or more suitable electronic apparatuses to which the display devices according to one or more embodiments are applied may not include (e.g., may exclude) only an image-displaying electronic apparatus, such as a smart phone EA_1a, a tablet PC EA_1b, a laptop computer EA_1c, a TV EA_1d, and a desktop monitor EA_1e, but also include a wearable electronic apparatus, such as smart glasses EA_2a, a head mounted display EA_2b, or a smart watch EA_2c, and a vehicular electronic apparatus EA_3 including a display module, such as a car dashboard, a center fascia, a center information display (CID) arranged in a dashboard, or a room mirror display, and/or the like.

Hereinafter, with reference to Examples and Comparative Examples, the fused polycyclic compound according to one or more embodiments of the present disclosure and the light-emitting element according to one or more embodiments will be described in more detail. Also, the examples shown are exemplified only for helping the understanding of the present disclosure, and the scope of the present disclosure is not limited thereto.

### EXAMPLES

### 1. Synthesis of Fused Polycyclic Compound

A synthetic method of the fused polycyclic compound according to one or more embodiments of the present disclosure will be described by exemplifying the synthetic methods of Fused Polycyclic Compounds 25, 37, 173, 245, 390, 513, and 579. Also, the synthetic methods of the fused polycyclic compounds described hereinafter are examples, and the synthetic method of the compound according to one or more embodiments of the present disclosure is not limited thereto.

### (1) Synthesis of Fused Polycyclic Compound 25

Fused Polycyclic Compound 25 according to one example may be synthesized by, for example, methods in Reaction Scheme 1.

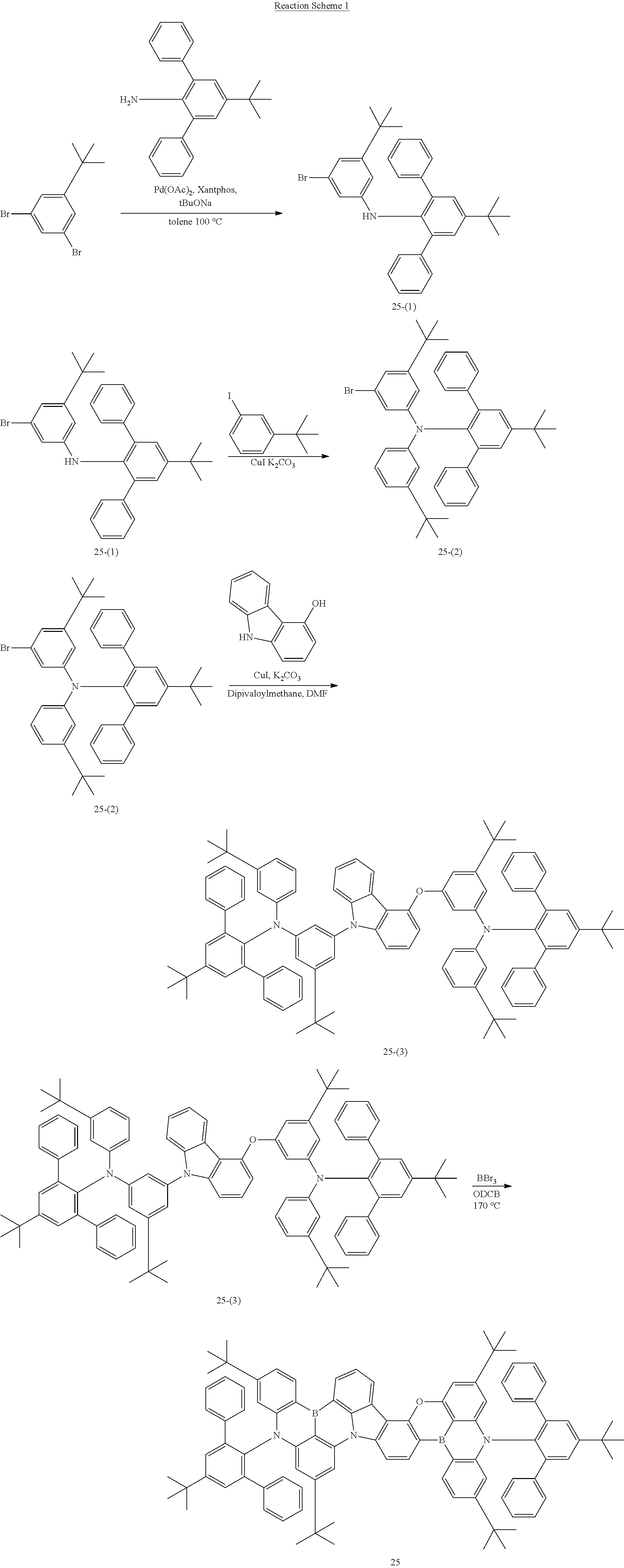

### Synthesis of Intermediate Compound 25-(1)

Under an argon atmosphere, 1,3-dibromo-5-(tert-butyl)benzene (8.85 g, 30.31 mmol), 5′-(tert-butyl)-[1,1′:3′,1″-terphenyl]-2′-amine (9.14 g, 30.31 mmol), Pd(OAc)₂ (0.2 g, 0.91 mmol), XantPhos (1.05 g, 1.82 mmol), and tBuONa (3.5 g, 36.37 mmol) were added to toluene (151 mL), and then the resultant mixture was heated and stirred at about 100° C. for about 8 hours. Thereafter, water was added, and the mixture was filtered through Celite to separate an organic layer. The organic layer was concentrated and then purified through silica gel column chromatography to obtain Intermediate Compound 25-(1) (14.14 g, yield of 91%). A molecular weight (as represented by the mass-to-charge ratio (m/z)) of the obtained purified product, as measured by fast atom bombardment—mass spectrometry (FAB MS), was confirmed to be about 513 m/z, and thus obtaining Intermediate Compound 25-(1), which was a target product, was clearly identified.

### Synthesis of Intermediate Compound 25-(2)

Intermediate Compound 25-(1) (12.11 g, 23.63 mmol), 1-(tert-butyl)-3-iodobenzene (49.17 g, 189.02 mmol), CuI (11.25 g, 59.07 mmol), and K₂CO₃ (48.98 g, 354.41 mmol) were added to a small amount of toluene (about 10 mL), and then the resultant mixture was heated at about 215° C. for about 24 hours. Thereafter, the obtained was diluted with dichloromethane (CH₂Cl₂), water was added, and the mixture was filtered through Celite to separate an organic layer. The organic layer was concentrated and then purified through silica gel column chromatography to obtain Intermediate Compound 25-(2) (10.51 g, yield of 69%). A molecular weight (as represented by the mass-to-charge ratio (m/z)) of the obtained purified product, as measured by FAB MS, was confirmed to be about 645 m/z, and thus obtaining Intermediate Compound 25-(2), which was a target product, was clearly identified.

### Synthesis of Intermediate Compound 25-(3)

Intermediate Compound 25-(2) (9.83 g, 15.24 mmol), 9H-carbazol-4-ol (1.33 g, 7.26 mmol), CuI (1.52 g, 7.99 mmol), K₂CO₃ (4.01 g, 29.04 mmol), and dipivaloylmethane (15.21 g, 0.08 mmol) were added to dimethylformamide (DMF, 152 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 25-(3) (7.42 g, yield of 78%). A molecular weight (as represented by the mass-to-charge ratio (m/z)) of the obtained purified product, as measured by FAB MS, was confirmed to be about 1311 m/z, and thus obtaining Intermediate Compound 25-(3), which was a target product, was clearly identified.

### Synthesis of Compound 25

Under an argon atmosphere, Intermediate Compound 25-(3) (6.23 g, 4.75 mmol) was dissolved in ortho-dichlorobenzene (ODCB, 48 mL), BBr₃ (4.76 g, 19.01 mmol) was added, and then the resultant mixture was heated and stirred at about 170° C. for about 10 hours. Thereafter, the mixture was cooled to a room temperature, then N,N-diisopropylethylamine (DIPEA, 7.36 g, 57.03 mmol) was added, water was added, and the mixture was filtered through Celite to separate an organic layer. The organic layer was concentrated and then purified through silica gel column chromatography to obtain Intermediate Compound 25 (2.58 g, yield of 41%). A molecular weight (as represented by the mass-to-charge ratio (m/z)) of the obtained purified product, as measured by FAB MS, was confirmed to be about 1326 m/z, and thus obtaining Compound 25, which was a target product, was clearly identified. Compound 25 was purified by sublimation in a condition of about 380° C. and about 2.4×10⁻³ Pa and was used as an emission layer of the light-emitting element.

### (2) Synthesis of Fused Polycyclic Compound 37

Fused Polycyclic Compound 37 according to one example may be synthesized by, for example, methods in Reaction Scheme 2.

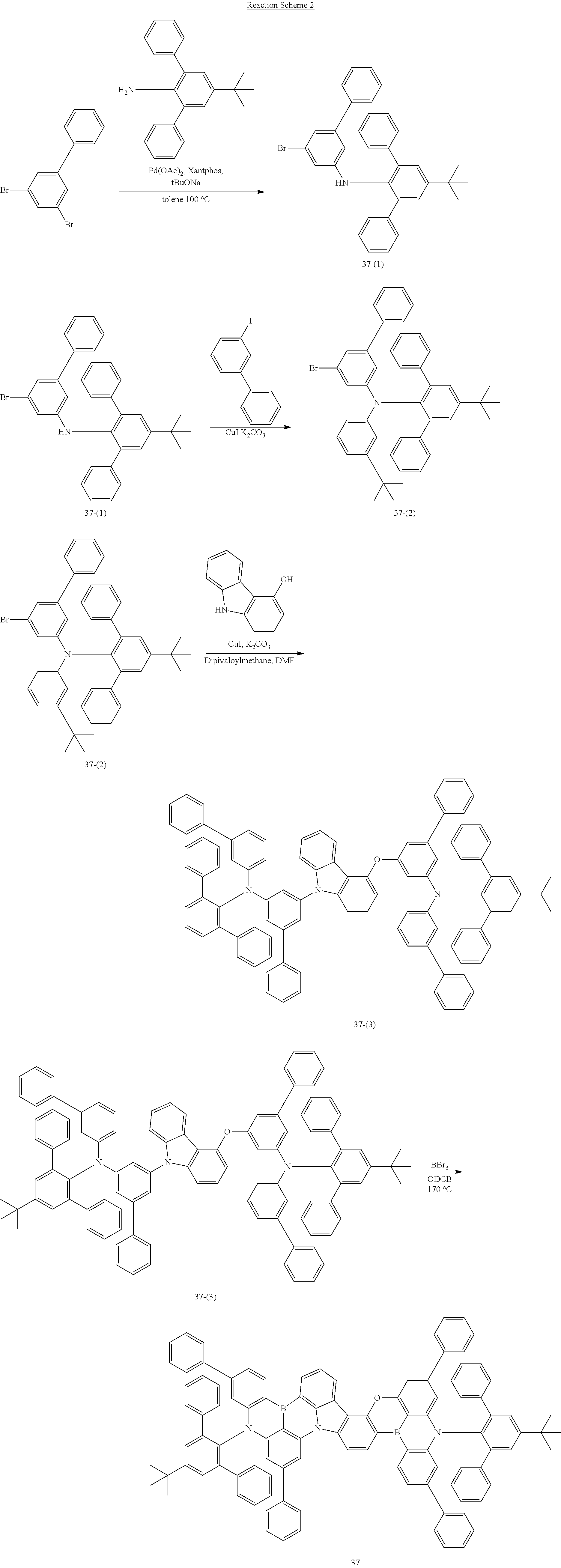

### Synthesis of Intermediate Compound 37-(1)

Under an argon atmosphere, 3,5-dibromo-1,1′-biphenyl/methane (1/1) (8.22 g, 25.06 mmol), 5′-(tert-butyl)-[1,1′:3′,1″-terphenyl]-2′-amine (7.55 g, 25.06 mmol), Pd(OAc)₂ (0.17 g, 0.75 mmol), XantPhos (0.87 g, 1.5 mmol), and tBuONa (2.89 g, 30.07 mmol) were added to toluene (125 mL), and then the resultant mixture was heated and stirred at about 100° C. for about 8 hours. Thereafter, water was added, and the mixture was filtered through Celite to separate an organic layer. The organic layer was concentrated and then purified through silica gel column chromatography to obtain Intermediate Compound 37-(1) (12.10 g, yield of 88%). A molecular weight (as represented by the mass-to-charge ratio (m/z)) of the obtained purified product, as measured by FAB MS, was confirmed to be about 549 m/z, and thus obtaining Intermediate Compound 37-(1), which was a target product, was clearly identified.

### Synthesis of Intermediate Compound 37-(2)

Intermediate Compound 37-(1) (11.051 g, 20.14 mmol), 3-iodo-1,1′-biphenyl (45.14 g, 161.15 mmol), CuI (9.59 g, 50.36 mmol), and K₂CO₃ (41.76 g, 302.15 mmol) were added to a small amount of toluene (about 10 mL), and then the resultant mixture was heated at about 215° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 37-(2) (8.97 g, yield of 65%). A molecular weight (as represented by the mass-to-charge ratio (m/z)) of the obtained purified product, as measured by FAB MS, was confirmed to be about 685 m/z, and thus obtaining Intermediate Compound 37-(2), which was a target product, was clearly identified.

### Synthesis of Intermediate Compound 37-(3)

Intermediate Compound 37-(2) (10.44 g, 15.24 mmol), 9H-carbazol-4-ol (1.33 g, 7.26 mmol), CuI (1.52 g, 7.99 mmol), K₂CO₃ (4.01 g, 29.04 mmol), and dipivaloylmethane (15.21 g, 0.08 mmol) were added to dimethylformamide (DMF, 152 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 37-(3) (7.47 g, yield of 74%). A molecular weight (as represented by the mass-to-charge ratio (m/z)) of the obtained purified product, as measured by FAB MS, was confirmed to be about 1391 m/z, and thus obtaining Intermediate Compound 37-(3), which was a target product, was clearly identified.

### Synthesis of Compound 37

Under an argon atmosphere, Intermediate Compound 37-(3) (7.11 g, 5.11 mmol) was dissolved in ortho-dichlorobenzene (ODCB, 51 mL), BBr₃ (5.12 g, 20.45 mmol) was added, and then the resultant mixture was heated and stirred at about 170° C. for about 10 hours. Thereafter, the mixture was cooled to a room temperature, then N,N-diisopropylethylamine (DIPEA, 7.91 g, 61.34 mmol) was added, water was added, and the mixture was filtered through Celite to separate an organic layer. The organic layer was concentrated and then purified through silica gel column chromatography to obtain Compound 37 (2.73 g, yield of 38%). A molecular weight (as represented by the mass-to-charge ratio (m/z)) of the obtained purified product, as measured by FAB MS, was confirmed to be about 1406 m/z, and thus obtaining Compound 37, which was a target product, was clearly identified. Compound 37 was purified by sublimation in a condition of about 380° C. and about 2.4×10⁻³ Pa and was used as an emission layer of the light-emitting element.

### (3) Synthesis of Fused Polycyclic Compound 173

Fused Polycyclic Compound 173 according to one example may be synthesized by, for example, methods in Reaction Scheme 3.

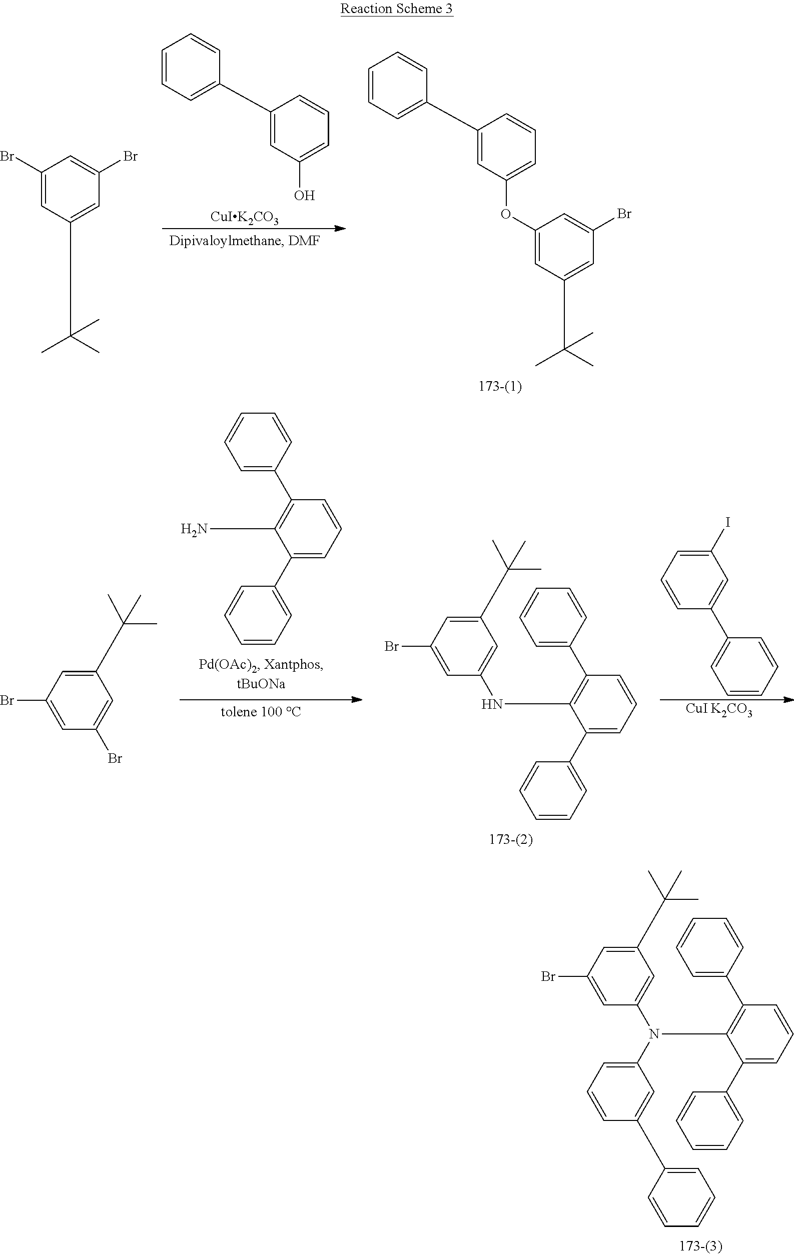

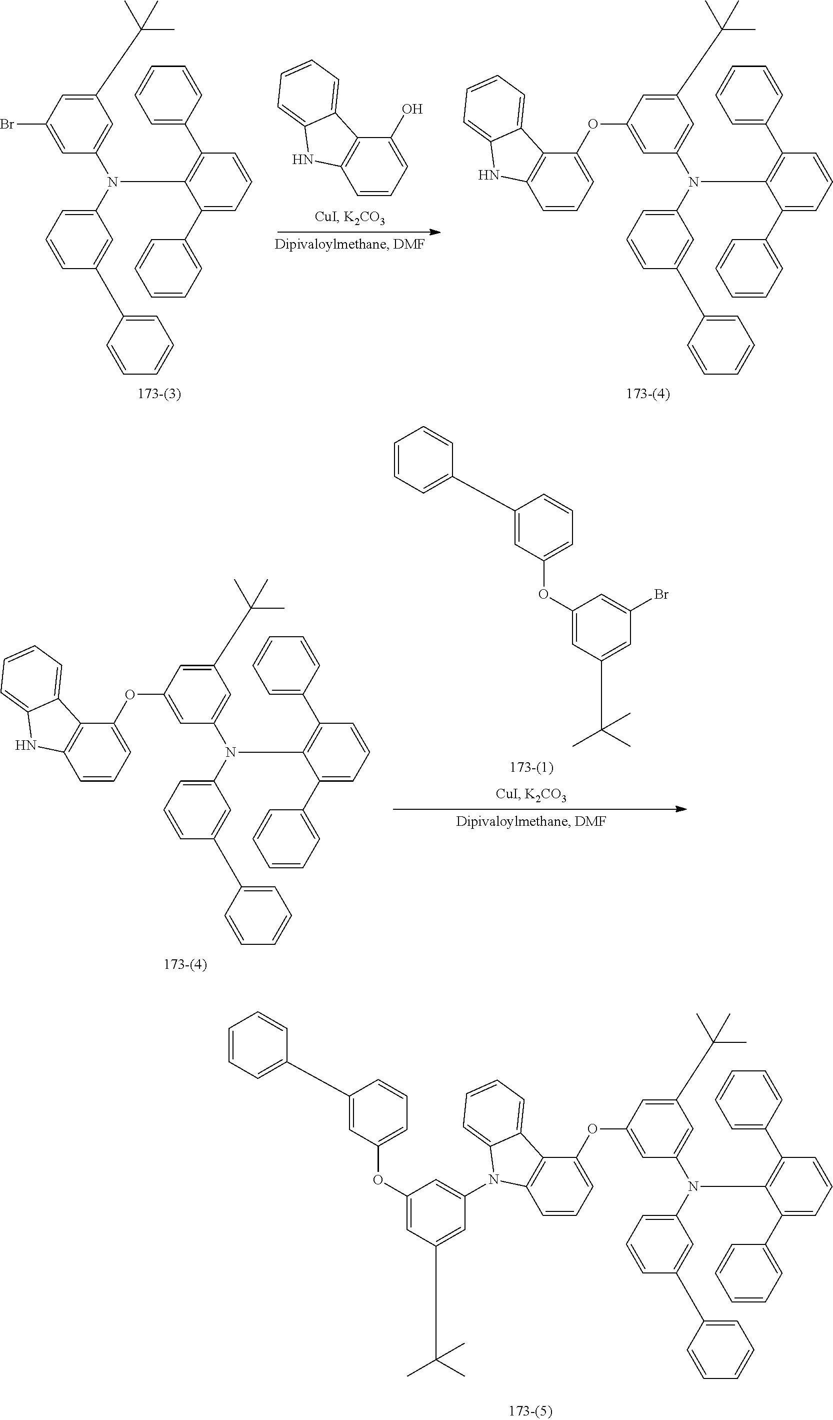 [SMILES: CC(C)(C)c1cc(Br)cc(N(c2cccc(-c3ccccc3)c2)c2c(-c3ccccc3)cccc2-c2ccccc2)c1 ; Oc1cccc2[nH]c3ccccc3c12 ; CC(C)(C)c1cc(Oc2cccc3[nH]c4ccccc4c23)cc(N(c2cccc(-c3ccccc3)c2)c2c(-c3ccccc3)cccc2-c2ccccc2)c1 ; CC(C)(C)c1cc(Oc2cccc3[nH]c4ccccc4c23)cc(N(c2cccc(-c3ccccc3)c2)c2c(-c3ccccc3)cccc2-c2ccccc2)c1 ; CC(C)(C)c1cc(Br)cc(Oc2cccc(-c3ccccc3)c2)c1 ; CC(C)(C)c1cc(Oc2cccc3c2c2ccccc2n3-c2cc(Oc3cccc(-c4ccccc4)c3)cc(C(C)(C)C)c2)cc(N(c2cccc(-c3ccccc3)c2)c2c(-c3ccccc3)cccc2-c2ccccc2)c1]

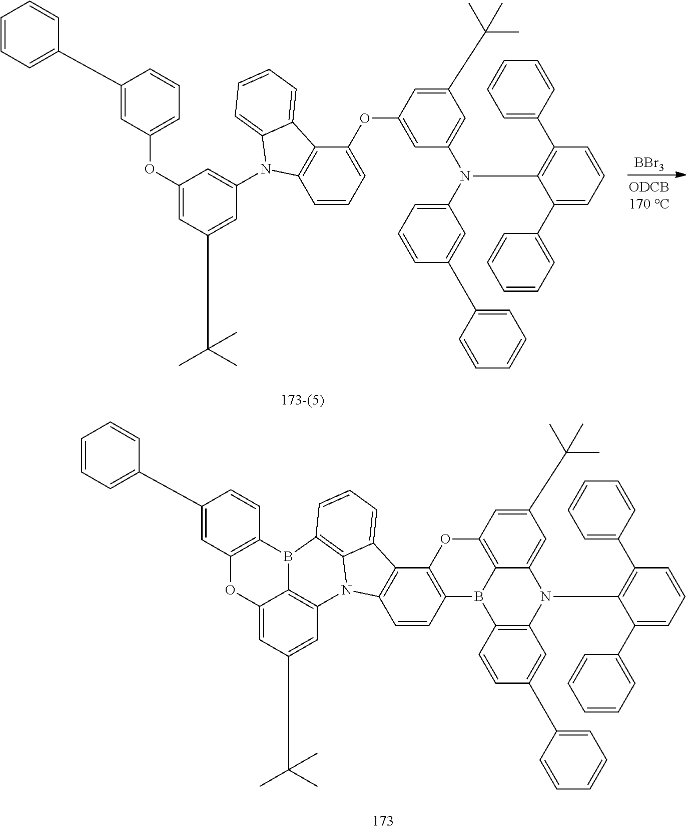

### Synthesis of Intermediate Compound 173-(1)

1,3-Dibromo-5-(tert-butyl)benzene (15.02 g, 51.44 mmol), [1,1′-biphenyl]-3-ol (8.76 g, 51.44 mmol), CuI (10.78 g, 56.58 mmol), K₂CO₃ (28.43 g, 205.75 mmol), and dipivaloylmethane (107.76 g, 0.58 mmol) were added to dimethylformamide (DMF, 1077 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 173-(1) (10.79 g, yield of 55%). A molecular weight (as represented by the mass-to-charge ratio (m/z)) of the obtained purified product, as measured by FAB MS, was confirmed to be about 381 m/z, and thus obtaining Intermediate Compound 173-(1), which was a target product, was clearly identified.

### Synthesis of Intermediate Compound 173-(2)

Under an argon atmosphere, 1,3-dibromo-5-(tert-butyl)benzene (10.11 g, 30.82 mmol), [1,1′:3′,1″-terphenyl]-2′-amine (7.56 g, 30.82 mmol), Pd(OAc)₂ (0.21 g, 0.92 mmol), XantPhos (1.07 g, 1.85 mmol), and tBuONa (3.55 g, 36.98 mmol) were added to toluene (154 mL), and then the resultant mixture was heated and stirred at about 100° C. for about 8 hours. Thereafter, water was added, and the mixture was filtered through Celite to separate an organic layer. The organic layer was concentrated and then purified through silica gel column chromatography to obtain Intermediate Compound 173-(2) (12.24 g, yield of 87%). A molecular weight (as represented by the mass-to-charge ratio (m/z)) of the obtained purified product, as measured by FAB MS, was confirmed to be about 456 m/z, and thus obtaining Intermediate Compound 173-(2), which was a target product, was clearly identified.

### Synthesis of Intermediate Compound 173-(3)

Intermediate Compound 173-(2) (12.11 g, 26.53 mmol), 3-iodo-1,1′-biphenyl (59.46 g, 212.26 mmol), CuI (12.63 g, 66.33 mmol), and K₂CO₃ (55 g, 397.98 mmol) were added to a small amount of toluene (about 10 mL), and then the resultant mixture was heated at about 215° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 173-(3) (10.98 g, yield of 68%). A molecular weight (as represented by the mass-to-charge ratio (m/z)) of the obtained purified product, as measured by FAB MS, was confirmed to be about 609 m/z, and thus obtaining Intermediate Compound 173-(3), which was a target product, was clearly identified.

### Synthesis of Intermediate Compound 173-(4)

Intermediate Compound 173-(3) (10.05 g, 16.51 mmol), 9H-carbazol-4-ol (3.03 g, 16.51 mmol), CuI (3.46 g, 18.16 mmol), K₂CO₃ (9.13 g, 66.05 mmol), and dipivaloylmethane (34.59 g, 0.19 mmol) were added to dimethylformamide (DMF, 345 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 173-(4) (2.47 g, yield of 21%). A molecular weight (as represented by the mass-to-charge ratio (m/z)) of the obtained purified product, as measured by FAB MS, was confirmed to be about 711 m/z, and thus obtaining Intermediate Compound 173-(4), which was a target product, was clearly identified.

### Synthesis of Intermediate Compound 173-(5)

Intermediate Compound 173-(1) (1.25 g, 3.28 mmol), Intermediate Compound 173-(4) (2.33 g, 3.28 mmol), CuI (0.69 g, 3.61 mmol), K₂CO₃ (1.81 g, 13.11 mmol), and dipivaloylmethane (6.87 g, 0.04 mmol) were added to dimethylformamide (DMF, 68 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 173-(5) (2.88 g, yield of 87%). A molecular weight (as represented by the mass-to-charge ratio (m/z)) of the obtained purified product, as measured by FAB MS, was confirmed to be about 1011 m/z, and thus obtaining Intermediate Compound 173-(5), which was a target product, was clearly identified.

### Synthesis of Compound 173

Under an argon atmosphere, Intermediate Compound 173-(5) (2.51 g, 2.48 mmol) was dissolved in ortho-dichlorobenzene (ODCB, 25 mL), BBr₃ (2.49 g, 9.93 mmol) was added, and then the resultant mixture was heated and stirred at about 170° C. for about 10 hours. Thereafter, the mixture was cooled to a room temperature, then N,N-diisopropylethylamine (DIPEA, 3.84 g, 29.78 mmol) was added, water was added, and the mixture was filtered through Celite to separate an organic layer. The organic layer was concentrated and then purified through silica gel column chromatography to obtain Compound 173 (1.48 g, yield of 58%). A molecular weight (as represented by the mass-to-charge ratio (m/z)) of the obtained purified product, as measured by FAB MS, was confirmed to be about 1027 m/z, and thus obtaining Compound 173, which was a target product, was clearly identified. Compound 173 was purified by sublimation in a condition of about 360° C. and about 2.5×10⁻³ Pa and was used as an emission layer of the light-emitting element.

### (4) Synthesis of Fused Polycyclic Compound 245

Fused Polycyclic Compound 245 according to one example may be synthesized by, for example, methods in Reaction Scheme 4.

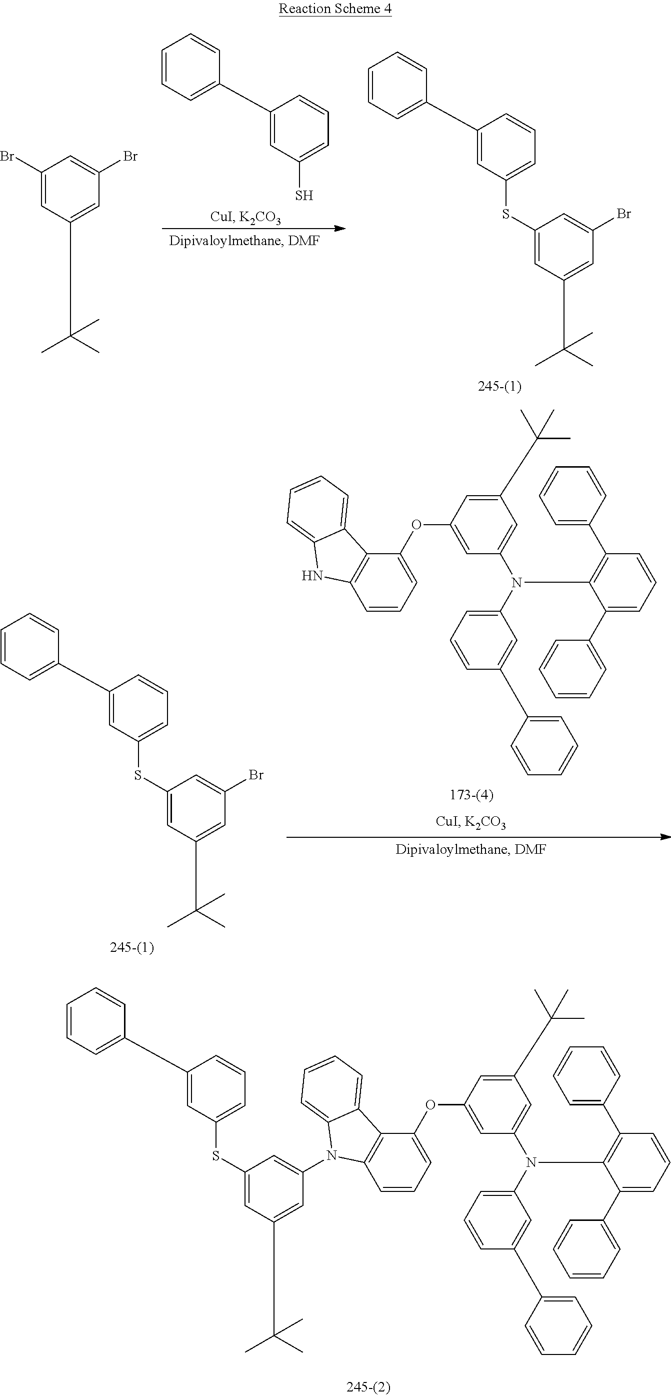

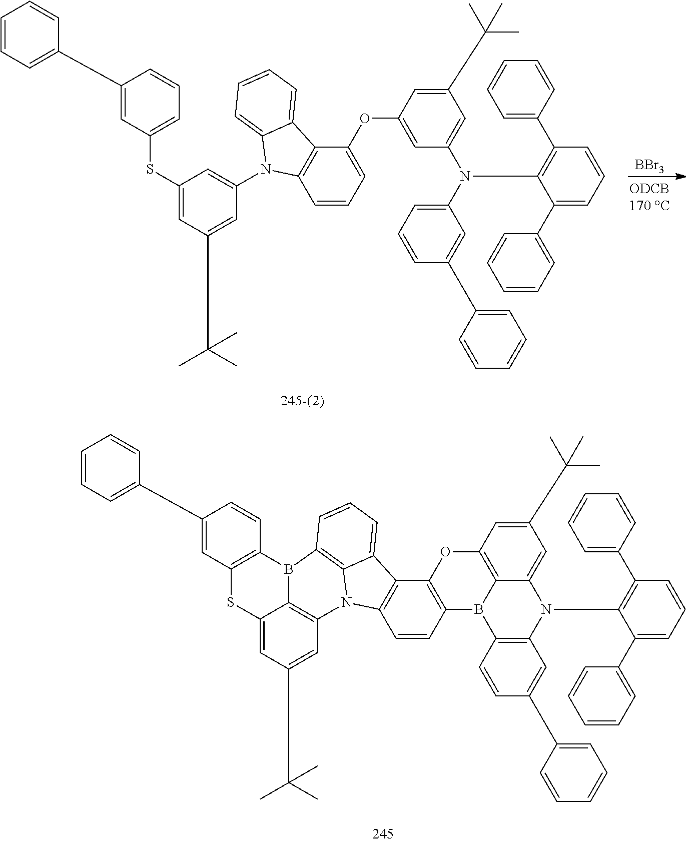

### Synthesis of Intermediate Compound 245-(1)

1,3-Dibromo-5-(tert-butyl)benzene (10.21 g, 34.96 mmol), [1,1′-biphenyl]-3-thiol (6.51 g, 34.96 mmol), Gui (7.32 g, 38.46 mmol), K₂CO₃ (19.33 g, 139.86 mmol), and dipivaloylmethane (73.25 g, 0.4 mmol) were added to dimethylformamide (DMF, 732 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 245-(1) (9.03 g, yield of 65%). A molecular weight (as represented by the mass-to-charge ratio (m/z)) of the obtained purified product, as measured by FAB MS, was confirmed to be about 397 m/z, and thus obtaining Intermediate Compound 245-(1), which was a target product, was clearly identified.

### Synthesis of Intermediate Compound 245-(2)

Intermediate Compound 245-(1) (1.22 g, 3.07 mmol), Intermediate Compound 173-(4) (2.18 g, 3.07 mmol), CuI (0.64 g, 3.38 mmol), K₂CO₃ (1.7 g, 12.28 mmol), and dipivaloylmethane (6.43 g, 0.03 mmol) were added to dimethylformamide (DMF, 64 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 245-(2) (2.65 g, yield of 84%). A molecular weight (as represented by the mass-to-charge ratio (m/z)) of the obtained purified product, as measured by FAB MS, was confirmed to be about 1027 m/z, and thus obtaining Intermediate Compound 245-(2), which was a target product, was clearly identified.

### Synthesis of Compound 245

Under an argon atmosphere, Intermediate Compound 245-(2) (2.55 g, 2.48 mmol) was dissolved in ortho-dichlorobenzene (ODCB, 25 mL), BBr₃ (2.49 g, 9.93 mmol) was added, and then the resultant mixture was heated and stirred at about 170° C. for about 10 hours. Thereafter, the mixture was cooled to a room temperature, then N,N-diisopropylethylamine (DIPEA, 3.84 g, 29.78 mmol) was added, water was added, and the mixture was filtered through Celite to separate an organic layer. The organic layer was concentrated and then purified through silica gel column chromatography to obtain Compound 245 (1.11 g, yield of 43%). A molecular weight (as represented by the mass-to-charge ratio (m/z)) of the obtained purified product, as measured by FAB MS, was confirmed to be about 1043 m/z, and thus obtaining Compound 245, which was a target product, was clearly identified. Compound 245 was purified by sublimation in a condition of about 360° C. and about 2.8×10⁻³ Pa and was used as an emission layer of the light-emitting element.

### (5) Synthesis of Fused Polycyclic Compound 390

Fused Polycyclic Compound 390 according to one example may be synthesized by, for example, methods in Reaction Scheme 5.

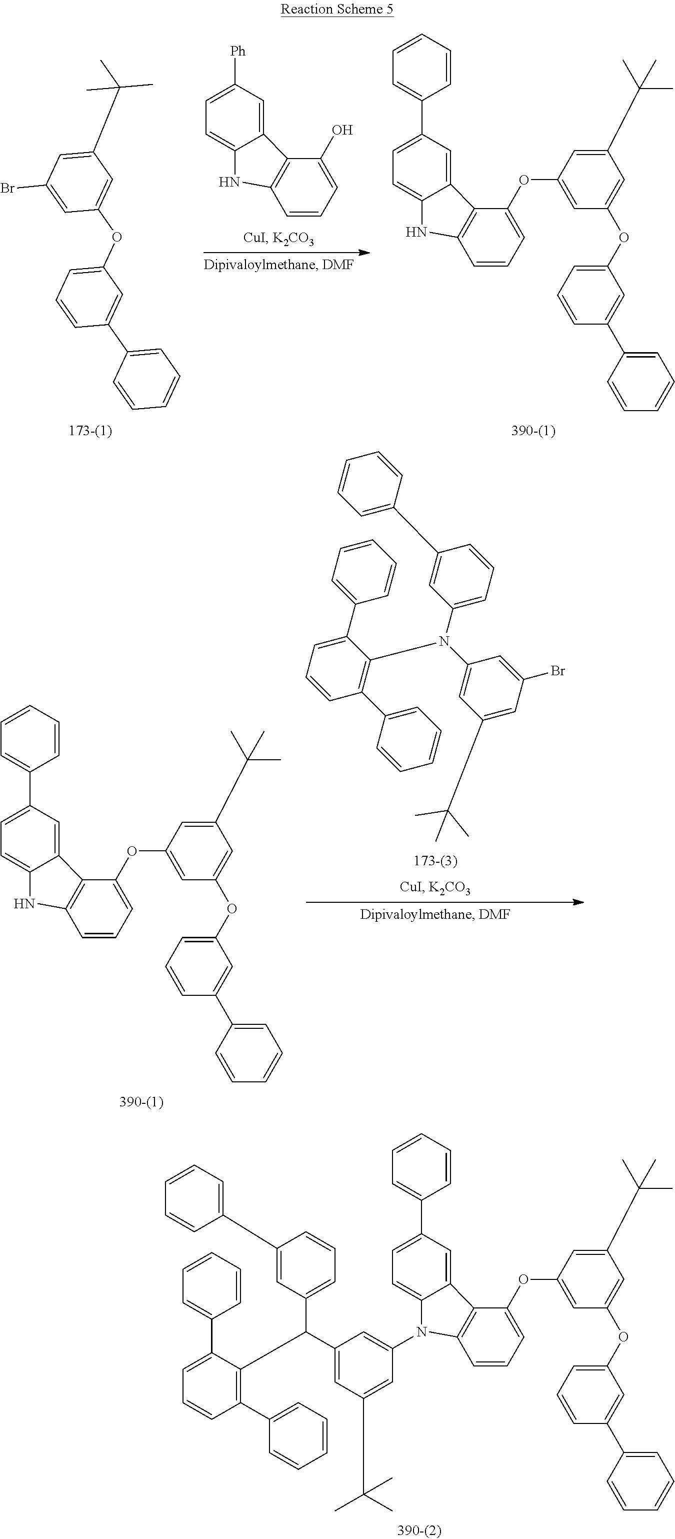 [SMILES: CC(C)(C)c1cc(Br)cc(Oc2cccc(-c3ccccc3)c2)c1 ; Oc1cccc2[nH]c3ccc(-c4ccccc4)cc3c12 ; CC(C)(C)c1cc(Oc2cccc(-c3ccccc3)c2)cc(Oc2cccc3[nH]c4ccc(-c5ccccc5)cc4c23)c1 ; CC(C)(C)c1cc(Oc2cccc(-c3ccccc3)c2)cc(Oc2cccc3[nH]c4ccc(-c5ccccc5)cc4c23)c1 ; CC(C)(C)c1cc(Br)cc(N(c2cccc(-c3ccccc3)c2)c2c(-c3ccccc3)cccc2-c2ccccc2)c1 ; CC(C)(C)c1cc(Oc2cccc(-c3ccccc3)c2)cc(Oc2cccc3c2c2cc(-c4ccccc4)ccc2n3-c2cc(C(c3cccc(-c4ccccc4)c3)c3c(-c4ccccc4)cccc3-c3ccccc3)cc(C(C)(C)C)c2)c1]

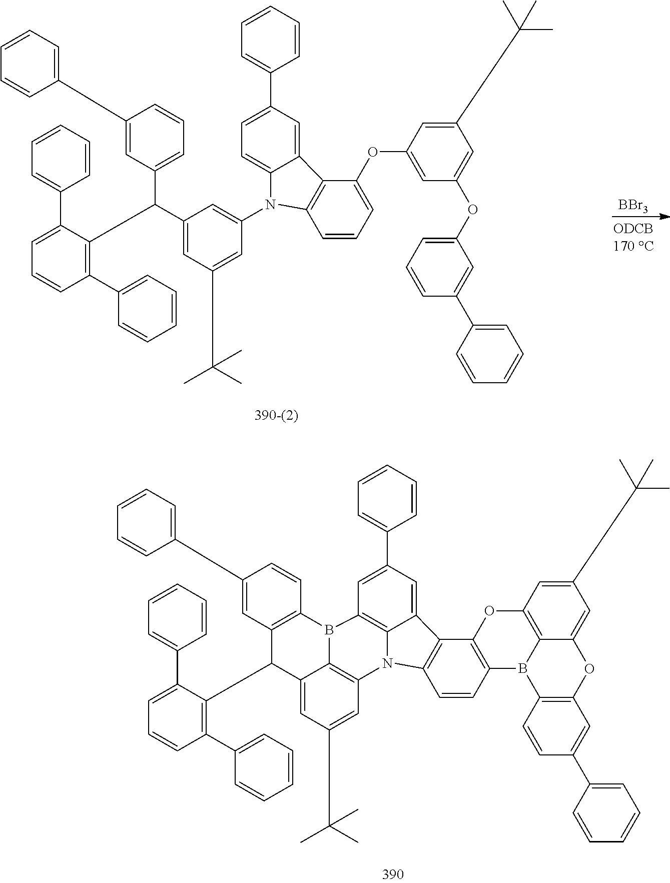 [SMILES: CC(C)(C)c1cc(Oc2cccc(-c3ccccc3)c2)cc(Oc2cccc3c2c2cc(-c4ccccc4)ccc2n3-c2cc(C(c3cccc(-c4ccccc4)c3)c3c(-c4ccccc4)cccc3-c3ccccc3)cc(C(C)(C)C)c2)c1 ; "BBr3" ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1C4c1c(-c4ccccc4)cccc1-c1ccccc1)B3c1ccc(-c3ccccc3)cc1O2]

### Synthesis of Intermediate Compound 390-(1)

Intermediate Compound 173-(1) (15.55 g, 40.78 mmol), 6-phenyl-9H-carbazol-4-ol (10.57 g, 40.78 mmol), CuI (8.54 g, 44.86 mmol), K₂CO₃ (22.54 g, 163.12 mmol), and dipivaloylmethane (85.43 g, 0.46 mmol) were added to dimethylformamide (DMF, 854 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 390-(1) (7.54 g, yield of 33%). A molecular weight (as represented by the mass-to-charge ratio (m/z)) of the obtained purified product, as measured by FAB MS, was confirmed to be about 560 m/z, and thus obtaining Intermediate Compound 390-(1), which was a target product, was clearly identified.

### Synthesis of Intermediate Compound 390-(2)

Intermediate Compound 390-(1) (6.02 g, 10.76 mmol), Intermediate Compound 173-(3) (6.55 g, 10.76 mmol), CuI (2.25 g, 11.83 mmol), K₂CO₃ (5.95 g, 43.02 mmol), and dipivaloylmethane (22.53 g, 0.12 mmol) were added to dimethylformamide (DMF, 225 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 390-(2) (10.06 g, yield of 86%). A molecular weight (as represented by the mass-to-charge ratio (m/z)) of the obtained purified product, as measured by FAB MS, was confirmed to be about 1087 m/z, and thus obtaining Intermediate Compound 390-(2), which was a target product, was clearly identified.

### Synthesis of Compound 390

Under an argon atmosphere, Intermediate Compound 390-(2) (5.12 g, 4.71 mmol) was dissolved in ortho-dichlorobenzene (ODCB, 47 mL), BBr₃ (4.72 g, 18.83 mmol) was added, and then the resultant mixture was heated and stirred at about 170° C. for about 10 hours. Thereafter, the mixture was cooled to a room temperature, then N,N-diisopropylethylamine (DIPEA, 7.29 g, 56.5 mmol) was added, water was added, and the mixture was filtered through Celite to separate an organic layer. The organic layer was concentrated and then purified through silica gel column chromatography to obtain Compound 390 (2.39 g, yield of 46%). A molecular weight (as represented by the mass-to-charge ratio (m/z)) of the obtained purified product, as measured by FAB MS, was confirmed to be about 1103 m/z, and thus obtaining Compound 390, which was a target product, was clearly identified. Compound 390 was purified by sublimation in a condition of about 360° C. and about 2.3×10⁻³ Pa and was used as an emission layer of the light-emitting element.

### (6) Synthesis of Fused Polycyclic Compound 513

Fused Polycyclic Compound 513 according to one example may be synthesized by, for example, methods in Reaction Scheme 6.

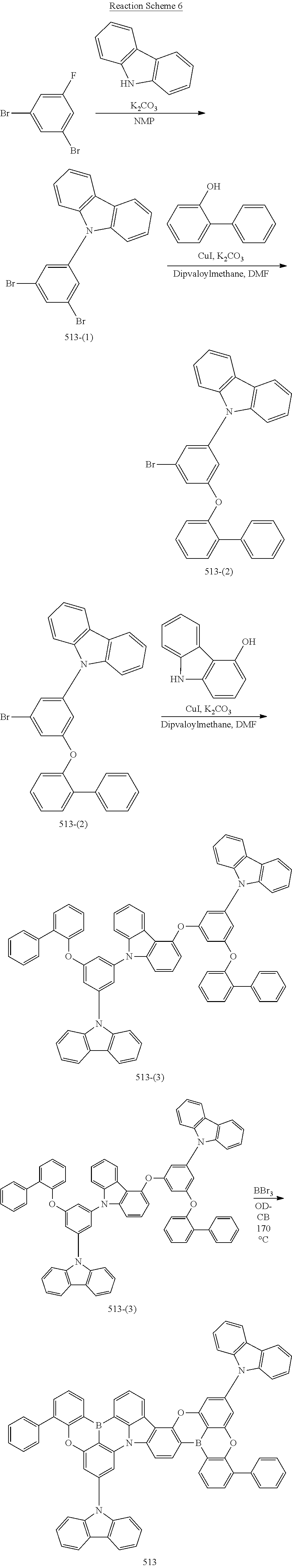

### Synthesis of Intermediate Compound 513-(1)

Under an argon atmosphere, 1,3-dibromo-5-fluorobenzene (8.23 g, 32.41 mmol), 9H-carbazole (5.42 g, 32.41 mmol), and K₂CO₃ (20.16 g, 145.86 mmol) were added to N-methyl-2-pyrrolidone (NMP, 82 mL), and then the resultant mixture was heated at about 140° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 513-(1) (10.01 g, yield of 77%). A molecular weight (as represented by the mass-to-charge ratio (m/z)) of the obtained purified product, as measured by FAB MS, was confirmed to be about 401 m/z, and thus obtaining Intermediate Compound 513-(1), which was a target product, was clearly identified.

### Synthesis of Intermediate Compound 513-(2)

Intermediate Compound 513-(1) (9.56 g, 23.83 mmol), [1,1′-biphenyl]-2-ol (4.06 g, 23.83 mmol), CuI (4.99 g, 26.22 mmol), K₂CO₃ (13.18 g, 95.34 mmol), and dipivaloylmethane (49.93 g, 0.27 mmol) were added to dimethylformamide (DMF, 499 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 513-(2) (7.25 g, yield of 62%). A molecular weight (as represented by the mass-to-charge ratio (m/z)) of the obtained purified product, as measured by FAB MS, was confirmed to be about 490 m/z, and thus obtaining Intermediate Compound 513-(2), which was a target product, was clearly identified.

### Synthesis of Intermediate Compound 513-(3)

Intermediate Compound 513-(2) (6.86 g, 13.98 mmol), 9H-carbazol-4-ol (1.22 g, 6.66 mmol), CuI (1.4 g, 7.32 mmol), K₂CO₃ (3.68 g, 26.64 mmol), and dipivaloylmethane (13.95 g, 0.08 mmol) were added to dimethylformamide (DMF, 139 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 513-(3) (5.21 g, yield of 78%). A molecular weight (as represented by the mass-to-charge ratio (m/z)) of the obtained purified product, as measured by FAB MS, was confirmed to be about 1002 m/z, and thus obtaining Intermediate Compound 513-(3), which was a target product, was clearly identified.

### Synthesis of Compound 513

Under an argon atmosphere, Intermediate Compound 513-(3) (4.87 g, 4.86 mmol) was dissolved in ortho-dichlorobenzene (ODCB, 49 mL), BBr₃ (4.87 g, 19.44 mmol) was added, and then the resultant mixture was heated and stirred at about 170° C. for about 10 hours. Thereafter, the mixture was cooled to a room temperature, then N,N-diisopropylethylamine (DIPEA, 7.52 g, 58.31 mmol) was added, water was added, and the mixture was filtered through Celite to separate an organic layer. The organic layer was concentrated and then purified through silica gel column chromatography to obtain Compound 513 (1.93 g, yield of 39%). A molecular weight (as represented by the mass-to-charge ratio (m/z)) of the obtained purified product, as measured by FAB MS, was confirmed to be about 1018 m/z, and thus obtaining Compound 513, which was a target product, was clearly identified. Compound 513 was purified by sublimation in a condition of about 350° C. and about 2.7×10⁻³ Pa and was used as an emission layer of the light-emitting element.

### (7) Synthesis of Fused Polycyclic Compound 579

Fused Polycyclic Compound 579 according to one example may be synthesized by, for example, methods in Reaction Scheme 7. Reaction Scheme 7

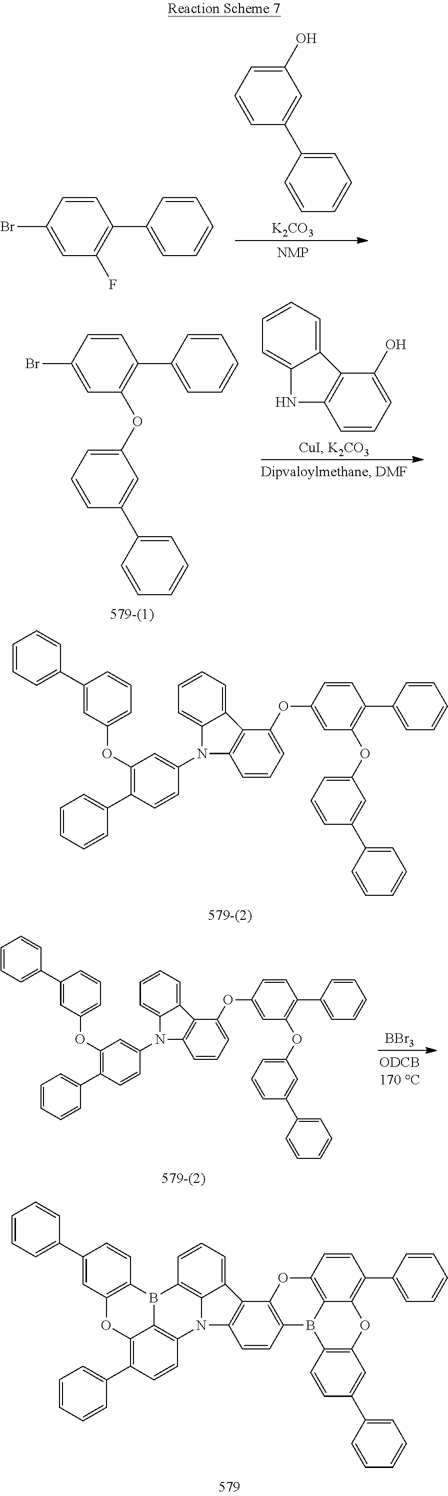

### Synthesis of Intermediate Compound 579-(1)

Under an argon atmosphere, 4-bromo-2-fluoro-1,1′-biphenyl (10.2 g, 40.62 mmol), [1,1′-biphenyl]-3-ol (6.91 g, 40.62 mmol), and K₂CO₃ (25.26 g, 182.8 mmol) were added to N-methyl-2-pyrrolidone (NMP, 102 mL), and then the resultant mixture was heated at about 140° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 579-(1) (9.13 g, yield of 56%). A molecular weight (as represented by the mass-to-charge ratio (m/z)) of the obtained purified product, as measured by FAB MS, was confirmed to be about 401 m/z, and thus obtaining Intermediate Compound 579-(1), which was a target product, was clearly identified.

### Synthesis of Intermediate Compound 579-(2)

Intermediate Compound 579-(2) (8.83 g, 22.01 mmol), 9H-carbazol-4-ol (1.92 g, 10.48 mmol), CuI (2.2 g, 11.53 mmol), K₂CO₃ (5.79 g, 41.92 mmol), and dipivaloylmethane (21.95 g, 0.12 mmol) were added to dimethylformamide (DMF, 219 mL), and then the resultant mixture was heated at about 100° C. for about 24 hours. Thereafter, the mixture was diluted with dichloromethane (CH₂Cl₂), water was added, and the mixture was filtered through Celite to separate an organic layer. The organic layer was concentrated and then purified through silica gel column chromatography to obtain Intermediate Compound 579-(2) (6.39 g, yield of 74%). A molecular weight (as represented by the mass-to-charge ratio (m/z)) of the obtained purified product, as measured by FAB MS, was confirmed to be about 824 m/z, and thus obtaining of Intermediate Compound 579-(2), which was a target product, was clearly identified.

### Synthesis of Compound 579

Under an argon atmosphere, Intermediate Compound 579-(2) (6.11 g, 7.42 mmol) was dissolved in ortho-dichlorobenzene (ODCB, 74 mL), BBr₃ (7.43 g, 29.66 mmol) was added, and then the resultant mixture was heated and stirred at about 170° C. for about 10 hours. Thereafter, the mixture was cooled to a room temperature, then N,N-diisopropylethylamine (DIPEA, 11.48 g, 88.98 mmol) was added, water was added, and the mixture was filtered through Celite to separate an organic layer. The organic layer was concentrated and then purified through silica gel column chromatography to obtain Compound 579 (2.74 g, yield of 44%). A molecular weight (as represented by the mass-to-charge ratio (m/z)) of the obtained purified product, as measured by FAB MS, was confirmed to be about 840 m/z, and thus obtaining Compound 579, which was a target product, was clearly identified. Compound 579 was purified by sublimation in a condition of about 330° C. and about 2.5×10⁻³ Pa and was used as an emission layer of the light-emitting element.

### 2. Manufacture and Evaluation of Light-Emitting Element

### (1) Manufacture of Light-Emitting Element

The light-emitting elements respectively including the fused polycyclic compounds according to Examples or Comparative Example Compounds in the emission layer were manufactured by the following method. The light-emitting elements according to Examples 1 to 7 were manufactured respectively using Compounds 25, 37, 173, 245, 390, 513, and 579, which are the fused polycyclic compounds according to Examples, as a dopant material for the emission layer. The light-emitting elements according to Comparative Examples 1 to 3 were manufactured respectively using Comparative Example Compounds X1 to X3 as a dopant material of the emission layer. The element was manufactured with the following layer structure and was evaluated.

### Example Compounds

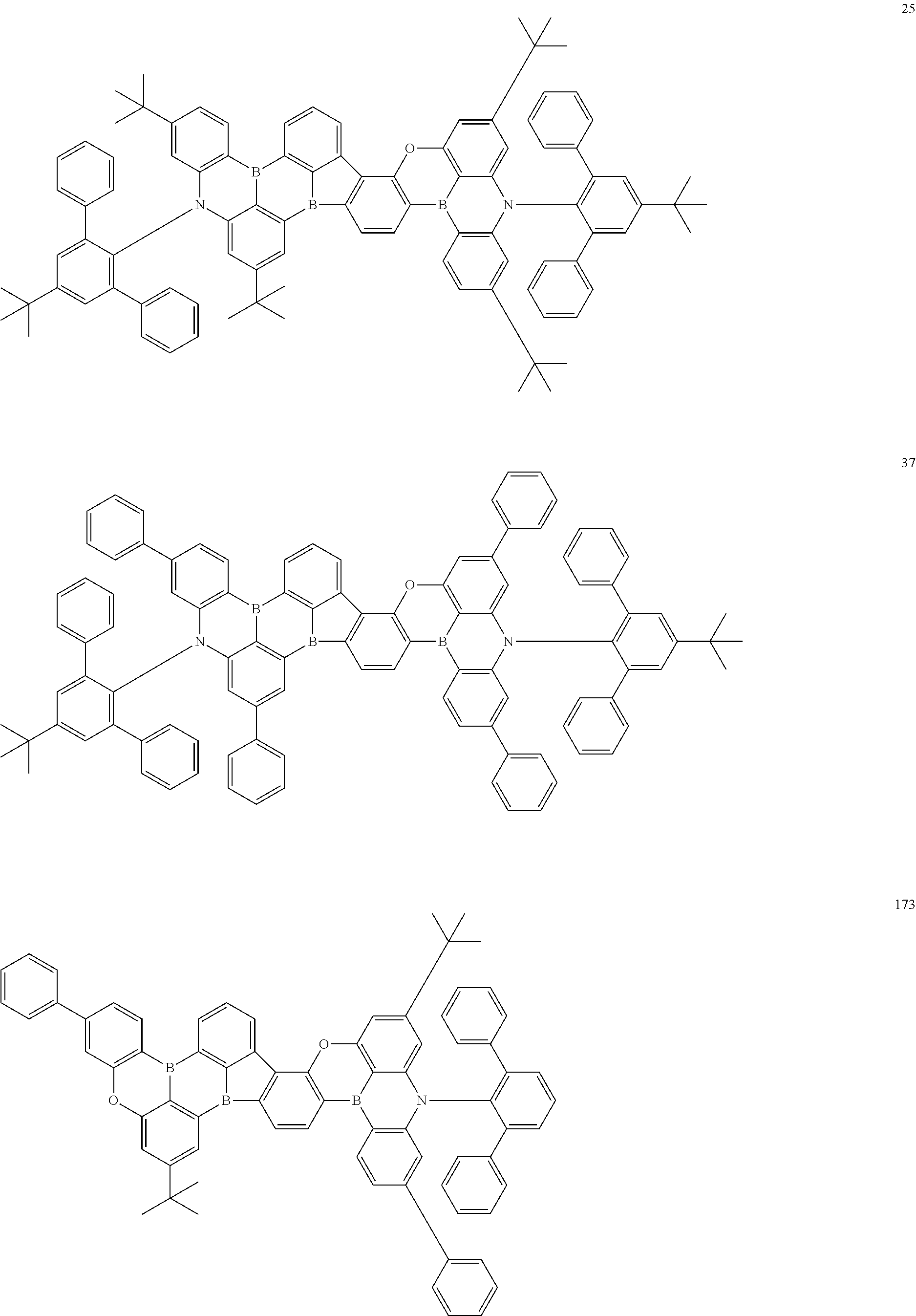

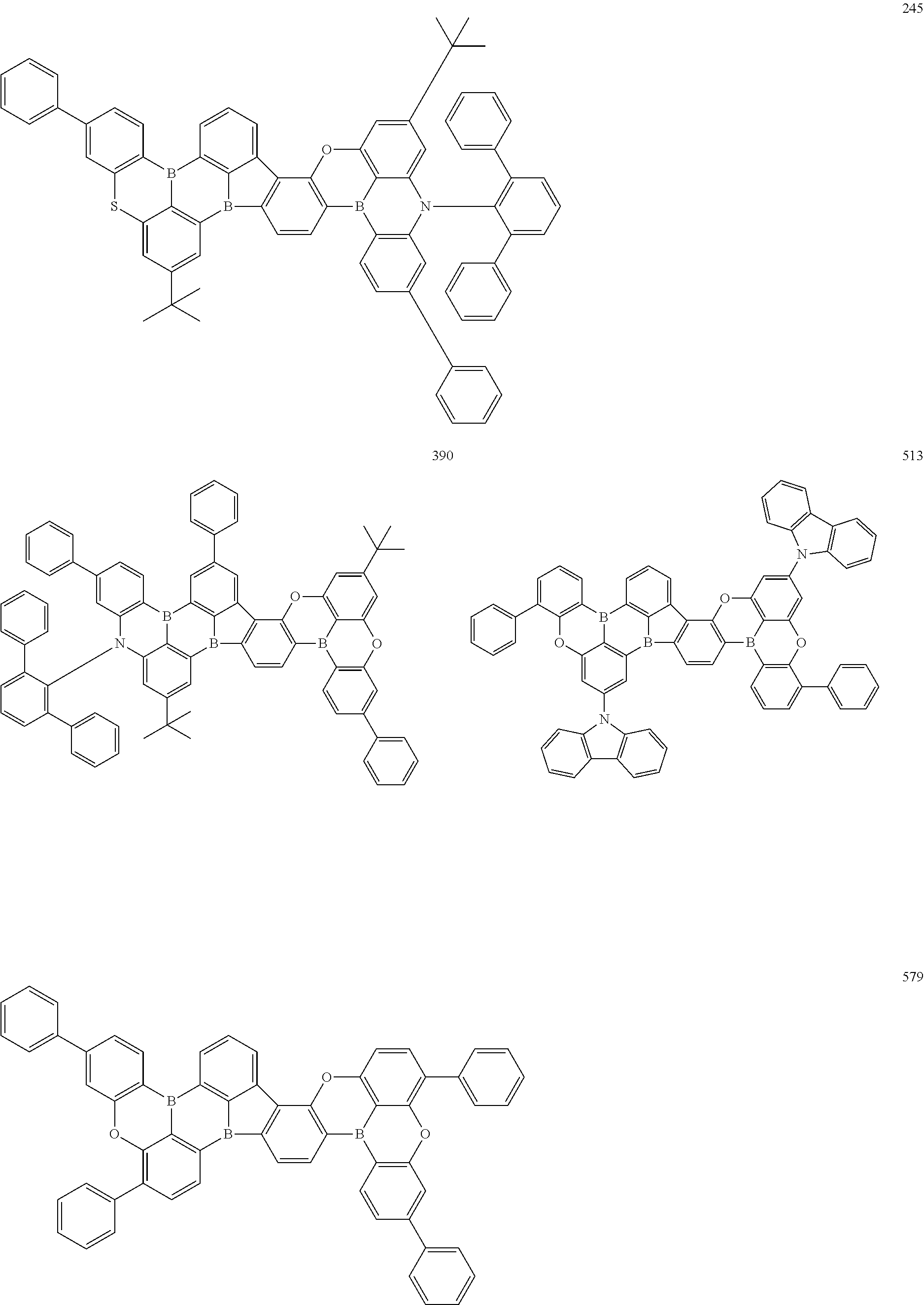

### Comparative Example Compounds

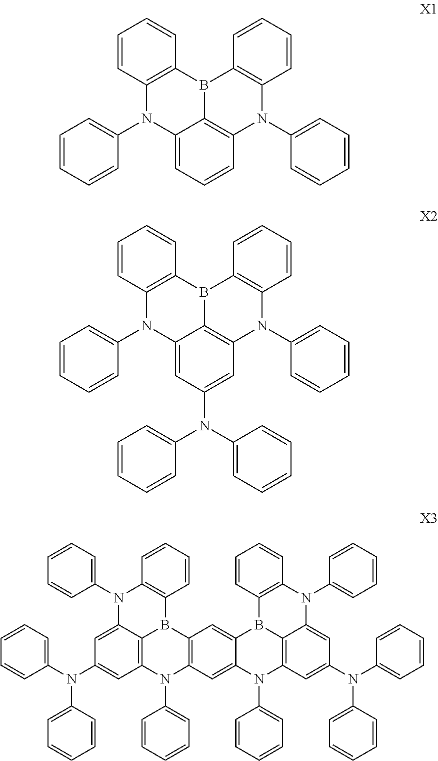 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

Layer structure: ITO/HAT-CN (10 nm)/α-NPD (80 nm)/mCP (5 nm)/1% dopant: mCBP (20 nm)/TPBi (30 nm)/LiF (0.5 nm)/Al (100 nm)

For example, a first electrode having a thickness of about 150 nm was formed with ITO and a hole injection layer having a thickness of about 10 nm was formed on the first electrode with dipyrazino[2,3-f:2′,3′-h]quinoxaline-2,3,6,7,10,11-hexacarbonitrile (HAT-CN).

A hole transport layer having a thickness of about 80 nm was formed on the hole injection layer with N,N′-bis(naphthalen-1-yl)-N,N′-bis(phenyl)-2,2′-dimethylbenzidine (α-NPD), and an electron-blocking layer having a thickness of about 5 nm was formed on the hole transport layer with 1,3-bis(N-carbazolyl)benzene (mCP).

Example Compounds or Comparative Example Compounds, and 3,3′-di(9H-carbazol-9-yl)-1,1′-biphenyl (mCBP) were provided on the electron-blocking layer at a weight ratio of about 1:99 to form an emission layer having a thickness of about 20 nm. An electron transport layer having a thickness of about 30 nm was formed on the emission layer with 2,2′,2″-(1,3,5-benzinetriyl)-tris(1-phenyl-1-H-benzimidazole) (TPBi), and an electron injection layer having a thickness of about 0.5 nm was formed on the electron transport layer with LiF.

A second electrode having a thickness of about 100 nm was formed on the electron injection layer with aluminum (Al). Each layer was formed through deposition under vacuum atmosphere.

### Materials Used in Manufacture of Light-Emitting Elements

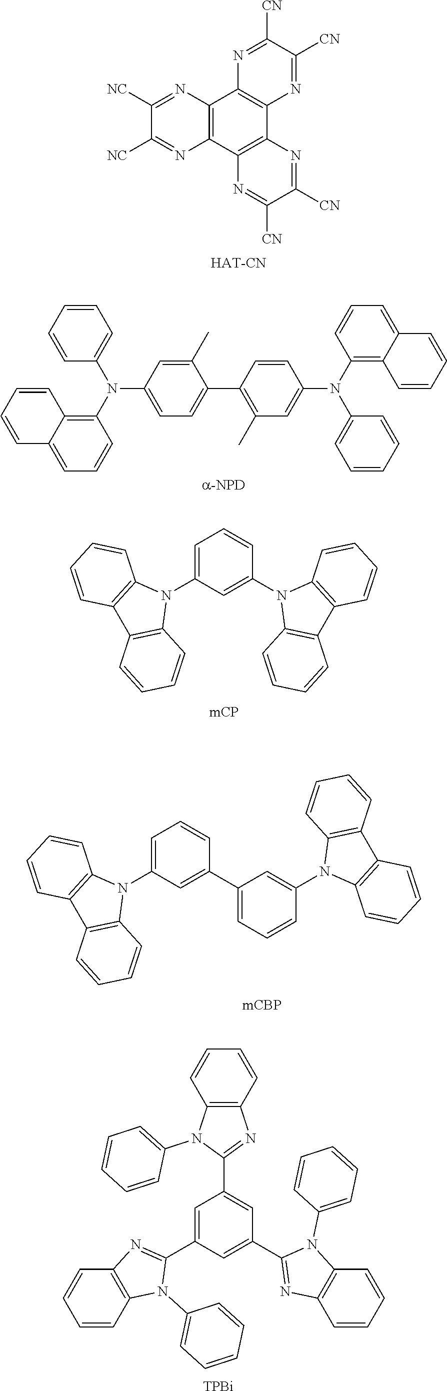

### (2) Evaluation of Light-Emitting Element

The light-emitting elements according to Examples and Comparative Examples were evaluated and the results are listed in Table 1. The peak emission wavelength (λₘₐₓ) and the relative lifespan (LT₅₀) in Table 1 were measured using an external quantum efficiency measurement system C9920-12 manufactured by Hamamatsu Photonics K.K. The peak emission wavelength (λₘₐₓ) was listed by measuring a wavelength of a position at which an emission intensity is maximum in an emission spectrum. A half lifespan of the light-emitting element according to Comparative Example 3, as determined by measuring PL of a thin film of 1% dopant:mCBP (20 nm), was set to 1, and a value of each light-emitting element relative to the half lifespan of Comparative Example 3 is listed as the relative lifespan (LT₅₀).

TABLE 1

| Examples of | | | LT₅₀ |
|---|---|---|---|
| manufacture of | | λₘₐₓ | Relative |
| elements | Dopant | nm | lifespan |
| Example 1 | Example Compound 25 | 470 | 3.8 |
| Example 2 | Example Compound 37 | 478 | 6.2 |
| Example 3 | Example Compound 173 | 458 | 6.6 |
| Example 4 | Example Compound 245 | 465 | 3.2 |
| Example 5 | Example Compound 390 | 461 | 4.8 |
| Example 6 | Example Compound 513 | 455 | 3.2 |
| Example 7 | Example Compound 579 | 458 | 4.6 |
| Comparative | Comparative Example Compound X1 | 457 | 0.3 |
| Example 1 | | | |
| Comparative | Comparative Example Compound X2 | 446 | 0.2 |
| Example 2 | | | |
| Comparative | Comparative Example Compound X3 | 467 | 1.0 |
| Example 3 | | | |

Referring to Table 1, it can be seen that the light-emitting elements according to Examples and Comparative Examples emit light in a wavelength region of about 440 nm to about 480Gm. It can be seen that, as compared to the light-emitting elements according to Comparative Examples 1 to 3, the light-emitting elements according to Examples 1 to 7 each exhibit 3.2- to 6.6-fold improved or enhanced relative lifespan. The light-emitting elements according to Examples 1 to 7 respectively include Compounds 25, 37, 173, 245, 390, 513, and 579, which are fused polycyclic compounds according to Examples.

Compounds 25, 37, 173, 245, 390, 513, and 579 are fused polycyclic compounds according to Examples and each include, as a core structure, a fused polycyclic ring with 11 rings in which a carbazole ring is fused with two or more rings. The fused polycyclic compound according to one or more embodiments includes a carbazole ring, has a large resonance or conjugation, and exhibit improved or enhanced molar extinction coefficient (ε) and oscillator strength. Therefore, the fused polycyclic compound according to one or more embodiments may exhibit excellent or suitable material stability and contribute to improvements or enhancements in lifespan of the light-emitting element.

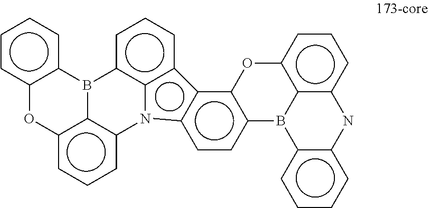

Structural Formula 173-core represents a core structure of Example Compound 173. Referring to Structural Formula 173-core, it can be seen that Example Compound 173 includes a carbazole ring in the core structure, and seven aromatic rings are conjugated. Therefore, the fused polycyclic compound according to one or more embodiments has an increase in a molar extinction coefficient and thus may contribute to improvements or enhancements in lifespan of the light-emitting element. Also, referring to Structural Formula 173-core, it can be seen that Example Compound 173 has a conjugation distributed across a wide range of the core structure. Therefore, the fused polycyclic compound according to one or more embodiments has improved or enhanced electrical and physical stability and may contribute to improvements or enhancements in efficiency of the light-emitting element including the fused polycyclic compound according to one or more embodiments.

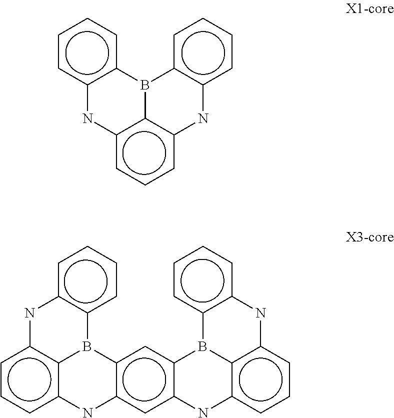

Structural Formula X1-core exhibits a core structure of Comparative Example Compounds X1 and X2, and Structural Formula X3-core exhibits a core structure of Comparative Example Compound X3. Comparative Example Compound X3 represents v-DABNA which is a compound that is generally available or generally used.

Referring to Structural Formula X1-core, it can be seen that Comparative Example Compounds X1 and X2 each do not include a carbazole ring in the core structure, and three aromatic rings are conjugated. Also, referring to Structural Formula X3-core, it can be seen that Comparative Example Compound X3 does not include a carbazole ring in the core structure, and five aromatic rings are conjugated. Therefore, it can be confirmed that a small number of aromatic rings are conjugated in Comparative Example Compounds X1 to X3, compared to Example Compound 173. Therefore, Comparative Example Compounds X1 to X3 each exhibit a reduced molar extinction coefficient, and the light-emitting elements respectively including Comparative Example Compounds X1 to X3 may exhibit a short lifespan.

The light-emitting elements according to Comparative Examples 1 to 3 respectively include Comparative Example Compounds X1 to X3. The core structures of Comparative Example Compounds X1 and X2 are each a fused ring with five rings and do not include a carbazole ring, which differs from the fused polycyclic compound according to one or more embodiments. The core structure of Comparative Example Compound X3 is a fused ring with nine rings and does not include a carbazole ring, which differs from the fused polycyclic compound according to one or more embodiments. Therefore, the light-emitting elements according to Comparative Examples 1 to 3 exhibit reduced element stability and a short lifespan.

The electronic apparatus according to one or more embodiments may include a light-emitting element. In the light-emitting element according to one or more embodiments, the emission layer may include the fused polycyclic compound according to one or more embodiments, represented by Formula 1. The fused polycyclic compound according to one or more embodiments may include, as a core structure, a fused ring with 11 rings in which a carbazole ring is fused with two or more rings. Also, the fused polycyclic compound according to one or more embodiments may include at least one of an oxygen atom, a sulfur atom, or a nitrogen atom as a ring-forming atom at a para-position with respect to two boron atoms. Therefore, the fused polycyclic compound according to one or more embodiments may exhibit excellent or suitable material stability, and the light-emitting element including the fused polycyclic compound according to one or more embodiments may exhibit long lifespan properties.

The light-emitting element according to one or more embodiments and the electronic apparatus including the light-emitting element may include the fused polycyclic compound according to one or more embodiments and thus may exhibit long lifespan properties.

The fused polycyclic compound according to one or more embodiments may contribute to improvements or enhancements in lifespan of the light-emitting element.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although one or more embodiments of the present disclosure have been described, those skilled in the art or those of ordinary skill in the art will understand that one or more suitable modifications and changes can be made to the embodiments within the scope that does not depart from the spirit and scope of the present disclosure. Accordingly, the scope of the present disclosure should not be limited to the embodiments as described in the detailed description of the present disclosure, but should be determined by the appended claims and equivalents thereof.

What is claimed is:

1. A light-emitting element comprising:
a first electrode;
a second electrode on the first electrode; and
an emission layer between the first electrode and the second electrode and comprising a first compound represented by Formula 1: 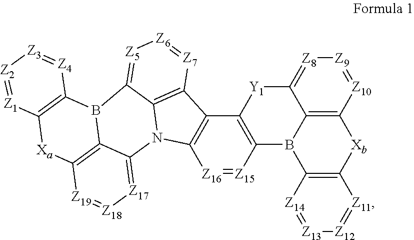
wherein, in Formula 1,
Xₐ, X_{b}, and Y₁ are each independently O, S, or NRₓ,
Z₁ to Z₁₉ are each independently N or CR_{y},
Rₓ and R_{y} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring, and
the first compound comprises a chemical structure in which one or more hydrogen atoms of the first compound are optionally substituted with deuterium atom.

2. The light-emitting element as claimed in claim 1, wherein the emission layer further comprises at least one selected from among a second compound represented by Formula HT-1, a third compound represented by Formula ET-1, and a fourth compound represented by Formula D-1: 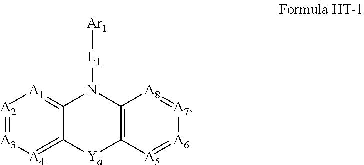
wherein, in Formula HT-1,
A₁ to A₅ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring: 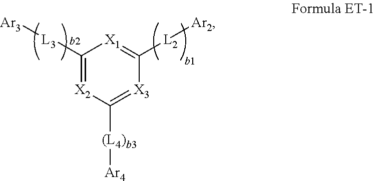
and
wherein, in Formula ET-1,
at least one selected from among X₁ to X₃ is N, and the others are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms: 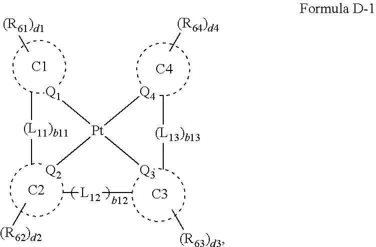
wherein, in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
L₁₁ to L₁₃ are each independently a direct linkage, *—O—*, *—S—*, 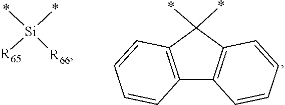
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

3. The light-emitting element as claimed in claim 1, wherein Formula 1 is represented by Formula 2: 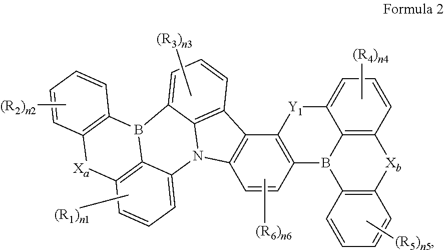
and
wherein, in Formula 2,
R₁ to R₆ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
n1, n3, and n4 are each independently an integer of 0 to 3,
n2 and n5 are each independently an integer of 0 to 4,
n6 is an integer of 0 to 2, and
Xₐ, X_{b}, and Y₁ are the same as defined in Formula 1.

4. The light-emitting element as claimed in claim 3, wherein Formula 2 is represented by any one selected from among Formula 2-1 to Formula 2-8: 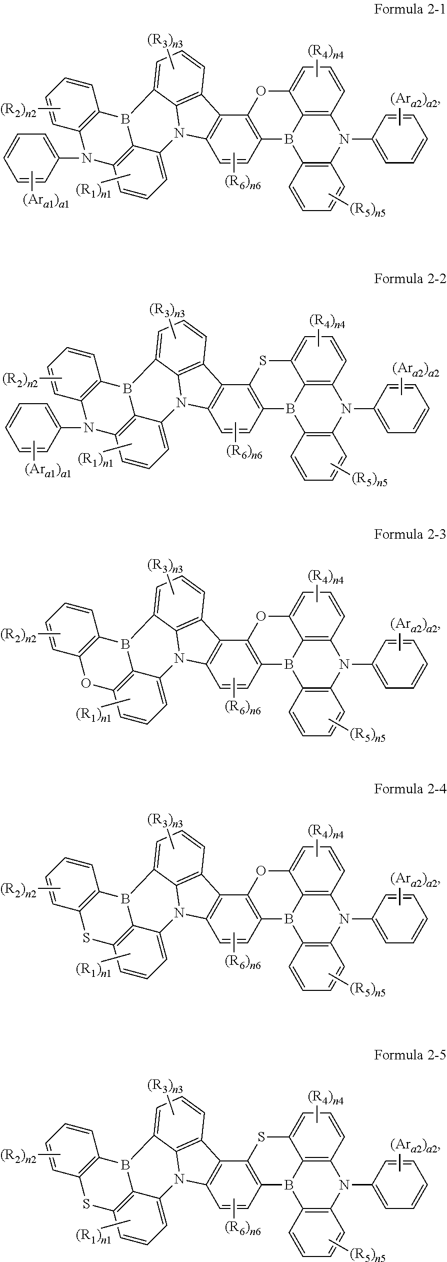 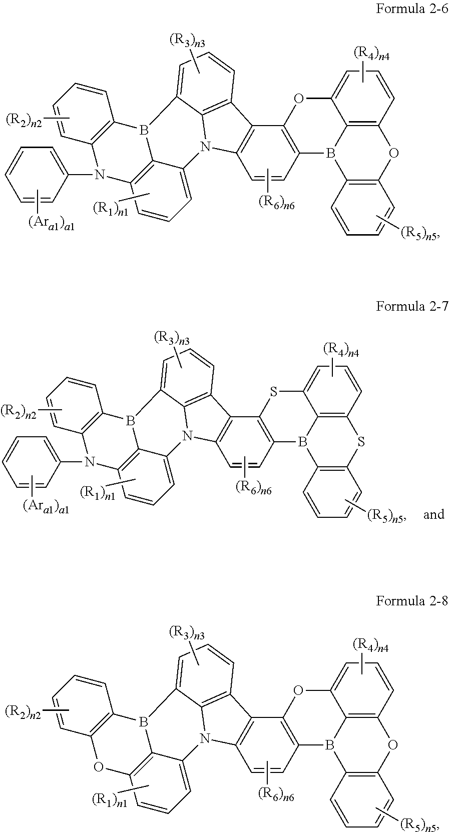
wherein, in Formula 2-1 to Formula 2-8,
Arₐ₁ and Arₐ₂ are each independently a hydrogen atom, a deuterium atom, a substituted or unsubstituted alkyl group having 1 to 20 carbon atoms, a substituted or unsubstituted cycloalkyl group having 3 to 10 ring-forming carbon atoms, or a substituted or unsubstituted aryl group having 6 to 30 ring-forming carbon atoms, and/or are bonded to an adjacent group to form a ring,
a1 and a2 are each independently an integer of 0 to 5, and
R₁ to R₆ and n1 to n6 are the same as defined in Formula 2.

5. The light-emitting element as claimed in claim 3, wherein Formula 2 is represented by Formula 3: 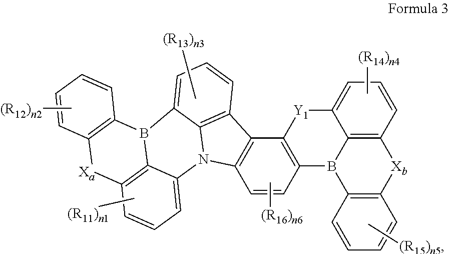
and
wherein, in Formula 3,
R₁₁ to R₁₅ are each independently a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
R₁₆ is a hydrogen atom or a deuterium atom,
n16 is an integer of 0 to 2,
Xₐ, X_{b}, and Y₁ are the same as defined in Formula 1, and
n1 to n5 are the same as defined in Formula 2.

6. The light-emitting element as claimed in claim 3, wherein Formula 2 is represented by Formula 4: 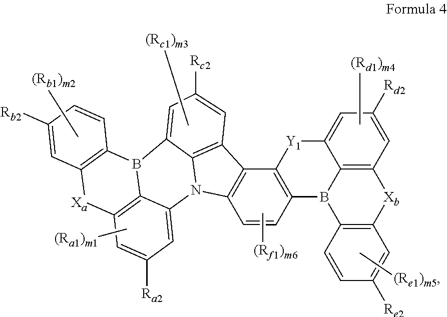
and
wherein, in Formula 4, Rₐ₁, R_{b1}, R_{c1}, R_{d1}, Rₑ₁, and R_{f1} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
Rₐ₂, R_{b2}, R_{c2}, R_{d2}, and Rₑ₂ are each independently a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
m1, m3, and m4 are each independently an integer of 0 to 2,
m2 and m5 are each independently an integer of 0 to 3,
m6 is an integer of 0 to 2, and
Xₐ, X_{b}, and Y₁ are the same as defined in Formula 1.

7. The light-emitting element as claimed in claim 3, wherein R₁ to R₆ in Formula 2 are each independently a hydrogen atom, a deuterium atom, or represented by any one selected from among R-1 to R-14: 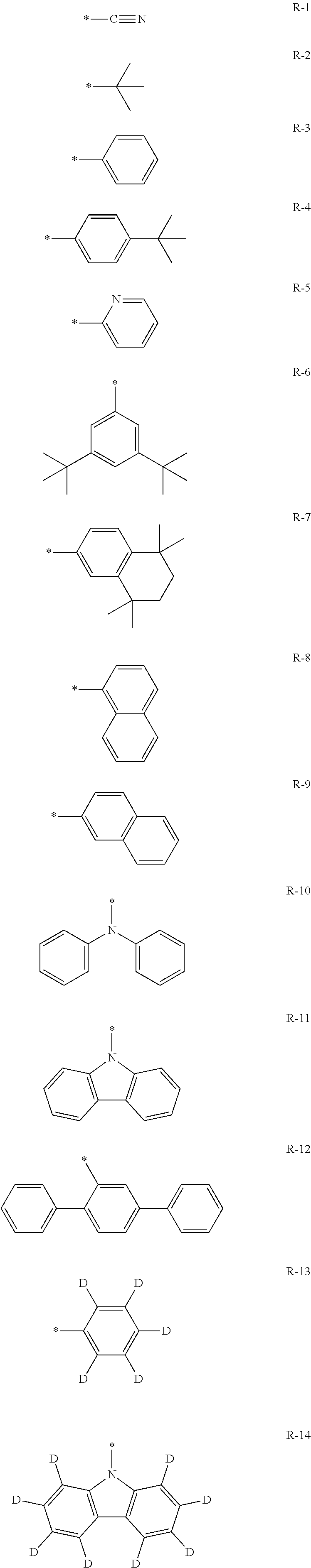
and
wherein, in R-13 and R-14, D is a deuterium atom.

8. The light-emitting element as claimed in claim 1, wherein, in Formula 1, Rₓ is a hydrogen atom, a deuterium atom, a substituted or unsubstituted phenyl group, a substituted or unsubstituted benzocyclohexyl group, a substituted or unsubstituted biphenyl group, a substituted or unsubstituted terphenyl group, or a substituted or unsubstituted quarterphenyl group.

9. The light-emitting element as claimed in claim 1, wherein, in Formula 1, Rₓ are each independently represented by any one selected from among W-1 to W-14: 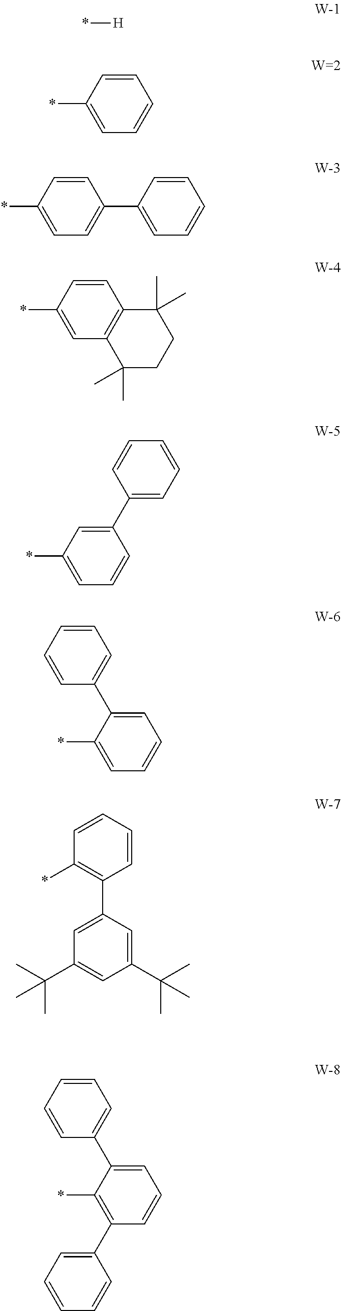 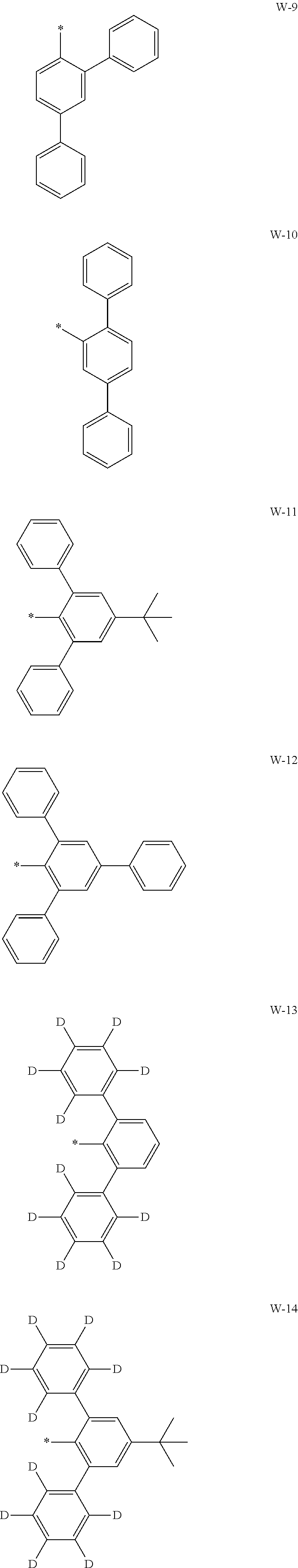 [SMILES: *c1ccc(-c2ccccc2)cc1-c1ccccc1 ; *c1cc(-c2ccccc2)ccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2c([2H])c([2H])c([2H])c([2H])c2[2H])cccc1-c1c([2H])c([2H])c([2H])c([2H])c1[2H] ; *c1c(-c2c([2H])c([2H])c([2H])c([2H])c2[2H])cc(C(C)(C)C)cc1-c1c([2H])c([2H])c([2H])c([2H])c1[2H]]
and
wherein, in W-13 and W-14, D is a deuterium atom.

10. The light-emitting element as claimed in claim 1, wherein the first compound is represented by any one selected from among the compounds in Compound Group 1: 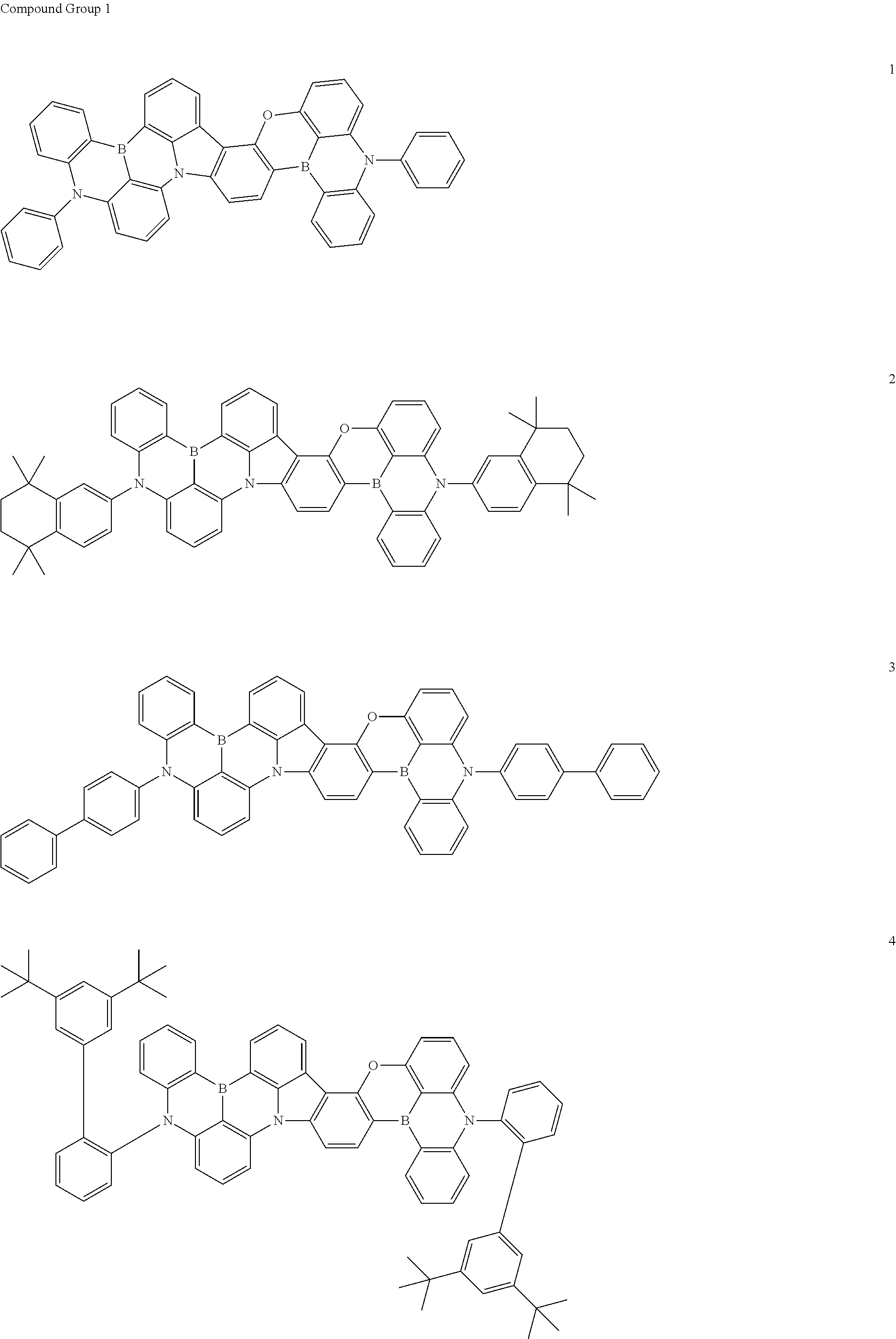 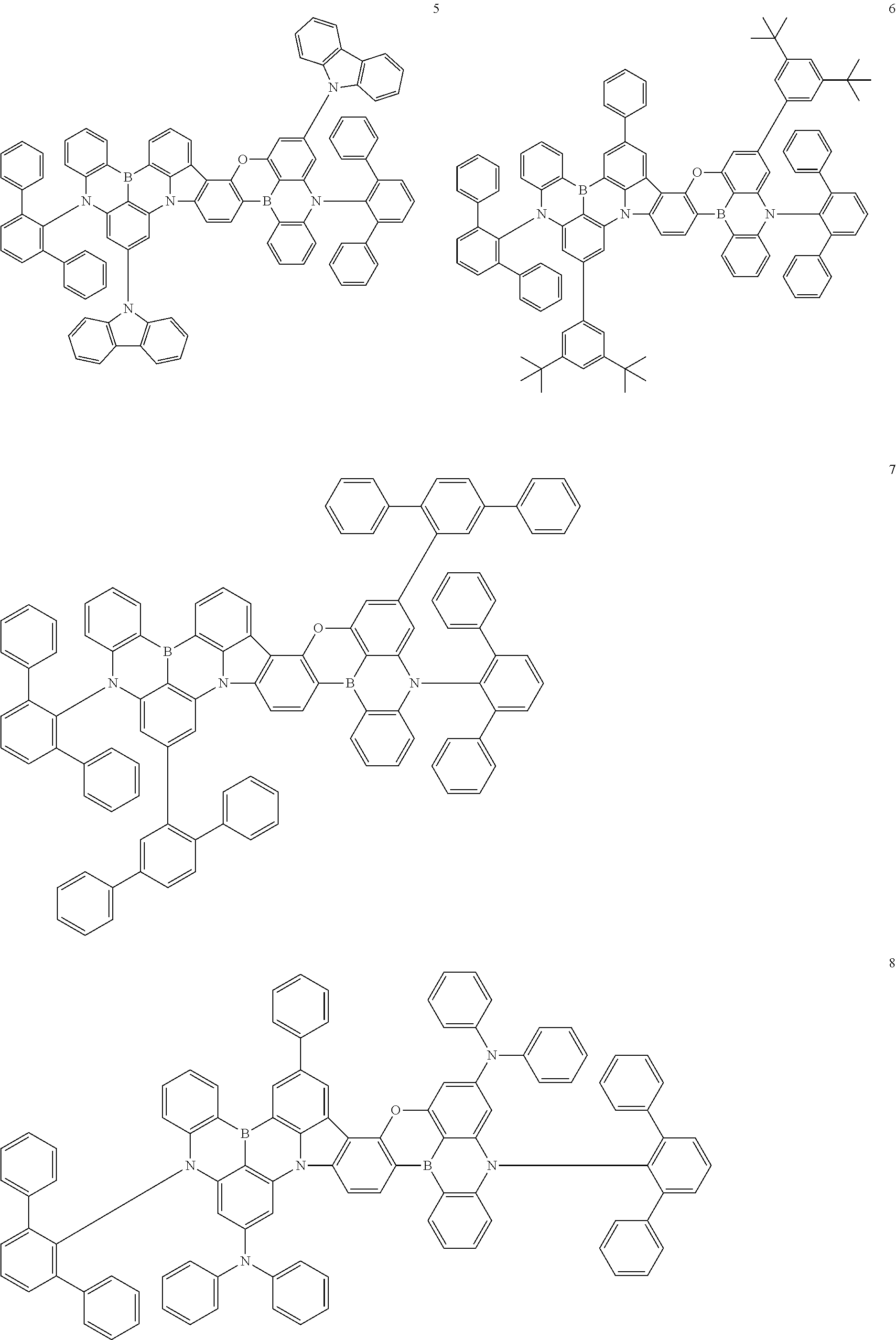 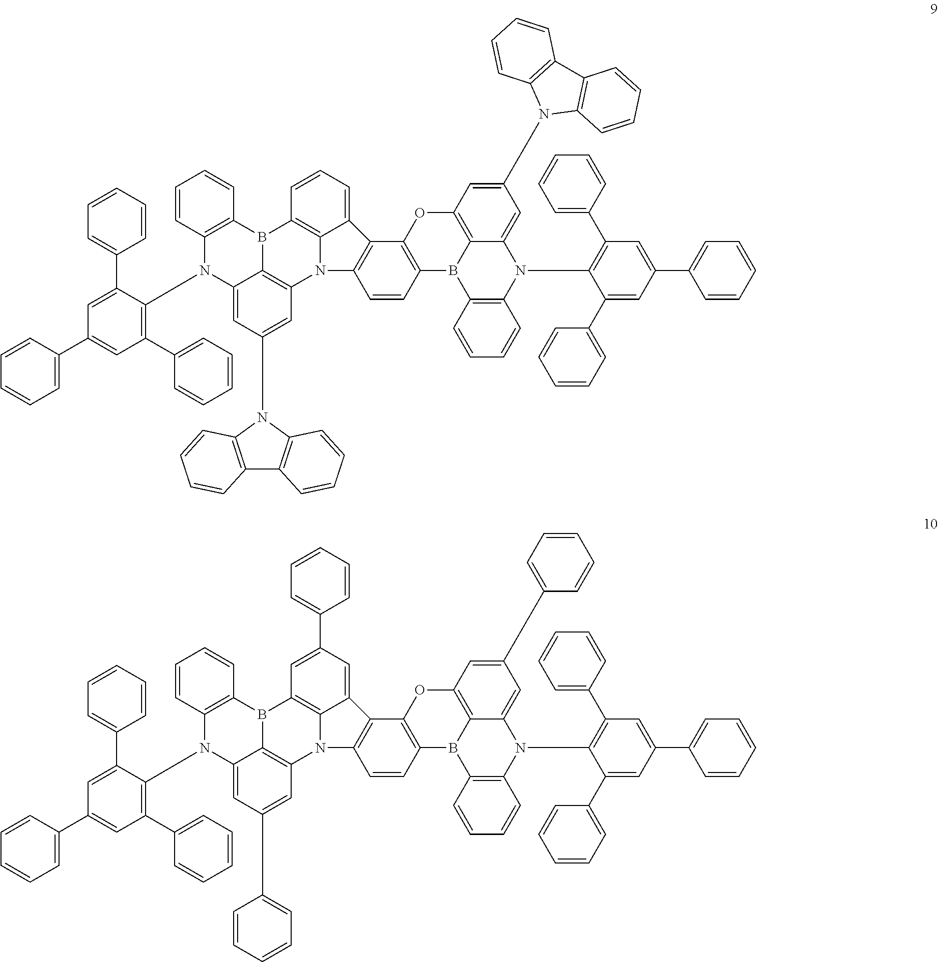 [SMILES: c1ccc(-c2cc(-c3ccccc3)c(N3c4ccccc4B4c5ccc6c(c5Oc5cc(-n7c8ccccc8c8ccccc87)cc3c54)c3cccc4c3n6-c3cc(-n5c6ccccc6c6ccccc65)cc5c3B4c3ccccc3N5c3c(-c4ccccc4)cc(-c4ccccc4)cc3-c3ccccc3)c(-c3ccccc3)c2)cc1 ; c1ccc(-c2cc(-c3ccccc3)c(N3c4ccccc4B4c5ccc6c(c5Oc5cc(-c7ccccc7)cc3c54)c3cc(-c4ccccc4)cc4c3n6-c3cc(-c5ccccc5)cc5c3B4c3ccccc3N5c3c(-c4ccccc4)cc(-c4ccccc4)cc3-c3ccccc3)c(-c3ccccc3)c2)cc1] 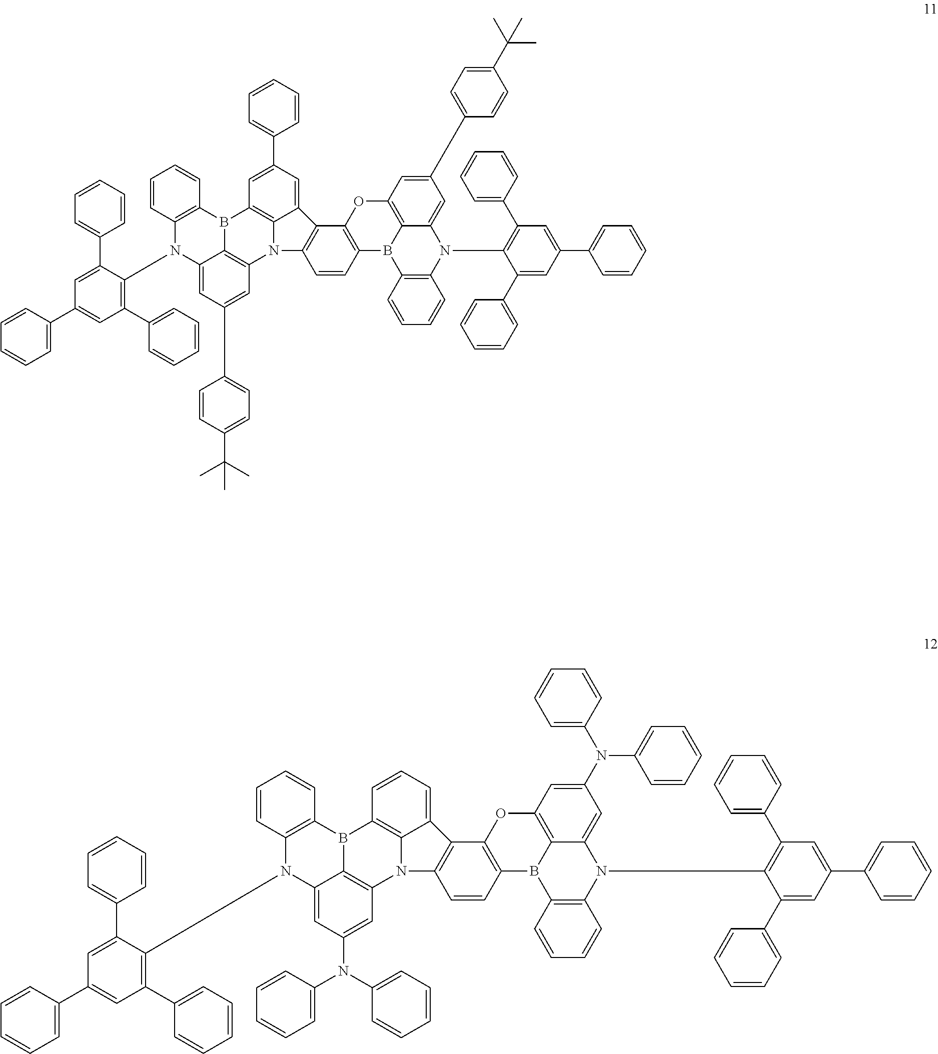 [SMILES: CC(C)(C)c1ccc(-c2cc3c4c(c2)N(c2c(-c5ccccc5)cc(-c5ccccc5)cc2-c2ccccc2)c2ccccc2B4c2ccc4c(c2O3)c2cc(-c3ccccc3)cc3c2n4-c2cc(-c4ccc(C(C)(C)C)cc4)cc4c2B3c2ccccc2N4c2c(-c3ccccc3)cc(-c3ccccc3)cc2-c2ccccc2)cc1 ; c1ccc(-c2cc(-c3ccccc3)c(N3c4ccccc4B4c5ccc6c(c5Oc5cc(N(c7ccccc7)c7ccccc7)cc3c54)c3cccc4c3n6-c3cc(N(c5ccccc5)c5ccccc5)cc5c3B4c3ccccc3N5c3c(-c4ccccc4)cc(-c4ccccc4)cc3-c3ccccc3)c(-c3ccccc3)c2)cc1] 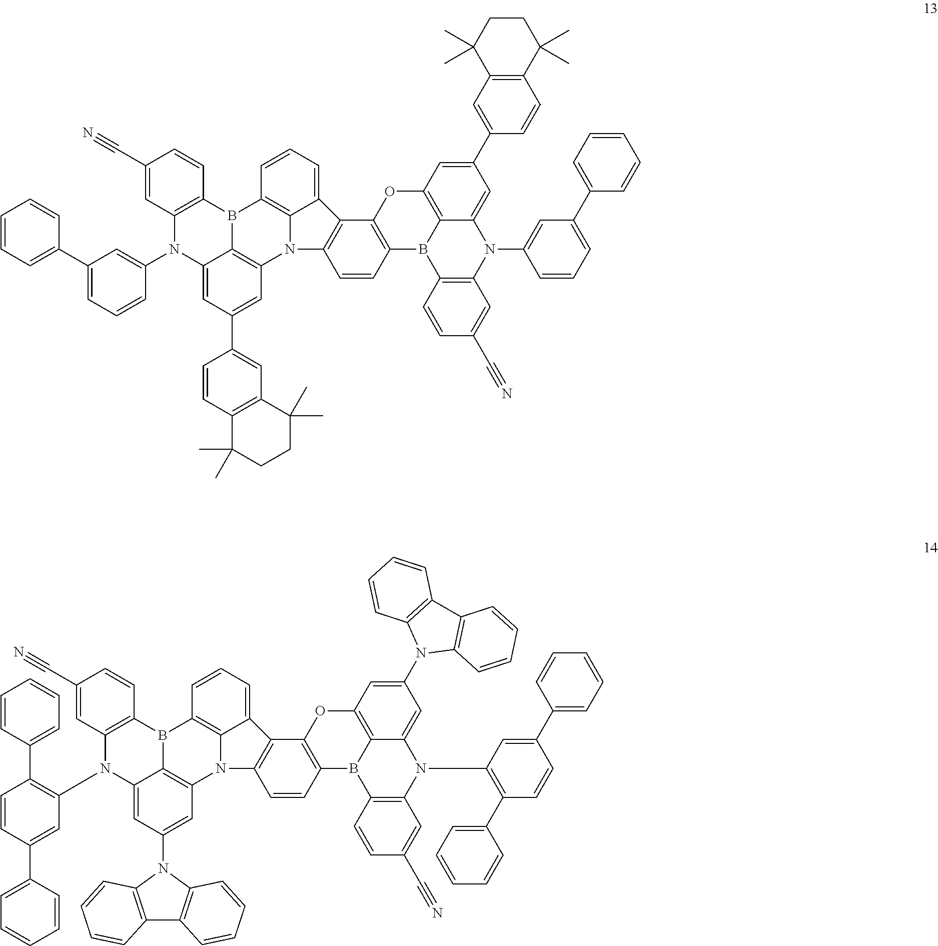 [SMILES: CC1(C)CCC(C)(C)c2cc(-c3cc4c5c(c3)N(c3cccc(-c6ccccc6)c3)c3cc(C#N)ccc3B5c3ccc5c(c3O4)c3cccc4c3n5-c3cc(-c5ccc6c(c5)C(C)(C)CCC6(C)C)cc5c3B4c3ccc(C#N)cc3N5c3cccc(-c4ccccc4)c3)ccc21 ; N#Cc1ccc2c(c1)N(c1cc(-c3ccccc3)ccc1-c1ccccc1)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1N2c1cc(-c2ccccc2)ccc1-c1ccccc1] 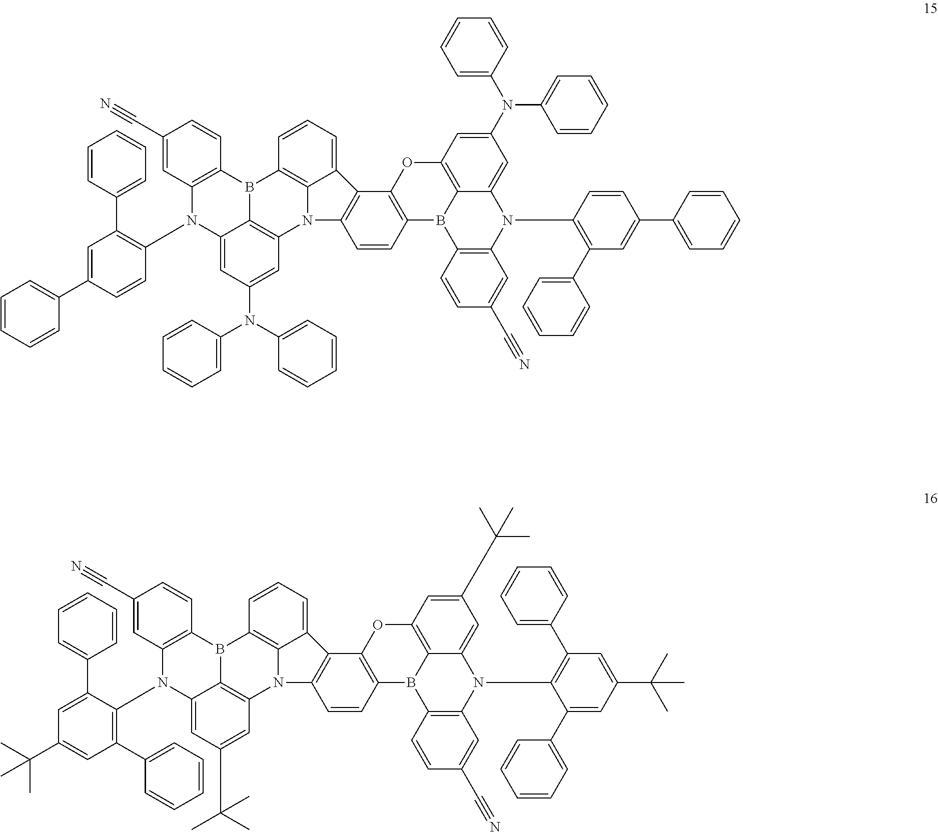 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C#N)ccc3B3c4ccc5c(c4Oc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1] 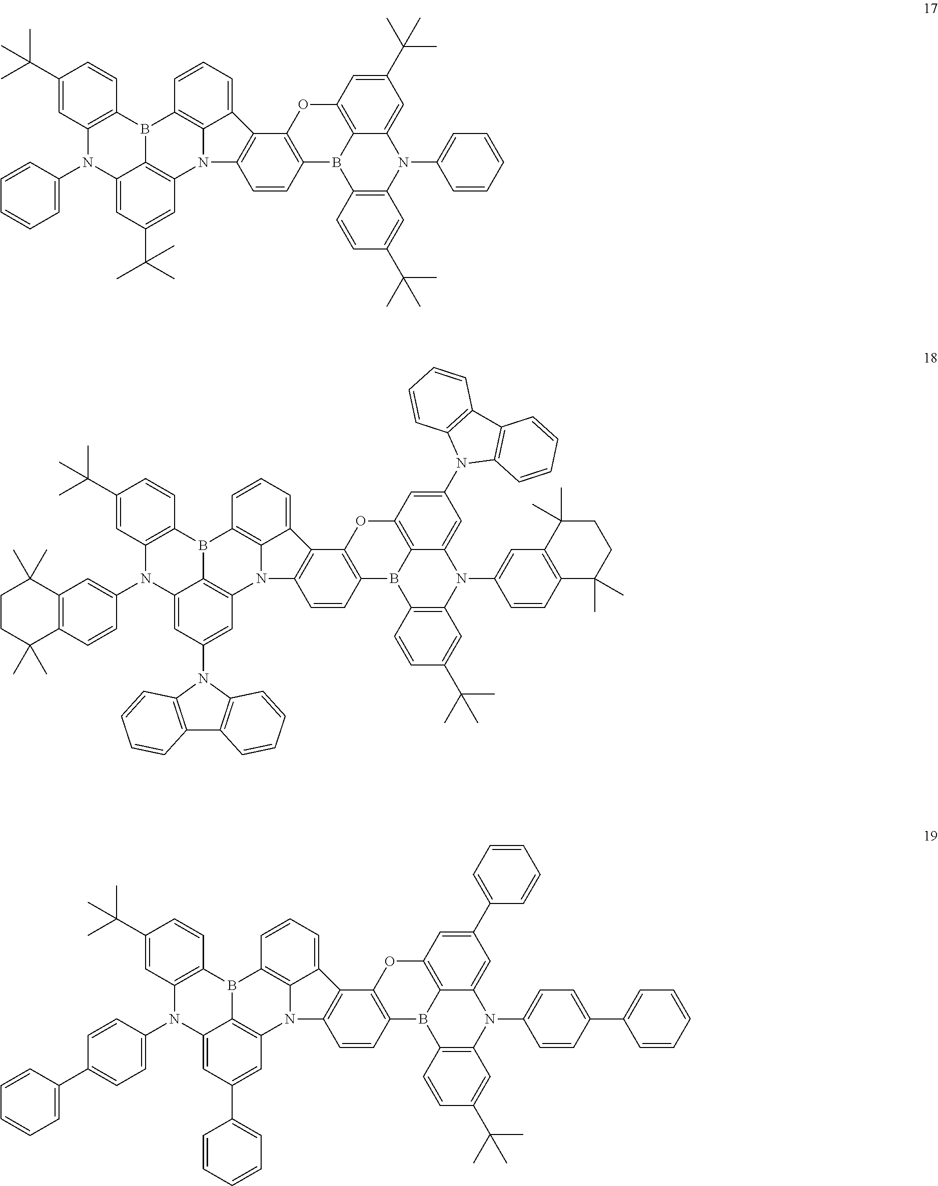 [SMILES: CC(C)(C)c1ccc2c(c1)N(c1ccccc1)c1cc(C(C)(C)C)cc3c1B2c1ccc2c(c1O3)c1cccc3c1n2-c1cc(C(C)(C)C)cc2c1B3c1ccc(C(C)(C)C)cc1N2c1ccccc1 ; CC(C)(C)c1ccc2c(c1)N(c1ccc3c(c1)C(C)(C)CCC3(C)C)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1N2c1ccc2c(c1)C(C)(C)CCC2(C)C ; CC(C)(C)c1ccc2c(c1)N(c1ccc(-c3ccccc3)cc1)c1cc(-c3ccccc3)cc3c1B2c1ccc2c(c1O3)c1cccc3c1n2-c1cc(-c2ccccc2)cc2c1B3c1ccc(C(C)(C)C)cc1N2c1ccc(-c2ccccc2)cc1] 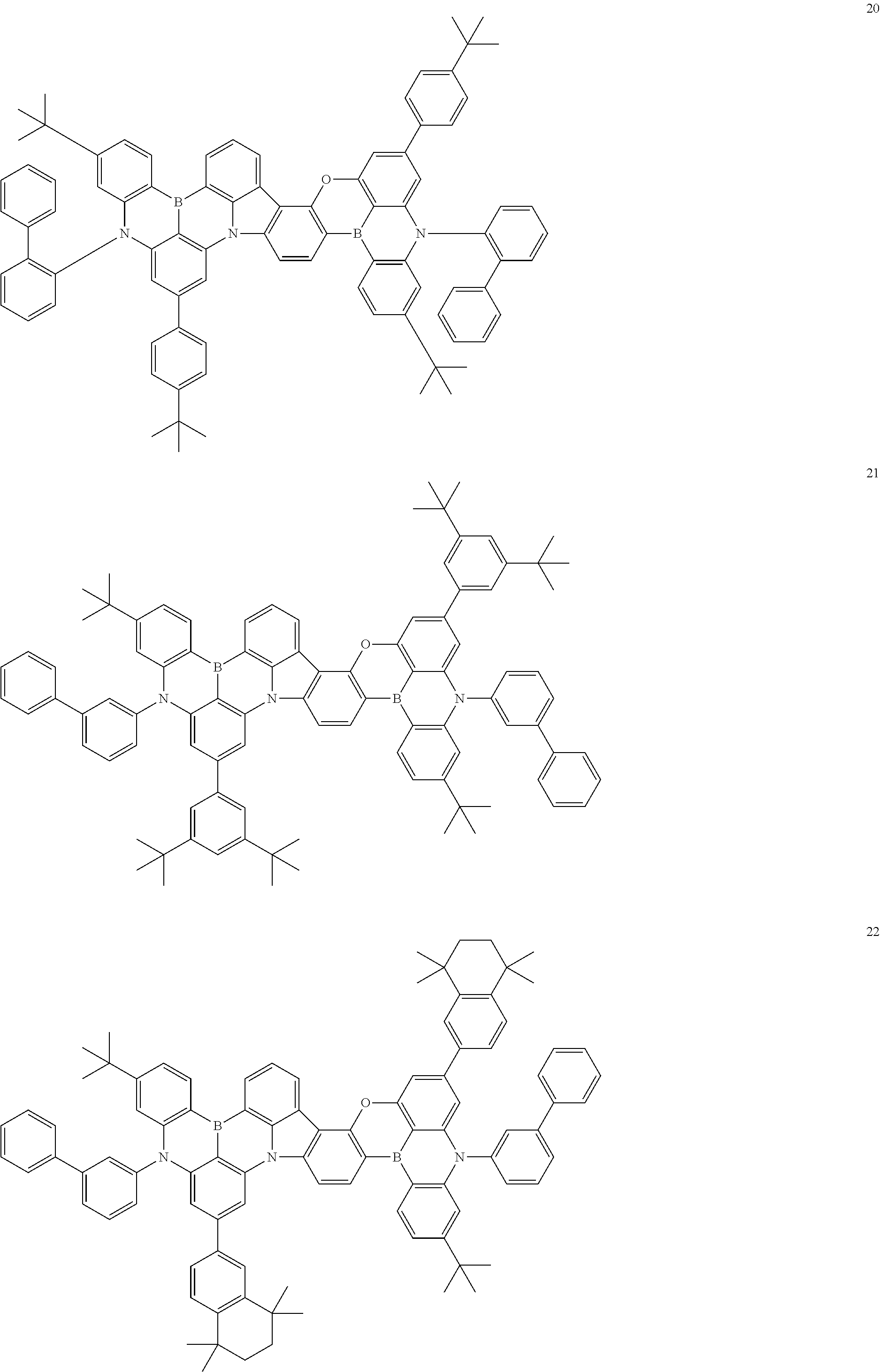 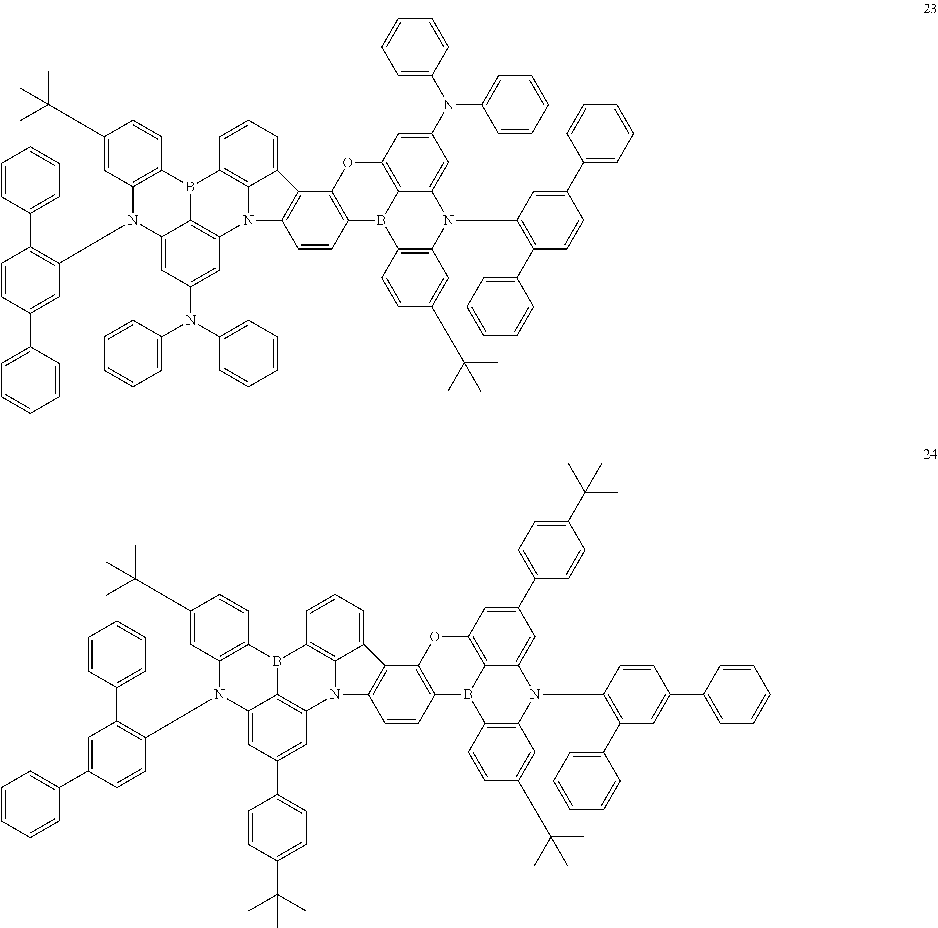 [SMILES: CC(C)(C)c1ccc2c(c1)N(c1cc(-c3ccccc3)ccc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)N(c2ccc(-c5ccccc5)cc2-c2ccccc2)c2cc(C(C)(C)C)ccc2B4c2ccc4c(c2O3)c2cccc3c2n4-c2cc(-c4ccc(C(C)(C)C)cc4)cc4c2B3c2ccc(C(C)(C)C)cc2N4c2ccc(-c3ccccc3)cc2-c2ccccc2)cc1] 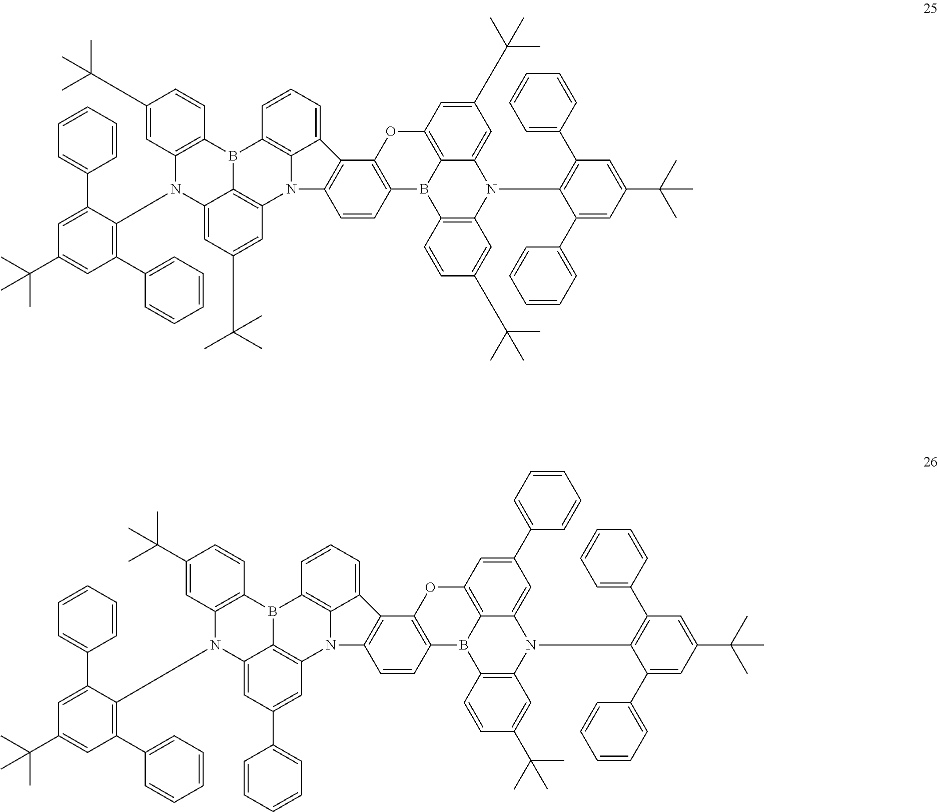 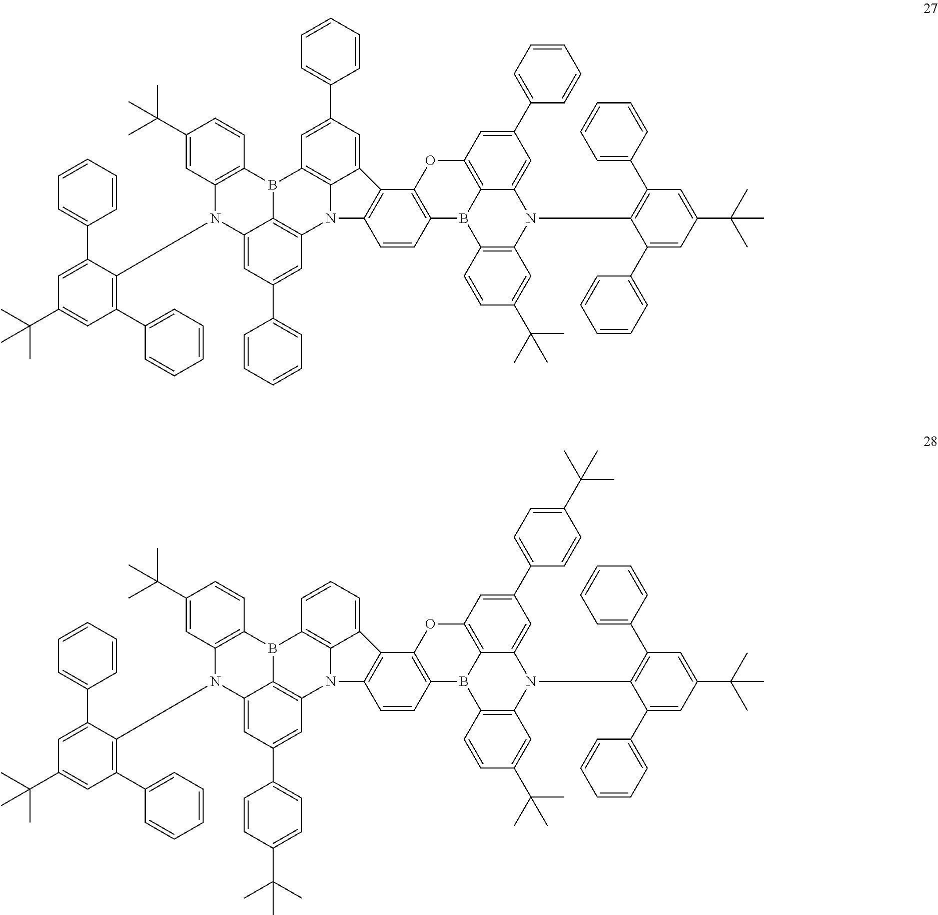 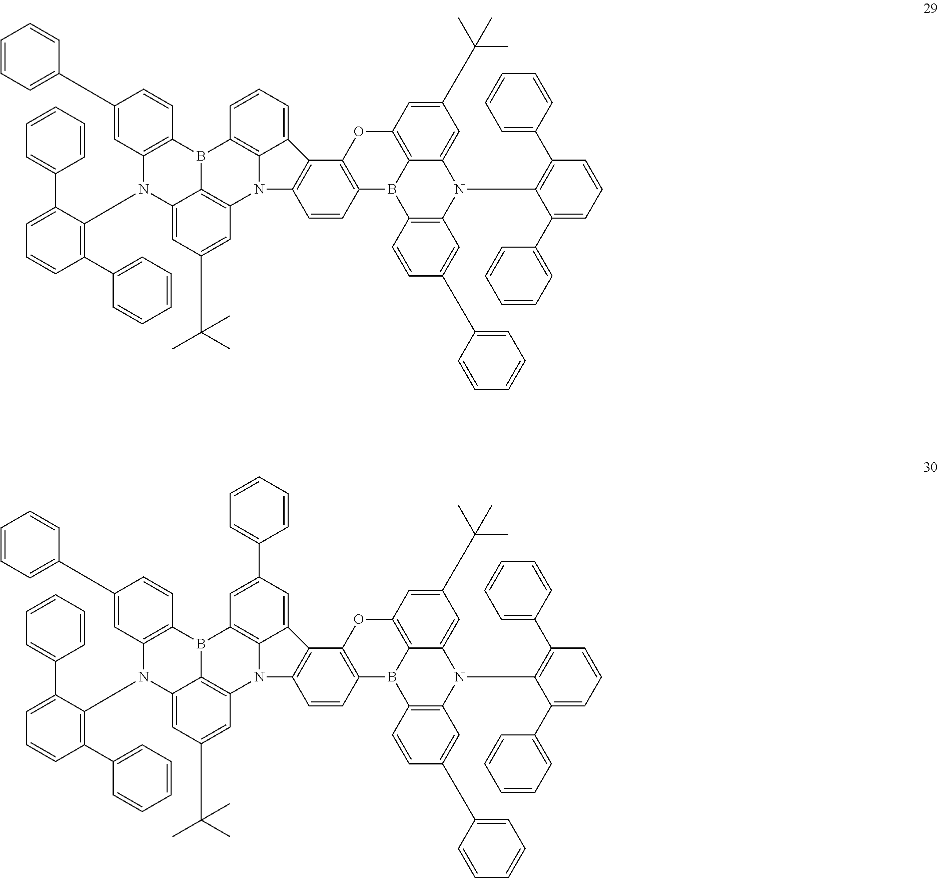 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1] 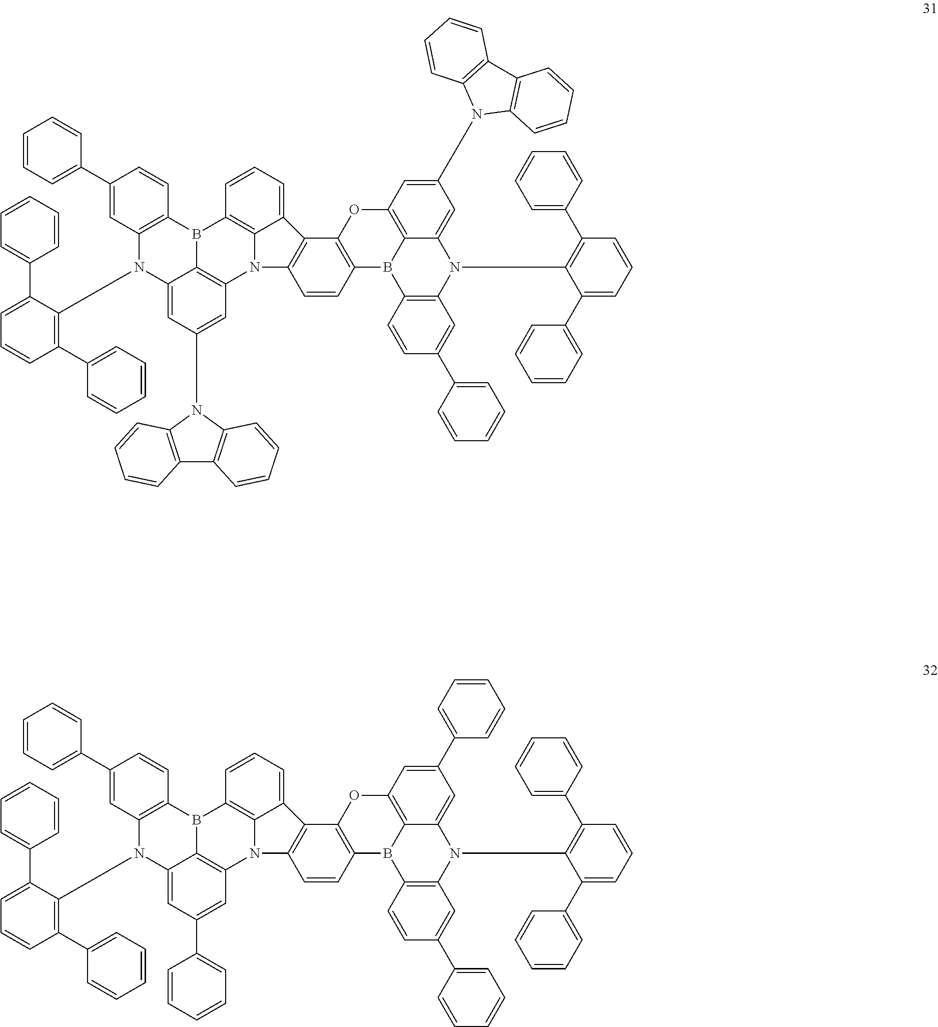 [SMILES: c1ccc(-c2ccc3c(c2)N(c2c(-c4ccccc4)cccc2-c2ccccc2)c2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccccc4)cc2N3c2c(-c3ccccc3)cccc2-c2ccccc2)cc1] 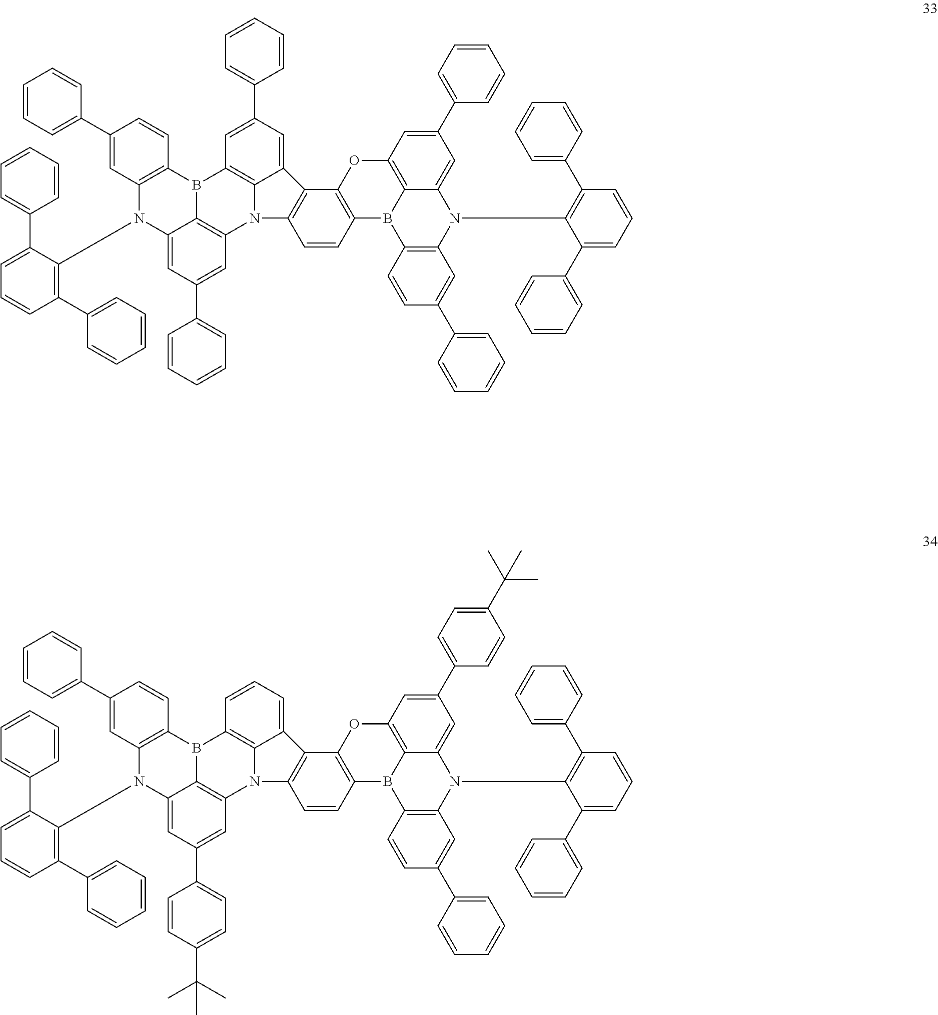 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cc(-c4ccccc4)cc4c2n3-c2cc(-c3ccccc3)cc3c2B4c2ccc(-c4ccccc4)cc2N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2N4c2c(-c3ccccc3)cccc2-c2ccccc2)cc1] 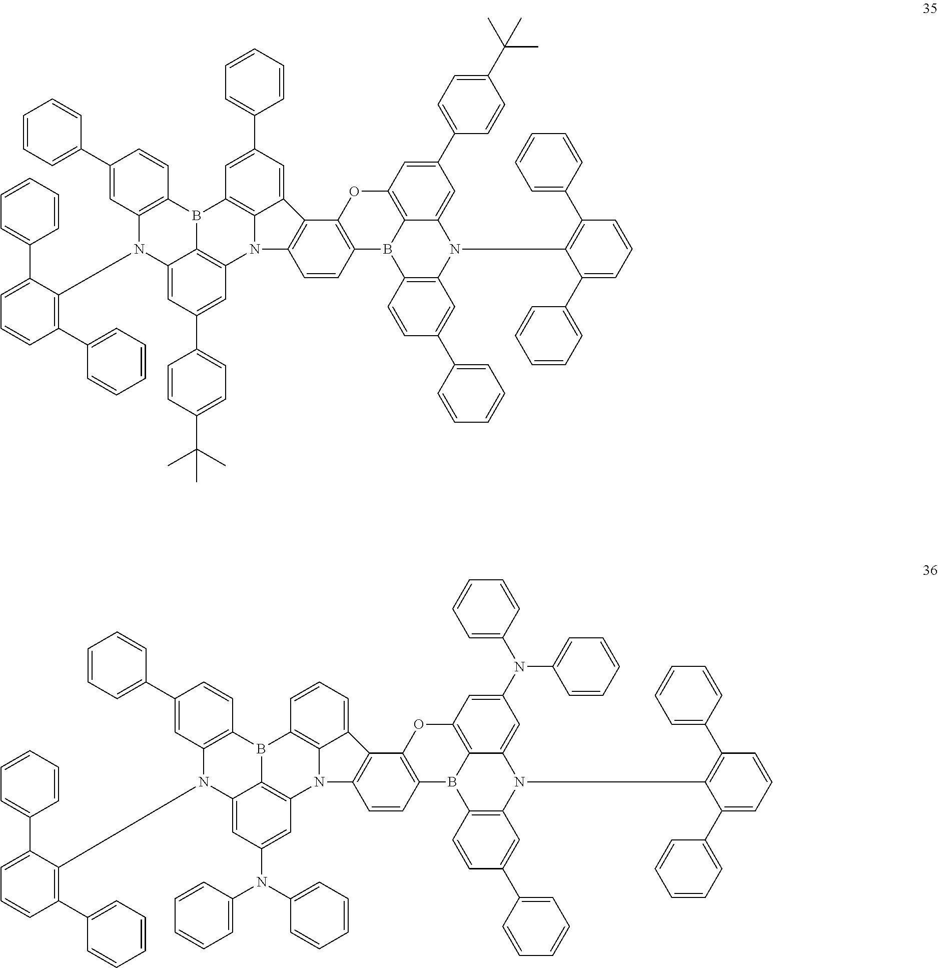 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2N4c2c(-c3ccccc3)cccc2-c2ccccc2)cc1 ; c1ccc(-c2ccc3c(c2)N(c2c(-c4ccccc4)cccc2-c2ccccc2)c2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 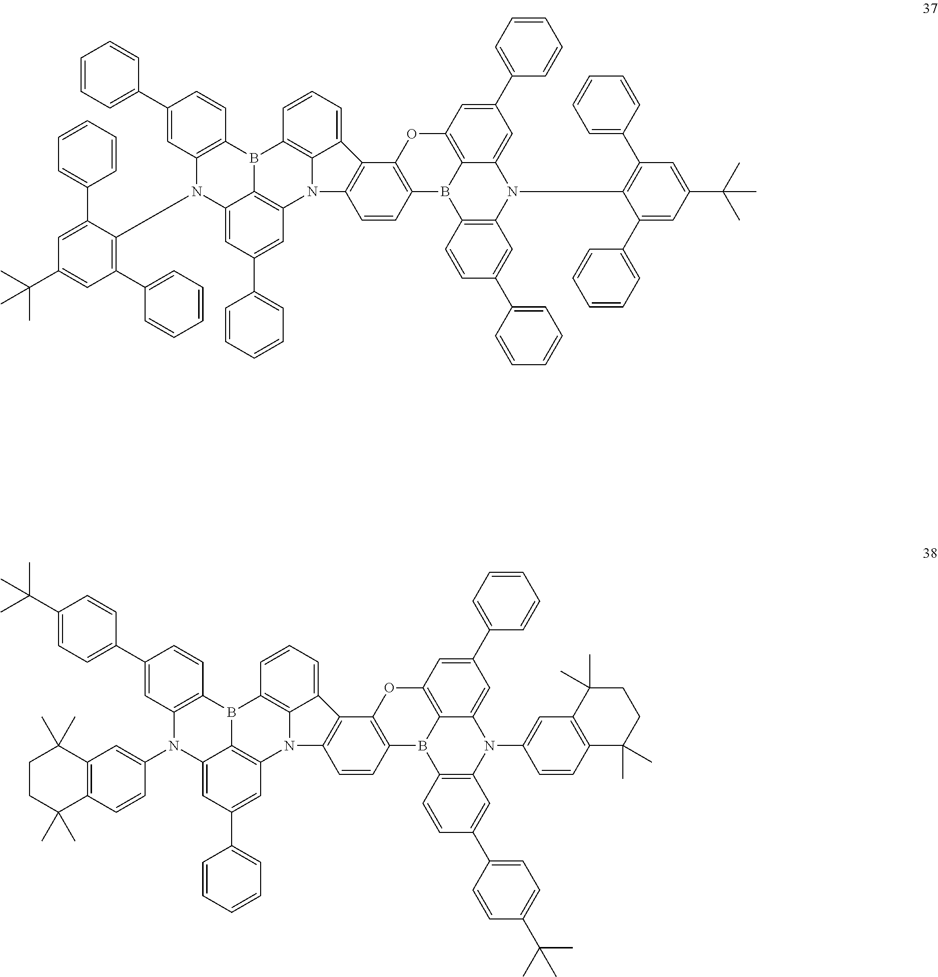 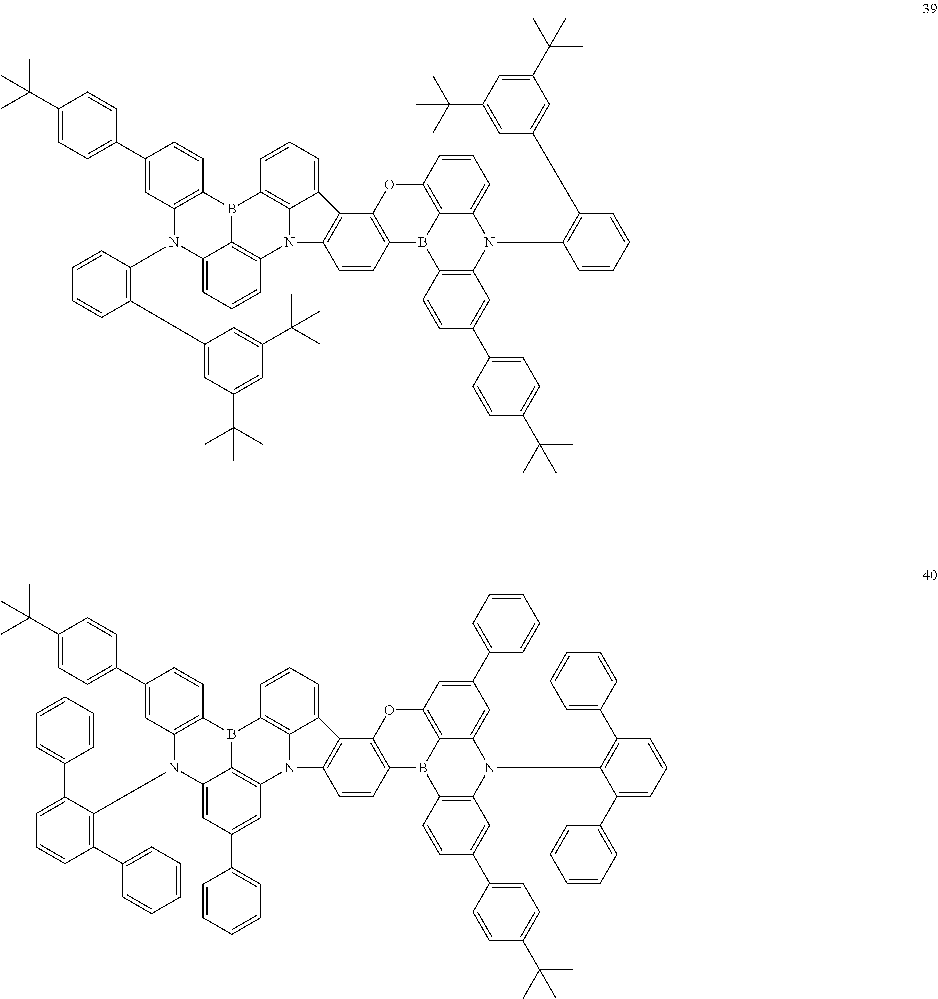 [SMILES: CC(C)(C)c1ccc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4ccc(C(C)(C)C)cc4)cc2N3c2ccccc2-c2cc(C(C)(C)C)cc(C(C)(C)C)c2)cc1 ; CC(C)(C)c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2N3c2c(-c3ccccc3)cccc2-c2ccccc2)cc1] 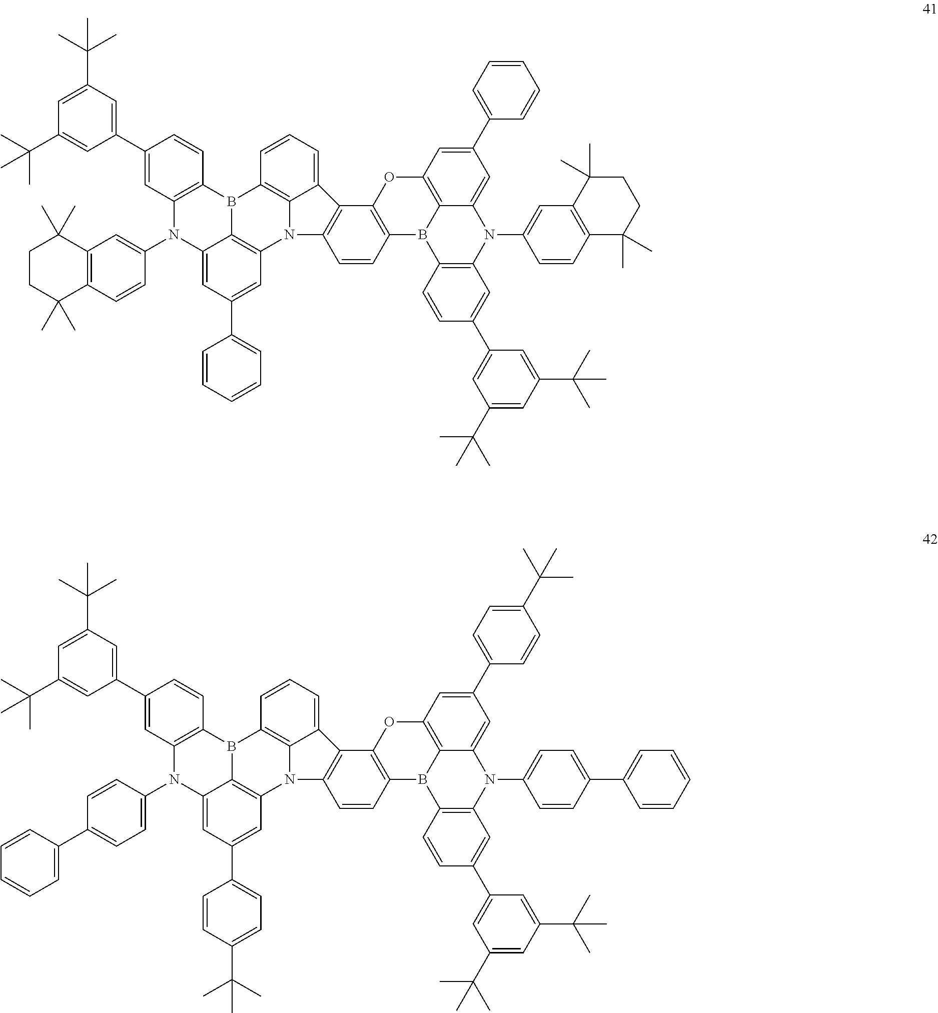 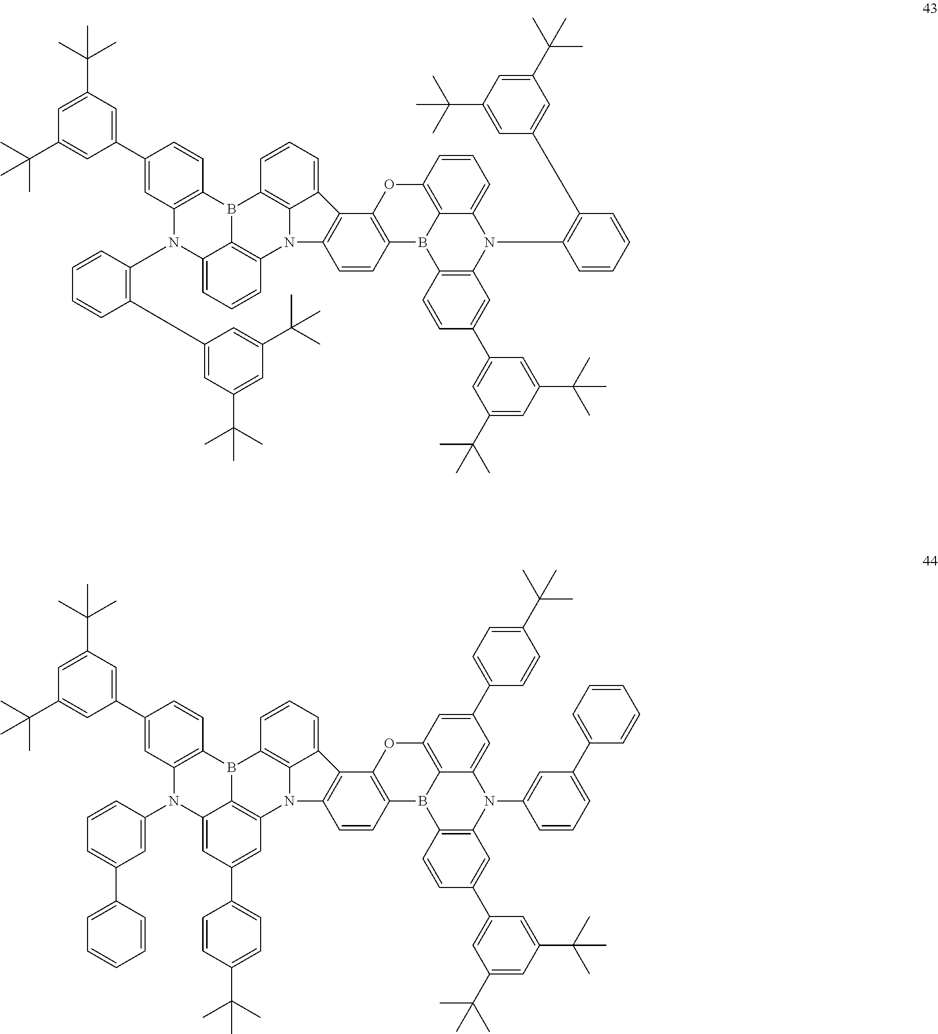 [SMILES: CC(C)(C)c1cc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4cc(C(C)(C)C)cc(C(C)(C)C)c4)cc2N3c2ccccc2-c2cc(C(C)(C)C)cc(C(C)(C)C)c2)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2N4c2cccc(-c3ccccc3)c2)cc1] 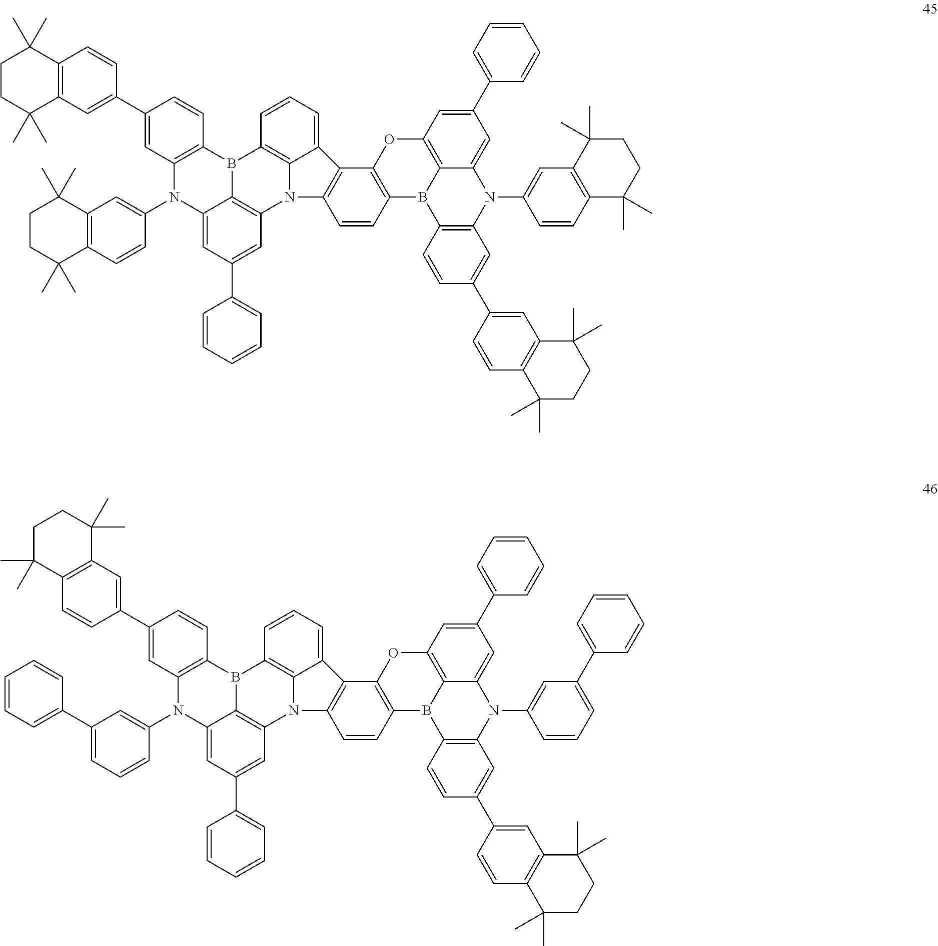 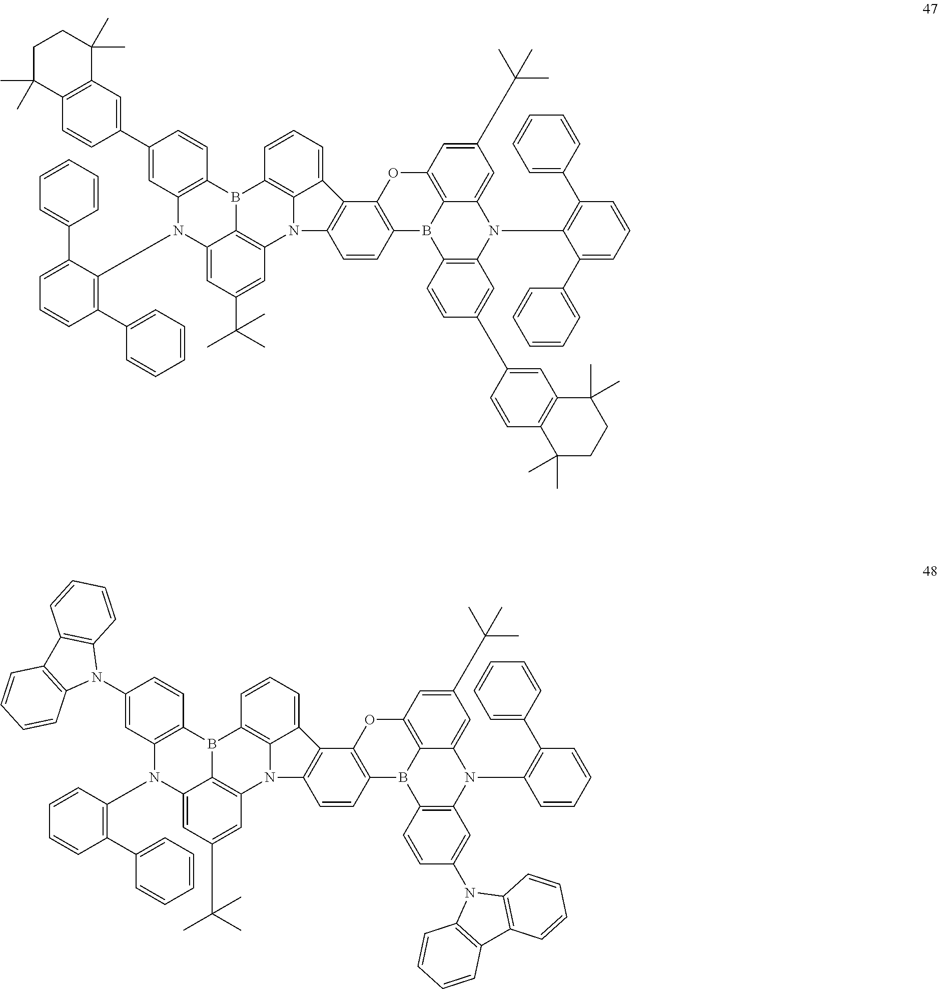 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1N3c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1ccccc1-c1ccccc1] 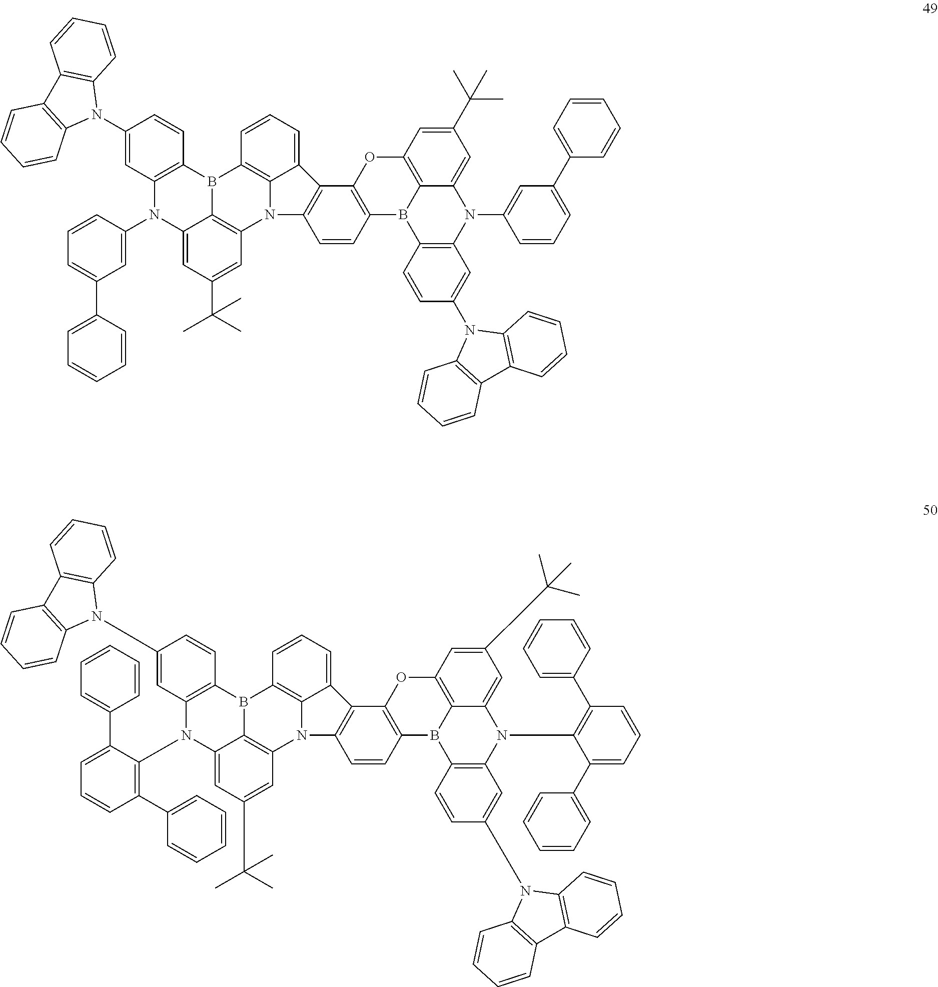 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cccc1-c1ccccc1] 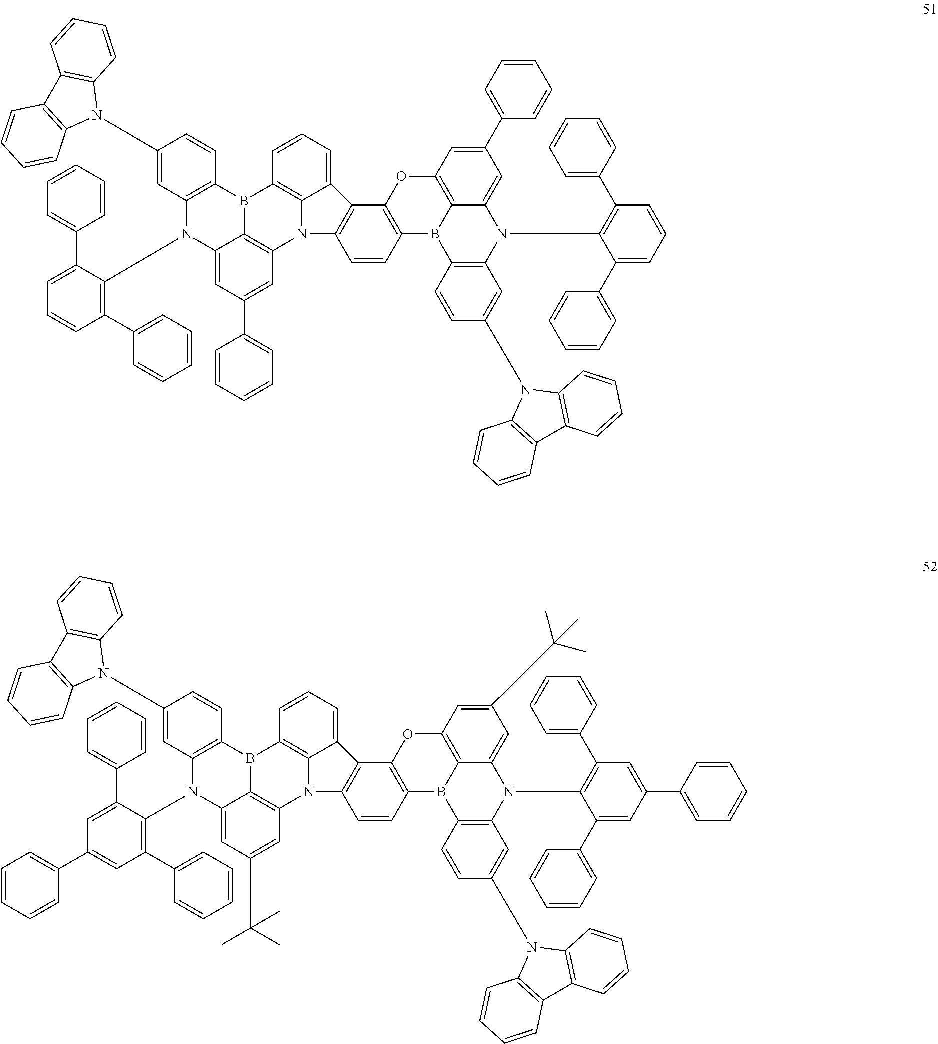 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2N4c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cc(-c2ccccc2)cc1-c1ccccc1] 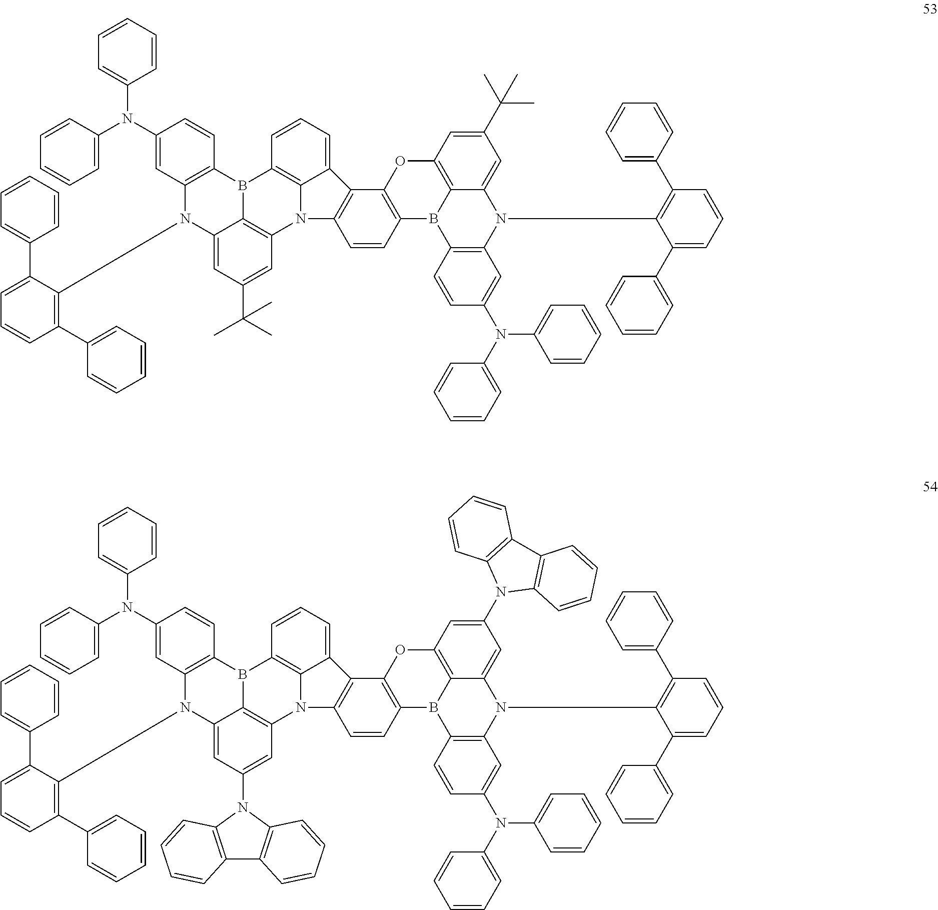 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1N3c1c(-c2ccccc2)cccc1-c1ccccc1 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2N4c2c(-c3ccccc3)cccc2-c2ccccc2)cc1] 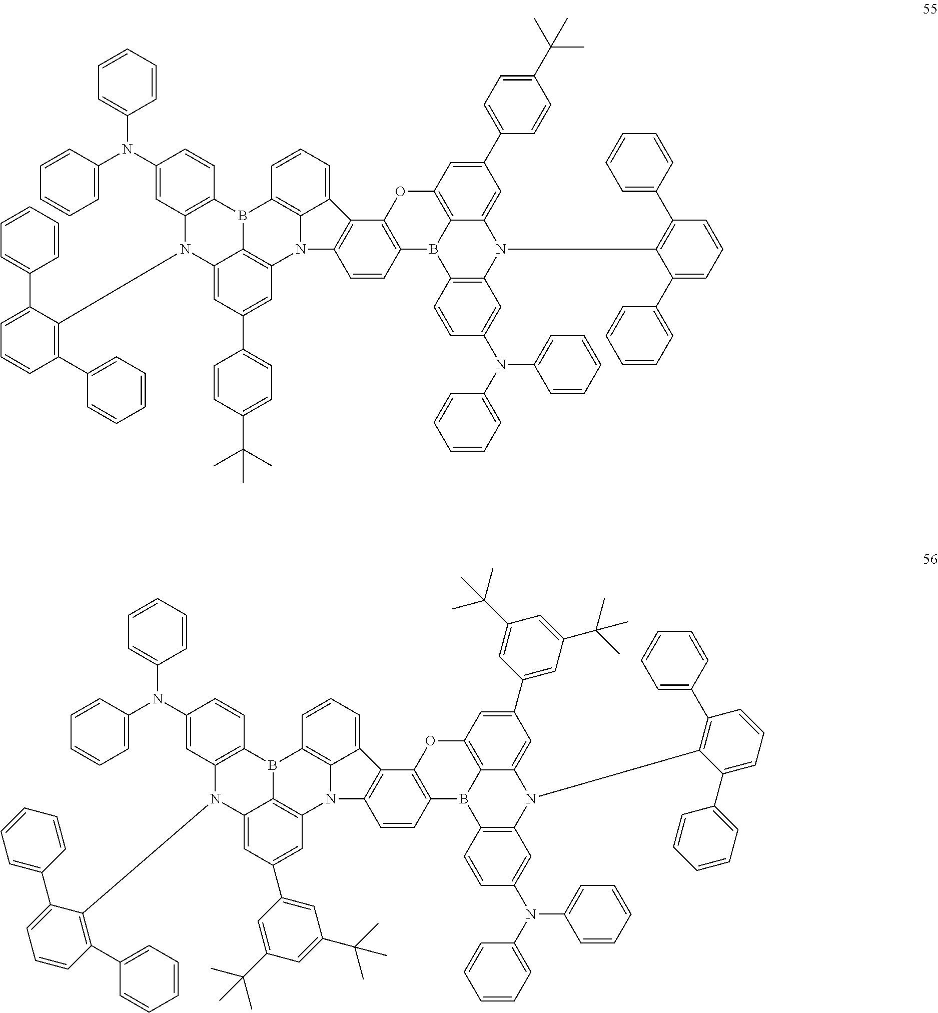 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2N4c2c(-c3ccccc3)cccc2-c2ccccc2)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2N4c2c(-c3ccccc3)cccc2-c2ccccc2)cc(C(C)(C)C)c1] 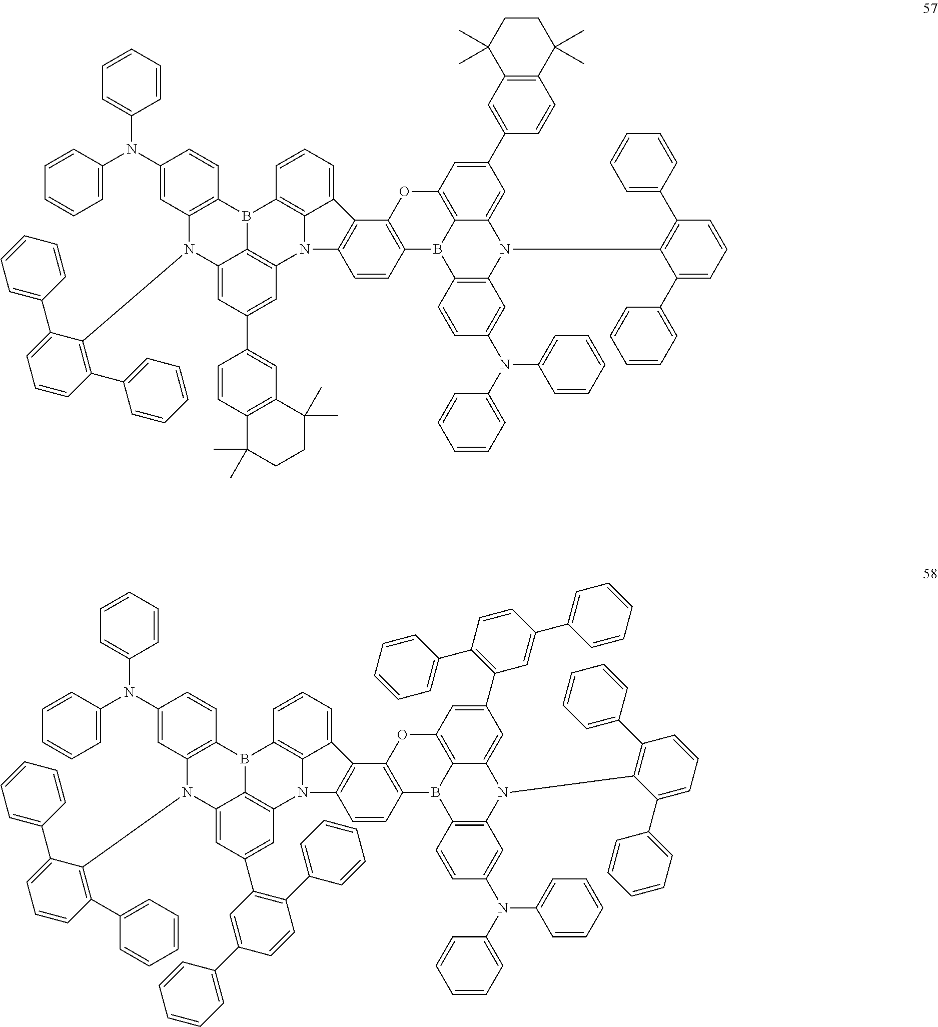 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3N5c3c(-c4ccccc4)cccc3-c3ccccc3)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3N5c3c(-c4ccccc4)cccc3-c3ccccc3)c2)cc1] 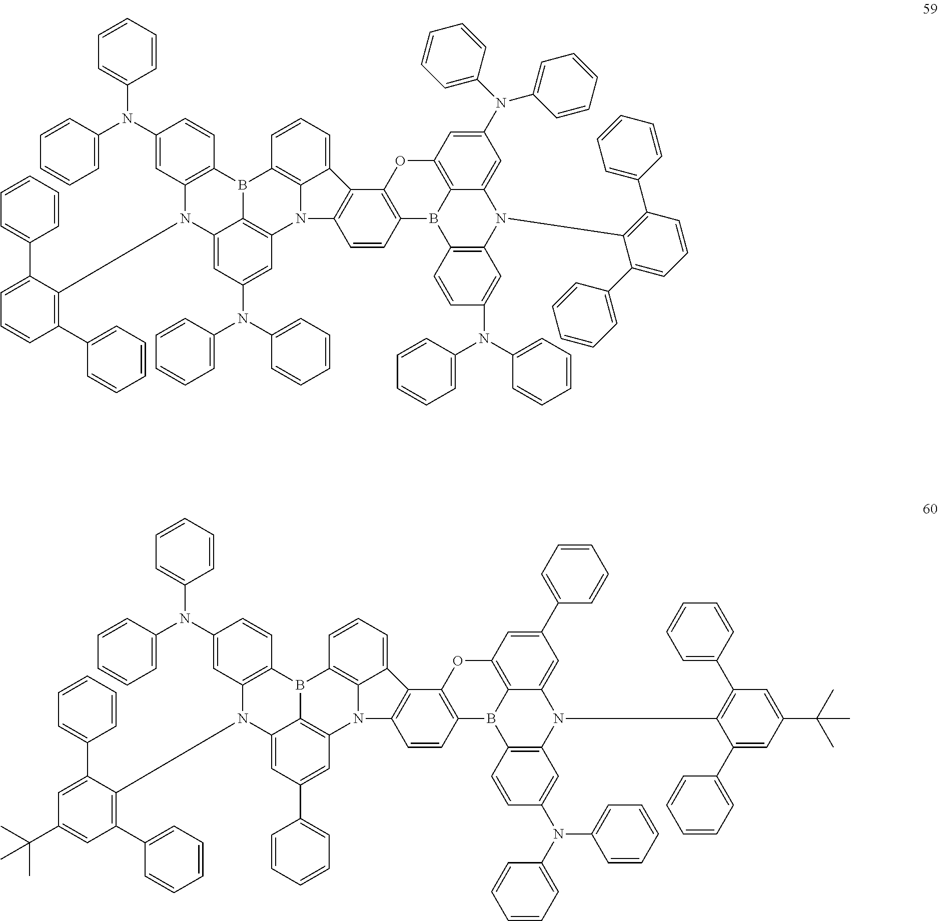 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2N4c2c(-c3ccccc3)cccc2-c2ccccc2)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2N4c2c(-c3ccccc3)cc(C(C)(C)C)cc2-c2ccccc2)c(-c2ccccc2)c1] 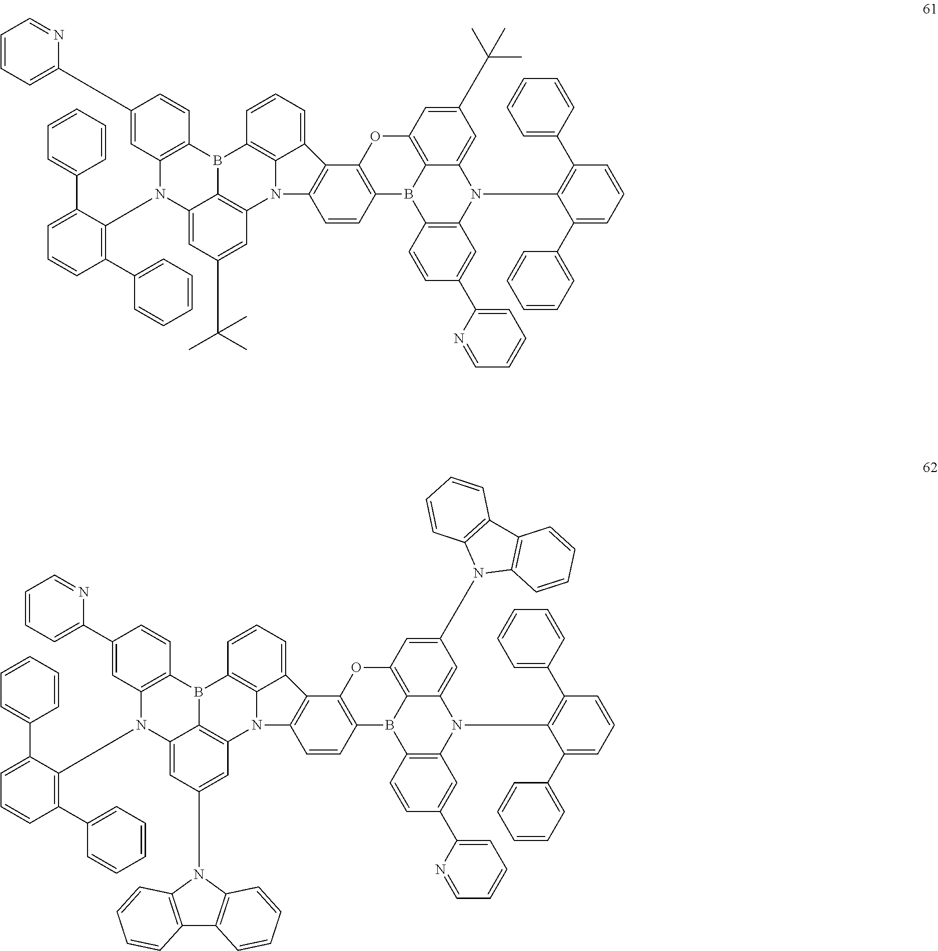 [SMILES: CC(C)(C)c1cc2c3c(c1)N(c1c(-c4ccccc4)cccc1-c1ccccc1)c1cc(-c4ccccn4)ccc1B3c1ccc3c(c1O2)c1cccc2c1n3-c1cc(C(C)(C)C)cc3c1B2c1ccc(-c2ccccn2)cc1N3c1c(-c2ccccc2)cccc1-c1ccccc1 ; c1ccc(-c2cccc(-c3ccccc3)c2N2c3cc(-c4ccccn4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(-c3ccccn3)cc2N4c2c(-c3ccccc3)cccc2-c2ccccc2)cc1] 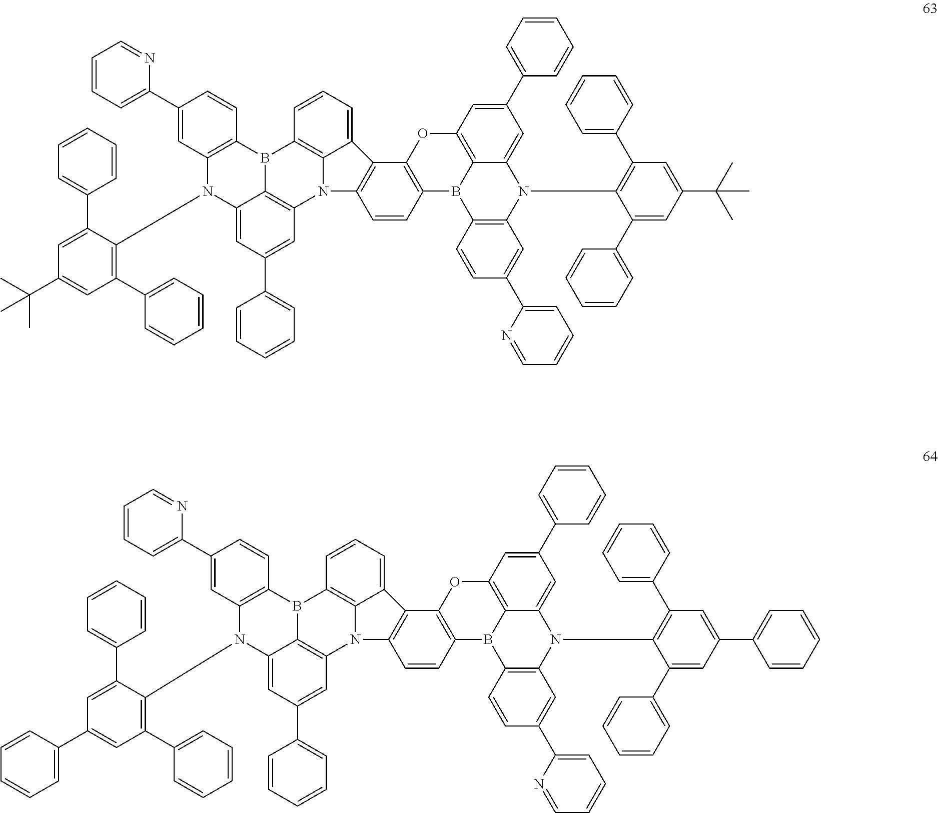 [SMILES: CC(C)(C)c1cc(-c2ccccc2)c(N2c3cc(-c4ccccn4)ccc3B3c4ccc5c(c4Oc4cc(-c6ccccc6)cc2c43)c2cccc3c2n5-c2cc(-c4ccccc4)cc4c2B3c2ccc(-c3ccccn3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccccn5)ccc4B4c5ccc6c(c5Oc5cc(-c7ccccc7)cc3c54)c3cccc4c3n6-c3cc(-c5ccccc5)cc5c3B4c3ccc(-c4ccccn4)cc3N5c3c(-c4ccccc4)cc(-c4ccccc4)cc3-c3ccccc3)c(-c3ccccc3)c2)cc1] 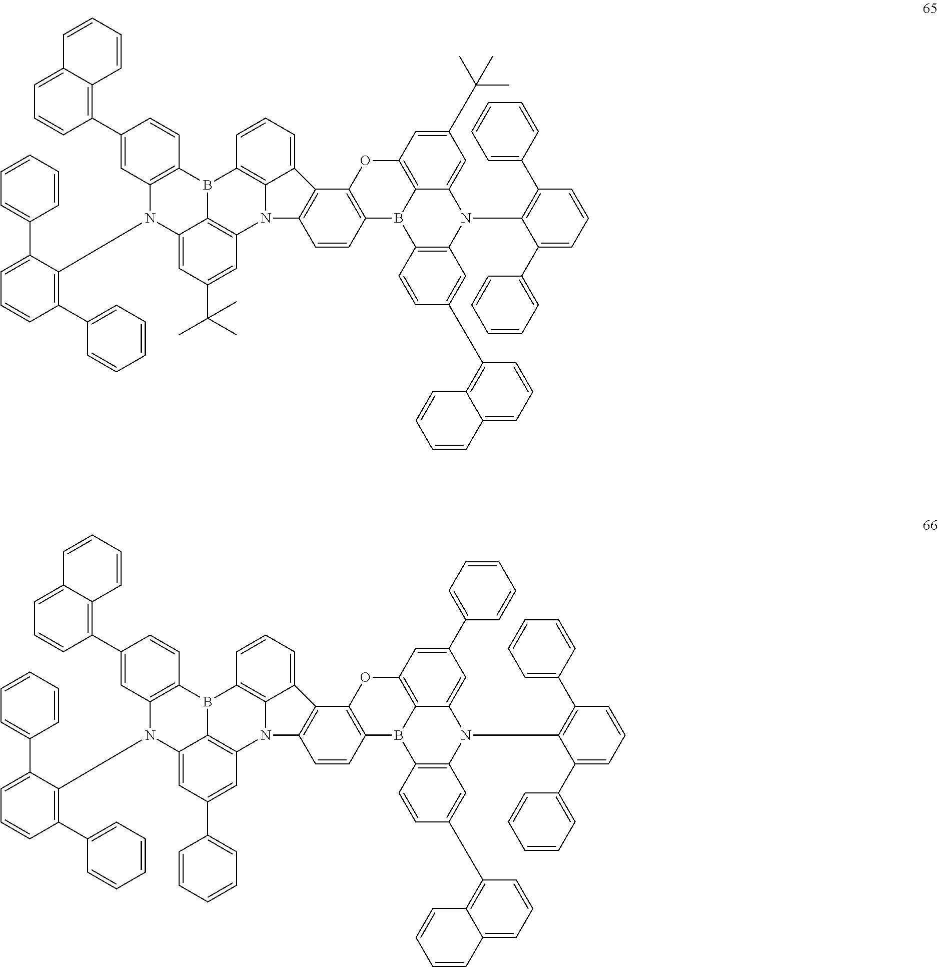 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1N3c1c(-c2ccccc2)cccc1-c1ccccc1 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2N4c2c(-c3ccccc3)cccc2-c2ccccc2)cc1] 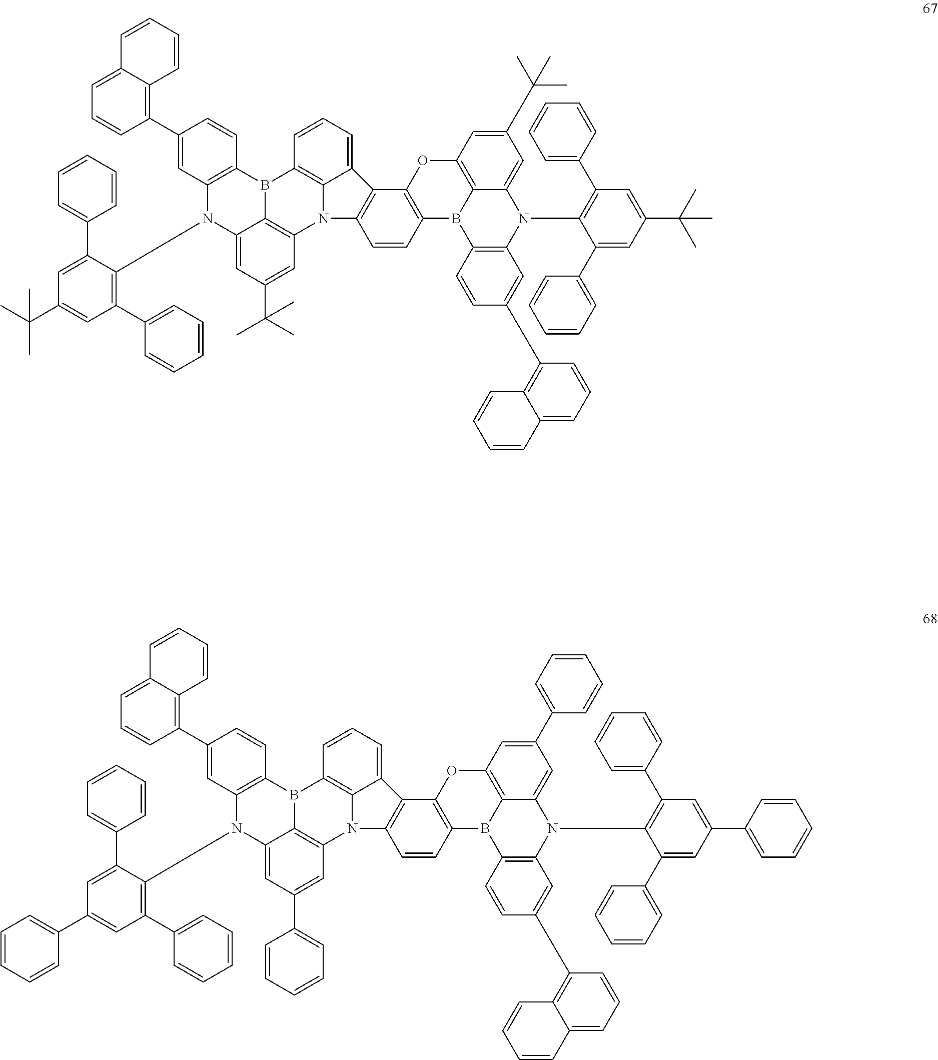 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3N5c3c(-c4ccccc4)cc(-c4ccccc4)cc3-c3ccccc3)c(-c3ccccc3)c2)cc1] 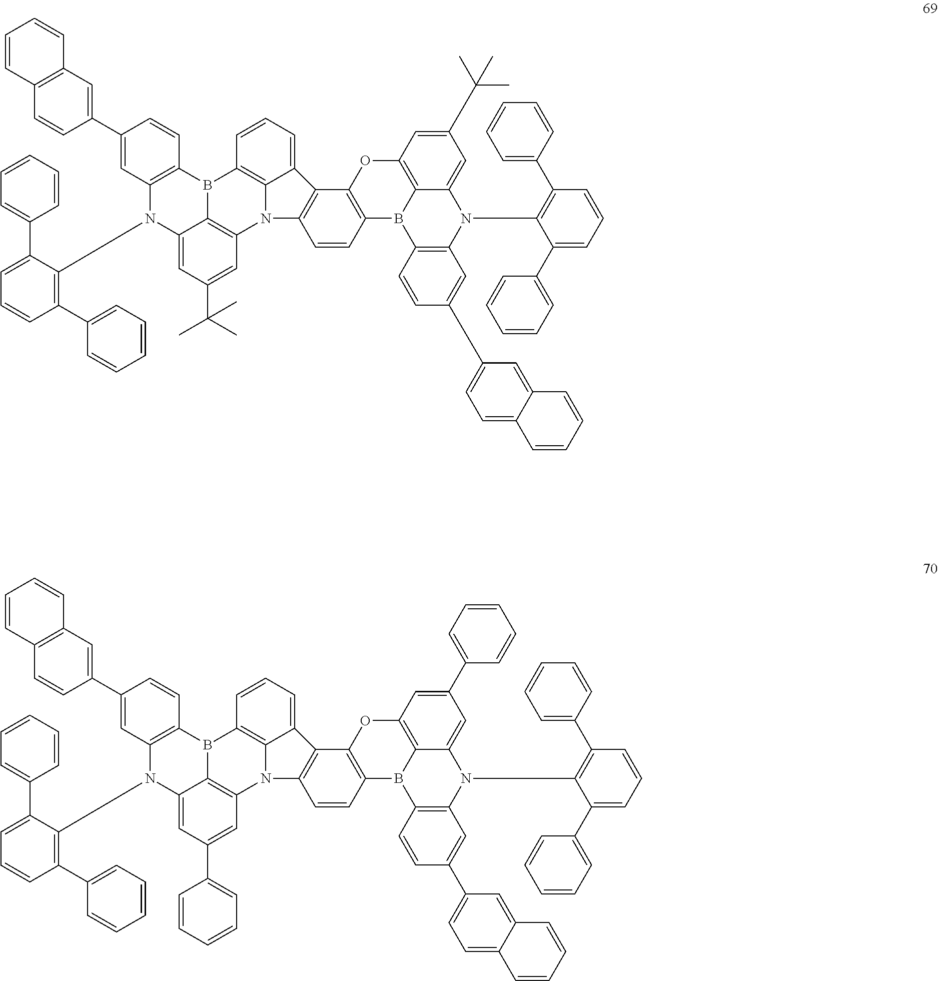 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1N3c1c(-c2ccccc2)cccc1-c1ccccc1 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2N4c2c(-c3ccccc3)cccc2-c2ccccc2)cc1] 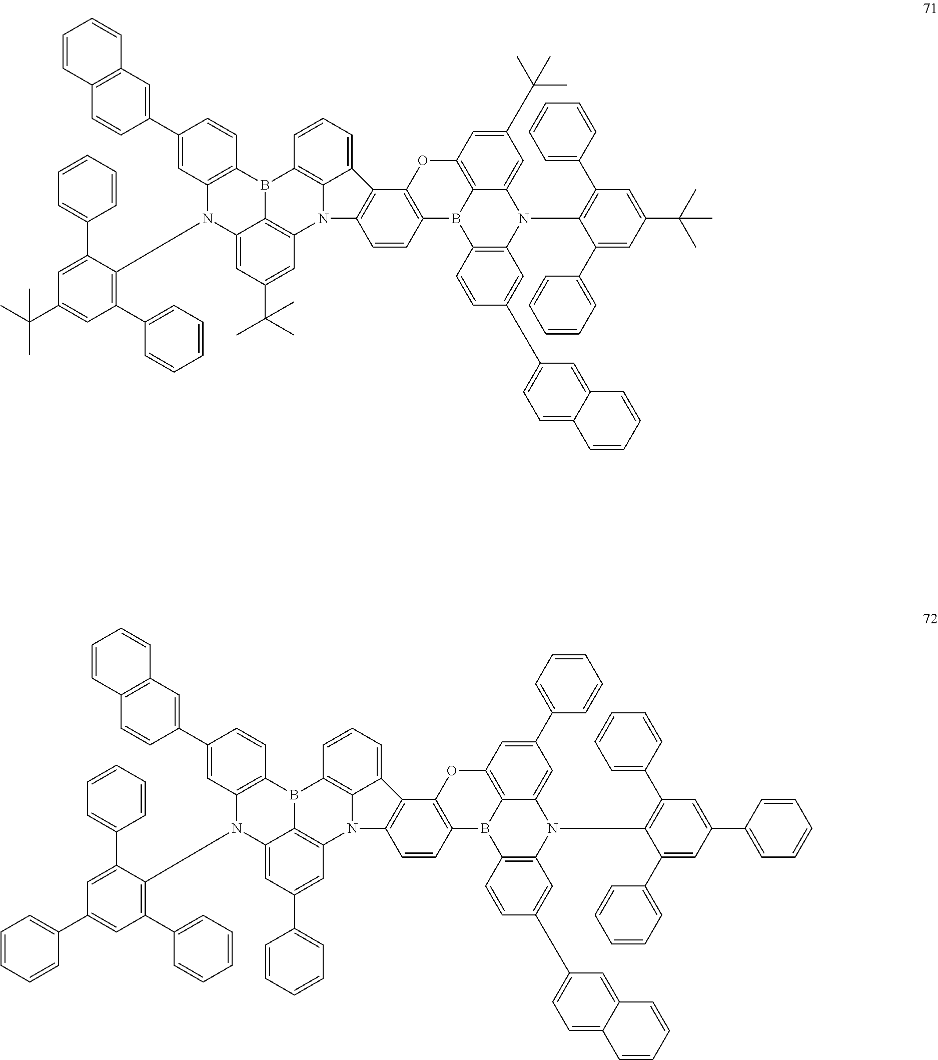 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3N5c3c(-c4ccccc4)cc(-c4ccccc4)cc3-c3ccccc3)c(-c3ccccc3)c2)cc1] 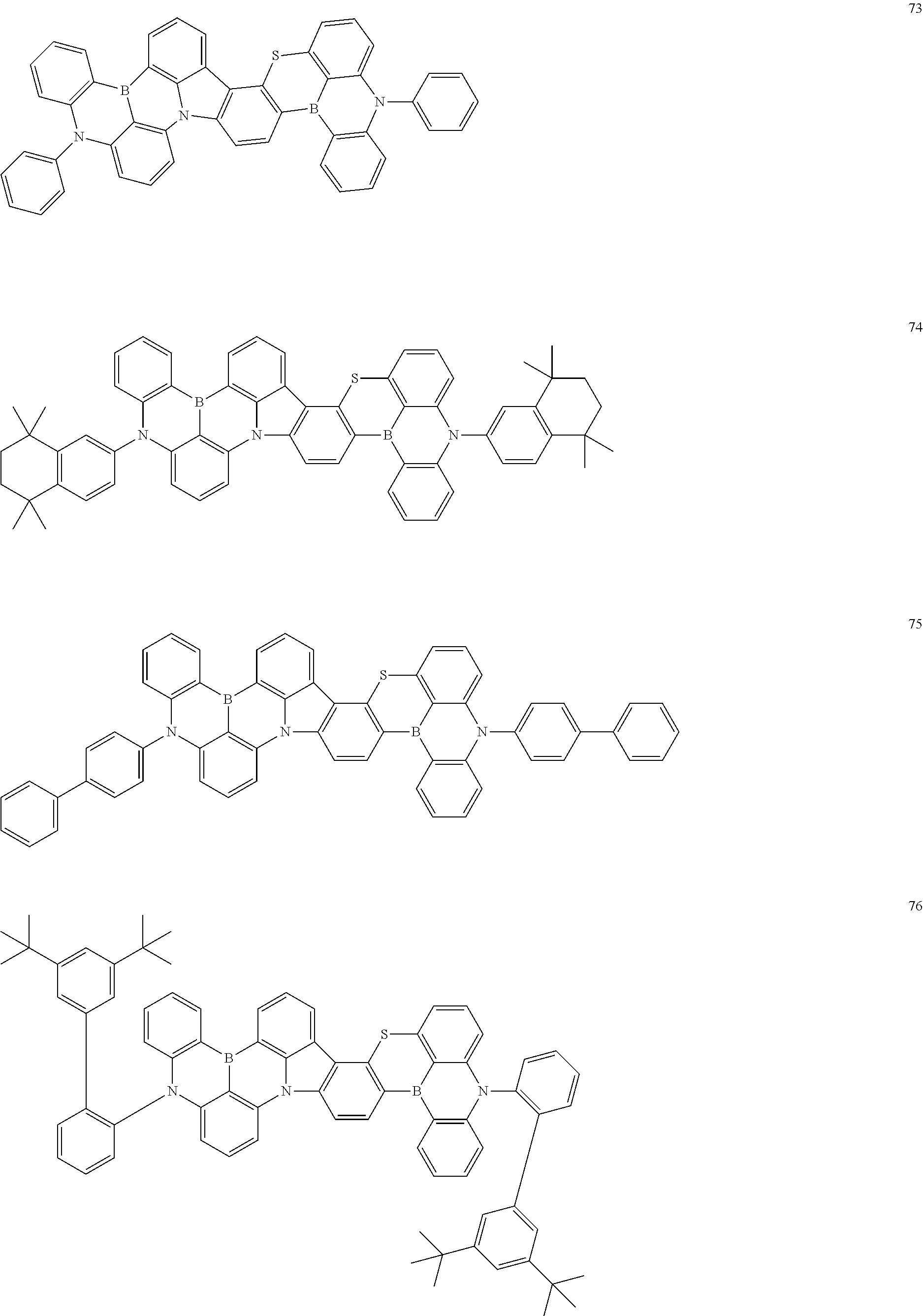 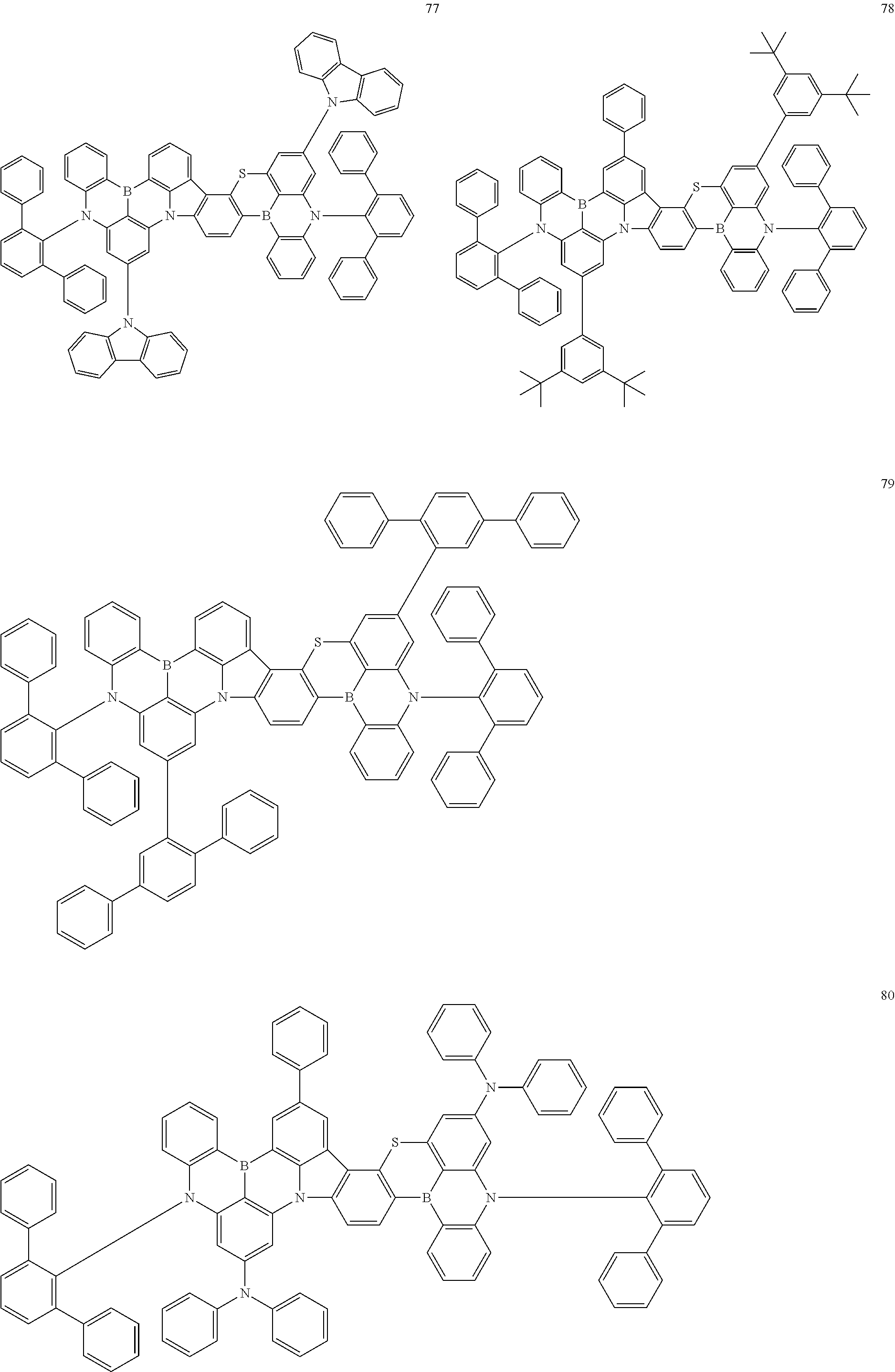 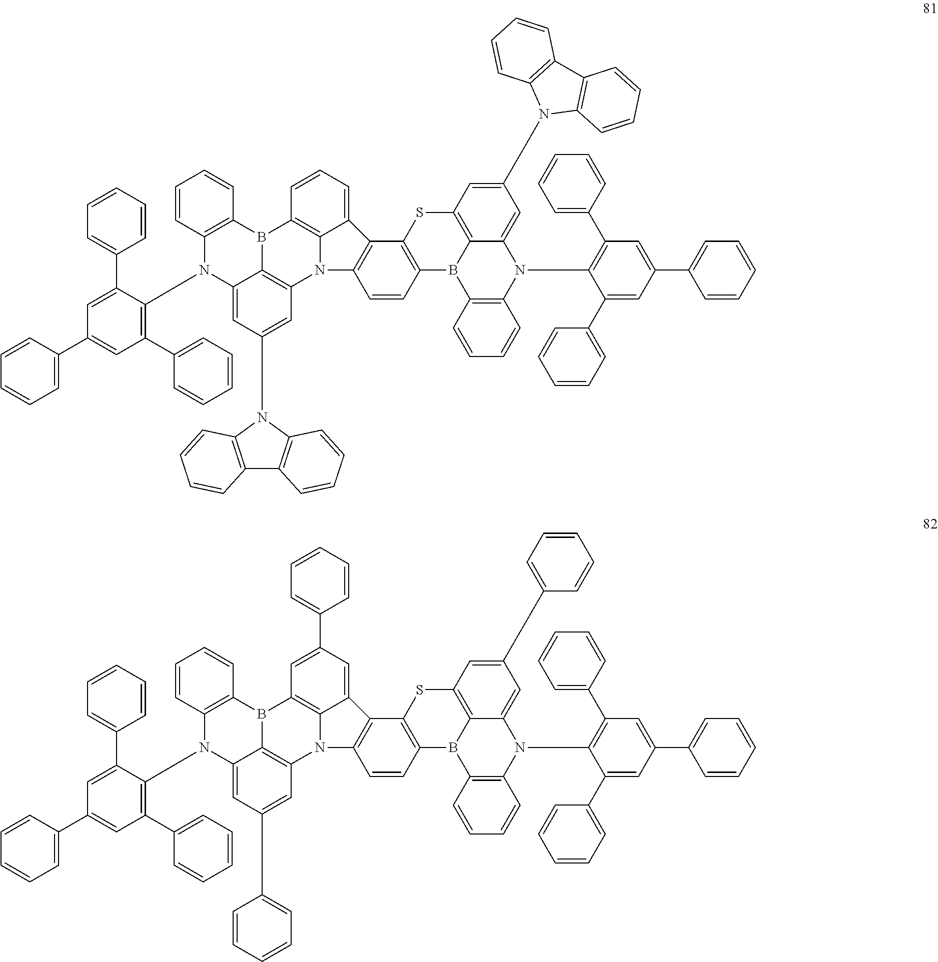 [SMILES: c1ccc(-c2cc(-c3ccccc3)c(N3c4ccccc4B4c5ccc6c(c5Sc5cc(-n7c8ccccc8c8ccccc87)cc3c54)c3cccc4c3n6-c3cc(-n5c6ccccc6c6ccccc65)cc5c3B4c3ccccc3N5c3c(-c4ccccc4)cc(-c4ccccc4)cc3-c3ccccc3)c(-c3ccccc3)c2)cc1 ; c1ccc(-c2cc(-c3ccccc3)c(N3c4ccccc4B4c5ccc6c(c5Sc5cc(-c7ccccc7)cc3c54)c3cc(-c4ccccc4)cc4c3n6-c3cc(-c5ccccc5)cc5c3B4c3ccccc3N5c3c(-c4ccccc4)cc(-c4ccccc4)cc3-c3ccccc3)c(-c3ccccc3)c2)cc1] 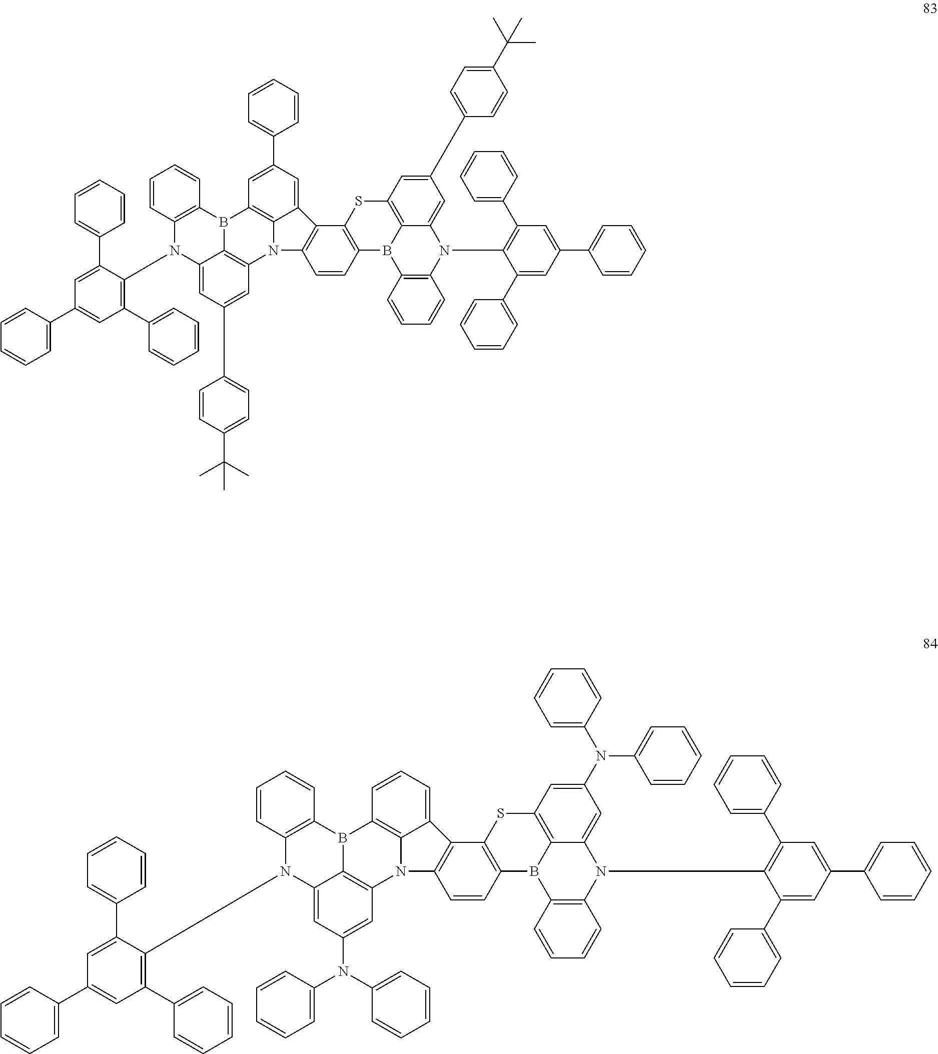 [SMILES: CC(C)(C)c1ccc(-c2cc3c4c(c2)N(c2c(-c5ccccc5)cc(-c5ccccc5)cc2-c2ccccc2)c2ccccc2B4c2ccc4c(c2S3)c2cc(-c3ccccc3)cc3c2n4-c2cc(-c4ccc(C(C)(C)C)cc4)cc4c2B3c2ccccc2N4c2c(-c3ccccc3)cc(-c3ccccc3)cc2-c2ccccc2)cc1 ; c1ccc(-c2cc(-c3ccccc3)c(N3c4ccccc4B4c5ccc6c(c5Sc5cc(N(c7ccccc7)c7ccccc7)cc3c54)c3cccc4c3n6-c3cc(N(c5ccccc5)c5ccccc5)cc5c3B4c3ccccc3N5c3c(-c4ccccc4)cc(-c4ccccc4)cc3-c3ccccc3)c(-c3ccccc3)c2)cc1] 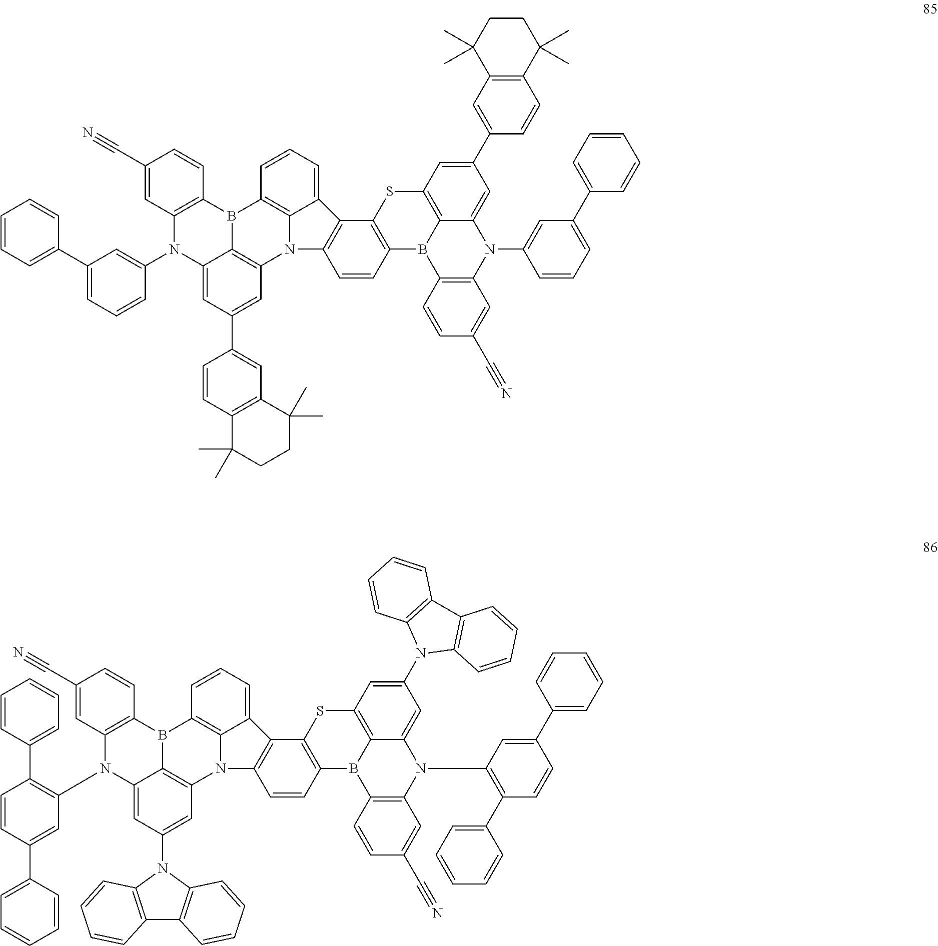 [SMILES: CC1(C)CCC(C)(C)c2cc(-c3cc4c5c(c3)N(c3cccc(-c6ccccc6)c3)c3cc(C#N)ccc3B5c3ccc5c(c3S4)c3cccc4c3n5-c3cc(-c5ccc6c(c5)C(C)(C)CCC6(C)C)cc5c3B4c3ccc(C#N)cc3N5c3cccc(-c4ccccc4)c3)ccc21 ; N#Cc1ccc2c(c1)N(c1cc(-c3ccccc3)ccc1-c1ccccc1)c1cc(-n3c4ccccc4c4ccccc43)cc3c1B2c1ccc2c(c1S3)c1cccc3c1n2-c1cc(-n2c4ccccc4c4ccccc42)cc2c1B3c1ccc(C#N)cc1N2c1cc(-c2ccccc2)ccc1-c1ccccc1] 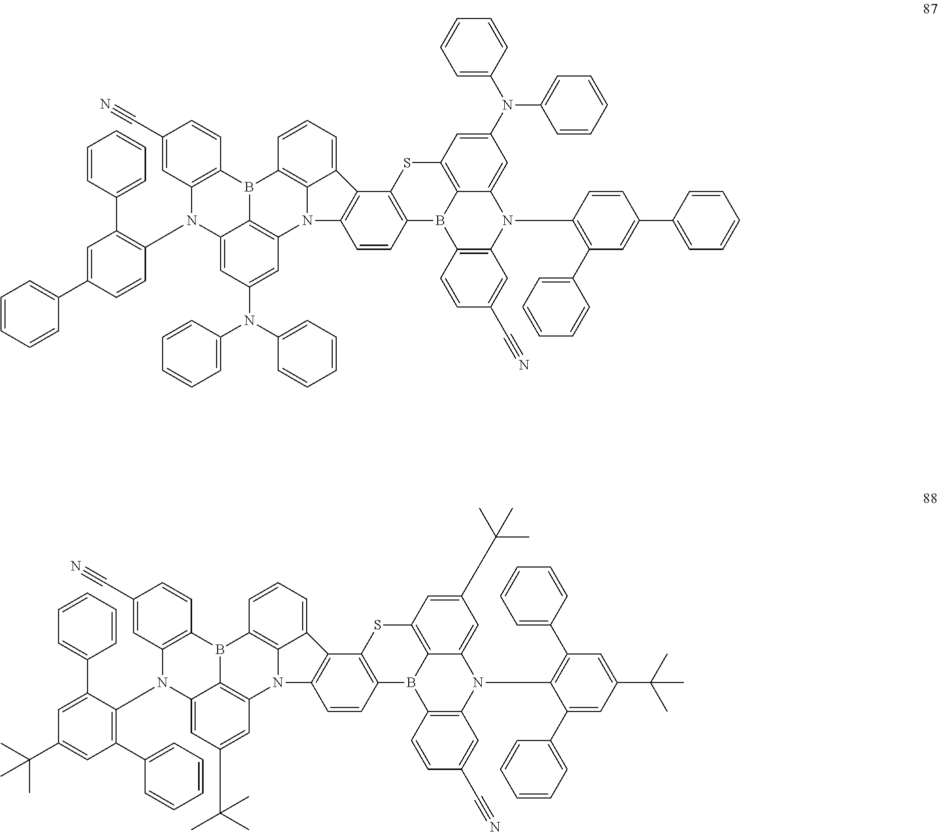 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C#N)ccc3B3c4ccc5c(c4Sc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1] 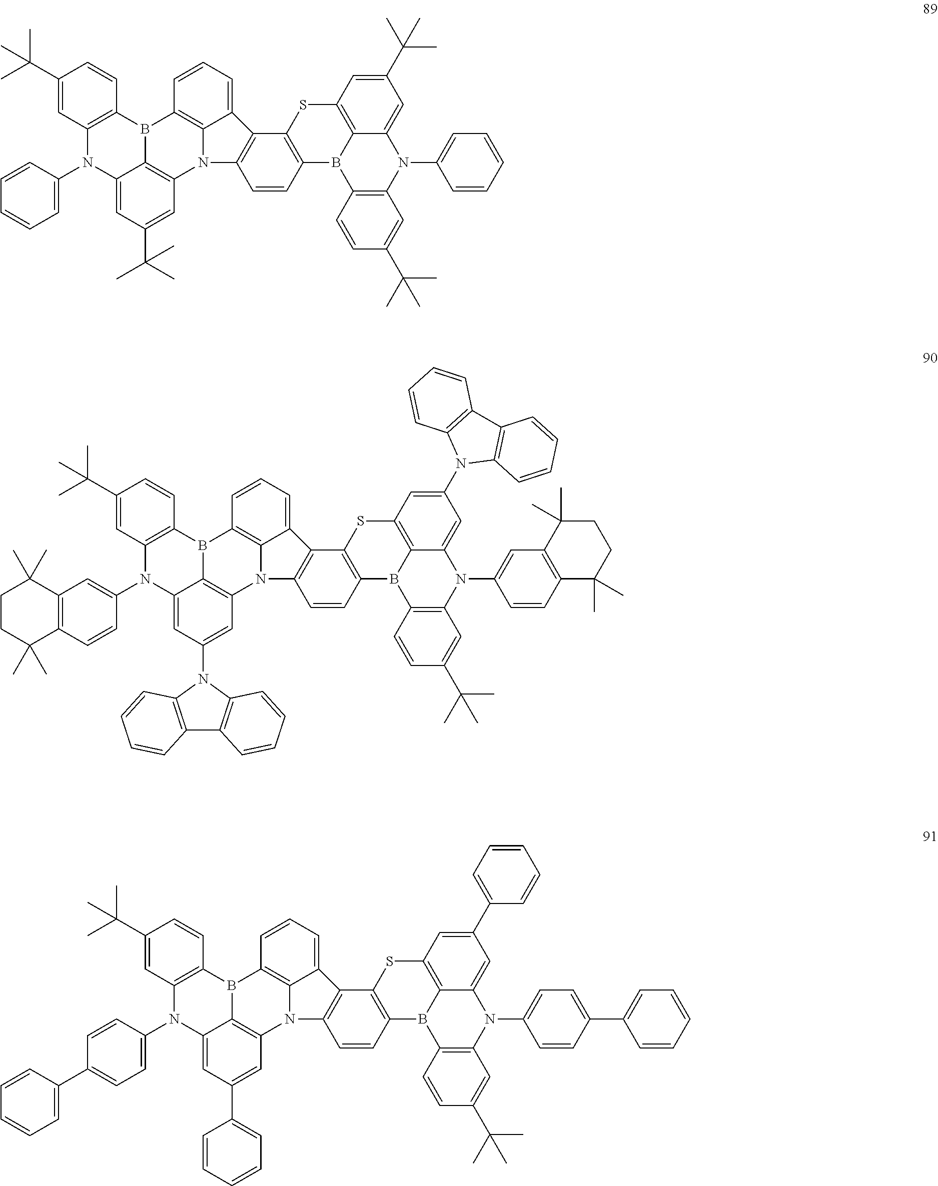 [SMILES: CC(C)(C)c1ccc2c(c1)N(c1ccccc1)c1cc(C(C)(C)C)cc3c1B2c1ccc2c(c1S3)c1cccc3c1n2-c1cc(C(C)(C)C)cc2c1B3c1ccc(C(C)(C)C)cc1N2c1ccccc1 ; CC(C)(C)c1ccc2c(c1)N(c1ccc3c(c1)C(C)(C)CCC3(C)C)c1cc(-n3c4ccccc4c4ccccc43)cc3c1B2c1ccc2c(c1S3)c1cccc3c1n2-c1cc(-n2c4ccccc4c4ccccc42)cc2c1B3c1ccc(C(C)(C)C)cc1N2c1ccc2c(c1)C(C)(C)CCC2(C)C ; CC(C)(C)c1ccc2c(c1)N(c1ccc(-c3ccccc3)cc1)c1cc(-c3ccccc3)cc3c1B2c1ccc2c(c1S3)c1cccc3c1n2-c1cc(-c2ccccc2)cc2c1B3c1ccc(C(C)(C)C)cc1N2c1ccc(-c2ccccc2)cc1] 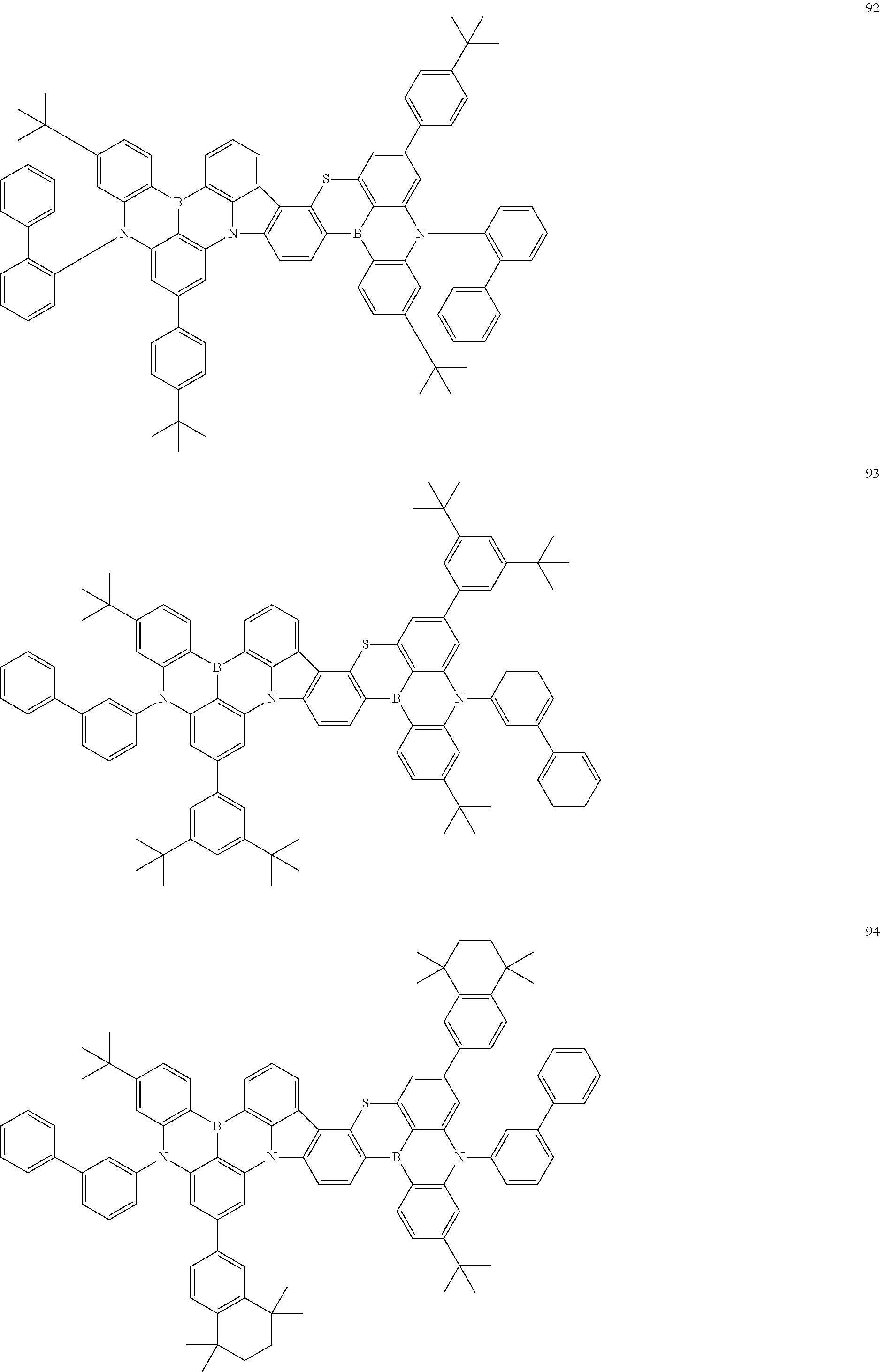 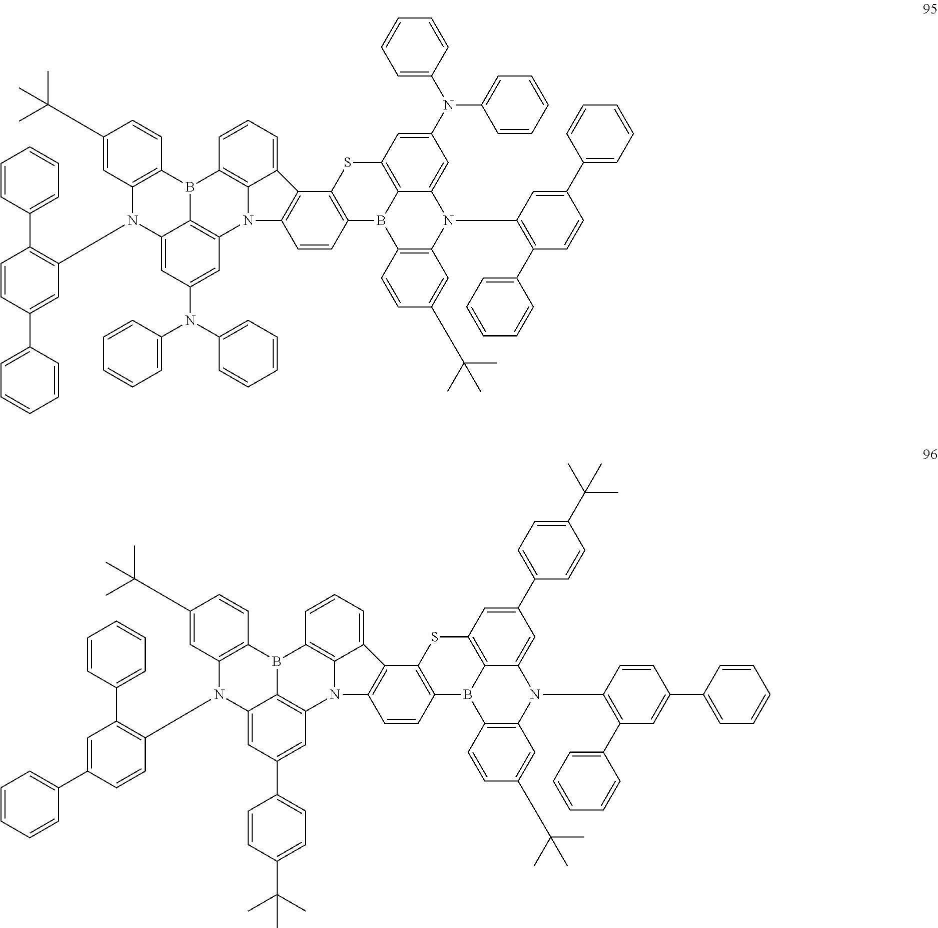 [SMILES: CC(C)(C)c1ccc2c(c1)N(c1cc(-c3ccccc3)ccc1-c1ccccc1)c1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)N(c2ccc(-c5ccccc5)cc2-c2ccccc2)c2cc(C(C)(C)C)ccc2B4c2ccc4c(c2S3)c2cccc3c2n4-c2cc(-c4ccc(C(C)(C)C)cc4)cc4c2B3c2ccc(C(C)(C)C)cc2N4c2ccc(-c3ccccc3)cc2-c2ccccc2)cc1] 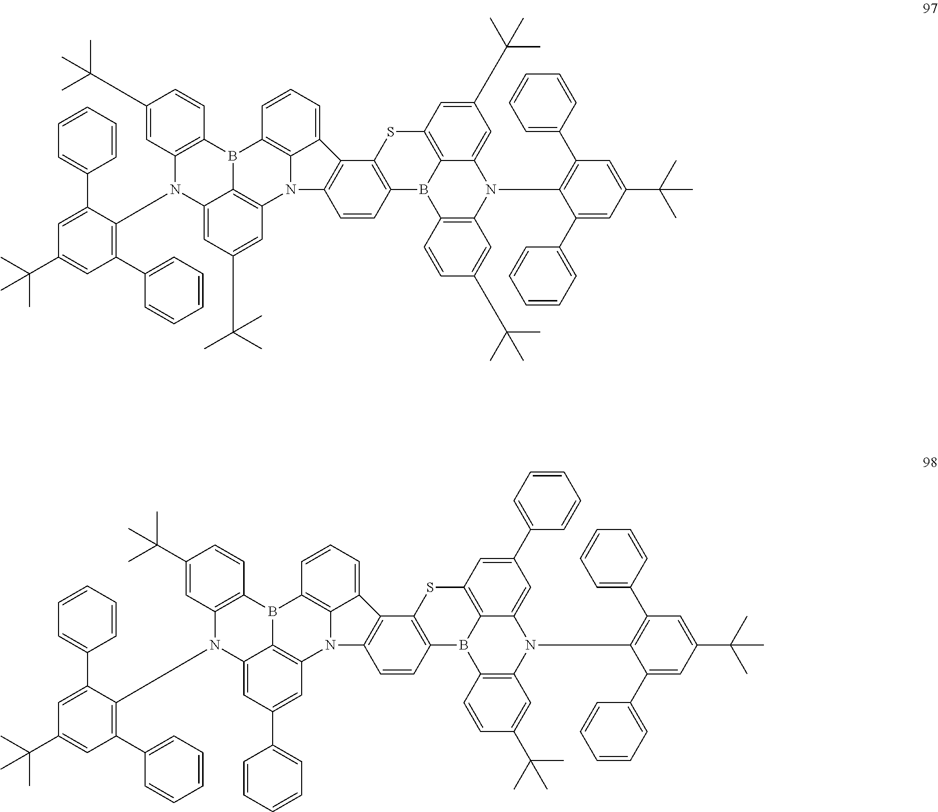 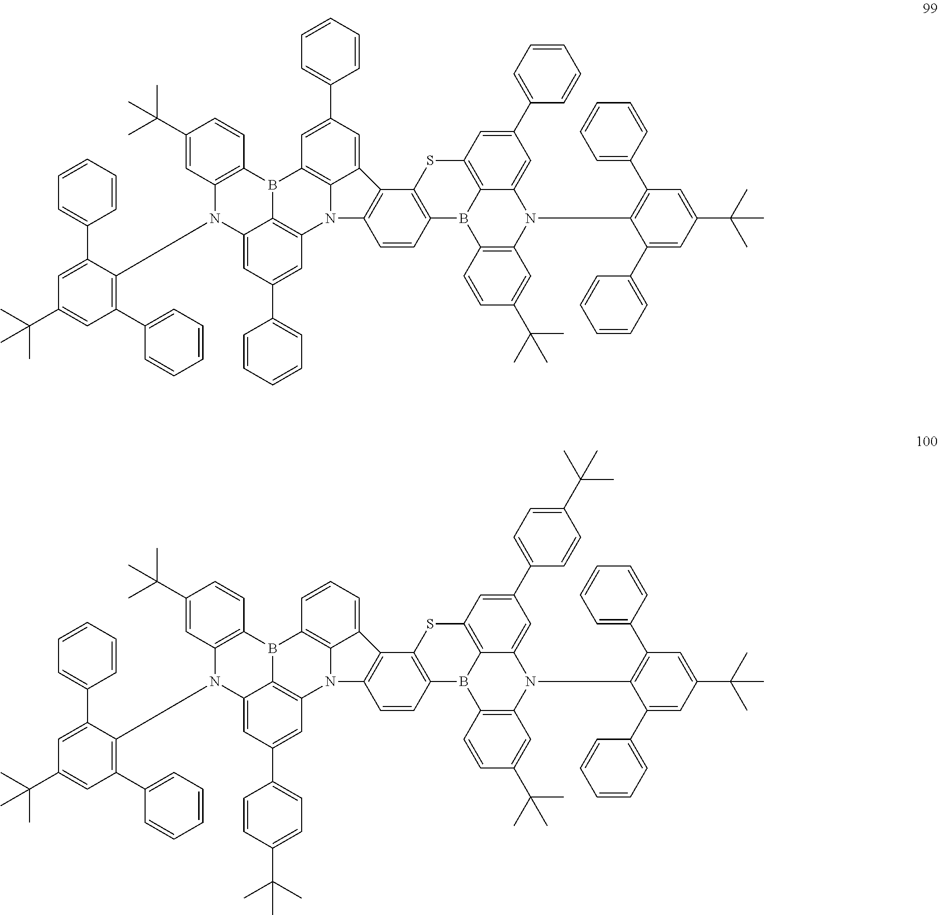 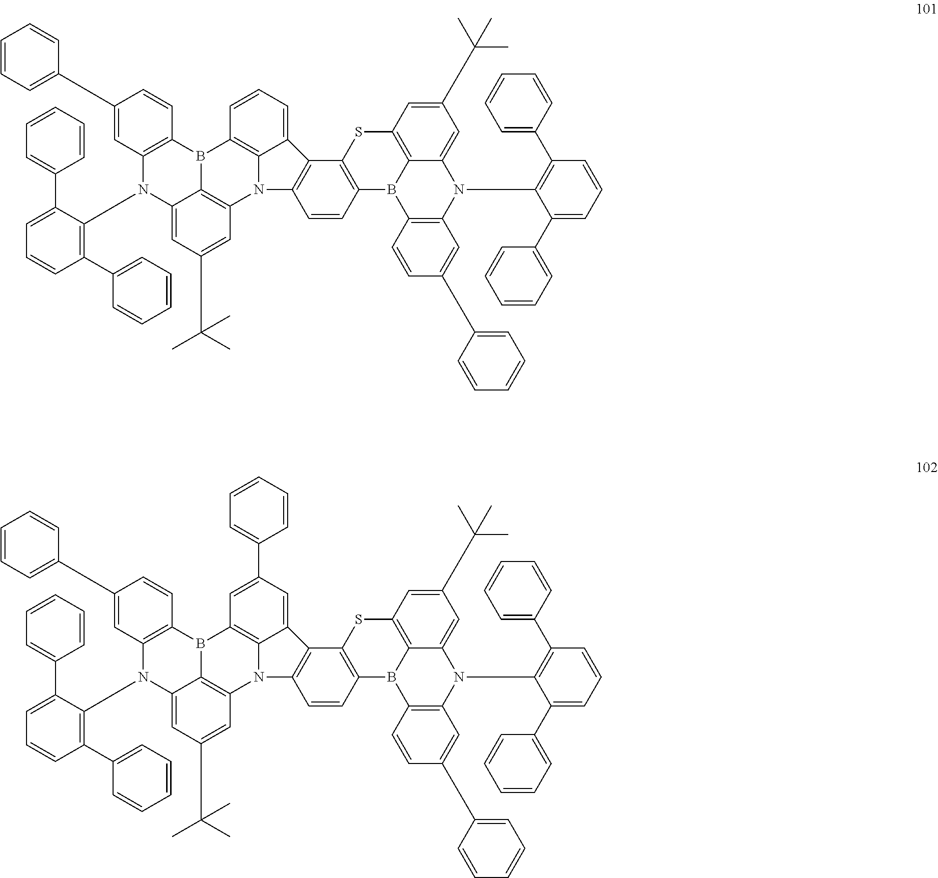 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cccc2c1n3-c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1] 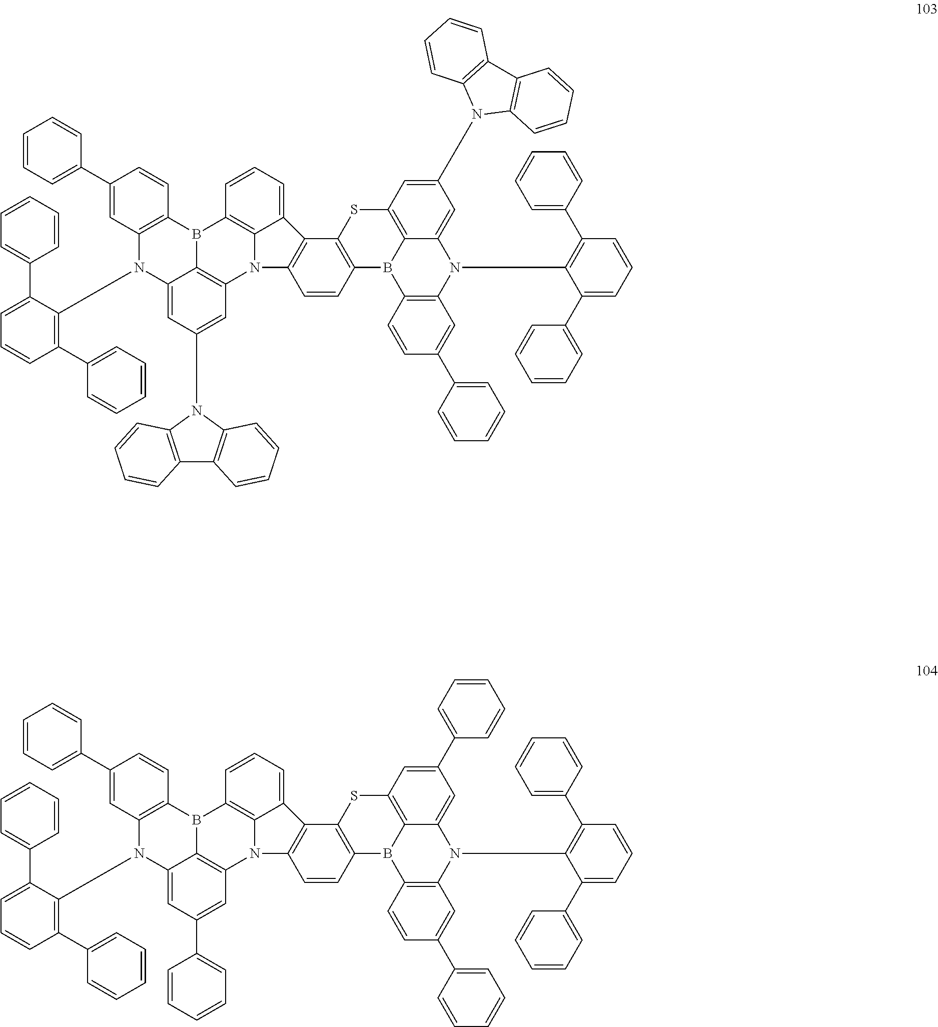 [SMILES: c1ccc(-c2ccc3c(c2)N(c2c(-c4ccccc4)cccc2-c2ccccc2)c2cc(-n4c5ccccc5c5ccccc54)cc4c2B3c2ccc3c(c2S4)c2cccc4c2n3-c2cc(-n3c5ccccc5c5ccccc53)cc3c2B4c2ccc(-c4ccccc4)cc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc3c(c2S4)c2cccc4c2n3-c2cc(-c3ccccc3)cc3c2B4c2ccc(-c4ccccc4)cc2N3c2c(-c3ccccc3)cccc2-c2ccccc2)cc1] 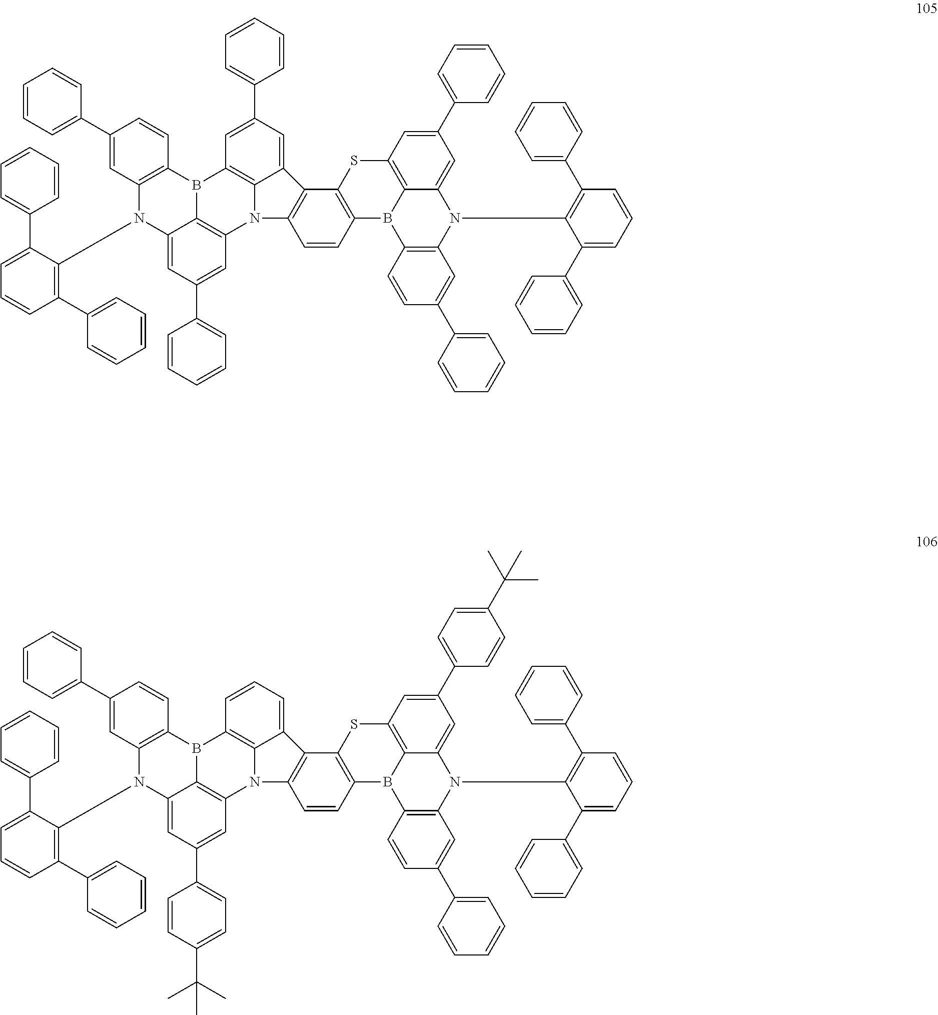 [SMILES: c1ccc(-c2ccc3c(c2)N(c2c(-c4ccccc4)cccc2-c2ccccc2)c2cc(-c4ccccc4)cc4c2B3c2ccc3c(c2S4)c2cc(-c4ccccc4)cc4c2n3-c2cc(-c3ccccc3)cc3c2B4c2ccc(-c4ccccc4)cc2N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cccc3c2n4-c2cc(-c4ccc(C(C)(C)C)cc4)cc4c2B3c2ccc(-c3ccccc3)cc2N4c2c(-c3ccccc3)cccc2-c2ccccc2)cc1] 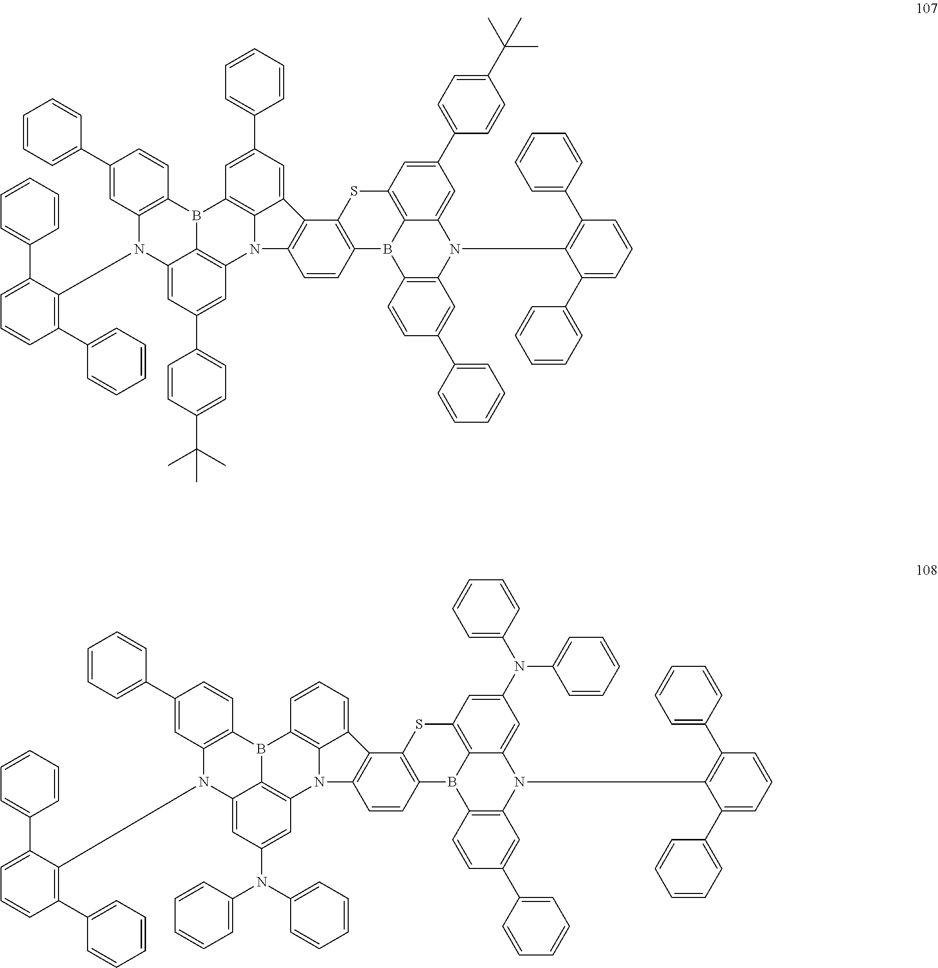 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cc(-c3ccccc3)cc3c2n4-c2cc(-c4ccc(C(C)(C)C)cc4)cc4c2B3c2ccc(-c3ccccc3)cc2N4c2c(-c3ccccc3)cccc2-c2ccccc2)cc1 ; c1ccc(-c2ccc3c(c2)N(c2c(-c4ccccc4)cccc2-c2ccccc2)c2cc(N(c4ccccc4)c4ccccc4)cc4c2B3c2ccc3c(c2S4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 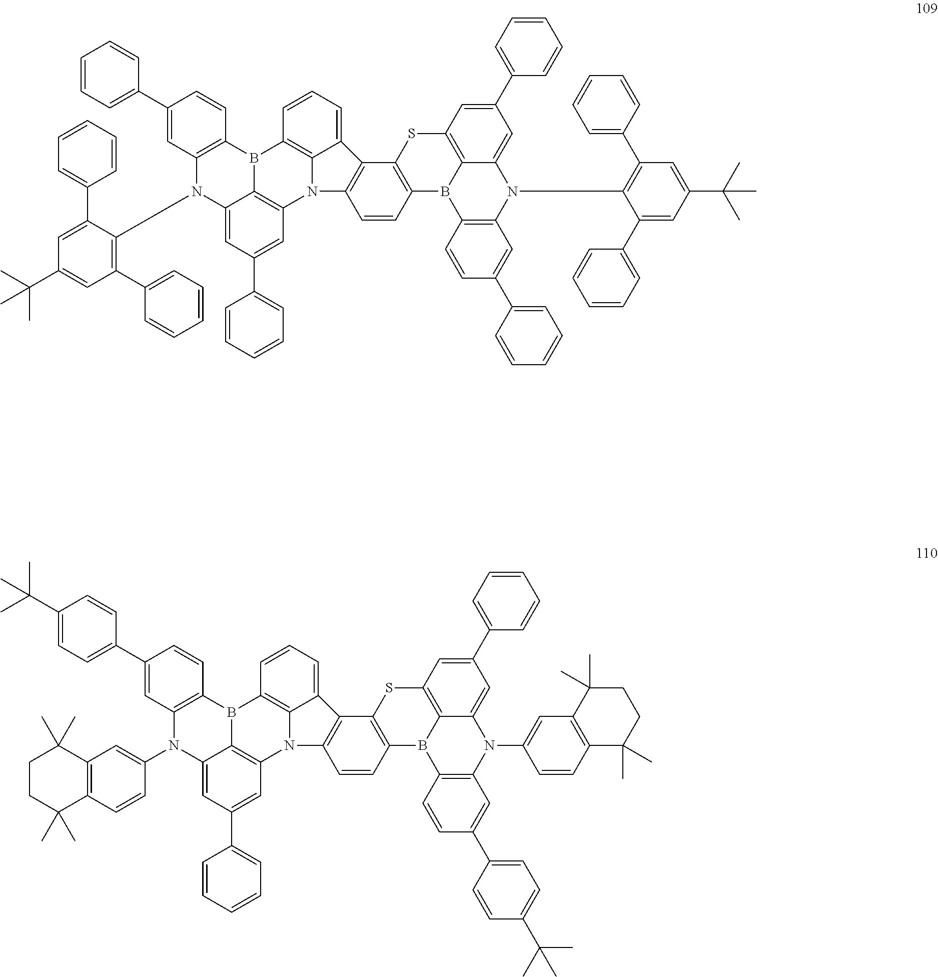 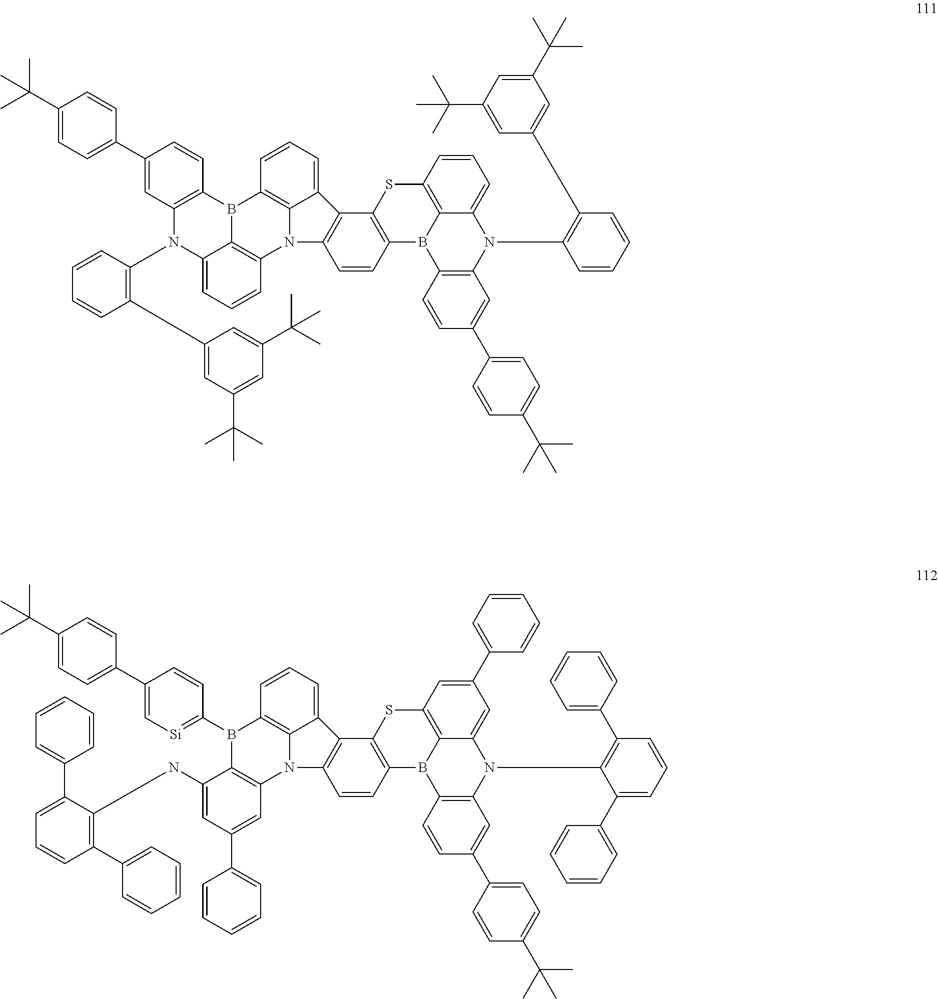 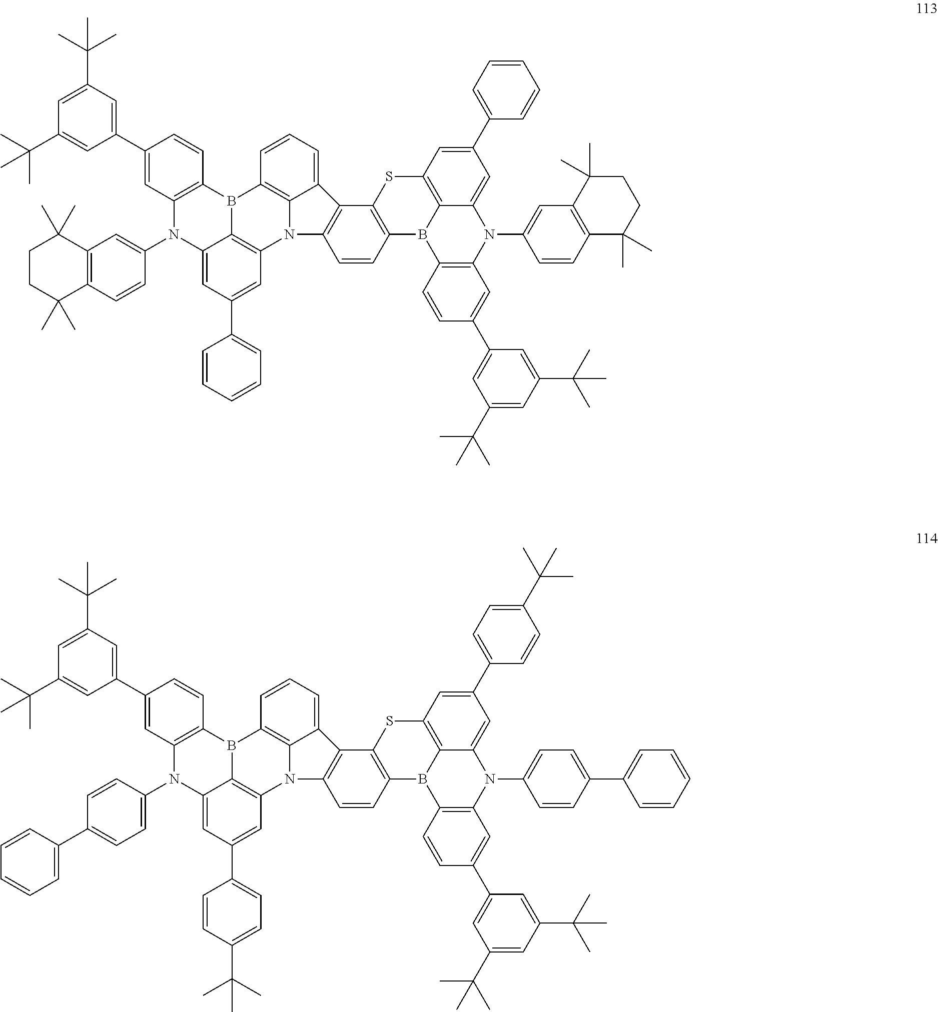 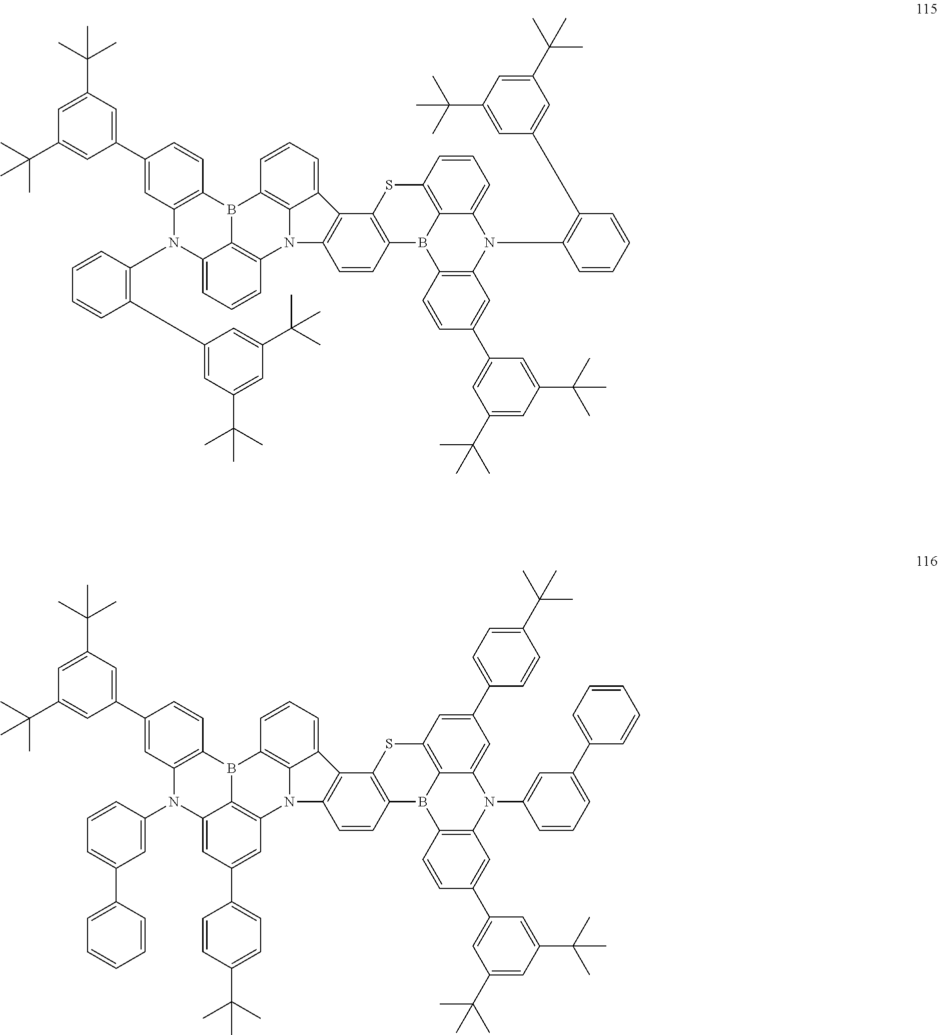 [SMILES: CC(C)(C)c1cc(-c2ccc3c(c2)N(c2ccccc2-c2cc(C(C)(C)C)cc(C(C)(C)C)c2)c2cccc4c2B3c2ccc3c(c2S4)c2cccc4c2n3-c2cccc3c2B4c2ccc(-c4cc(C(C)(C)C)cc(C(C)(C)C)c4)cc2N3c2ccccc2-c2cc(C(C)(C)C)cc(C(C)(C)C)c2)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2S3)c2cccc3c2n4-c2cc(-c4ccc(C(C)(C)C)cc4)cc4c2B3c2ccc(-c3cc(C(C)(C)C)cc(C(C)(C)C)c3)cc2N4c2cccc(-c3ccccc3)c2)cc1] 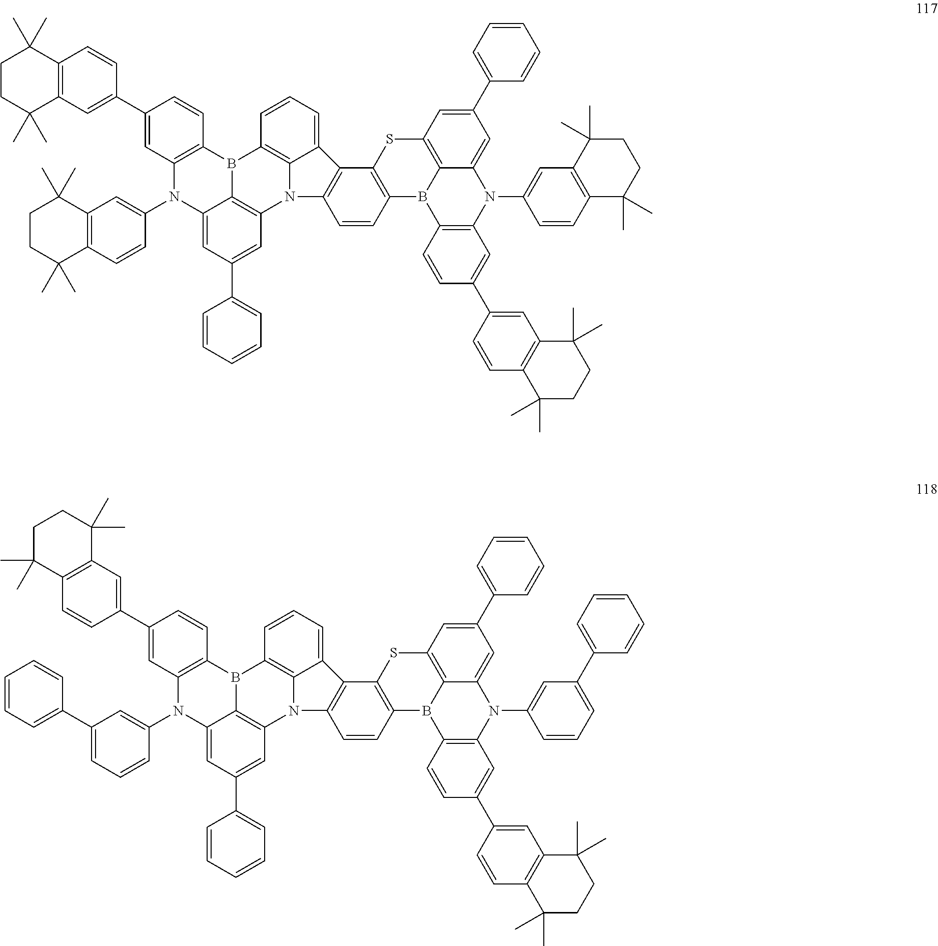 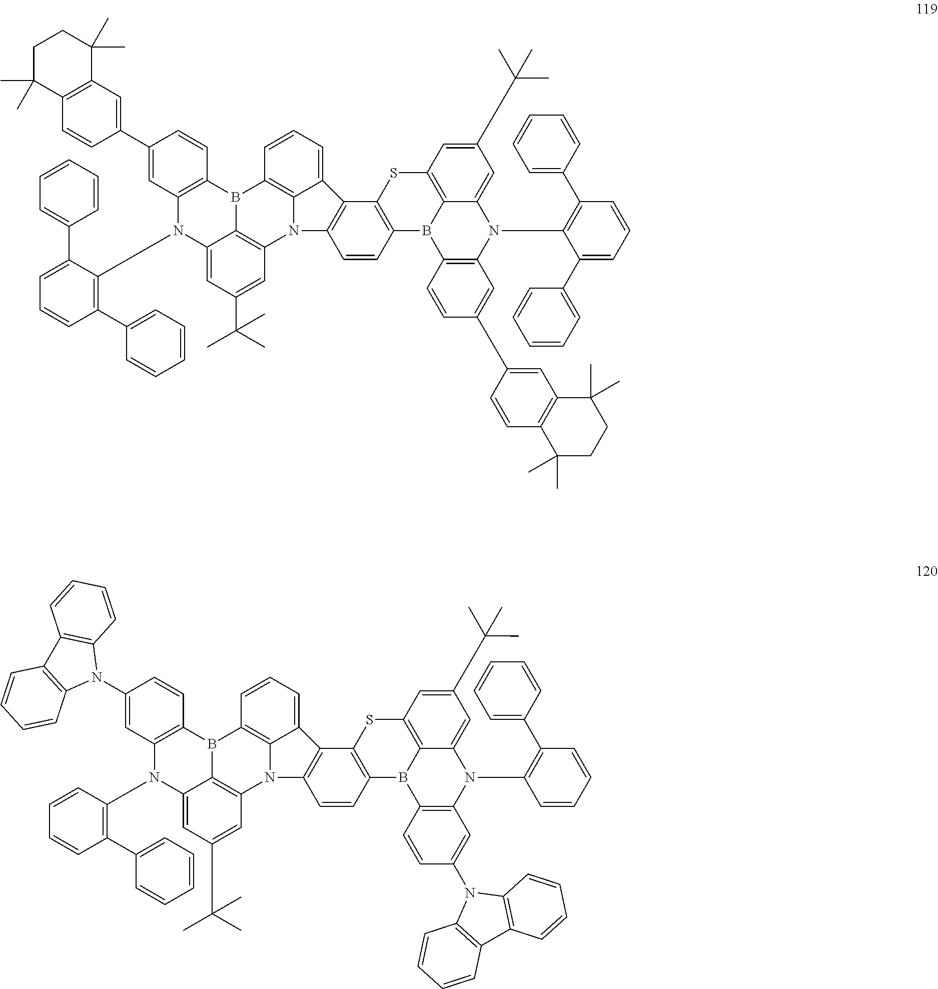 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1S2)c1cccc2c1n3-c1cc(C(C)(C)C)cc3c1B2c1ccc(-c2ccc4c(c2)C(C)(C)CCC4(C)C)cc1N3c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1ccccc1-c1ccccc1] 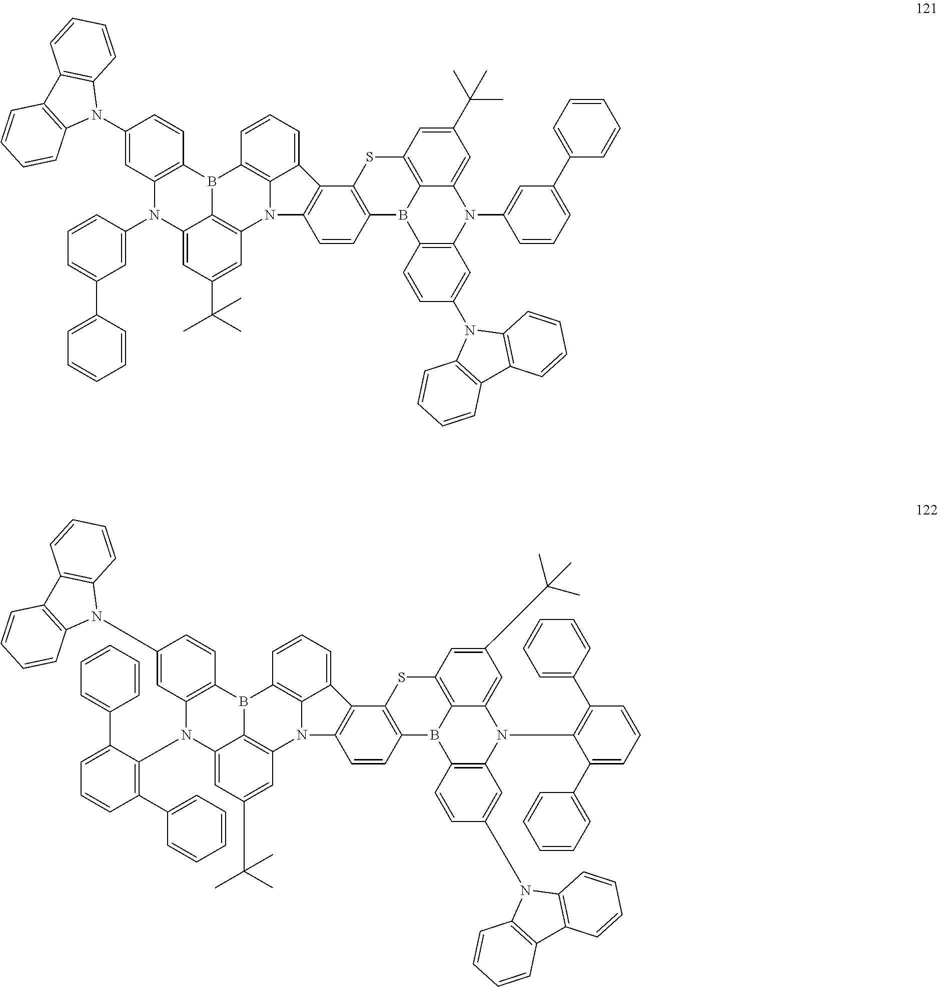 [SMILES: CC(C)(C)c1cc2c3c(c1)N(c1cccc(-c4ccccc4)c1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1c(-c2ccccc2)cccc1-c1ccccc1] 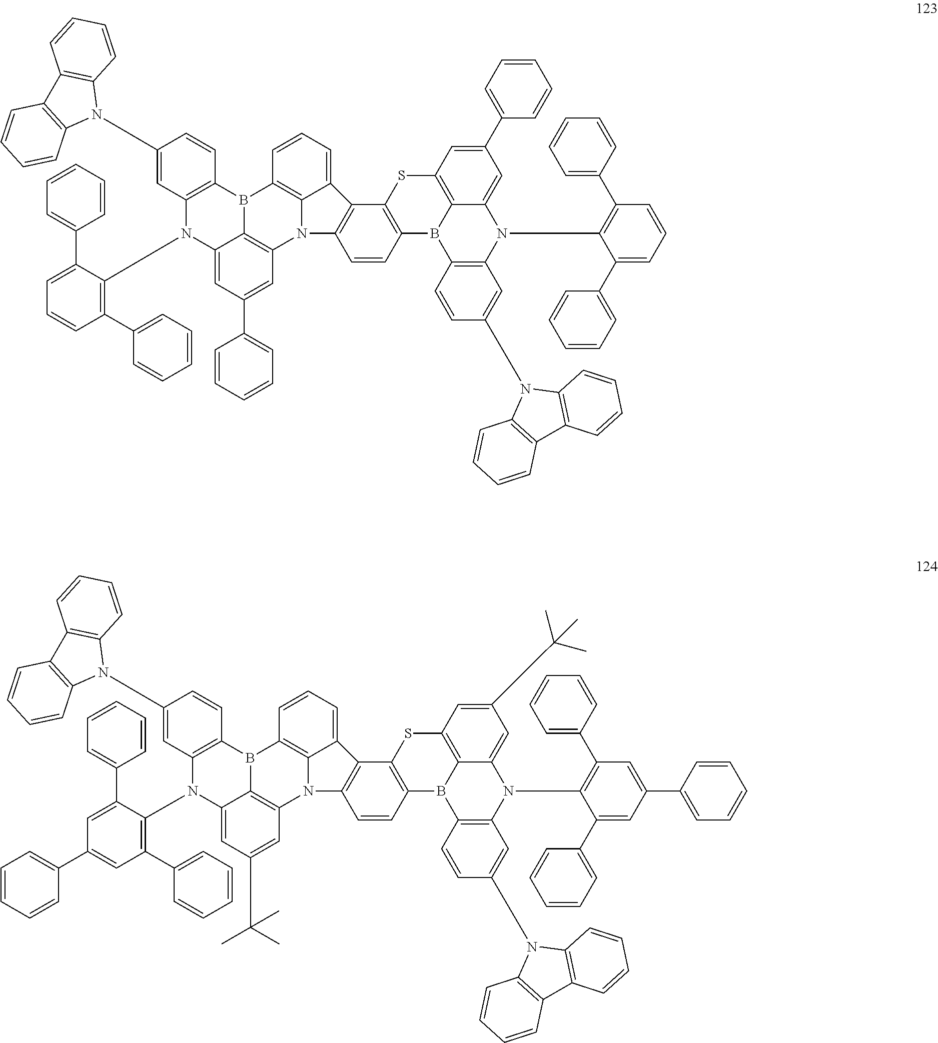 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2S3)c2cccc3c2n4-c2cc(-c4ccccc4)cc4c2B3c2ccc(-n3c5ccccc5c5ccccc53)cc2N4c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1c(-c2ccccc2)cc(-c2ccccc2)cc1-c1ccccc1] 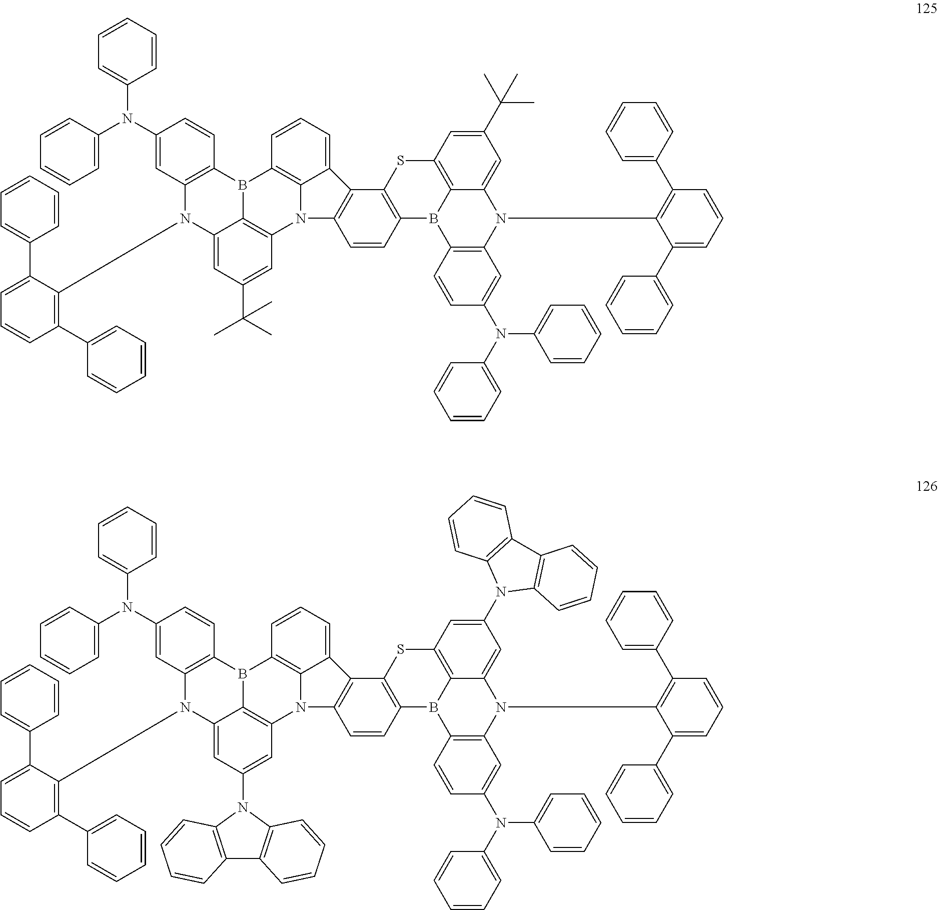 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1S2)c1cccc2c1n3-c1cc(C(C)(C)C)cc3c1B2c1ccc(N(c2ccccc2)c2ccccc2)cc1N3c1c(-c2ccccc2)cccc1-c1ccccc1 ; c1ccc(-c2cccc(-c3ccccc3)c2N2c3cc(N(c4ccccc4)c4ccccc4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2N4c2c(-c3ccccc3)cccc2-c2ccccc2)cc1] 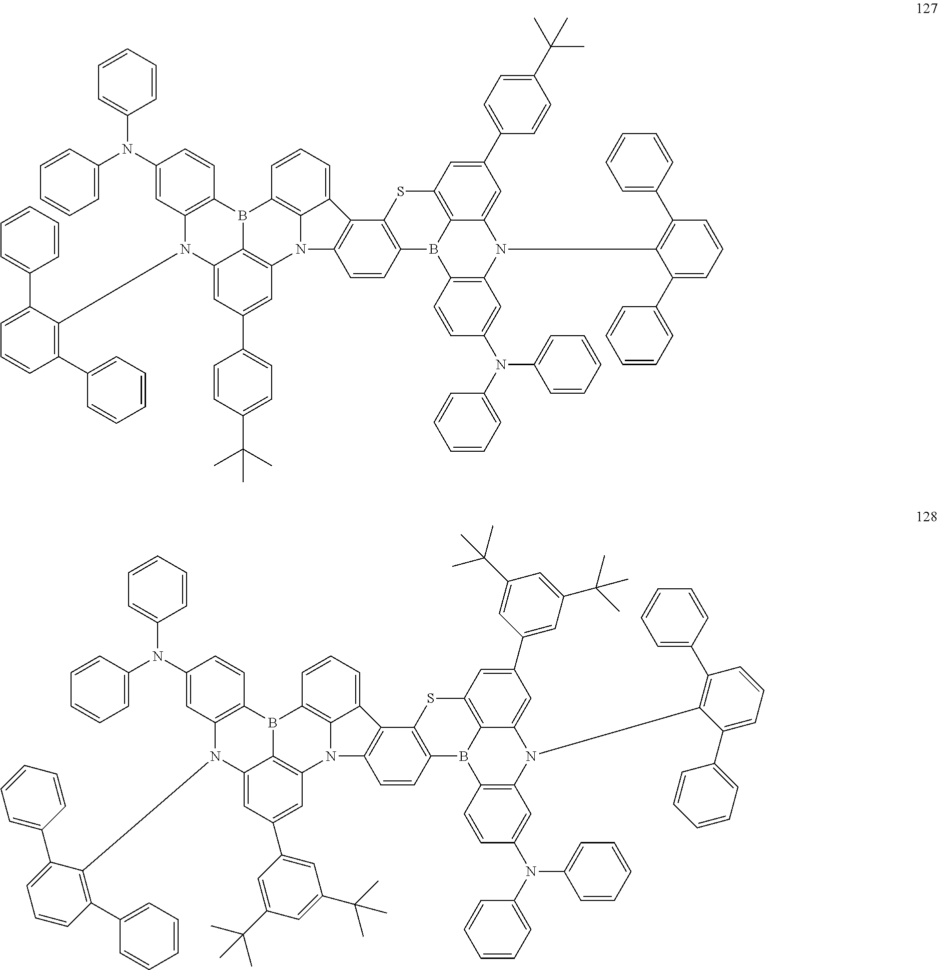 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4ccc(C(C)(C)C)cc4)cc4c2B3c2ccc(N(c3ccccc3)c3ccccc3)cc2N4c2c(-c3ccccc3)cccc2-c2ccccc2)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4cc(C(C)(C)C)cc(C(C)(C)C)c4)cc4c2B3c2ccc(N(c3ccccc3)c3ccccc3)cc2N4c2c(-c3ccccc3)cccc2-c2ccccc2)cc(C(C)(C)C)c1] 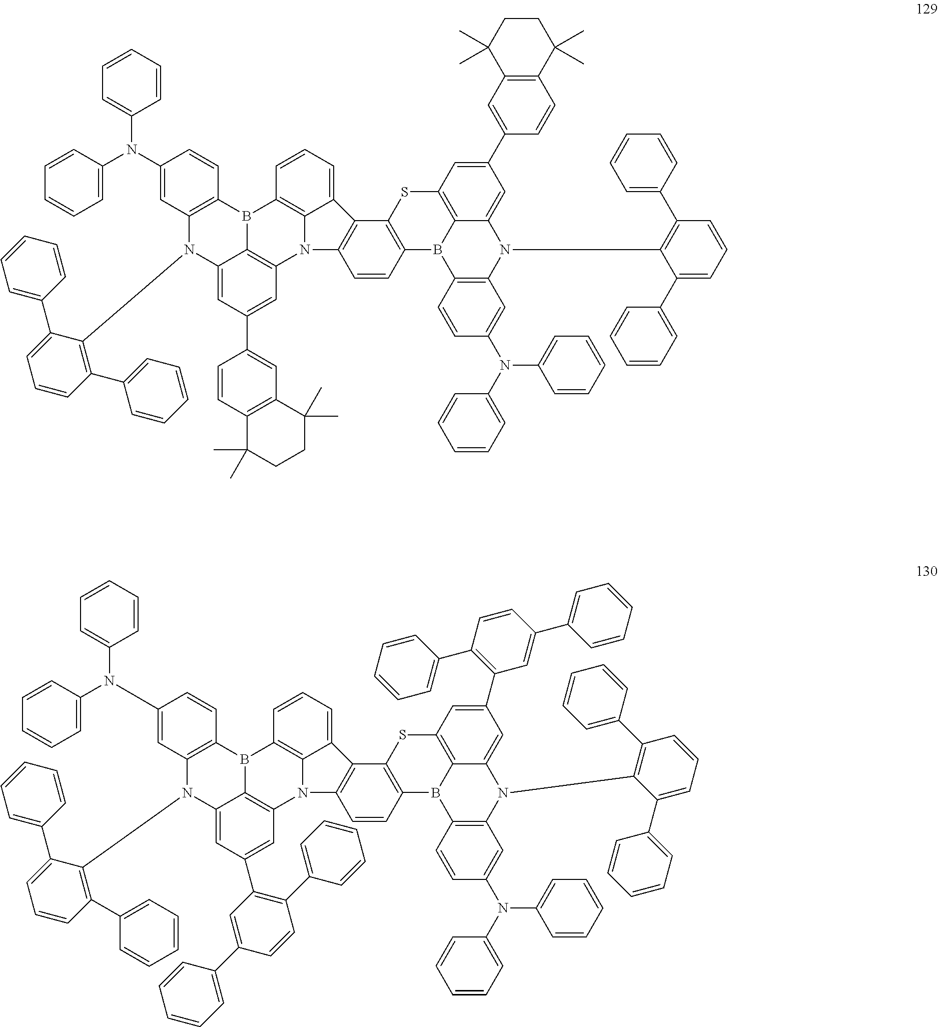 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5ccc6c(c5)C(C)(C)CCC6(C)C)cc5c3B4c3ccc(N(c4ccccc4)c4ccccc4)cc3N5c3c(-c4ccccc4)cccc3-c3ccccc3)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5cc(-c6ccccc6)ccc5-c5ccccc5)cc5c3B4c3ccc(N(c4ccccc4)c4ccccc4)cc3N5c3c(-c4ccccc4)cccc3-c3ccccc3)c2)cc1] 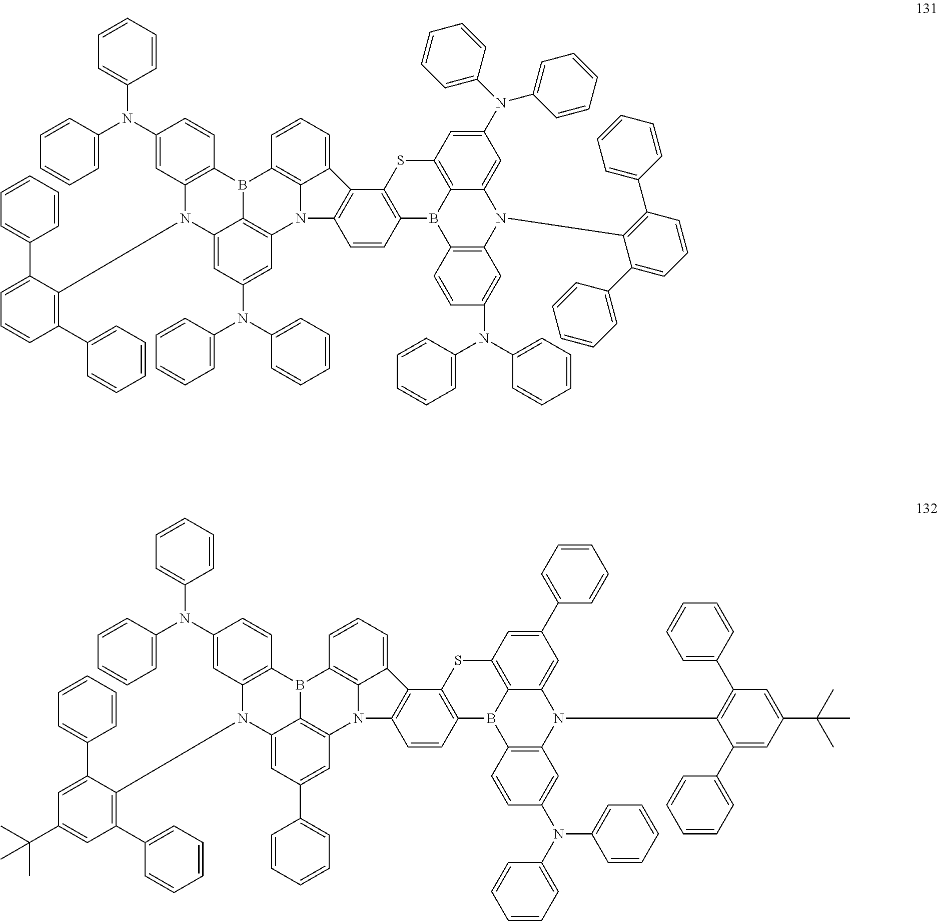 [SMILES: c1ccc(-c2cccc(-c3ccccc3)c2N2c3cc(N(c4ccccc4)c4ccccc4)ccc3B3c4ccc5c(c4Sc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2N4c2c(-c3ccccc3)cccc2-c2ccccc2)cc1 ; CC(C)(C)c1cc(-c2ccccc2)c(N2c3cc(N(c4ccccc4)c4ccccc4)ccc3B3c4ccc5c(c4Sc4cc(-c6ccccc6)cc2c43)c2cccc3c2n5-c2cc(-c4ccccc4)cc4c2B3c2ccc(N(c3ccccc3)c3ccccc3)cc2N4c2c(-c3ccccc3)cc(C(C)(C)C)cc2-c2ccccc2)c(-c2ccccc2)c1] 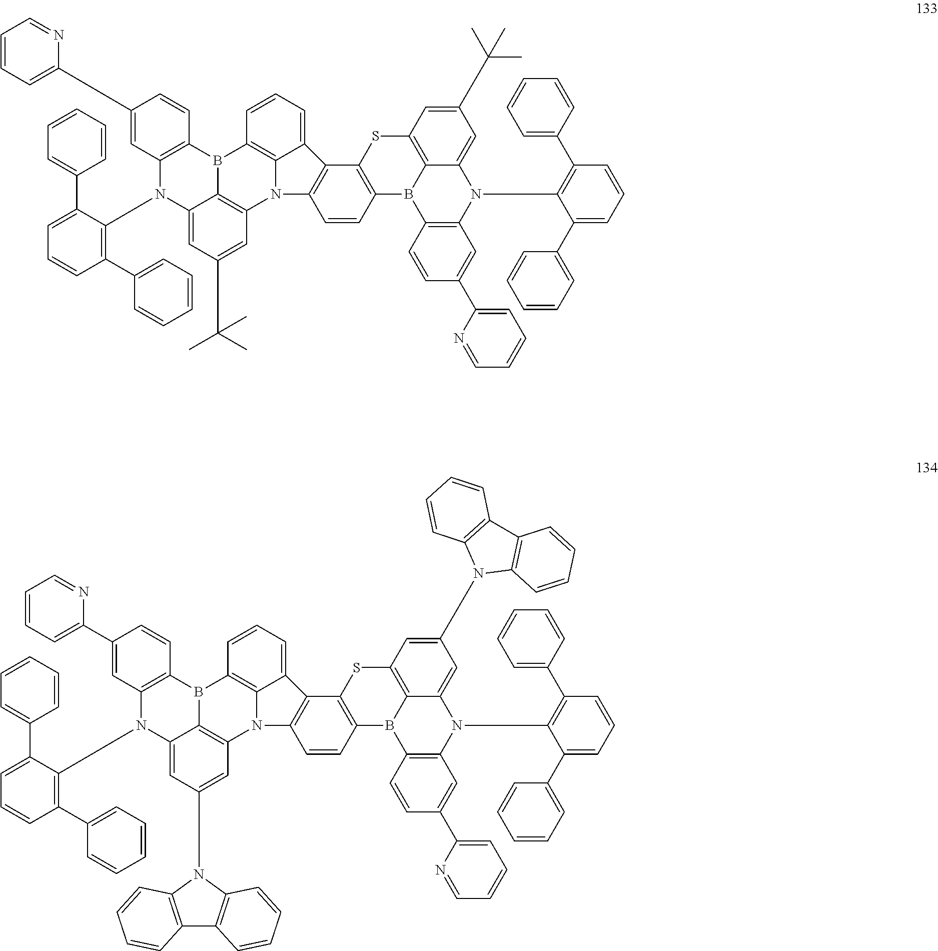 [SMILES: CC(C)(C)c1cc2c3c(c1)N(c1c(-c4ccccc4)cccc1-c1ccccc1)c1cc(-c4ccccn4)ccc1B3c1ccc3c(c1S2)c1cccc2c1n3-c1cc(C(C)(C)C)cc3c1B2c1ccc(-c2ccccn2)cc1N3c1c(-c2ccccc2)cccc1-c1ccccc1 ; c1ccc(-c2cccc(-c3ccccc3)c2N2c3cc(-c4ccccn4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(-c3ccccn3)cc2N4c2c(-c3ccccc3)cccc2-c2ccccc2)cc1] 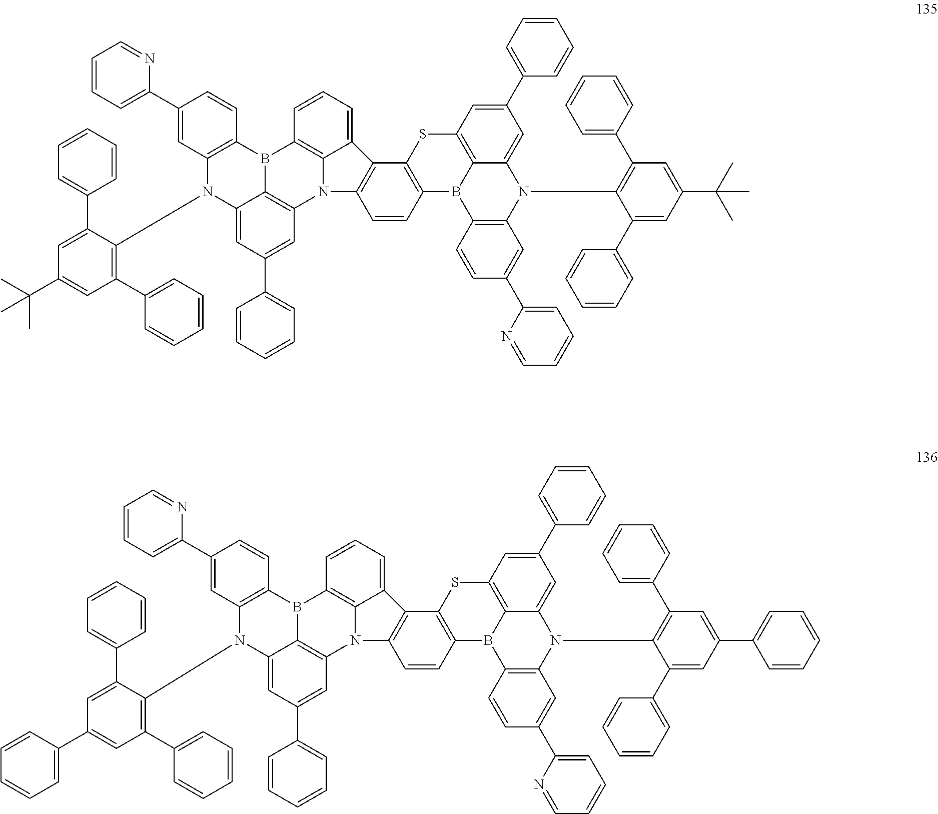 [SMILES: CC(C)(C)c1cc(-c2ccccc2)c(N2c3cc(-c4ccccn4)ccc3B3c4ccc5c(c4Sc4cc(-c6ccccc6)cc2c43)c2cccc3c2n5-c2cc(-c4ccccc4)cc4c2B3c2ccc(-c3ccccn3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccccn5)ccc4B4c5ccc6c(c5Sc5cc(-c7ccccc7)cc3c54)c3cccc4c3n6-c3cc(-c5ccccc5)cc5c3B4c3ccc(-c4ccccn4)cc3N5c3c(-c4ccccc4)cc(-c4ccccc4)cc3-c3ccccc3)c(-c3ccccc3)c2)cc1] 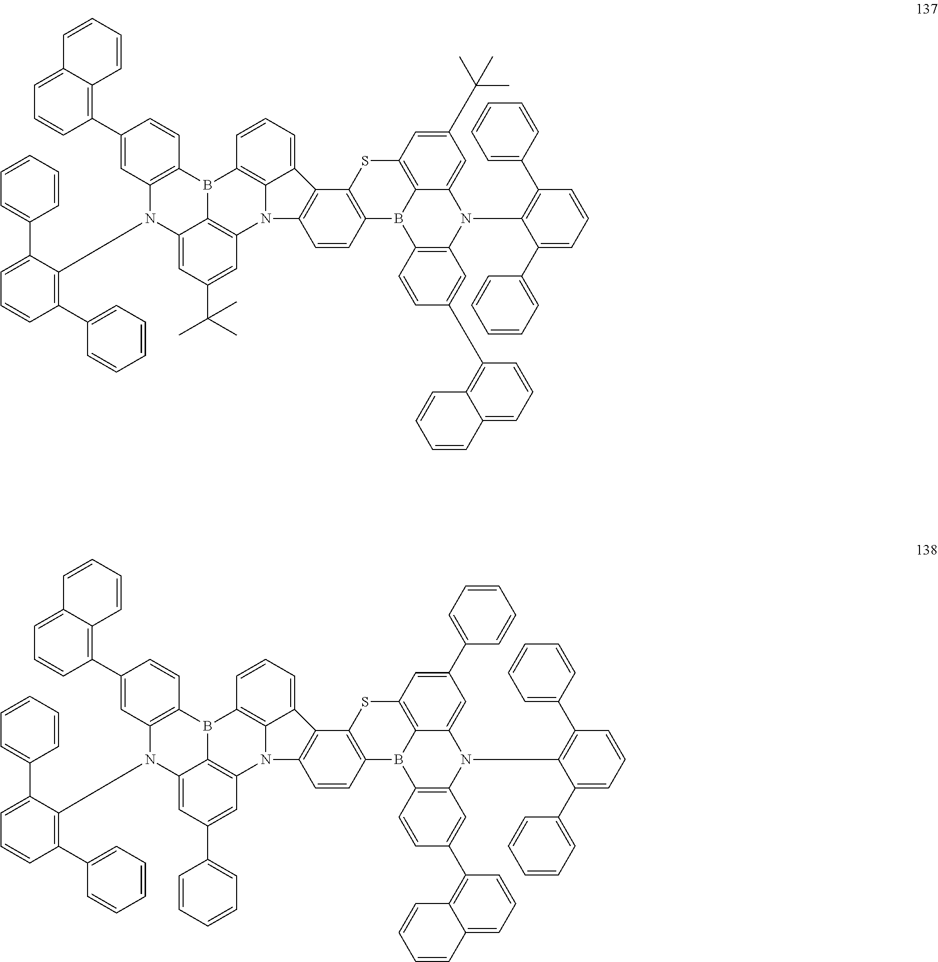 [SMILES: CC(C)(C)c1cc2c3c(c1)N(c1c(-c4ccccc4)cccc1-c1ccccc1)c1cc(-c4cccc5ccccc45)ccc1B3c1ccc3c(c1S2)c1cccc2c1n3-c1cc(C(C)(C)C)cc3c1B2c1ccc(-c2cccc4ccccc24)cc1N3c1c(-c2ccccc2)cccc1-c1ccccc1 ; c1ccc(-c2cc3c4c(c2)N(c2c(-c5ccccc5)cccc2-c2ccccc2)c2cc(-c5cccc6ccccc56)ccc2B4c2ccc4c(c2S3)c2cccc3c2n4-c2cc(-c4ccccc4)cc4c2B3c2ccc(-c3cccc5ccccc35)cc2N4c2c(-c3ccccc3)cccc2-c2ccccc2)cc1] 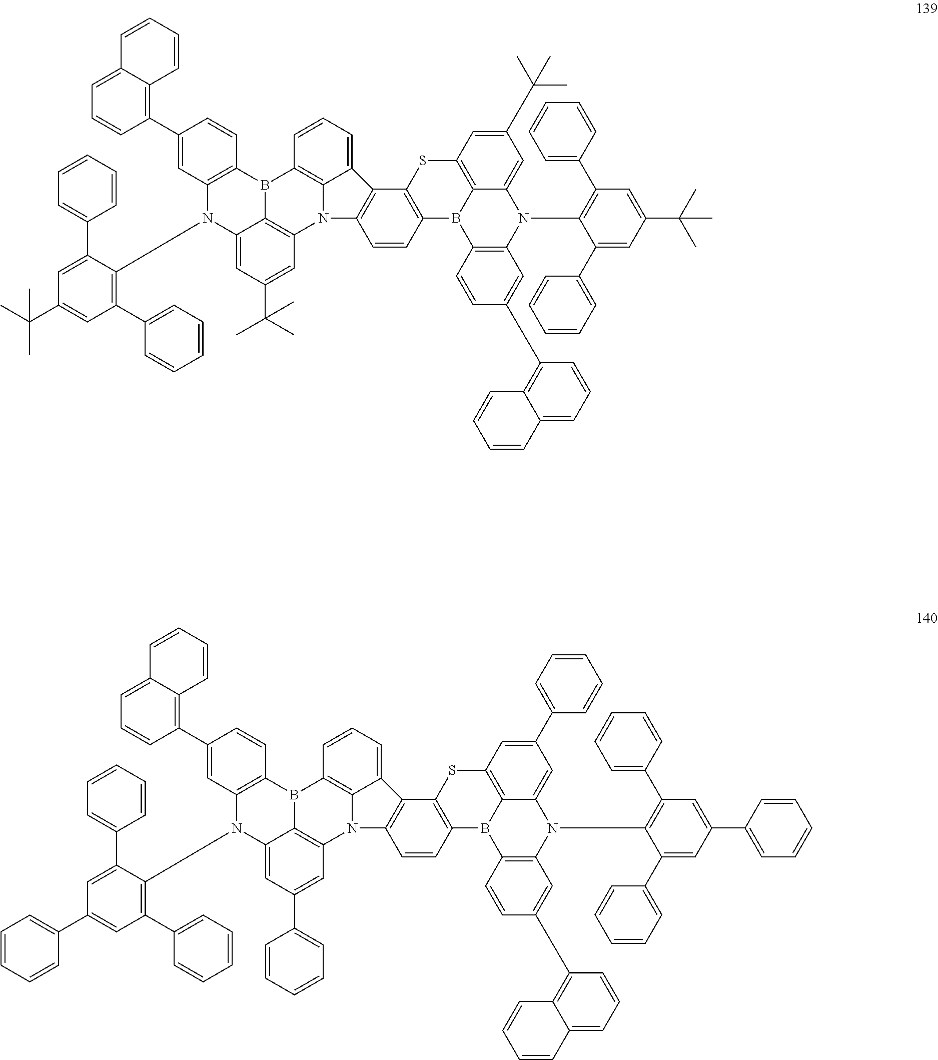 [SMILES: CC(C)(C)c1cc(-c2ccccc2)c(N2c3cc(-c4cccc5ccccc45)ccc3B3c4ccc5c(c4Sc4cc(C(C)(C)C)cc2c43)c2cccc3c2n5-c2cc(C(C)(C)C)cc4c2B3c2ccc(-c3cccc5ccccc35)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5cccc6ccccc56)ccc4B4c5ccc6c(c5Sc5cc(-c7ccccc7)cc3c54)c3cccc4c3n6-c3cc(-c5ccccc5)cc5c3B4c3ccc(-c4cccc6ccccc46)cc3N5c3c(-c4ccccc4)cc(-c4ccccc4)cc3-c3ccccc3)c(-c3ccccc3)c2)cc1] 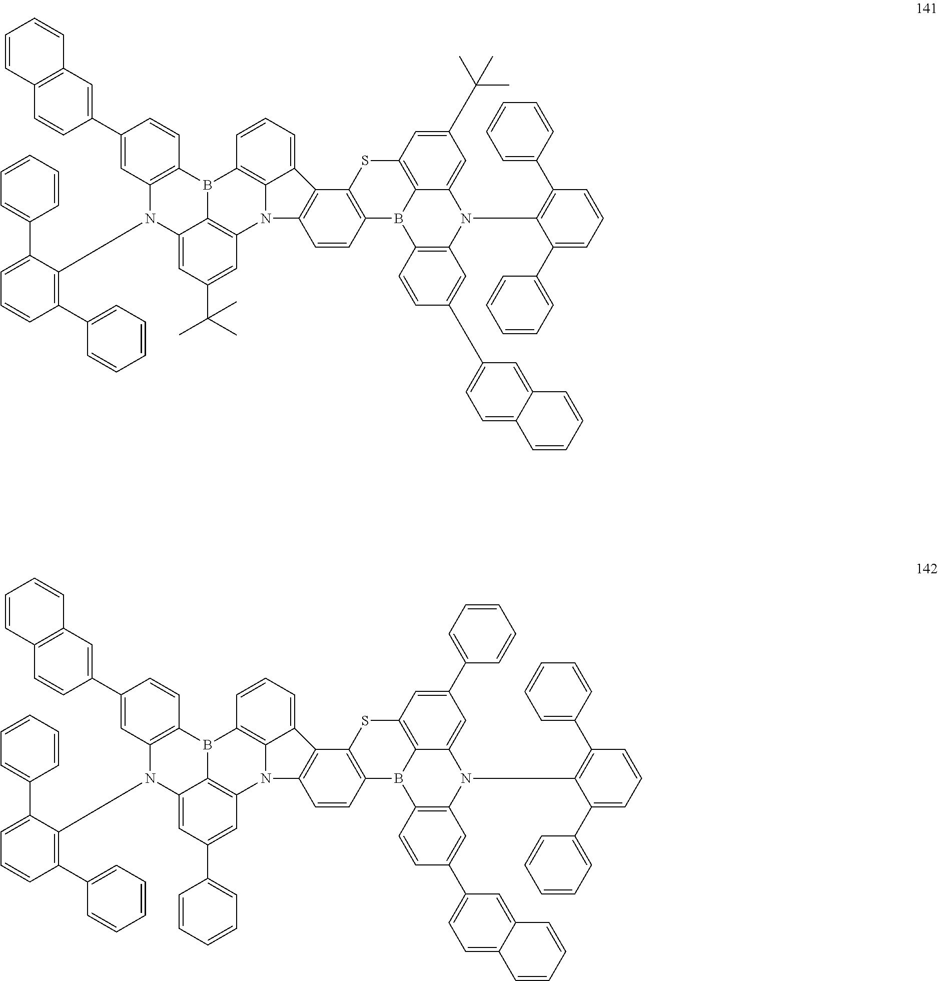 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1S2)c1cccc2c1n3-c1cc(C(C)(C)C)cc3c1B2c1ccc(-c2ccc4ccccc4c2)cc1N3c1c(-c2ccccc2)cccc1-c1ccccc1 ; c1ccc(-c2cc3c4c(c2)N(c2c(-c5ccccc5)cccc2-c2ccccc2)c2cc(-c5ccc6ccccc6c5)ccc2B4c2ccc4c(c2S3)c2cccc3c2n4-c2cc(-c4ccccc4)cc4c2B3c2ccc(-c3ccc5ccccc5c3)cc2N4c2c(-c3ccccc3)cccc2-c2ccccc2)cc1] 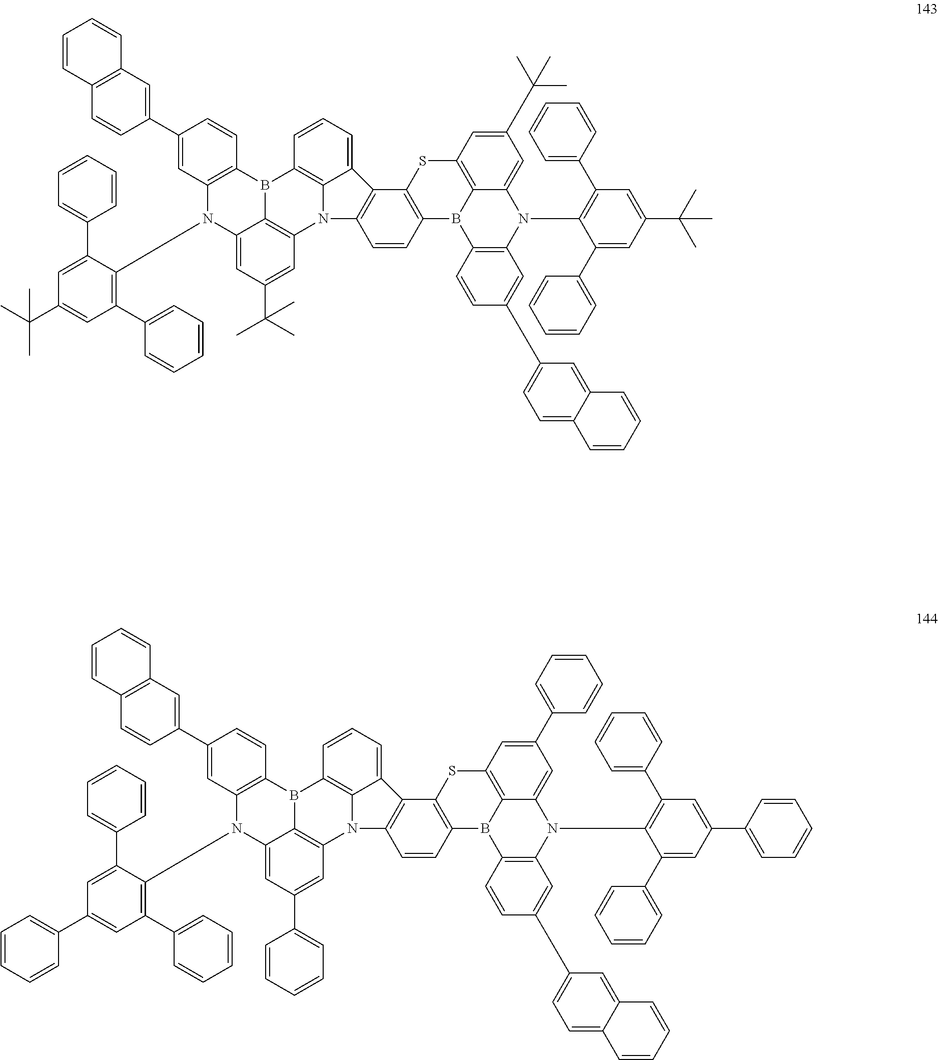 [SMILES: CC(C)(C)c1cc(-c2ccccc2)c(N2c3cc(-c4ccc5ccccc5c4)ccc3B3c4ccc5c(c4Sc4cc(C(C)(C)C)cc2c43)c2cccc3c2n5-c2cc(C(C)(C)C)cc4c2B3c2ccc(-c3ccc5ccccc5c3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccc6ccccc6c5)ccc4B4c5ccc6c(c5Sc5cc(-c7ccccc7)cc3c54)c3cccc4c3n6-c3cc(-c5ccccc5)cc5c3B4c3ccc(-c4ccc6ccccc6c4)cc3N5c3c(-c4ccccc4)cc(-c4ccccc4)cc3-c3ccccc3)c(-c3ccccc3)c2)cc1] 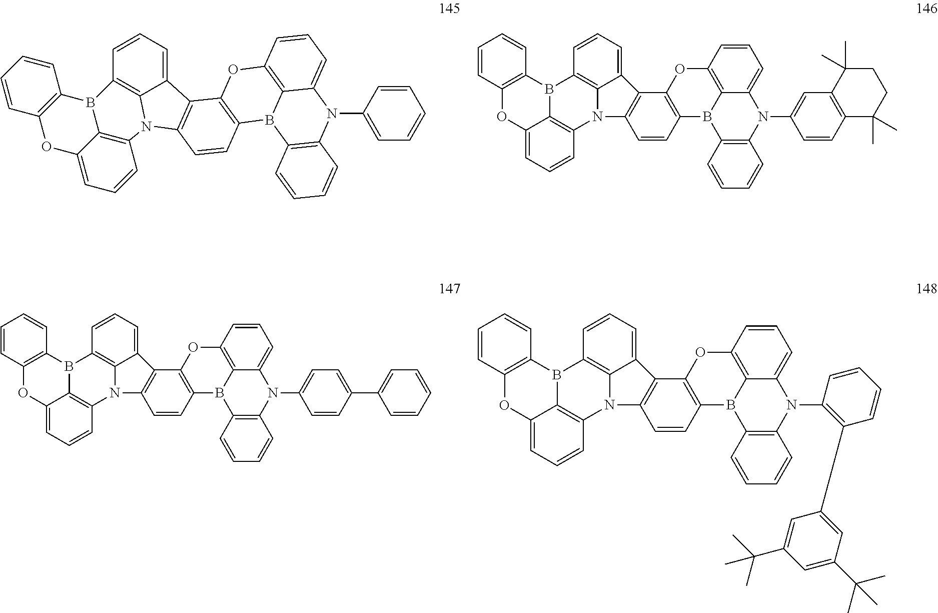 [SMILES: c1ccc(N2c3ccccc3B3c4ccc5c(c4Oc4cccc2c43)c2cccc3c2n5-c2cccc4c2B3c2ccccc2O4)cc1 ; CC1(C)CCC(C)(C)c2cc(N3c4ccccc4B4c5ccc6c(c5Oc5cccc3c54)c3cccc4c3n6-c3cccc5c3B4c3ccccc3O5)ccc21 ; c1ccc(-c2ccc(N3c4ccccc4B4c5ccc6c(c5Oc5cccc3c54)c3cccc4c3n6-c3cccc5c3B4c3ccccc3O5)cc2)cc1 ; CC(C)(C)c1cc(-c2ccccc2N2c3ccccc3B3c4ccc5c(c4Oc4cccc2c43)c2cccc3c2n5-c2cccc4c2B3c2ccccc2O4)cc(C(C)(C)C)c1] 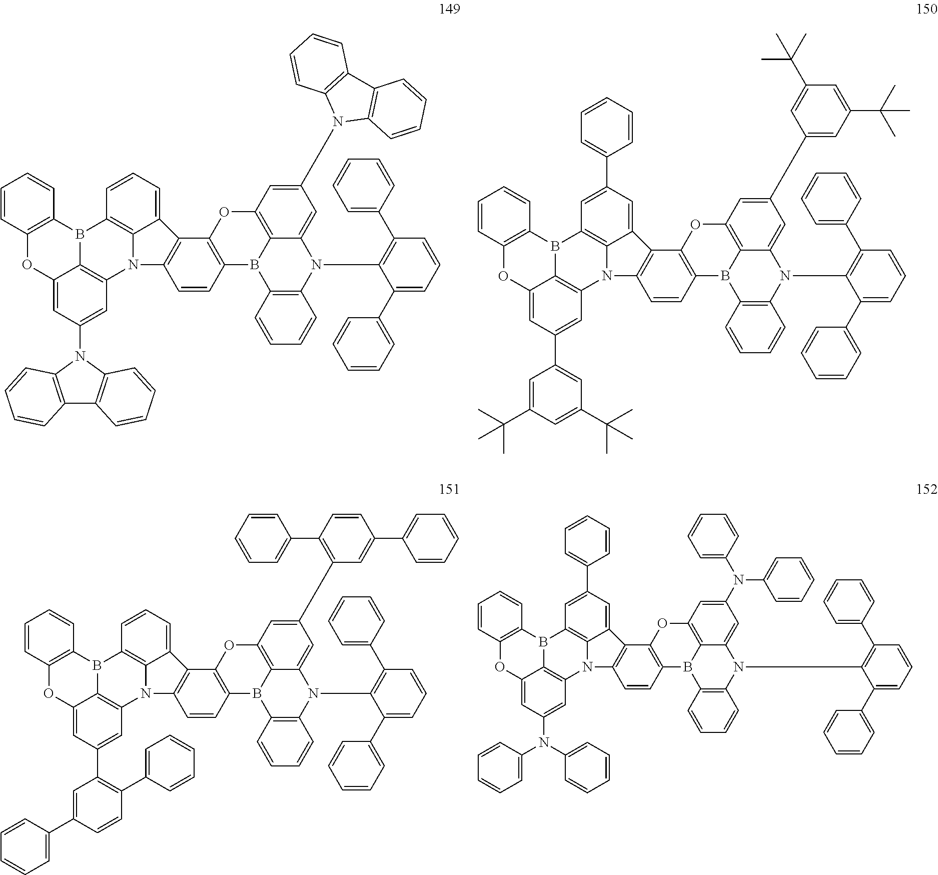 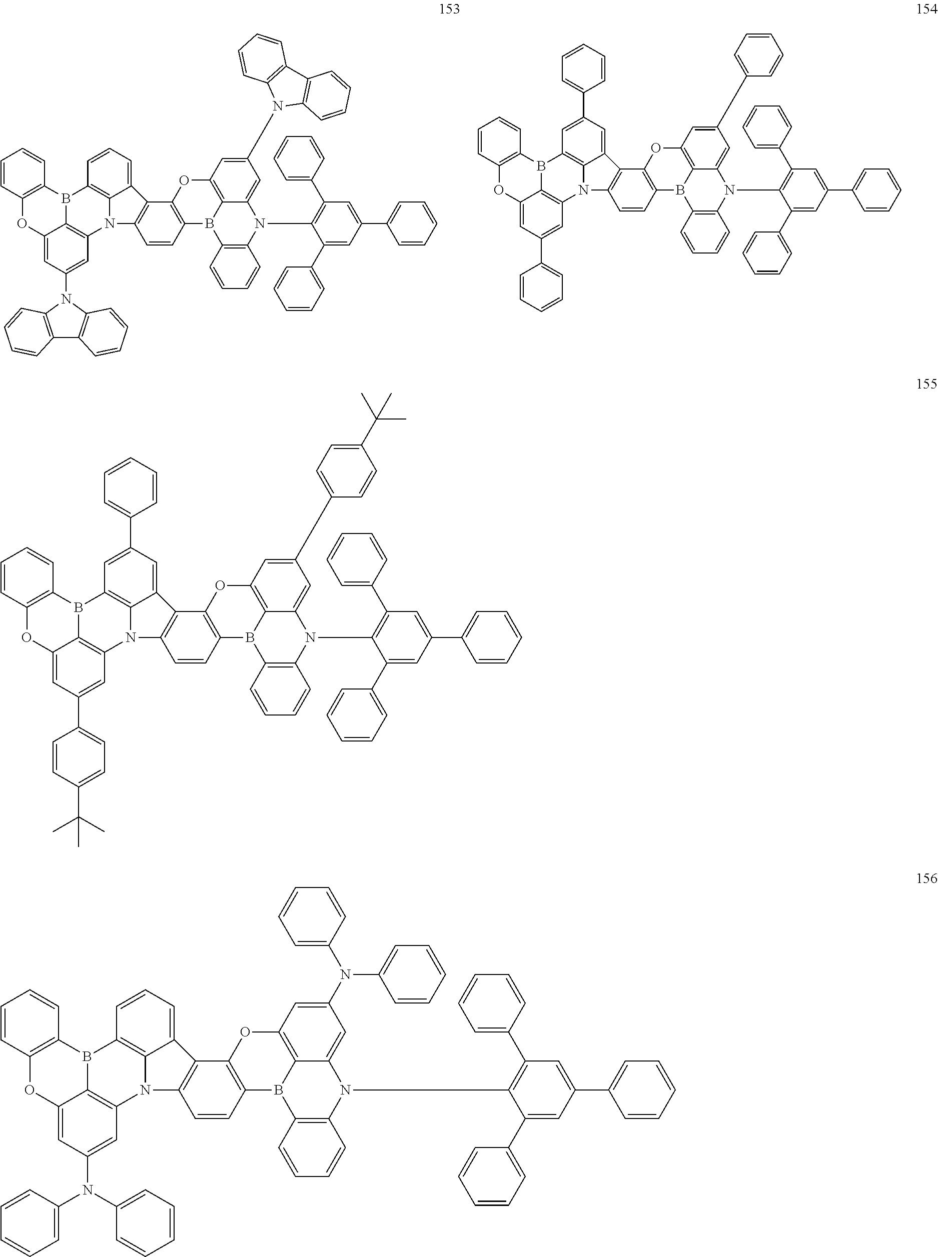 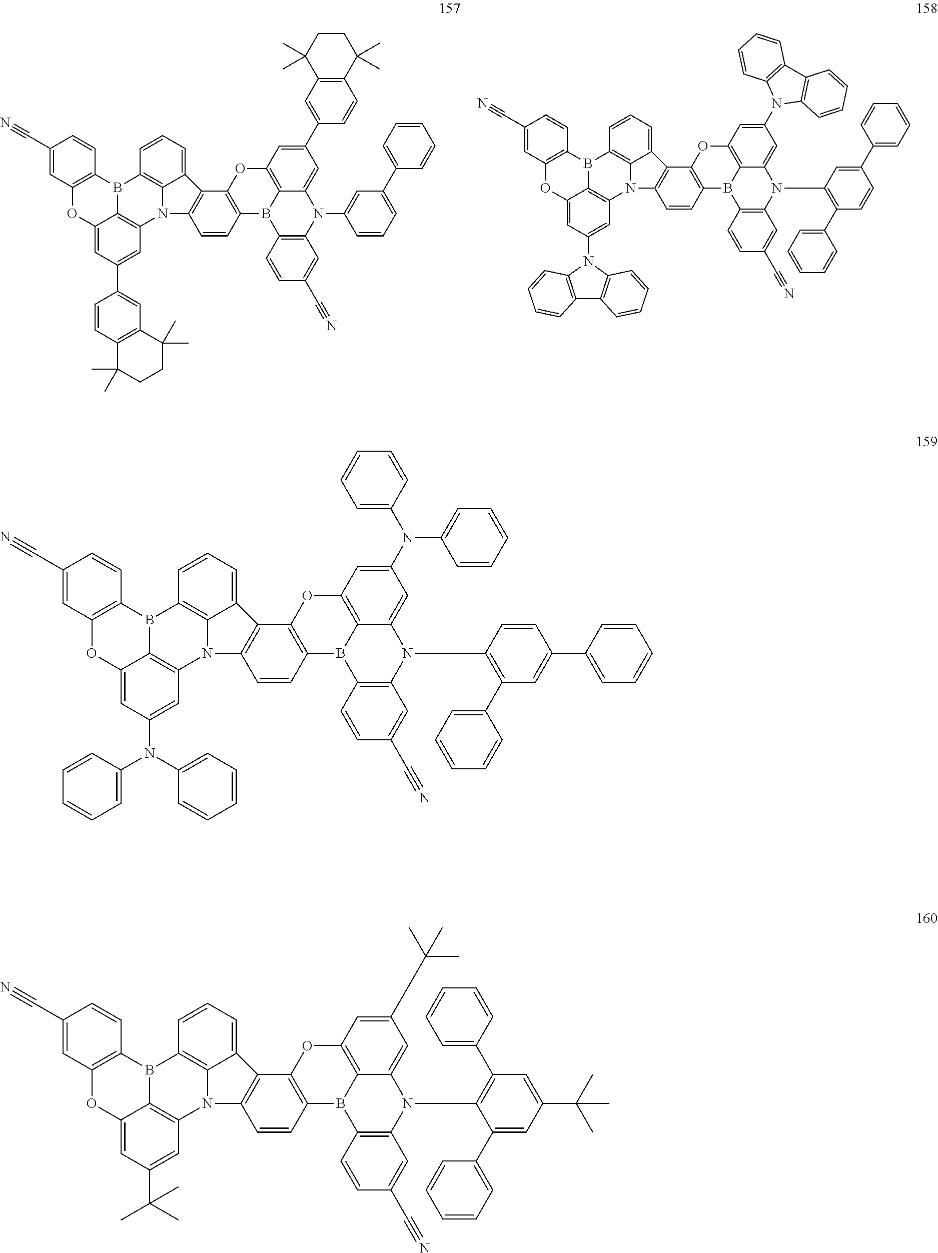 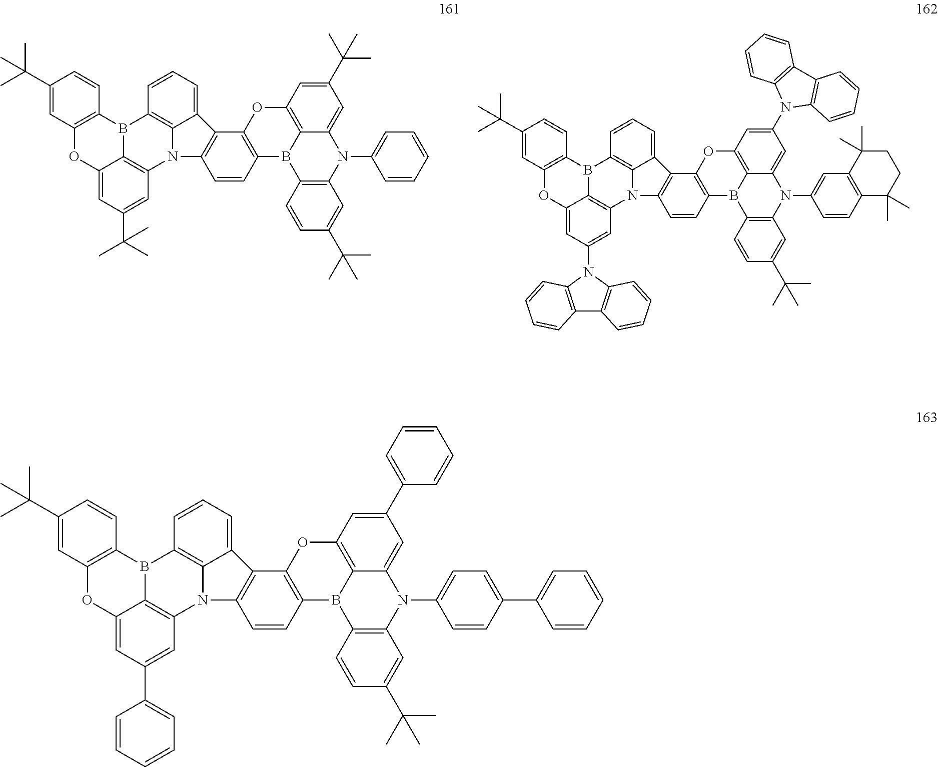 [SMILES: CC(C)(C)c1ccc2c(c1)Oc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)O5 ; CC(C)(C)c1ccc2c(c1)Oc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)O5 ; CC(C)(C)c1ccc2c(c1)Oc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)O5] 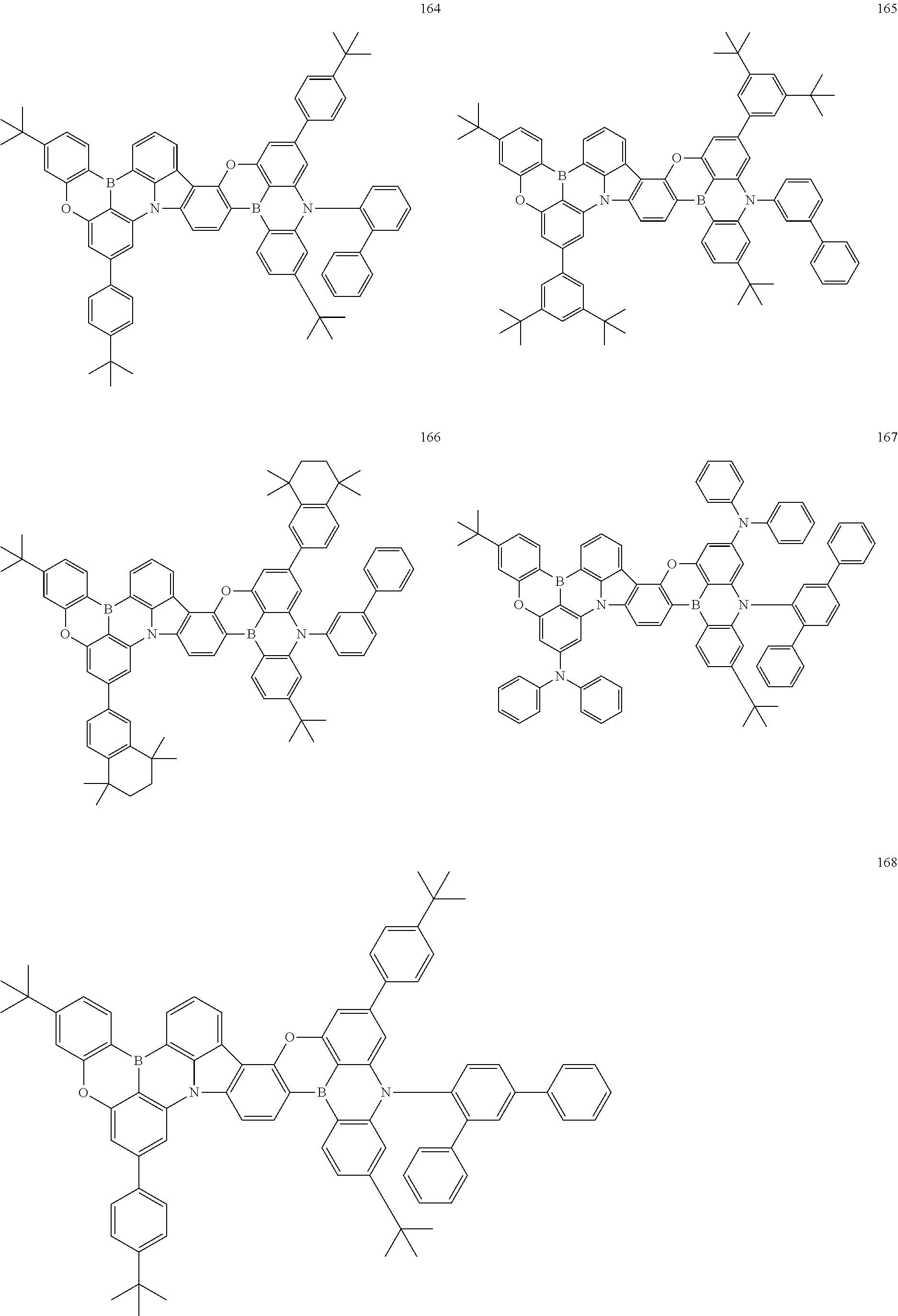 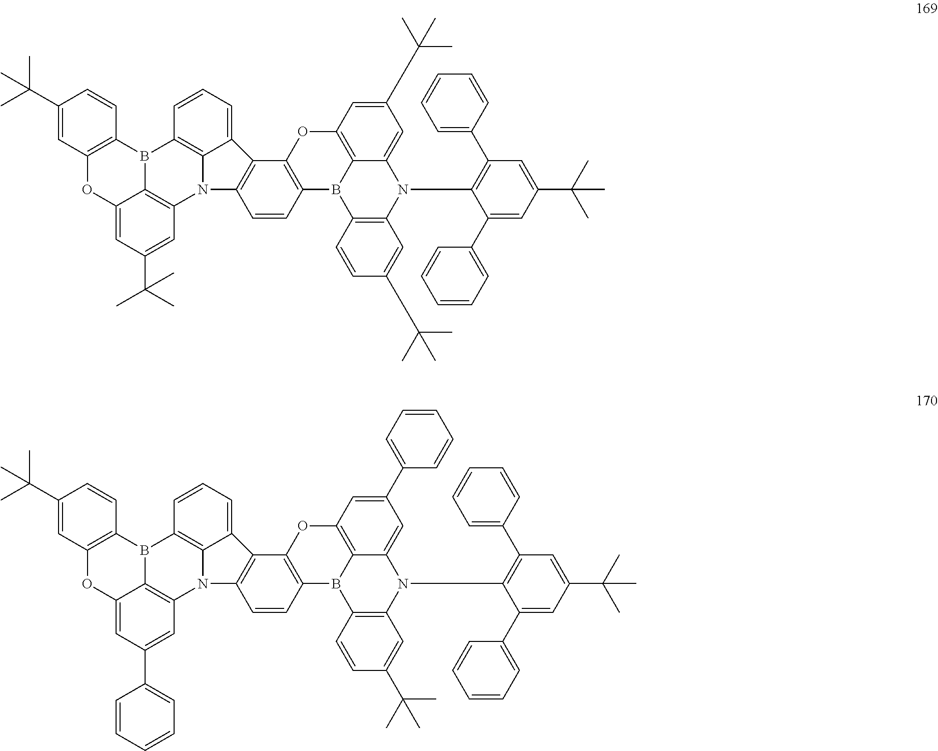 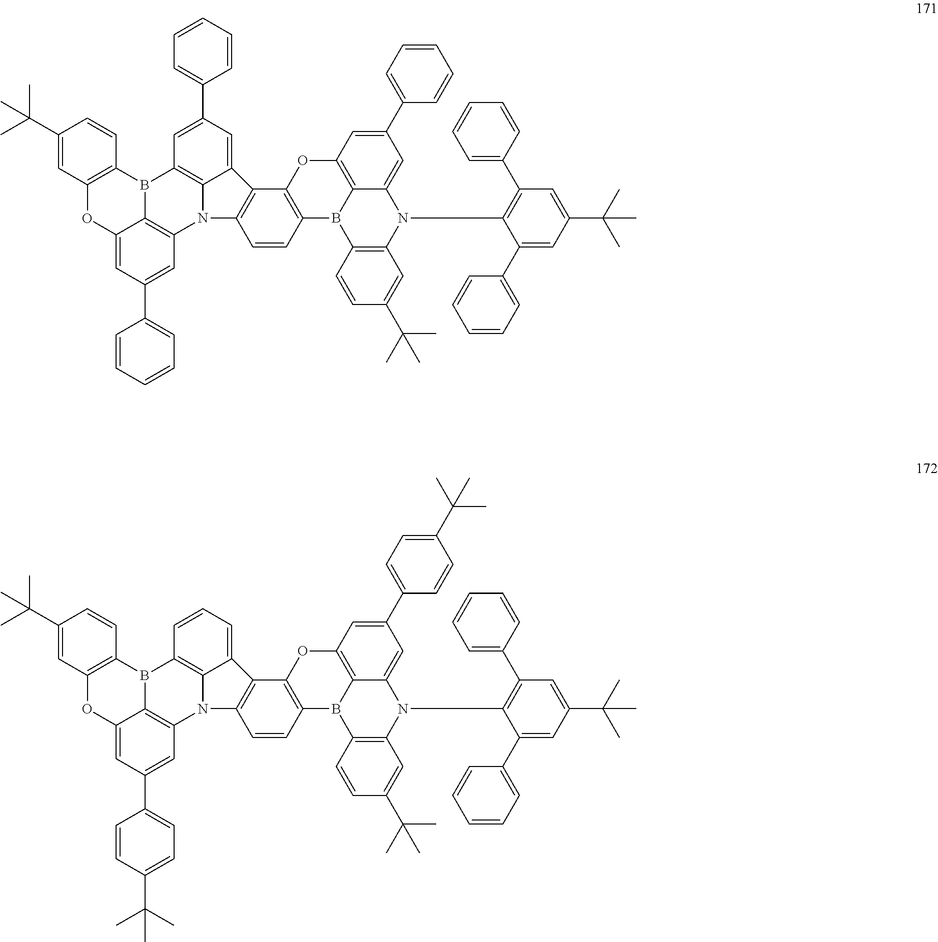 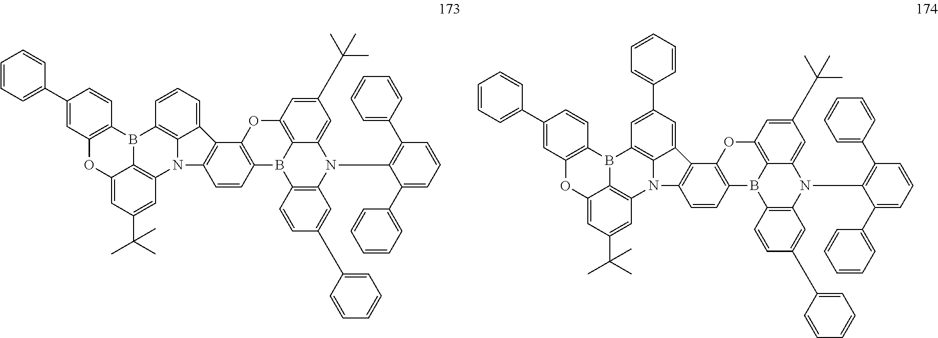 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1O3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1O3] 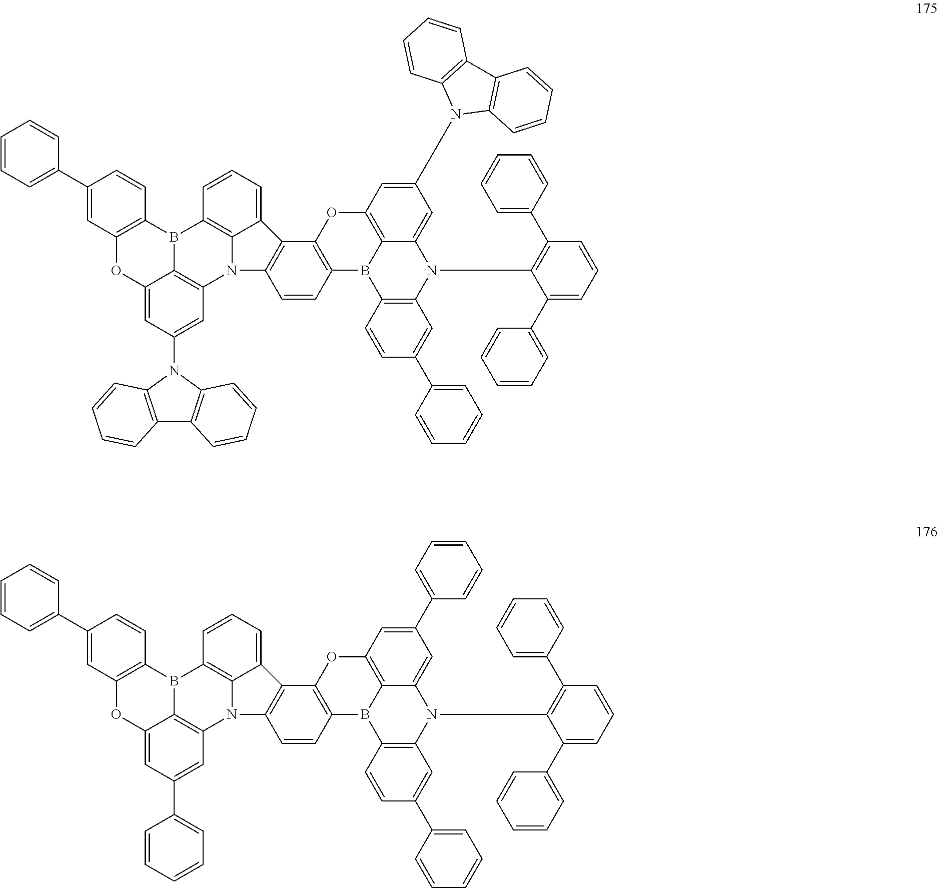 [SMILES: c1ccc(-c2ccc3c(c2)Oc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)O6)cc1 ; c1ccc(-c2ccc3c(c2)Oc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1] 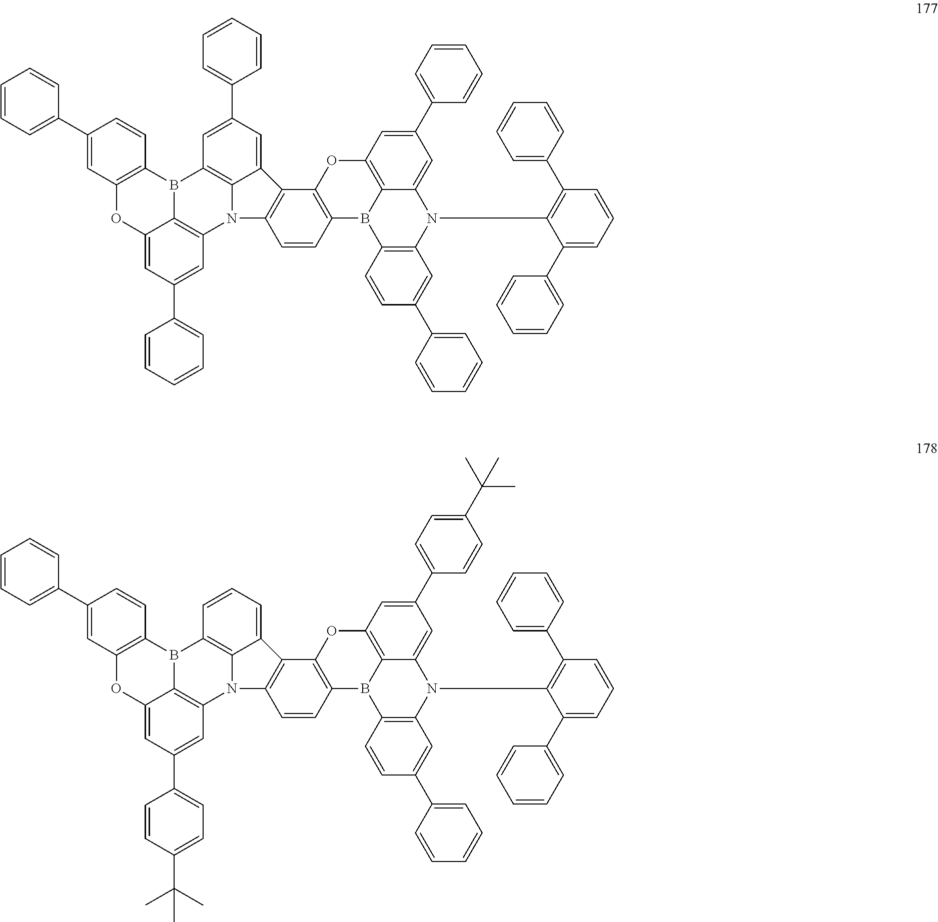 [SMILES: c1ccc(-c2ccc3c(c2)Oc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2O4)cc1] 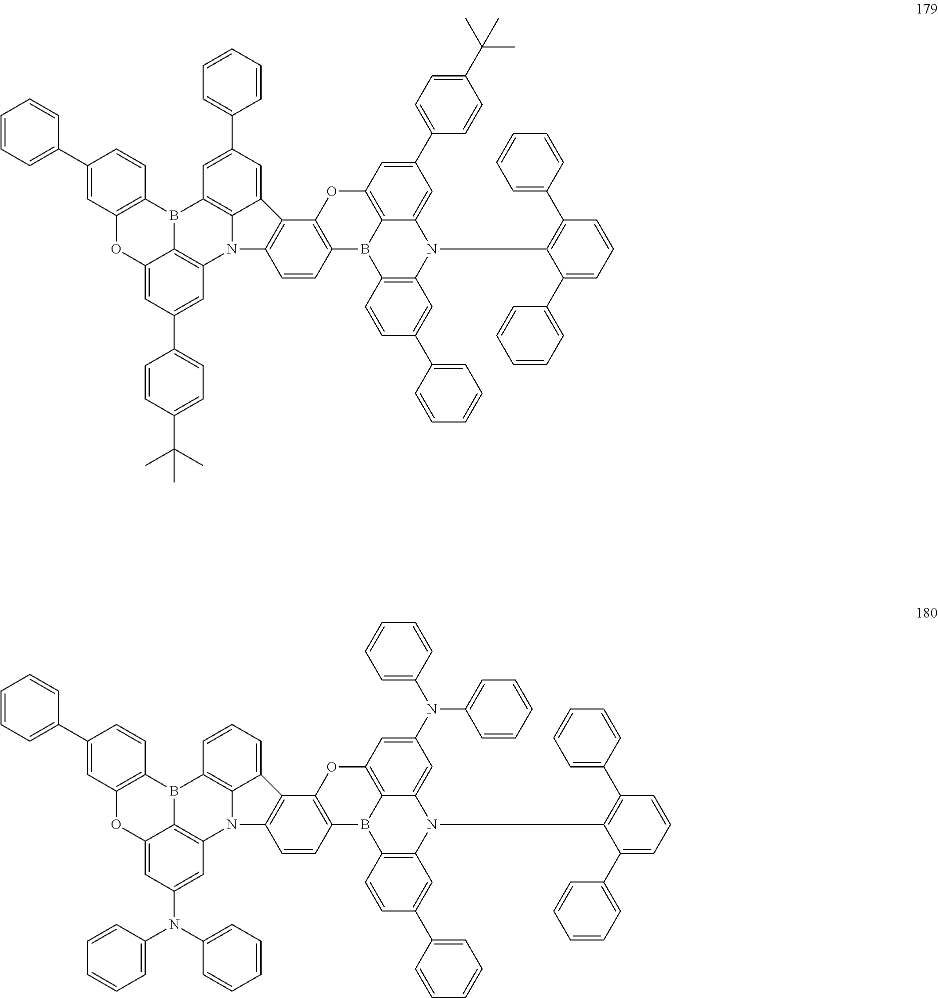 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2O4)cc1 ; c1ccc(-c2ccc3c(c2)Oc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 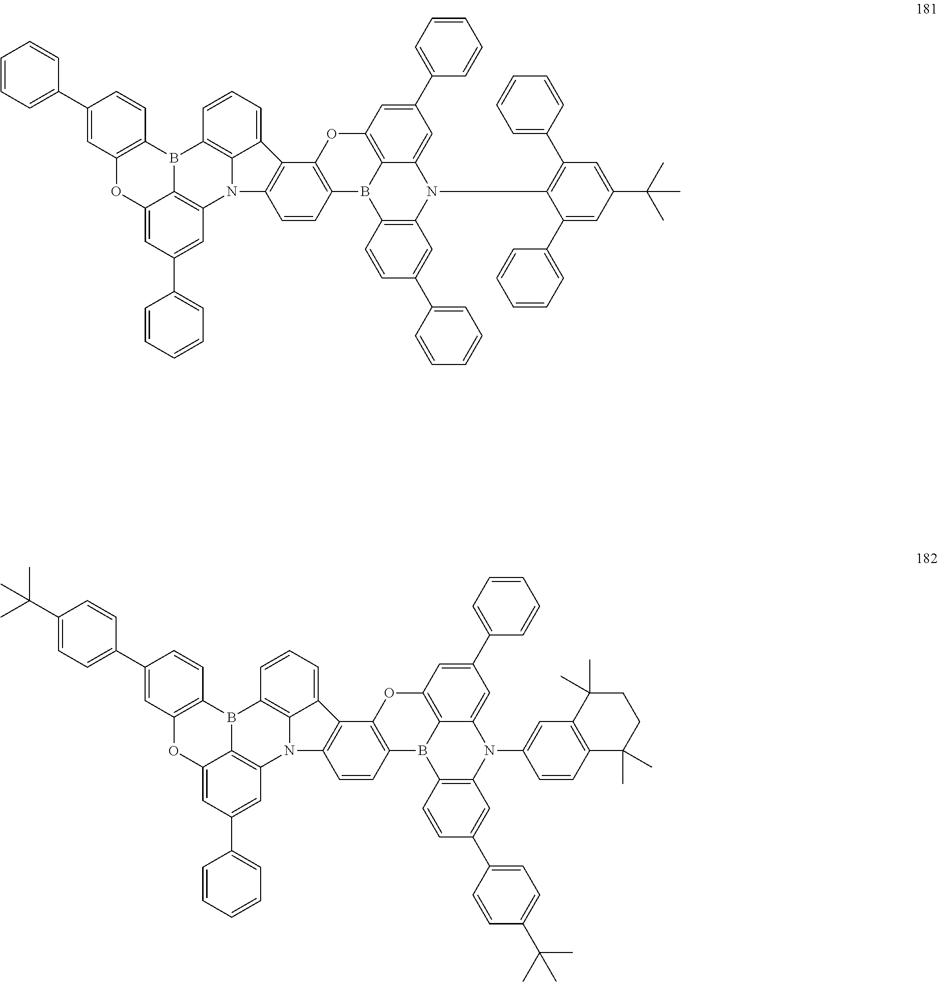 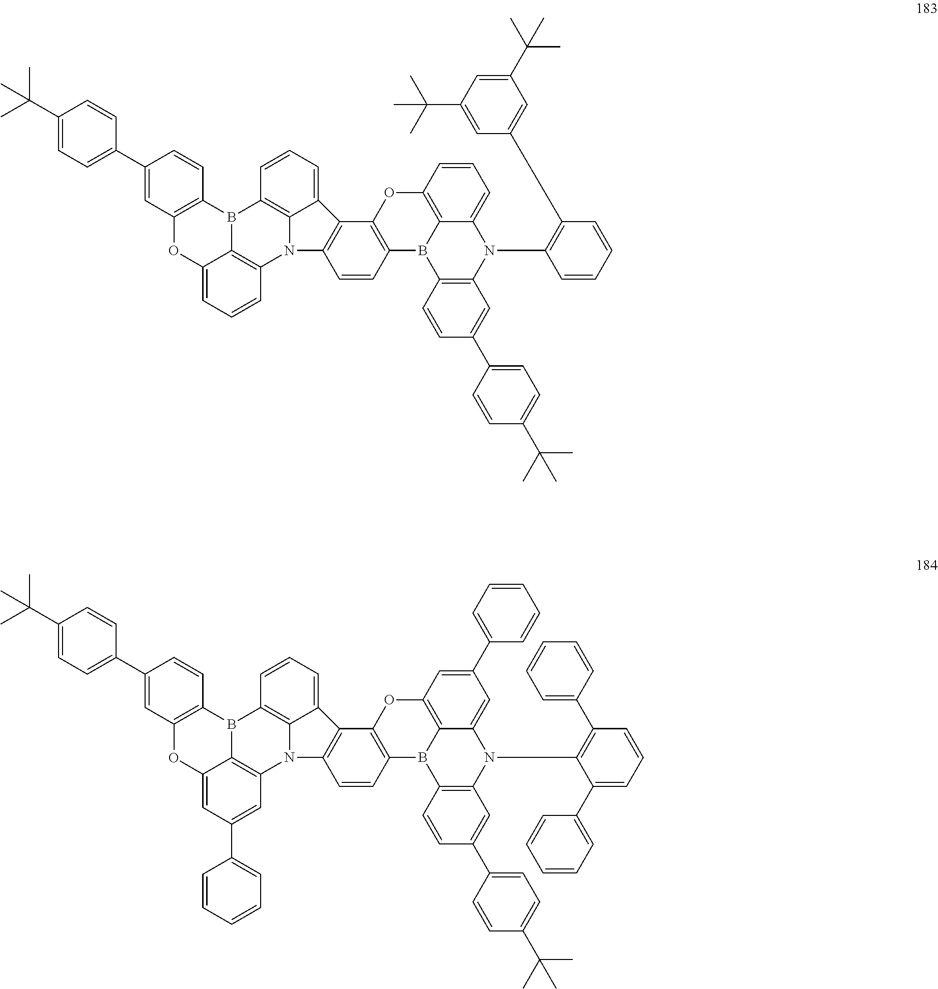 [SMILES: CC(C)(C)c1ccc(-c2ccc3c(c2)Oc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)O6)cc1 ; CC(C)(C)c1ccc(-c2ccc3c(c2)Oc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)O6)cc1] 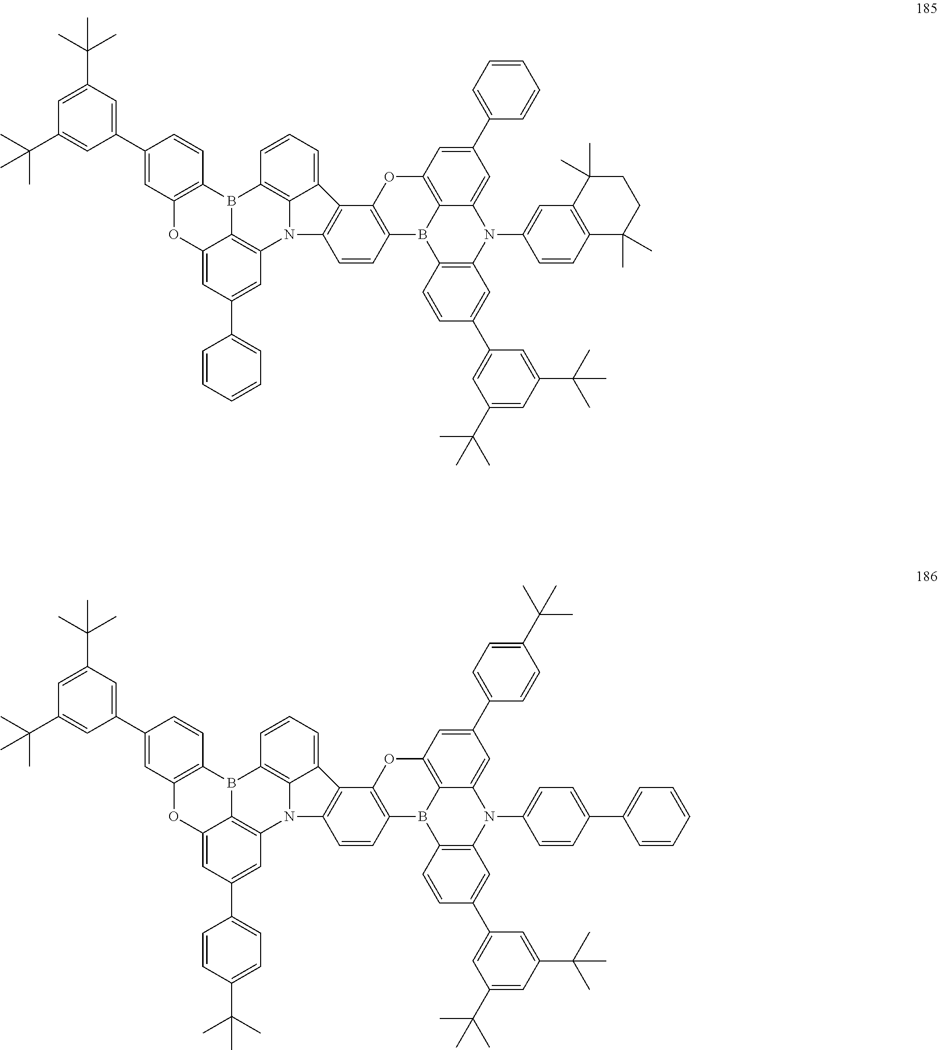 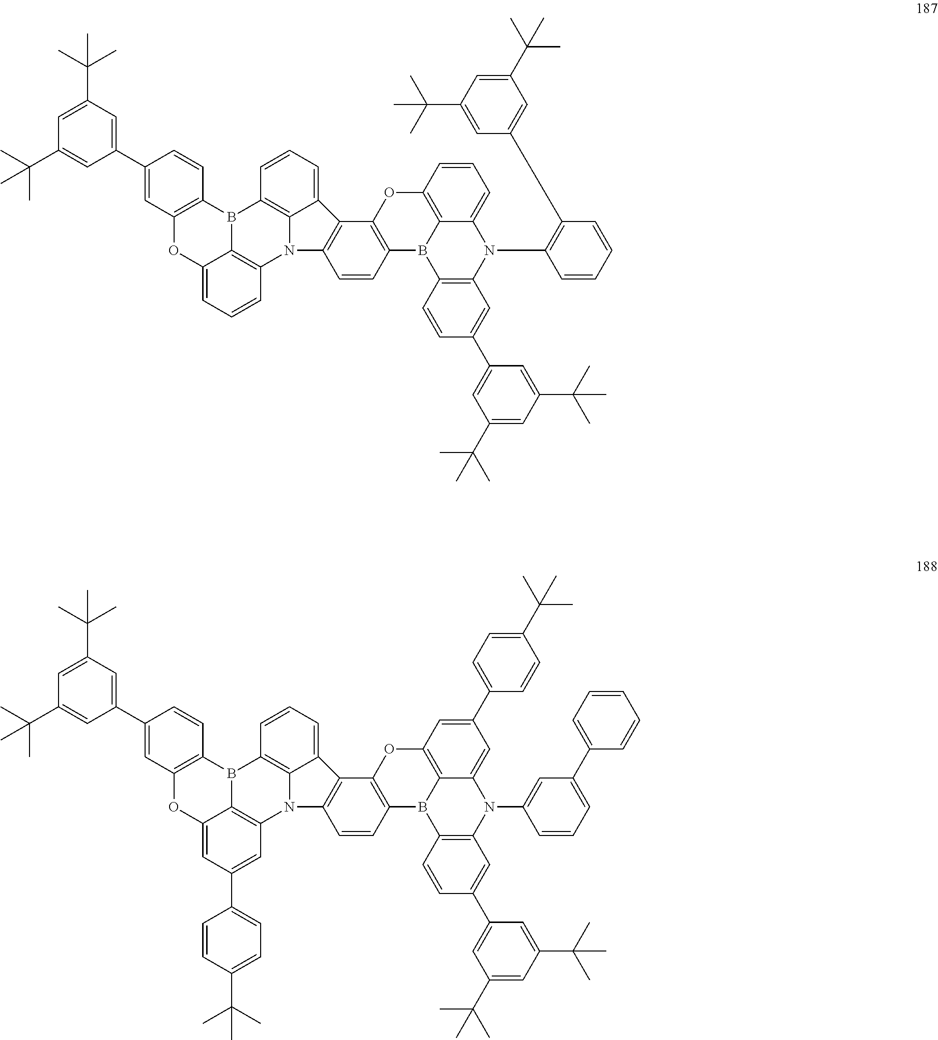 [SMILES: CC(C)(C)c1cc(-c2ccc3c(c2)Oc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)O6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2O4)cc1] 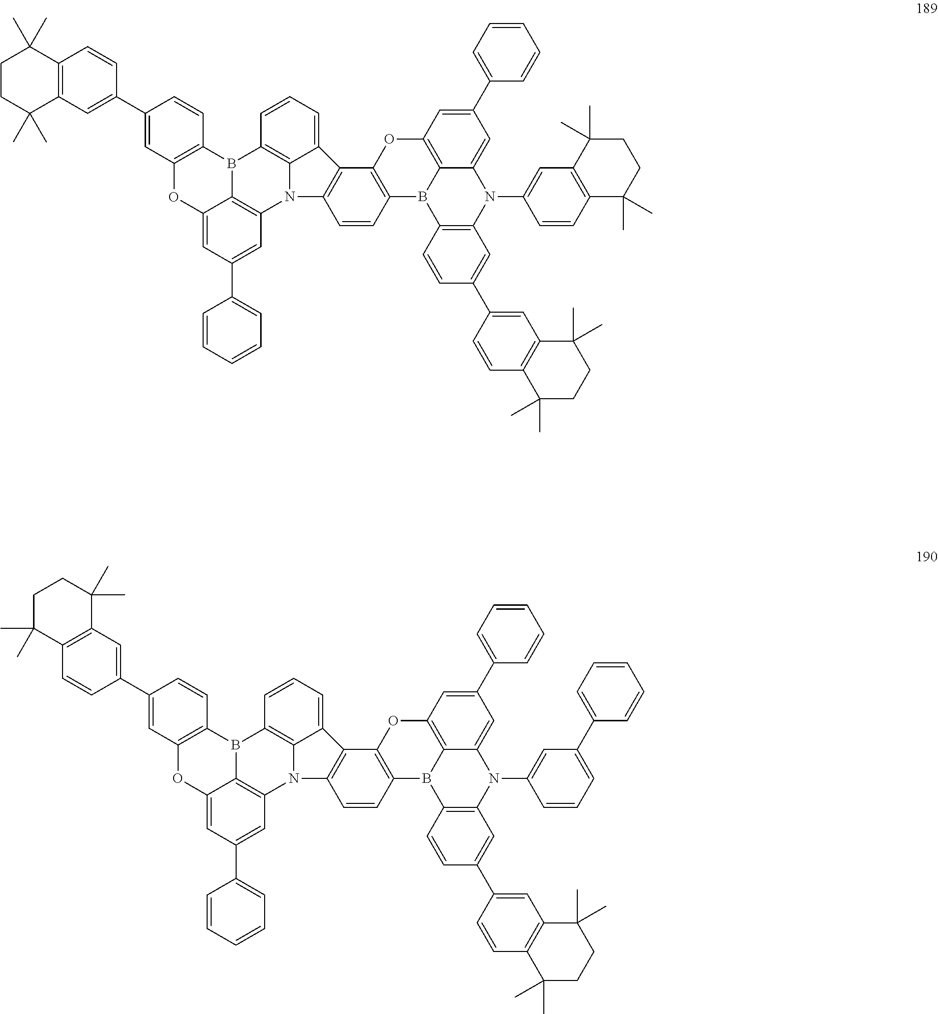 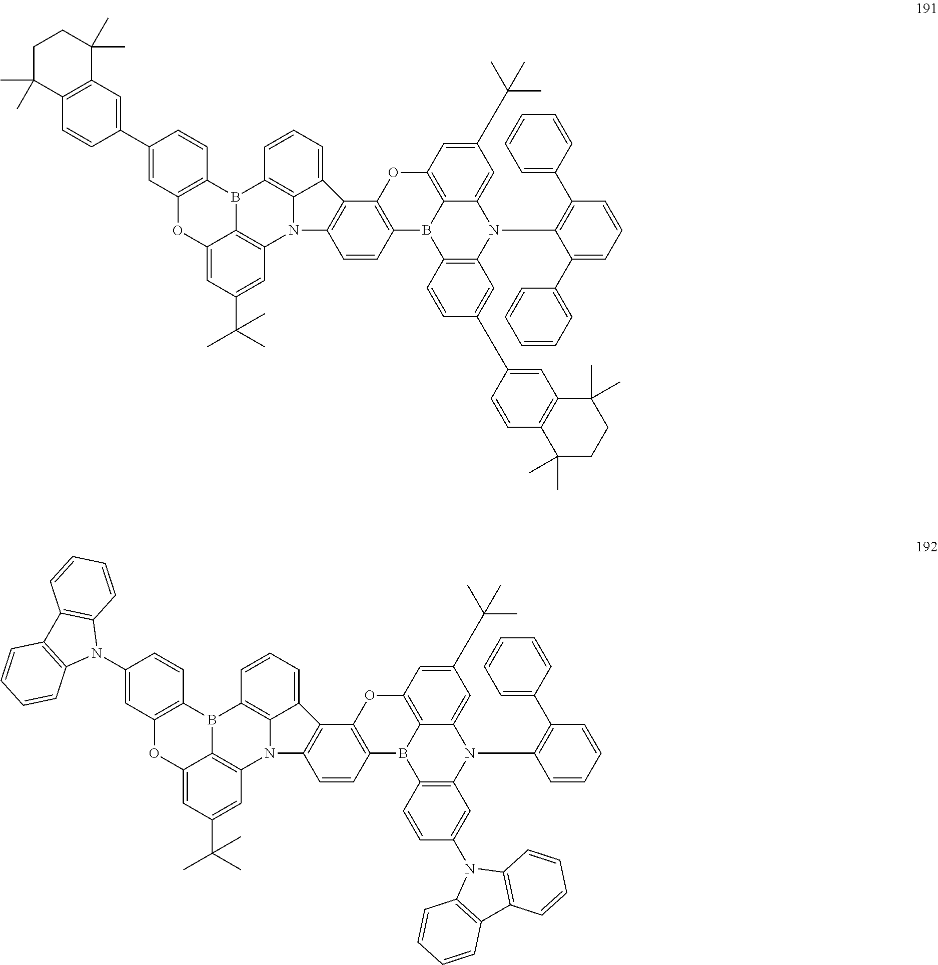 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1O3 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 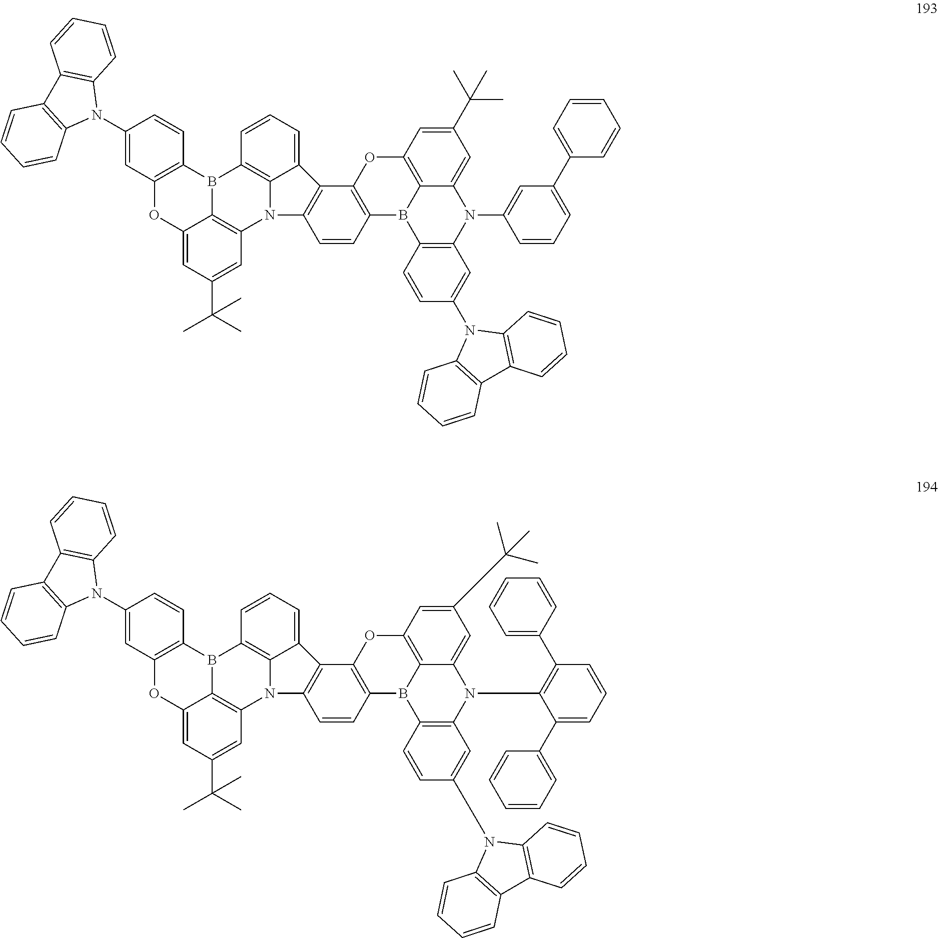 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 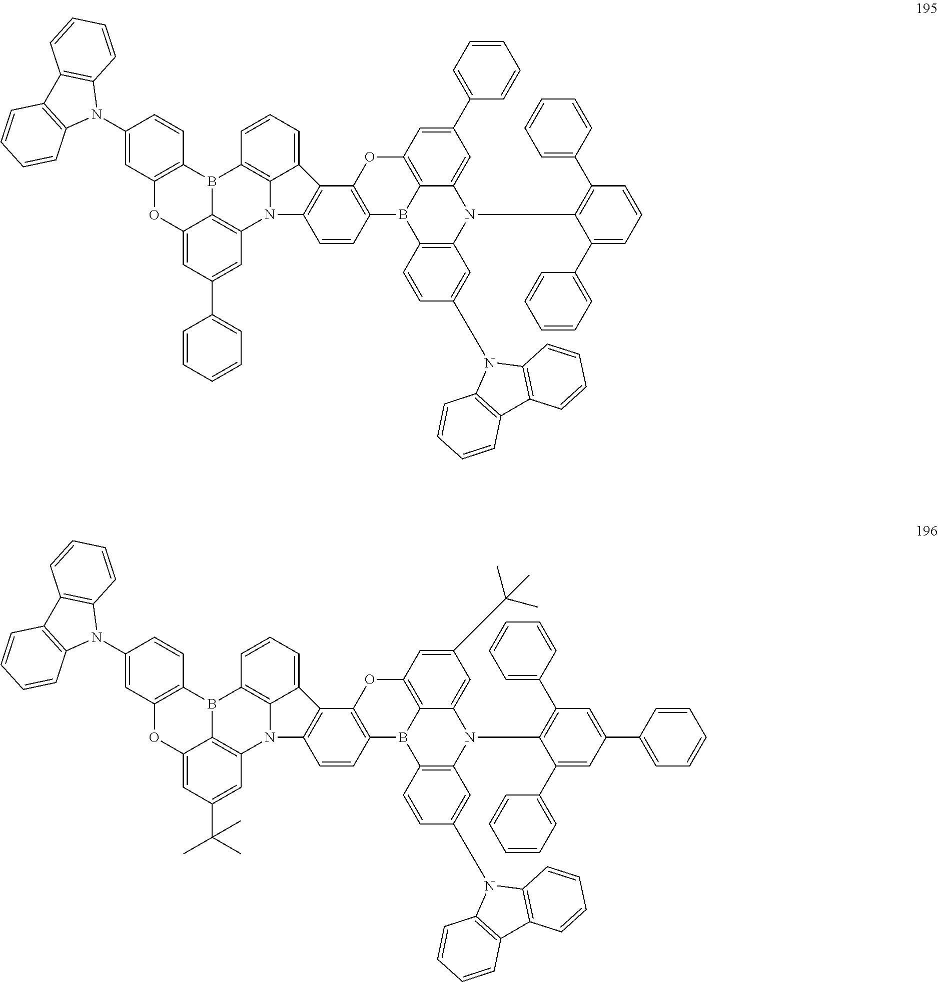 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2O4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 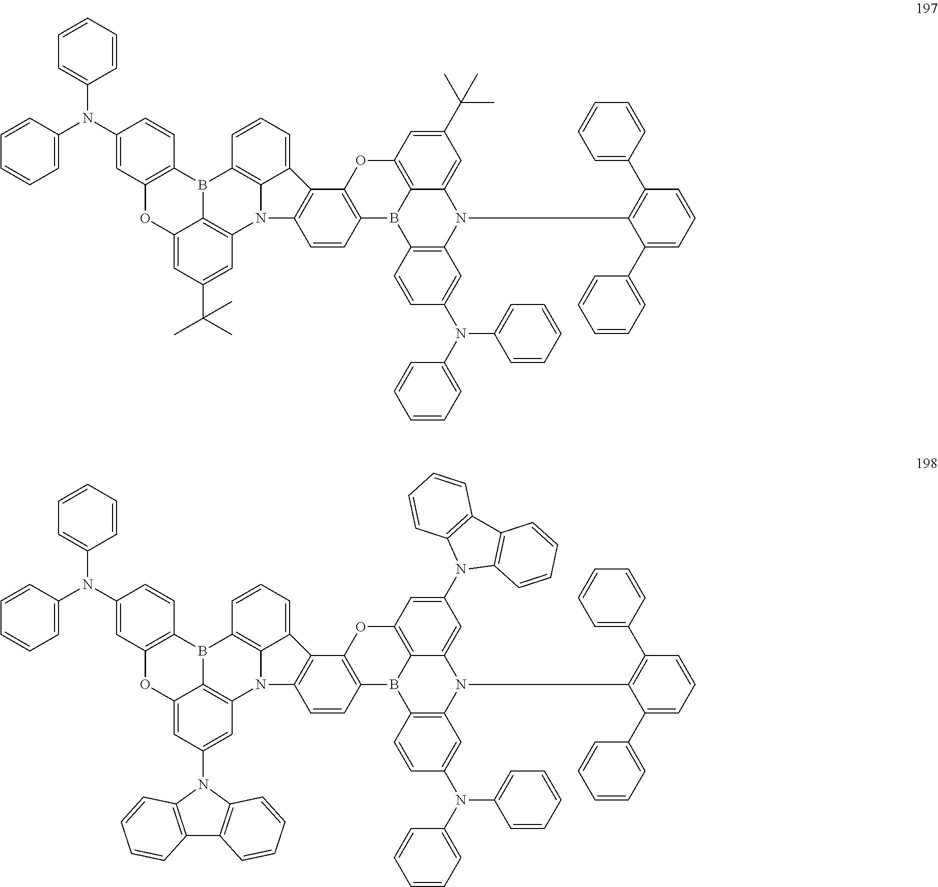 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1O3 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2O4)cc1] 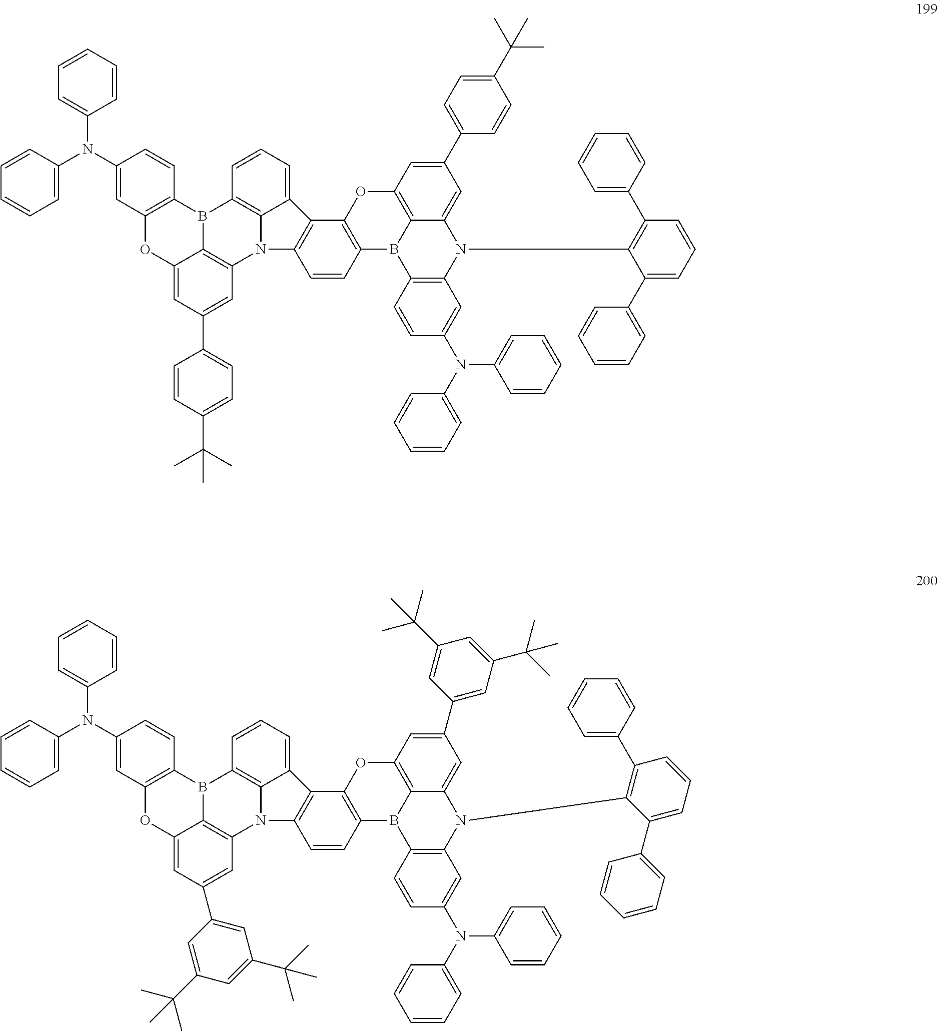 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2O4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2O4)cc(C(C)(C)C)c1] 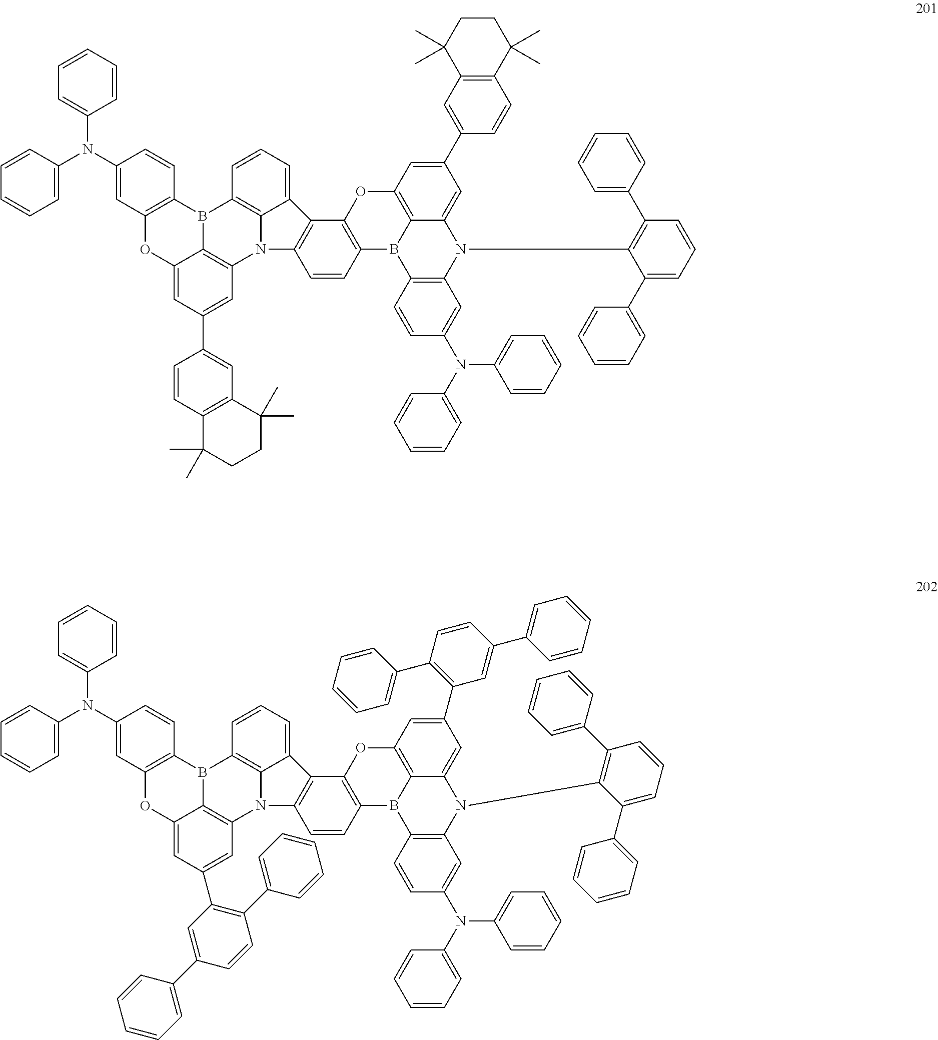 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3O5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3O5)c2)cc1] 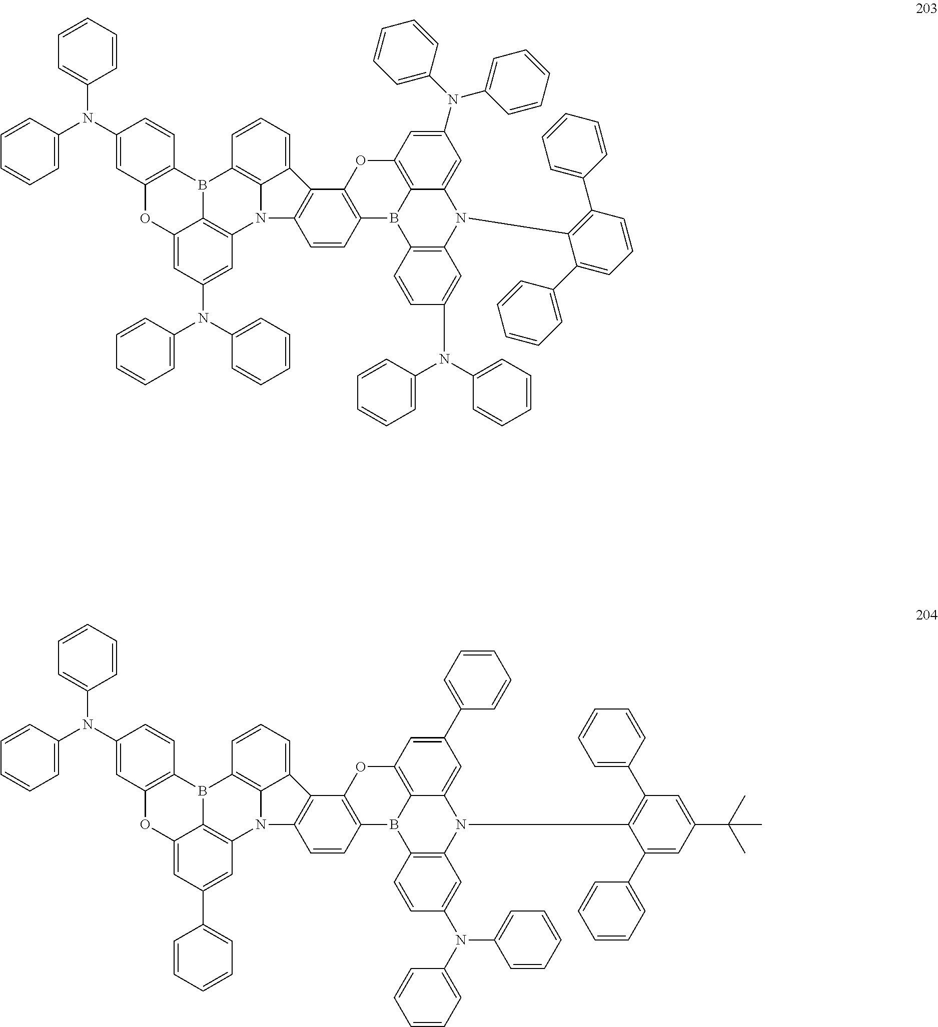 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2O4)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2O4)c(-c2ccccc2)c1] 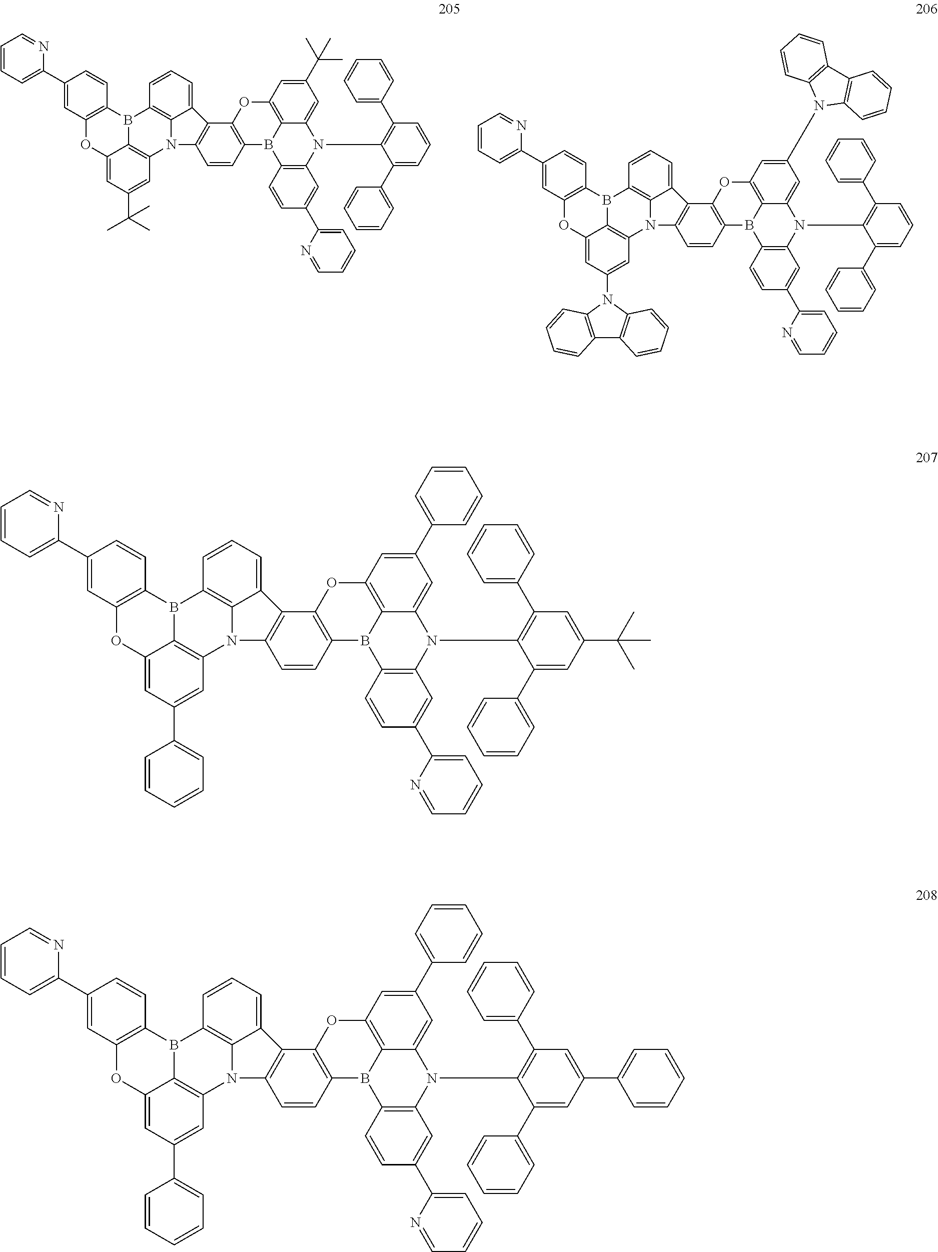 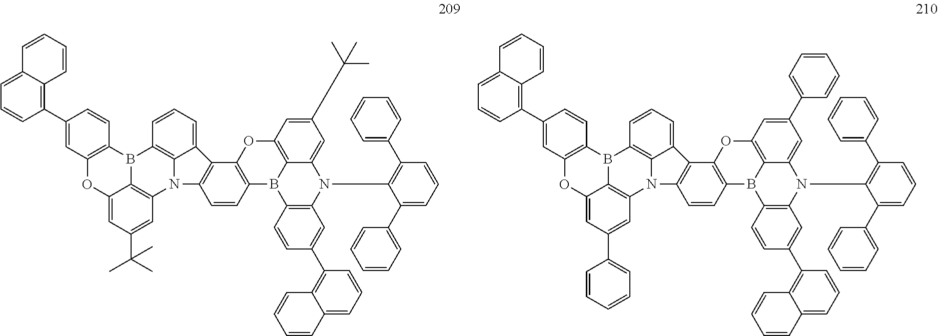 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1O3 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2O4)cc1] 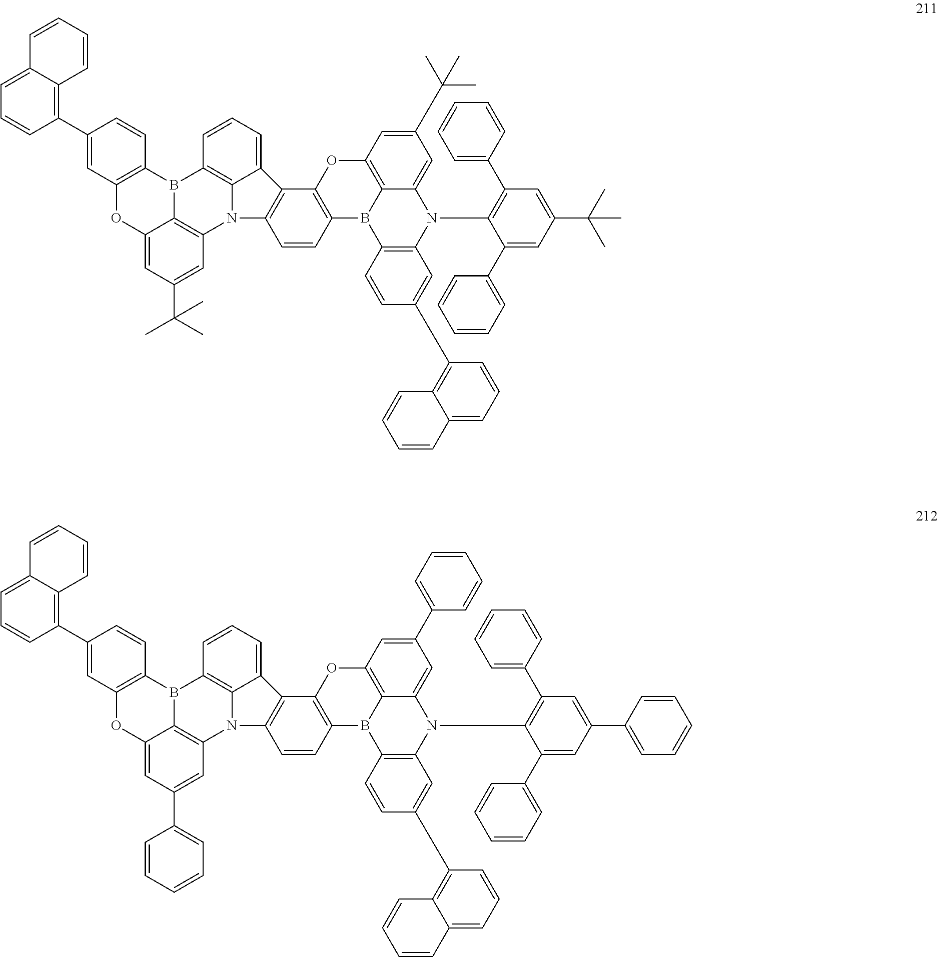 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2O4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3O5)c(-c3ccccc3)c2)cc1] 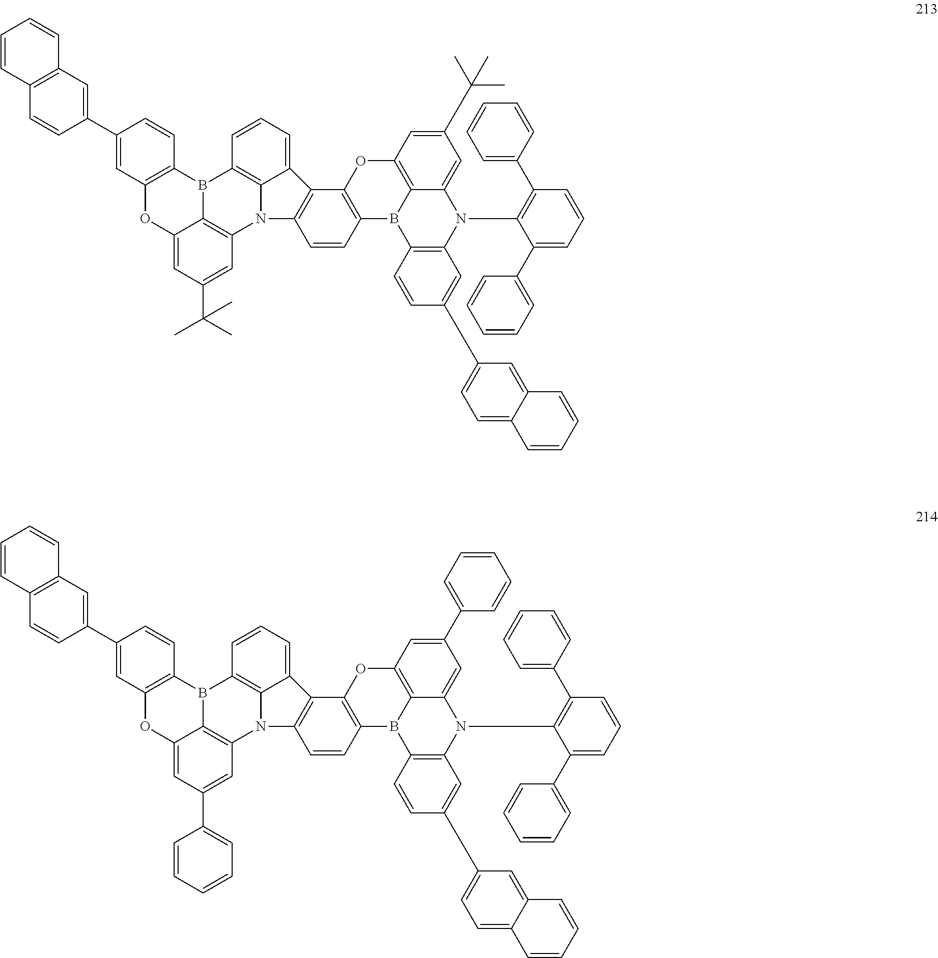 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1O3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2O4)cc1] 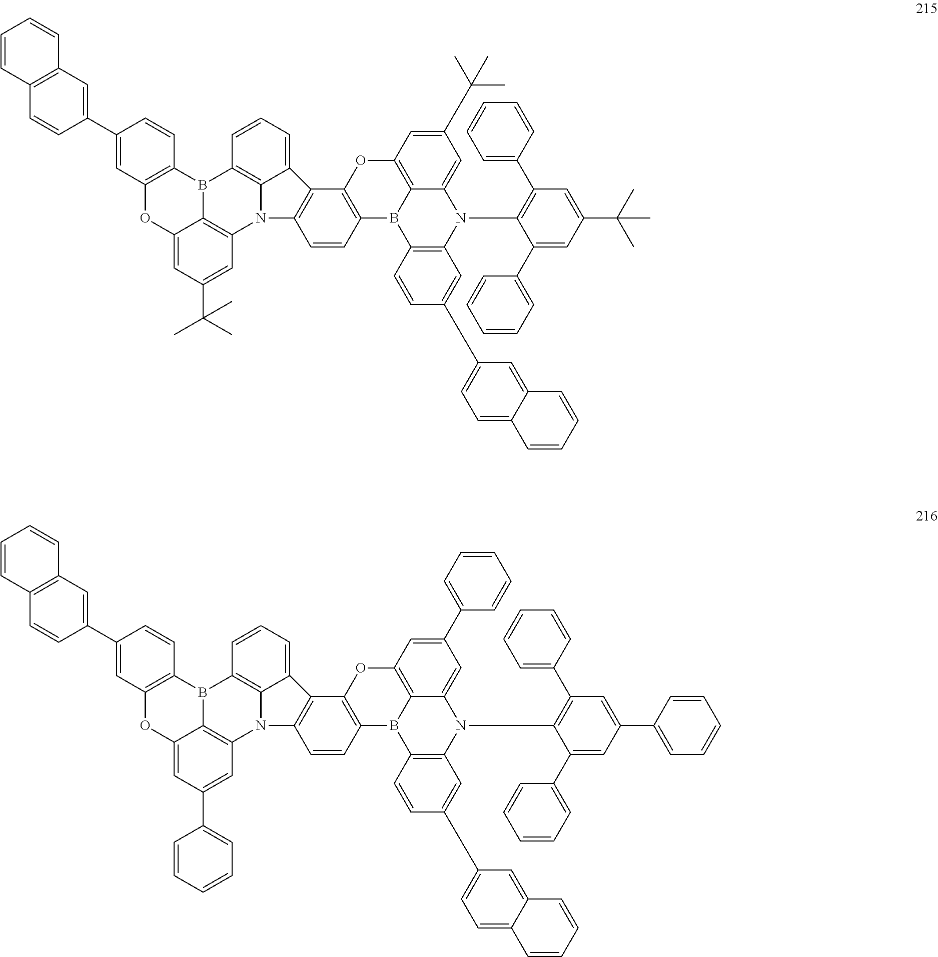 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2O4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3O5)c(-c3ccccc3)c2)cc1] 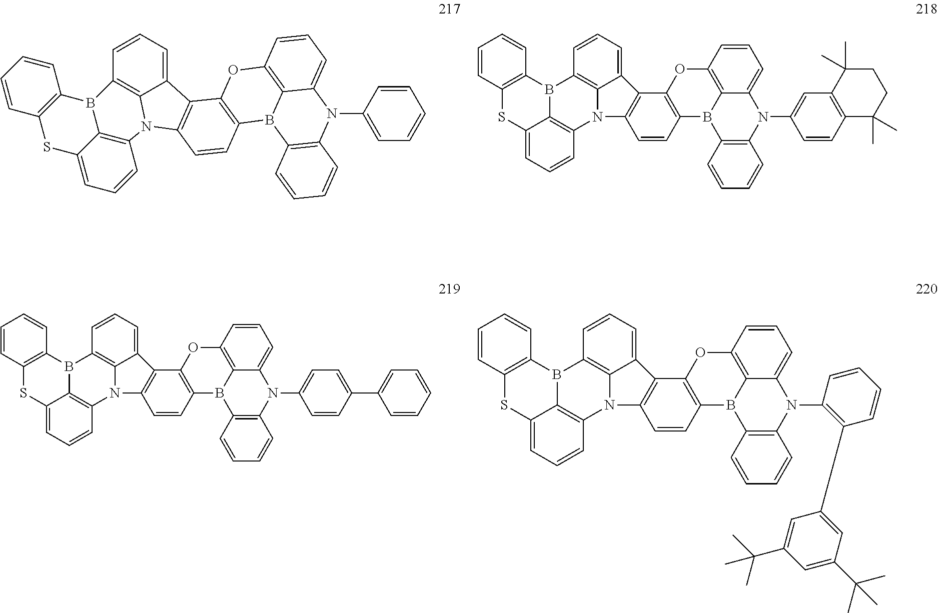 [SMILES: c1ccc(N2c3ccccc3B3c4ccc5c(c4Oc4cccc2c43)c2cccc3c2n5-c2cccc4c2B3c2ccccc2S4)cc1 ; CC1(C)CCC(C)(C)c2cc(N3c4ccccc4B4c5ccc6c(c5Oc5cccc3c54)c3cccc4c3n6-c3cccc5c3B4c3ccccc3S5)ccc21 ; c1ccc(-c2ccc(N3c4ccccc4B4c5ccc6c(c5Oc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Oc4cccc2c43)c2cccc3c2n5-c2cccc4c2B3c2ccccc2S4)cc(C(C)(C)C)c1] 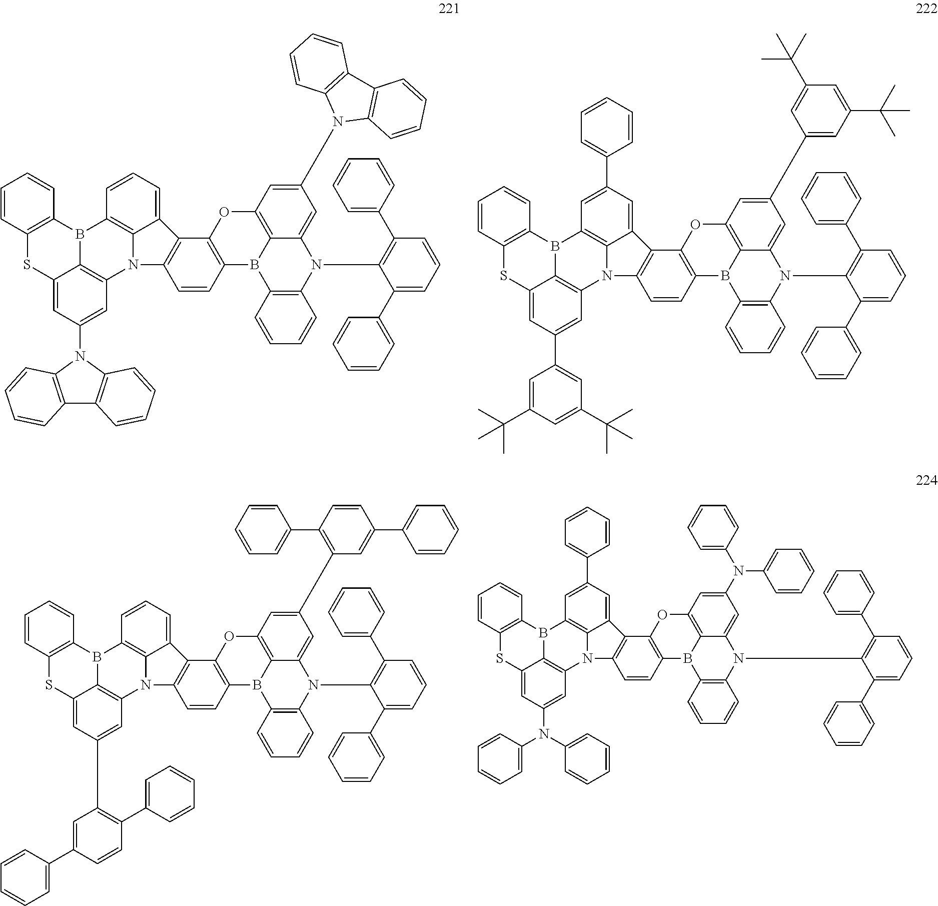 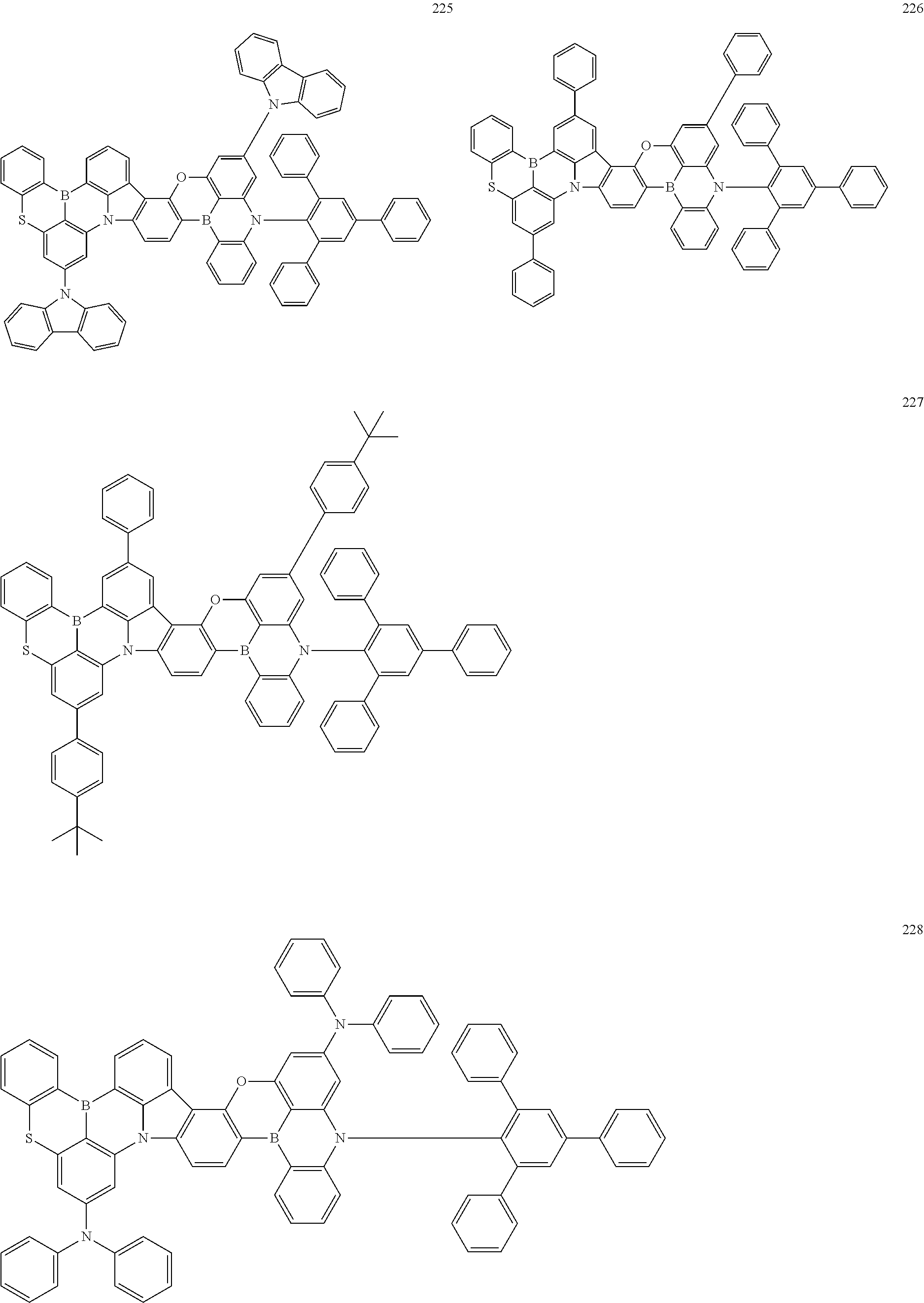 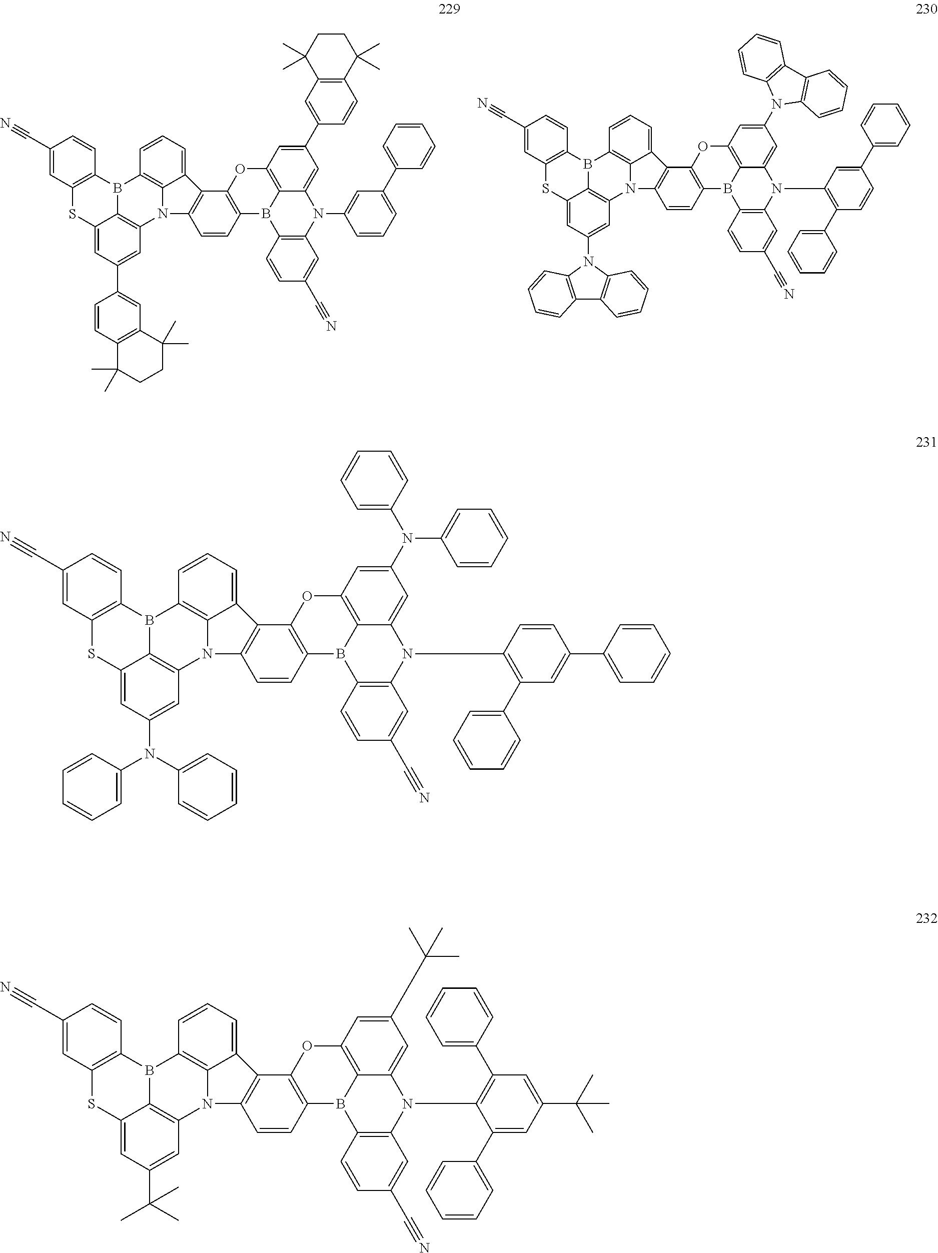 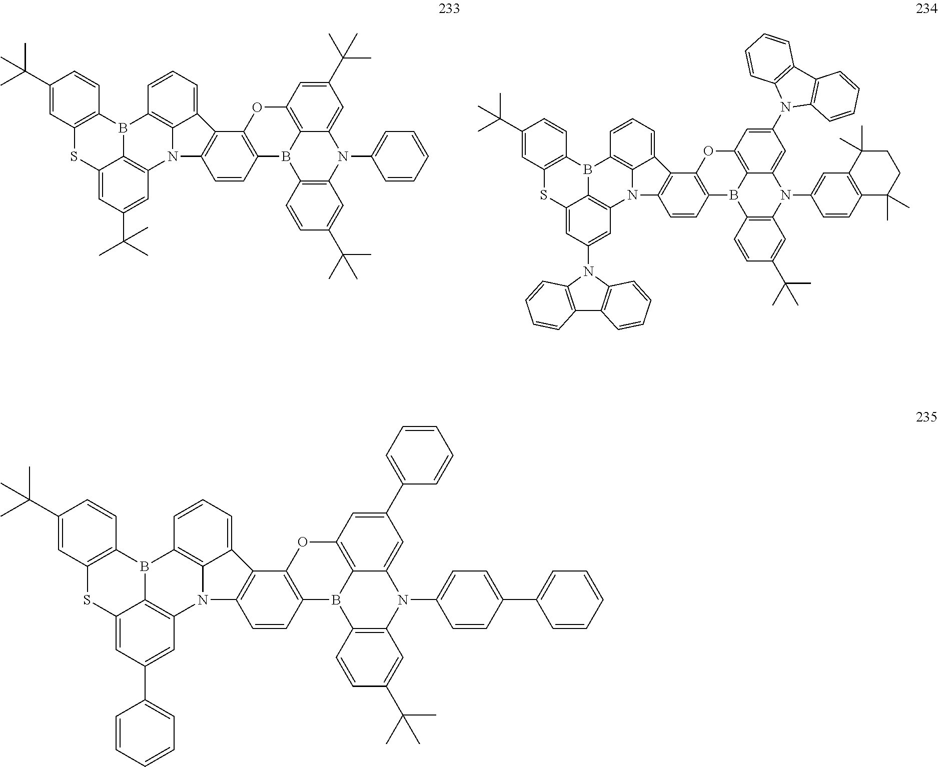 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)O5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)O5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)O5] 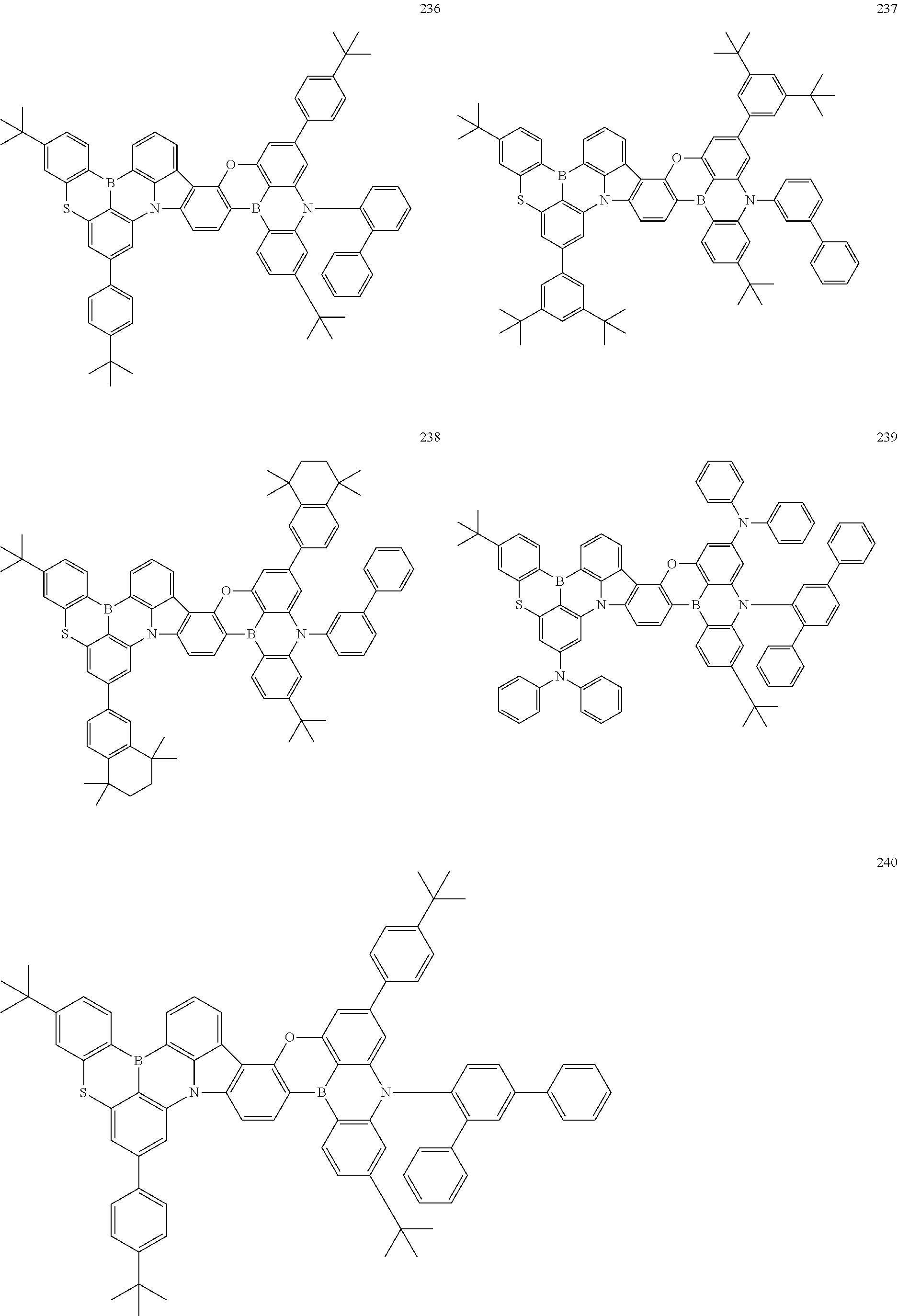 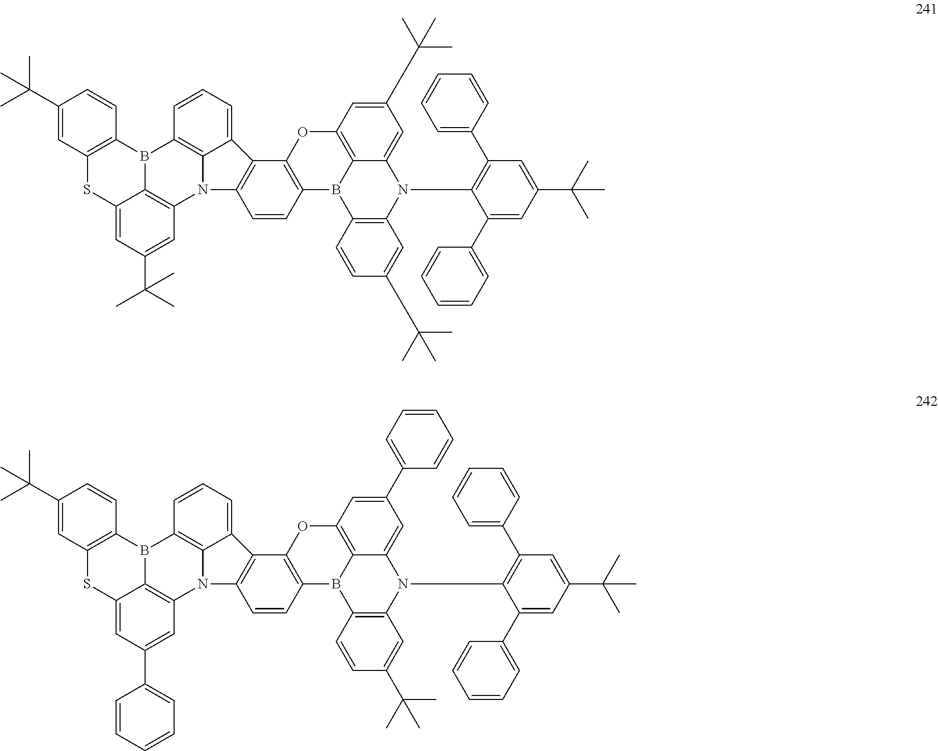 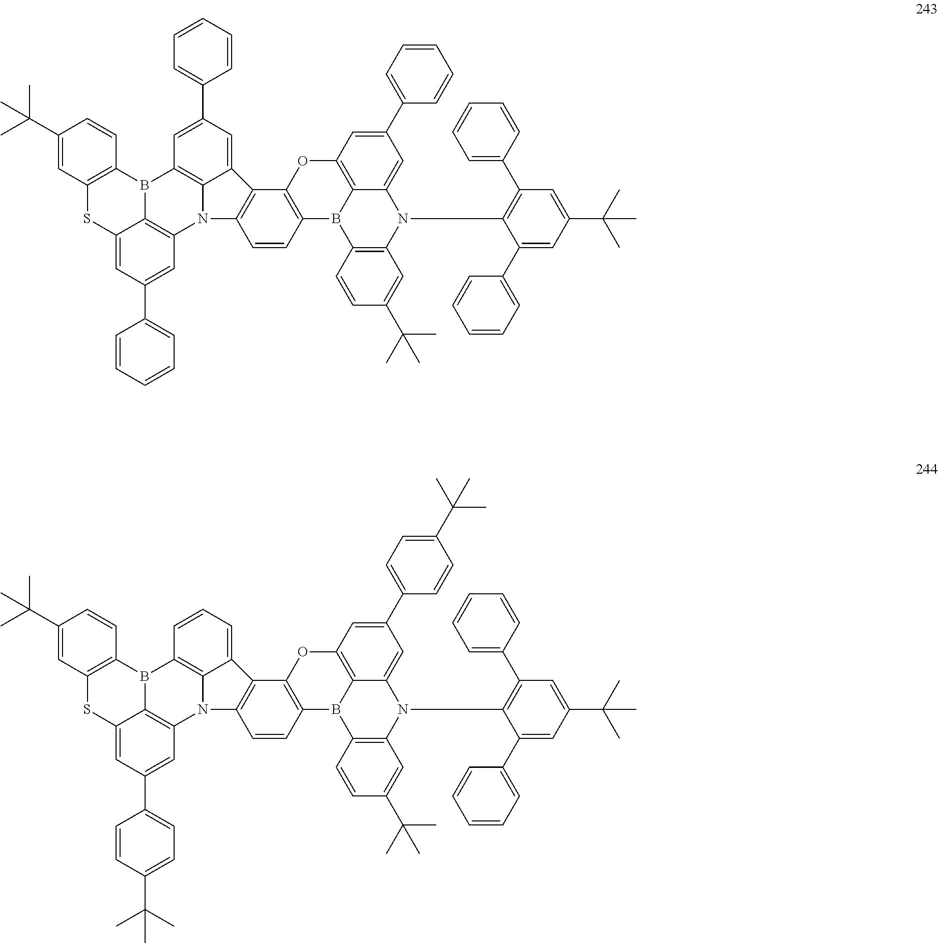 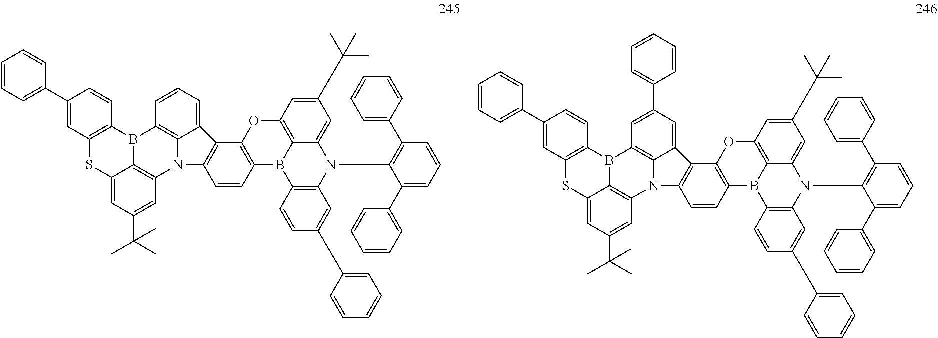 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1S3] 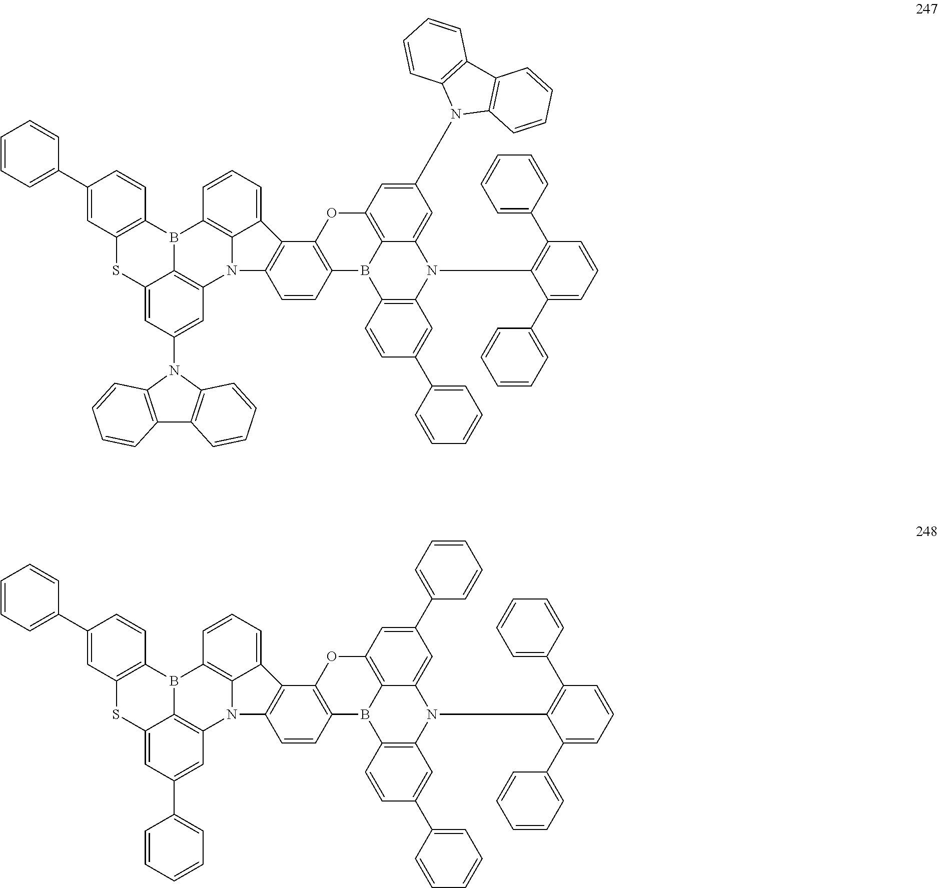 [SMILES: c1ccc(-c2ccc3c(c2)Sc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)O6)cc1 ; c1ccc(-c2ccc3c(c2)Sc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1] 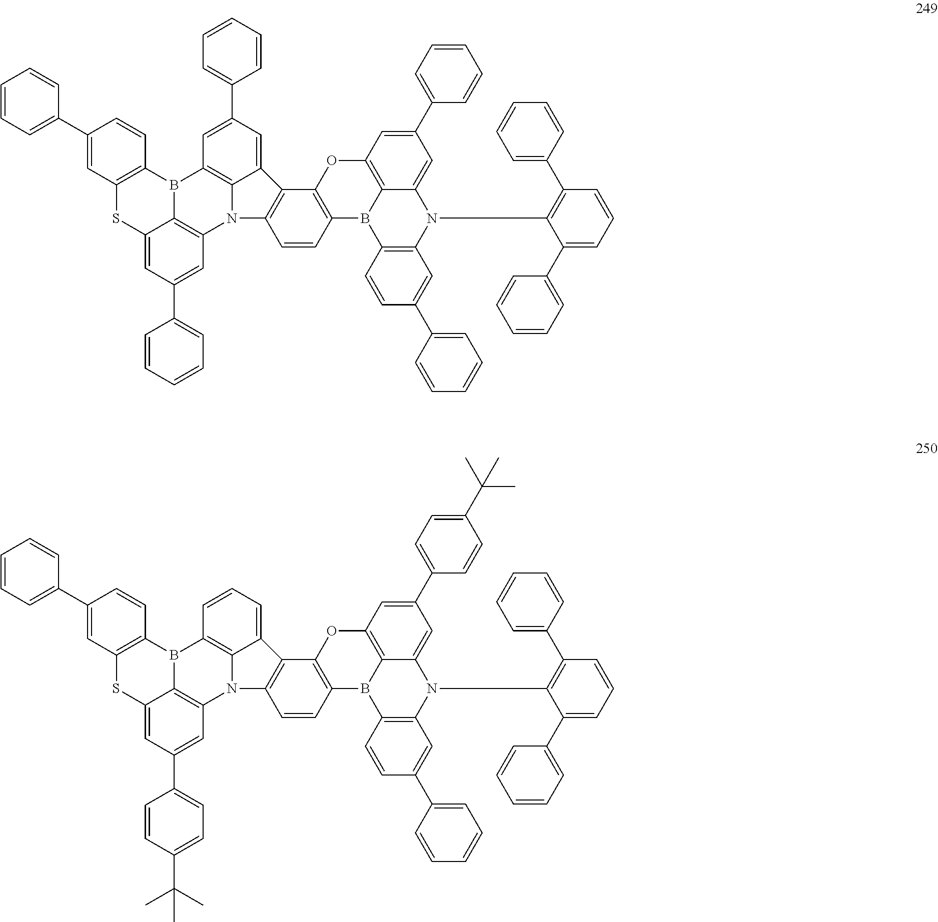 [SMILES: c1ccc(-c2ccc3c(c2)Sc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2S4)cc1] 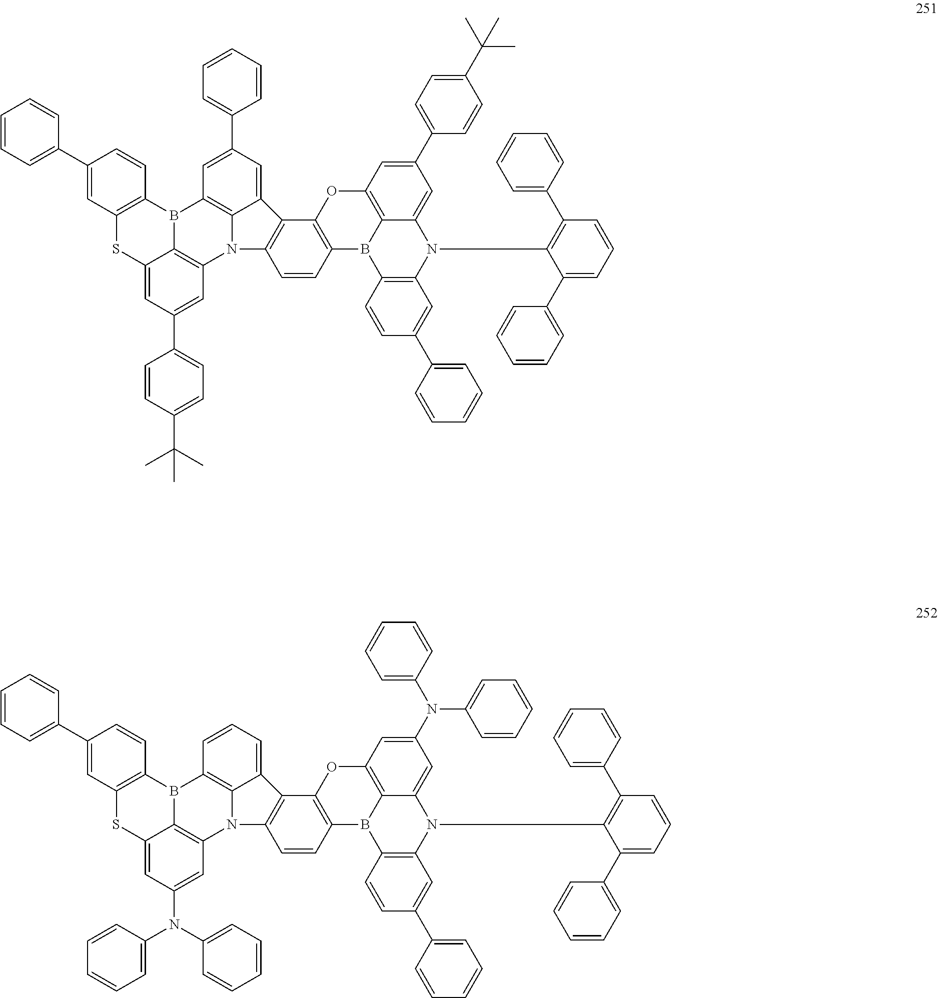 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2S4)cc1 ; c1ccc(-c2ccc3c(c2)Sc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 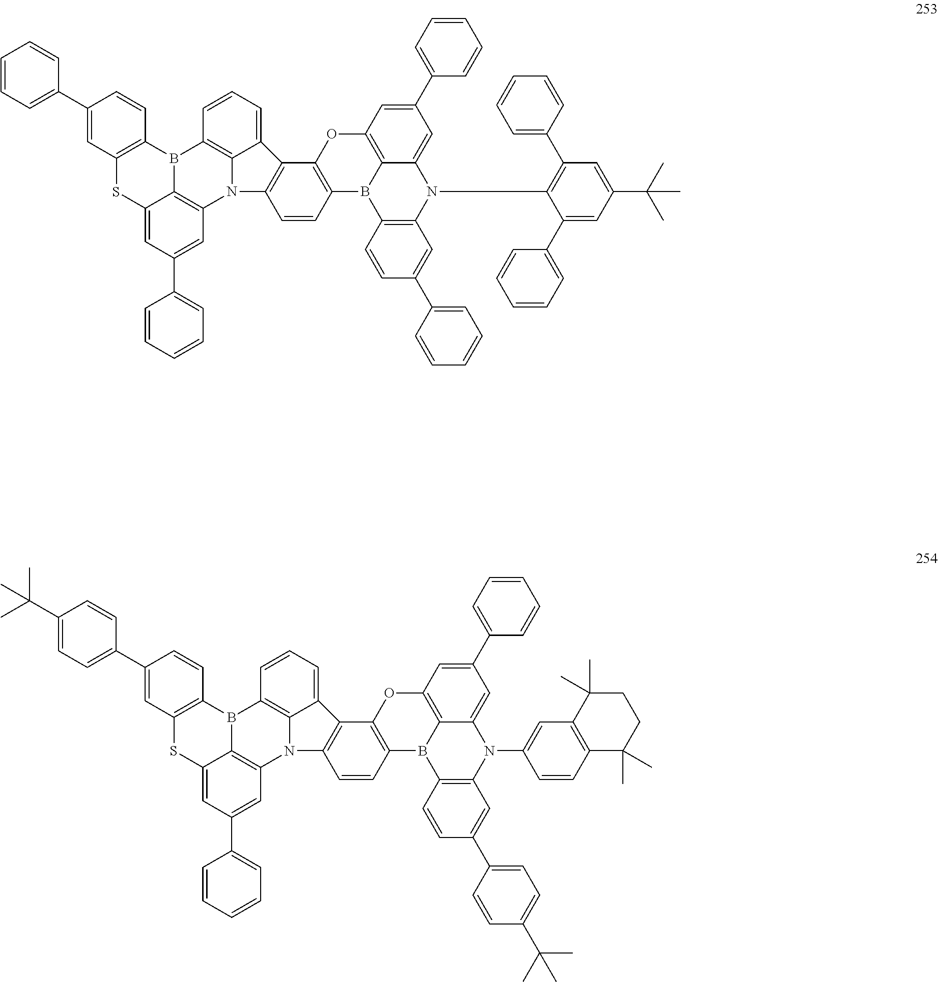 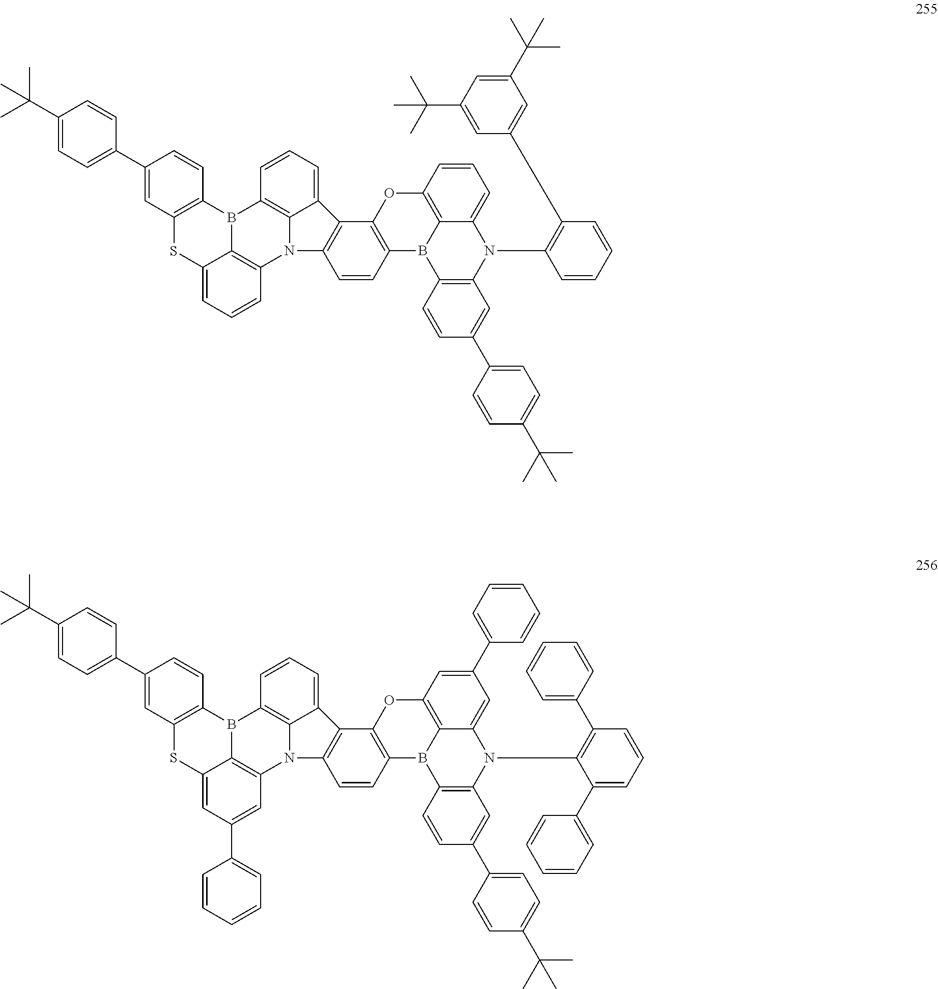 [SMILES: CC(C)(C)c1ccc(-c2ccc3c(c2)Sc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)O6)cc1 ; CC(C)(C)c1ccc(-c2ccc3c(c2)Sc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)O6)cc1] 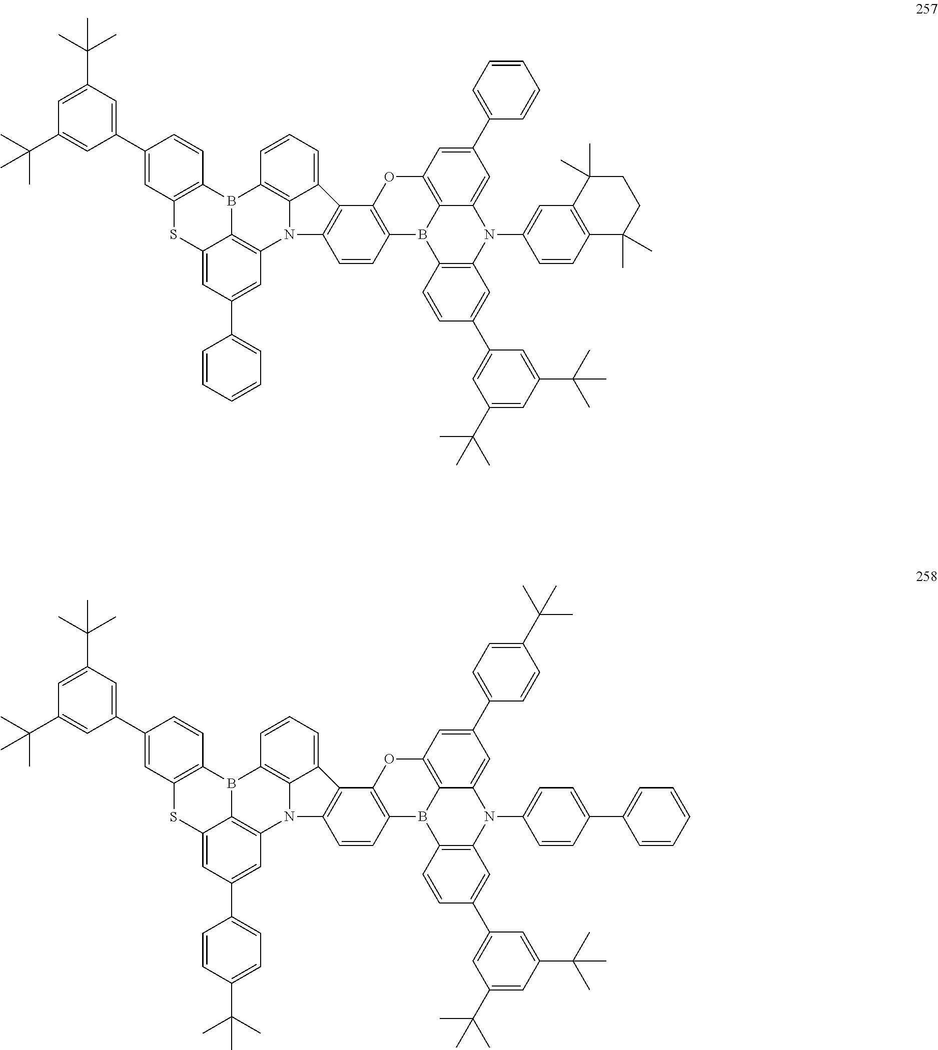 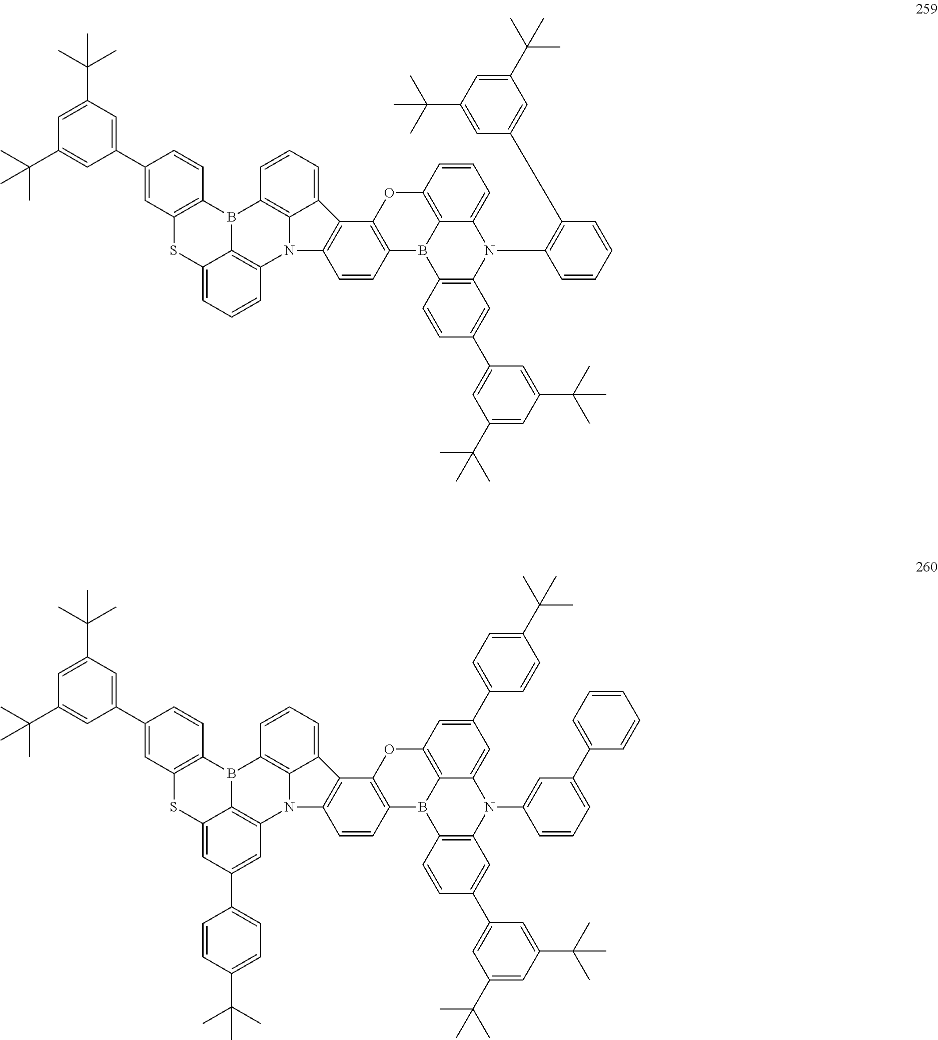 [SMILES: CC(C)(C)c1cc(-c2ccc3c(c2)Sc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)O6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2S4)cc1] 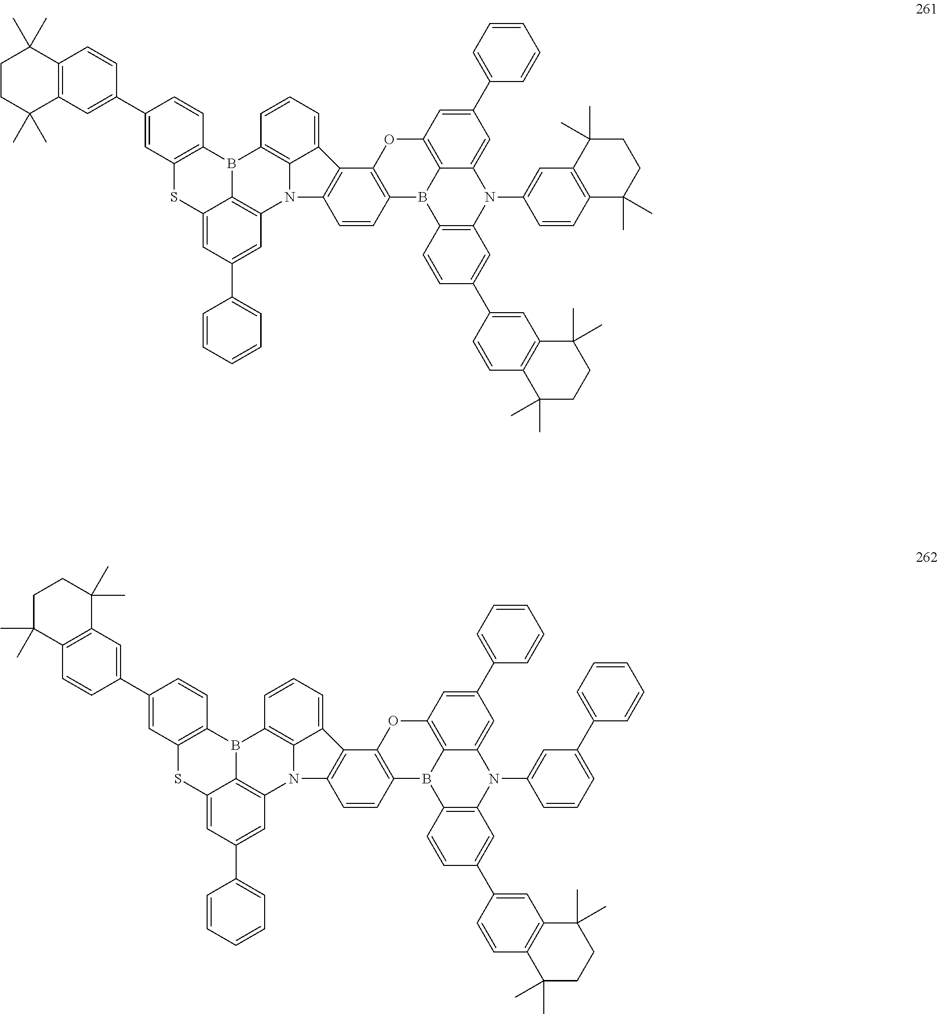 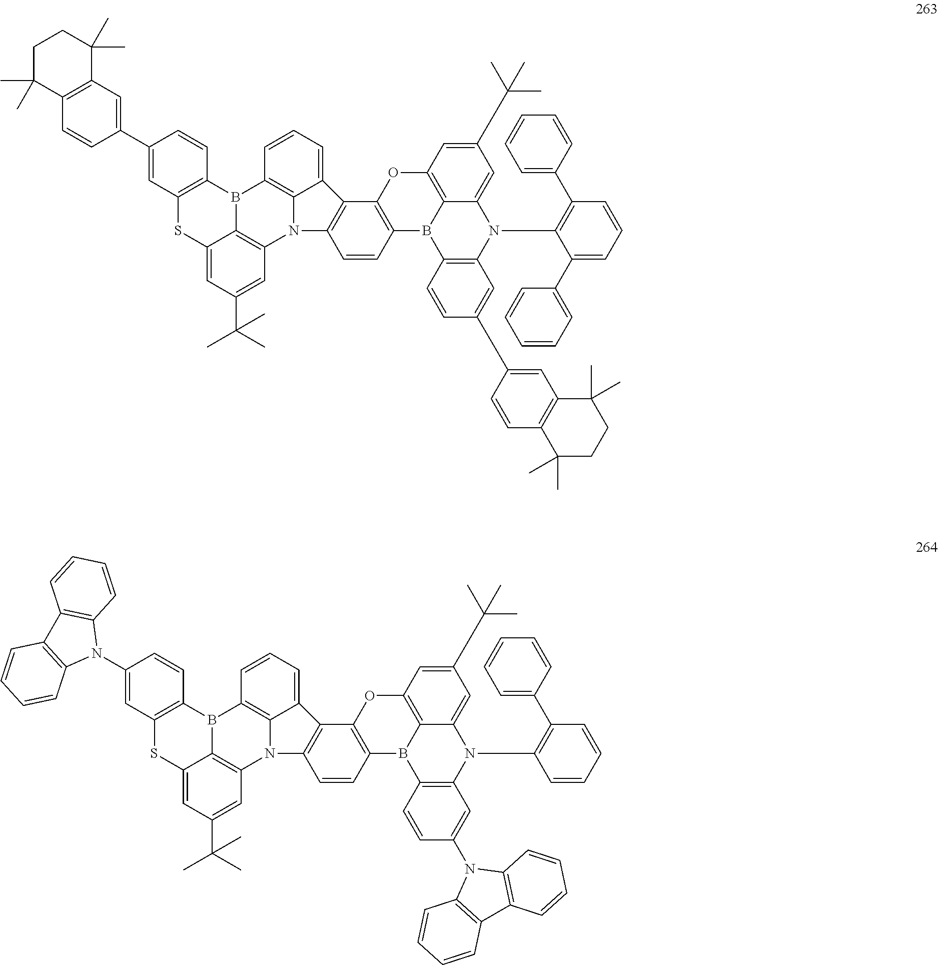 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1S3 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 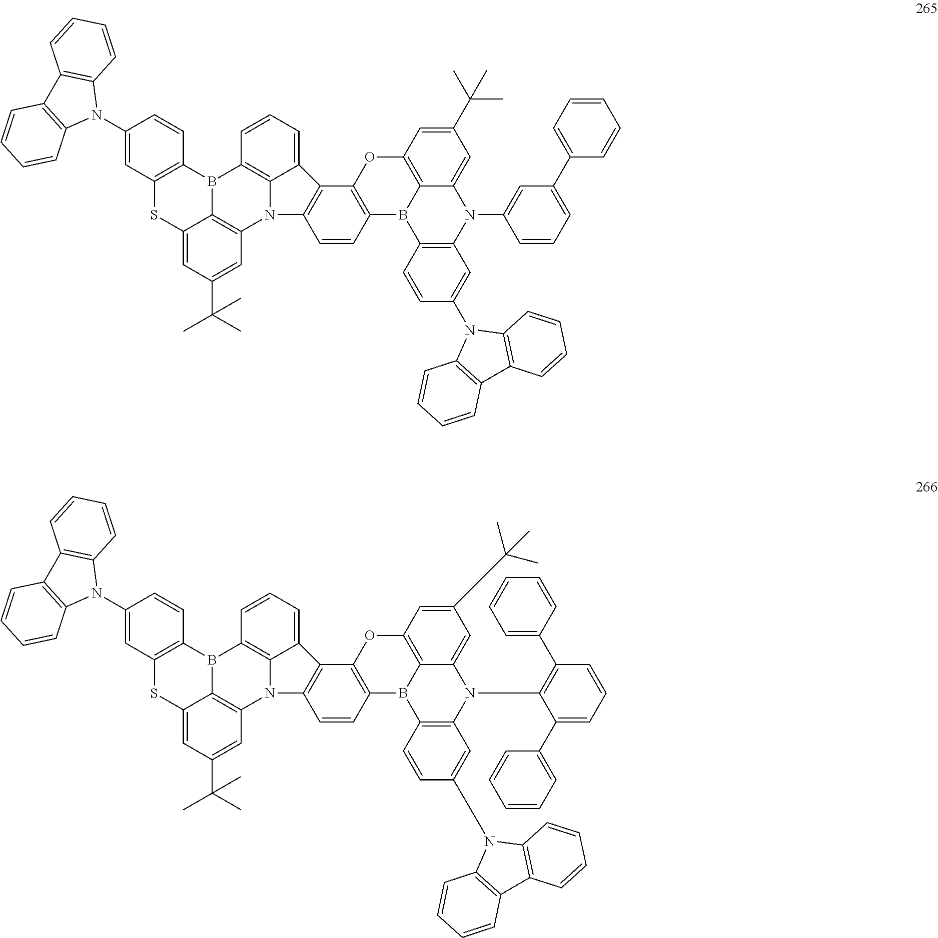 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 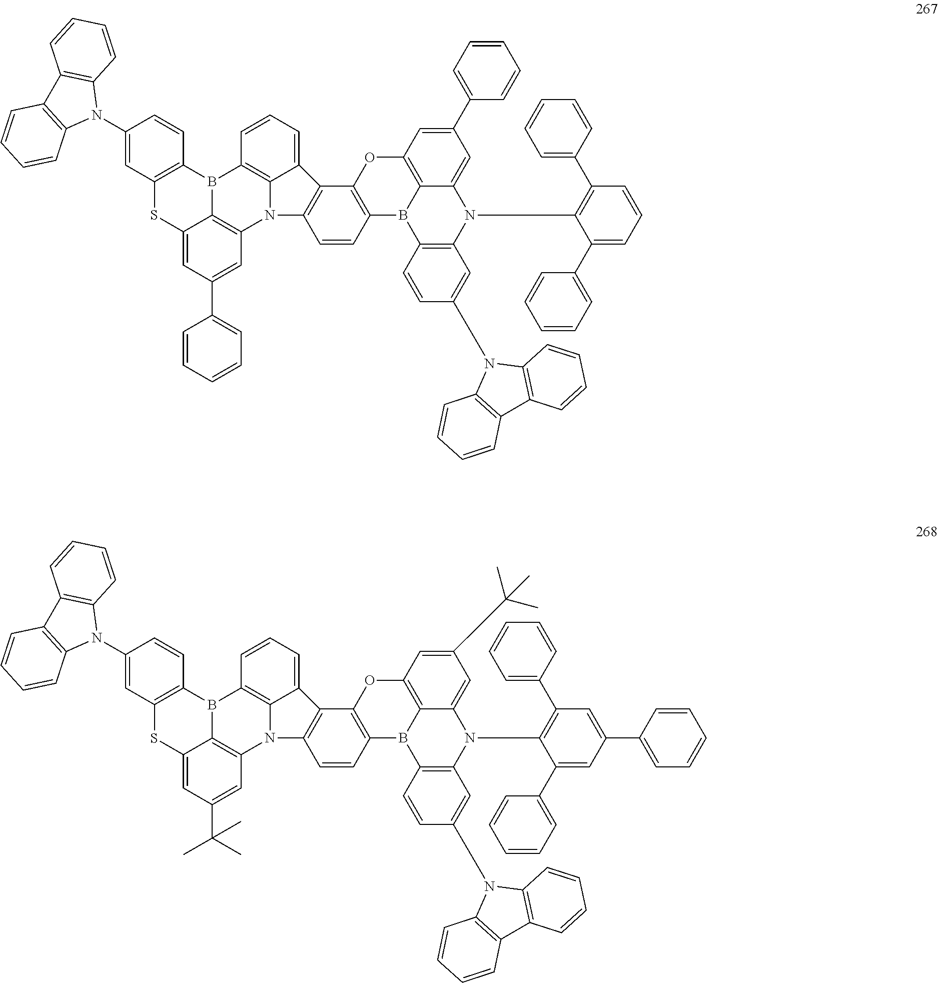 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2S4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 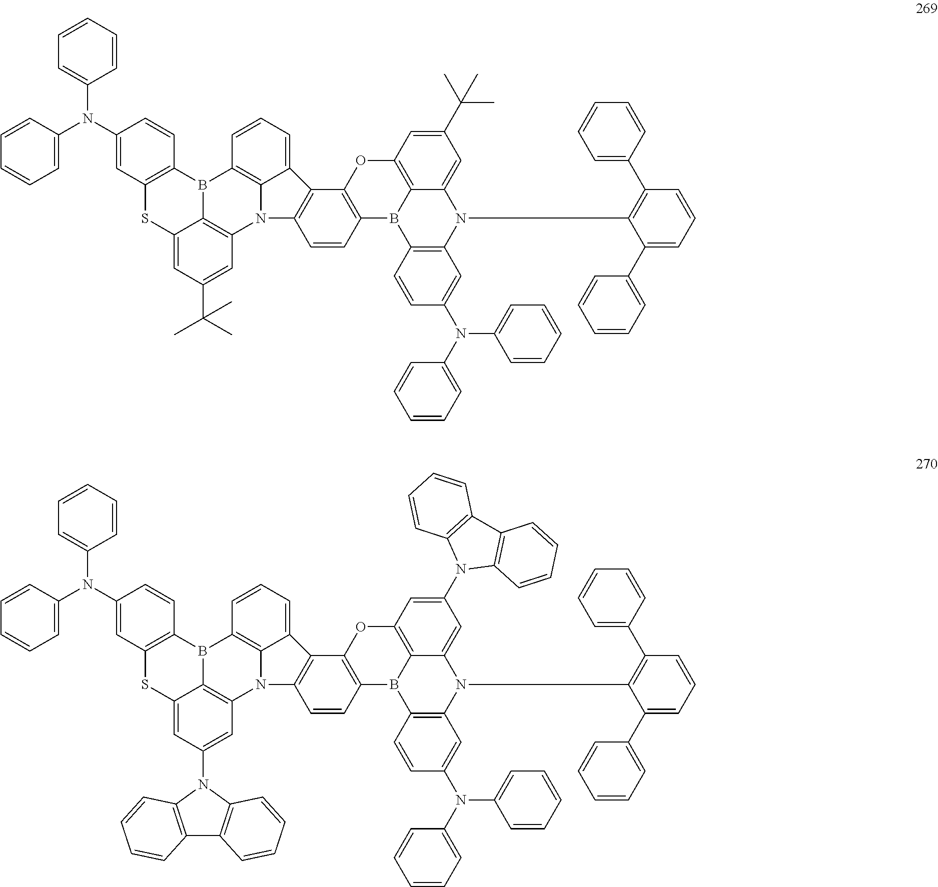 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1S3 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2S4)cc1] 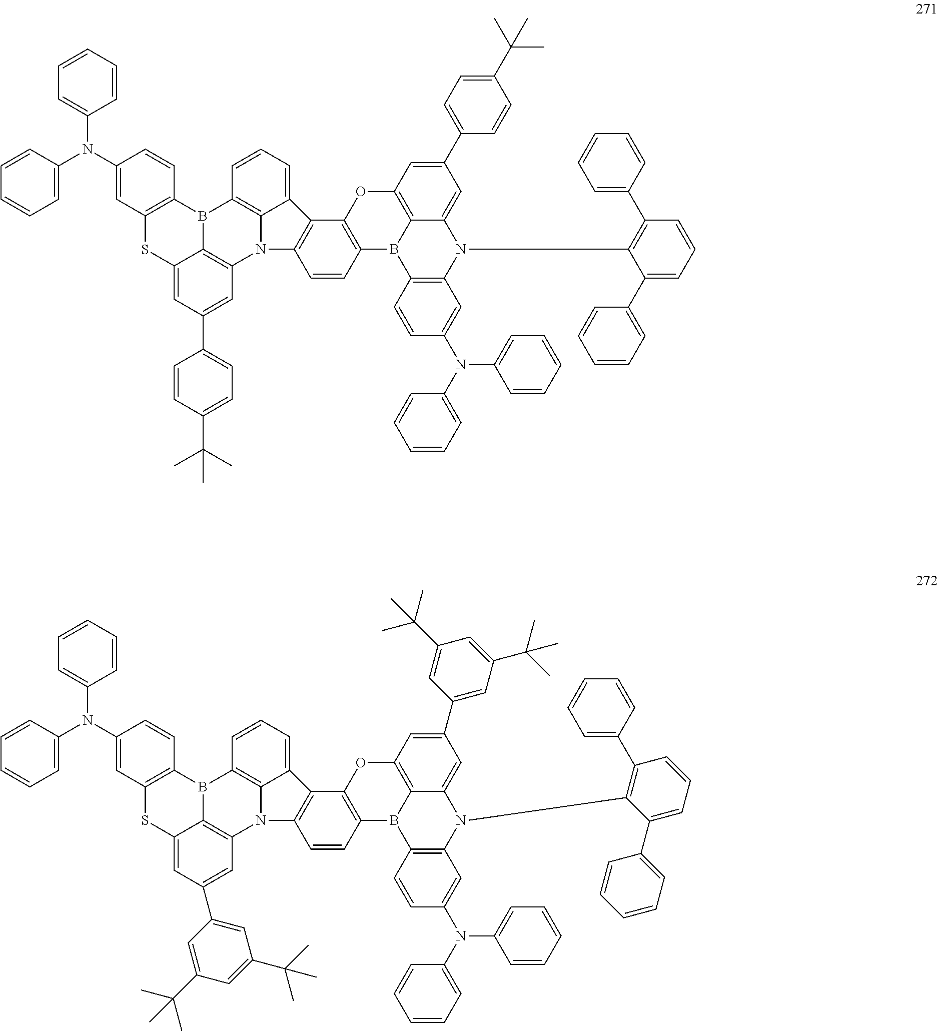 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2S4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2S4)cc(C(C)(C)C)c1] 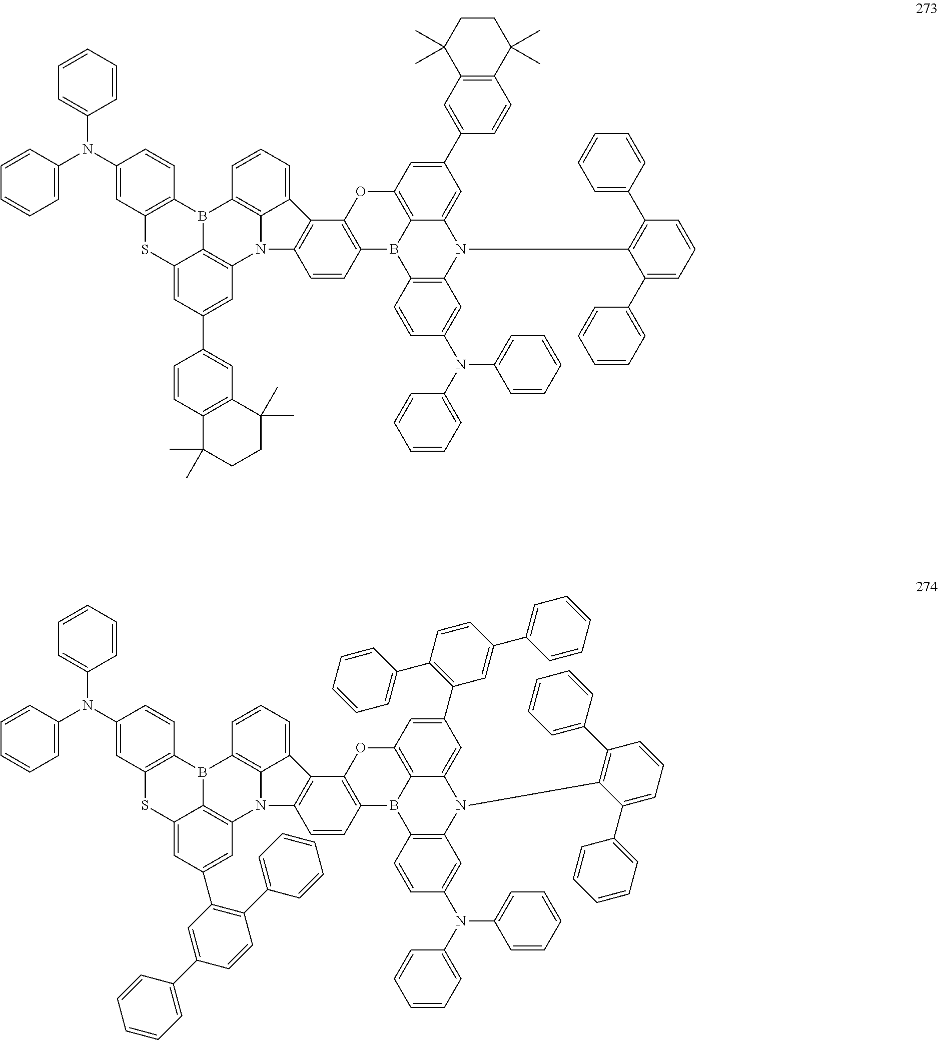 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3S5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3S5)c2)cc1] 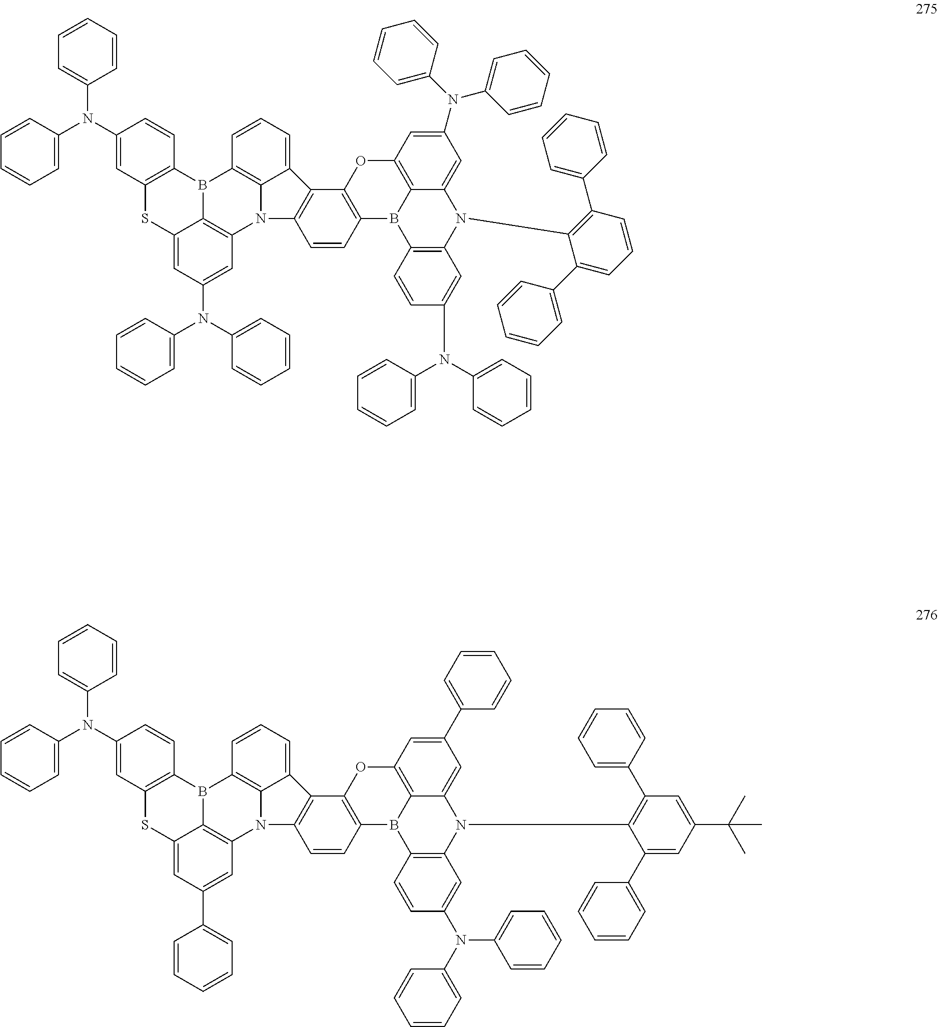 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2S4)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2S4)c(-c2ccccc2)c1] 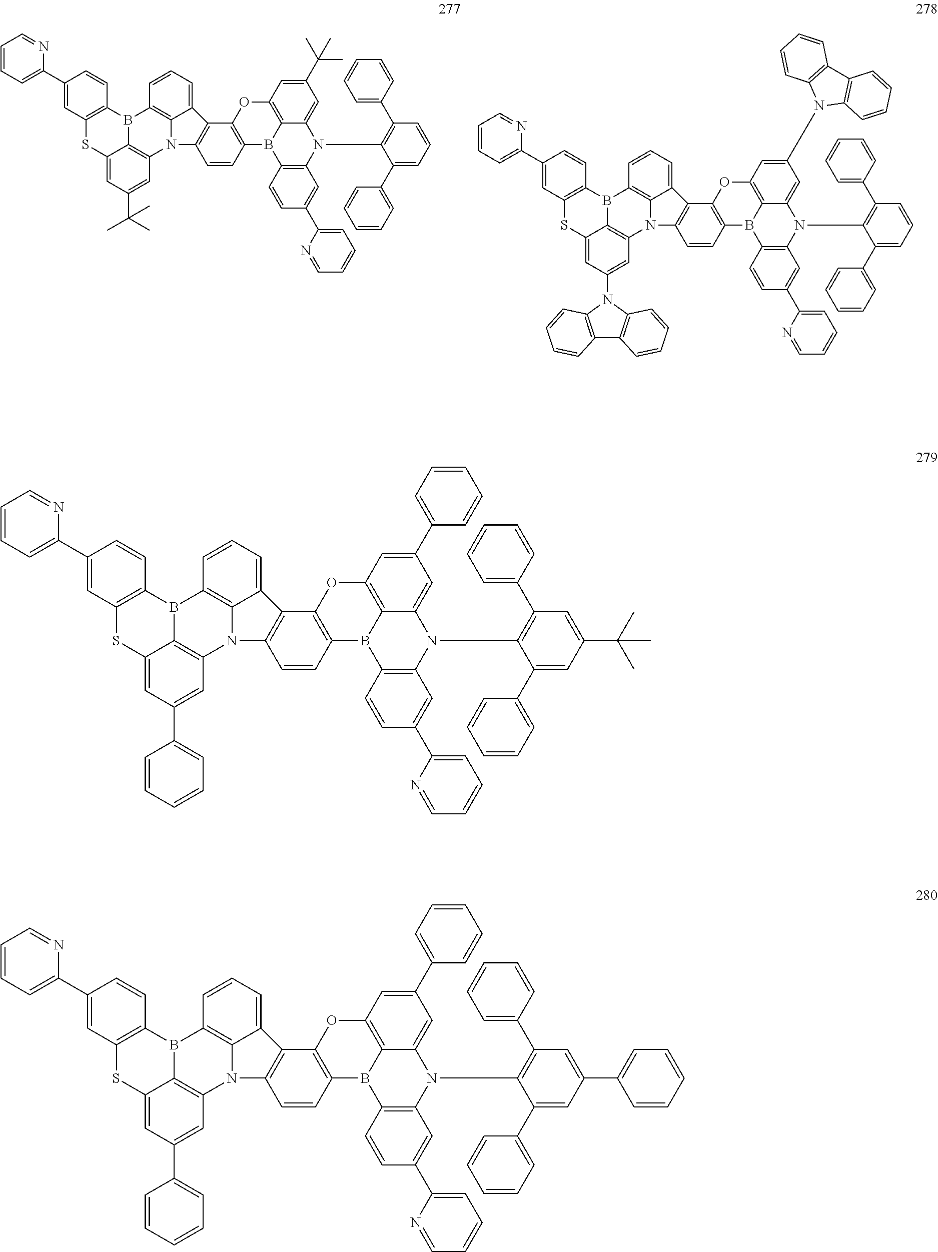 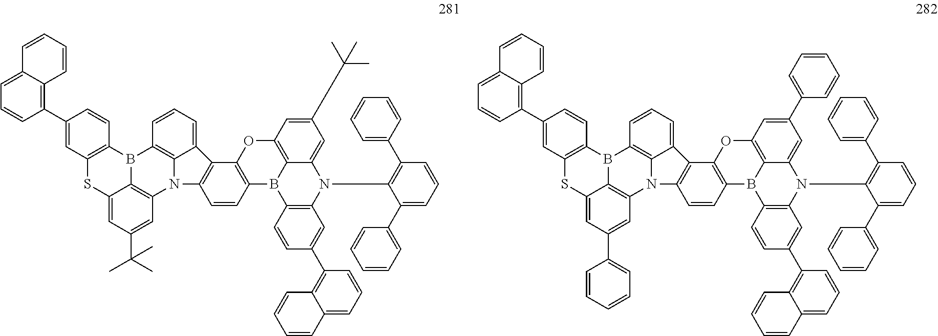 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1S3 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2S4)cc1] 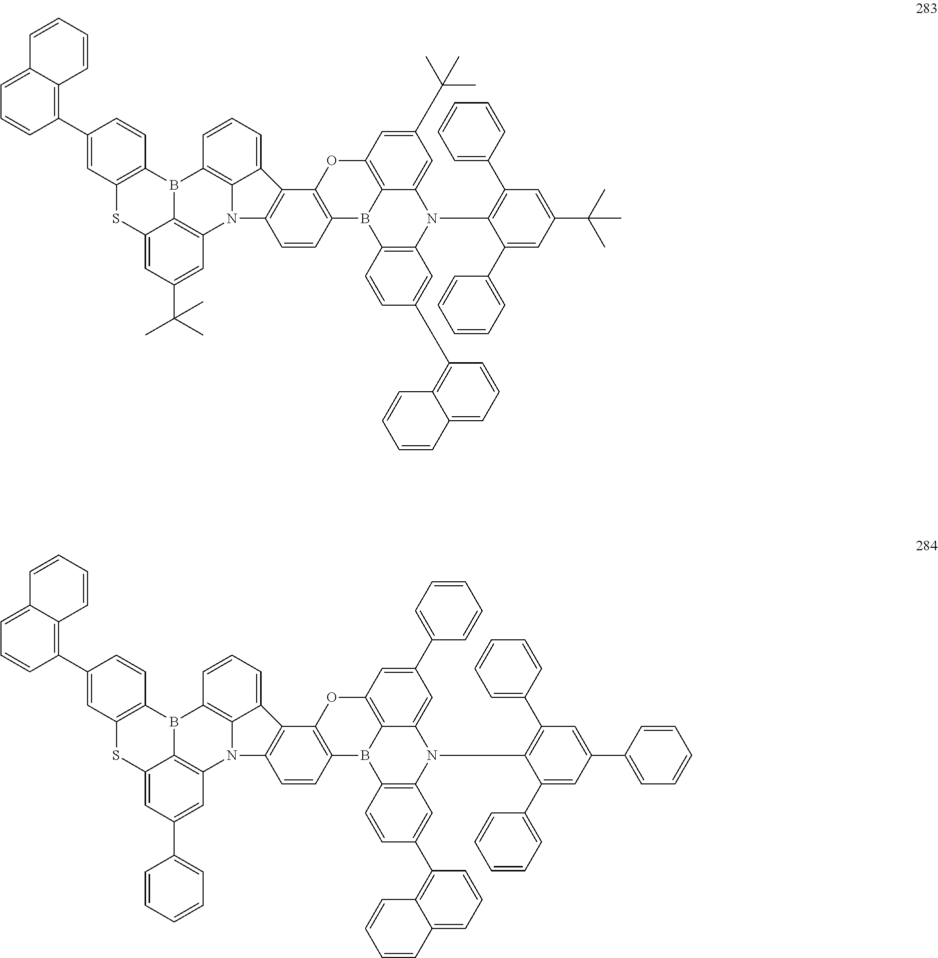 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1] 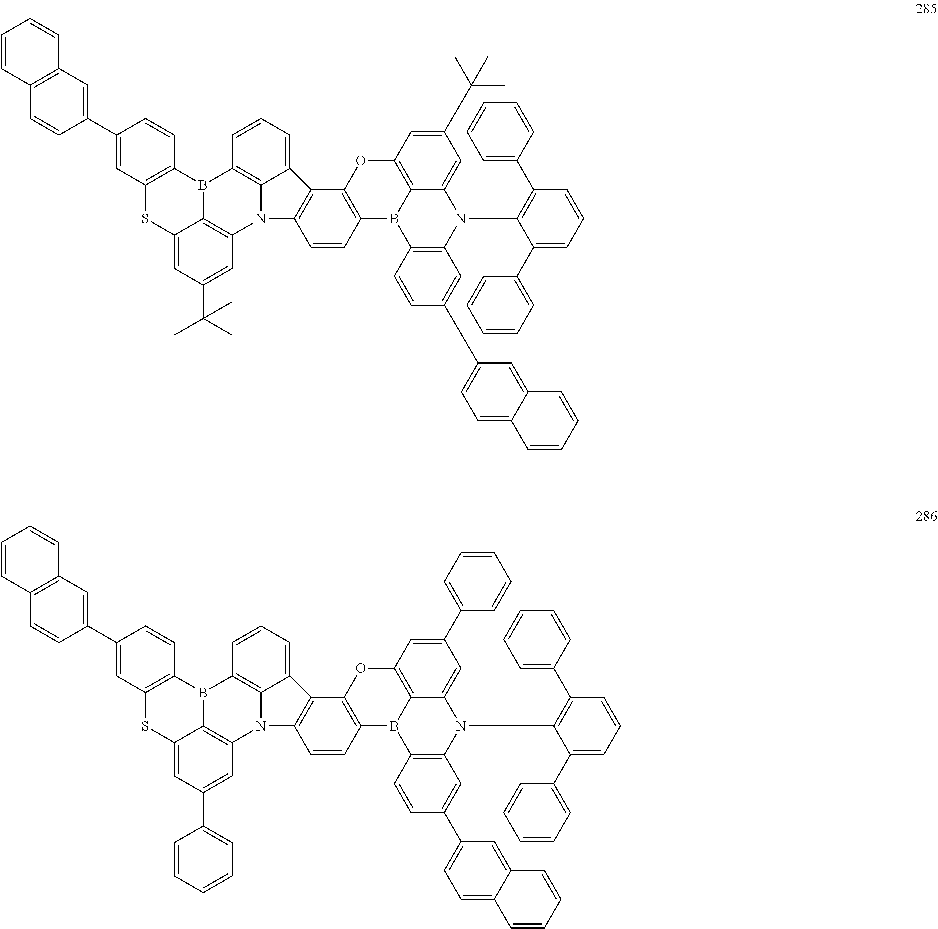 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2S4)cc1] 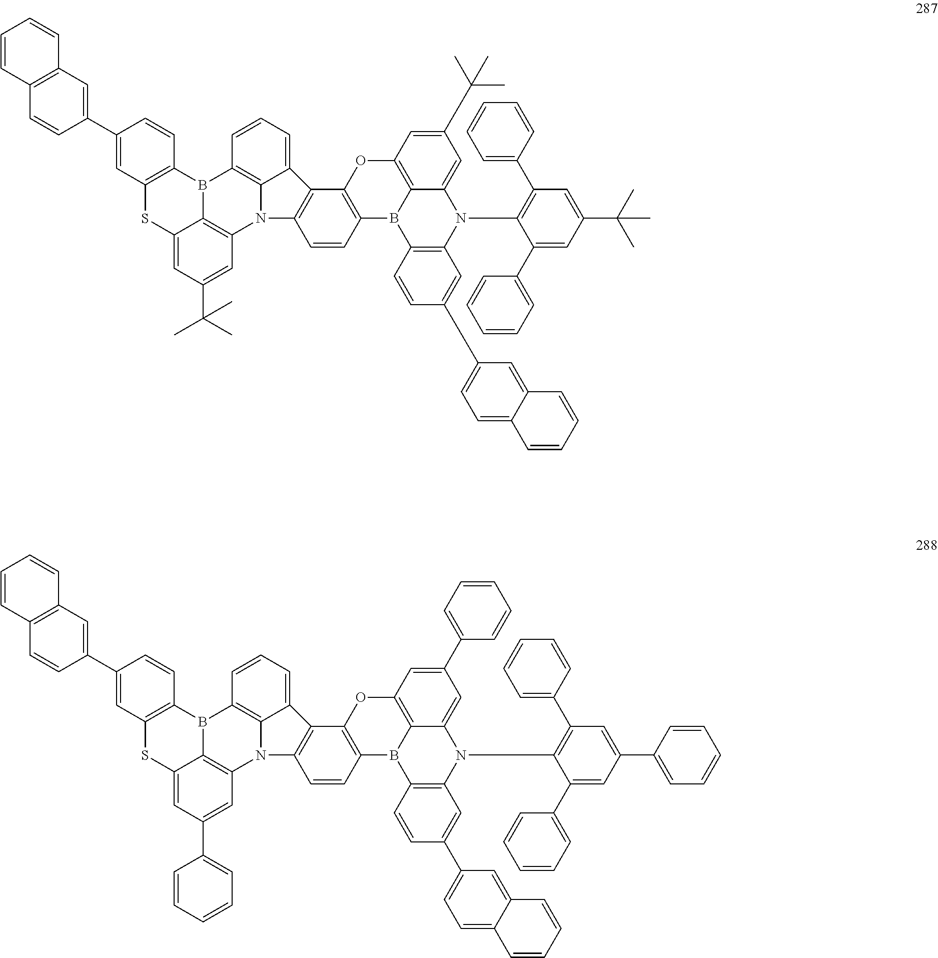 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1] 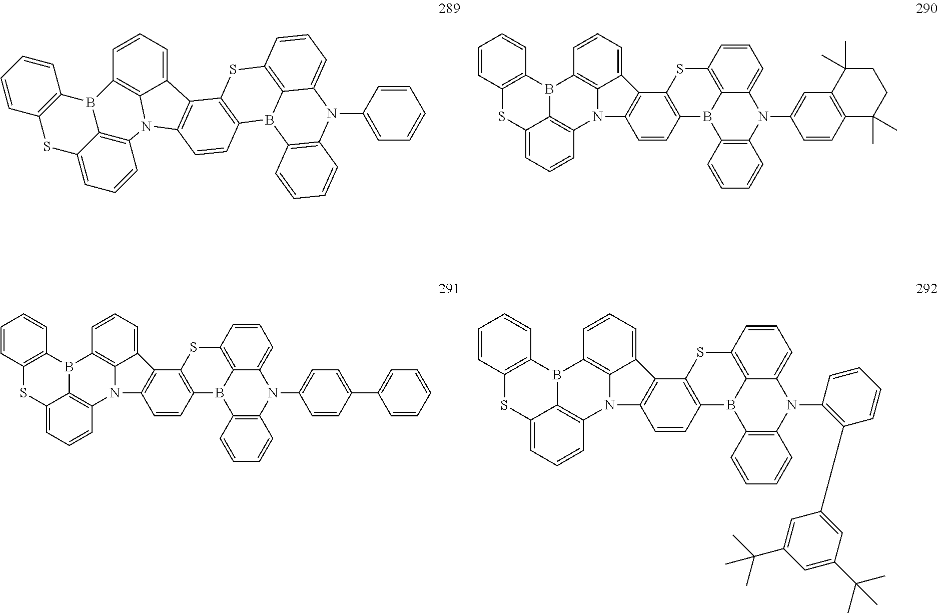 [SMILES: c1ccc(N2c3ccccc3B3c4ccc5c(c4Sc4cccc2c43)c2cccc3c2n5-c2cccc4c2B3c2ccccc2S4)cc1 ; CC1(C)CCC(C)(C)c2cc(N3c4ccccc4B4c5ccc6c(c5Sc5cccc3c54)c3cccc4c3n6-c3cccc5c3B4c3ccccc3S5)ccc21 ; c1ccc(-c2ccc(N3c4ccccc4B4c5ccc6c(c5Sc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Sc4cccc2c43)c2cccc3c2n5-c2cccc4c2B3c2ccccc2S4)cc(C(C)(C)C)c1] 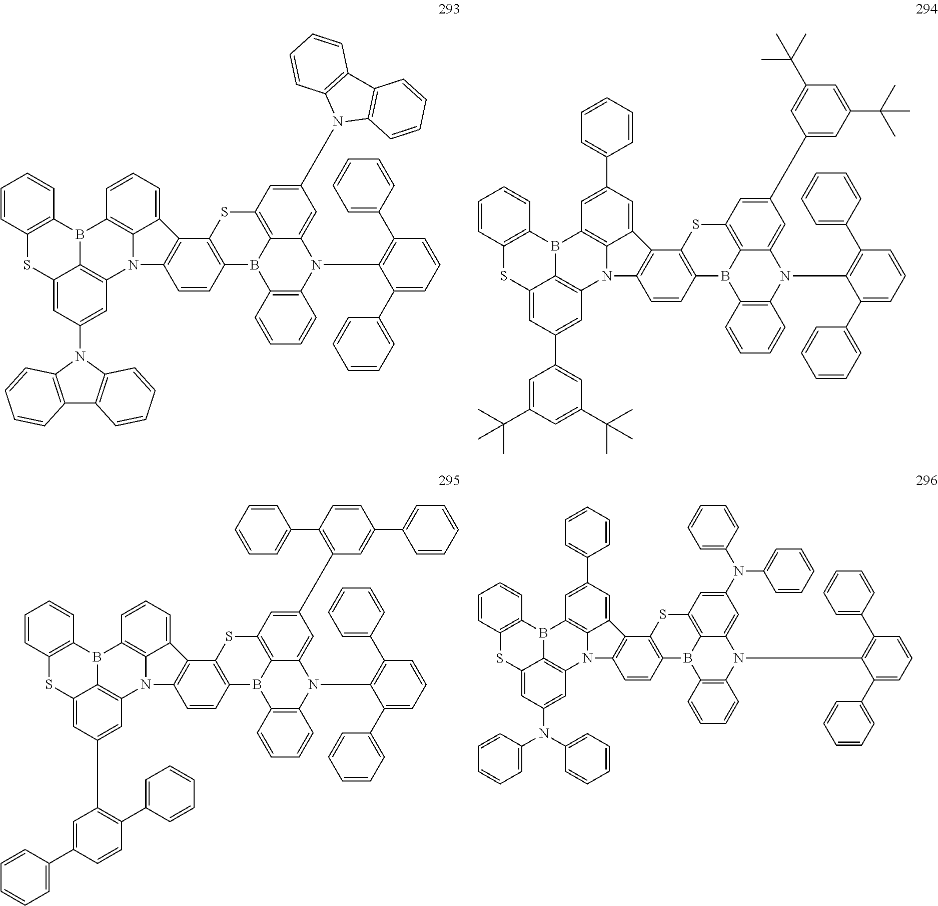 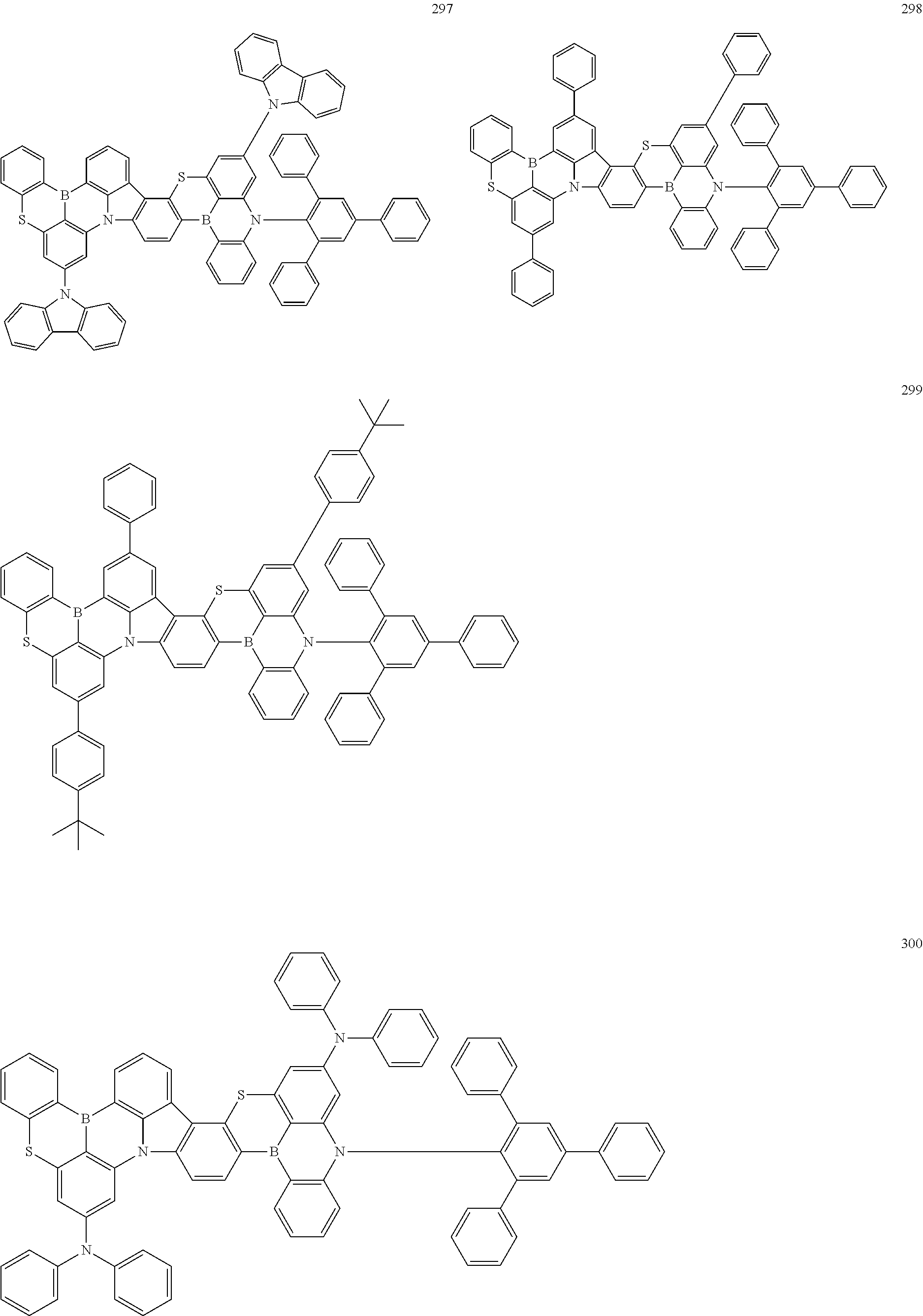 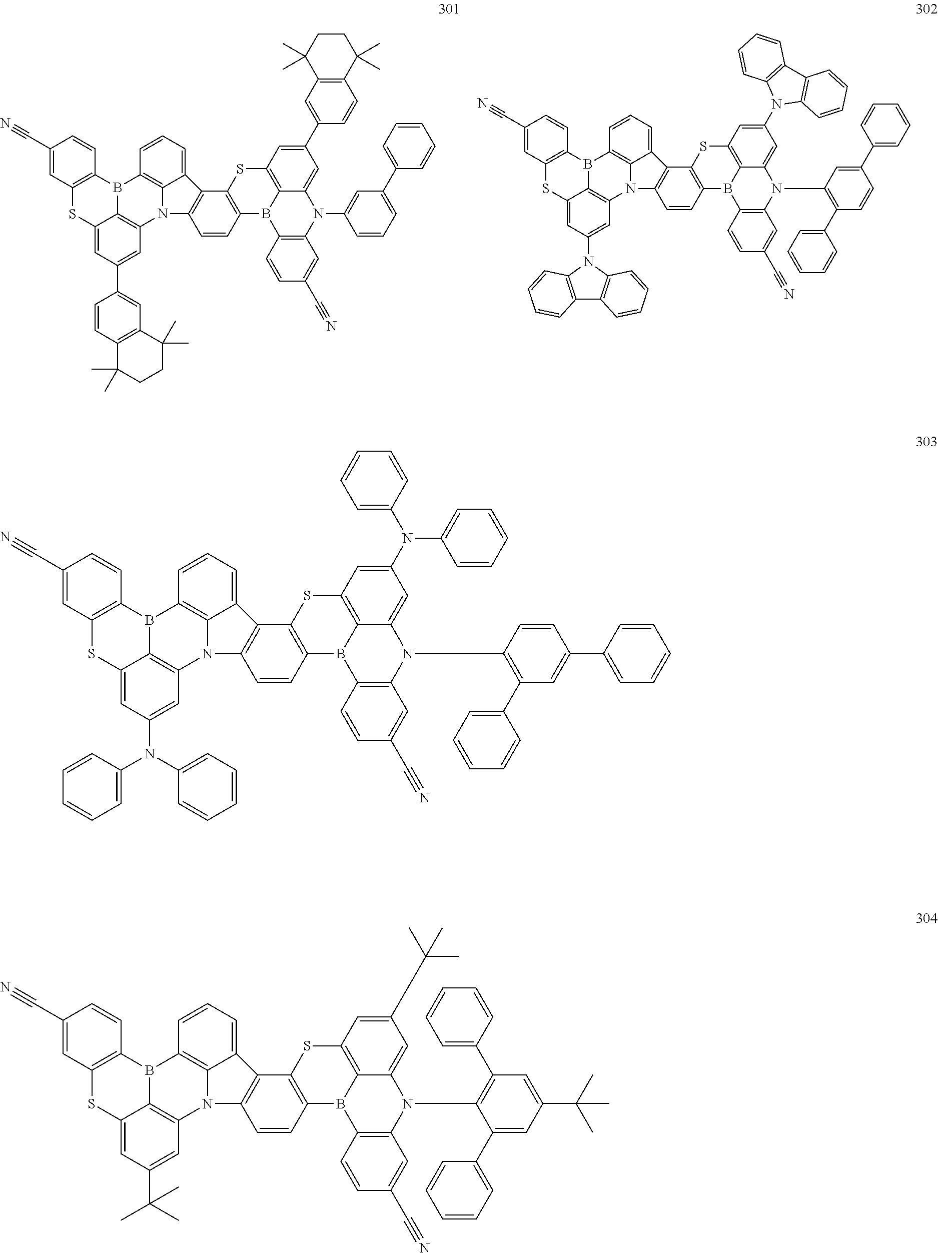 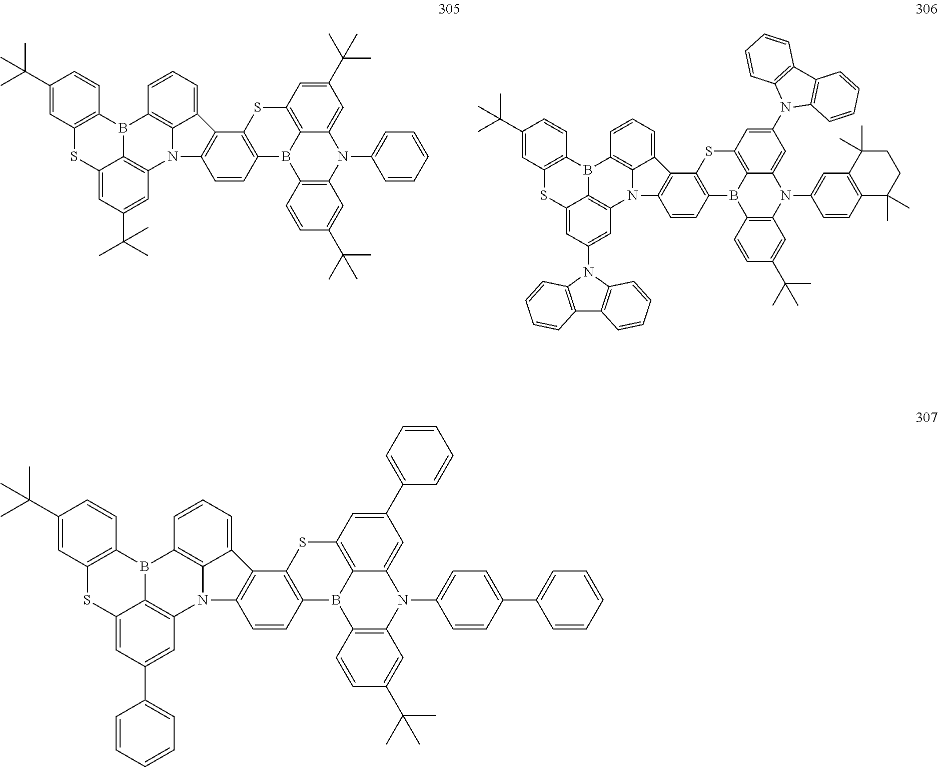 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)S5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)S5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)S5] 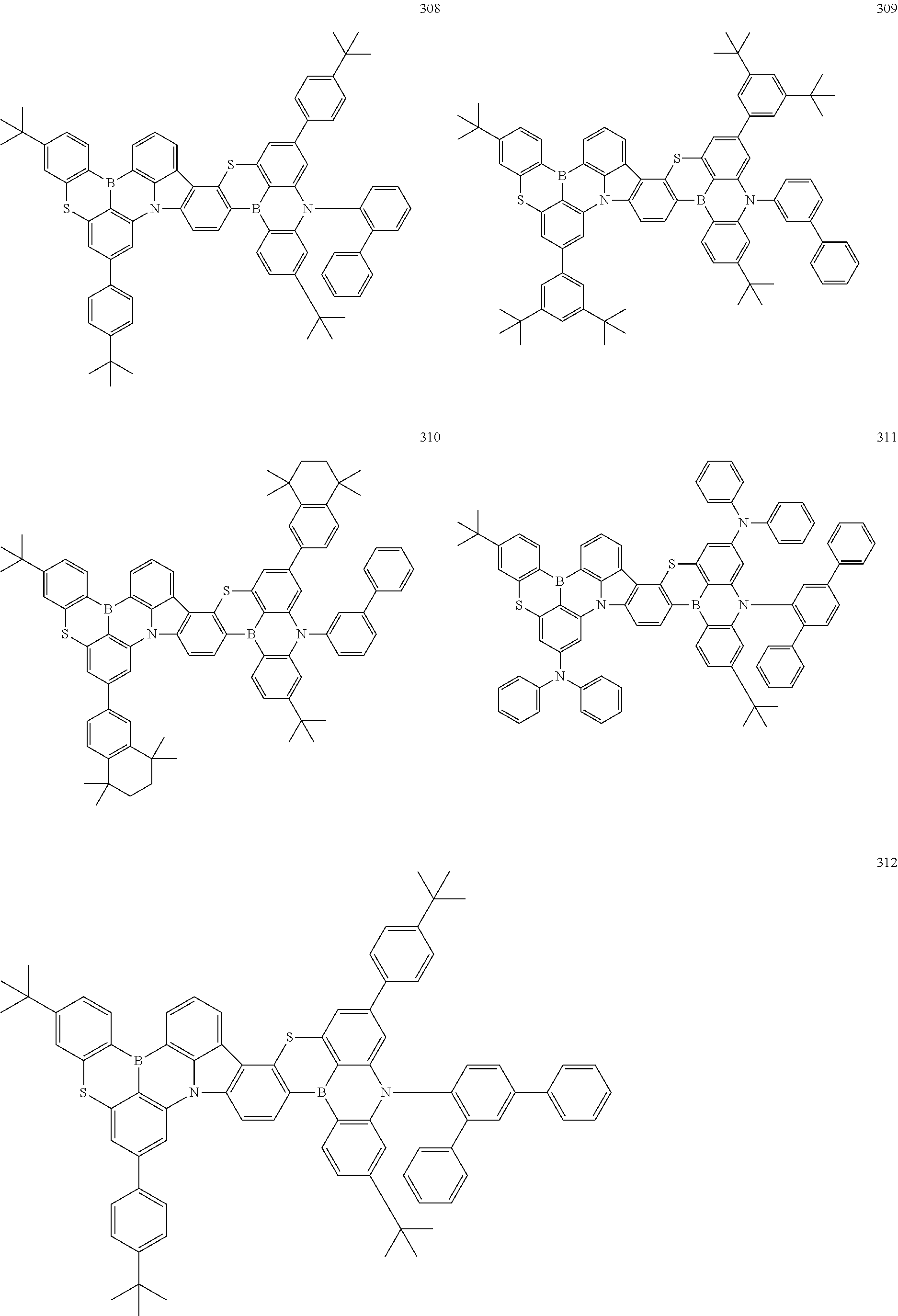 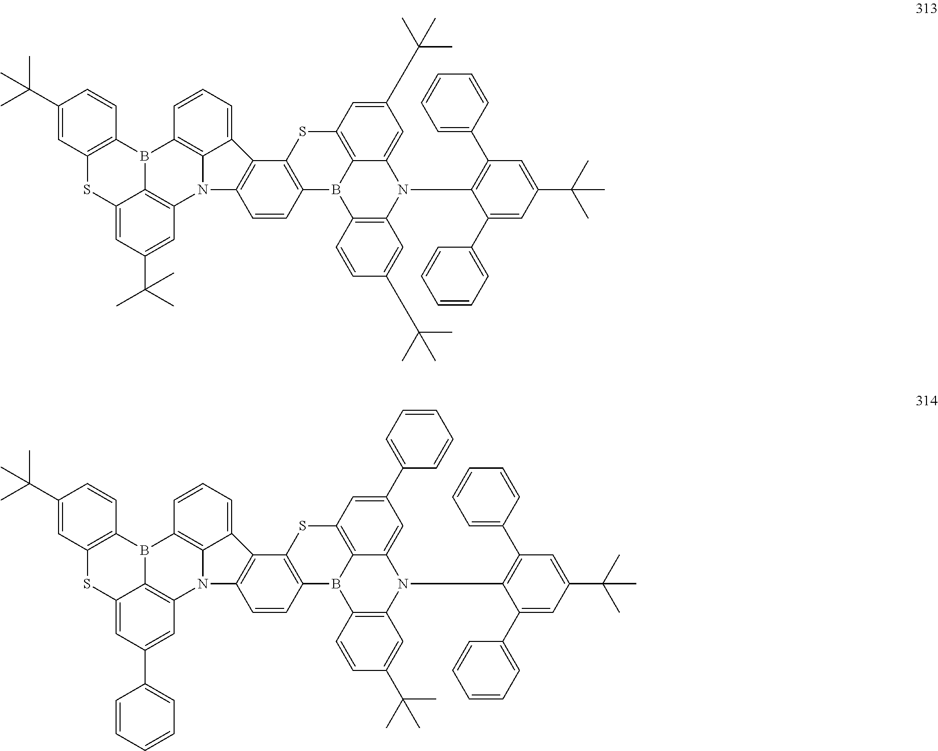 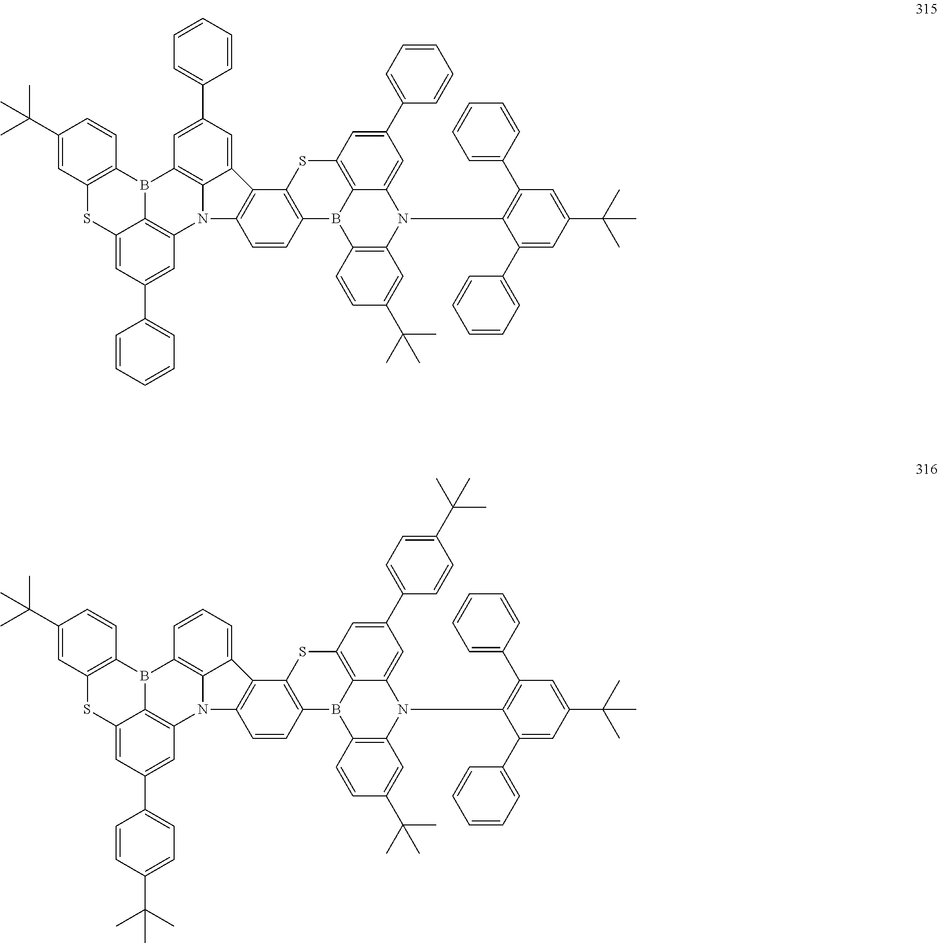 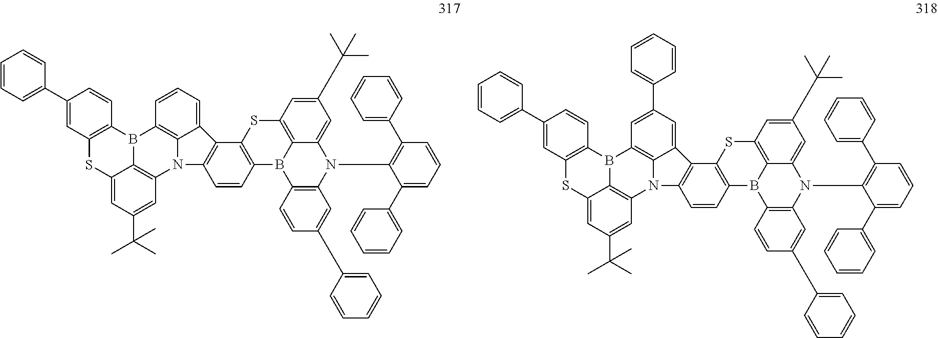 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1S3] 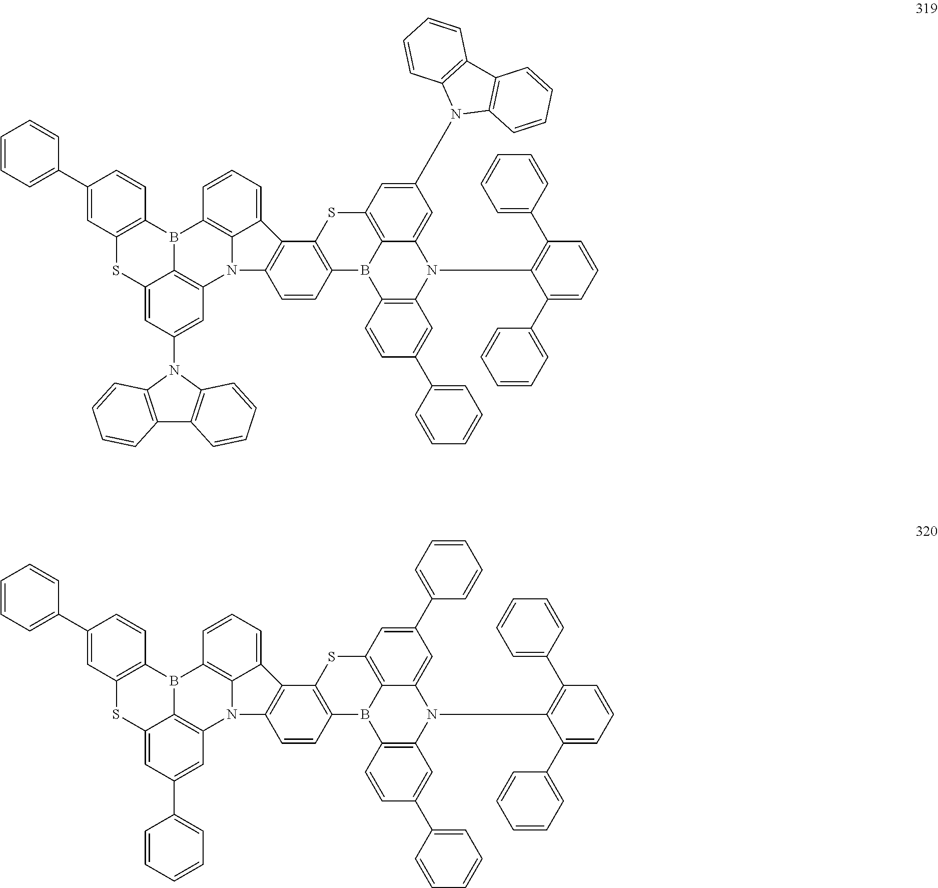 [SMILES: c1ccc(-c2ccc3c(c2)Sc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)S6)cc1 ; c1ccc(-c2ccc3c(c2)Sc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)S6)cc1] 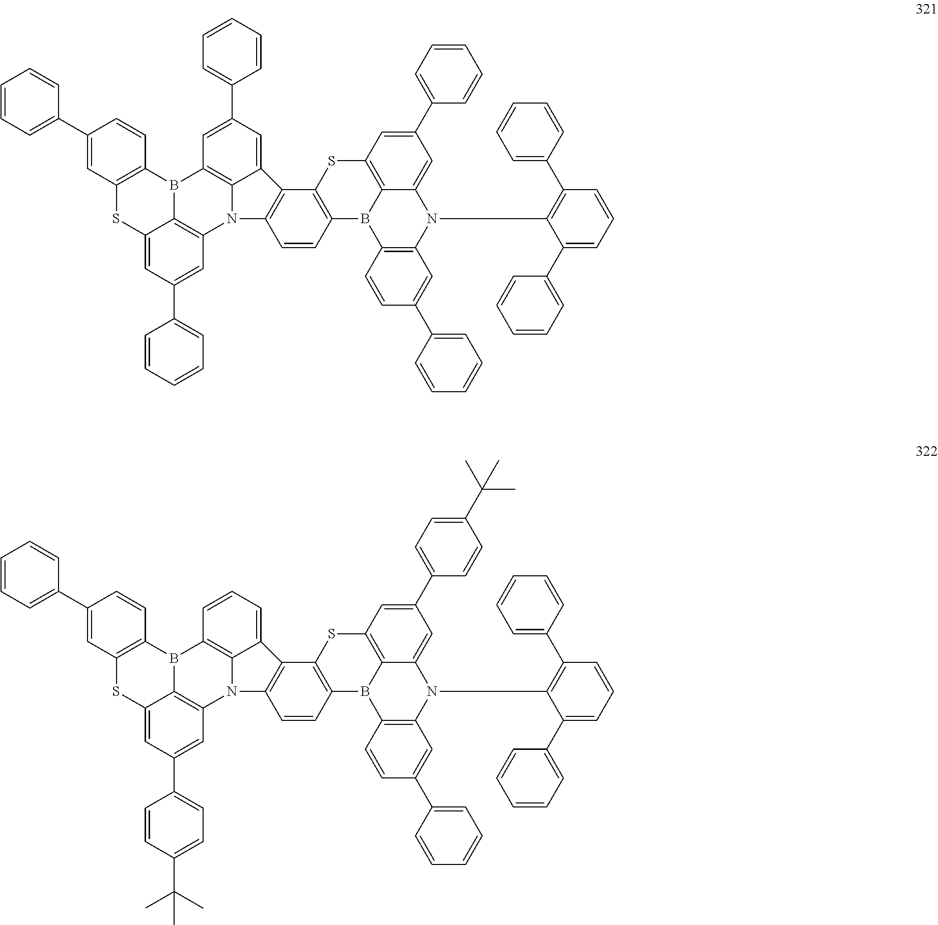 [SMILES: c1ccc(-c2ccc3c(c2)Sc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)S6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cccc3c2n4-c2cc(-c4ccc(C(C)(C)C)cc4)cc4c2B3c2ccc(-c3ccccc3)cc2S4)cc1] 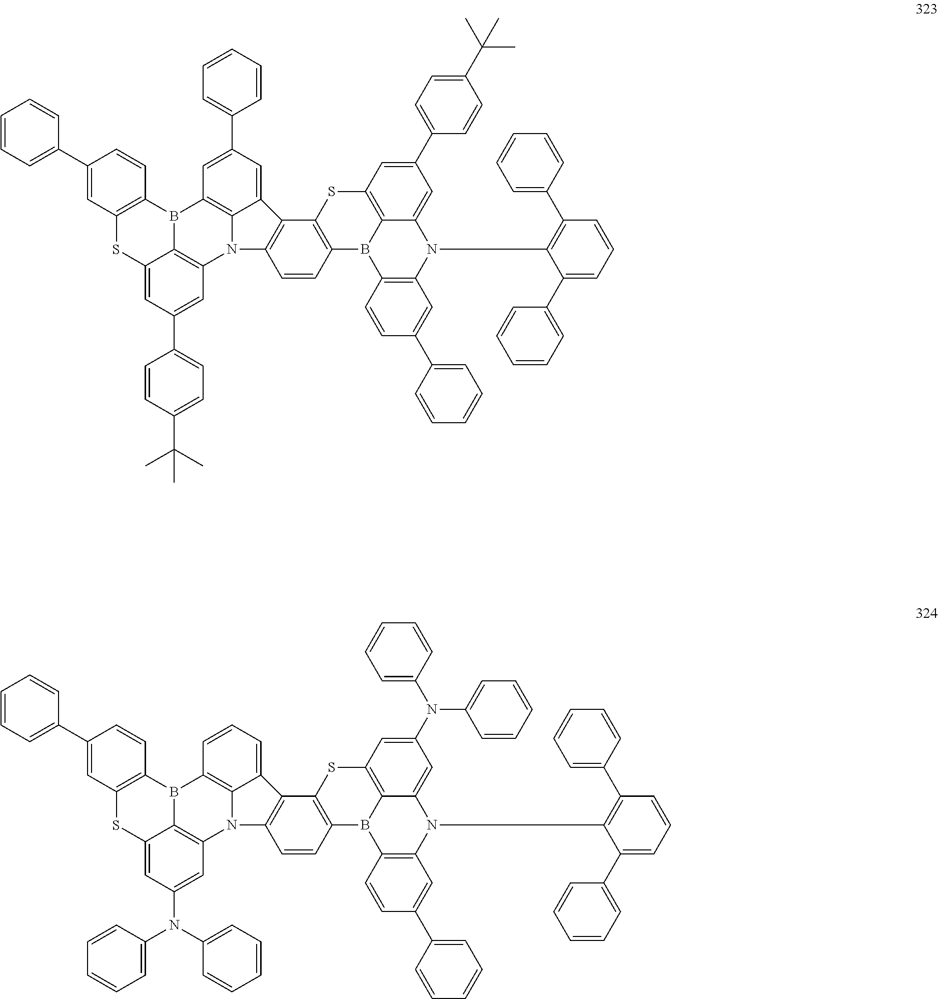 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cc(-c3ccccc3)cc3c2n4-c2cc(-c4ccc(C(C)(C)C)cc4)cc4c2B3c2ccc(-c3ccccc3)cc2S4)cc1 ; c1ccc(-c2ccc3c(c2)Sc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)S6)cc1] 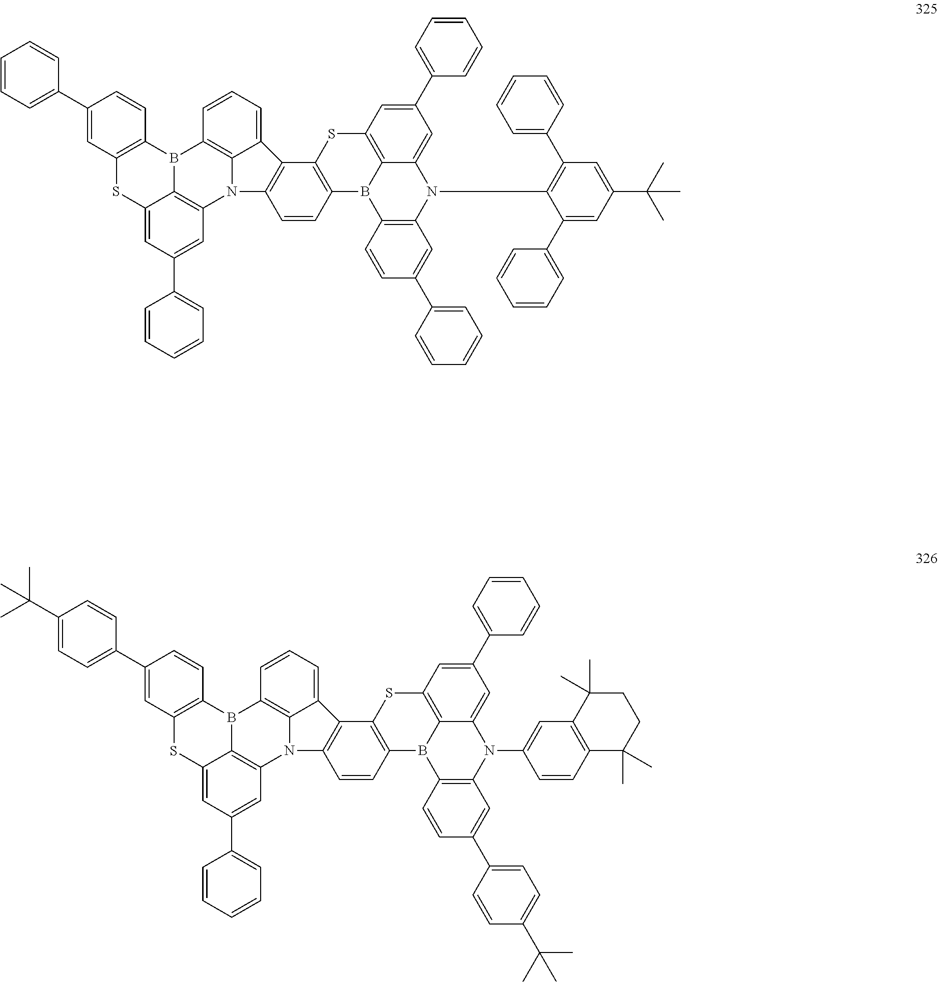 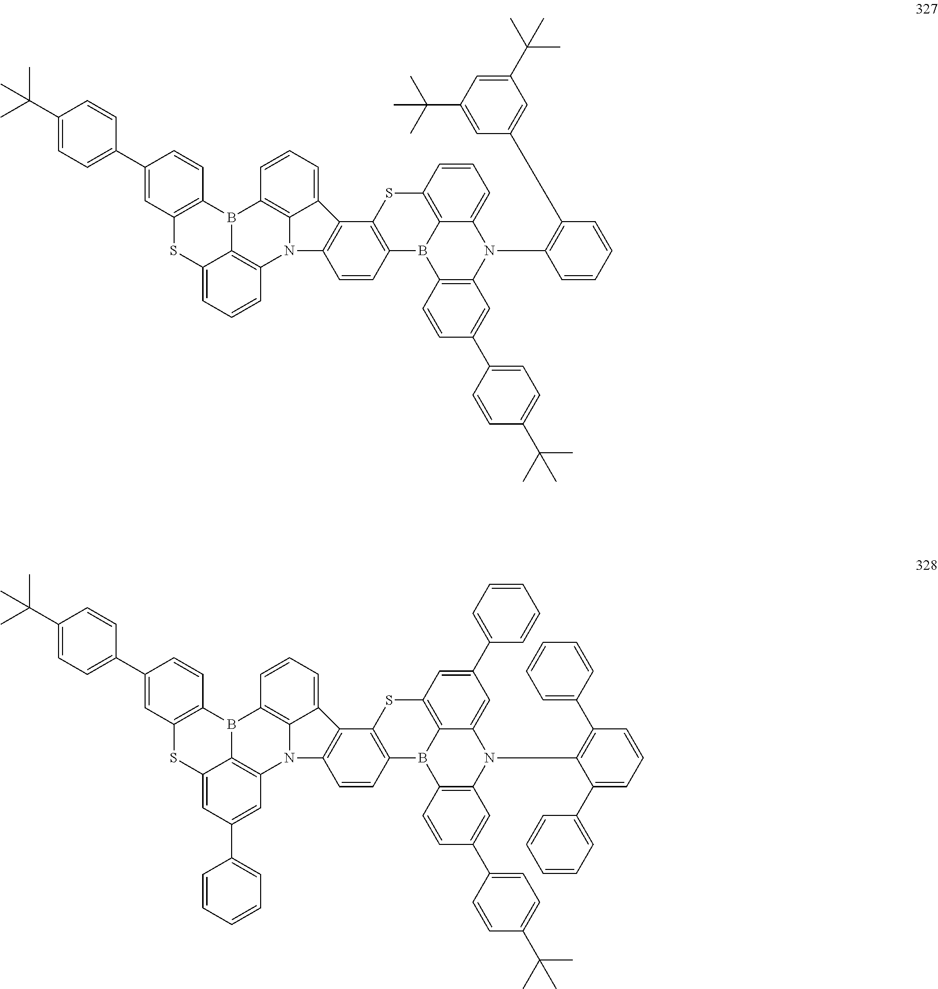 [SMILES: CC(C)(C)c1ccc(-c2ccc3c(c2)Sc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)S6)cc1 ; CC(C)(C)c1ccc(-c2ccc3c(c2)Sc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)S6)cc1] 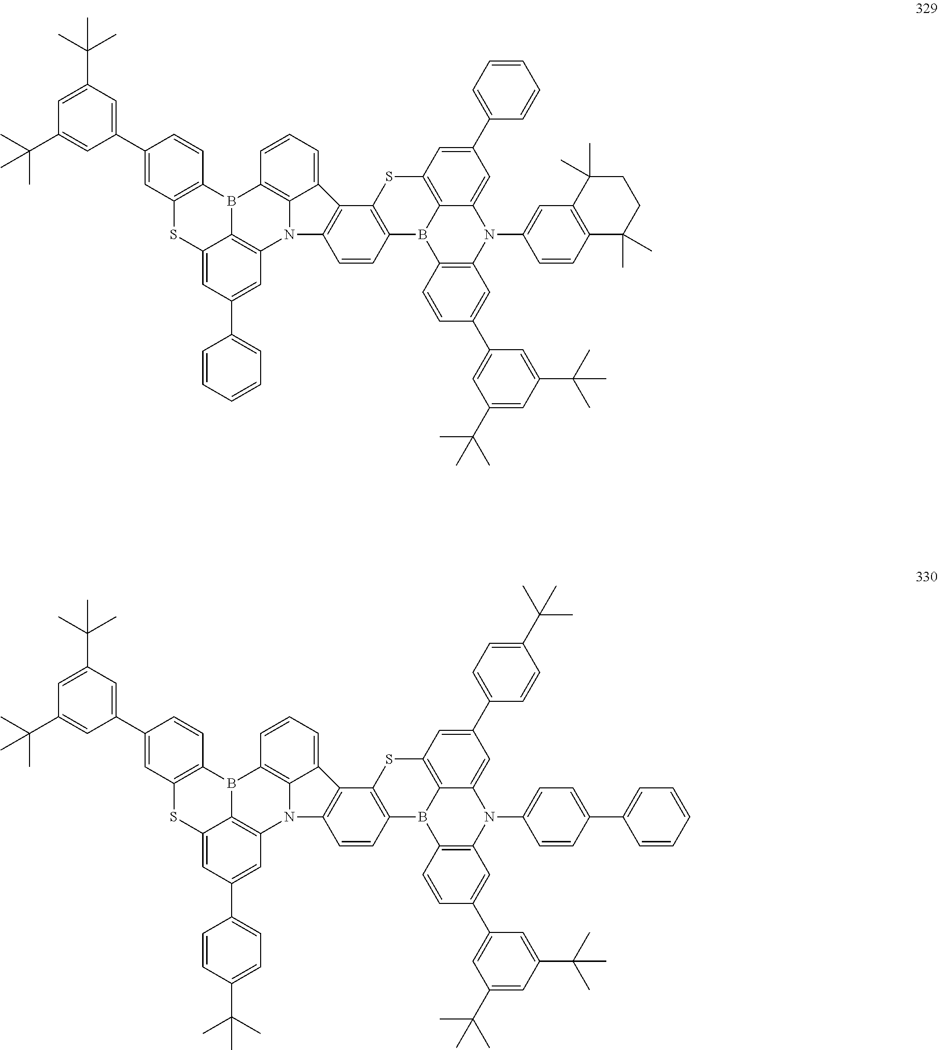 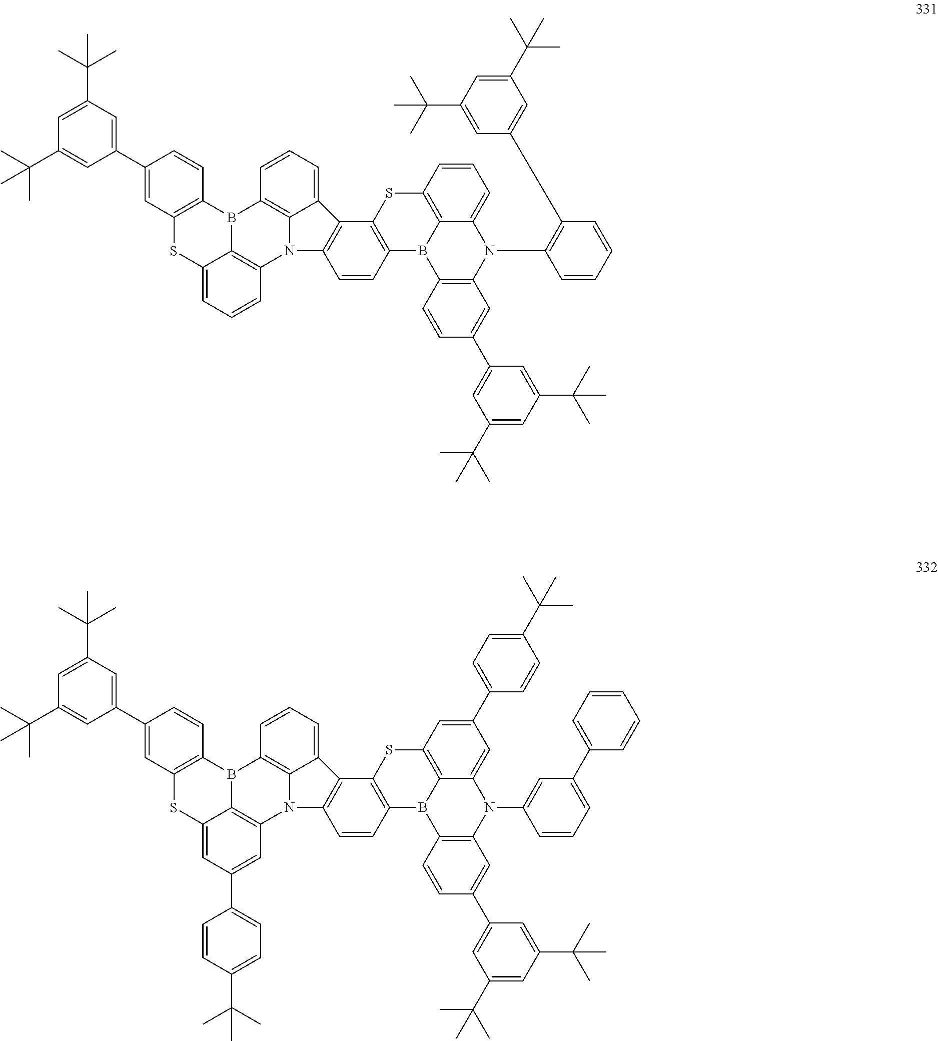 [SMILES: CC(C)(C)c1cc(-c2ccc3c(c2)Sc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)S6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2S3)c2cccc3c2n4-c2cc(-c4ccc(C(C)(C)C)cc4)cc4c2B3c2ccc(-c3cc(C(C)(C)C)cc(C(C)(C)C)c3)cc2S4)cc1] 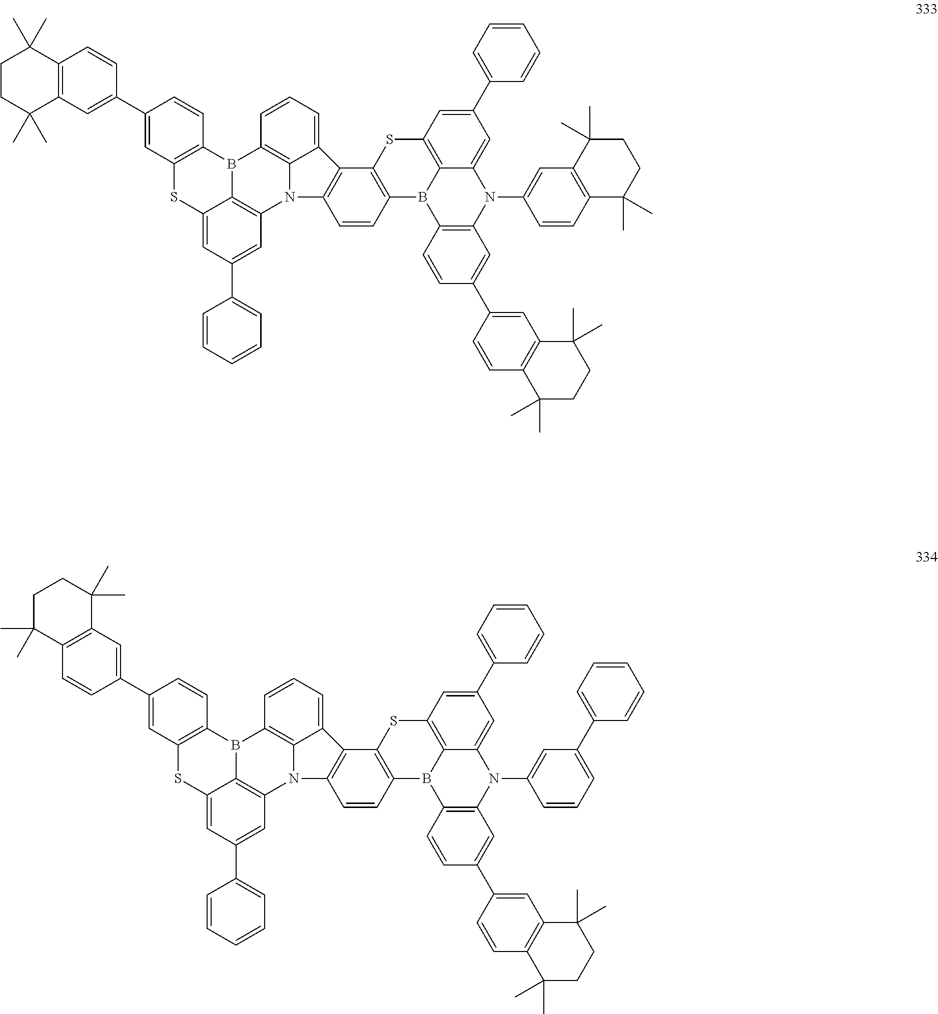 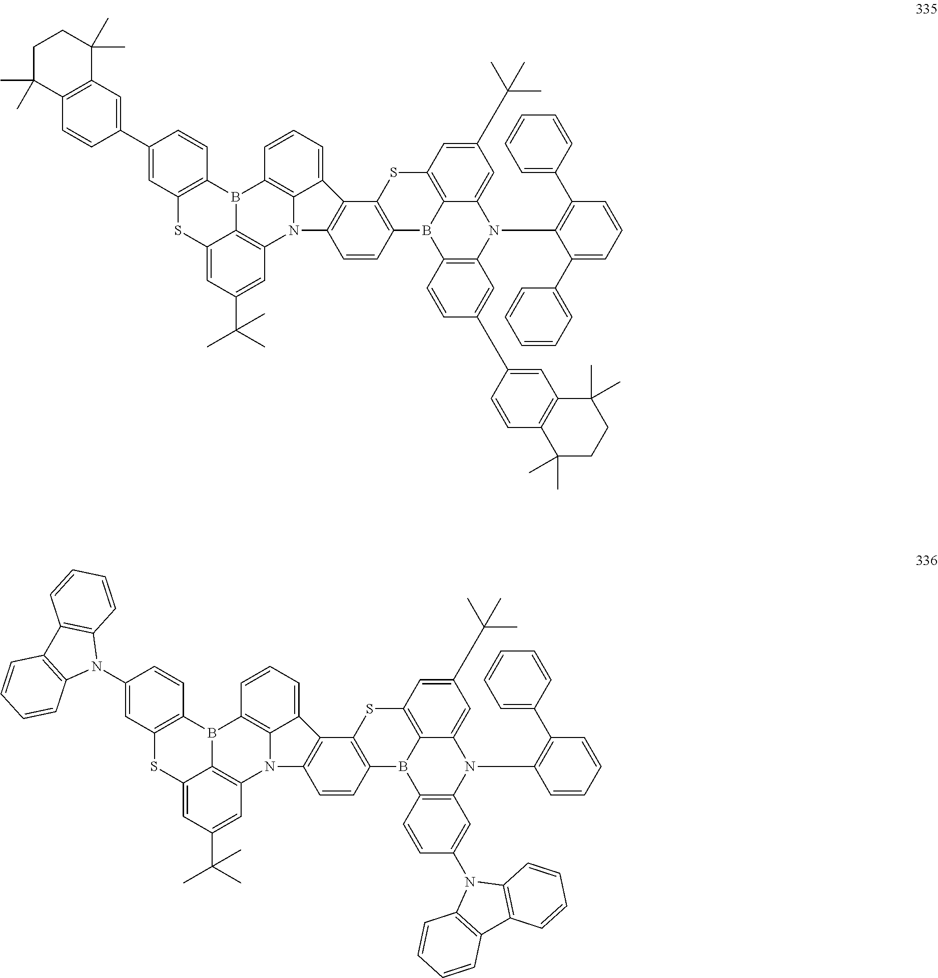 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1S2)c1cccc2c1n3-c1cc(C(C)(C)C)cc3c1B2c1ccc(-c2ccc4c(c2)C(C)(C)CCC4(C)C)cc1S3 ; CC(C)(C)c1cc2c3c(c1)N(c1ccccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 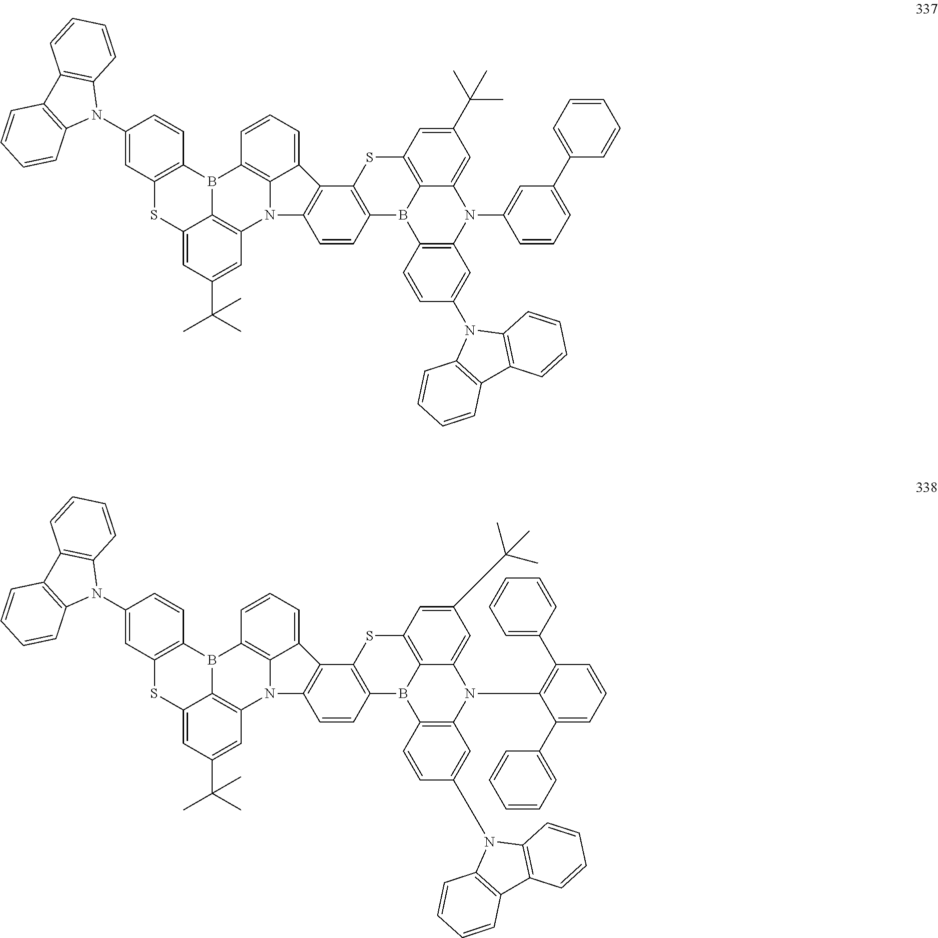 [SMILES: CC(C)(C)c1cc2c3c(c1)N(c1cccc(-c4ccccc4)c1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 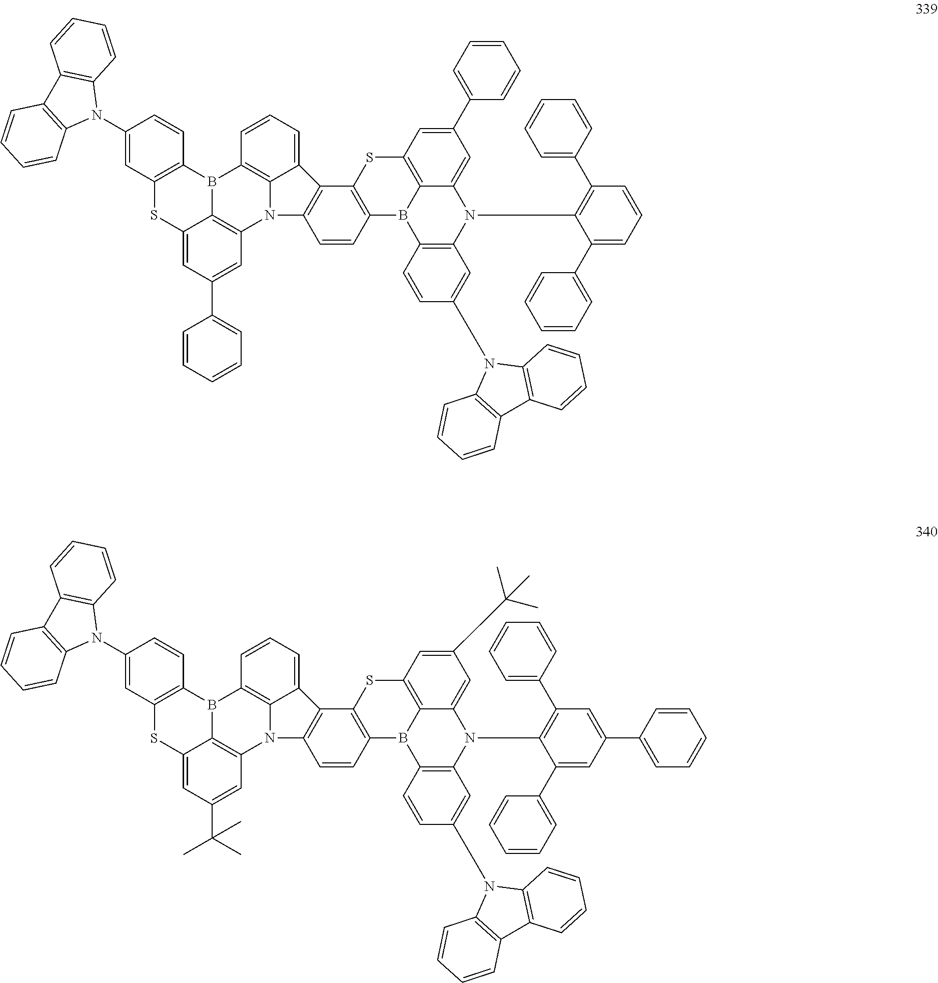 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2S3)c2cccc3c2n4-c2cc(-c4ccccc4)cc4c2B3c2ccc(-n3c5ccccc5c5ccccc53)cc2S4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 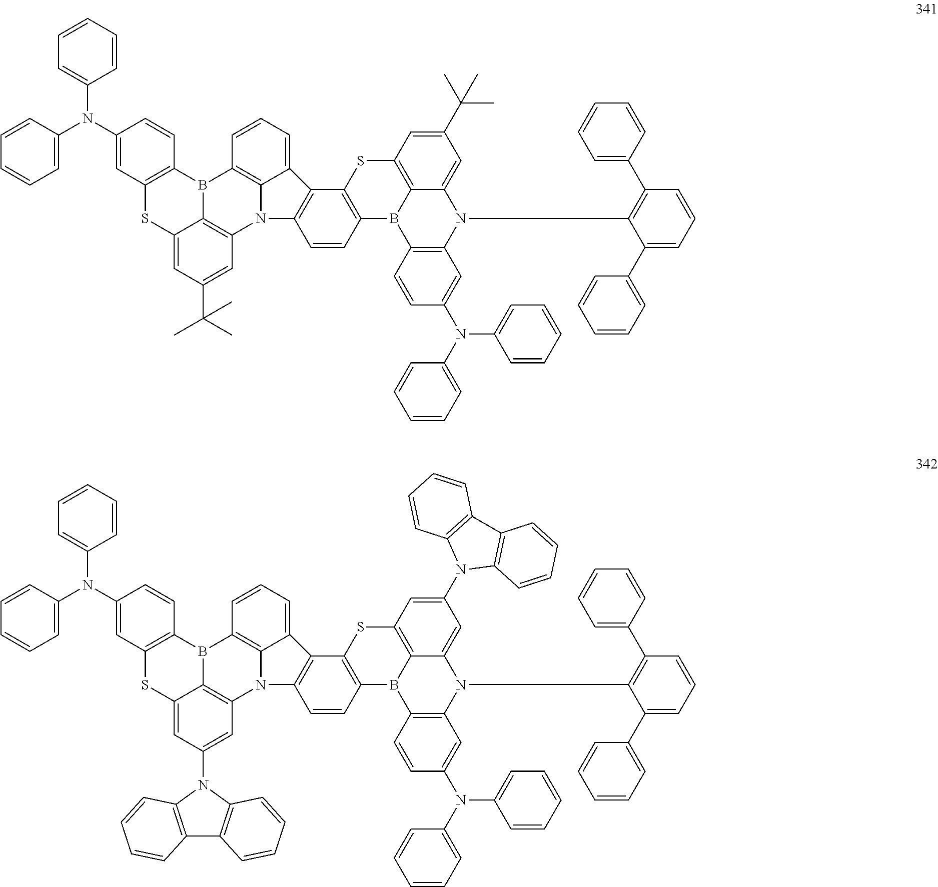 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1S2)c1cccc2c1n3-c1cc(C(C)(C)C)cc3c1B2c1ccc(N(c2ccccc2)c2ccccc2)cc1S3 ; c1ccc(-c2cccc(-c3ccccc3)c2N2c3cc(N(c4ccccc4)c4ccccc4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2S4)cc1] 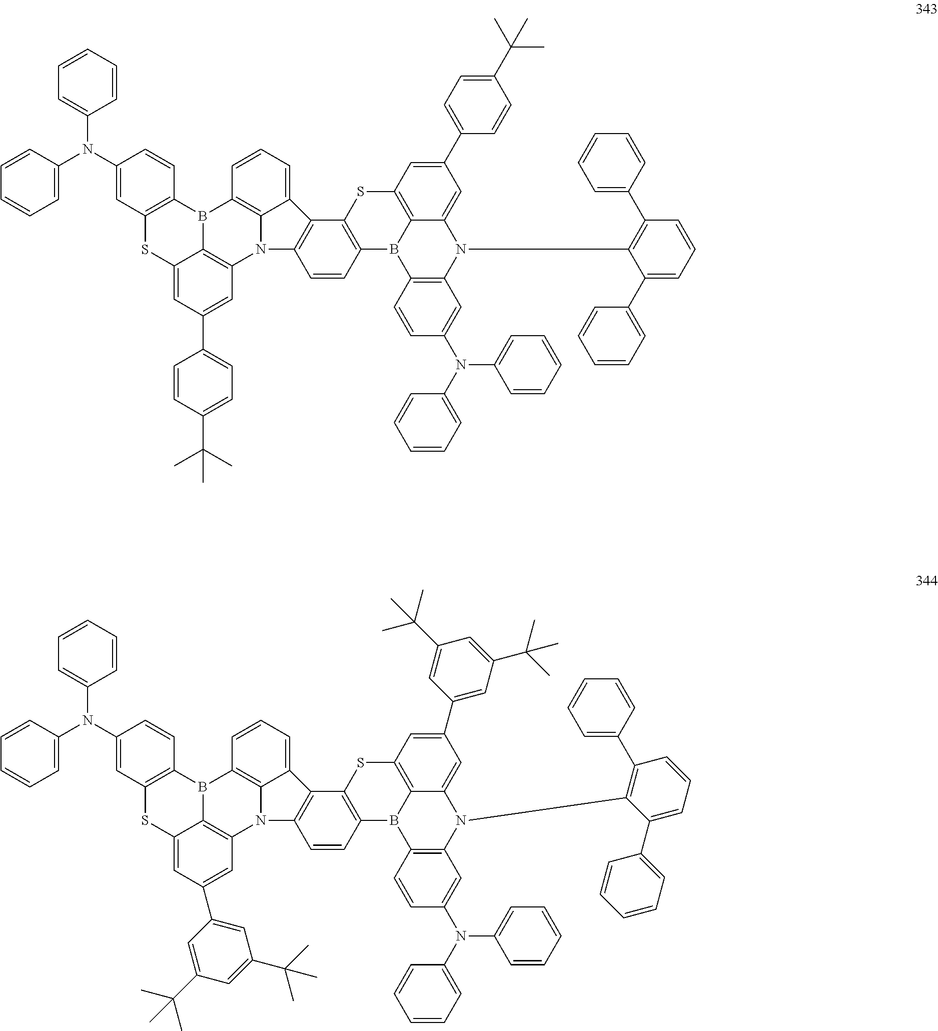 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4ccc(C(C)(C)C)cc4)cc4c2B3c2ccc(N(c3ccccc3)c3ccccc3)cc2S4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4cc(C(C)(C)C)cc(C(C)(C)C)c4)cc4c2B3c2ccc(N(c3ccccc3)c3ccccc3)cc2S4)cc(C(C)(C)C)c1] 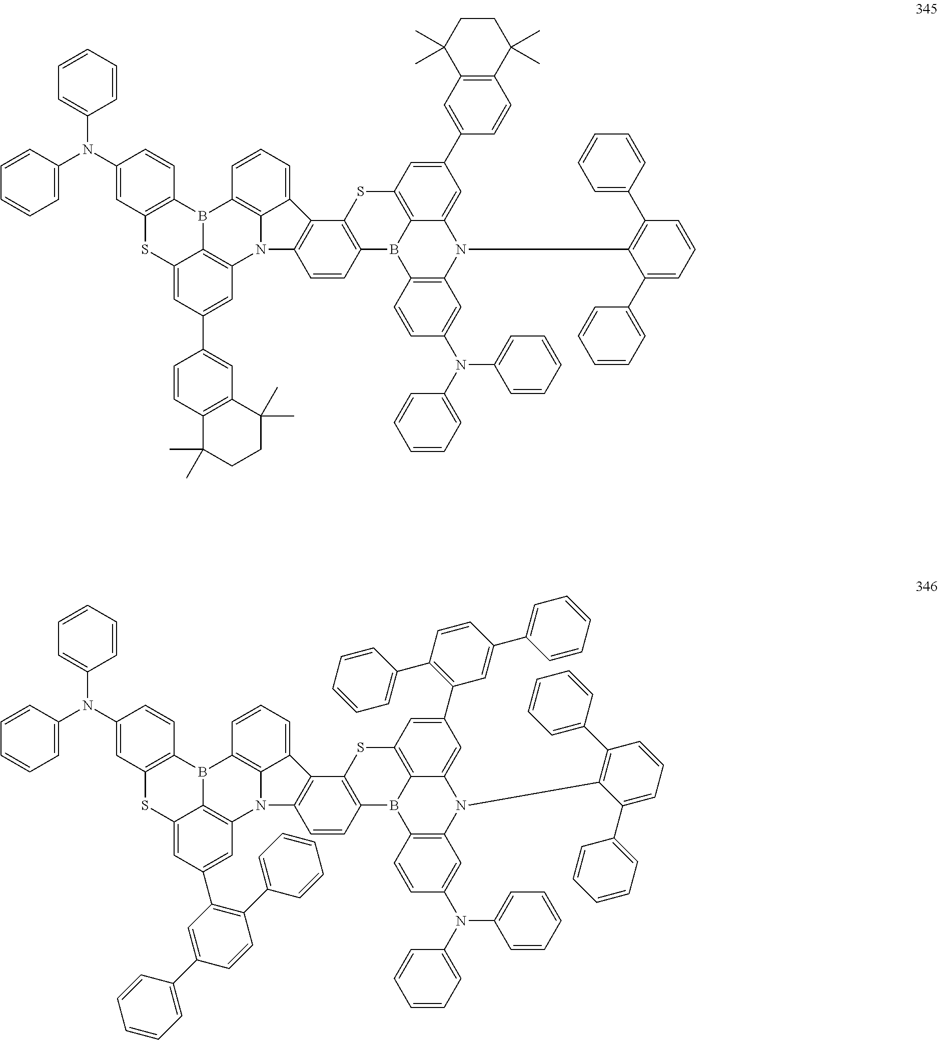 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5ccc6c(c5)C(C)(C)CCC6(C)C)cc5c3B4c3ccc(N(c4ccccc4)c4ccccc4)cc3S5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5cc(-c6ccccc6)ccc5-c5ccccc5)cc5c3B4c3ccc(N(c4ccccc4)c4ccccc4)cc3S5)c2)cc1] 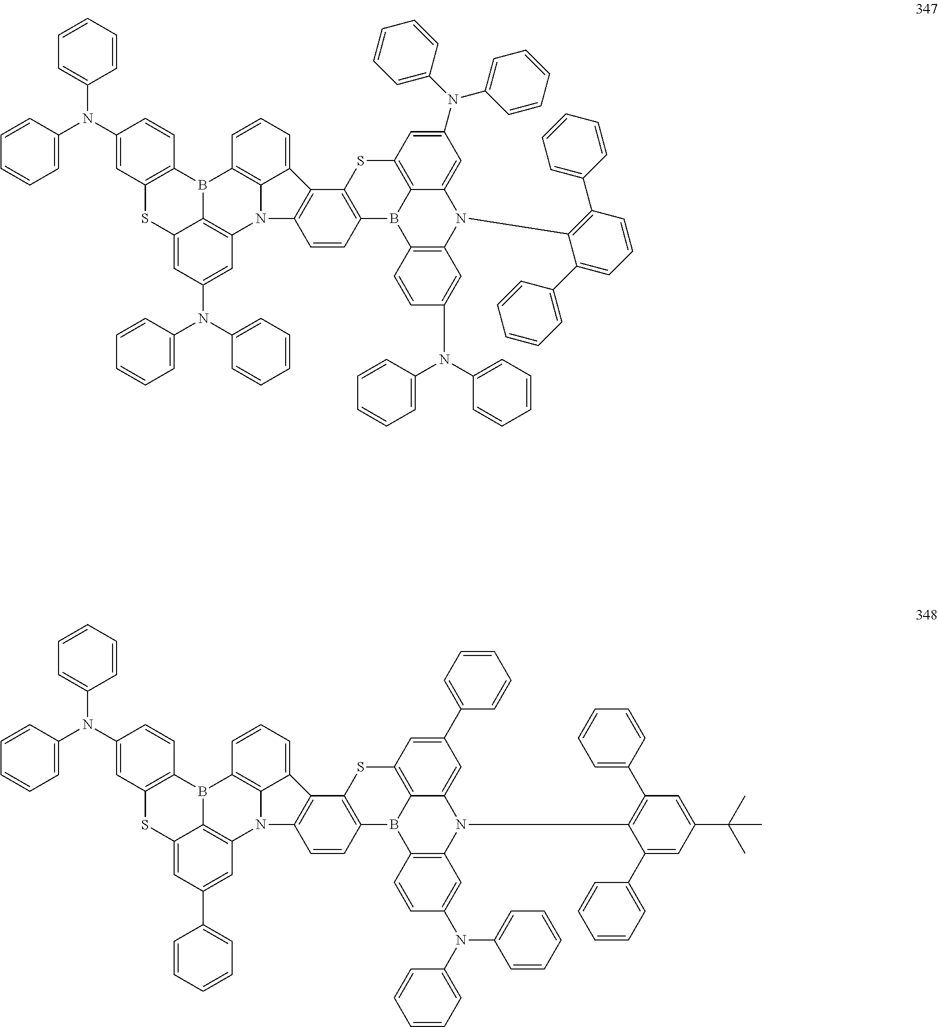 [SMILES: c1ccc(-c2cccc(-c3ccccc3)c2N2c3cc(N(c4ccccc4)c4ccccc4)ccc3B3c4ccc5c(c4Sc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2S4)cc1 ; CC(C)(C)c1cc(-c2ccccc2)c(N2c3cc(N(c4ccccc4)c4ccccc4)ccc3B3c4ccc5c(c4Sc4cc(-c6ccccc6)cc2c43)c2cccc3c2n5-c2cc(-c4ccccc4)cc4c2B3c2ccc(N(c3ccccc3)c3ccccc3)cc2S4)c(-c2ccccc2)c1] 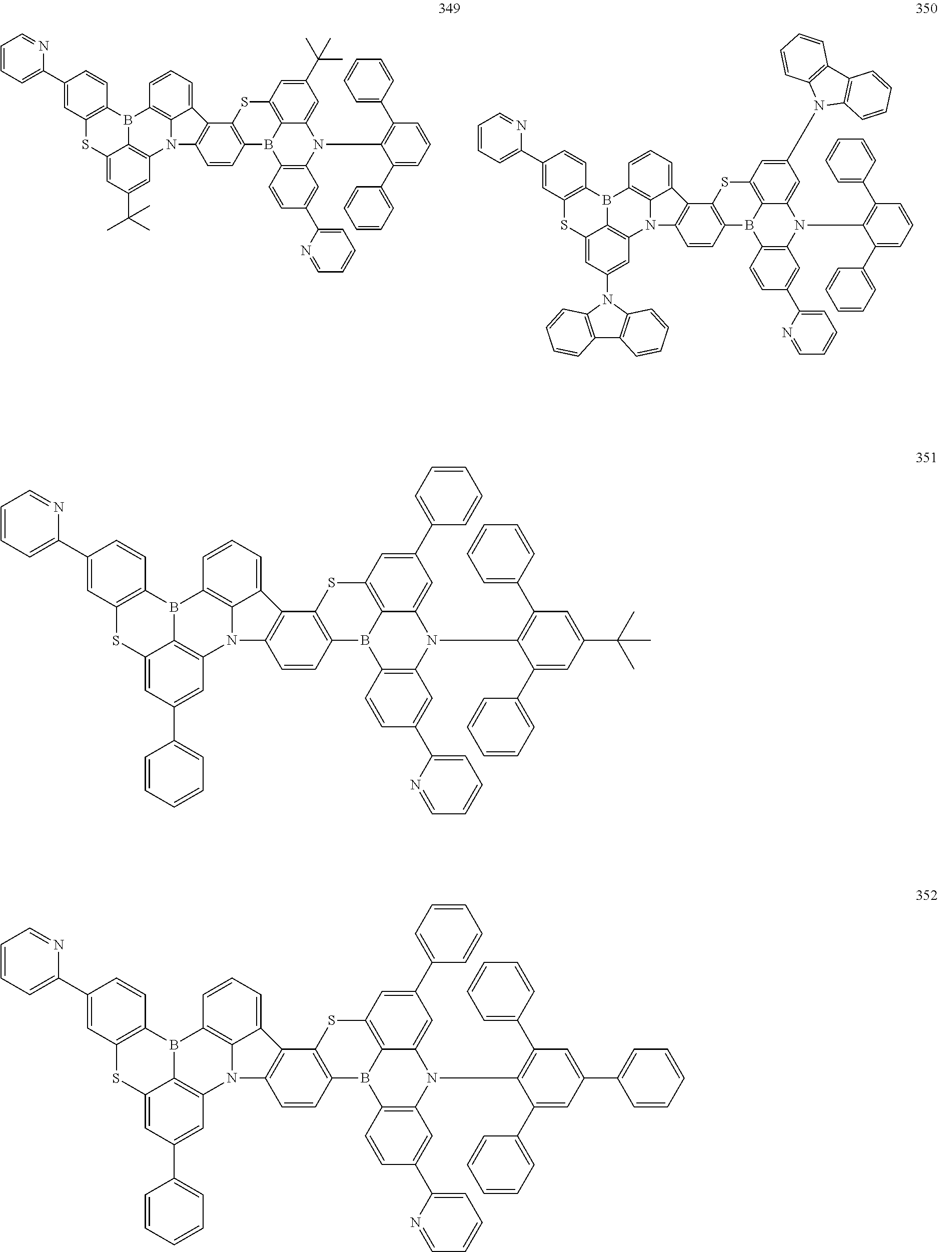 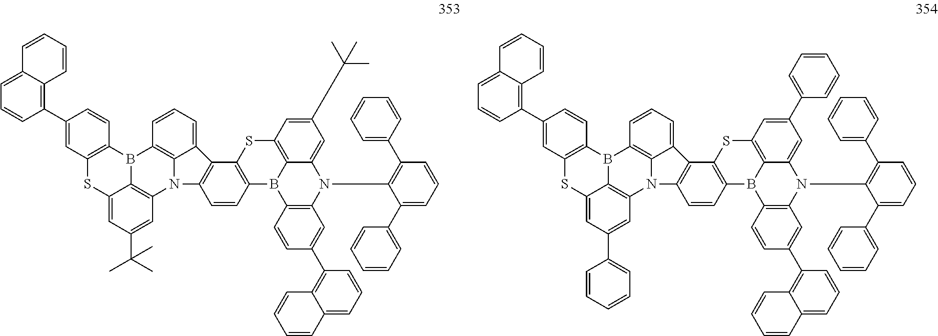 [SMILES: CC(C)(C)c1cc2c3c(c1)N(c1c(-c4ccccc4)cccc1-c1ccccc1)c1cc(-c4cccc5ccccc45)ccc1B3c1ccc3c(c1S2)c1cccc2c1n3-c1cc(C(C)(C)C)cc3c1B2c1ccc(-c2cccc4ccccc24)cc1S3 ; c1ccc(-c2cc3c4c(c2)N(c2c(-c5ccccc5)cccc2-c2ccccc2)c2cc(-c5cccc6ccccc56)ccc2B4c2ccc4c(c2S3)c2cccc3c2n4-c2cc(-c4ccccc4)cc4c2B3c2ccc(-c3cccc5ccccc35)cc2S4)cc1] 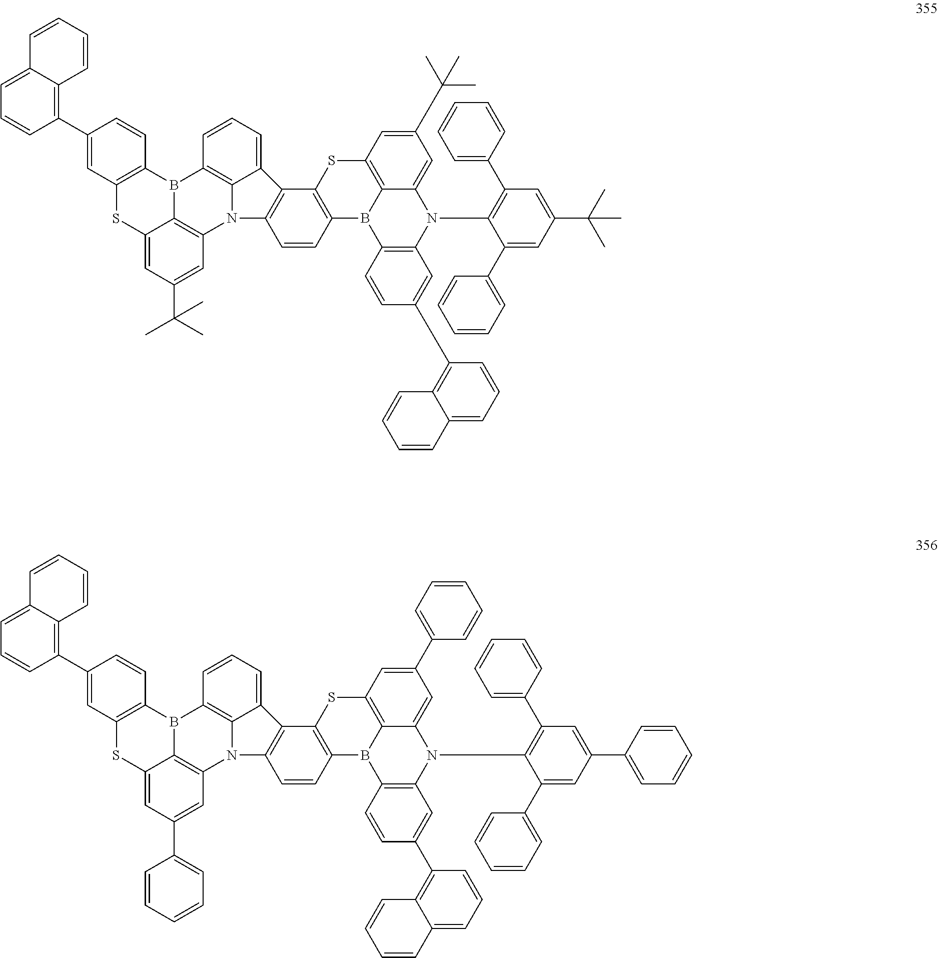 [SMILES: CC(C)(C)c1cc(-c2ccccc2)c(N2c3cc(-c4cccc5ccccc45)ccc3B3c4ccc5c(c4Sc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Sc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1] 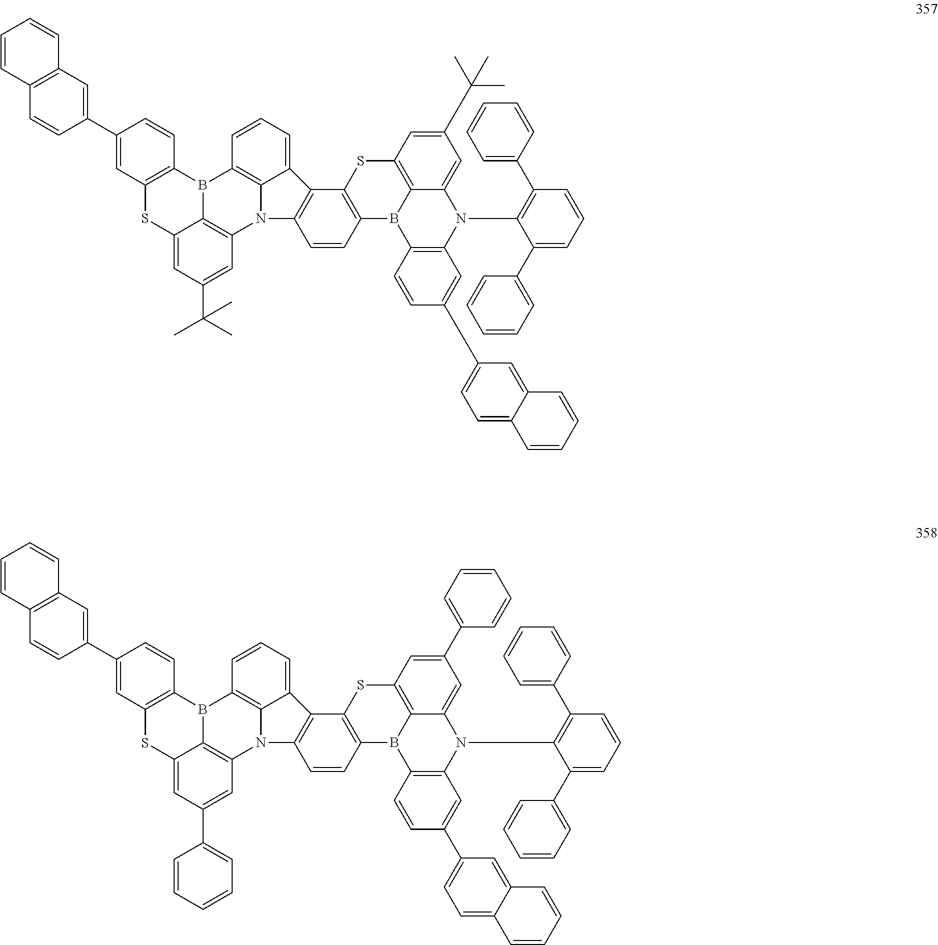 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1S2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2S3)c2cccc3c2n4-c2cc(-c4ccccc4)cc4c2B3c2ccc(-c3ccc5ccccc5c3)cc2S4)cc1] 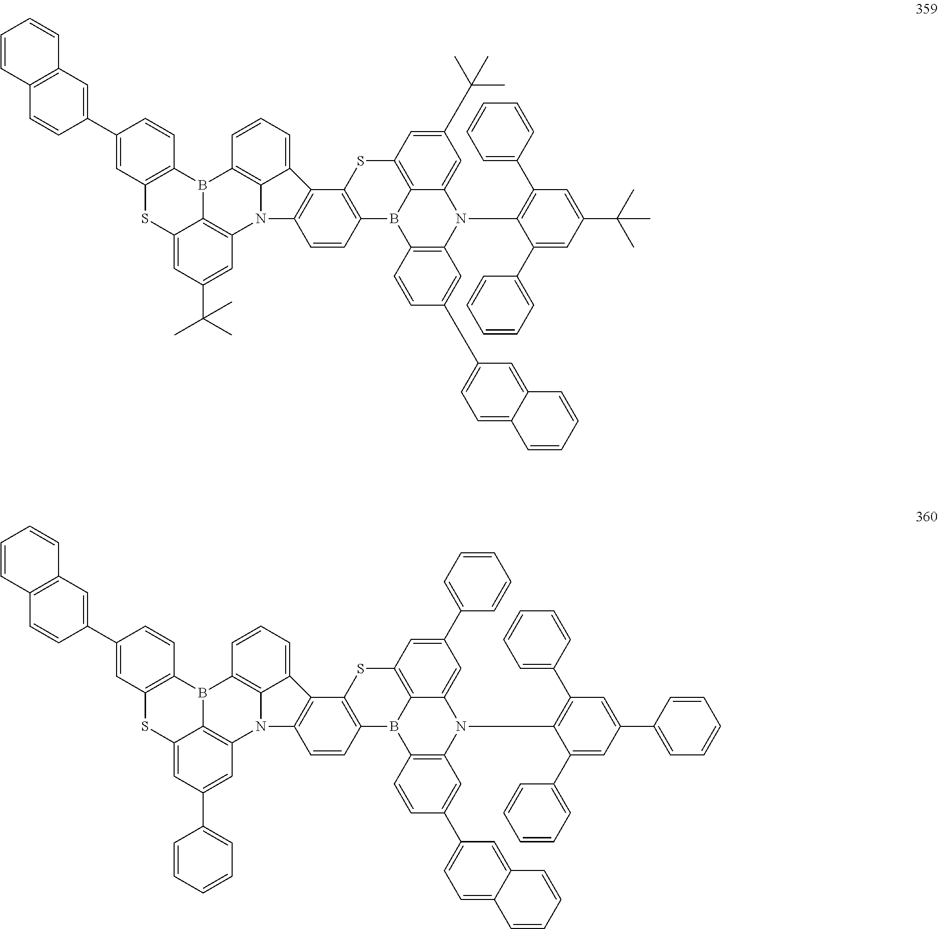 [SMILES: CC(C)(C)c1cc(-c2ccccc2)c(N2c3cc(-c4ccc5ccccc5c4)ccc3B3c4ccc5c(c4Sc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Sc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1] 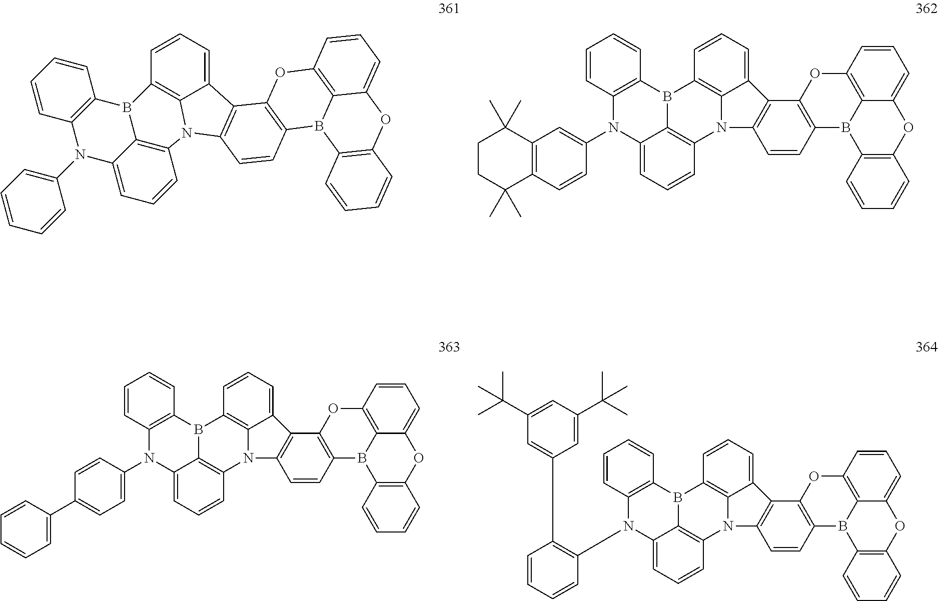 [SMILES: c1ccc(N2c3ccccc3B3c4c2cccc4-n2c4ccc5c(c4c4cccc3c42)Oc2cccc3c2B5c2ccccc2O3)cc1 ; CC1(C)CCC(C)(C)c2cc(N3c4ccccc4B4c5c3cccc5-n3c5ccc6c(c5c5cccc4c53)Oc3cccc4c3B6c3ccccc3O4)ccc21 ; c1ccc(-c2ccc(N3c4ccccc4B4c5c3cccc5-n3c5ccc6c(c5c5cccc4c53)Oc3cccc4c3B6c3ccccc3O4)cc2)cc1 ; CC(C)(C)c1cc(-c2ccccc2N2c3ccccc3B3c4c2cccc4-n2c4ccc5c(c4c4cccc3c42)Oc2cccc3c2B5c2ccccc2O3)cc(C(C)(C)C)c1] 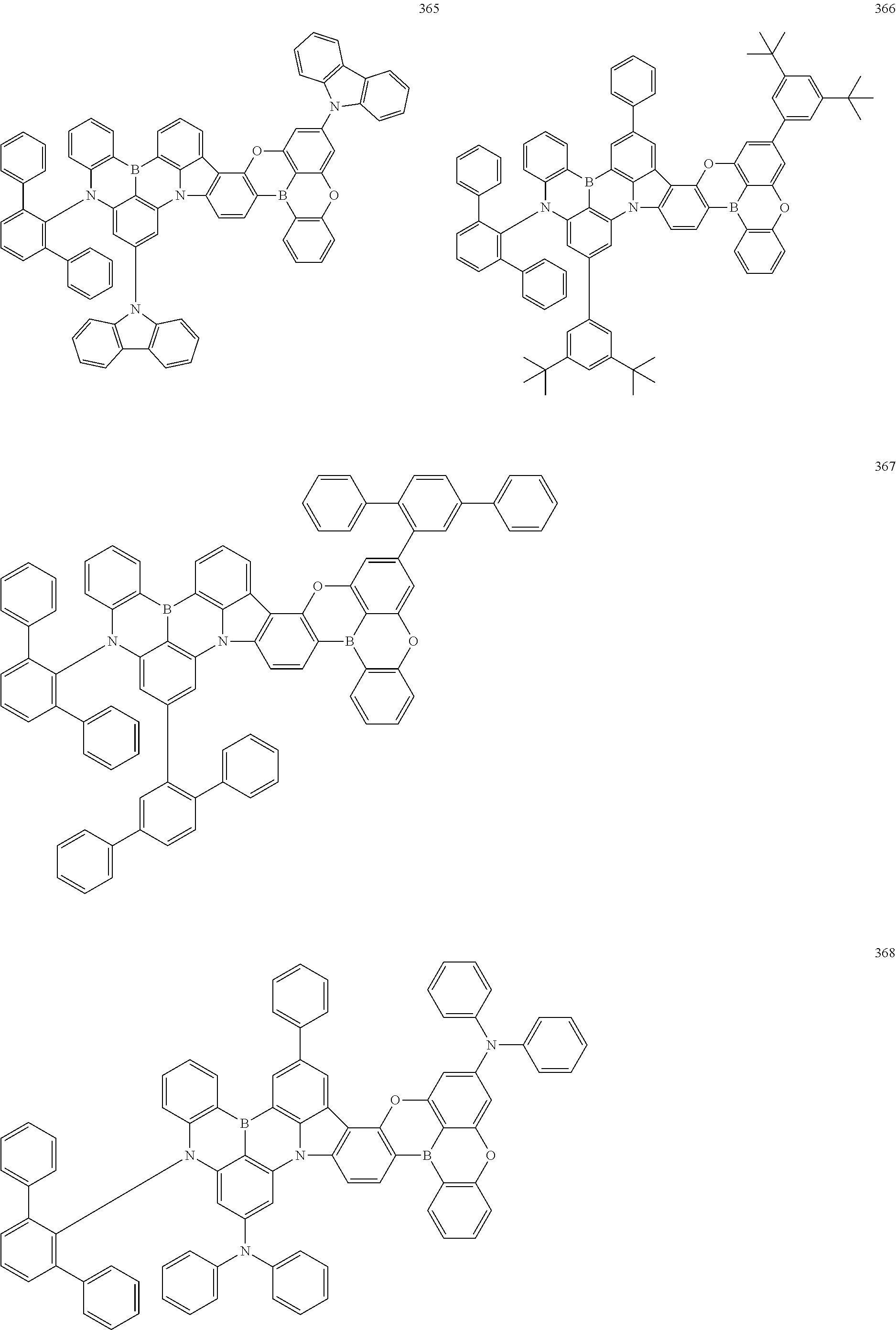 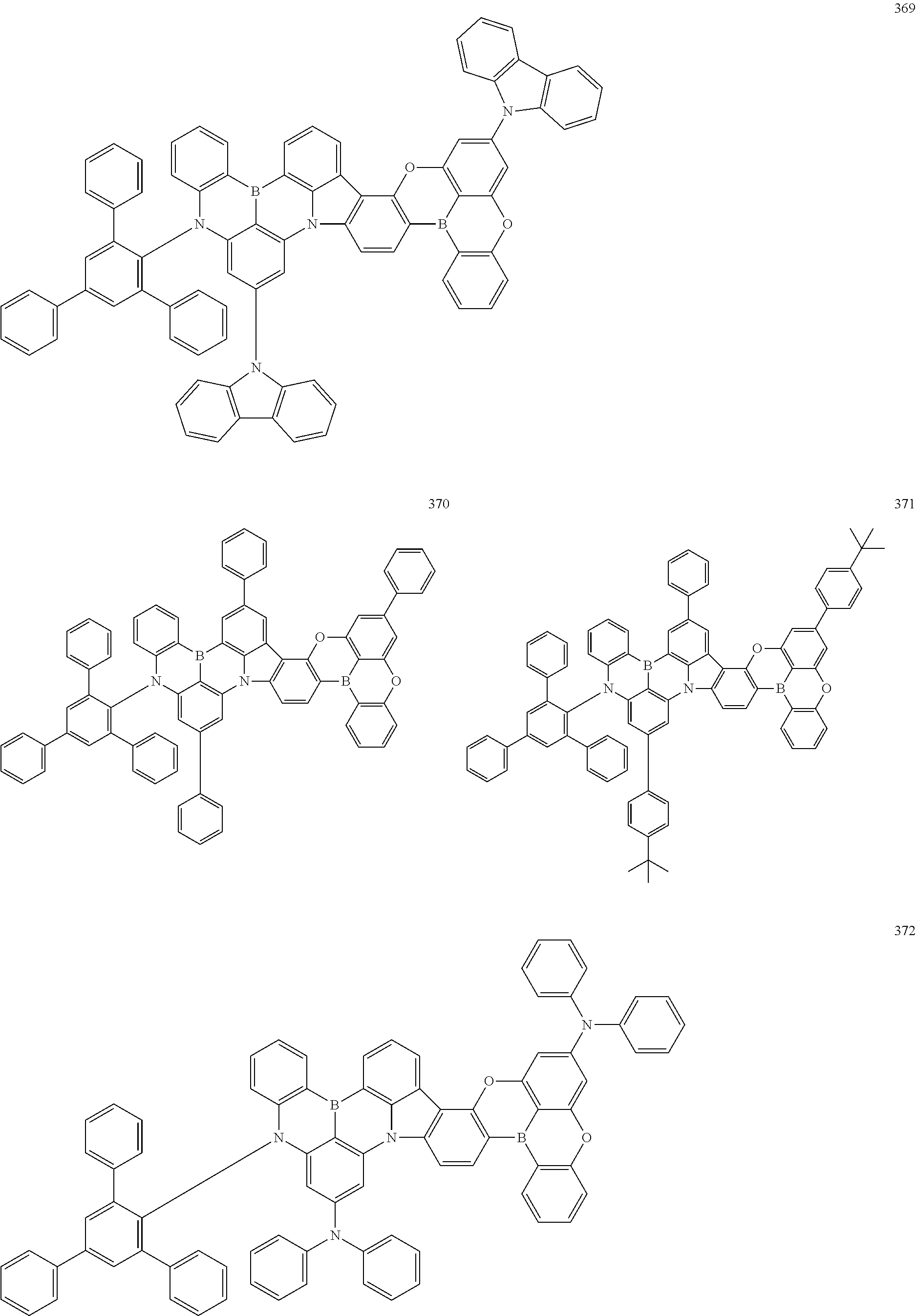 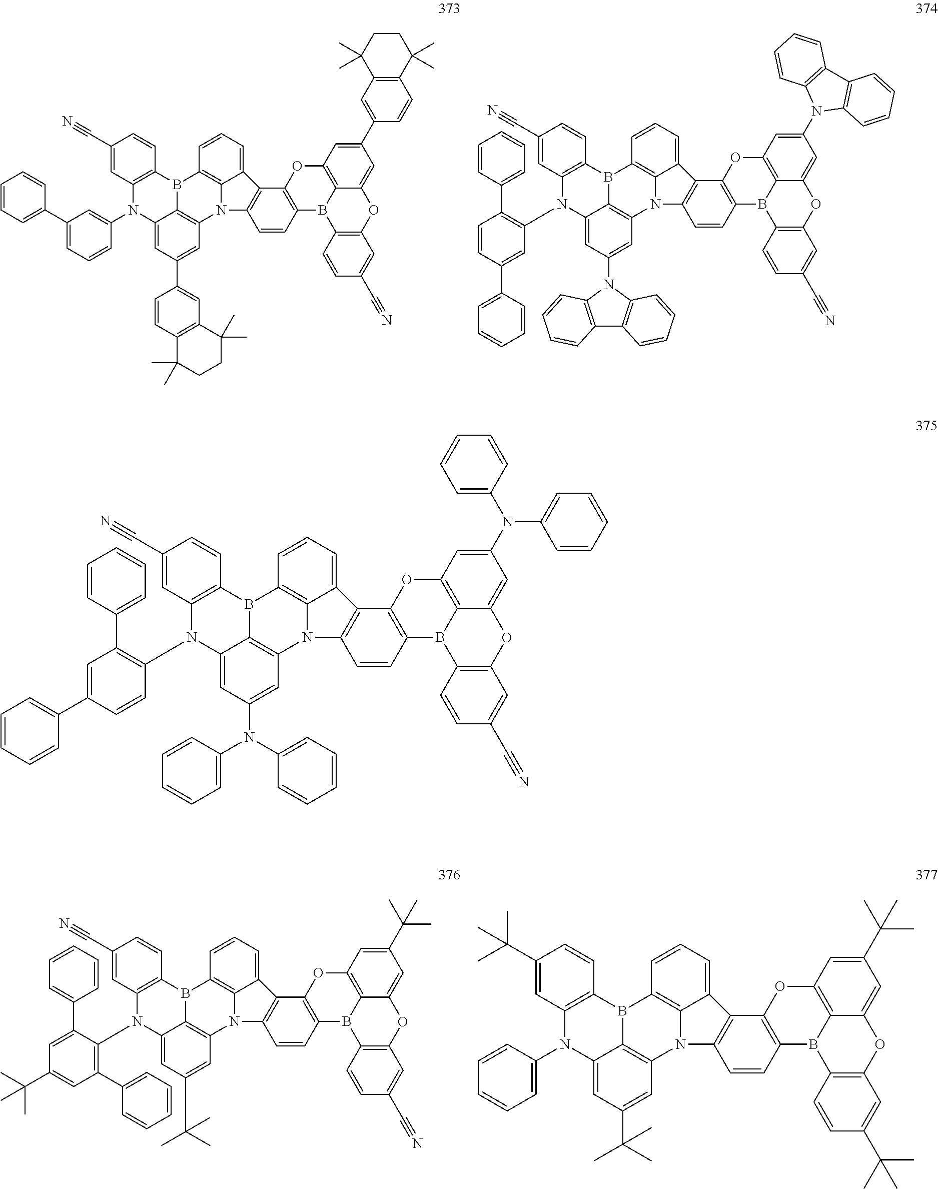 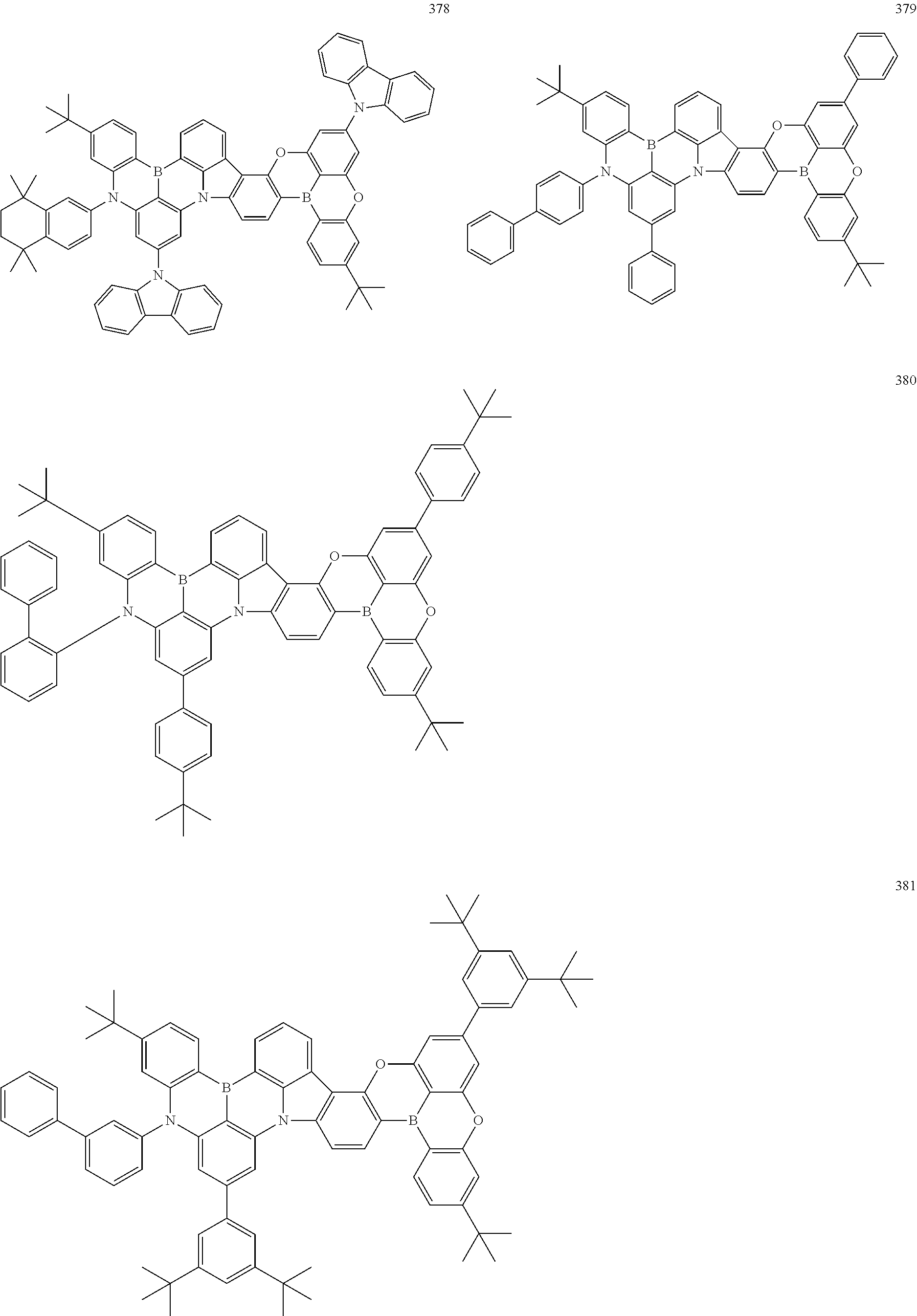 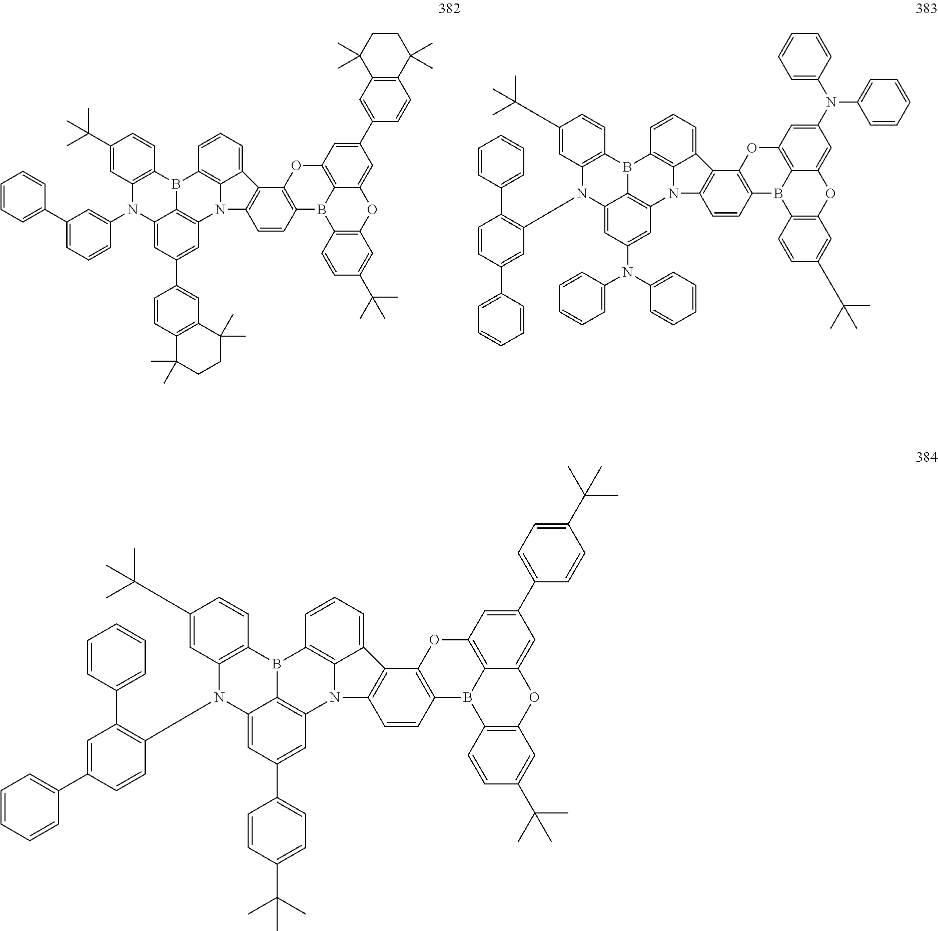 [SMILES: CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1N2c1cccc(-c2ccccc2)c1 ; CC(C)(C)c1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2N5c2ccc(-c5ccccc5)cc2-c2ccccc2)B4c2ccc(C(C)(C)C)cc2O3)cc1] 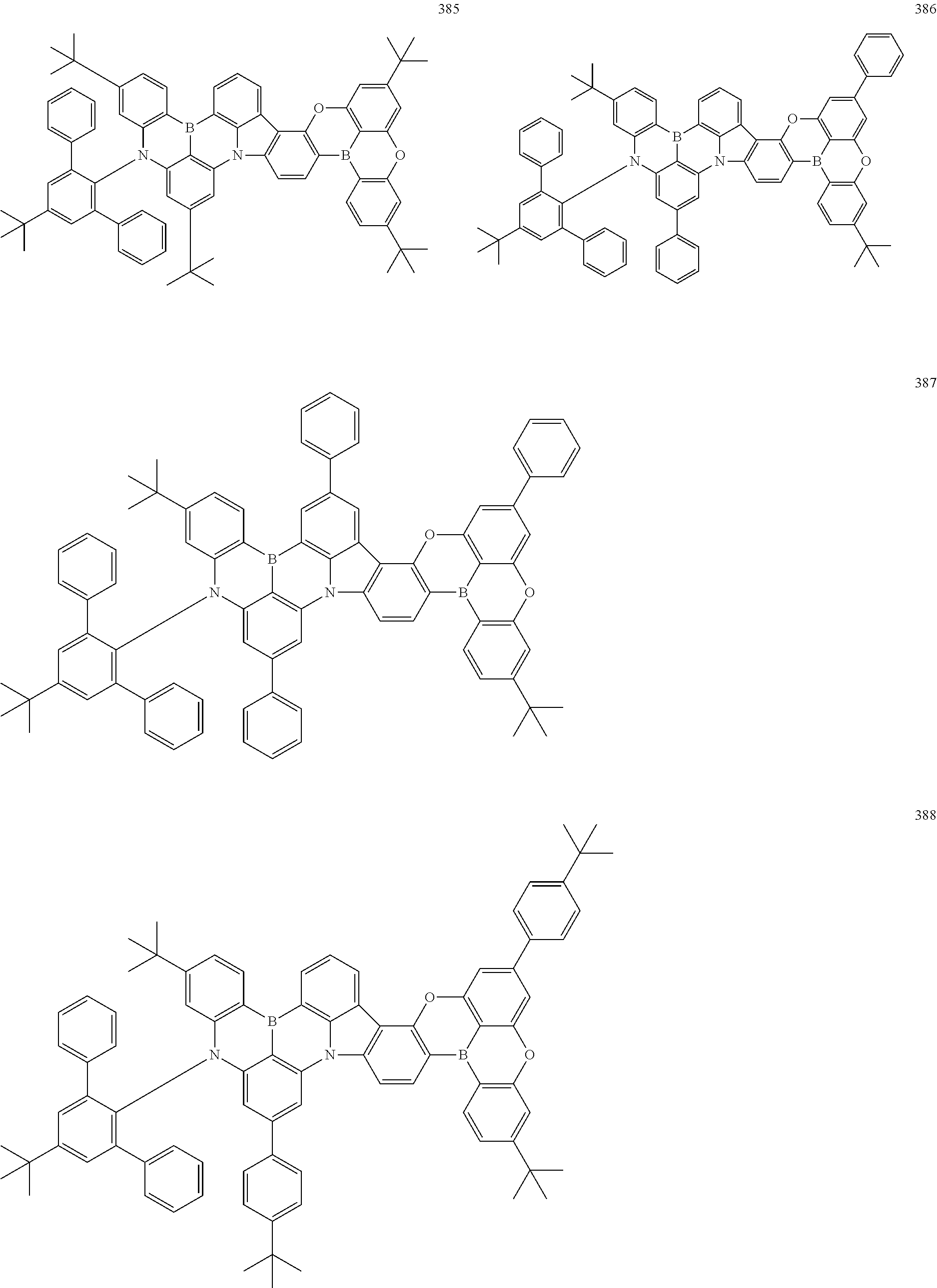 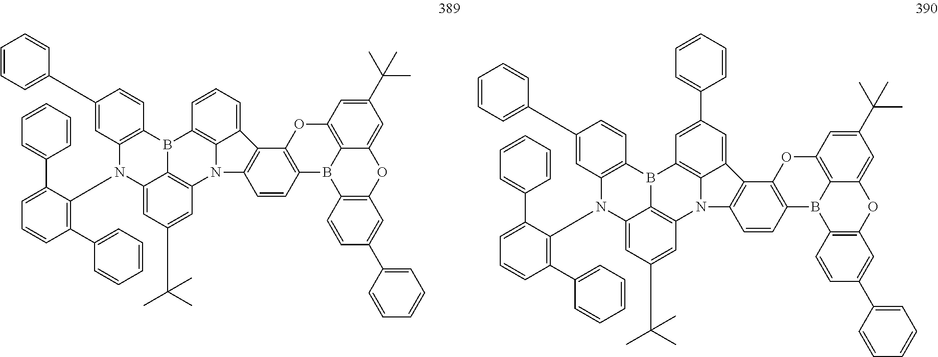 [SMILES: CC(C)(C)c1cc2c3c(c1)Oc1c(ccc4c1c1cccc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2] 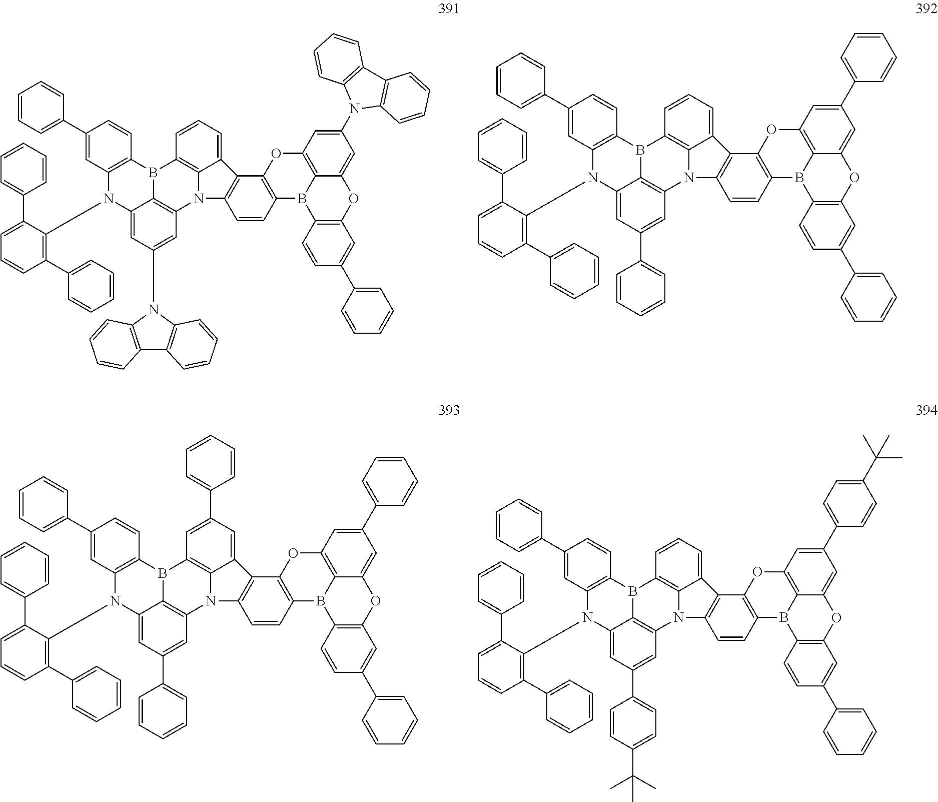 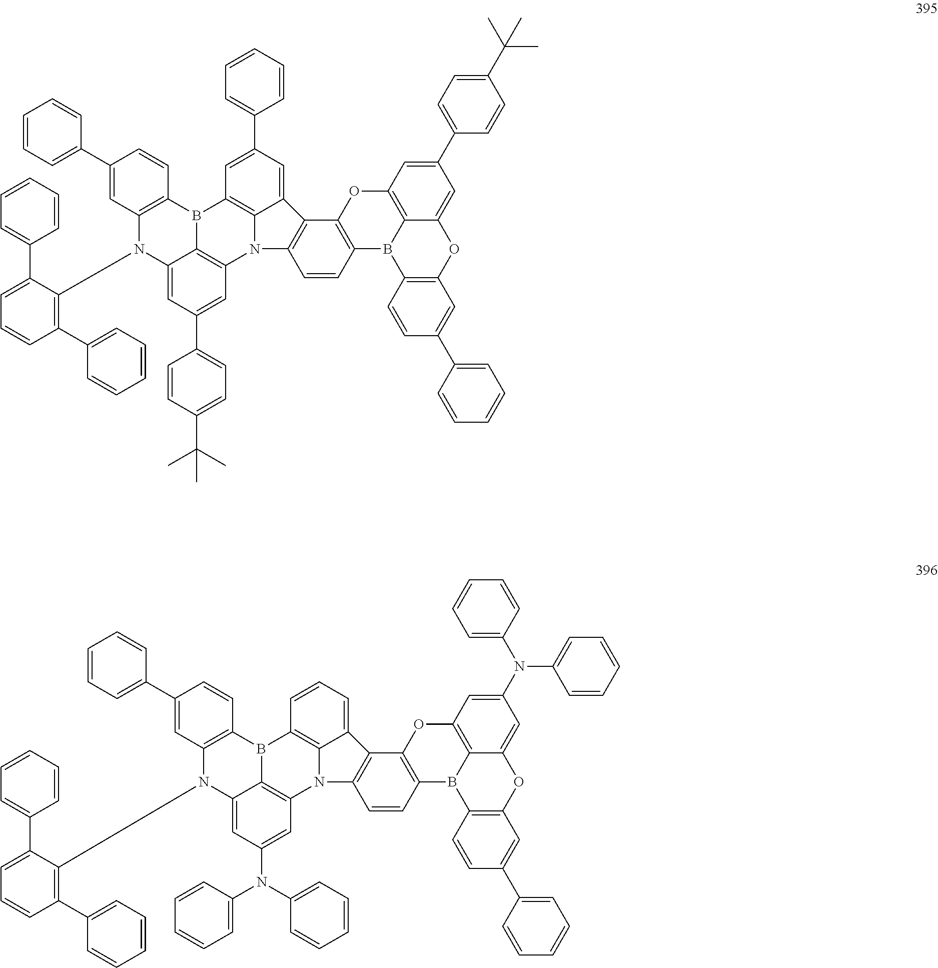 [SMILES: CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2O3)cc1 ; c1ccc(-c2ccc3c(c2)Oc2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 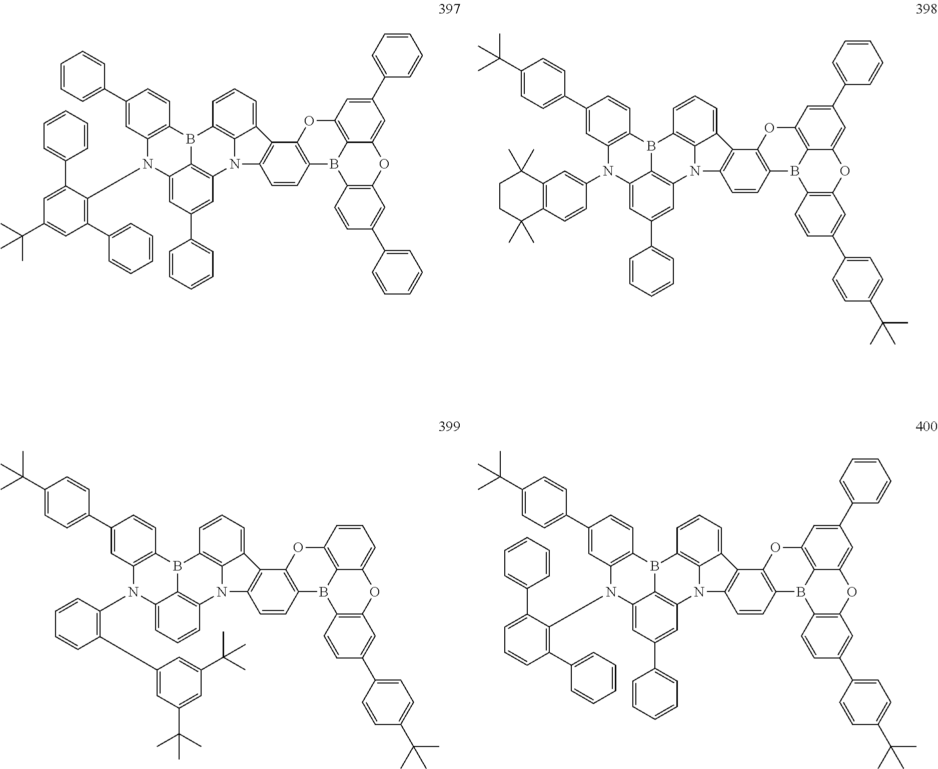 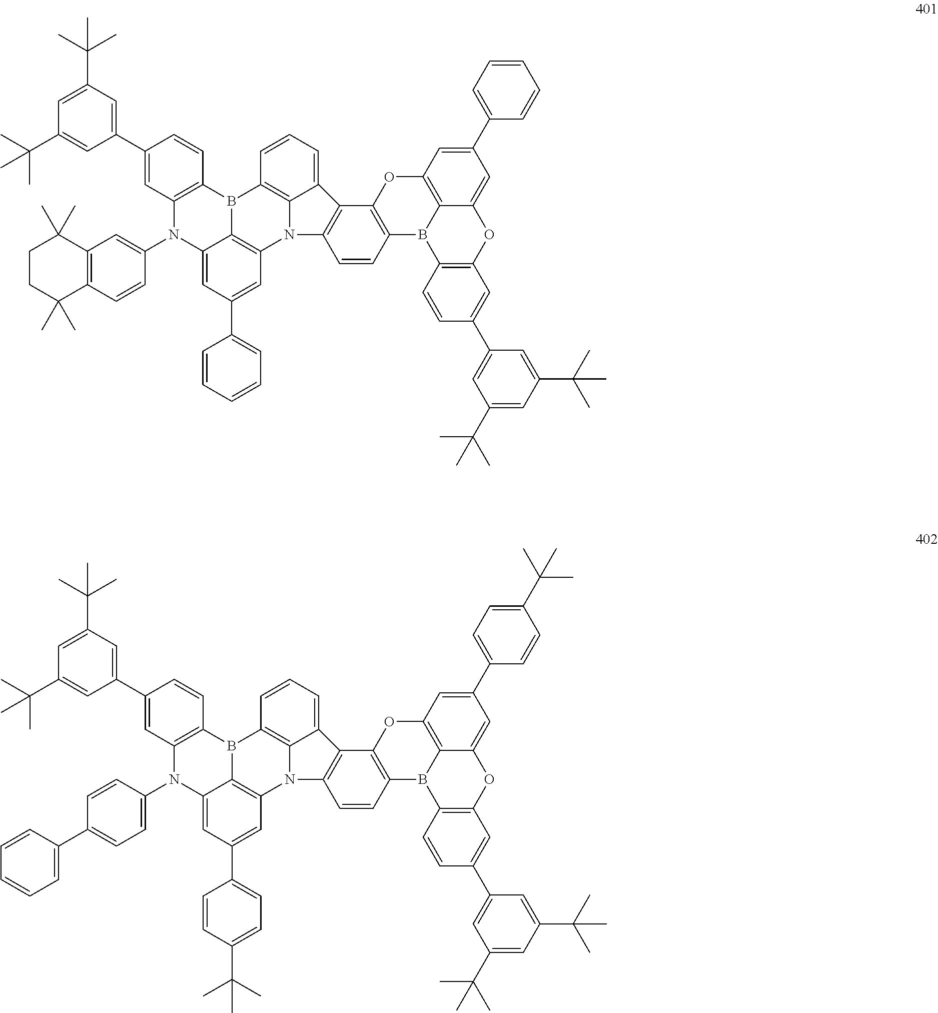 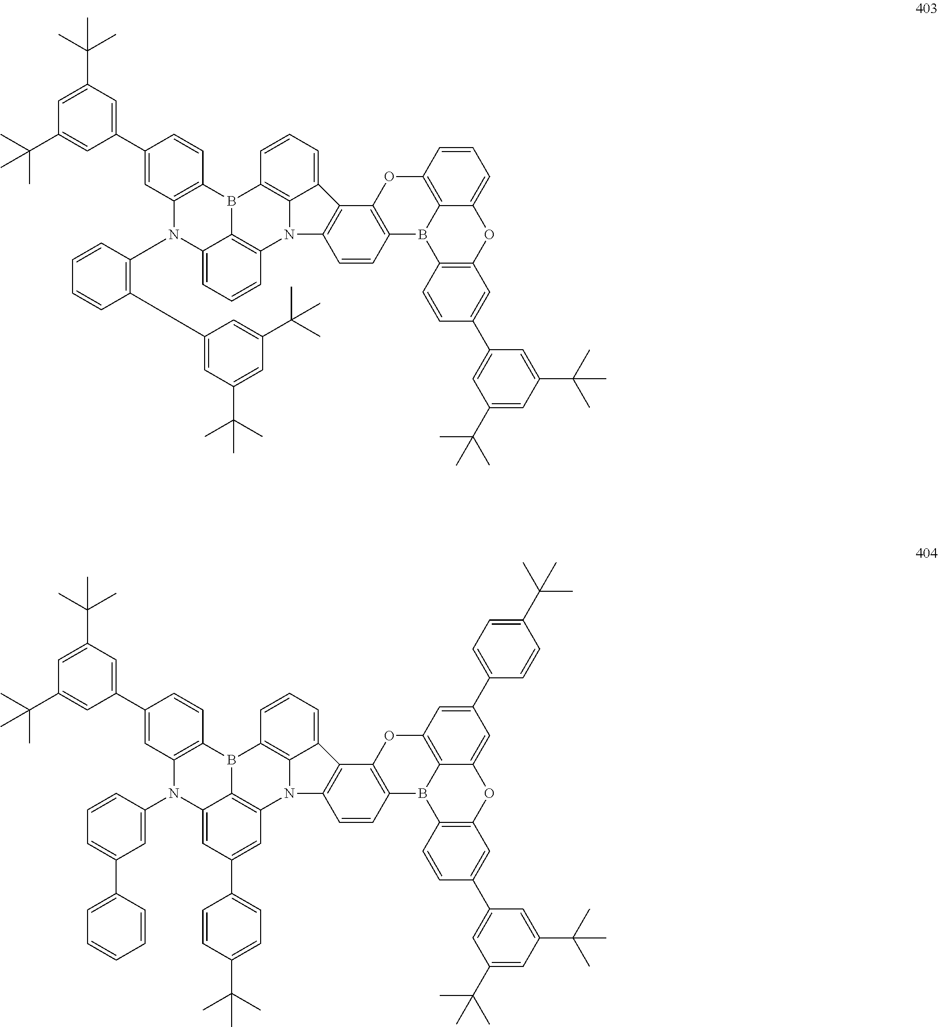 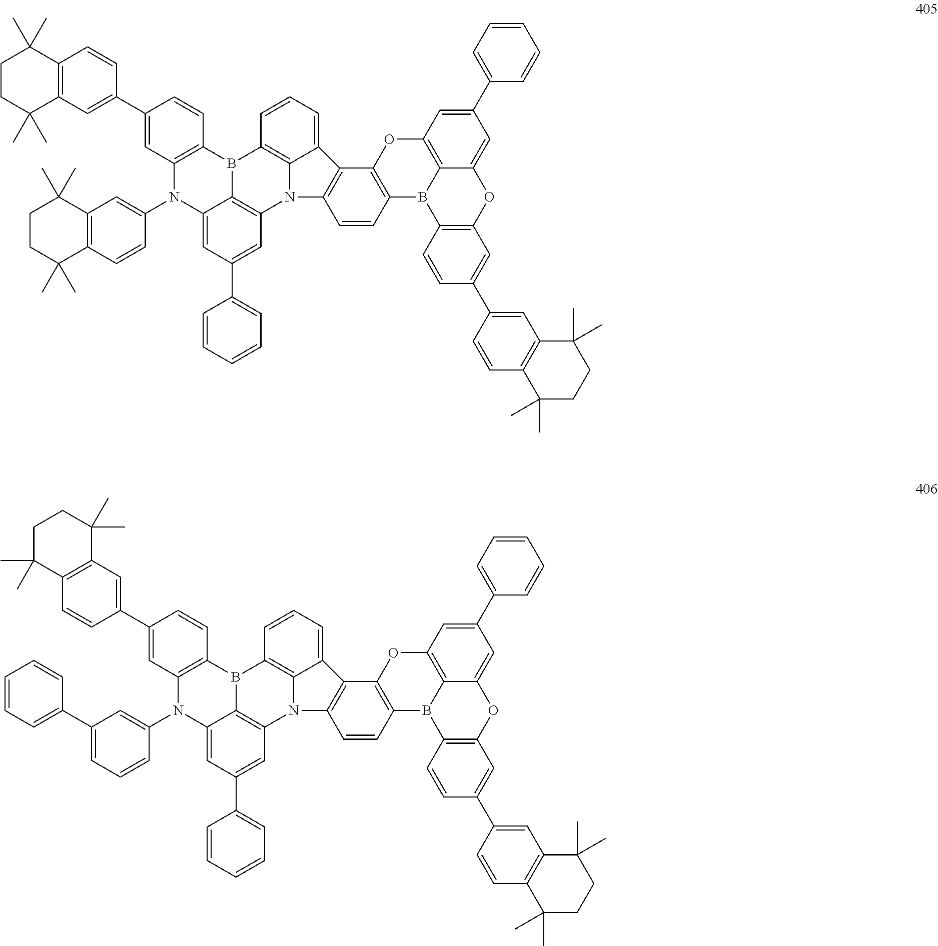 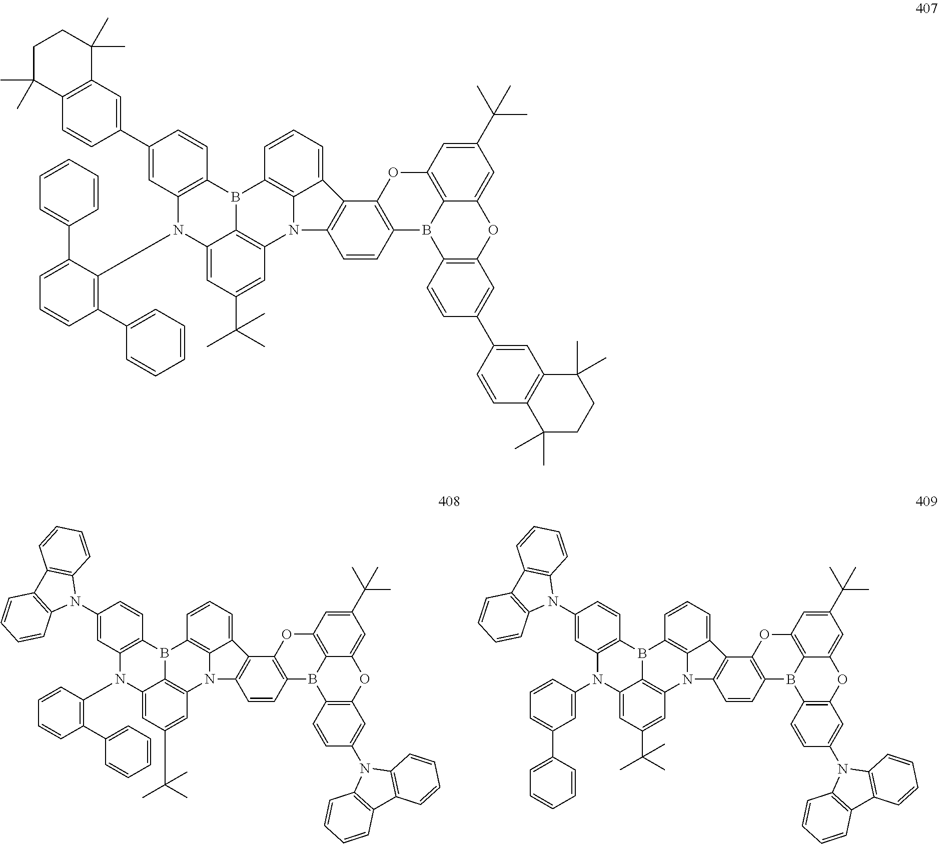 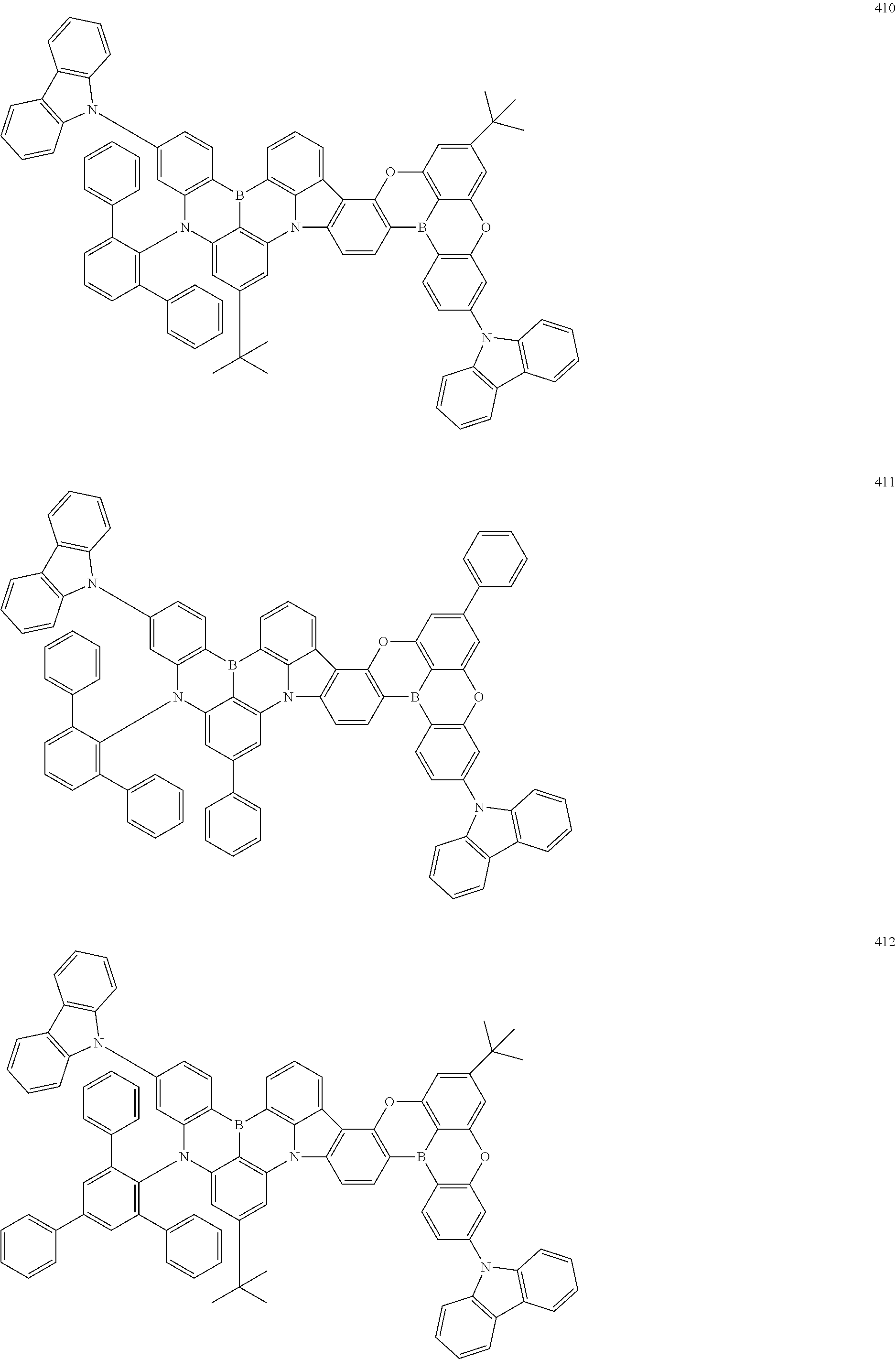 [SMILES: CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1O2 ; c1ccc(-c2cc3c4c(c2)Oc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2O3)cc1 ; CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1O2] 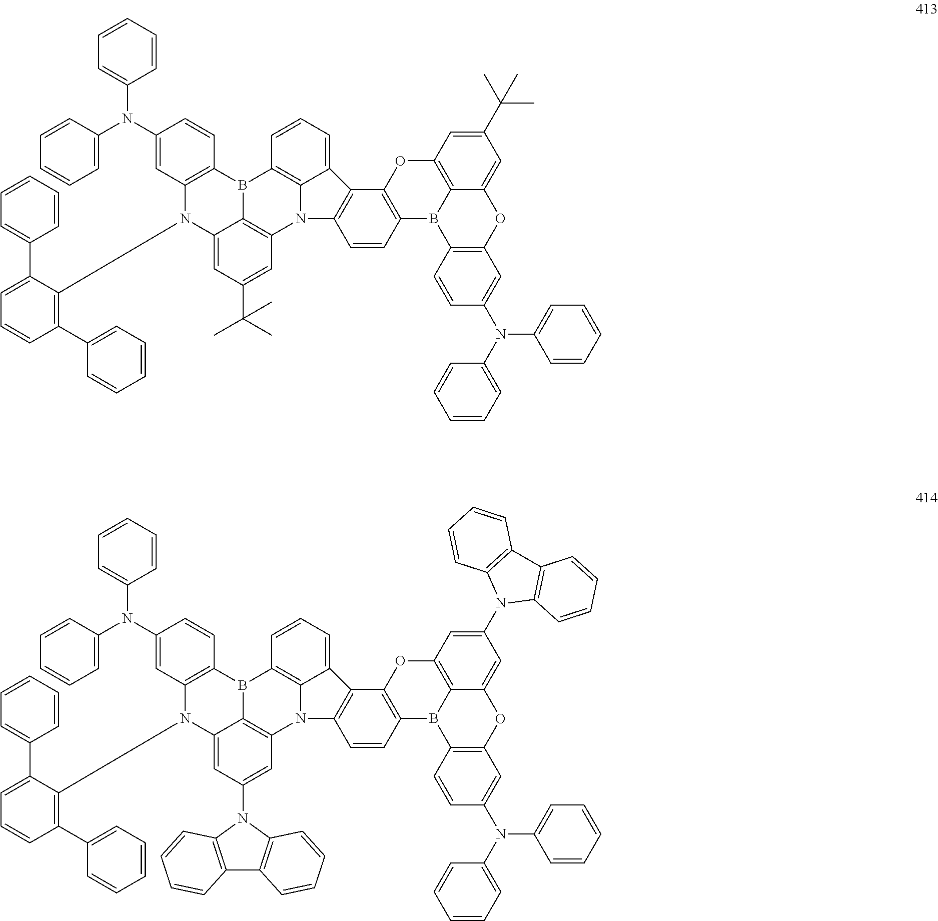 [SMILES: CC(C)(C)c1cc2c3c(c1)Oc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1O2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Oc2cc(-n3c4ccccc4c4ccccc43)cc3c2B5c2ccc(N(c4ccccc4)c4ccccc4)cc2O3)cc1] 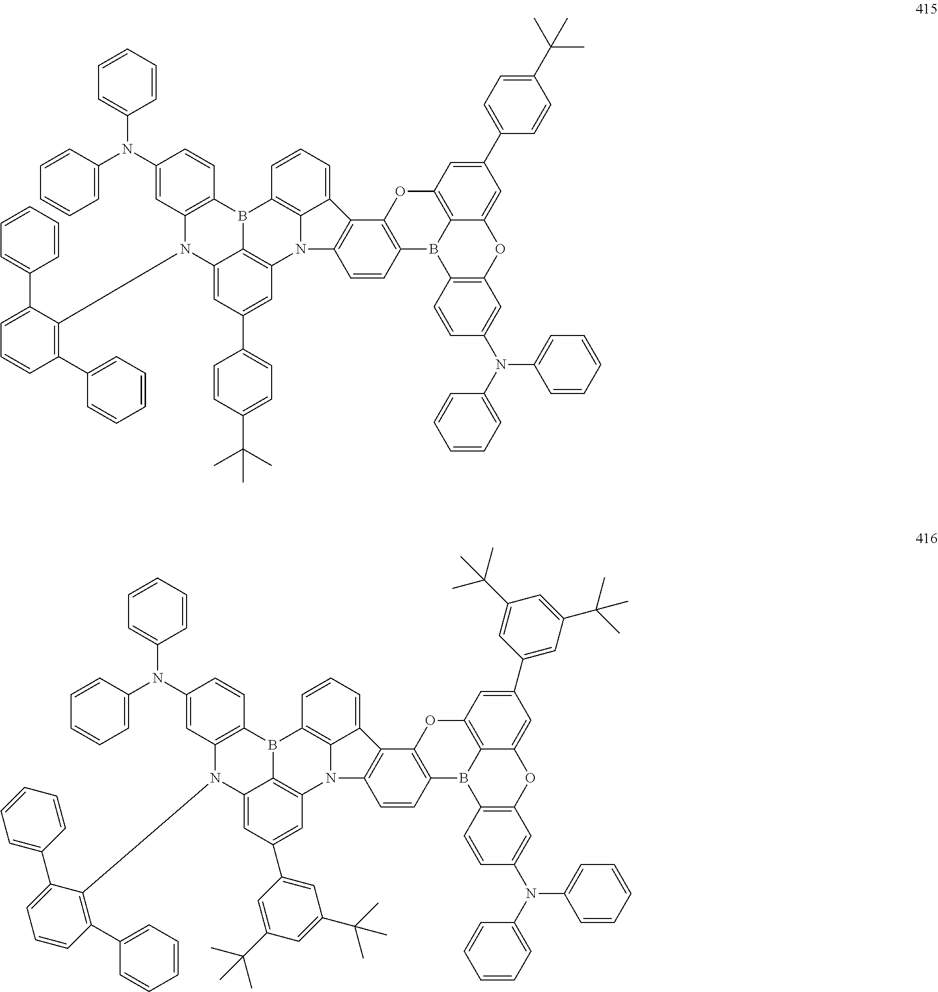 [SMILES: CC(C)(C)c1ccc(-c2cc3c4c(c2)Oc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc1 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc(C(C)(C)C)c1] 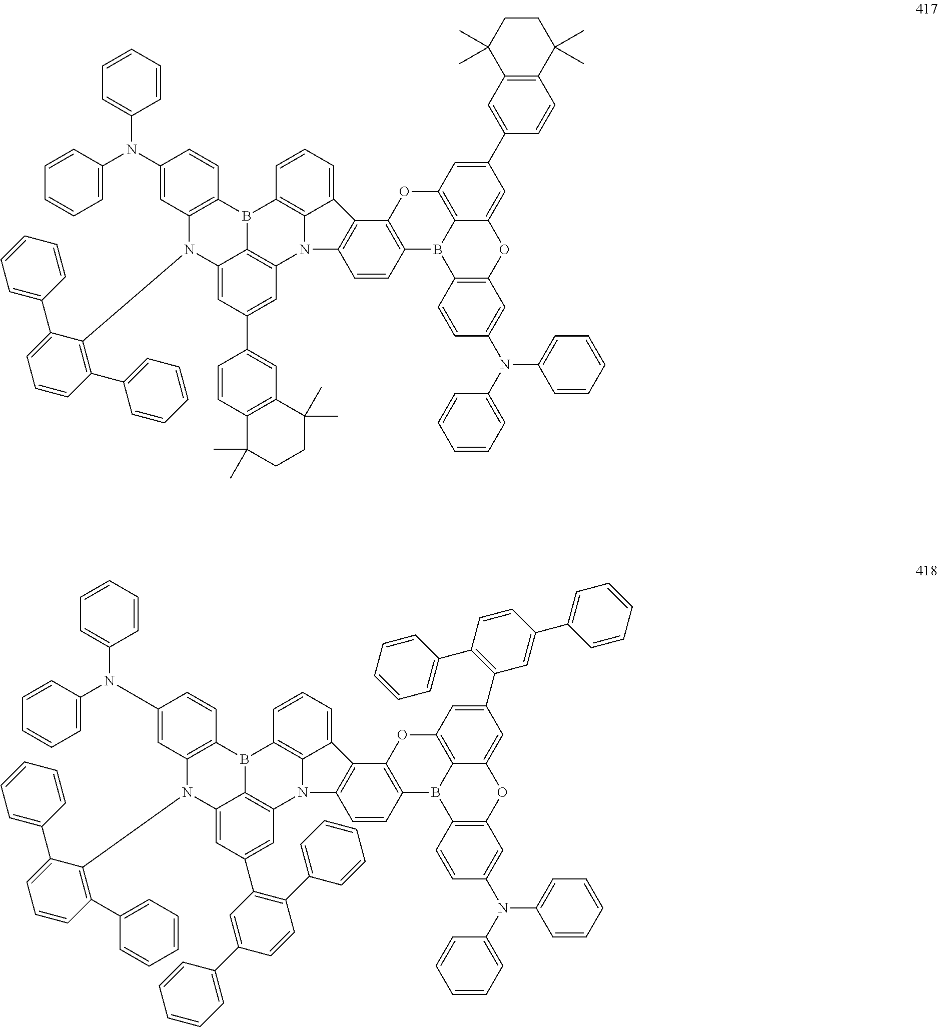 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)ccc21 ; c1ccc(-c2ccc(-c3ccccc3)c(-c3cc4c5c(c3)Oc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)c2)cc1] 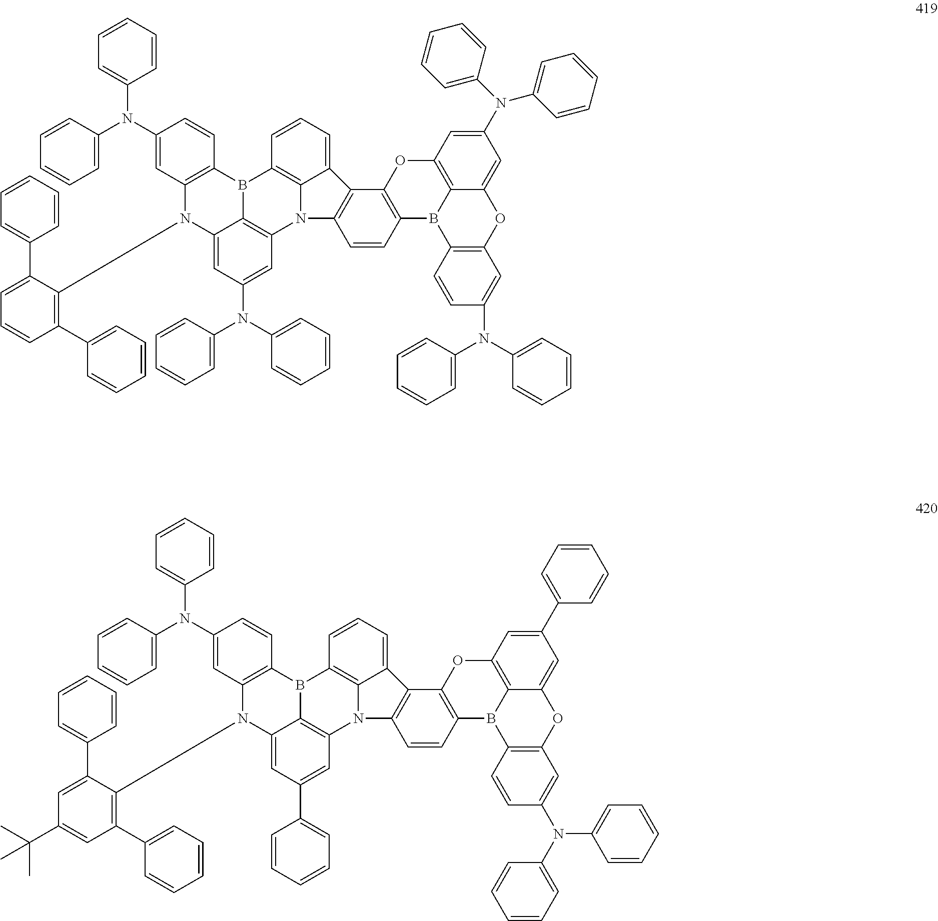 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Oc2cc(N(c3ccccc3)c3ccccc3)cc3c2B5c2ccc(N(c4ccccc4)c4ccccc4)cc2O3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Oc2cc(-c3ccccc3)cc3c2B5c2ccc(N(c4ccccc4)c4ccccc4)cc2O3)c(-c2ccccc2)c1] 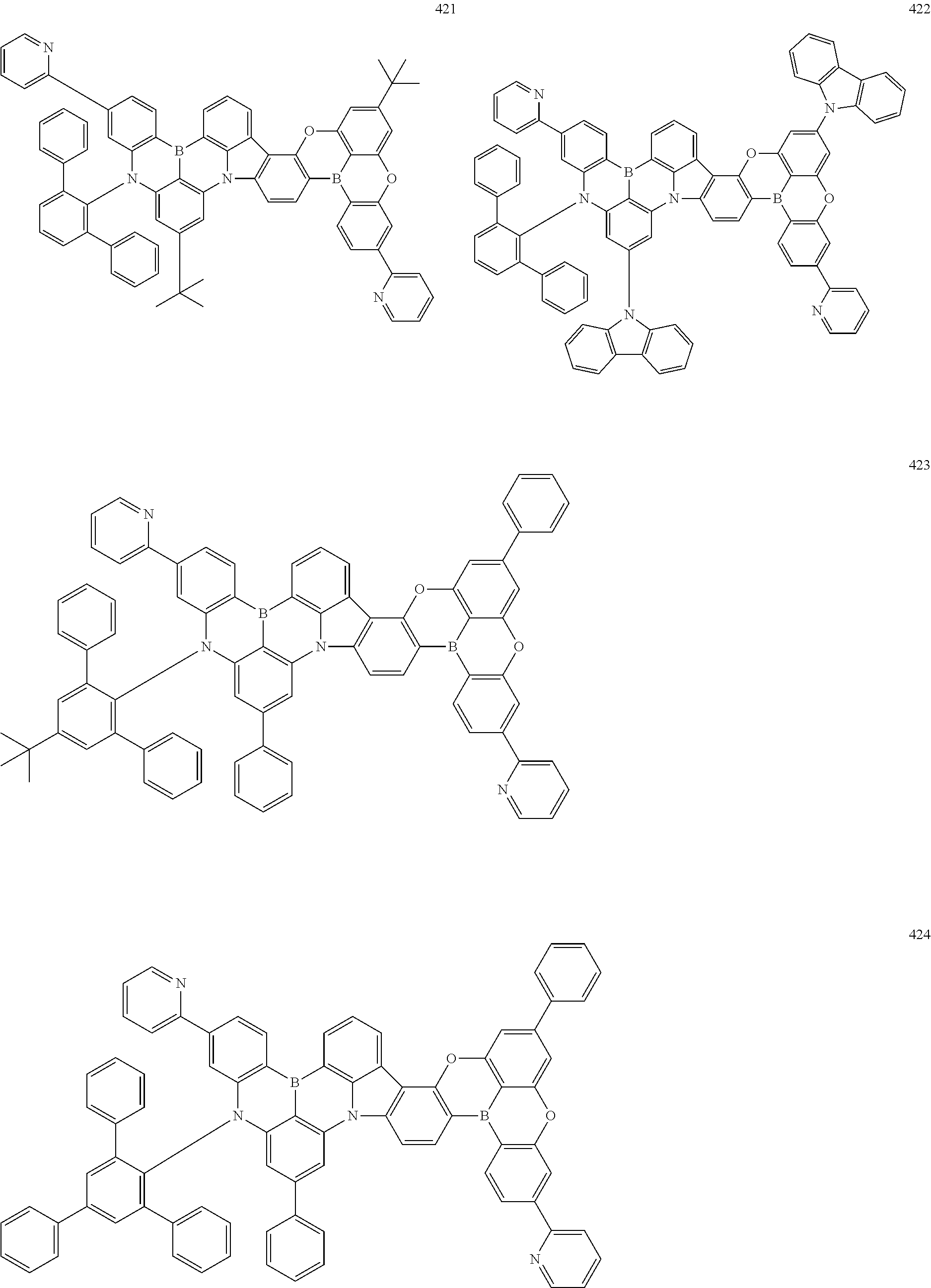 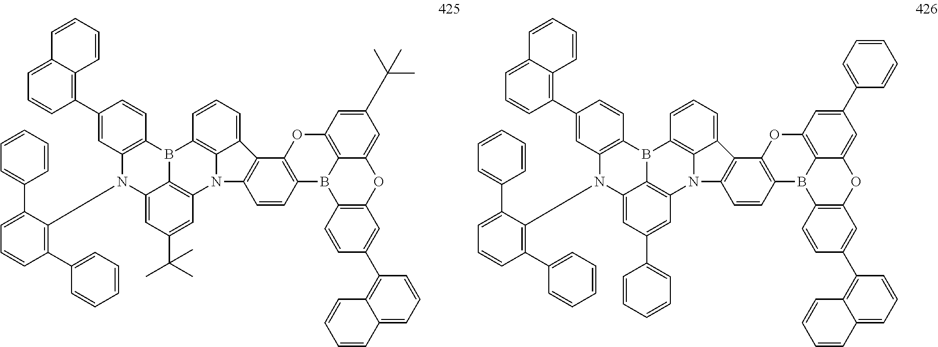 [SMILES: CC(C)(C)c1cc2c3c(c1)Oc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2O3)cc1] 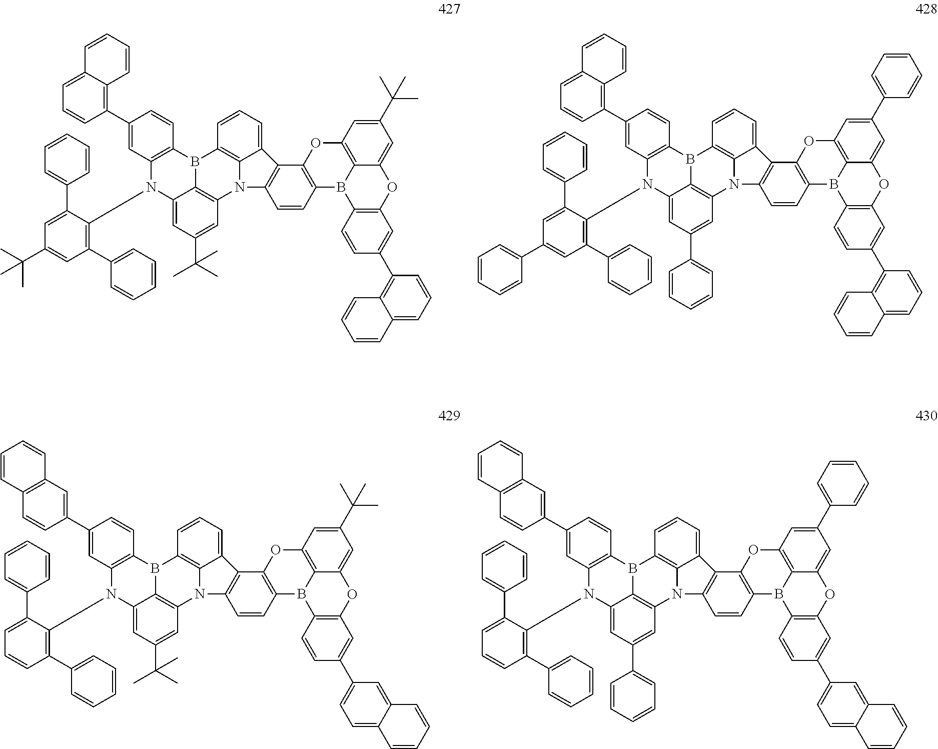 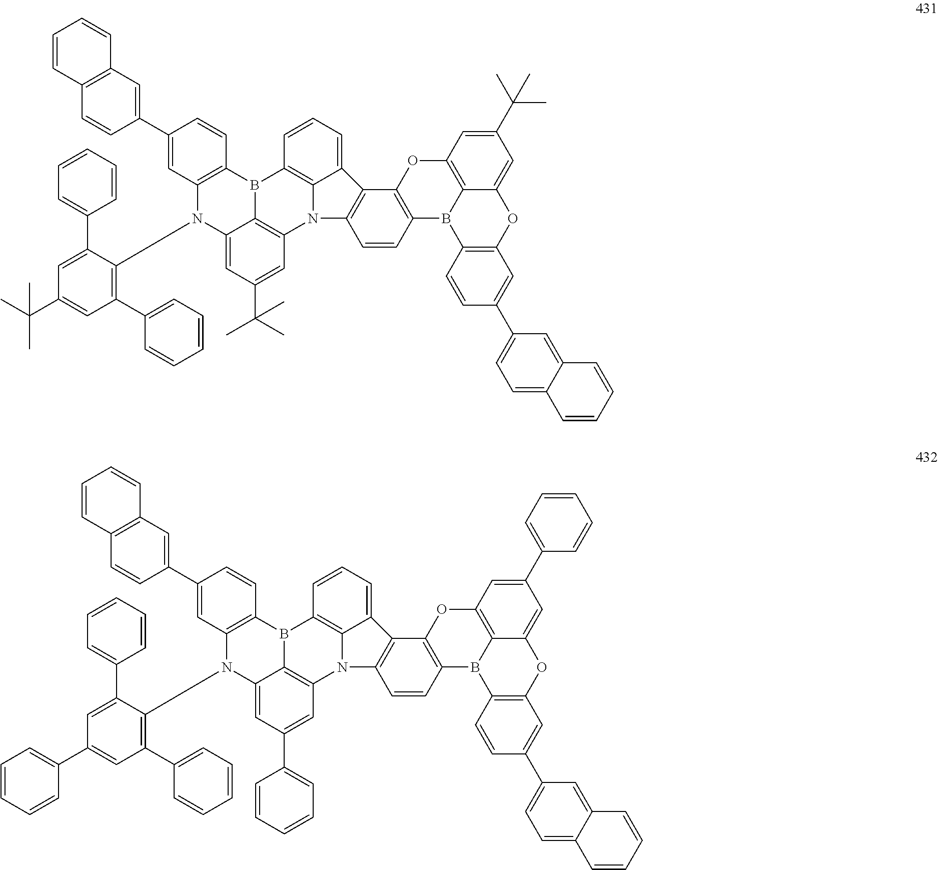 [SMILES: CC(C)(C)c1cc2c3c(c1)Oc1c(ccc4c1c1cccc5c1n4-c1cc(C(C)(C)C)cc4c1B5c1ccc(-c5ccc6ccccc6c5)cc1N4c1c(-c4ccccc4)cc(C(C)(C)C)cc1-c1ccccc1)B3c1ccc(-c3ccc4ccccc4c3)cc1O2 ; c1ccc(-c2cc3c4c(c2)Oc2c(ccc5c2c2cccc6c2n5-c2cc(-c5ccccc5)cc5c2B6c2ccc(-c6ccc7ccccc7c6)cc2N5c2c(-c5ccccc5)cc(-c5ccccc5)cc2-c2ccccc2)B4c2ccc(-c4ccc5ccccc5c4)cc2O3)cc1] 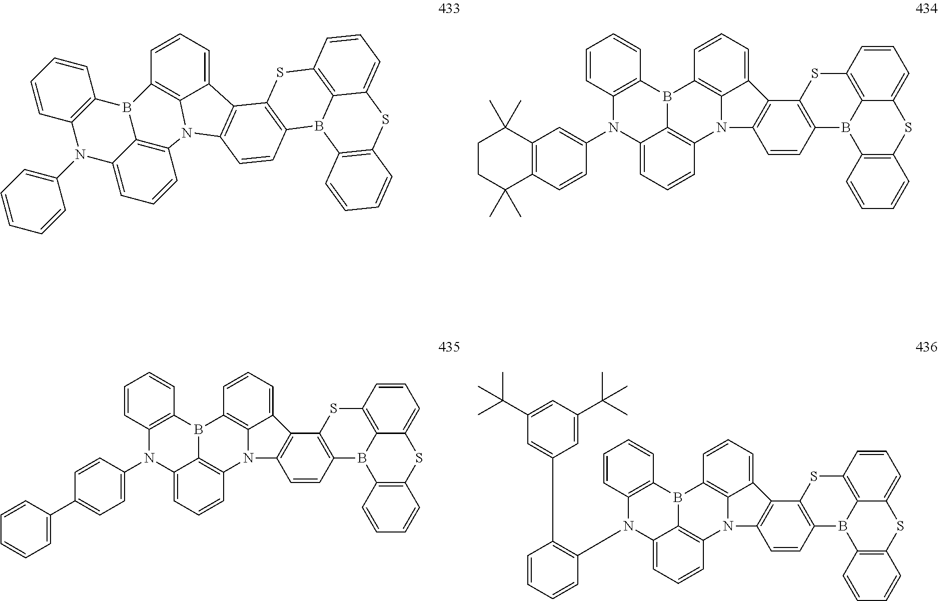 [SMILES: c1ccc(N2c3ccccc3B3c4c2cccc4-n2c4ccc5c(c4c4cccc3c42)Sc2cccc3c2B5c2ccccc2S3)cc1 ; CC1(C)CCC(C)(C)c2cc(N3c4ccccc4B4c5c3cccc5-n3c5ccc6c(c5c5cccc4c53)Sc3cccc4c3B6c3ccccc3S4)ccc21 ; c1ccc(-c2ccc(N3c4ccccc4B4c5c3cccc5-n3c5ccc6c(c5c5cccc4c53)Sc3cccc4c3B6c3ccccc3S4)cc2)cc1 ; CC(C)(C)c1cc(-c2ccccc2N2c3ccccc3B3c4c2cccc4-n2c4ccc5c(c4c4cccc3c42)Sc2cccc3c2B5c2ccccc2S3)cc(C(C)(C)C)c1] 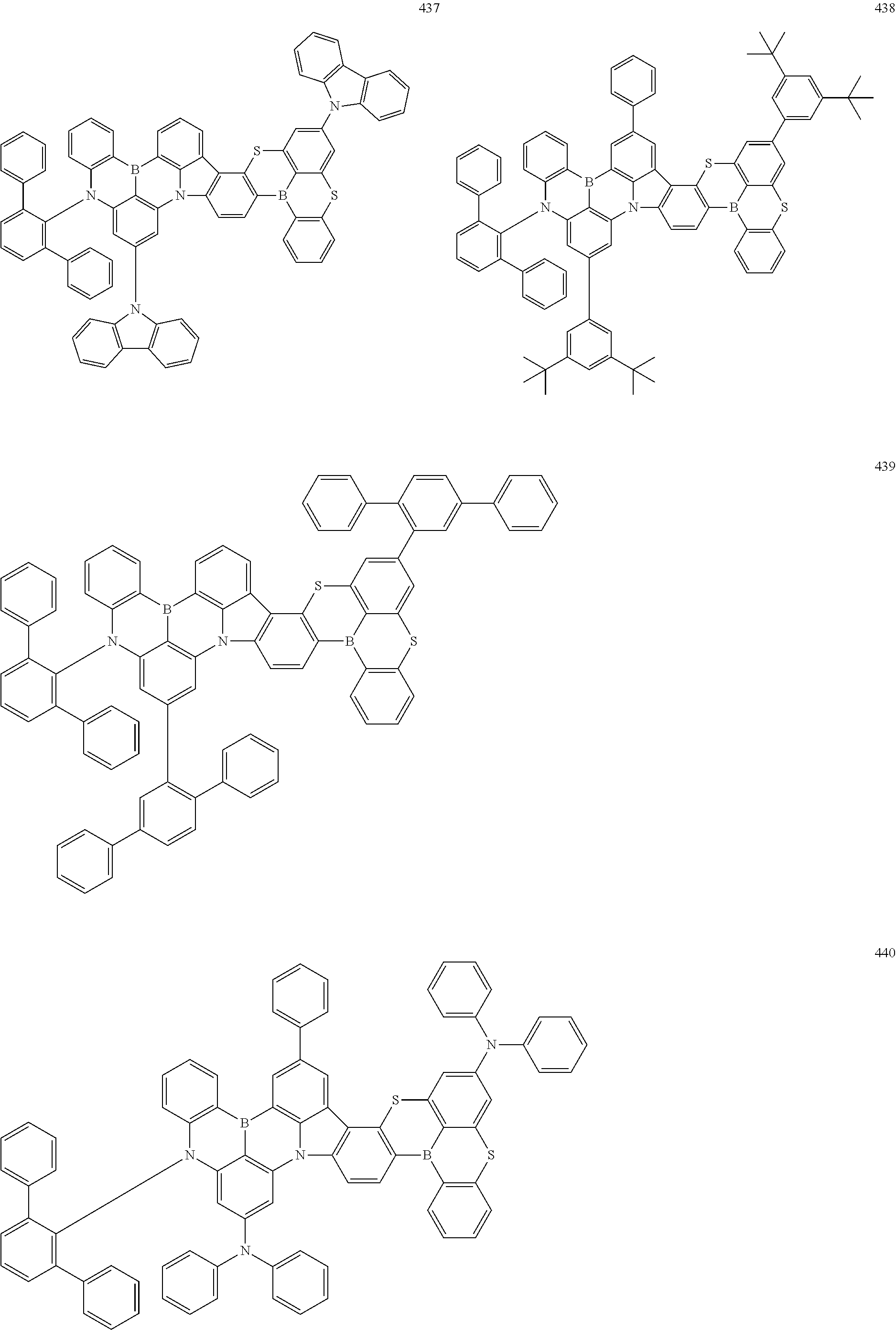 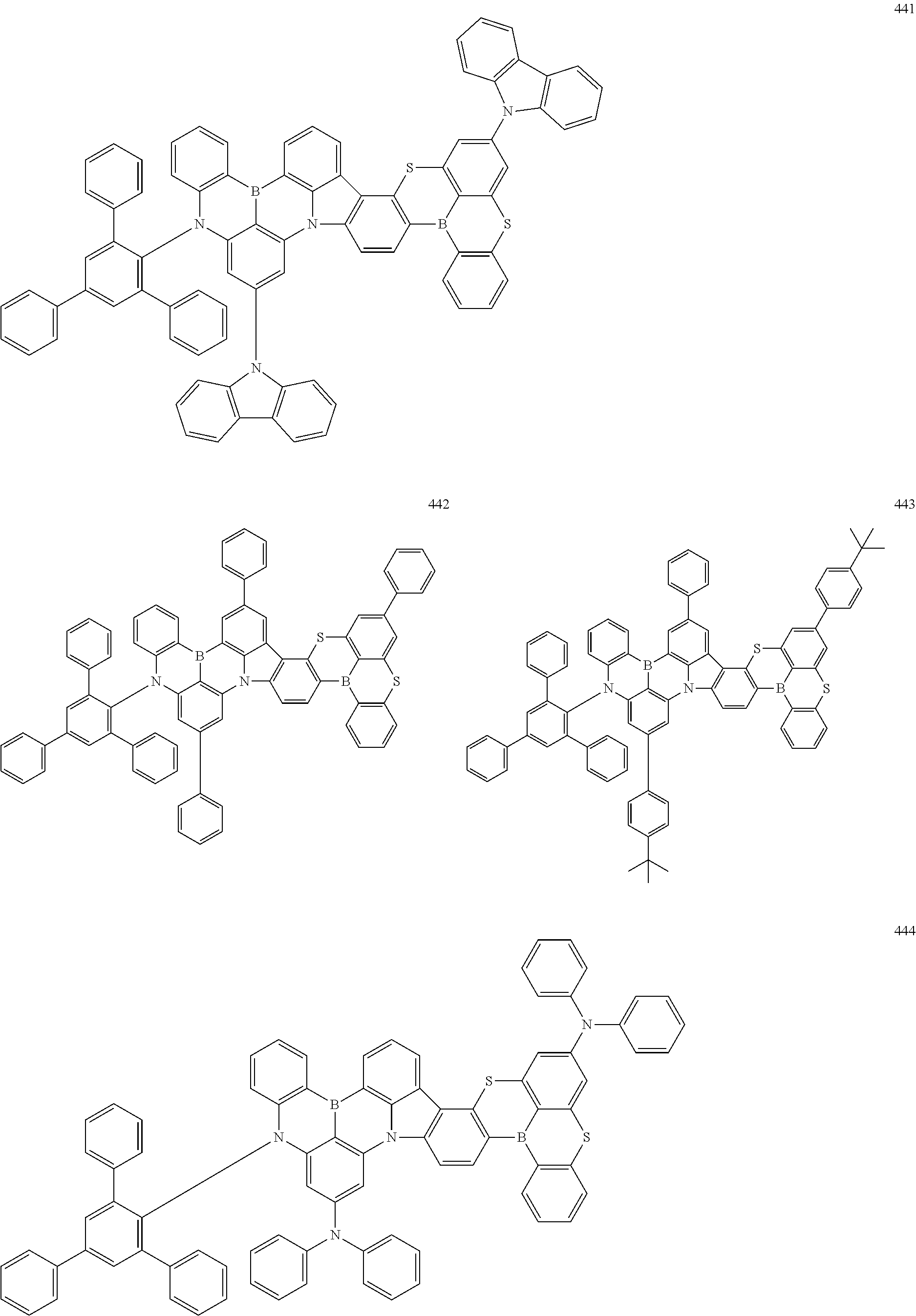 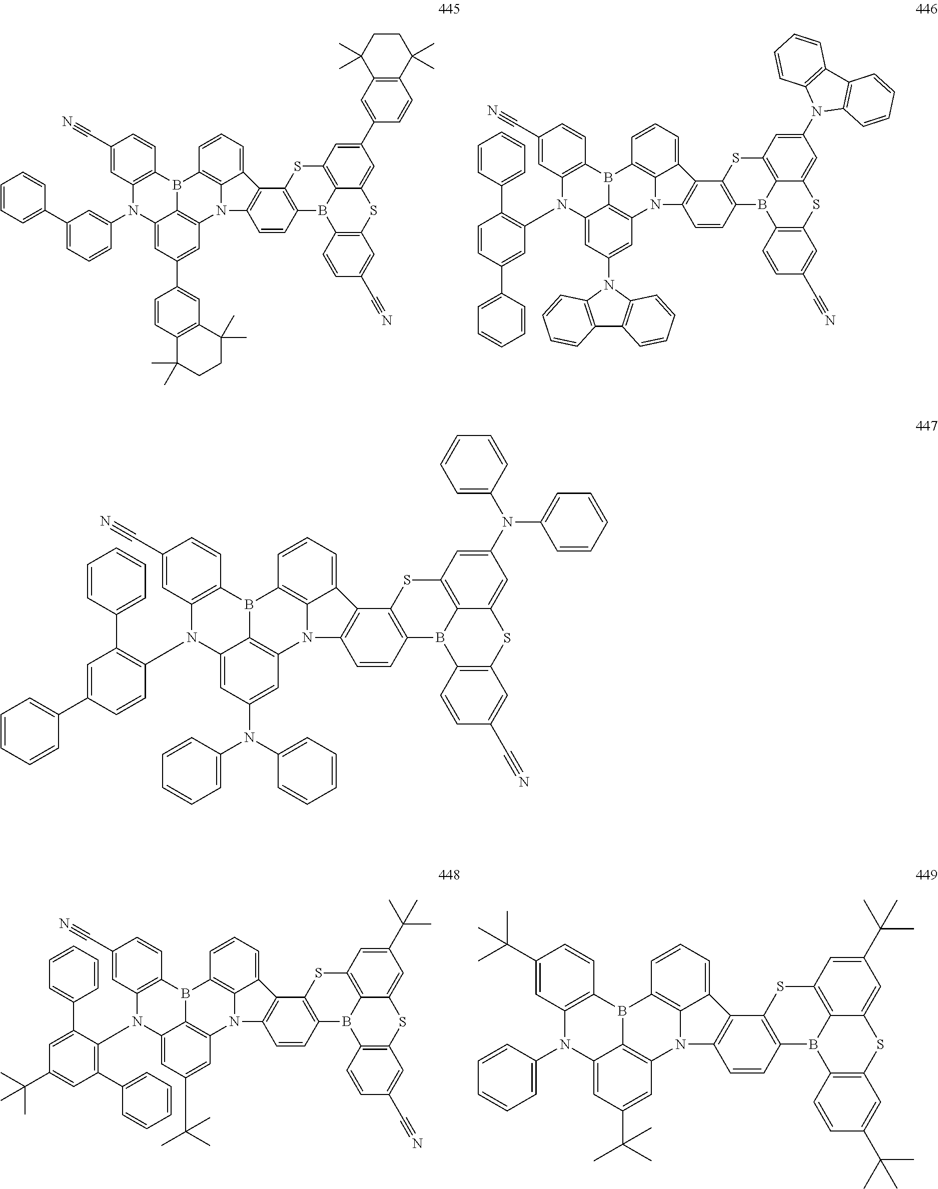 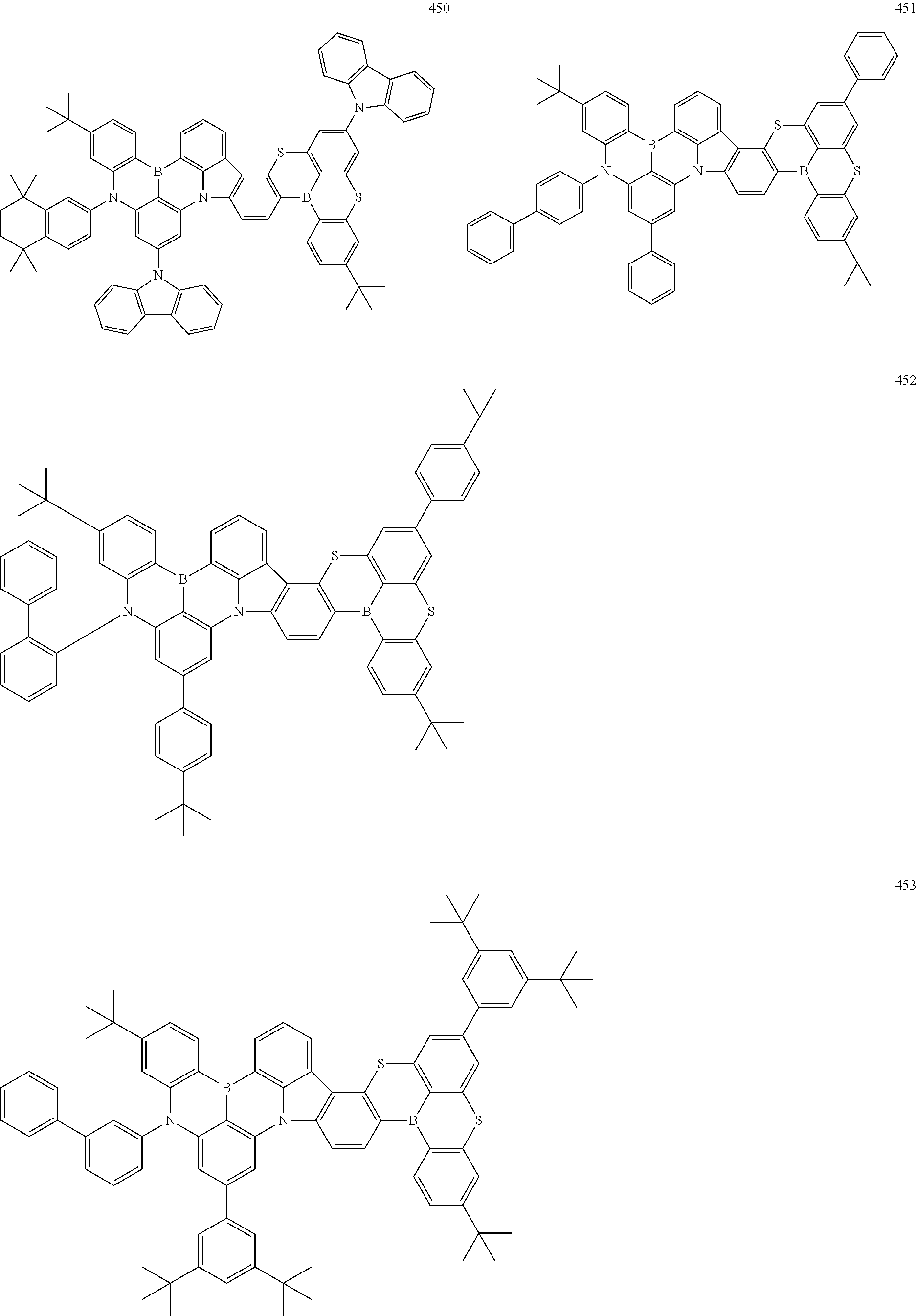 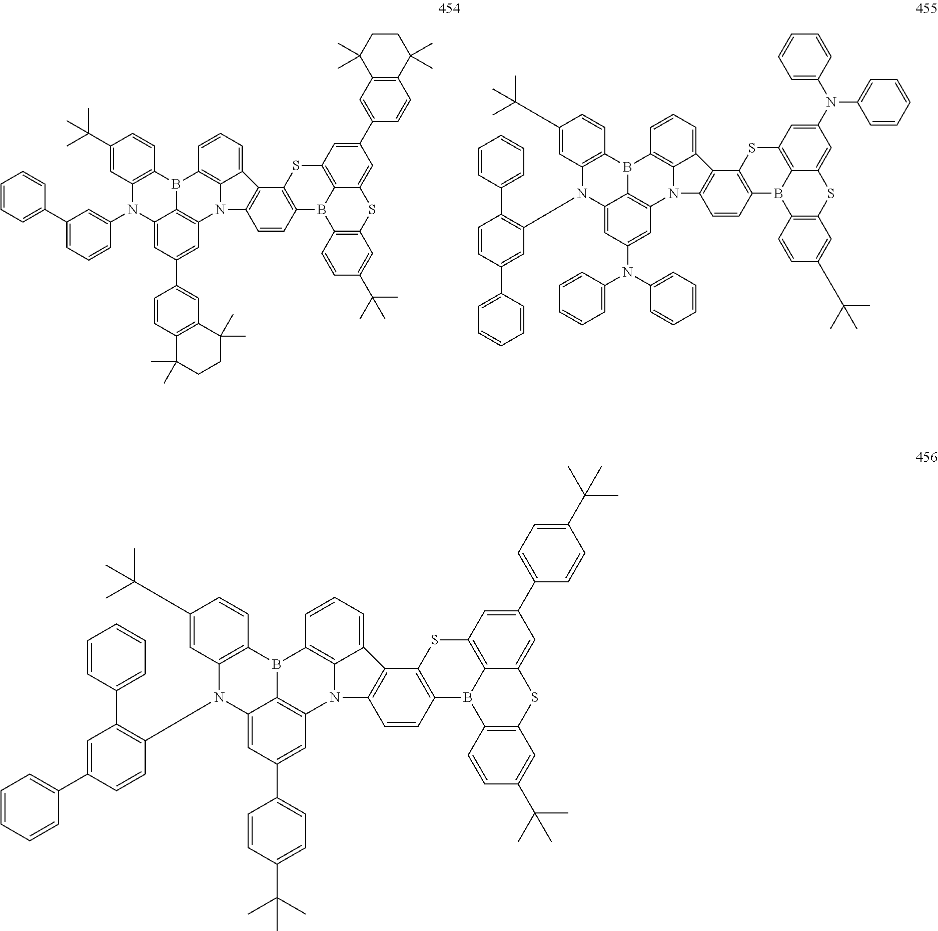 [SMILES: CC(C)(C)c1ccc2c(c1)Sc1cc(-c3ccc4c(c3)C(C)(C)CCC4(C)C)cc3c1B2c1ccc2c(c1S3)c1cccc3c1n2-c1cc(-c2ccc4c(c2)C(C)(C)CCC4(C)C)cc2c1B3c1ccc(C(C)(C)C)cc1N2c1cccc(-c2ccccc2)c1 ; CC(C)(C)c1ccc2c(c1)Sc1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)Sc2c(ccc5c2c2cccc6c2n5-c2cc(-c5ccc(C(C)(C)C)cc5)cc5c2B6c2ccc(C(C)(C)C)cc2N5c2ccc(-c5ccccc5)cc2-c2ccccc2)B4c2ccc(C(C)(C)C)cc2S3)cc1] 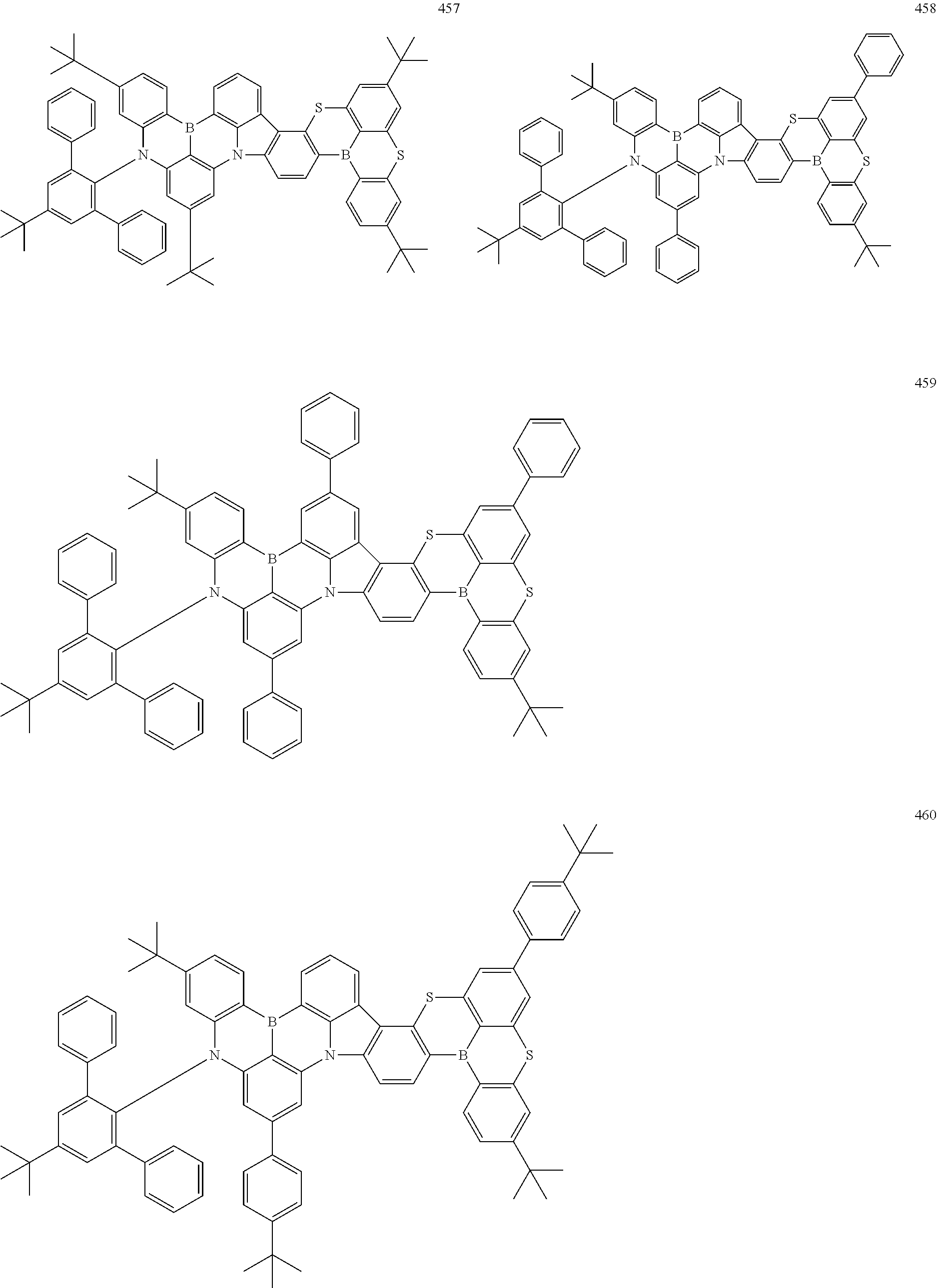 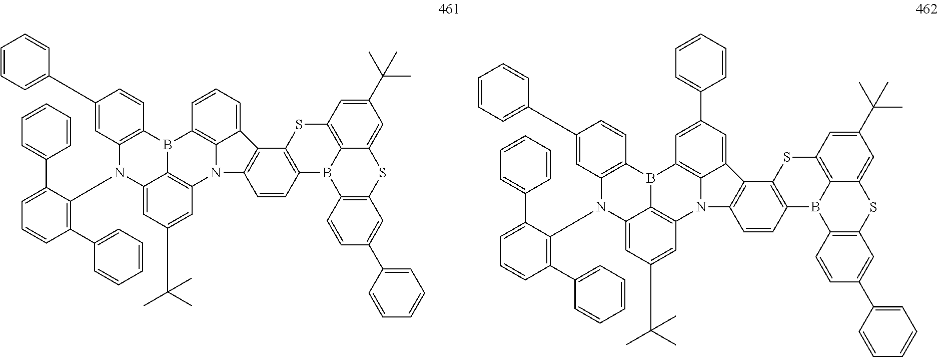 [SMILES: CC(C)(C)c1cc2c3c(c1)Sc1c(ccc4c1c1cccc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1S2 ; CC(C)(C)c1cc2c3c(c1)Sc1c(ccc4c1c1cc(-c5ccccc5)cc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1S2] 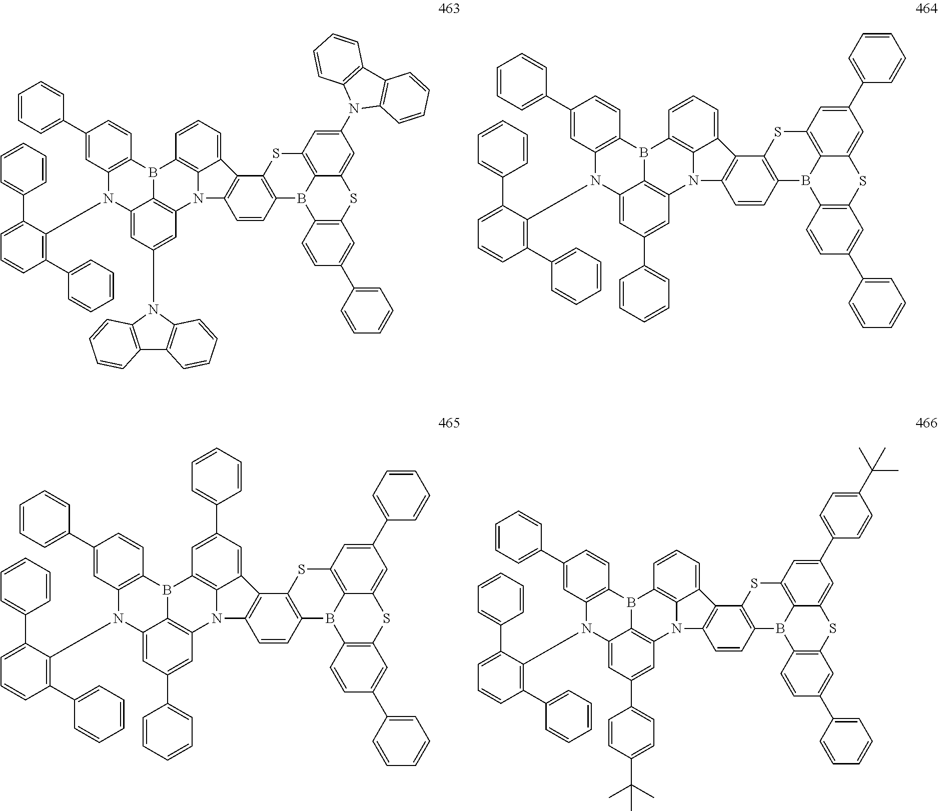 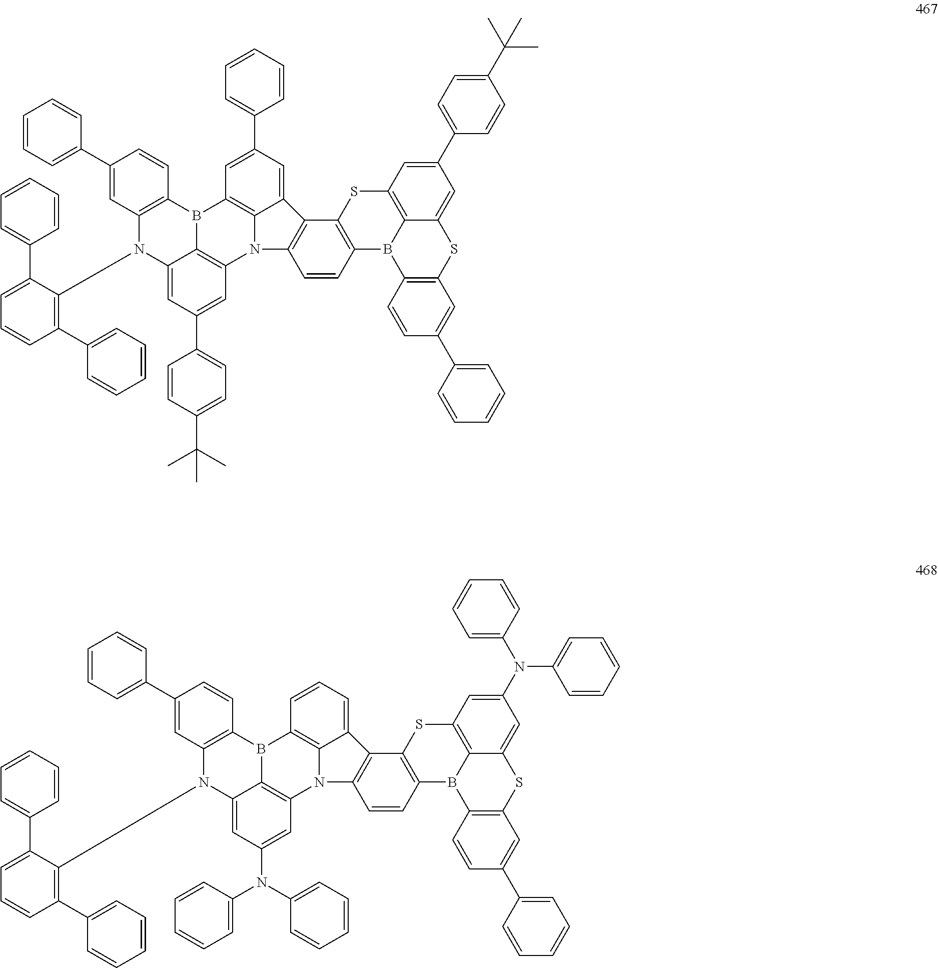 [SMILES: CC(C)(C)c1ccc(-c2cc3c4c(c2)Sc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2S3)cc1 ; c1ccc(-c2ccc3c(c2)Sc2cc(N(c4ccccc4)c4ccccc4)cc4c2B3c2ccc3c(c2S4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 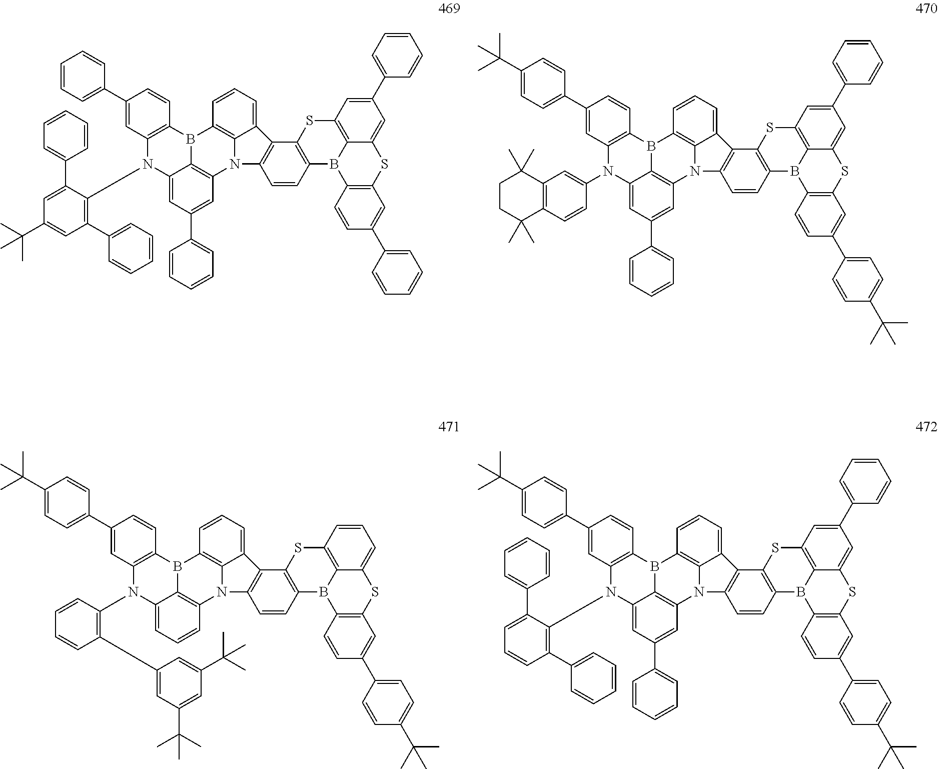 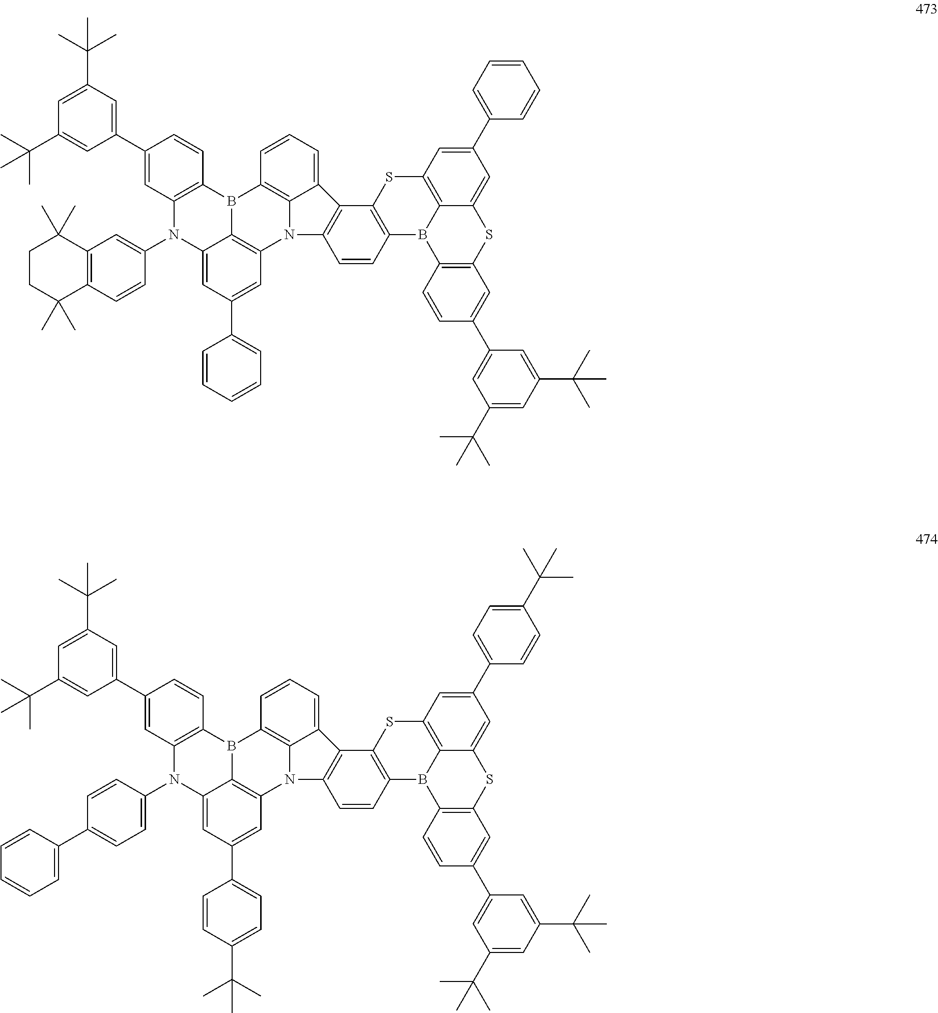 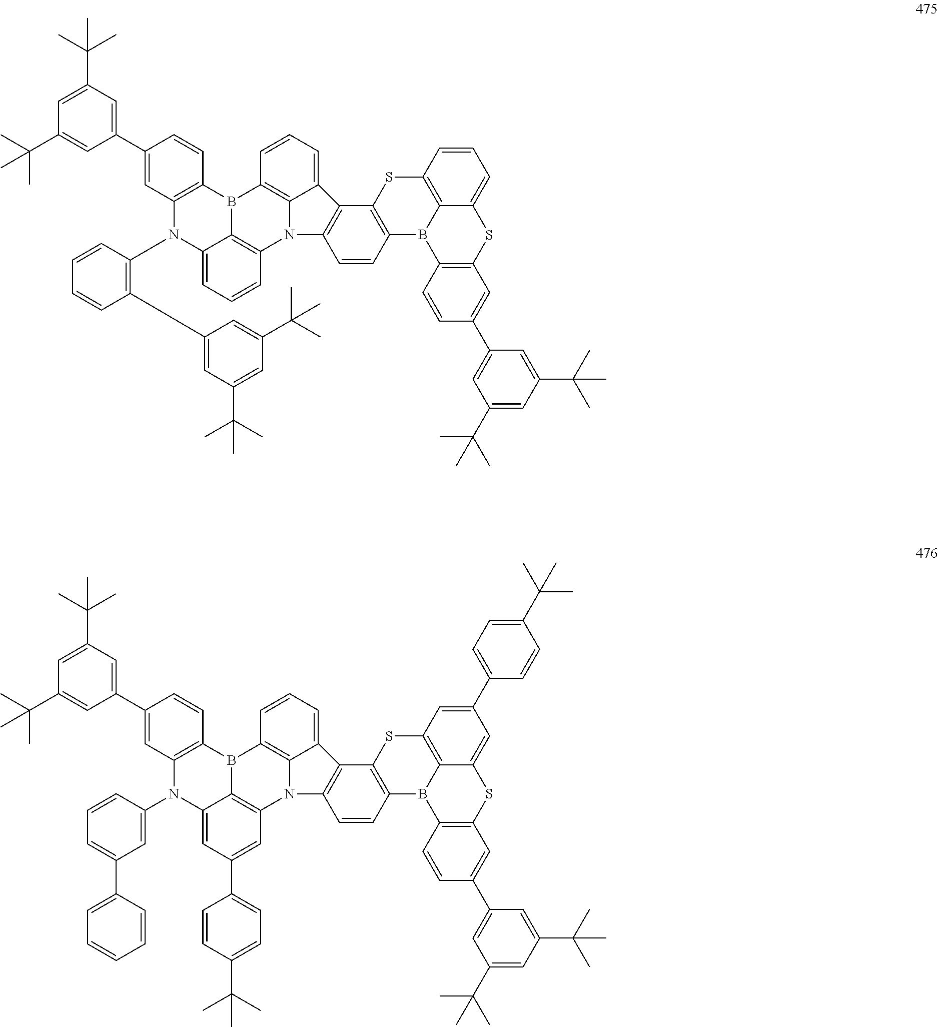 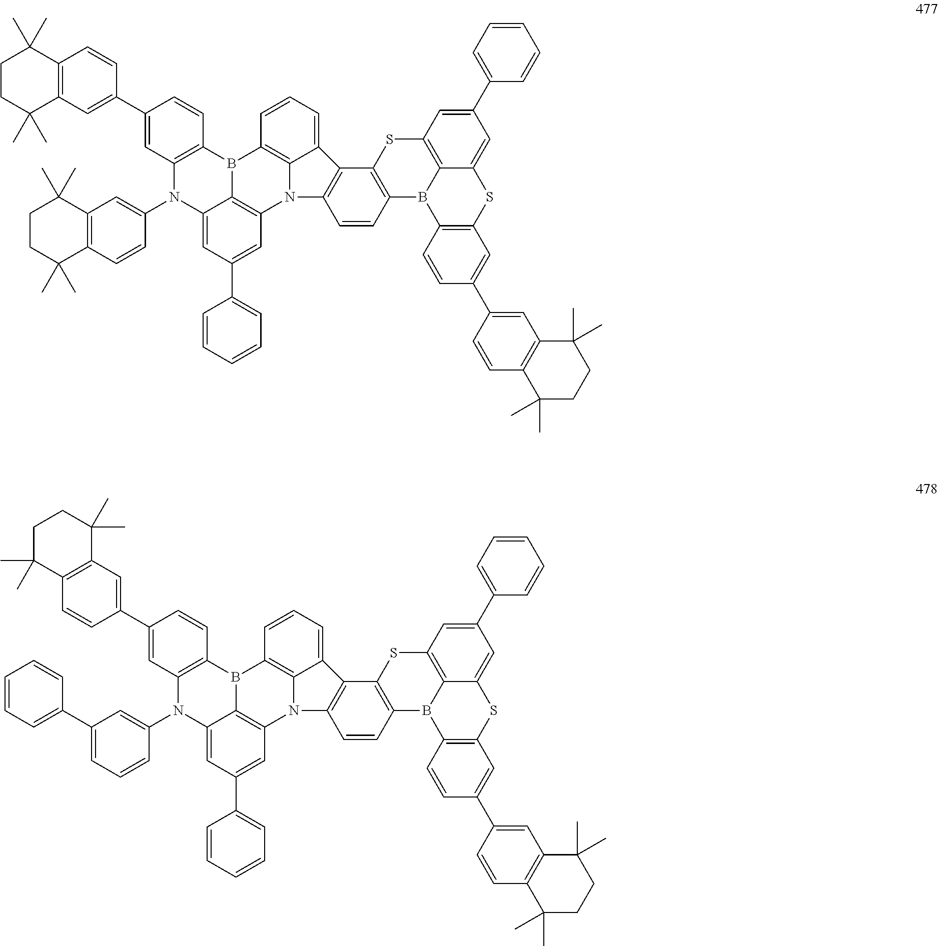 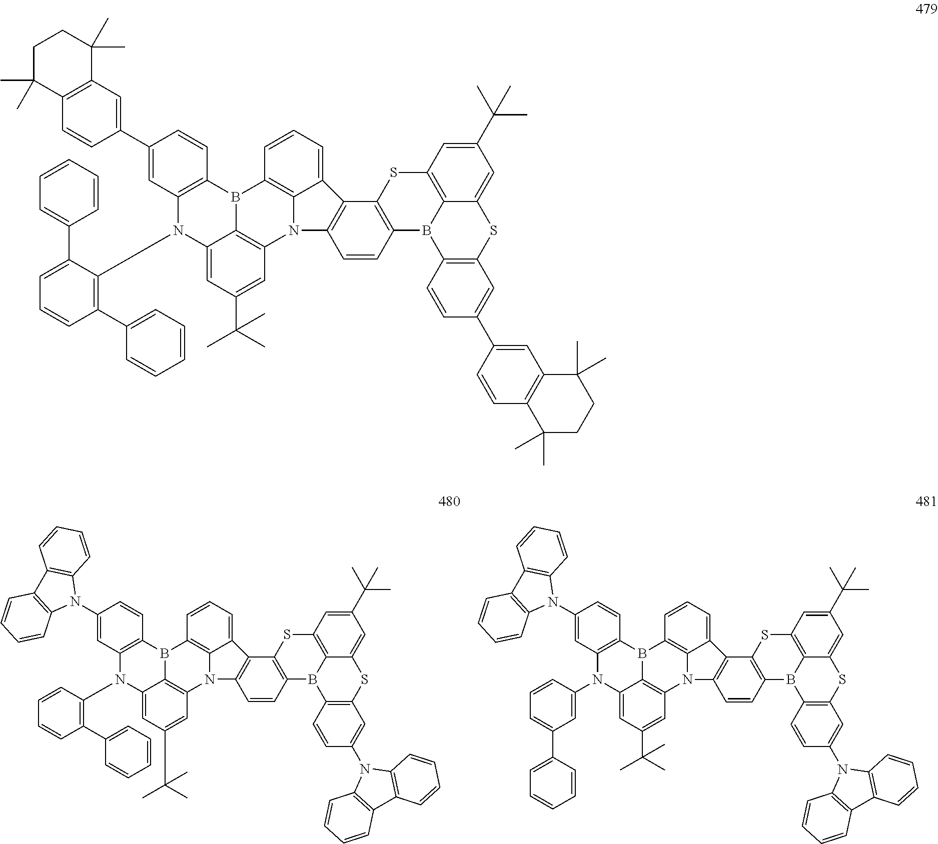 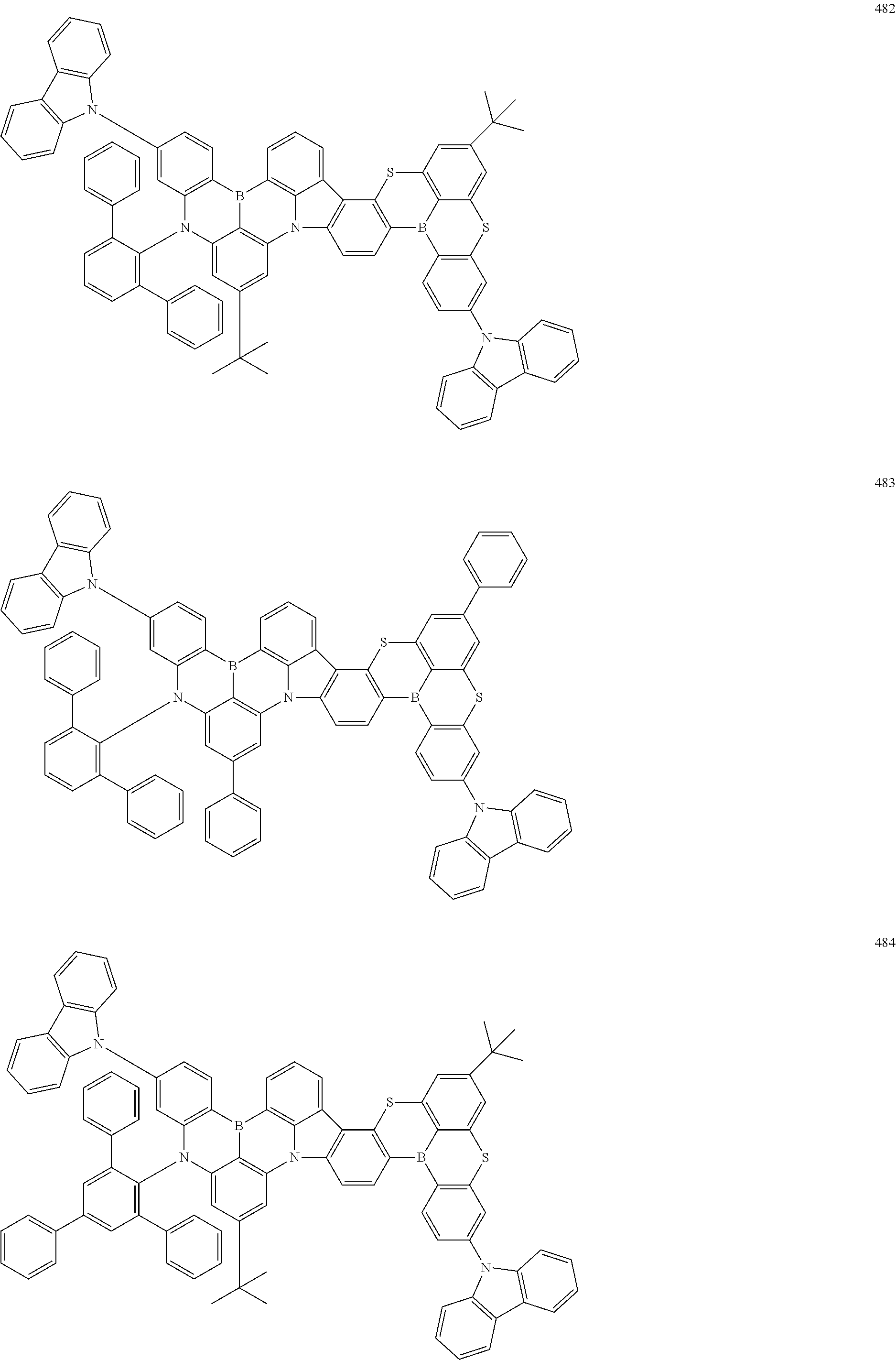 [SMILES: CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1S2 ; c1ccc(-c2cc3c4c(c2)Sc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2S3)cc1 ; CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1S2] 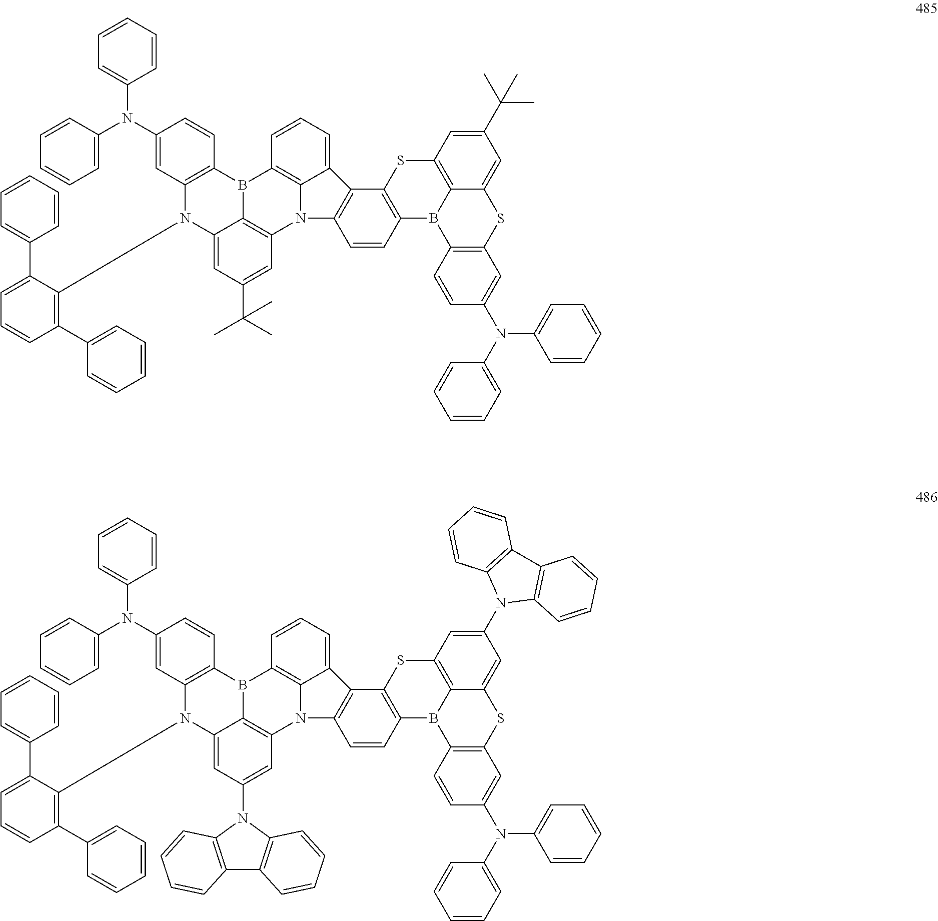 [SMILES: CC(C)(C)c1cc2c3c(c1)Sc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1S2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Sc2cc(-n3c4ccccc4c4ccccc43)cc3c2B5c2ccc(N(c4ccccc4)c4ccccc4)cc2S3)cc1] 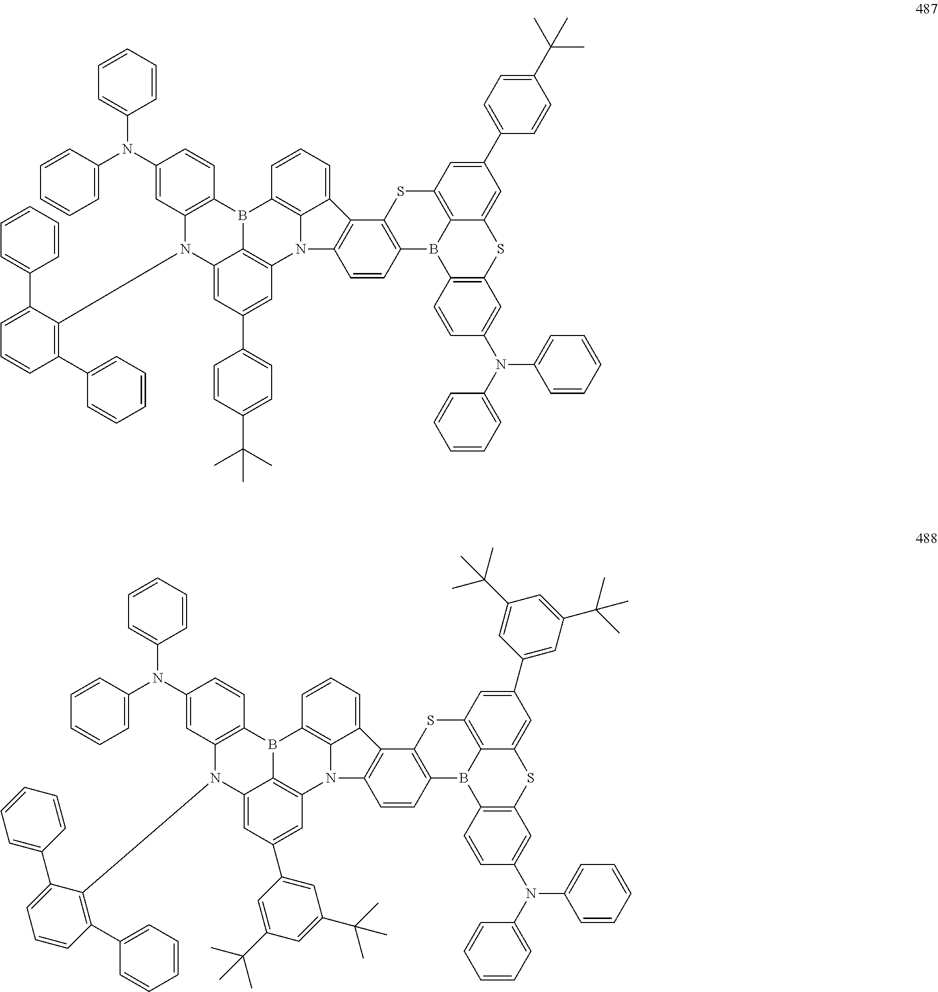 [SMILES: CC(C)(C)c1ccc(-c2cc3c4c(c2)Sc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc1 ; CC(C)(C)c1cc(-c2cc3c4c(c2)Sc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc(C(C)(C)C)c1] 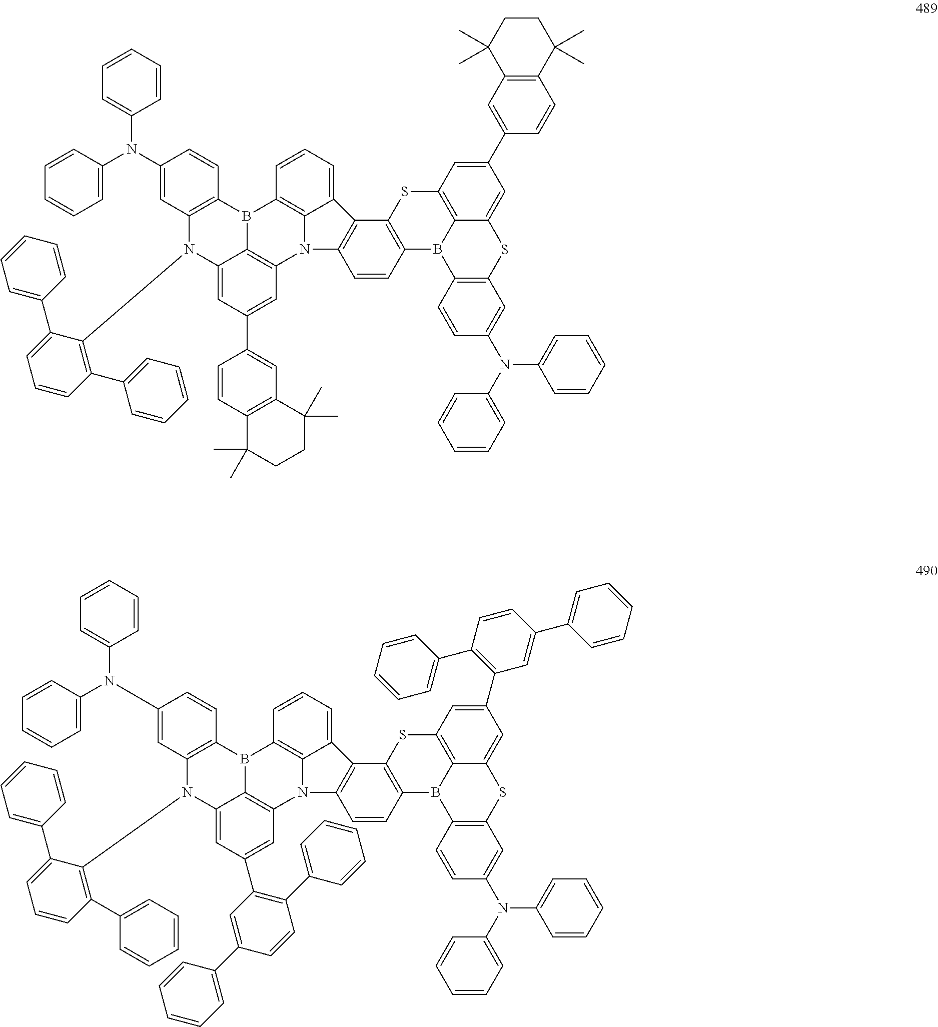 [SMILES: CC1(C)CCC(C)(C)c2cc(-c3cc4c5c(c3)Sc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)ccc21 ; c1ccc(-c2ccc(-c3ccccc3)c(-c3cc4c5c(c3)Sc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)c2)cc1] 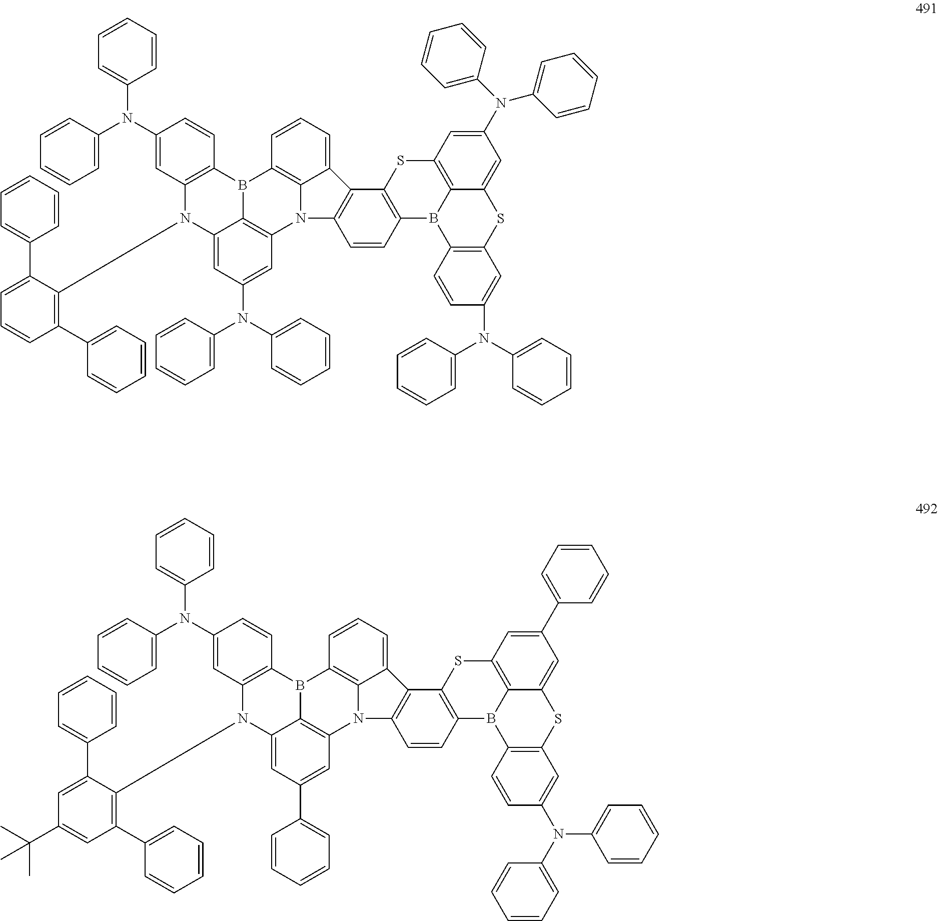 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Sc2cc(N(c3ccccc3)c3ccccc3)cc3c2B5c2ccc(N(c4ccccc4)c4ccccc4)cc2S3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Sc2cc(-c3ccccc3)cc3c2B5c2ccc(N(c4ccccc4)c4ccccc4)cc2S3)c(-c2ccccc2)c1] 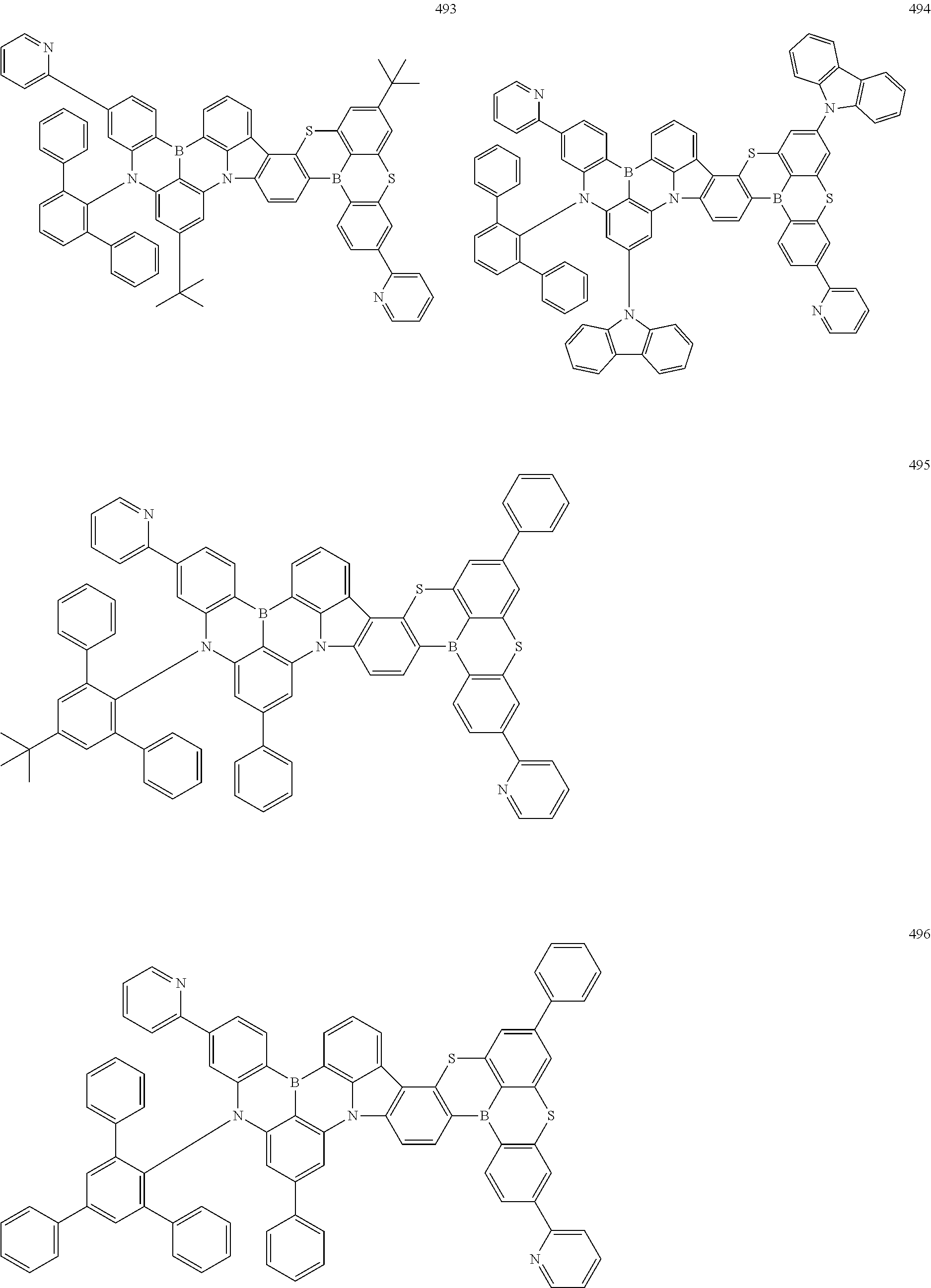 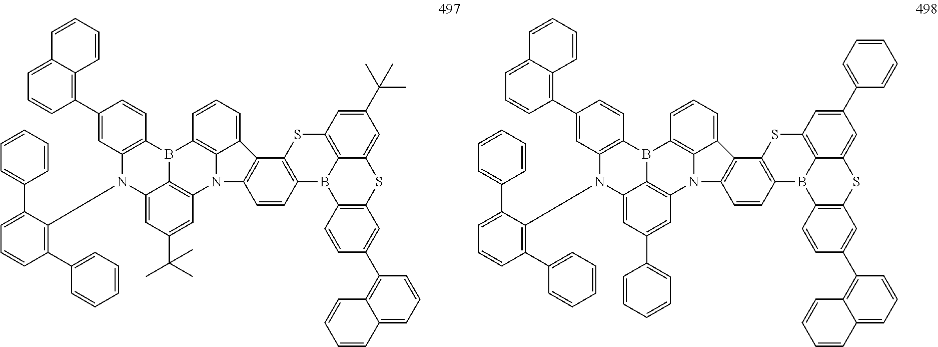 [SMILES: CC(C)(C)c1cc2c3c(c1)Sc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1S2 ; c1ccc(-c2cc3c4c(c2)Sc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2S3)cc1] 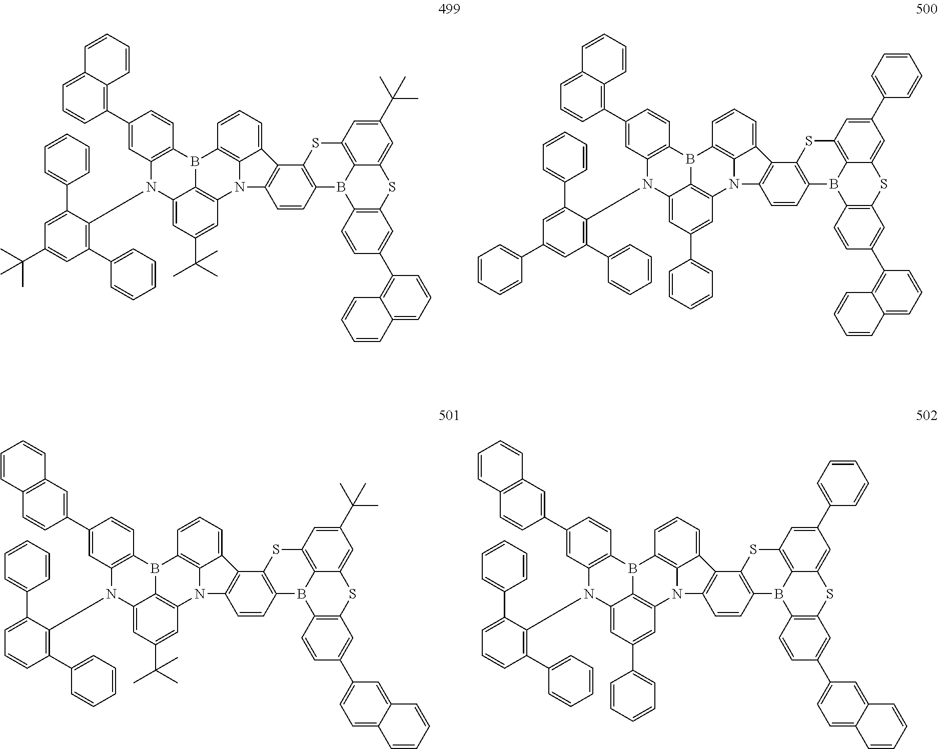 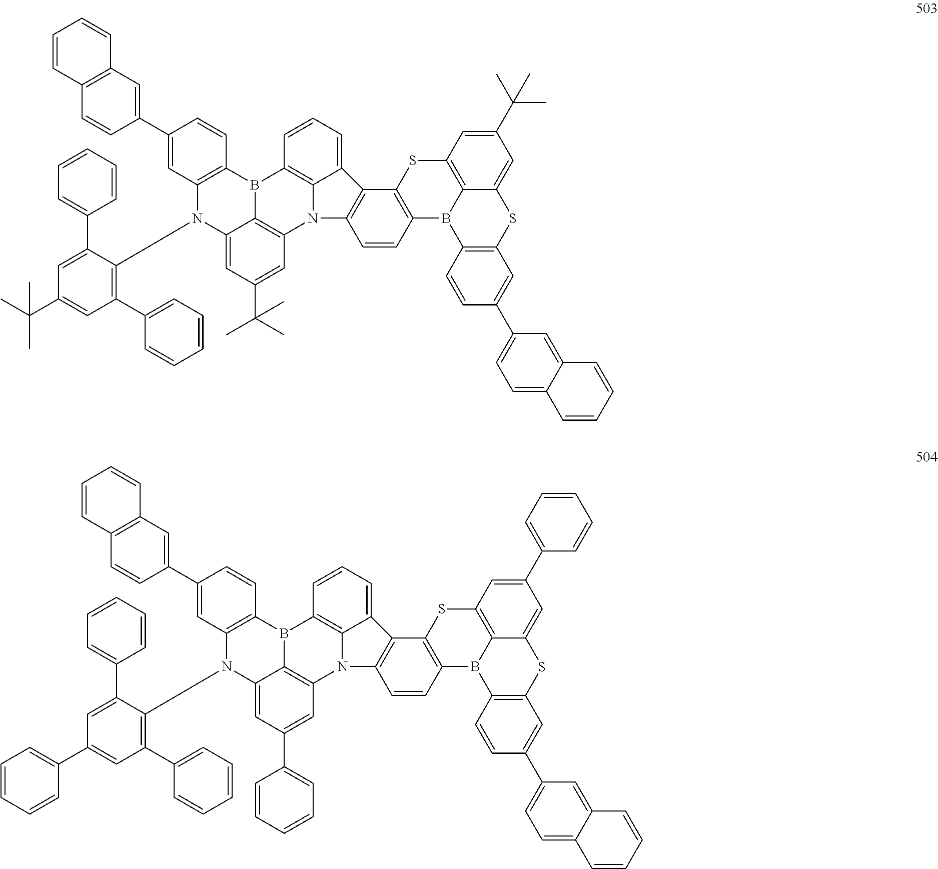 [SMILES: CC(C)(C)c1cc2c3c(c1)Sc1c(ccc4c1c1cccc5c1n4-c1cc(C(C)(C)C)cc4c1B5c1ccc(-c5ccc6ccccc6c5)cc1N4c1c(-c4ccccc4)cc(C(C)(C)C)cc1-c1ccccc1)B3c1ccc(-c3ccc4ccccc4c3)cc1S2 ; c1ccc(-c2cc3c4c(c2)Sc2c(ccc5c2c2cccc6c2n5-c2cc(-c5ccccc5)cc5c2B6c2ccc(-c6ccc7ccccc7c6)cc2N5c2c(-c5ccccc5)cc(-c5ccccc5)cc2-c2ccccc2)B4c2ccc(-c4ccc5ccccc5c4)cc2S3)cc1] 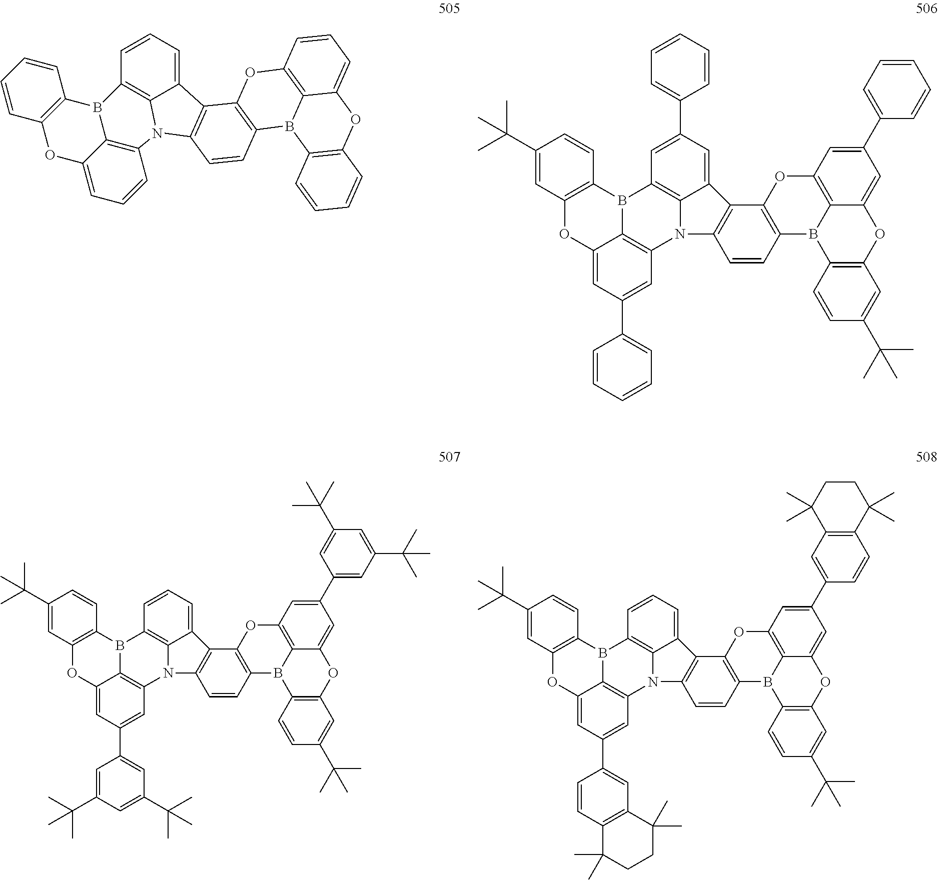 [SMILES: c1ccc2c(c1)Oc1cccc3c1B2c1ccc2c(c1O3)c1cccc3c1n2-c1cccc2c1B3c1ccccc1O2 ; CC(C)(C)c1ccc2c(c1)Oc1cc(-c3ccccc3)cc3c1B2c1ccc2c(c1O3)c1cc(-c3ccccc3)cc3c1n2-c1cc(-c2ccccc2)cc2c1B3c1ccc(C(C)(C)C)cc1O2 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(C(C)(C)C)cc2O5)B4c2ccc(C(C)(C)C)cc2O3)cc(C(C)(C)C)c1 ; CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1O2] 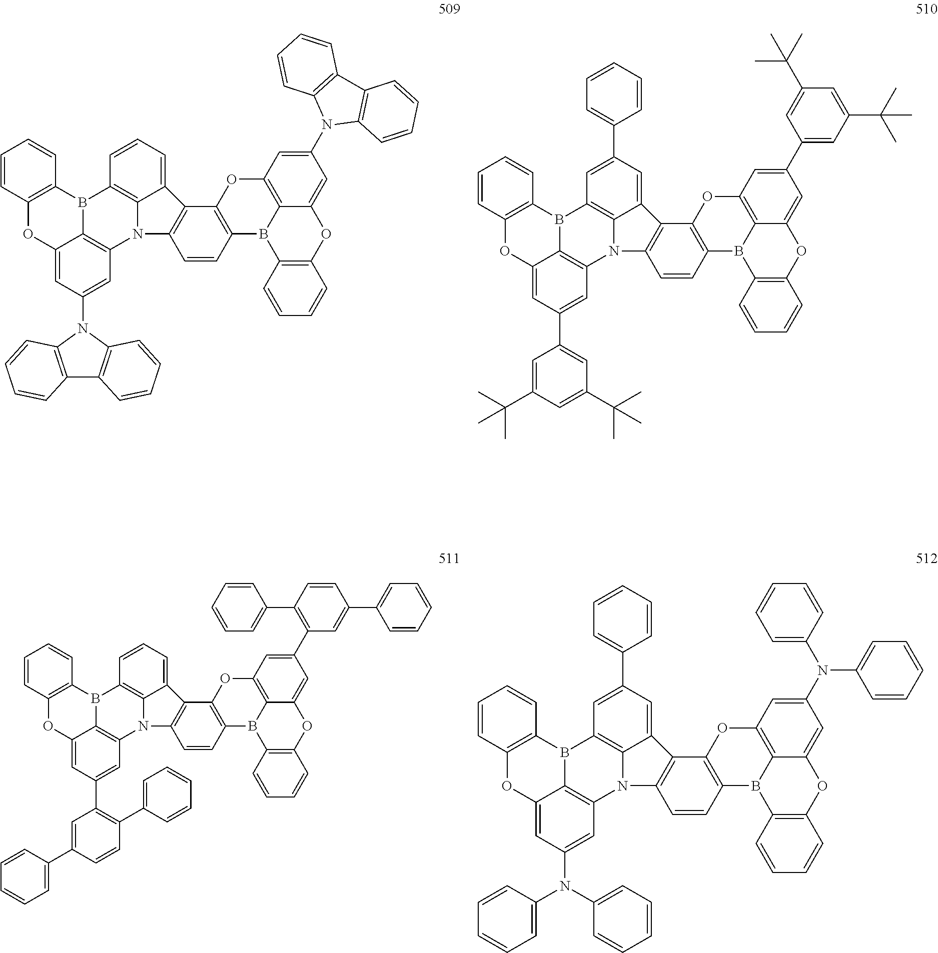 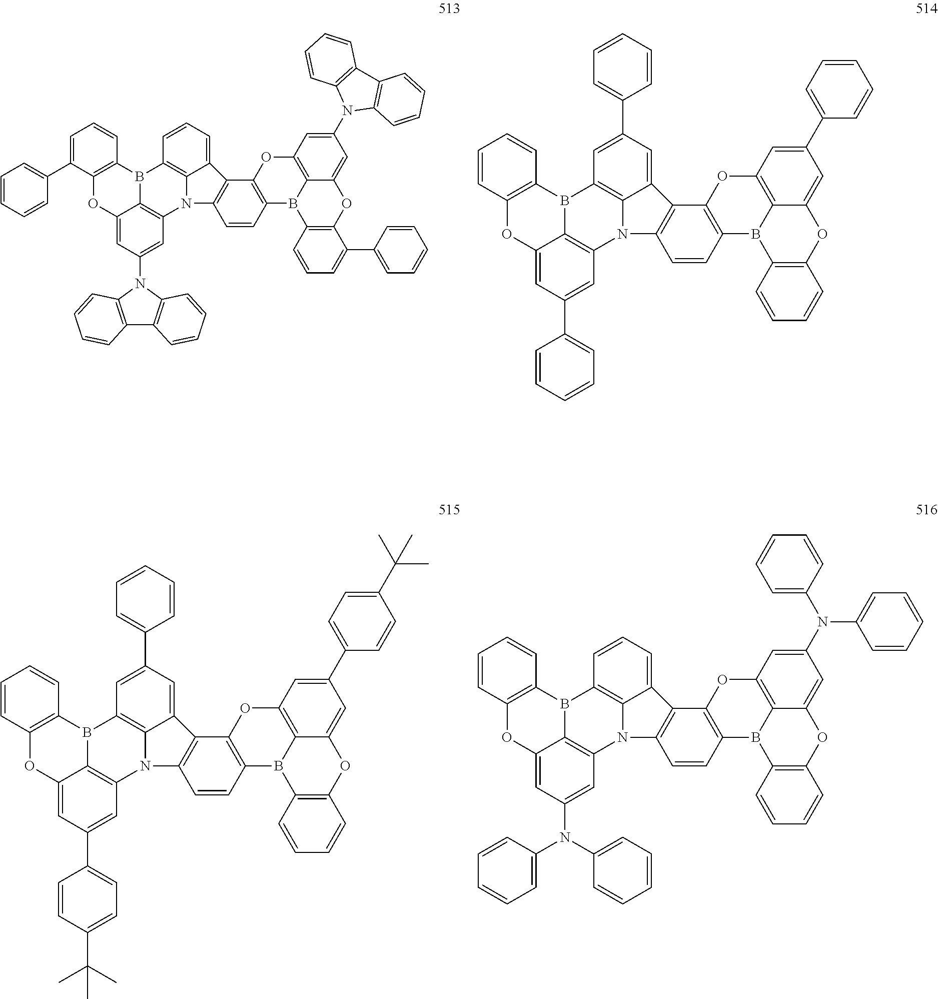 [SMILES: c1ccc(-c2cccc3c2Oc2cc(-n4c5ccccc5c5ccccc54)cc4c2B3c2ccc3c(c2O4)c2cccc4c2n3-c2cc(-n3c5ccccc5c5ccccc53)cc3c2B4c2cccc(-c4ccccc4)c2O3)cc1 ; c1ccc(-c2cc3c4c(c2)Oc2c(ccc5c2c2cc(-c6ccccc6)cc6c2n5-c2cc(-c5ccccc5)cc5c2B6c2ccccc2O5)B4c2ccccc2O3)cc1 ; CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccccc2O5)B4c2ccccc2O3)cc1 ; c1ccc(N(c2ccccc2)c2cc3c4c(c2)Oc2c(ccc5c2c2cccc6c2n5-c2cc(N(c5ccccc5)c5ccccc5)cc5c2B6c2ccccc2O5)B4c2ccccc2O3)cc1] 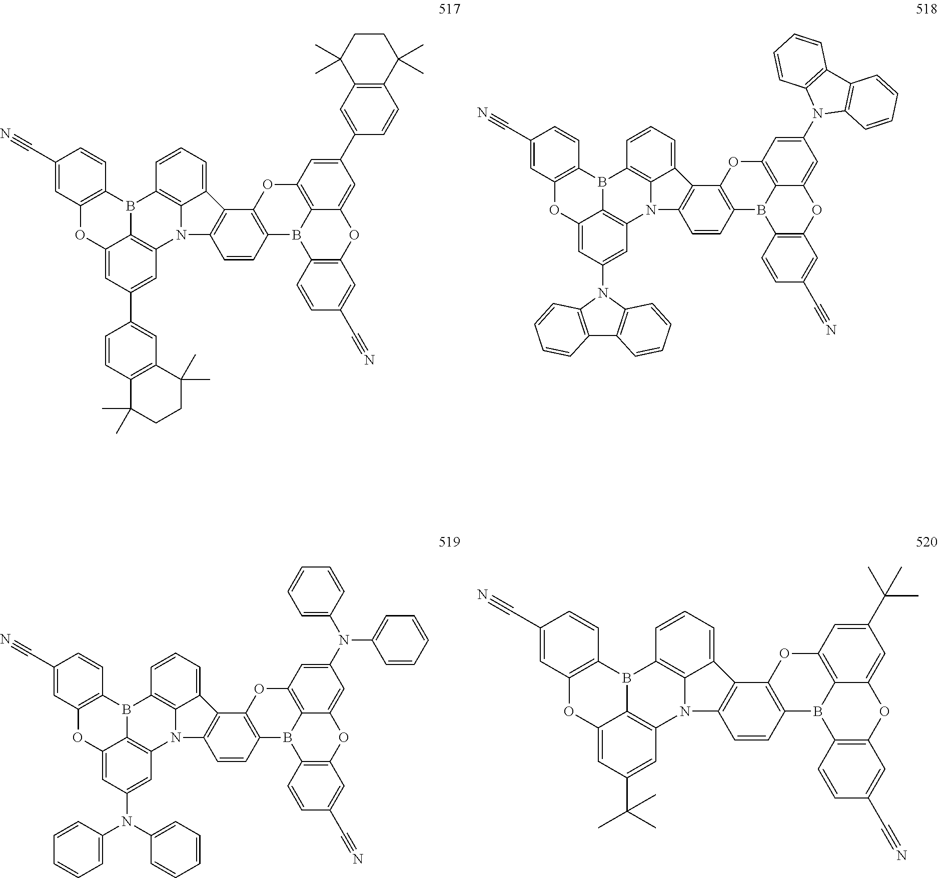 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(C#N)cc3O6)B5c3ccc(C#N)cc3O4)ccc21 ; N#Cc1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1O2 ; N#Cc1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1O2 ; CC(C)(C)c1cc2c3c(c1)Oc1c(ccc4c1c1cccc5c1n4-c1cc(C(C)(C)C)cc4c1B5c1ccc(C#N)cc1O4)B3c1ccc(C#N)cc1O2] 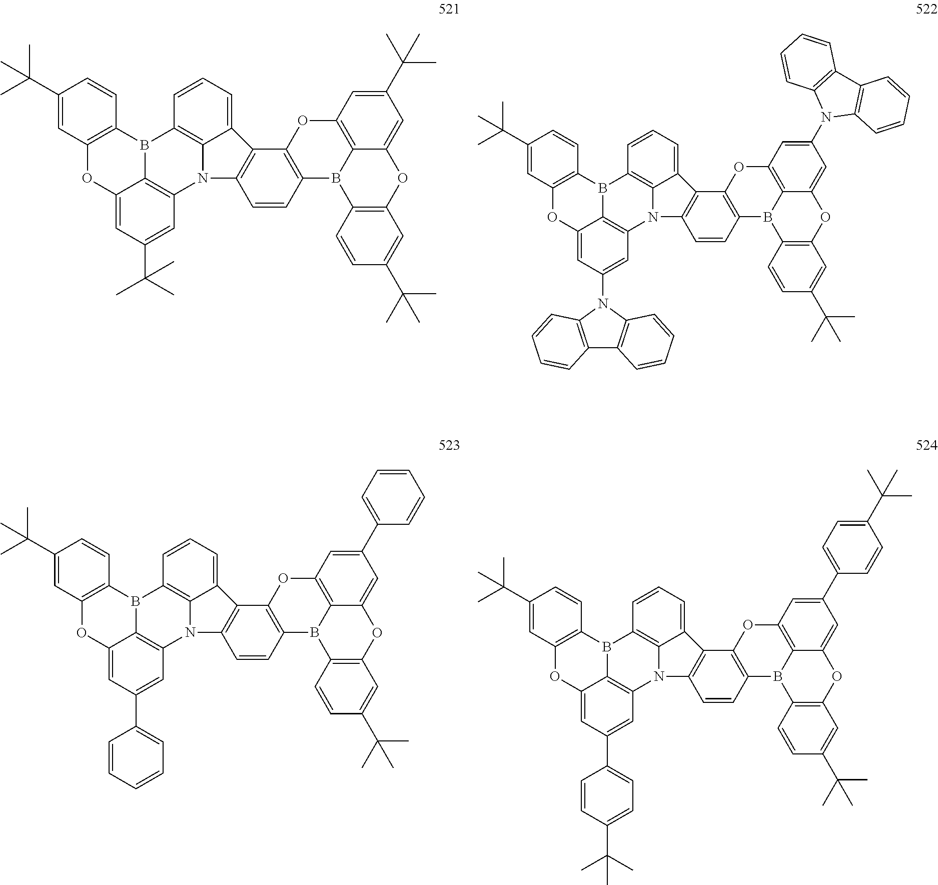 [SMILES: CC(C)(C)c1ccc2c(c1)Oc1cc(C(C)(C)C)cc3c1B2c1ccc2c(c1O3)c1cccc3c1n2-c1cc(C(C)(C)C)cc2c1B3c1ccc(C(C)(C)C)cc1O2 ; CC(C)(C)c1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1O2 ; CC(C)(C)c1ccc2c(c1)Oc1cc(-c3ccccc3)cc3c1B2c1ccc2c(c1O3)c1cccc3c1n2-c1cc(-c2ccccc2)cc2c1B3c1ccc(C(C)(C)C)cc1O2 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2O5)B4c2ccc(C(C)(C)C)cc2O3)cc1] 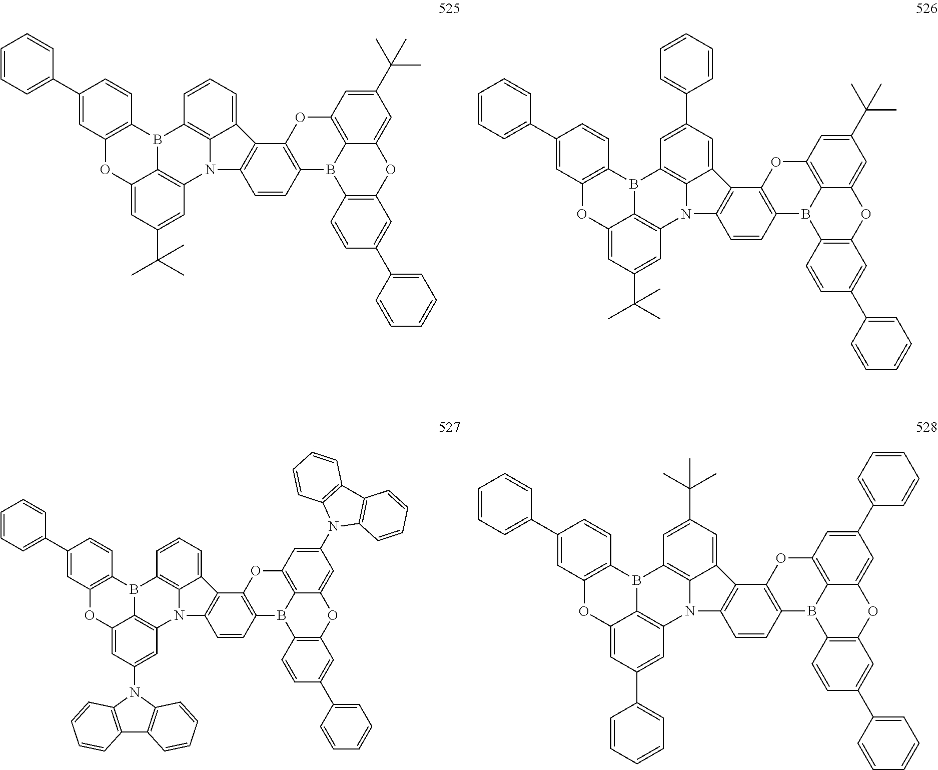 [SMILES: CC(C)(C)c1cc2c3c(c1)Oc1c(ccc4c1c1cccc5c1n4-c1cc(C(C)(C)C)cc4c1B5c1ccc(-c5ccccc5)cc1O4)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1O4)B3c1ccc(-c3ccccc3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2O3)cc1 ; CC(C)(C)c1cc2c3c(c1)c1c4c(ccc1n3-c1cc(-c3ccccc3)cc3c1B2c1ccc(-c2ccccc2)cc1O3)B1c2ccc(-c3ccccc3)cc2Oc2cc(-c3ccccc3)cc(c21)O4] 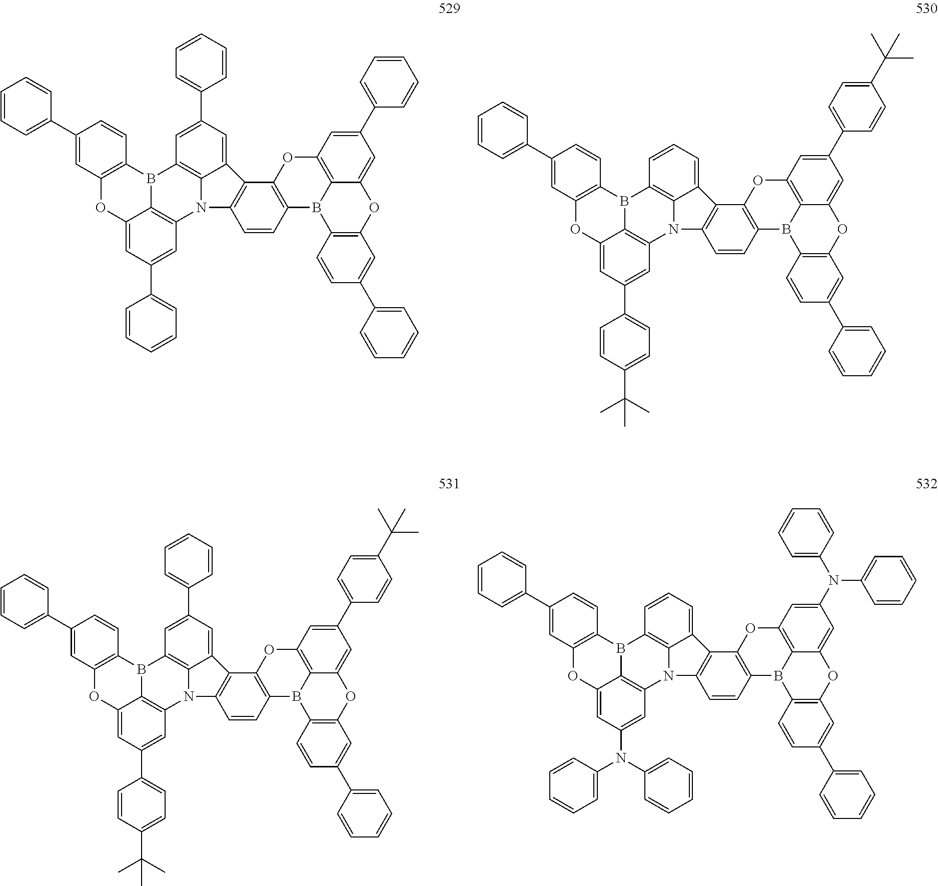 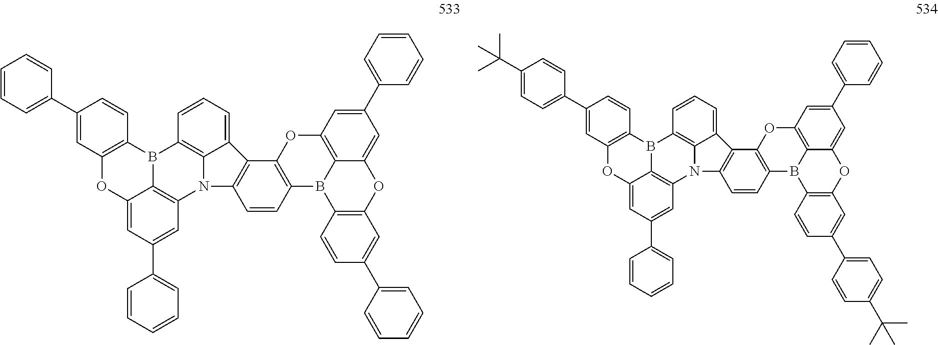 [SMILES: c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccccc4)cc2O3)cc1 ; CC(C)(C)c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2O3)cc1] 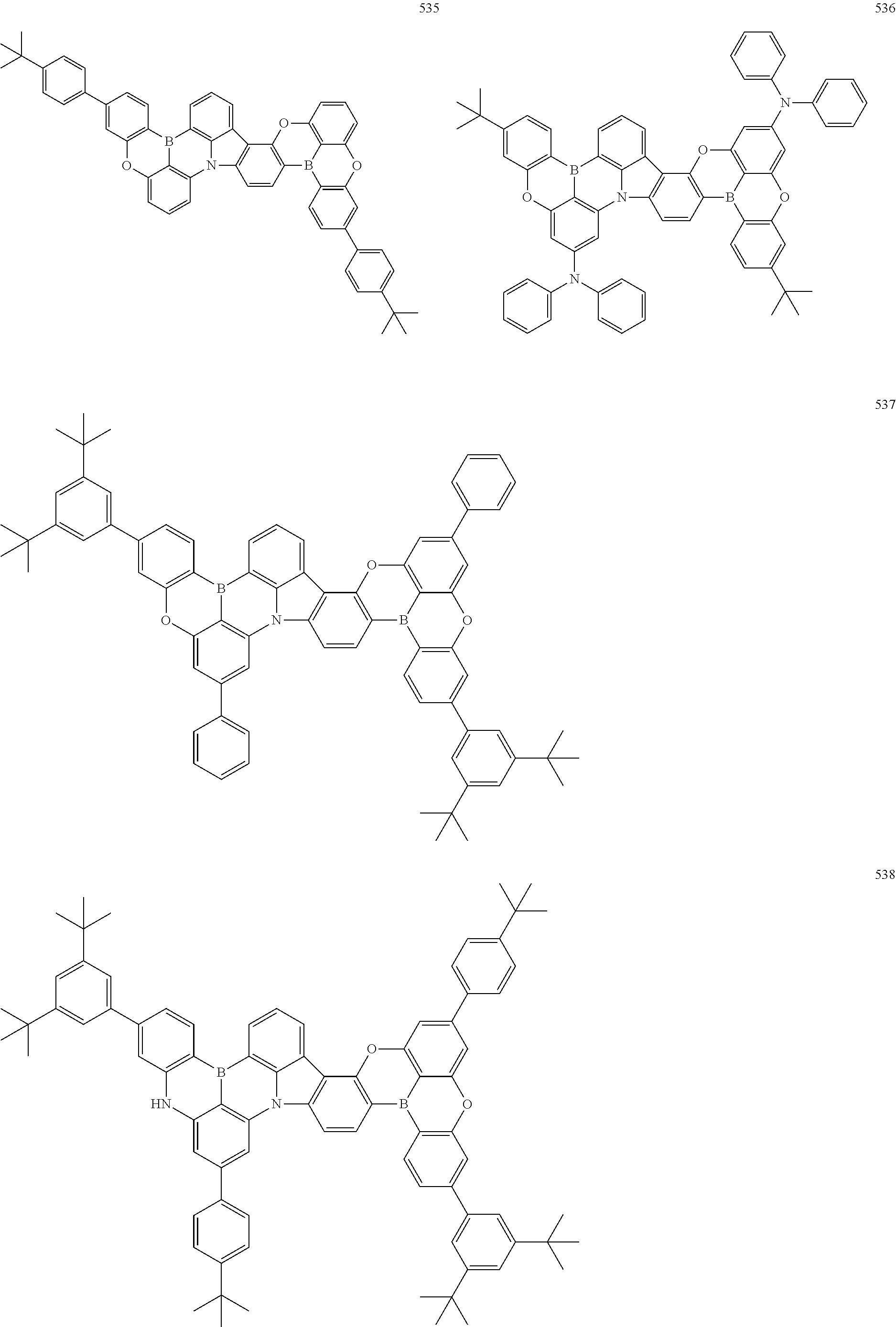 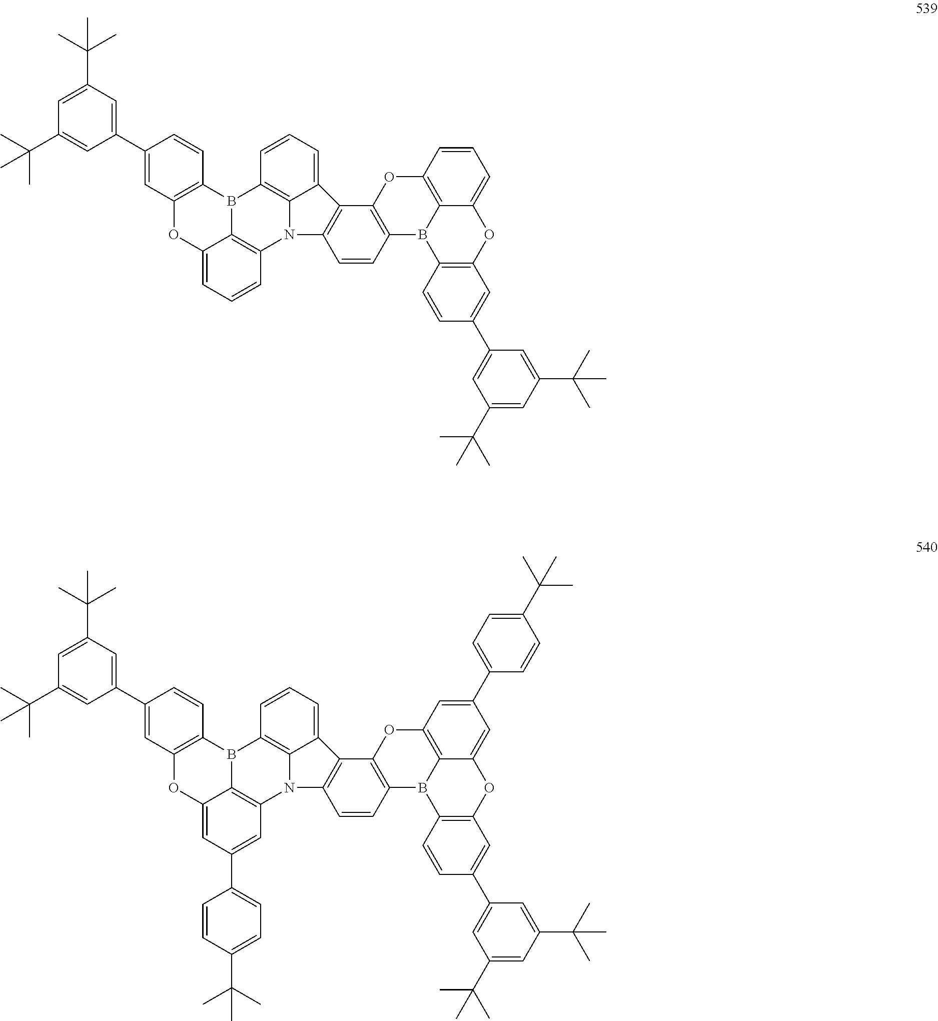 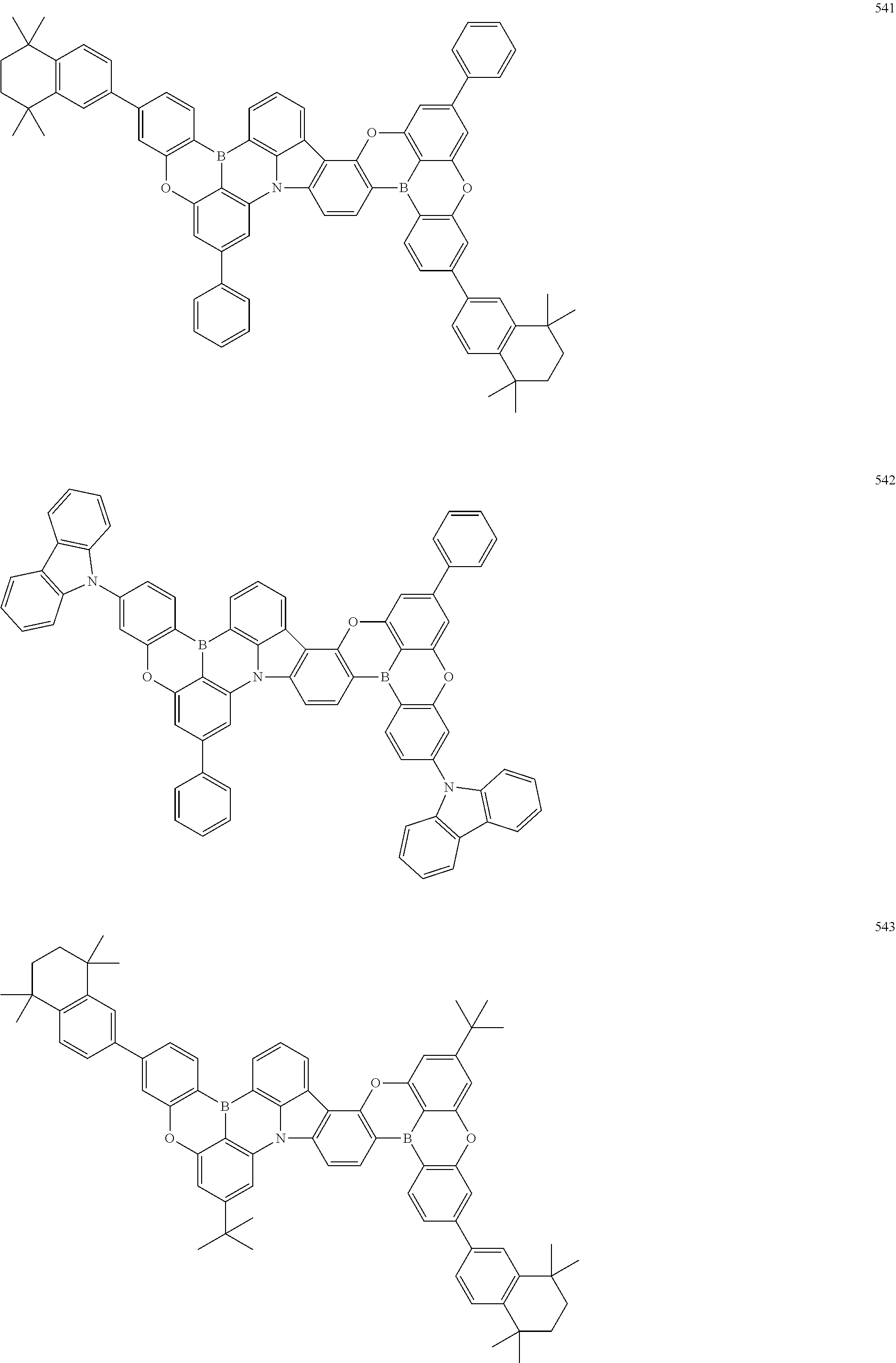 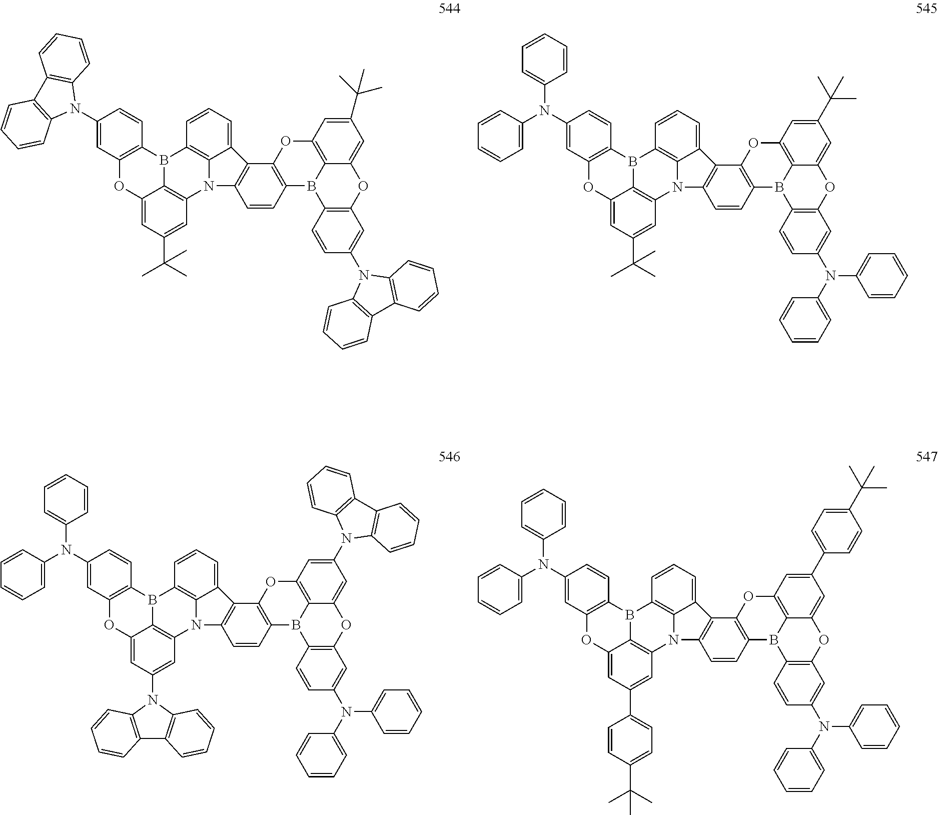 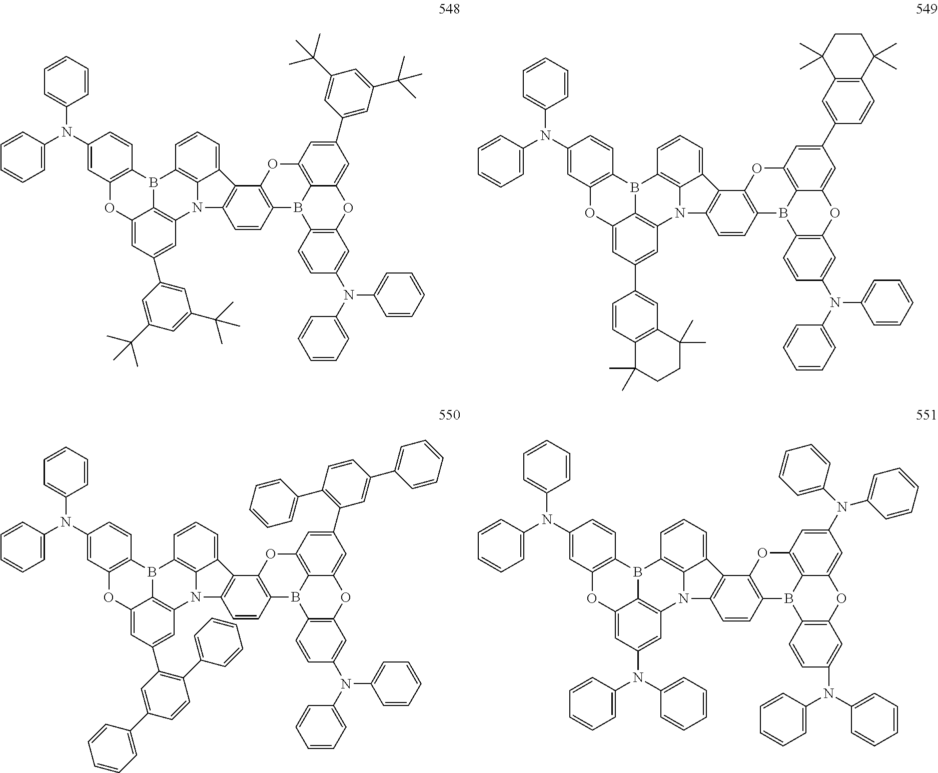 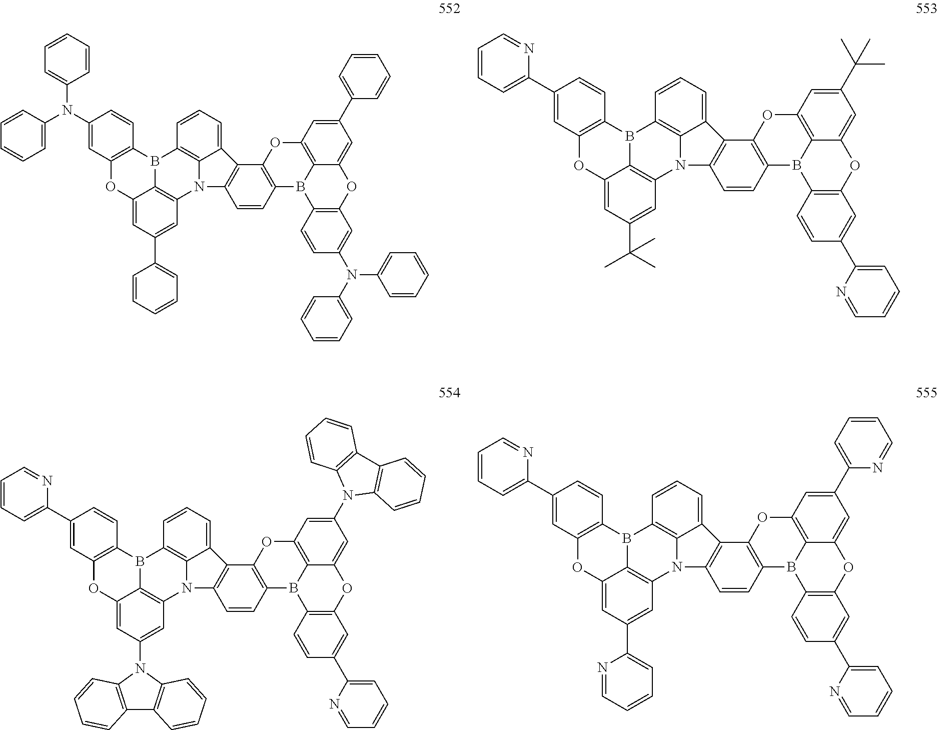 [SMILES: c1ccc(-c2cc3c4c(c2)Oc2c(ccc5c2c2cccc6c2n5-c2cc(-c5ccccc5)cc5c2B6c2ccc(N(c6ccccc6)c6ccccc6)cc2O5)B4c2ccc(N(c4ccccc4)c4ccccc4)cc2O3)cc1 ; CC(C)(C)c1cc2c3c(c1)Oc1c(ccc4c1c1cccc5c1n4-c1cc(C(C)(C)C)cc4c1B5c1ccc(-c5ccccn5)cc1O4)B3c1ccc(-c3ccccn3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccn4)cc2O3)nc1 ; c1ccc(-c2ccc3c(c2)Oc2cc(-c4ccccn4)cc4c2B3c2ccc3c(c2O4)c2cccc4c2n3-c2cc(-c3ccccn3)cc3c2B4c2ccc(-c4ccccn4)cc2O3)nc1] 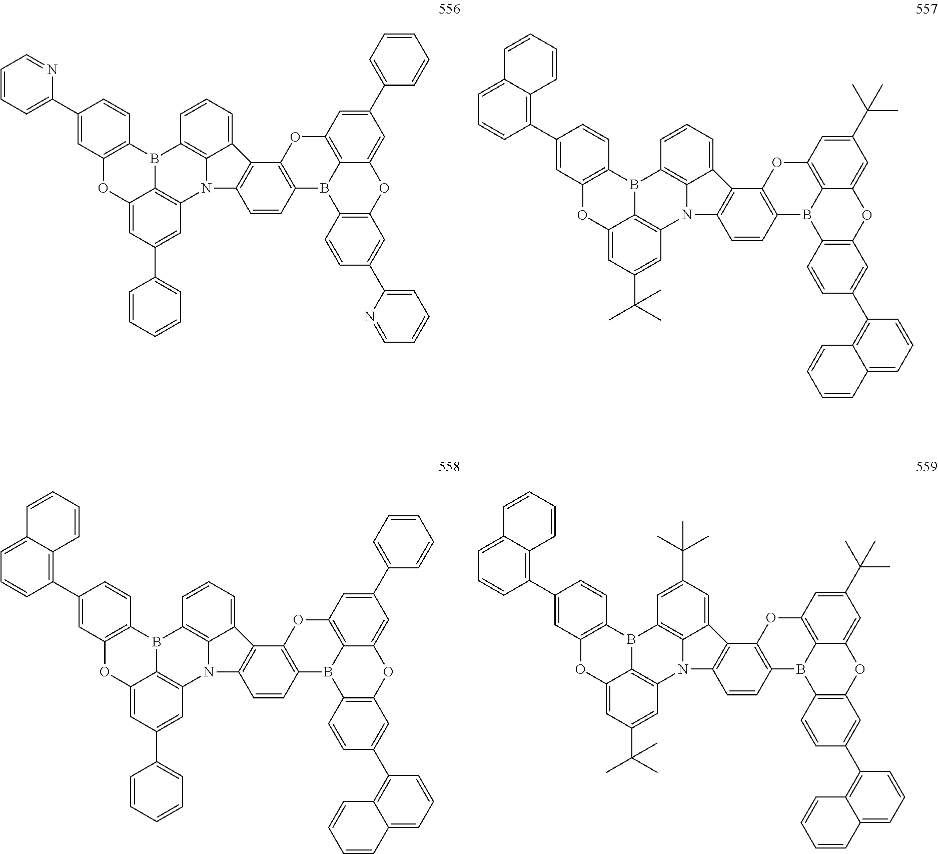 [SMILES: c1ccc(-c2cc3c4c(c2)Oc2c(ccc5c2c2cccc6c2n5-c2cc(-c5ccccc5)cc5c2B6c2ccc(-c6ccccn6)cc2O5)B4c2ccc(-c4ccccn4)cc2O3)cc1 ; CC(C)(C)c1cc2c3c(c1)Oc1c(ccc4c1c1cccc5c1n4-c1cc(C(C)(C)C)cc4c1B5c1ccc(-c5cccc6ccccc56)cc1O4)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2O5)B4c2ccc(-c4cccc5ccccc45)cc2O3)cc1 ; CC(C)(C)c1cc2c3c(c1)Oc1c(ccc4c1c1cc(C(C)(C)C)cc5c1n4-c1cc(C(C)(C)C)cc4c1B5c1ccc(-c5cccc6ccccc56)cc1O4)B3c1ccc(-c3cccc4ccccc34)cc1O2] 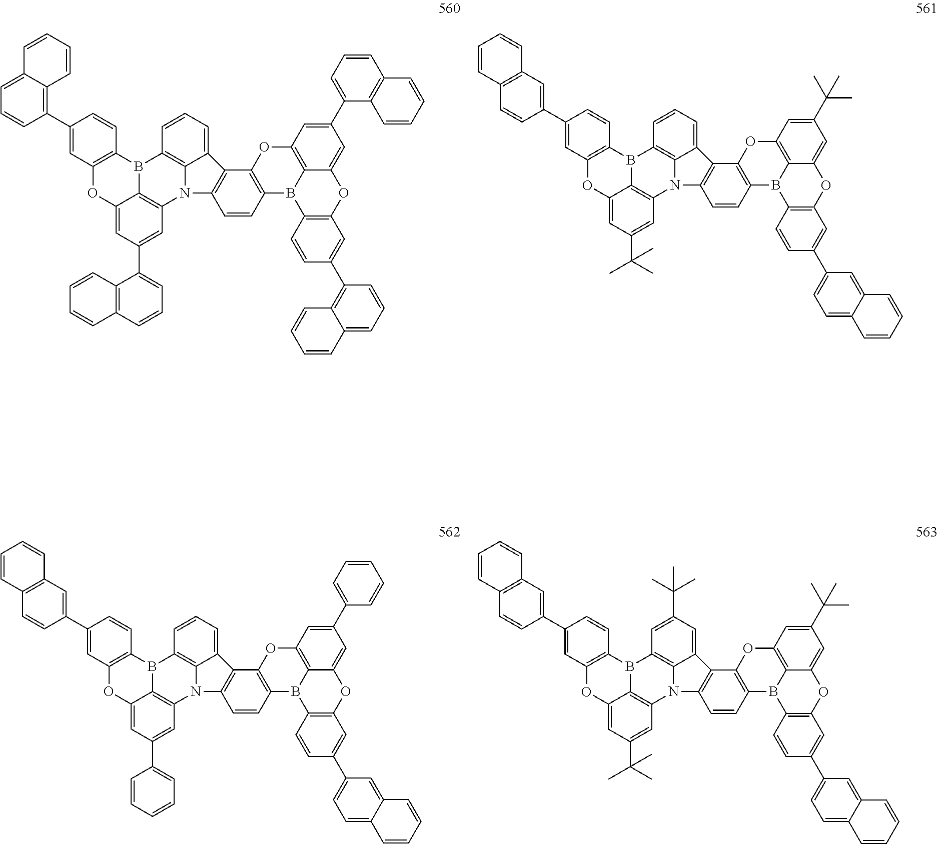 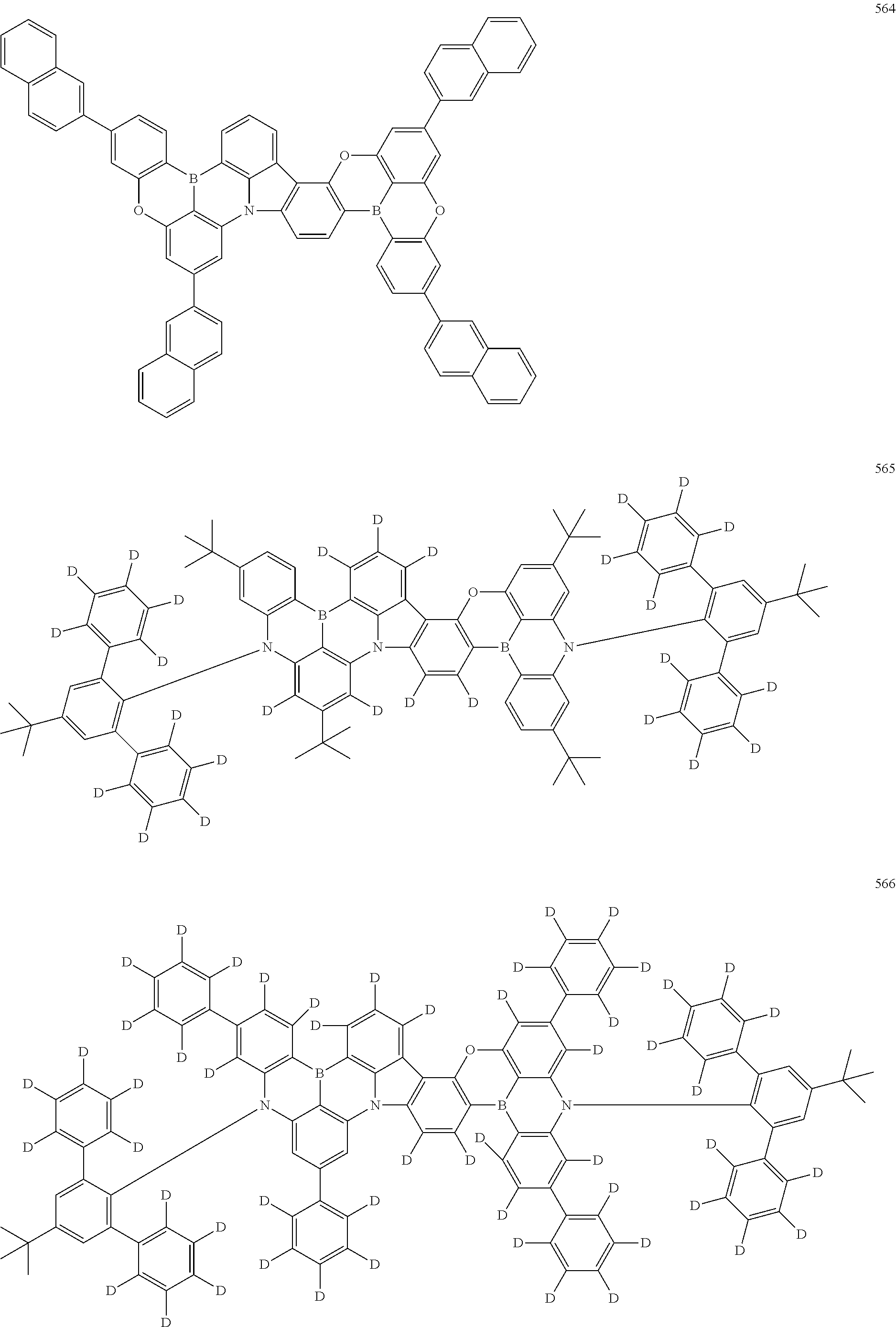 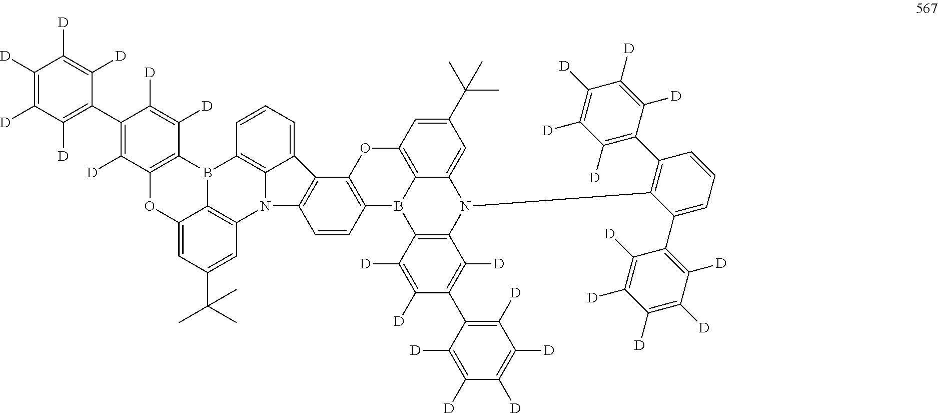 [SMILES: [2H]c1c([2H])c([2H])c(-c2cccc(-c3c([2H])c([2H])c([2H])c([2H])c3[2H])c2N2c3cc(C(C)(C)C)cc4c3B(c3ccc5c(c3O4)c3cccc4c3n5-c3cc(C(C)(C)C)cc5c3B4c3c([2H])c([2H])c(-c4c([2H])c([2H])c([2H])c([2H])c4[2H])c([2H])c3O5)c3c([2H])c([2H])c(-c4c([2H])c([2H])c([2H])c([2H])c4[2H])c([2H])c32)c([2H])c1[2H]] 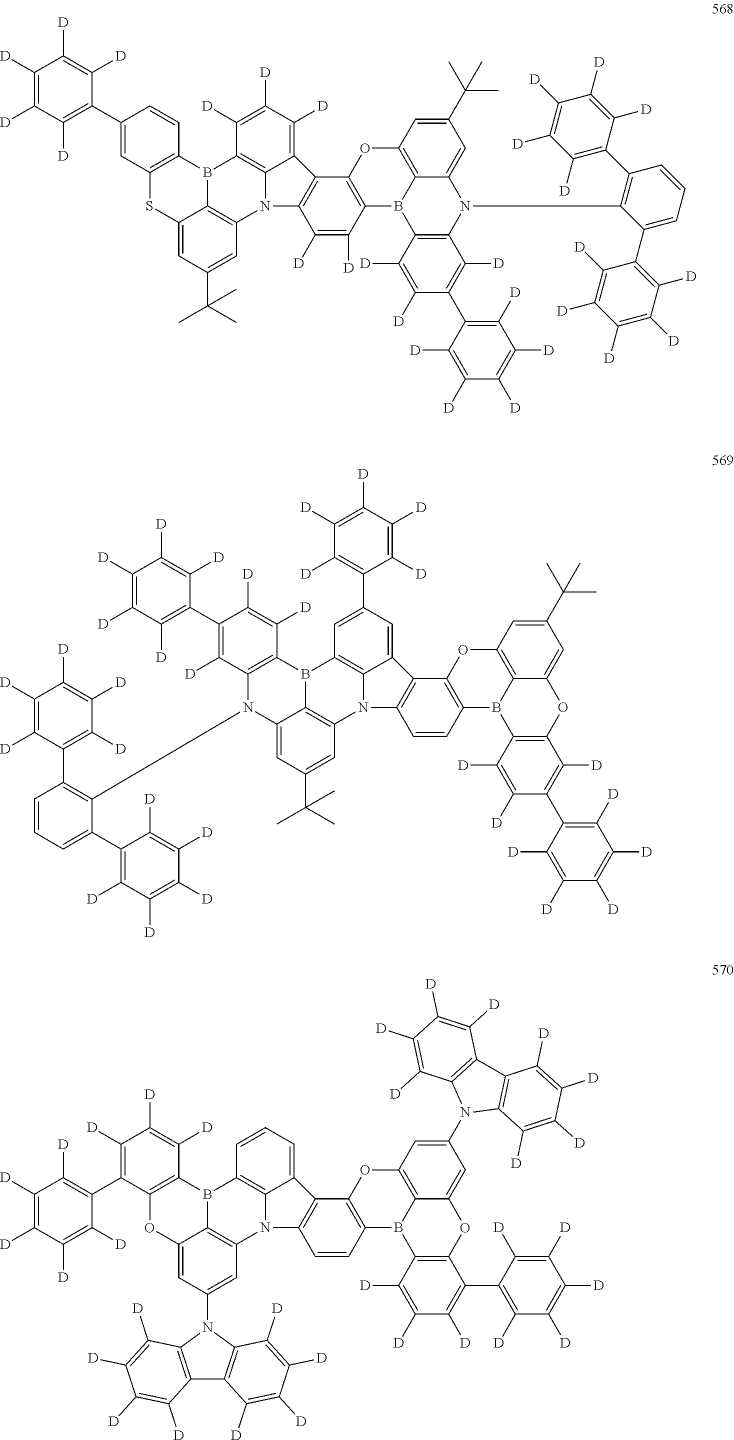 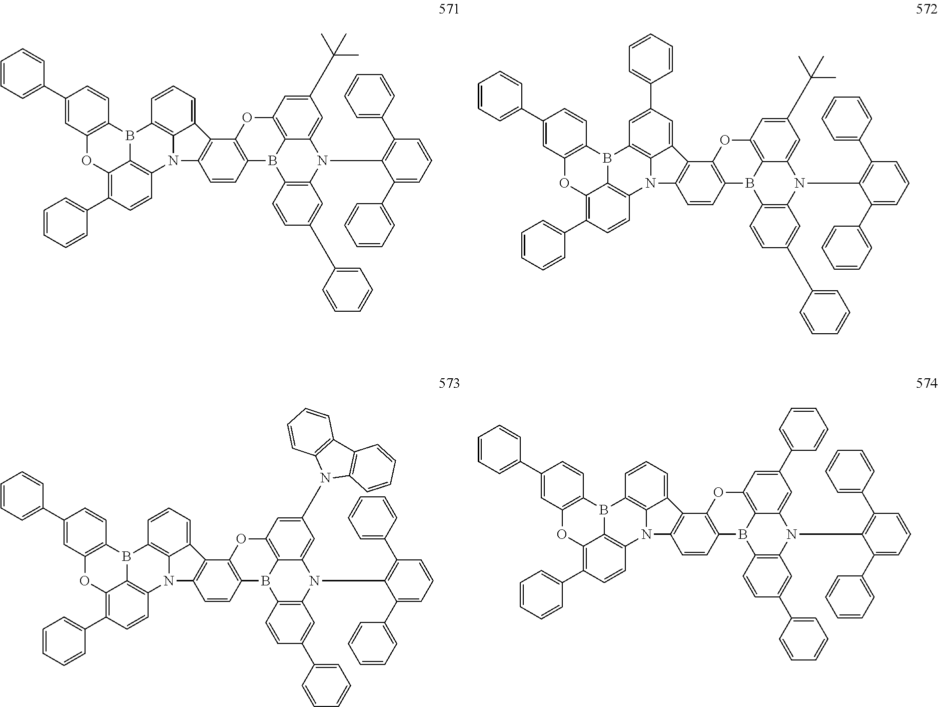 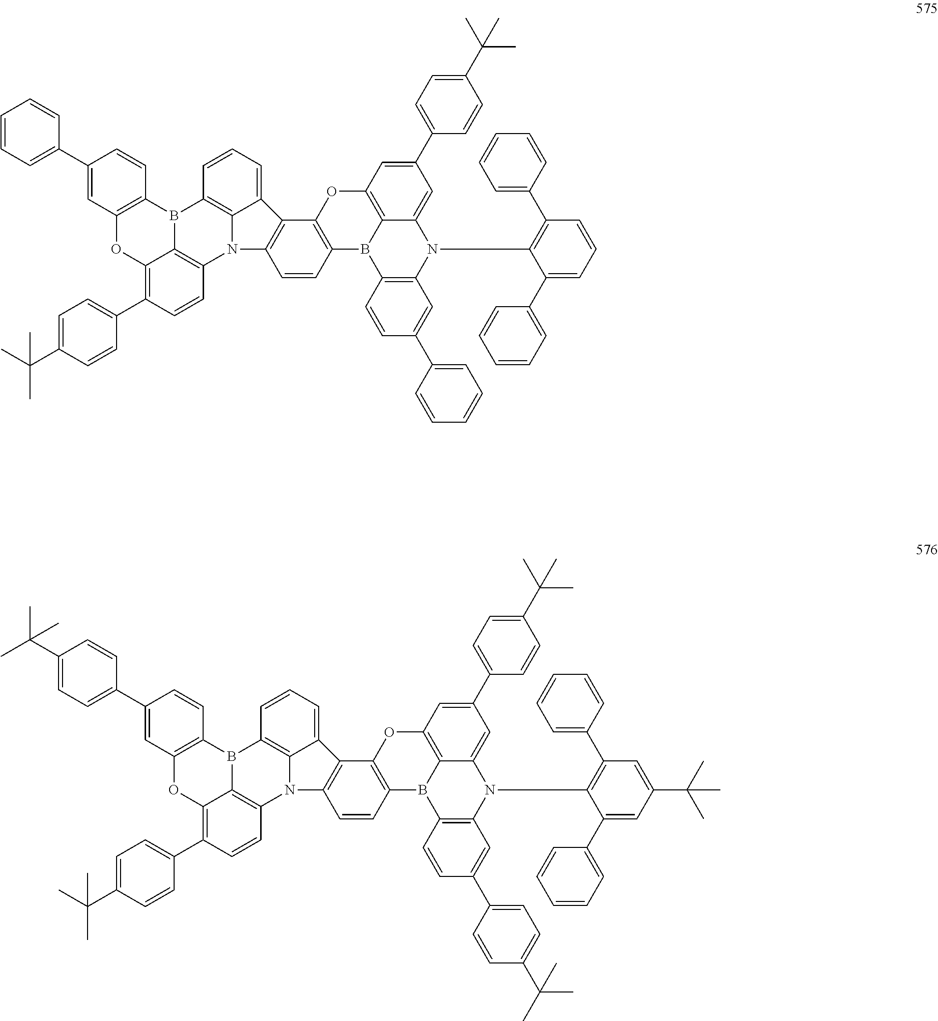 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2ccc(-c4ccc(C(C)(C)C)cc4)c4c2B3c2ccc(-c3ccccc3)cc2O4)cc1 ; CC(C)(C)c1ccc(-c2ccc3c(c2)Oc2c(-c4ccc(C(C)(C)C)cc4)ccc4c2B3c2cccc3c5c6c(ccc5n-4c23)B2c3ccc(-c4ccc(C(C)(C)C)cc4)cc3N(c3c(-c4ccccc4)cc(C(C)(C)C)cc3-c3ccccc3)c3cc(-c4ccc(C(C)(C)C)cc4)cc(c32)O6)cc1] 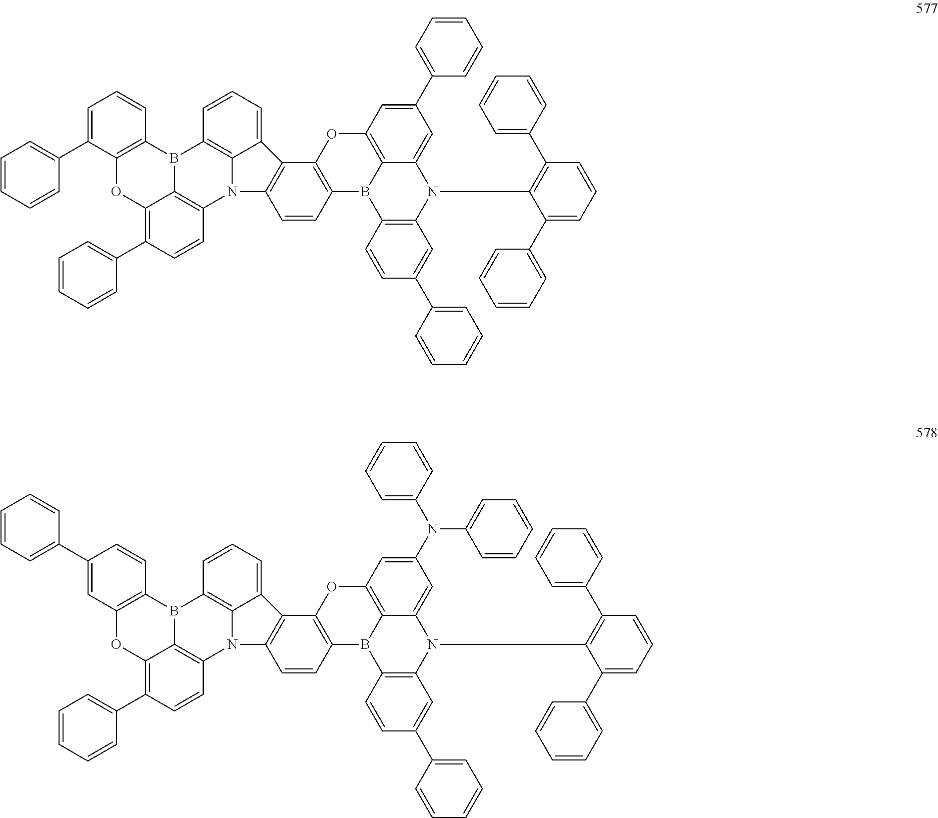 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2ccc(-c3ccccc3)c3c2B4c2cccc(-c4ccccc4)c2O3)cc1 ; c1ccc(-c2ccc3c(c2)Oc2c(-c4ccccc4)ccc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 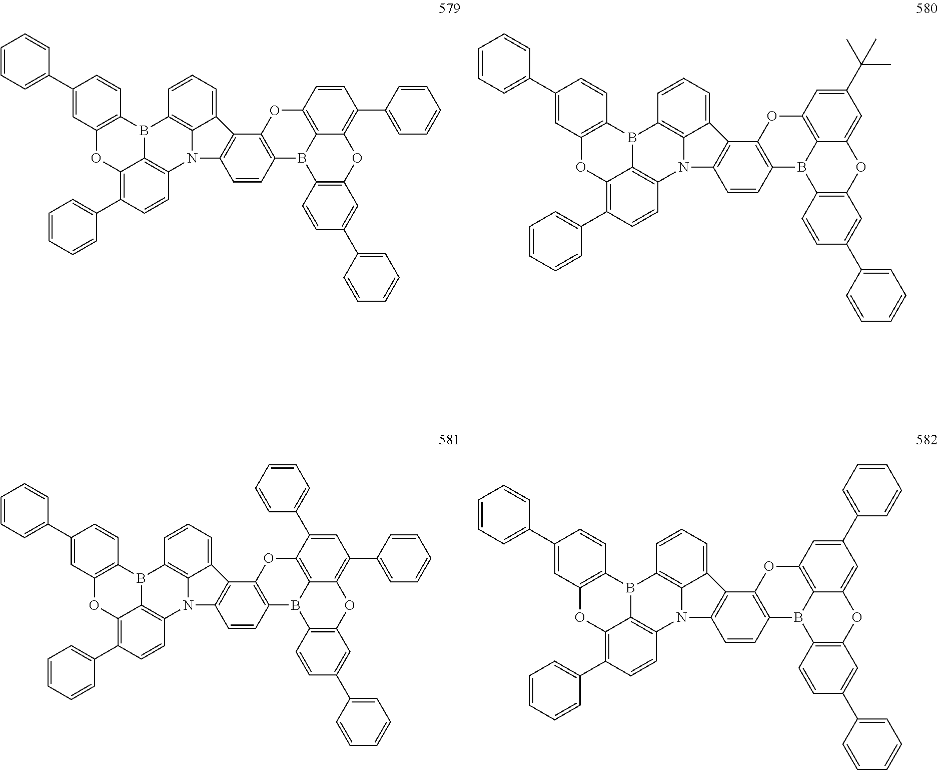 [SMILES: c1ccc(-c2ccc3c(c2)Oc2c(-c4ccccc4)ccc4c2B3c2ccc3c(c2O4)c2cccc4c2n3-c2ccc(-c3ccccc3)c3c2B4c2ccc(-c4ccccc4)cc2O3)cc1 ; CC(C)(C)c1cc2c3c(c1)Oc1c(ccc4c1c1cccc5c1n4-c1ccc(-c4ccccc4)c4c1B5c1ccc(-c5ccccc5)cc1O4)B3c1ccc(-c3ccccc3)cc1O2 ; c1ccc(-c2ccc3c(c2)Oc2c(-c4ccccc4)cc(-c4ccccc4)c4c2B3c2ccc3c(c2O4)c2cccc4c2n3-c2ccc(-c3ccccc3)c3c2B4c2ccc(-c4ccccc4)cc2O3)cc1 ; c1ccc(-c2ccc3c(c2)Oc2cc(-c4ccccc4)cc4c2B3c2ccc3c(c2O4)c2cccc4c2n3-c2ccc(-c3ccccc3)c3c2B4c2ccc(-c4ccccc4)cc2O3)cc1] 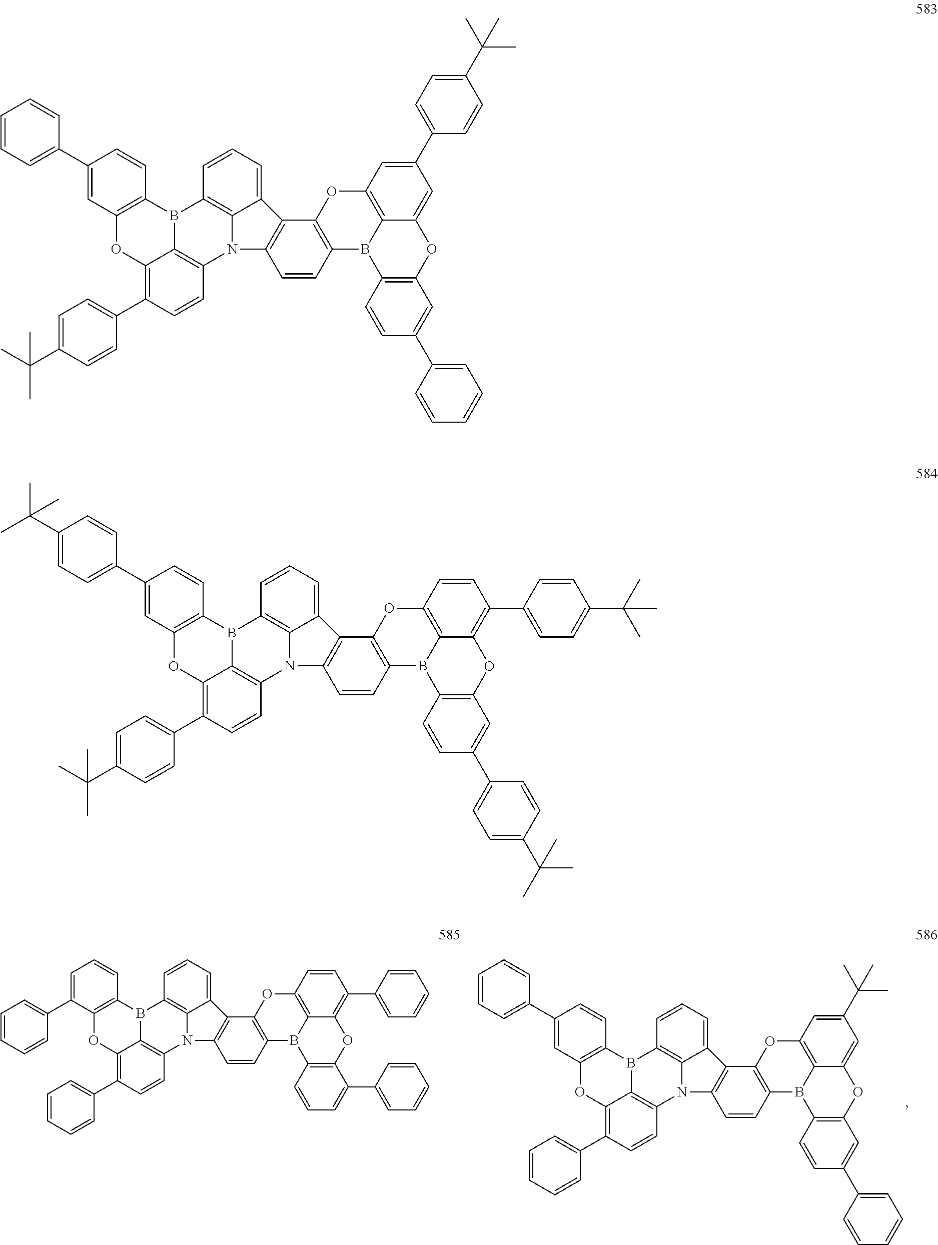
and
where, in Compound Group 1, D is a deuterium atom.

11. A fused polycyclic compound represented by Formula 1: 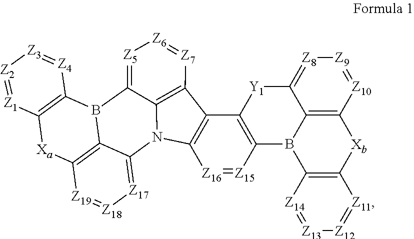
and
wherein, in Formula 1,
Xₐ, X_{b}, and Y₁ are each independently O, S, or NRₓ,
Z₁ to Z₁₉ are each independently N or CR_{y},
Rₓ and R_{y} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring, and
the fused polycyclic compound comprises a chemical structure in which one or more hydrogen atoms of the fused polycyclic compound are optionally substituted with deuterium atom.

12. The fused polycyclic compound as claimed in claim 11, wherein Formula is represented by Formula 2: 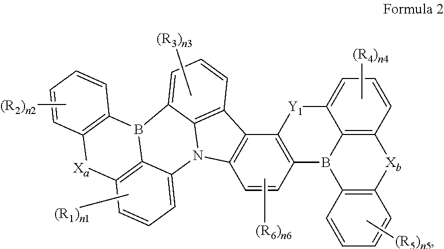
and
wherein, in Formula 2,
R₁ to R₆ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
n1, n3, and n4 are each independently an integer of 0 to 3,
n2 and n5 are each independently an integer of 0 to 4,
n6 is an integer of 0 to 2, and
Xₐ, X_{b}, and Y₁ are the same as defined in Formula 1.

13. The fused polycyclic compound as claimed in claim 12, wherein Formula 2 is represented by any one selected from among Formula 2-1 to Formula 2-8: 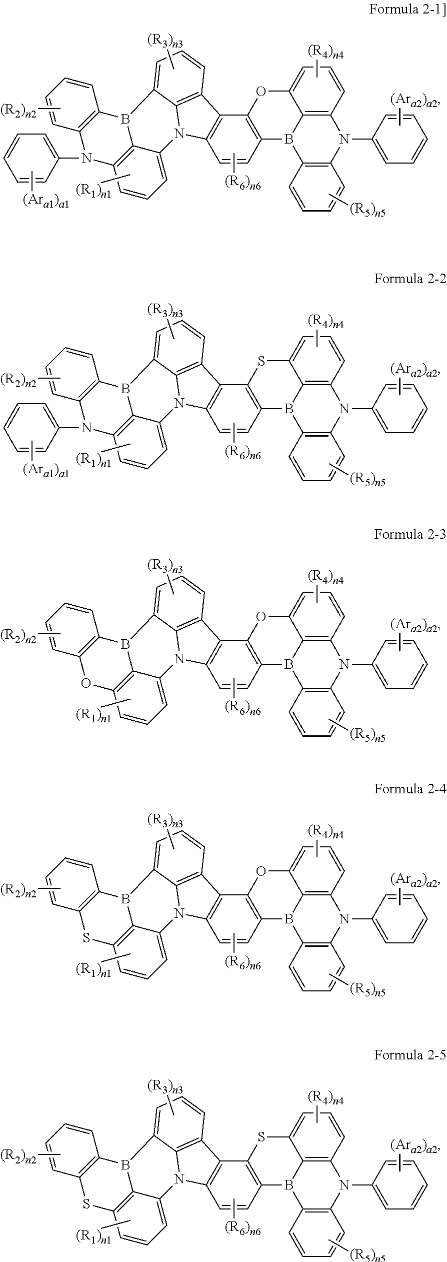 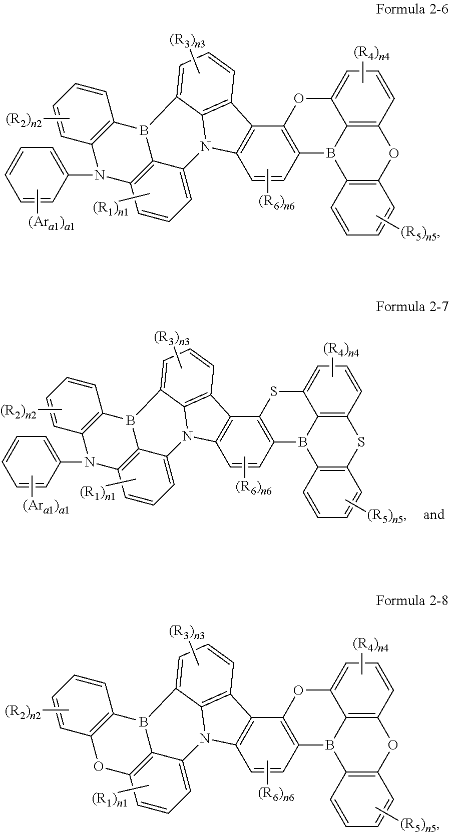
wherein, in Formula 2-1 to Formula 2-8,
Arₐ₁ and Arₐ₂ are each independently a hydrogen atom, a deuterium atom, a substituted or unsubstituted alkyl group having 1 to 20 carbon atoms, a substituted or unsubstituted cycloalkyl group having 3 to 10 ring-forming carbon atoms, or a substituted or unsubstituted aryl group having 6 to 30 ring-forming carbon atoms, and/or are bonded to an adjacent group to form a ring,
a1 and a2 are each independently an integer of 0 to 5, and
R₁ to R₆ and n1 to n6 are the same as defined in Formula 2.

14. The fused polycyclic compound as claimed in claim 12, wherein Formula 2 is represented by Formula 3: 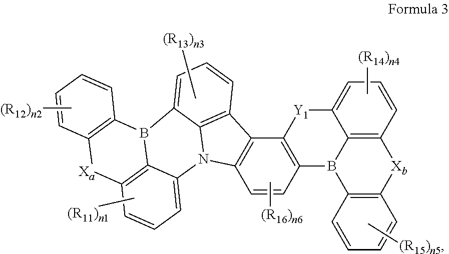
and
wherein, in Formula 3,
R₁₁ to R₁₅ are each independently a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
R₁₆ is a hydrogen atom or a deuterium atom,
n16 is an integer of 0 to 2,
Xₐ, X_{b}, and Y₁ are the same as defined in Formula 1, and
n1 to n5 are the same as defined in Formula 2.

15. The fused polycyclic compound as claimed in claim 12, wherein Formula 2 is represented by Formula 4: 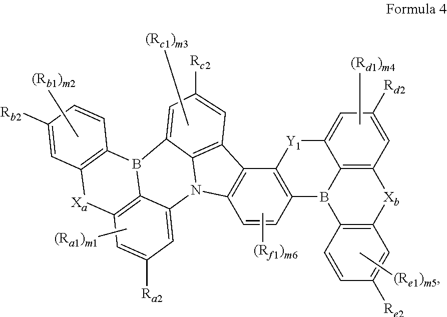
and
wherein, in Formula 4,
Rₐ₁, R_{b1}, R_{c1}, R_{d1}, Rₑ₁, and R_{f1} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
Rₐ₂, R_{b2}, R_{c2}, R_{d2}, and Rₑ₂ are each independently a hydrogen atom, a deuterium atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring,
m1, m3, and m4 are each independently an integer of 0 to 2,
m2 and m5 are each independently an integer of 0 to 3,
m6 is an integer of 0 to 2, and
Xₐ, X_{b}, and Y₁ are the same as defined in Formula 1.

16. The fused polycyclic compound as claimed in claim 12, wherein R₁ to R₆ in Formula 2 are each independently a hydrogen atom, a deuterium atom, or represented by any one selected from among R-1 to R-14: 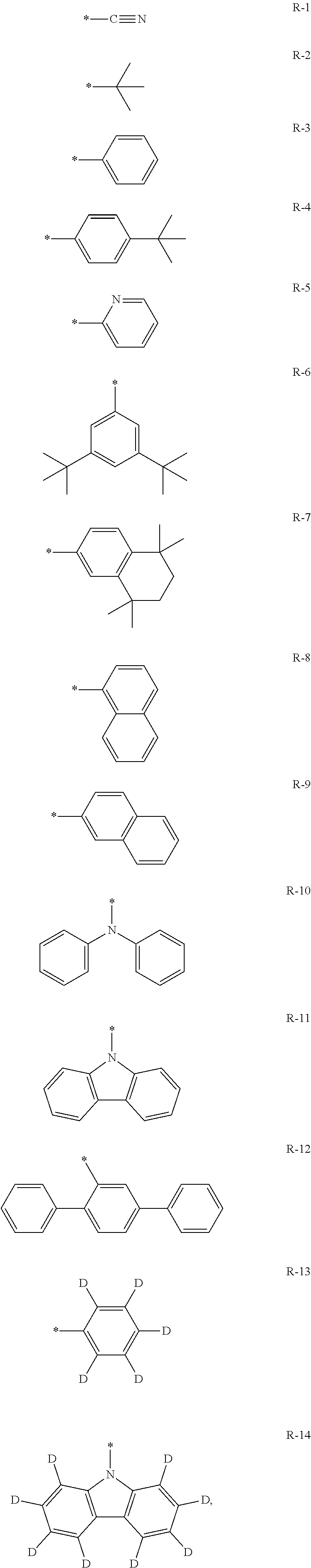
and
wherein, in R-13 and R-14, D is a deuterium atom.

17. The fused polycyclic compound as claimed in claim 11, wherein, in Formula 1, Rₓ is a hydrogen atom, a deuterium atom, a substituted or unsubstituted phenyl group, a substituted or unsubstituted benzocyclohexyl group, a substituted or unsubstituted biphenyl group, a substituted or unsubstituted terphenyl group, or a substituted or unsubstituted quarterphenyl group.

18. The fused polycyclic compound as claimed in claim 11, wherein the fused polycyclic compound is represented by any one selected from among the compounds in Compound Group 1: 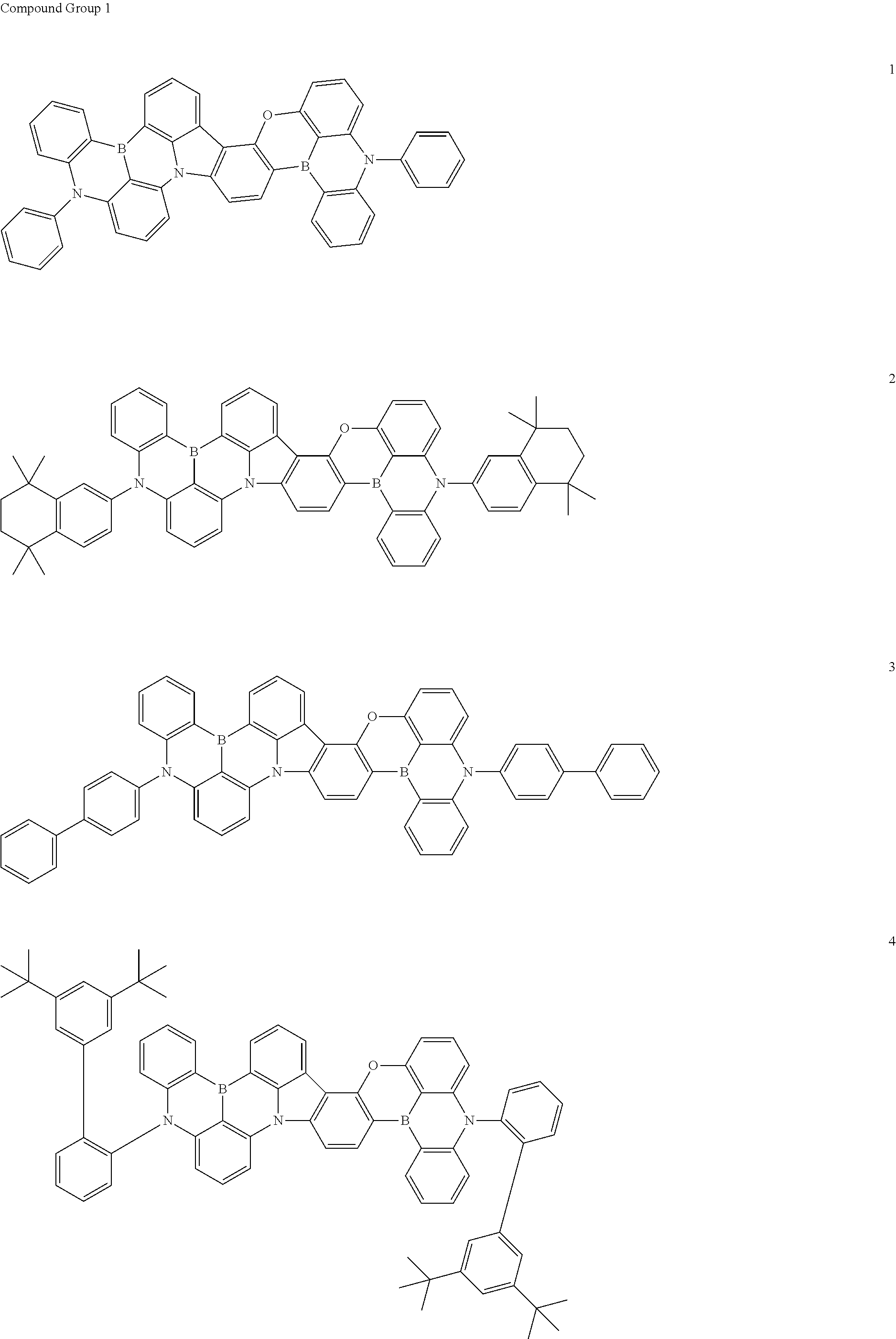 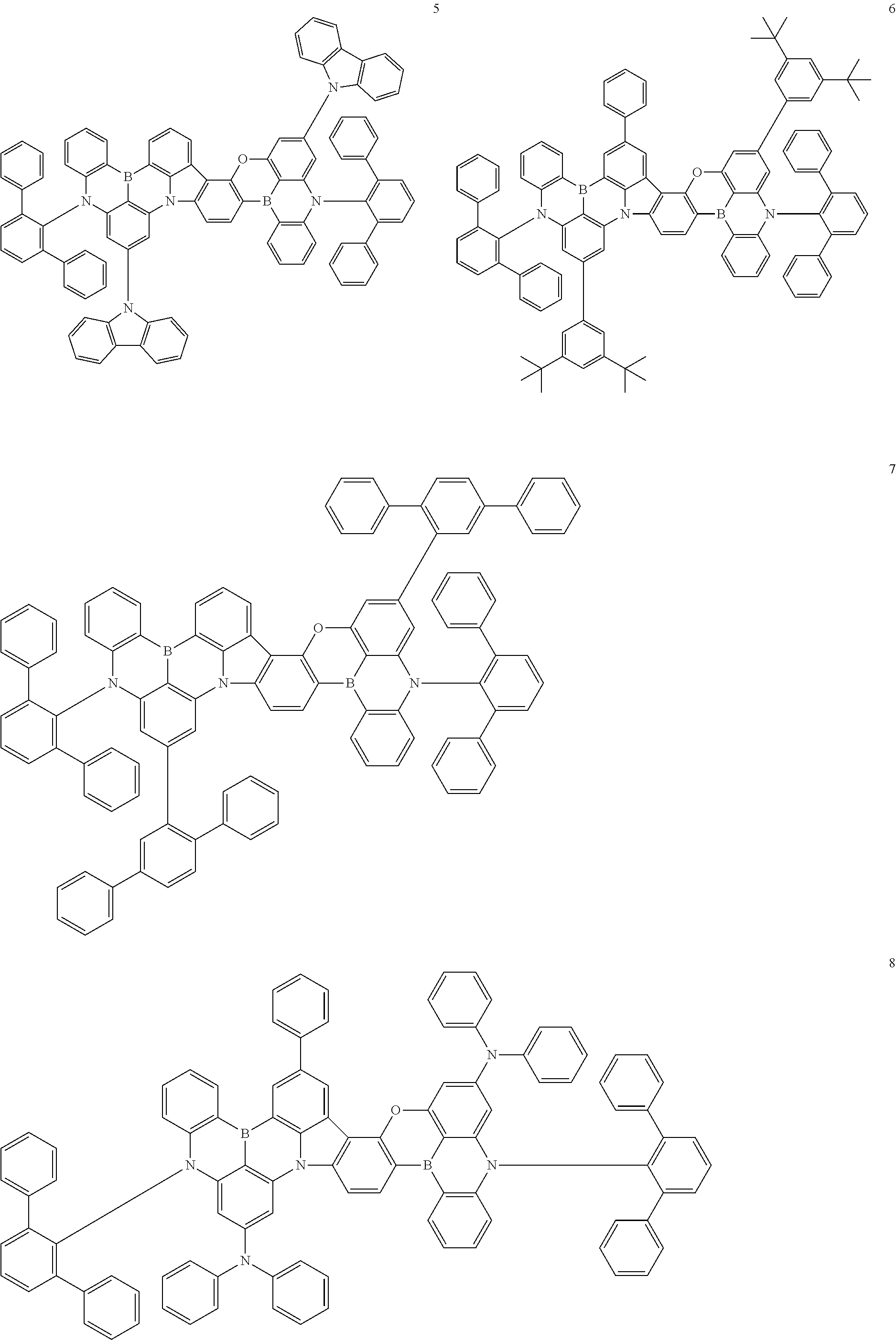 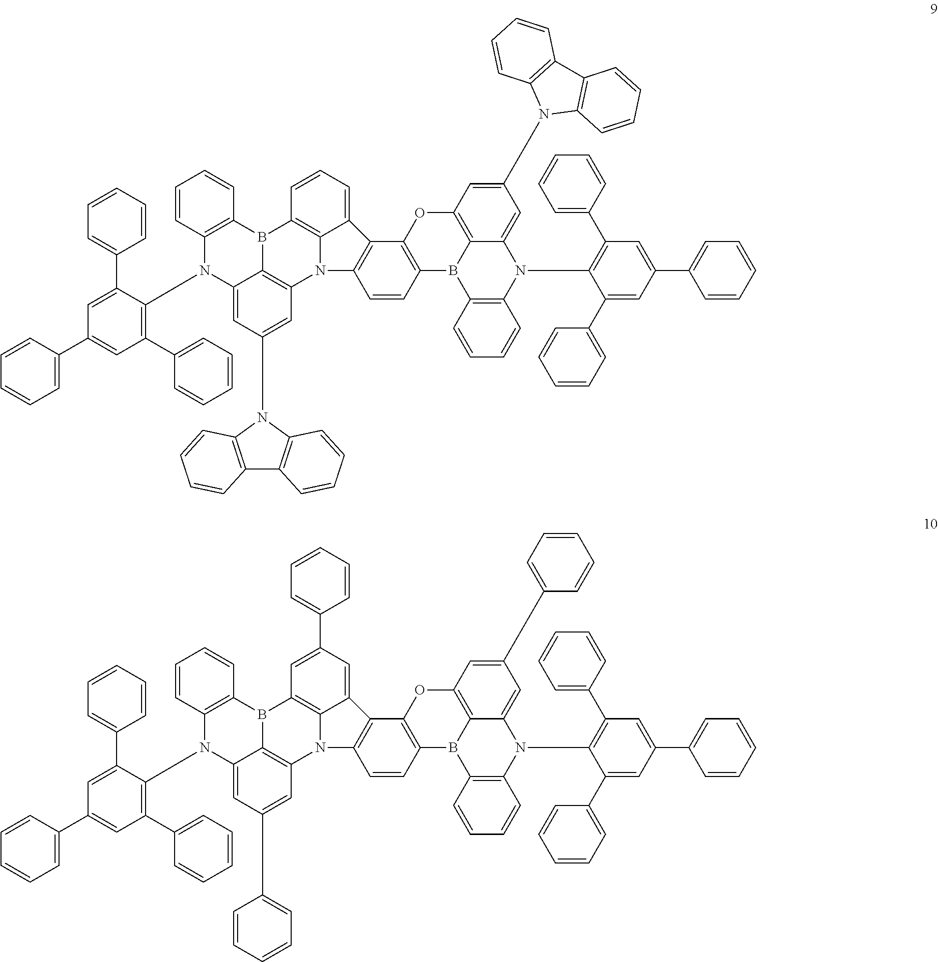 [SMILES: c1ccc(-c2cc(-c3ccccc3)c(N3c4ccccc4B4c5ccc6c(c5Oc5cc(-n7c8ccccc8c8ccccc87)cc3c54)c3cccc4c3n6-c3cc(-n5c6ccccc6c6ccccc65)cc5c3B4c3ccccc3N5c3c(-c4ccccc4)cc(-c4ccccc4)cc3-c3ccccc3)c(-c3ccccc3)c2)cc1 ; c1ccc(-c2cc(-c3ccccc3)c(N3c4ccccc4B4c5ccc6c(c5Oc5cc(-c7ccccc7)cc3c54)c3cc(-c4ccccc4)cc4c3n6-c3cc(-c5ccccc5)cc5c3B4c3ccccc3N5c3c(-c4ccccc4)cc(-c4ccccc4)cc3-c3ccccc3)c(-c3ccccc3)c2)cc1] 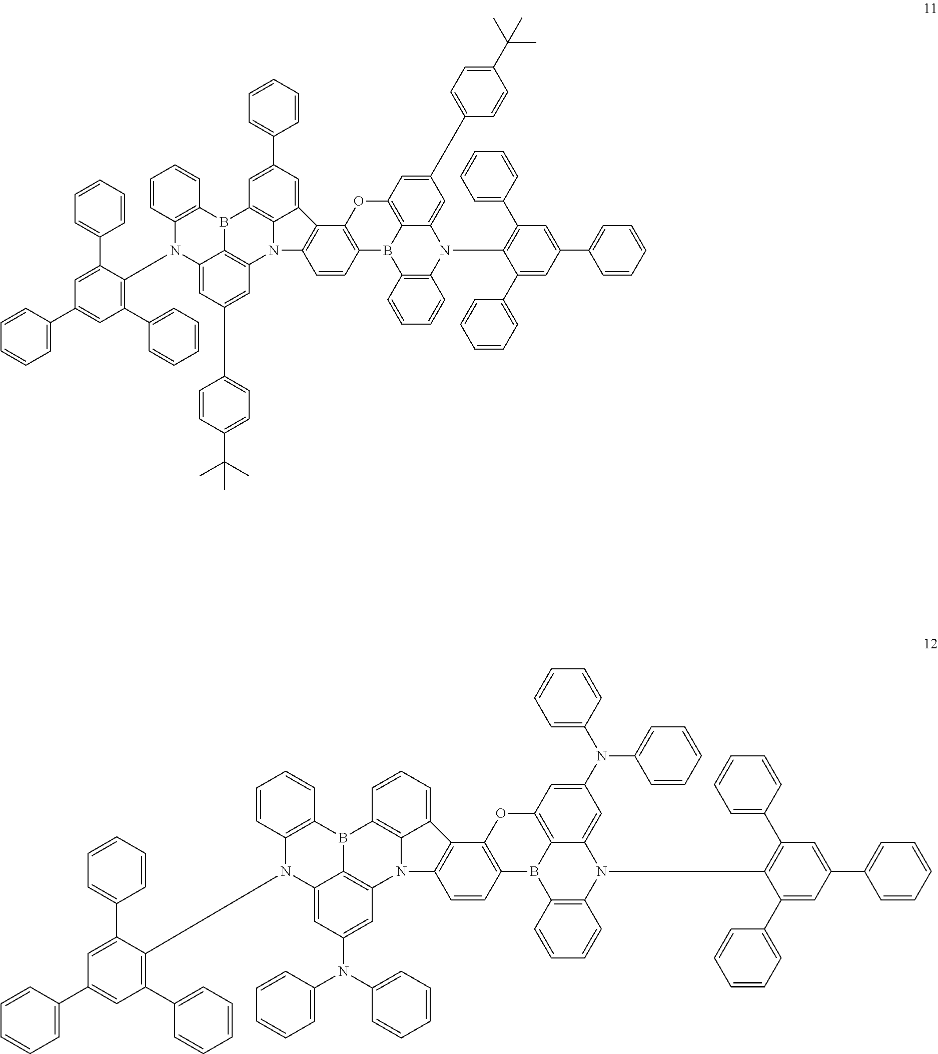 [SMILES: CC(C)(C)c1ccc(-c2cc3c4c(c2)N(c2c(-c5ccccc5)cc(-c5ccccc5)cc2-c2ccccc2)c2ccccc2B4c2ccc4c(c2O3)c2cc(-c3ccccc3)cc3c2n4-c2cc(-c4ccc(C(C)(C)C)cc4)cc4c2B3c2ccccc2N4c2c(-c3ccccc3)cc(-c3ccccc3)cc2-c2ccccc2)cc1 ; c1ccc(-c2cc(-c3ccccc3)c(N3c4ccccc4B4c5ccc6c(c5Oc5cc(N(c7ccccc7)c7ccccc7)cc3c54)c3cccc4c3n6-c3cc(N(c5ccccc5)c5ccccc5)cc5c3B4c3ccccc3N5c3c(-c4ccccc4)cc(-c4ccccc4)cc3-c3ccccc3)c(-c3ccccc3)c2)cc1] 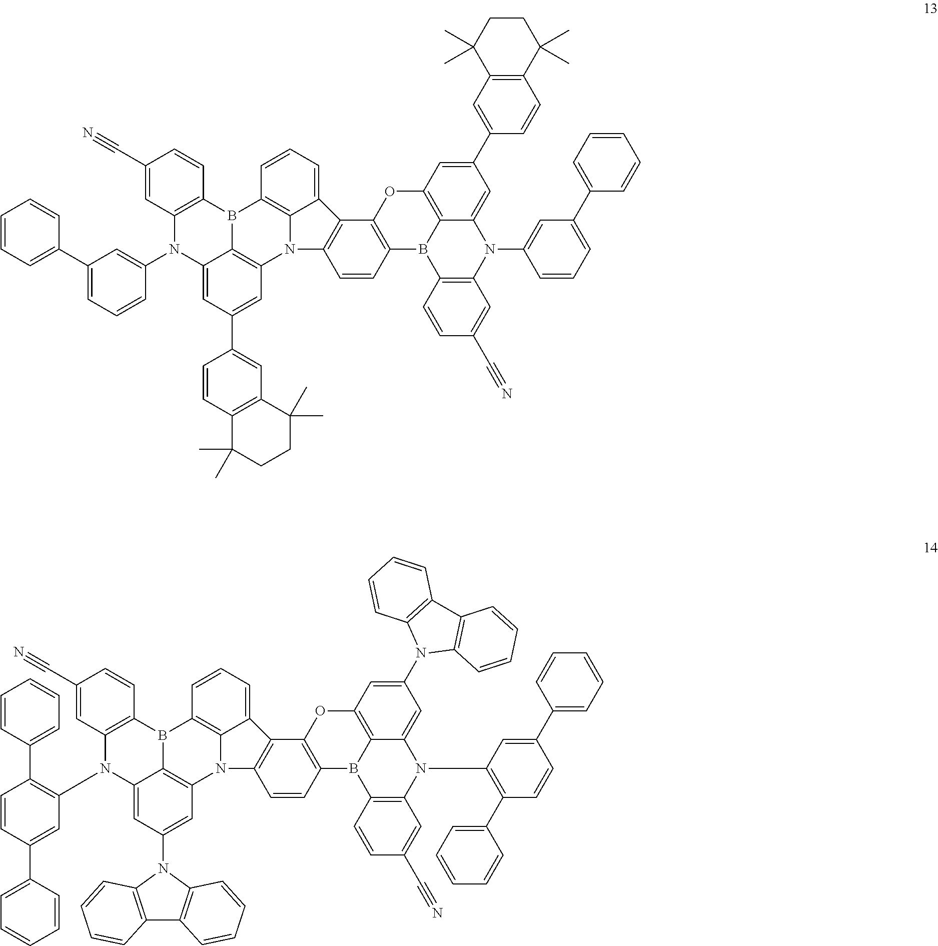 [SMILES: CC1(C)CCC(C)(C)c2cc(-c3cc4c5c(c3)N(c3cccc(-c6ccccc6)c3)c3cc(C#N)ccc3B5c3ccc5c(c3O4)c3cccc4c3n5-c3cc(-c5ccc6c(c5)C(C)(C)CCC6(C)C)cc5c3B4c3ccc(C#N)cc3N5c3cccc(-c4ccccc4)c3)ccc21 ; N#Cc1ccc2c(c1)N(c1cc(-c3ccccc3)ccc1-c1ccccc1)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1N2c1cc(-c2ccccc2)ccc1-c1ccccc1] 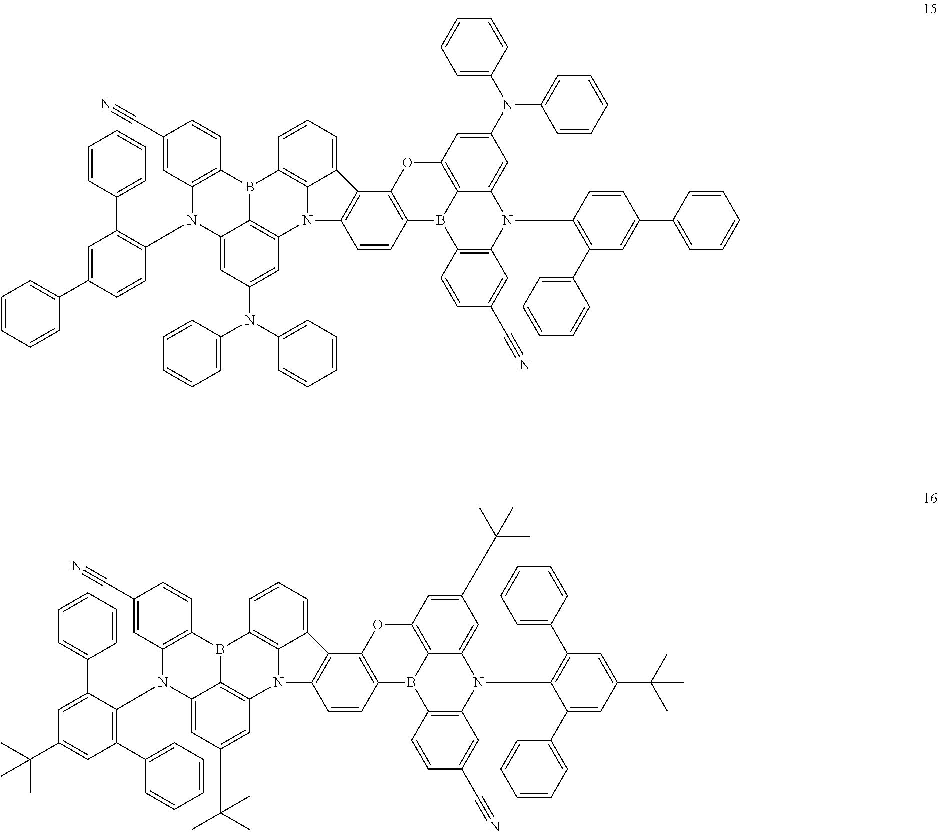 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C#N)ccc3B3c4ccc5c(c4Oc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1] 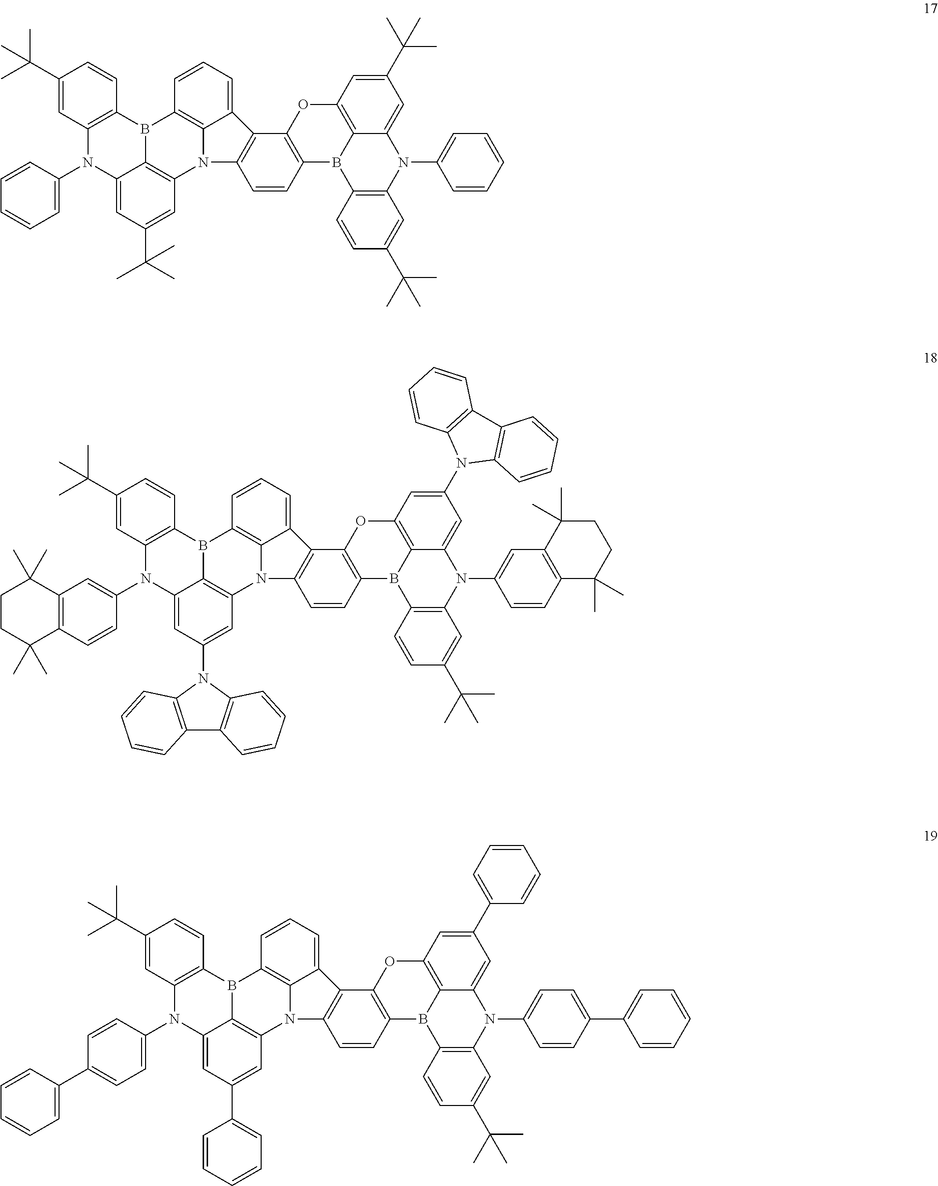 [SMILES: CC(C)(C)c1ccc2c(c1)N(c1ccccc1)c1cc(C(C)(C)C)cc3c1B2c1ccc2c(c1O3)c1cccc3c1n2-c1cc(C(C)(C)C)cc2c1B3c1ccc(C(C)(C)C)cc1N2c1ccccc1 ; CC(C)(C)c1ccc2c(c1)N(c1ccc3c(c1)C(C)(C)CCC3(C)C)c1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1N2c1ccc2c(c1)C(C)(C)CCC2(C)C ; CC(C)(C)c1ccc2c(c1)N(c1ccc(-c3ccccc3)cc1)c1cc(-c3ccccc3)cc3c1B2c1ccc2c(c1O3)c1cccc3c1n2-c1cc(-c2ccccc2)cc2c1B3c1ccc(C(C)(C)C)cc1N2c1ccc(-c2ccccc2)cc1] 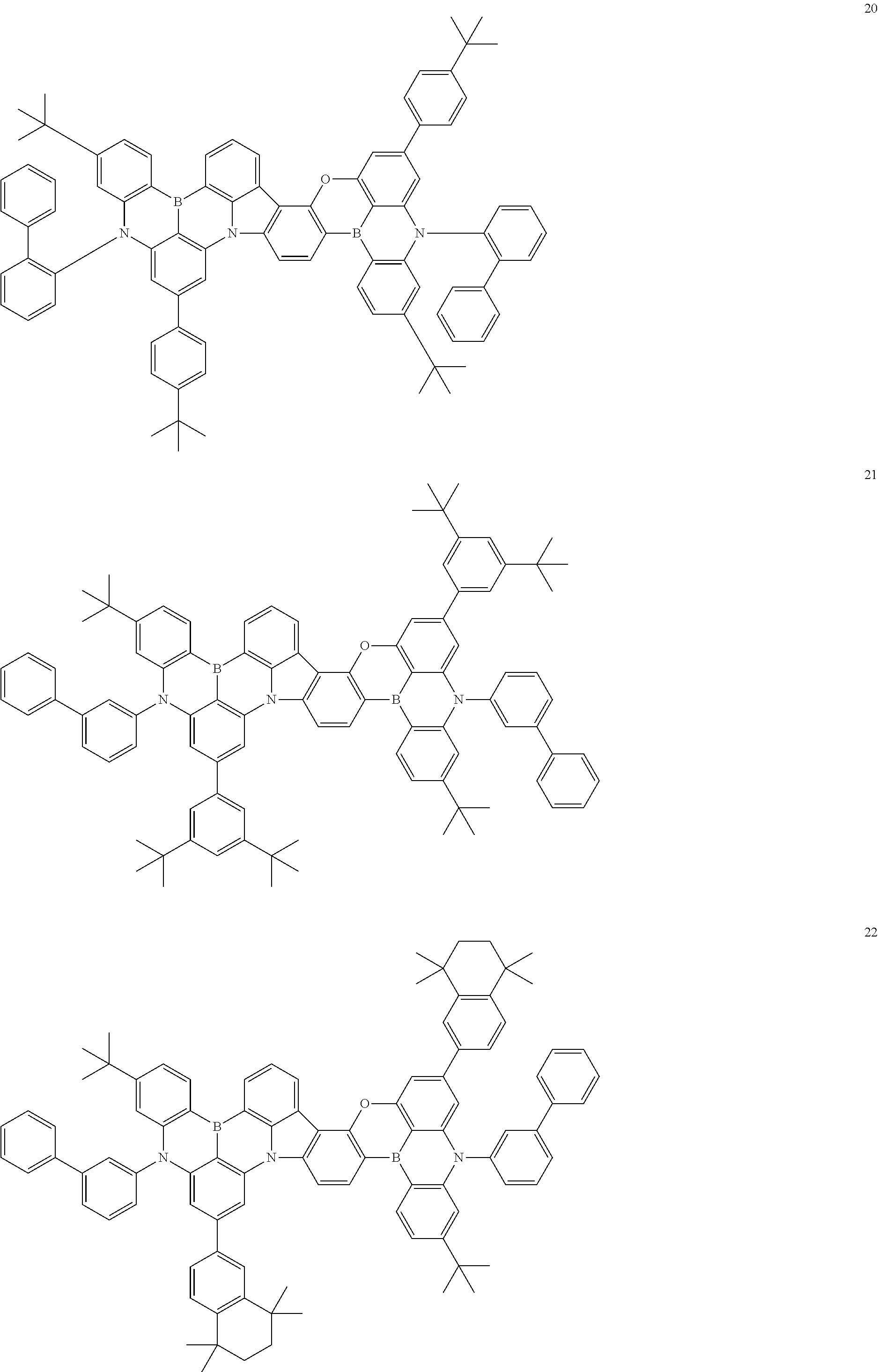 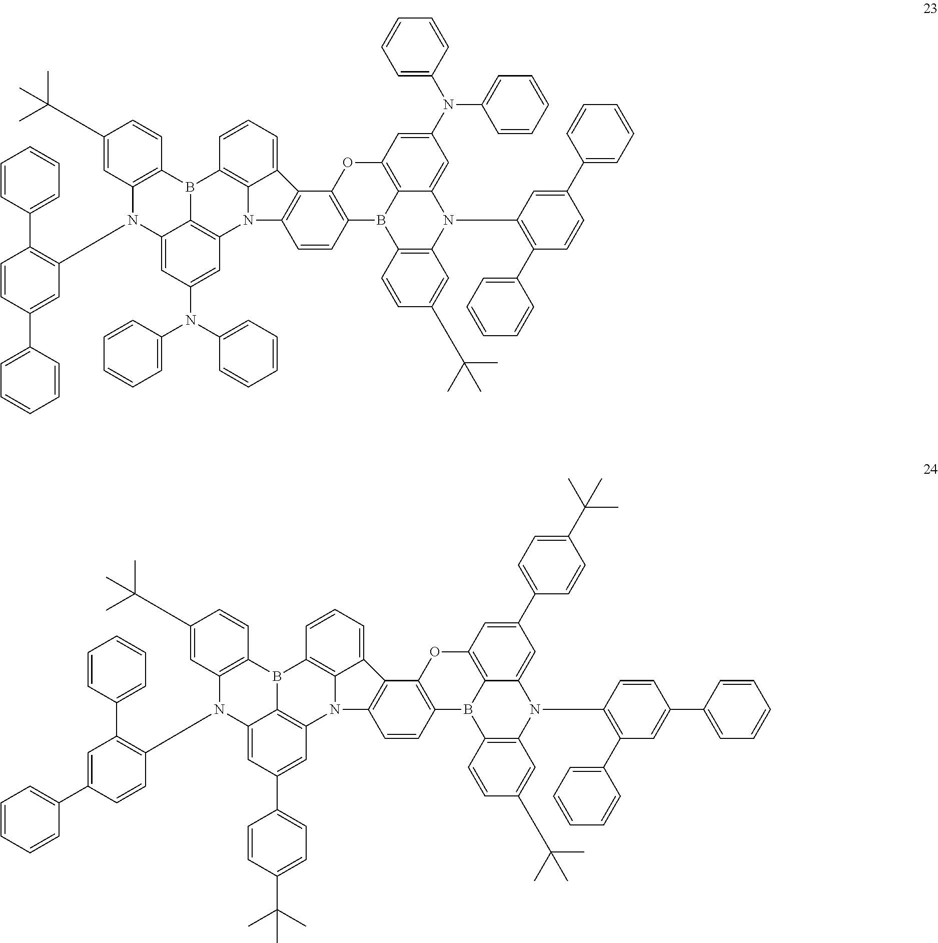 [SMILES: CC(C)(C)c1ccc2c(c1)N(c1cc(-c3ccccc3)ccc1-c1ccccc1)c1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)N(c2ccc(-c5ccccc5)cc2-c2ccccc2)c2cc(C(C)(C)C)ccc2B4c2ccc4c(c2O3)c2cccc3c2n4-c2cc(-c4ccc(C(C)(C)C)cc4)cc4c2B3c2ccc(C(C)(C)C)cc2N4c2ccc(-c3ccccc3)cc2-c2ccccc2)cc1] 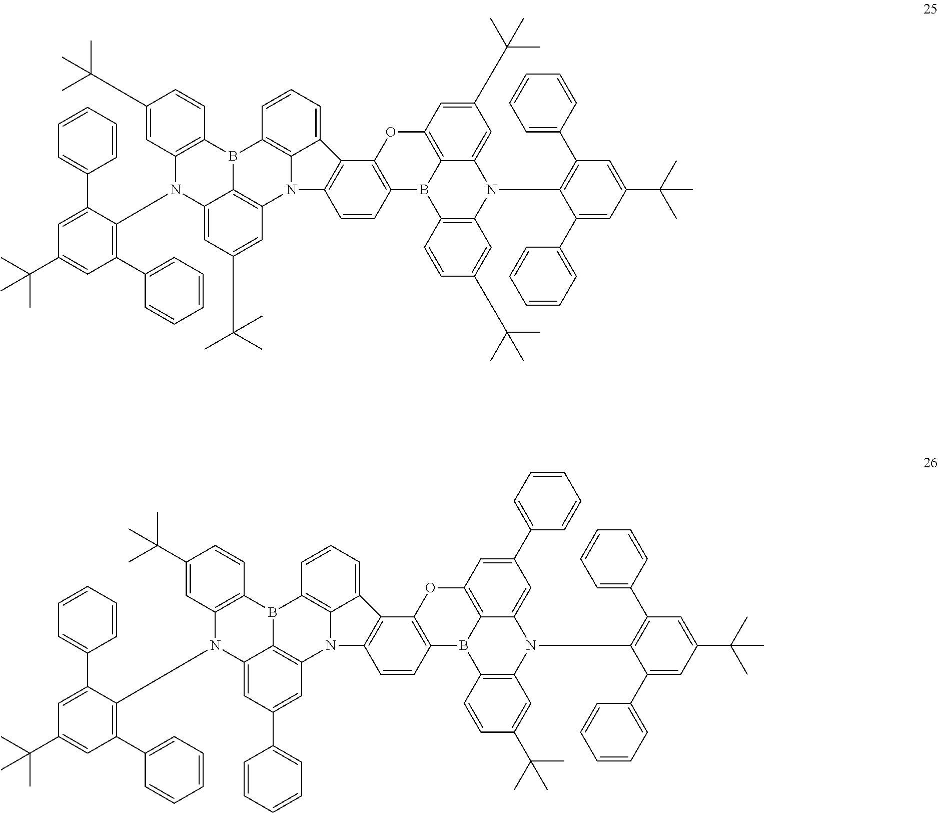 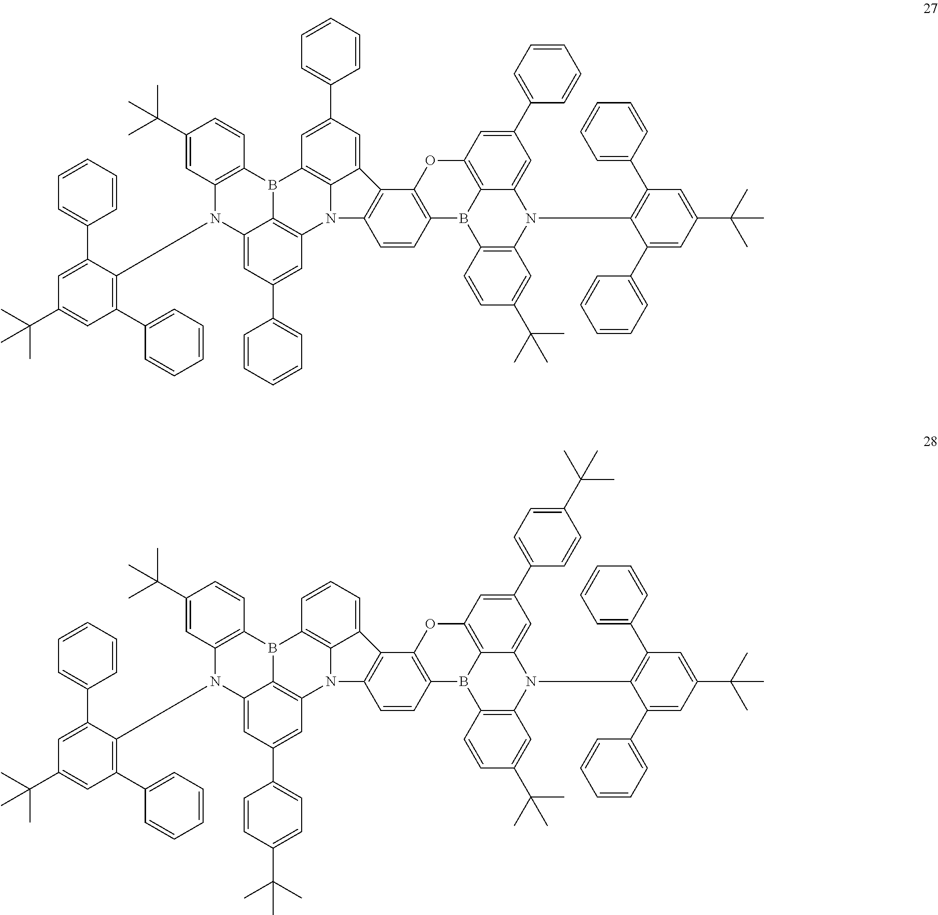 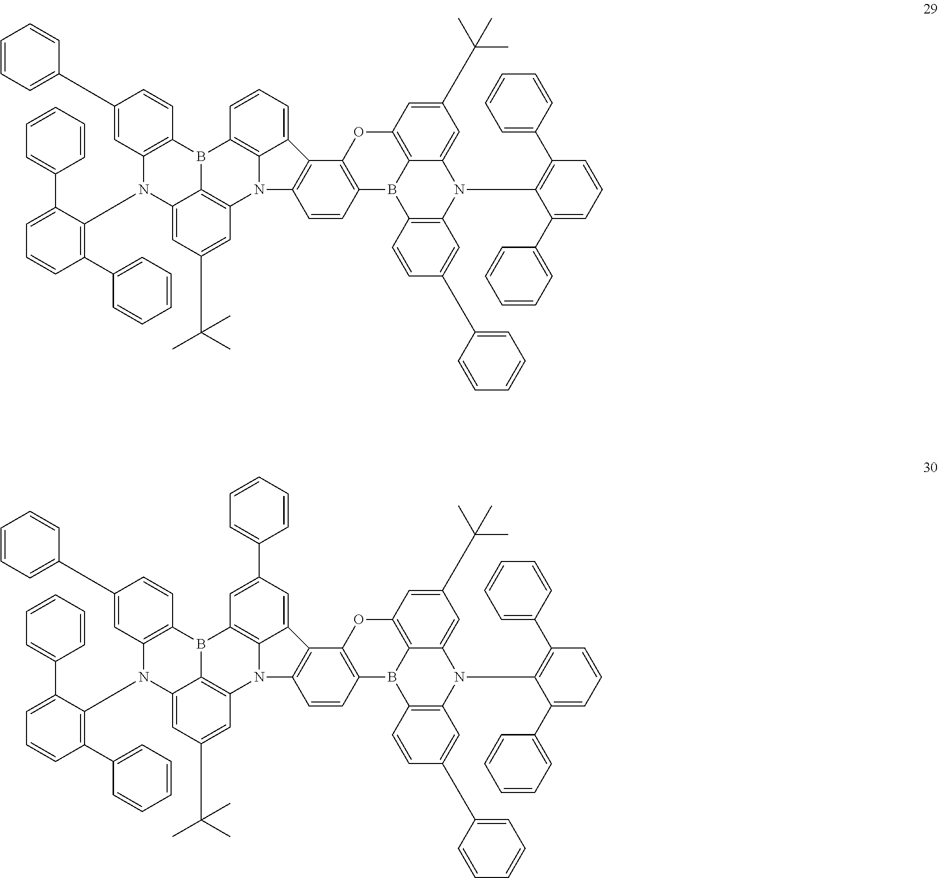 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1] 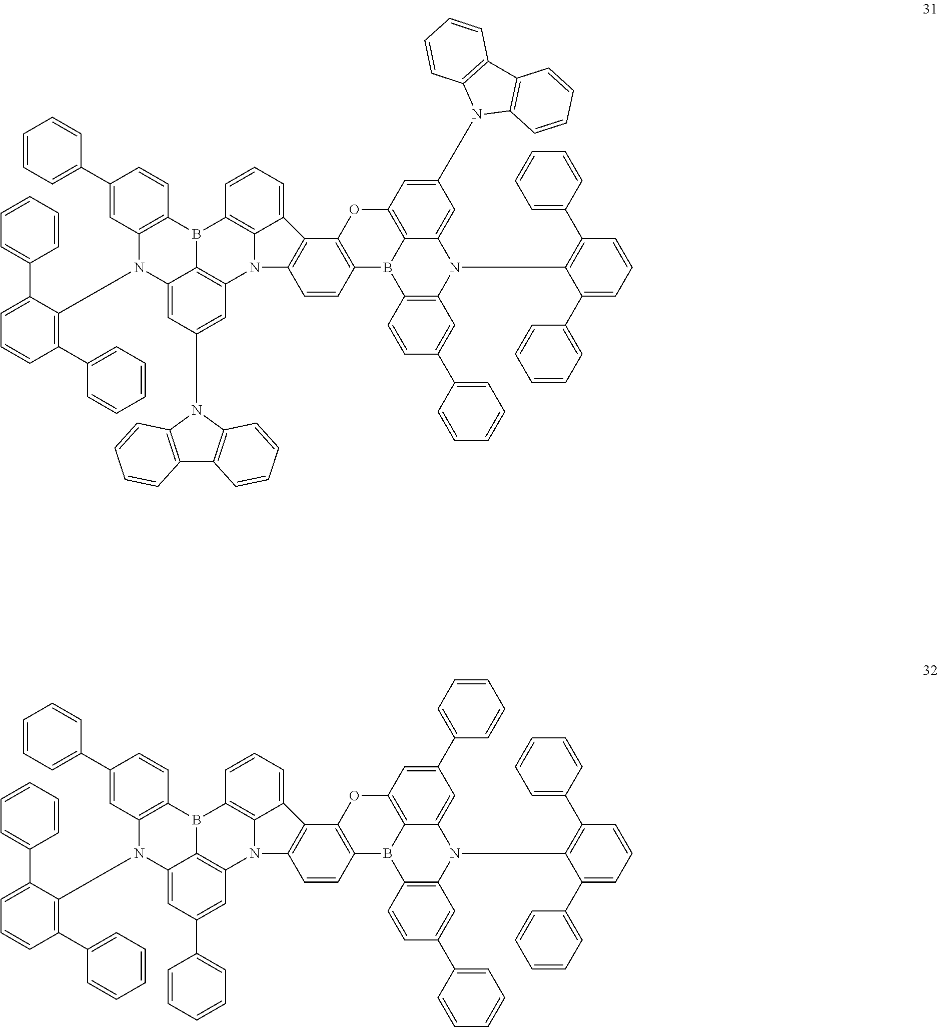 [SMILES: c1ccc(-c2ccc3c(c2)N(c2c(-c4ccccc4)cccc2-c2ccccc2)c2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccccc4)cc2N3c2c(-c3ccccc3)cccc2-c2ccccc2)cc1] 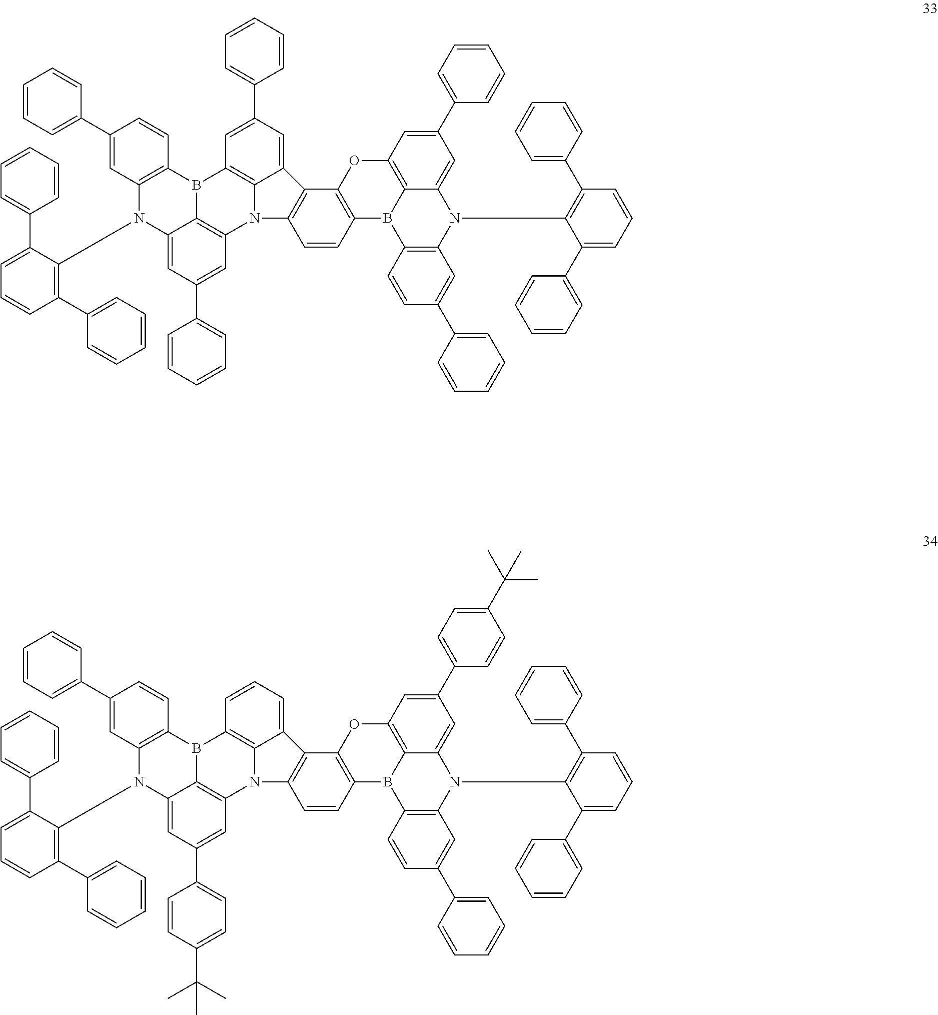 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cc(-c4ccccc4)cc4c2n3-c2cc(-c3ccccc3)cc3c2B4c2ccc(-c4ccccc4)cc2N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2N4c2c(-c3ccccc3)cccc2-c2ccccc2)cc1] 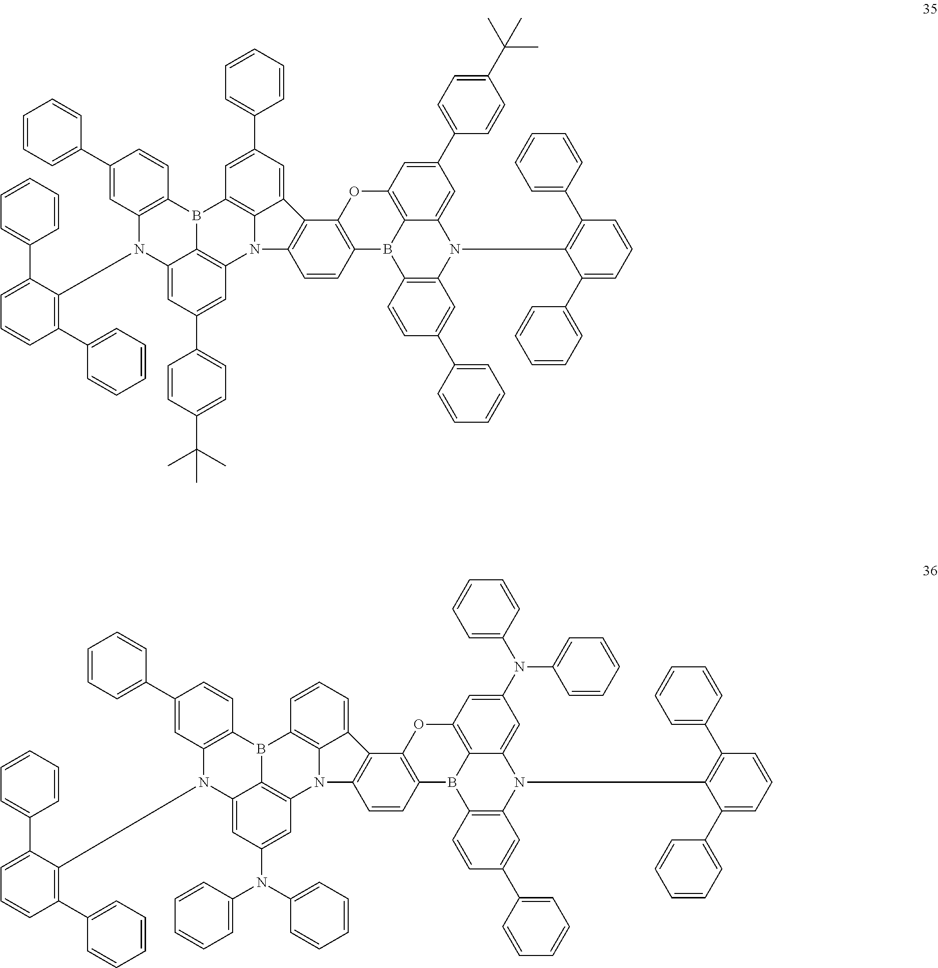 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2N4c2c(-c3ccccc3)cccc2-c2ccccc2)cc1 ; c1ccc(-c2ccc3c(c2)N(c2c(-c4ccccc4)cccc2-c2ccccc2)c2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 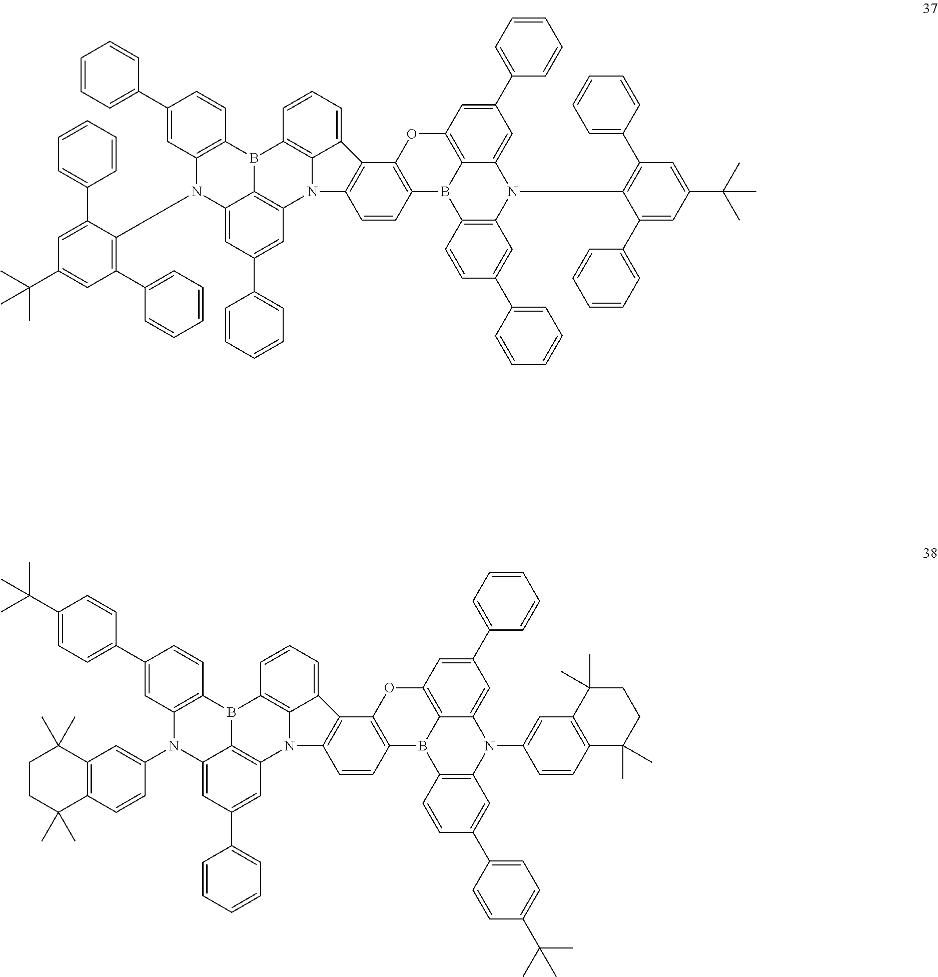 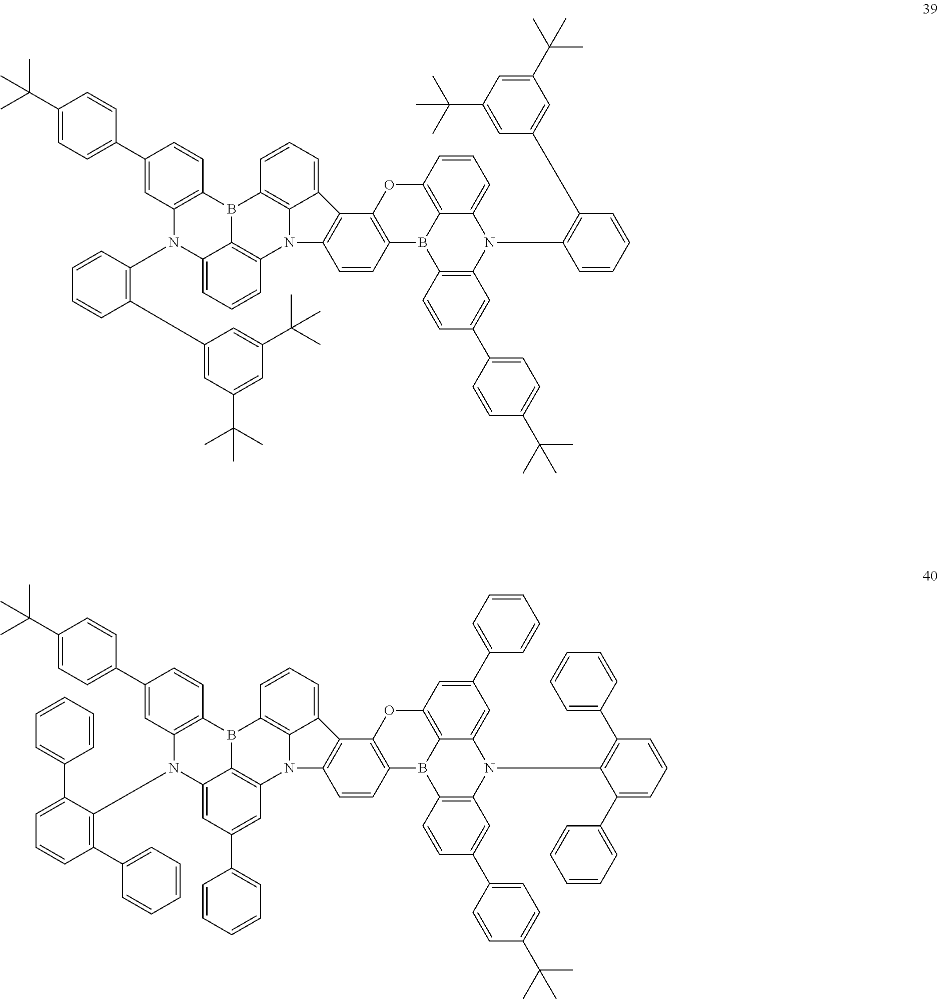 [SMILES: CC(C)(C)c1ccc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4ccc(C(C)(C)C)cc4)cc2N3c2ccccc2-c2cc(C(C)(C)C)cc(C(C)(C)C)c2)cc1 ; CC(C)(C)c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2N3c2c(-c3ccccc3)cccc2-c2ccccc2)cc1] 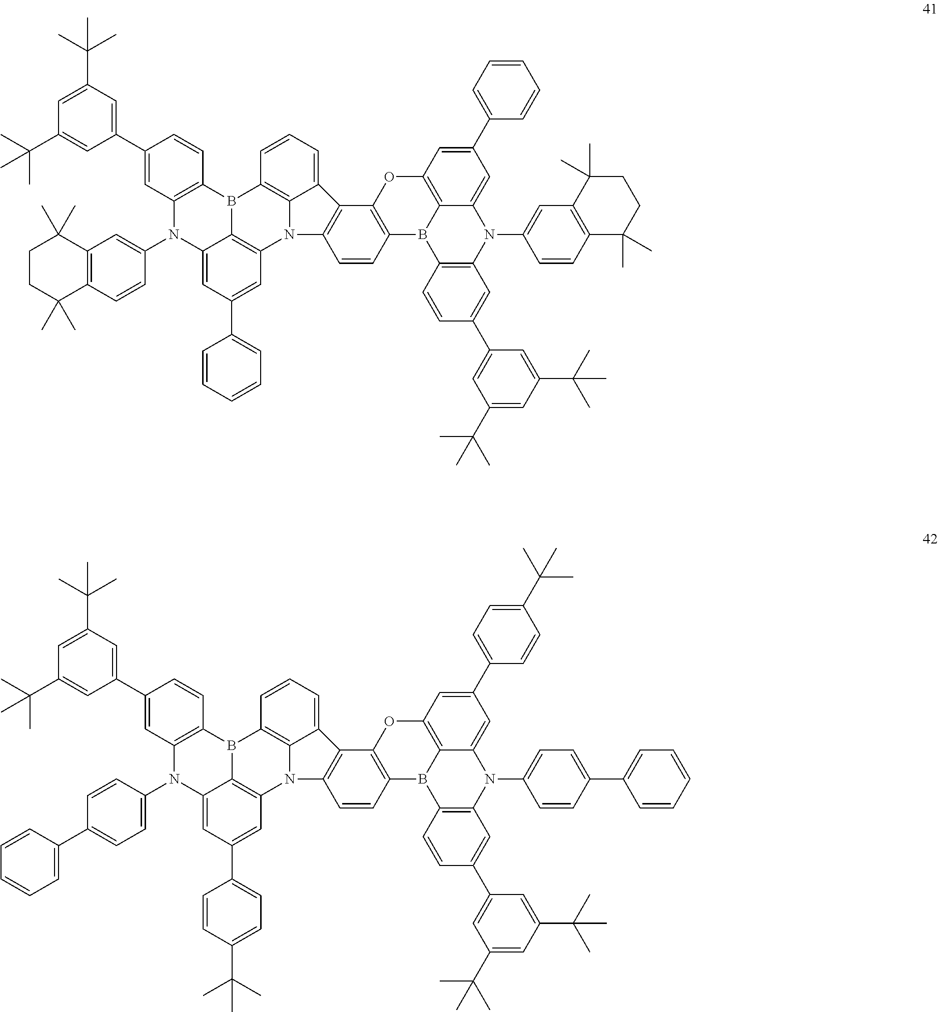 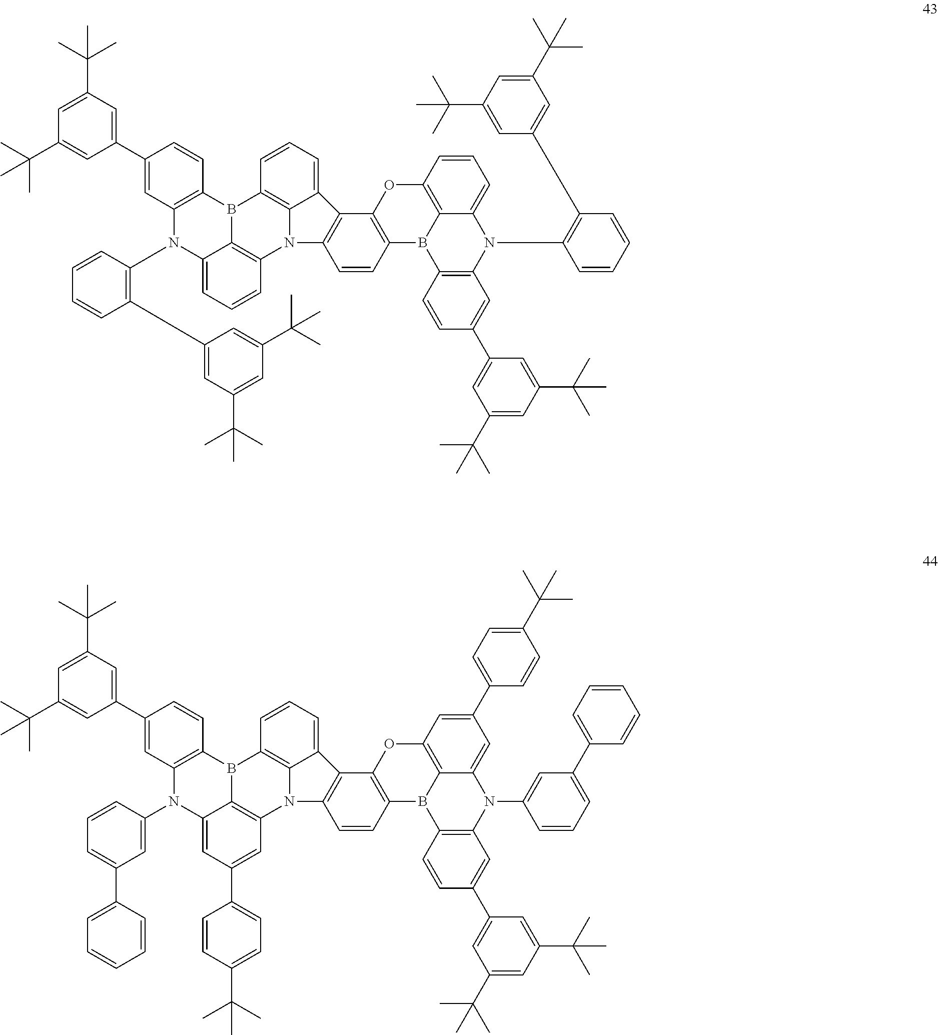 [SMILES: CC(C)(C)c1cc(-c2ccc3c(c2)N(c2ccccc2-c2cc(C(C)(C)C)cc(C(C)(C)C)c2)c2cccc4c2B3c2ccc3c(c2O4)c2cccc4c2n3-c2cccc3c2B4c2ccc(-c4cc(C(C)(C)C)cc(C(C)(C)C)c4)cc2N3c2ccccc2-c2cc(C(C)(C)C)cc(C(C)(C)C)c2)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2N4c2cccc(-c3ccccc3)c2)cc1] 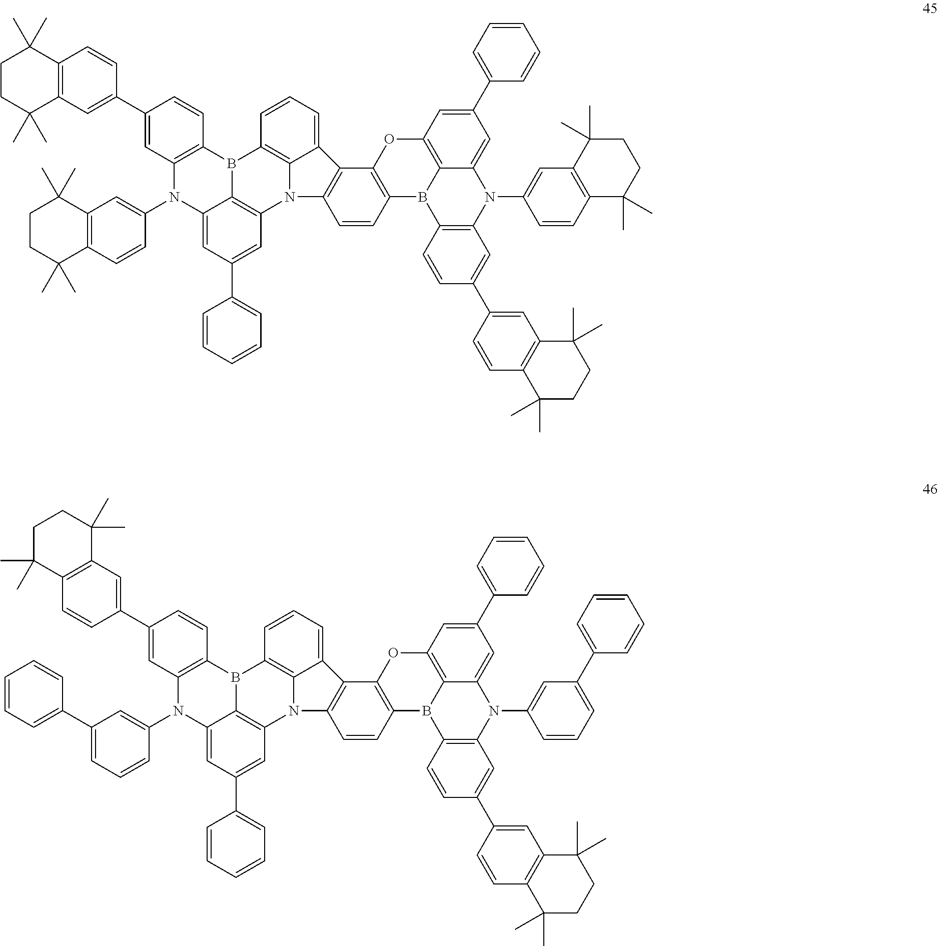 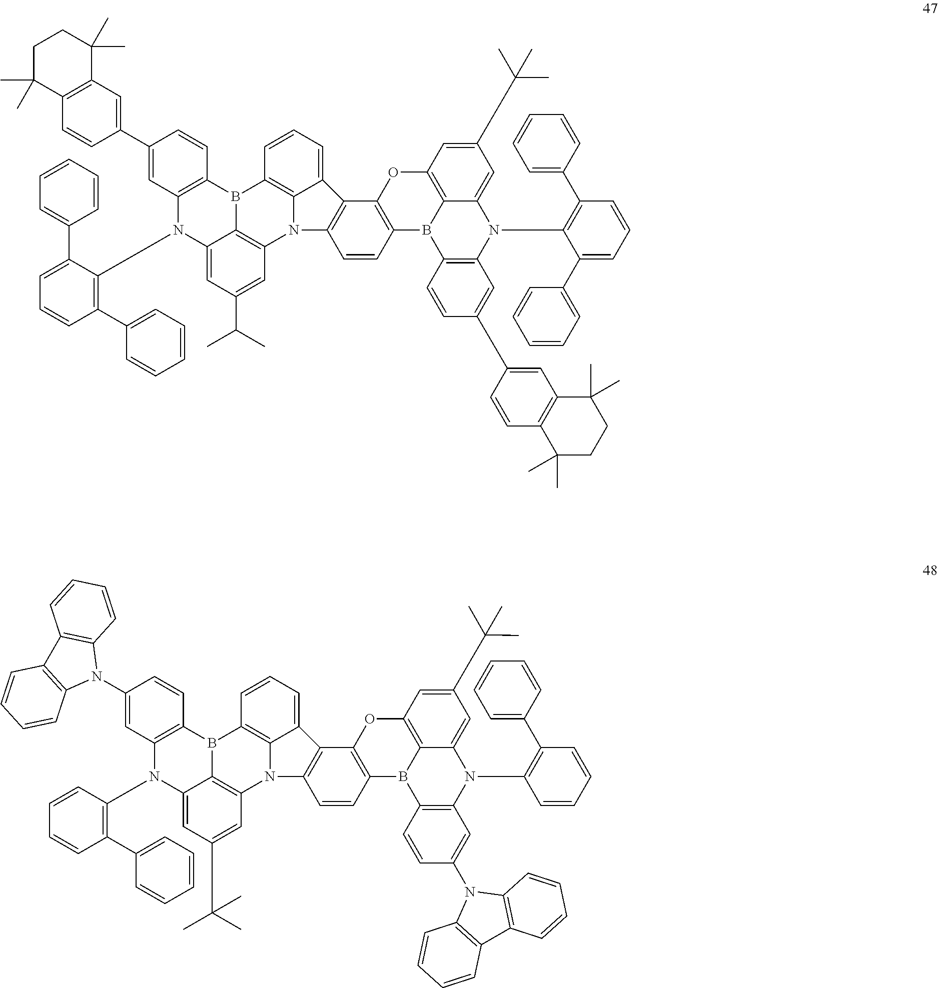 [SMILES: CC(C)c1cc2c3c(c1)-n1c4ccc5c(c4c4cccc(c41)B3c1ccc(-c3ccc4c(c3)C(C)(C)CCC4(C)C)cc1N2c1c(-c2ccccc2)cccc1-c1ccccc1)Oc1cc(C(C)(C)C)cc2c1B5c1ccc(-c3ccc4c(c3)C(C)(C)CCC4(C)C)cc1N2c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1ccccc1-c1ccccc1] 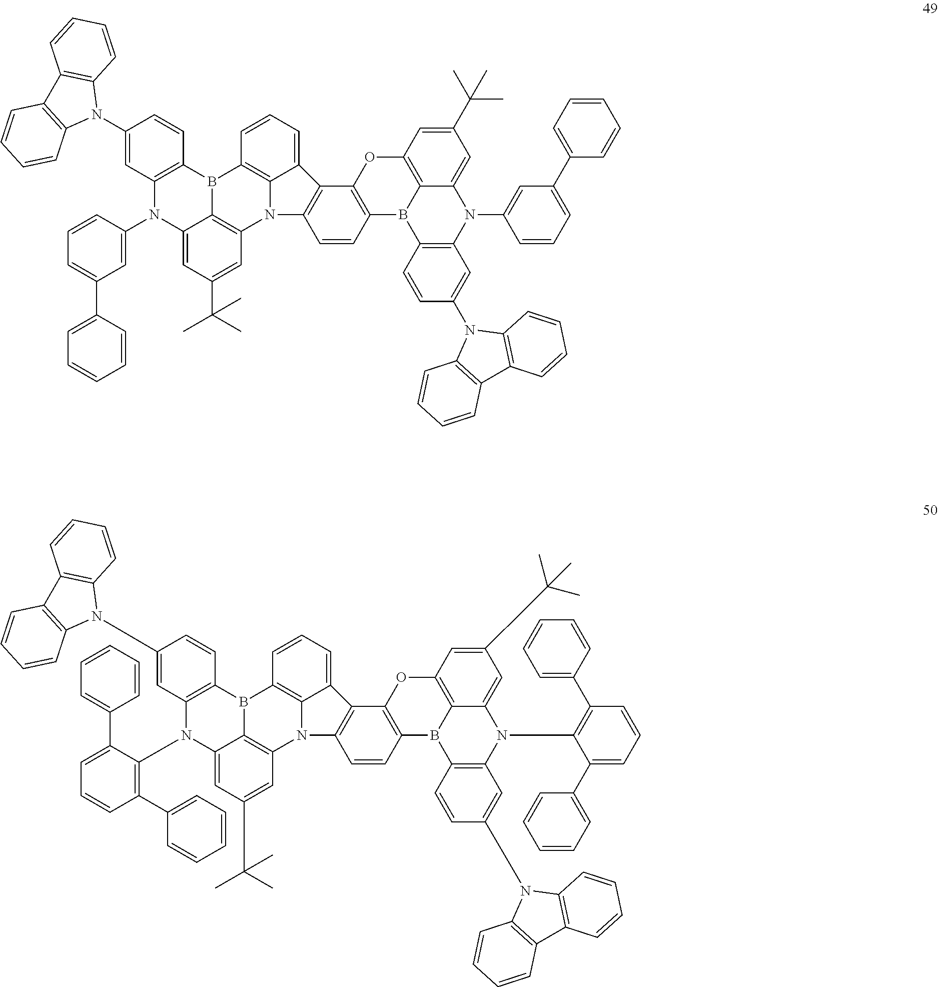 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cccc1-c1ccccc1] 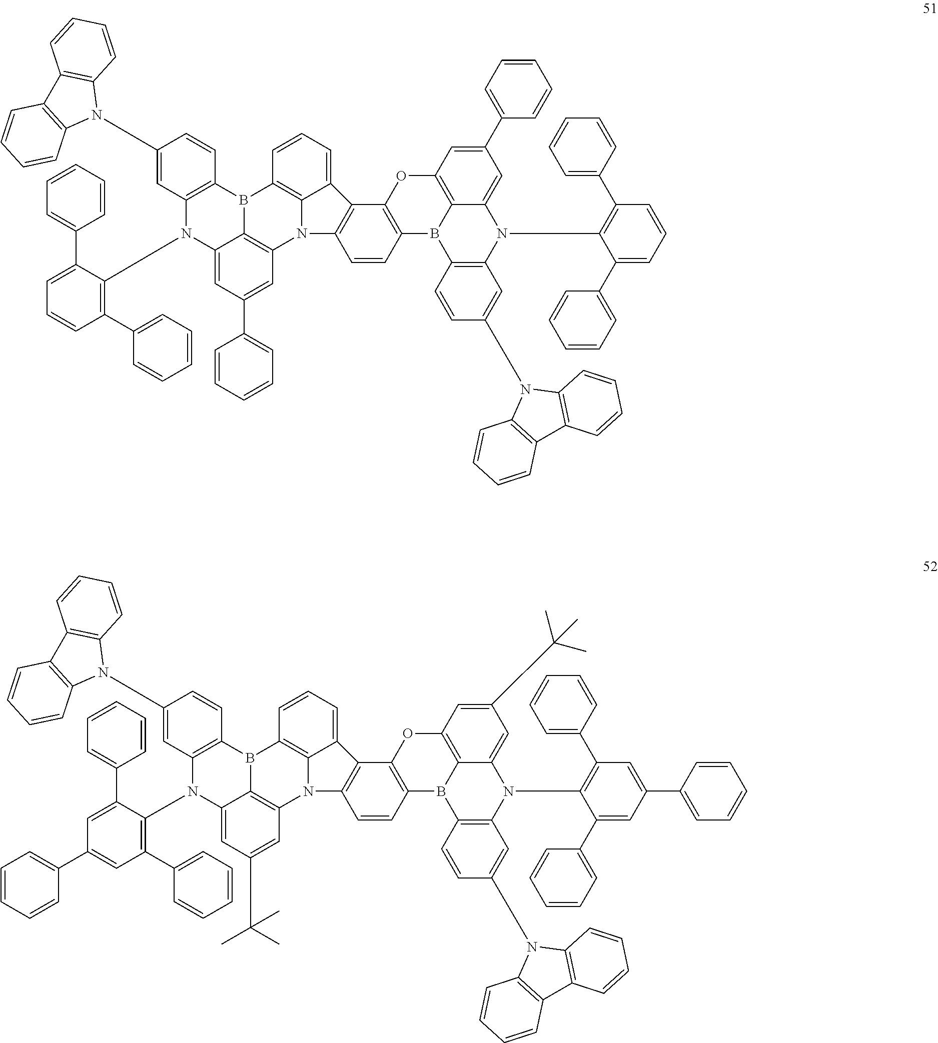 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2N4c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1N3c1c(-c2ccccc2)cc(-c2ccccc2)cc1-c1ccccc1] 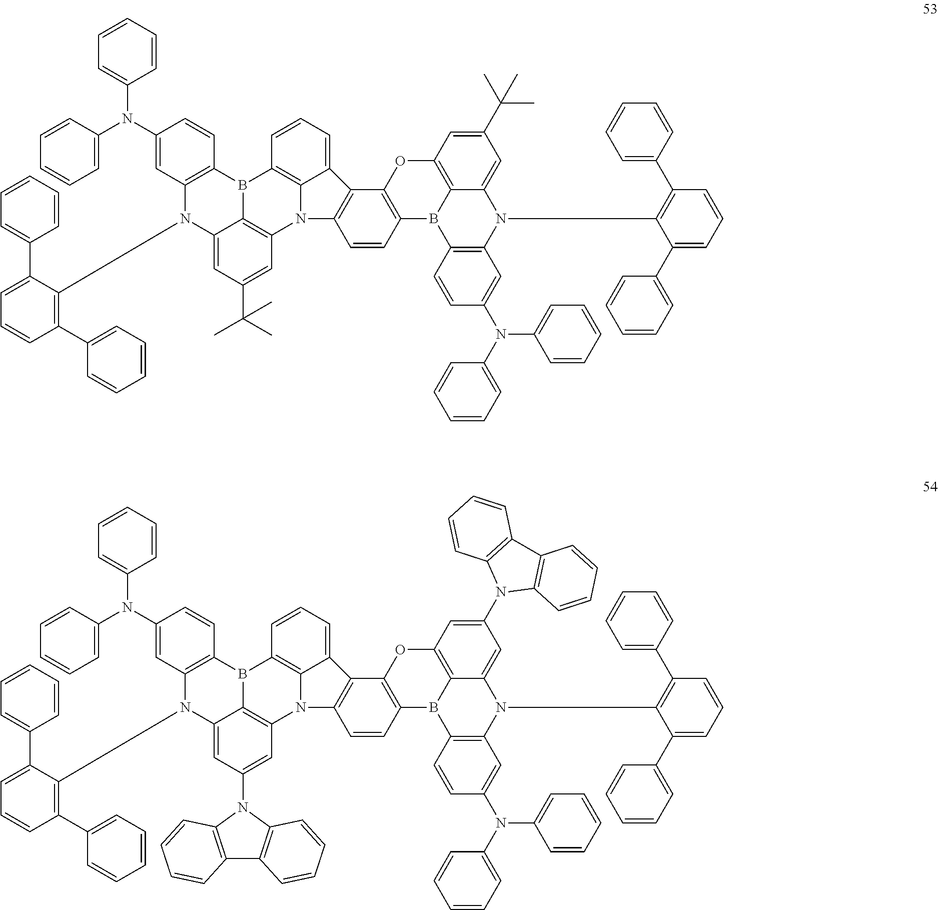 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1N3c1c(-c2ccccc2)cccc1-c1ccccc1 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2N4c2c(-c3ccccc3)cccc2-c2ccccc2)cc1] 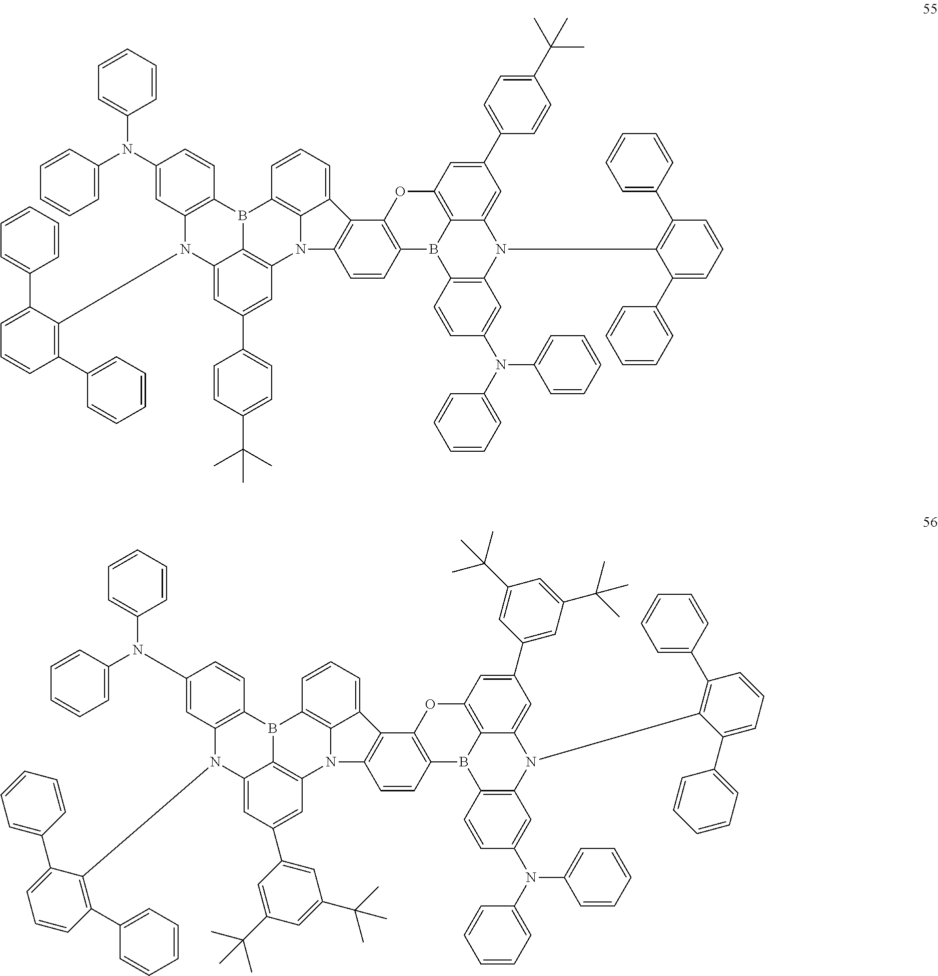 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2N4c2c(-c3ccccc3)cccc2-c2ccccc2)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2N4c2c(-c3ccccc3)cccc2-c2ccccc2)cc(C(C)(C)C)c1] 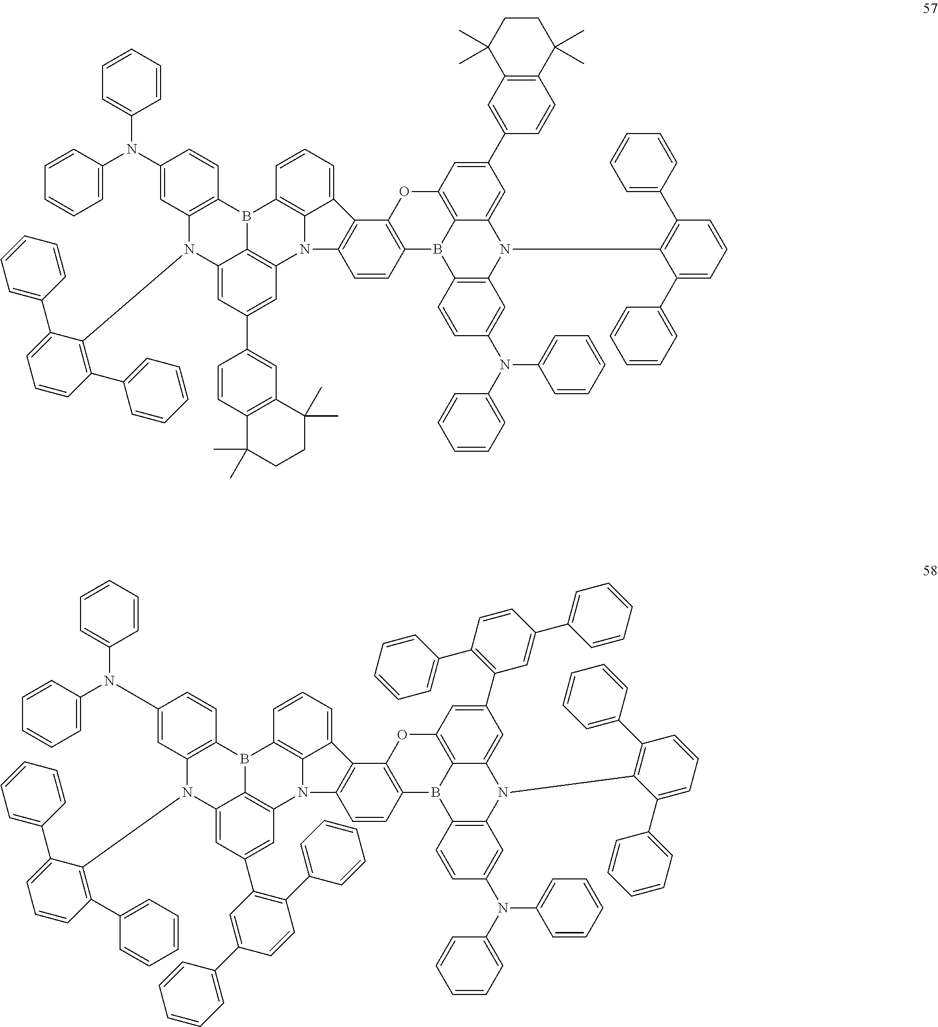 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3N5c3c(-c4ccccc4)cccc3-c3ccccc3)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3N5c3c(-c4ccccc4)cccc3-c3ccccc3)c2)cc1] 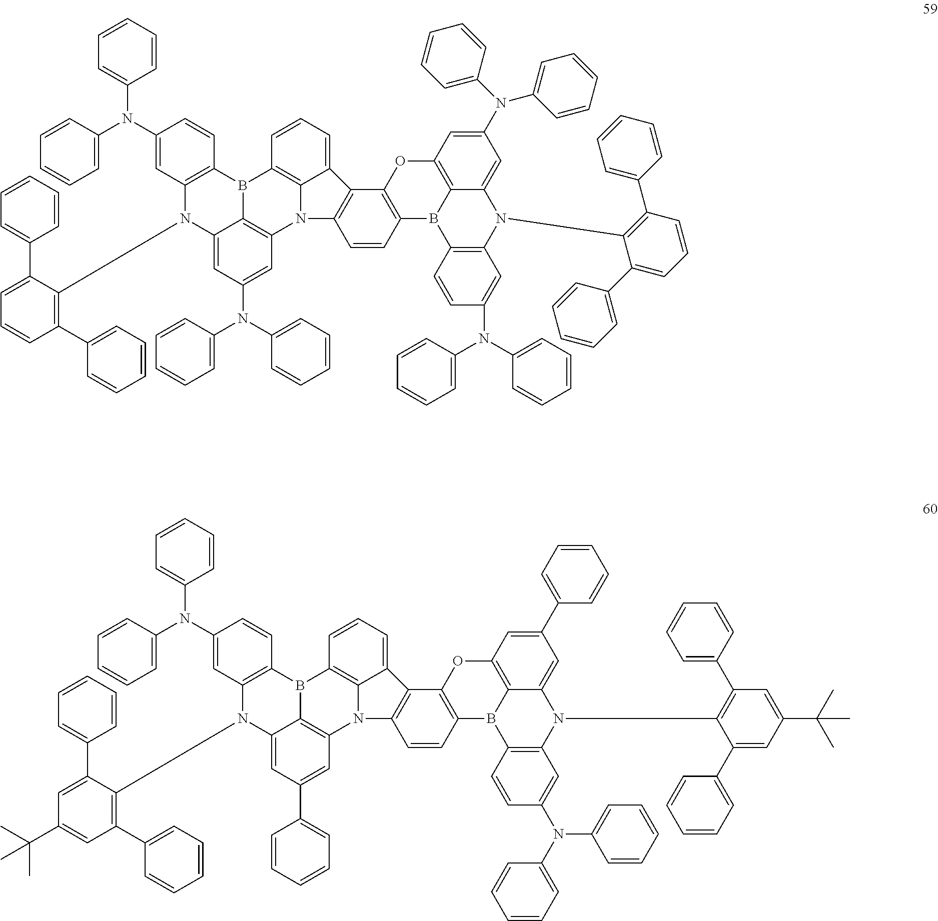 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2N4c2c(-c3ccccc3)cccc2-c2ccccc2)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2N4c2c(-c3ccccc3)cc(C(C)(C)C)cc2-c2ccccc2)c(-c2ccccc2)c1] 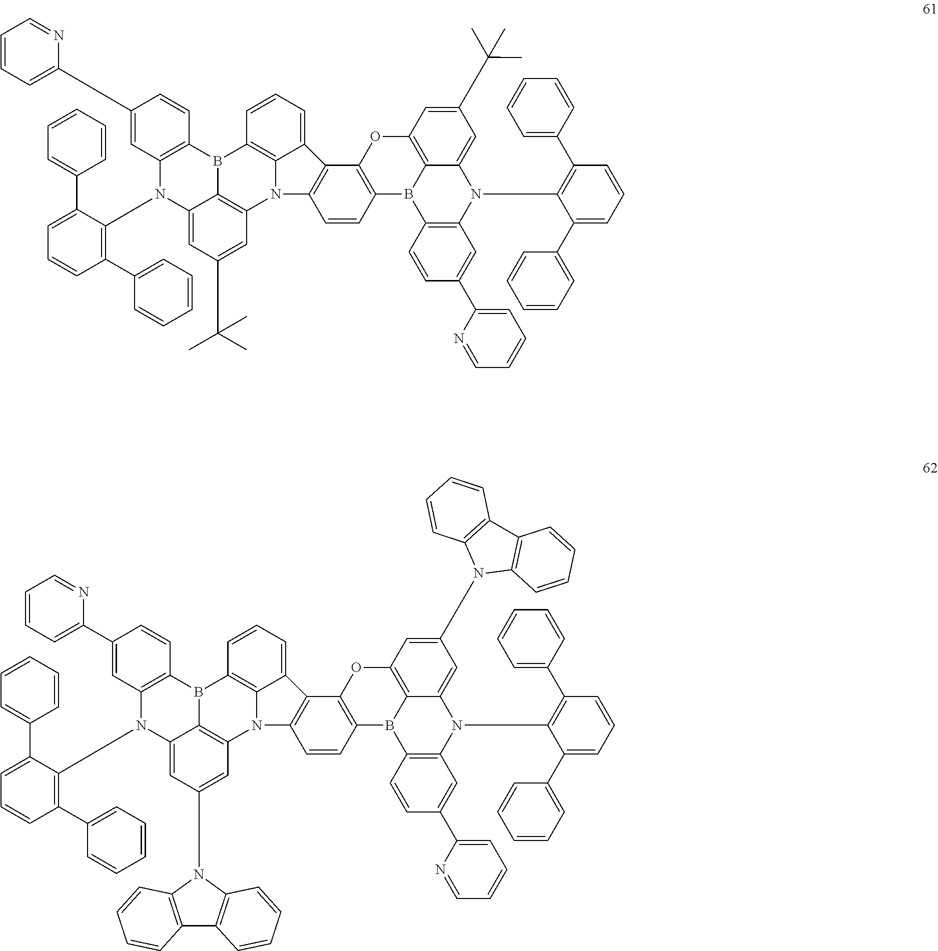 [SMILES: CC(C)(C)c1cc2c3c(c1)N(c1c(-c4ccccc4)cccc1-c1ccccc1)c1cc(-c4ccccn4)ccc1B3c1ccc3c(c1O2)c1cccc2c1n3-c1cc(C(C)(C)C)cc3c1B2c1ccc(-c2ccccn2)cc1N3c1c(-c2ccccc2)cccc1-c1ccccc1 ; c1ccc(-c2cccc(-c3ccccc3)c2N2c3cc(-c4ccccn4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(-c3ccccn3)cc2N4c2c(-c3ccccc3)cccc2-c2ccccc2)cc1] 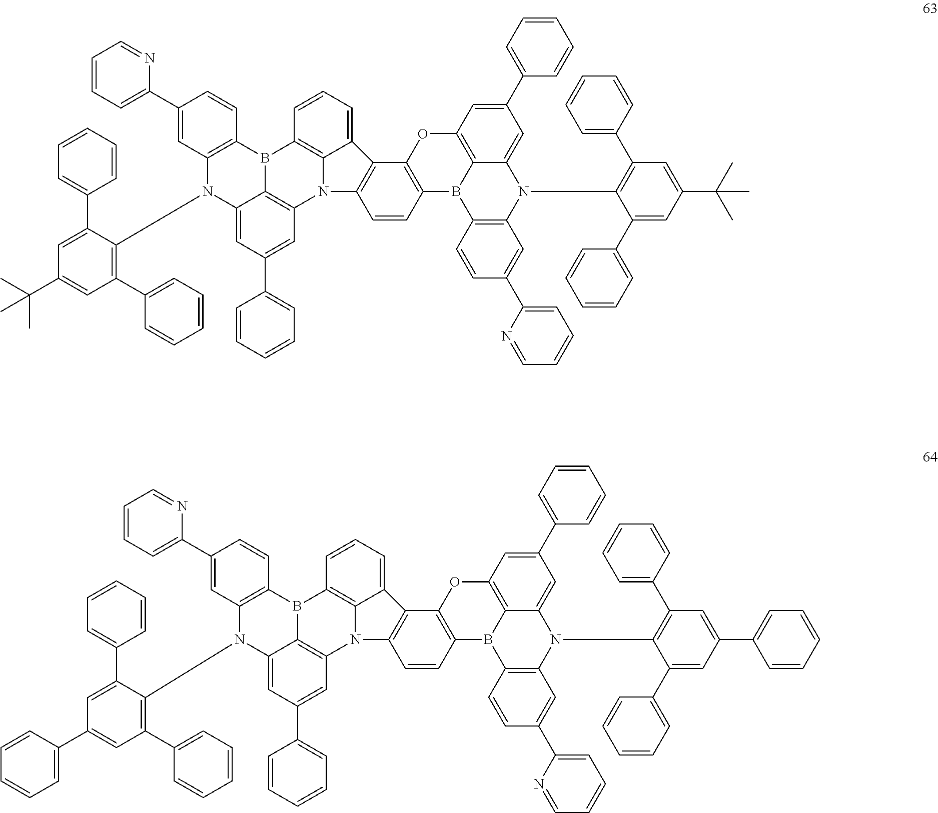 [SMILES: CC(C)(C)c1cc(-c2ccccc2)c(N2c3cc(-c4ccccn4)ccc3B3c4ccc5c(c4Oc4cc(-c6ccccc6)cc2c43)c2cccc3c2n5-c2cc(-c4ccccc4)cc4c2B3c2ccc(-c3ccccn3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccccn5)ccc4B4c5ccc6c(c5Oc5cc(-c7ccccc7)cc3c54)c3cccc4c3n6-c3cc(-c5ccccc5)cc5c3B4c3ccc(-c4ccccn4)cc3N5c3c(-c4ccccc4)cc(-c4ccccc4)cc3-c3ccccc3)c(-c3ccccc3)c2)cc1] 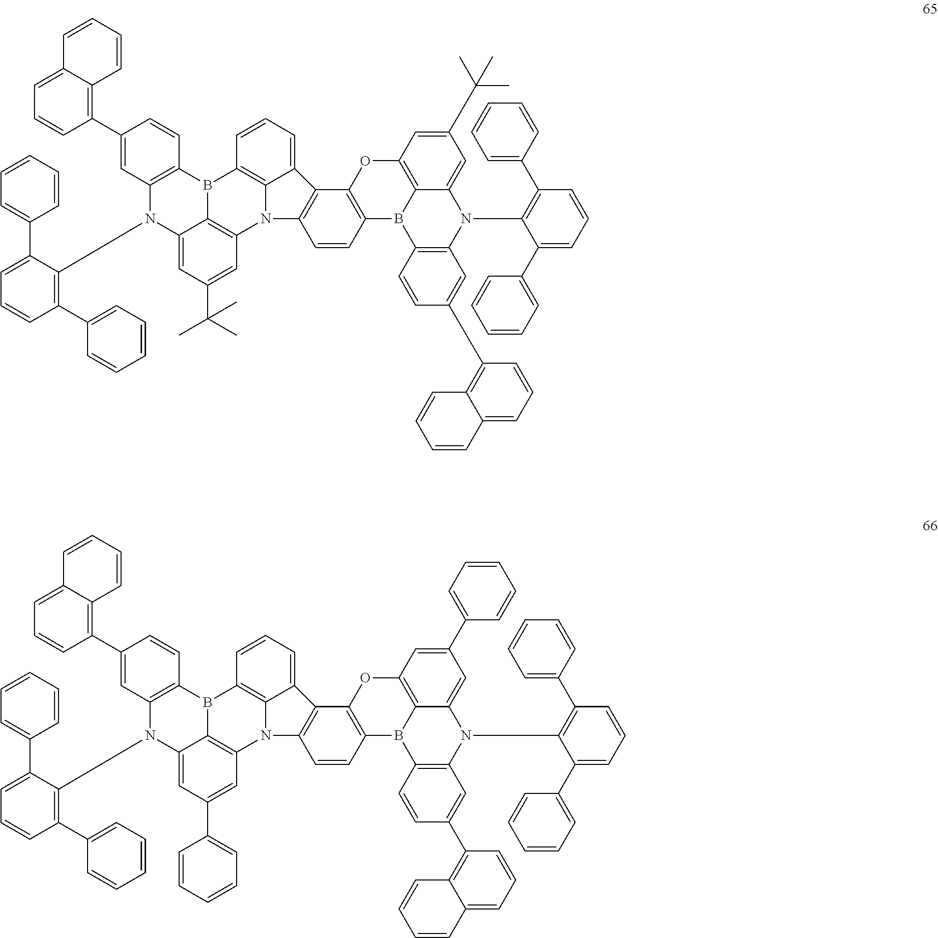 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1N3c1c(-c2ccccc2)cccc1-c1ccccc1 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2N4c2c(-c3ccccc3)cccc2-c2ccccc2)cc1] 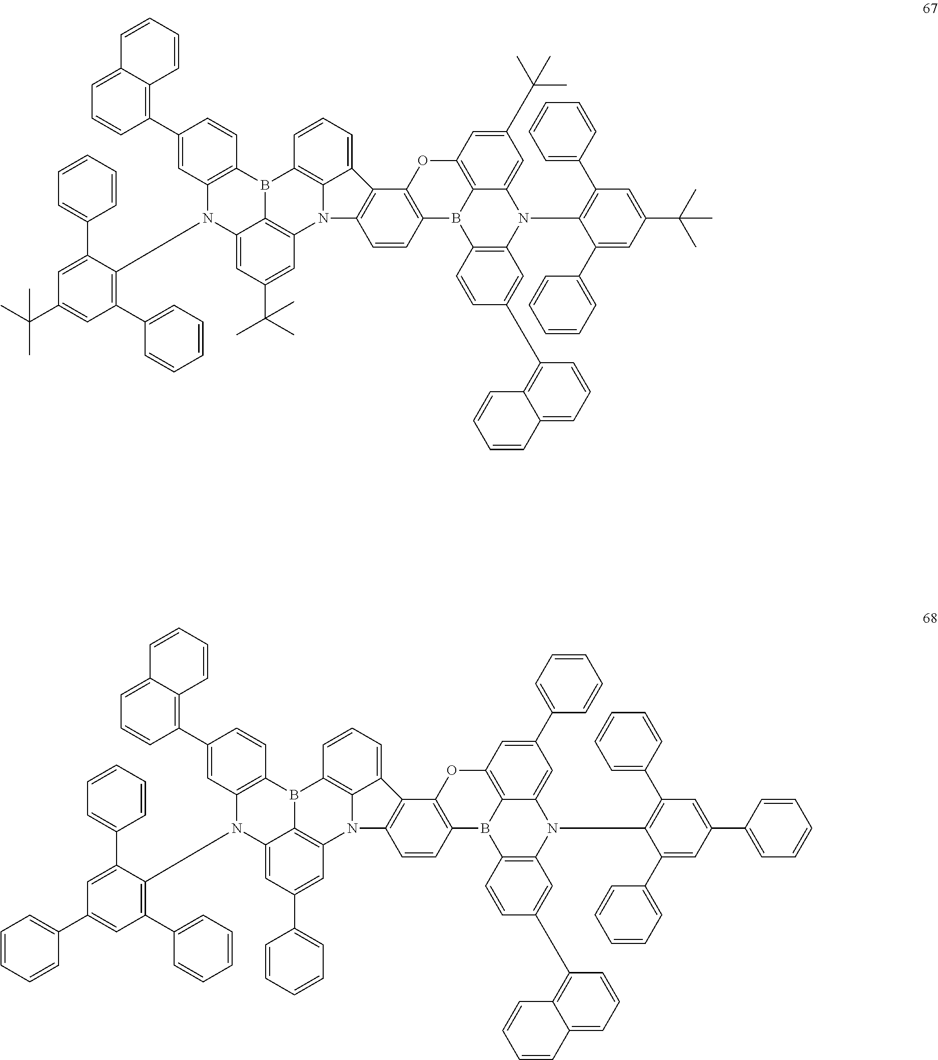 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3N5c3c(-c4ccccc4)cc(-c4ccccc4)cc3-c3ccccc3)c(-c3ccccc3)c2)cc1] 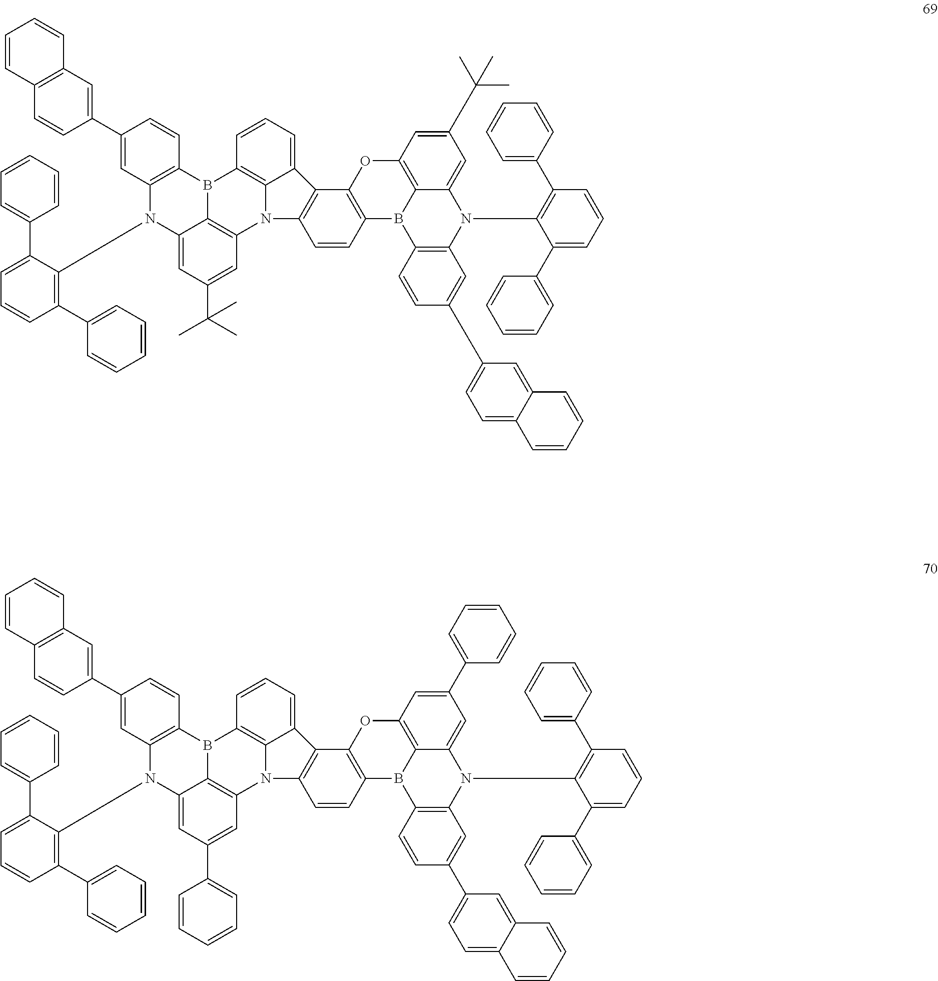 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1N3c1c(-c2ccccc2)cccc1-c1ccccc1 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2N4c2c(-c3ccccc3)cccc2-c2ccccc2)cc1] 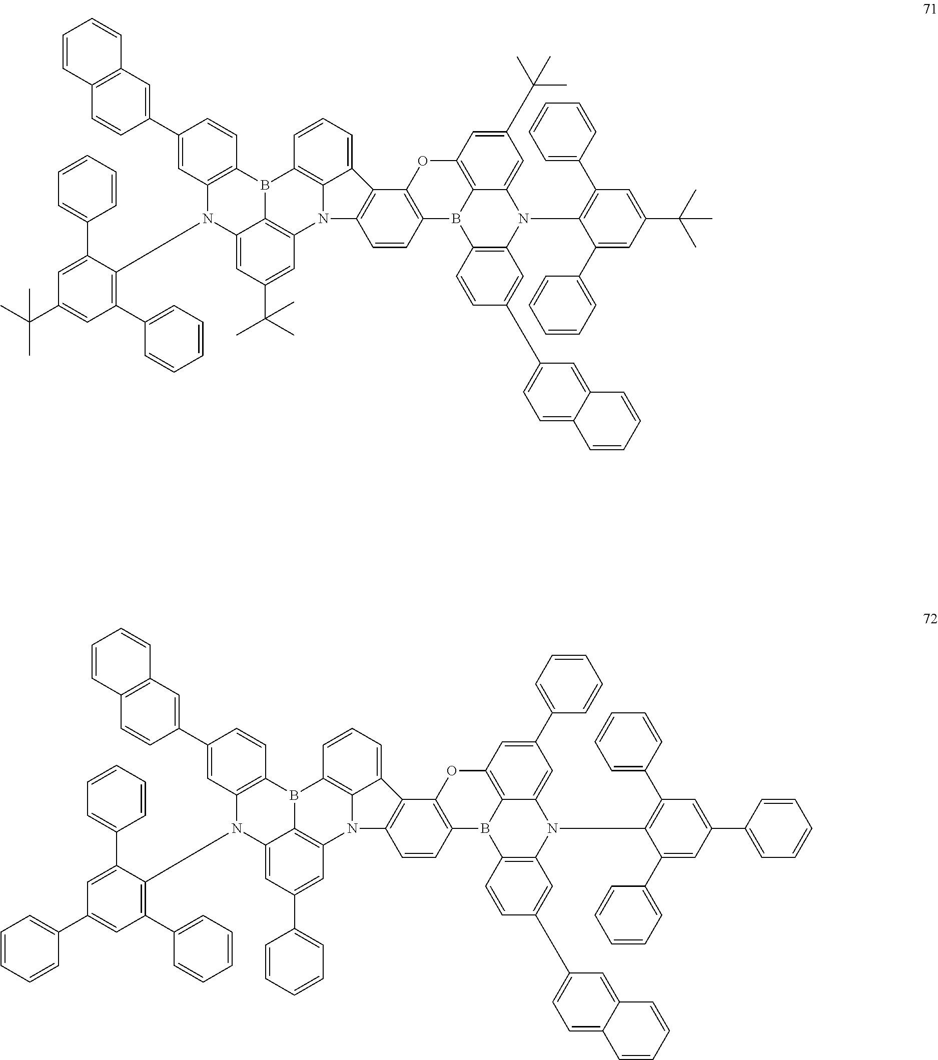 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3N5c3c(-c4ccccc4)cc(-c4ccccc4)cc3-c3ccccc3)c(-c3ccccc3)c2)cc1] 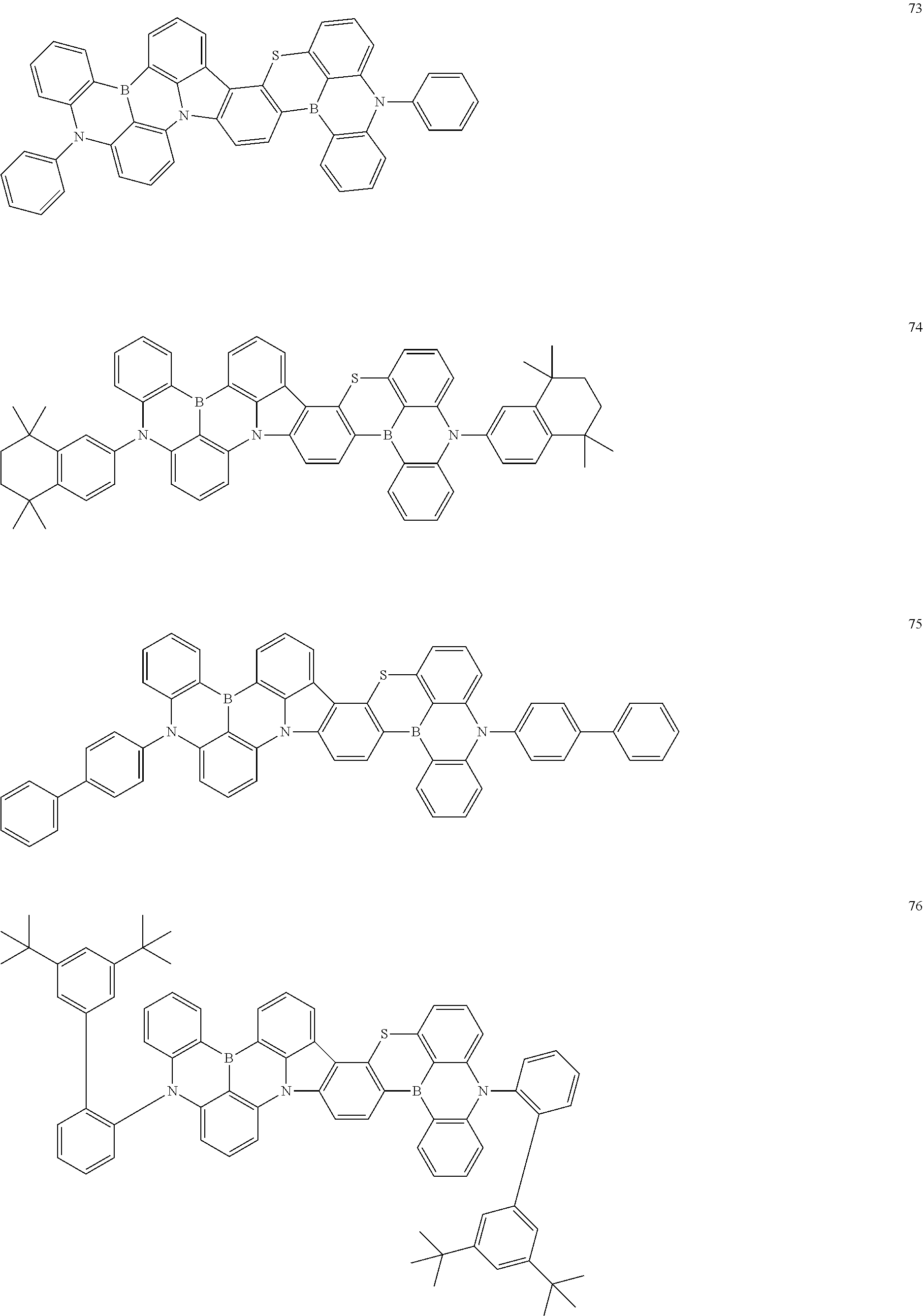 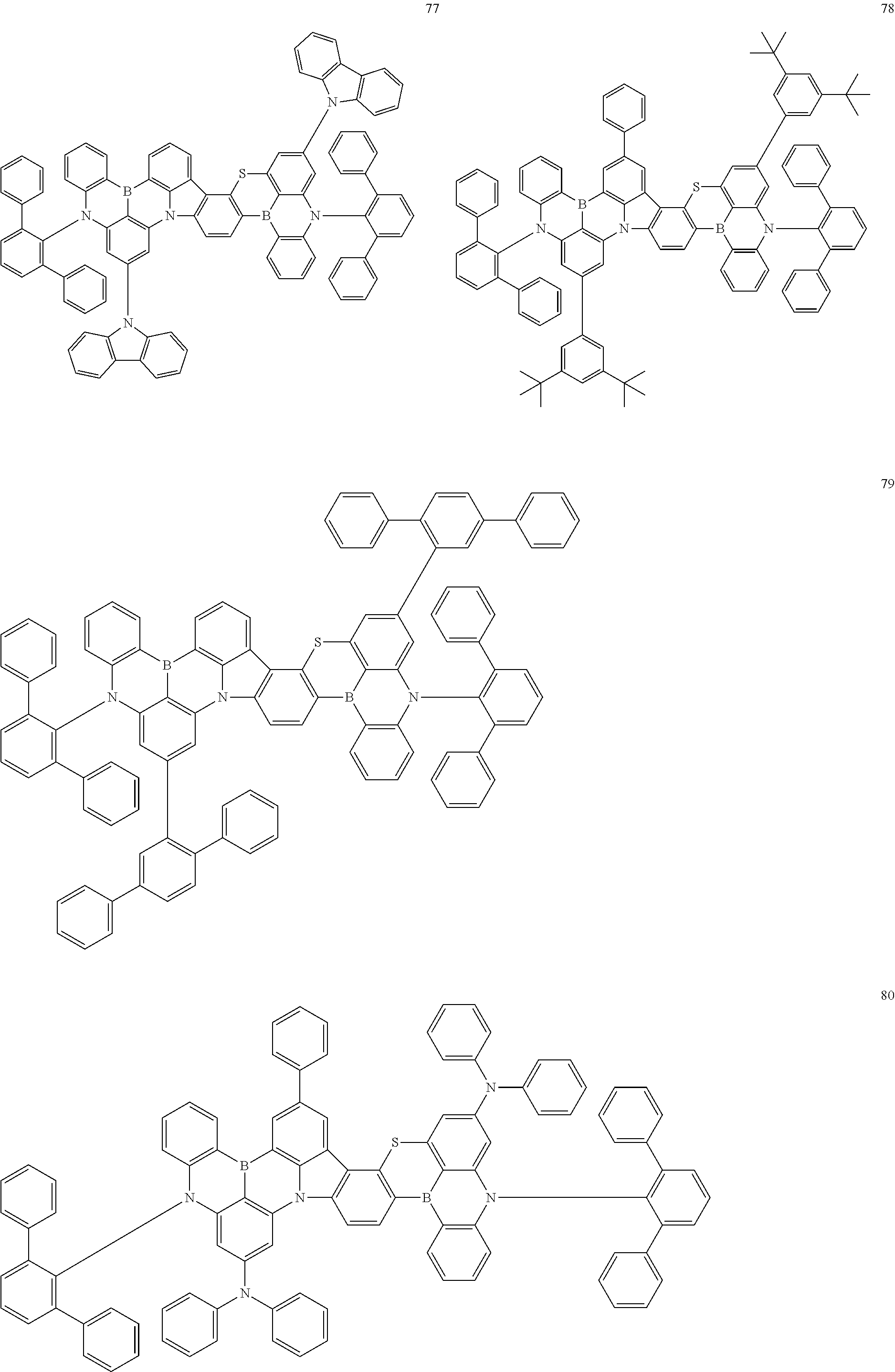 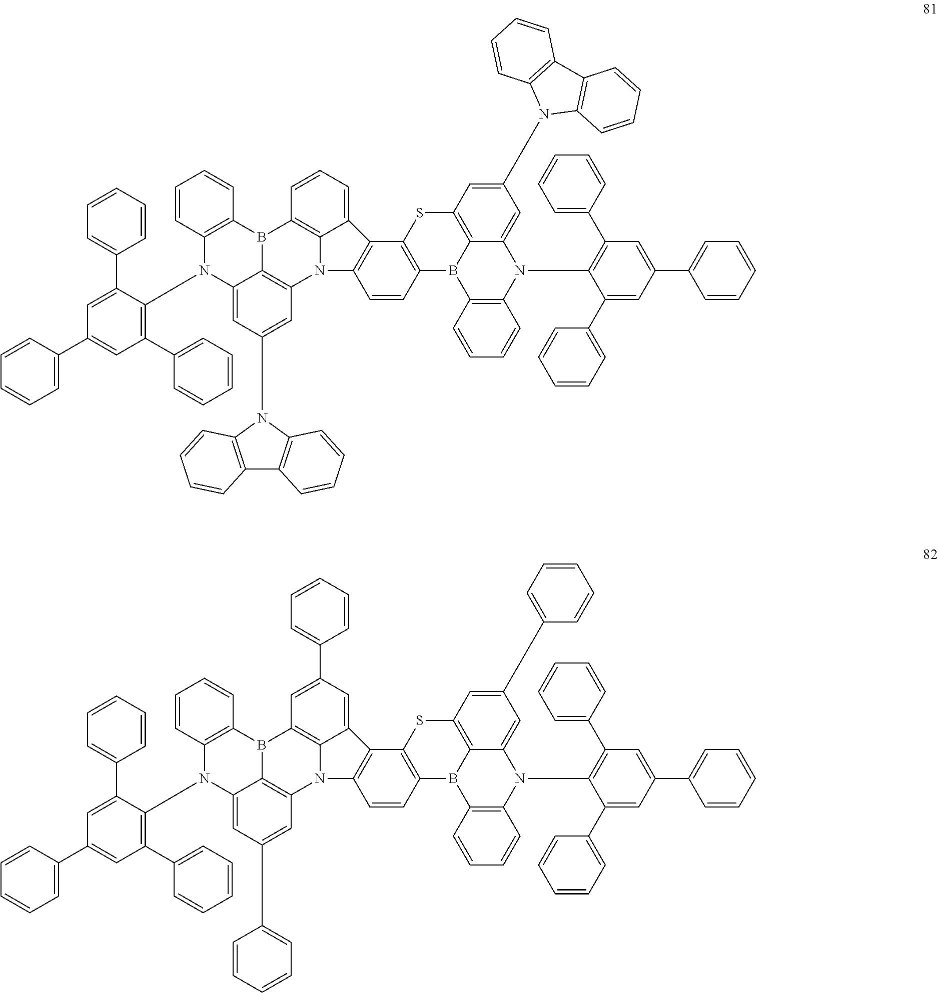 [SMILES: c1ccc(-c2cc(-c3ccccc3)c(N3c4ccccc4B4c5ccc6c(c5Sc5cc(-n7c8ccccc8c8ccccc87)cc3c54)c3cccc4c3n6-c3cc(-n5c6ccccc6c6ccccc65)cc5c3B4c3ccccc3N5c3c(-c4ccccc4)cc(-c4ccccc4)cc3-c3ccccc3)c(-c3ccccc3)c2)cc1 ; c1ccc(-c2cc(-c3ccccc3)c(N3c4ccccc4B4c5ccc6c(c5Sc5cc(-c7ccccc7)cc3c54)c3cc(-c4ccccc4)cc4c3n6-c3cc(-c5ccccc5)cc5c3B4c3ccccc3N5c3c(-c4ccccc4)cc(-c4ccccc4)cc3-c3ccccc3)c(-c3ccccc3)c2)cc1] 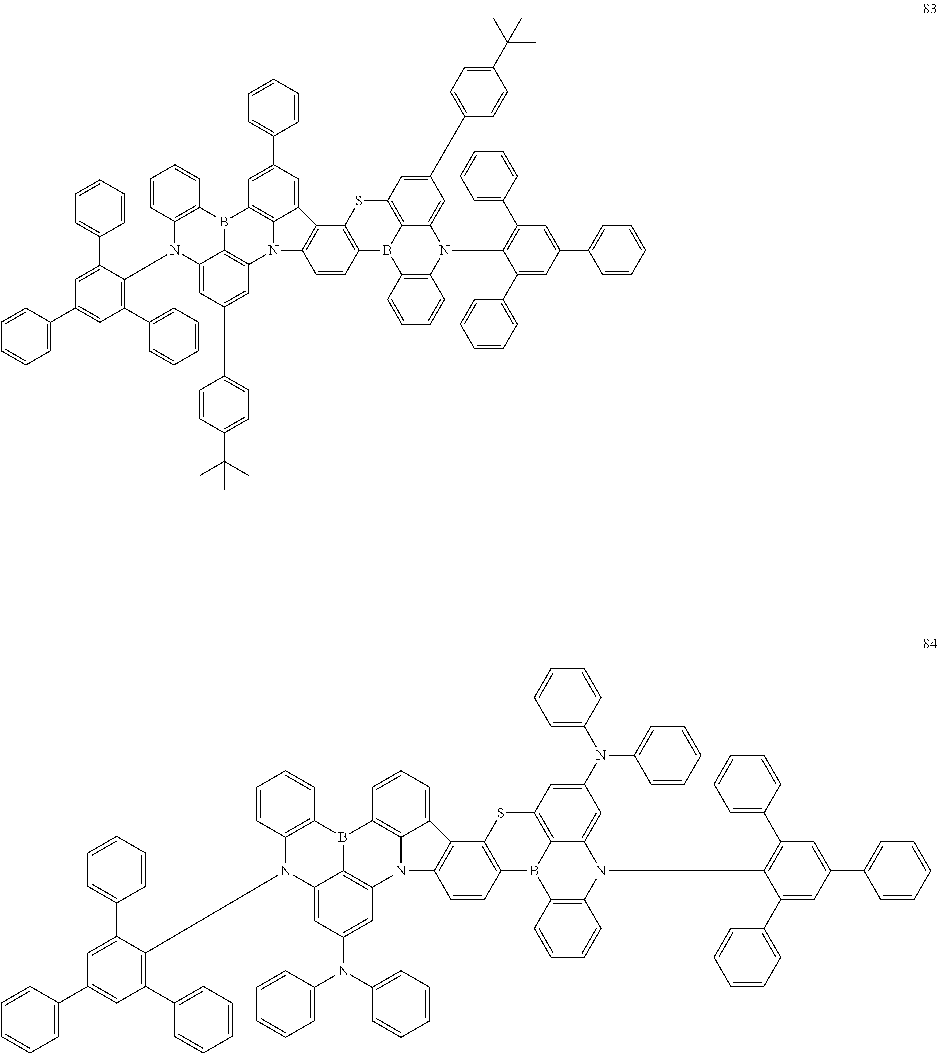 [SMILES: CC(C)(C)c1ccc(-c2cc3c4c(c2)N(c2c(-c5ccccc5)cc(-c5ccccc5)cc2-c2ccccc2)c2ccccc2B4c2ccc4c(c2S3)c2cc(-c3ccccc3)cc3c2n4-c2cc(-c4ccc(C(C)(C)C)cc4)cc4c2B3c2ccccc2N4c2c(-c3ccccc3)cc(-c3ccccc3)cc2-c2ccccc2)cc1 ; c1ccc(-c2cc(-c3ccccc3)c(N3c4ccccc4B4c5ccc6c(c5Sc5cc(N(c7ccccc7)c7ccccc7)cc3c54)c3cccc4c3n6-c3cc(N(c5ccccc5)c5ccccc5)cc5c3B4c3ccccc3N5c3c(-c4ccccc4)cc(-c4ccccc4)cc3-c3ccccc3)c(-c3ccccc3)c2)cc1] 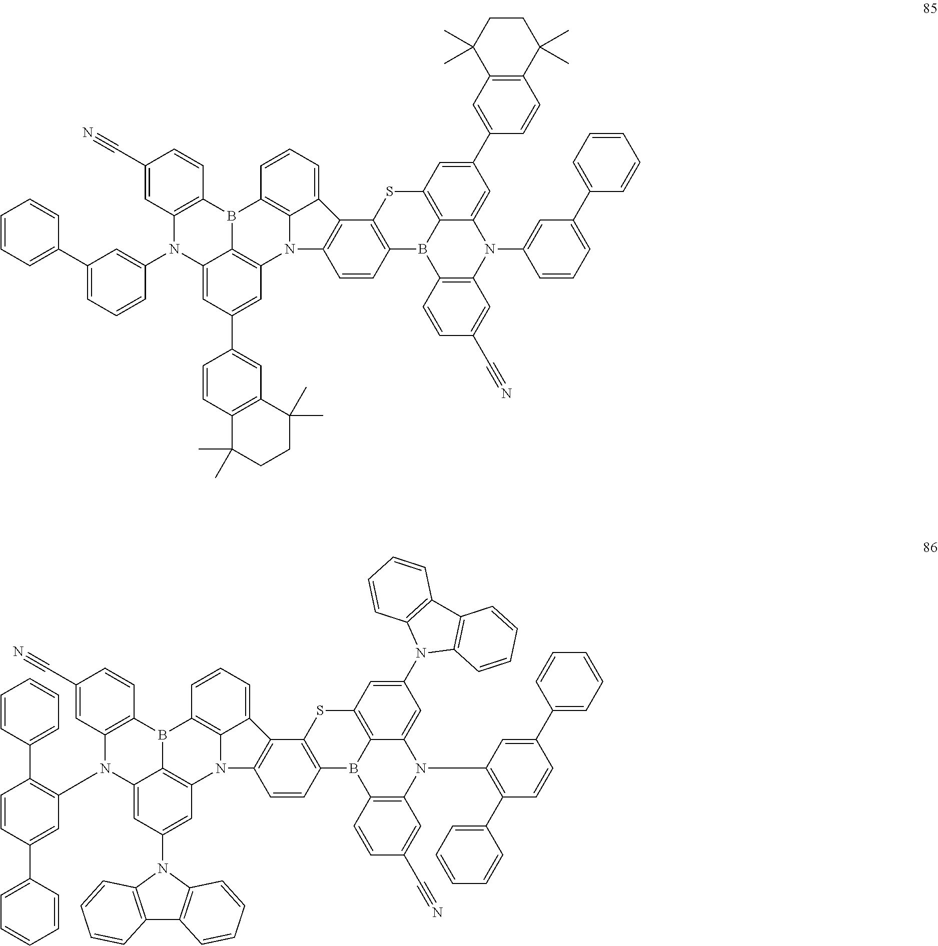 [SMILES: CC1(C)CCC(C)(C)c2cc(-c3cc4c5c(c3)N(c3cccc(-c6ccccc6)c3)c3cc(C#N)ccc3B5c3ccc5c(c3S4)c3cccc4c3n5-c3cc(-c5ccc6c(c5)C(C)(C)CCC6(C)C)cc5c3B4c3ccc(C#N)cc3N5c3cccc(-c4ccccc4)c3)ccc21 ; N#Cc1ccc2c(c1)N(c1cc(-c3ccccc3)ccc1-c1ccccc1)c1cc(-n3c4ccccc4c4ccccc43)cc3c1B2c1ccc2c(c1S3)c1cccc3c1n2-c1cc(-n2c4ccccc4c4ccccc42)cc2c1B3c1ccc(C#N)cc1N2c1cc(-c2ccccc2)ccc1-c1ccccc1] 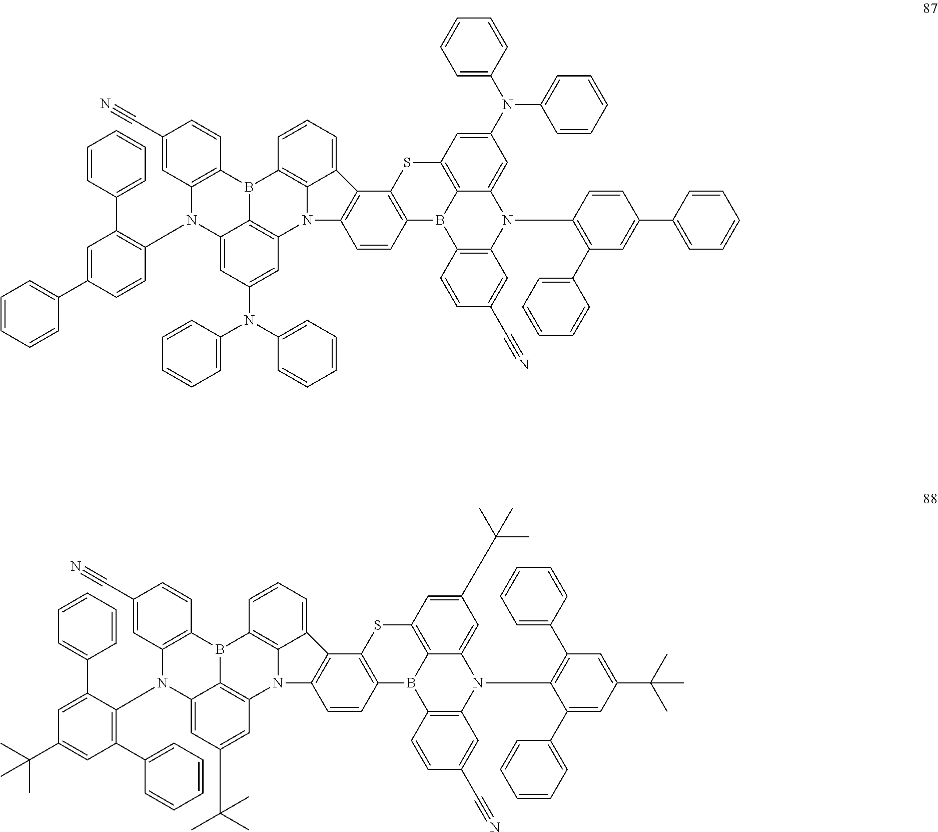 [SMILES: N#Cc1ccc2c(c1)N(c1ccc(-c3ccccc3)cc1-c1ccccc1)c1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C#N)cc1N2c1ccc(-c2ccccc2)cc1-c1ccccc1 ; CC(C)(C)c1cc(-c2ccccc2)c(N2c3cc(C#N)ccc3B3c4ccc5c(c4Sc4cc(C(C)(C)C)cc2c43)c2cccc3c2n5-c2cc(C(C)(C)C)cc4c2B3c2ccc(C#N)cc2N4c2c(-c3ccccc3)cc(C(C)(C)C)cc2-c2ccccc2)c(-c2ccccc2)c1] 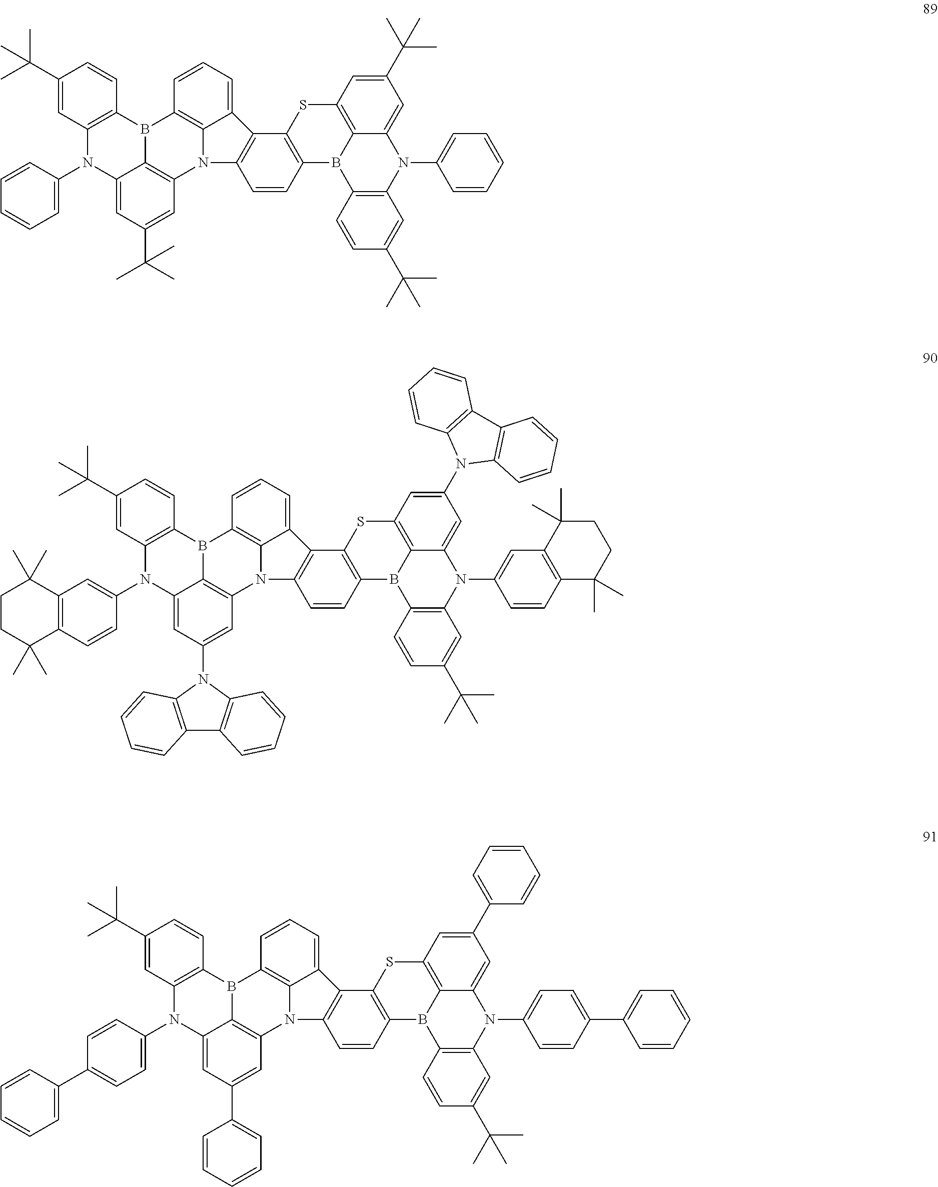 [SMILES: CC(C)(C)c1ccc2c(c1)N(c1ccccc1)c1cc(C(C)(C)C)cc3c1B2c1ccc2c(c1S3)c1cccc3c1n2-c1cc(C(C)(C)C)cc2c1B3c1ccc(C(C)(C)C)cc1N2c1ccccc1 ; CC(C)(C)c1ccc2c(c1)N(c1ccc3c(c1)C(C)(C)CCC3(C)C)c1cc(-n3c4ccccc4c4ccccc43)cc3c1B2c1ccc2c(c1S3)c1cccc3c1n2-c1cc(-n2c4ccccc4c4ccccc42)cc2c1B3c1ccc(C(C)(C)C)cc1N2c1ccc2c(c1)C(C)(C)CCC2(C)C ; CC(C)(C)c1ccc2c(c1)N(c1ccc(-c3ccccc3)cc1)c1cc(-c3ccccc3)cc3c1B2c1ccc2c(c1S3)c1cccc3c1n2-c1cc(-c2ccccc2)cc2c1B3c1ccc(C(C)(C)C)cc1N2c1ccc(-c2ccccc2)cc1] 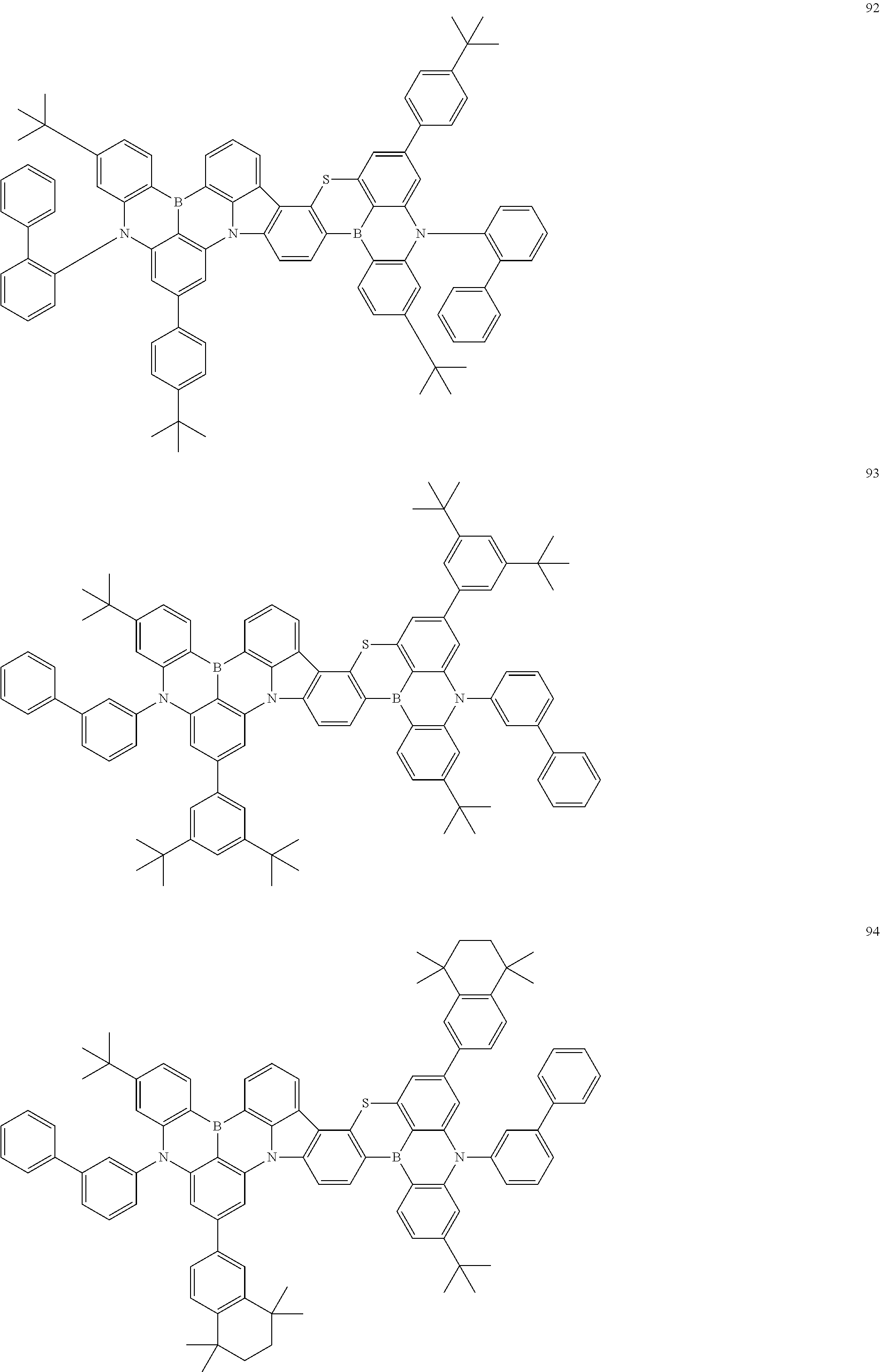 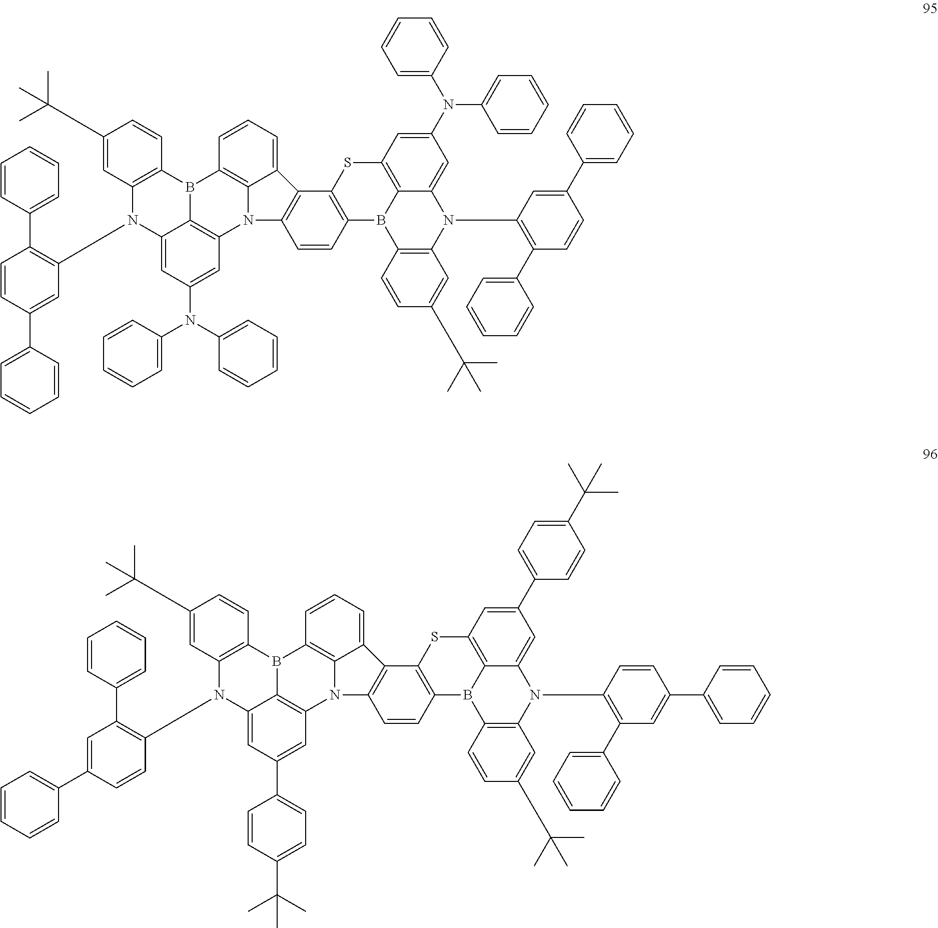 [SMILES: CC(C)(C)c1ccc2c(c1)N(c1cc(-c3ccccc3)ccc1-c1ccccc1)c1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)N(c2ccc(-c5ccccc5)cc2-c2ccccc2)c2cc(C(C)(C)C)ccc2B4c2ccc4c(c2S3)c2cccc3c2n4-c2cc(-c4ccc(C(C)(C)C)cc4)cc4c2B3c2ccc(C(C)(C)C)cc2N4c2ccc(-c3ccccc3)cc2-c2ccccc2)cc1] 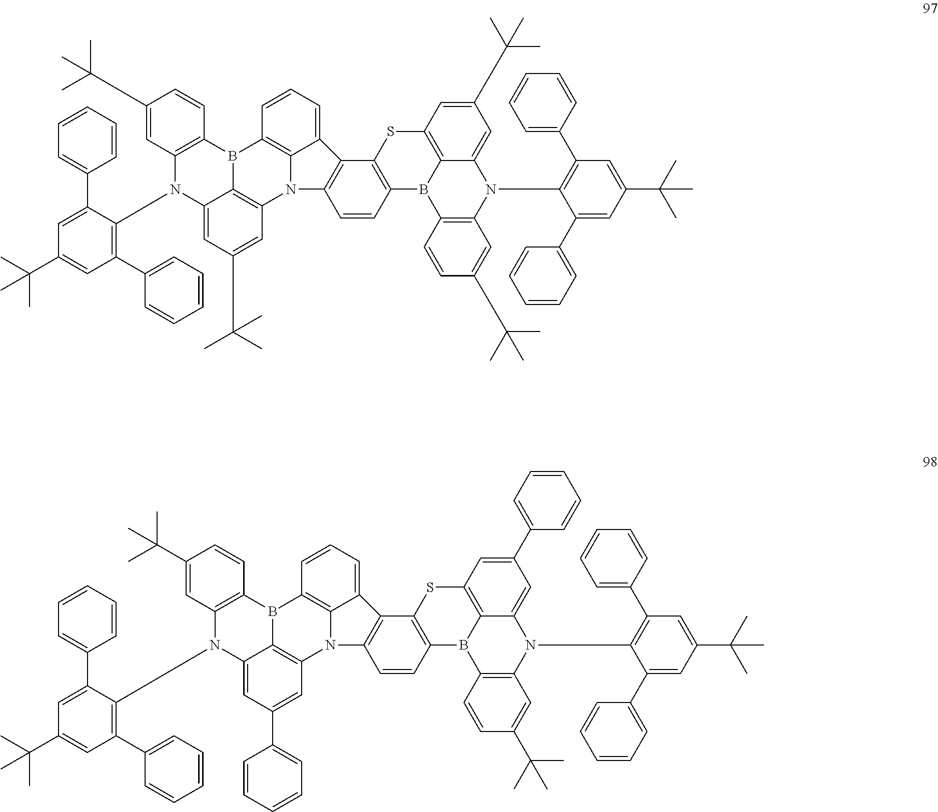 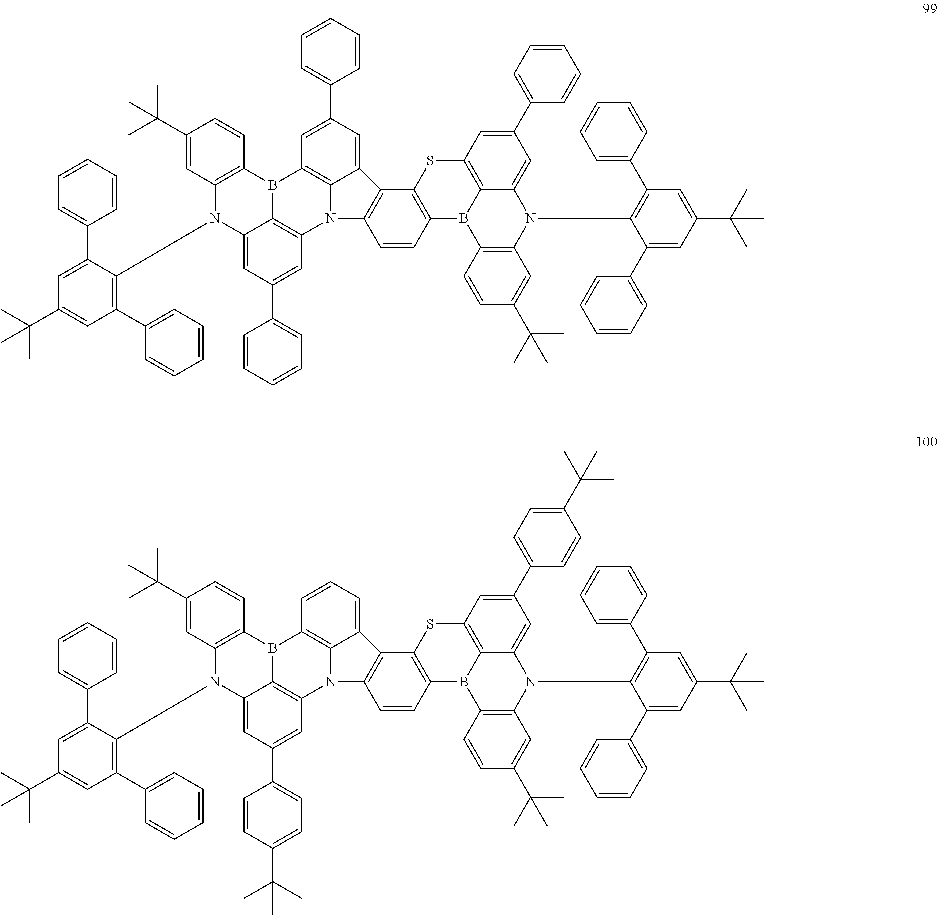 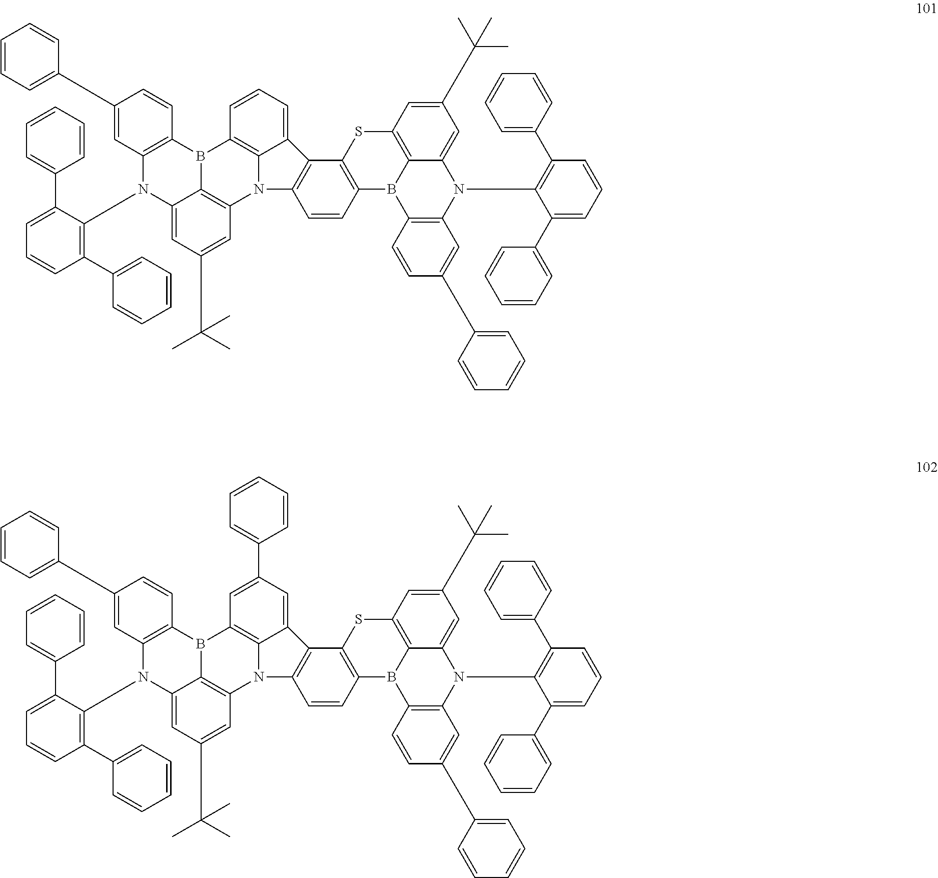 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cccc2c1n3-c1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1N3c1c(-c2ccccc2)cccc1-c1ccccc1] 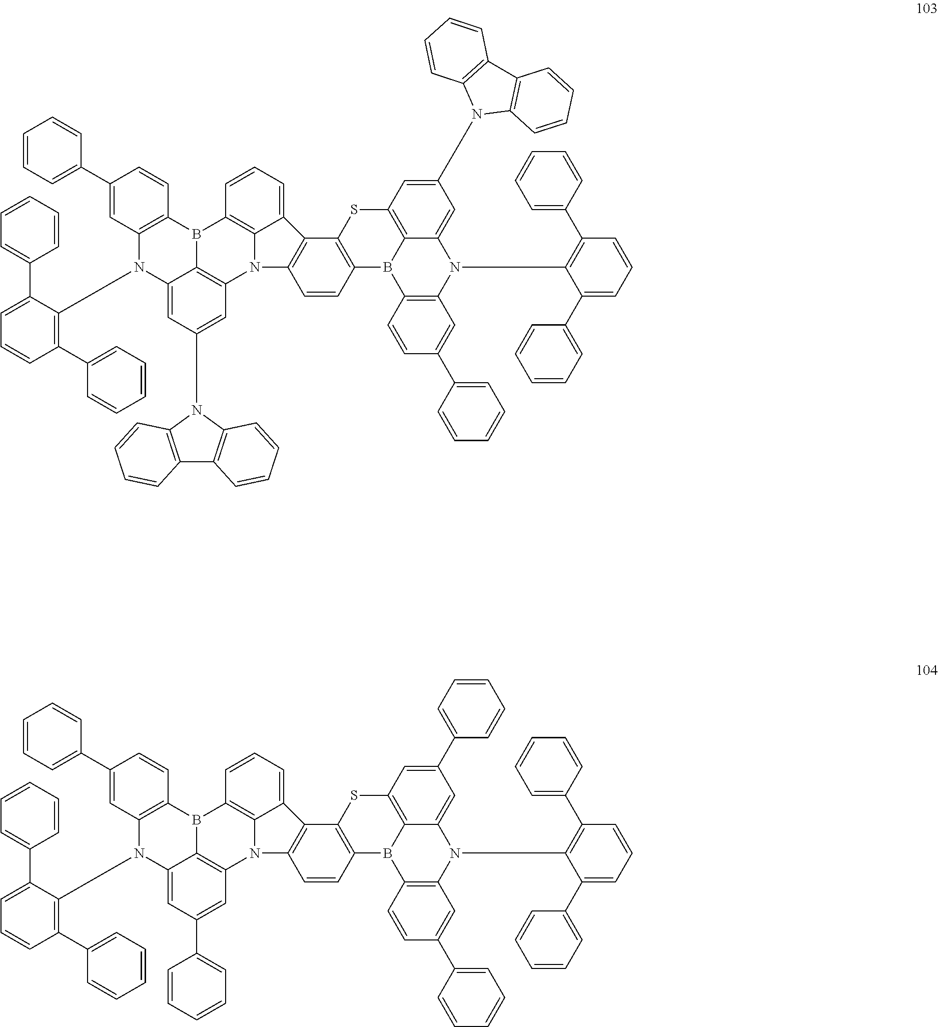 [SMILES: c1ccc(-c2ccc3c(c2)N(c2c(-c4ccccc4)cccc2-c2ccccc2)c2cc(-n4c5ccccc5c5ccccc54)cc4c2B3c2ccc3c(c2S4)c2cccc4c2n3-c2cc(-n3c5ccccc5c5ccccc53)cc3c2B4c2ccc(-c4ccccc4)cc2N3c2c(-c3ccccc3)cccc2-c2ccccc2)cc1 ; c1ccc(-c2ccc3c(c2)N(c2c(-c4ccccc4)cccc2-c2ccccc2)c2cc(-c4ccccc4)cc4c2B3c2ccc3c(c2S4)c2cccc4c2n3-c2cc(-c3ccccc3)cc3c2B4c2ccc(-c4ccccc4)cc2N3c2c(-c3ccccc3)cccc2-c2ccccc2)cc1] 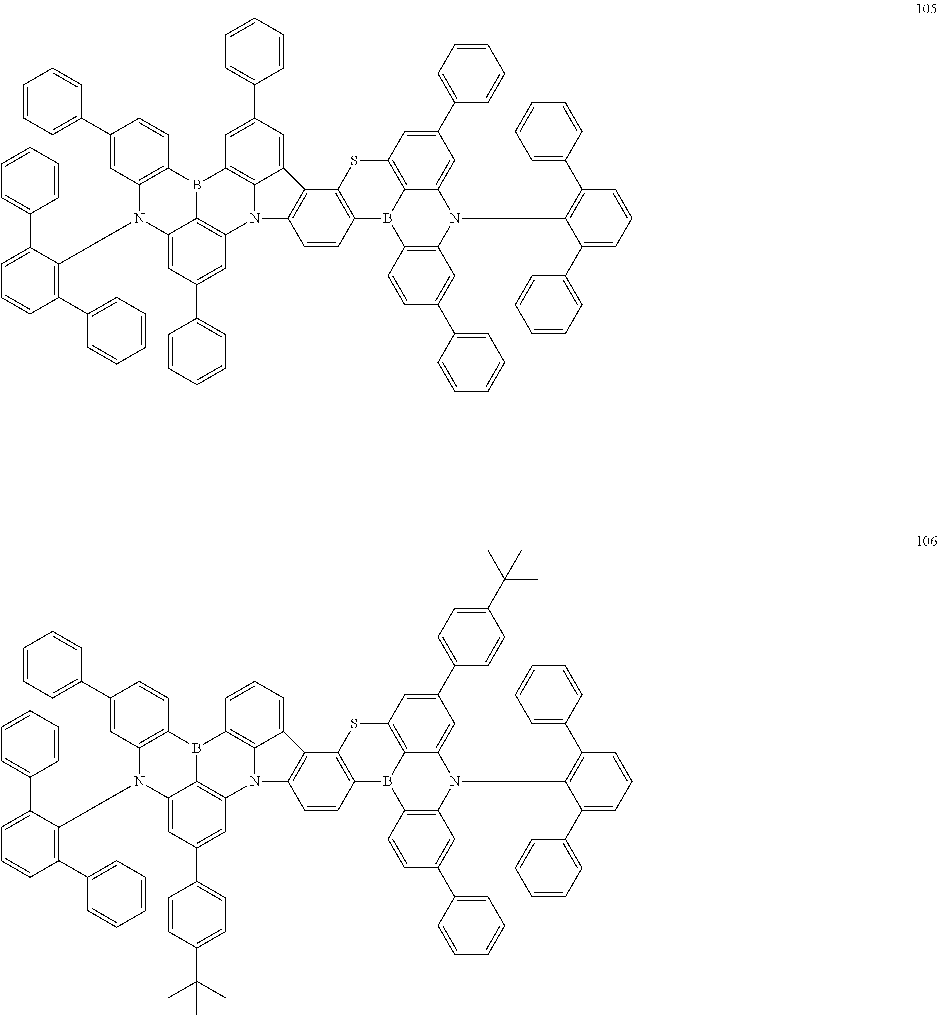 [SMILES: c1ccc(-c2ccc3c(c2)N(c2c(-c4ccccc4)cccc2-c2ccccc2)c2cc(-c4ccccc4)cc4c2B3c2ccc3c(c2S4)c2cc(-c4ccccc4)cc4c2n3-c2cc(-c3ccccc3)cc3c2B4c2ccc(-c4ccccc4)cc2N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cccc3c2n4-c2cc(-c4ccc(C(C)(C)C)cc4)cc4c2B3c2ccc(-c3ccccc3)cc2N4c2c(-c3ccccc3)cccc2-c2ccccc2)cc1] 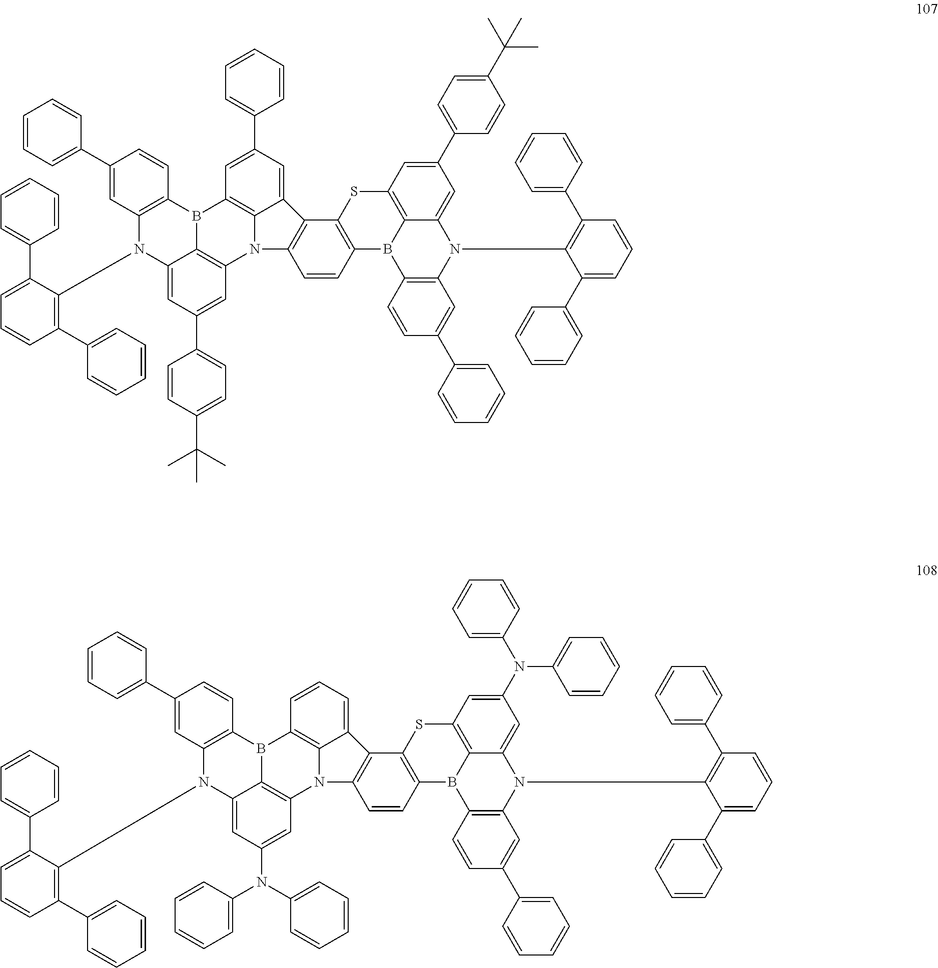 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cc(-c3ccccc3)cc3c2n4-c2cc(-c4ccc(C(C)(C)C)cc4)cc4c2B3c2ccc(-c3ccccc3)cc2N4c2c(-c3ccccc3)cccc2-c2ccccc2)cc1 ; c1ccc(-c2ccc3c(c2)N(c2c(-c4ccccc4)cccc2-c2ccccc2)c2cc(N(c4ccccc4)c4ccccc4)cc4c2B3c2ccc3c(c2S4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 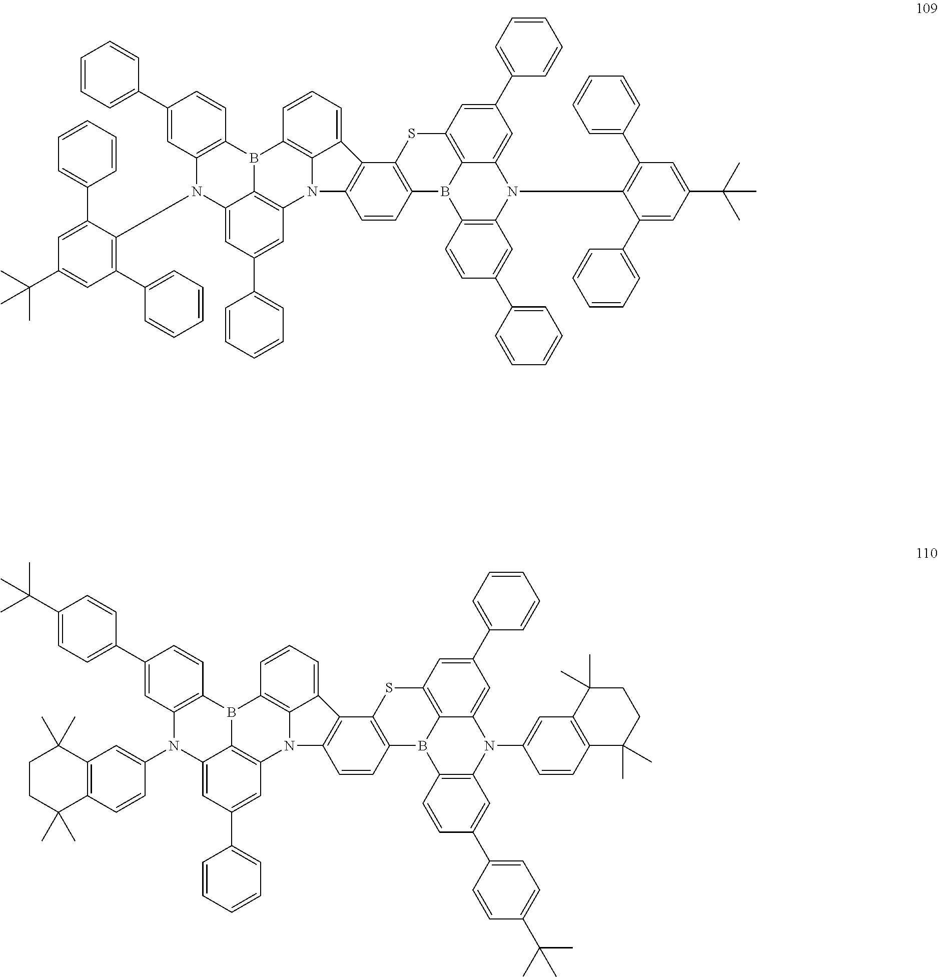 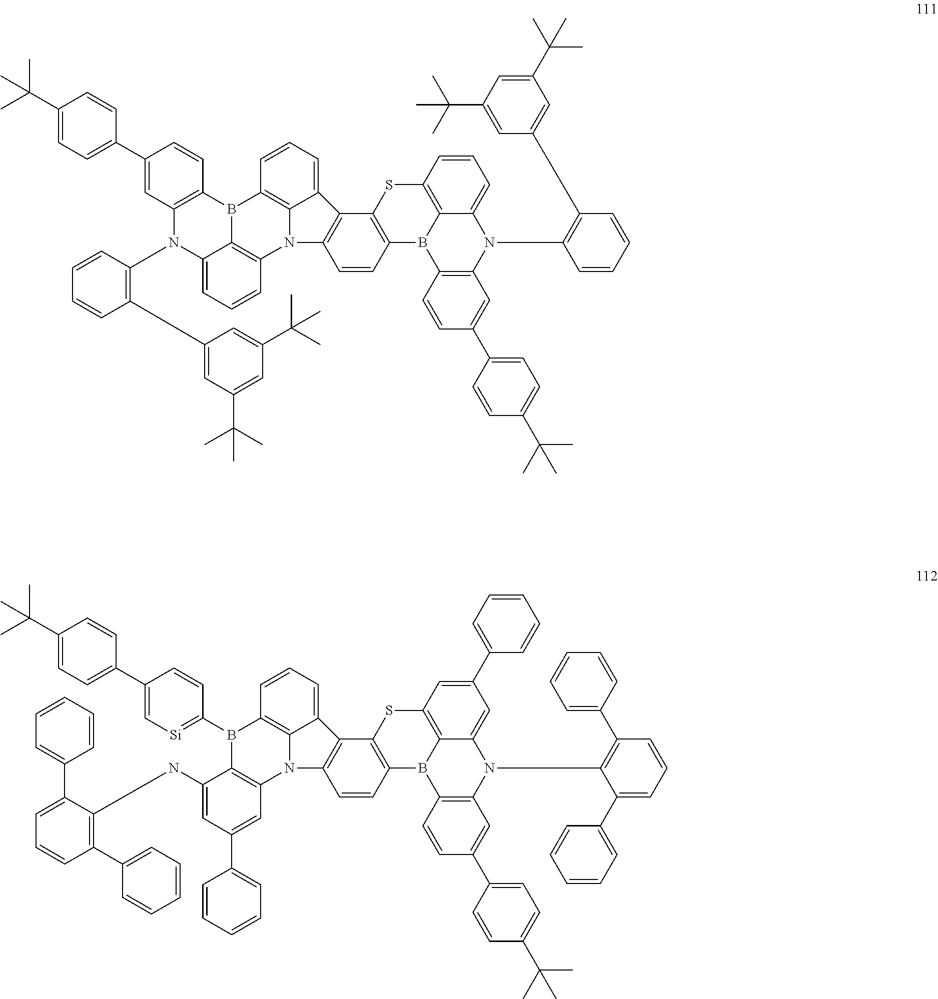 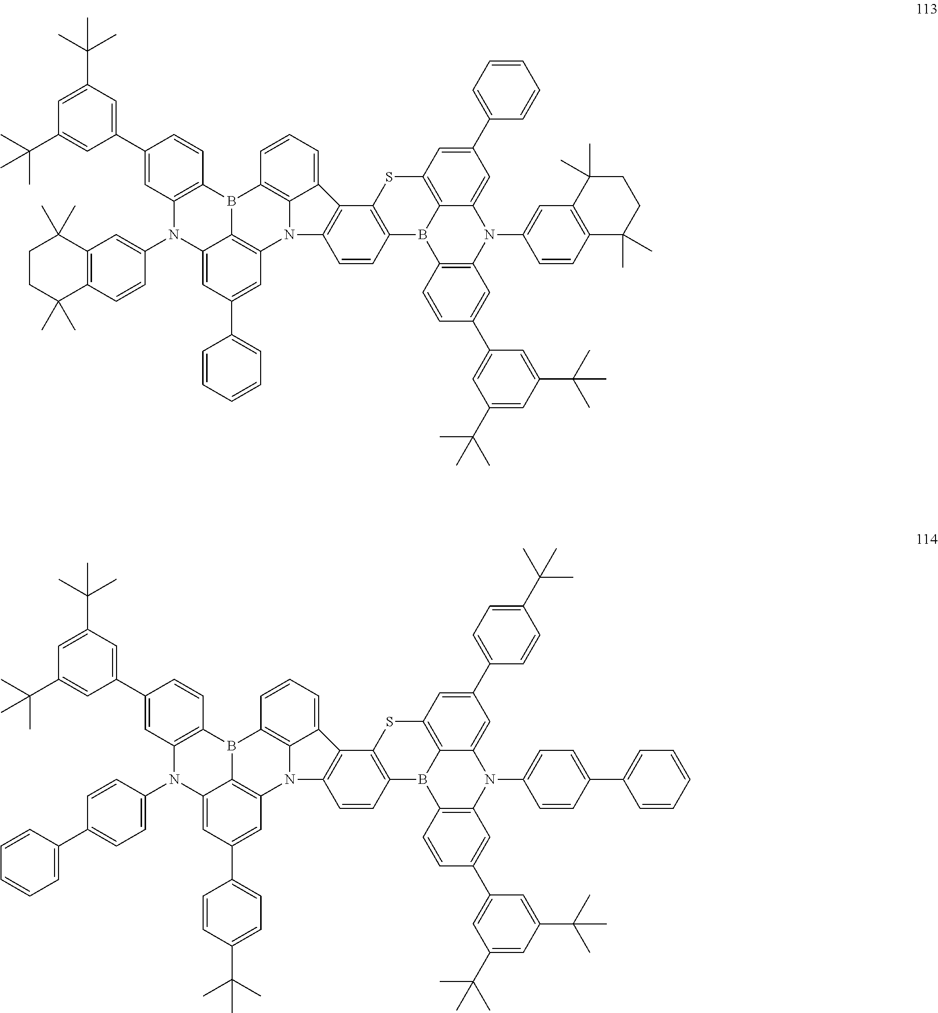 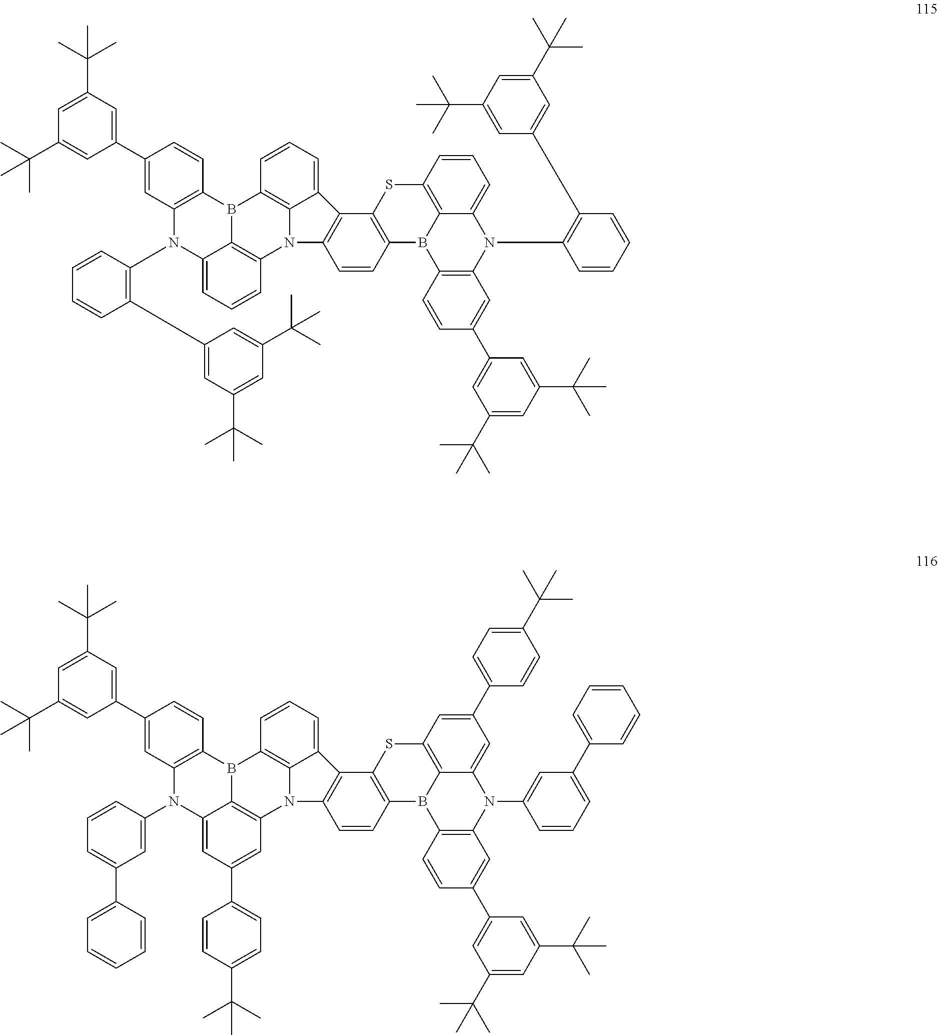 [SMILES: CC(C)(C)c1cc(-c2ccc3c(c2)N(c2ccccc2-c2cc(C(C)(C)C)cc(C(C)(C)C)c2)c2cccc4c2B3c2ccc3c(c2S4)c2cccc4c2n3-c2cccc3c2B4c2ccc(-c4cc(C(C)(C)C)cc(C(C)(C)C)c4)cc2N3c2ccccc2-c2cc(C(C)(C)C)cc(C(C)(C)C)c2)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2S3)c2cccc3c2n4-c2cc(-c4ccc(C(C)(C)C)cc4)cc4c2B3c2ccc(-c3cc(C(C)(C)C)cc(C(C)(C)C)c3)cc2N4c2cccc(-c3ccccc3)c2)cc1] 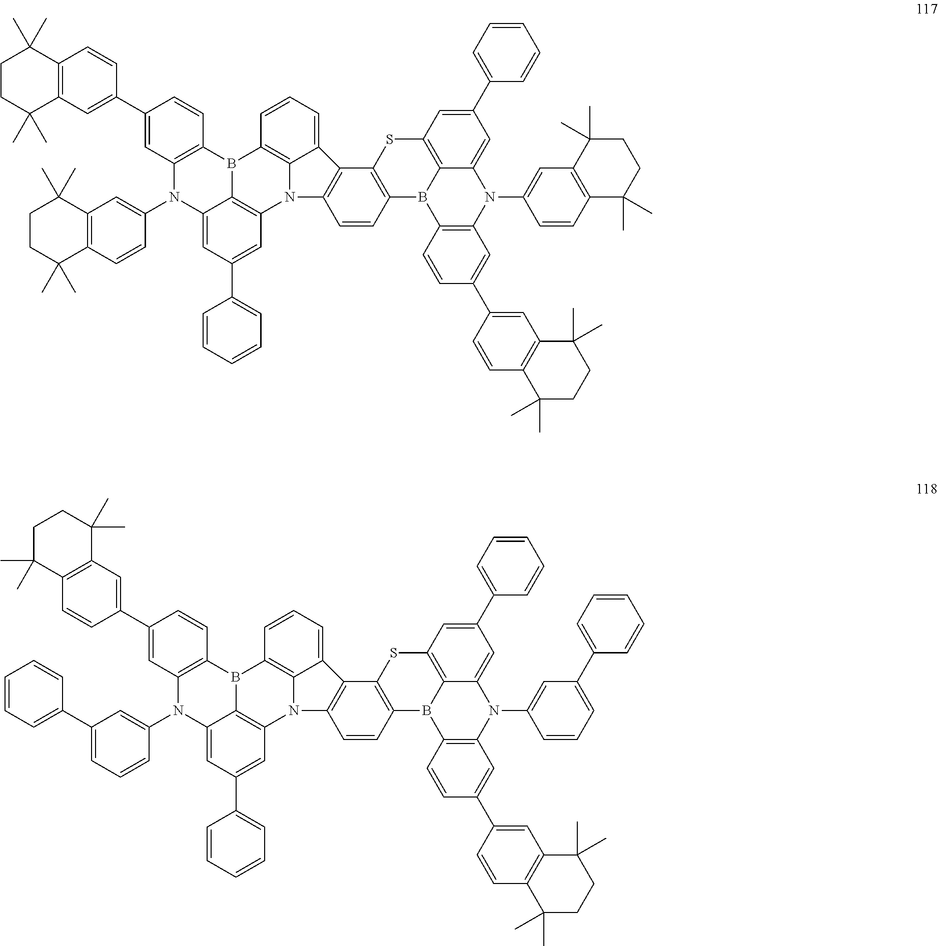 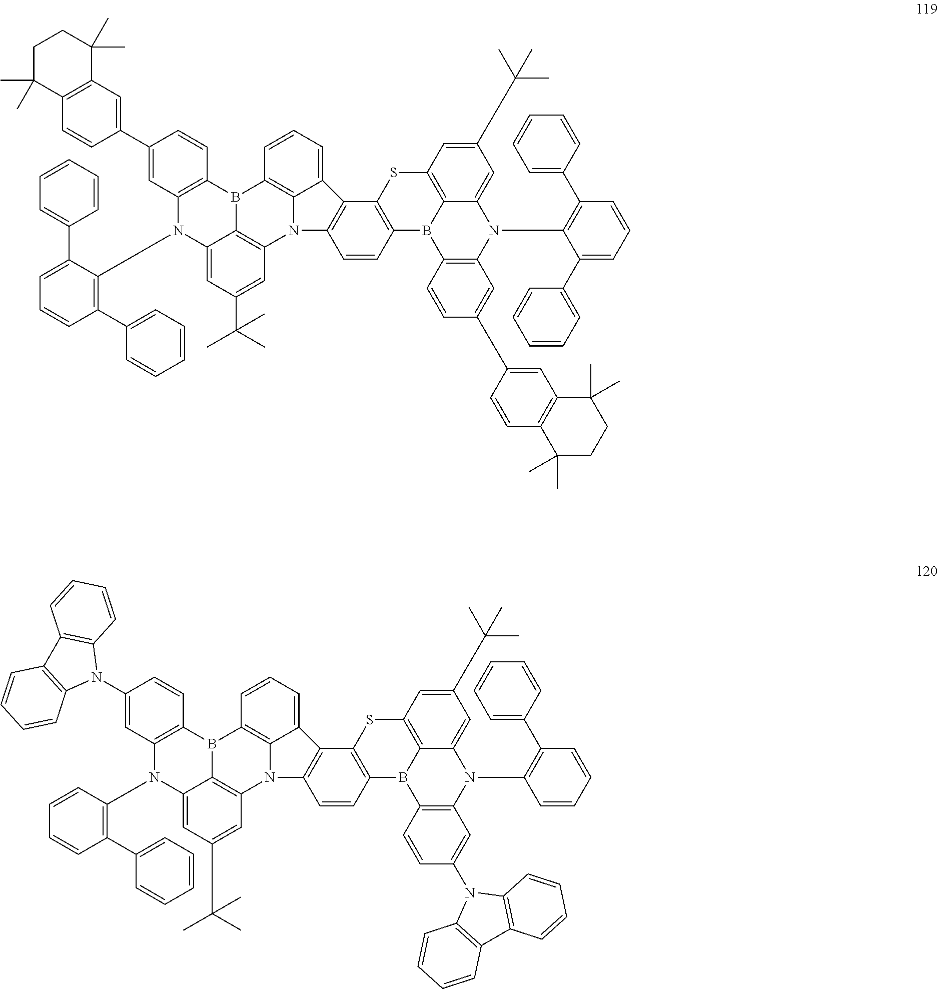 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1S2)c1cccc2c1n3-c1cc(C(C)(C)C)cc3c1B2c1ccc(-c2ccc4c(c2)C(C)(C)CCC4(C)C)cc1N3c1c(-c2ccccc2)cccc1-c1ccccc1 ; CC(C)(C)c1cc2c3c(c1)N(c1ccccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1ccccc1-c1ccccc1] 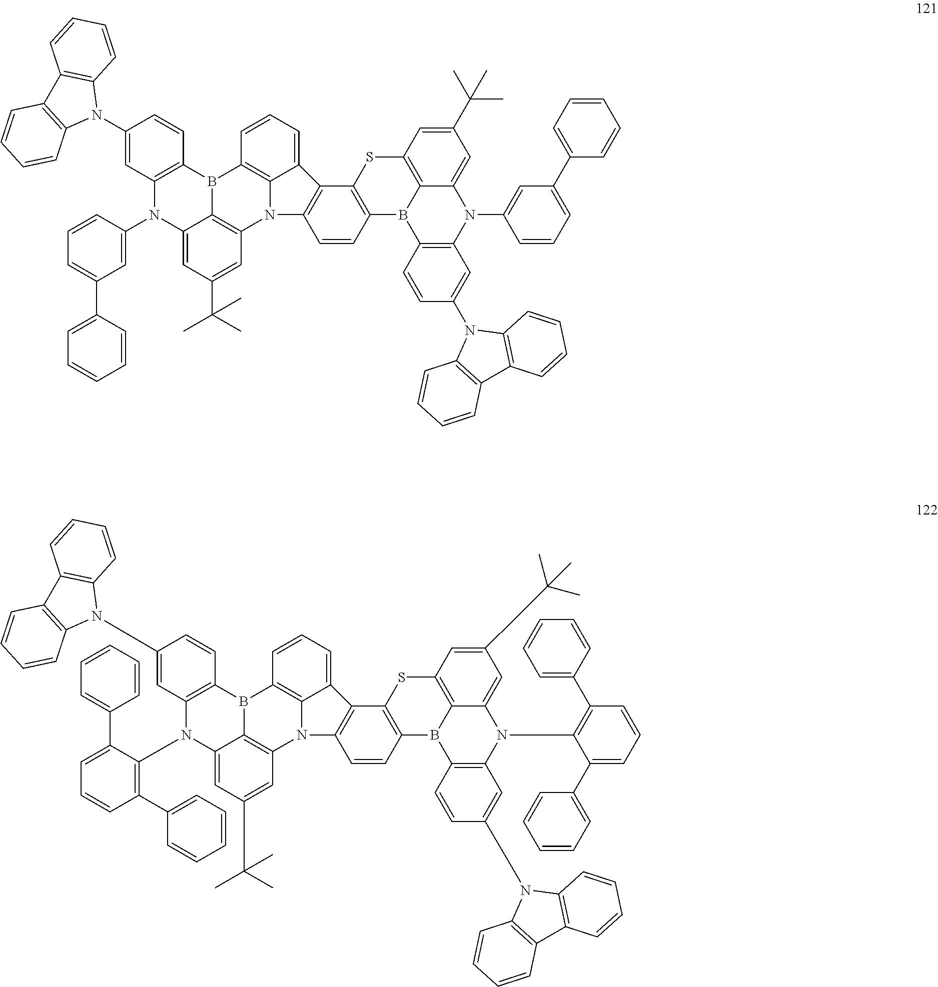 [SMILES: CC(C)(C)c1cc2c3c(c1)N(c1cccc(-c4ccccc4)c1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1cccc(-c2ccccc2)c1 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1c(-c2ccccc2)cccc1-c1ccccc1] 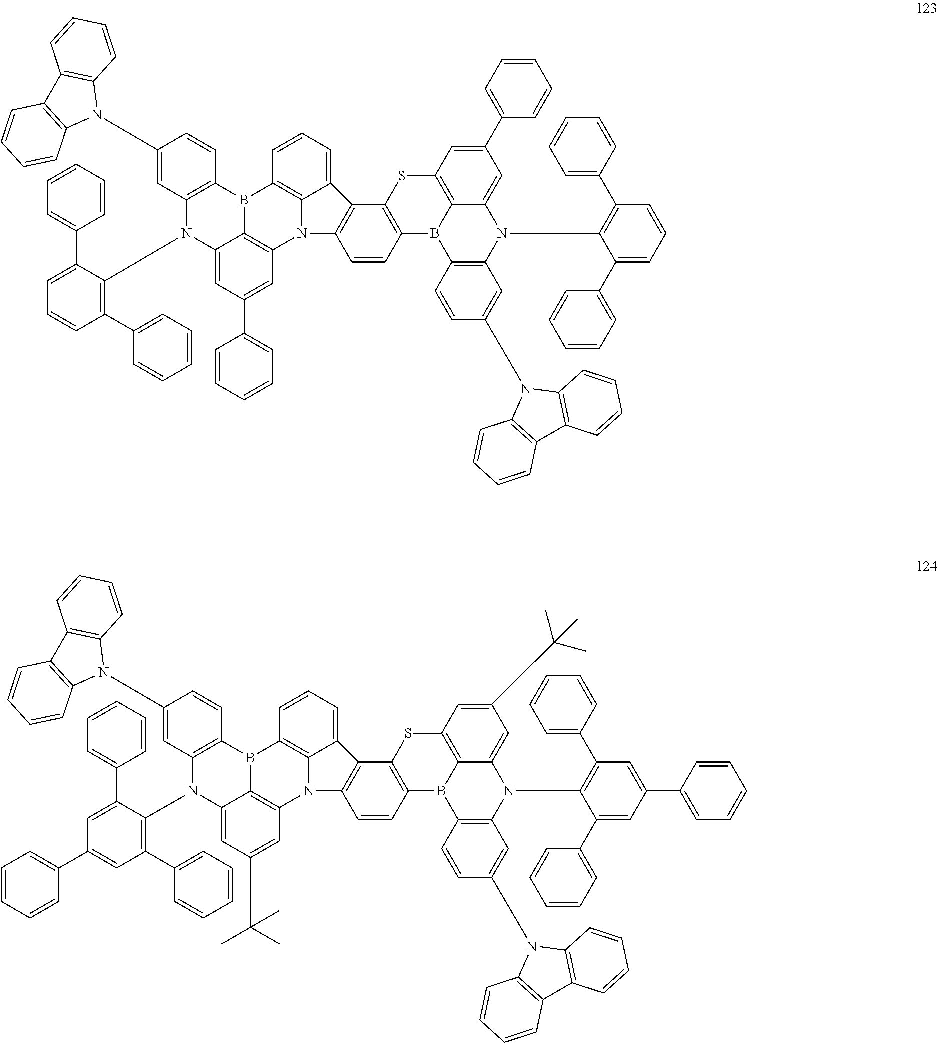 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2S3)c2cccc3c2n4-c2cc(-c4ccccc4)cc4c2B3c2ccc(-n3c5ccccc5c5ccccc53)cc2N4c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1N3c1c(-c2ccccc2)cc(-c2ccccc2)cc1-c1ccccc1] 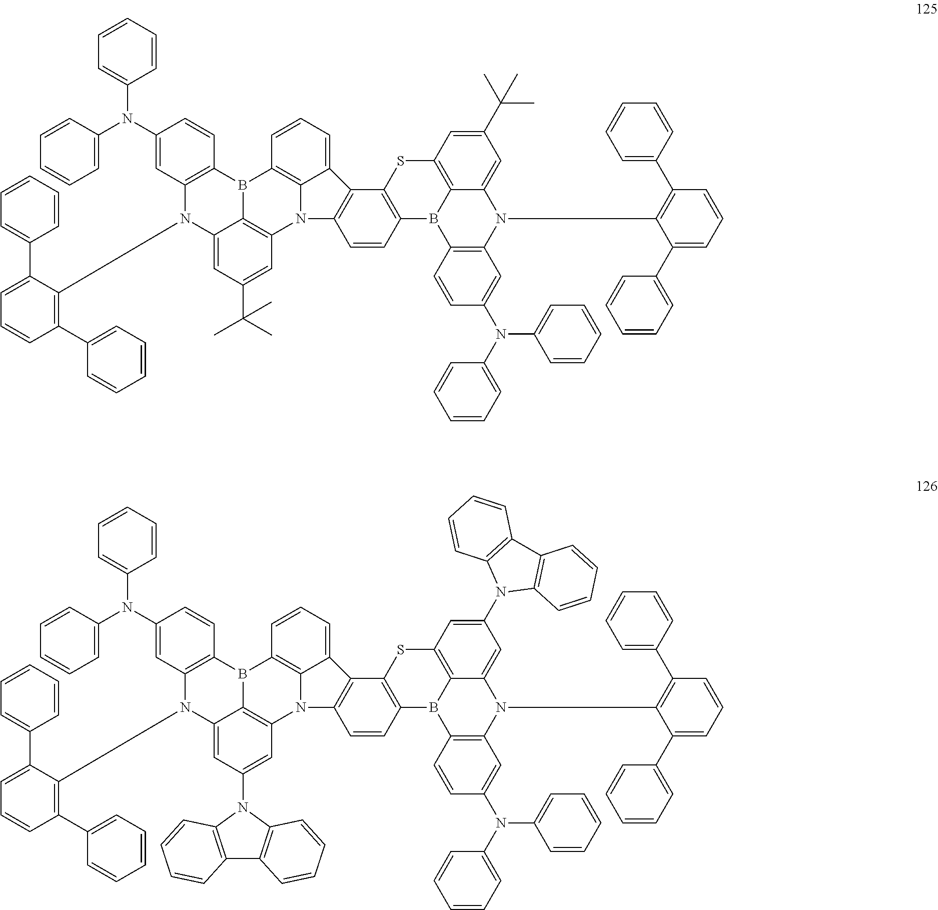 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1S2)c1cccc2c1n3-c1cc(C(C)(C)C)cc3c1B2c1ccc(N(c2ccccc2)c2ccccc2)cc1N3c1c(-c2ccccc2)cccc1-c1ccccc1 ; c1ccc(-c2cccc(-c3ccccc3)c2N2c3cc(N(c4ccccc4)c4ccccc4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2N4c2c(-c3ccccc3)cccc2-c2ccccc2)cc1] 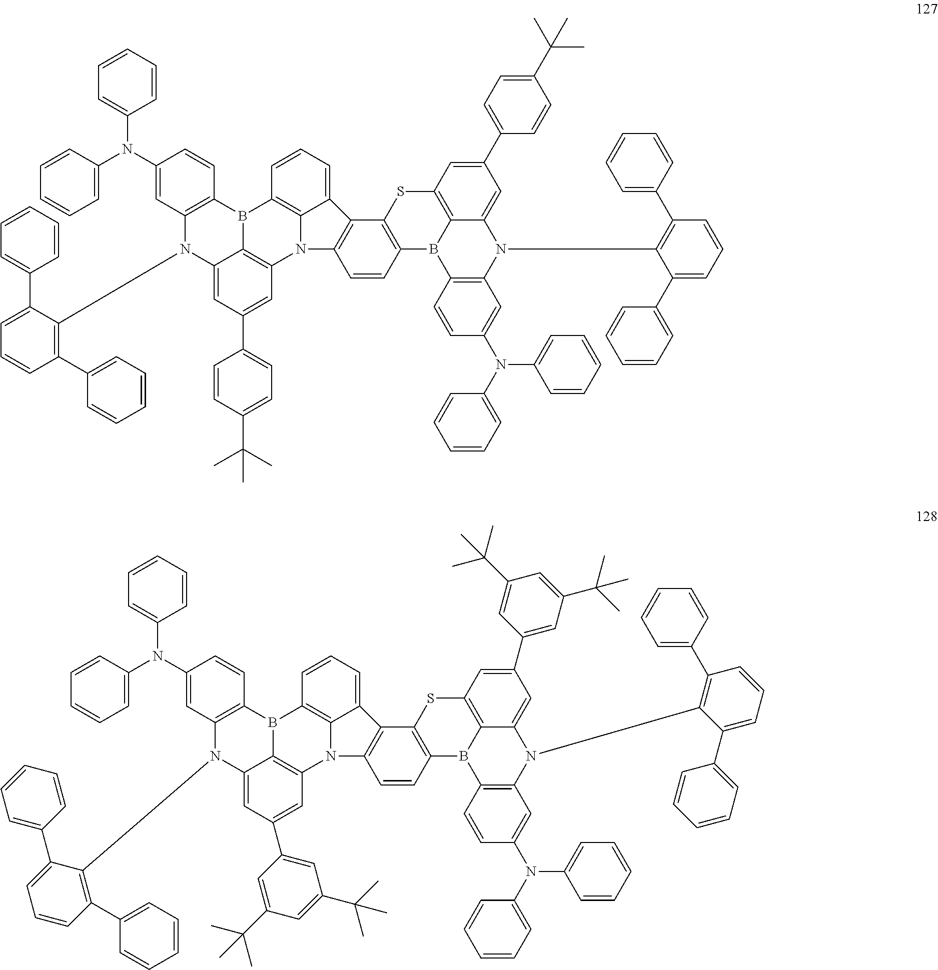 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4ccc(C(C)(C)C)cc4)cc4c2B3c2ccc(N(c3ccccc3)c3ccccc3)cc2N4c2c(-c3ccccc3)cccc2-c2ccccc2)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4cc(C(C)(C)C)cc(C(C)(C)C)c4)cc4c2B3c2ccc(N(c3ccccc3)c3ccccc3)cc2N4c2c(-c3ccccc3)cccc2-c2ccccc2)cc(C(C)(C)C)c1] 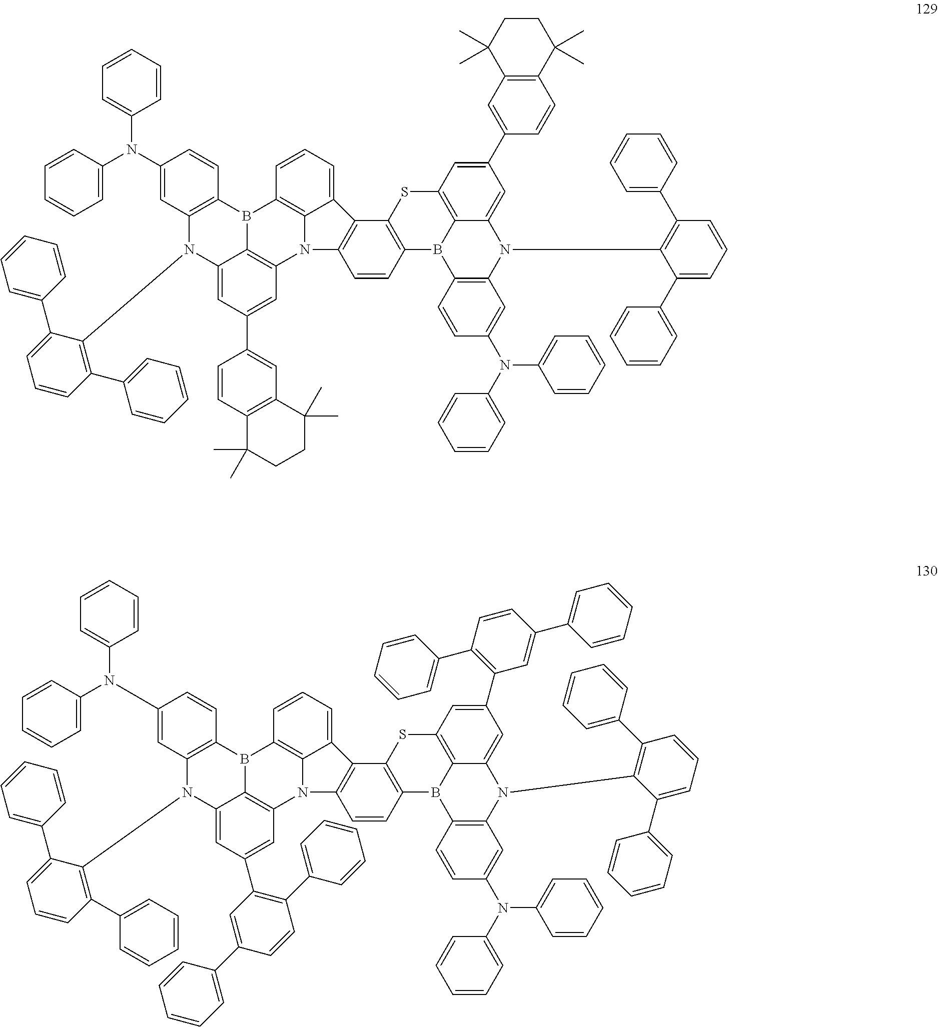 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5ccc6c(c5)C(C)(C)CCC6(C)C)cc5c3B4c3ccc(N(c4ccccc4)c4ccccc4)cc3N5c3c(-c4ccccc4)cccc3-c3ccccc3)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5cc(-c6ccccc6)ccc5-c5ccccc5)cc5c3B4c3ccc(N(c4ccccc4)c4ccccc4)cc3N5c3c(-c4ccccc4)cccc3-c3ccccc3)c2)cc1] 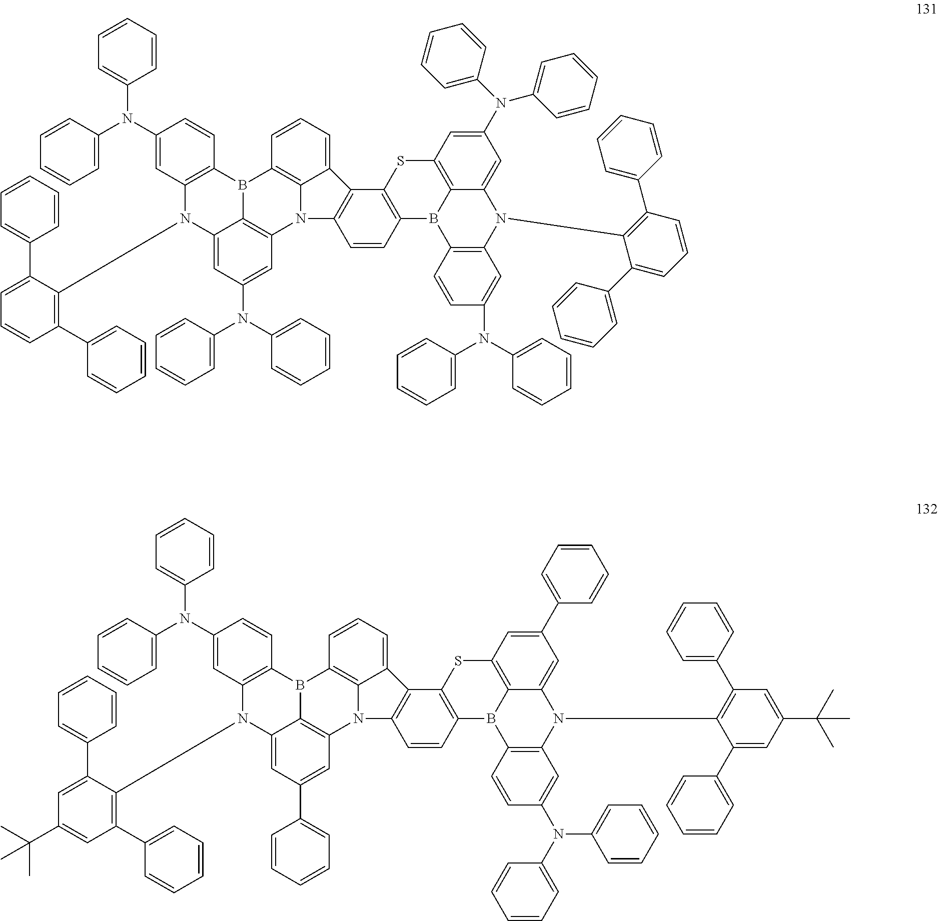 [SMILES: c1ccc(-c2cccc(-c3ccccc3)c2N2c3cc(N(c4ccccc4)c4ccccc4)ccc3B3c4ccc5c(c4Sc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2N4c2c(-c3ccccc3)cccc2-c2ccccc2)cc1 ; CC(C)(C)c1cc(-c2ccccc2)c(N2c3cc(N(c4ccccc4)c4ccccc4)ccc3B3c4ccc5c(c4Sc4cc(-c6ccccc6)cc2c43)c2cccc3c2n5-c2cc(-c4ccccc4)cc4c2B3c2ccc(N(c3ccccc3)c3ccccc3)cc2N4c2c(-c3ccccc3)cc(C(C)(C)C)cc2-c2ccccc2)c(-c2ccccc2)c1] 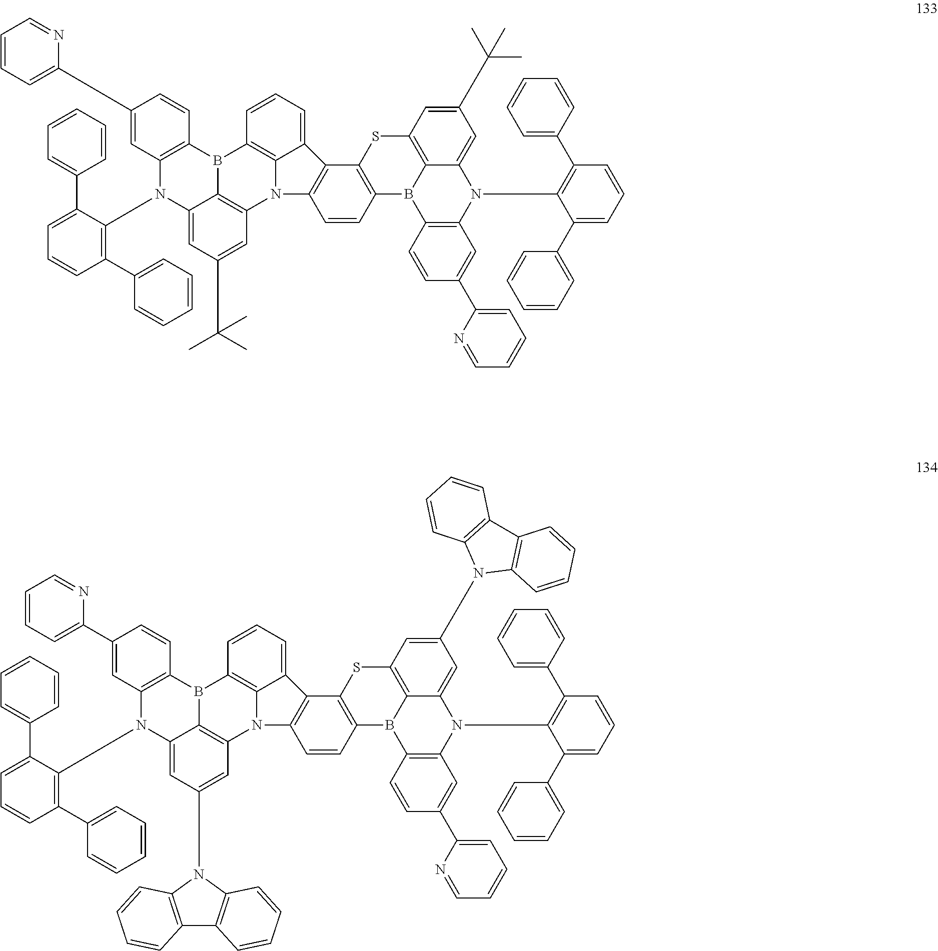 [SMILES: CC(C)(C)c1cc2c3c(c1)N(c1c(-c4ccccc4)cccc1-c1ccccc1)c1cc(-c4ccccn4)ccc1B3c1ccc3c(c1S2)c1cccc2c1n3-c1cc(C(C)(C)C)cc3c1B2c1ccc(-c2ccccn2)cc1N3c1c(-c2ccccc2)cccc1-c1ccccc1 ; c1ccc(-c2cccc(-c3ccccc3)c2N2c3cc(-c4ccccn4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(-c3ccccn3)cc2N4c2c(-c3ccccc3)cccc2-c2ccccc2)cc1] 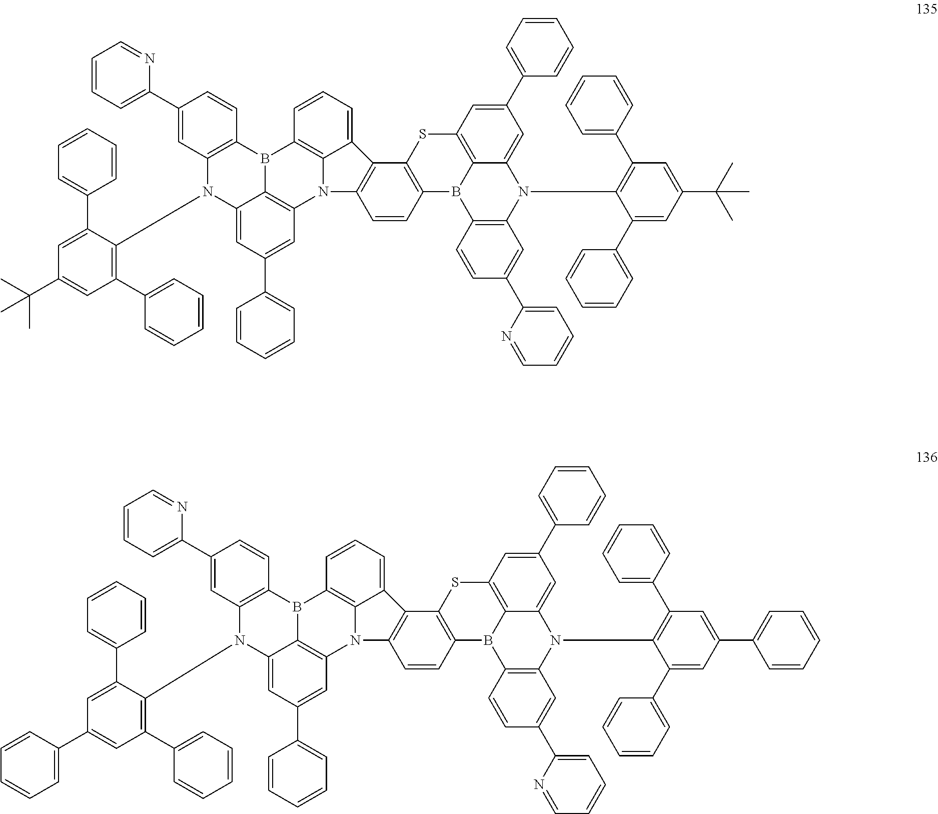 [SMILES: CC(C)(C)c1cc(-c2ccccc2)c(N2c3cc(-c4ccccn4)ccc3B3c4ccc5c(c4Sc4cc(-c6ccccc6)cc2c43)c2cccc3c2n5-c2cc(-c4ccccc4)cc4c2B3c2ccc(-c3ccccn3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccccn5)ccc4B4c5ccc6c(c5Sc5cc(-c7ccccc7)cc3c54)c3cccc4c3n6-c3cc(-c5ccccc5)cc5c3B4c3ccc(-c4ccccn4)cc3N5c3c(-c4ccccc4)cc(-c4ccccc4)cc3-c3ccccc3)c(-c3ccccc3)c2)cc1] 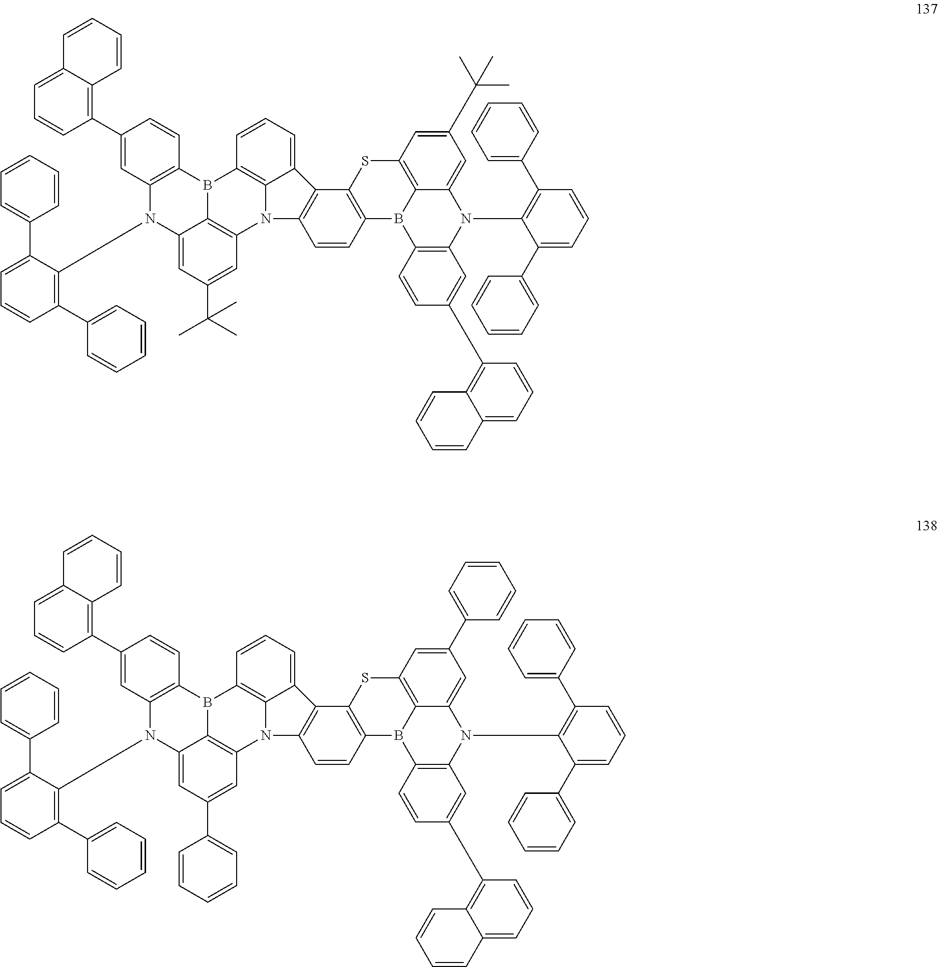 [SMILES: CC(C)(C)c1cc2c3c(c1)N(c1c(-c4ccccc4)cccc1-c1ccccc1)c1cc(-c4cccc5ccccc45)ccc1B3c1ccc3c(c1S2)c1cccc2c1n3-c1cc(C(C)(C)C)cc3c1B2c1ccc(-c2cccc4ccccc24)cc1N3c1c(-c2ccccc2)cccc1-c1ccccc1 ; c1ccc(-c2cc3c4c(c2)N(c2c(-c5ccccc5)cccc2-c2ccccc2)c2cc(-c5cccc6ccccc56)ccc2B4c2ccc4c(c2S3)c2cccc3c2n4-c2cc(-c4ccccc4)cc4c2B3c2ccc(-c3cccc5ccccc35)cc2N4c2c(-c3ccccc3)cccc2-c2ccccc2)cc1] 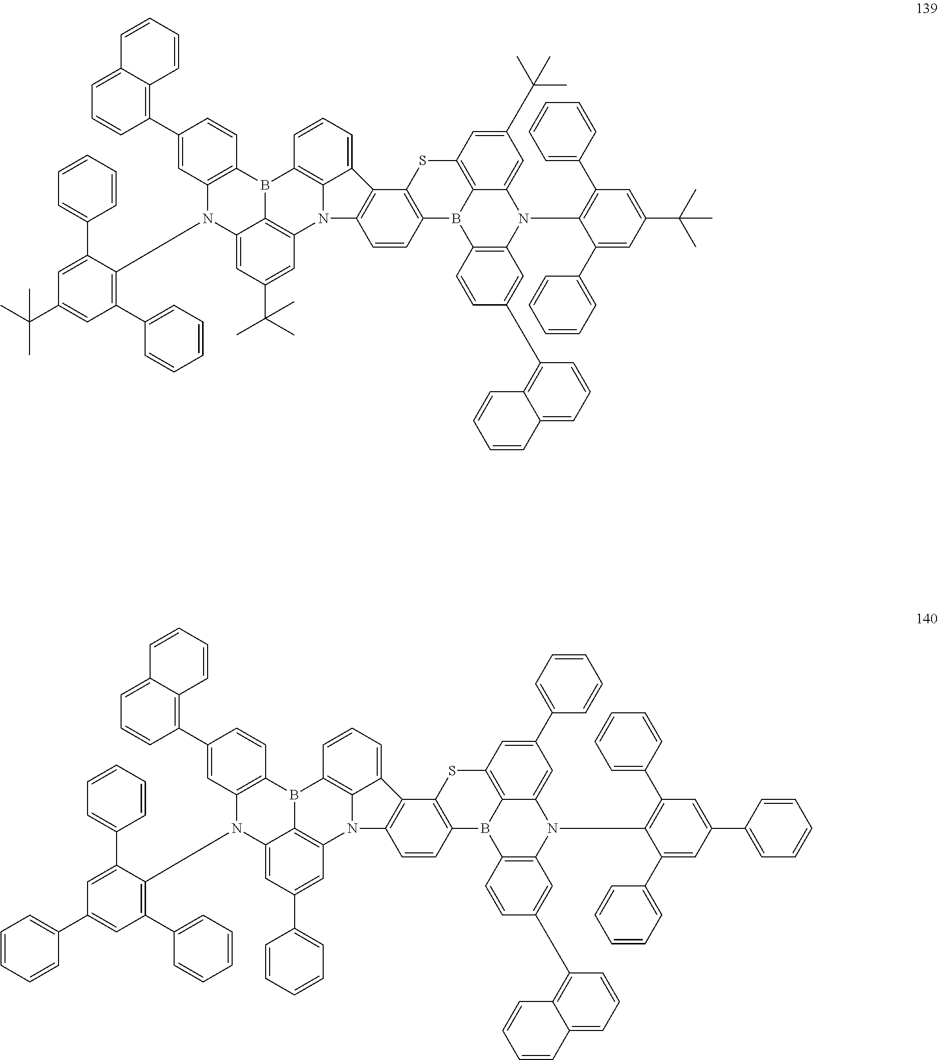 [SMILES: CC(C)(C)c1cc(-c2ccccc2)c(N2c3cc(-c4cccc5ccccc45)ccc3B3c4ccc5c(c4Sc4cc(C(C)(C)C)cc2c43)c2cccc3c2n5-c2cc(C(C)(C)C)cc4c2B3c2ccc(-c3cccc5ccccc35)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5cccc6ccccc56)ccc4B4c5ccc6c(c5Sc5cc(-c7ccccc7)cc3c54)c3cccc4c3n6-c3cc(-c5ccccc5)cc5c3B4c3ccc(-c4cccc6ccccc46)cc3N5c3c(-c4ccccc4)cc(-c4ccccc4)cc3-c3ccccc3)c(-c3ccccc3)c2)cc1] 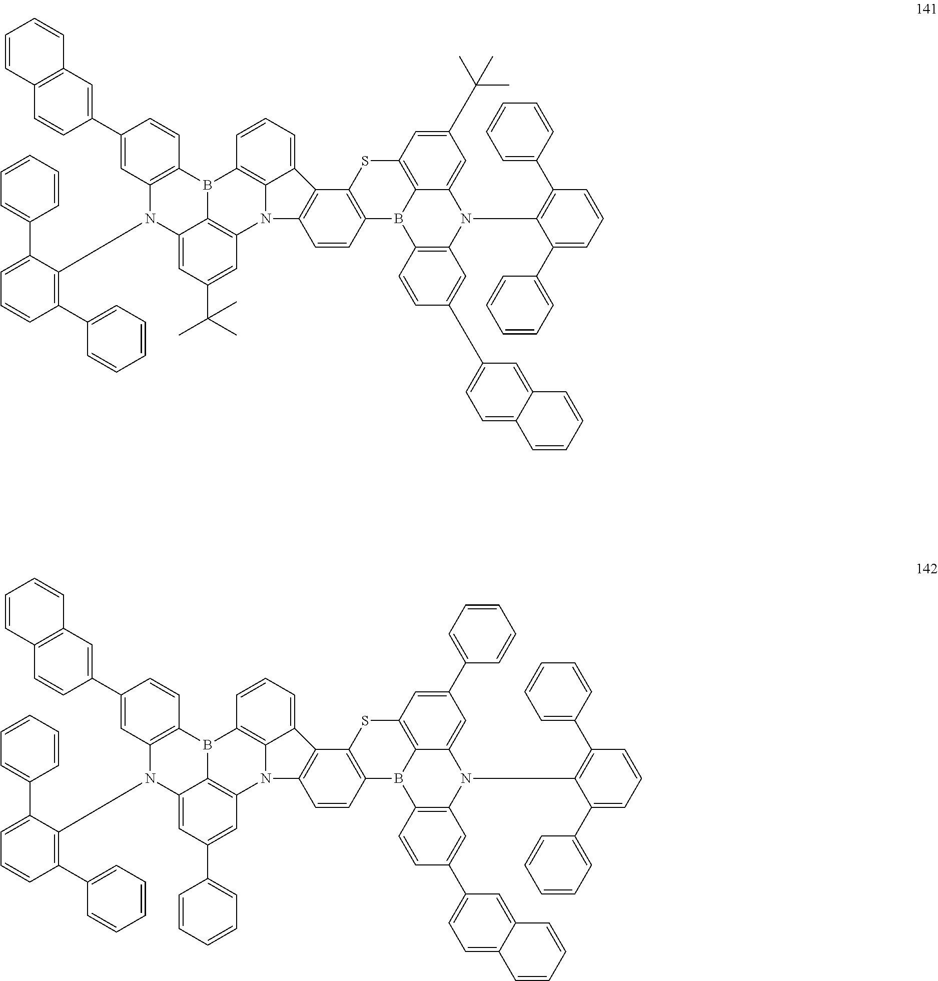 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1S2)c1cccc2c1n3-c1cc(C(C)(C)C)cc3c1B2c1ccc(-c2ccc4ccccc4c2)cc1N3c1c(-c2ccccc2)cccc1-c1ccccc1 ; c1ccc(-c2cc3c4c(c2)N(c2c(-c5ccccc5)cccc2-c2ccccc2)c2cc(-c5ccc6ccccc6c5)ccc2B4c2ccc4c(c2S3)c2cccc3c2n4-c2cc(-c4ccccc4)cc4c2B3c2ccc(-c3ccc5ccccc5c3)cc2N4c2c(-c3ccccc3)cccc2-c2ccccc2)cc1] 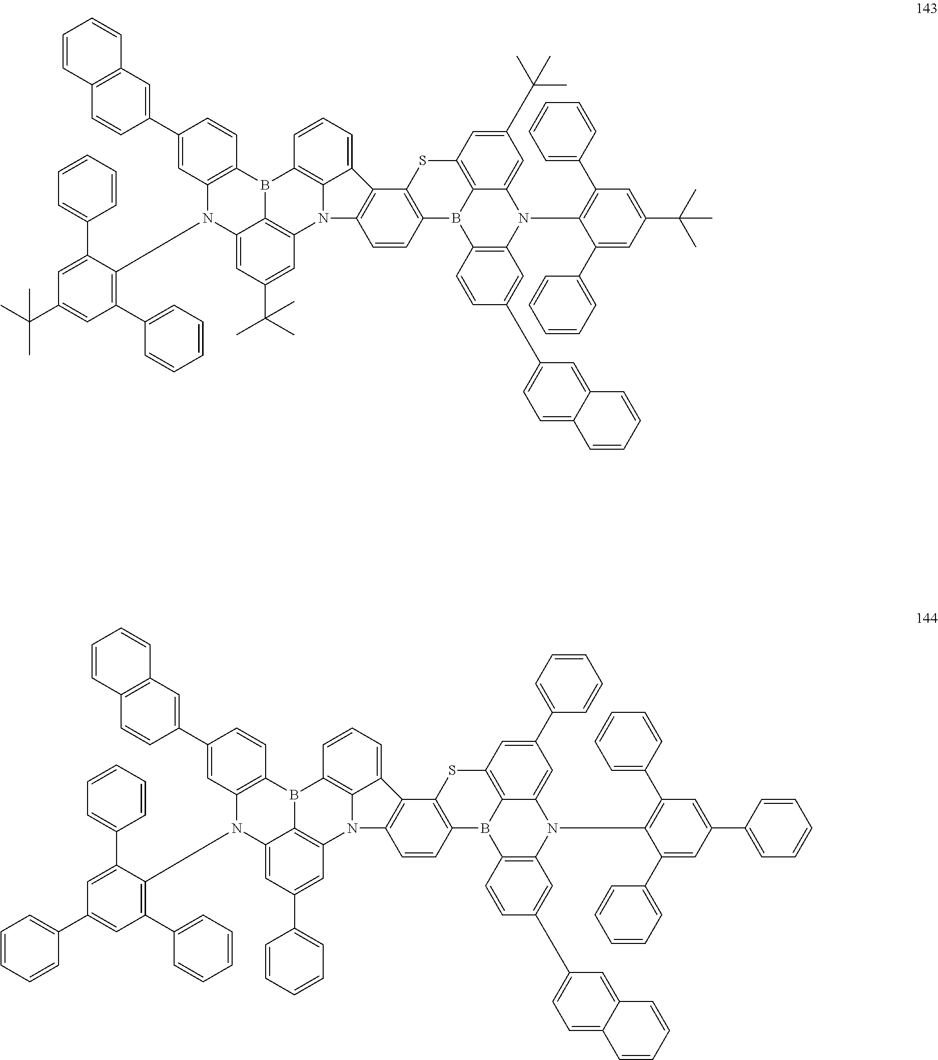 [SMILES: CC(C)(C)c1cc(-c2ccccc2)c(N2c3cc(-c4ccc5ccccc5c4)ccc3B3c4ccc5c(c4Sc4cc(C(C)(C)C)cc2c43)c2cccc3c2n5-c2cc(C(C)(C)C)cc4c2B3c2ccc(-c3ccc5ccccc5c3)cc2N4c2c(-c3ccccc3)cc(C(C)(C)C)cc2-c2ccccc2)c(-c2ccccc2)c1 ; c1ccc(-c2cc(-c3ccccc3)c(N3c4cc(-c5ccc6ccccc6c5)ccc4B4c5ccc6c(c5Sc5cc(-c7ccccc7)cc3c54)c3cccc4c3n6-c3cc(-c5ccccc5)cc5c3B4c3ccc(-c4ccc6ccccc6c4)cc3N5c3c(-c4ccccc4)cc(-c4ccccc4)cc3-c3ccccc3)c(-c3ccccc3)c2)cc1] 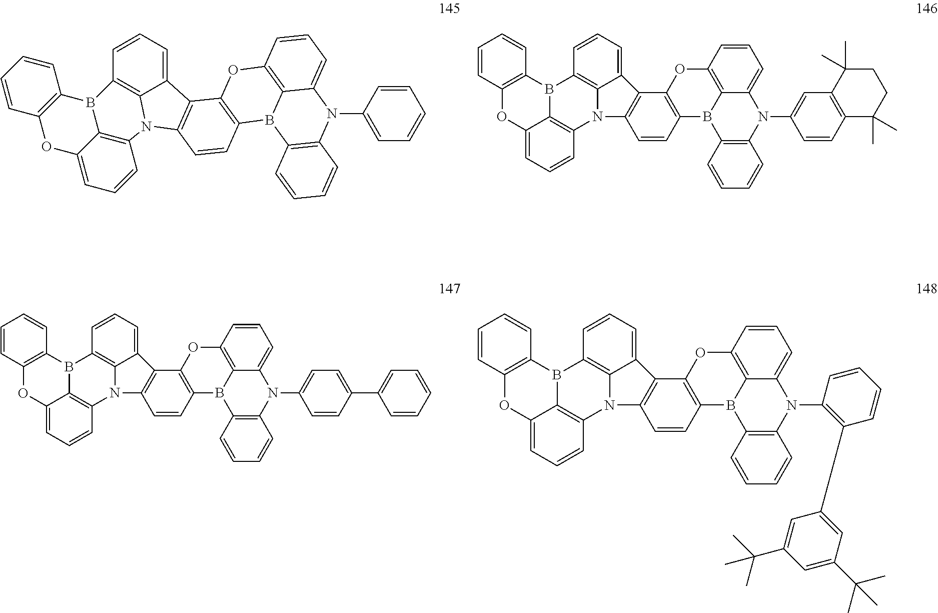 [SMILES: c1ccc(N2c3ccccc3B3c4ccc5c(c4Oc4cccc2c43)c2cccc3c2n5-c2cccc4c2B3c2ccccc2O4)cc1 ; CC1(C)CCC(C)(C)c2cc(N3c4ccccc4B4c5ccc6c(c5Oc5cccc3c54)c3cccc4c3n6-c3cccc5c3B4c3ccccc3O5)ccc21 ; c1ccc(-c2ccc(N3c4ccccc4B4c5ccc6c(c5Oc5cccc3c54)c3cccc4c3n6-c3cccc5c3B4c3ccccc3O5)cc2)cc1 ; CC(C)(C)c1cc(-c2ccccc2N2c3ccccc3B3c4ccc5c(c4Oc4cccc2c43)c2cccc3c2n5-c2cccc4c2B3c2ccccc2O4)cc(C(C)(C)C)c1] 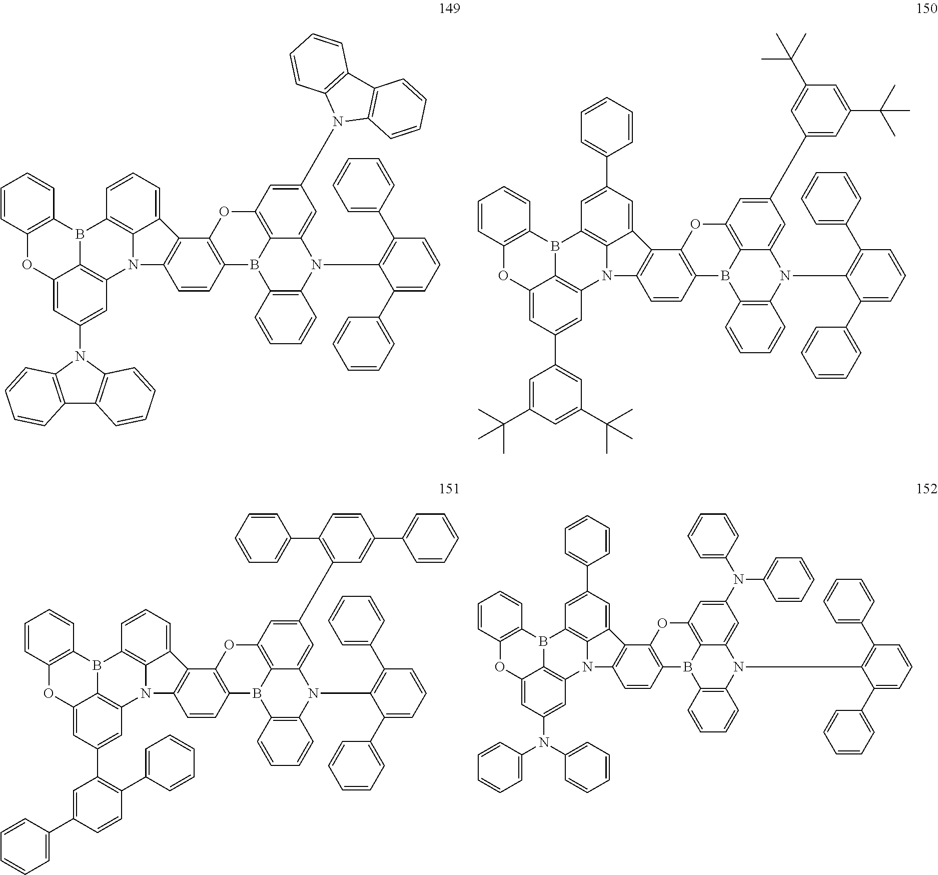 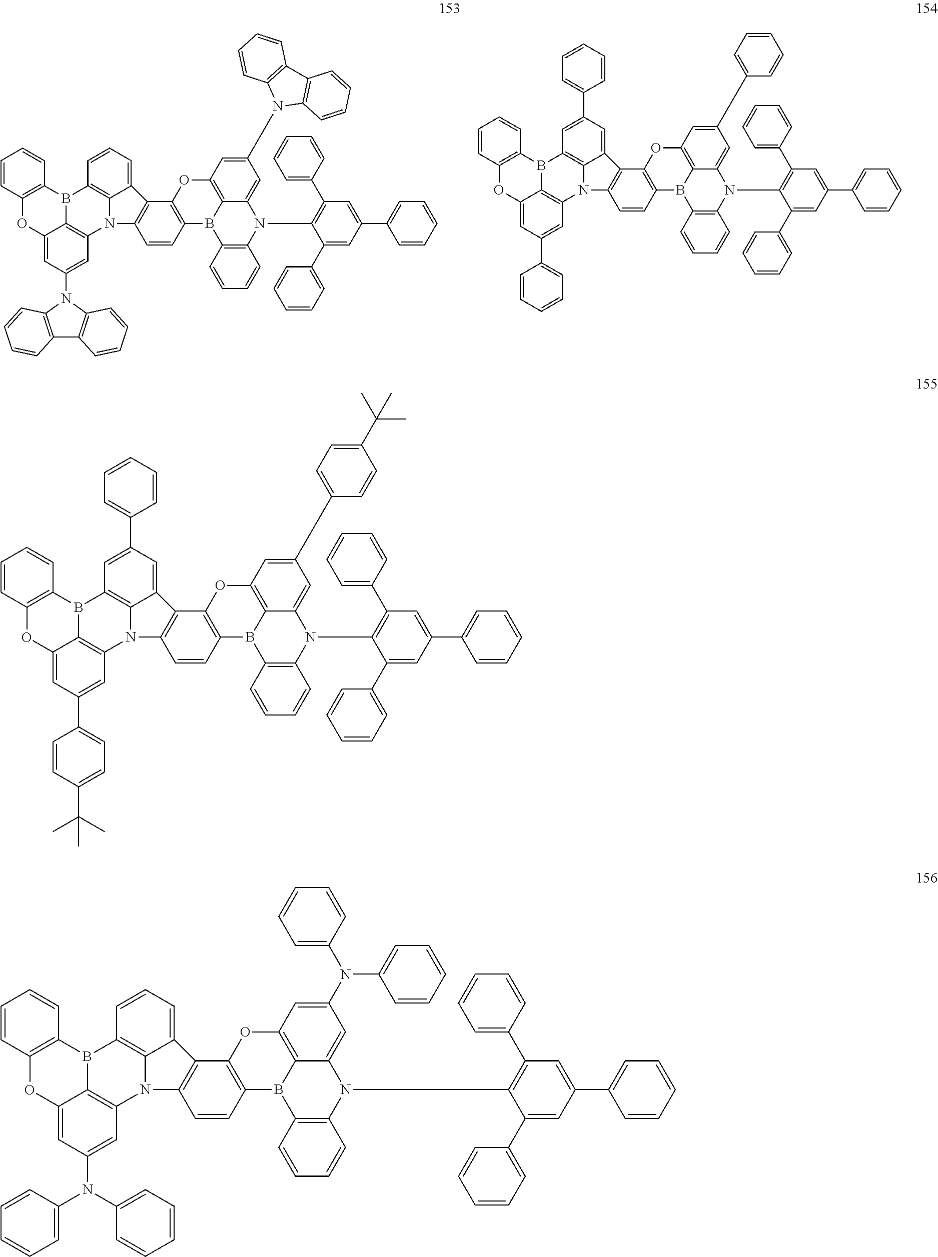 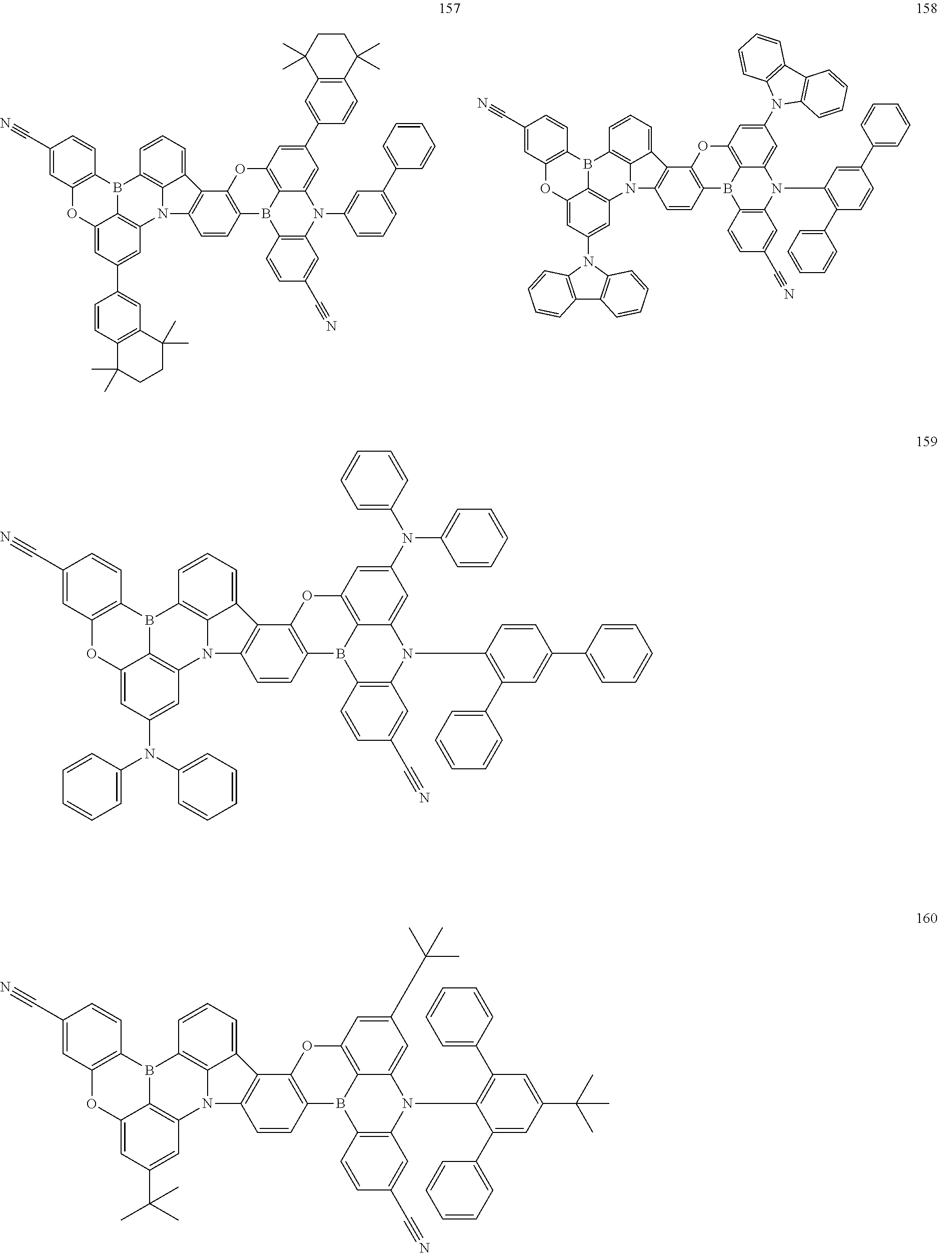 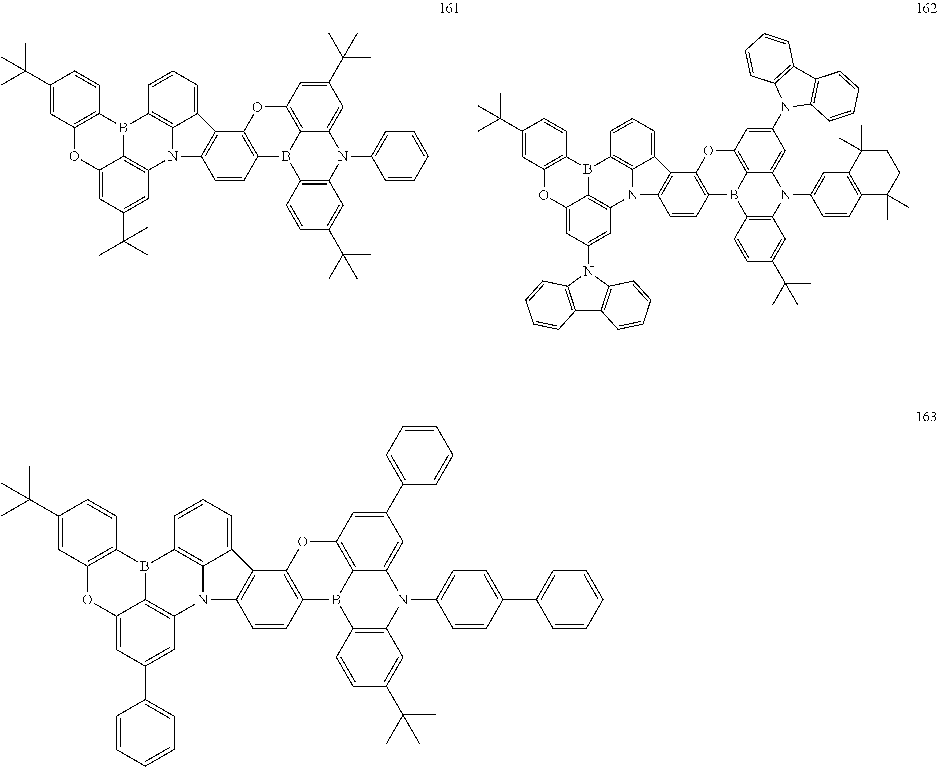 [SMILES: CC(C)(C)c1ccc2c(c1)Oc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)O5 ; CC(C)(C)c1ccc2c(c1)Oc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)O5 ; CC(C)(C)c1ccc2c(c1)Oc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)O5] 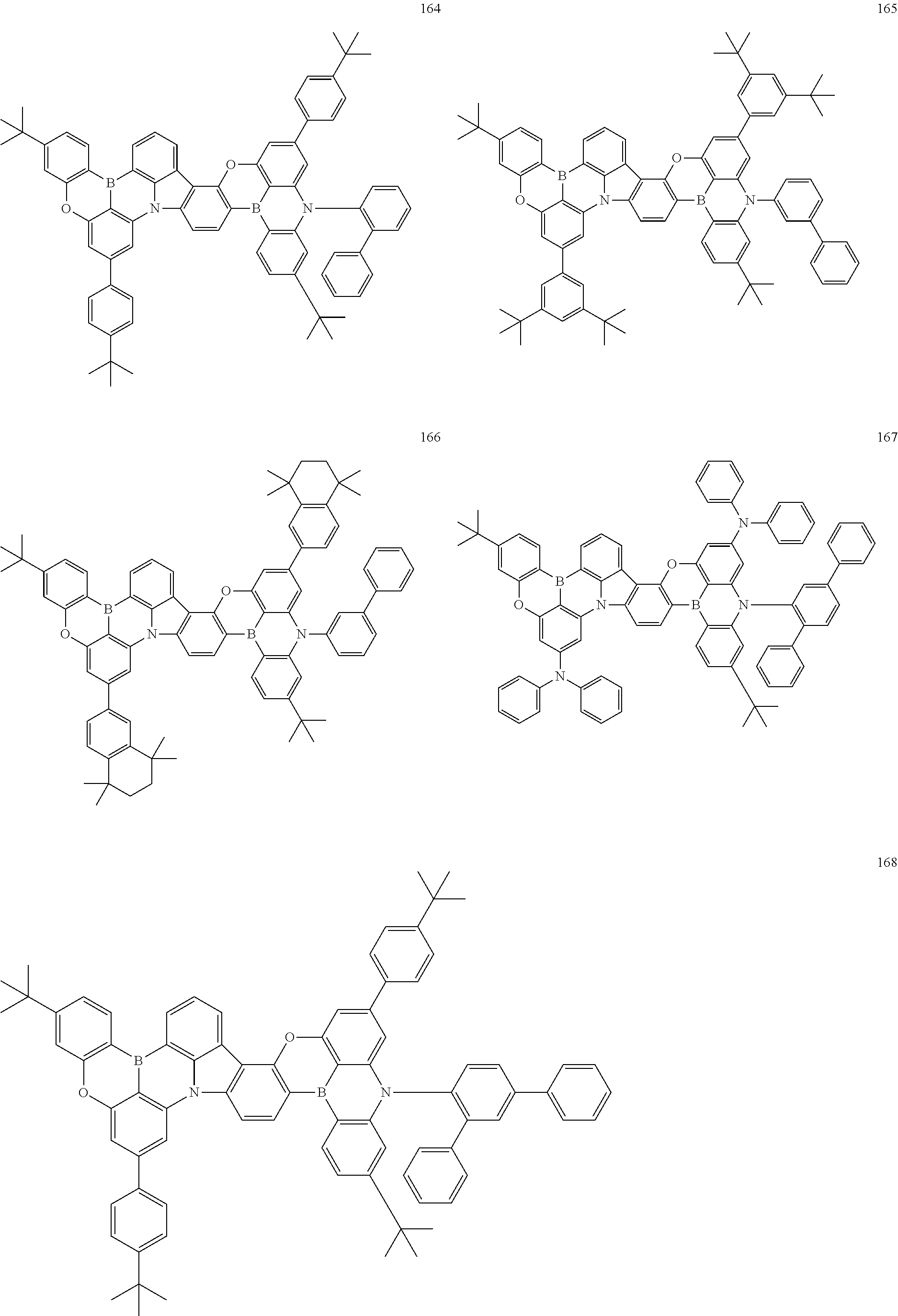 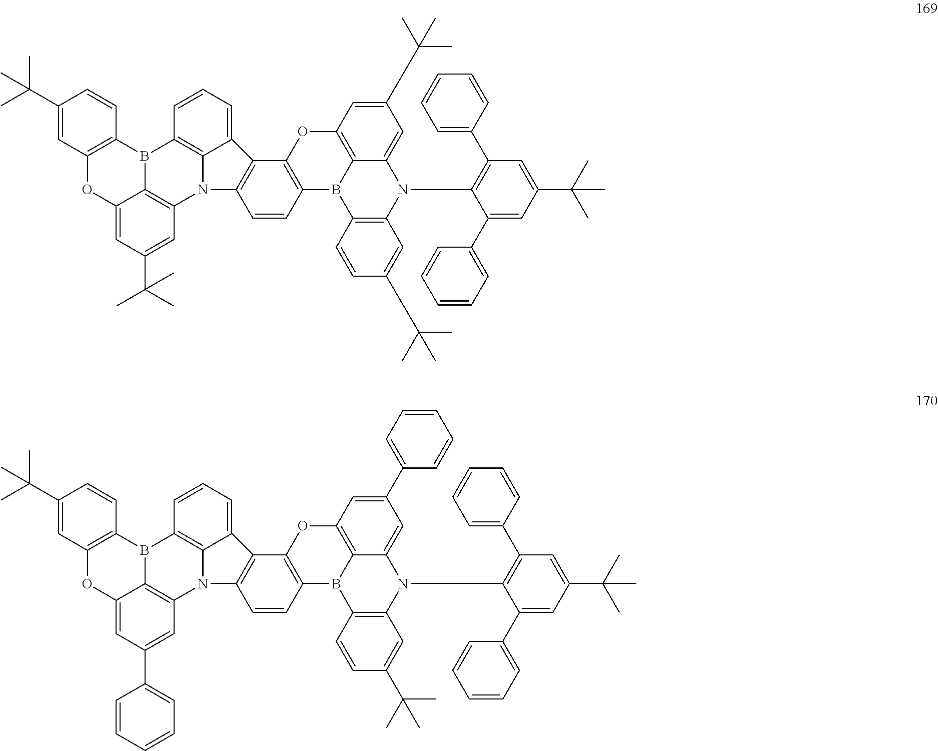 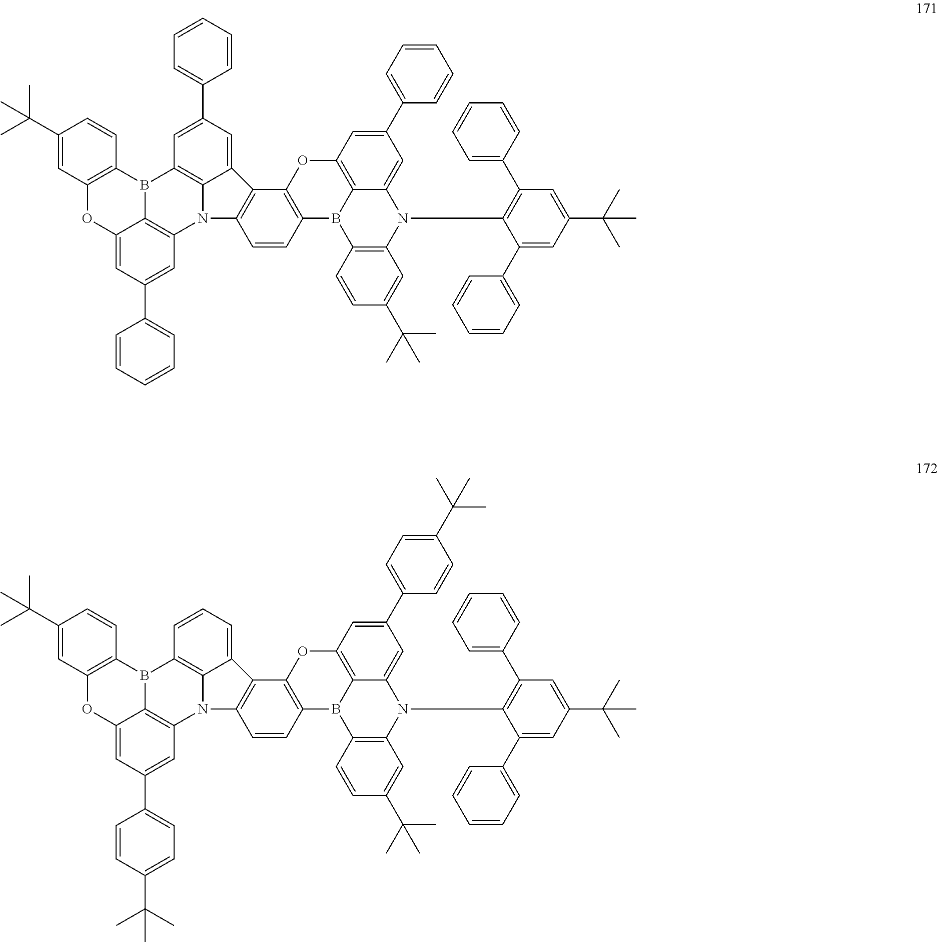 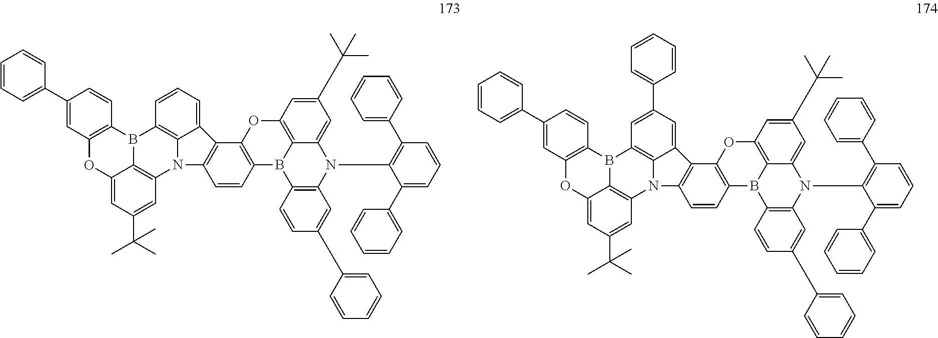 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1O3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1O3] 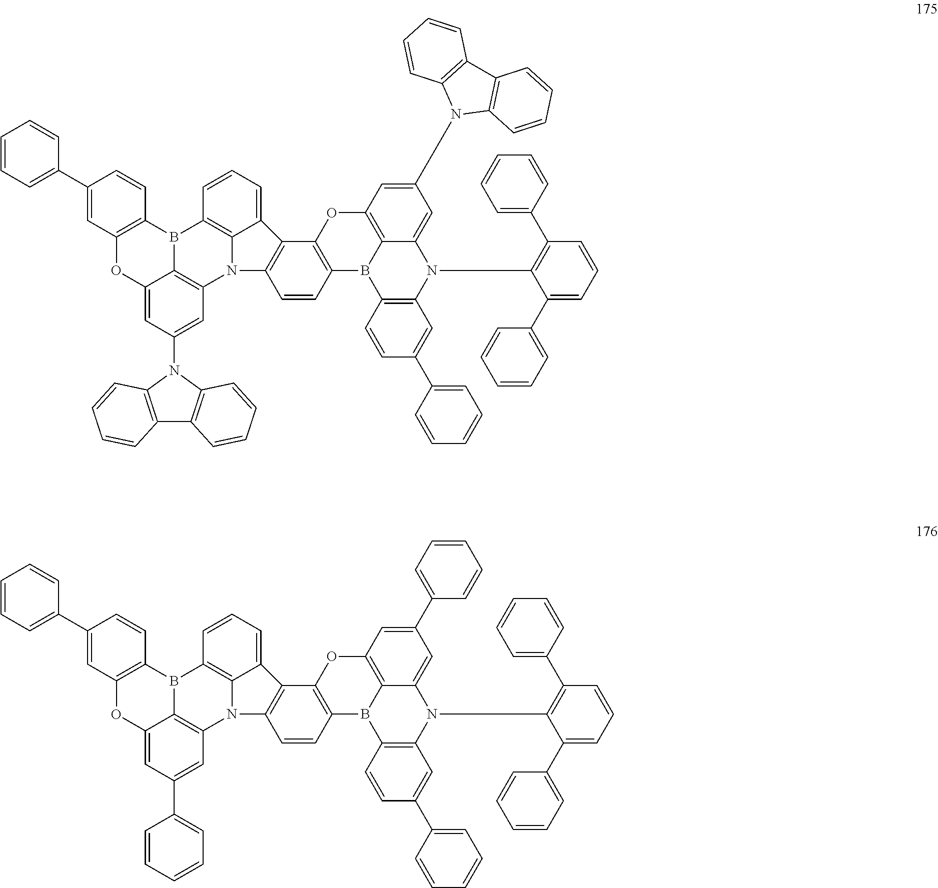 [SMILES: c1ccc(-c2ccc3c(c2)Oc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)O6)cc1 ; c1ccc(-c2ccc3c(c2)Oc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1] 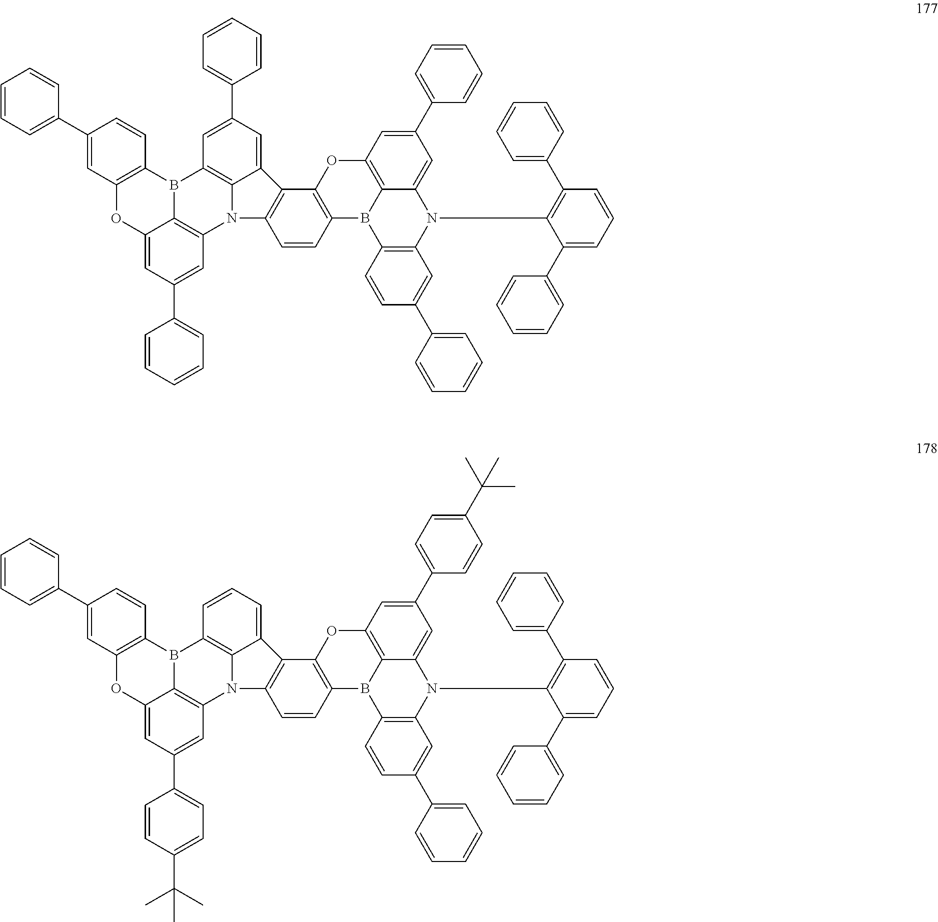 [SMILES: c1ccc(-c2ccc3c(c2)Oc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2O4)cc1] 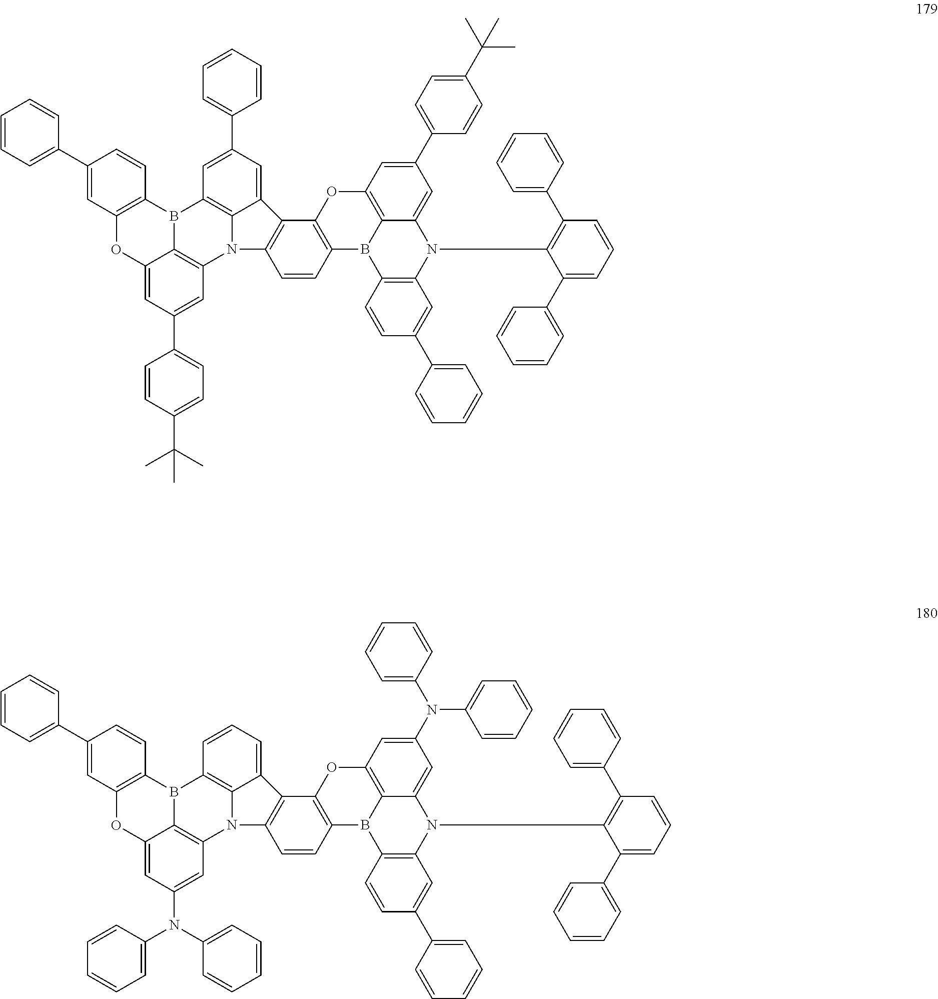 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2O4)cc1 ; c1ccc(-c2ccc3c(c2)Oc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 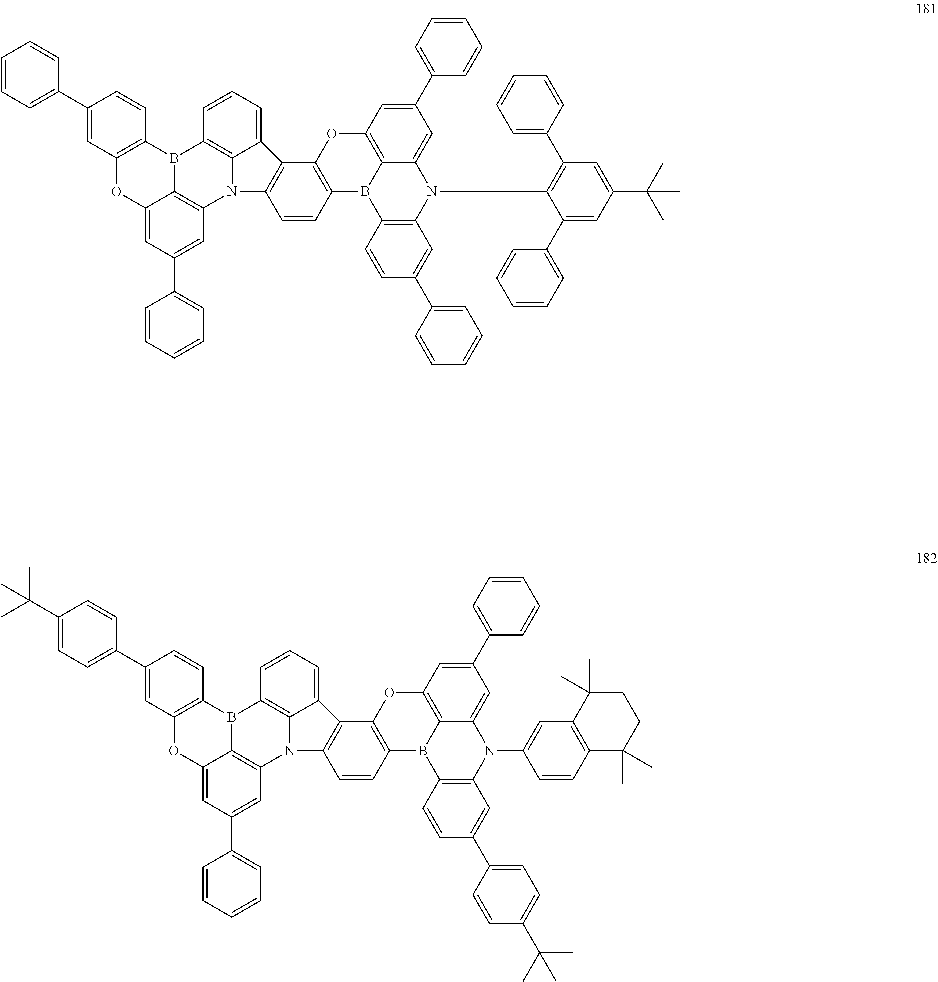 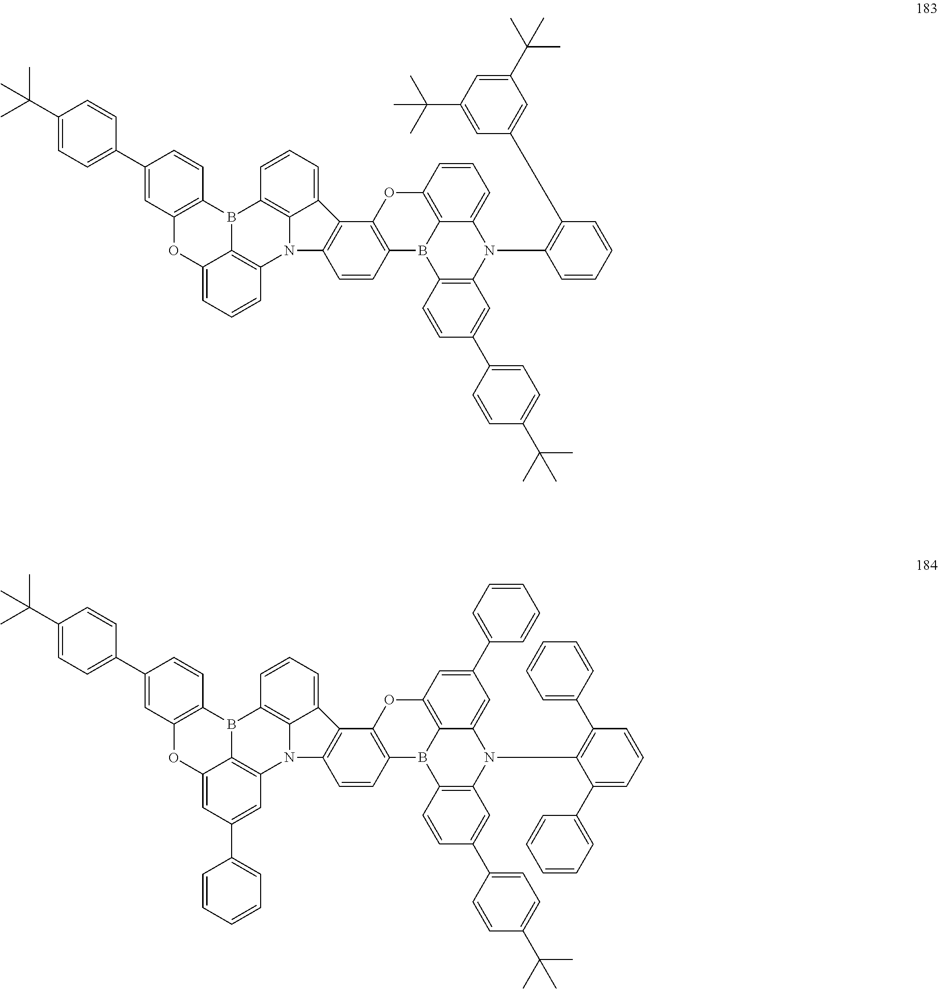 [SMILES: CC(C)(C)c1ccc(-c2ccc3c(c2)Oc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)O6)cc1 ; CC(C)(C)c1ccc(-c2ccc3c(c2)Oc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)O6)cc1] 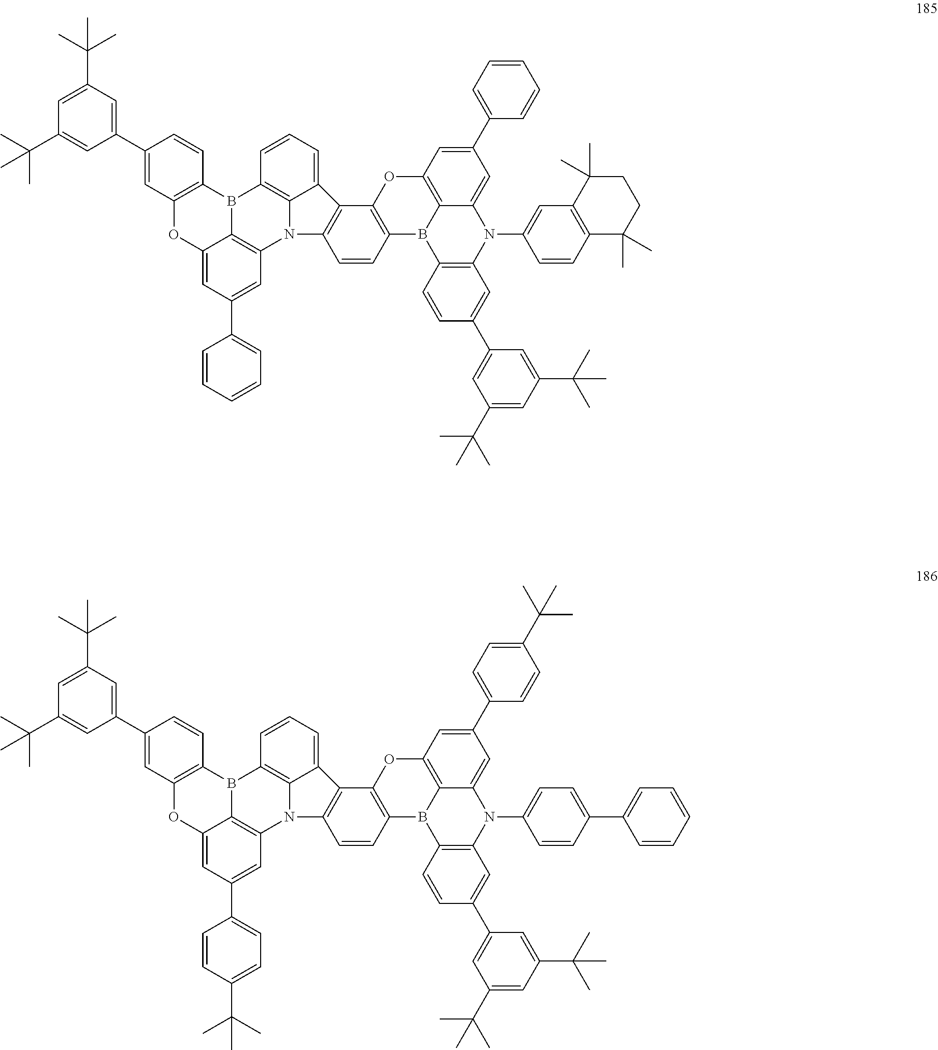 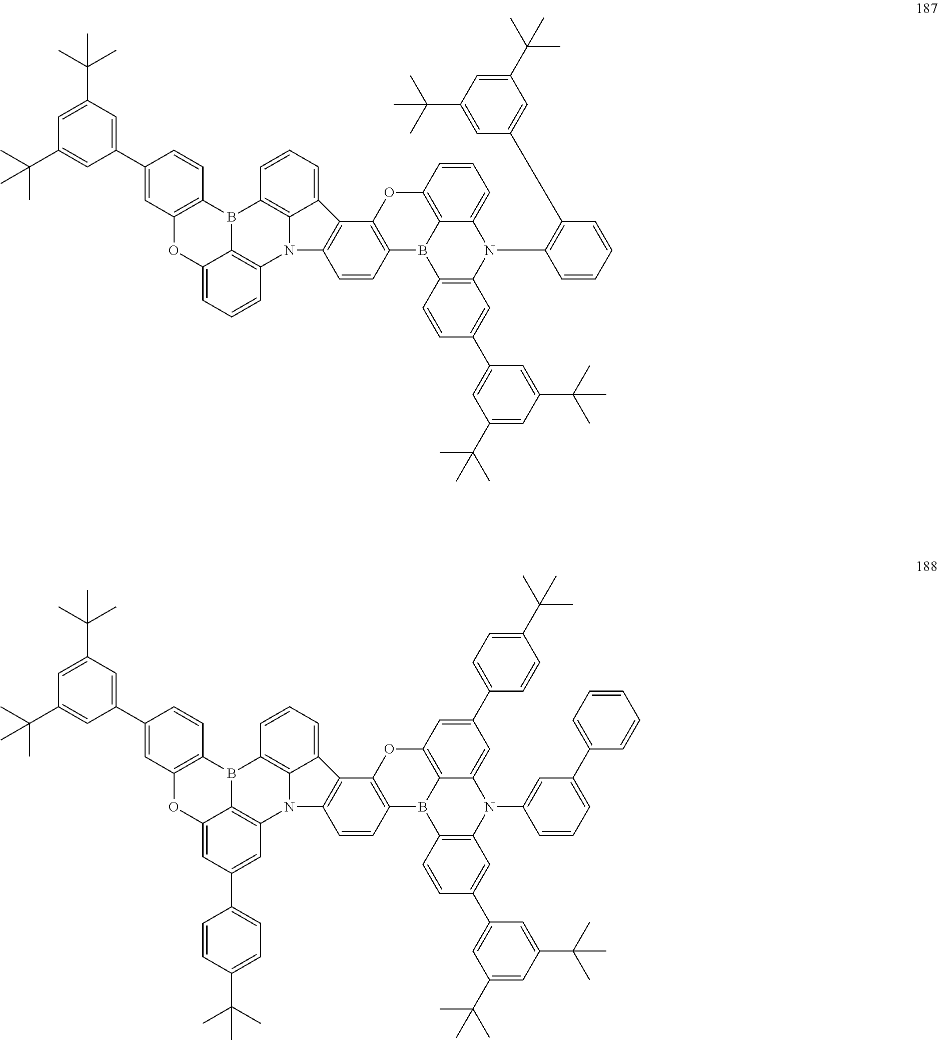 [SMILES: CC(C)(C)c1cc(-c2ccc3c(c2)Oc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)O6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2O4)cc1] 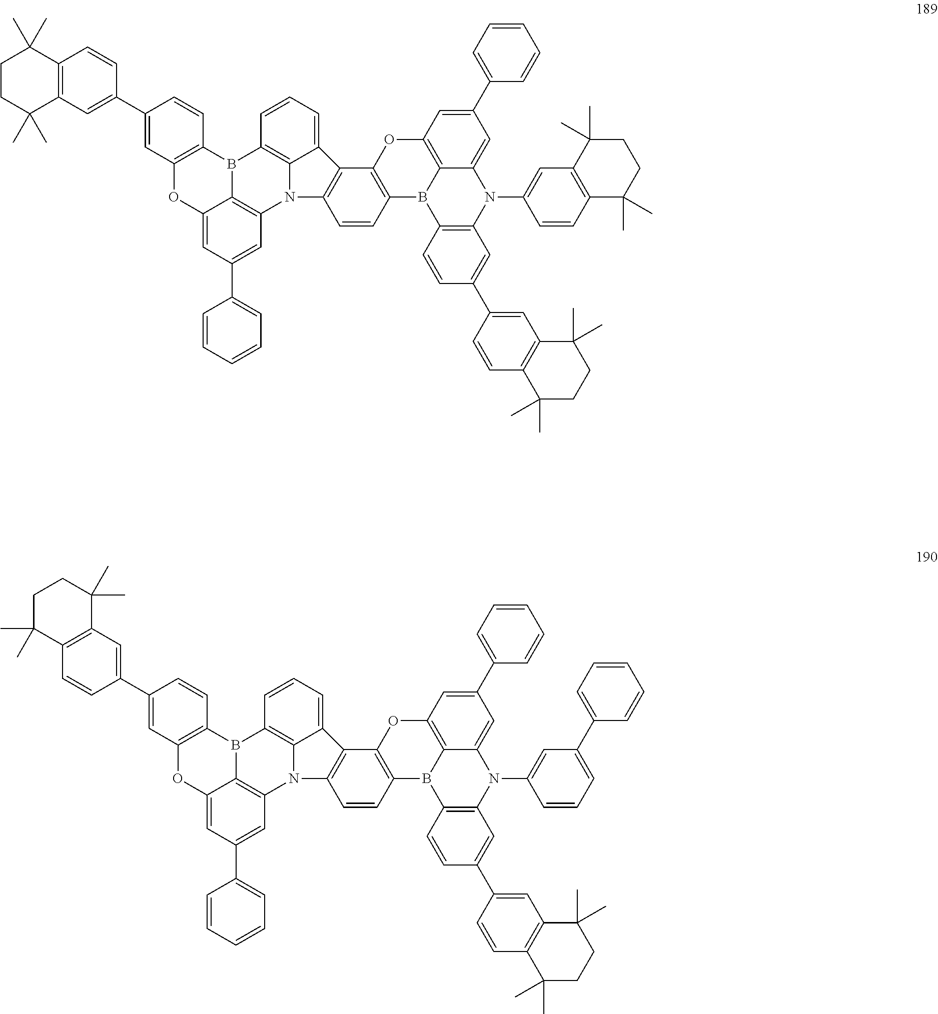 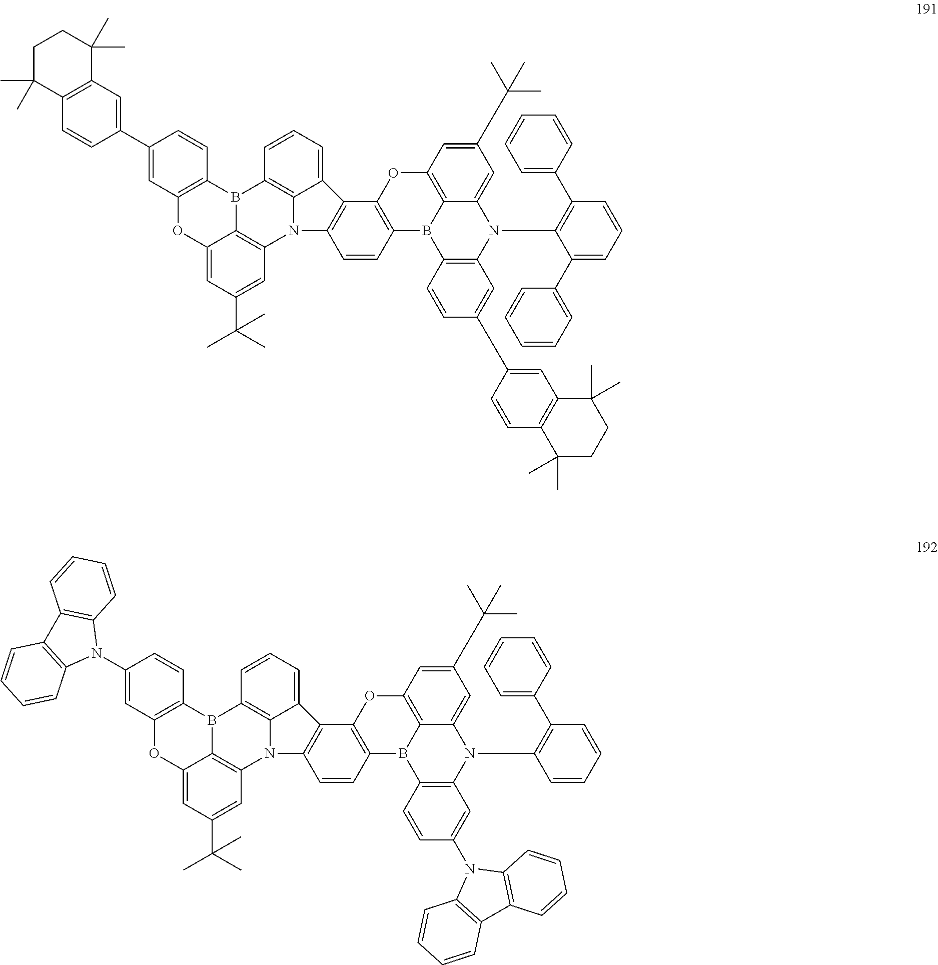 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1O3 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 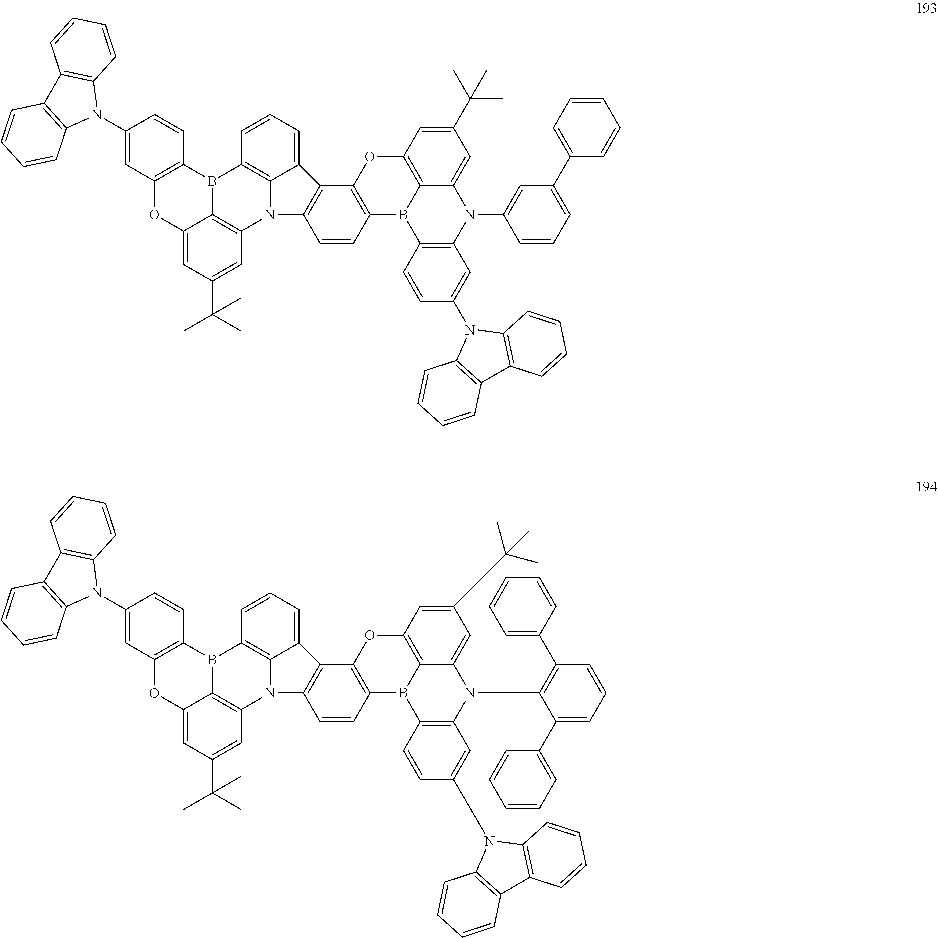 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 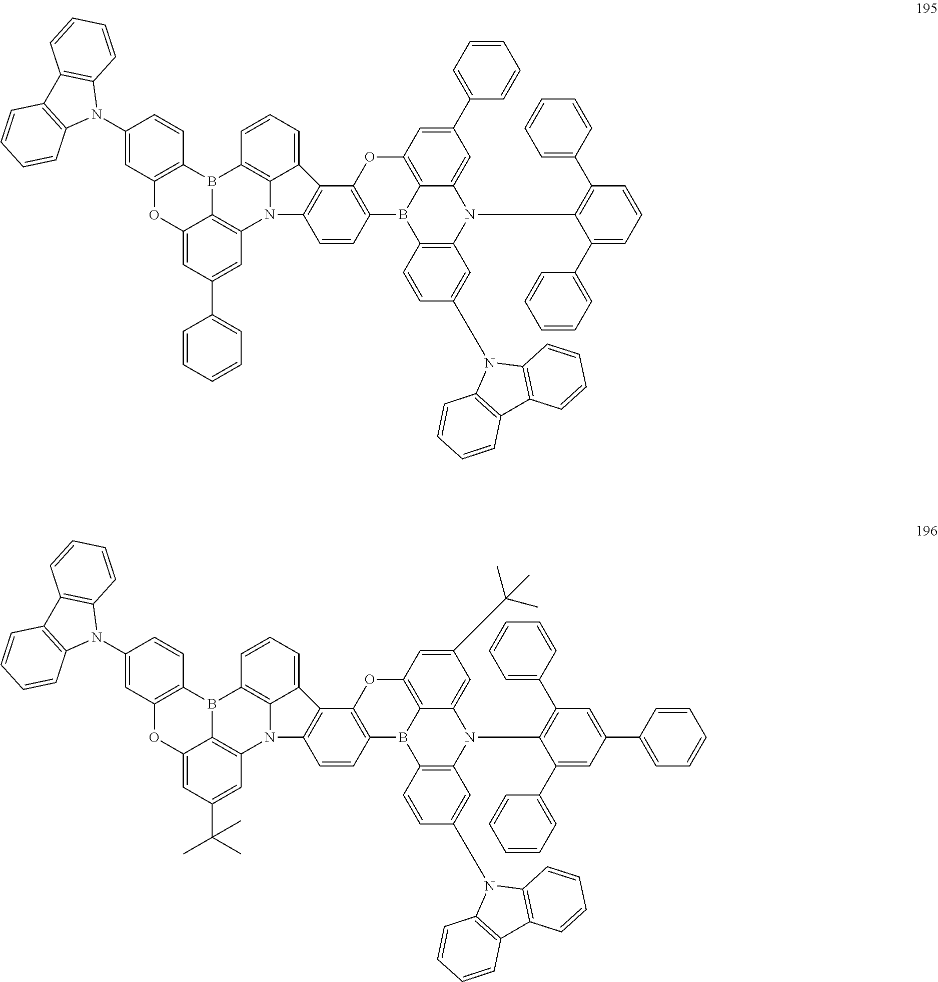 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2O4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1O3] 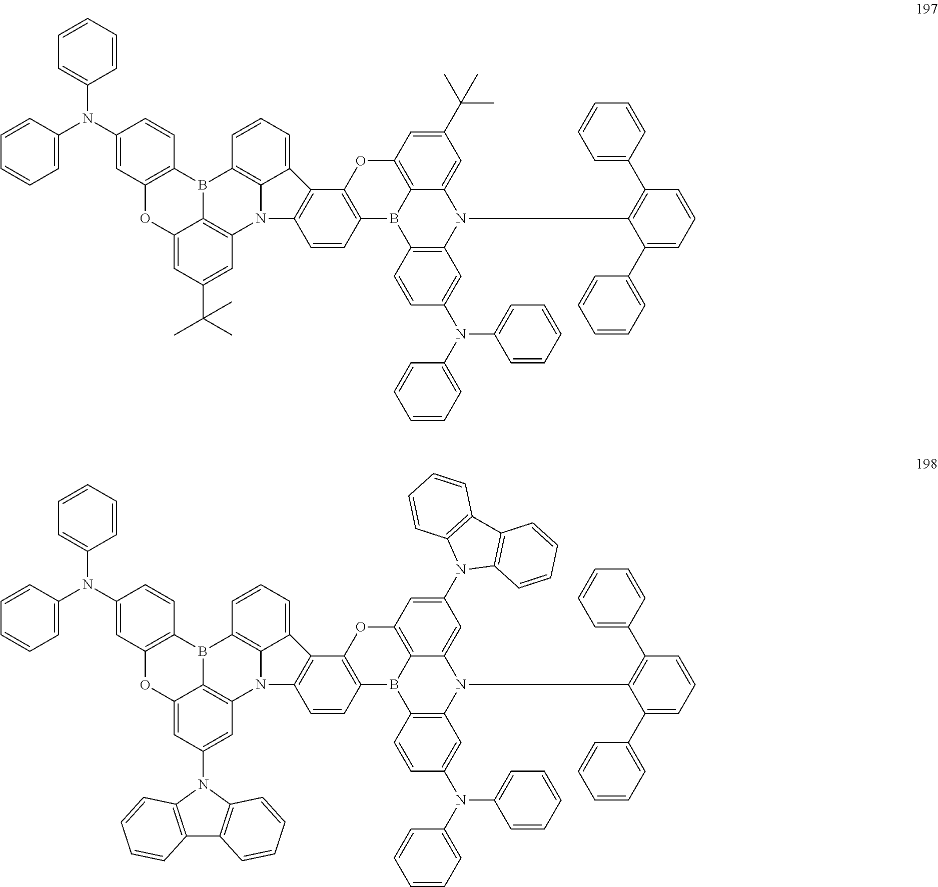 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1O3 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2O4)cc1] 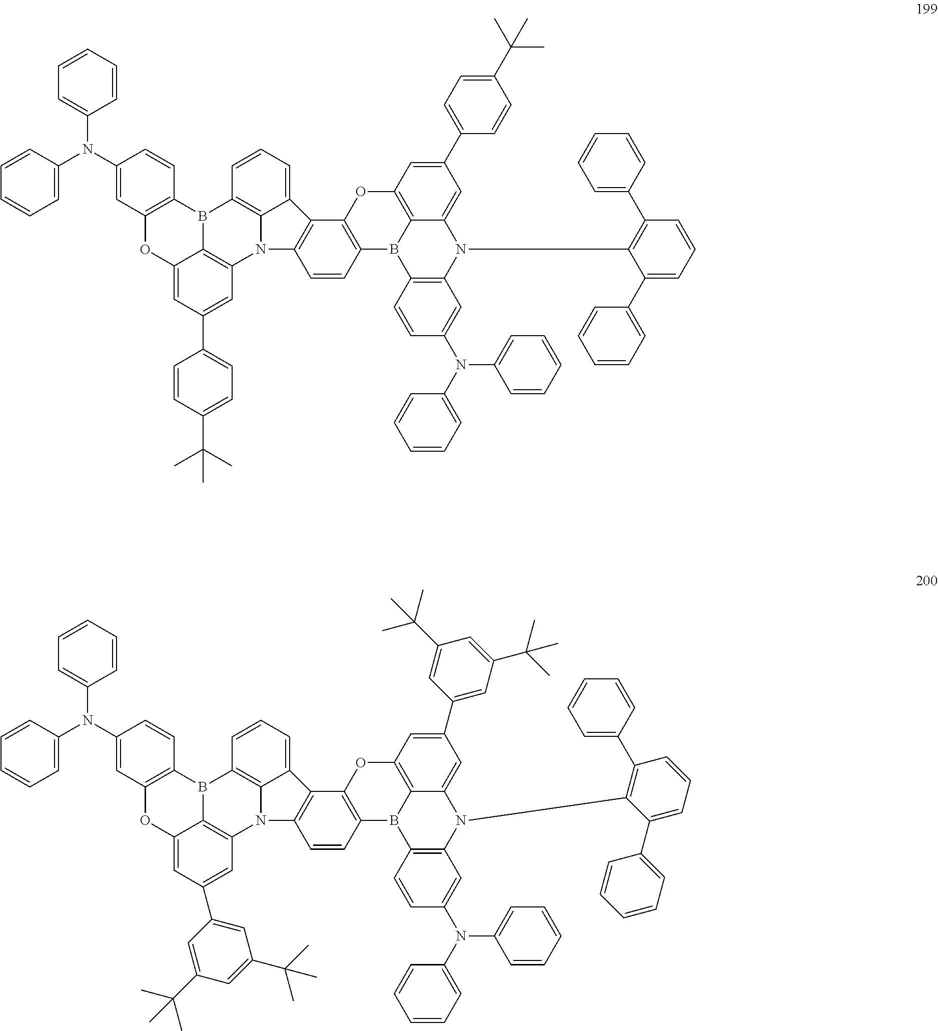 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2O4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2O4)cc(C(C)(C)C)c1] 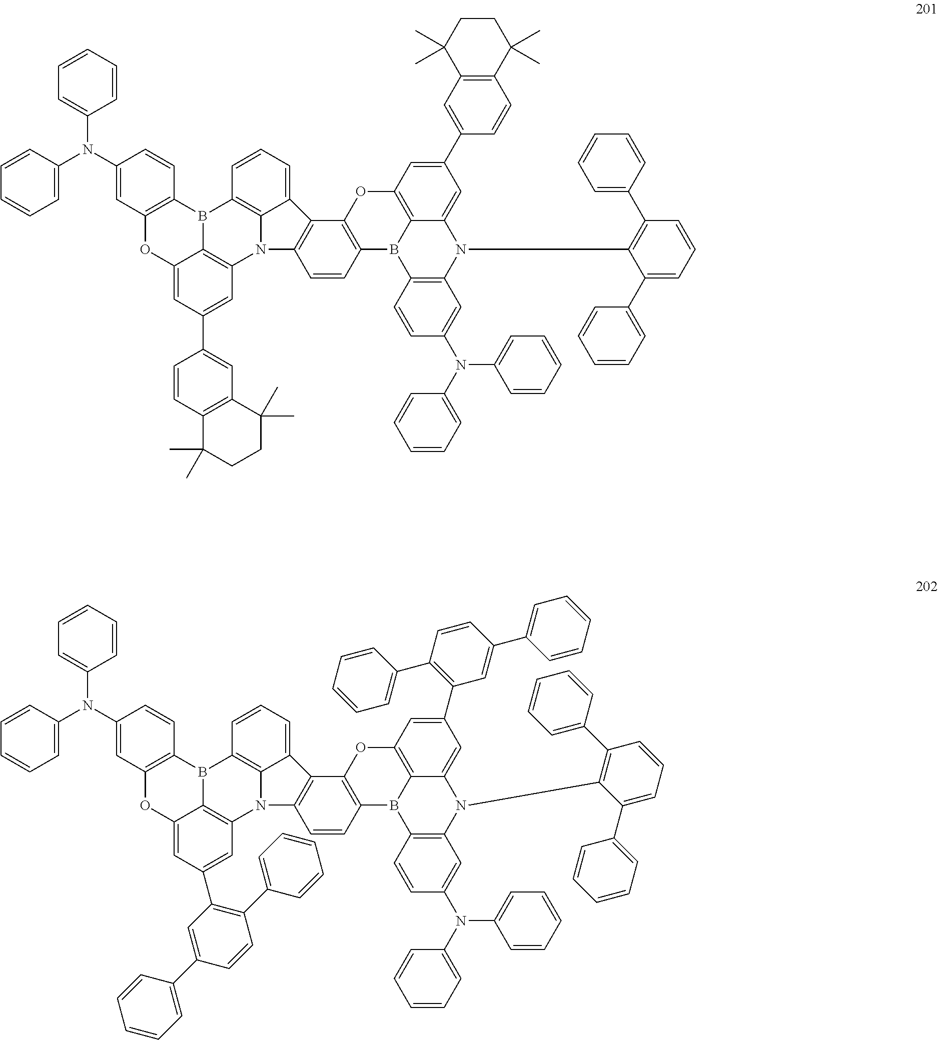 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3O5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3O5)c2)cc1] 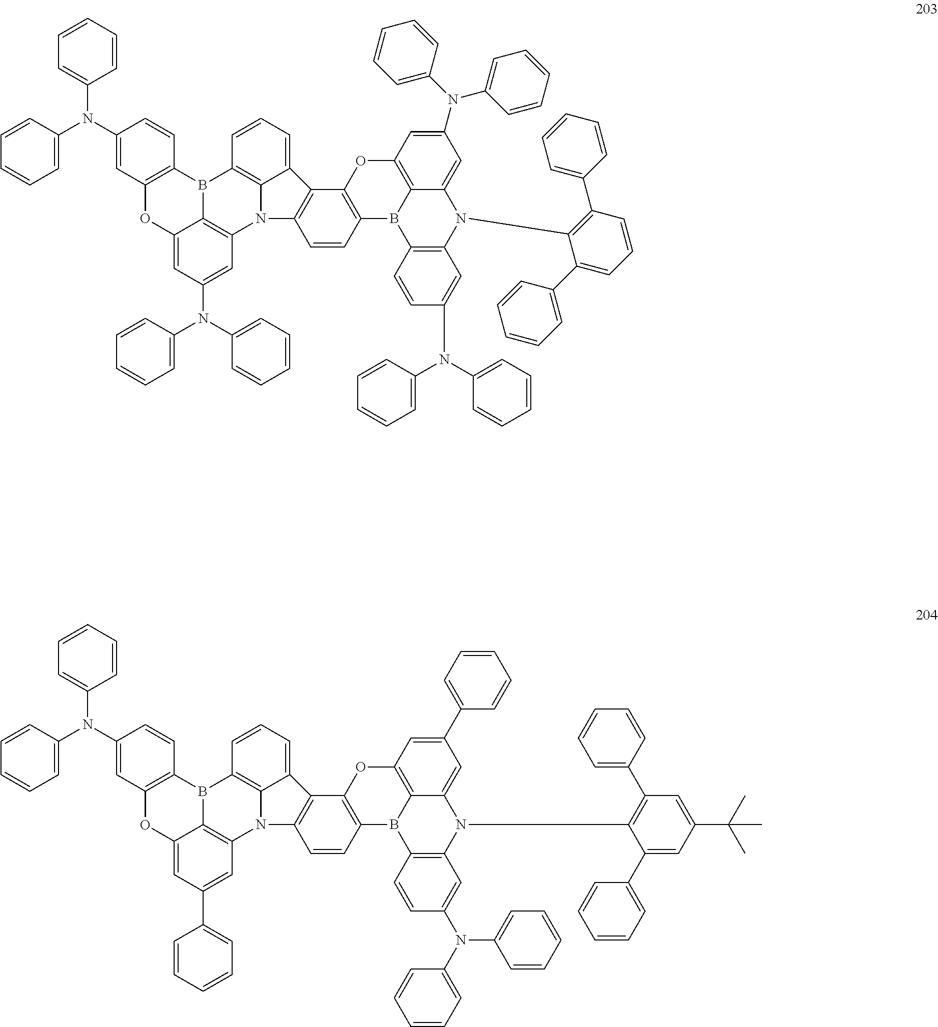 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2O4)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2O4)c(-c2ccccc2)c1] 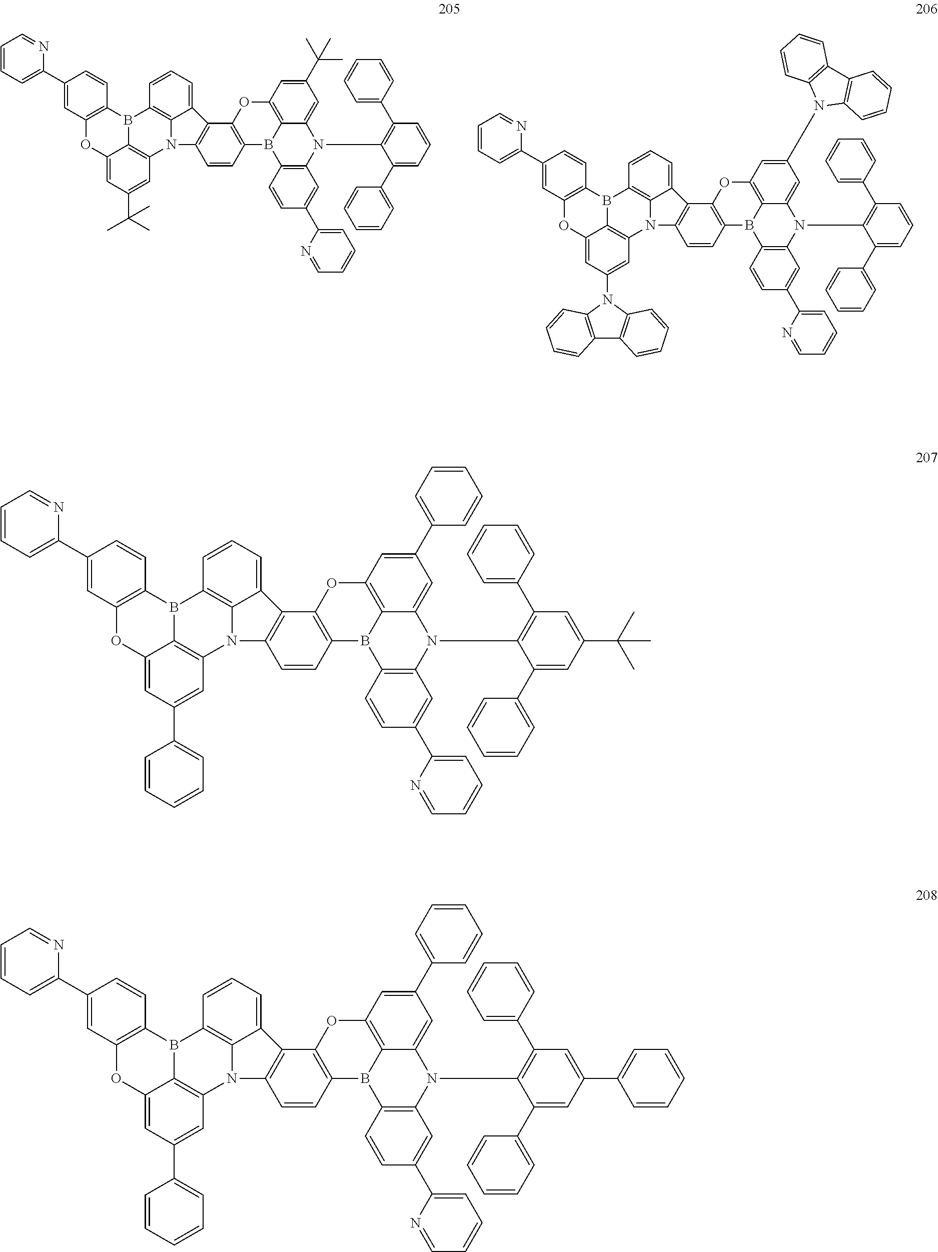 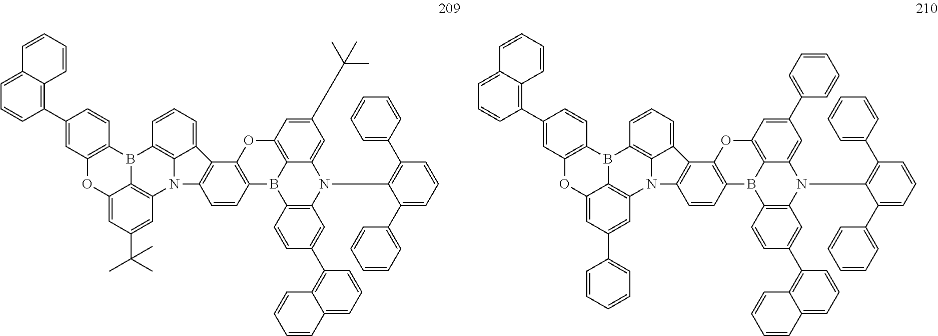 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1O3 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2O4)cc1] 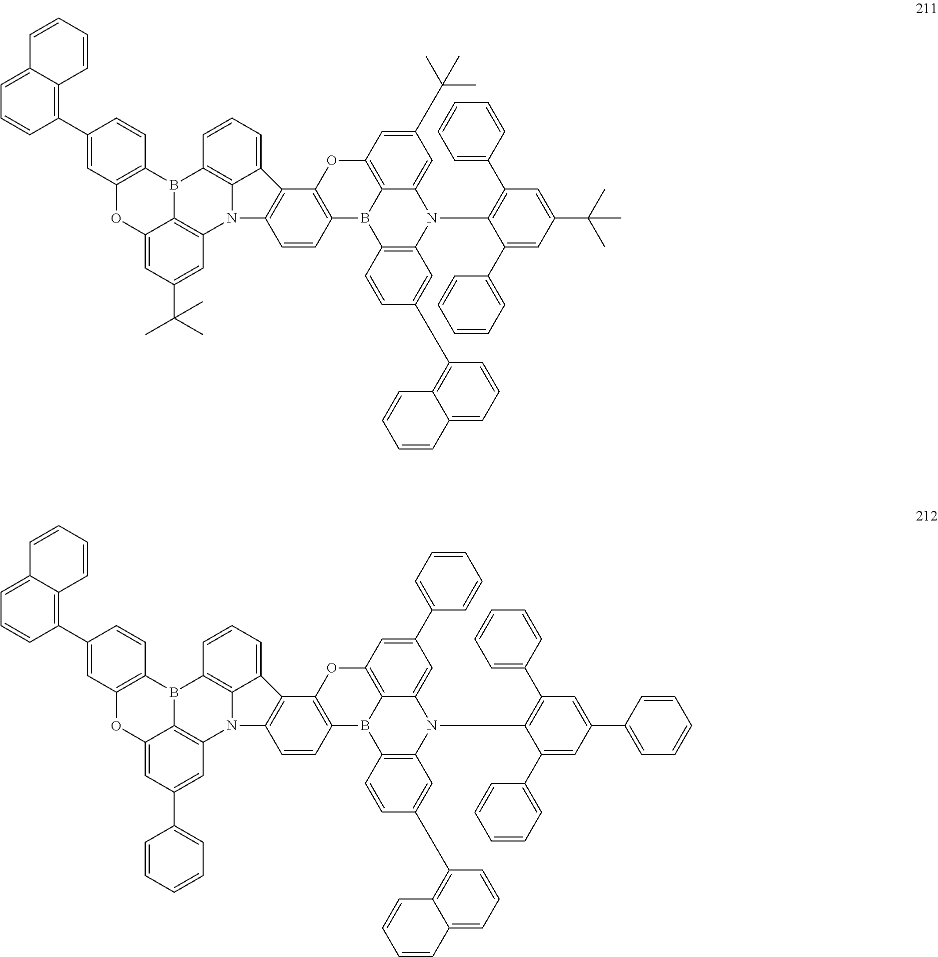 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2O4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3O5)c(-c3ccccc3)c2)cc1] 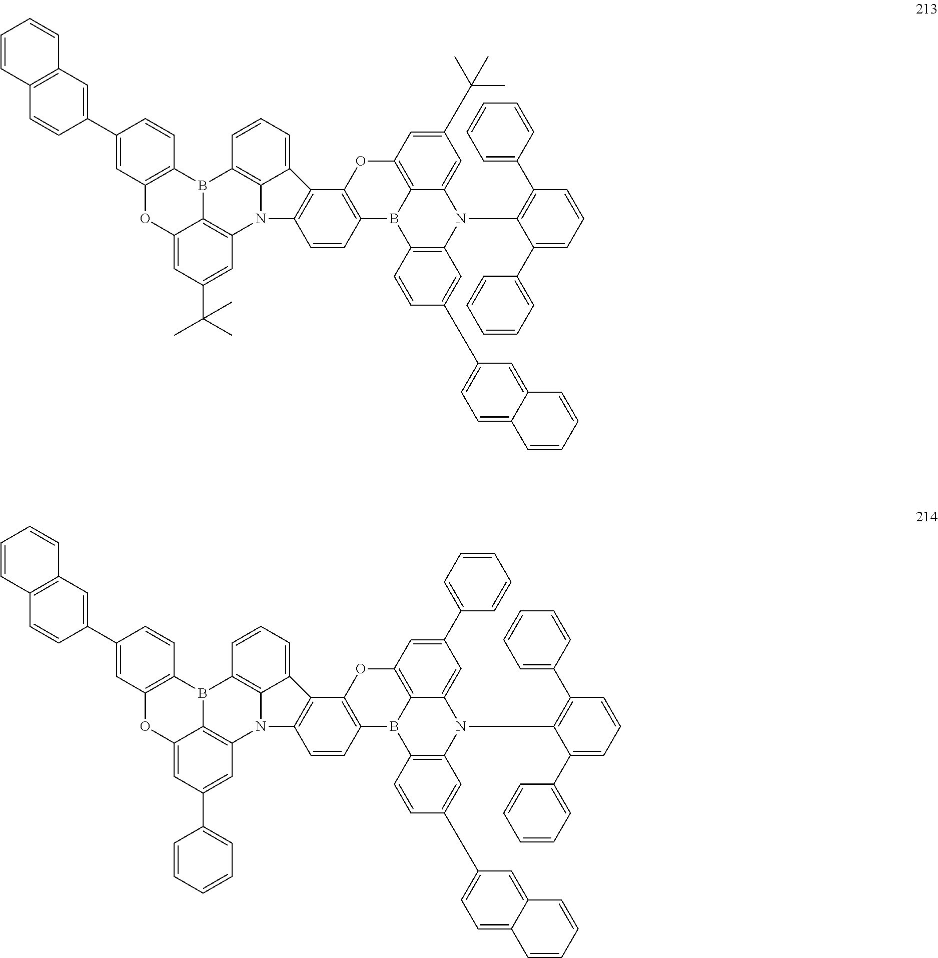 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1O3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2O4)cc1] 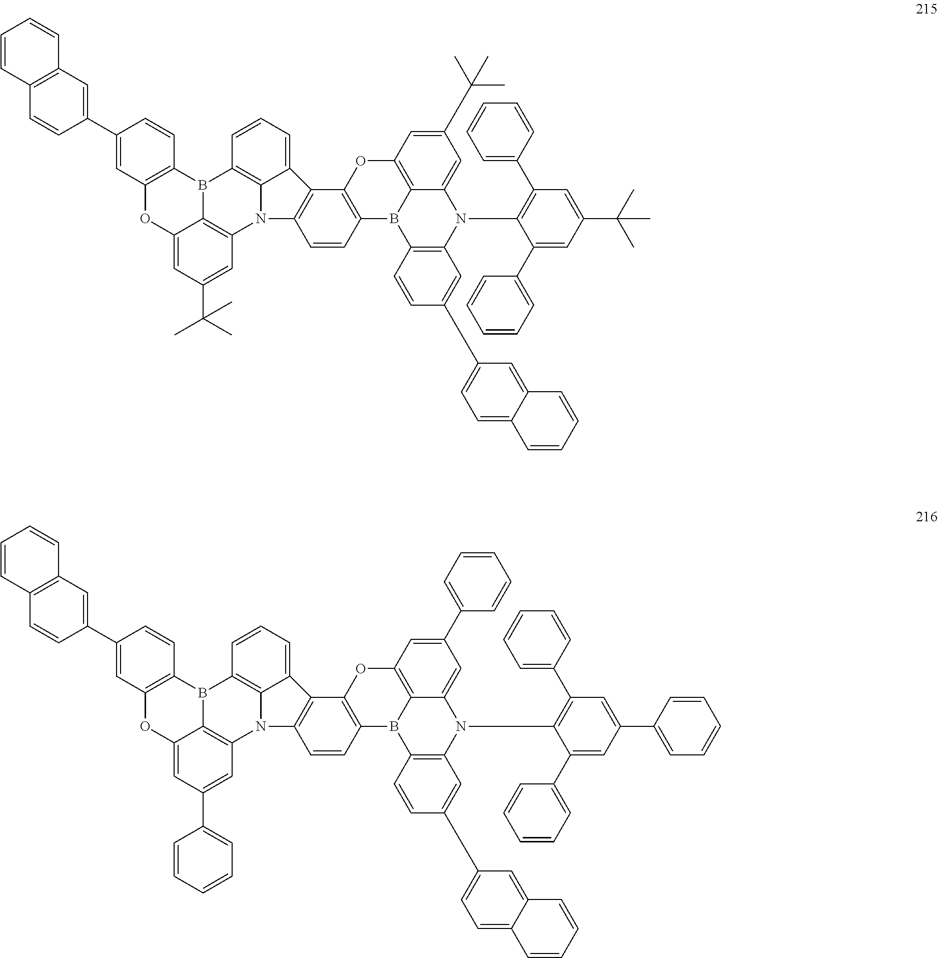 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2O4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3O5)c(-c3ccccc3)c2)cc1] 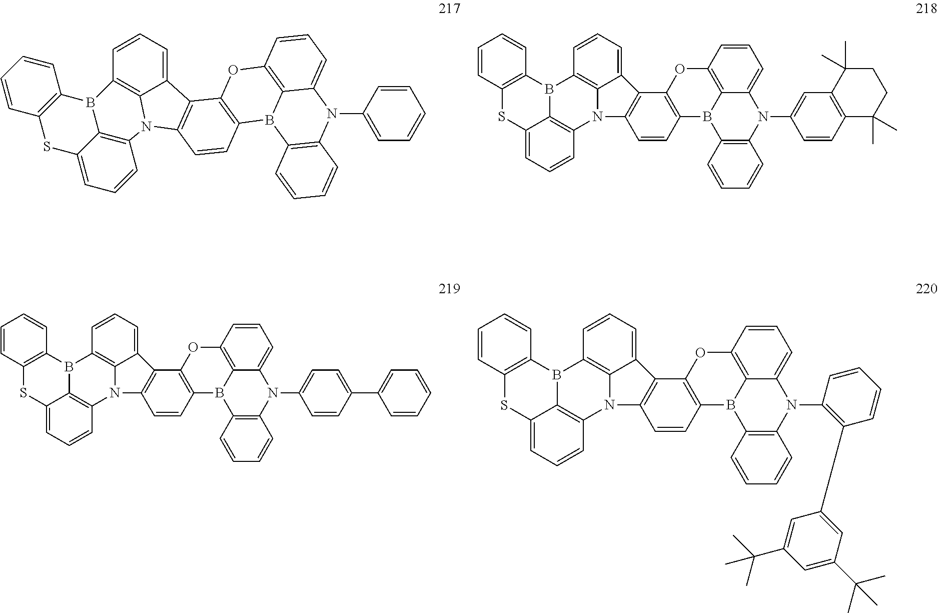 [SMILES: c1ccc(N2c3ccccc3B3c4ccc5c(c4Oc4cccc2c43)c2cccc3c2n5-c2cccc4c2B3c2ccccc2S4)cc1 ; CC1(C)CCC(C)(C)c2cc(N3c4ccccc4B4c5ccc6c(c5Oc5cccc3c54)c3cccc4c3n6-c3cccc5c3B4c3ccccc3S5)ccc21 ; c1ccc(-c2ccc(N3c4ccccc4B4c5ccc6c(c5Oc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Oc4cccc2c43)c2cccc3c2n5-c2cccc4c2B3c2ccccc2S4)cc(C(C)(C)C)c1] 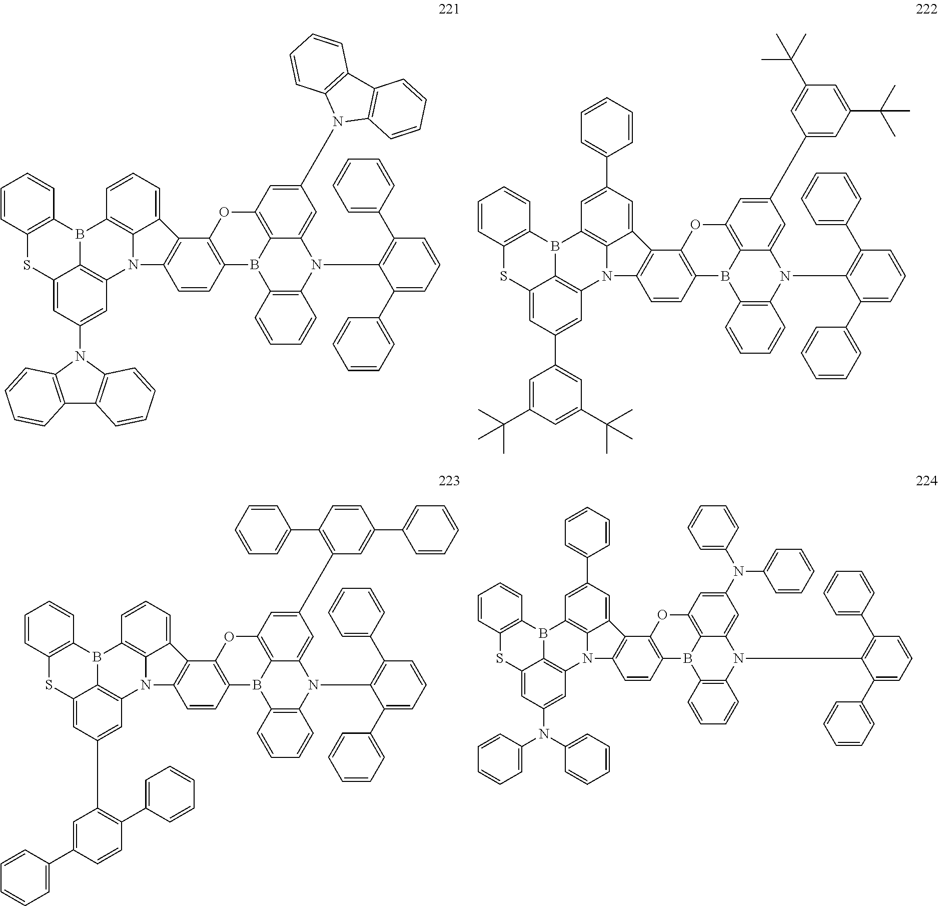 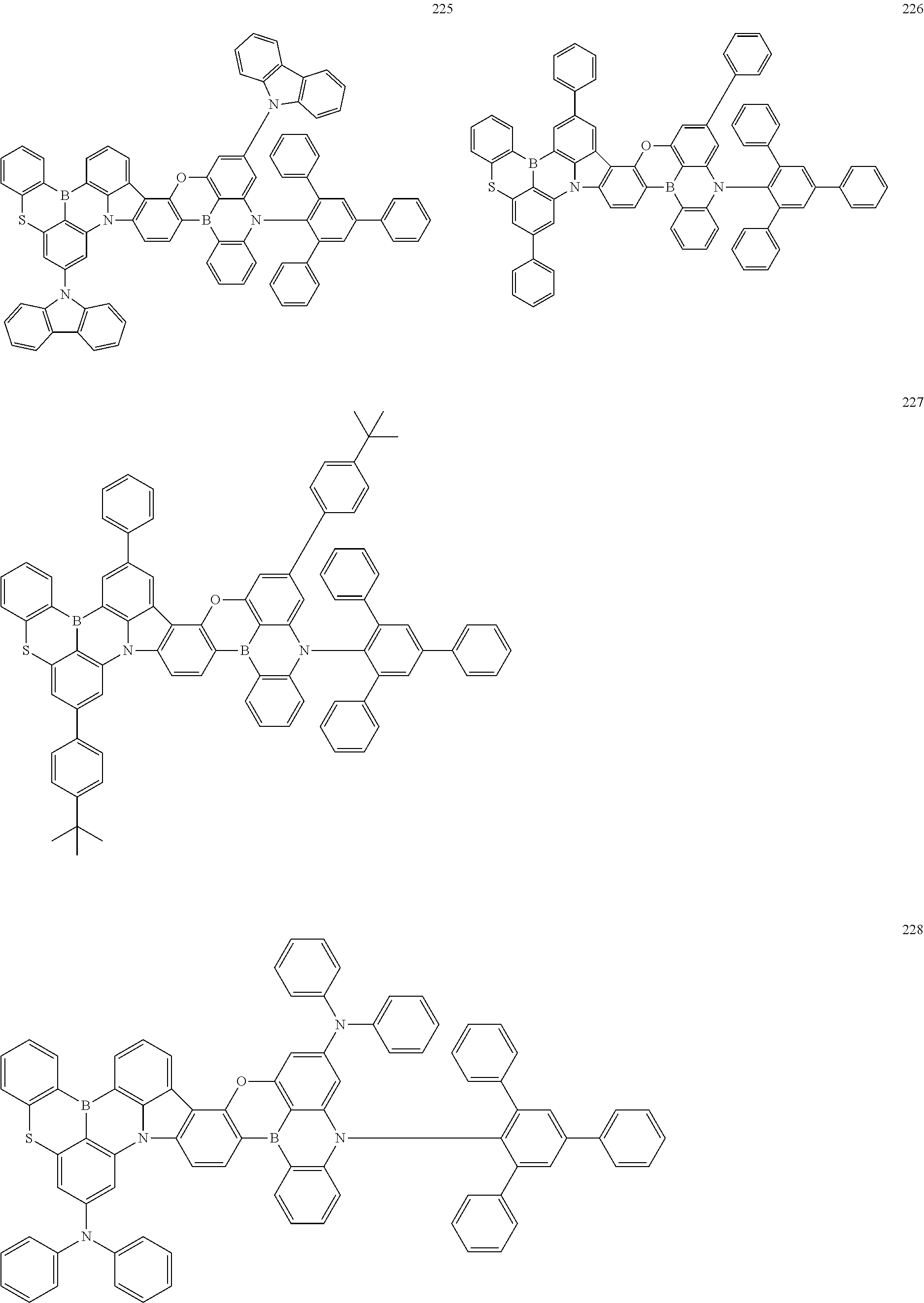 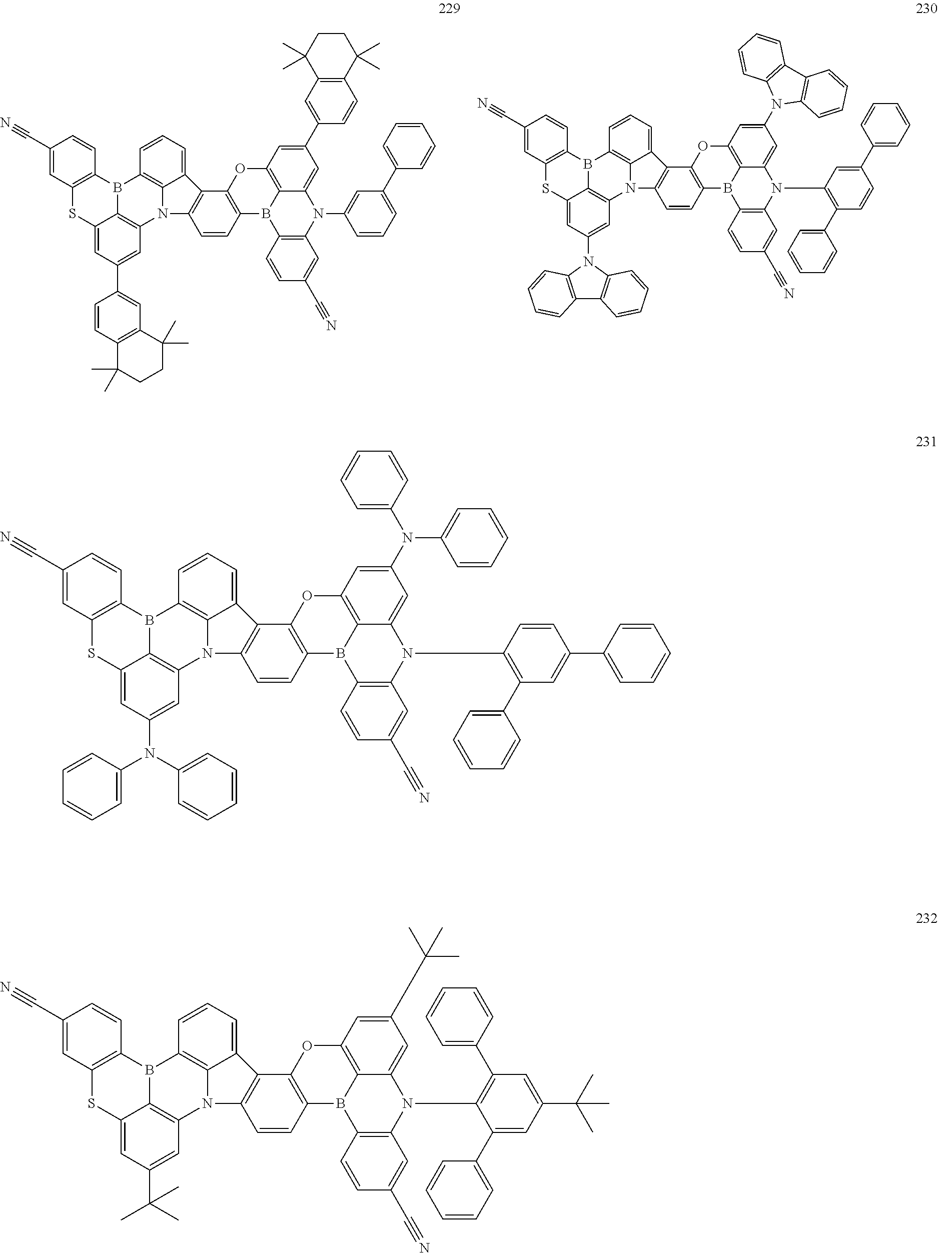 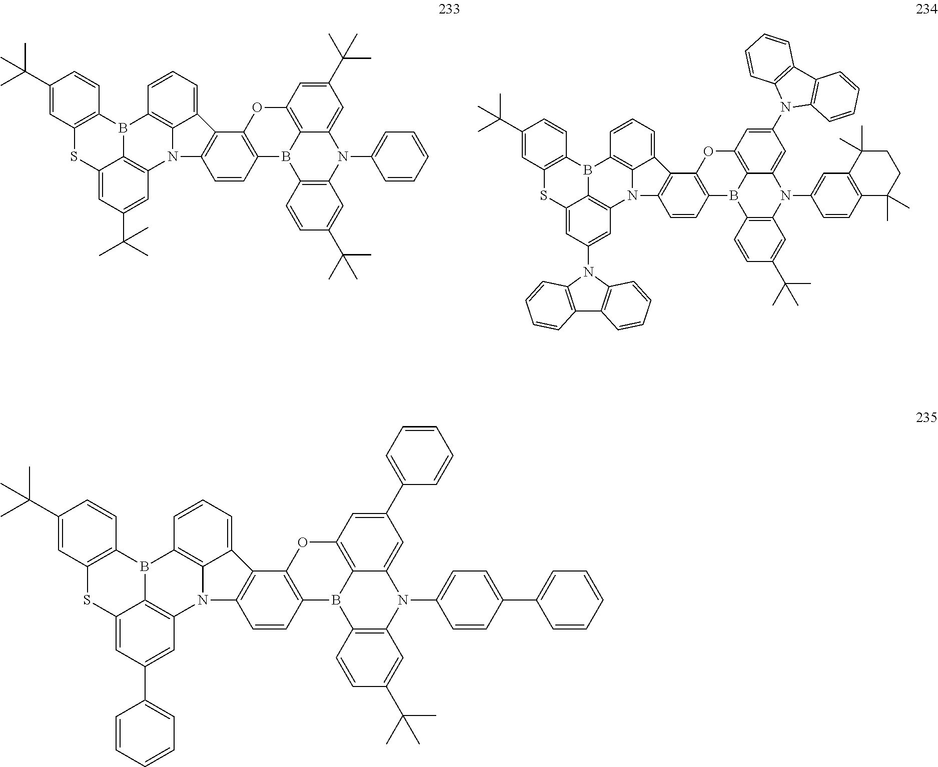 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)O5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)O5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)O5] 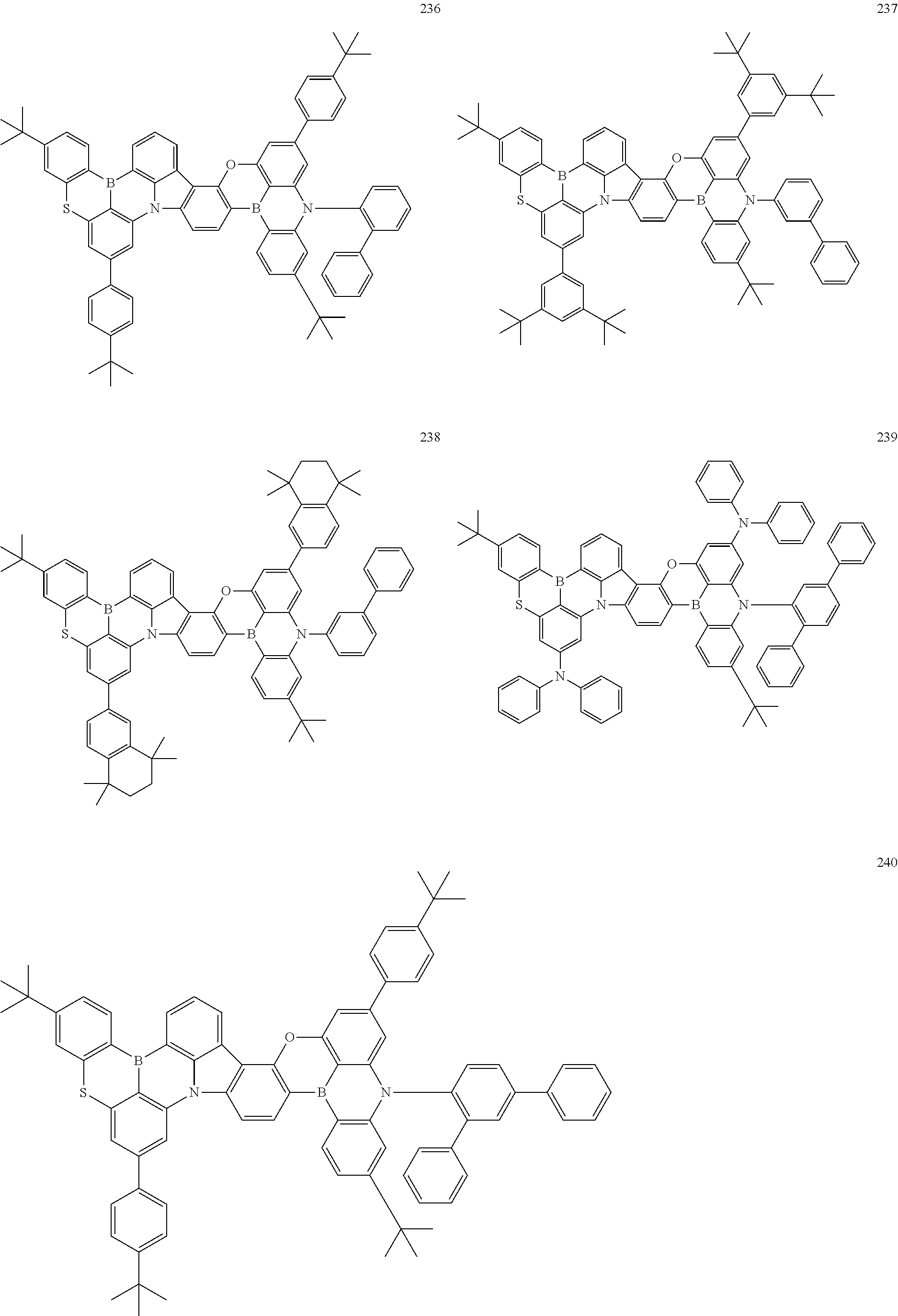 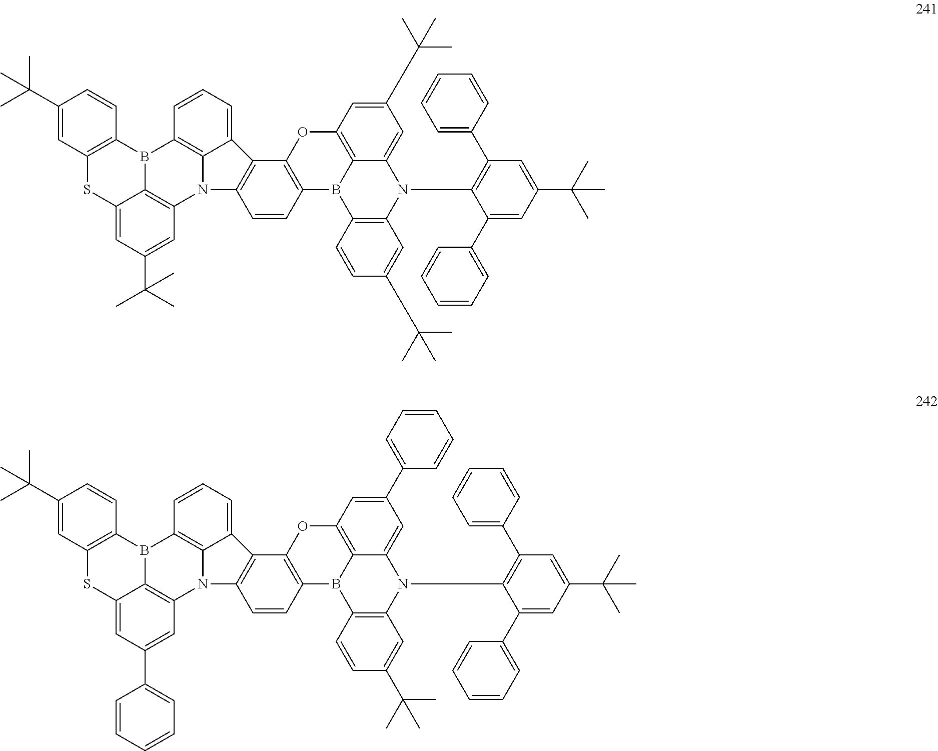 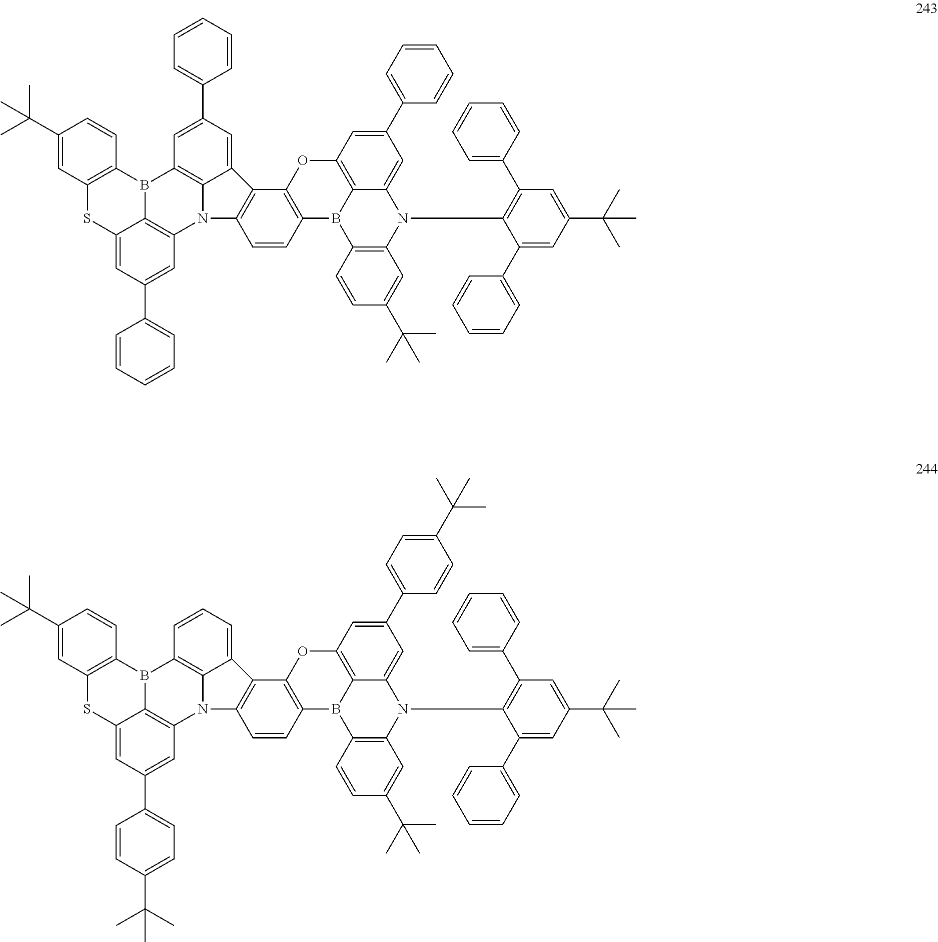 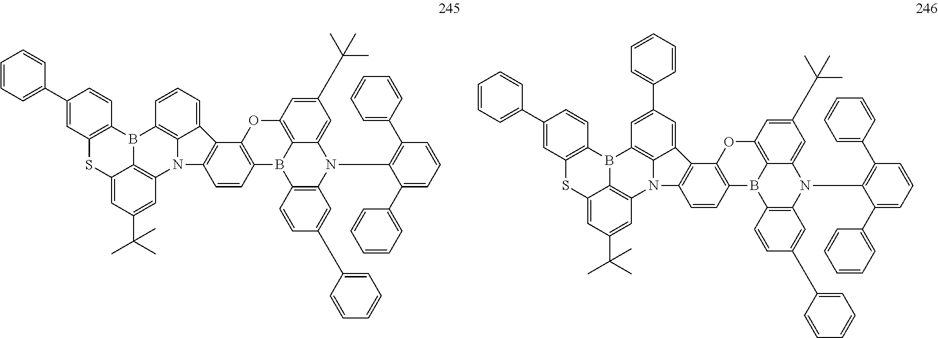 [SMILES: CC(C)(C)c1cc2c3c(c1)N(c1c(-c4ccccc4)cccc1-c1ccccc1)c1cc(-c4ccccc4)ccc1B3c1ccc3c(c1O2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1O2)c1cc(-c2ccccc2)cc2c1n3-c1cc(C(C)(C)C)cc3c1B2c1ccc(-c2ccccc2)cc1S3] 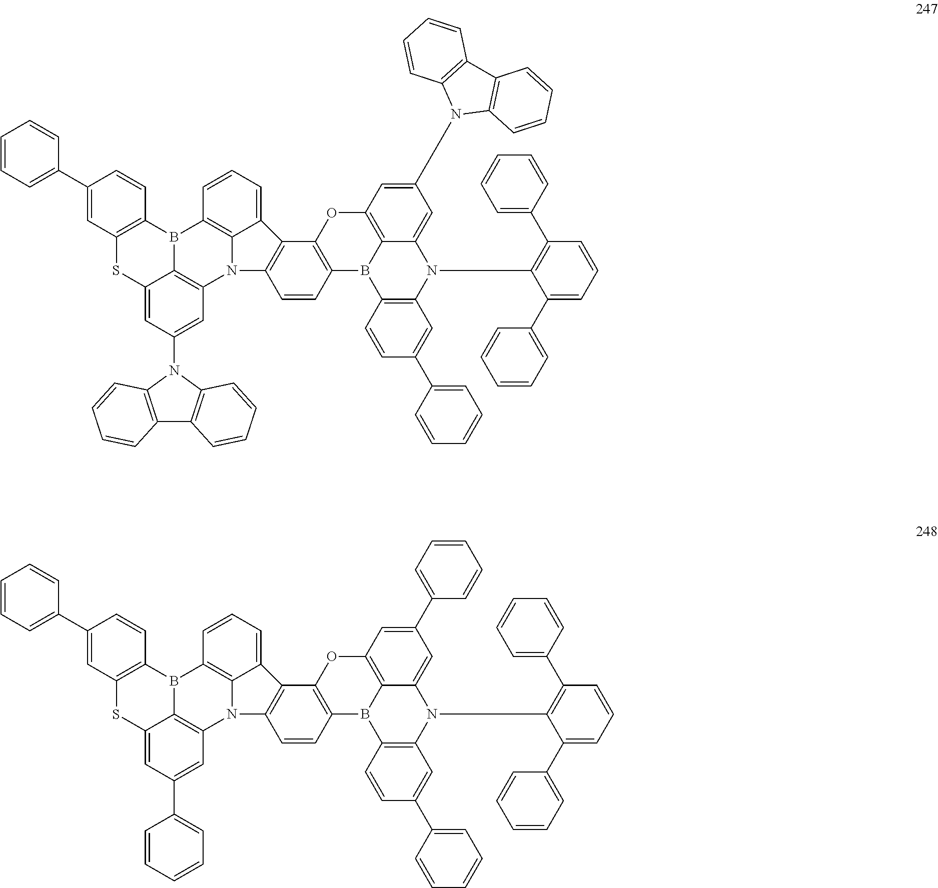 [SMILES: c1ccc(-c2ccc3c(c2)Sc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)O6)cc1 ; c1ccc(-c2ccc3c(c2)Sc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1] 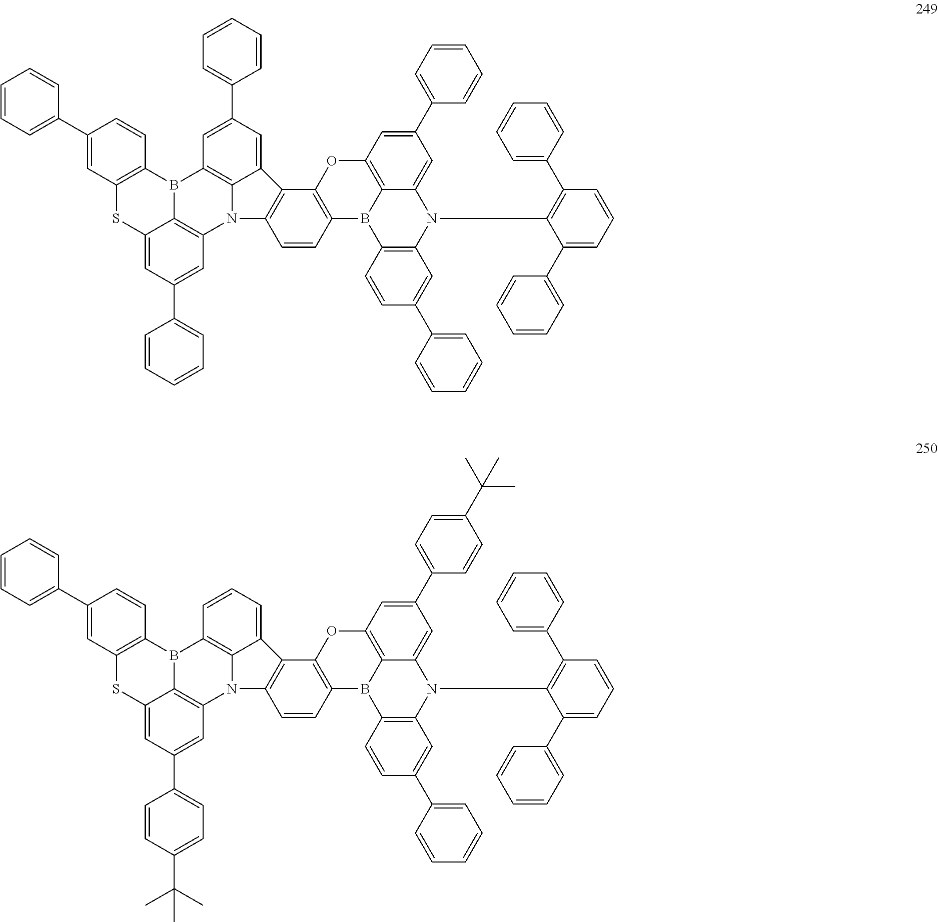 [SMILES: c1ccc(-c2ccc3c(c2)Sc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)O6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2cc(-c4ccc(C(C)(C)C)cc4)cc4c2B3c2ccc(-c3ccccc3)cc2S4)cc1] 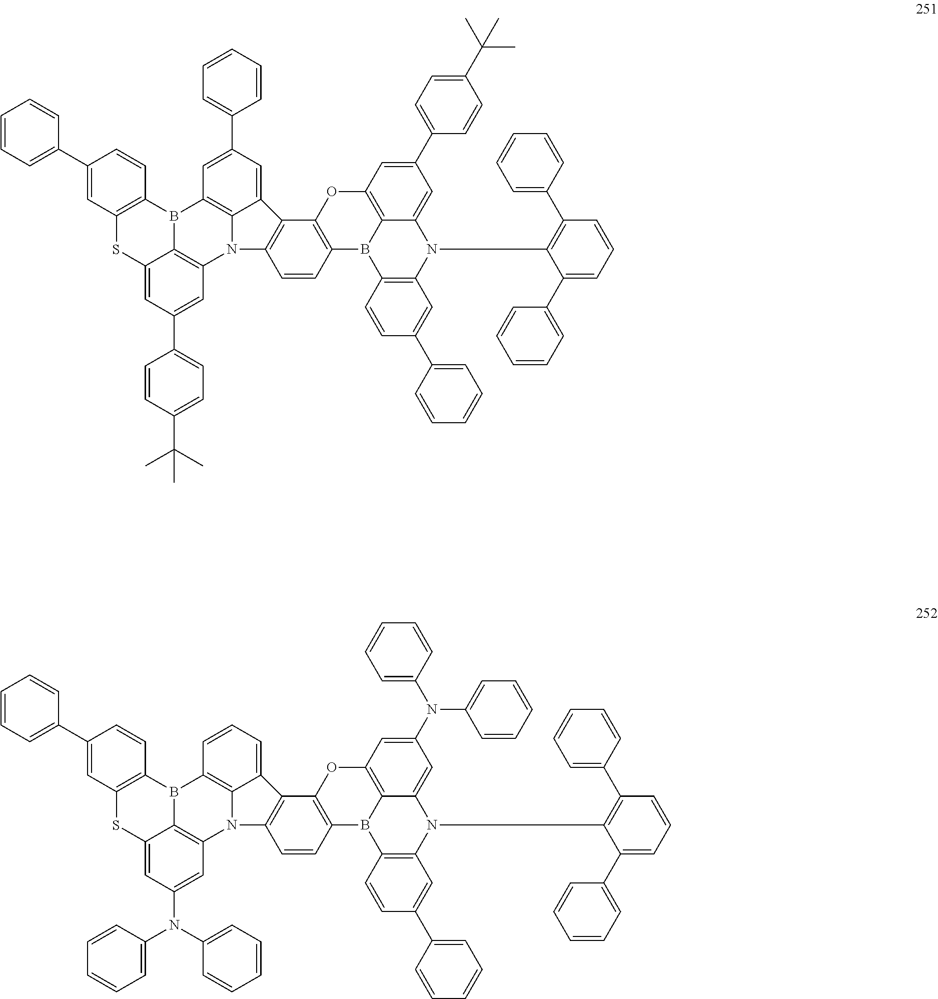 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cc(-c3ccccc3)cc3c2n4-c2cc(-c4ccc(C(C)(C)C)cc4)cc4c2B3c2ccc(-c3ccccc3)cc2S4)cc1 ; c1ccc(-c2ccc3c(c2)Sc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 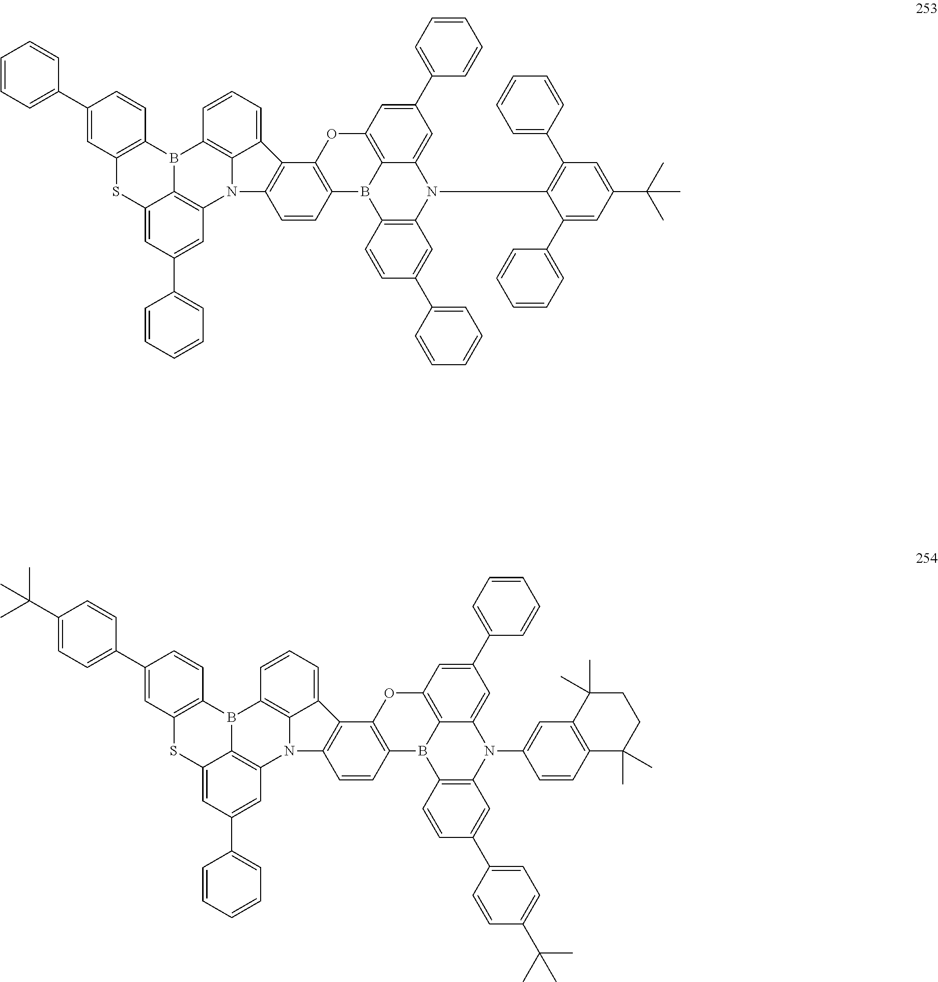 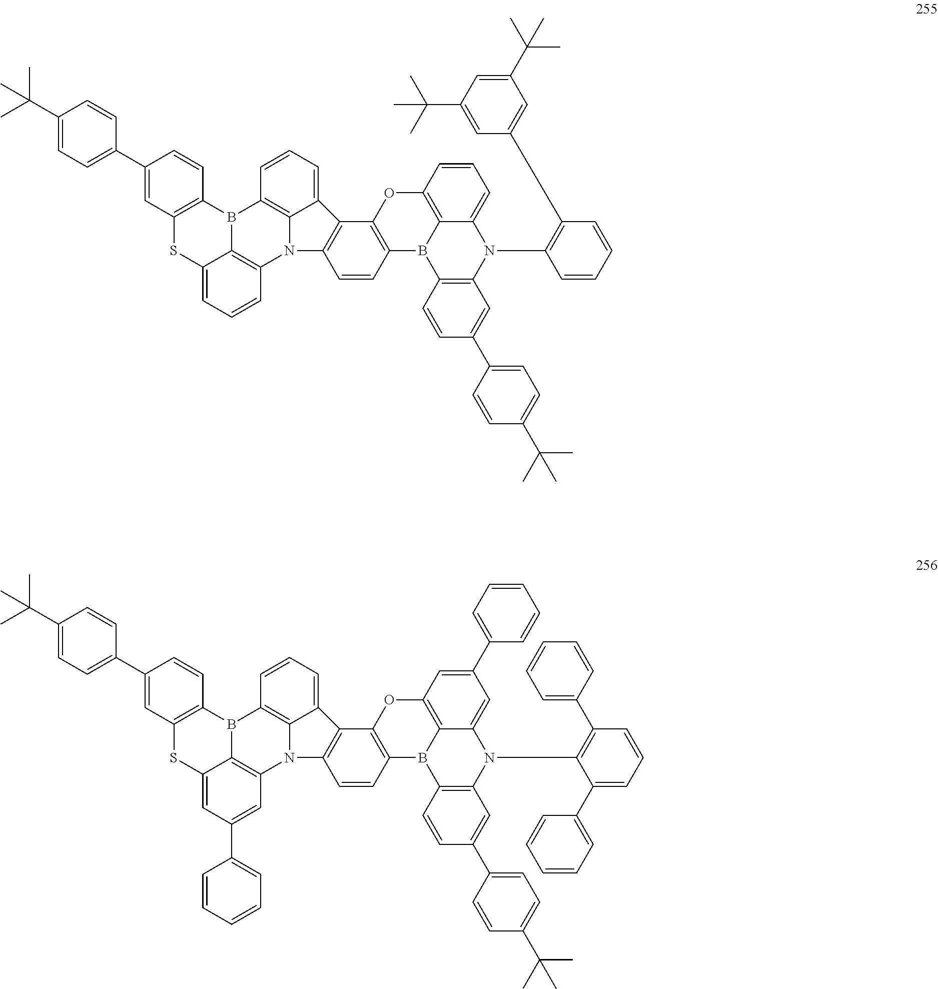 [SMILES: CC(C)(C)c1ccc(-c2ccc3c(c2)Sc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)O6)cc1 ; CC(C)(C)c1ccc(-c2ccc3c(c2)Sc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)O6)cc1] 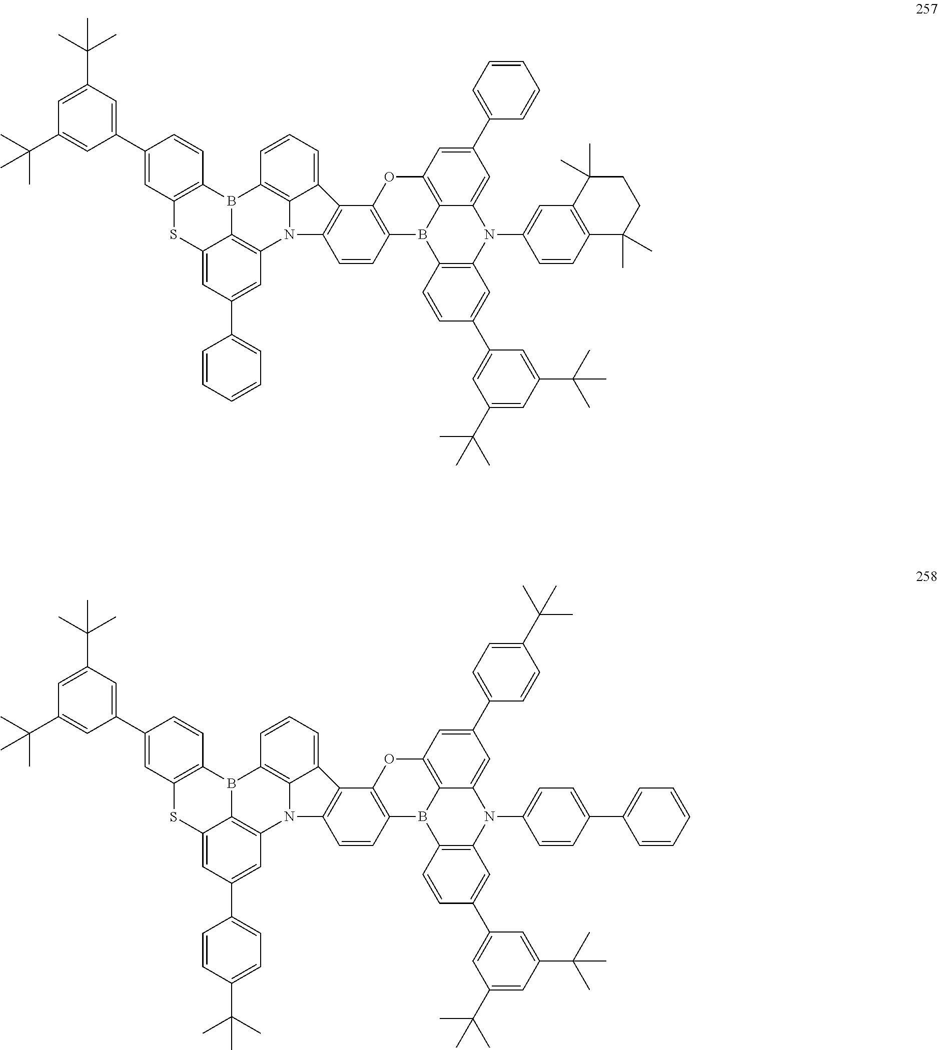 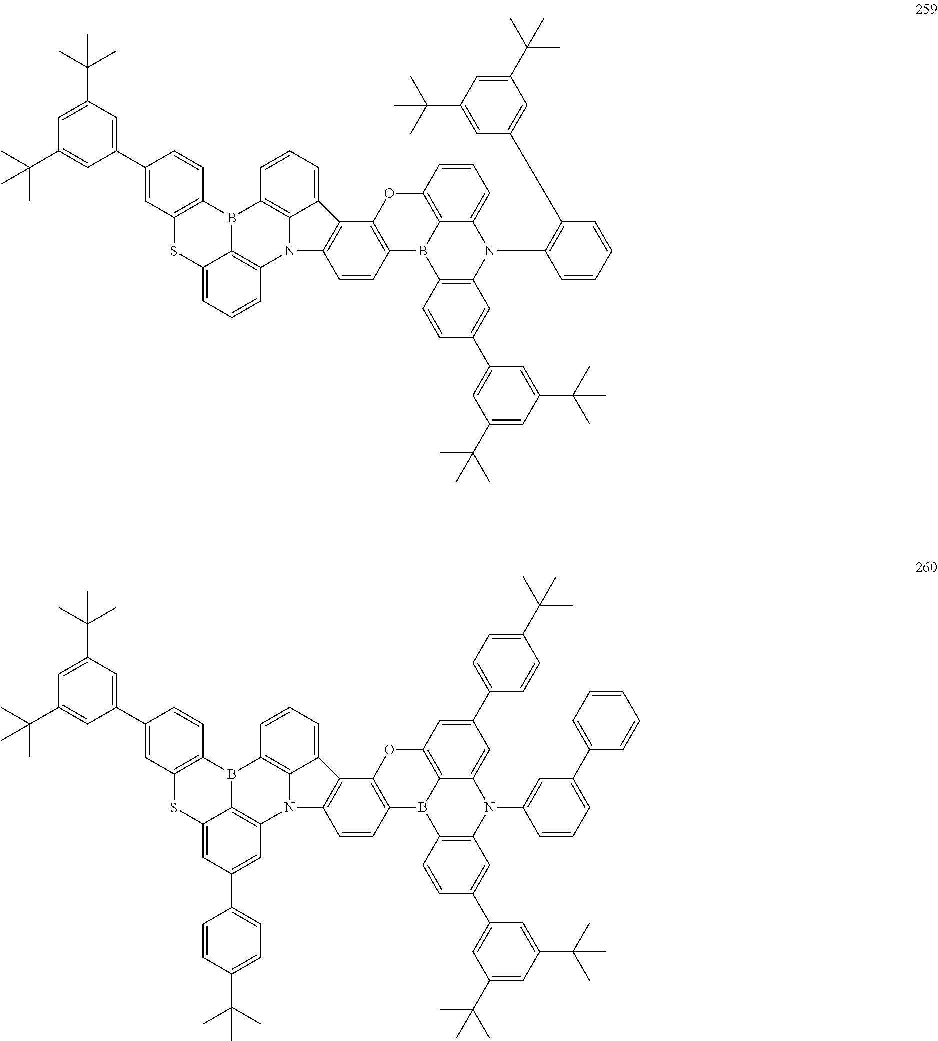 [SMILES: CC(C)(C)c1cc(-c2ccc3c(c2)Sc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)O6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2O3)c2cccc3c2n4-c2cc(-c4ccc(C(C)(C)C)cc4)cc4c2B3c2ccc(-c3cc(C(C)(C)C)cc(C(C)(C)C)c3)cc2S4)cc1] 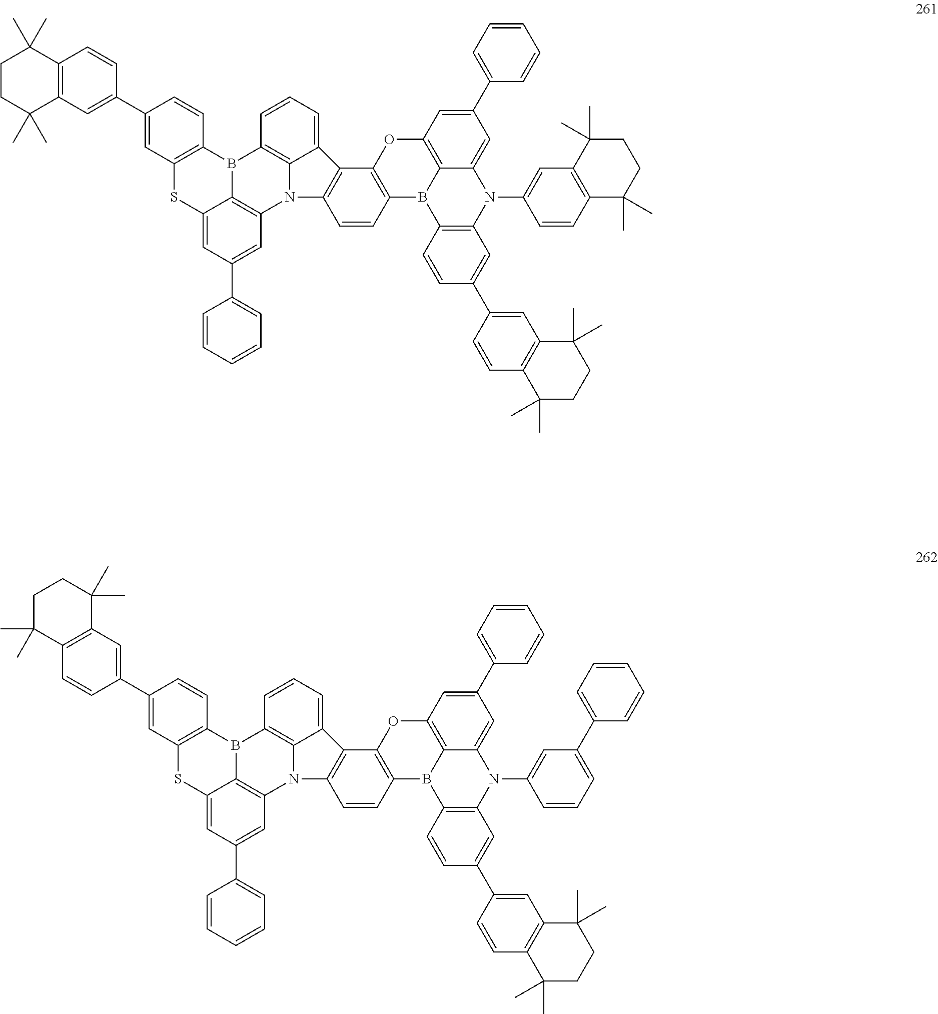 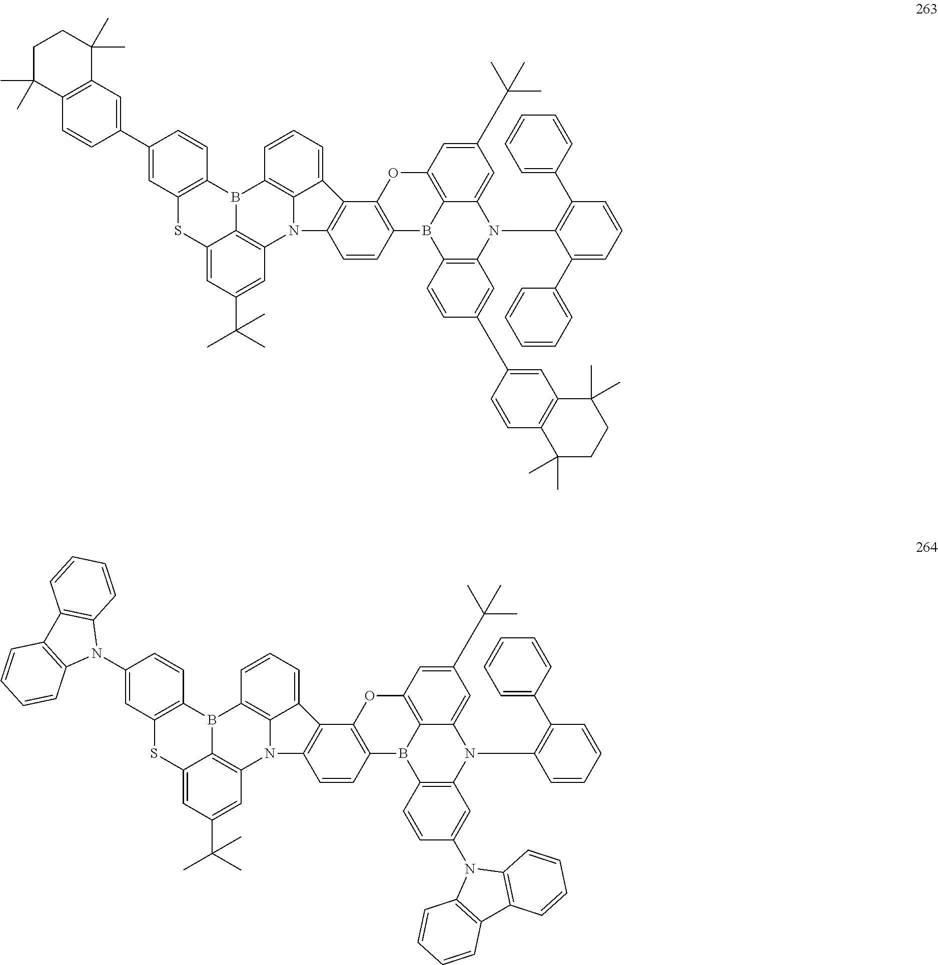 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1O2)c1cccc2c1n3-c1cc(C(C)(C)C)cc3c1B2c1ccc(-c2ccc4c(c2)C(C)(C)CCC4(C)C)cc1S3 ; CC(C)(C)c1cc2c3c(c1)N(c1ccccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 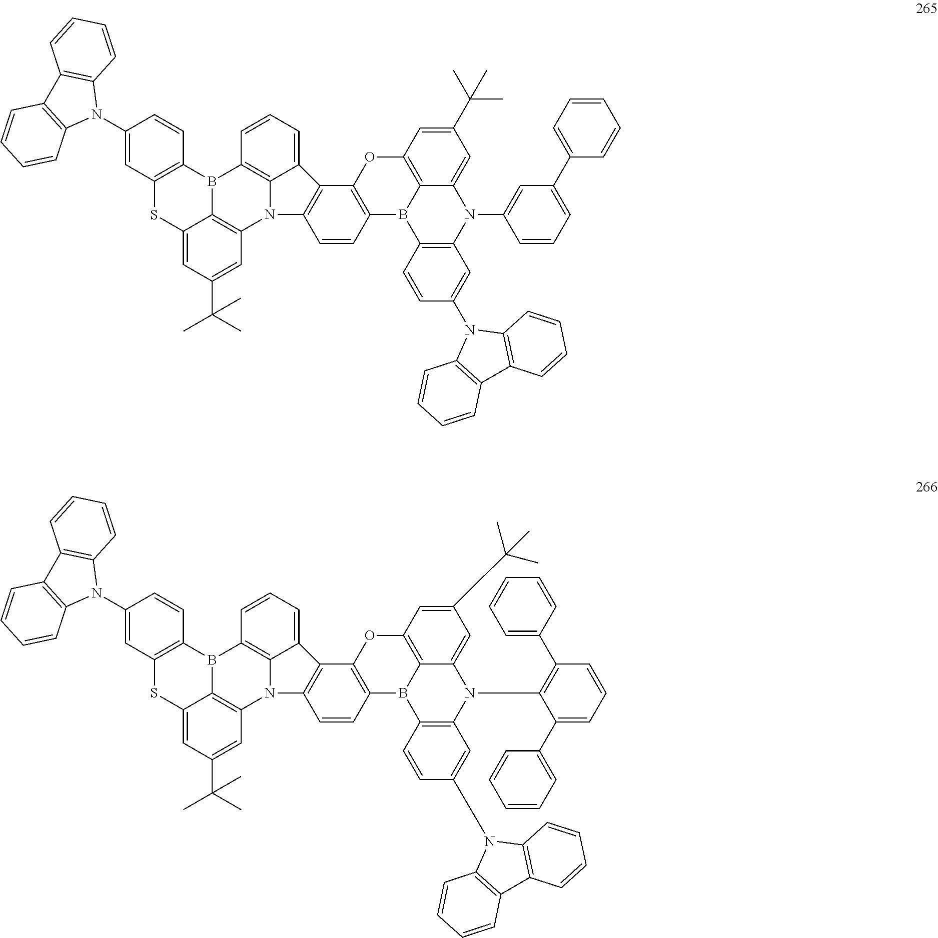 [SMILES: CC(C)(C)c1cc2c3c(c1)N(c1cccc(-c4ccccc4)c1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 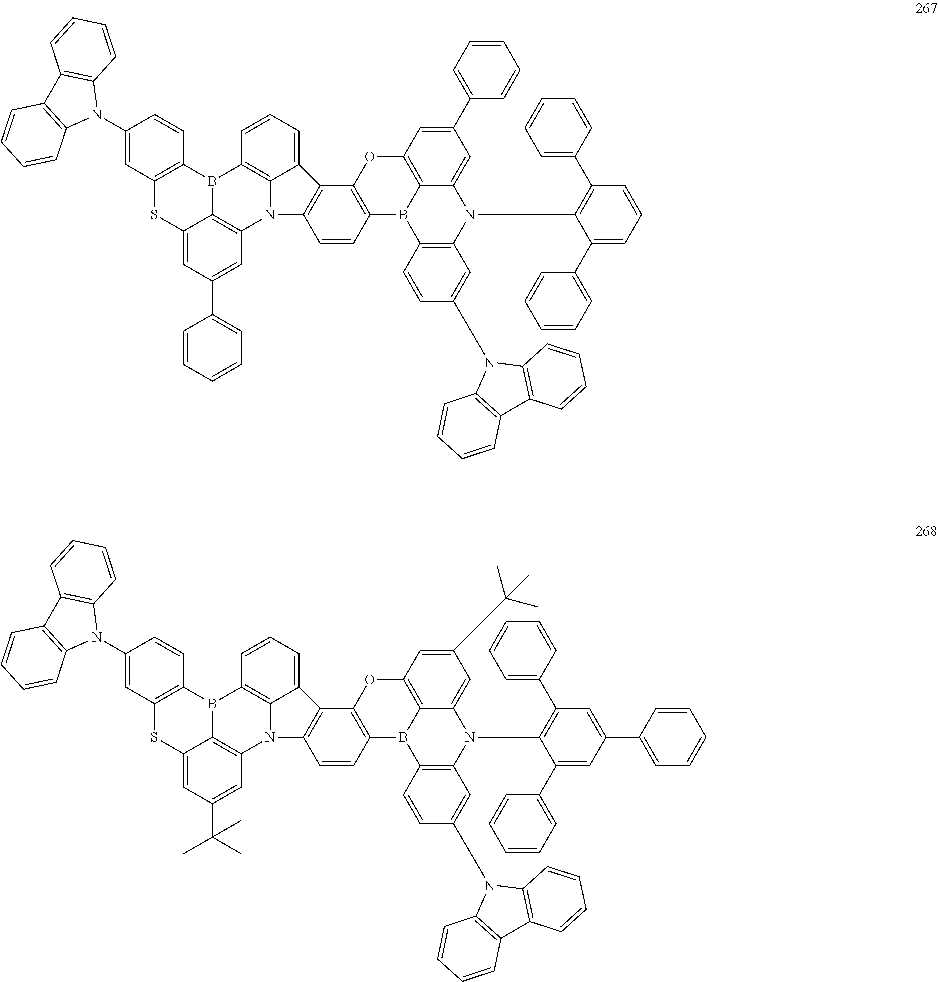 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2O3)c2cccc3c2n4-c2cc(-c4ccccc4)cc4c2B3c2ccc(-n3c5ccccc5c5ccccc53)cc2S4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1O2)c1cccc2c1n3-c1cc(C(C)(C)C)cc3c1B2c1ccc(-n2c4ccccc4c4ccccc42)cc1S3] 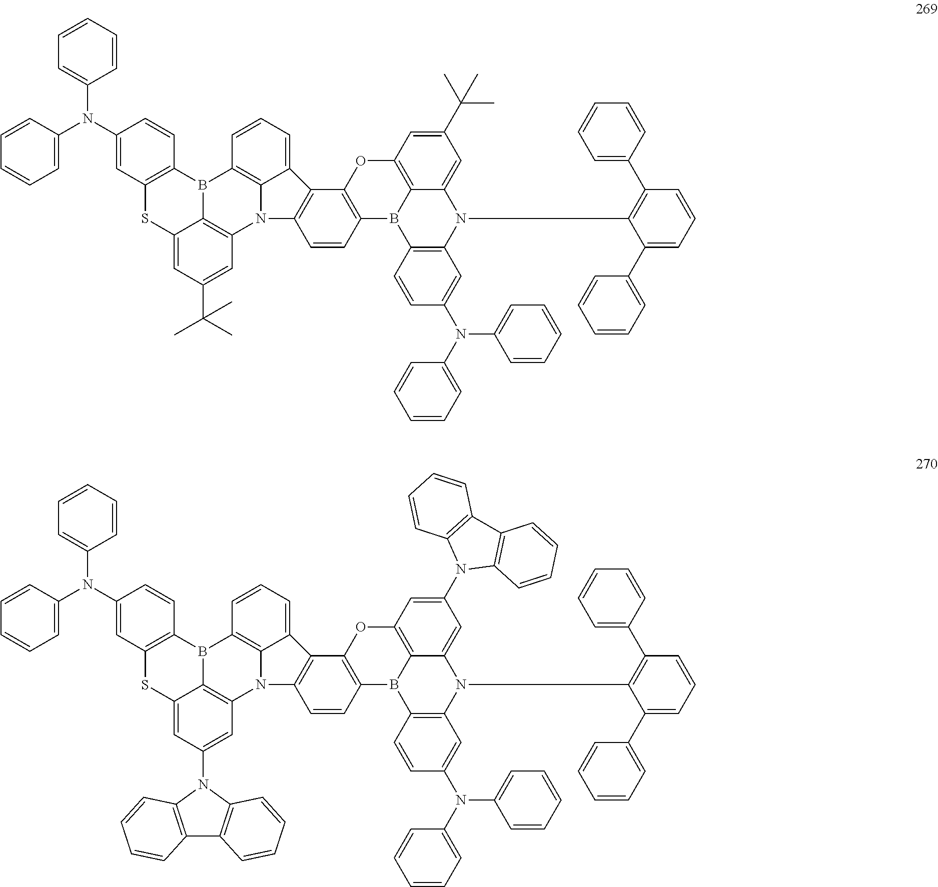 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1O2)c1cccc2c1n3-c1cc(C(C)(C)C)cc3c1B2c1ccc(N(c2ccccc2)c2ccccc2)cc1S3 ; c1ccc(-c2cccc(-c3ccccc3)c2N2c3cc(N(c4ccccc4)c4ccccc4)ccc3B3c4ccc5c(c4Oc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2S4)cc1] 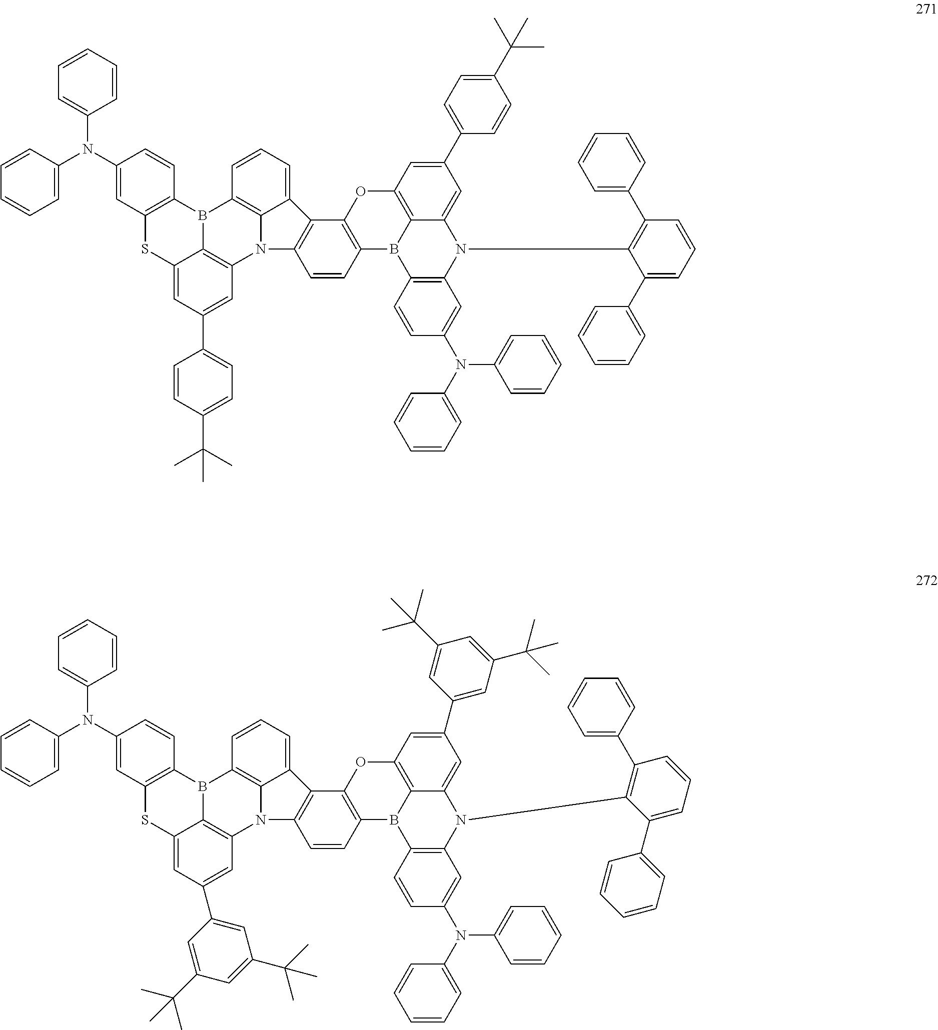 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4ccc(C(C)(C)C)cc4)cc4c2B3c2ccc(N(c3ccccc3)c3ccccc3)cc2S4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2O3)c2cccc3c2n4-c2cc(-c4cc(C(C)(C)C)cc(C(C)(C)C)c4)cc4c2B3c2ccc(N(c3ccccc3)c3ccccc3)cc2S4)cc(C(C)(C)C)c1] 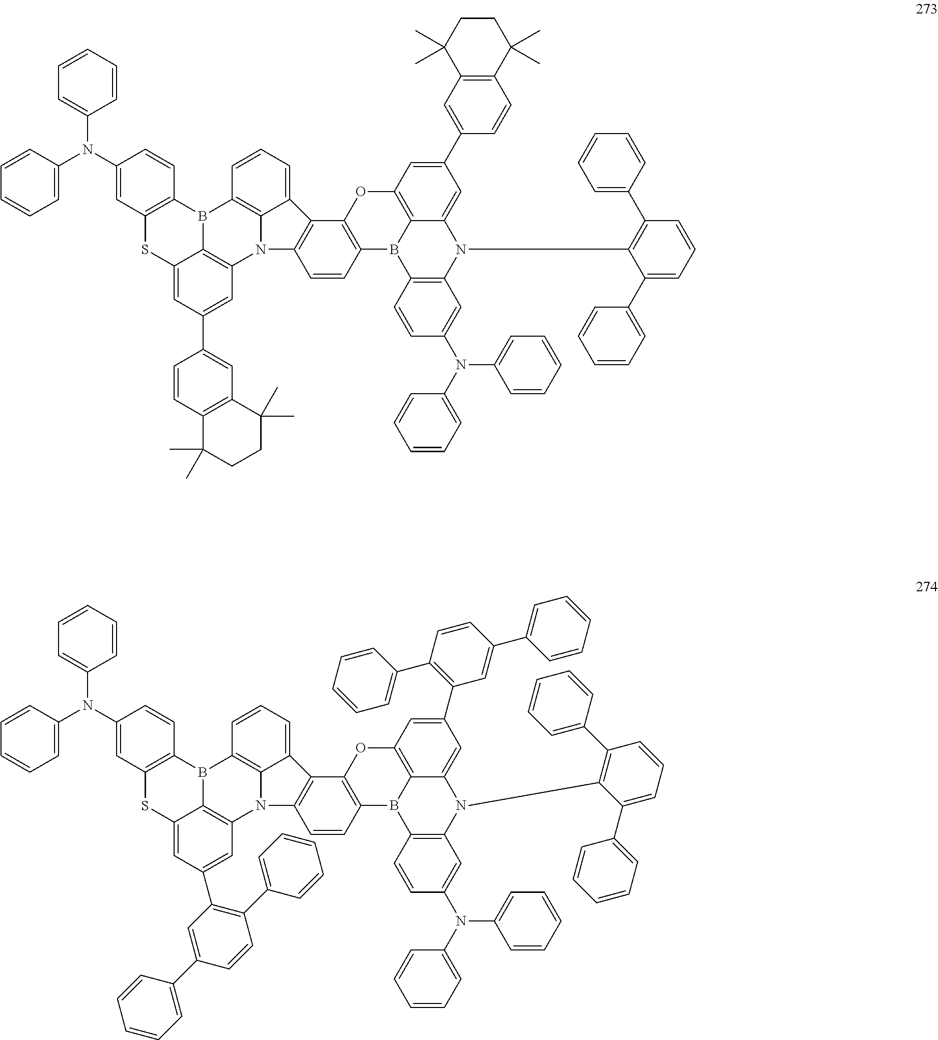 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5ccc6c(c5)C(C)(C)CCC6(C)C)cc5c3B4c3ccc(N(c4ccccc4)c4ccccc4)cc3S5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3O4)c3cccc4c3n5-c3cc(-c5cc(-c6ccccc6)ccc5-c5ccccc5)cc5c3B4c3ccc(N(c4ccccc4)c4ccccc4)cc3S5)c2)cc1] 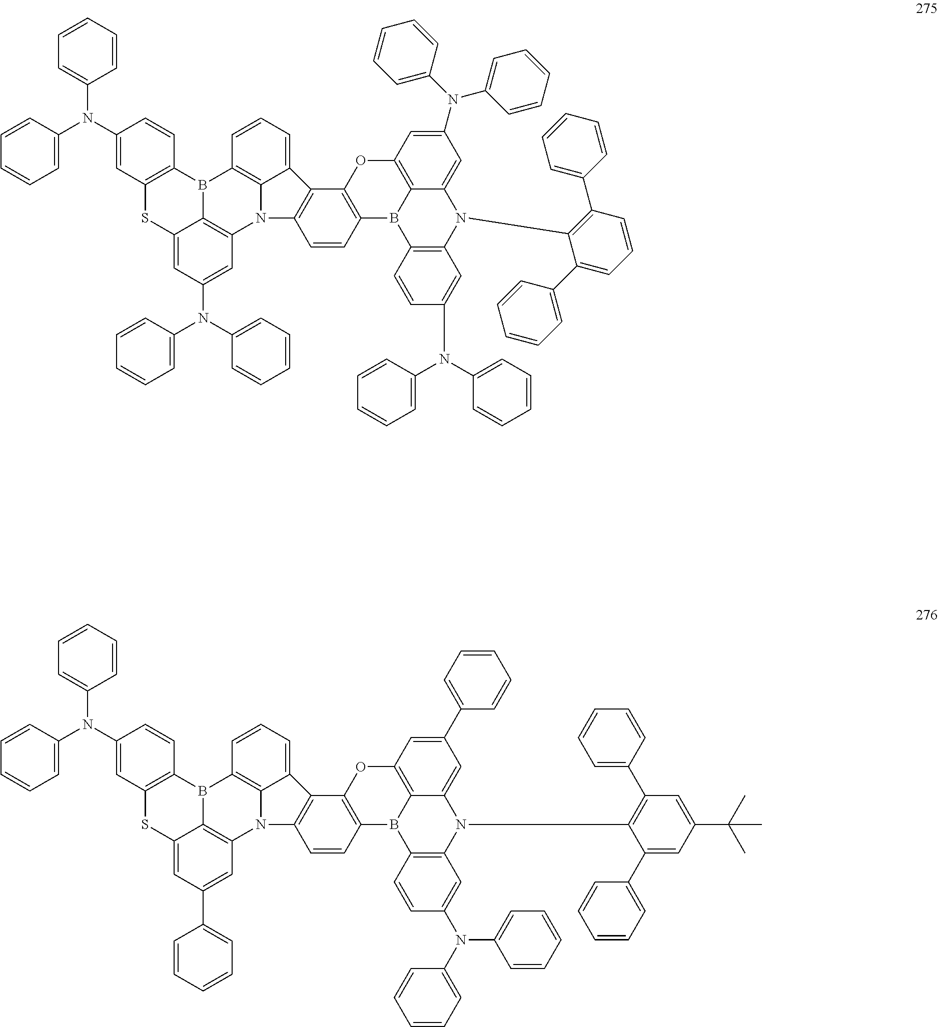 [SMILES: c1ccc(-c2cccc(-c3ccccc3)c2N2c3cc(N(c4ccccc4)c4ccccc4)ccc3B3c4ccc5c(c4Oc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2S4)cc1 ; CC(C)(C)c1cc(-c2ccccc2)c(N2c3cc(N(c4ccccc4)c4ccccc4)ccc3B3c4ccc5c(c4Oc4cc(-c6ccccc6)cc2c43)c2cccc3c2n5-c2cc(-c4ccccc4)cc4c2B3c2ccc(N(c3ccccc3)c3ccccc3)cc2S4)c(-c2ccccc2)c1] 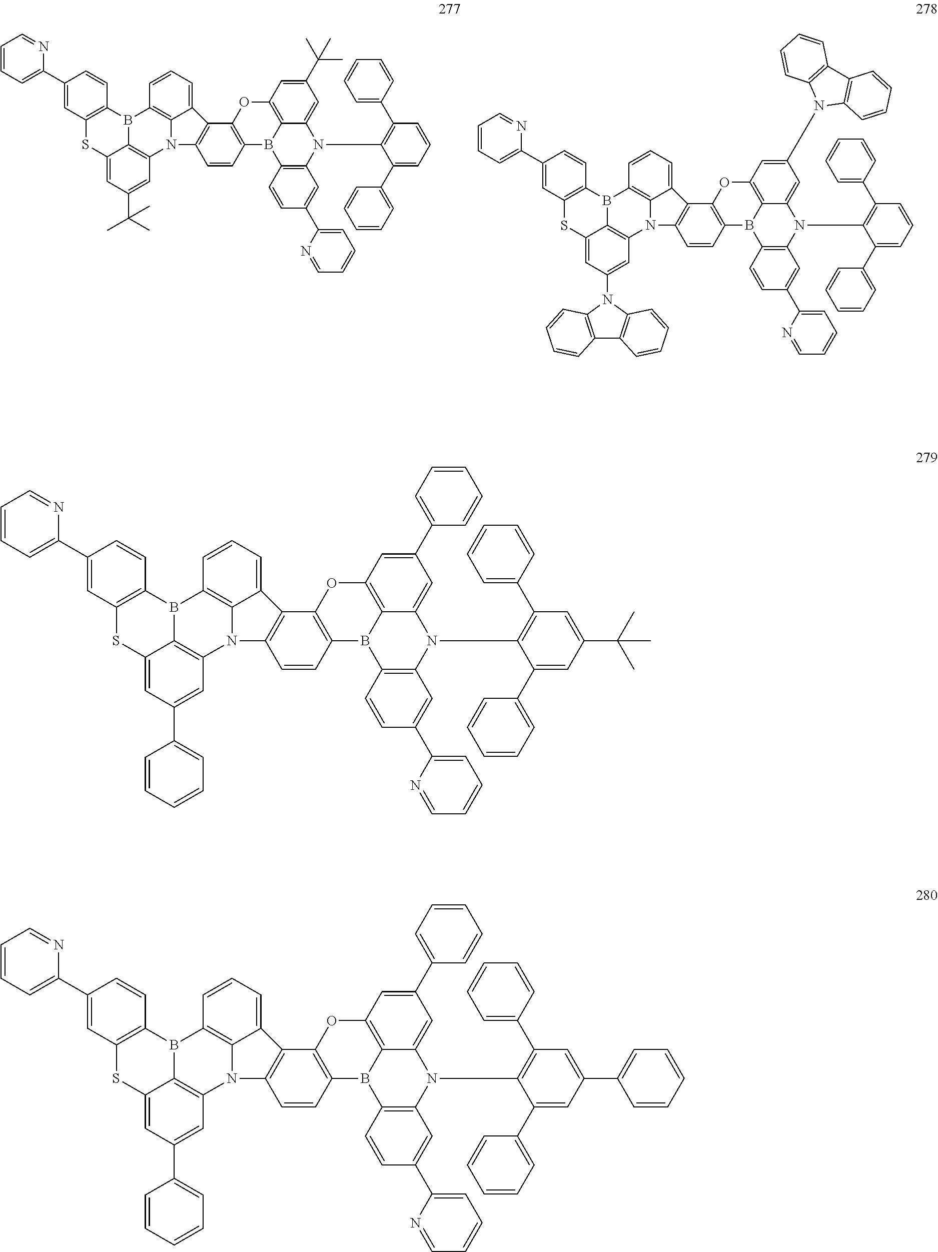 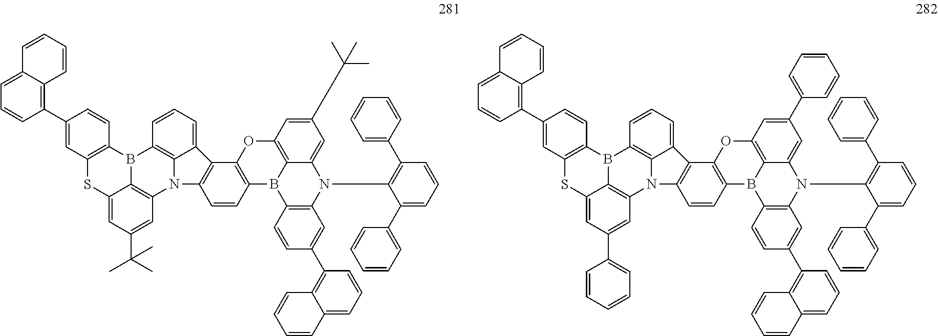 [SMILES: CC(C)(C)c1cc2c3c(c1)N(c1c(-c4ccccc4)cccc1-c1ccccc1)c1cc(-c4cccc5ccccc45)ccc1B3c1ccc3c(c1O2)c1cccc2c1n3-c1cc(C(C)(C)C)cc3c1B2c1ccc(-c2cccc4ccccc24)cc1S3 ; c1ccc(-c2cc3c4c(c2)N(c2c(-c5ccccc5)cccc2-c2ccccc2)c2cc(-c5cccc6ccccc56)ccc2B4c2ccc4c(c2O3)c2cccc3c2n4-c2cc(-c4ccccc4)cc4c2B3c2ccc(-c3cccc5ccccc35)cc2S4)cc1] 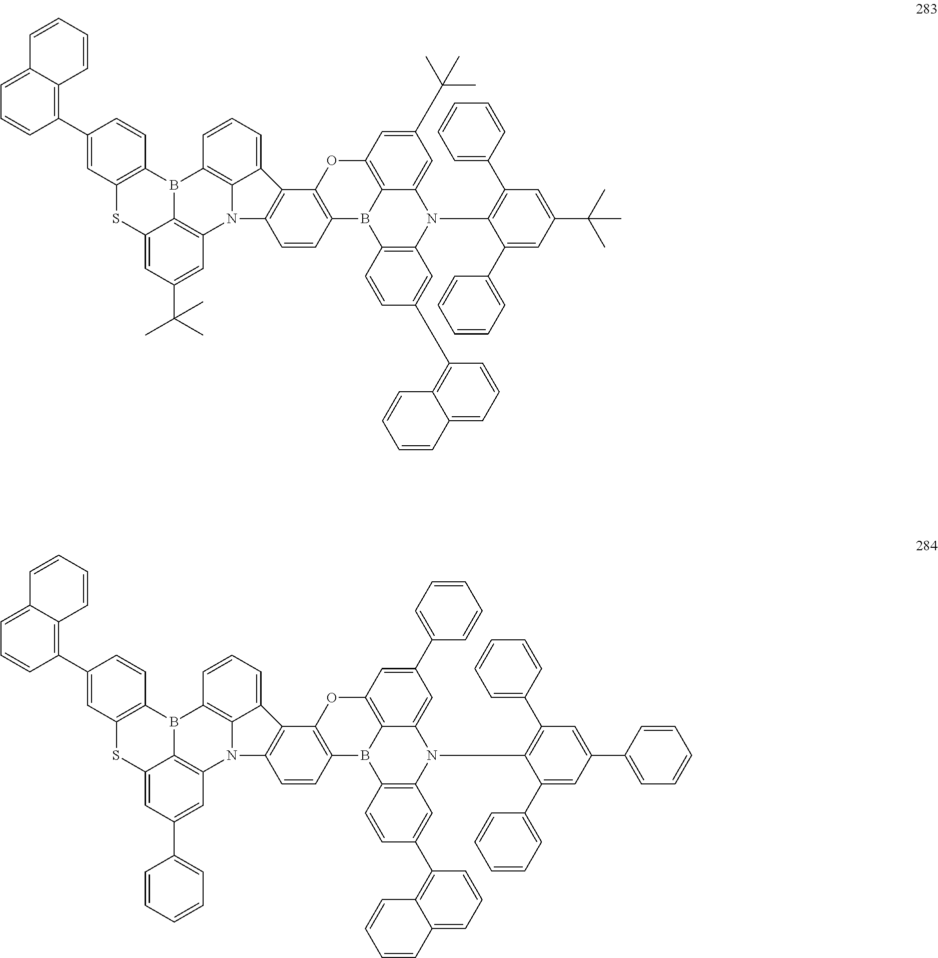 [SMILES: CC(C)(C)c1cc(-c2ccccc2)c(N2c3cc(-c4cccc5ccccc45)ccc3B3c4ccc5c(c4Oc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Oc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1] 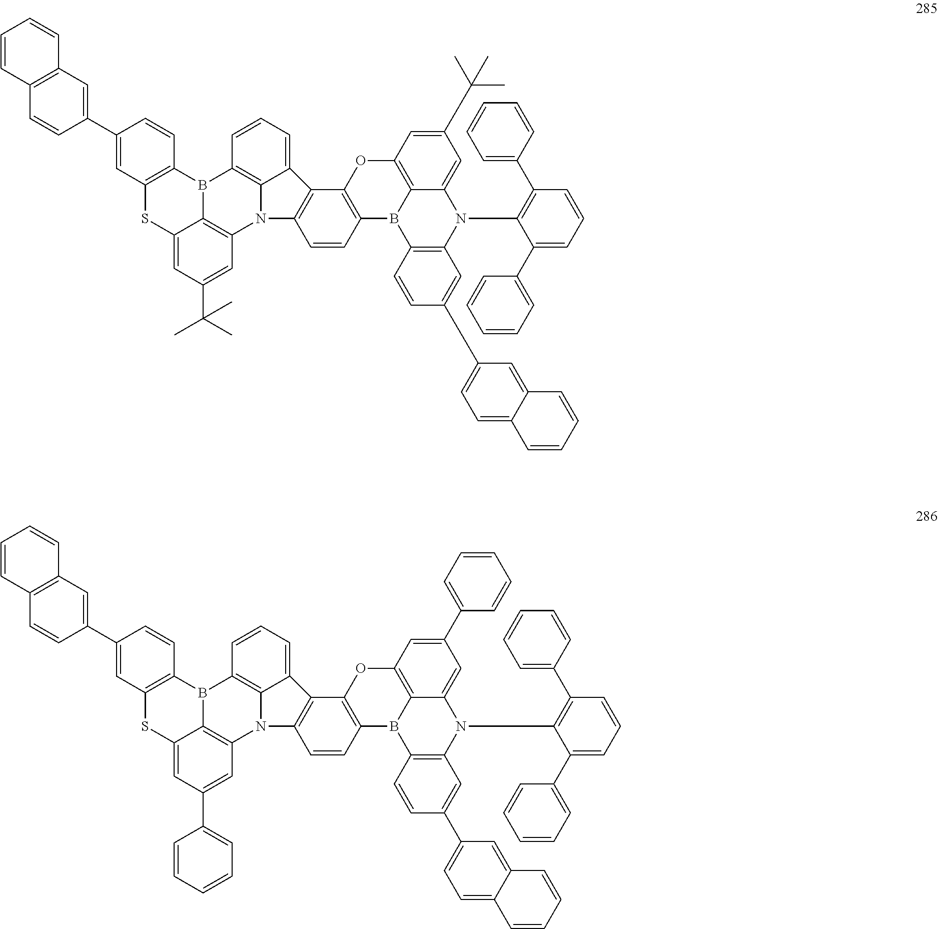 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1O2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2O3)c2cccc3c2n4-c2cc(-c4ccccc4)cc4c2B3c2ccc(-c3ccc5ccccc5c3)cc2S4)cc1] 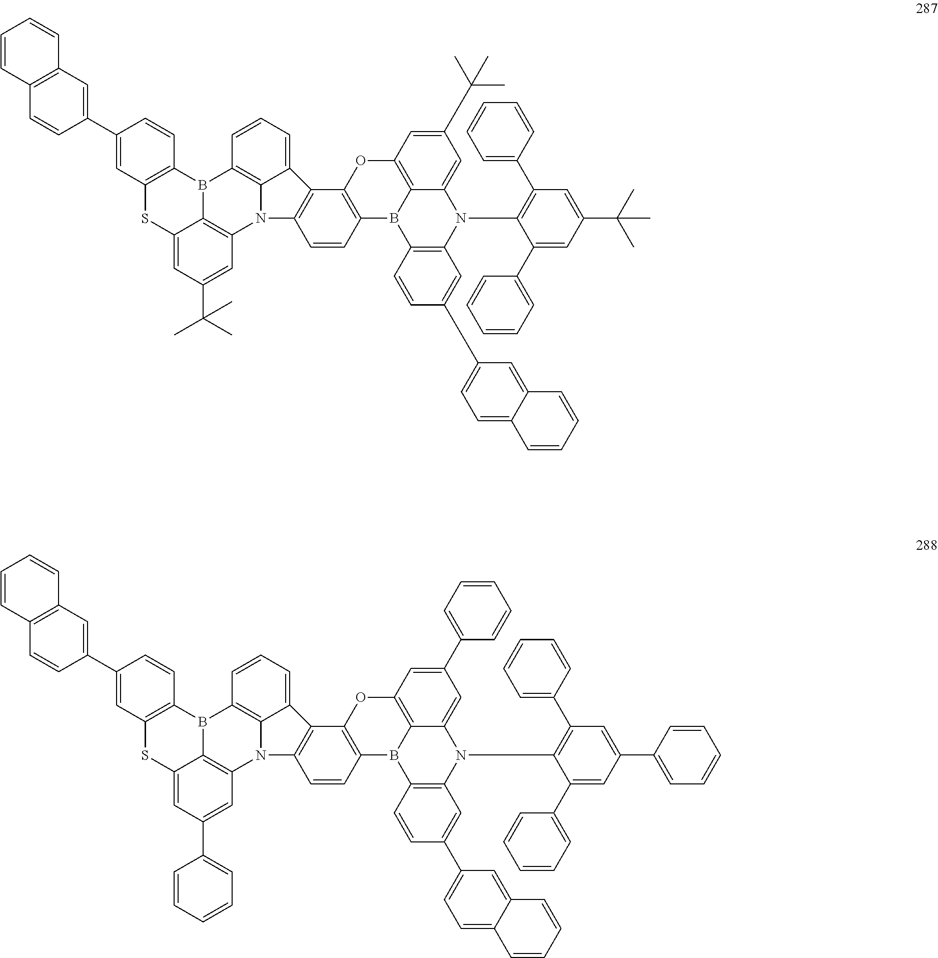 [SMILES: CC(C)(C)c1cc(-c2ccccc2)c(N2c3cc(-c4ccc5ccccc5c4)ccc3B3c4ccc5c(c4Oc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Oc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1] 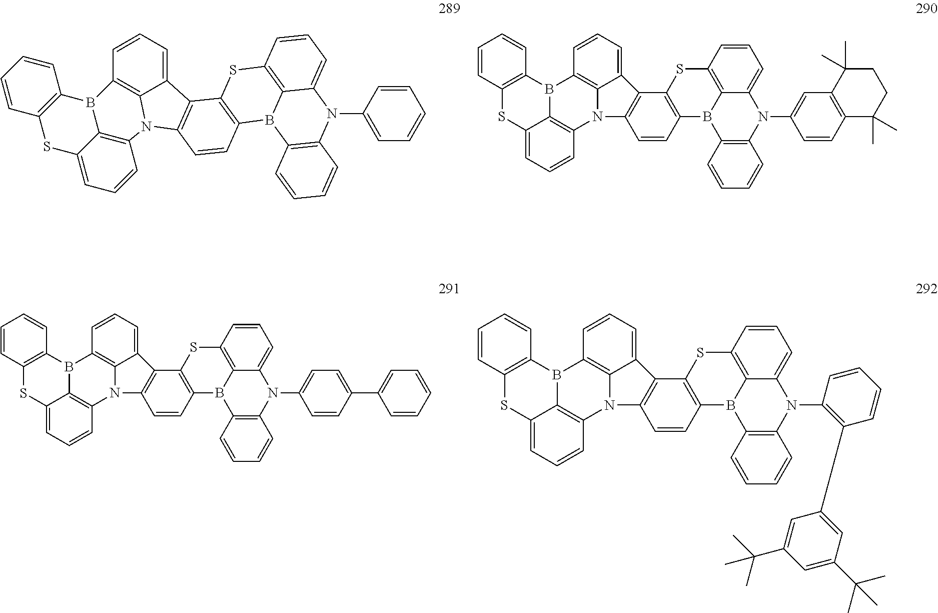 [SMILES: c1ccc(N2c3ccccc3B3c4ccc5c(c4Sc4cccc2c43)c2cccc3c2n5-c2cccc4c2B3c2ccccc2S4)cc1 ; CC1(C)CCC(C)(C)c2cc(N3c4ccccc4B4c5ccc6c(c5Sc5cccc3c54)c3cccc4c3n6-c3cccc5c3B4c3ccccc3S5)ccc21 ; c1ccc(-c2ccc(N3c4ccccc4B4c5ccc6c(c5Sc5cccc3c54)c3cccc4c3n6-c3cccc5c3B4c3ccccc3S5)cc2)cc1 ; CC(C)(C)c1cc(-c2ccccc2N2c3ccccc3B3c4ccc5c(c4Sc4cccc2c43)c2cccc3c2n5-c2cccc4c2B3c2ccccc2S4)cc(C(C)(C)C)c1] 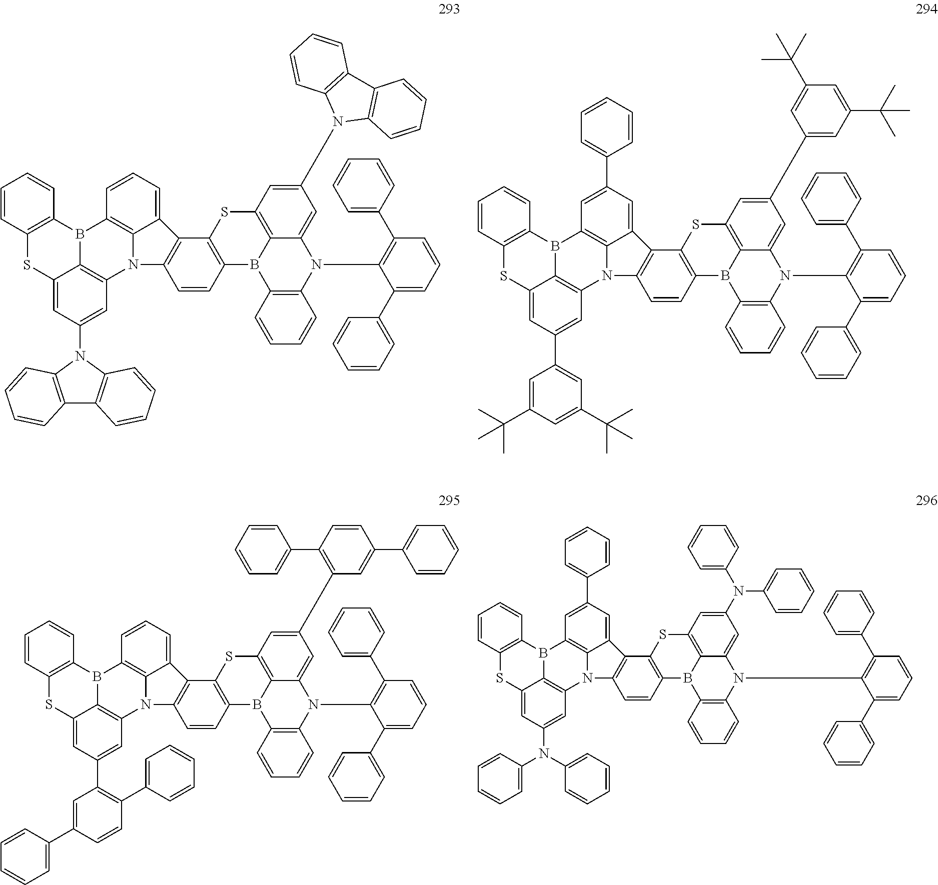 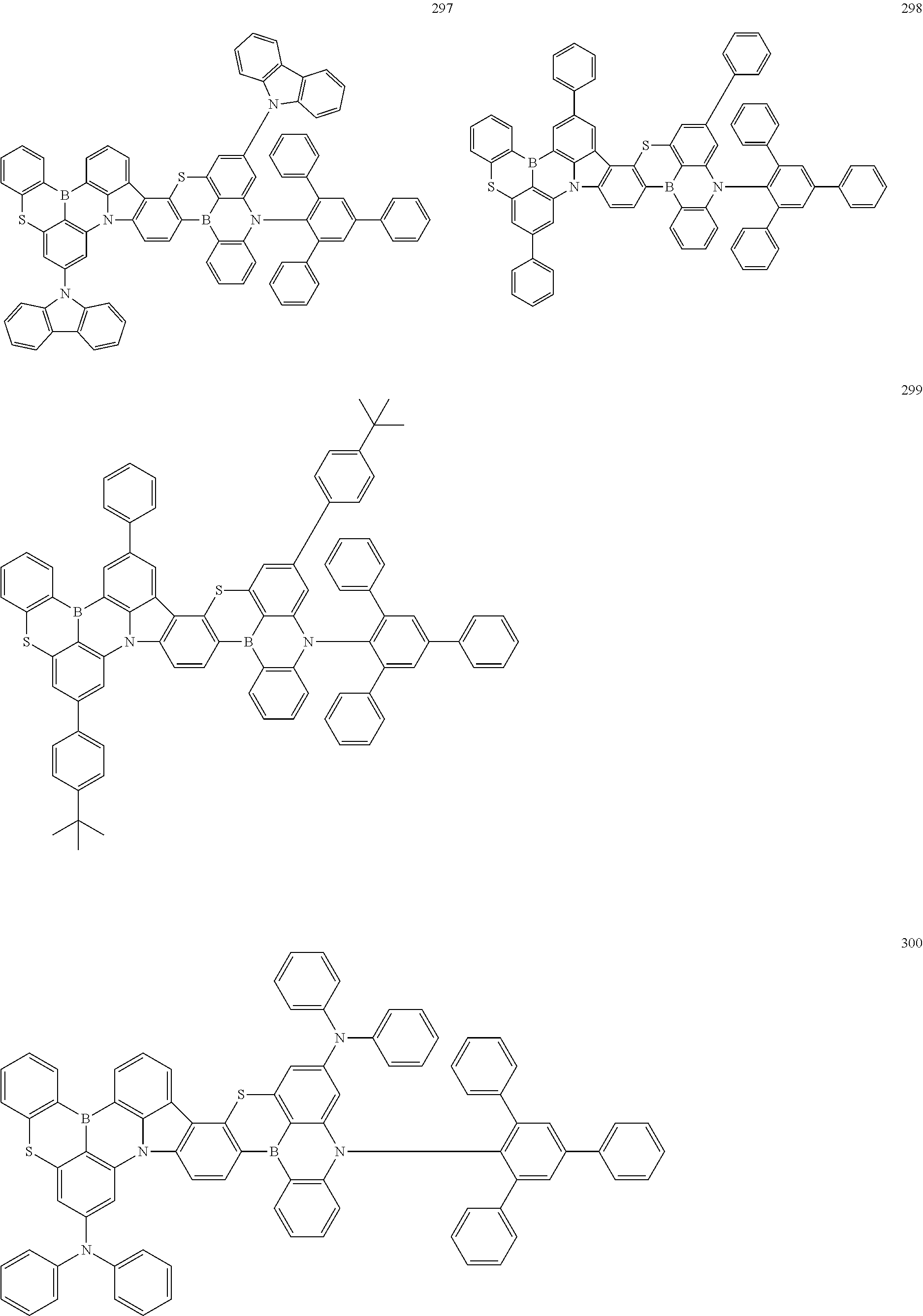 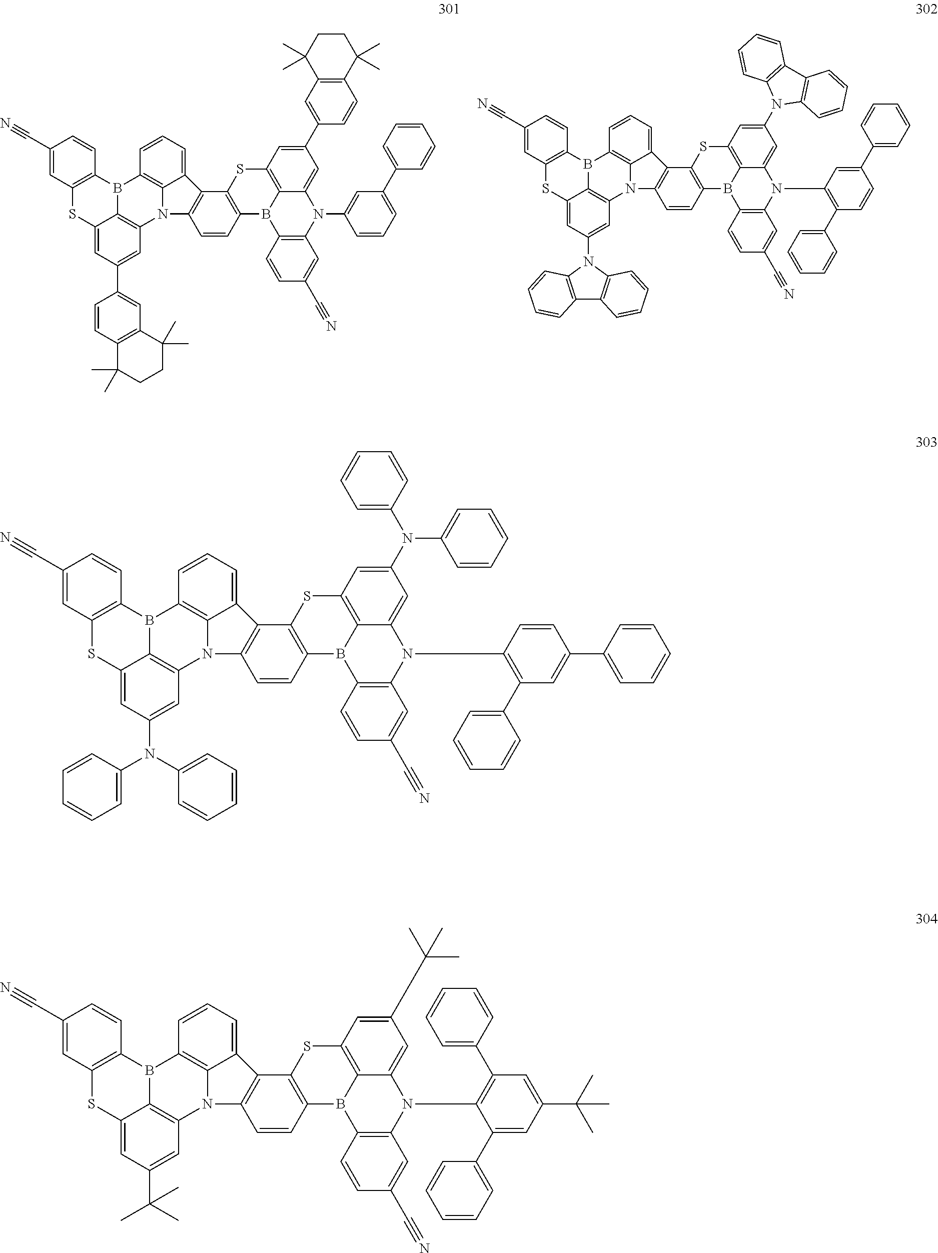 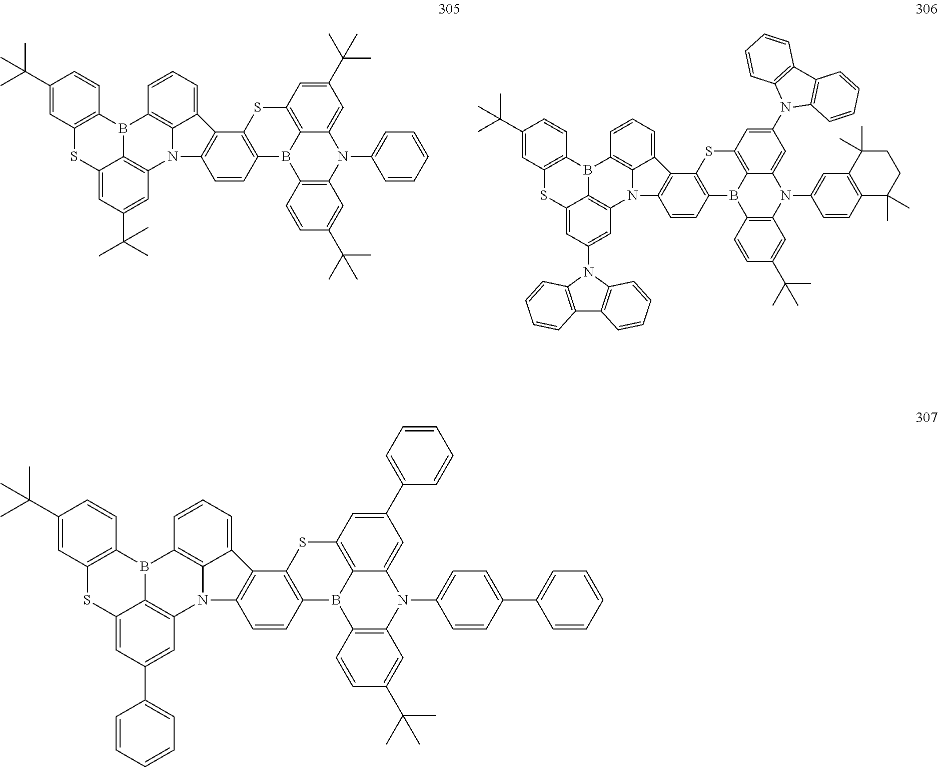 [SMILES: CC(C)(C)c1ccc2c(c1)Sc1cc(C(C)(C)C)cc3c1B2c1cccc2c4c5c(ccc4n-3c12)B1c2ccc(C(C)(C)C)cc2N(c2ccccc2)c2cc(C(C)(C)C)cc(c21)S5 ; CC(C)(C)c1ccc2c(c1)Sc1cc(-n3c4ccccc4c4ccccc43)cc3c1B2c1cccc2c4c5c(ccc4n-3c12)B1c2ccc(C(C)(C)C)cc2N(c2ccc3c(c2)C(C)(C)CCC3(C)C)c2cc(-n3c4ccccc4c4ccccc43)cc(c21)S5 ; CC(C)(C)c1ccc2c(c1)Sc1cc(-c3ccccc3)cc3c1B2c1cccc2c4c5c(ccc4n-3c12)B1c2ccc(C(C)(C)C)cc2N(c2ccc(-c3ccccc3)cc2)c2cc(-c3ccccc3)cc(c21)S5] 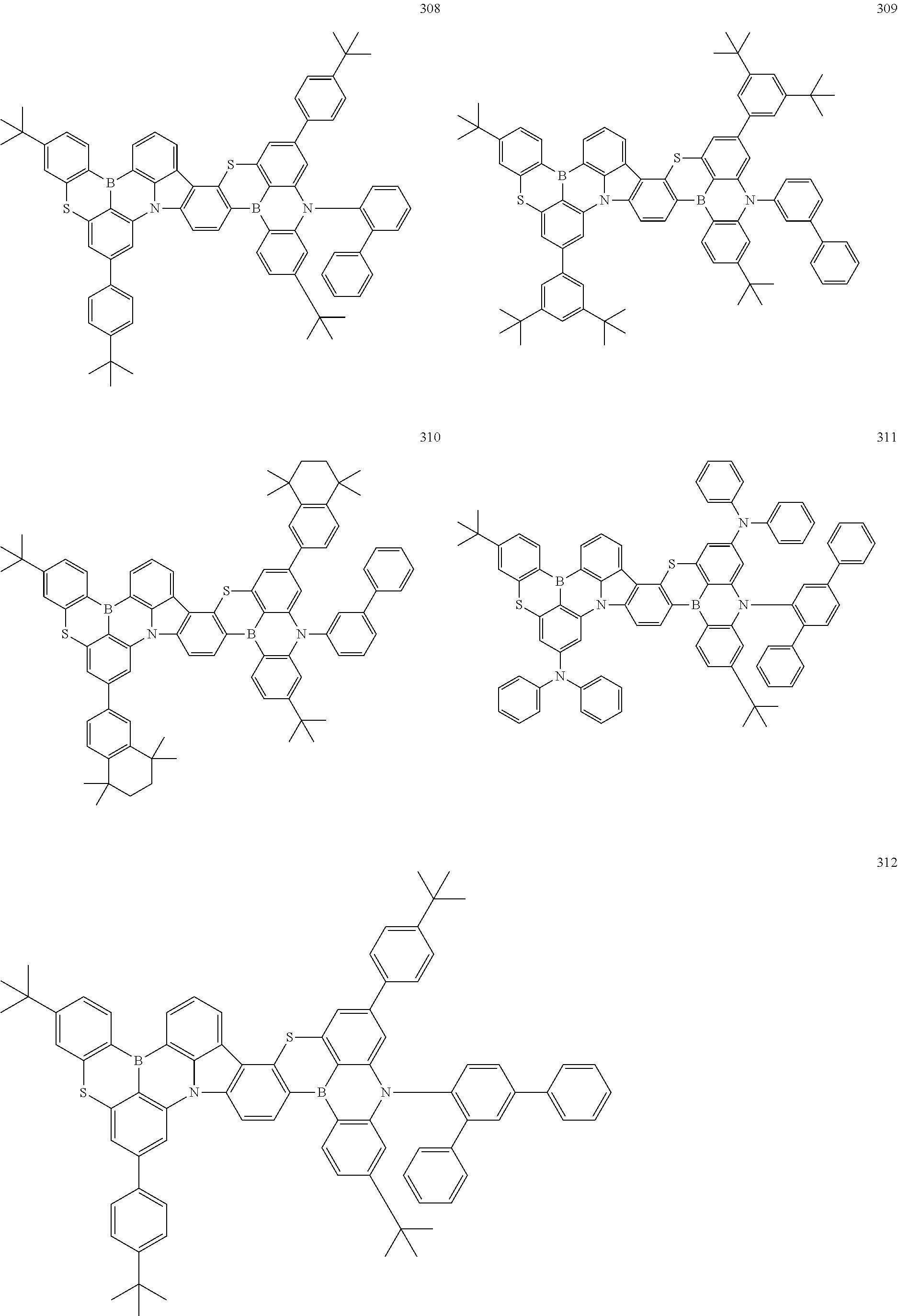 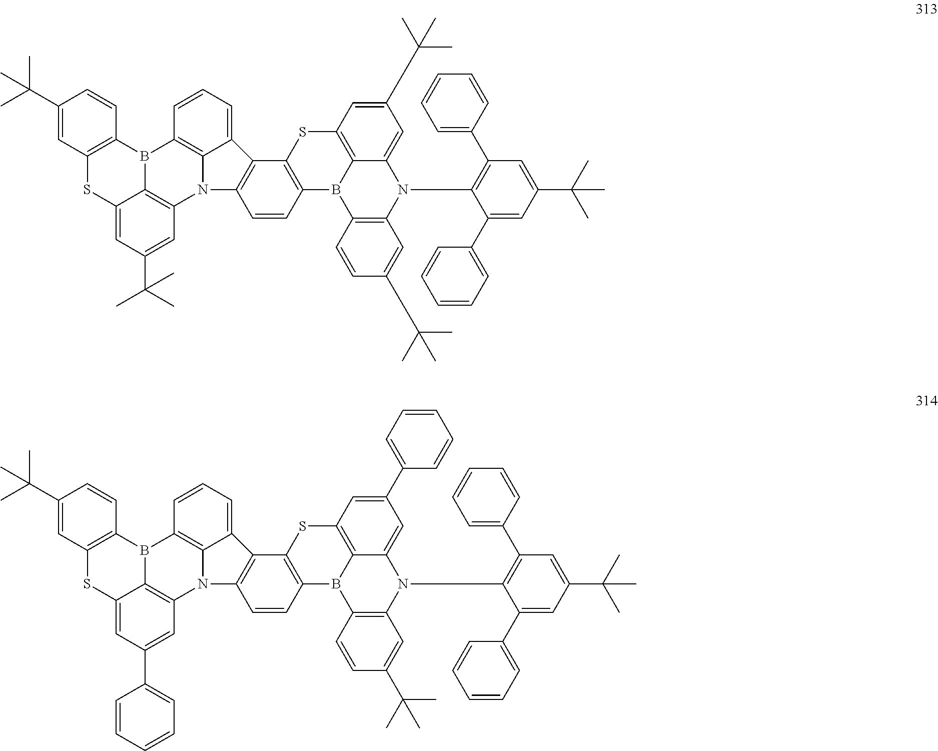 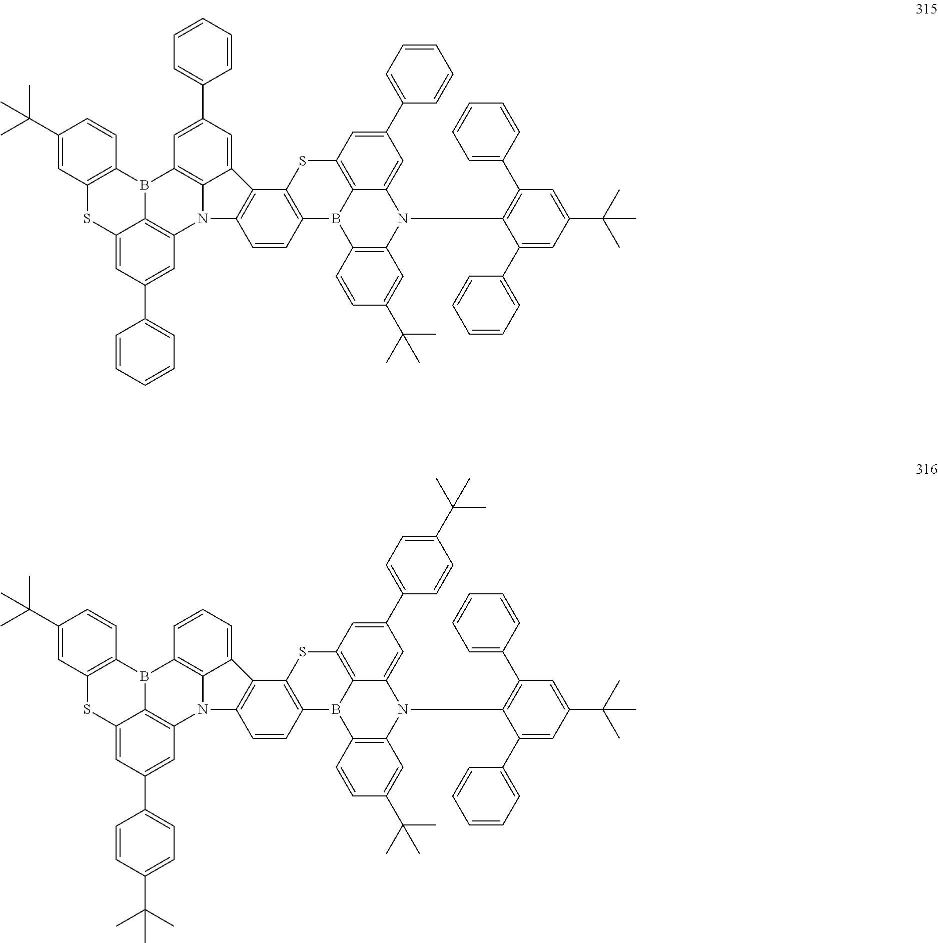 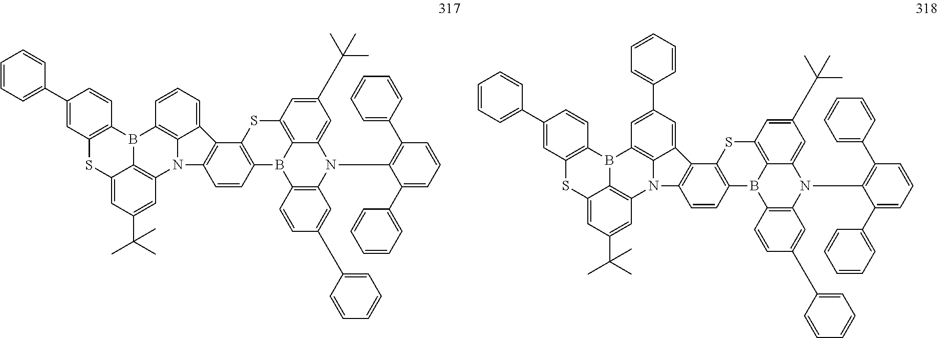 [SMILES: CC(C)(C)c1cc2c3c(c1)N(c1c(-c4ccccc4)cccc1-c1ccccc1)c1cc(-c4ccccc4)ccc1B3c1ccc3c(c1S2)c1cccc2c1n3-c1cc(C(C)(C)C)cc3c1B2c1ccc(-c2ccccc2)cc1S3 ; CC(C)(C)c1cc2c3c(c1)N(c1c(-c4ccccc4)cccc1-c1ccccc1)c1cc(-c4ccccc4)ccc1B3c1ccc3c(c1S2)c1cc(-c2ccccc2)cc2c1n3-c1cc(C(C)(C)C)cc3c1B2c1ccc(-c2ccccc2)cc1S3] 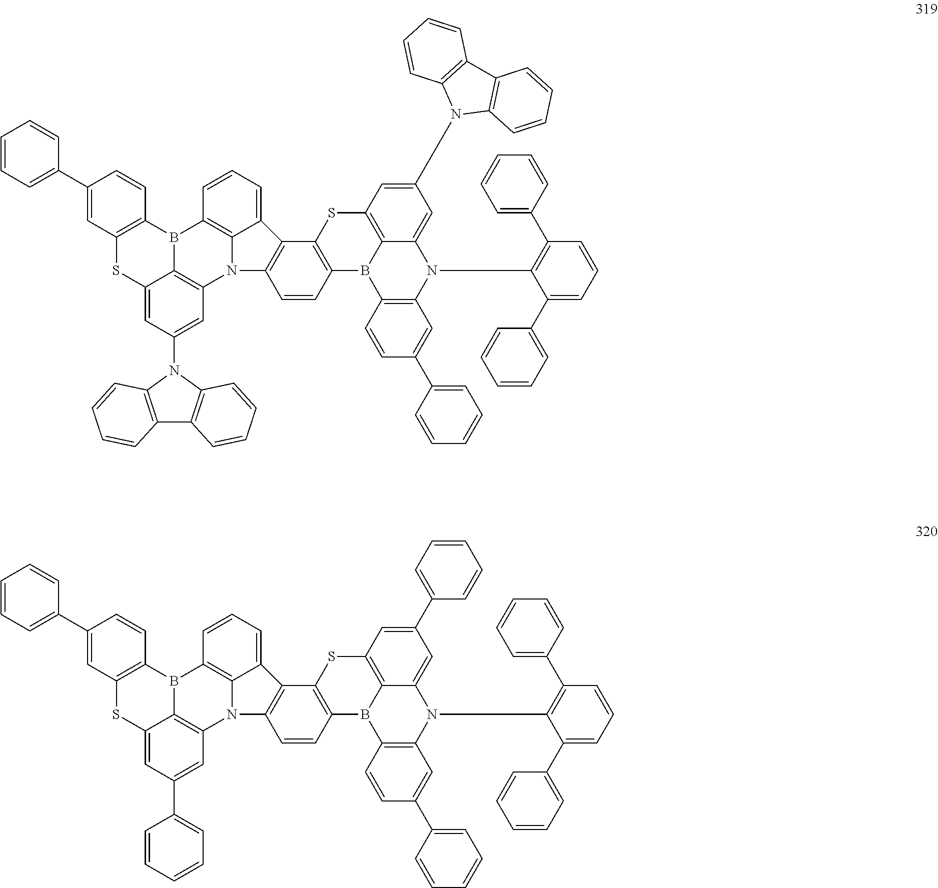 [SMILES: c1ccc(-c2ccc3c(c2)Sc2cc(-n4c5ccccc5c5ccccc54)cc4c2B3c2cccc3c5c6c(ccc5n-4c23)B2c3ccc(-c4ccccc4)cc3N(c3c(-c4ccccc4)cccc3-c3ccccc3)c3cc(-n4c5ccccc5c5ccccc54)cc(c32)S6)cc1 ; c1ccc(-c2ccc3c(c2)Sc2cc(-c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(-c4ccccc4)cc(c32)S6)cc1] 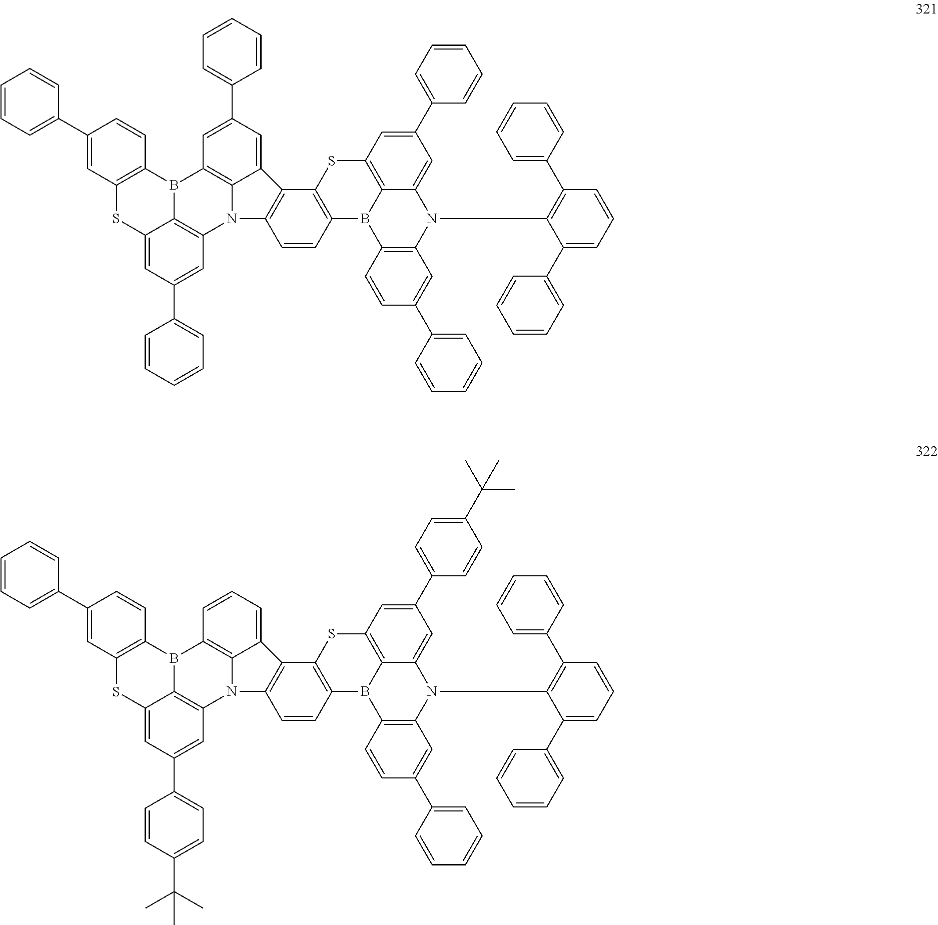 [SMILES: c1ccc(-c2ccc3c(c2)Sc2cc(-c4ccccc4)cc4c2B3c2cc(-c3ccccc3)cc3c5c6c(ccc5n-4c23)B2c3ccc(-c4ccccc4)cc3N(c3c(-c4ccccc4)cccc3-c3ccccc3)c3cc(-c4ccccc4)cc(c32)S6)cc1 ; CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cccc3c2n4-c2cc(-c4ccc(C(C)(C)C)cc4)cc4c2B3c2ccc(-c3ccccc3)cc2S4)cc1] 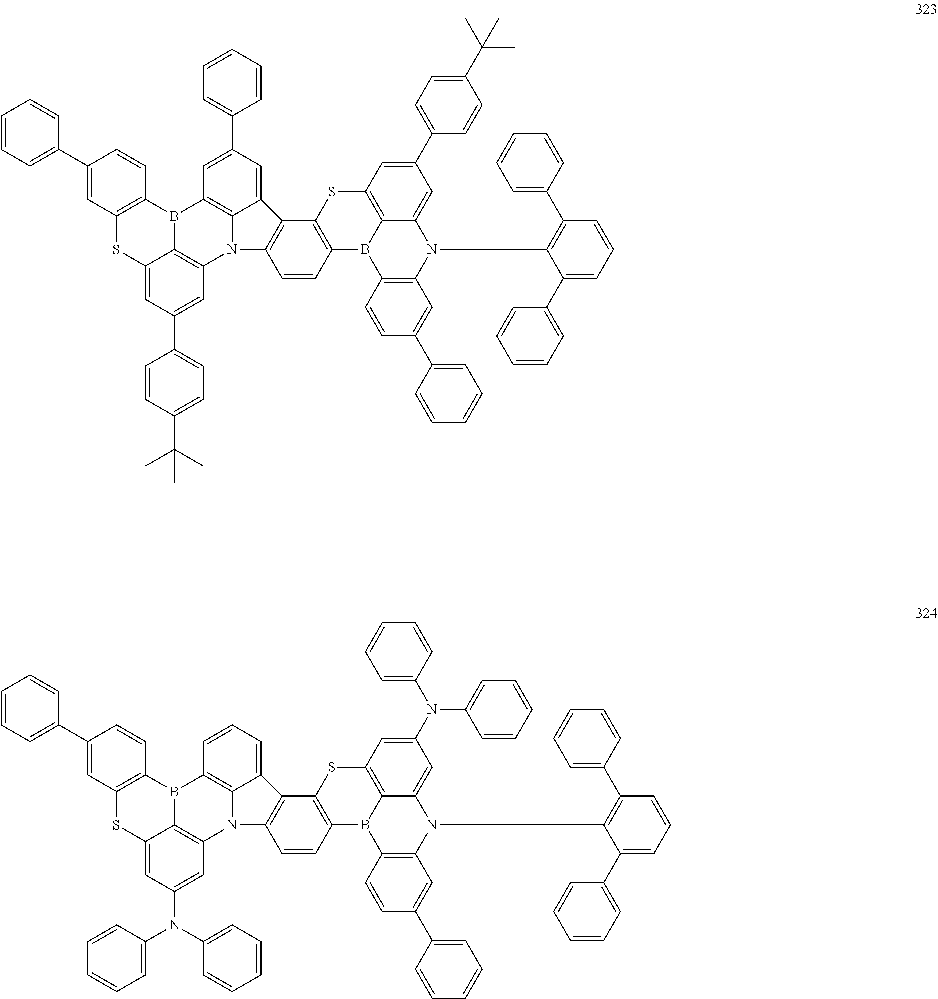 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2S3)c2cc(-c3ccccc3)cc3c2n4-c2cc(-c4ccc(C(C)(C)C)cc4)cc4c2B3c2ccc(-c3ccccc3)cc2S4)cc1 ; c1ccc(-c2ccc3c(c2)Sc2cc(N(c4ccccc4)c4ccccc4)cc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)S6)cc1] 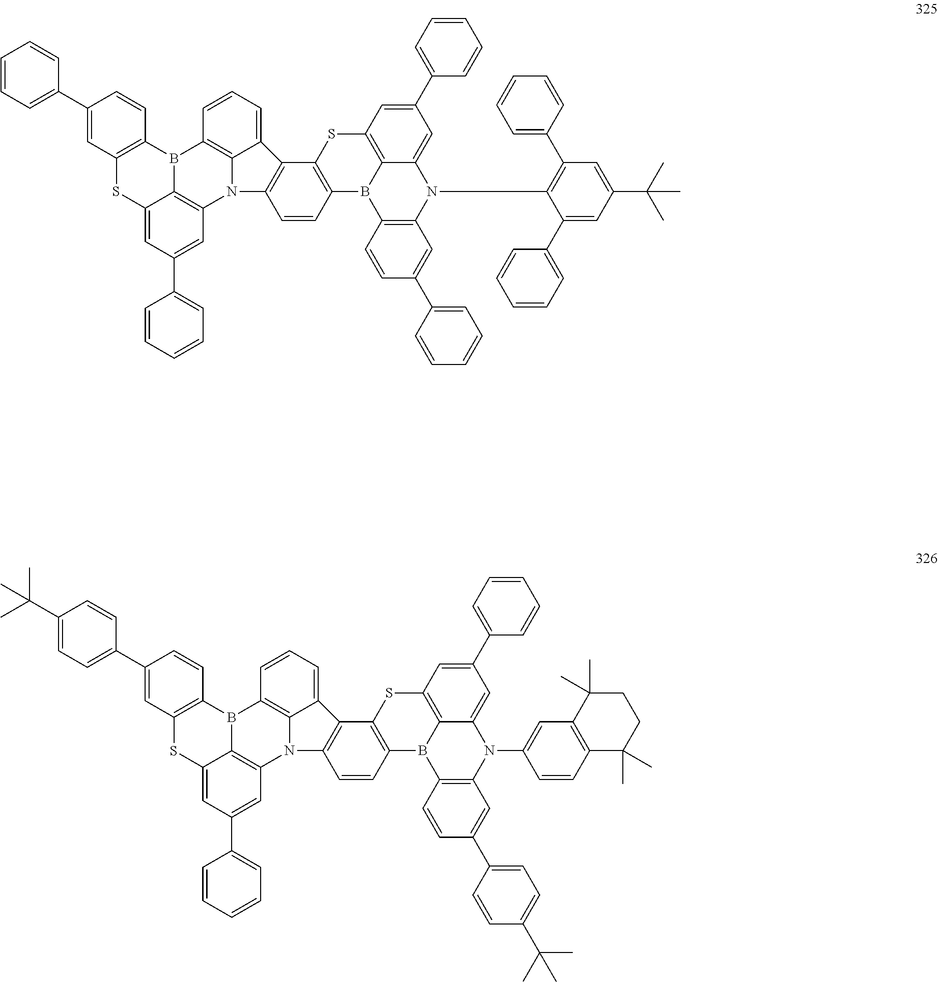 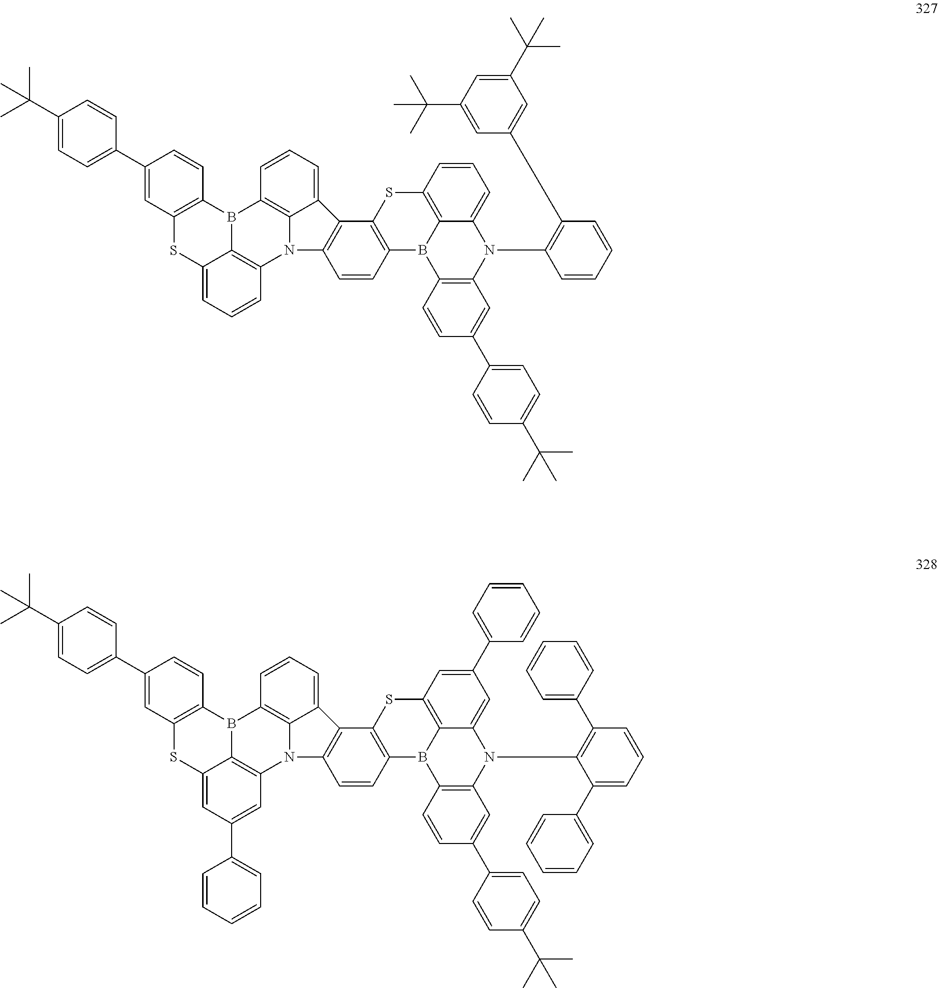 [SMILES: CC(C)(C)c1ccc(-c2ccc3c(c2)Sc2cccc4c2B3c2cccc3c5c6c(ccc5n-4c23)B2c3ccc(-c4ccc(C(C)(C)C)cc4)cc3N(c3ccccc3-c3cc(C(C)(C)C)cc(C(C)(C)C)c3)c3cccc(c32)S6)cc1 ; CC(C)(C)c1ccc(-c2ccc3c(c2)Sc2cc(-c4ccccc4)cc4c2B3c2cccc3c5c6c(ccc5n-4c23)B2c3ccc(-c4ccc(C(C)(C)C)cc4)cc3N(c3c(-c4ccccc4)cccc3-c3ccccc3)c3cc(-c4ccccc4)cc(c32)S6)cc1] 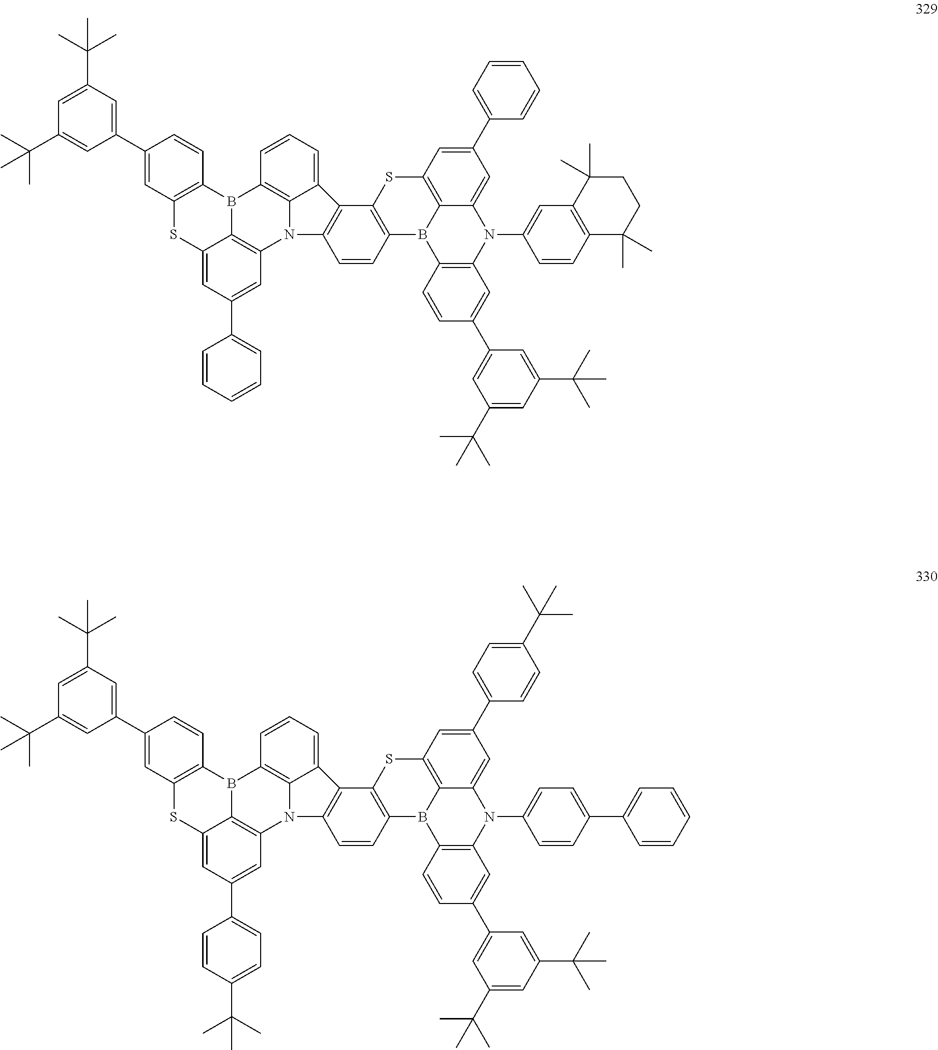 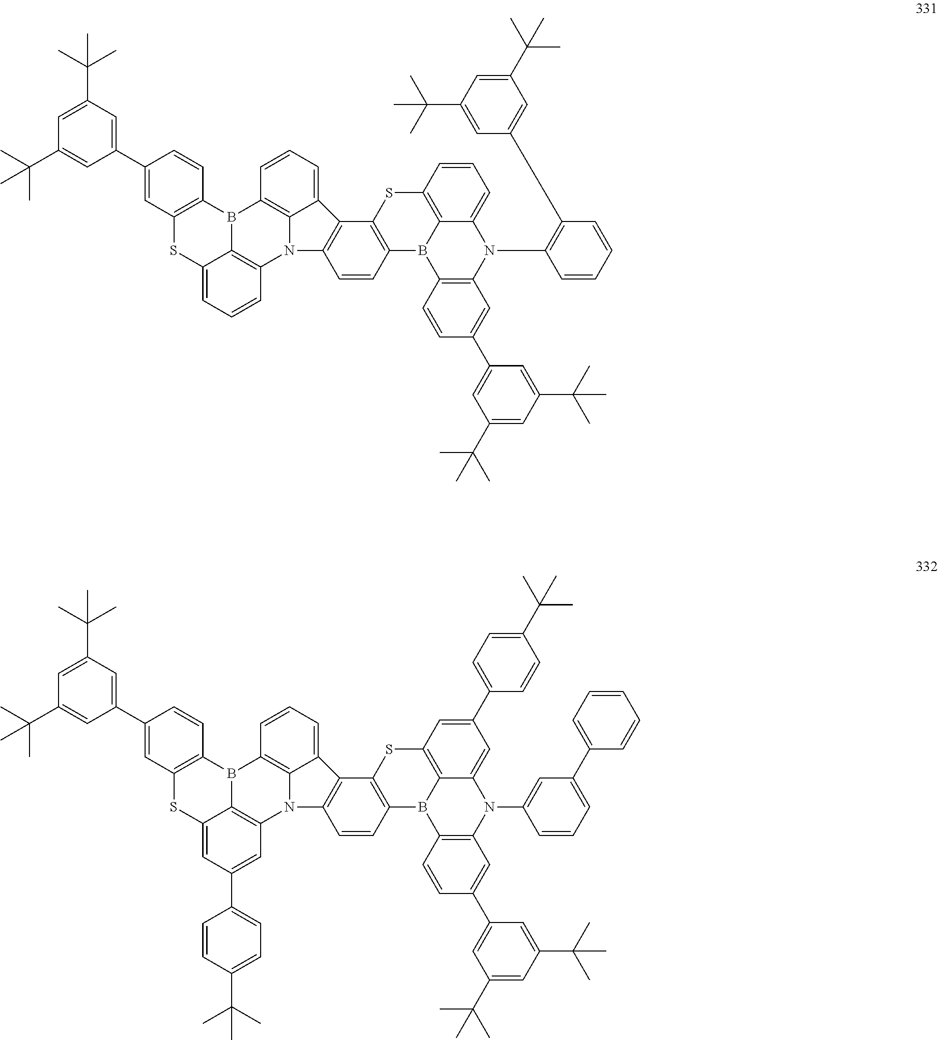 [SMILES: CC(C)(C)c1cc(-c2ccc3c(c2)Sc2cccc4c2B3c2cccc3c5c6c(ccc5n-4c23)B2c3ccc(-c4cc(C(C)(C)C)cc(C(C)(C)C)c4)cc3N(c3ccccc3-c3cc(C(C)(C)C)cc(C(C)(C)C)c3)c3cccc(c32)S6)cc(C(C)(C)C)c1 ; CC(C)(C)c1ccc(-c2cc3c4c(c2)N(c2cccc(-c5ccccc5)c2)c2cc(-c5cc(C(C)(C)C)cc(C(C)(C)C)c5)ccc2B4c2ccc4c(c2S3)c2cccc3c2n4-c2cc(-c4ccc(C(C)(C)C)cc4)cc4c2B3c2ccc(-c3cc(C(C)(C)C)cc(C(C)(C)C)c3)cc2S4)cc1] 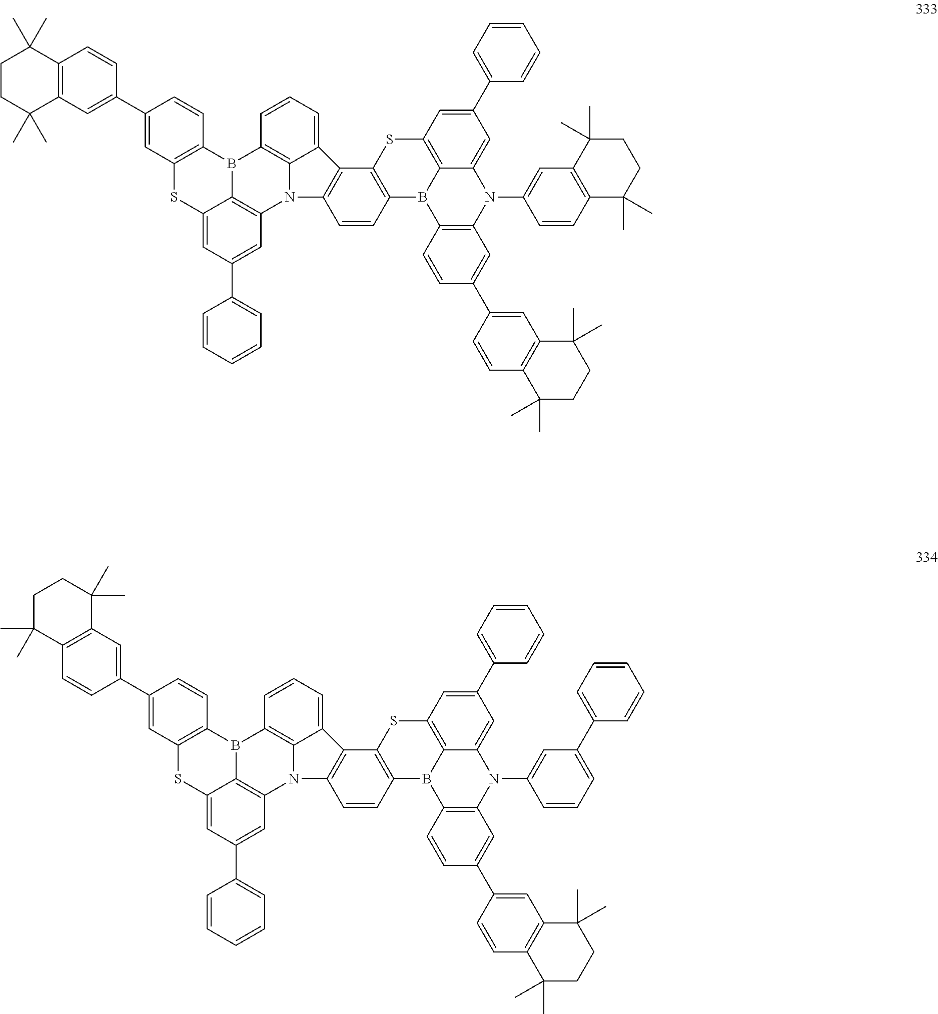 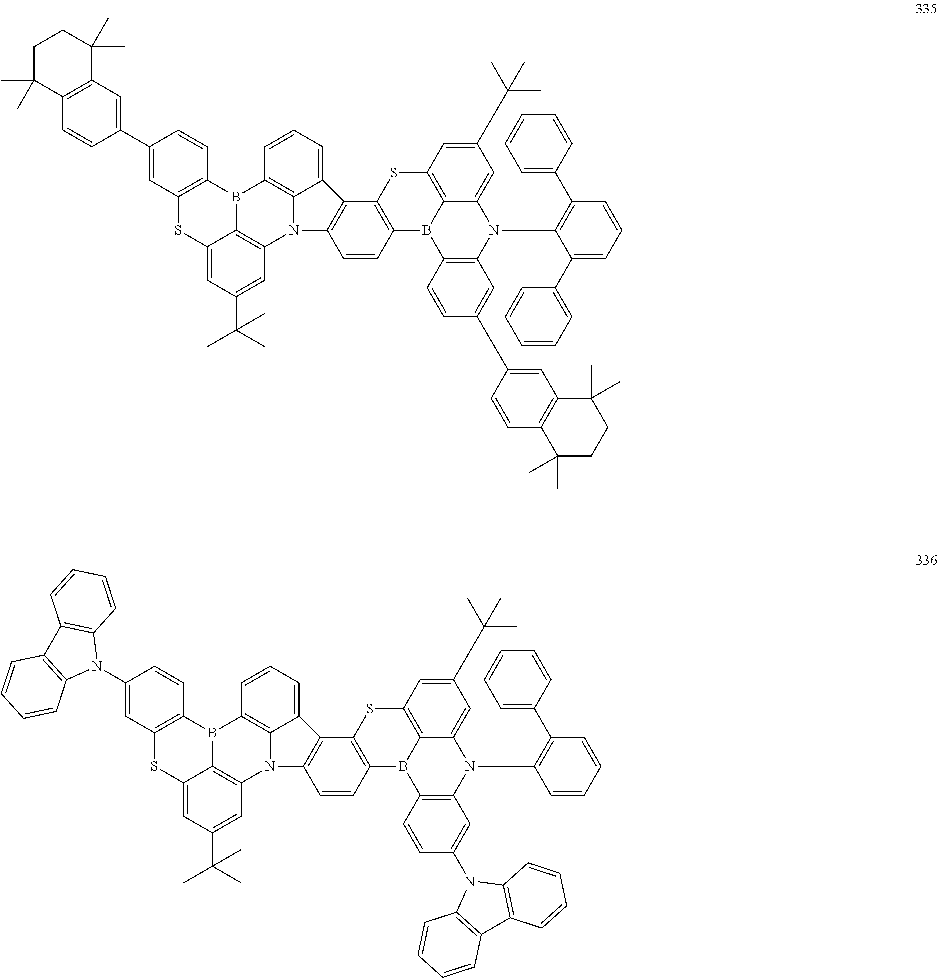 [SMILES: CC(C)(C)c1cc2c3c(c1)N(c1c(-c4ccccc4)cccc1-c1ccccc1)c1cc(-c4ccc5c(c4)C(C)(C)CCC5(C)C)ccc1B3c1ccc3c(c1S2)c1cccc2c1n3-c1cc(C(C)(C)C)cc3c1B2c1ccc(-c2ccc4c(c2)C(C)(C)CCC4(C)C)cc1S3 ; CC(C)(C)c1cc2c3c(c1)N(c1ccccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 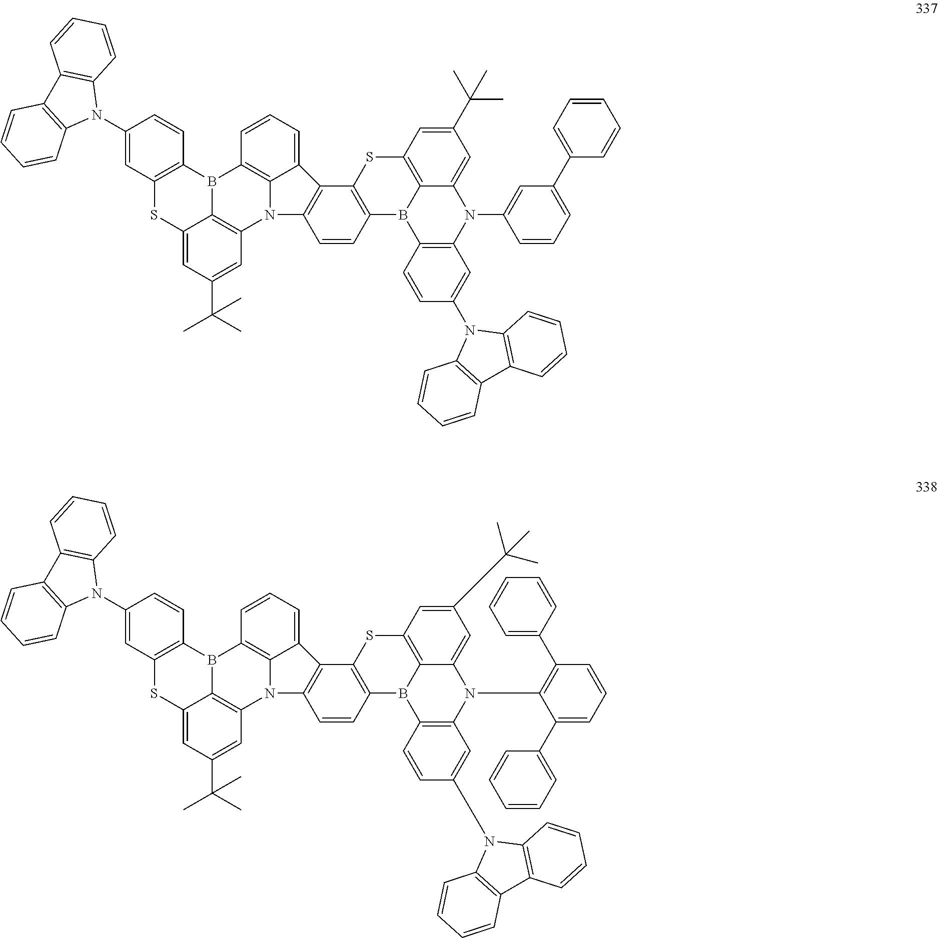 [SMILES: CC(C)(C)c1cc2c3c(c1)N(c1cccc(-c4ccccc4)c1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3 ; CC(C)(C)c1cc2c3c(c1)N(c1c(-c4ccccc4)cccc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 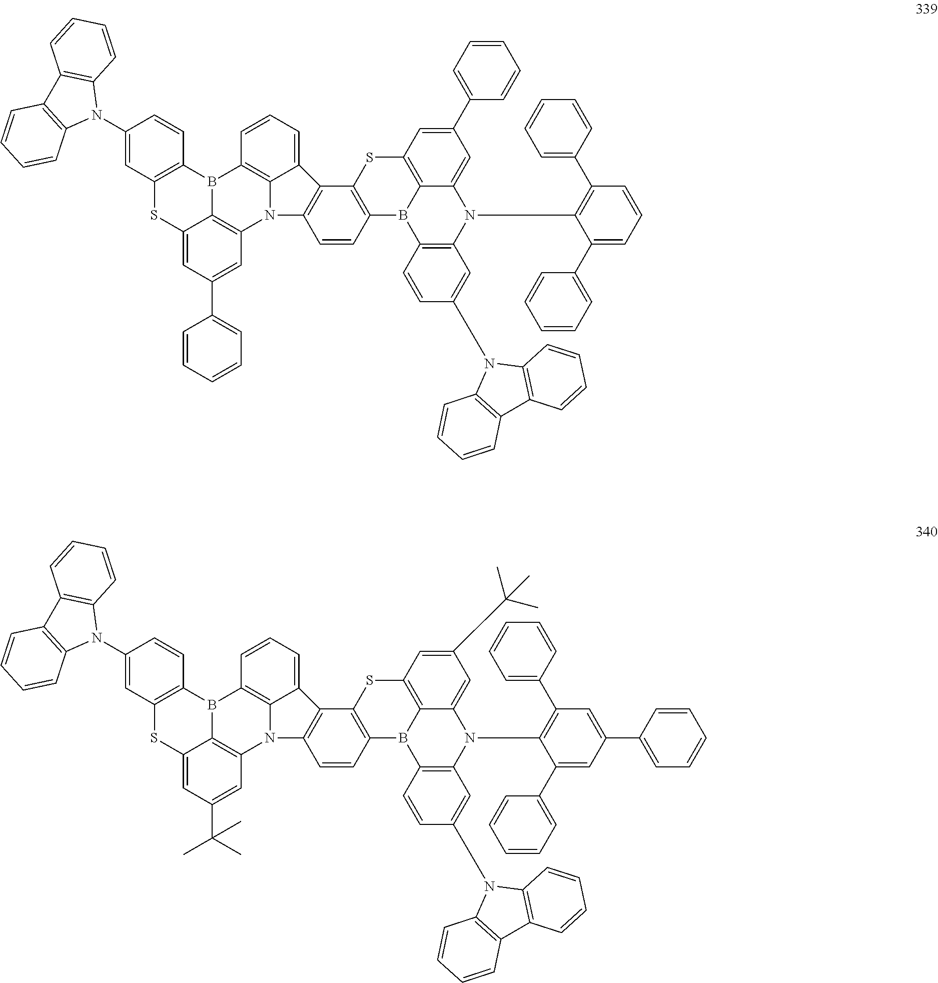 [SMILES: c1ccc(-c2cc3c4c(c2)N(c2c(-c5ccccc5)cccc2-c2ccccc2)c2cc(-n5c6ccccc6c6ccccc65)ccc2B4c2ccc4c(c2S3)c2cccc3c2n4-c2cc(-c4ccccc4)cc4c2B3c2ccc(-n3c5ccccc5c5ccccc53)cc2S4)cc1 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc3c(c1S2)c1cccc2c1n3-c1cc(C(C)(C)C)cc3c1B2c1ccc(-n2c4ccccc4c4ccccc42)cc1S3] 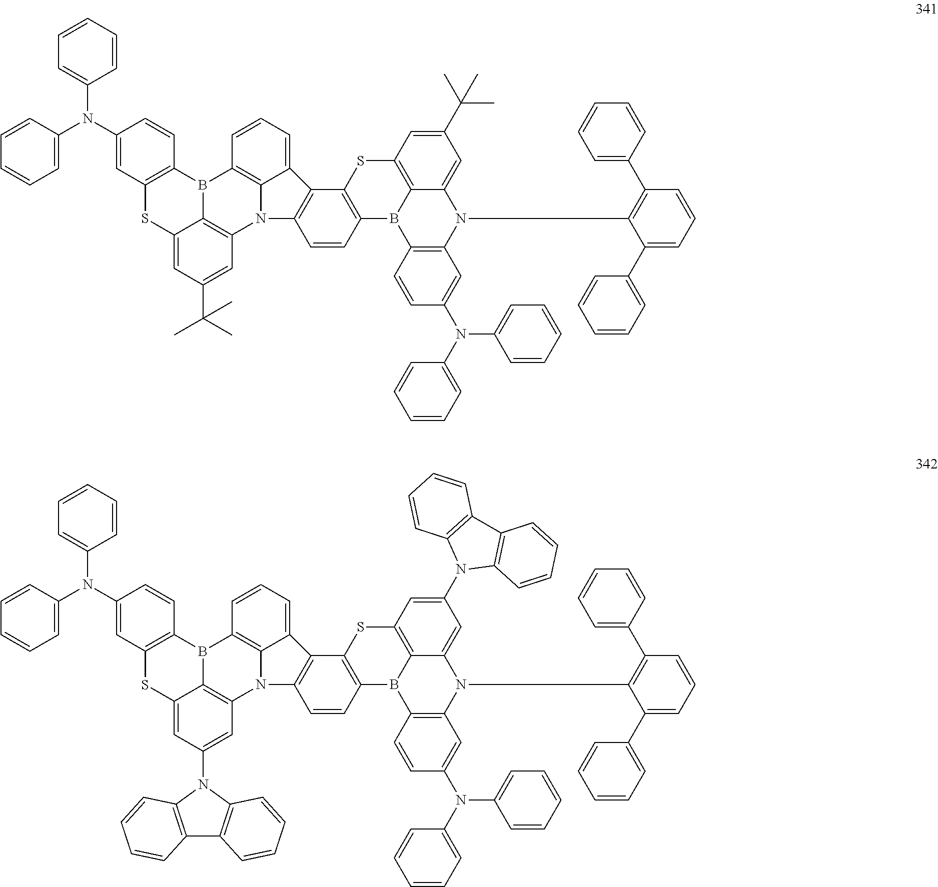 [SMILES: CC(C)(C)c1cc2c3c(c1)N(c1c(-c4ccccc4)cccc1-c1ccccc1)c1cc(N(c4ccccc4)c4ccccc4)ccc1B3c1ccc3c(c1S2)c1cccc2c1n3-c1cc(C(C)(C)C)cc3c1B2c1ccc(N(c2ccccc2)c2ccccc2)cc1S3 ; c1ccc(-c2cccc(-c3ccccc3)c2N2c3cc(N(c4ccccc4)c4ccccc4)ccc3B3c4ccc5c(c4Sc4cc(-n6c7ccccc7c7ccccc76)cc2c43)c2cccc3c2n5-c2cc(-n4c5ccccc5c5ccccc54)cc4c2B3c2ccc(N(c3ccccc3)c3ccccc3)cc2S4)cc1] 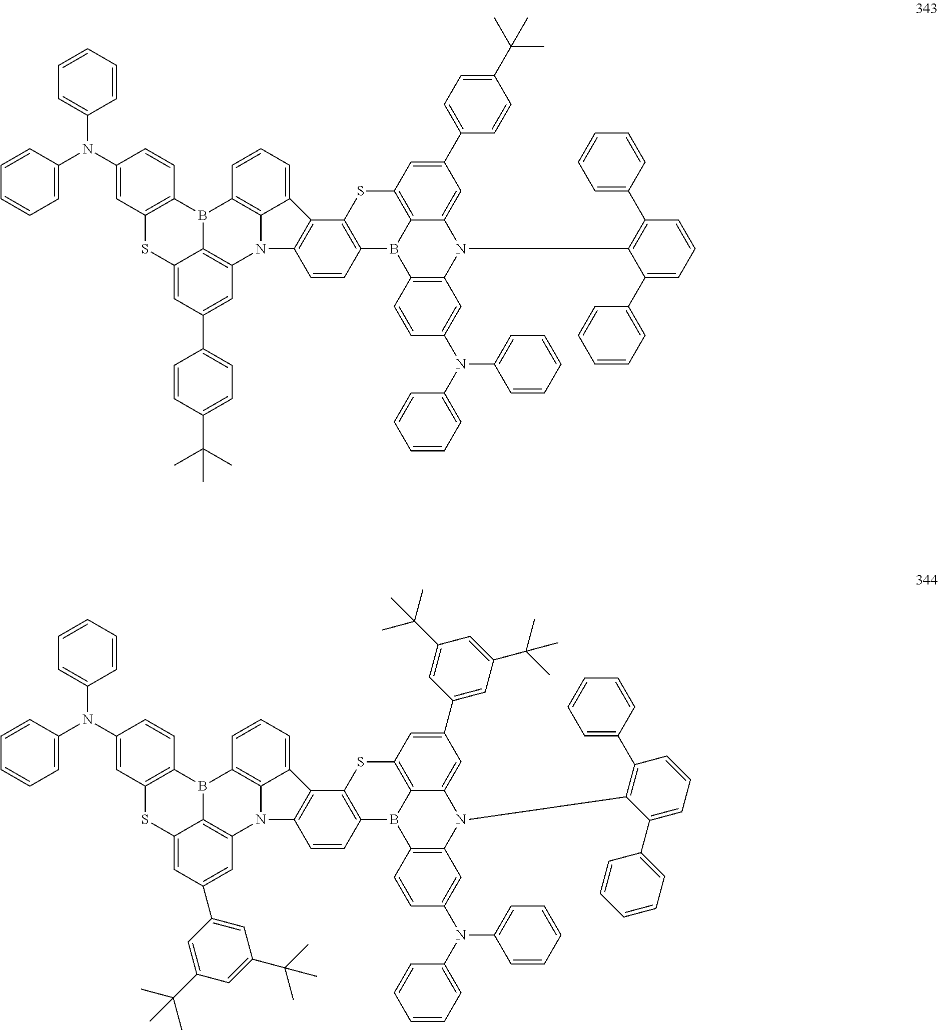 [SMILES: CC(C)(C)c1ccc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4ccc(C(C)(C)C)cc4)cc4c2B3c2ccc(N(c3ccccc3)c3ccccc3)cc2S4)cc1 ; CC(C)(C)c1cc(-c2cc3c4c(c2)N(c2c(-c5ccccc5)cccc2-c2ccccc2)c2cc(N(c5ccccc5)c5ccccc5)ccc2B4c2ccc4c(c2S3)c2cccc3c2n4-c2cc(-c4cc(C(C)(C)C)cc(C(C)(C)C)c4)cc4c2B3c2ccc(N(c3ccccc3)c3ccccc3)cc2S4)cc(C(C)(C)C)c1] 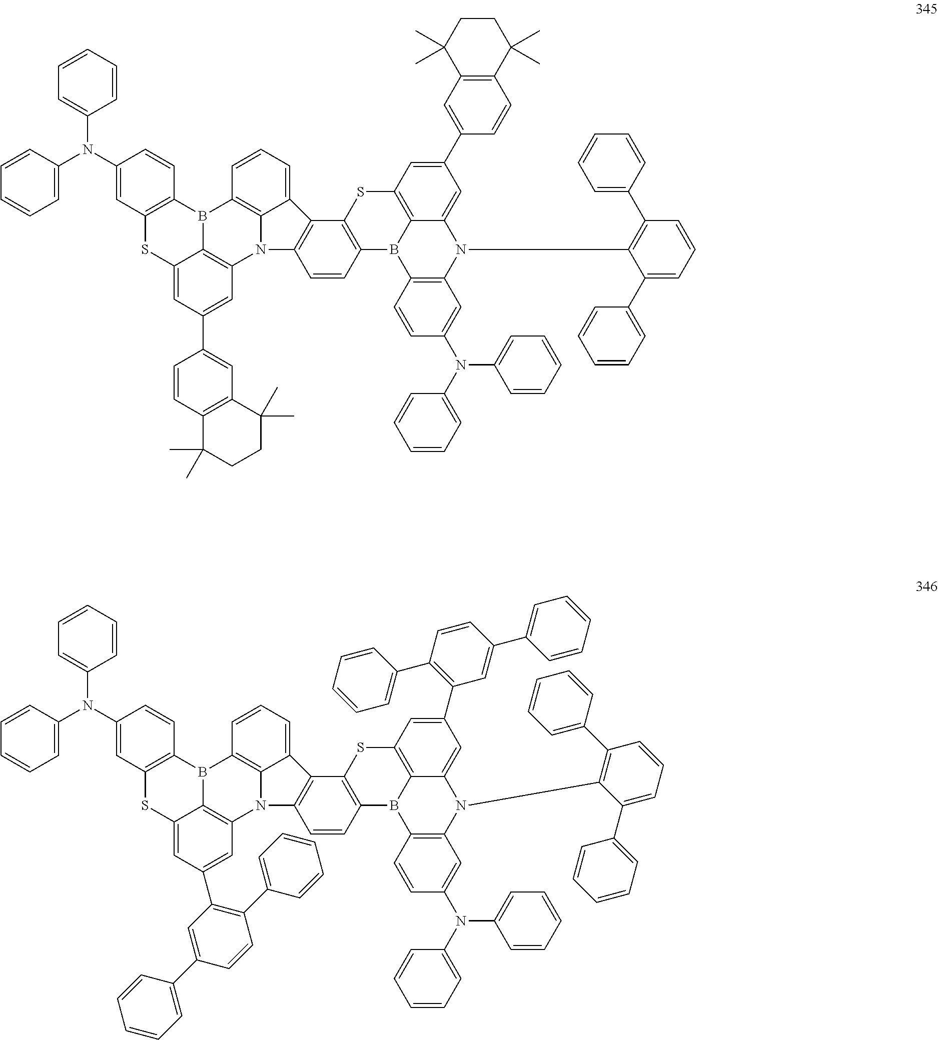 [SMILES: CC1(C)CCC(C)(C)c2cc(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5ccc6c(c5)C(C)(C)CCC6(C)C)cc5c3B4c3ccc(N(c4ccccc4)c4ccccc4)cc3S5)ccc21 ; c1ccc(-c2ccc(-c3ccccc3)c(-c3cc4c5c(c3)N(c3c(-c6ccccc6)cccc3-c3ccccc3)c3cc(N(c6ccccc6)c6ccccc6)ccc3B5c3ccc5c(c3S4)c3cccc4c3n5-c3cc(-c5cc(-c6ccccc6)ccc5-c5ccccc5)cc5c3B4c3ccc(N(c4ccccc4)c4ccccc4)cc3S5)c2)cc1] 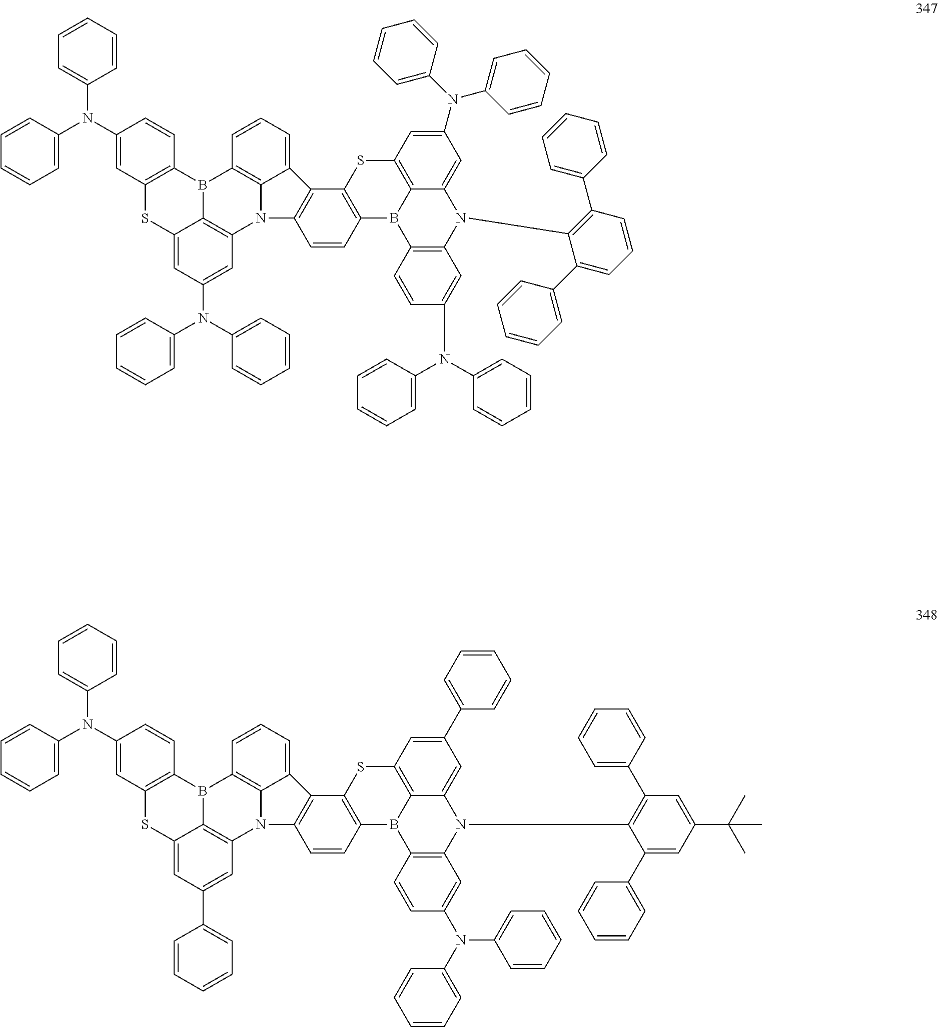 [SMILES: c1ccc(-c2cccc(-c3ccccc3)c2N2c3cc(N(c4ccccc4)c4ccccc4)ccc3B3c4ccc5c(c4Sc4cc(N(c6ccccc6)c6ccccc6)cc2c43)c2cccc3c2n5-c2cc(N(c4ccccc4)c4ccccc4)cc4c2B3c2ccc(N(c3ccccc3)c3ccccc3)cc2S4)cc1 ; CC(C)(C)c1cc(-c2ccccc2)c(N2c3cc(N(c4ccccc4)c4ccccc4)ccc3B3c4ccc5c(c4Sc4cc(-c6ccccc6)cc2c43)c2cccc3c2n5-c2cc(-c4ccccc4)cc4c2B3c2ccc(N(c3ccccc3)c3ccccc3)cc2S4)c(-c2ccccc2)c1] 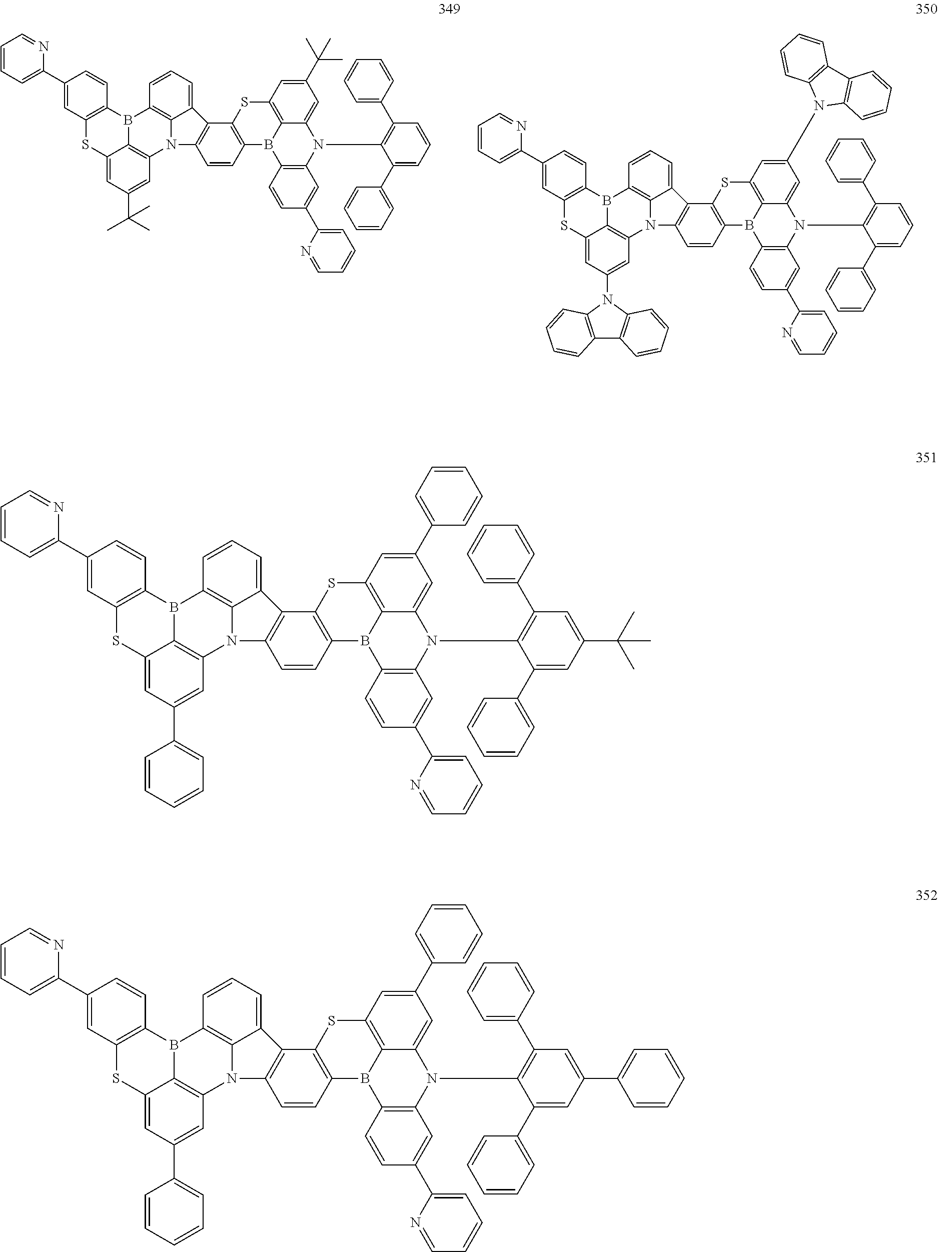 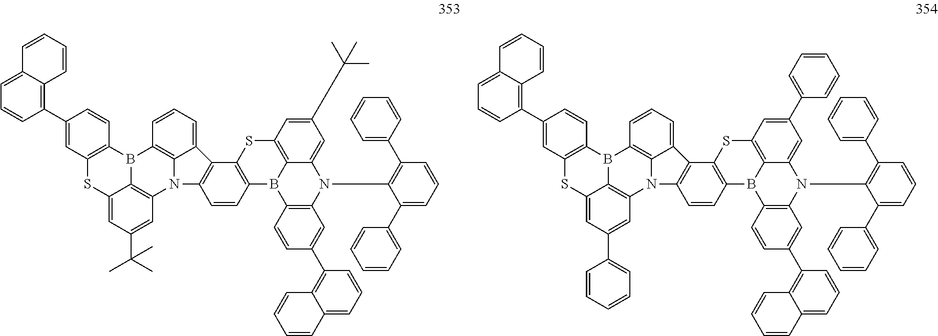 [SMILES: CC(C)(C)c1cc2c3c(c1)N(c1c(-c4ccccc4)cccc1-c1ccccc1)c1cc(-c4cccc5ccccc45)ccc1B3c1ccc3c(c1S2)c1cccc2c1n3-c1cc(C(C)(C)C)cc3c1B2c1ccc(-c2cccc4ccccc24)cc1S3 ; c1ccc(-c2cc3c4c(c2)N(c2c(-c5ccccc5)cccc2-c2ccccc2)c2cc(-c5cccc6ccccc56)ccc2B4c2ccc4c(c2S3)c2cccc3c2n4-c2cc(-c4ccccc4)cc4c2B3c2ccc(-c3cccc5ccccc35)cc2S4)cc1] 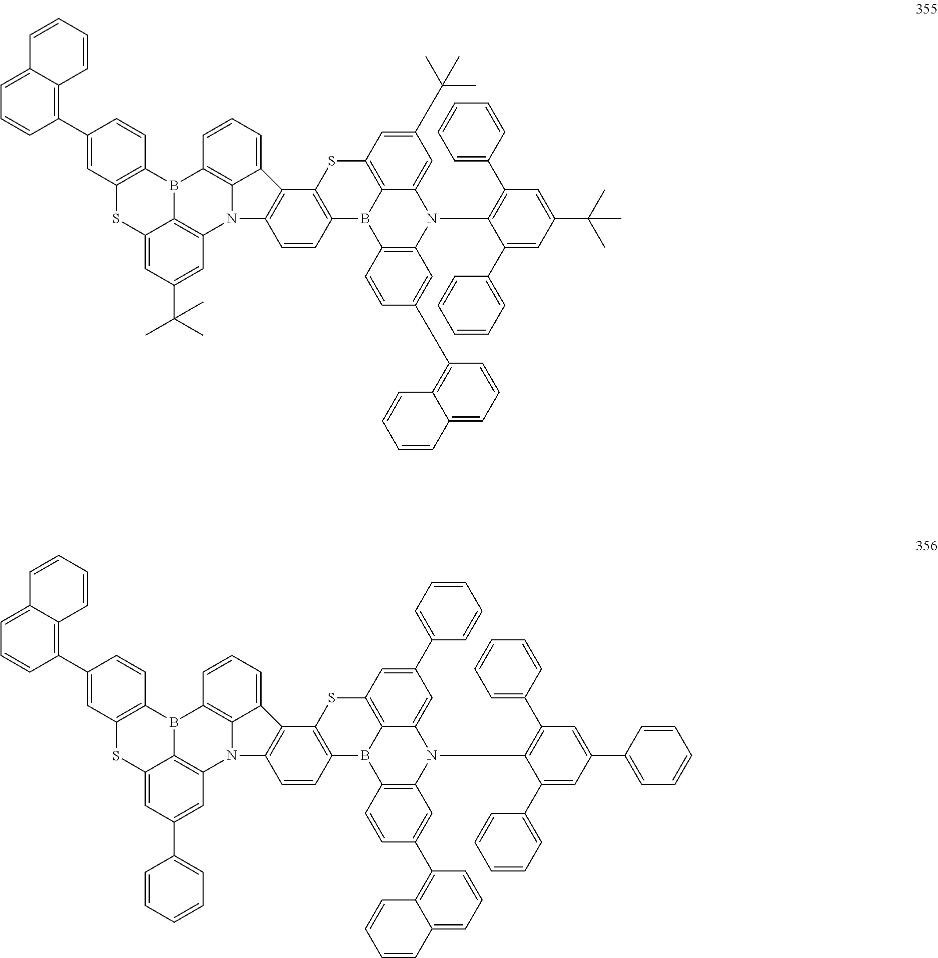 [SMILES: CC(C)(C)c1cc(-c2ccccc2)c(N2c3cc(-c4cccc5ccccc45)ccc3B3c4ccc5c(c4Sc4cc(C(C)(C)C)cc2c43)c2cccc3c2n5-c2cc(C(C)(C)C)cc4c2B3c2ccc(-c3cccc5ccccc35)cc2S4)c(-c2ccccc2)c1 ; c1ccc(-c2cc(-c3ccccc3)c(N3c4cc(-c5cccc6ccccc56)ccc4B4c5ccc6c(c5Sc5cc(-c7ccccc7)cc3c54)c3cccc4c3n6-c3cc(-c5ccccc5)cc5c3B4c3ccc(-c4cccc6ccccc46)cc3S5)c(-c3ccccc3)c2)cc1] 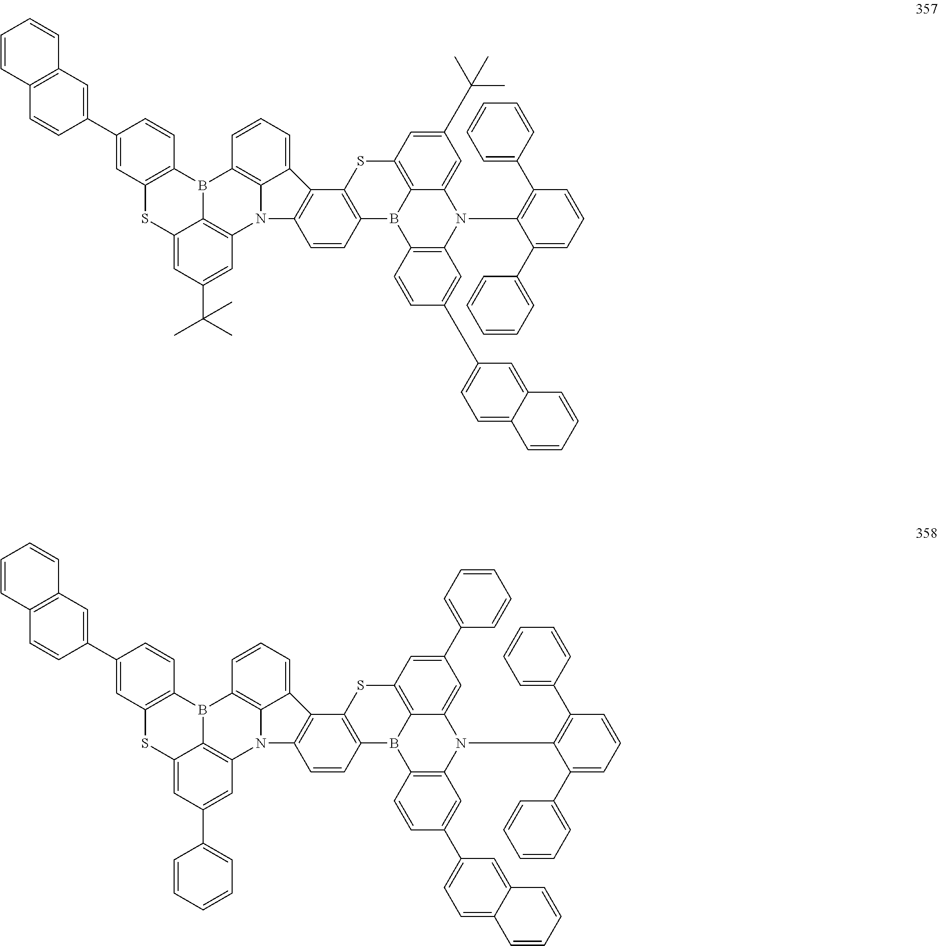 [SMILES: CC(C)(C)c1cc2c3c(c1)N(c1c(-c4ccccc4)cccc1-c1ccccc1)c1cc(-c4ccc5ccccc5c4)ccc1B3c1ccc3c(c1S2)c1cccc2c1n3-c1cc(C(C)(C)C)cc3c1B2c1ccc(-c2ccc4ccccc4c2)cc1S3 ; c1ccc(-c2cc3c4c(c2)N(c2c(-c5ccccc5)cccc2-c2ccccc2)c2cc(-c5ccc6ccccc6c5)ccc2B4c2ccc4c(c2S3)c2cccc3c2n4-c2cc(-c4ccccc4)cc4c2B3c2ccc(-c3ccc5ccccc5c3)cc2S4)cc1] 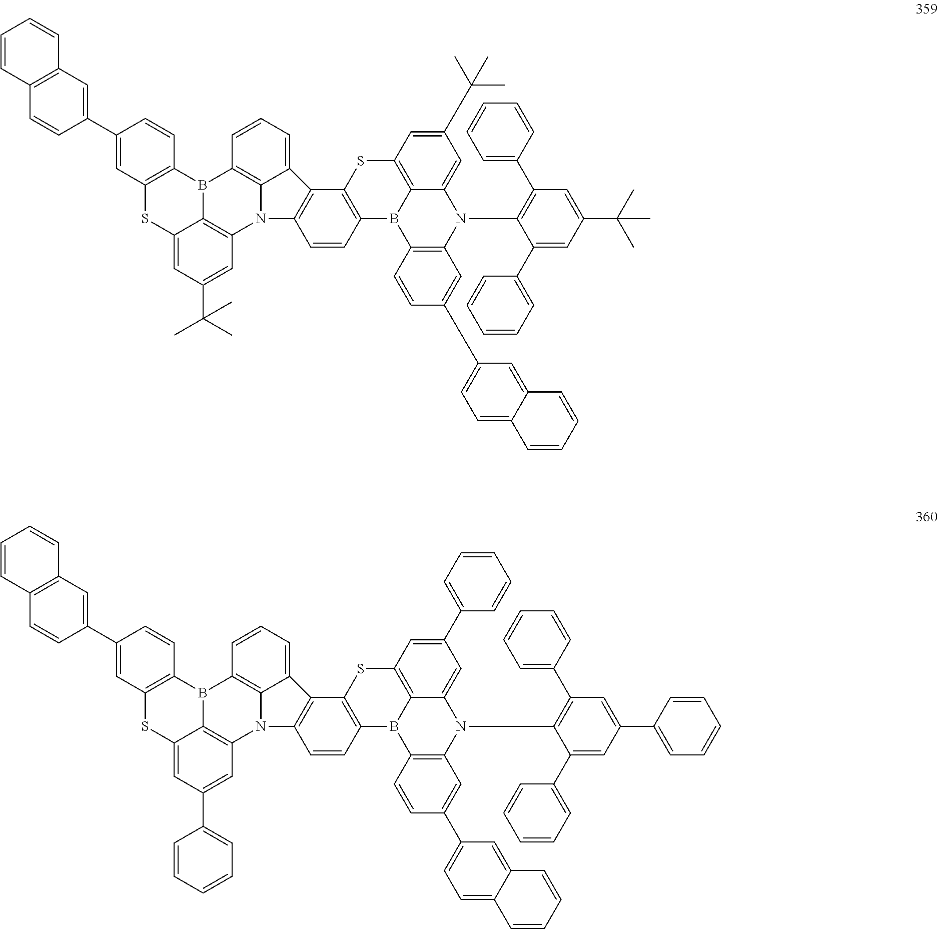 [SMILES: CC(C)(C)c1cc(-c2ccccc2)c(N2c3cc(-c4ccc5ccccc5c4)ccc3B3c4ccc5c(c4Sc4cc(C(C)(C)C)cc2c43)c2cccc3c2n5-c2cc(C(C)(C)C)cc4c2B3c2ccc(-c3ccc5ccccc5c3)cc2S4)c(-c2ccccc2)c1 ; c1ccc(-c2cc(-c3ccccc3)c(N3c4cc(-c5ccc6ccccc6c5)ccc4B4c5ccc6c(c5Sc5cc(-c7ccccc7)cc3c54)c3cccc4c3n6-c3cc(-c5ccccc5)cc5c3B4c3ccc(-c4ccc6ccccc6c4)cc3S5)c(-c3ccccc3)c2)cc1] 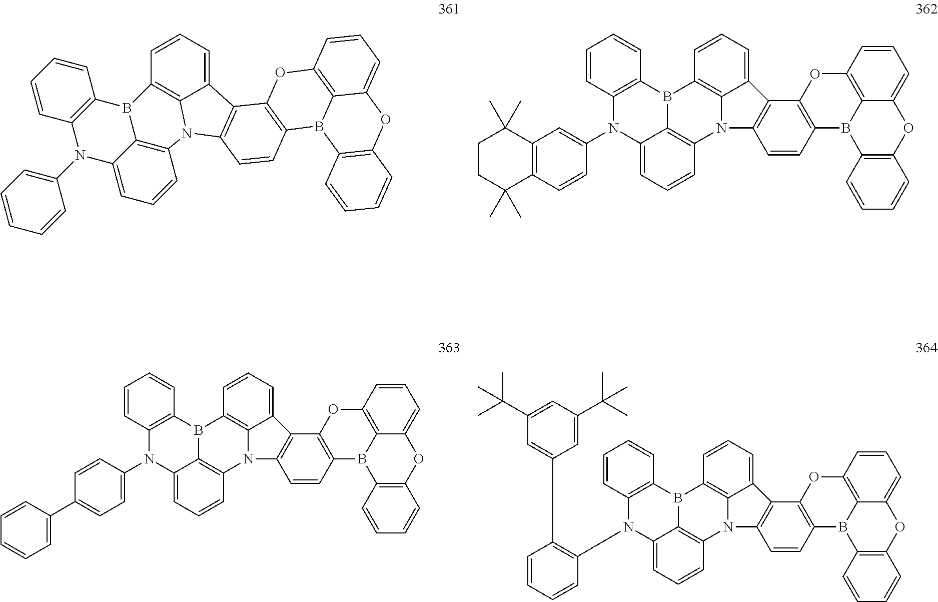 [SMILES: c1ccc(N2c3ccccc3B3c4c2cccc4-n2c4ccc5c(c4c4cccc3c42)Oc2cccc3c2B5c2ccccc2O3)cc1 ; CC1(C)CCC(C)(C)c2cc(N3c4ccccc4B4c5c3cccc5-n3c5ccc6c(c5c5cccc4c53)Oc3cccc4c3B6c3ccccc3O4)ccc21 ; c1ccc(-c2ccc(N3c4ccccc4B4c5c3cccc5-n3c5ccc6c(c5c5cccc4c53)Oc3cccc4c3B6c3ccccc3O4)cc2)cc1 ; CC(C)(C)c1cc(-c2ccccc2N2c3ccccc3B3c4c2cccc4-n2c4ccc5c(c4c4cccc3c42)Oc2cccc3c2B5c2ccccc2O3)cc(C(C)(C)C)c1] 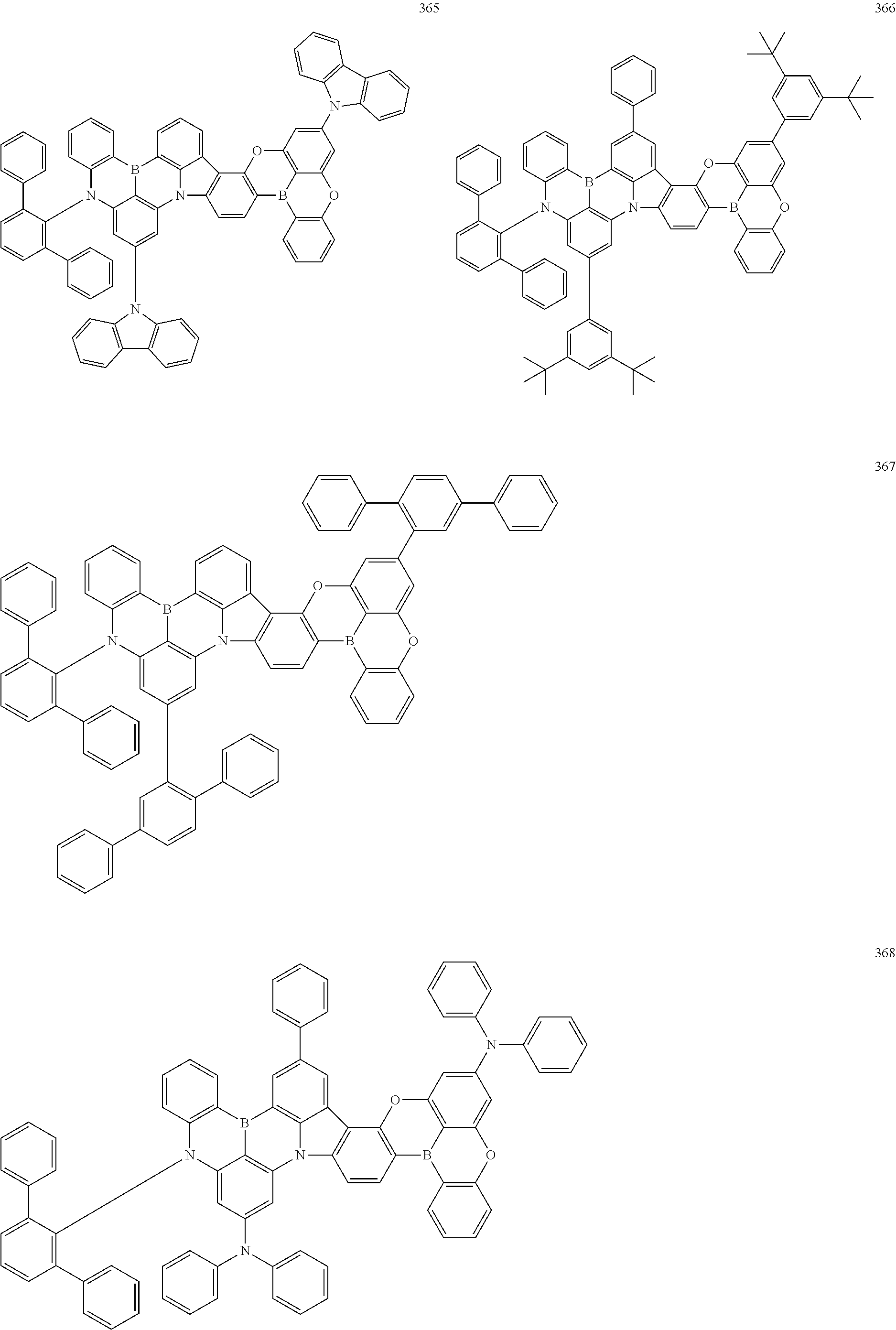 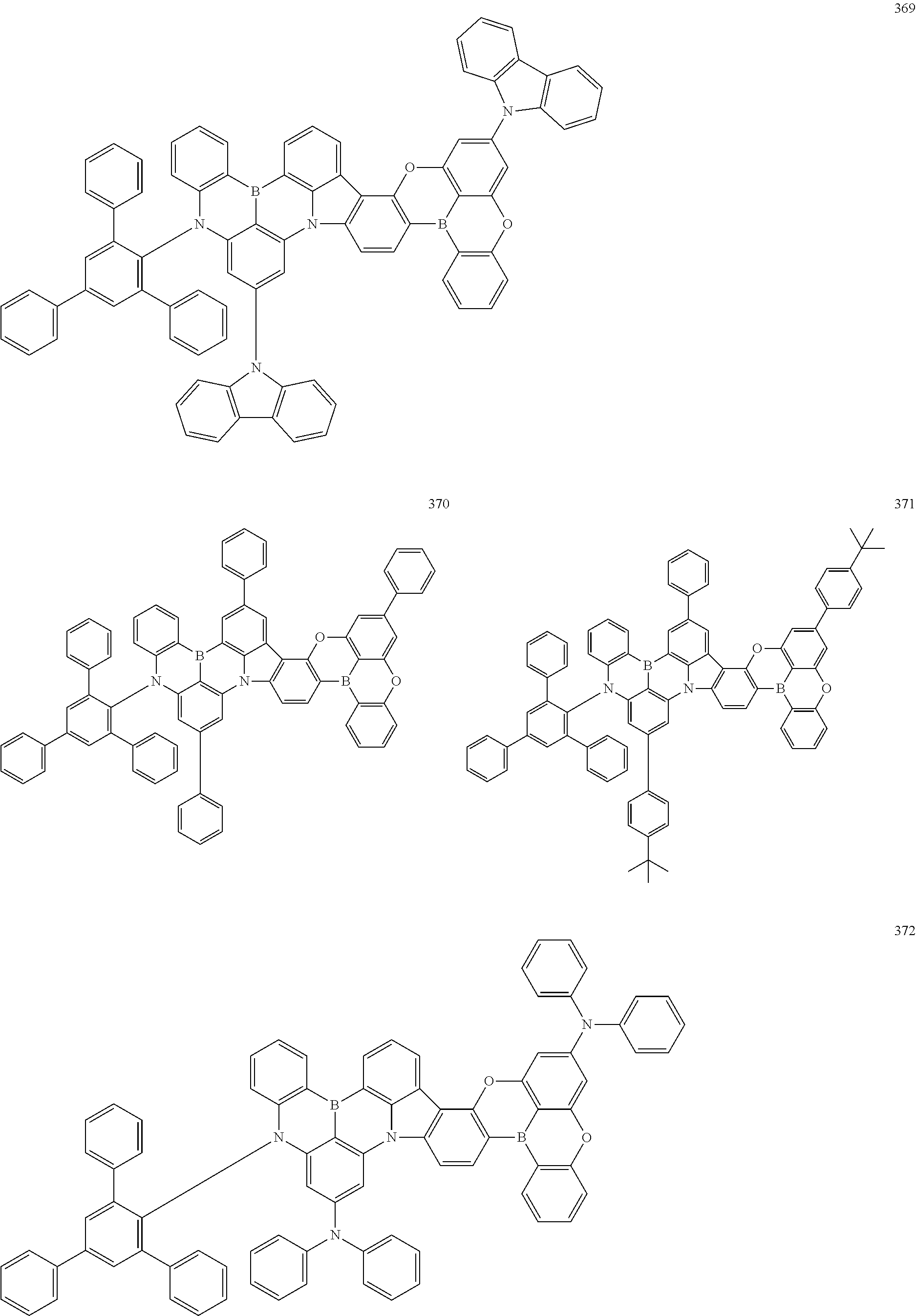 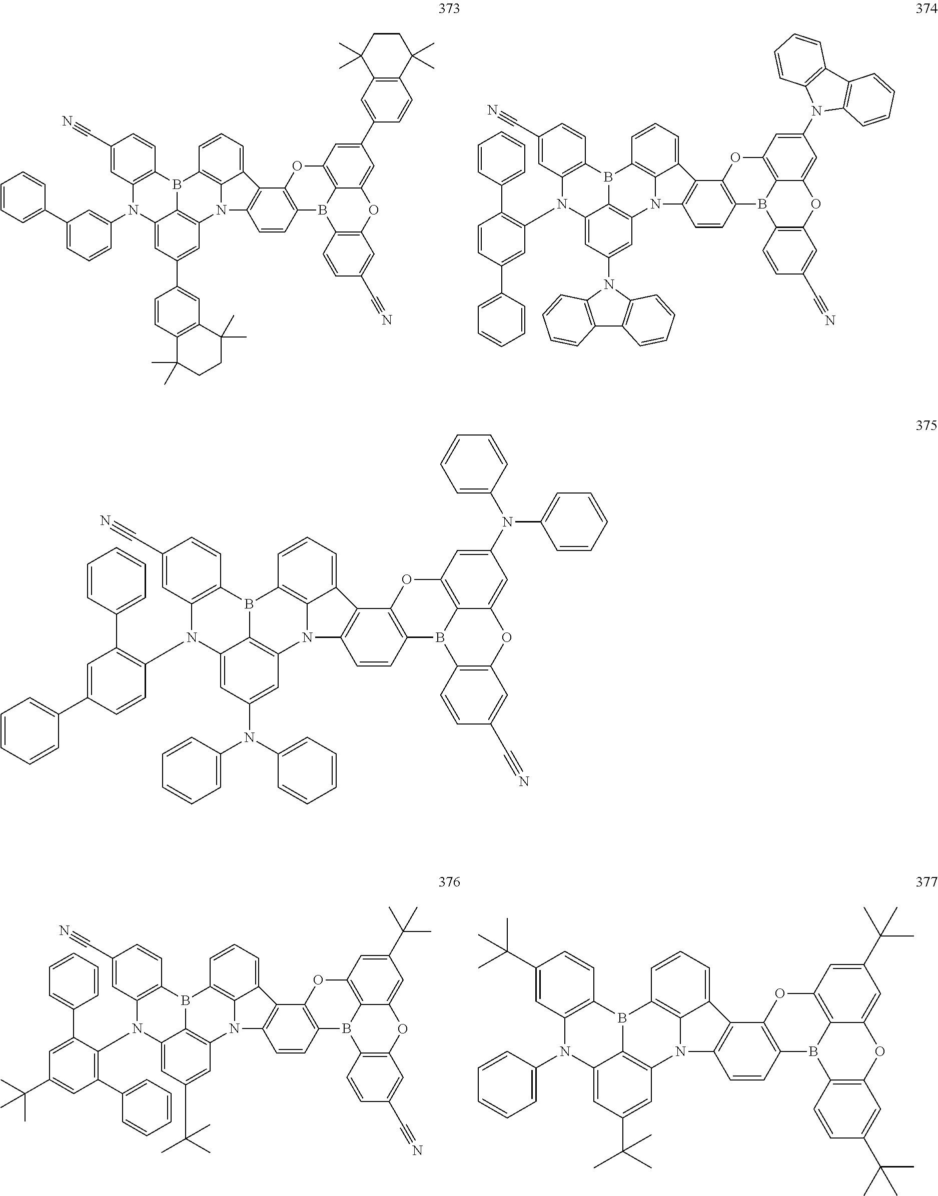 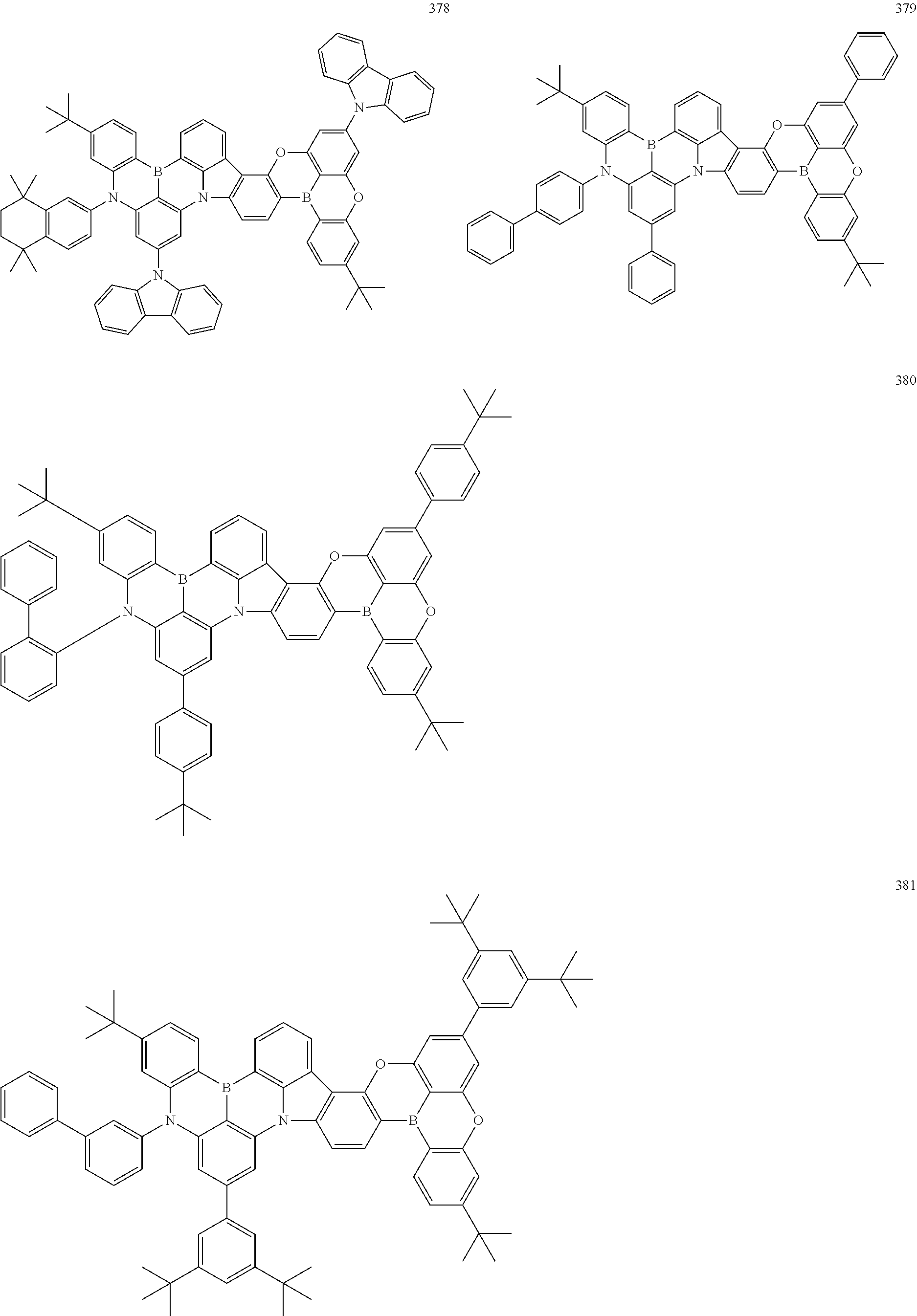 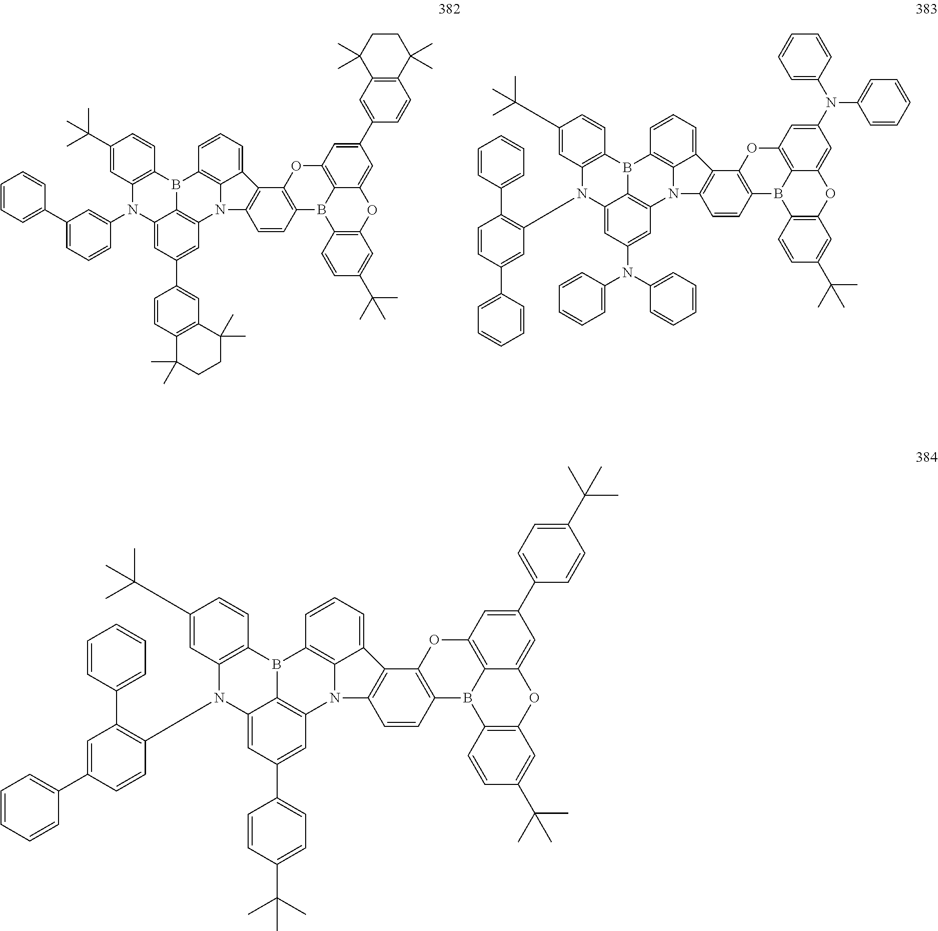 [SMILES: CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1N2c1cccc(-c2ccccc2)c1 ; CC(C)(C)c1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2N5c2ccc(-c5ccccc5)cc2-c2ccccc2)B4c2ccc(C(C)(C)C)cc2O3)cc1] 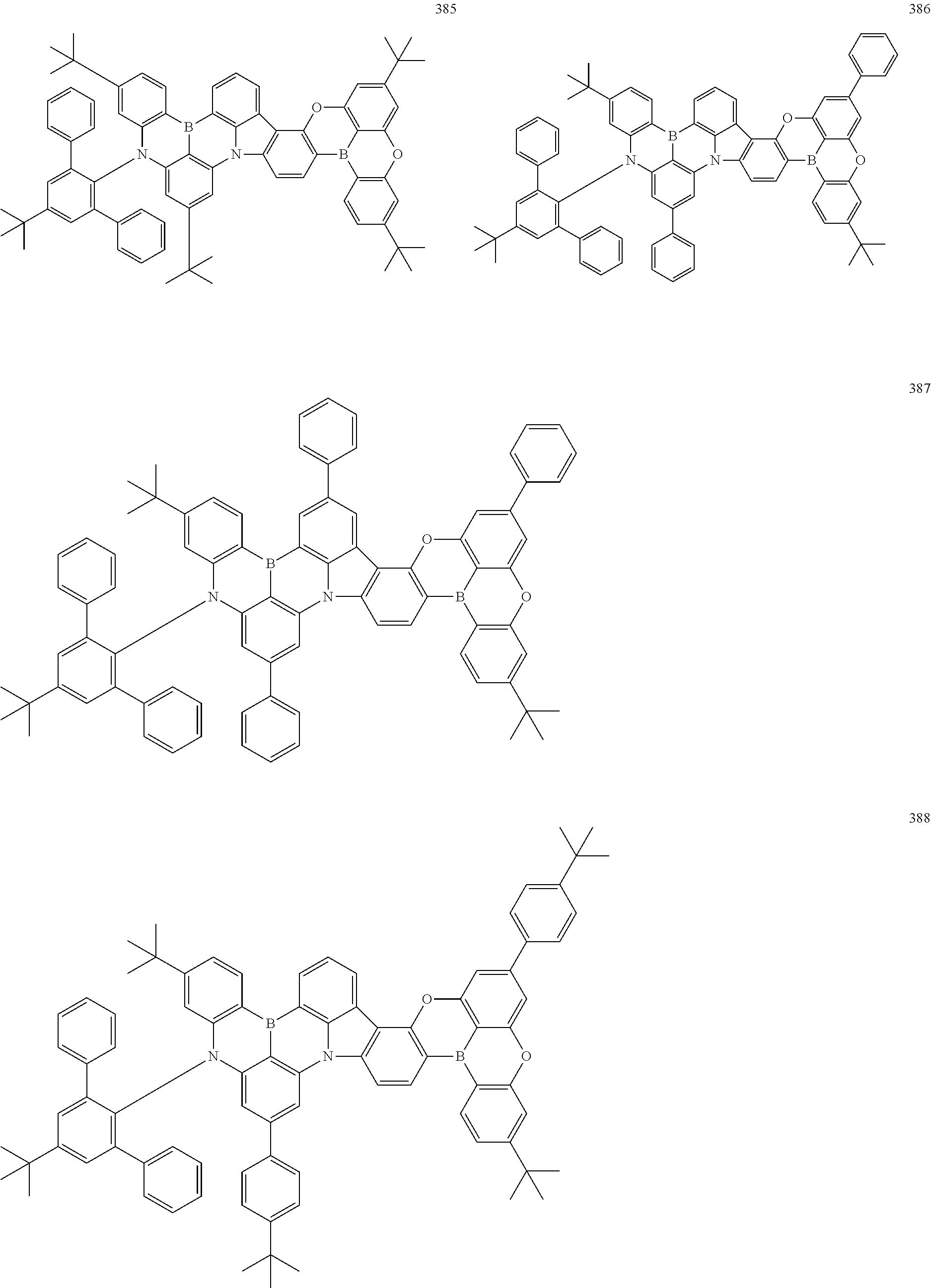 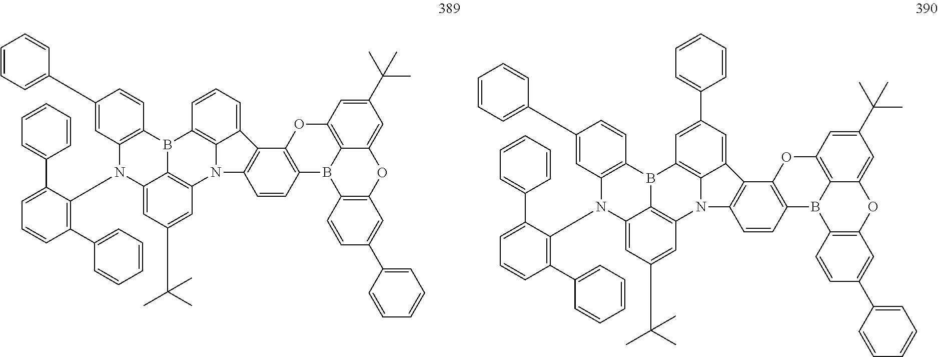 [SMILES: CC(C)(C)c1cc2c3c(c1)Oc1c(ccc4c1c1cccc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1O2] 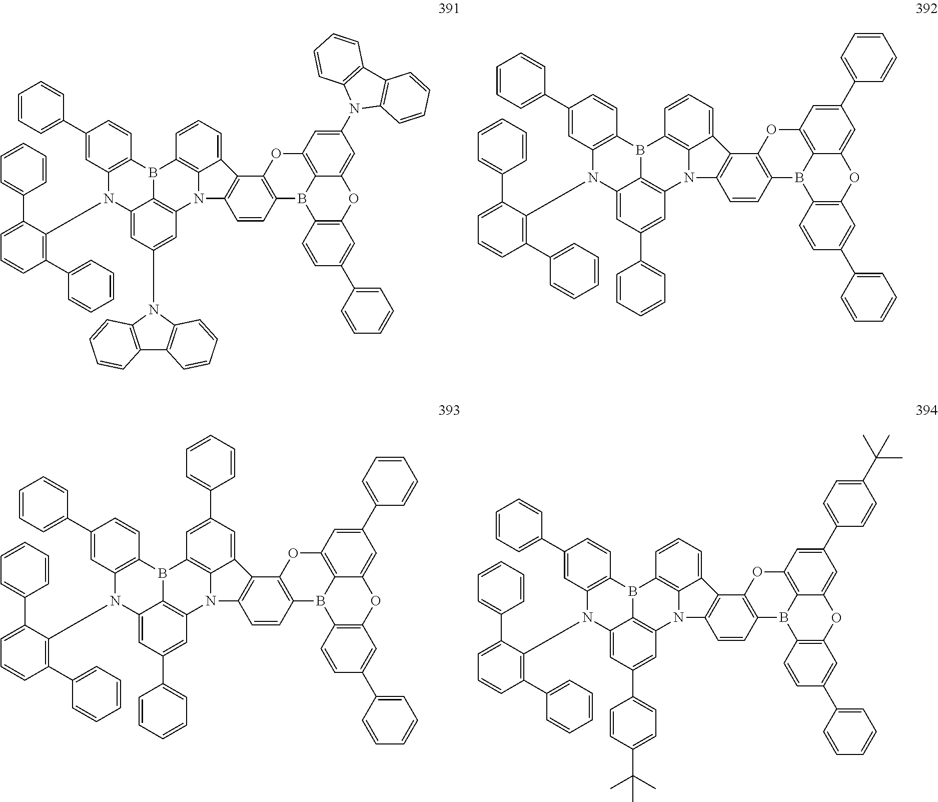 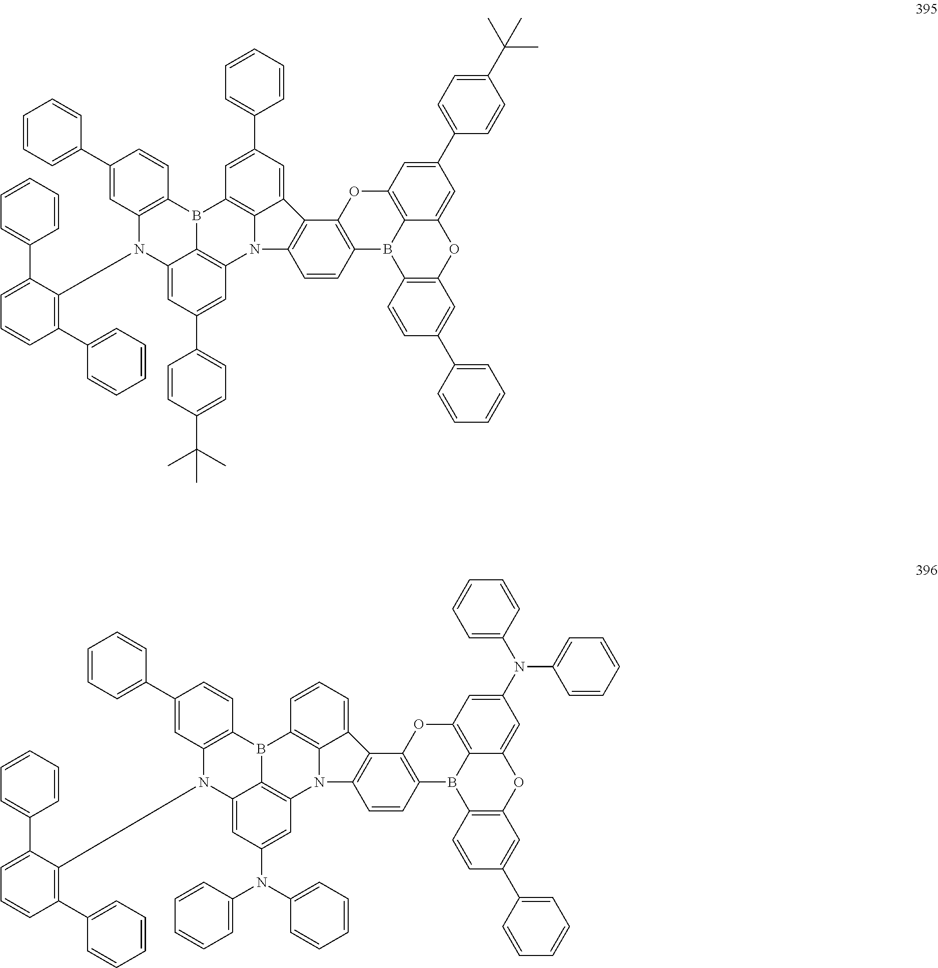 [SMILES: CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2O3)cc1 ; c1ccc(-c2ccc3c(c2)Oc2cc(N(c4ccccc4)c4ccccc4)cc4c2B3c2ccc3c(c2O4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 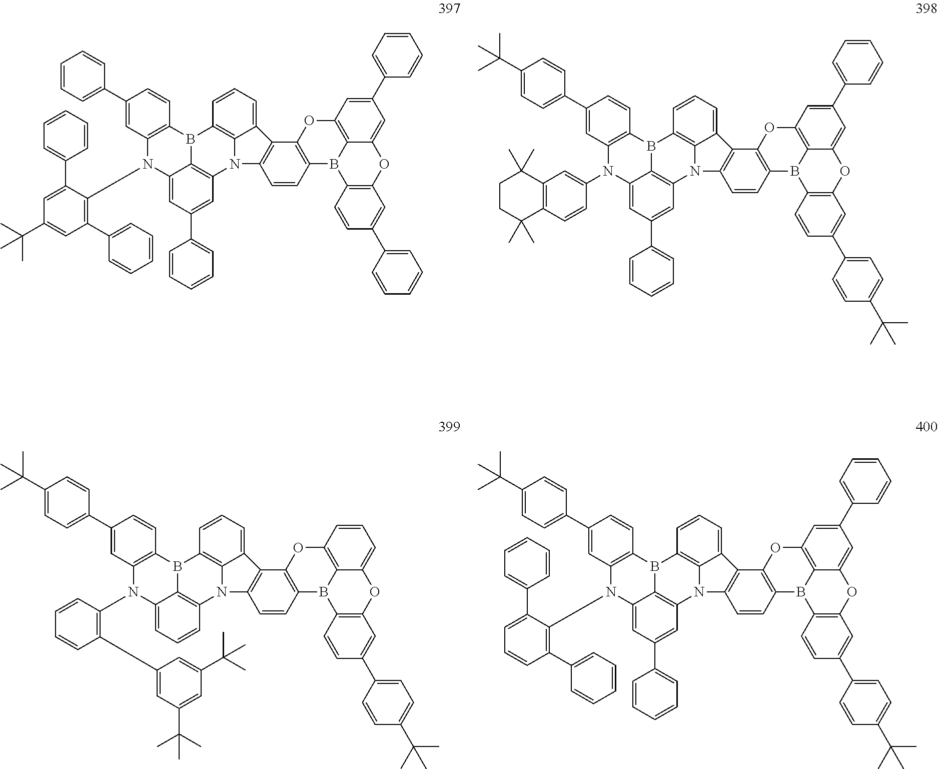 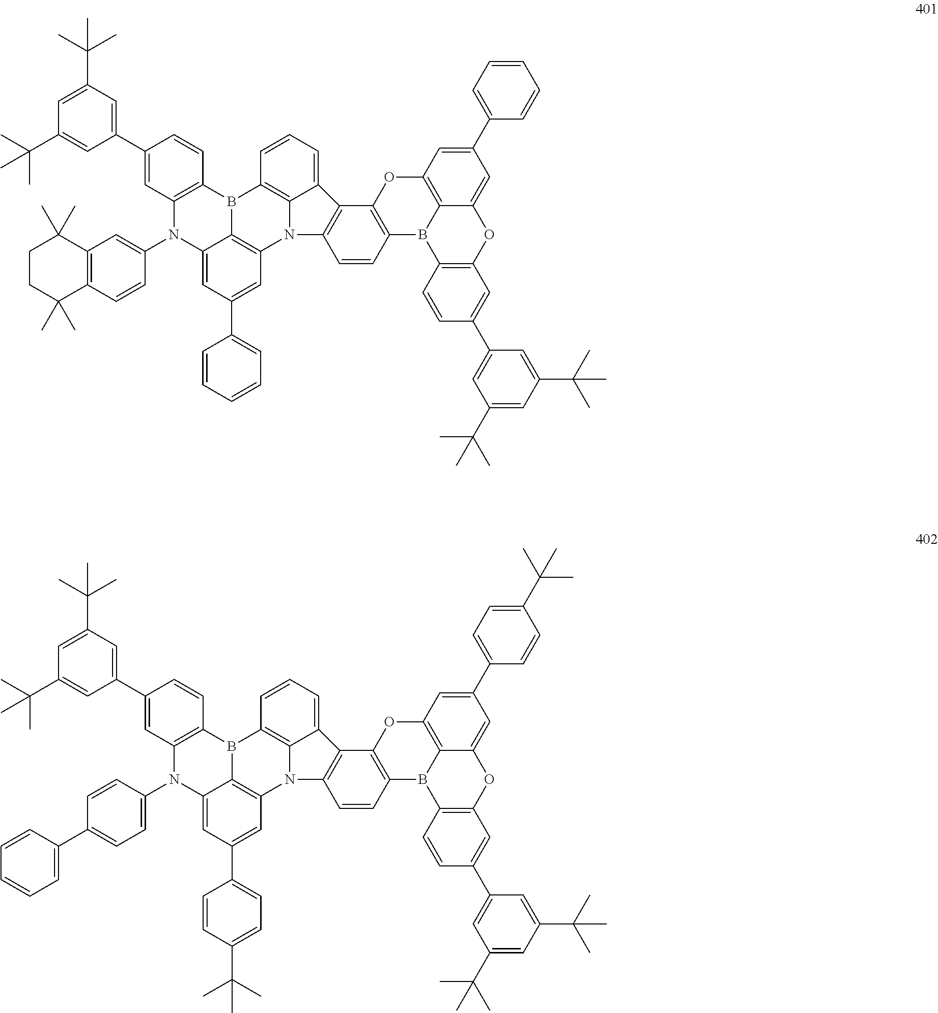 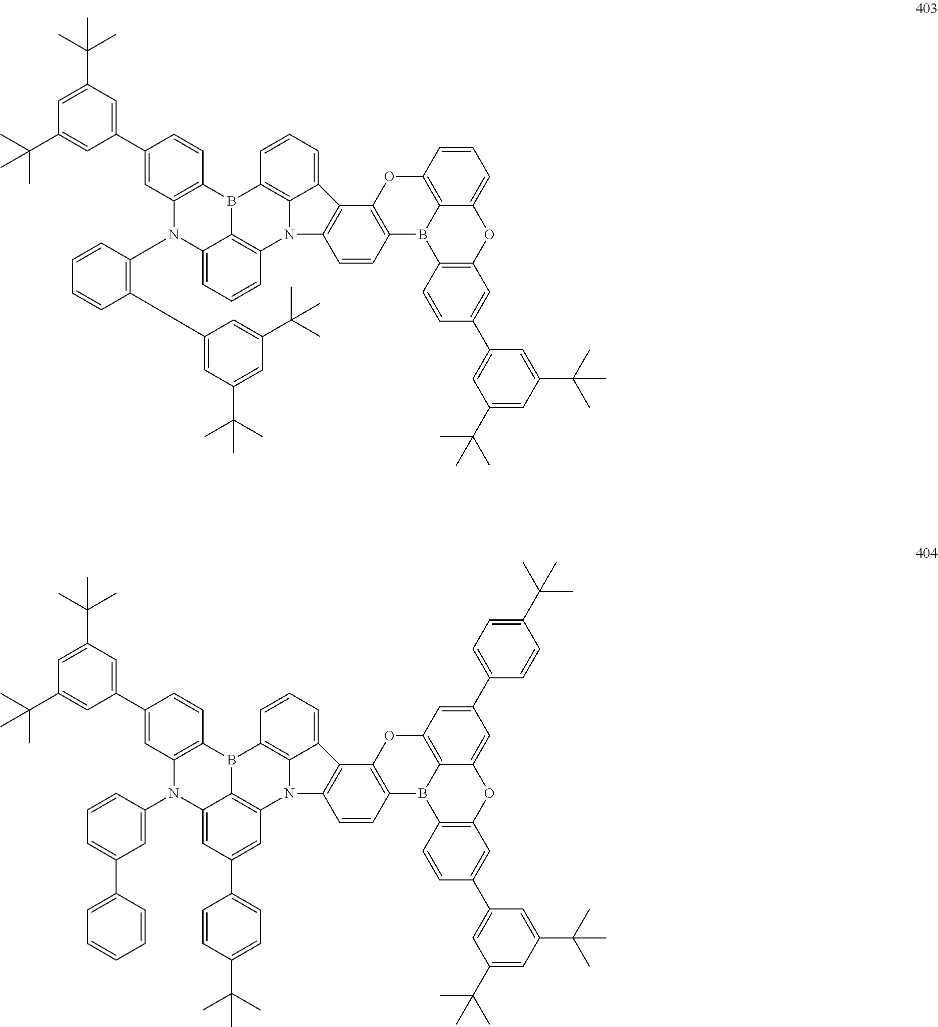 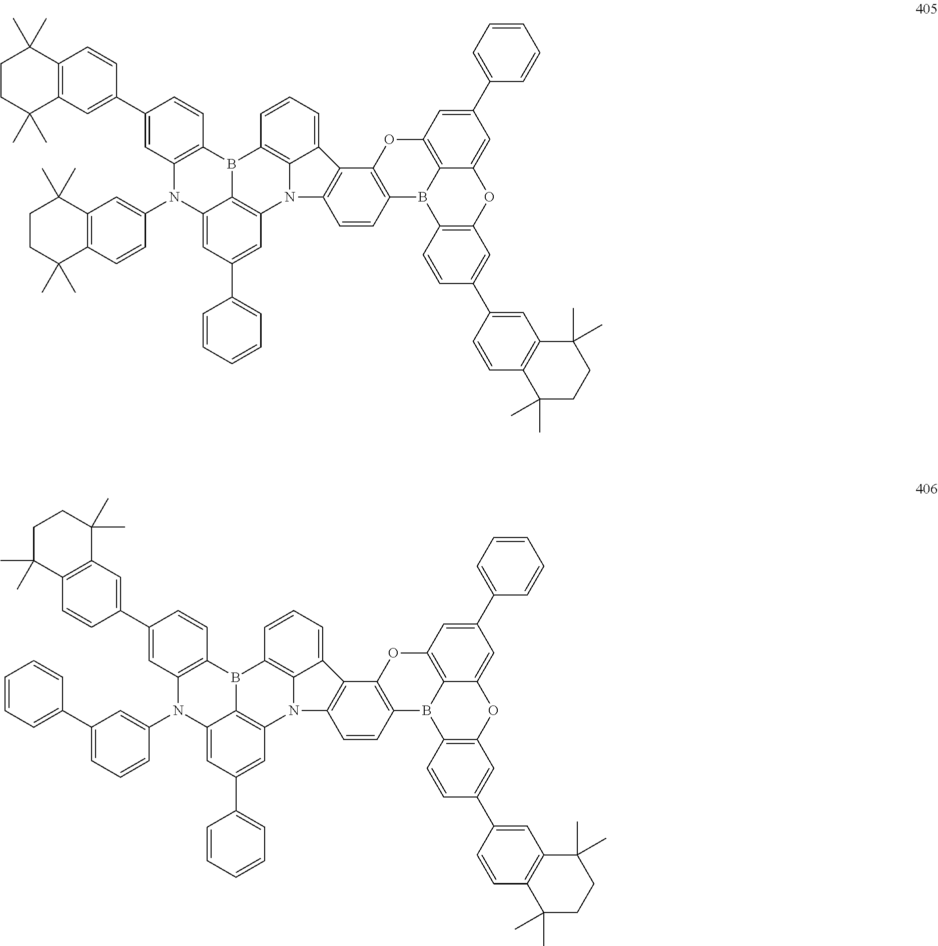 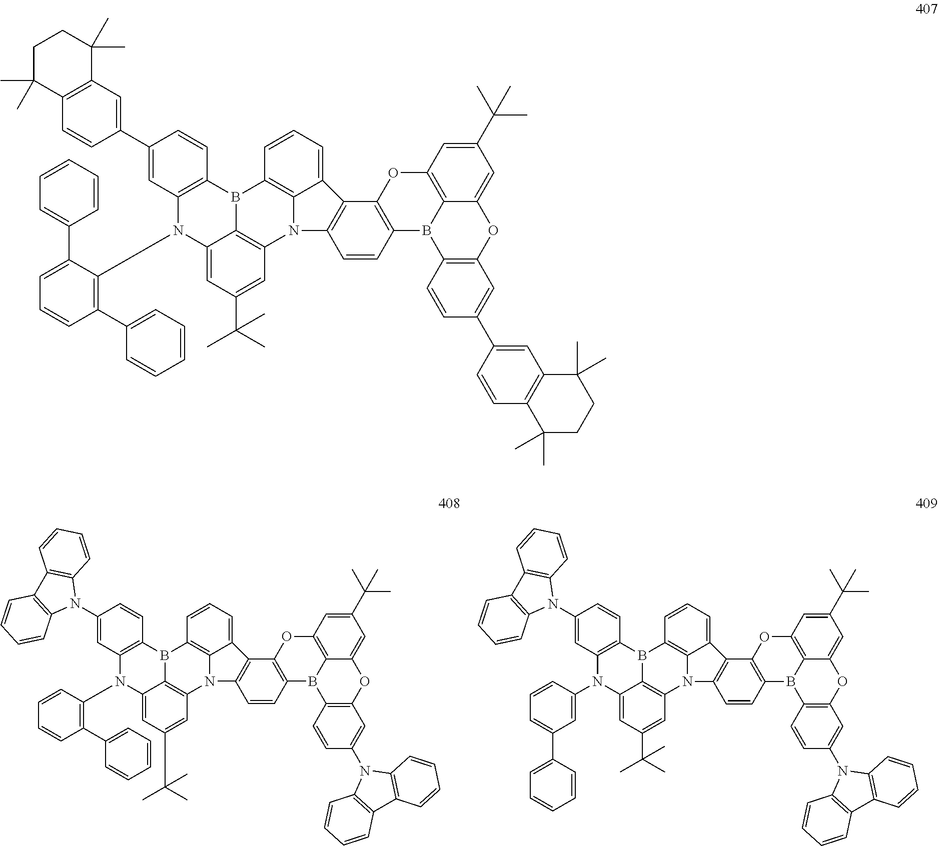 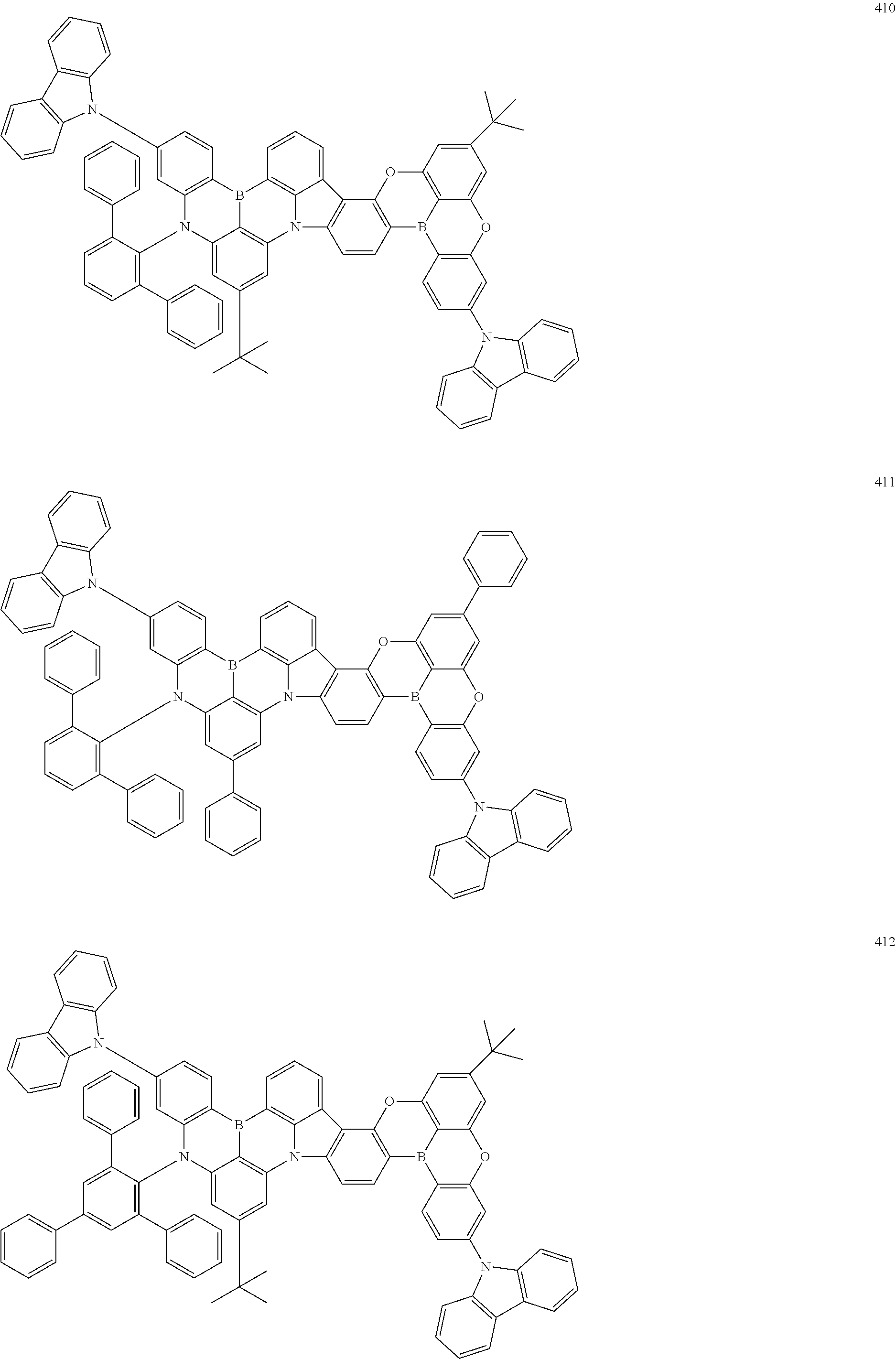 [SMILES: CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1O2 ; c1ccc(-c2cc3c4c(c2)Oc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2O3)cc1 ; CC(C)(C)c1cc2c3c(c1)Oc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1O2] 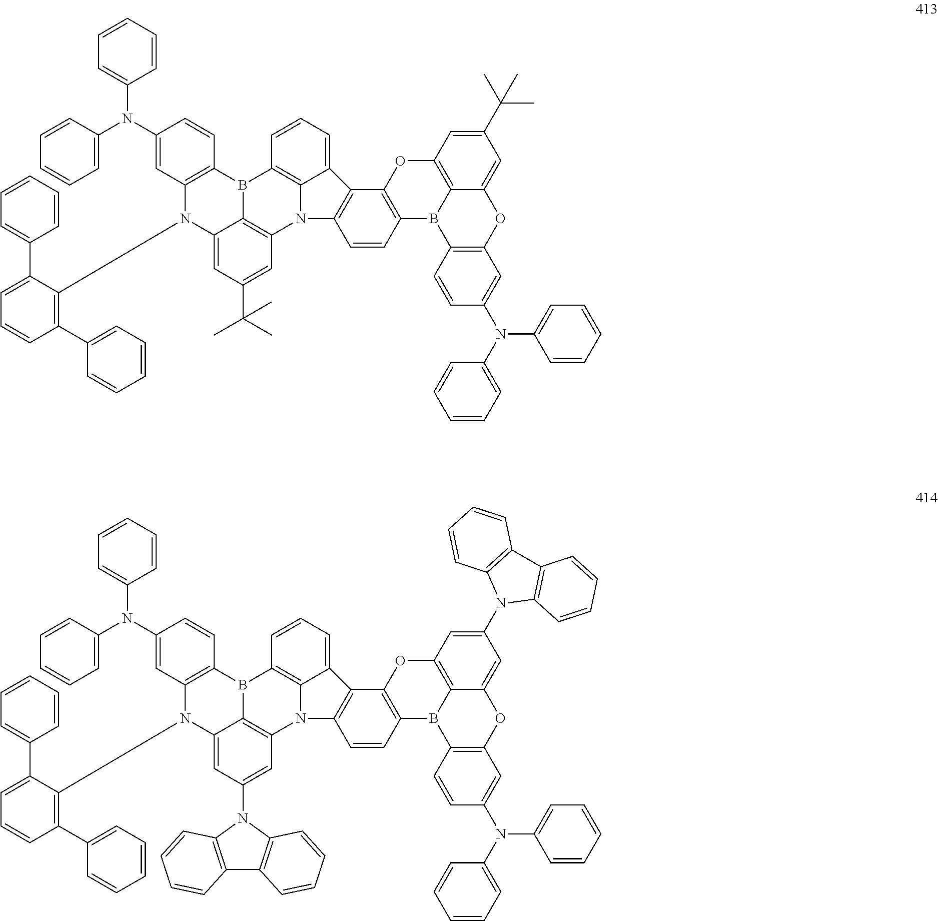 [SMILES: CC(C)(C)c1cc2c3c(c1)Oc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1O2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Oc2cc(-n3c4ccccc4c4ccccc43)cc3c2B5c2ccc(N(c4ccccc4)c4ccccc4)cc2O3)cc1] 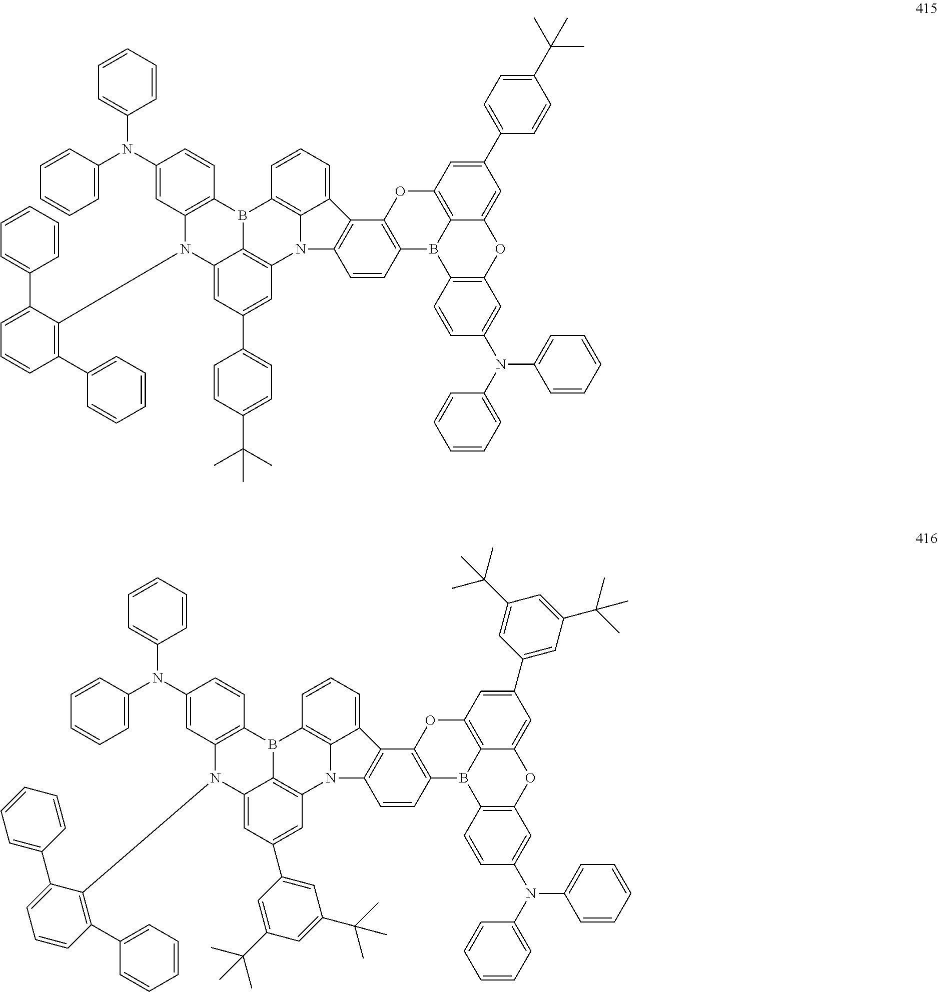 [SMILES: CC(C)(C)c1ccc(-c2cc3c4c(c2)Oc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc1 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2O3)cc(C(C)(C)C)c1] 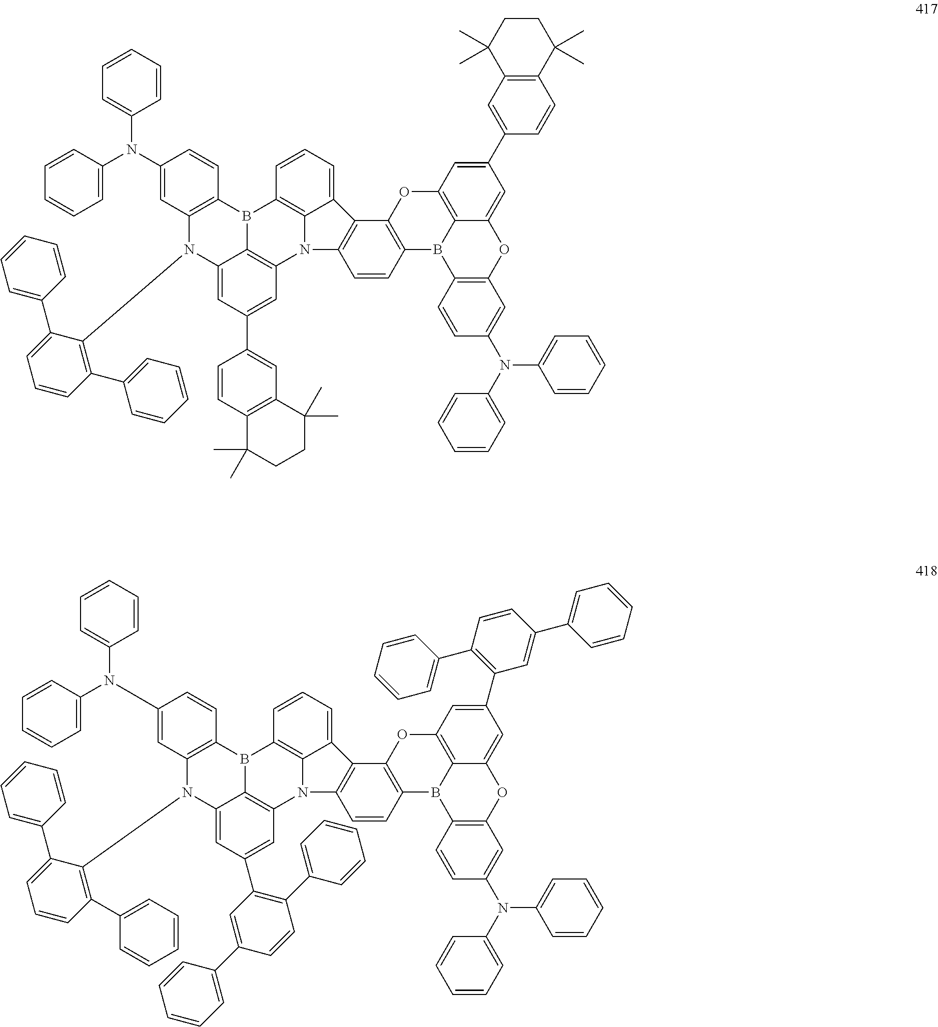 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)ccc21 ; c1ccc(-c2ccc(-c3ccccc3)c(-c3cc4c5c(c3)Oc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3O4)c2)cc1] 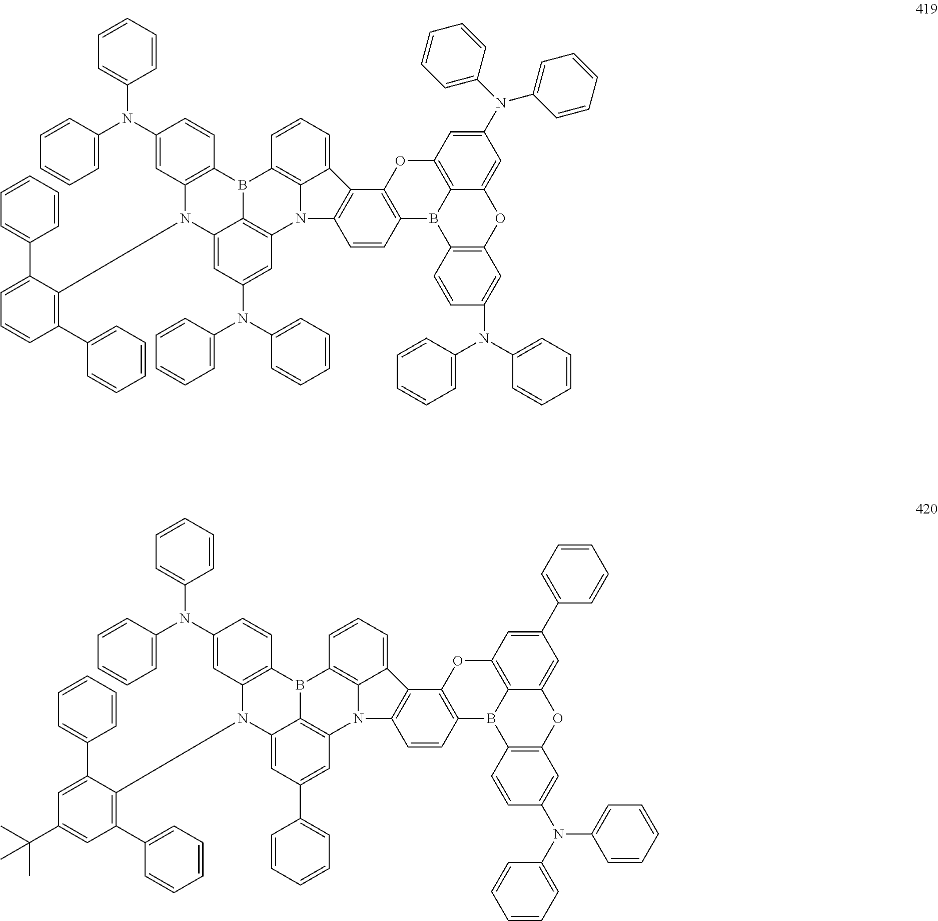 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Oc2cc(N(c3ccccc3)c3ccccc3)cc3c2B5c2ccc(N(c4ccccc4)c4ccccc4)cc2O3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Oc2cc(-c3ccccc3)cc3c2B5c2ccc(N(c4ccccc4)c4ccccc4)cc2O3)c(-c2ccccc2)c1] 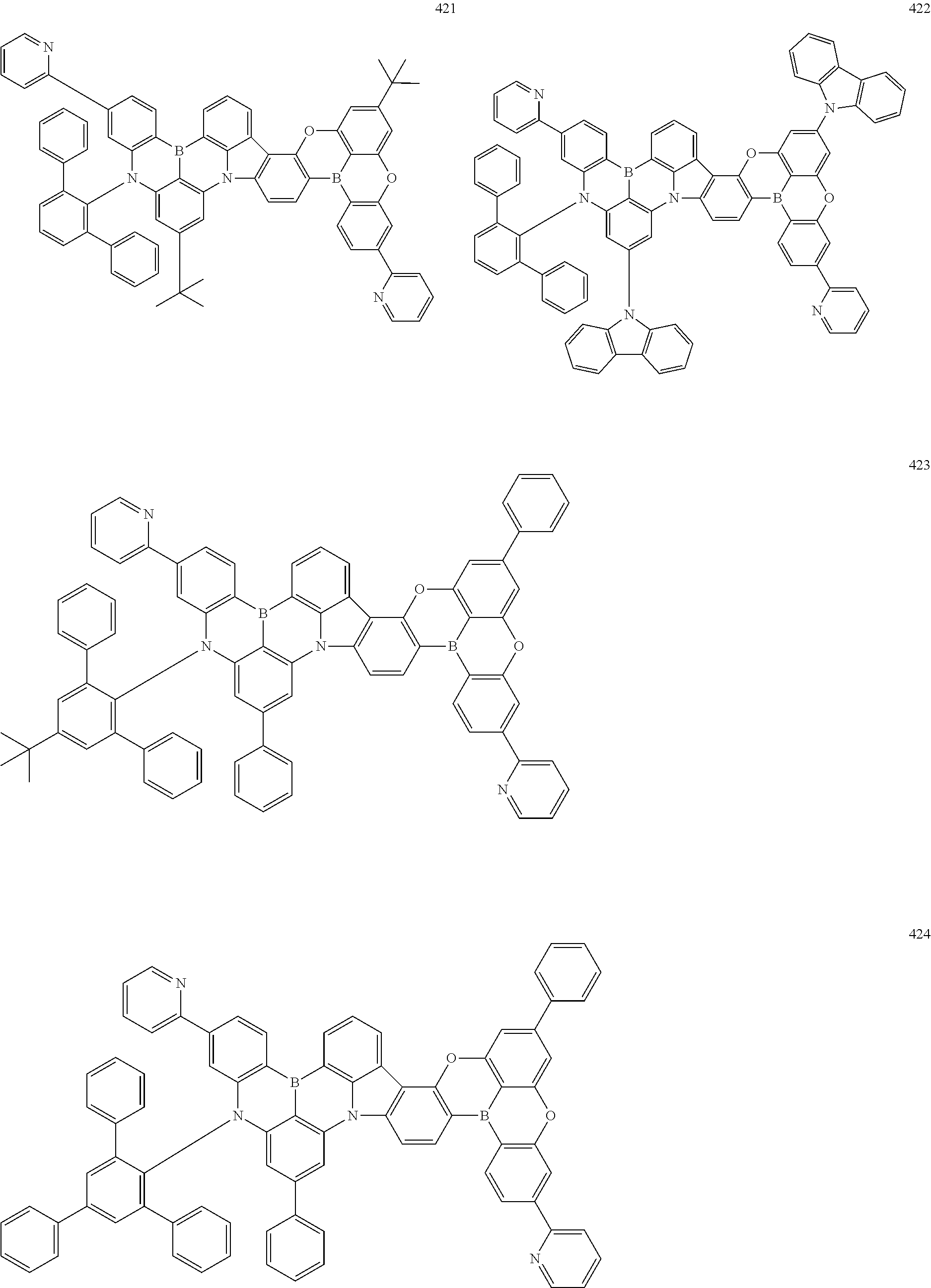 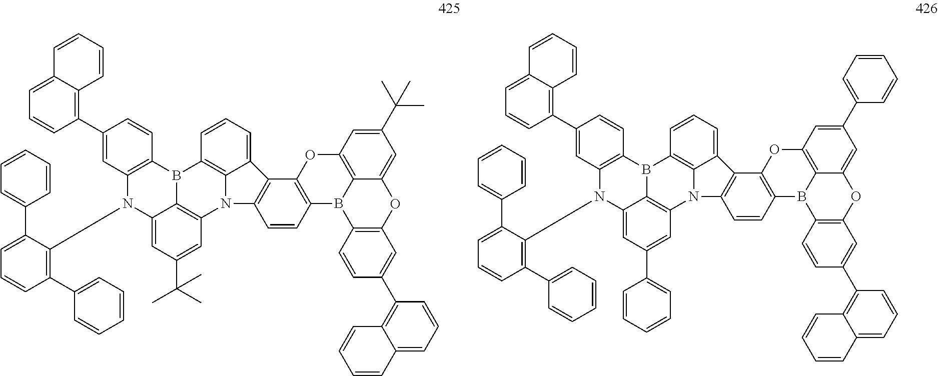 [SMILES: CC(C)(C)c1cc2c3c(c1)Oc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2O3)cc1] 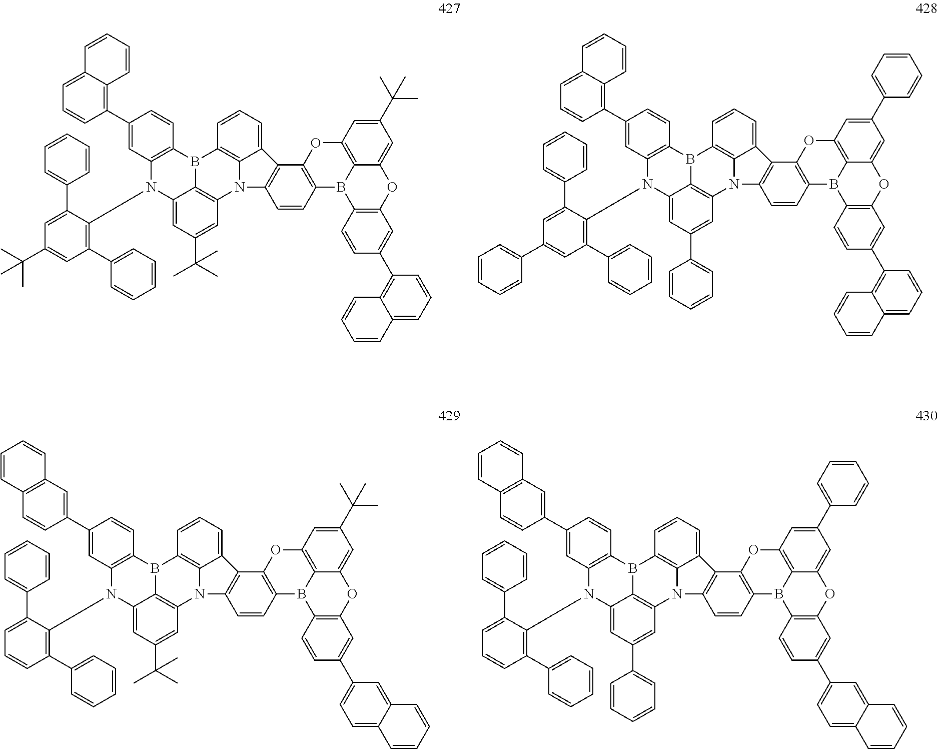 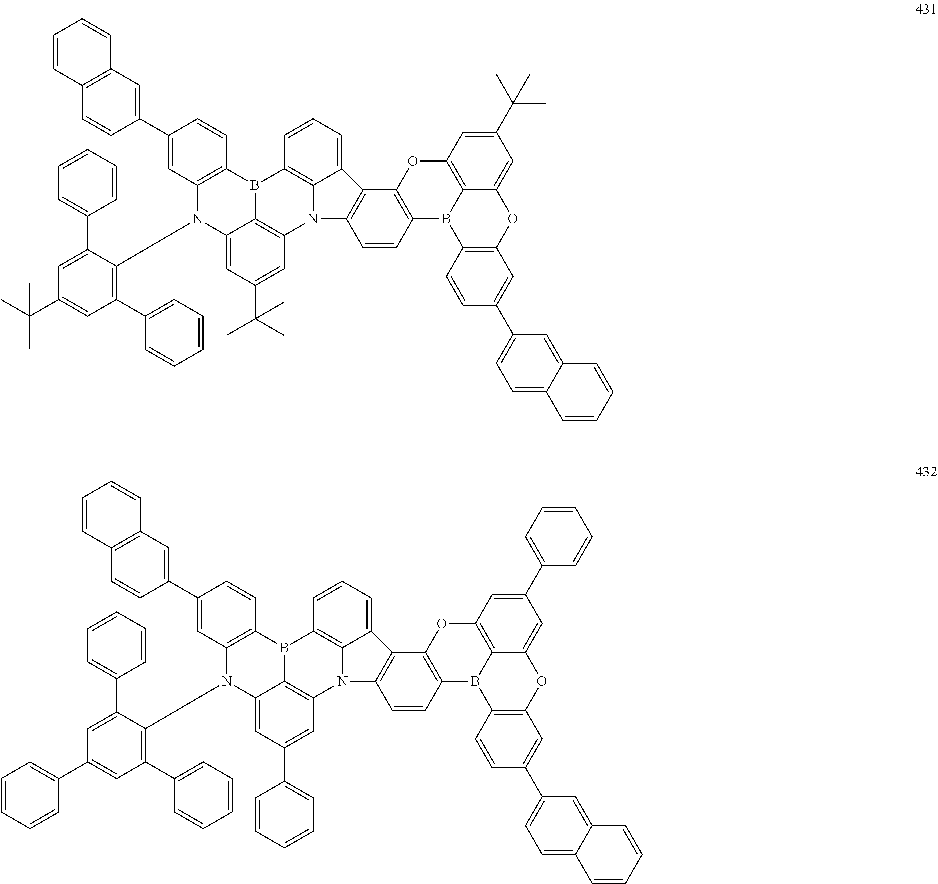 [SMILES: CC(C)(C)c1cc2c3c(c1)Oc1c(ccc4c1c1cccc5c1n4-c1cc(C(C)(C)C)cc4c1B5c1ccc(-c5ccc6ccccc6c5)cc1N4c1c(-c4ccccc4)cc(C(C)(C)C)cc1-c1ccccc1)B3c1ccc(-c3ccc4ccccc4c3)cc1O2 ; c1ccc(-c2cc3c4c(c2)Oc2c(ccc5c2c2cccc6c2n5-c2cc(-c5ccccc5)cc5c2B6c2ccc(-c6ccc7ccccc7c6)cc2N5c2c(-c5ccccc5)cc(-c5ccccc5)cc2-c2ccccc2)B4c2ccc(-c4ccc5ccccc5c4)cc2O3)cc1] 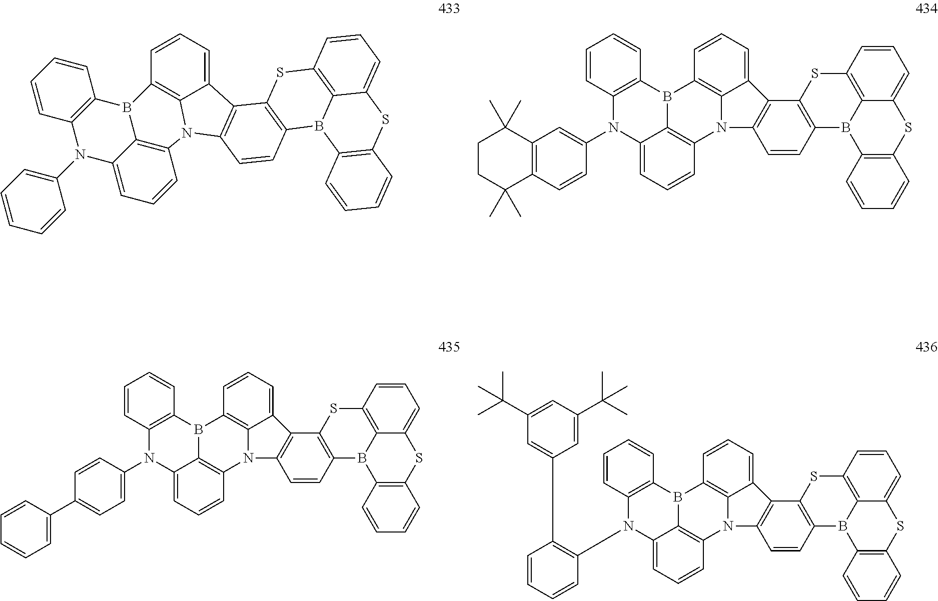 [SMILES: c1ccc(N2c3ccccc3B3c4c2cccc4-n2c4ccc5c(c4c4cccc3c42)Sc2cccc3c2B5c2ccccc2S3)cc1 ; CC1(C)CCC(C)(C)c2cc(N3c4ccccc4B4c5c3cccc5-n3c5ccc6c(c5c5cccc4c53)Sc3cccc4c3B6c3ccccc3S4)ccc21 ; c1ccc(-c2ccc(N3c4ccccc4B4c5c3cccc5-n3c5ccc6c(c5c5cccc4c53)Sc3cccc4c3B6c3ccccc3S4)cc2)cc1 ; CC(C)(C)c1cc(-c2ccccc2N2c3ccccc3B3c4c2cccc4-n2c4ccc5c(c4c4cccc3c42)Sc2cccc3c2B5c2ccccc2S3)cc(C(C)(C)C)c1] 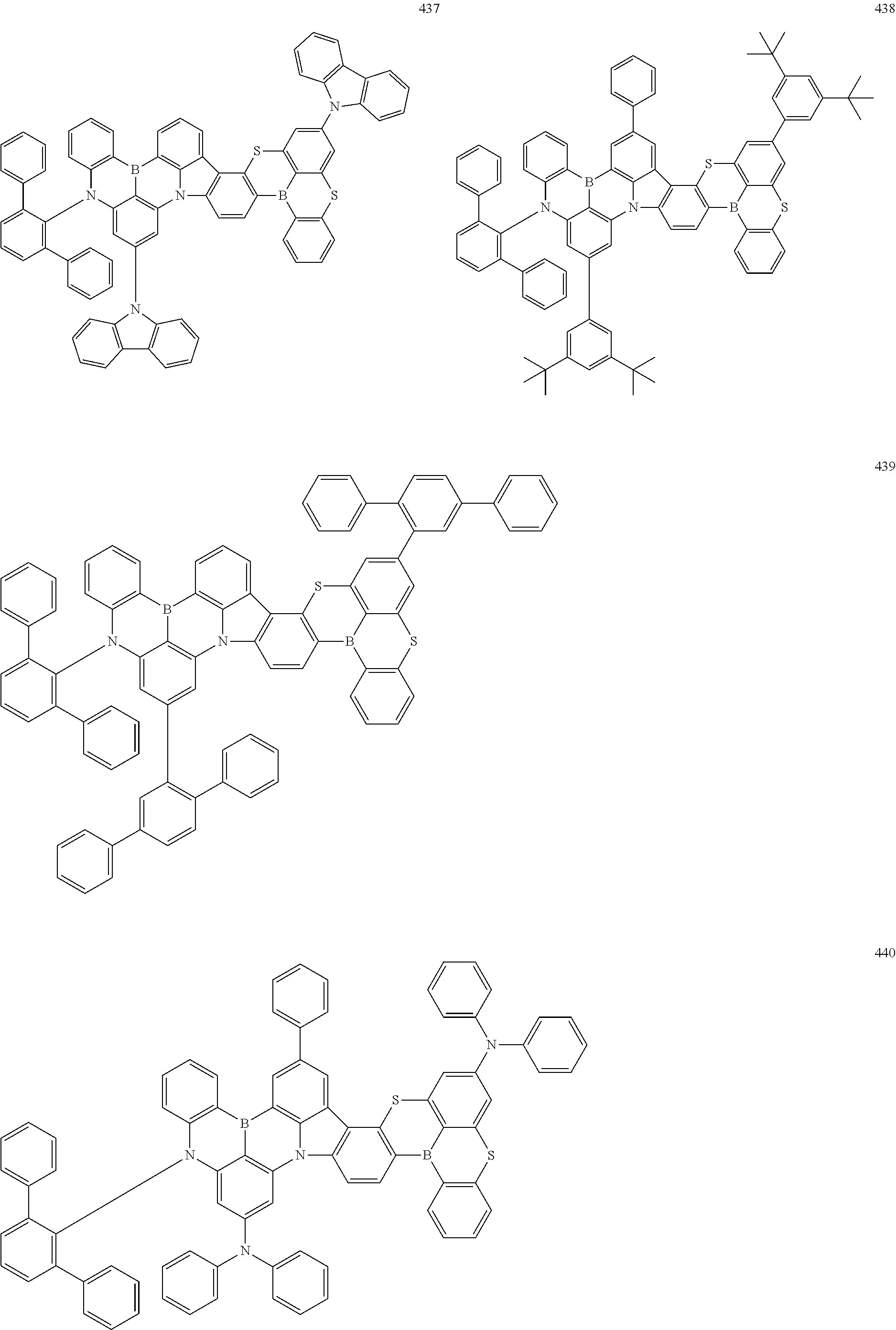 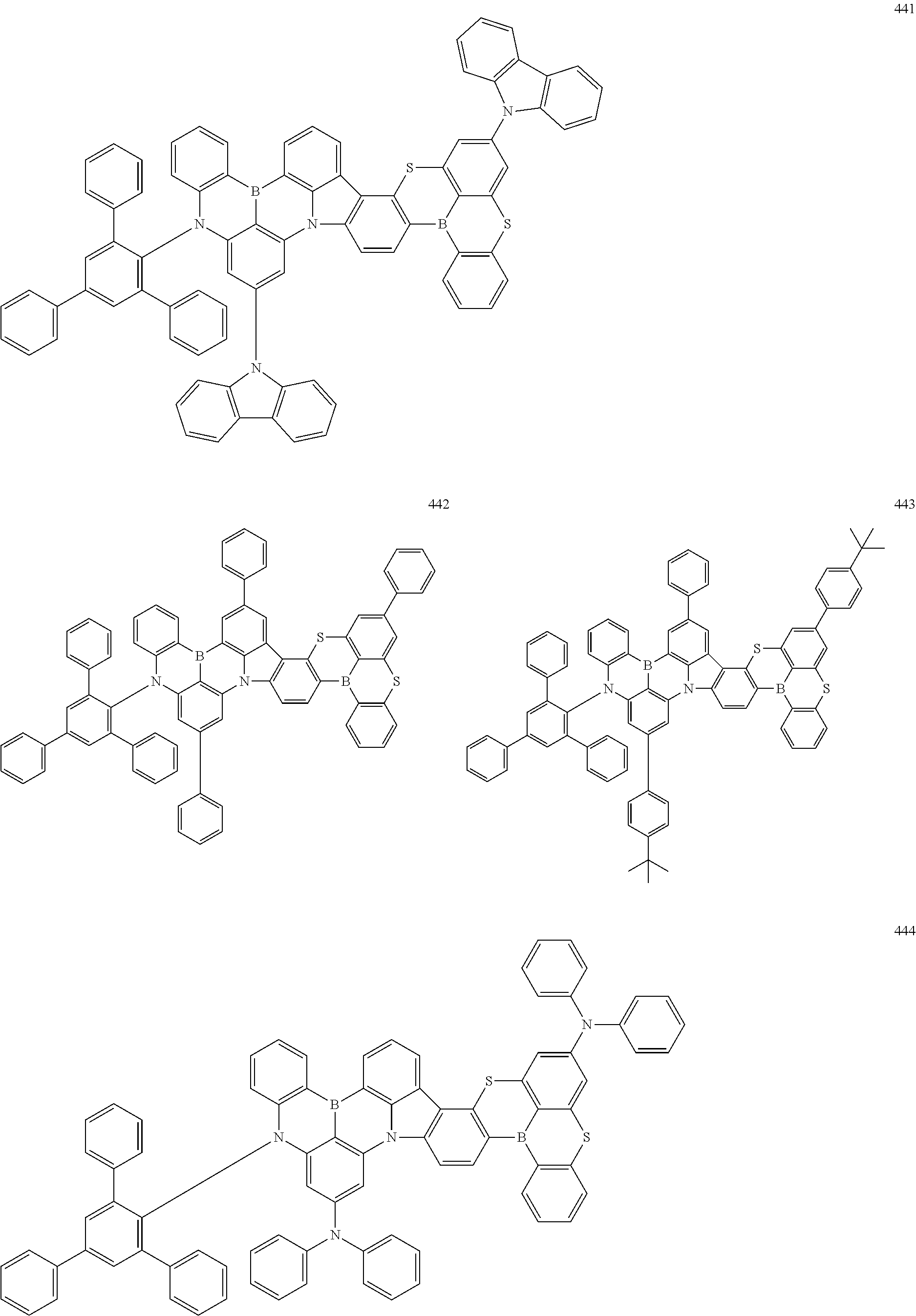 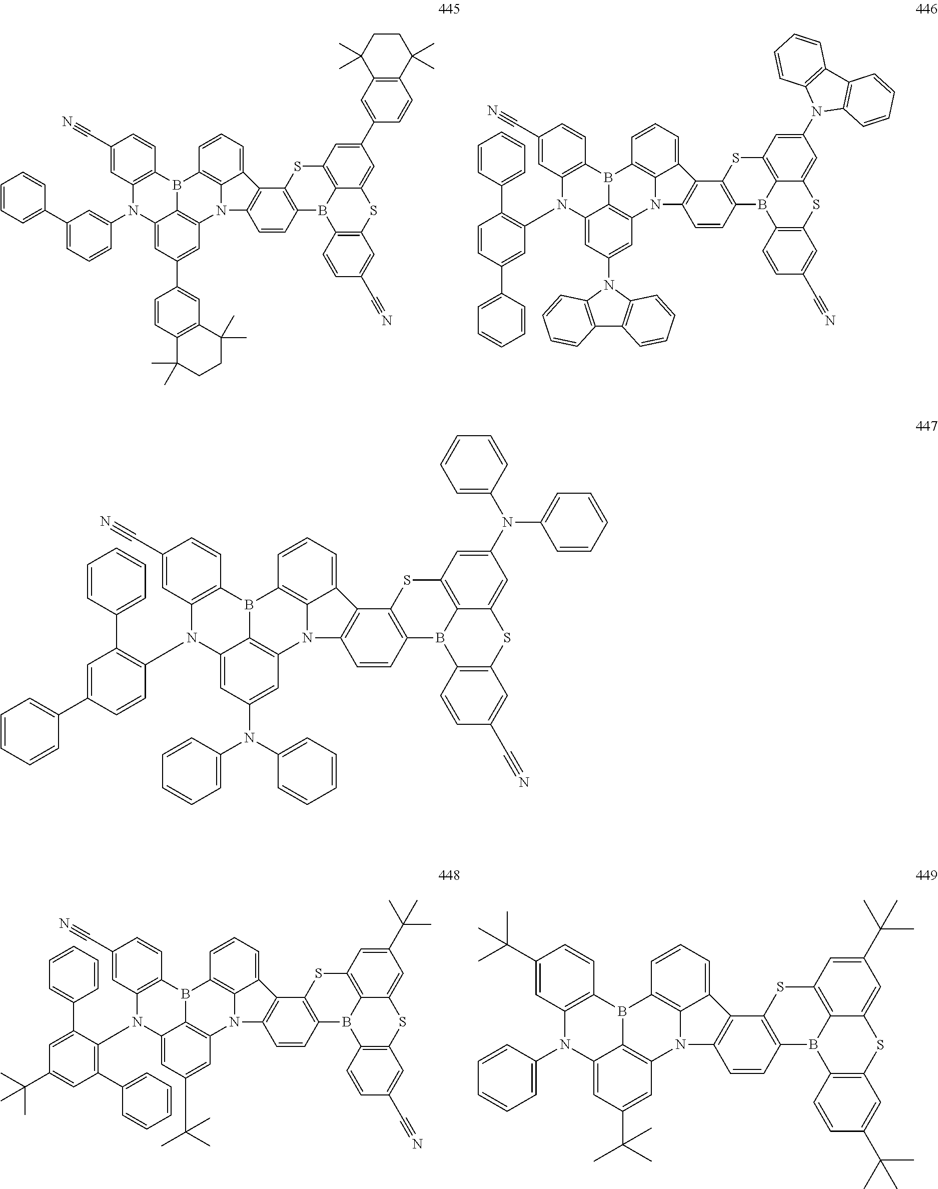 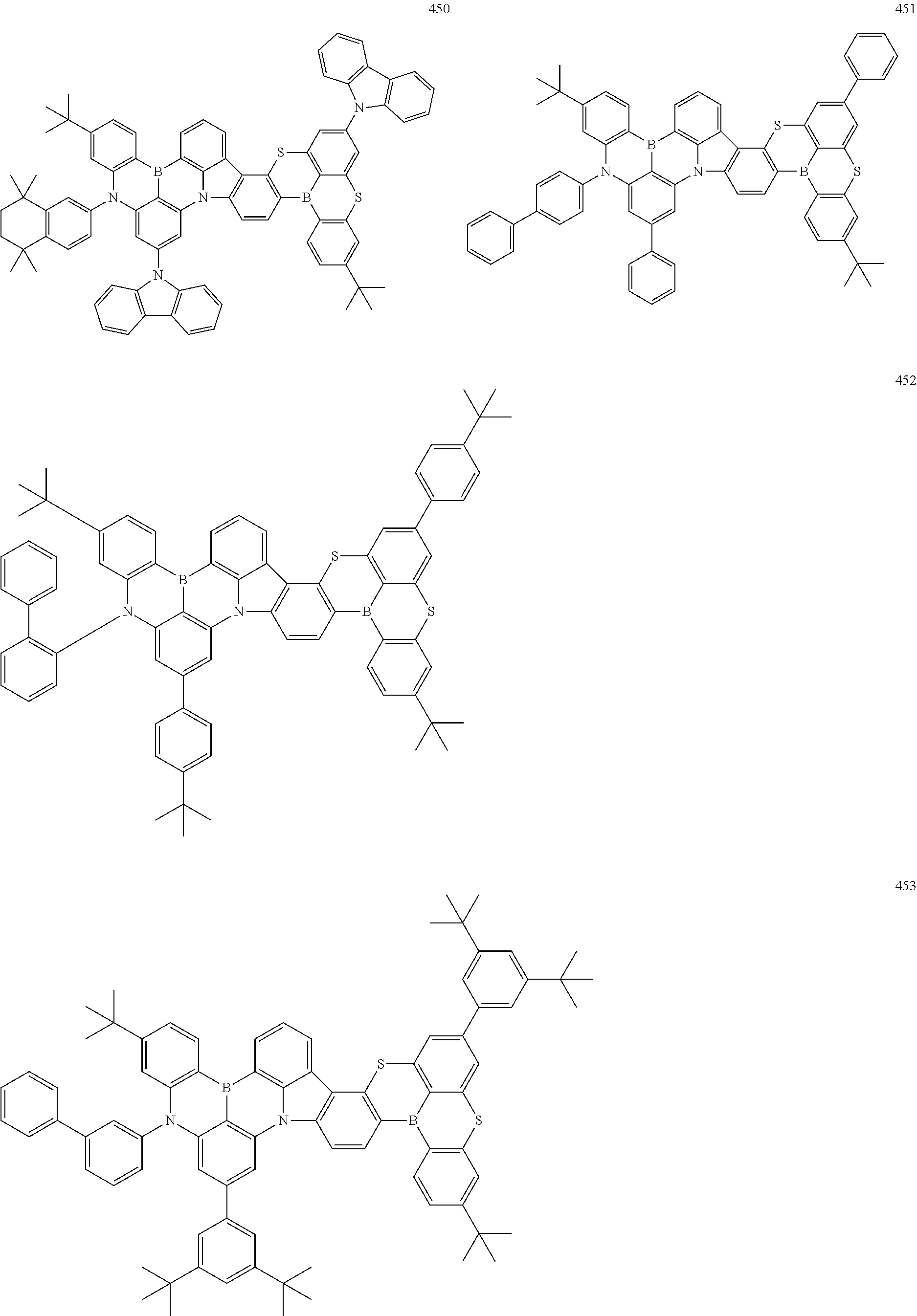 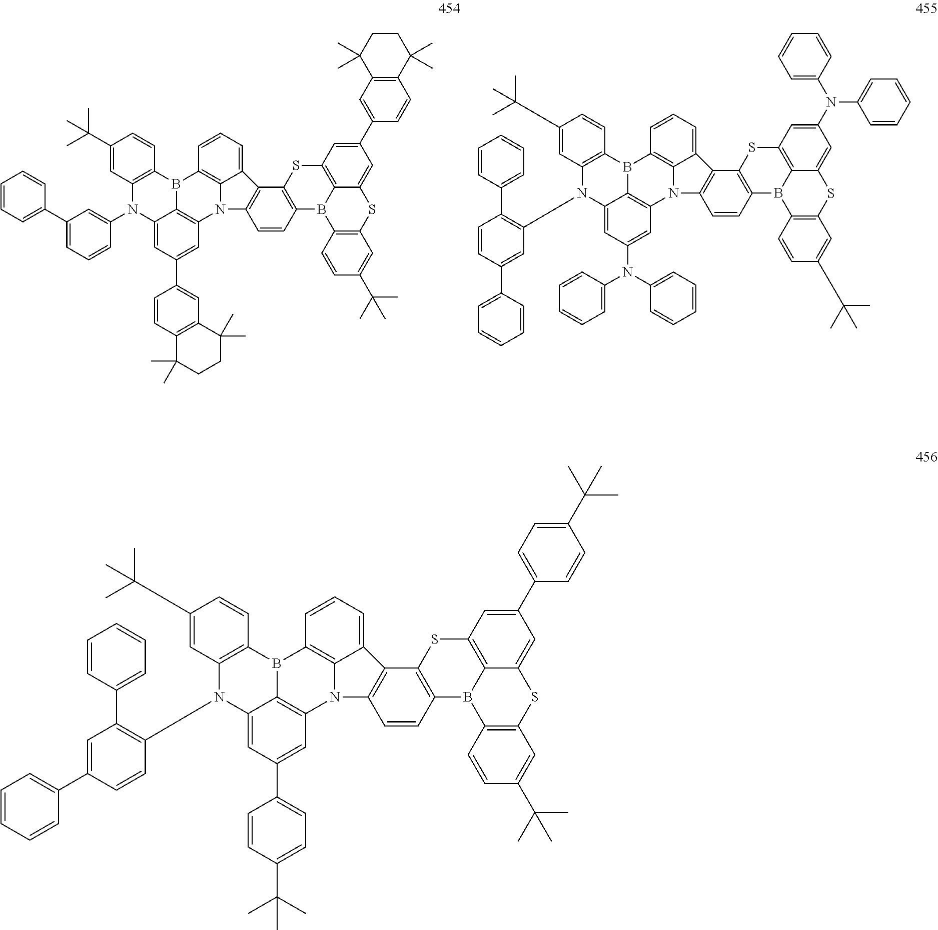 [SMILES: CC(C)(C)c1ccc2c(c1)Sc1cc(-c3ccc4c(c3)C(C)(C)CCC4(C)C)cc3c1B2c1ccc2c(c1S3)c1cccc3c1n2-c1cc(-c2ccc4c(c2)C(C)(C)CCC4(C)C)cc2c1B3c1ccc(C(C)(C)C)cc1N2c1cccc(-c2ccccc2)c1 ; CC(C)(C)c1ccc2c(c1)Sc1cc(N(c3ccccc3)c3ccccc3)cc3c1B2c1ccc2c(c1S3)c1cccc3c1n2-c1cc(N(c2ccccc2)c2ccccc2)cc2c1B3c1ccc(C(C)(C)C)cc1N2c1cc(-c2ccccc2)ccc1-c1ccccc1 ; CC(C)(C)c1ccc(-c2cc3c4c(c2)Sc2c(ccc5c2c2cccc6c2n5-c2cc(-c5ccc(C(C)(C)C)cc5)cc5c2B6c2ccc(C(C)(C)C)cc2N5c2ccc(-c5ccccc5)cc2-c2ccccc2)B4c2ccc(C(C)(C)C)cc2S3)cc1] 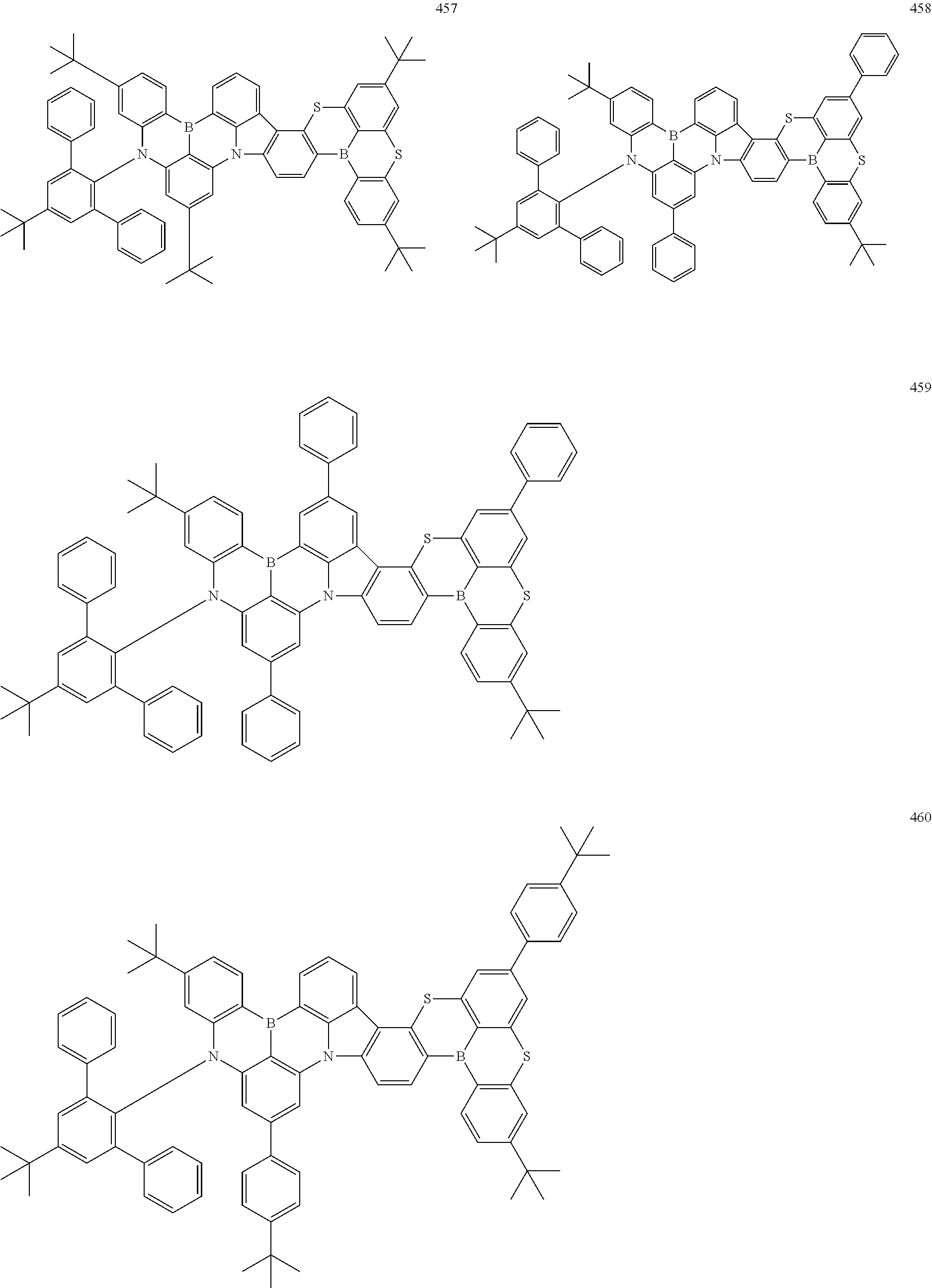 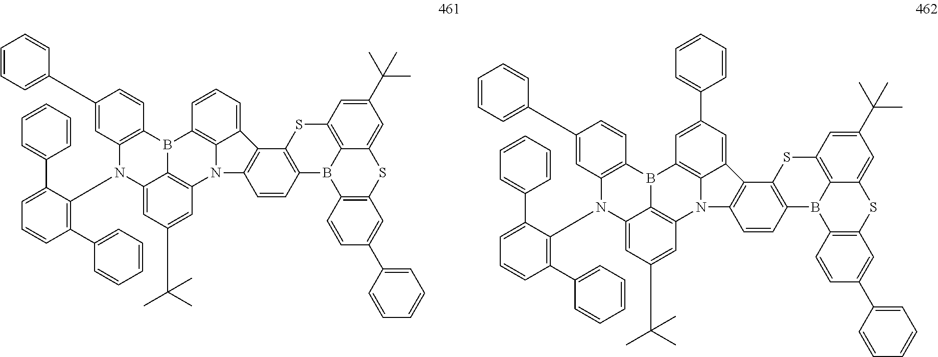 [SMILES: CC(C)(C)c1cc2c3c(c1)Sc1c(ccc4c1c1cccc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1S2 ; CC(C)(C)c1cc2c3c(c1)Sc1c(ccc4c1c1cc(-c5ccccc5)cc5c1n4-c1cc(C(C)(C)C)cc4c1B5c1ccc(-c5ccccc5)cc1N4c1c(-c4ccccc4)cccc1-c1ccccc1)B3c1ccc(-c3ccccc3)cc1S2] 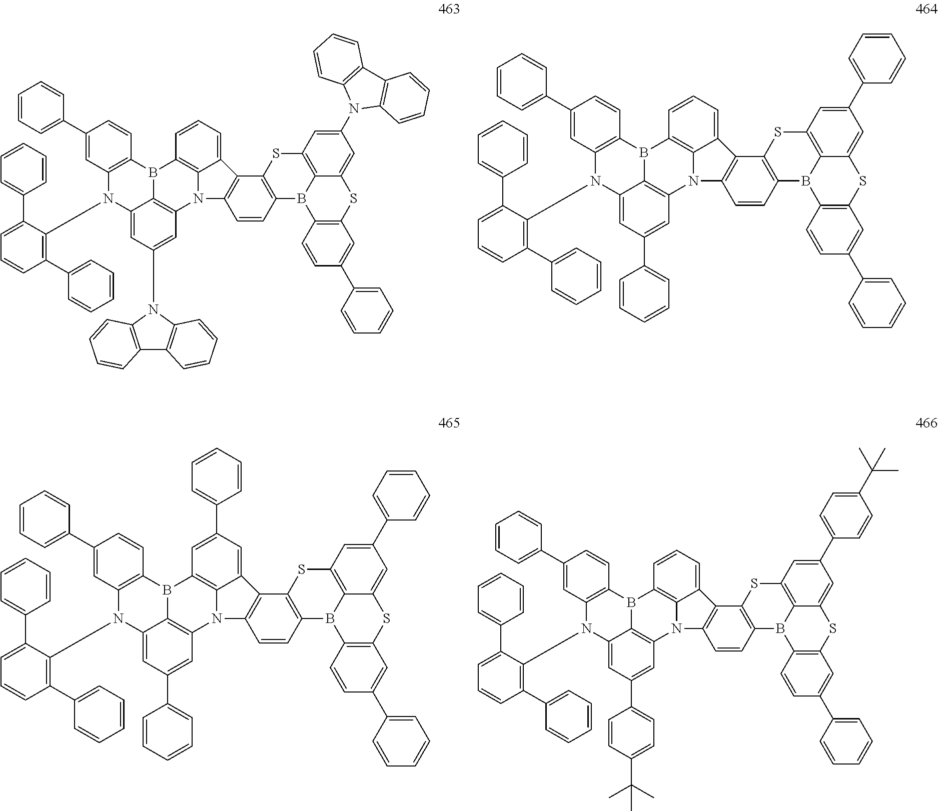 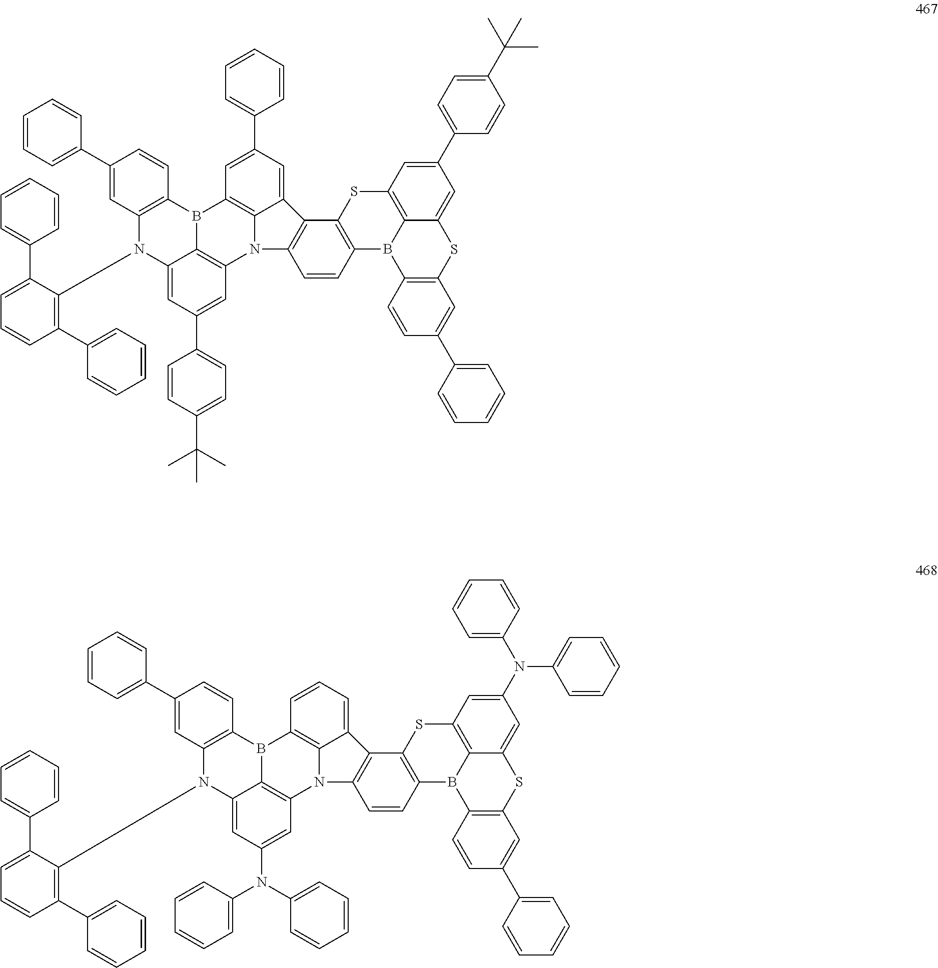 [SMILES: CC(C)(C)c1ccc(-c2cc3c4c(c2)Sc2c(ccc5c2c2cc(-c6ccccc6)cc6c2n5-c2cc(-c5ccc(C(C)(C)C)cc5)cc5c2B6c2ccc(-c6ccccc6)cc2N5c2c(-c5ccccc5)cccc2-c2ccccc2)B4c2ccc(-c4ccccc4)cc2S3)cc1 ; c1ccc(-c2ccc3c(c2)Sc2cc(N(c4ccccc4)c4ccccc4)cc4c2B3c2ccc3c(c2S4)c2cccc4c2n3-c2cc(N(c3ccccc3)c3ccccc3)cc3c2B4c2ccc(-c4ccccc4)cc2N3c2c(-c3ccccc3)cccc2-c2ccccc2)cc1] 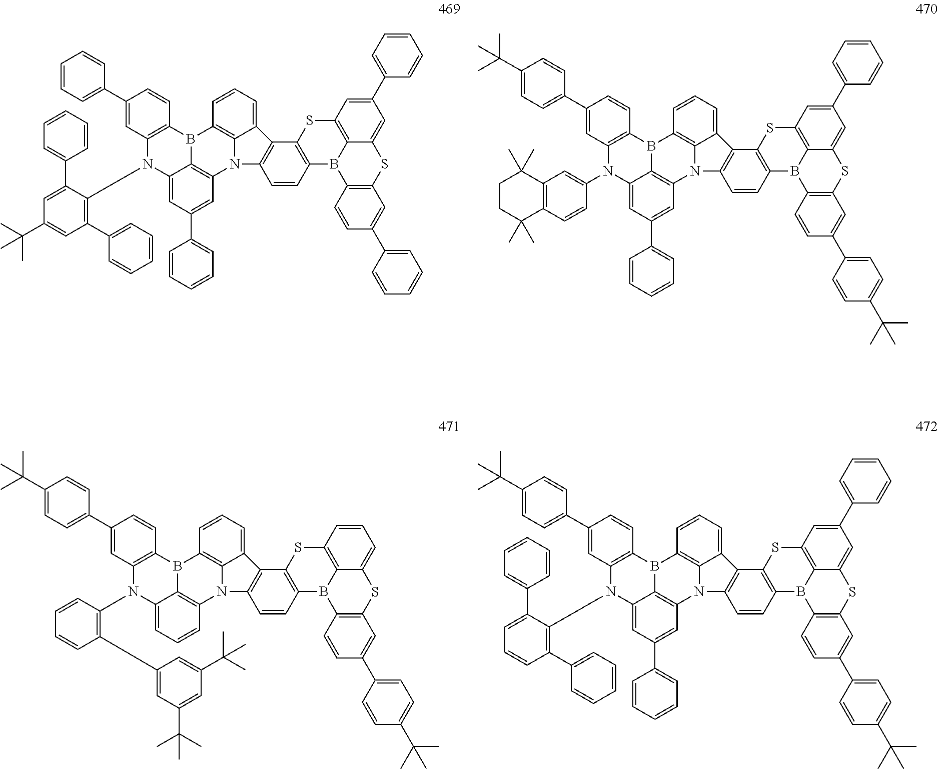 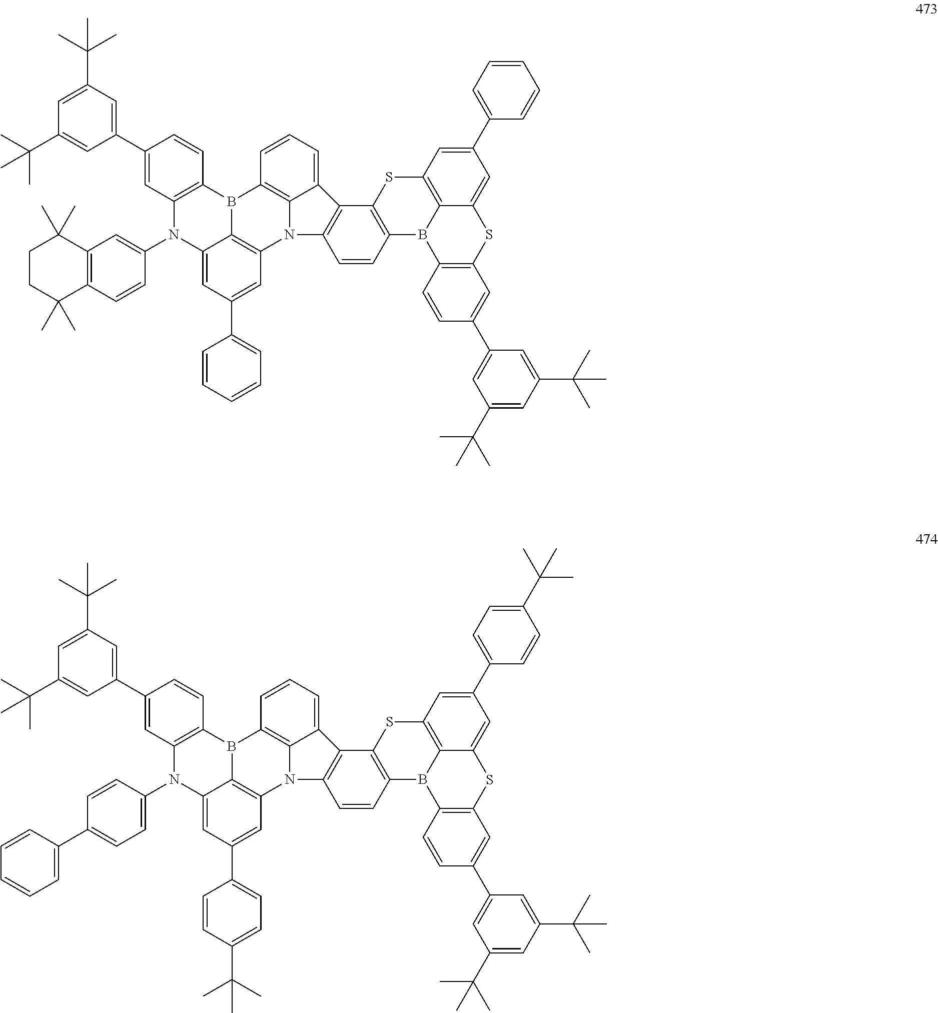 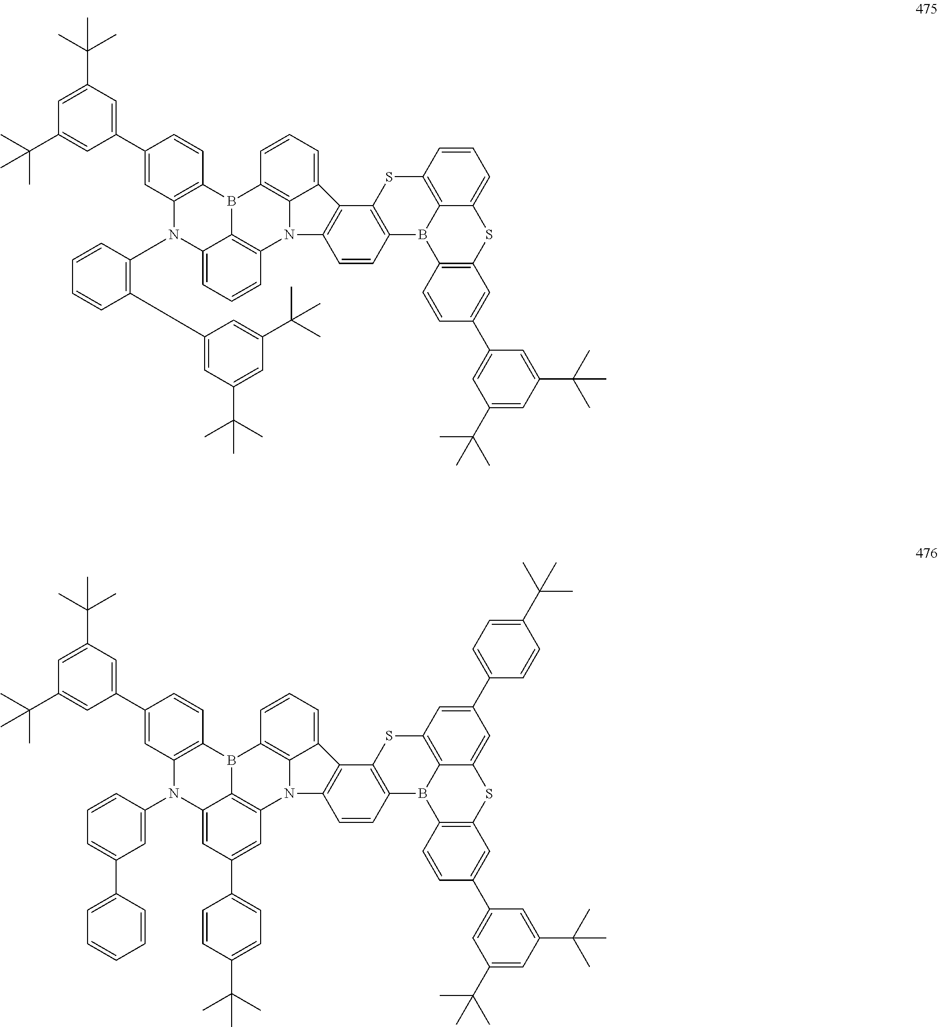 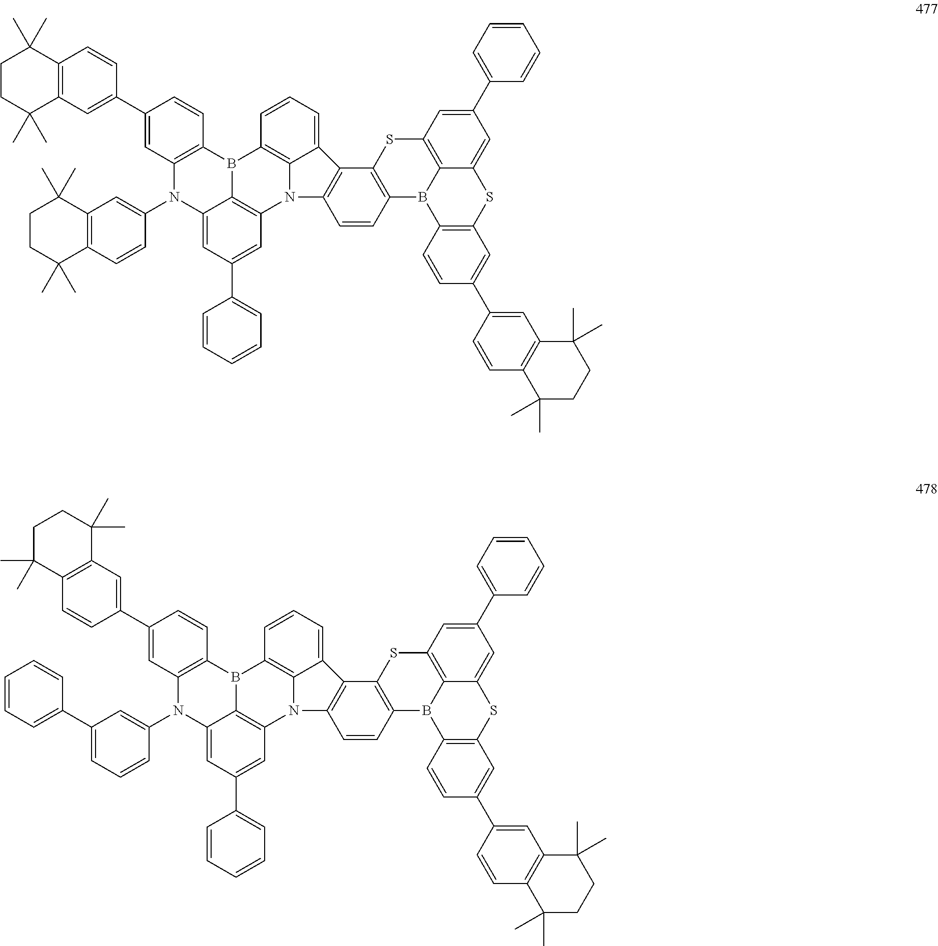 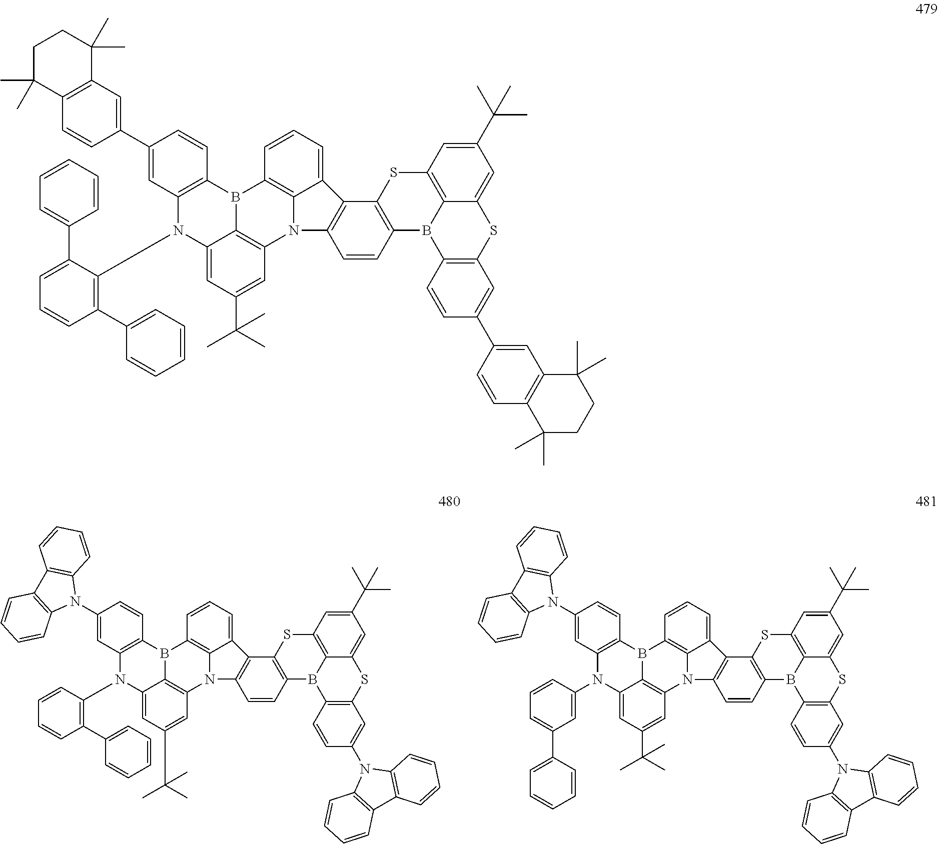 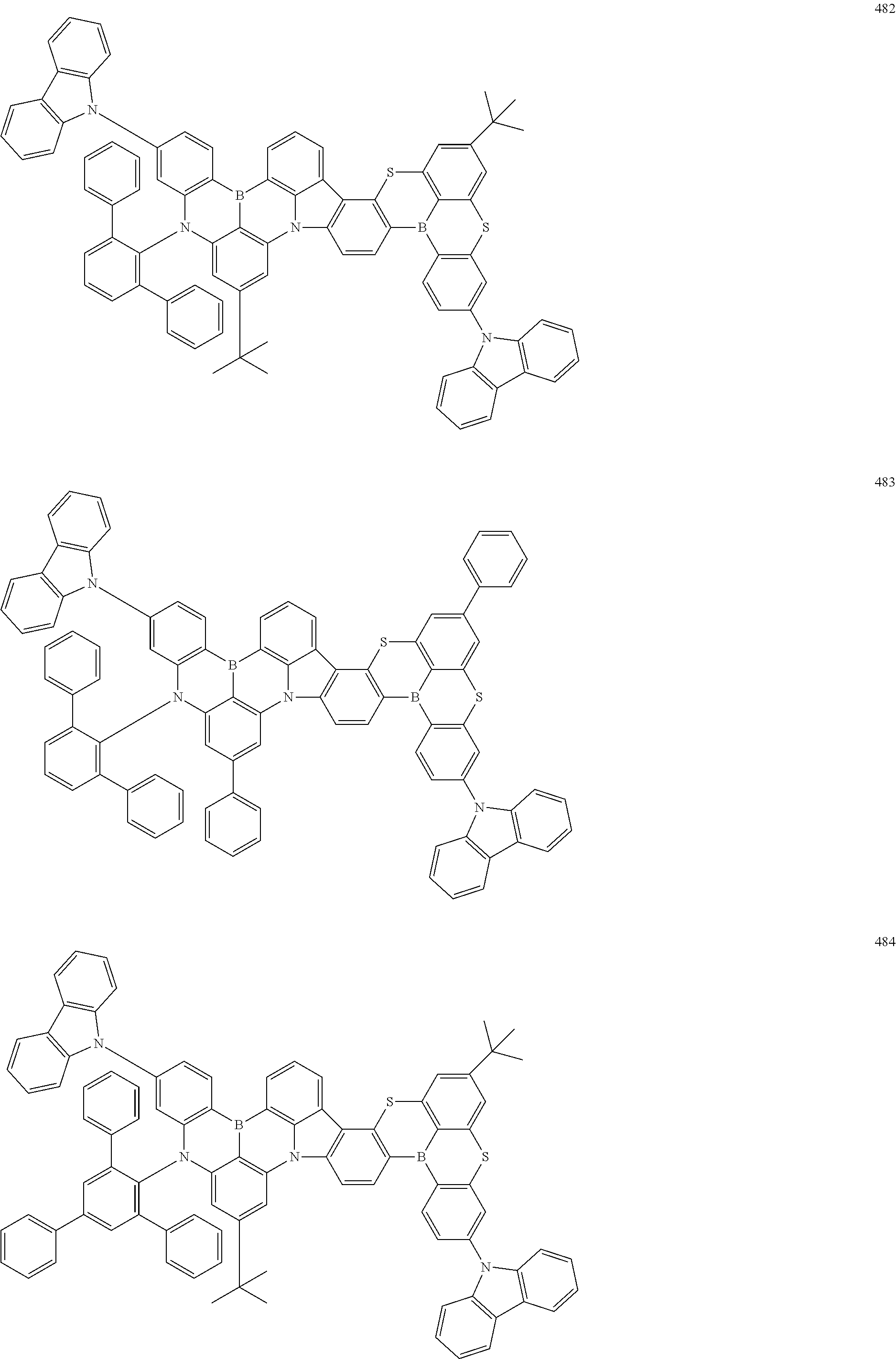 [SMILES: CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cccc1-c1ccccc1)B3c1ccc(-n3c4ccccc4c4ccccc43)cc1S2 ; c1ccc(-c2cc3c4c(c2)Sc2c(ccc5c2c2cccc6c2n5-c2cc(-c5ccccc5)cc5c2B6c2ccc(-n6c7ccccc7c7ccccc76)cc2N5c2c(-c5ccccc5)cccc2-c2ccccc2)B4c2ccc(-n4c5ccccc5c5ccccc54)cc2S3)cc1 ; CC(C)(C)c1cc2c3c(c1)Sc1c(ccc4c1c1cccc5c1n4-c1cc(C(C)(C)C)cc4c1B5c1ccc(-n5c6ccccc6c6ccccc65)cc1N4c1c(-c4ccccc4)cc(-c4ccccc4)cc1-c1ccccc1)B3c1ccc(-n3c4ccccc4c4ccccc43)cc1S2] 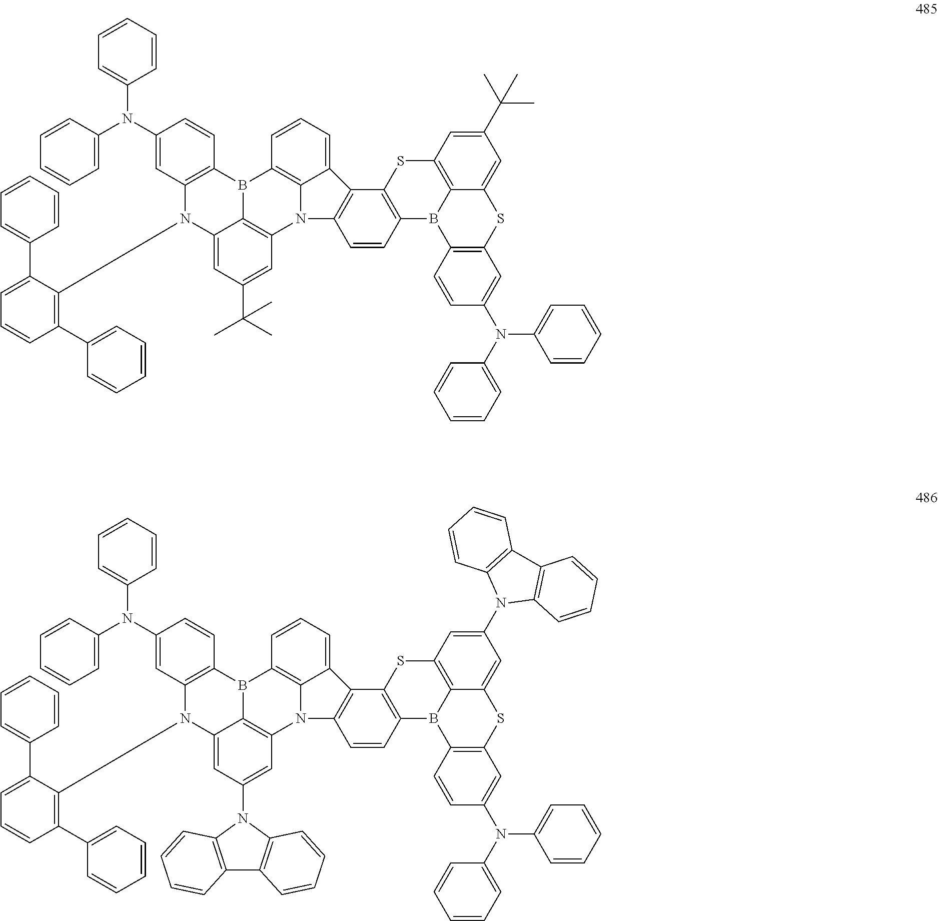 [SMILES: CC(C)(C)c1cc2c3c(c1)Sc1c(ccc4c1c1cccc5c1n4-c1cc(C(C)(C)C)cc4c1B5c1ccc(N(c5ccccc5)c5ccccc5)cc1N4c1c(-c4ccccc4)cccc1-c1ccccc1)B3c1ccc(N(c3ccccc3)c3ccccc3)cc1S2 ; c1ccc(-c2cccc(-c3ccccc3)c2N2c3cc(N(c4ccccc4)c4ccccc4)ccc3B3c4c2cc(-n2c5ccccc5c5ccccc52)cc4-n2c4ccc5c(c4c4cccc3c42)Sc2cc(-n3c4ccccc4c4ccccc43)cc3c2B5c2ccc(N(c4ccccc4)c4ccccc4)cc2S3)cc1] 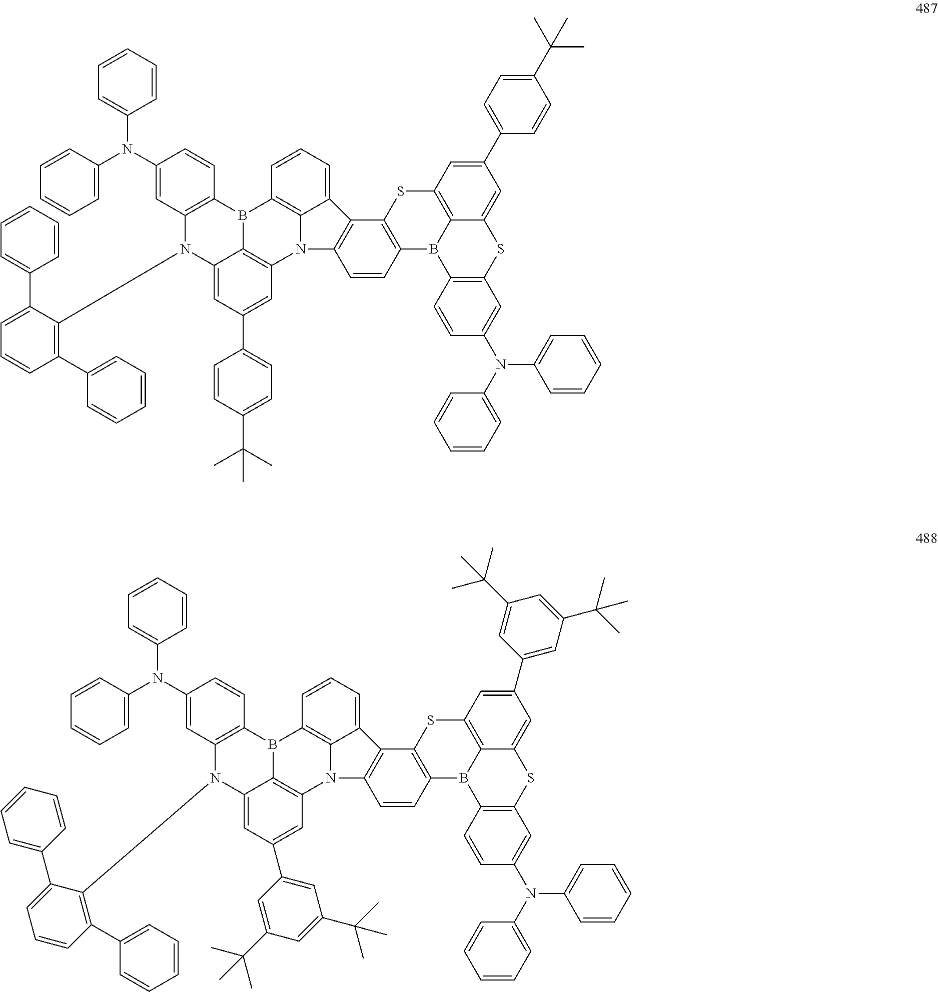 [SMILES: CC(C)(C)c1ccc(-c2cc3c4c(c2)Sc2c(ccc5c2c2cccc6c2n5-c2cc(-c5ccc(C(C)(C)C)cc5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc1 ; CC(C)(C)c1cc(-c2cc3c4c(c2)Sc2c(ccc5c2c2cccc6c2n5-c2cc(-c5cc(C(C)(C)C)cc(C(C)(C)C)c5)cc5c2B6c2ccc(N(c6ccccc6)c6ccccc6)cc2N5c2c(-c5ccccc5)cccc2-c2ccccc2)B4c2ccc(N(c4ccccc4)c4ccccc4)cc2S3)cc(C(C)(C)C)c1] 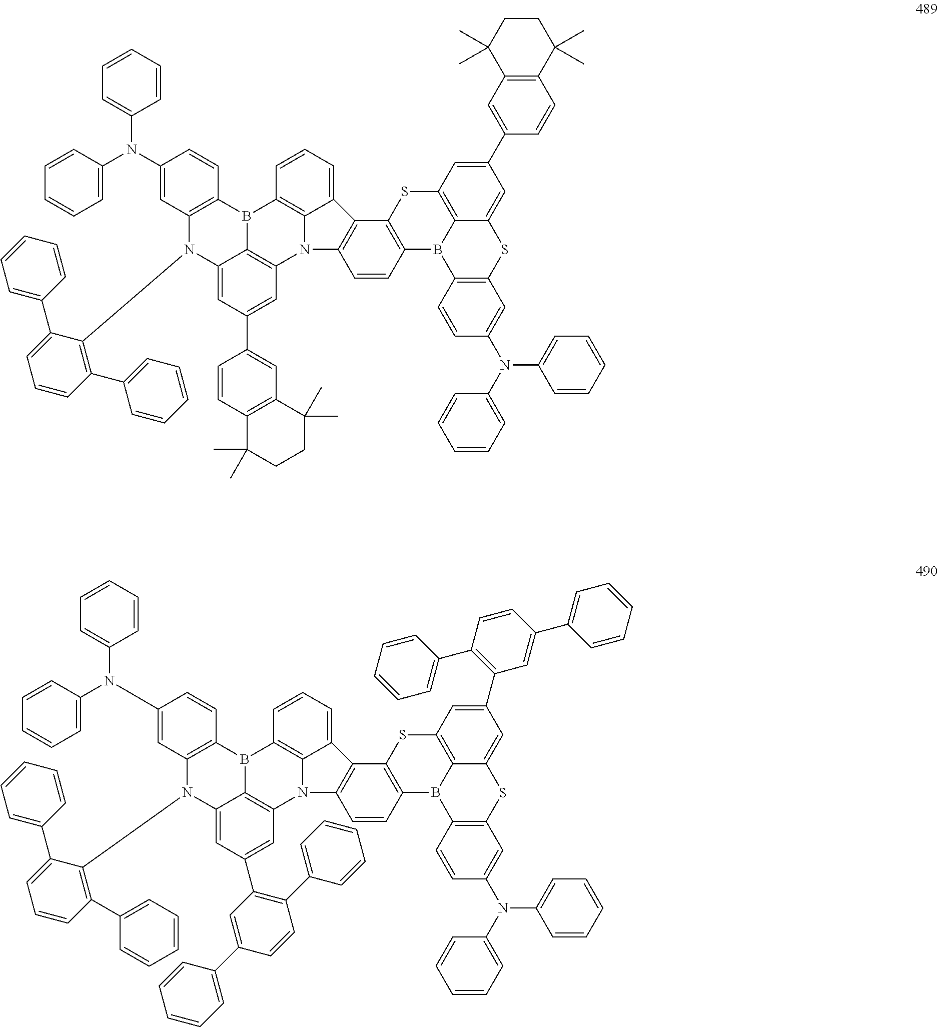 [SMILES: CC1(C)CCC(C)(C)c2cc(-c3cc4c5c(c3)Sc3c(ccc6c3c3cccc7c3n6-c3cc(-c6ccc8c(c6)C(C)(C)CCC8(C)C)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)ccc21 ; c1ccc(-c2ccc(-c3ccccc3)c(-c3cc4c5c(c3)Sc3c(ccc6c3c3cccc7c3n6-c3cc(-c6cc(-c8ccccc8)ccc6-c6ccccc6)cc6c3B7c3ccc(N(c7ccccc7)c7ccccc7)cc3N6c3c(-c6ccccc6)cccc3-c3ccccc3)B5c3ccc(N(c5ccccc5)c5ccccc5)cc3S4)c2)cc1] 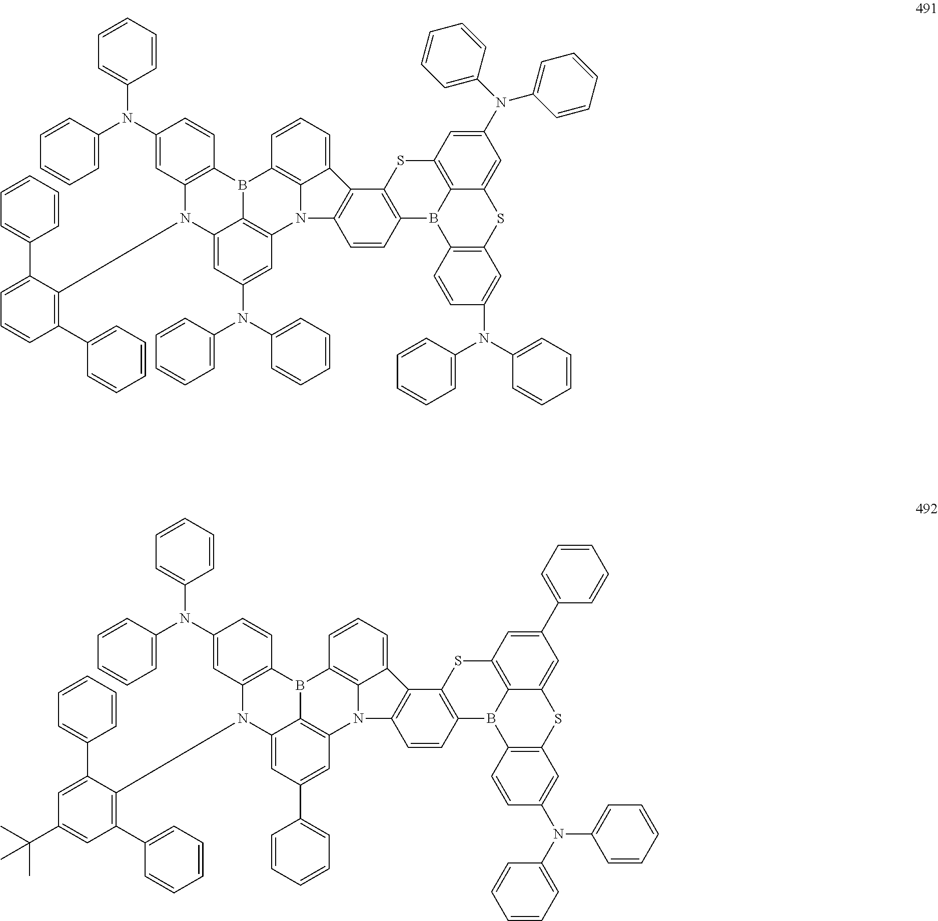 [SMILES: c1ccc(-c2cccc(-c3ccccc3)c2N2c3cc(N(c4ccccc4)c4ccccc4)ccc3B3c4c2cc(N(c2ccccc2)c2ccccc2)cc4-n2c4ccc5c(c4c4cccc3c42)Sc2cc(N(c3ccccc3)c3ccccc3)cc3c2B5c2ccc(N(c4ccccc4)c4ccccc4)cc2S3)cc1 ; CC(C)(C)c1cc(-c2ccccc2)c(N2c3cc(N(c4ccccc4)c4ccccc4)ccc3B3c4c2cc(-c2ccccc2)cc4-n2c4ccc5c(c4c4cccc3c42)Sc2cc(-c3ccccc3)cc3c2B5c2ccc(N(c4ccccc4)c4ccccc4)cc2S3)c(-c2ccccc2)c1] 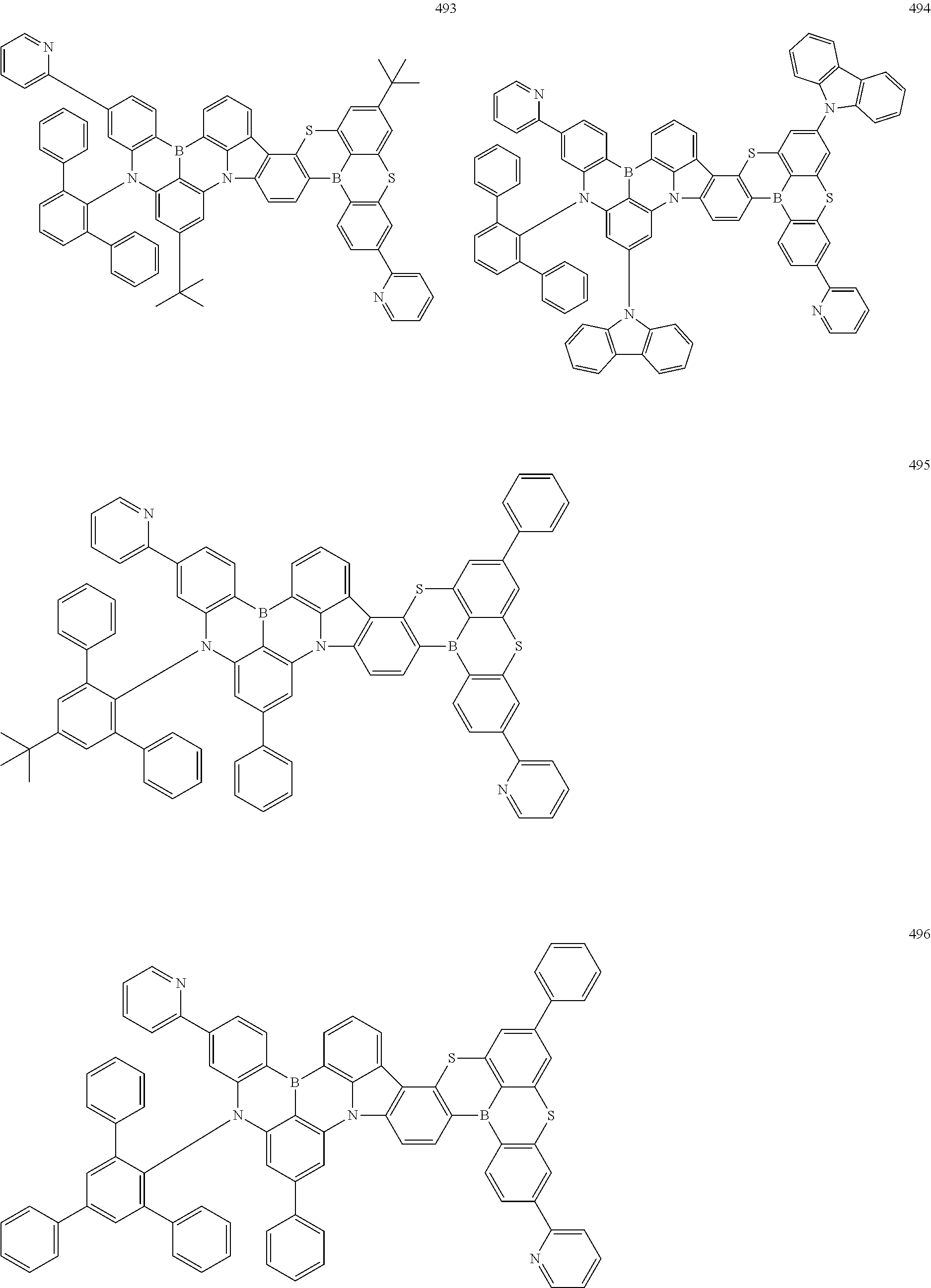 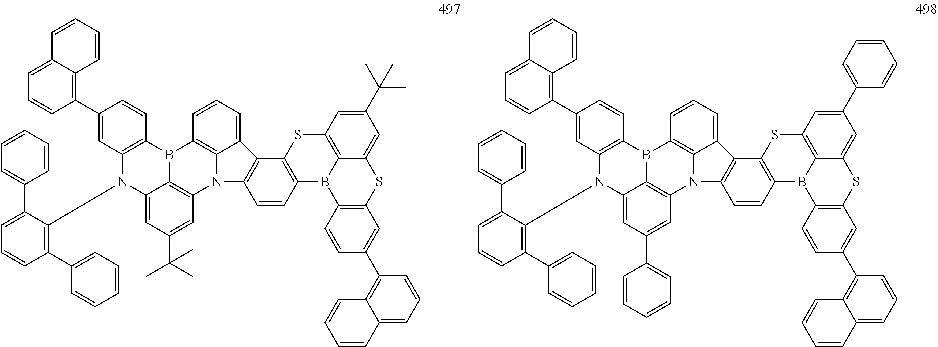 [SMILES: CC(C)(C)c1cc2c3c(c1)Sc1c(ccc4c1c1cccc5c1n4-c1cc(C(C)(C)C)cc4c1B5c1ccc(-c5cccc6ccccc56)cc1N4c1c(-c4ccccc4)cccc1-c1ccccc1)B3c1ccc(-c3cccc4ccccc34)cc1S2 ; c1ccc(-c2cc3c4c(c2)Sc2c(ccc5c2c2cccc6c2n5-c2cc(-c5ccccc5)cc5c2B6c2ccc(-c6cccc7ccccc67)cc2N5c2c(-c5ccccc5)cccc2-c2ccccc2)B4c2ccc(-c4cccc5ccccc45)cc2S3)cc1] 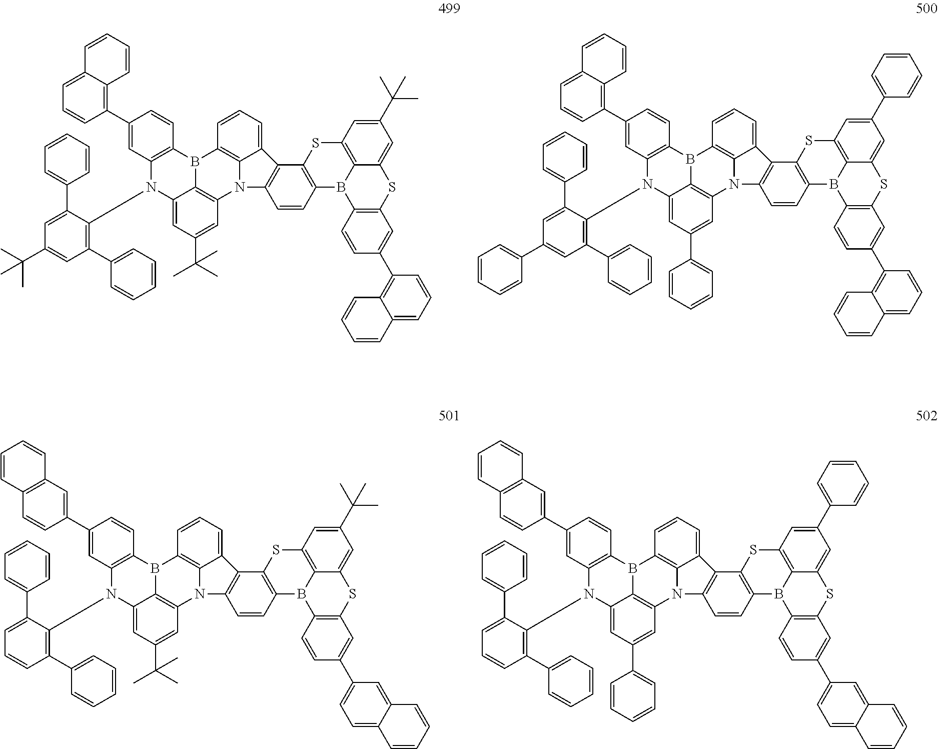 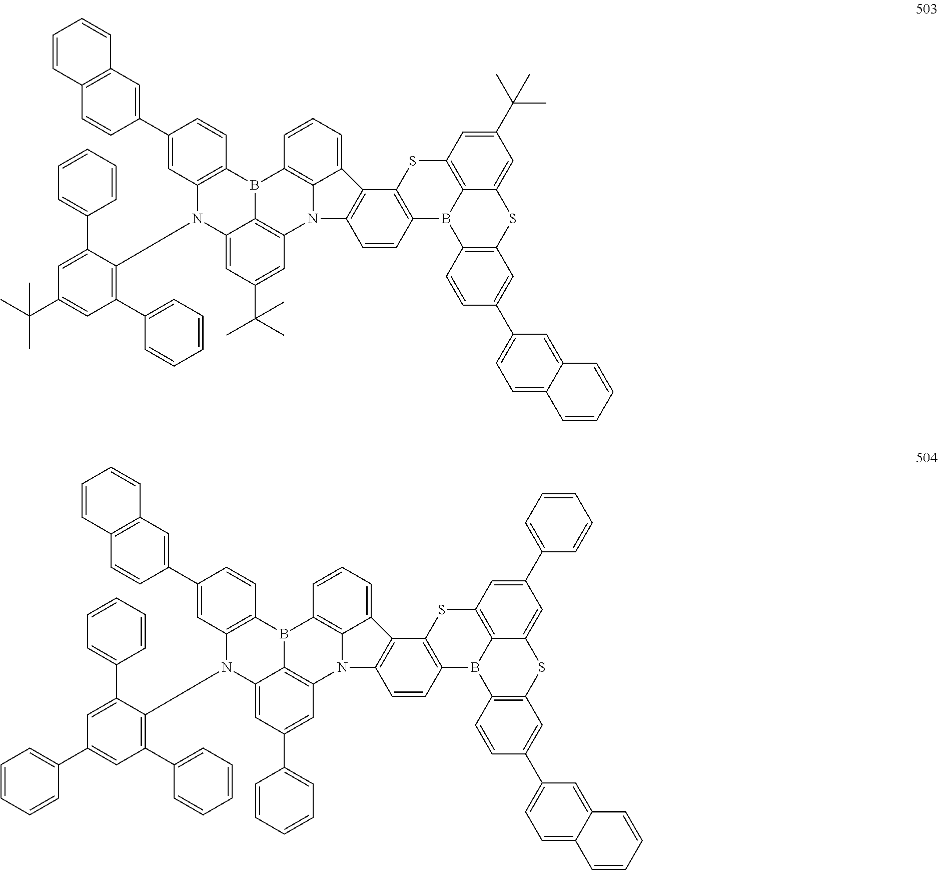 [SMILES: CC(C)(C)c1cc2c3c(c1)Sc1c(ccc4c1c1cccc5c1n4-c1cc(C(C)(C)C)cc4c1B5c1ccc(-c5ccc6ccccc6c5)cc1N4c1c(-c4ccccc4)cc(C(C)(C)C)cc1-c1ccccc1)B3c1ccc(-c3ccc4ccccc4c3)cc1S2 ; c1ccc(-c2cc3c4c(c2)Sc2c(ccc5c2c2cccc6c2n5-c2cc(-c5ccccc5)cc5c2B6c2ccc(-c6ccc7ccccc7c6)cc2N5c2c(-c5ccccc5)cc(-c5ccccc5)cc2-c2ccccc2)B4c2ccc(-c4ccc5ccccc5c4)cc2S3)cc1] 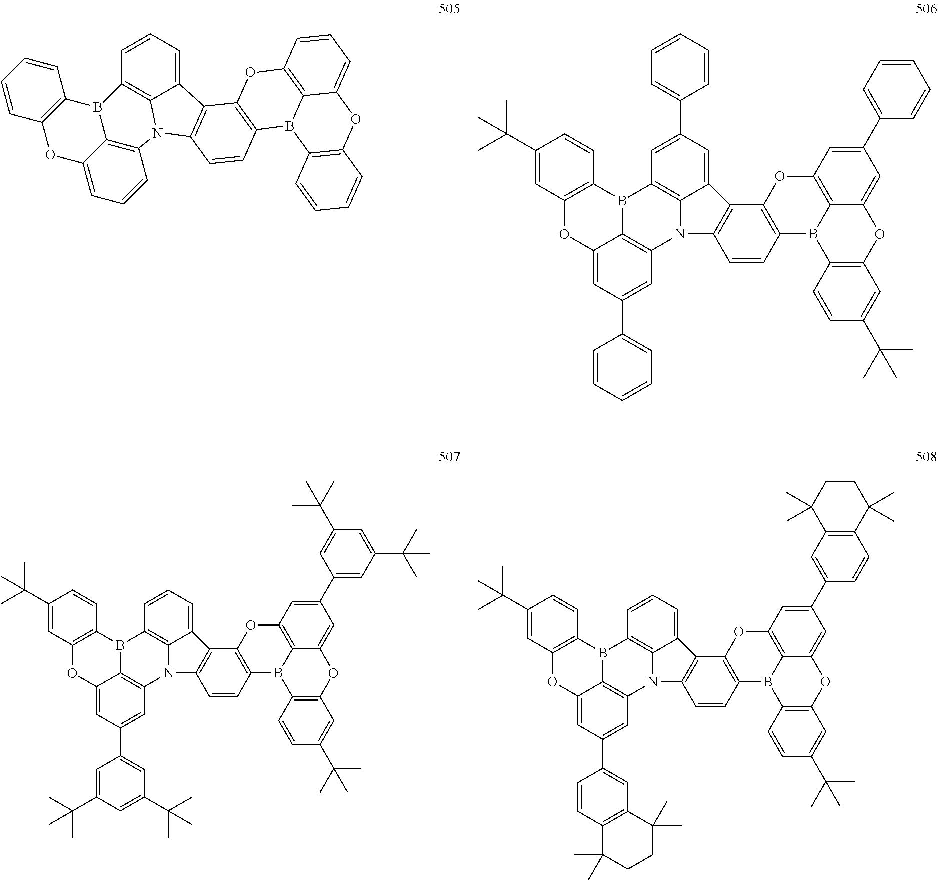 [SMILES: c1ccc2c(c1)Oc1cccc3c1B2c1ccc2c(c1O3)c1cccc3c1n2-c1cccc2c1B3c1ccccc1O2 ; CC(C)(C)c1ccc2c(c1)Oc1cc(-c3ccccc3)cc3c1B2c1ccc2c(c1O3)c1cc(-c3ccccc3)cc3c1n2-c1cc(-c2ccccc2)cc2c1B3c1ccc(C(C)(C)C)cc1O2 ; CC(C)(C)c1cc(-c2cc3c4c(c2)Oc2c(ccc5c2c2cccc6c2n5-c2cc(-c5cc(C(C)(C)C)cc(C(C)(C)C)c5)cc5c2B6c2ccc(C(C)(C)C)cc2O5)B4c2ccc(C(C)(C)C)cc2O3)cc(C(C)(C)C)c1 ; CC(C)(C)c1ccc2c(c1)Oc1cc(-c3ccc4c(c3)C(C)(C)CCC4(C)C)cc3c1B2c1ccc2c(c1O3)c1cccc3c1n2-c1cc(-c2ccc4c(c2)C(C)(C)CCC4(C)C)cc2c1B3c1ccc(C(C)(C)C)cc1O2] 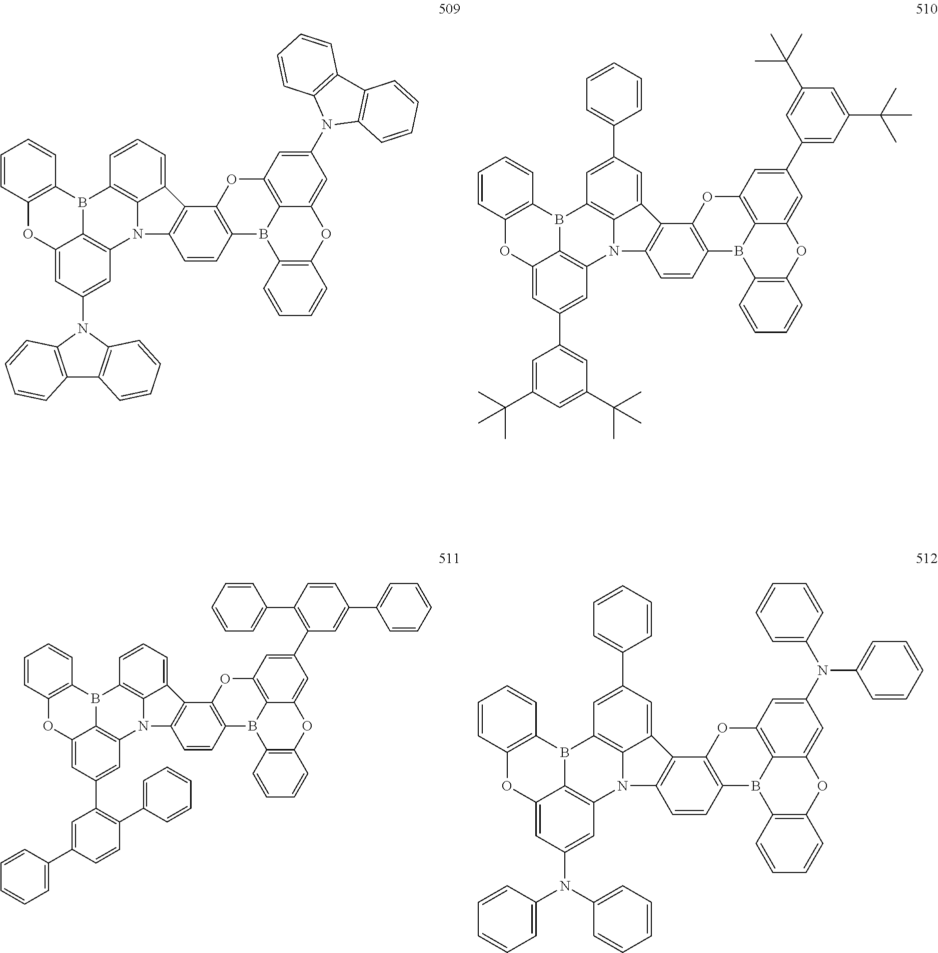 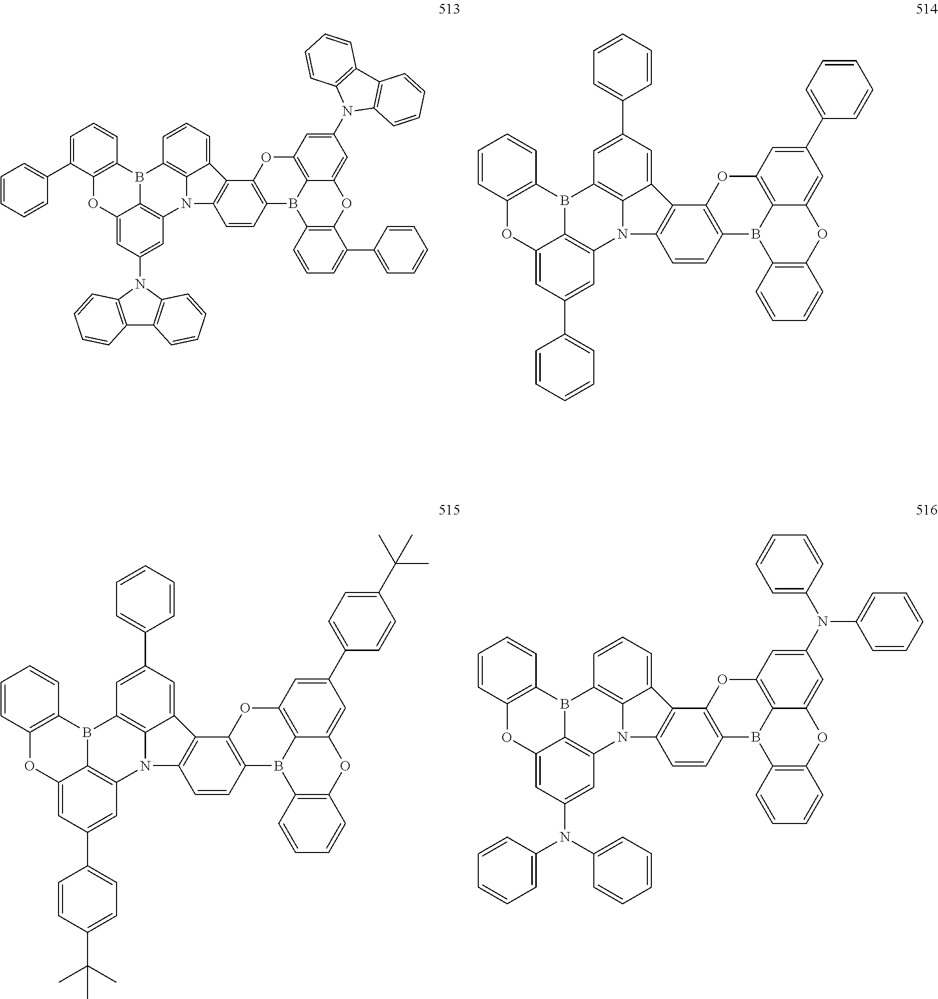 [SMILES: c1ccc(-c2cccc3c2Oc2cc(-n4c5ccccc5c5ccccc54)cc4c2B3c2ccc3c(c2O4)c2cccc4c2n3-c2cc(-n3c5ccccc5c5ccccc53)cc3c2B4c2cccc(-c4ccccc4)c2O3)cc1 ; c1ccc(-c2cc3c4c(c2)Oc2c(ccc5c2c2cc(-c6ccccc6)cc6c2n5-c2cc(-c5ccccc5)cc5c2B6c2ccccc2O5)B4c2ccccc2O3)cc1 ; CC(C)(C)c1ccc(-c2cc3c4c(c2)Oc2c(ccc5c2c2cc(-c6ccccc6)cc6c2n5-c2cc(-c5ccc(C(C)(C)C)cc5)cc5c2B6c2ccccc2O5)B4c2ccccc2O3)cc1 ; c1ccc(N(c2ccccc2)c2cc3c4c(c2)Oc2c(ccc5c2c2cccc6c2n5-c2cc(N(c5ccccc5)c5ccccc5)cc5c2B6c2ccccc2O5)B4c2ccccc2O3)cc1] 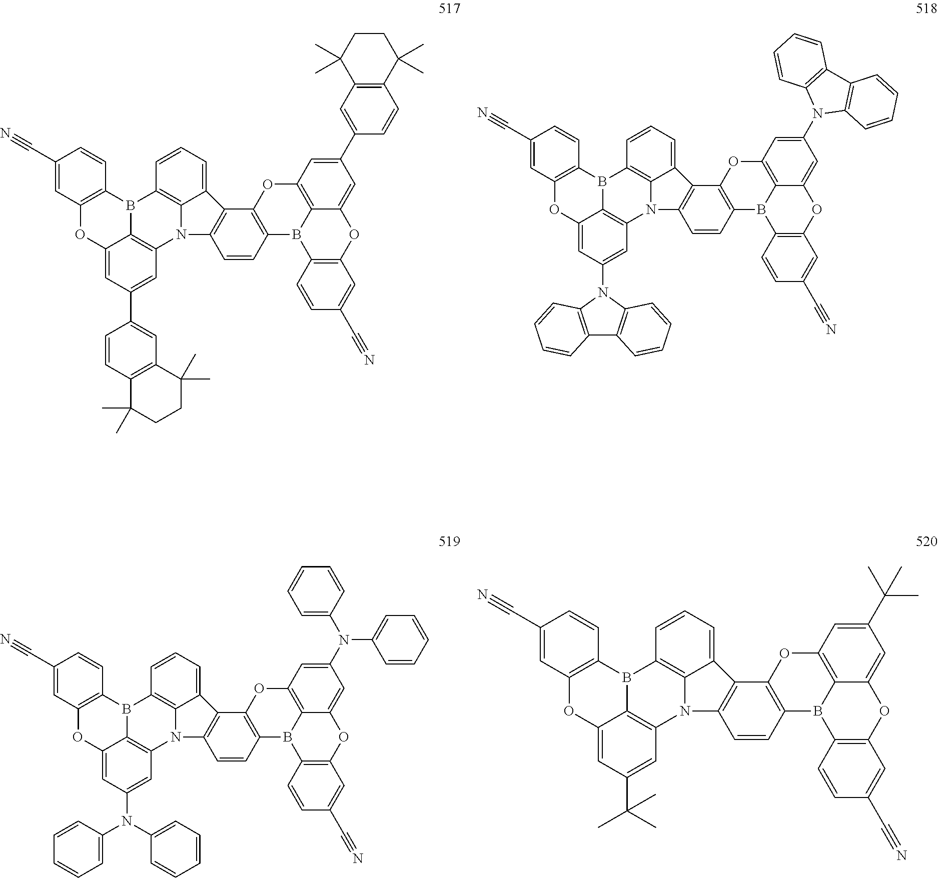 [SMILES: CC1(C)CCC(C)(C)c2cc(-c3cc4c5c(c3)Oc3c(ccc6c3c3cccc7c3n6-c3cc(-c6ccc8c(c6)C(C)(C)CCC8(C)C)cc6c3B7c3ccc(C#N)cc3O6)B5c3ccc(C#N)cc3O4)ccc21 ; N#Cc1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C#N)cc1O2 ; N#Cc1ccc2c(c1)Oc1cc(N(c3ccccc3)c3ccccc3)cc3c1B2c1ccc2c(c1O3)c1cccc3c1n2-c1cc(N(c2ccccc2)c2ccccc2)cc2c1B3c1ccc(C#N)cc1O2 ; CC(C)(C)c1cc2c3c(c1)Oc1c(ccc4c1c1cccc5c1n4-c1cc(C(C)(C)C)cc4c1B5c1ccc(C#N)cc1O4)B3c1ccc(C#N)cc1O2] 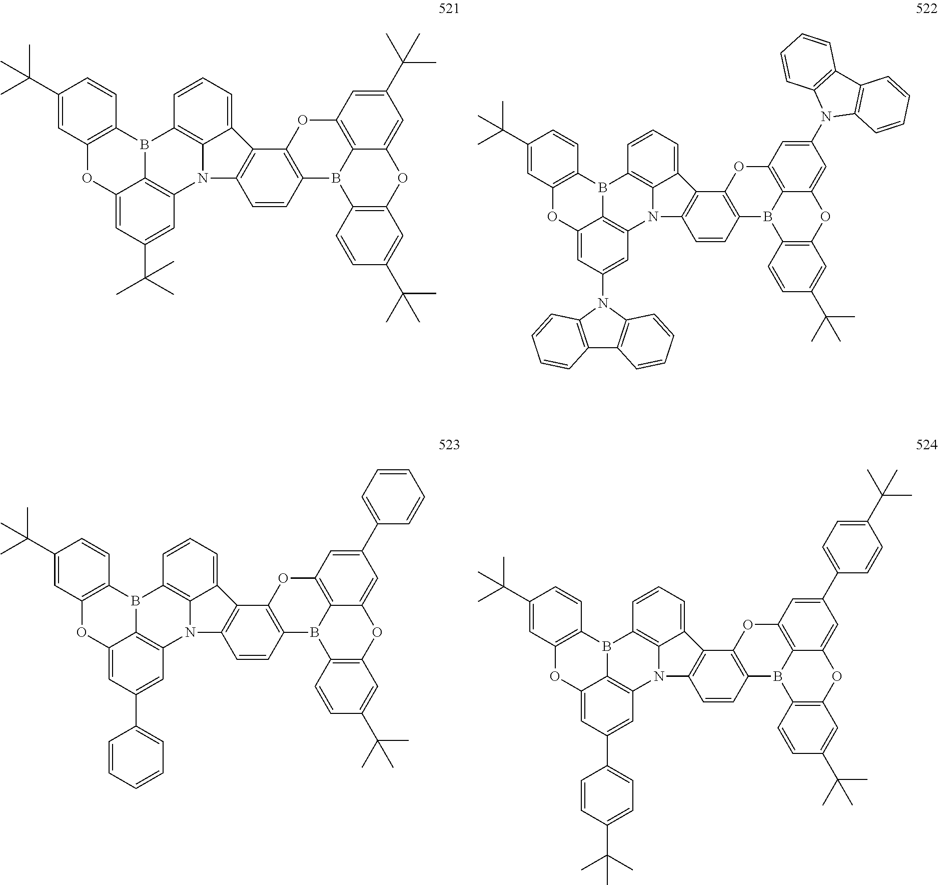 [SMILES: CC(C)(C)c1ccc2c(c1)Oc1cc(C(C)(C)C)cc3c1B2c1ccc2c(c1O3)c1cccc3c1n2-c1cc(C(C)(C)C)cc2c1B3c1ccc(C(C)(C)C)cc1O2 ; CC(C)(C)c1ccc2c(c1)Oc1cc(-n3c4ccccc4c4ccccc43)cc3c1B2c1ccc2c(c1O3)c1cccc3c1n2-c1cc(-n2c4ccccc4c4ccccc42)cc2c1B3c1ccc(C(C)(C)C)cc1O2 ; CC(C)(C)c1ccc2c(c1)Oc1cc(-c3ccccc3)cc3c1B2c1ccc2c(c1O3)c1cccc3c1n2-c1cc(-c2ccccc2)cc2c1B3c1ccc(C(C)(C)C)cc1O2 ; CC(C)(C)c1ccc(-c2cc3c4c(c2)Oc2c(ccc5c2c2cccc6c2n5-c2cc(-c5ccc(C(C)(C)C)cc5)cc5c2B6c2ccc(C(C)(C)C)cc2O5)B4c2ccc(C(C)(C)C)cc2O3)cc1] 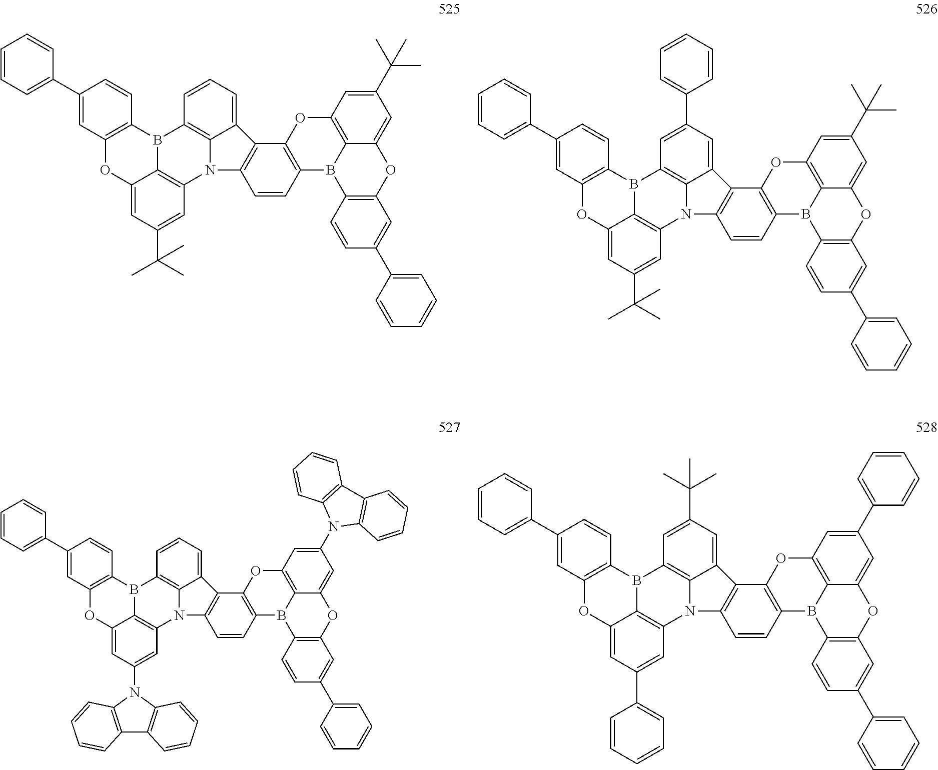 [SMILES: CC(C)(C)c1cc2c3c(c1)Oc1c(ccc4c1c1cccc5c1n4-c1cc(C(C)(C)C)cc4c1B5c1ccc(-c5ccccc5)cc1O4)B3c1ccc(-c3ccccc3)cc1O2 ; CC(C)(C)c1cc2c3c(c1)Oc1c(ccc4c1c1cc(-c5ccccc5)cc5c1n4-c1cc(C(C)(C)C)cc4c1B5c1ccc(-c5ccccc5)cc1O4)B3c1ccc(-c3ccccc3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccc4)cc2O3)cc1 ; CC(C)(C)c1cc2c3c(c1)c1c4c(ccc1n3-c1cc(-c3ccccc3)cc3c1B2c1ccc(-c2ccccc2)cc1O3)B1c2ccc(-c3ccccc3)cc2Oc2cc(-c3ccccc3)cc(c21)O4] 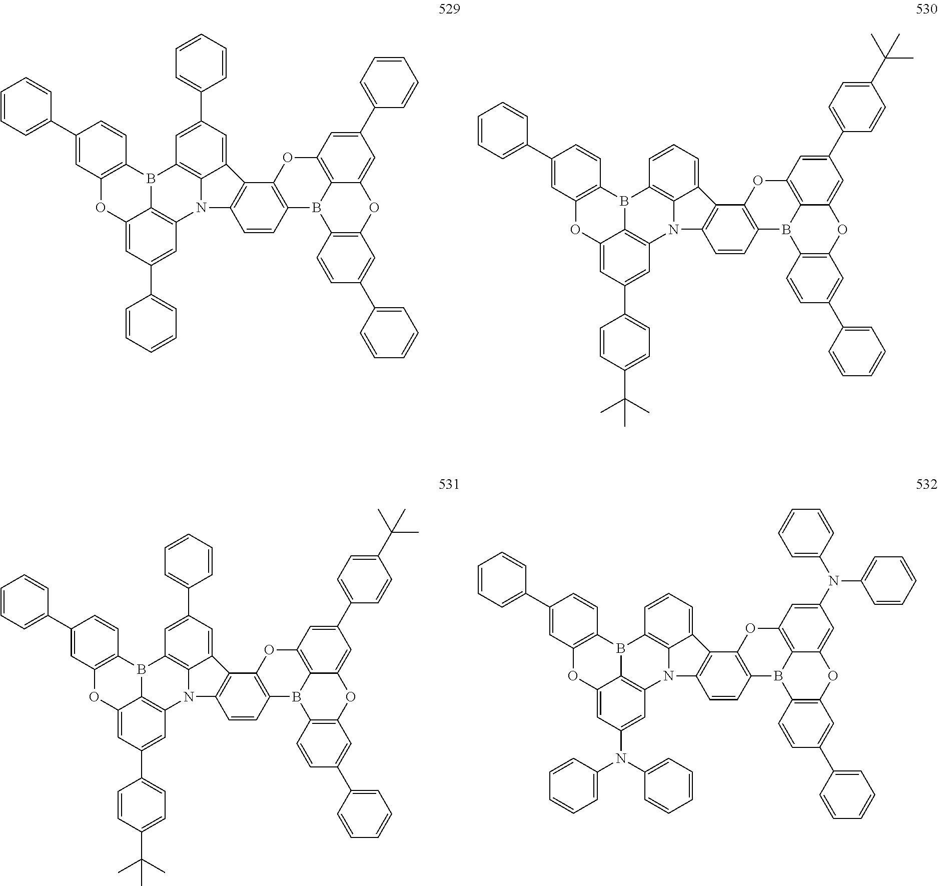 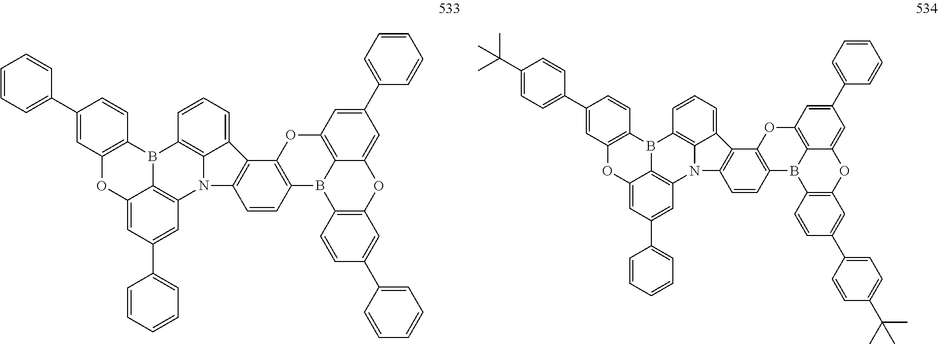 [SMILES: c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccccc4)cc2O3)cc1 ; CC(C)(C)c1ccc(-c2ccc3c(c2)Oc2cc(-c4ccccc4)cc4c2B3c2ccc3c(c2O4)c2cccc4c2n3-c2cc(-c3ccccc3)cc3c2B4c2ccc(-c4ccc(C(C)(C)C)cc4)cc2O3)cc1] 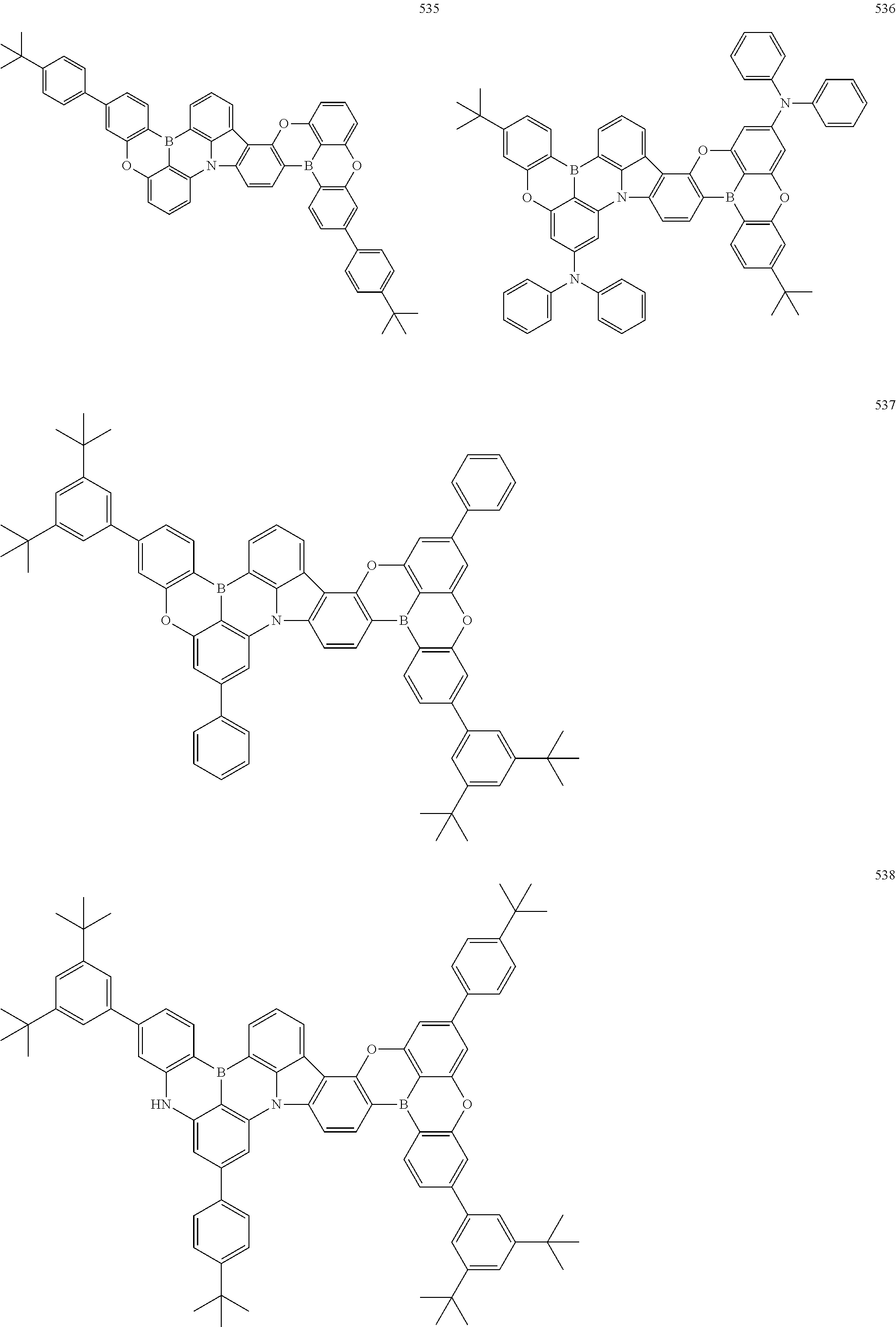 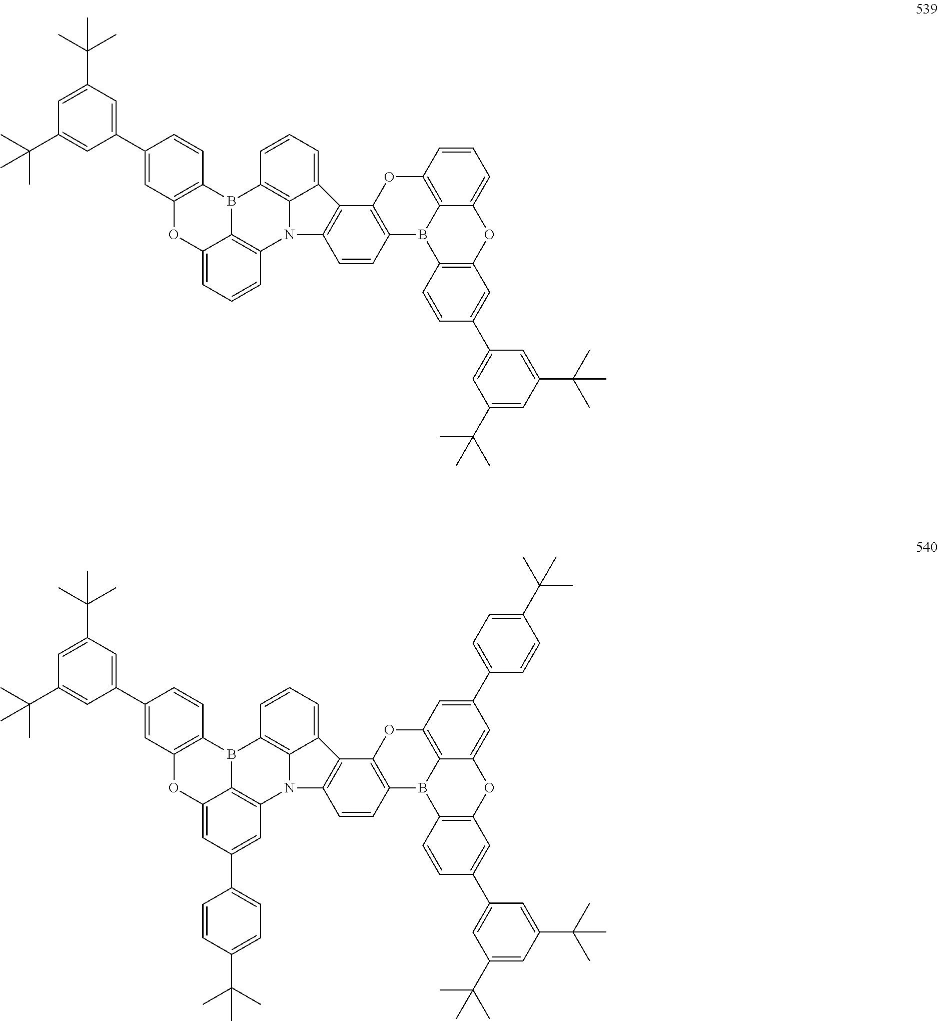 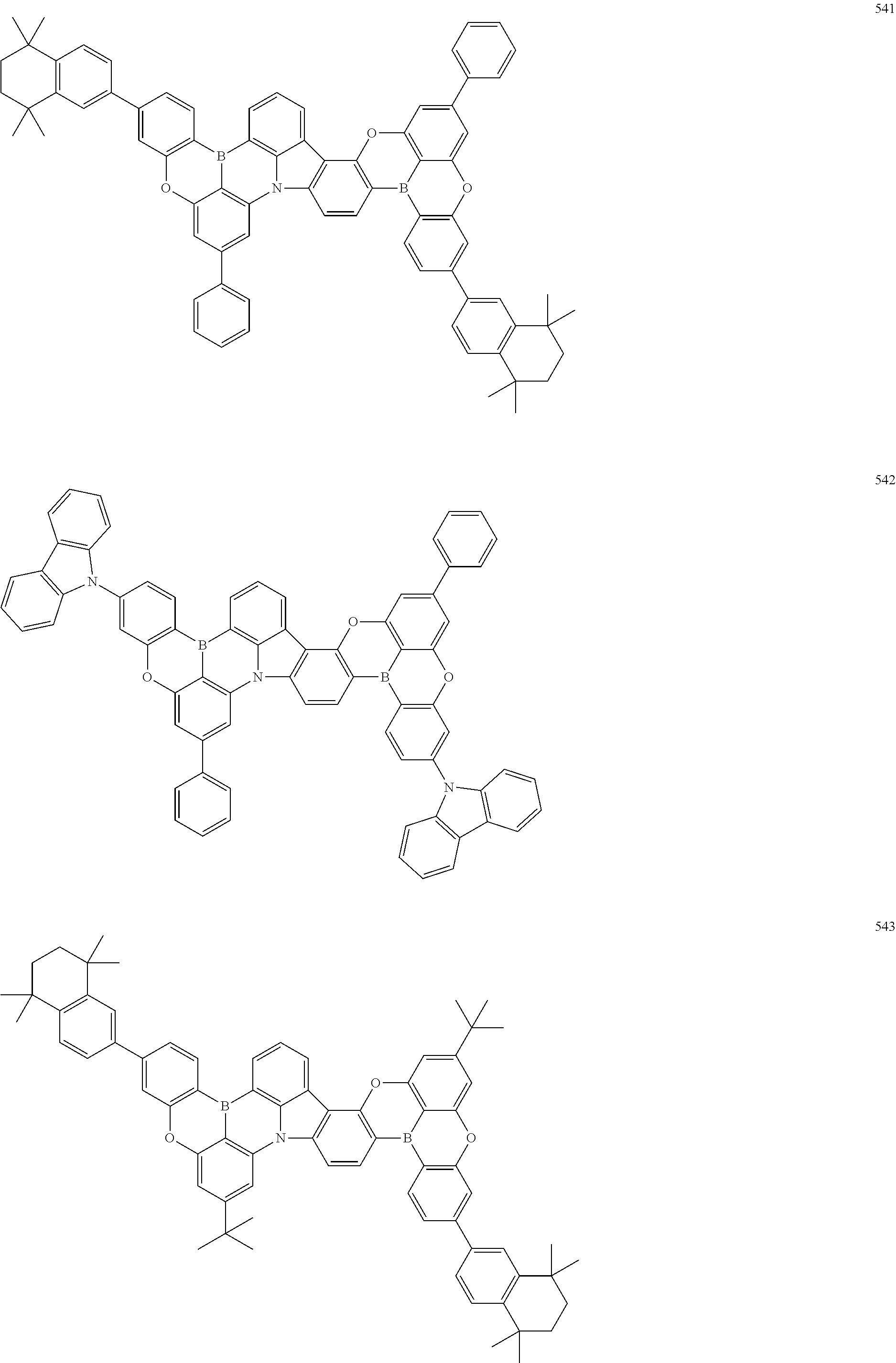 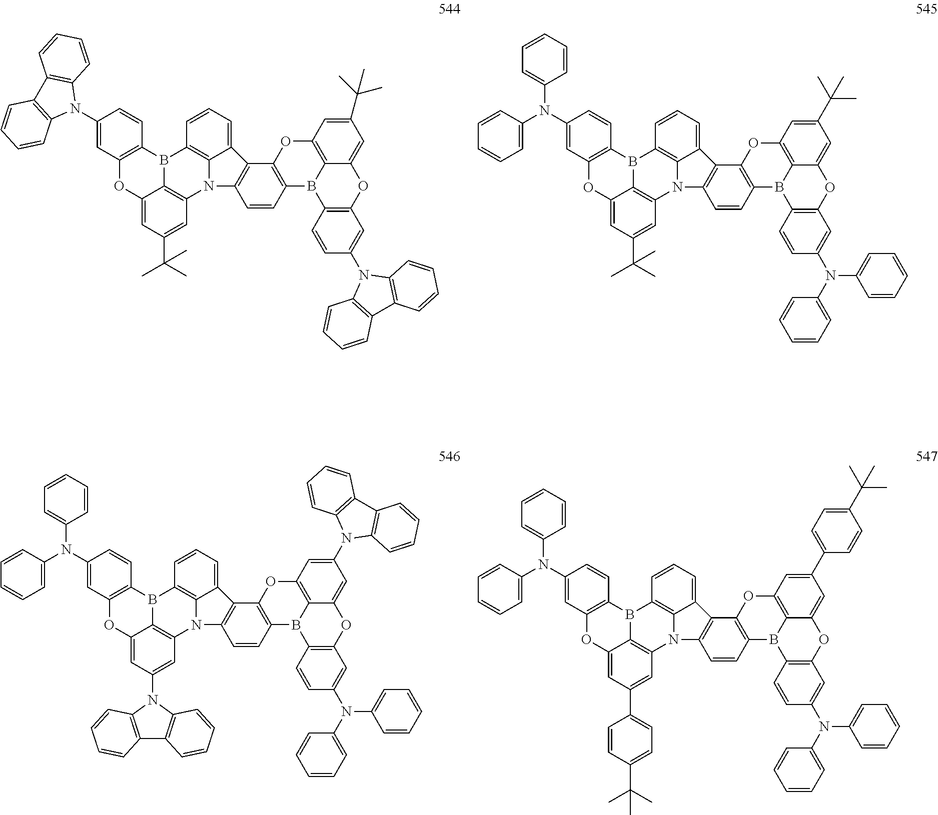 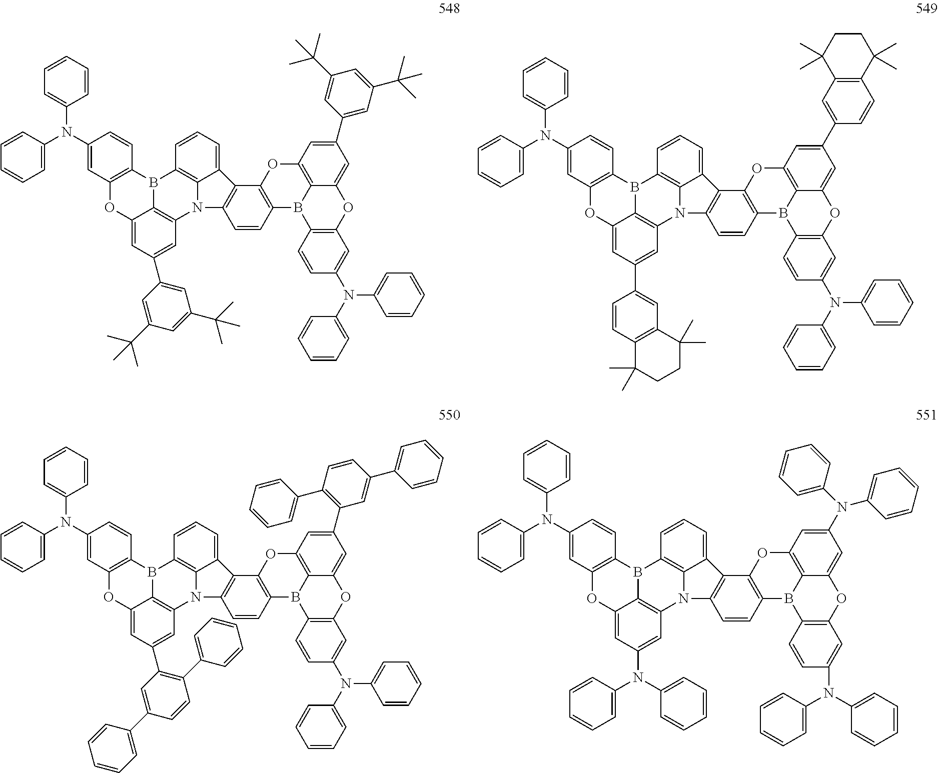 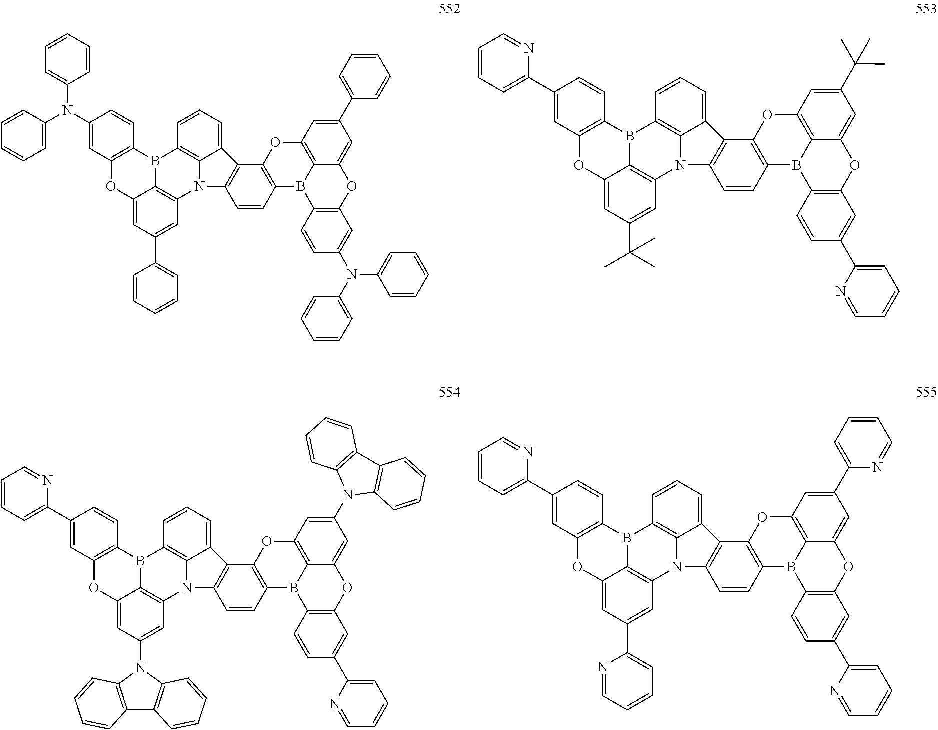 [SMILES: c1ccc(-c2cc3c4c(c2)Oc2c(ccc5c2c2cccc6c2n5-c2cc(-c5ccccc5)cc5c2B6c2ccc(N(c6ccccc6)c6ccccc6)cc2O5)B4c2ccc(N(c4ccccc4)c4ccccc4)cc2O3)cc1 ; CC(C)(C)c1cc2c3c(c1)Oc1c(ccc4c1c1cccc5c1n4-c1cc(C(C)(C)C)cc4c1B5c1ccc(-c5ccccn5)cc1O4)B3c1ccc(-c3ccccn3)cc1O2 ; c1ccc(-c2ccc3c(c2)Oc2cc(-n4c5ccccc5c5ccccc54)cc4c2B3c2ccc3c(c2O4)c2cccc4c2n3-c2cc(-n3c5ccccc5c5ccccc53)cc3c2B4c2ccc(-c4ccccn4)cc2O3)nc1 ; c1ccc(-c2ccc3c(c2)Oc2cc(-c4ccccn4)cc4c2B3c2ccc3c(c2O4)c2cccc4c2n3-c2cc(-c3ccccn3)cc3c2B4c2ccc(-c4ccccn4)cc2O3)nc1] 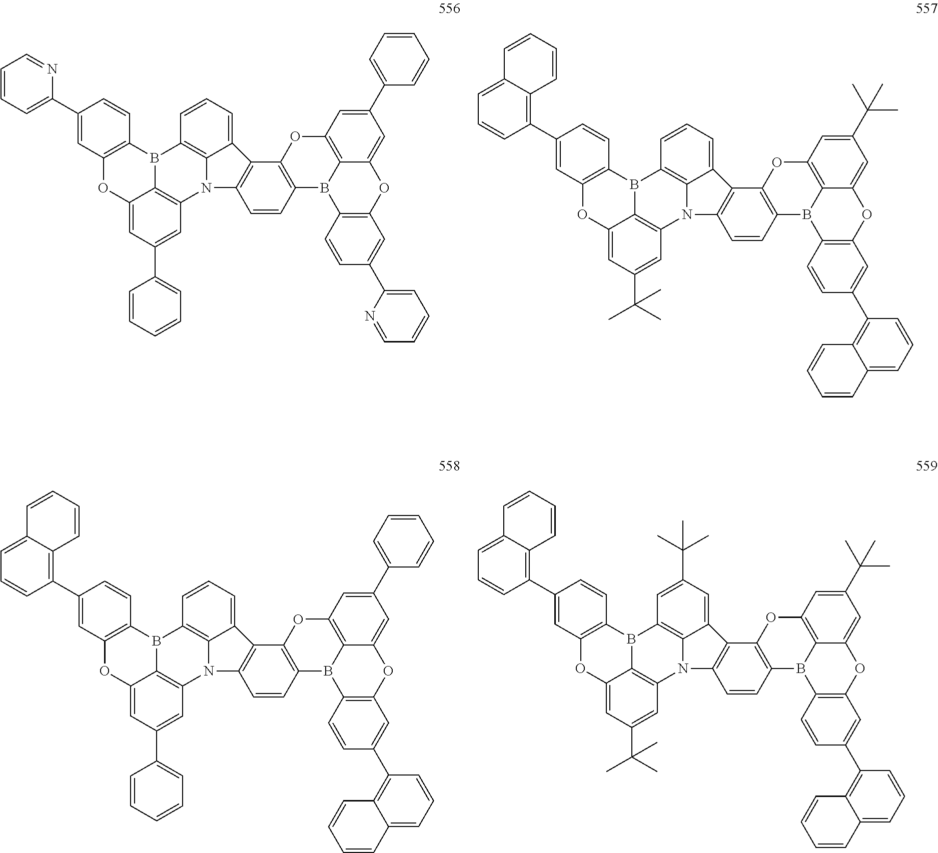 [SMILES: c1ccc(-c2cc3c4c(c2)Oc2c(ccc5c2c2cccc6c2n5-c2cc(-c5ccccc5)cc5c2B6c2ccc(-c6ccccn6)cc2O5)B4c2ccc(-c4ccccn4)cc2O3)cc1 ; CC(C)(C)c1cc2c3c(c1)Oc1c(ccc4c1c1cccc5c1n4-c1cc(C(C)(C)C)cc4c1B5c1ccc(-c5cccc6ccccc56)cc1O4)B3c1ccc(-c3cccc4ccccc34)cc1O2 ; c1ccc(-c2cc3c4c(c2)Oc2c(ccc5c2c2cccc6c2n5-c2cc(-c5ccccc5)cc5c2B6c2ccc(-c6cccc7ccccc67)cc2O5)B4c2ccc(-c4cccc5ccccc45)cc2O3)cc1 ; CC(C)(C)c1cc2c3c(c1)Oc1c(ccc4c1c1cc(C(C)(C)C)cc5c1n4-c1cc(C(C)(C)C)cc4c1B5c1ccc(-c5cccc6ccccc56)cc1O4)B3c1ccc(-c3cccc4ccccc34)cc1O2] 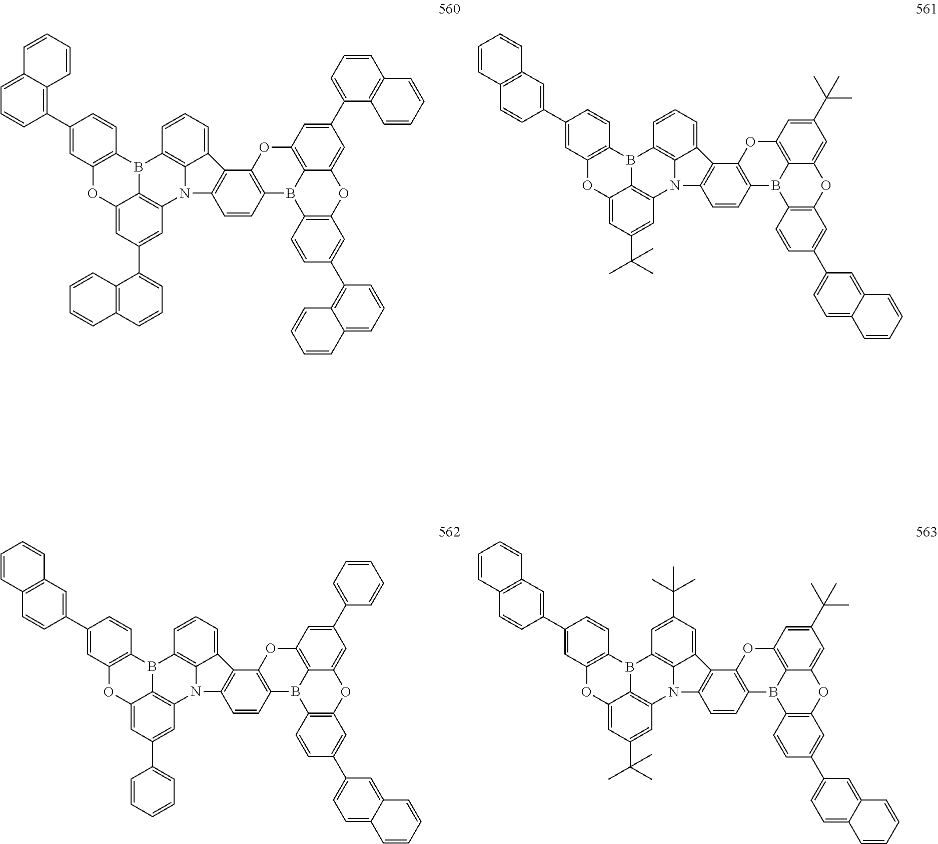 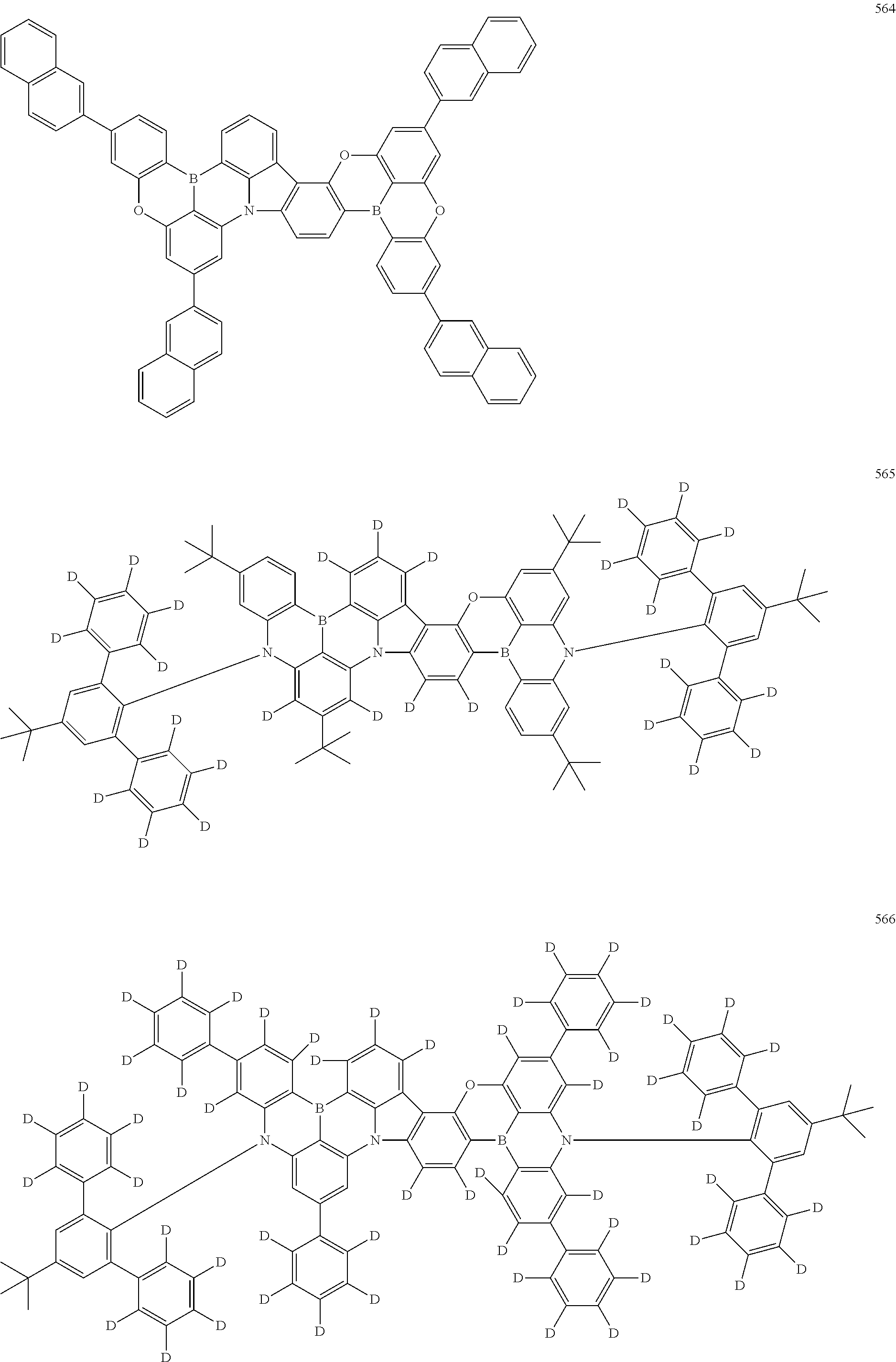 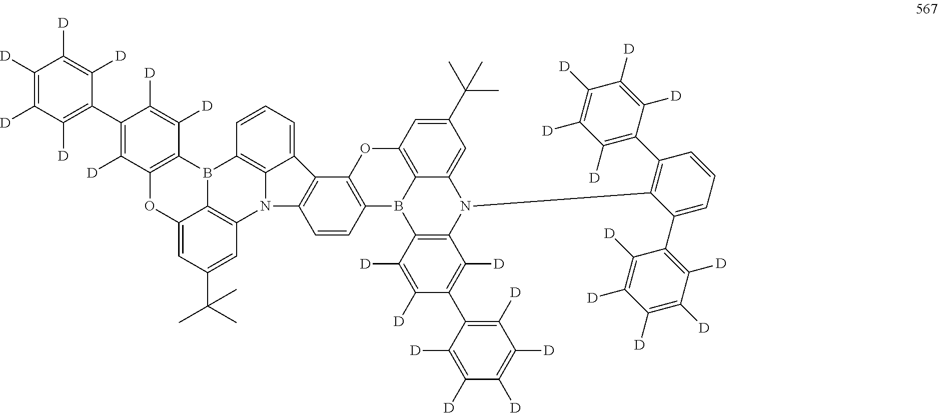 [SMILES: [2H]c1c([2H])c([2H])c(-c2cccc(-c3c([2H])c([2H])c([2H])c([2H])c3[2H])c2N2c3cc(C(C)(C)C)cc4c3B(c3ccc5c(c3O4)c3cccc4c3n5-c3cc(C(C)(C)C)cc5c3B4c3c([2H])c([2H])c(-c4c([2H])c([2H])c([2H])c([2H])c4[2H])c([2H])c3O5)c3c([2H])c([2H])c(-c4c([2H])c([2H])c([2H])c([2H])c4[2H])c([2H])c32)c([2H])c1[2H]] 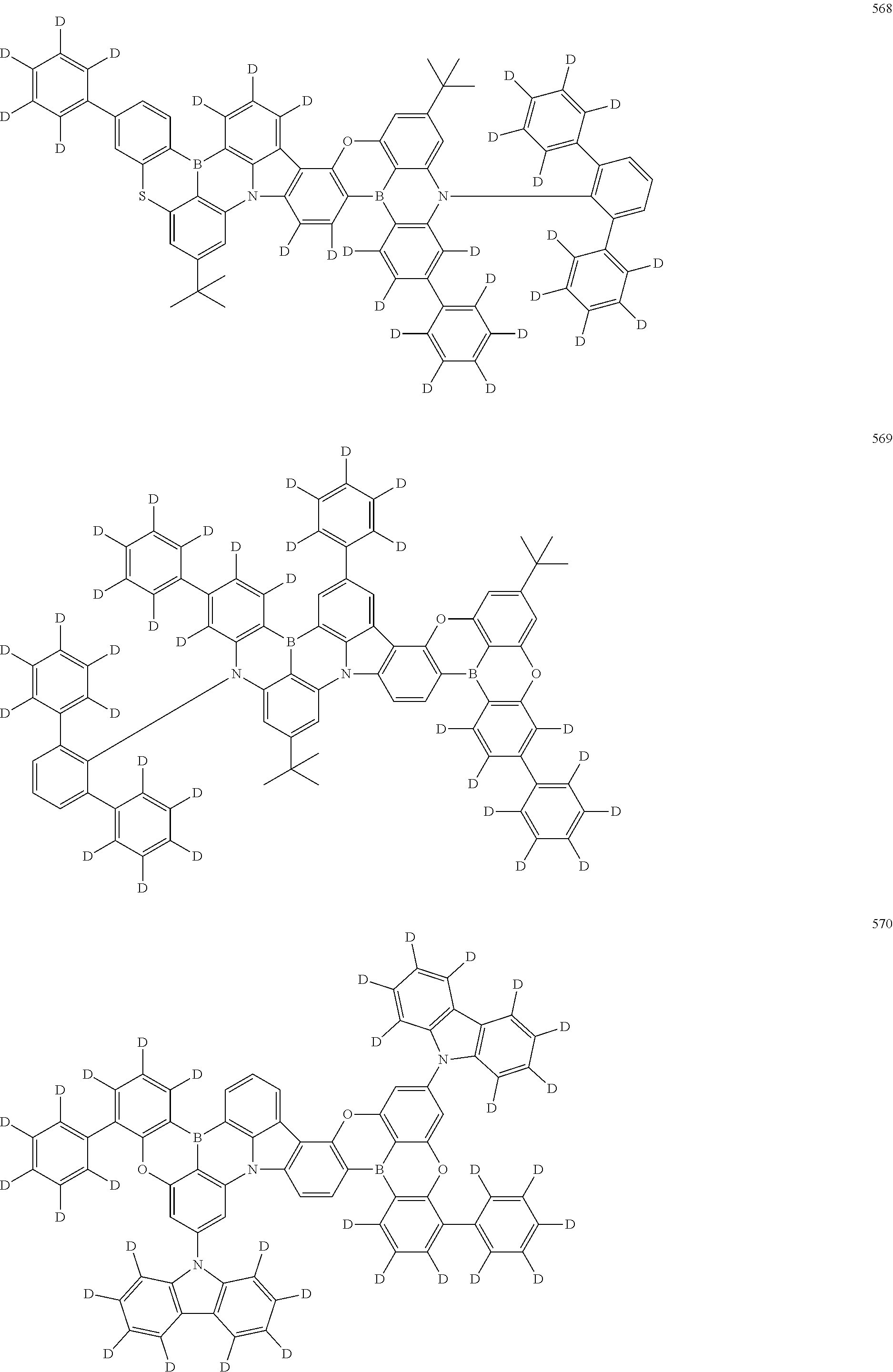 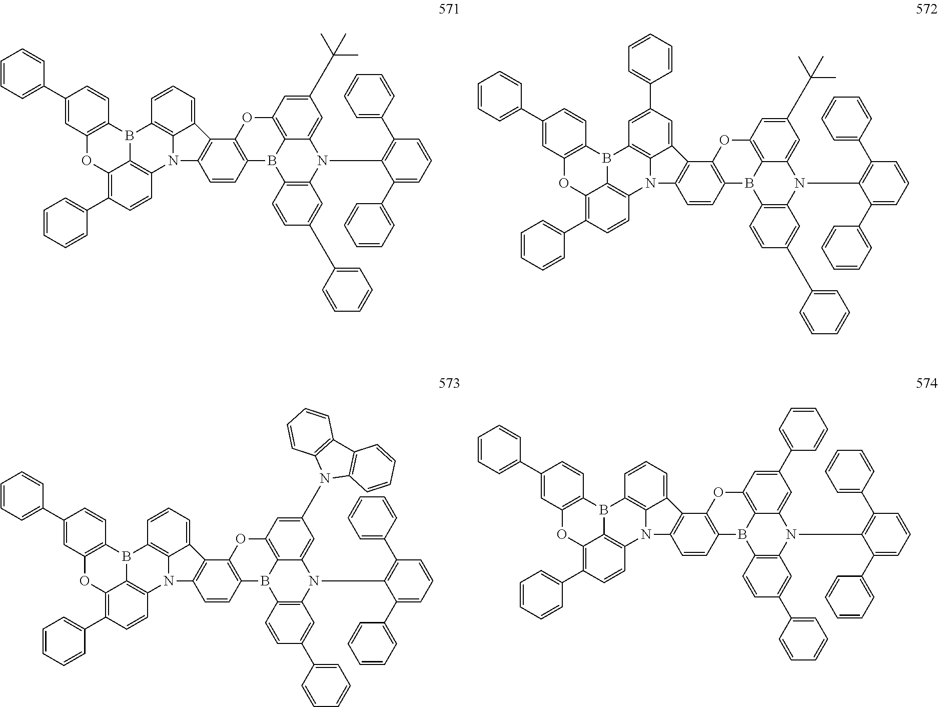 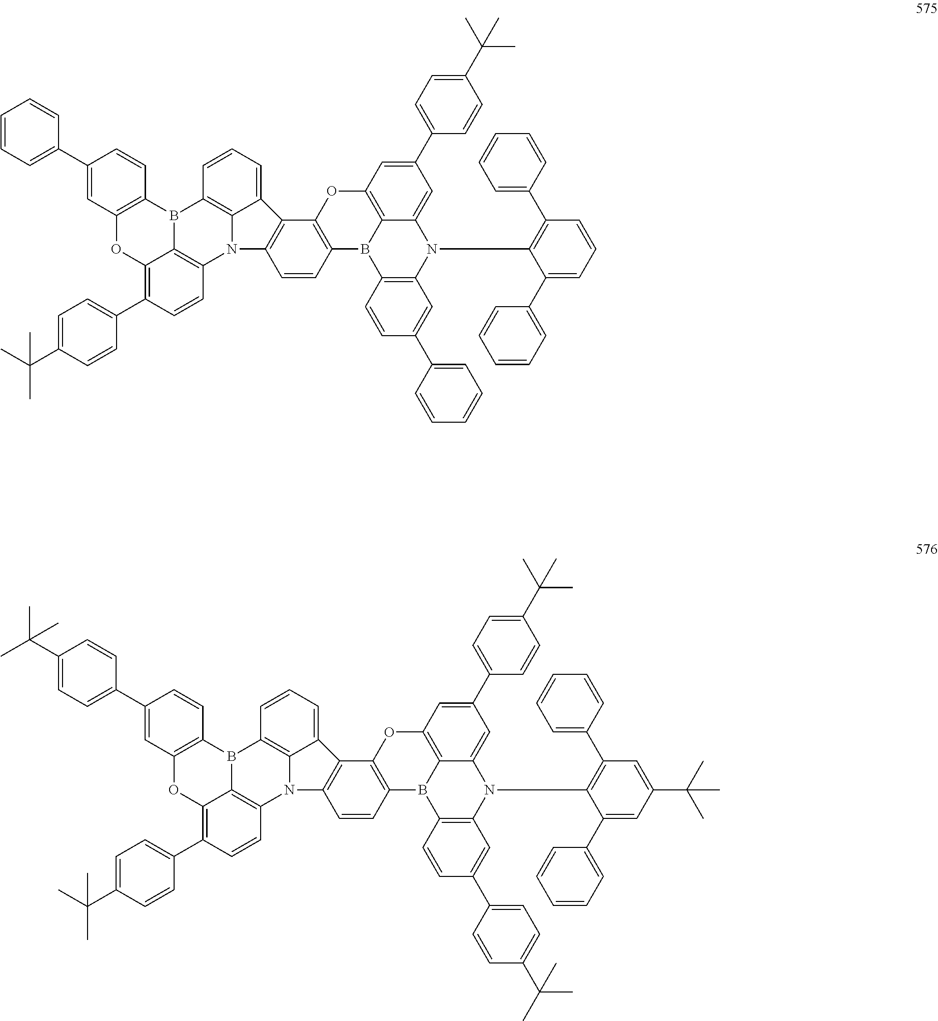 [SMILES: CC(C)(C)c1ccc(-c2cc3c4c(c2)N(c2c(-c5ccccc5)cccc2-c2ccccc2)c2cc(-c5ccccc5)ccc2B4c2ccc4c(c2O3)c2cccc3c2n4-c2ccc(-c4ccc(C(C)(C)C)cc4)c4c2B3c2ccc(-c3ccccc3)cc2O4)cc1 ; CC(C)(C)c1ccc(-c2ccc3c(c2)Oc2c(-c4ccc(C(C)(C)C)cc4)ccc4c2B3c2cccc3c5c6c(ccc5n-4c23)B2c3ccc(-c4ccc(C(C)(C)C)cc4)cc3N(c3c(-c4ccccc4)cc(C(C)(C)C)cc3-c3ccccc3)c3cc(-c4ccc(C(C)(C)C)cc4)cc(c32)O6)cc1] 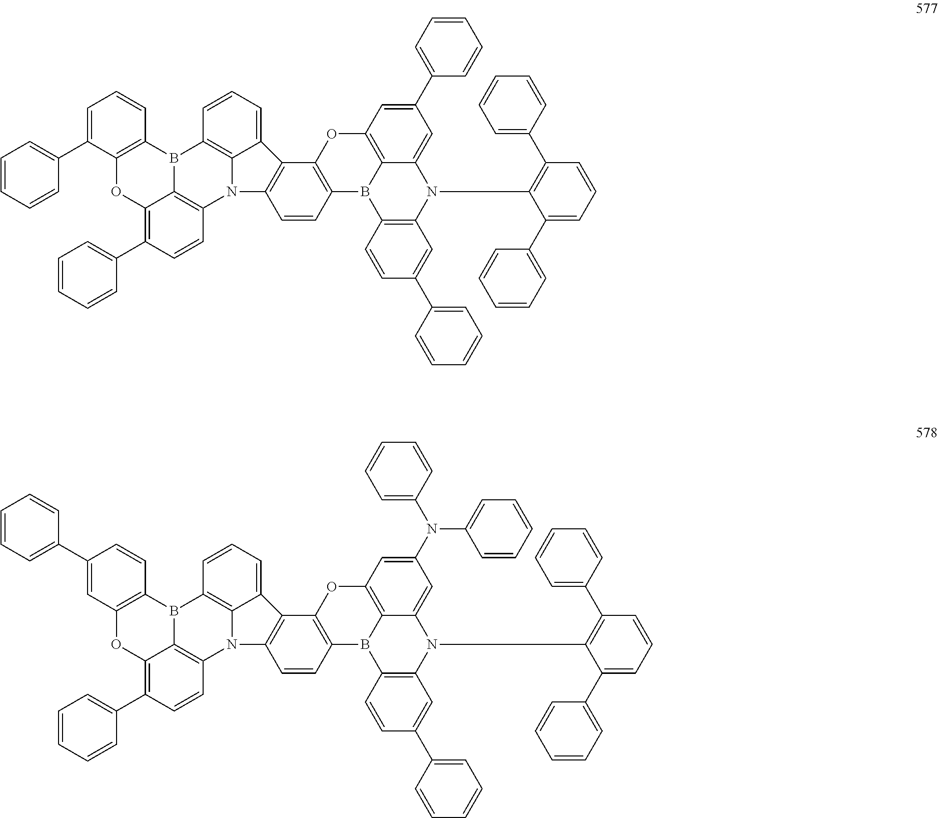 [SMILES: c1ccc(-c2ccc3c(c2)N(c2c(-c4ccccc4)cccc2-c2ccccc2)c2cc(-c4ccccc4)cc4c2B3c2ccc3c(c2O4)c2cccc4c2n3-c2ccc(-c3ccccc3)c3c2B4c2cccc(-c4ccccc4)c2O3)cc1 ; c1ccc(-c2ccc3c(c2)Oc2c(-c4ccccc4)ccc4c2B3c2cccc3c5c6c(ccc5n-4c23)B2c3ccc(-c4ccccc4)cc3N(c3c(-c4ccccc4)cccc3-c3ccccc3)c3cc(N(c4ccccc4)c4ccccc4)cc(c32)O6)cc1] 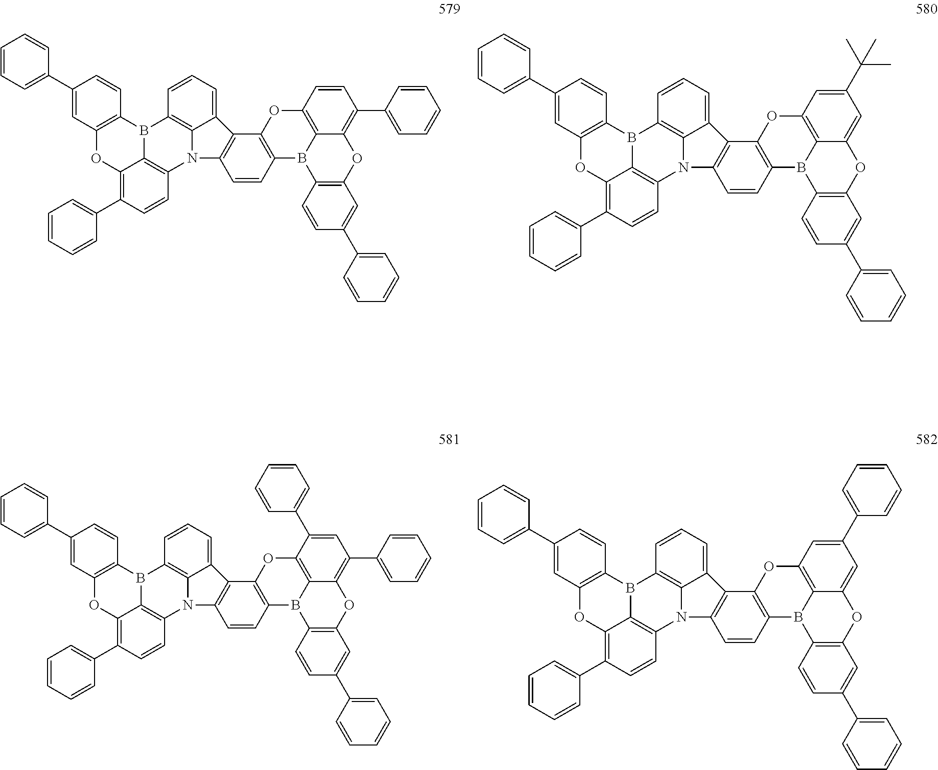 [SMILES: c1ccc(-c2ccc3c(c2)Oc2c(-c4ccccc4)ccc4c2B3c2ccc3c(c2O4)c2cccc4c2n3-c2ccc(-c3ccccc3)c3c2B4c2ccc(-c4ccccc4)cc2O3)cc1 ; CC(C)(C)c1cc2c3c(c1)Oc1c(ccc4c1c1cccc5c1n4-c1ccc(-c4ccccc4)c4c1B5c1ccc(-c5ccccc5)cc1O4)B3c1ccc(-c3ccccc3)cc1O2 ; c1ccc(-c2ccc3c(c2)Oc2c(-c4ccccc4)cc(-c4ccccc4)c4c2B3c2ccc3c(c2O4)c2cccc4c2n3-c2ccc(-c3ccccc3)c3c2B4c2ccc(-c4ccccc4)cc2O3)cc1 ; c1ccc(-c2ccc3c(c2)Oc2cc(-c4ccccc4)cc4c2B3c2ccc3c(c2O4)c2cccc4c2n3-c2ccc(-c3ccccc3)c3c2B4c2ccc(-c4ccccc4)cc2O3)cc1] 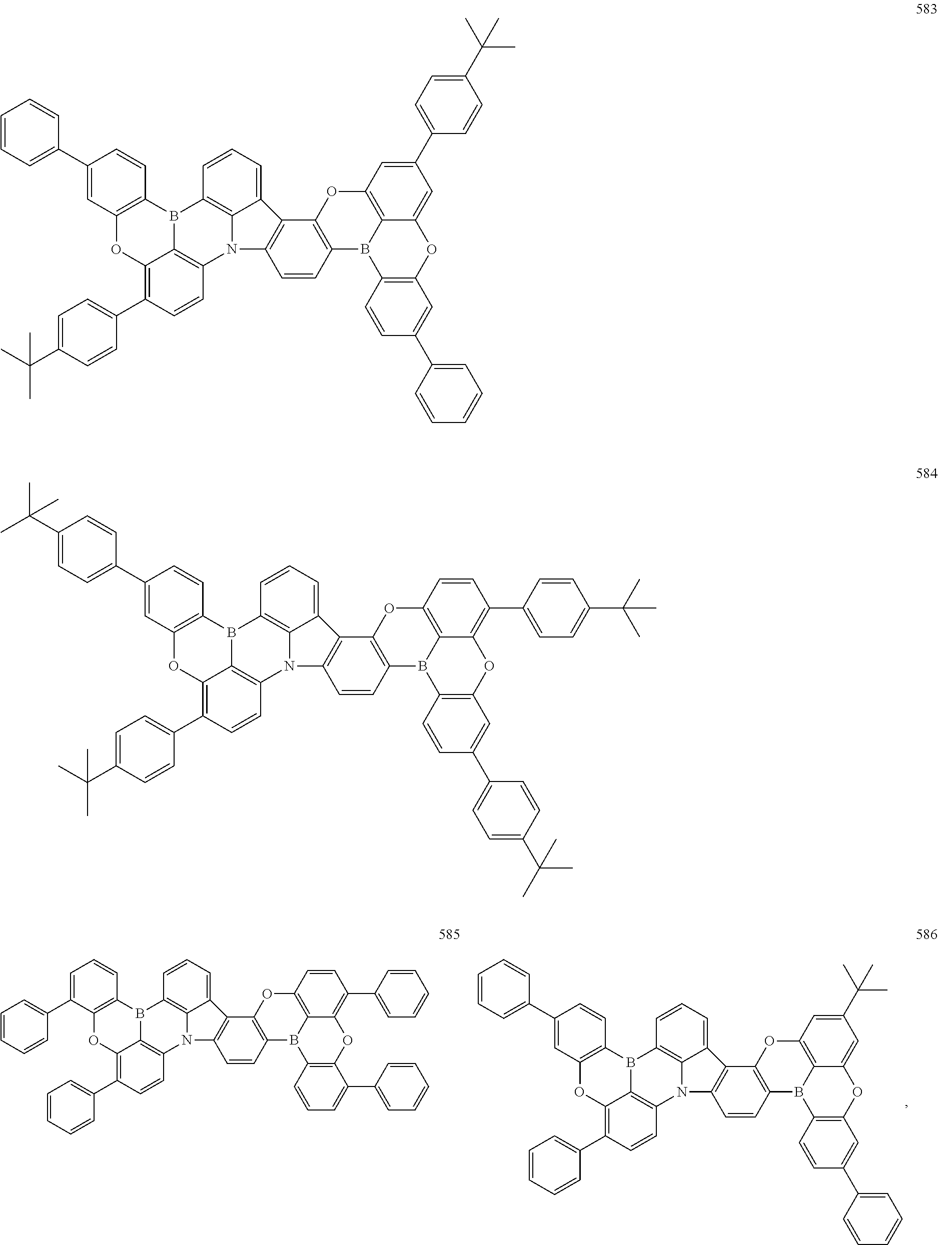
and
wherein, in Compound Group 1, D is a deuterium atom.

19. An electronic apparatus comprising a display device to provide an image,
wherein the display device comprises:
a base layer;
a circuit layer on the base layer; and
a display element layer on the circuit layer and comprising a light-emitting element,
the light-emitting element comprises a first electrode, a second electrode on the first electrode, and an emission layer between the first electrode and the second electrode, and
the emission layer comprises a fused polycyclic compound represented by Formula 1: 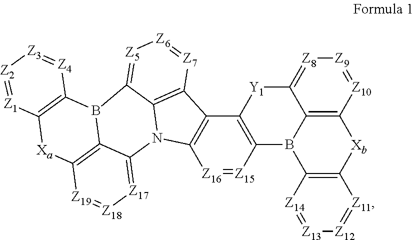
and
wherein, in Formula 1,
Xₐ, X_{b}, and Y₁ are each independently O, S, or NRₓ,
Z₁ to Z₁₉ are each independently N or CR_{y},
Rₓ and R_{y} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, and/or are bonded to an adjacent group to form a ring, and
the fused polycyclic compound comprises a chemical structure in which one or more hydrogen atoms of the fused polycyclic compound are optionally substituted with deuterium atom.

20. The electronic apparatus as claimed in claim 19, further comprising at least one selected from among a processor, a memory, and a power module.
